(19) United States
(12) Patent Application Publication
(10) Pub. No.: US 2024/0251585 A1
(43) Pub. Date: Jul. 25, 2024

(54) ORGANIC ELECTROLUMINESCENT ELEMENT, ORGANIC ELECTROLUMINESCENT DISPLAY APPARATUS, AND ELECTRONIC DEVICE

(71) Applicant: IDEMITSU KOSAN CO.,LTD., Tokyo (JP)

(72) Inventors: Tetsuya MASUDA, Tokyo (JP); Satomi TASAKI, Tokyo (JP); Hiroaki TOYOSHIMA, Tokyo (JP); Masato NAKAMURA, Tokyo (JP); Kazuki NISHIMURA, Tokyo (JP); Hiroaki ITOI, Tokyo (JP); Emiko KAMBE, Tokyo (JP)

(73) Assignee: IDEMITSU KOSAN CO.,LTD., Tokyo (JP)

(21) Appl. No.: 18/288,147

(22) PCT Filed: Apr. 26, 2022
(86) PCT No.: PCT/JP2022/018803

§ 371 Date: Feb. 26, 2024

(30) Foreign Application Priority Data
Apr. 26, 2021 (JP) 2021-074498

(51) Int. Cl. H10K 50/13; H10K 50/15; H10K 59/35; H10K 101/60

(52) U.S. Cl. CPC H10K 50/131; H10K 50/156; H10K 59/35; H10K 2101/60

(57) ABSTRACT

An organic EL device includes: an anode; a cathode; an emitting region; and a hole transporting zone, in which the emitting region includes a first emitting layer containing a first host material and a second emitting layer containing a second host material, at least one organic layer in the hole transporting zone is a first organic layer, the first organic layer contains a hole transporting zone material, the first emitting layer is disposed close to the anode, and a triplet energy of the first host material T₁(H1) and a triplet energy of the second host material T₁(H2) satisfy Numerical Formula 1, and a dipole of the first host material is 0.4 D or more,

T₁(H1)>T₁(H2) (Numerical Formula 1).

### TECHNICAL FIELD

The present invention relates to an organic electroluminescence device, an organic electroluminescence display device, and an electronic device.

### BACKGROUND ART

An organic electroluminescence device (hereinafter, occasionally referred to as “organic EL device”) has found its application in a full-color display for mobile phones, televisions, and the like. When voltage is applied to an organic EL device, holes are injected from an anode and electrons are injected from a cathode into an emitting layer. The injected holes and electrons are recombined in the emitting layer to form excitons. Specifically, according to the electron spin statistics theory, singlet excitons and triplet excitons are generated at a ratio of 25%:75%.

In order to enhance performance of the organic EL device, for instance, layering a plurality of emitting layers has been studied in Patent Literatures 1 and 2. Further, in order to enhance performance of the organic EL device, Patent Literature 3 describes a phenomenon in which a singlet exciton is generated by collision and fusion of two triplet excitons (hereinafter, occasionally referred to as a Triplet-Triplet Fusion (TTF) phenomenon).

The performance of the organic EL device is evaluable in terms of, for instance, luminance, emission wavelength, chromaticity, luminous efficiency, drive voltage, and lifetime.

### CITATION LIST

### Patent Literature(s)

Patent Literature 1 JP 2007-294261 A
Patent Literature 2 US Patent Application Publication No. 2019/280209
Patent Literature 3 International Publication No. WO 2010/134350

### SUMMARY OF THE INVENTION

### Problem(s) to be Solved by the Invention

An organic electroluminescence device described in Patent Literature 1 includes a plurality of emitting layers between an anode and a cathode, characterized in that: adjacent ones of the emitting layers are each formed from a mixture of a plurality of materials and have different main components; the adjacent ones of the emitting layers are constituted by a combination in which a value obtained by dividing an electron mobility by a hole mobility of an emitting layer provided close to the anode is larger than a value obtained by dividing an electron mobility by a hole mobility of an emitting layer provided close to the cathode; and in the adjacent ones of the emitting layers, the electron mobility of the emitting layer provided close to the anode is larger than the electron mobility of the emitting layer provided close to the cathode.

When the number of organic layers forming a hole transporting zone that is disposed between the anode and the emitting layer is reduced as in the organic electroluminescence device described in Patent Literature 1, the supply amount of holes into the emitting layers may decrease to cause a luminous efficiency reduction. However, Patent Literature 1 fails to mention the decrease in hole supply amount.

An object of the invention is to provide an organic electroluminescence device capable of emitting light with a high efficiency even when the number of organic layers forming a hole transporting zone is reduced, an electronic device including the organic electroluminescence device, an organic electroluminescence display device, and an electronic device including the organic electroluminescence display device.

### Means for Solving the Problem(s)

According to an aspect of the invention, there is provided an organic electroluminescence device, including: an anode; a cathode; an emitting region disposed between the anode and the cathode; and a hole transporting zone disposed between the anode and the emitting region, in which the emitting region includes a first emitting layer and a second emitting layer, the first emitting layer is disposed close to the anode in the emitting region, the hole transporting zone is in direct contact with the anode and the first emitting layer, the hole transporting zone includes one or more organic layers, at least one of the organic layers in the hole transporting zone is a first organic layer that is in direct contact with the first emitting layer, the first organic layer contains a hole transporting zone material, the first emitting layer contains a first host material and a first emitting compound that emits light having a maximum peak wavelength of 500 nm or less, the second emitting layer contains a second host material and a second emitting compound that emits light having a maximum peak wavelength of 500 nm or less, the first host material is different from the second host material, the first emitting compound and the second emitting compound are mutually the same or different, a triplet energy of the first host material T₁(H1) and a triplet energy of the second host material T₁(H2) satisfy a relationship of a numerical formula (Numerical Formula 1) below, and in the emitting region, a dipole of the first host material contained in the first emitting layer is 0.4 D or more.

T₁(H1)>T₁(H2) (Numerical Formula 1)

According to another aspect of the invention, there is provided an electronic device including the organic electroluminescence device according to the aspect of the invention described above.

According to still another aspect of the invention, there is provided an organic electroluminescence display device including: an anode and a cathode arranged opposite each other; a blue-emitting organic EL device as a blue pixel; a green-emitting organic EL device as a green pixel; and a red-emitting organic EL device as a red pixel, in which the blue-emitting organic EL device includes a blue emitting region having a first emitting layer and a second emitting layer provided between the anode and the cathode, the first emitting layer is disposed close to the anode in the blue emitting region, the green-emitting organic EL device includes a green emitting layer provided between the anode and the cathode, the red-emitting organic EL device includes a red emitting layer provided between the anode and the cathode, a hole transporting zone is provided between the anode and the blue emitting region of the blue-emitting organic EL device, the green emitting layer of the green-emitting organic EL device, and the red emitting layer of the red-emitting organic EL device in a shared manner across the blue-emitting organic EL device, the green-emitting organic EL device, and the red-emitting organic EL device, the hole transporting zone is in direct contact with the first emitting layer in the blue emitting region of the blue-emitting organic EL device, the hole transporting zone includes one or more organic layers, the first emitting layer contains a first host material and a first emitting compound that emits light having a maximum peak wavelength of 500 nm or less, the second emitting layer contains a second host material and a second emitting compound that emits light having a maximum peak wavelength of 500 nm or less, the first host material is different from the second host material, the first emitting compound and the second emitting compound are mutually the same or different, a triplet energy of the first host material T₁(H1) and a triplet energy of the second host material T₁(H2) satisfy a relationship of a numerical formula (Numerical Formula 1) below, and in the blue emitting region of the blue-emitting organic EL device, a dipole of the first host material contained in the first emitting layer is 0.4 D or more.

T₁(H1)>T₁(H2) (Numerical Formula 1)

According to a further aspect of the invention, there is provided an electronic device including the organic electroluminescence display device according to the still another aspect of the invention described above.

According to the aspects of the invention, there can be provided an organic electroluminescence device capable of emitting light with a high efficiency even when the number of organic layers forming a hole transporting zone is reduced, an electronic device including the organic electroluminescence device, an organic electroluminescence display device, and an electronic device including the organic electroluminescence display device.

### BRIEF EXPLANATION OF DRAWINGS

FIG. 1 schematically depicts an exemplary arrangement of an organic electroluminescence device according to a first exemplary embodiment.

FIG. 2 schematically depicts another exemplary arrangement of the organic electroluminescence device according to the first exemplary embodiment.

FIG. 3 schematically depicts still another exemplary arrangement of the organic electroluminescence device according to the first exemplary embodiment.

FIG. 4 schematically depicts an exemplary arrangement of an organic electroluminescence display device according to a second exemplary embodiment.

FIG. 5 schematically depicts another exemplary arrangement of the organic electroluminescence display device according to the second exemplary embodiment.

FIG. 6 schematically depicts an apparatus for measuring transient PL.

FIG. 7 illustrates an example of decay curves of the transient PL.

### DESCRIPTION OF EMBODIMENT(S)

### Definitions

Herein, a hydrogen atom includes isotope having different numbers of neutrons, specifically, protium, deuterium and tritium.

In chemical formulae herein, it is assumed that a hydrogen atom (i.e. protium, deuterium and tritium) is bonded to each of bondable positions that are not annexed with signs “R” or the like or “D” representing a deuterium.

Herein, the ring carbon atoms refer to the number of carbon atoms among atoms forming a ring of a compound (e.g., a monocyclic compound, fused-ring compound, cross-linking compound, carbon ring compound, and heterocyclic compound) in which the atoms are bonded to each other to form the ring. When the ring is substituted by a substituent(s), carbon atom(s) contained in the substituent(s) is not counted in the ring carbon atoms. Unless otherwise specified, the same applies to the “ring carbon atoms” described later. For instance, a benzene ring has 6 ring carbon atoms, a naphthalene ring has 10 ring carbon atoms, a pyridine ring has 5 ring carbon atoms, and a furan ring has 4 ring carbon atoms. Further, for instance, 9,9-diphenylfluorenyl group has 13 ring carbon atoms and 9,9′-spirobifluorenyl group has 25 ring carbon atoms.

When a benzene ring is substituted by a substituent in a form of, for instance, an alkyl group, the number of carbon atoms of the alkyl group is not counted in the number of the ring carbon atoms of the benzene ring. Accordingly, the benzene ring substituted by an alkyl group has 6 ring carbon atoms. When a naphthalene ring is substituted by a substituent in a form of, for instance, an alkyl group, the number of carbon atoms of the alkyl group is not counted in the number of the ring carbon atoms of the naphthalene ring. Accordingly, the naphthalene ring substituted by an alkyl group has 10 ring carbon atoms.

Herein, the ring atoms refer to the number of atoms forming a ring of a compound (e.g., a monocyclic compound, fused-ring compound, cross-linking compound, carbon ring compound, and heterocyclic compound) in which the atoms are bonded to each other to form the ring (e.g., monocyclic ring, fused ring, and ring assembly). Atom(s) not forming the ring (e.g., hydrogen atom(s) for saturating the valence of the atom which forms the ring) and atom(s) in a substituent by which the ring is substituted are not counted as the ring atoms. Unless otherwise specified, the same applies to the “ring atoms” described later. For instance, a pyridine ring has 6 ring atoms, a quinazoline ring has 10 ring atoms, and a furan ring has 5 ring atoms. For instance, the number of hydrogen atom(s) bonded to a pyridine ring or the number of atoms forming a substituent is not counted as the pyridine ring atoms.

Accordingly, a pyridine ring bonded to a hydrogen atom(s) or a substituent(s) has 6 ring atoms. For instance, the hydrogen atom(s) bonded to carbon atom(s) of a quinazoline ring or the atoms forming a substituent are not counted as the quinazoline ring atoms. Accordingly, a quinazoline ring bonded to hydrogen atom(s) or a substituent(s) has 10 ring atoms.

Herein, “XX to YY carbon atoms” in the description of “substituted or unsubstituted ZZ group having XX to YY carbon atoms” represent carbon atoms of an unsubstituted ZZ group and do not include carbon atoms of a substituent(s) of the substituted ZZ group. Herein, “YY” is larger than “XX,” “XX” representing an integer of 1 or more and “YY” representing an integer of 2 or more.

Herein, “XX to YY atoms” in the description of “substituted or unsubstituted ZZ group having XX to YY atoms” represent atoms of an unsubstituted ZZ group and does not include atoms of a substituent(s) of the substituted ZZ group. Herein, “YY” is larger than “XX,” “XX” representing an integer of 1 or more and “YY” representing an integer of 2 or more.

Herein, an unsubstituted ZZ group refers to an “unsubstituted ZZ group” in a “substituted or unsubstituted ZZ group,” and a substituted ZZ group refers to a “substituted ZZ group” in a “substituted or unsubstituted ZZ group.”

Herein, the term “unsubstituted” used in a “substituted or unsubstituted ZZ group” means that a hydrogen atom(s) in the ZZ group is not substituted with a substituent(s). The hydrogen atom(s) in the “unsubstituted ZZ group” is protium, deuterium, or tritium.

Herein, the term “substituted” used in a “substituted or unsubstituted ZZ group” means that at least one hydrogen atom in the ZZ group is substituted with a substituent. Similarly, the term “substituted” used in a “BB group substituted by AA group” means that at least one hydrogen atom in the BB group is substituted with the AA group.

### Substituent Mentioned Herein

Substituent mentioned herein will be described below.

An “unsubstituted aryl group” mentioned herein has, unless otherwise specified herein, 6 to 50, preferably 6 to 30, more preferably 6 to 18 ring carbon atoms.

An “unsubstituted heterocyclic group” mentioned herein has, unless otherwise specified herein, 5 to 50, preferably 5 to 30, more preferably 5 to 18 ring atoms.

An “unsubstituted alkyl group” mentioned herein has, unless otherwise specified herein, 1 to 50, preferably 1 to 20, more preferably 1 to 6 carbon atoms.

An “unsubstituted alkenyl group” mentioned herein has, unless otherwise specified herein, 2 to 50, preferably 2 to 20, more preferably 2 to 6 carbon atoms. An “unsubstituted alkynyl group” mentioned herein has, unless otherwise specified herein, 2 to 50, preferably 2 to 20, more preferably 2 to 6 carbon atoms.

An “unsubstituted cycloalkyl group” mentioned herein has, unless otherwise specified herein, 3 to 50, preferably 3 to 20, more preferably 3 to 6 ring carbon atoms. An “unsubstituted arylene group” mentioned herein has, unless otherwise specified herein, 6 to 50, preferably 6 to 30, more preferably 6 to 18 ring carbon atoms.

An “unsubstituted divalent heterocyclic group” mentioned herein has, unless otherwise specified herein, 5 to 50, preferably 5 to 30, more preferably 5 to 18 ring atoms.

An “unsubstituted alkylene group” mentioned herein has, unless otherwise specified herein, 1 to 50, preferably 1 to 20, more preferably 1 to 6 carbon atoms.

### Substituted or Unsubstituted Aryl Group

Specific examples (specific example group G1) of the “substituted or unsubstituted aryl group” mentioned herein include unsubstituted aryl groups (specific example group G1A) below and substituted aryl groups (specific example group G1B). (Herein, an unsubstituted aryl group refers to an “unsubstituted aryl group” in a “substituted or unsubstituted aryl group”, and a substituted aryl group refers to a “substituted aryl group” in a “substituted or unsubstituted aryl group.”) A simply termed “aryl group” herein includes both of an “unsubstituted aryl group” and a “substituted aryl group”.

The “substituted aryl group” refers to a group derived by substituting at least one hydrogen atom in an “unsubstituted aryl group” with a substituent. Examples of the “substituted aryl group” include a group derived by substituting at least one hydrogen atom in the “unsubstituted aryl group” in the specific example group G1A below with a substituent, and examples of the substituted aryl group in the specific example group G1B below. It should be noted that the examples of the “unsubstituted aryl group” and the “substituted aryl group” mentioned herein are merely exemplary, and the “substituted aryl group” mentioned herein includes a group derived by further substituting a hydrogen atom bonded to a carbon atom of a skeleton of a “substituted aryl group” in the specific example group G1B below, and a group derived by further substituting a hydrogen atom of a substituent of the “substituted aryl group” in the specific example group G1B below.

### Unsubstituted Aryl Group (Specific Example Group G1A):

a phenyl group, p-biphenyl group, m-biphenyl group, o-biphenyl group, p-terphenyl-4-yl group, p-terphenyl-3-yl group, p-terphenyl-2-yl group, m-terphenyl-4-yl group, m-terphenyl-3-yl group, m-terphenyl-2-yl group, o-terphenyl-4-yl group, o-terphenyl-3-yl group, o-terphenyl-2-yl group, 1-naphthyl group, 2-naphthyl group, anthryl group, benzanthryl group, phenanthryl group, benzophenanthryl group, phenalenyl group, pyrenyl group, chrysenyl group, benzochrysenyl group, triphenylenyl group, benzotriphenylenyl group, tetracenyl group, pentacenyl group, fluorenyl group, 9,9′-spirobifluorenyl group, benzofluorenyl group, dibenzofluorenyl group, fluoranthenyl group, benzofluoranthenyl group, perylenyl group, and a monovalent aryl group derived by removing one hydrogen atom from cyclic structures represented by formulae (TEMP-1) to (TEMP-15) below.

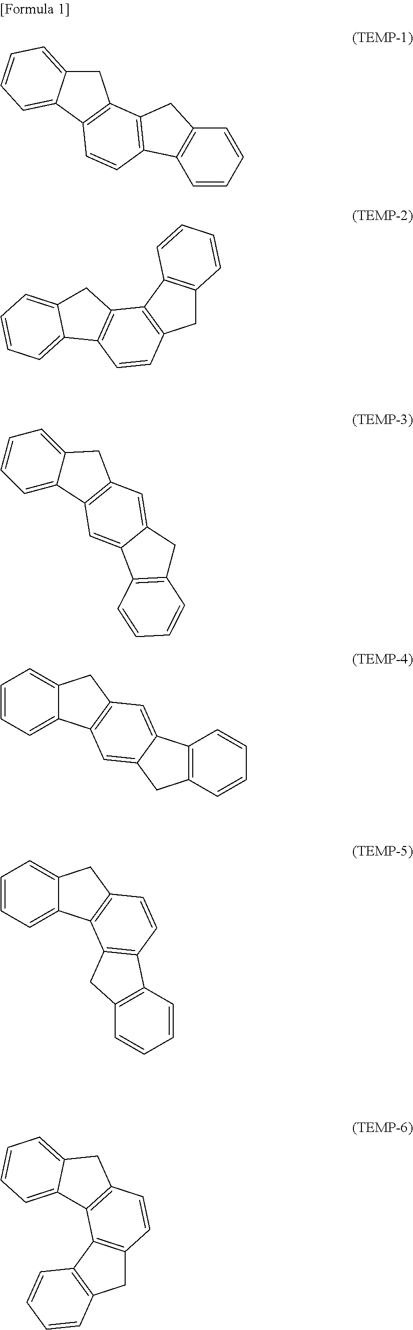

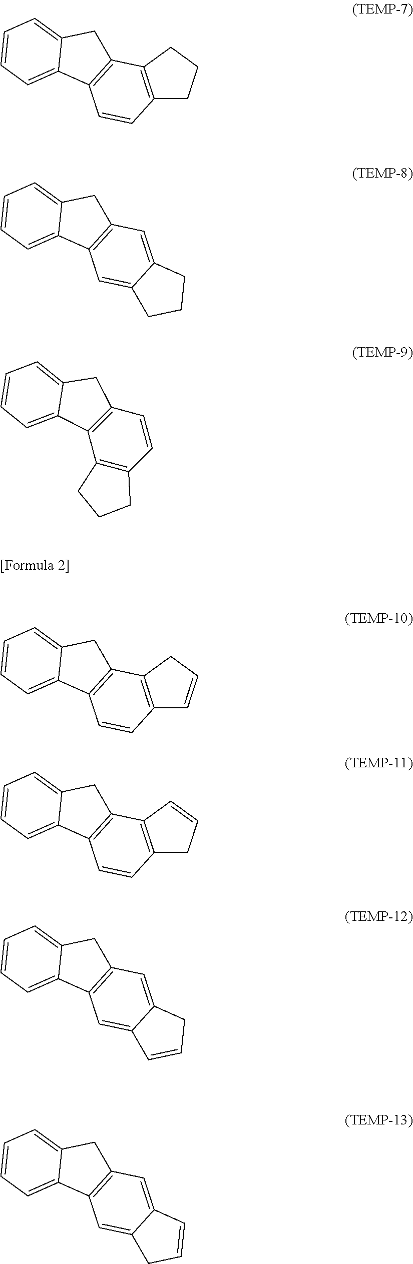

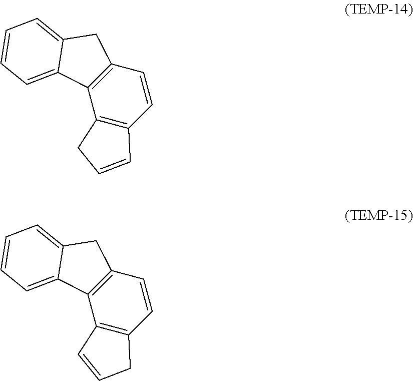

### Substituted Aryl Group (Specific Example Group G1B):

an o-tolyl group, m-tolyl group, p-tolyl group, para-xylyl group, meta-xylyl group, ortho-xylyl group, para-isopropylphenyl group, meta-isopropylphenyl group, ortho-isopropylphenyl group, para-t-butylphenyl group, meta-t-butylphenyl group, ortho-t-butylphenyl group, 3,4,5-trimethylphenyl group, 9,9-dimethylfluorenyl group, 9,9-diphenylfluorenyl group, 9,9-bis(4-methylphenyl)fluorenyl group, 9,9-bis(4-isopropylphenyl)fluorenyl group, 9,9-bis(4-t-butylphenyl)fluorenyl group, cyanophenyl group, triphenylsilylphenyl group, trimethylsilylphenyl group, phenylnaphthyl group, naphthylphenyl group, and group derived by substituting at least one hydrogen atom of a monovalent group derived from one of the cyclic structures represented by the formulae (TEMP-1) to (TEMP-15) with a substituent.

### Substituted or Unsubstituted Heterocyclic Group

The “heterocyclic group” mentioned herein refers to a cyclic group having at least one hetero atom in the ring atoms. Specific examples of the hetero atom include a nitrogen atom, oxygen atom, sulfur atom, silicon atom, phosphorus atom, and boron atom.

The “heterocyclic group” mentioned herein is a monocyclic group or a fused-ring group.

The “heterocyclic group” mentioned herein is an aromatic heterocyclic group or a non-aromatic heterocyclic group.

Specific examples (specific example group G2) of the “substituted or unsubstituted heterocyclic group” mentioned herein include unsubstituted heterocyclic groups (specific example group G2A) and substituted heterocyclic groups (specific example group G2B). (Herein, an unsubstituted heterocyclic group refers to an “unsubstituted heterocyclic group” in a “substituted or unsubstituted heterocyclic group,” and a substituted heterocyclic group refers to a “substituted heterocyclic group” in a “substituted or unsubstituted heterocyclic group.”) A simply termed “heterocyclic group” herein includes both of an “unsubstituted heterocyclic group” and a “substituted heterocyclic group.”

The “substituted heterocyclic group” refers to a group derived by substituting at least one hydrogen atom in an “unsubstituted heterocyclic group” with a substituent. Specific examples of the “substituted heterocyclic group” include a group derived by substituting at least one hydrogen atom in the “unsubstituted heterocyclic group” in the specific example group G2A below with a substituent, and examples of the substituted heterocyclic group in the specific example group G2B below. It should be noted that the examples of the “unsubstituted heterocyclic group” and the “substituted heterocyclic group” mentioned herein are merely exemplary, and the “substituted heterocyclic group” mentioned herein includes a group derived by further substituting a hydrogen atom bonded to a ring atom of a skeleton of a “substituted heterocyclic group” in the specific example group G2B below, and a group derived by further substituting a hydrogen atom of a substituent of the “substituted heterocyclic group” in the specific example group G2B below.

The specific example group G2A includes, for instance, unsubstituted heterocyclic groups including a nitrogen atom (specific example group G2A1) below, unsubstituted heterocyclic groups including an oxygen atom (specific example group G2A2) below, unsubstituted heterocyclic groups including a sulfur atom (specific example group G2A3) below, and monovalent heterocyclic groups (specific example group G2A4) derived by removing a hydrogen atom from cyclic structures represented by formulae (TEMP-16) to (TEMP-33) below.

The specific example group G2B includes, for instance, substituted heterocyclic groups including a nitrogen atom (specific example group G2B1) below, substituted heterocyclic groups including an oxygen atom (specific example group G2B2) below, substituted heterocyclic groups including a sulfur atom (specific example group G2B3) below, and groups derived by substituting at least one hydrogen atom of the monovalent heterocyclic groups (specific example group G2B4) derived from the cyclic structures represented by formulae (TEMP-16) to (TEMP-33) below.

### Unsubstituted Heterocyclic Groups Including Nitrogen Atom (Specific Example Group G2A1):

a pyrrolyl group, imidazolyl group, pyrazolyl group, triazolyl group, tetrazolyl group, oxazolyl group, isoxazolyl group, oxadiazolyl group, thiazolyl group, isothiazolyl group, thiadiazolyl group, pyridyl group, pyridazynyl group, pyrimidinyl group, pyrazinyl group, triazinyl group, indolyl group, isoindolyl group, indolizinyl group, quinolizinyl group, quinolyl group, isoquinolyl group, cinnolyl group, phthalazinyl group, quinazolinyl group, quinoxalinyl group, benzimidazolyl group, indazolyl group, phenanthrolinyl group, phenanthridinyl group, acridinyl group, phenazinyl group, carbazolyl group, benzocarbazolyl group, morpholino group, phenoxazinyl group, phenothiazinyl group, azacarbazolyl group, and diazacarbazolyl group.

### Unsubstituted Heterocyclic Groups Including Oxygen Atom (Specific Example Group G2A2):

a furyl group, oxazolyl group, isoxazolyl group, oxadiazolyl group, xanthenyl group, benzofuranyl group, isobenzofuranyl group, dibenzofuranyl group, naphthobenzofuranyl group, benzoxazolyl group, benzisoxazolyl group, phenoxazinyl group, morpholino group, dinaphthofuranyl group, azadibenzofuranyl group, diazadibenzofuranyl group, azanaphthobenzofuranyl group, and diazanaphthobenzofuranyl group.

### Unsubstituted Heterocyclic Groups Including Sulfur Atom (Specific Example Group G2A3):

a thienyl group, thiazolyl group, isothiazolyl group, thiadiazolyl group, benzothiophenyl group (benzothienyl group), isobenzothiophenyl group (isobenzothienyl group), dibenzothiophenyl group (dibenzothienyl group), naphthobenzothiophenyl group (nahthobenzothienyl group), benzothiazolyl group, benzisothiazolyl group, phenothiazinyl group, dinaphthothiophenyl group (dinaphthothienyl group), azadibenzothiophenyl group (azadibenzothienyl group), diazadibenzothiophenyl group (diazadibenzothienyl group), azanaphthobenzothiophenyl group (azanaphthobenzothienyl group), and diazanaphthobenzothiophenyl group (diazanaphthobenzothienyl group).

Monovalent Heterocyclic Groups Derived by Removing One Hydrogen Atom from Cyclic Structures Represented by Formulae (TEMP-16) to (TEMP-33) (Specific Example Group G2A4):

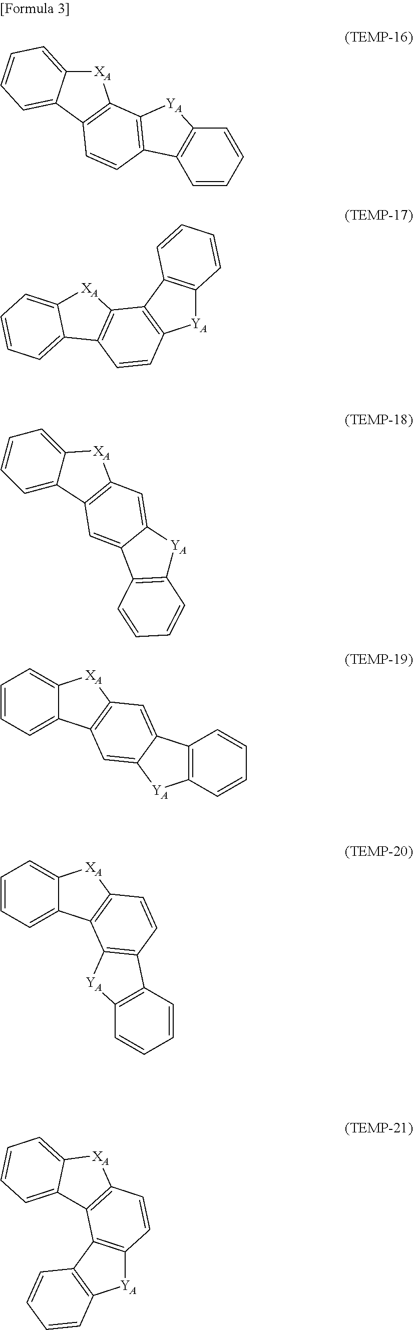

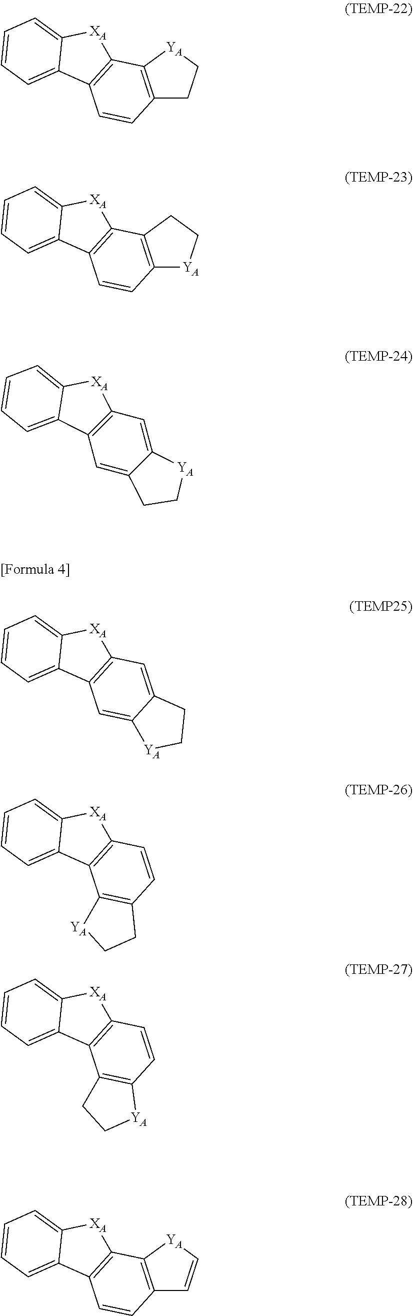

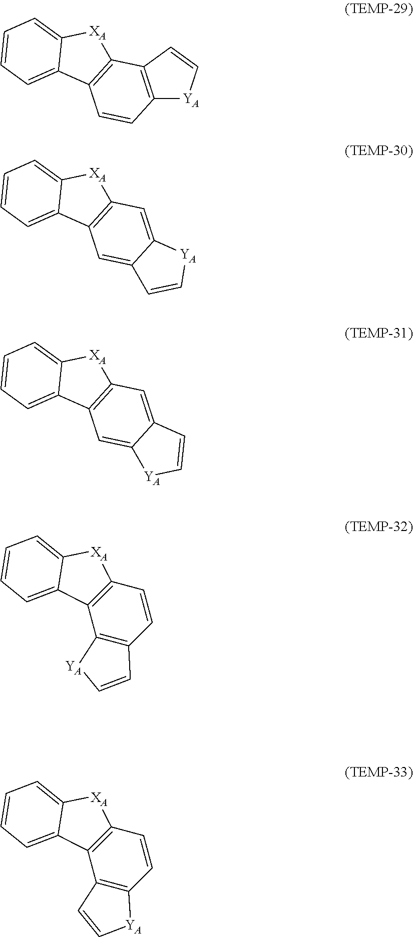

In the formulae (TEMP-16) to (TEMP-33), XA and YA are each independently an oxygen atom, a sulfur atom, NH or CH₂, with a proviso that at least one of XA or 5 YA is an oxygen atom, a sulfur atom, or NH.

When at least one of XA or YA in the formulae (TEMP-16) to (TEMP-33) is NH or CH₂, the monovalent heterocyclic groups derived from the cyclic structures represented by the formulae (TEMP-16) to (TEMP-33) include a monovalent group derived by removing one hydrogen atom from NH or CH₂.

### Substituted Heterocyclic Groups Including Nitrogen Atom (Specific Example Group G2B1):

a (9-phenyl)carbazolyl group, (9-biphenylyl)carbazolyl group, (9-phenyl)phenylcarbazolyl group, (9-naphthyl)carbazolyl group, diphenylcarbazole-9-yl group, phenylcarbazole-9-yl group, methylbenzimidazolyl group, ethylbenzimidazolyl group, phenyltriazinyl group, biphenylyltriazinyl group, diphenyltriazinyl group, phenylquinazolinyl group, and biphenylquinazolinyl group.

### Substituted Heterocyclic Groups Including Oxygen Atom (Specific Example Group G2B2):

a phenyldibenzofuranyl group, methyldibenzofuranyl group, t-butyldibenzofuranyl group, and monovalent residue of spiro[9H-xanthene-9,9′-[9H]fluorene].

### Substituted Heterocyclic Groups Including Sulfur Atom (Specific Example Group G2B3):

a phenyldibenzothiophenyl group, methyldibenzothiophenyl group, t-butyldibenzothiophenyl group, and a monovalent residue of spiro[9H-thioxanthene-9,9′-[9H]fluorene].

Groups Obtained by Substituting at Least One Hydrogen Atom of Monovalent Heterocyclic Group Derived from Cyclic Structures Represented by Formulae (TEMP-16) to (TEMP-33) with Substituent (Specific Example Group G2B4):

The “at least one hydrogen atom of a monovalent heterocyclic group” means at least one hydrogen atom selected from a hydrogen atom bonded to a ring carbon atom of the monovalent heterocyclic group, a hydrogen atom bonded to a nitrogen atom of at least one of XA or YA in a form of NH, and a hydrogen atom of one of XA and YA in a form of a methylene group (CH₂).

### Substituted or Unsubstituted Alkyl Group

Specific examples (specific example group G3) of the “substituted or unsubstituted alkyl group” mentioned herein include unsubstituted alkyl groups (specific example group G3A) and substituted alkyl groups (specific example group G3B) below. (Herein, an unsubstituted alkyl group refers to an “unsubstituted alkyl group” in a “substituted or unsubstituted alkyl group,” and a substituted alkyl group refers to a “substituted alkyl group” in a “substituted or unsubstituted alkyl group.”) A simply termed “alkyl group” herein includes both of an “unsubstituted alkyl group” and a “substituted alkyl group”.

The “substituted alkyl group” refers to a group derived by substituting at least one hydrogen atom in an “unsubstituted alkyl group” with a substituent. Specific examples of the “substituted alkyl group” include a group derived by substituting at least one hydrogen atom of an “unsubstituted alkyl group” (specific example group G3A) below with a substituent, and examples of the substituted alkyl group (specific example group G3B) below. Herein, the alkyl group for the “unsubstituted alkyl group” refers to a chain alkyl group. Accordingly, the “unsubstituted alkyl group” include linear “unsubstituted alkyl group” and branched “unsubstituted alkyl group.” It should be noted that the examples of the “unsubstituted alkyl group” and the “substituted alkyl group” mentioned herein are merely exemplary, and the “substituted alkyl group” mentioned herein includes a group derived by further substituting a hydrogen atom of a skeleton of the “substituted alkyl group” in the specific example group G3B, and a group derived by further substituting a hydrogen atom of a substituent of the “substituted alkyl group” in the specific example group G3B.

### Unsubstituted Alkyl Group (Specific Example Group G3A):

a methyl group, ethyl group, n-propyl group, isopropyl group, n-butyl group, isobutyl group, s-butyl group, and t-butyl group.

### Substituted Alkyl Group (Specific Example Group G3B):

a heptafluoropropyl group (including isomer thereof), pentafluoroethyl group, 2,2,2-trifluoroethyl group, and trifluoromethyl group.

### Substituted or Unsubstituted Alkenyl Group

Specific examples (specific example group G4) of the “substituted or unsubstituted alkenyl group” mentioned herein include unsubstituted alkenyl groups (specific example group G4A) and substituted alkenyl groups (specific example group G4B). (Herein, an unsubstituted alkenyl group refers to an “unsubstituted alkenyl group” in a “substituted or unsubstituted alkenyl group,” and a substituted alkenyl group refers to a “substituted alkenyl group” in a “substituted or unsubstituted alkenyl group.”) A simply termed “alkenyl group” herein includes both of an “unsubstituted alkenyl group” and a “substituted alkenyl group”.

The “substituted alkenyl group” refers to a group derived by substituting at least one hydrogen atom in an “unsubstituted alkenyl group” with a substituent. Specific examples of the “substituted alkenyl group” include an “unsubstituted alkenyl group” (specific example group G4A) substituted by a substituent, and examples of the substituted alkenyl group (specific example group G4B) below. It should be noted that the examples of the “unsubstituted alkenyl group” and the “substituted alkenyl group” mentioned herein are merely exemplary, and the “substituted alkenyl group” mentioned herein includes a group derived by further substituting a hydrogen atom of a skeleton of the “substituted alkenyl group” in the specific example group G4B with a substituent, and a group derived by further substituting a hydrogen atom of a substituent of the “substituted alkenyl group” in the specific example group G4B with a substituent.

### Unsubstituted Alkenyl Group (Specific Example Group G4A):

a vinyl group, allyl group, 1-butenyl group, 2-butenyl group, and 3-butenyl group.

### Substituted Alkenyl Group (Specific Example Group G4B):

a 1,3-butanedienyl group, 1-methylvinyl group, 1-methylallyl group, 1,1-dimethylallyl group, 2-methylallyl group, and 1,2-dimethylallyl group.

### Substituted or Unsubstituted Alkynyl Group

Specific examples (specific example group G5) of the “substituted or unsubstituted alkynyl group” mentioned herein include unsubstituted alkynyl groups (specific example group G5A) below. (Herein, an unsubstituted alkynyl group refers to an “unsubstituted alkynyl group” in a “substituted or unsubstituted alkynyl group.”) A simply termed “alkynyl group” herein includes both of “unsubstituted alkynyl group” and “substituted alkynyl group”.

The “substituted alkynyl group” refers to a group derived by substituting at least one hydrogen atom in an “unsubstituted alkynyl group” with a substituent. Specific examples of the “substituted alkynyl group” include a group derived by substituting at least one hydrogen atom of the “unsubstituted alkynyl group” (specific example group G5A) below with a substituent.

Unsubstituted Alkynyl Group (Specific Example Group G5A): ethynyl group

### Substituted or Unsubstituted Cycloalkyl Group

Specific examples (specific example group G6) of the “substituted or unsubstituted cycloalkyl group” mentioned herein include unsubstituted cycloalkyl groups (specific example group G6A) and substituted cycloalkyl groups (specific example group G6B). (Herein, an unsubstituted cycloalkyl group refers to an “unsubstituted cycloalkyl group” in a “substituted or unsubstituted cycloalkyl group,” and a substituted cycloalkyl group refers to a “substituted cycloalkyl group” in a “substituted or unsubstituted cycloalkyl group.”) A simply termed “cycloalkyl group” herein includes both of “unsubstituted cycloalkyl group” and “substituted cycloalkyl group”.

The “substituted cycloalkyl group” refers to a group derived by substituting at least one hydrogen atom of an “unsubstituted cycloalkyl group” with a substituent. Specific examples of the “substituted cycloalkyl group” include a group derived by substituting at least one hydrogen atom of the “unsubstituted cycloalkyl group” (specific example group G6A) below with a substituent, and examples of the substituted cycloalkyl group (specific example group G6B) below. It should be noted that the examples of the “unsubstituted cycloalkyl group” and the “substituted cycloalkyl group” mentioned herein are merely exemplary, and the “substituted cycloalkyl group” mentioned herein includes a group derived by substituting at least one hydrogen atom bonded to a carbon atom of a skeleton of the “substituted cycloalkyl group” in the specific example group G6B with a substituent, and a group derived by further substituting a hydrogen atom of a substituent of the “substituted cycloalkyl group” in the specific example group G6B with a substituent.

### Unsubstituted Cycloalkyl Group (Specific Example Group G6A):

a cyclopropyl group, cyclobutyl group, cyclopentyl group, cyclohexyl group, 1-adamantyl group, 2-adamantyl group, 1-norbornyl group, and 2-norbornyl group.

Substituted Cycloalkyl Group (Specific Example Group G6B): 4-methylcyclohexyl group.
Group Represented by —Si(R₉₀₁)(R₉₀₂)(R₉₀₃)

Specific examples (specific example group G7) of the group represented herein by —Si(R₉₀₁)(R₉₀₂)(R₉₀₃) include: —Si(G1)(G1)(G1); —Si(G1)(G2)(G2); —Si(G1)(G1)(G2); —Si(G2)(G2)(G2); —Si(G3)(G3)(G3); and —Si(G6)(G6)(G6);

where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3; and
G6 represents a “substituted or unsubstituted cycloalkyl group” in the specific example group G6;
a plurality of G1 in —Si(G1)(G1)(G1) are mutually the same or different;
a plurality of G2 in —Si(G1)(G2)(G2) are mutually the same or different;
a plurality of G1 in —Si(G1)(G1)(G2) are mutually the same or different;
a plurality of G2 in —Si(G2)(G2)(G2) are mutually the same or different;
a plurality of G3 in —Si(G3)(G3)(G3) are mutually the same or different; and
a plurality of G6 in —Si(G6)(G6)(G6) are mutually the same or different.

### Group Represented by —O—(R₉₀₄)

Specific examples (specific example group G8) of a group represented by —O—(R₉₀₄) herein include: —O(G1); —O(G2); —O(G3); and —O(G6);

where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3; and
G6 represents a “substituted or unsubstituted cycloalkyl group” in the specific example group G6.

### Group Represented by —S—(R₉₀₅)

Specific examples (specific example group G9) of a group represented herein by —S—(R₉₀₅) include: —S(G1); —S(G2); —S(G3); and —S(G6);

where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3; and
G6 represents a “substituted or unsubstituted cycloalkyl group” in the specific example group G6.
   Group Represented by —N(R₉₀₆)(R₉₀₇)

Specific examples (specific example group G10) of a group represented herein by —N(R₉₀₆)(R₉₀₇) include: —N(G1)(G1); —N(G2)(G2); —N(G1)(G2); —N(G3)(G3); and —N(G6)(G6),

where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3; and
G6 represents a “substituted or unsubstituted cycloalkyl group” in the specific example group G6;
a plurality of G1 in —N(G1)(G1) are mutually the same or different;
a plurality of G2 in —N(G2)(G2) are mutually the same or different;
a plurality of G3 in —N(G3)(G3) are mutually the same or different; and
a plurality of G6 in —N(G6)(G6) are mutually the same or different.

### Halogen Atom

Specific examples (specific example group G11) of “halogen atom” mentioned herein include a fluorine atom, chlorine atom, bromine atom, and iodine atom.

### Substituted or Unsubstituted Fluoroalkyl Group

The “substituted or unsubstituted fluoroalkyl group” mentioned herein refers to a group derived by substituting at least one hydrogen atom bonded to at least one of carbon atoms forming an alkyl group in the “substituted or unsubstituted alkyl group” with a fluorine atom, and also includes a group (perfluoro group) derived by substituting all of hydrogen atoms bonded to carbon atoms forming the alkyl group in the “substituted or unsubstituted alkyl group” with fluorine atoms. An “unsubstituted fluoroalkyl group” has, unless otherwise specified herein, 1 to 50, preferably 1 to 30, more preferably 1 to 18 carbon atoms. The “substituted fluoroalkyl group” refers to a group derived by substituting at least one hydrogen atom in a “fluoroalkyl group” with a substituent. It should be noted that the examples of the “substituted fluoroalkyl group” mentioned herein include a group derived by further substituting at least one hydrogen atom bonded to a carbon atom of an alkyl chain of a “substituted fluoroalkyl group” with a substituent, and a group derived by further substituting at least one hydrogen atom of a substituent of the “substituted fluoroalkyl group” with a substituent. Specific examples of the “unsubstituted fluoroalkyl group” include a group derived by substituting at least one hydrogen atom of the “alkyl group” (specific example group G3) with a fluorine atom.

### Substituted or Unsubstituted Haloalkyl Group

The “substituted or unsubstituted haloalkyl group” mentioned herein refers to a group derived by substituting at least one hydrogen atom bonded to carbon atoms forming the alkyl group in the “substituted or unsubstituted alkyl group” with a halogen atom, and also includes a group derived by substituting all hydrogen atoms bonded to carbon atoms forming the alkyl group in the “substituted or unsubstituted alkyl group” with halogen atoms. An “unsubstituted haloalkyl group” has, unless otherwise specified herein, 1 to 50, preferably 1 to 30, and more preferably 1 to 18 carbon atoms. The “substituted haloalkyl group” refers to a group derived by substituting at least one hydrogen atom in a “haloalkyl group” with a substituent. It should be noted that the examples of the “substituted haloalkyl group” mentioned herein include a group derived by further substituting at least one hydrogen atom bonded to a carbon atom of an alkyl chain of a “substituted haloalkyl group” with a substituent, and a group derived by further substituting at least one hydrogen atom of a substituent of the “substituted haloalkyl group” with a substituent. Specific examples of the “unsubstituted haloalkyl group” include a group derived by substituting at least one hydrogen atom of the “alkyl group” (specific example group G3) with a halogen atom. The haloalkyl group is occasionally referred to as a halogenated alkyl group.

### Substituted or Unsubstituted Alkoxy Group

Specific examples of a “substituted or unsubstituted alkoxy group” mentioned herein include a group represented by —O(G3), G3 being the “substituted or unsubstituted alkyl group” in the specific example group G3. An “unsubstituted alkoxy group” has, unless otherwise specified herein, 1 to 50, preferably 1 to 30, more preferably 1 to 18 carbon atoms.

### Substituted or Unsubstituted Alkylthio Group

Specific examples of a “substituted or unsubstituted alkylthio group” mentioned herein include a group represented by —S(G3), G3 being the “substituted or unsubstituted alkyl group” in the specific example group G3. An “unsubstituted alkylthio group” has, unless otherwise specified herein, 1 to 50, preferably 1 to 30, more preferably 1 to 18 carbon atoms.

### Substituted or Unsubstituted Aryloxy Group

Specific examples of a “substituted or unsubstituted aryloxy group” mentioned herein include a group represented by —O(G1), G1 being the “substituted or unsubstituted aryl group” in the specific example group G1. An “unsubstituted aryloxy group” has, unless otherwise specified herein, 6 to 50, preferably 6 to 30, more preferably 6 to 18 ring carbon atoms.

### Substituted or Unsubstituted Arylthio Group

Specific examples of a “substituted or unsubstituted arylthio group” mentioned herein include a group represented by —S(G1), G1 being the “substituted or unsubstituted aryl group” in the specific example group G1. An “unsubstituted arylthio group” has, unless otherwise specified herein, 6 to 50, preferably 6 to 30, more preferably 6 to 18 ring carbon atoms.

### Substituted or Unsubstituted Trialkylsilyl Group

Specific examples of a “trialkylsilyl group” mentioned herein include a group represented by —Si(G3)(G3)(G3), G3 being the “substituted or unsubstituted alkyl group” in the specific example group G3. The plurality of G3 in —Si(G3)(G3)(G3) are mutually the same or different. Each of the alkyl groups in the “trialkylsilyl group” has, unless otherwise specified herein, 1 to 50, preferably 1 to 20, more preferably 1 to 6 carbon atoms.

### Substituted or Unsubstituted Aralkyl Group

Specific examples of a “substituted or unsubstituted aralkyl group” mentioned herein include a group represented by -(G3)-(G1), G3 being the “substituted or unsubstituted alkyl group” in the specific example group G3, G1 being the “substituted or unsubstituted aryl group” in the specific example group G1. Accordingly, the “aralkyl group” is a group derived by substituting a hydrogen atom of the “alkyl group” with a substituent in a form of the “aryl group,” which is an example of the “substituted alkyl group.” An “unsubstituted aralkyl group,” which is an “unsubstituted alkyl group” substituted by an “unsubstituted aryl group,” has, unless otherwise specified herein, 7 to 50 carbon atoms, preferably 7 to 30 carbon atoms, more preferably 7 to 18 carbon atoms.

Specific examples of the “substituted or unsubstituted aralkyl group” include a benzyl group, 1-phenylethyl group, 2-phenylethyl group, 1-phenylisopropyl group, 2-phenylisopropyl group, phenyl-t-butyl group, α-naphthylmethyl group, 1-α-naphthylethyl group, 2-α-naphthylethyl group, 1-α-naphthylisopropyl group, 2-α-naphthylisopropyl group, β-naphthylmethyl group, 1-β-naphthylethyl group, 2-β-naphthylethyl group, 1-β-naphthylisopropyl group, and 2-β-naphthylisopropyl group.

Preferable examples of the substituted or unsubstituted aryl group mentioned herein include, unless otherwise specified herein, a phenyl group, p-biphenyl group, m-biphenyl group, o-biphenyl group, p-terphenyl-4-yl group, p-terphenyl-3-yl group, p-terphenyl-2-yl group, m-terphenyl-4-yl group, m-terphenyl-3-yl group, m-terphenyl-2-yl group, o-terphenyl-4-yl group, o-terphenyl-3-yl group, o-terphenyl-2-yl group, 1-naphthyl group, 2-naphthyl group, anthryl group, phenanthryl group, pyrenyl group, chrysenyl group, triphenylenyl group, fluorenyl group, 9,9′-spirobifluorenyl group, 9,9-dimethylfluorenyl group, and 9,9-diphenylfluorenyl group.

Preferable examples of the substituted or unsubstituted heterocyclic group mentioned herein include, unless otherwise specified herein, a pyridyl group, pyrimidinyl group, triazinyl group, quinolyl group, isoquinolyl group, quinazolinyl group, benzimidazolyl group, phenanthrolinyl group, carbazolyl group (1-carbazolyl group, 2-carbazolyl group, 3-carbazolyl group, 4-carbazolyl group, or 9-carbazolyl group), benzocarbazolyl group, azacarbazolyl group, diazacarbazolyl group, dibenzofuranyl group, naphthobenzofuranyl group, azadibenzofuranyl group, diazadibenzofuranyl group, dibenzothiophenyl group, naphthobenzothiophenyl group, azadibenzothiophenyl group, diazadibenzothiophenyl group, (9-phenyl)carbazolyl group ((9-phenyl)carbazole-1-yl group, (9-phenyl)carbazole-2-yl group, (9-phenyl)carbazole-3-yl group, or (9-phenyl)carbazole-4-yl group), (9-biphenylyl)carbazolyl group, (9-phenyl)phenylcarbazolyl group, diphenylcarbazole-9-yl group, phenylcarbazole-9-yl group, phenyltriazinyl group, biphenylyltriazinyl group, diphenyltriazinyl group, phenyldibenzofuranyl group, and phenyldibenzothiophenyl group.

The carbazolyl group mentioned herein is, unless otherwise specified herein, specifically a group represented by one of formulae below.

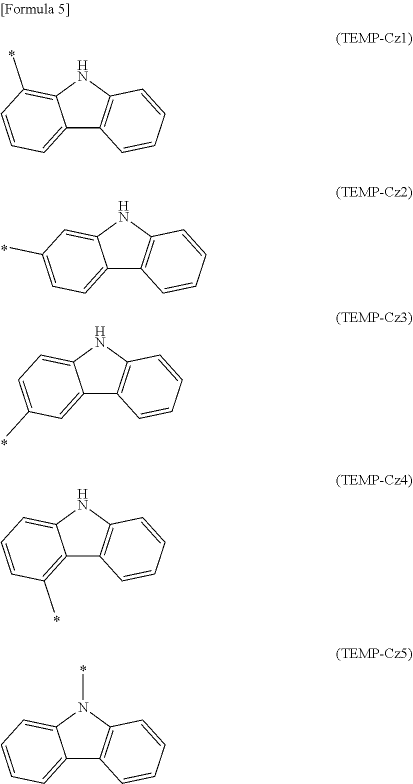

The (9-phenyl)carbazolyl group mentioned herein is, unless otherwise specified herein, specifically a group represented by one of formulae below.

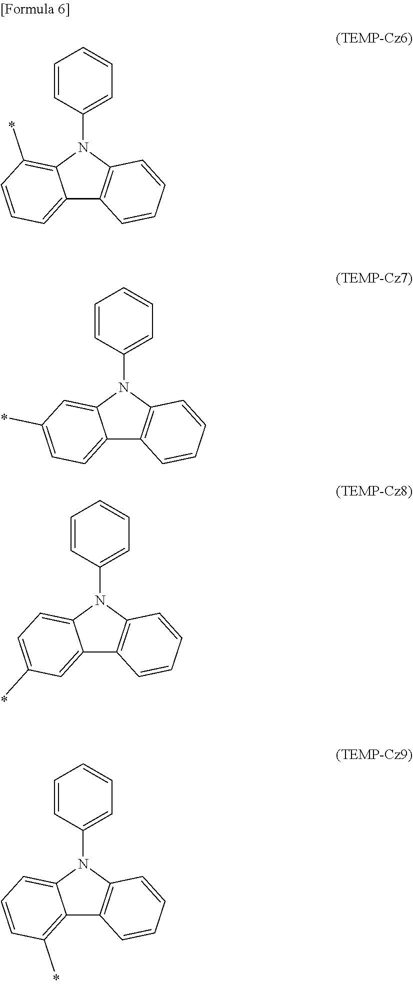

In the formulae (TEMP-Cz1) to (TEMP-Cz9), * represents a bonding position.

The dibenzofuranyl group and dibenzothiophenyl group mentioned herein are, unless otherwise specified herein, each specifically represented by one of formulae below.

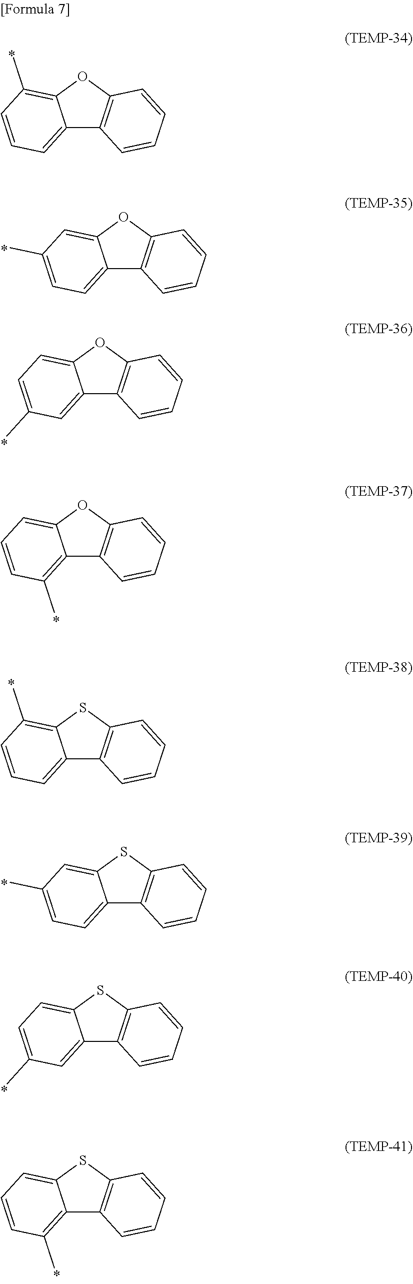

In the formulae (TEMP-34) to (TEMP-41), * represents a bonding position.

Preferable examples of the substituted or unsubstituted alkyl group mentioned herein include, unless otherwise specified herein, a methyl group, ethyl group, propyl group, isopropyl group, n-butyl group, isobutyl group, and t-butyl group.

### Substituted or Unsubstituted Arylene Group

The “substituted or unsubstituted arylene group” mentioned herein is, unless otherwise specified herein, a divalent group derived by removing one hydrogen atom on an aryl ring of the “substituted or unsubstituted aryl group.” Specific examples of the “substituted or unsubstituted arylene group” (specific example group G12) include a divalent group derived by removing one hydrogen atom on an aryl ring of the “substituted or unsubstituted aryl group” in the specific example group G1.

### Substituted or Unsubstituted Divalent Heterocyclic Group

The “substituted or unsubstituted divalent heterocyclic group” mentioned herein is, unless otherwise specified herein, a divalent group derived by removing one hydrogen atom on a heterocycle of the “substituted or unsubstituted heterocyclic group.” Specific examples of the “substituted or unsubstituted divalent heterocyclic group” (specific example group G13) include a divalent group derived by removing one hydrogen atom on a heterocyclic ring of the “substituted or unsubstituted heterocyclic group” in the specific example group G2.

### Substituted or Unsubstituted Alkylene Group

The “substituted or unsubstituted alkylene group” mentioned herein is, unless otherwise specified herein, a divalent group derived by removing one hydrogen atom on an alkyl chain of the “substituted or unsubstituted alkyl group.” Specific examples of the “substituted or unsubstituted alkylene group” (specific example group G14) include a divalent group derived by removing one hydrogen atom on an alkyl chain of the “substituted or unsubstituted alkyl group” in the specific example group G3.

The substituted or unsubstituted arylene group mentioned herein is, unless otherwise specified herein, preferably any one of groups represented by formulae (TEMP-42) to (TEMP-68) below.

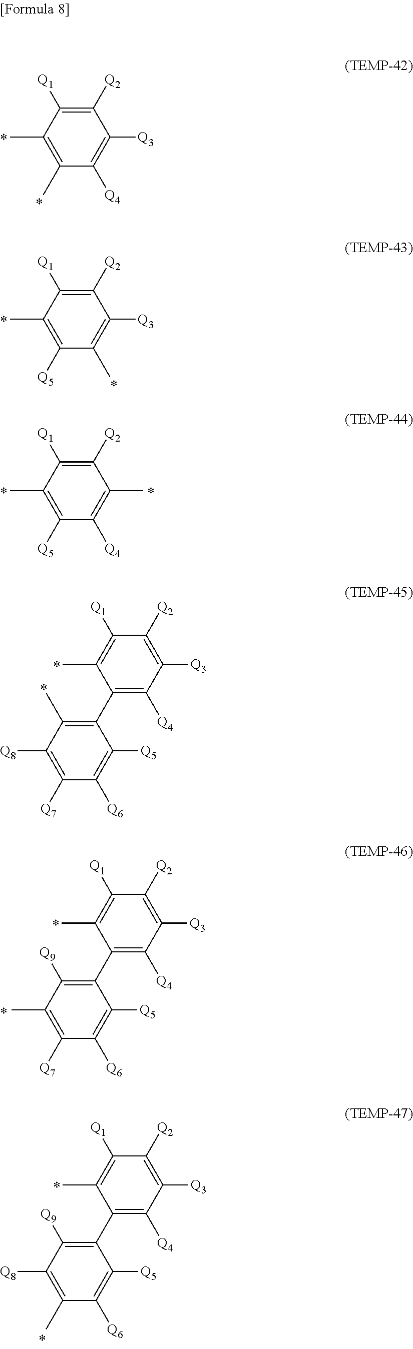

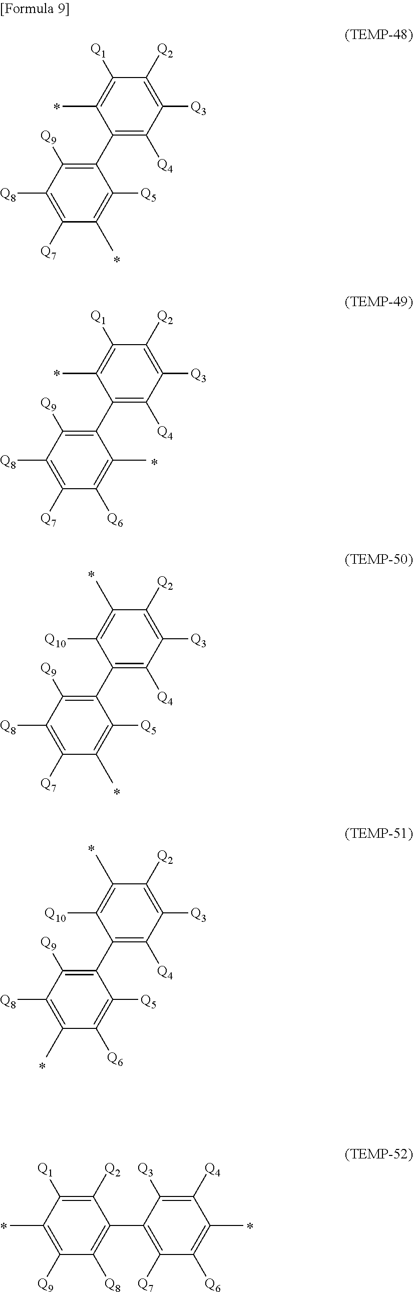

In the formulae (TEMP-42) to (TEMP-52), Q₁ to Q₁₀ are each independently a hydrogen atom or a substituent.

In the formulae (TEMP-42) to (TEMP-52), * represents a bonding position.

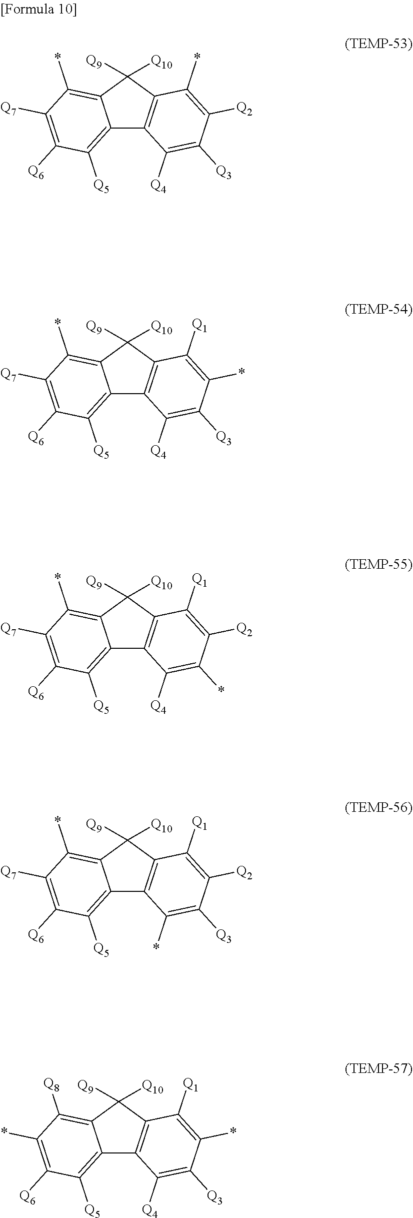

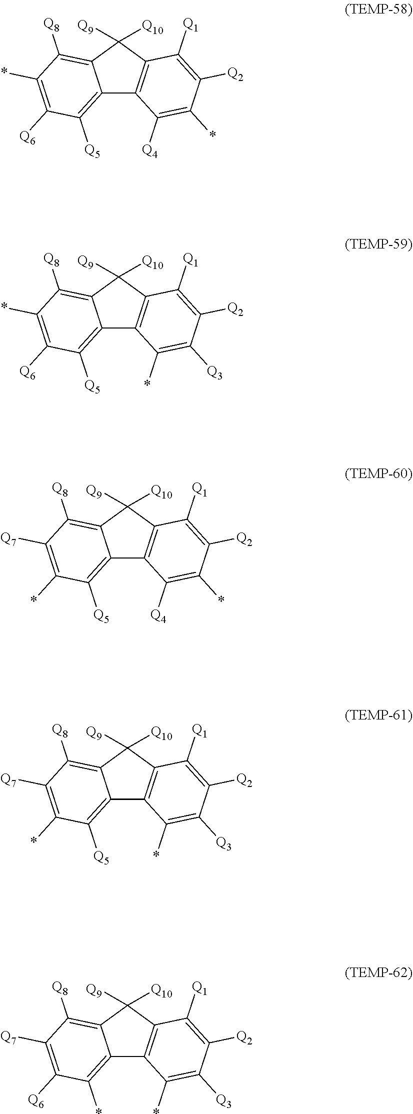

In the formulae (TEMP-53) to (TEMP-62), Q₁ to Q₁₀ are each independently a hydrogen atom or a substituent.

In the formulae, Q₉ and Q₁₀ may be mutually bonded through a single bond to form a ring.

In the formulae (TEMP-53) to (TEMP-62), * represents a bonding position.

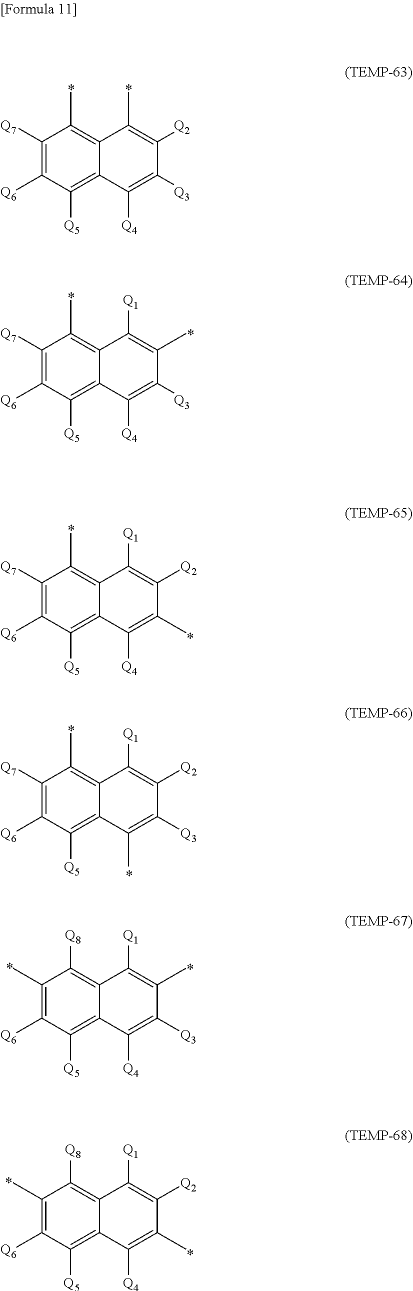

In the formulae (TEMP-63) to (TEMP-68), Q₁ to Q₈ are each independently a hydrogen atom or a substituent.

In the formulae (TEMP-63) to (TEMP-68), * represents a bonding position.

The substituted or unsubstituted divalent heterocyclic group mentioned herein is, unless otherwise specified herein, preferably a group represented by any one of formulae (TEMP-69) to (TEMP-102) below.

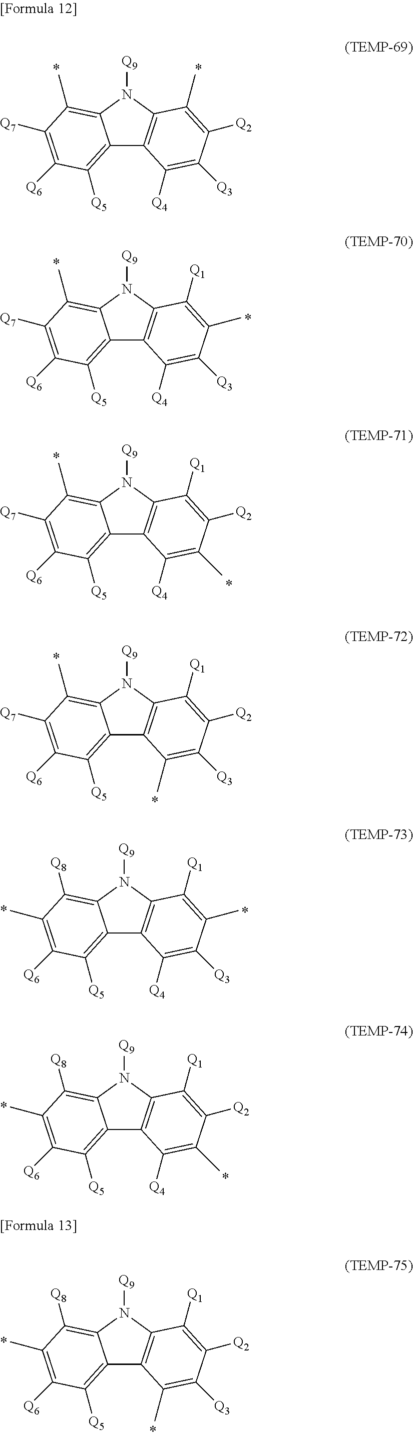

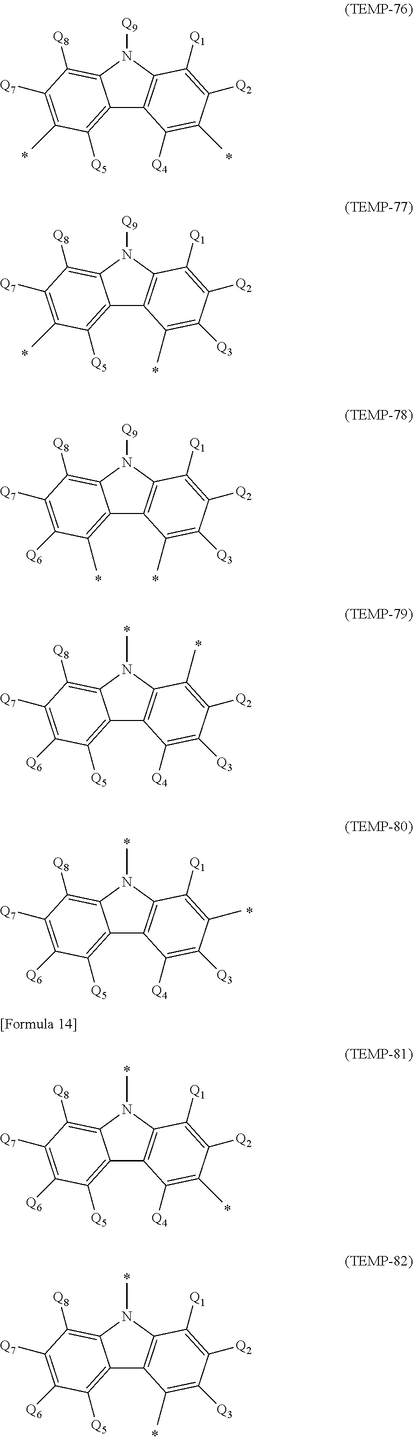

In the formulae (TEMP-69) to (TEMP-82), Q₁ to Q₉ are each independently a hydrogen atom or a substituent.

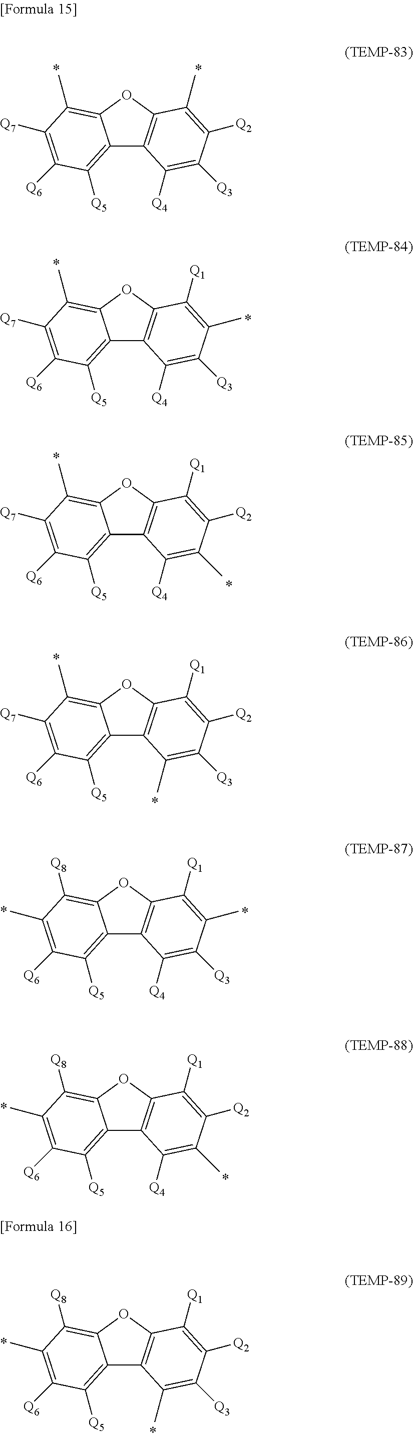

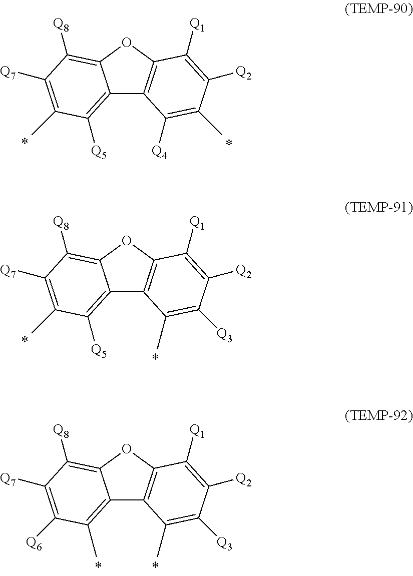

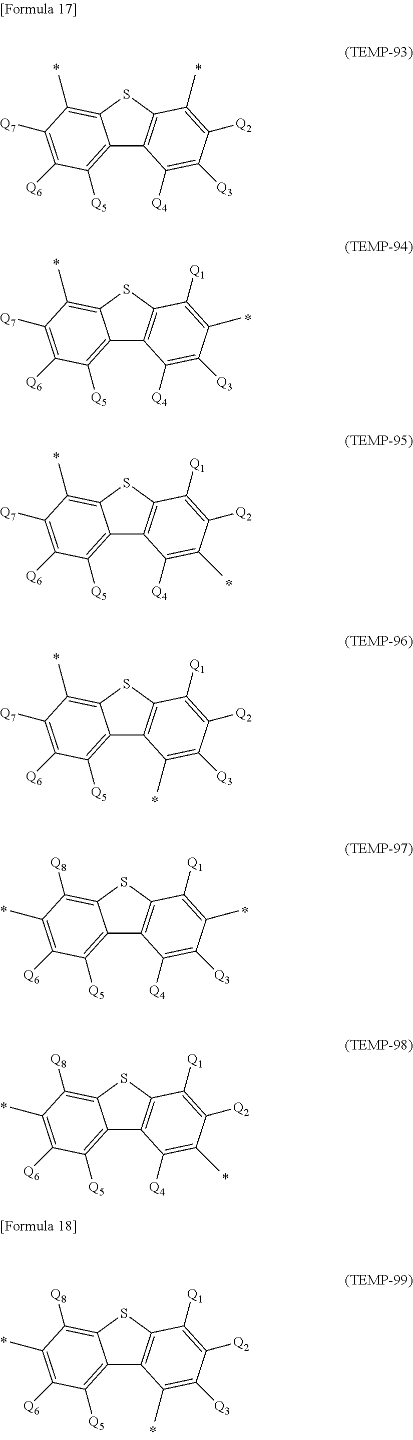

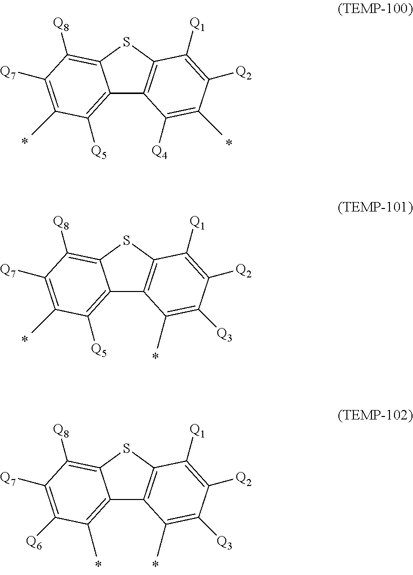

In the formulae (TEMP-83) to (TEMP-102), Q₁ to Q₈ are each independently a hydrogen atom or a substituent.

The substituent mentioned herein has been described above.

### Instance of “Bonded to Form Ring”

Instances where “at least one combination of adjacent two or more (of . . . ) are mutually bonded to form a substituted or unsubstituted monocyclic ring, mutually bonded to form a substituted or unsubstituted fused ring, or not mutually bonded” mentioned herein refer to instances where “at least one combination of adjacent two or more (of . . . ) are mutually bonded to form a substituted or unsubstituted monocyclic ring, “at least one combination of adjacent two or more (of . . . ) are mutually bonded to form a substituted or unsubstituted fused ring,” and “at least one combination of adjacent two or more (of . . . ) are not mutually bonded.”

Instances where “at least one combination of adjacent two or more (of . . . ) are mutually bonded to form a substituted or unsubstituted monocyclic ring” and “at least one combination of adjacent two or more (of . . . ) are mutually bonded to form a substituted or unsubstituted fused ring” mentioned herein (these instances will be sometimes collectively referred to as an instance of “bonded to form a ring” hereinafter) will be described below. An anthracene compound having a basic skeleton in a form of an anthracene ring and represented by a formula (TEMP-103) below will be used as an example for the description.

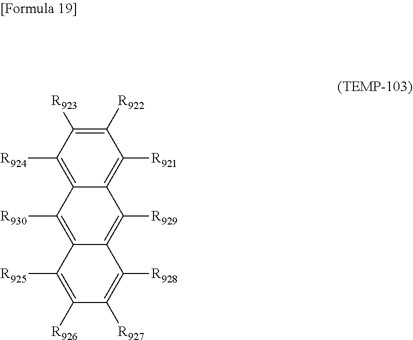

For instance, when “at least one combination of adjacent two or more of R₉₂₁ to R₉₃₀ are mutually bonded to form a ring,” the combination of adjacent ones of R₉₂₁ to R₉₃₀ (i.e. the combination at issue) is a combination of R₉₂₁ and R₉₂₂, a combination of R₉₂₂ and R₉₂₃, a combination of R₉₂₃ and R₉₂₄, a combination of R₉₂₄ and R₉₃₀, a combination of R₉₃₀ and R₉₂₅, a combination of R₉₂₅ and R₉₂₆, a combination of R₉₂₆ and R₉₂₇, a combination of R₉₂₇ and R₉₂₈, a combination of R₉₂₈ and R₉₂₉, or a combination of R₉₂₉ and R₉₂₁.

The term “at least one combination” means that two or more of the above combinations of adjacent two or more of R₉₂₁ to R₉₃₀ may simultaneously form rings. For instance, when R₉₂₁ and R₉₂₂ are mutually bonded to form a ring Q_{A} and R₉₂₅ and R₉₂₆ are simultaneously mutually bonded to form a ring Q_{B}, the anthracene compound represented by the formula (TEMP-103) is represented by a formula (TEMP-104) below.

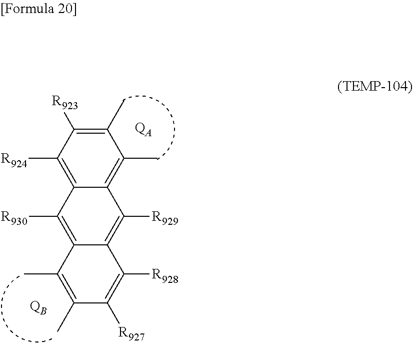

The instance where the “combination of adjacent two or more” form a ring means not only an instance where the “two” adjacent components are bonded but also an instance where adjacent “three or more” are bonded. For instance, R₉₂₁ and R₉₂₂ are mutually bonded to form a ring Q_{A} and R₉₂₂ and R₉₂₃ are mutually bonded to form a ring Q_{C}, and mutually adjacent three components (R₉₂₁, R₉₂₂ and R₉₂₃) are mutually bonded to form a ring fused to the anthracene basic skeleton. In this case, the anthracene compound represented by the formula (TEMP-103) is represented by a formula (TEMP-105) below. In the formula (TEMP-105) below, the ring Q_{A} and the ring Q_{C} share R₉₂₂.

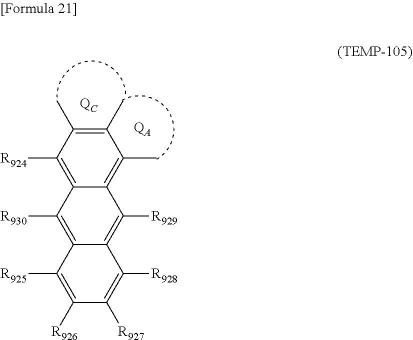

The formed “monocyclic ring” or “fused ring” may be, in terms of the formed ring in itself, a saturated ring or an unsaturated ring. When the “combination of adjacent two” form a “monocyclic ring” or a “fused ring,” the “monocyclic ring” or “fused ring” may be a saturated ring or an unsaturated ring. For instance, the ring Q_{A} and the ring Q_{B} formed in the formula (TEMP-104) are each independently a “monocyclic ring” or a “fused ring.” Further, the ring Q_{A} and the ring Q_{c} formed in the formula (TEMP-105) are each a “fused ring.” The ring Q_{A} and the ring Q_{c} in the formula (TEMP-105) are fused to form a fused ring. When the ring Q_{A} in the formula (TEMP-104) is a benzene ring, the ring Q_{A} is a monocyclic ring. When the ring Q_{A} in the formula (TEMP-104) is a naphthalene ring, the ring Q_{A} is a fused ring.

The “unsaturated ring” represents an aromatic hydrocarbon ring or an aromatic heterocycle. The “saturated ring” represents an aliphatic hydrocarbon ring or a non-aromatic heterocycle.

Specific examples of the aromatic hydrocarbon ring include a ring formed by terminating a bond of a group in the specific example of the specific example group G1 with a hydrogen atom.

Specific examples of the aromatic heterocycle include a ring formed by terminating a bond of an aromatic heterocyclic group in the specific example of the specific example group G2 with a hydrogen atom.

Specific examples of the aliphatic hydrocarbon ring include a ring formed by terminating a bond of a group in the specific example of the specific example group G6 with a hydrogen atom.

The phrase “to form a ring” herein means that a ring is formed only by a plurality of atoms of a basic skeleton, or by a combination of a plurality of atoms of the basic skeleton and one or more optional atoms. For instance, the ring Q_{A} formed by mutually bonding R₉₂₁ and R₉₂₂ shown in the formula (TEMP-104) is a ring formed by a carbon atom of the anthracene skeleton bonded to R₉₂₁, a carbon atom of the anthracene skeleton bonded to R₉₂₂, and one or more optional atoms. Specifically, when the ring Q_{A} is a monocyclic unsaturated ring formed by R₉₂₁ and R₉₂₂, the ring formed by a carbon atom of the anthracene skeleton bonded to R₉₂₁, a carbon atom of the anthracene skeleton bonded to R₉₂₂, and four carbon atoms is a benzene ring.

The “optional atom” is, unless otherwise specified herein, preferably at least one atom selected from the group consisting of a carbon atom, nitrogen atom, oxygen atom, and sulfur atom. A bond of the optional atom (e.g. a carbon atom and a nitrogen atom) not forming a ring may be terminated by a hydrogen atom or the like or may be substituted by an “optional substituent” described later. When the ring includes any other optional element than the carbon atom, the resultant ring is a heterocycle.

The number of “one or more optional atoms” forming the monocyclic ring or fused ring is, unless otherwise specified herein, preferably in a range from 2 to 15, more preferably in a range from 3 to 12, further preferably in a range from 3 to 5.

Unless otherwise specified herein, the ring, which may be a “monocyclic ring” or “fused ring,” is preferably a “monocyclic ring.”

Unless otherwise specified herein, the ring, which may be a “saturated ring” or “unsaturated ring,” is preferably an “unsaturated ring.”

Unless otherwise specified herein, the “monocyclic ring” is preferably a benzene ring.

Unless otherwise specified herein, the “unsaturated ring” is preferably a benzene ring.

When “at least one combination of adjacent two or more” (of . . . ) are “mutually bonded to form a substituted or unsubstituted monocyclic ring” or “mutually bonded to form a substituted or unsubstituted fused ring,” unless otherwise specified herein, at least one combination of adjacent two or more of components are preferably mutually bonded to form a substituted or unsubstituted “unsaturated ring” formed of a plurality of atoms of the basic skeleton, and 1 to 15 atoms of at least one element selected from the group consisting of carbon, nitrogen, oxygen and sulfur.

When the “monocyclic ring” or the “fused ring” has a substituent, the substituent is the substituent described in later-described “optional substituent.” When the “monocyclic ring” or the “fused ring” has a substituent, specific examples of the substituent are the substituents described in the above under the subtitle “Substituent Mentioned Herein.”

When the “saturated ring” or the “unsaturated ring” has a substituent, the substituent is the substituent described in later-described “optional substituent.” When the “monocyclic ring” or the “fused ring” has a substituent, specific examples of the substituent are the substituents described in the above under the subtitle “Substituent Mentioned Herein.”

The above is the description for the instances where “at least one combination of adjacent two or more (of . . . ) are mutually bonded to form a substituted or unsubstituted monocyclic ring” and “at least one combination of adjacent two or more (of . . . ) are mutually bonded to form a substituted or unsubstituted fused ring” mentioned herein (sometimes referred to as an instance of “bonded to form a ring”).

### Substituent for Substituted or Unsubstituted Group

In an exemplary embodiment herein, the substituent for the substituted or unsubstituted group (hereinafter occasionally referred to as an “optional substituent”), is for instance, a group selected from the group consisting of an unsubstituted alkyl group having 1 to 50 carbon atoms, an unsubstituted alkenyl group having 2 to 50 carbon atoms, an unsubstituted alkynyl group having 2 to 50 carbon atoms, an unsubstituted cycloalkyl group having 3 to 50 ring carbon atoms, —Si(R₉₀₁)(R₉₀₂)(R₉₀₃), —O—(R₉₀₄), —S—(R₉₀₅), —N(R₉₀₆)(R₉₀₇), a halogen atom, a cyano group, a nitro group, an unsubstituted aryl group having 6 to 50 ring carbon atoms, and an unsubstituted heterocyclic group having 5 to 50 ring atoms;

R₉₀₁ to R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;

when two or more R₉₀₁ are present, the two or more R₉₀₁ are mutually the same or different;

when two or more R₉₀₂ are present, the two or more R₉₀₂ are mutually the same or different;

when two or more R₉₀₃ are present, the two or more R₉₀₃ are mutually the same or different;

when two or more R₉₀₄ are present, the two or more R₉₀₄ are mutually the same or different;

when two or more R₉₀₅ are present, the two or more R₉₀₅ are mutually the same or different;

when two or more R₉₀₆ are present, the two or more R₉₀₆ are mutually the same or different; and

when two or more R₉₀₇ are present, the two or more R₉₀₇ are mutually the same or different.

In an exemplary embodiment, the substituent for the substituted or unsubstituted group is a group selected from the group consisting of an alkyl group having 1 to 50 carbon atoms, an aryl group having 6 to 50 ring carbon atoms, and a heterocyclic group having 5 to 50 ring atoms.

In an exemplary embodiment, the substituent for the substituted or unsubstituted group is a group selected from the group consisting of an alkyl group having 1 to 18 carbon atoms, an aryl group having 6 to 18 ring carbon atoms, and a heterocyclic group having 5 to 18 ring atoms.

Specific examples of the above optional substituent are the same as the specific examples of the substituent described in the above under the subtitle “Substituent Mentioned Herein.”

Unless otherwise specified herein, adjacent ones of the optional substituents may form a “saturated ring” or an “unsaturated ring,” preferably a substituted or unsubstituted saturated five-membered ring, a substituted or unsubstituted saturated six-membered ring, a substituted or unsubstituted unsaturated five-membered ring, or a substituted or unsubstituted unsaturated six-membered ring, more preferably a benzene ring.

Unless otherwise specified herein, the optional substituent may further include a substituent. Examples of the substituent for the optional substituent are the same as the examples of the optional substituent.

Herein, numerical ranges represented by “AA to BB” represent a range whose lower limit is the value (AA) recited before “to” and whose upper limit is the value (BB) recited after “to.”

### First Exemplary Embodiment

### Organic Electroluminescence Device

An organic electroluminescence device according to the exemplary embodiment includes: an anode; a cathode; an emitting region disposed between the anode and the cathode; and a hole transporting zone disposed between the anode and the emitting region, in which the emitting region includes a first emitting layer and a second emitting layer, the first emitting layer is disposed close to the anode in the emitting region, the hole transporting zone is in direct contact with the anode and the first emitting layer, the hole transporting zone includes one or more organic layers, at least one of the organic layers in the hole transporting zone is a first organic layer that is in direct contact with the first emitting layer, the first organic layer contains a hole transporting zone material, the first emitting layer contains a first host material and a first emitting compound that emits light having a maximum peak wavelength of 500 nm or less, the second emitting layer contains a second host material and a second emitting compound that emits light having a maximum peak wavelength of 500 nm or less, the first host material is different from the second host material, the first emitting compound and the second emitting compound are mutually the same or different, and a triplet energy of the first host material T₁(H1) and a triplet energy of the second host material T₁(H2) satisfy a relationship of a numerical formula (Numerical Formula 1) below.

T₁(H1)>T₁(H2) (Numerical Formula 1)

In the emitting region of the organic electroluminescence device according to the exemplary embodiment, the dipole of the first host material contained in the first emitting layer is 0.4 D or more.

Conventionally, Triplet-Triplet-Annihilation (occasionally referred to as TTA) has been known as a technique for improving the luminous efficiency of the organic electroluminescence device. TTA is a mechanism in which triplet excitons collide with one another to generate singlet excitons. The TTA mechanism is also referred to as a TTF mechanism as described in Patent Literature 3.

The TTF phenomenon will be described. Holes injected from an anode and electrons injected from a cathode are recombined in an emitting layer to generate excitons. As for the spin state, as is conventionally known, singlet excitons account for 25% and triplet excitons account for 75%. In a conventionally known fluorescent device, light is emitted when singlet excitons of 25% are relaxed to the ground state. The remaining triplet excitons of 75% are returned to the ground state without emitting light through a thermal deactivation process. Accordingly, the theoretical limit value of the internal quantum efficiency of the conventional fluorescent device is believed to be 25%.

The behavior of triplet excitons generated within an organic substance has been theoretically examined. According to S. M. Bachilo et al. (J. Phys. Chem. A, 104, 7711 (2000)), assuming that high-order excitons such as quintet excitons are quickly returned to triplet excitons, triplet excitons (hereinafter abbreviated as ³A*) collide with one another with an increase in density thereof, whereby a reaction shown by the following formula occurs. In the formula, ¹A represents the ground state and ¹A* represents the lowest singlet excitons.

³A*+³A*→(4/9)¹A+(1/9)¹A*+(13/9)³A*

In other words, 5³A*→4¹A+¹A* is satisfied, and it is expected that, among triplet excitons initially generated, which account for 75%, one fifth thereof (i.e., 20%) is changed to singlet excitons. Accordingly, the amount of singlet excitons which contribute to emission is 40%, which is a value obtained by adding 15% (75%×(1/5)=15%) to 25%, which is the amount ratio of initially generated singlet excitons. At this time, a ratio of luminous intensity derived from TTF (TTF ratio) relative to the total luminous intensity is 15/40, i.e., 37.5%. Assuming that singlet excitons are generated by collision of initially generated triplet excitons accounting for 75% (i.e., one singlet exciton is generated from two triplet excitons), a significantly high internal quantum efficiency of 62.5% is obtained, which is a value obtained by adding 37.5% (75%×(1/2)=37.5%) to 25% (the amount ratio of initially generated singlet excitons). At this time, the TTF ratio is 37.5/62.5=60%.

In the organic electroluminescence device according to the exemplary embodiment, it is considered that triplet excitons generated by recombination of holes and electrons in the first emitting layer and present on an interface between the first emitting layer and organic layer(s) in direct contact therewith are not likely to be quenched even under the presence of excessive carriers on the interface between the first emitting layer and the organic layer(s). For instance, the presence of a recombination region locally on an interface between the first emitting layer and a hole transporting layer or an electron blocking layer is considered to cause quenching by excessive electrons. Meanwhile, the presence of a recombination region locally on an interface between the first emitting layer and an electron transporting layer or a hole blocking layer is considered to cause quenching by excessive holes.

The organic electroluminescence device according to the exemplary embodiment includes at least two emitting layers (i.e., the first emitting layer and the second emitting layer) satisfying a predetermined relationship. The triplet energy of the first host material T₁(H1) in the first emitting layer and the triplet energy of the second host material T₁(H2) in the second emitting layer satisfy the relationship represented by the numerical formula (Numerical Formula 1).

By including the first emitting layer and the second emitting layer so as to satisfy the relationship of the numerical formula (Numerical Formula 1), triplet excitons generated in the first emitting layer can transfer to the second emitting layer without being quenched by excessive carriers and be inhibited from back-transferring from the second emitting layer to the first emitting layer. Consequently, the second emitting layer exhibits the TTF mechanism to effectively generate singlet excitons, thereby improving the luminous efficiency.

Accordingly, the organic electroluminescence device includes, as different regions, the first emitting layer mainly generating triplet excitons and the second emitting layer mainly exhibiting the TTF mechanism using triplet excitons having transferred from the first emitting layer, and has a difference in triplet energy provided by using a compound having a smaller triplet energy than that of the first host material in the first emitting layer as the second host material in the second emitting layer. The luminous efficiency is thus improved.

The organic EL device according to the exemplary embodiment includes the first emitting layer and the second emitting layer satisfying the relationship of the numerical formula (Numerical Formula 1), which improves the luminous efficiency of the device.

The organic EL device according to the exemplary embodiment has a layer arrangement (layer-saving arrangement) in which the number of organic layers forming the hole transporting zone between the emitting region and the anode is reduced. In the organic EL device with the layer-saving arrangement, the supply amount of holes to the emitting region is likely to be insufficient, which may decrease luminous efficiency.

In the organic EL device according to the exemplary embodiment, since a material with a large dipole (0.4 D or more) is used as the first host material contained in the first emitting layer that is in direct contact with the hole transporting zone, the transfer of holes from the hole transporting zone to the emitting region is facilitated. This easily achieves high efficiency even in a layer-saving arrangement of the hole transporting zone (e.g., the hole transporting zone with two layers) in which the supply amount of holes to the emitting region is likely to be insufficient.

In the organic EL device according to the exemplary embodiment, in order to facilitate the transfer of holes from the hole transporting zone to the emitting region, an ionization potential of the first host material contained in the first emitting layer is preferably smaller than 5.85 eV, more preferably 5.82 eV or less, and still more preferably 5.80 eV or less.

In the organic EL device according to the exemplary embodiment, in order to facilitate the dipole adjustment, the first host material contained in the first emitting layer preferably has a heterocyclic structure in which an oxygen atom or sulfur atom is contained in a molecule.

In an exemplary embodiment, one layer is provided between the anode and the emitting region.

In an exemplary embodiment, two layers are provided between the anode and the emitting region.

In an exemplary embodiment, not less than three layers are provided between the anode and the emitting region.

In an exemplary embodiment, the hole transporting zone disposed between the anode and the emitting region includes at least one organic layer of the hole injecting layer, the hole transporting layer, or the electron blocking layer.

For instance, the electron blocking layer permits transport of holes and blocks electrons from reaching a layer provided closer to the anode (e.g., hole transporting layer or hole injecting layer) beyond the electron blocking layer. Alternatively, the electron blocking layer may inhibit excitation energy from leaking out from the emitting region toward neighboring layer(s). In this case, the electron blocking layer blocks excitons generated in the emitting region from being transferred to a layer provided closer to the anode (e.g., hole transporting layer and hole injecting layer) beyond the electron blocking layer.

In the organic EL device according to the exemplary embodiment, the hole transporting zone may contain no material different from the hole transporting zone material.

In the organic EL device according to the exemplary embodiment, the hole transporting zone may consist of the first organic layer.

In the organic EL device according to the exemplary embodiment, the first organic layer may contain no material different from the hole transporting zone material.

In the organic EL device according to the exemplary embodiment, preferably, the organic layers in the hole transporting zone each contain the hole transporting zone material as a common hole transporting zone material.

In the organic EL device according to the exemplary embodiment, preferably, the organic layers in the hole transporting zone each contain a hole transporting zone material that is common to the organic layers.

Herein, the wording “common hole transporting material” is occasionally used for a hole transporting zone material contained commonly in all the organic layers in the hole transporting zone.

When the hole transporting zone includes one organic layer, the one organic layer (first organic layer) contains a hole transporting zone material. When the hole transporting zone includes two organic layers, the two organic layers preferably contain an identical compound as a common hole transporting zone material. When the hole transporting zone includes three organic layers, at least two of the organic layers preferably contain an identical compound as the common hole transporting zone material. More preferably, the three organic layers contain an identical compound as the common hole transporting zone material.

The hole transporting zone material contained in the organic layer(s) in the hole transporting zone may be a single compound or a mixture containing two or more compounds.

The common hole transporting zone material that may be contained in all the organic layers in the hole transporting zone may be a single compound or a mixture containing two or more compounds.

In the organic EL device according to the exemplary embodiment, the hole transporting zone also preferably includes the first organic layer and a second organic layer disposed between the first organic layer and the anode. The second organic layer may be in direct contact with the anode. The first organic layer and the second organic layer may be in direct contact with each other.

In the organic EL device according to the exemplary embodiment, also preferably, the first organic layer contains the hole transporting zone material and further contains a first hole transporting zone material different from the hole transporting zone material. The first hole transporting zone material is a compound having a molecule structure different from that of the hole transporting zone material.

In the organic EL device according to the exemplary embodiment, when the hole transporting zone includes the first organic layer and the second organic layer, it is also preferable that the second organic layer contains the hole transporting zone material and further contains a second hole transporting zone material different from the hole transporting zone material.

In the organic EL device according to the exemplary embodiment, when the hole transporting zone includes the first organic layer and the second organic layer, it is also preferable that the first organic layer contains the hole transporting zone material and the first hole transporting zone material different from the hole transporting zone material and the second organic layer contains the hole transporting zone material and the second hole transporting zone material different from the hole transporting zone material.

In the organic EL device according to the exemplary embodiment, the second hole transporting zone material is also preferably a doped compound (compound having a molecule structure different from that of the hole transporting zone material).

In the organic EL device according to the exemplary embodiment, when the hole transporting zone includes the first organic layer and the second organic layer, the first organic layer may be larger in film thickness than the second organic layer.

The film thickness of the second organic layer is preferably in a range from 5 nm to 15 nm.

In the organic EL device according to the exemplary embodiment, when each organic layer in the hole transporting zone contains the common hole transporting zone material, the content of the common hole transporting zone material in each organic layer is preferably 40 mass % or more, more preferably 45 mass % or more, and still more preferably 50 mass % or more. The upper limit of the content of the common hole transporting zone material in each organic layer is 100 mass %.

When the common hole transporting zone material in each organic layer is a mixture containing two or more, the upper limit of the content of the common hole transporting zone material (mixture) in each organic layer is 100 mass %.

In the organic EL device according to the exemplary embodiment, when the hole transporting zone includes the first organic layer and the second organic layer and the second organic layer contains the common hole transporting zone material and the doped compound as the second hole transporting zone material, the content of the doped compound in the second organic layer is preferably in a range from 0.5 mass % to 5 mass %, more preferably in a range from 1.0 mass % to 3 mass %. The content of the common hole transporting zone material in the second organic layer is preferably 40 mass % or more, more preferably 45 mass % or more, and still more preferably 50 mass % or more. The content of the common hole transporting zone material in the second organic layer is preferably 99.5 mass % or less. The total of contents of the common hole transporting zone material and the doped compound in the second organic layer is 100 mass % or less.

In the organic EL device according to the exemplary embodiment, the hole transporting zone may include the first organic layer, the second organic layer, and a third organic layer disposed between the second organic layer and the anode. The third organic layer may be in direct contact with the anode. The first organic layer, the second organic layer, and the third organic layer may be in contact with each other.

In the organic EL device according to the exemplary embodiment, when the hole transporting zone includes the first organic layer, the second organic layer, and the third organic layer, it is also preferable that the third organic layer contains the hole transporting zone material and further contains a third hole transporting zone material different from the hole transporting zone material. Also preferably, the second organic layer contains the hole transporting zone material and further contains the second hole transporting zone material different from the hole transporting zone material. Also preferably, the first organic layer contains the hole transporting zone material and further contains the first hole transporting zone material different from the hole transporting zone material.

The first hole transporting zone material, the second hole transporting zone material, and the third hole transporting zone material are mutually the same or different.

In the organic EL device according to the exemplary embodiment, when the hole transporting zone includes the first organic layer, the second organic layer, and the third organic layer and the third organic layer contains the third hole transporting zone material, the third hole transporting zone material is also preferably a doped compound.

In the organic EL device according to the exemplary embodiment, when the hole transporting zone includes the first organic layer, the second organic layer, and the third organic layer, it is also preferable that the first organic layer contains the hole transporting zone material and the first hole transporting zone material different from the hole transporting zone material and the third organic layer contains the hole transporting zone material and the third hole transporting zone material different from the hole transporting zone material. In this arrangement, the first hole transporting zone material and the third hole transporting zone material are mutually the same or different.

In the organic EL device according to the exemplary embodiment, when the hole transporting zone includes the first organic layer, the second organic layer, and the third organic layer, the first organic layer is also preferably larger in film thickness than the second organic layer and the third organic layer.

In the organic EL device according to the exemplary embodiment, when the hole transporting zone includes the first organic layer, the second organic layer, and the third organic layer, the second organic layer is also preferably larger in film thickness than the first organic layer and the third organic layer.

In the organic EL device according to the exemplary embodiment, when the hole transporting zone includes the first organic layer, the second organic layer, and the third organic layer, the third organic layer is also preferably smaller in film thickness than the first organic layer and the second organic layer.

The film thickness of the third organic layer is preferably in a range from 5 nm to 15 nm.

In the organic EL device according to the exemplary embodiment, when the hole transporting zone includes the first organic layer, the second organic layer, and the third organic layer and the third organic layer contains the common hole transporting zone material and the doped compound as the third hole transporting zone material, the content of the doped compound in the third organic layer and the content of the common hole transporting zone material in the third organic layer preferably fall within similar ranges of the content of the doped compound in the second organic layer and the content of the common hole transporting zone material in the second organic layer described above.

In the organic EL device according to the exemplary embodiment, when the hole transporting zone includes the first organic layer and the second organic layer, the first organic layer is also preferably a layer that contains the hole transporting zone material and the first hole transporting zone material different from the hole transporting zone material (hereinafter also referred to as a co-deposited layer). Making the first organic layer the co-deposited layer achieves both high hole transportability and hole injectability to the emitting layers, thus further improving luminous efficiency while omitting layers.

In the organic EL device according to the exemplary embodiment, when the hole transporting zone includes the first organic layer, the second organic layer, and the third organic layer, the first organic layer is also preferably a co-deposited layer. Making the first organic layer the co-deposited layer achieves both high hole transportability and hole injectability to the emitting layers, thus improving luminous efficiency.

In an organic EL display device provided with a blue-emitting organic EL device, a green-emitting organic EL device, and a red-emitting organic EL device, a hole transporting zone of the blue-emitting organic EL device may have four layers, which are the hole injecting layer, the first hole transporting layer, the second hole transporting layer as common layers and the electron blocking layer for the blue-emitting organic EL device as a non-common layer. Applying the organic EL device according to the exemplary embodiment to such an organic EL display device makes it possible to omit the electron blocking layer for the blue-emitting organic EL device from among the above four layers.

When the organic layer in the hole transporting zone is an organic layer containing a plurality of compounds, said organic layer is formable using the plurality of compounds by co-deposition; is formable, by vapor-deposition, using a mixture obtained by mixing in advance (premixing) the plurality of compounds; or formable, by coating, using a mixture obtained by mixing in advance (premixing) the plurality of compounds.

In the organic EL device according to the exemplary embodiment, for instance, the second organic layer also preferably contains a compound including at least one of a first cyclic structure represented by a formula (P11) below or a second cyclic structure represented by a formula (P12) below, as the doped compound (an example of the second hole transporting zone material), or also preferably contains a compound represented by a formula (21) described later or a formula (22) below, as the second hole transporting zone material.

In the organic EL device according to the exemplary embodiment, for instance, the third organic layer also preferably contains a compound including at least one of the first cyclic structure represented by the formula (P11) or the second cyclic structure represented by the formula (P12), as the doped compound (an example of the third hole transporting zone material), or also preferably contains at least one of a compound represented by the formula (21) or a compound represented by the formula (22), as the third hole transporting zone material.

In the organic EL device according to the exemplary embodiment, when the hole transporting zone includes the first organic layer and the second organic layer and the second organic layer is in direct contact with the anode, the second organic layer preferably contains the doped compound.

In the organic EL device according to the exemplary embodiment, when the hole transporting zone includes the first organic layer, the second organic layer, and the third organic layer and the third organic layer is in direct contact with the anode, the third organic layer preferably contains the doped compound. When the third organic layer contains the doped compound as the third hole transporting zone material, the second organic layer may not contain the second hole transporting zone material, but may contain, as the second hole transporting zone material, a compound different from the doped compound (e.g., at least one of a compound represented by the formula (21) or a compound represented by the formula (22)).

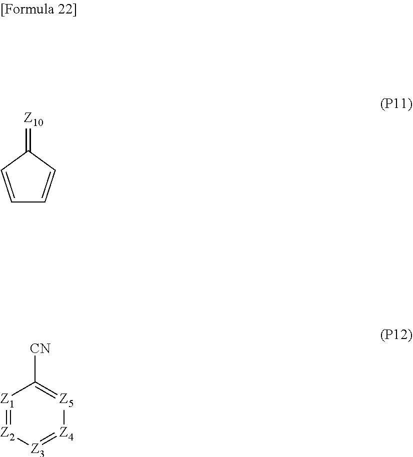

The first cyclic structure represented by the formula (P11) is fused to at least one cyclic structure of a substituted or unsubstituted aromatic hydrocarbon ring having 6 to 50 ring carbon atoms or a substituted or unsubstituted heterocycle having 5 to 50 ring atoms in a molecule of the doped compound, and a structure represented by ═Z₁₀ is represented by a formula (11a), (11b), (11c), (11d), (11e), (11f), (11g), (11h), (11i), (11j), (11k) or (11m) below.

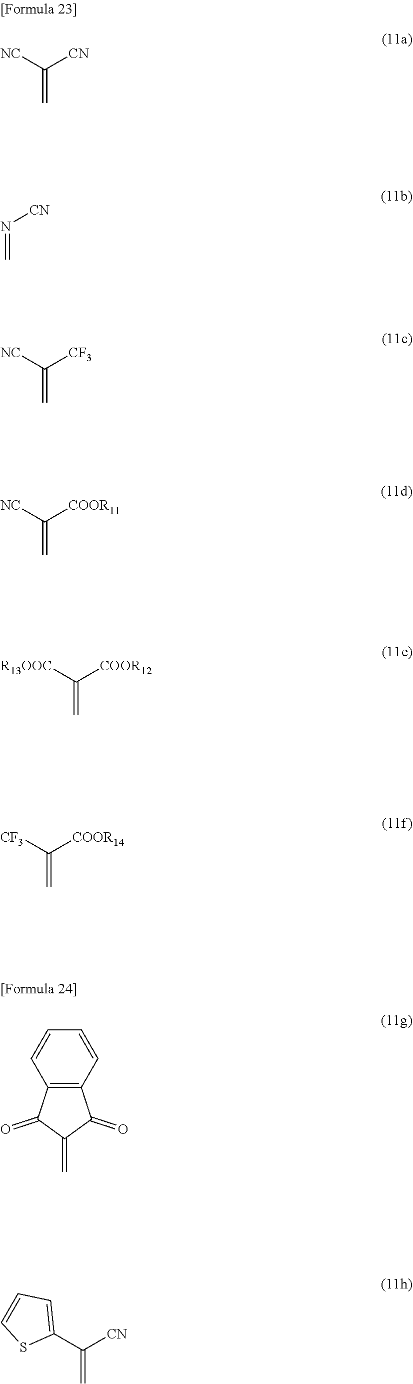

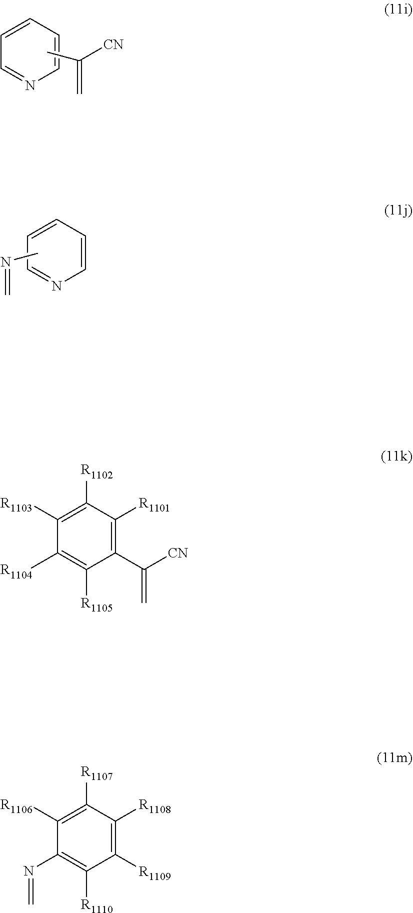

In the formula (11a), (11b), (11c), (11d), (11e), (11f), (11g), (11h), (11i), (11j), (11k) or (11m), R₁₁ to R₁₄ and R₁₁₀₁ to R₁₁₁₀ are each independently a hydrogen atom, a halogen atom, a hydroxy group, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aryl group having 6 to 50 ring carbon atoms, or a substituted or unsubstituted heterocyclic group having 5 to 50 ring atoms.

In the formula (P12), Z₁ to Z₅ are each independently a nitrogen atom, a carbon atom bonded to R₁₅, or a carbon atom bonded to another atom in a molecule of the doped compound;

at least one of Z₁ to Z₅ is a carbon atom bonded to another atom in a molecule of the doped compound;

R₁₅ is selected from the group consisting of a hydrogen atom, a halogen atom, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a substituted or unsubstituted aryl group having 6 to 50 ring carbon atoms, a substituted or unsubstituted heterocyclic group having 5 to 50 ring atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted alkenyl group having 2 to 50 carbon atoms, a substituted or unsubstituted aralkyl group having 7 to 50 carbon atoms, a carboxy group, a substituted or unsubstituted ester group, a substituted or unsubstituted carbamoyl group, a nitro group, and a substituted or unsubstituted siloxanyl group; and

when a plurality of R₁₅ are present, the plurality of R₁₅ are mutually the same or different.

In the doped compound, R₉₀₁ to R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;

when a plurality of R₉₀₁ are present, the plurality of R₉₀₁ are mutually the same or different;

when a plurality of R₉₀₂ are present, the plurality of R₉₀₂ are mutually the same or different;

when a plurality of R₉₀₃ are present, the plurality of R₉₀₃ are mutually the same or different;

when a plurality of R₉₀₄ are present, the plurality of R₉₀₄ are mutually the same or different;

when a plurality of R₉₀₅ are present, the plurality of R₉₀₅ are mutually the same or different;

when a plurality of R₉₀₆ are present, the plurality of R₉₀₆ are mutually the same or different; and

when a plurality of R₉₀₇ are present, the plurality of R₉₀₇ are mutually the same or different.

An ester group herein is at least one group selected from the group consisting of an alkyl ester group and an aryl ester group.

An alkyl ester group herein is represented, for instance, by —C(═O)OR^{E}. R^{E} is exemplified by a substituted or unsubstituted alkyl group having 1 to 50 carbon atoms (preferably 1 to 10 carbon atoms).

An aryl ester group herein is represented, for instance, by —C(═O)OR^{Ar}. R^{Ar} is exemplified by a substituted or unsubstituted aryl group having 6 to 30 ring carbon atoms.

A siloxanyl group herein, which is a silicon compound group through an ether bond, is exemplified by a trimethylsiloxanyl group.

A carbamoyl group herein is represented by —CONH₂.

A substituted carbamoyl group herein is represented, for instance, by —CONH—Ar^{C} or —CONH—R^{C}. Ar^{C} is, for instance, at least one group selected from the group consisting of a substituted or unsubstituted aryl group having 6 to 50 ring carbon atoms (preferably 6 to 10 ring carbon atoms) and a heterocyclic group having 5 to 50 ring atoms (preferably 5 to 14 ring atoms). Ar^{C} may be a group in which a substituted or unsubstituted aryl group having 6 to 50 ring carbon atoms is bonded to a substituted or unsubstituted heterocyclic group having 5 to 50 ring atoms.

R^{C} is exemplified by a substituted or unsubstituted alkyl group having 1 to 50 carbon atoms (preferably 1 to 6 carbon atoms).

In the doped compound, the groups specified to be “substituted or unsubstituted” are each preferably an “unsubstituted” group.

Specific examples of the doped compound (examples of the second hole transporting zone material and the third hole transporting zone material) include the following compounds. It should however be noted that the invention is not limited to the specific examples of the doped compound.

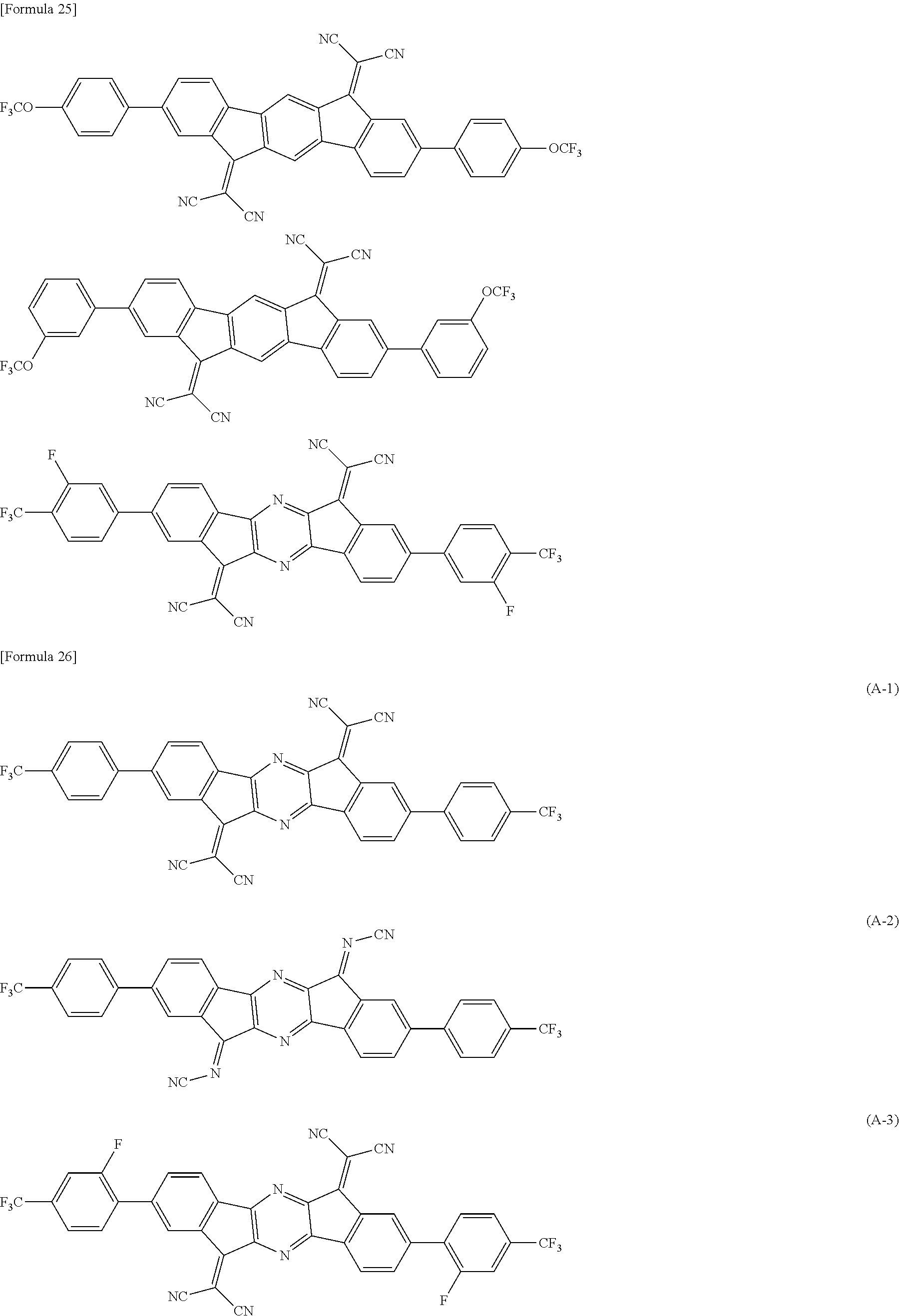

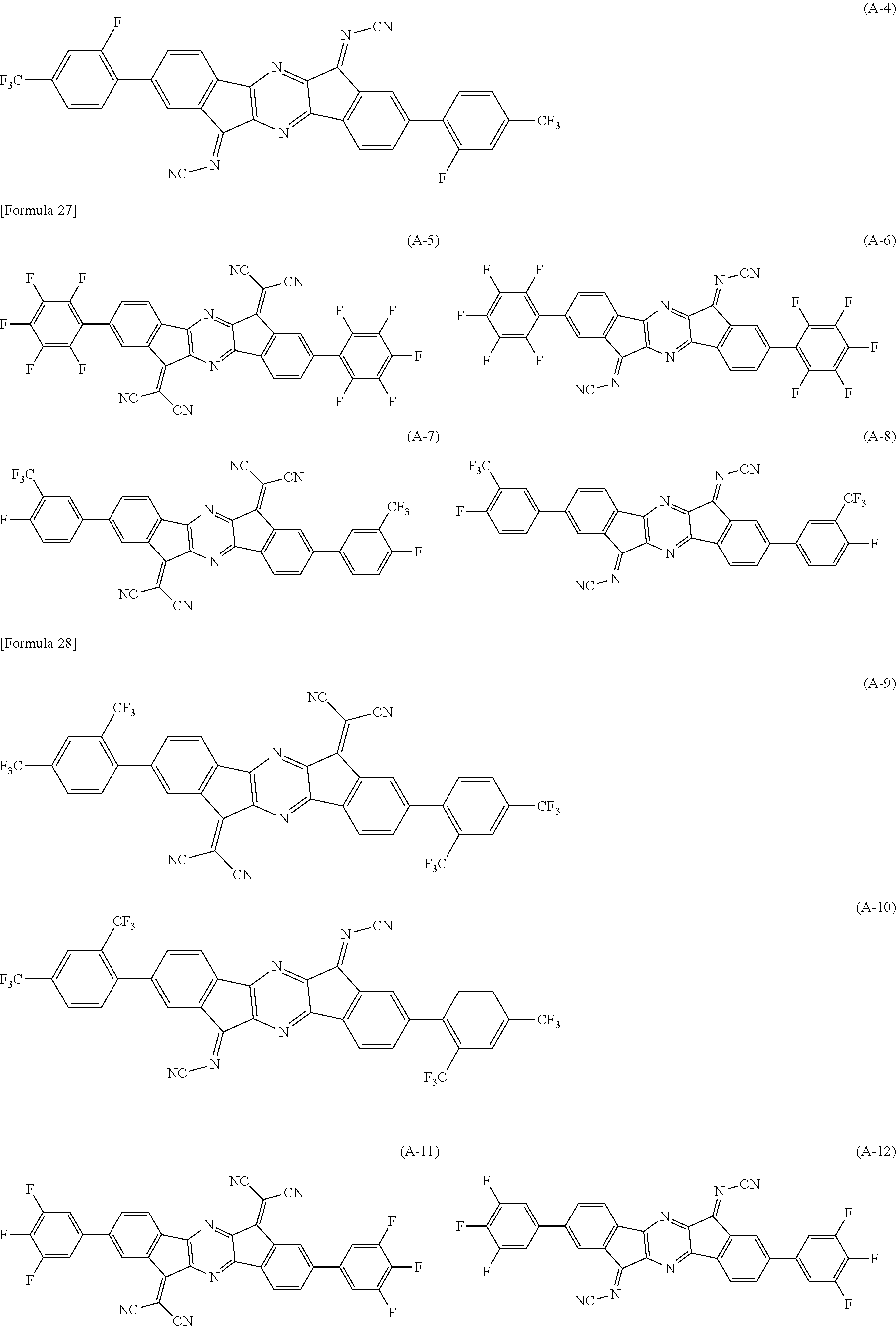

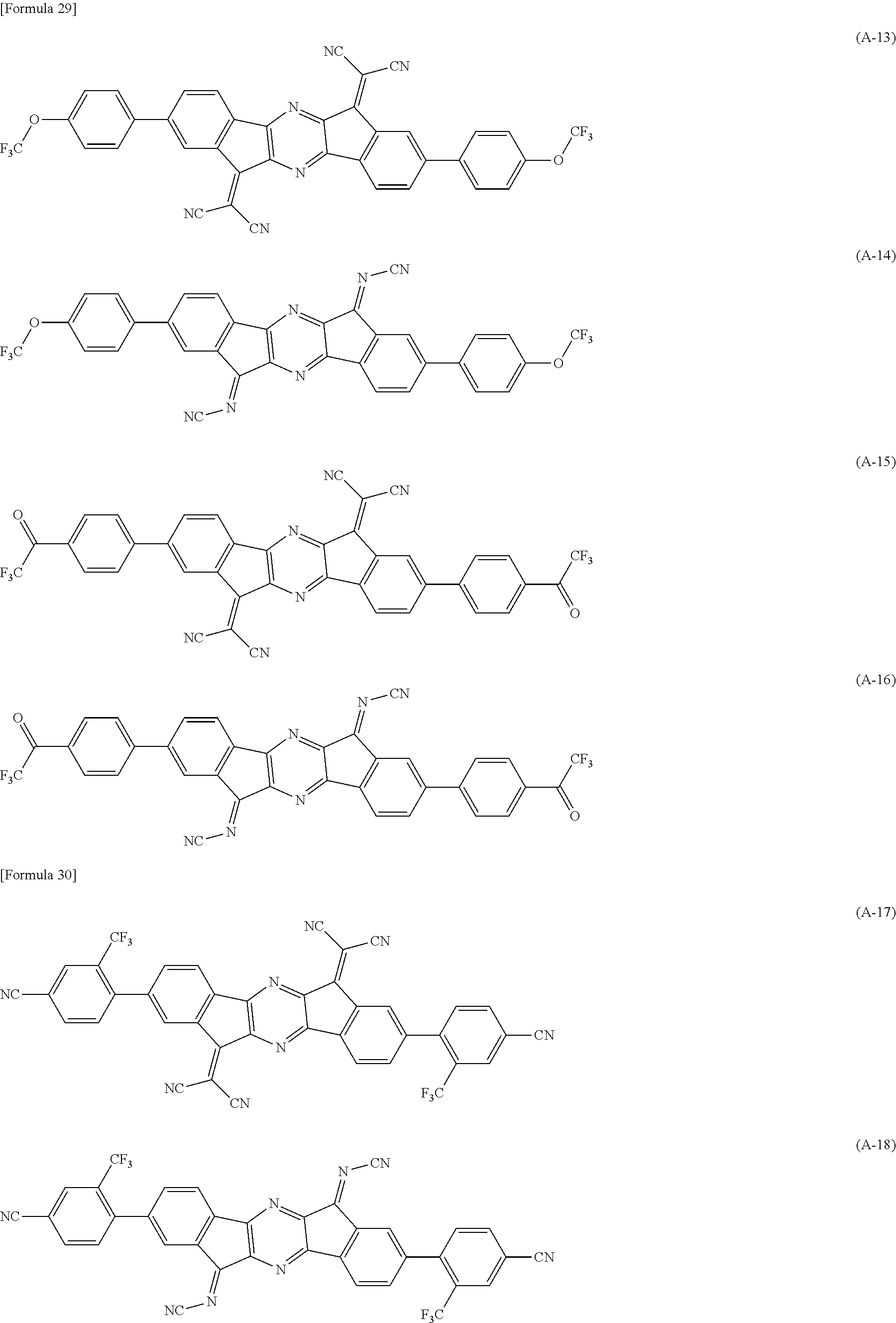

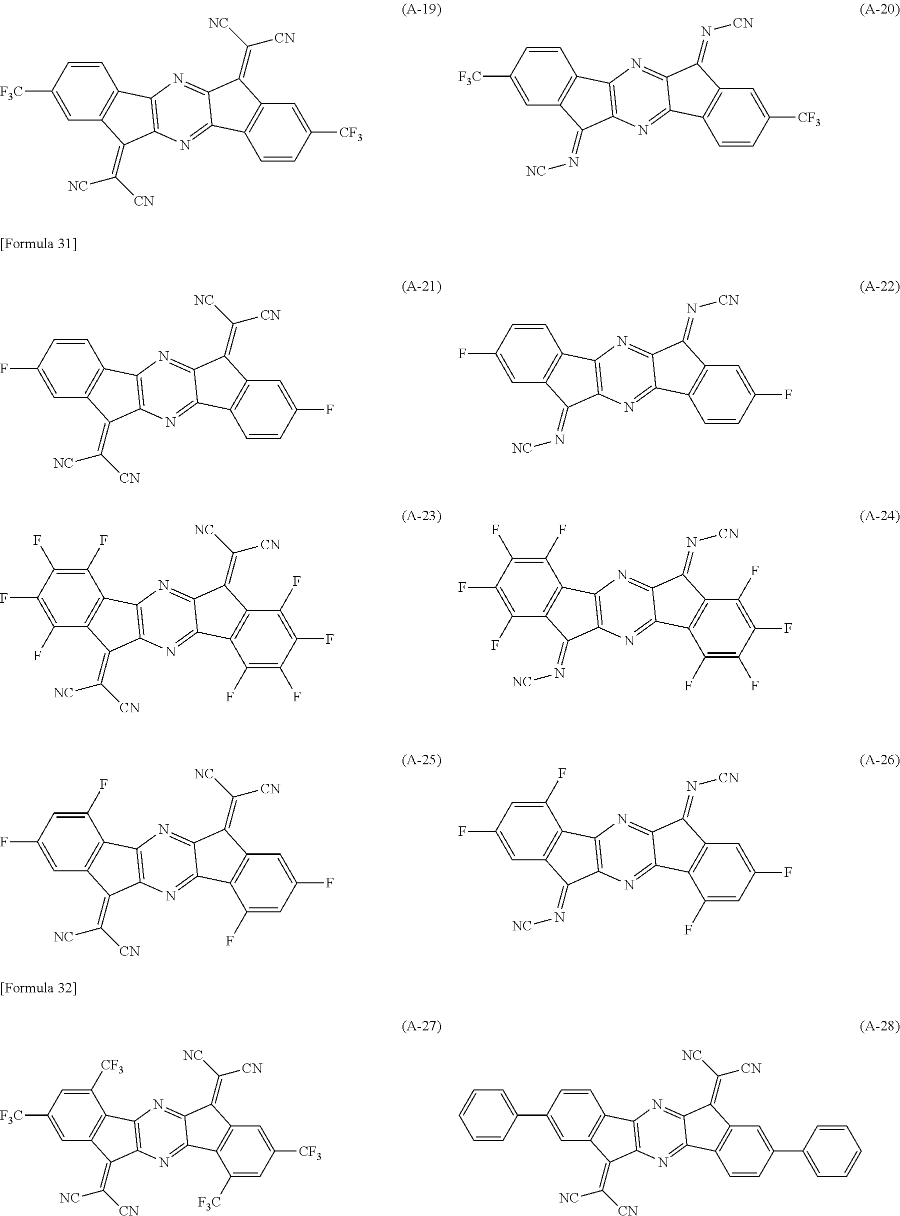

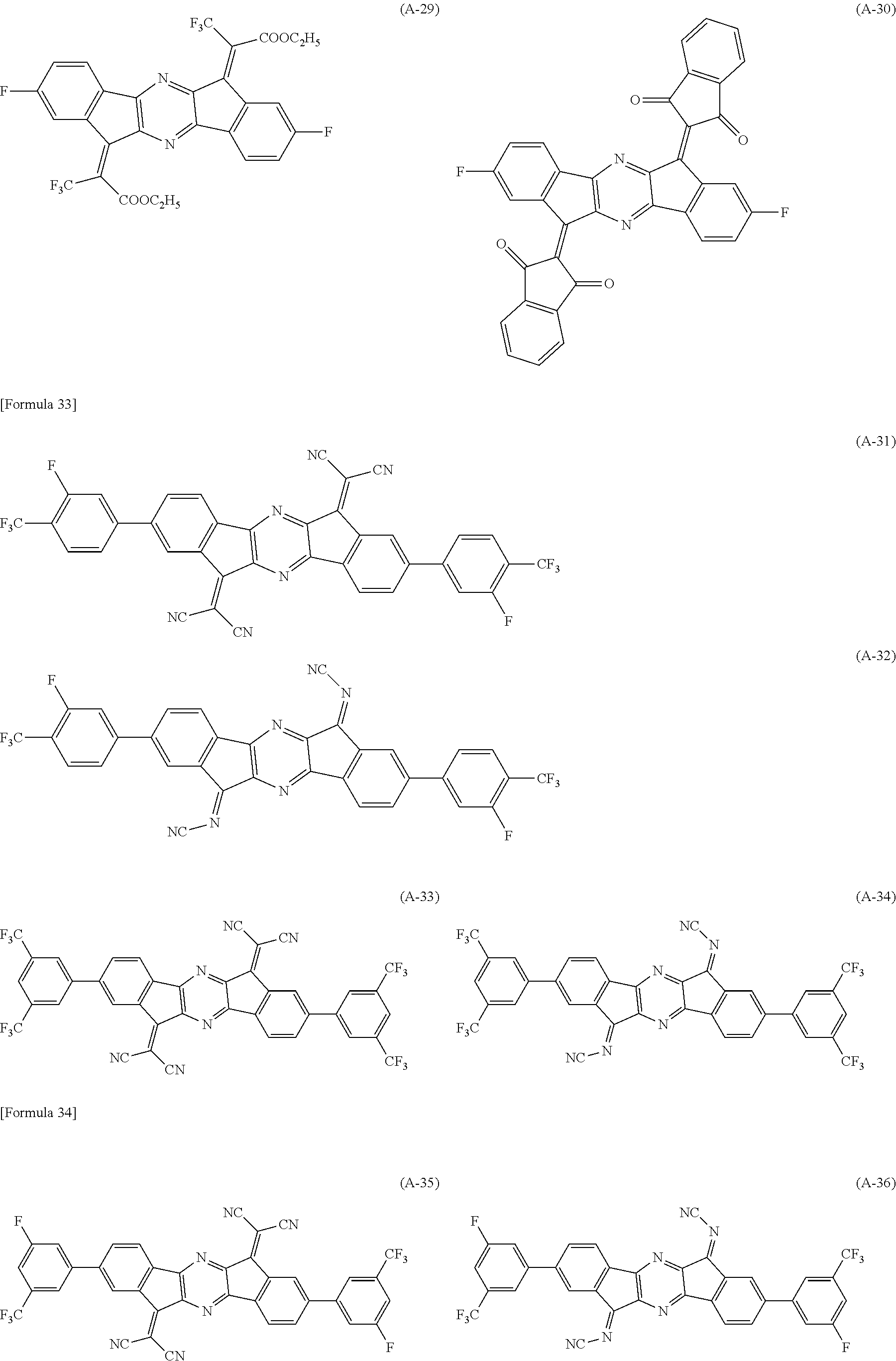

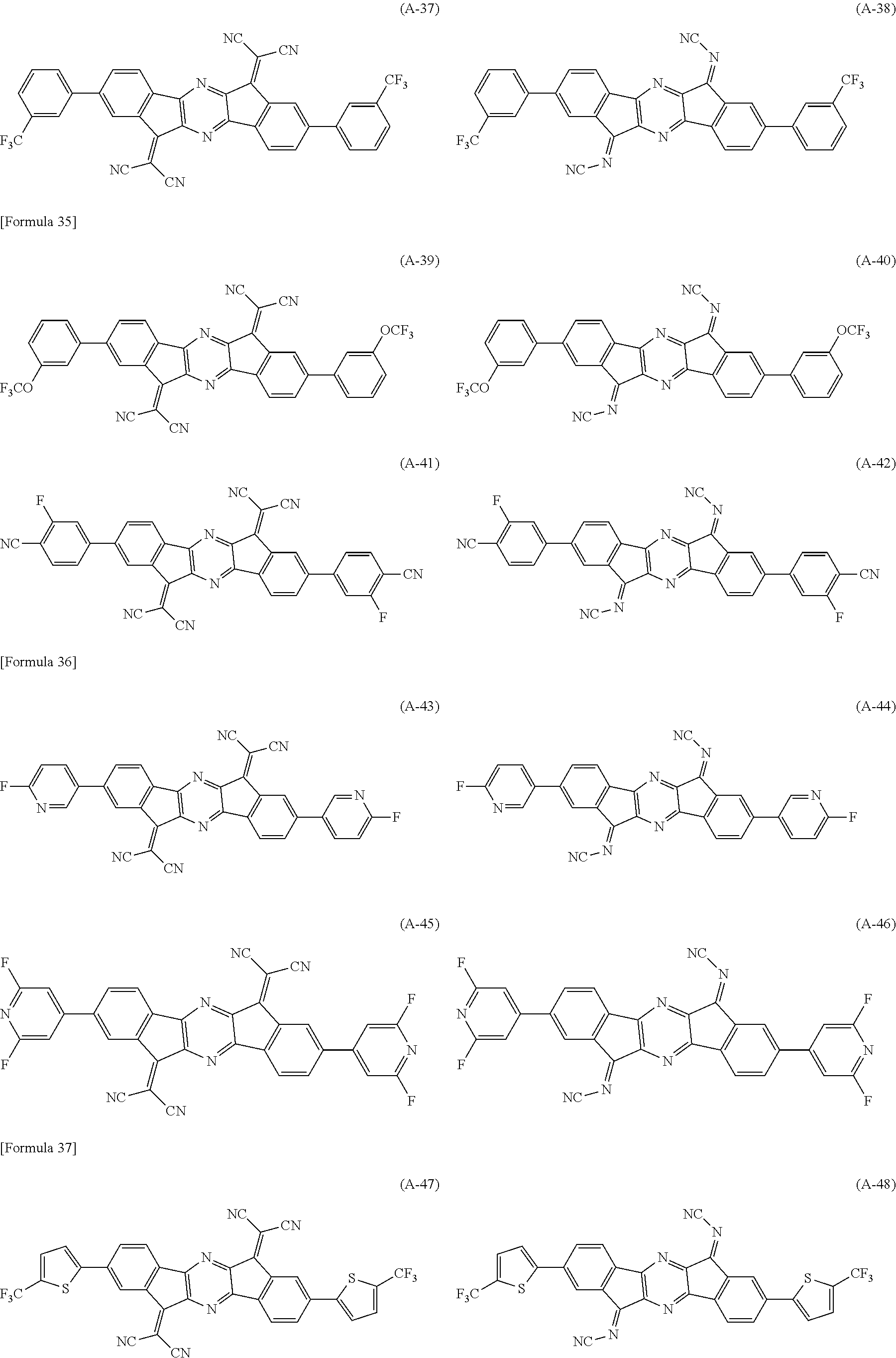

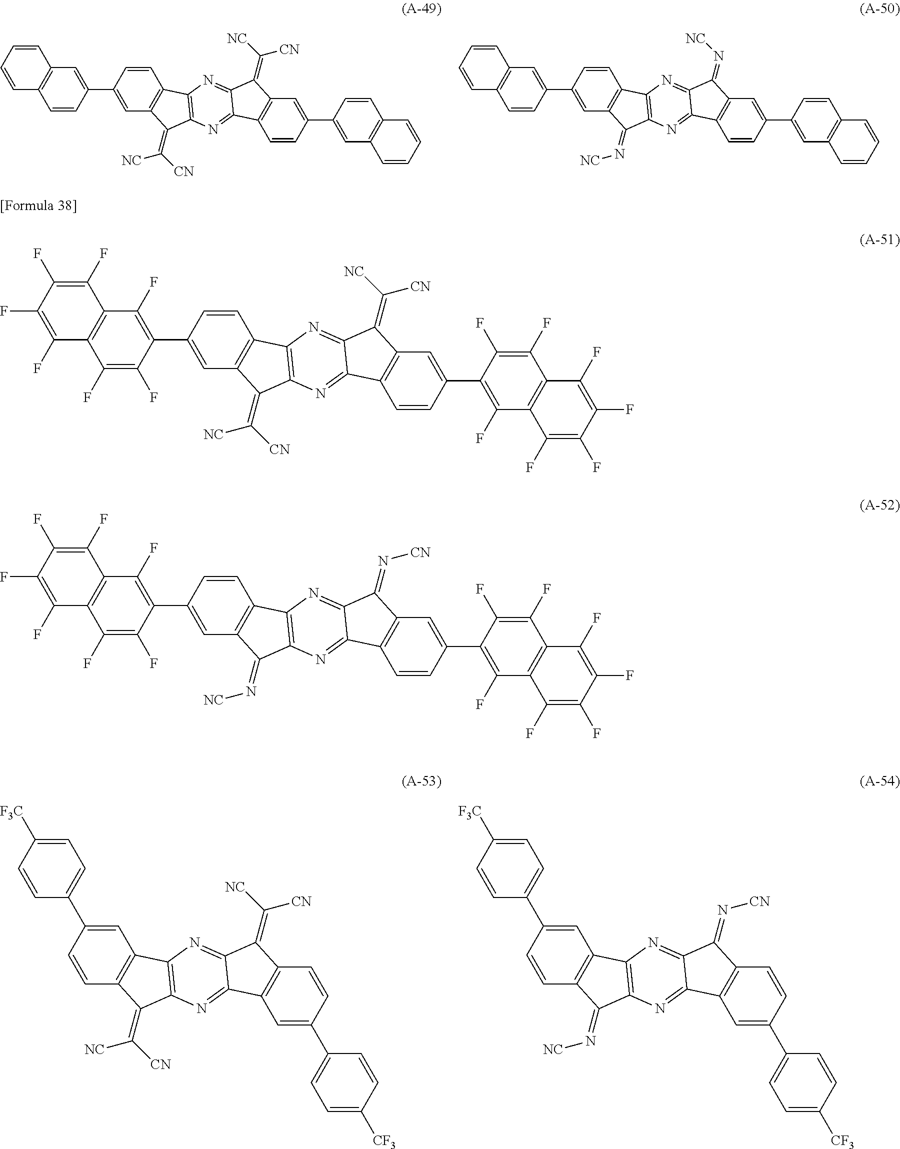

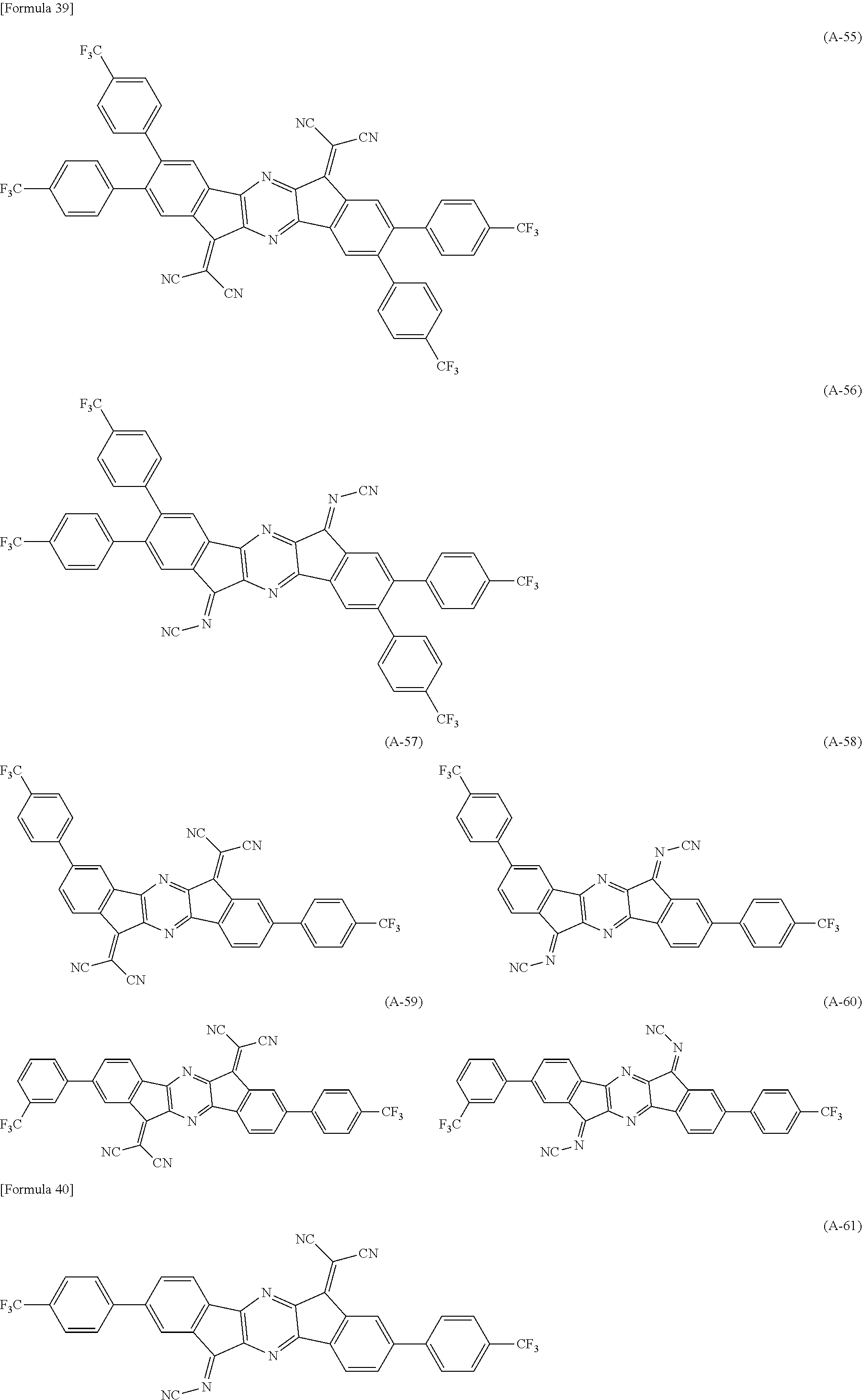

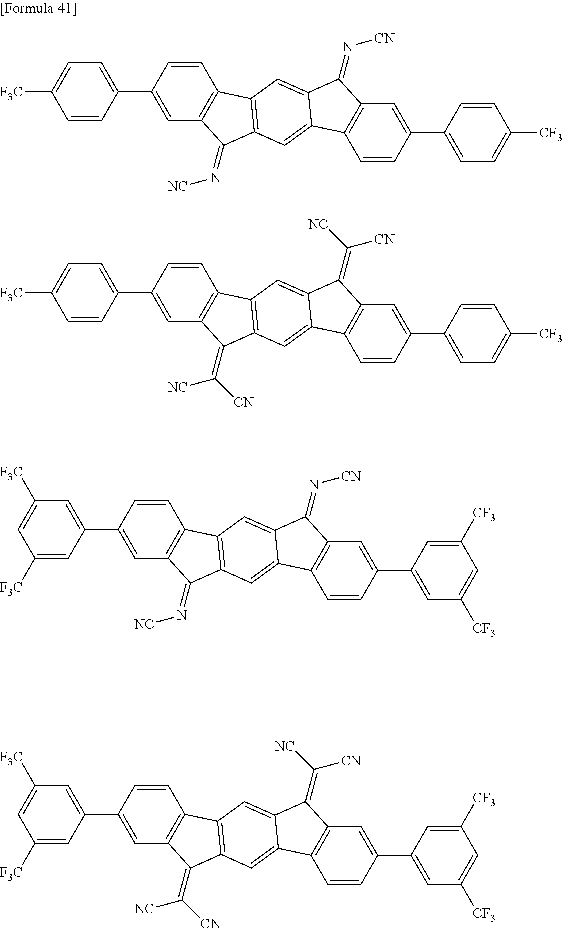 [SMILES: N#C/N=c1\c2cc(-c3ccc(C(F)(F)F)cc3)ccc2c2cc3/c(=N/C#N)c4cc(-c5ccc(C(F)(F)F)cc5)ccc4c3cc12 ; N#CC(C#N)=C1c2cc(-c3ccc(C(F)(F)F)cc3)ccc2-c2cc3c(cc21)-c1ccc(-c2ccc(C(F)(F)F)cc2)cc1C3=C(C#N)C#N ; N#C/N=c1\c2cc(-c3cc(C(F)(F)F)cc(C(F)(F)F)c3)ccc2c2cc3/c(=N/C#N)c4cc(-c5cc(C(F)(F)F)cc(C(F)(F)F)c5)ccc4c3cc12 ; N#CC(C#N)=C1c2cc(-c3cc(C(F)(F)F)cc(C(F)(F)F)c3)ccc2-c2cc3c(cc21)-c1ccc(-c2cc(C(F)(F)F)cc(C(F)(F)F)c2)cc1C3=C(C#N)C#N]

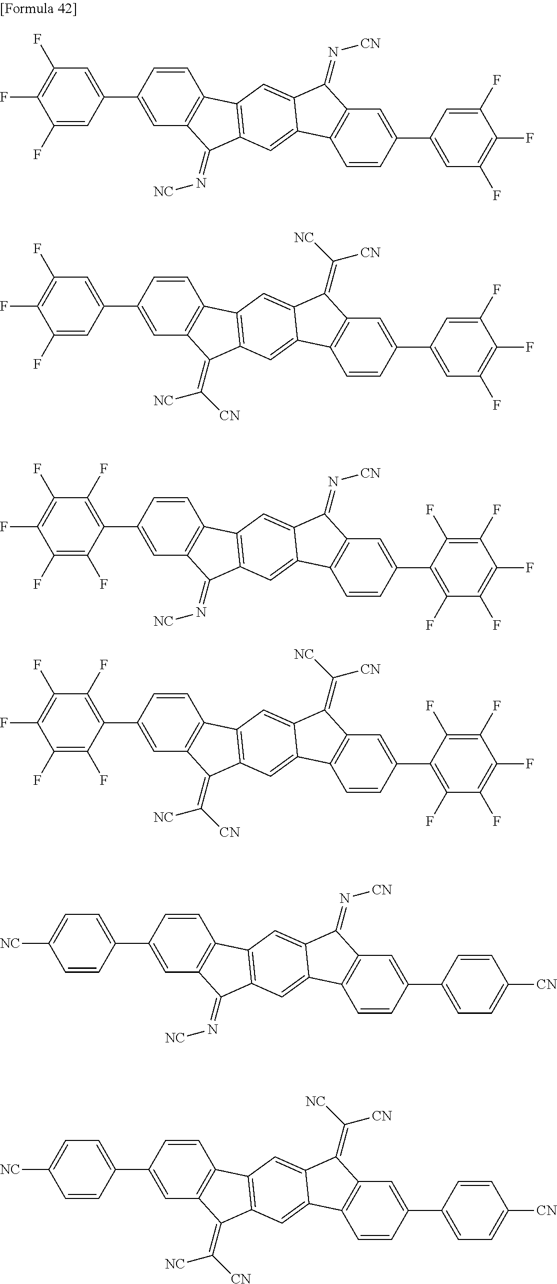

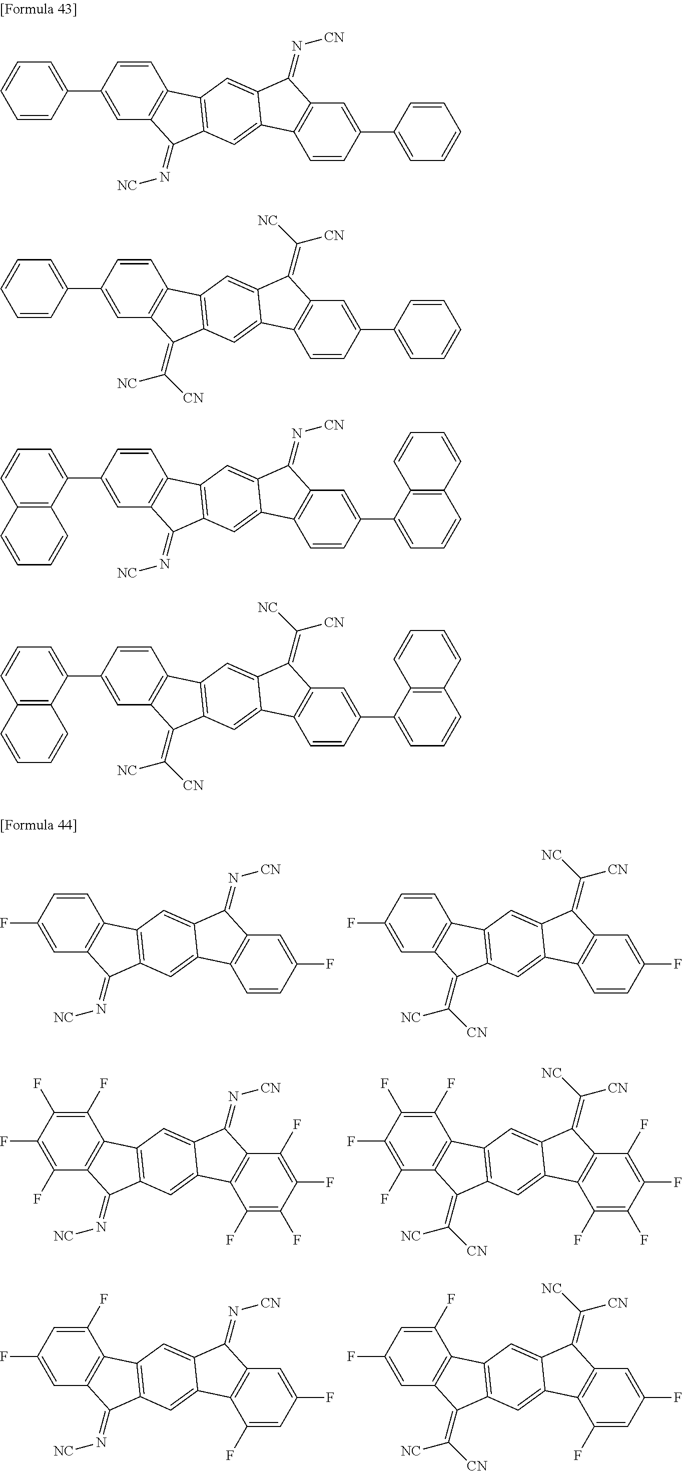

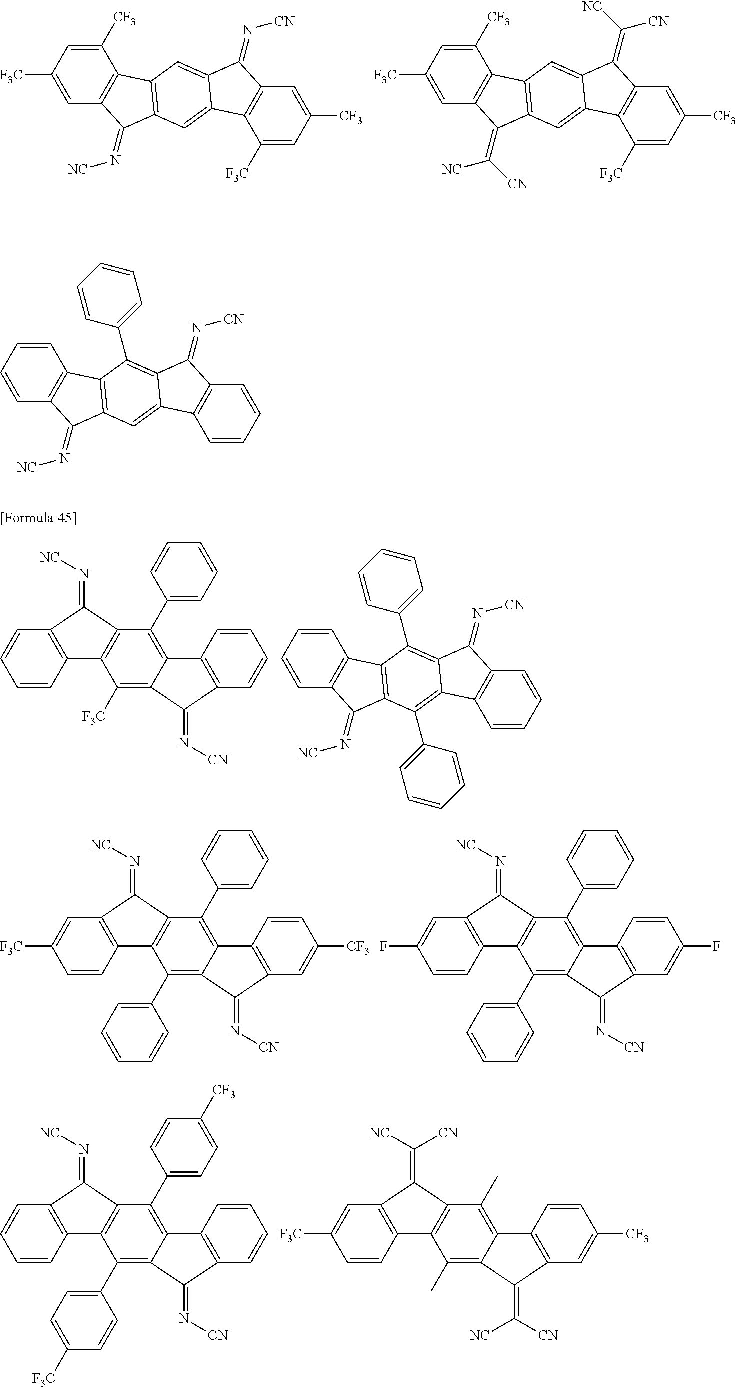

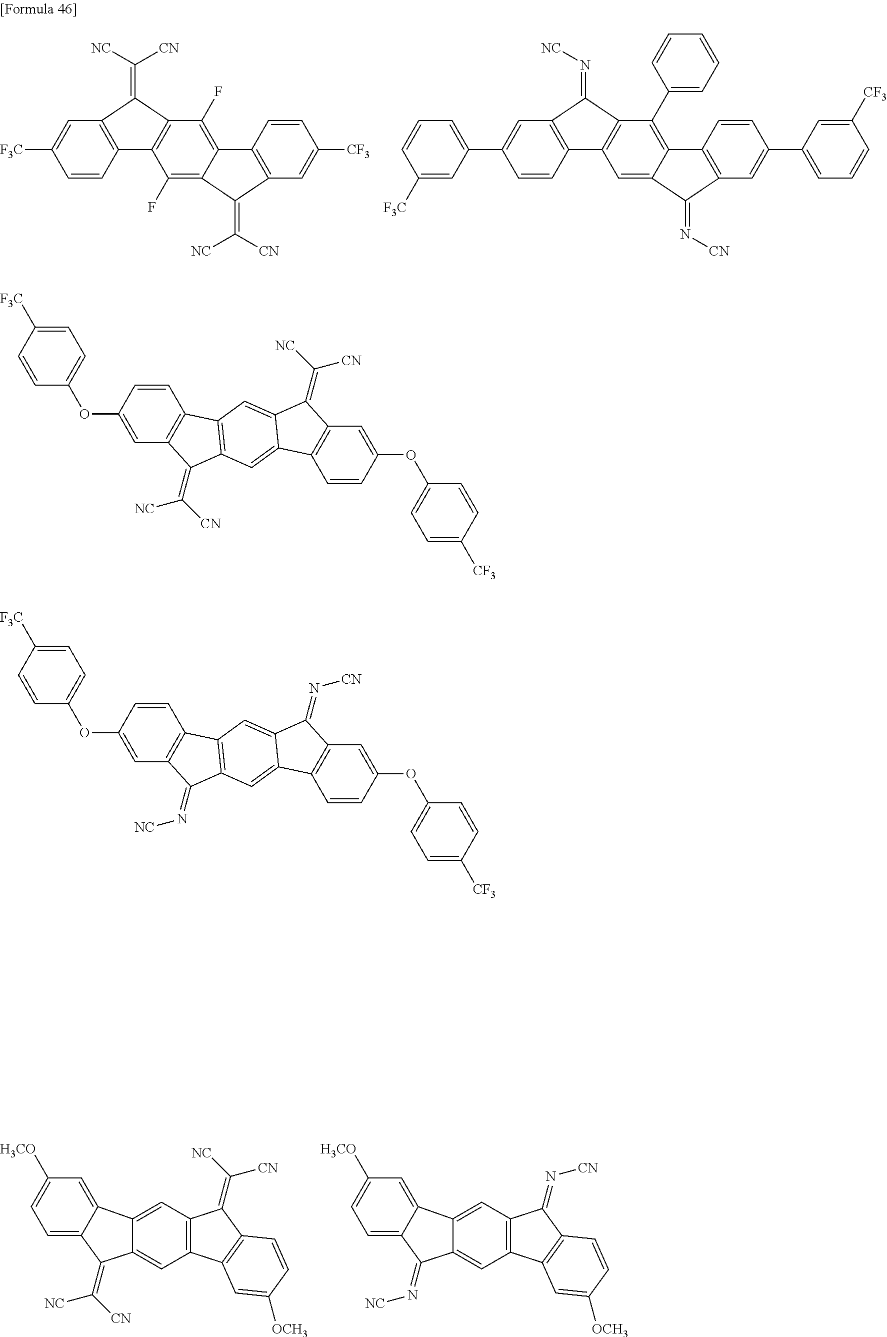 [SMILES: N#CC(C#N)=C1c2cc(C(F)(F)F)ccc2-c2c(F)c3c(c(F)c21)-c1ccc(C(F)(F)F)cc1C3=C(C#N)C#N ; N#C/N=c1\c2cc(-c3cccc(C(F)(F)F)c3)ccc2c2c(-c3ccccc3)c3/c(=N/C#N)c4cc(-c5cccc(C(F)(F)F)c5)ccc4c3cc12 ; N#CC(C#N)=C1c2cc(Oc3ccc(C(F)(F)F)cc3)ccc2-c2cc3c(cc21)-c1ccc(Oc2ccc(C(F)(F)F)cc2)cc1C3=C(C#N)C#N ; N#C/N=c1\c2cc(Oc3ccc(C(F)(F)F)cc3)ccc2c2cc3/c(=N/C#N)c4cc(Oc5ccc(C(F)(F)F)cc5)ccc4c3cc12 ; COc1ccc2c(c1)-c1cc3c(cc1C2=C(C#N)C#N)-c1cc(OC)ccc1C3=C(C#N)C#N ; COc1ccc2/c(=N\C#N)c3cc4c(cc3c2c1)/c(=N/C#N)c1ccc(OC)cc14]

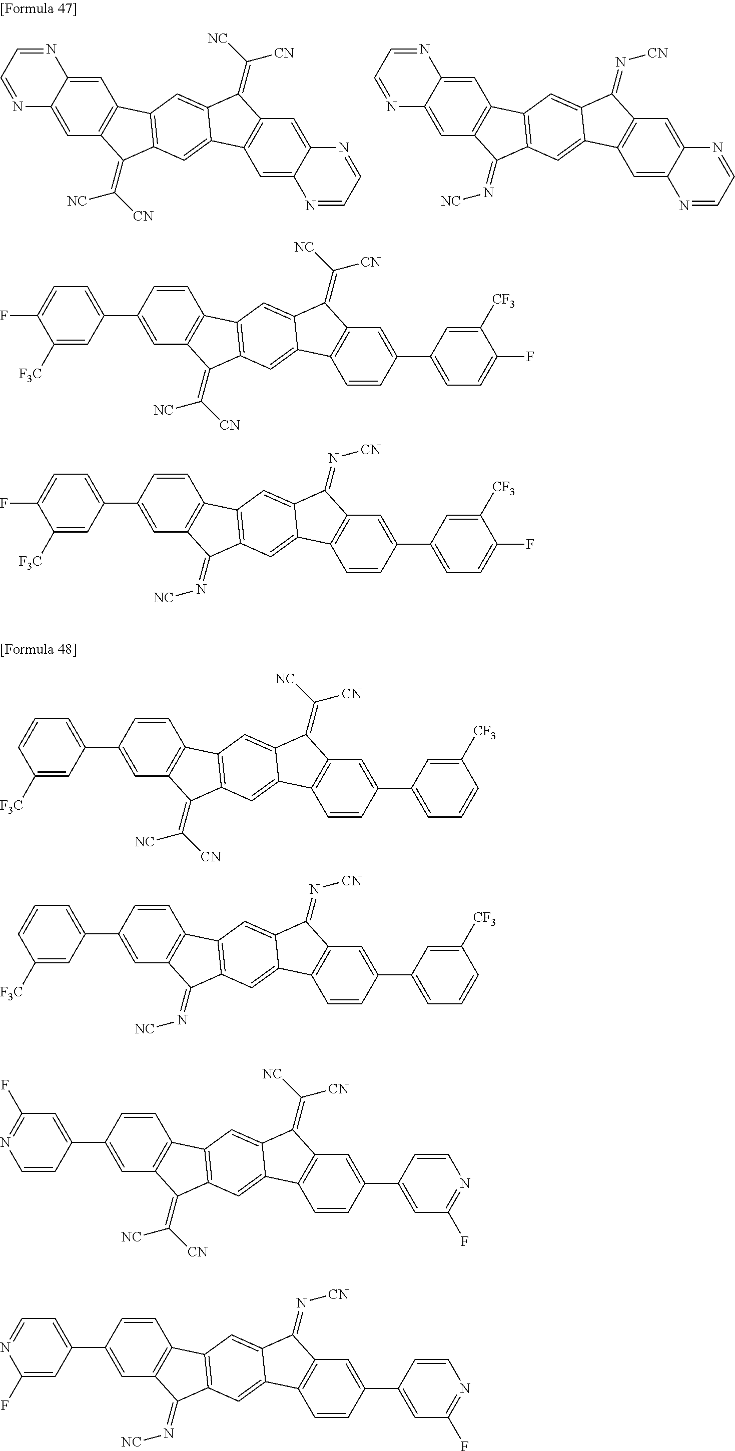

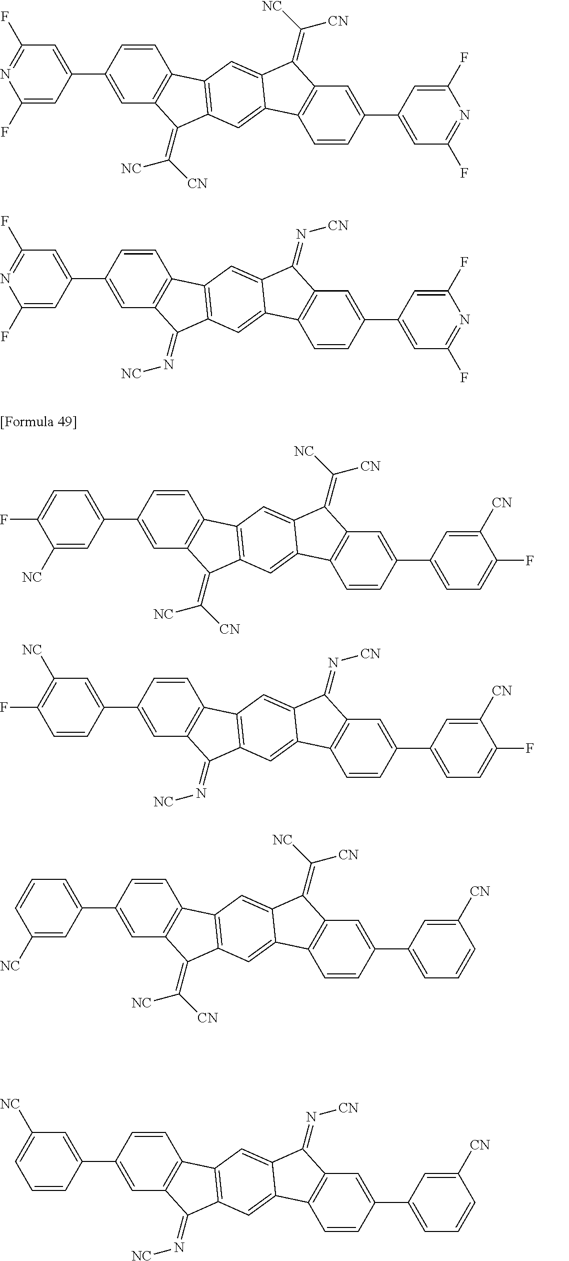

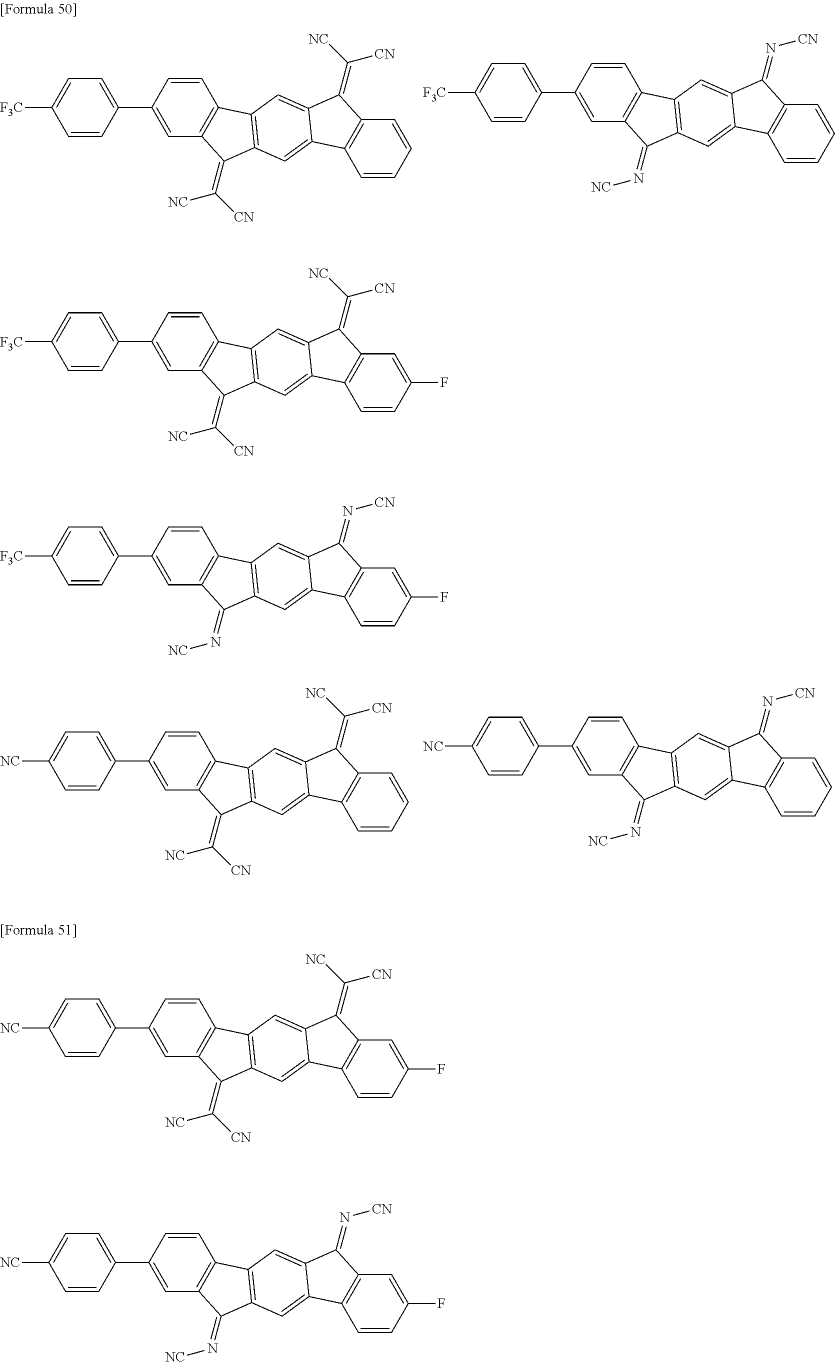

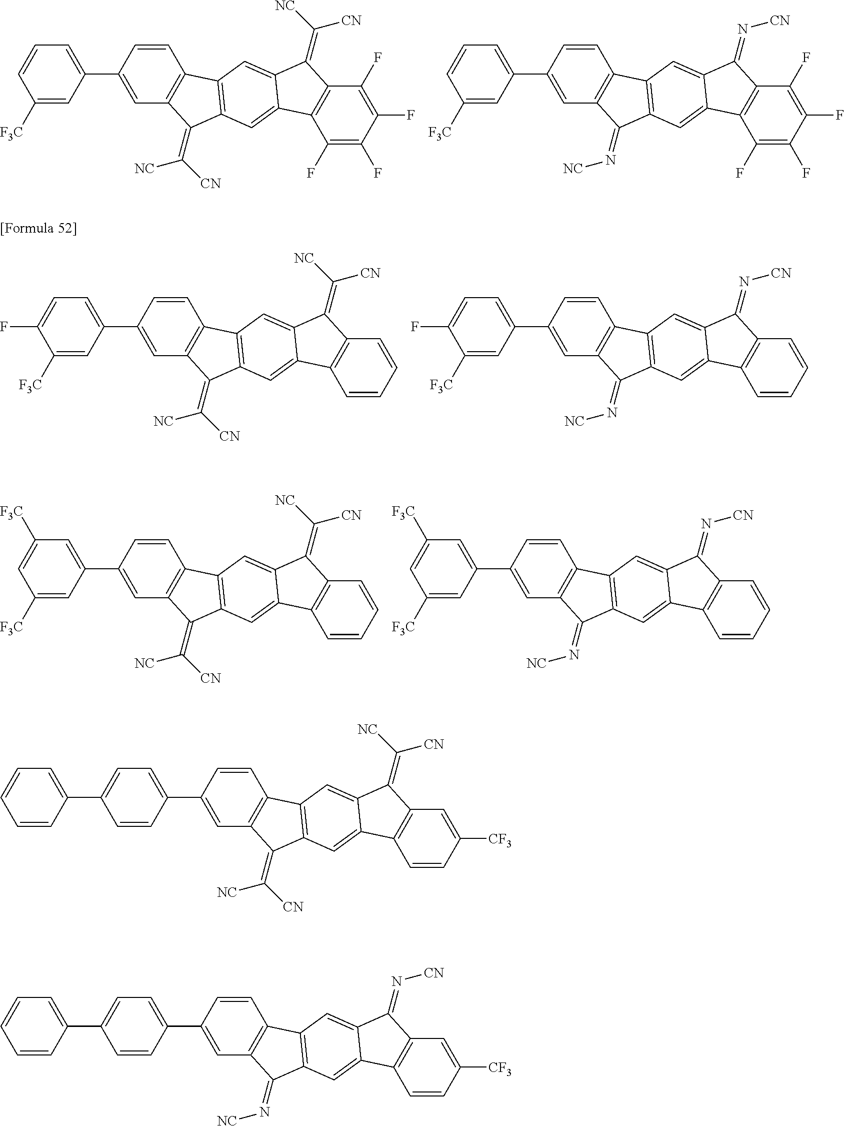

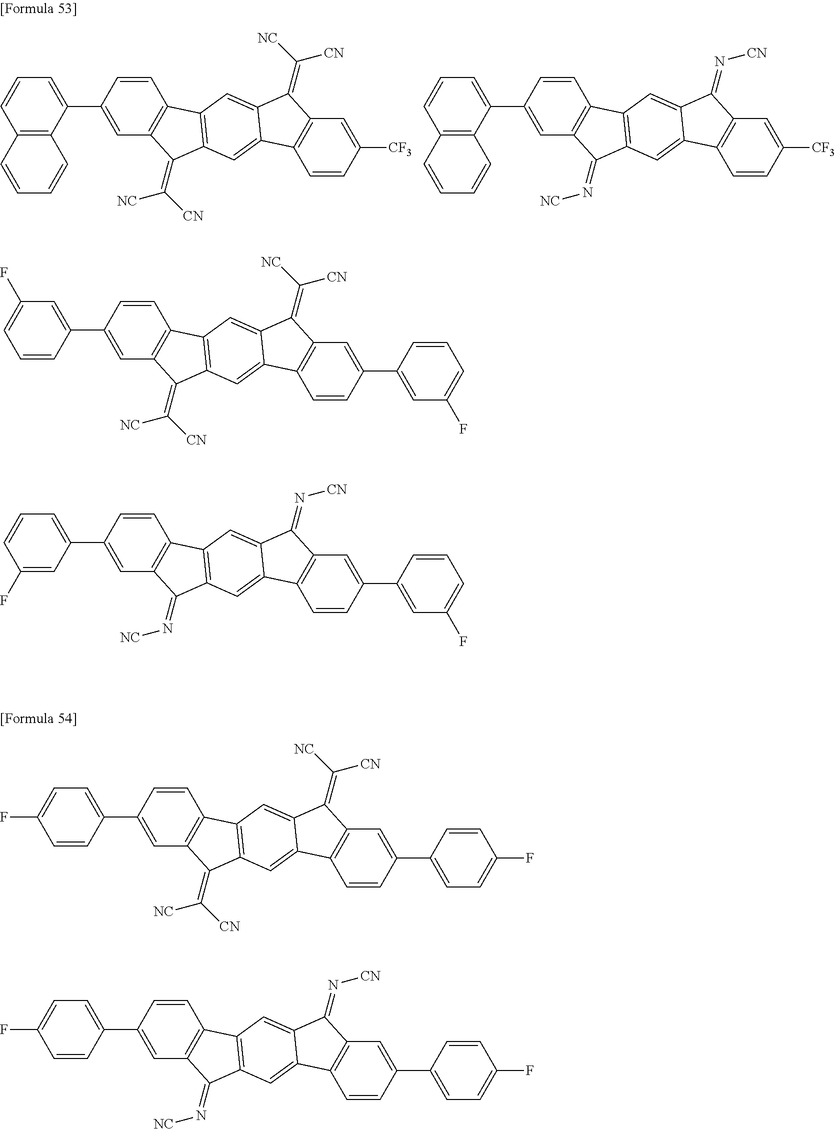

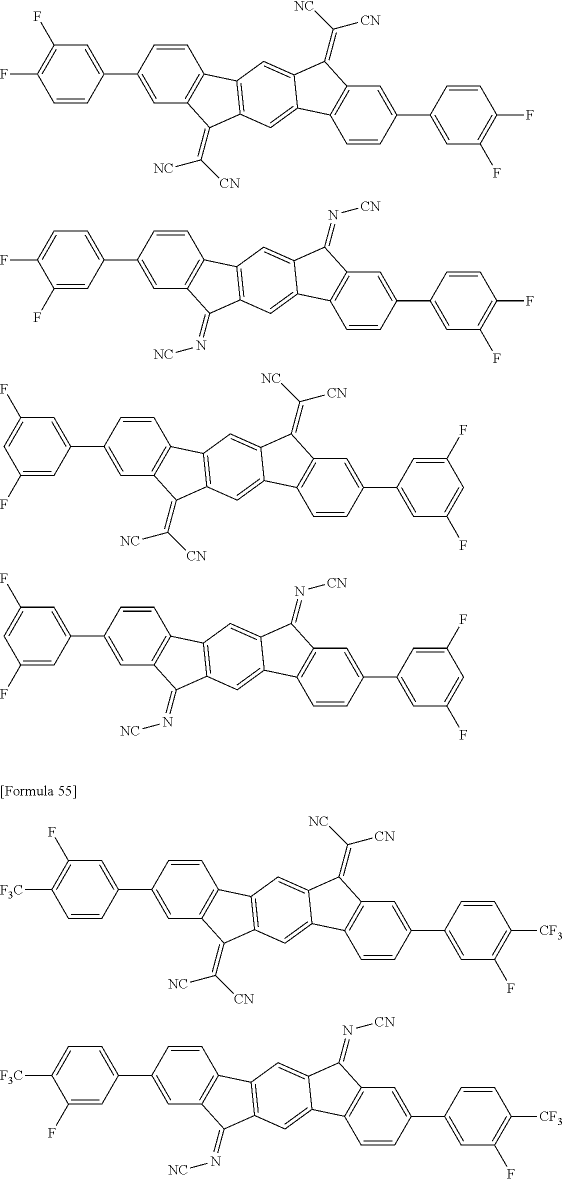

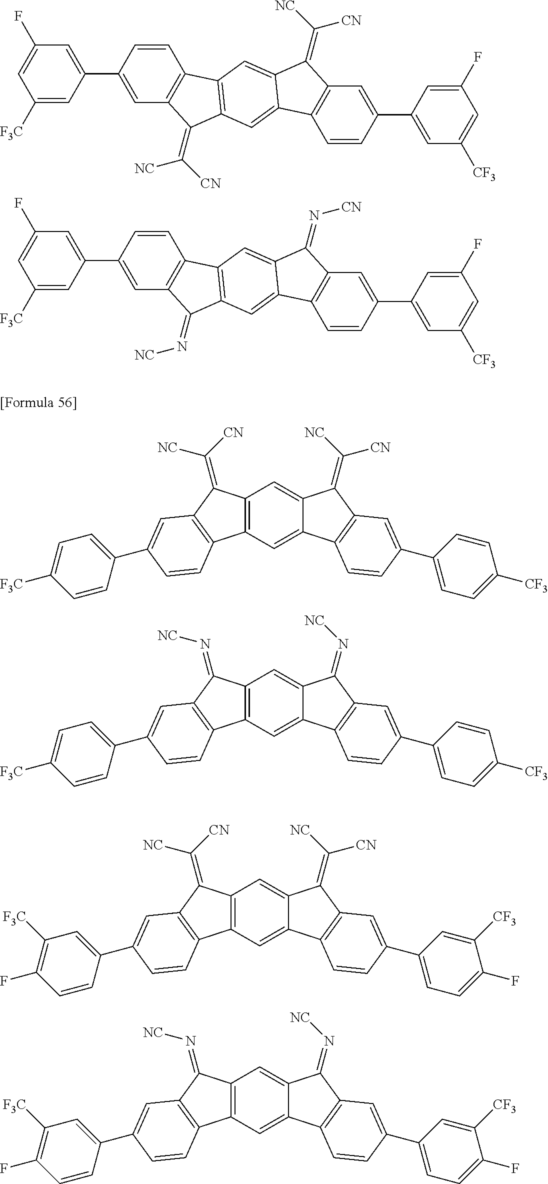

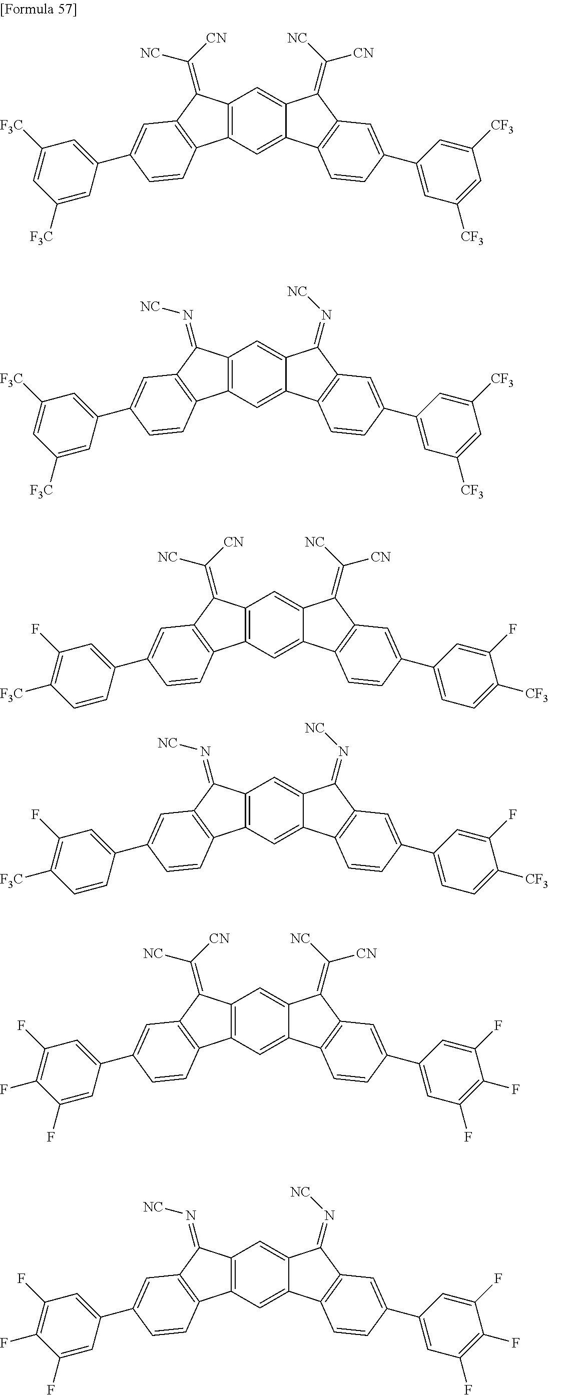

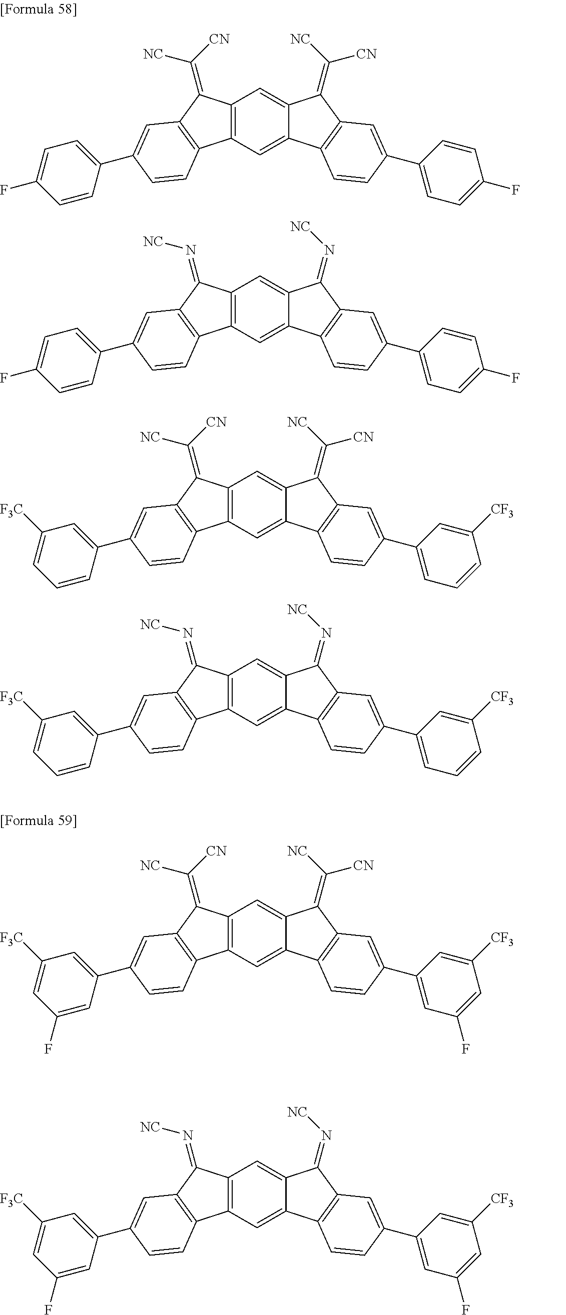

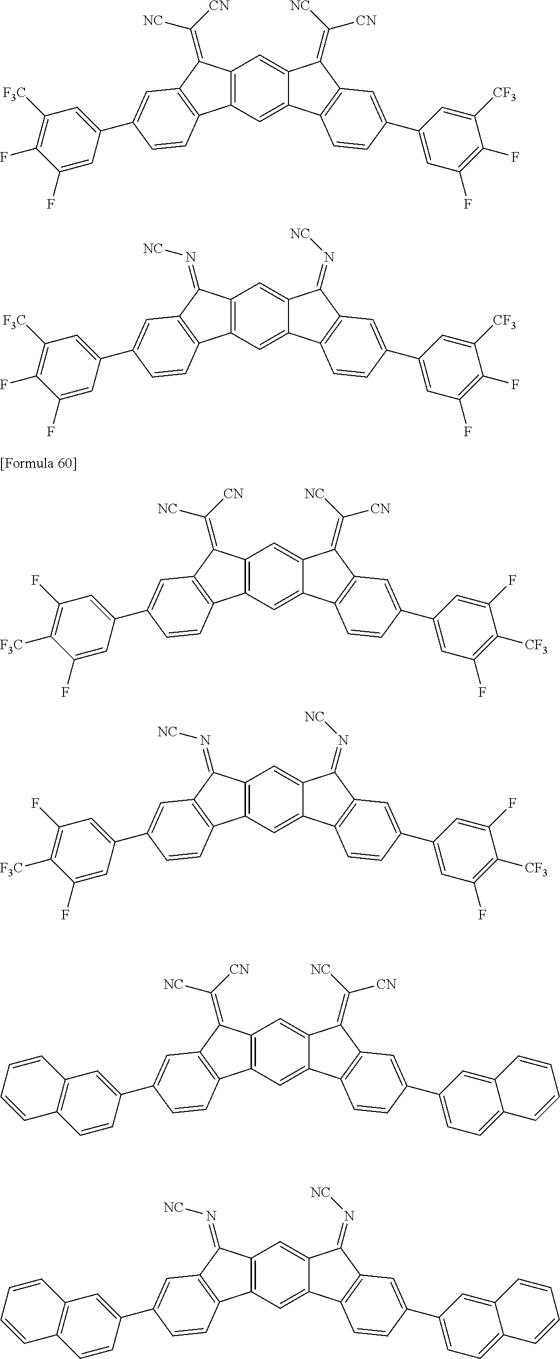

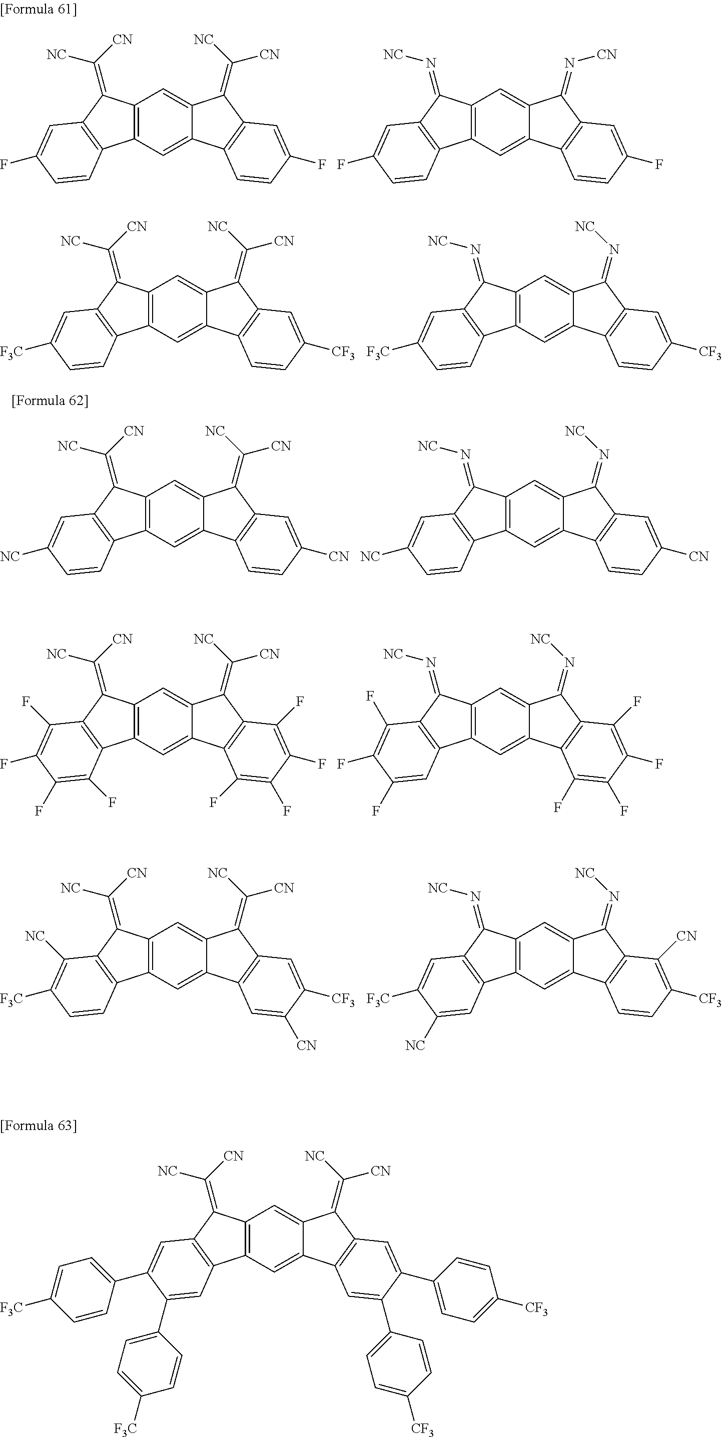

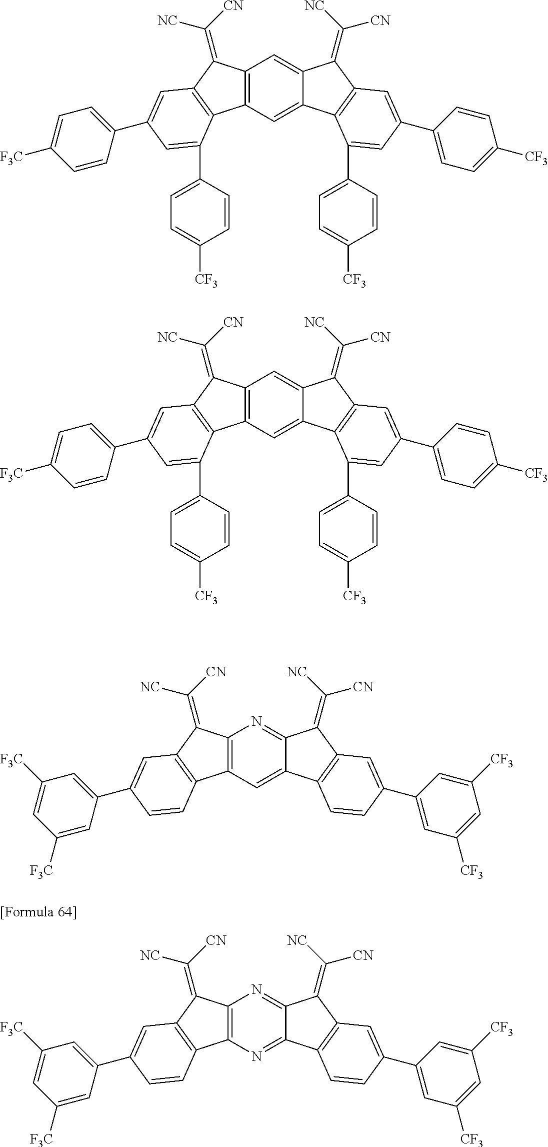

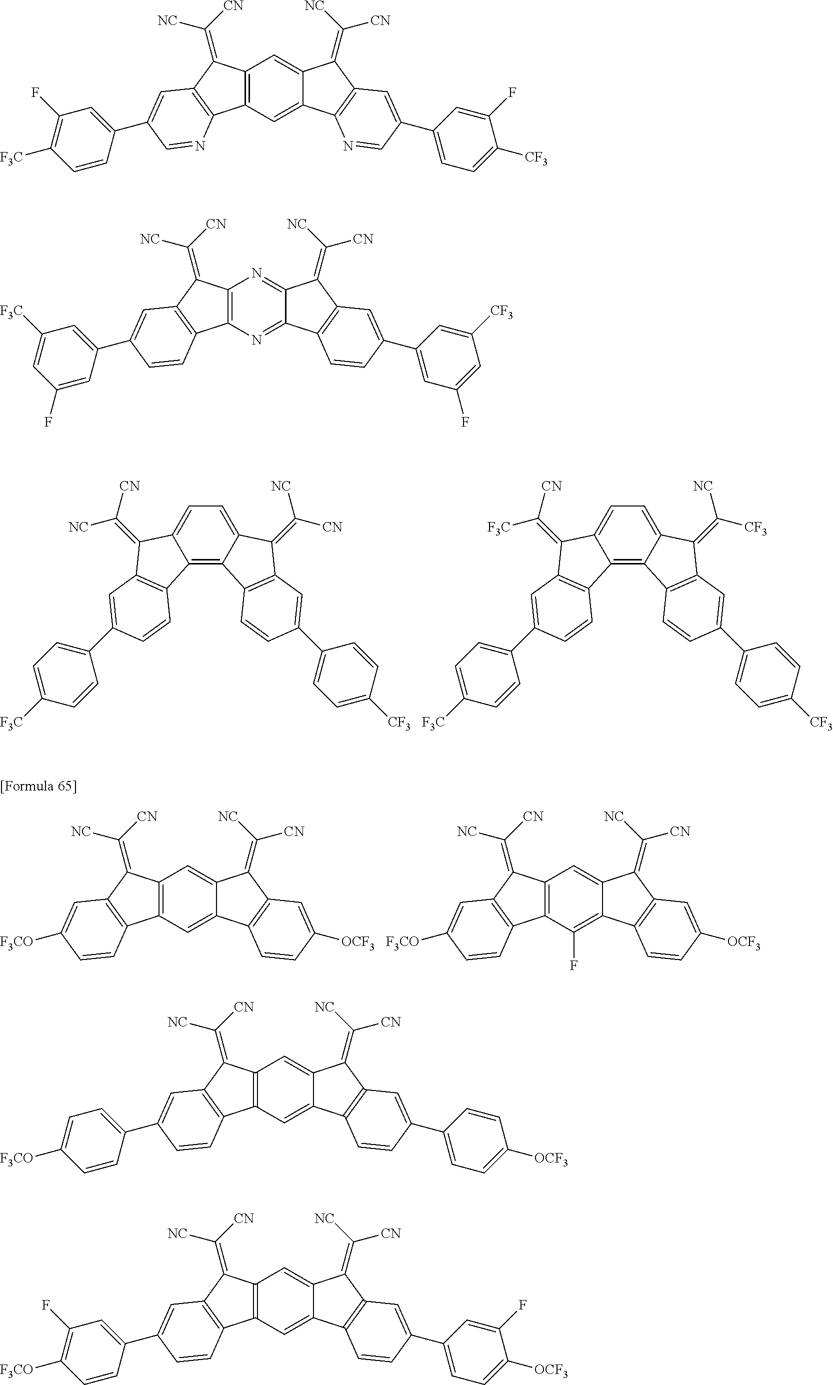

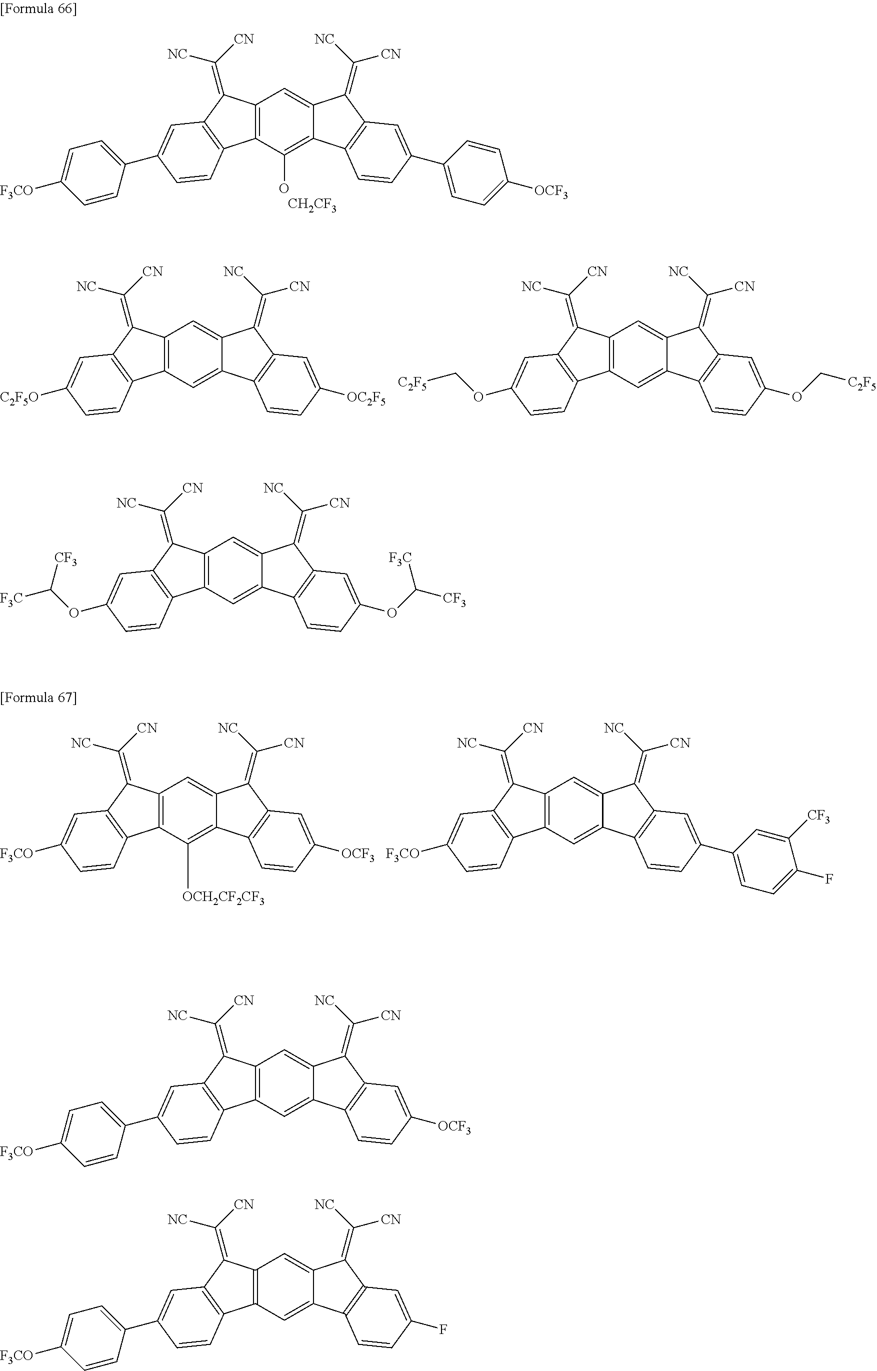

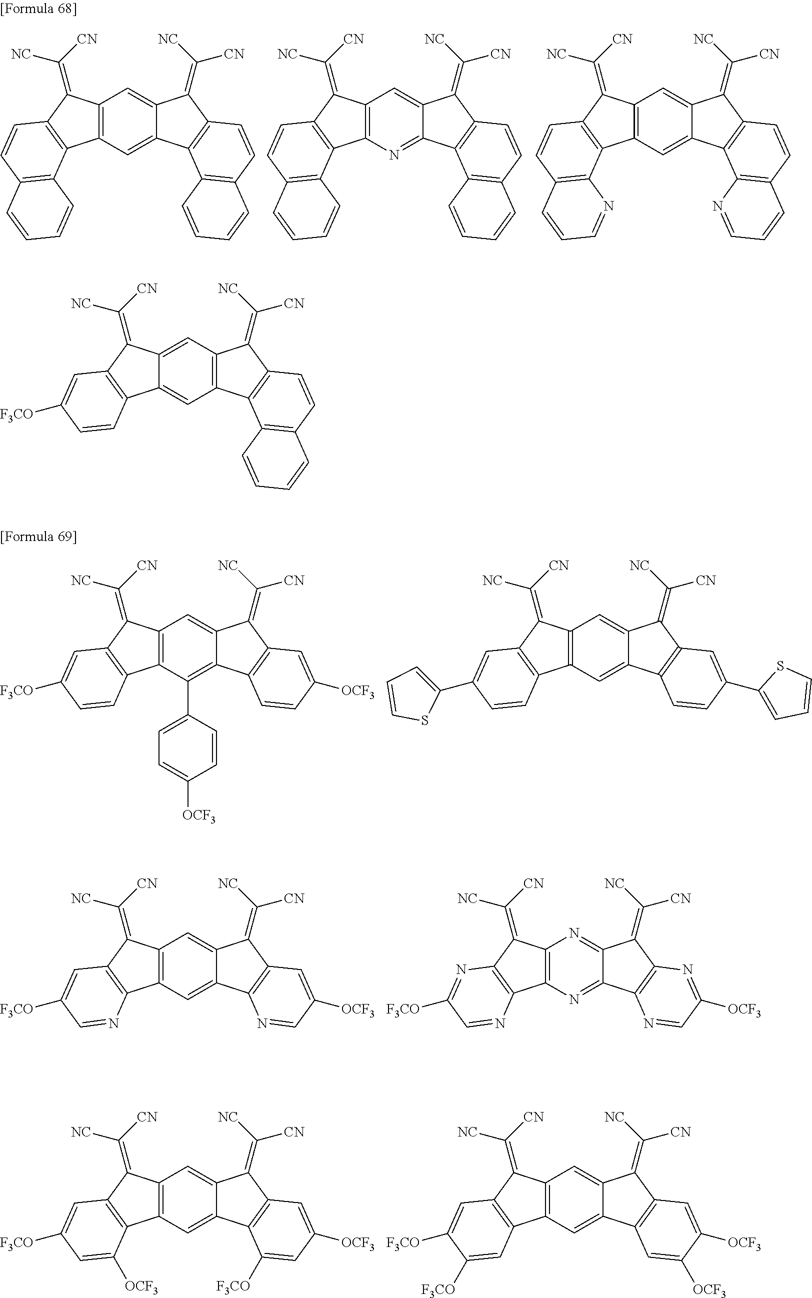

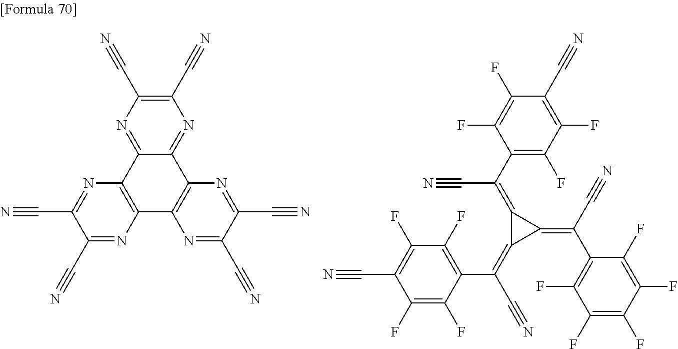 [SMILES: N#Cc1nc2c3nc(C#N)c(C#N)nc3c3nc(C#N)c(C#N)nc3c2nc1C#N ; N#C/C(=C1\C(=C(\C#N)c2c(F)c(F)c(F)c(F)c2F)\C1=C(\C#N)c1c(F)c(F)c(C#N)c(F)c1F)c1c(F)c(F)c(C#N)c(F)c1F]

In the organic EL device according to the exemplary embodiment, it is preferable that the hole transporting zone material is a monoamine compound having one substituted or unsubstituted amino group in a molecule, a diamine compound having two substituted or unsubstituted amino groups in a molecule, or a triamine compound having three substituted or unsubstituted amino groups in a molecule, and it is more preferable that the hole transporting zone material is a monoamine compound having one substituted or unsubstituted amino group in a molecule, or a diamine compound having two substituted or unsubstituted amino groups in a molecule.

In the organic EL device according to the exemplary embodiment, the hole transporting zone material is preferably a compound represented by the formula (21) or the formula (22) below.

### Compound Represented by Formula (21) or Formula (22)

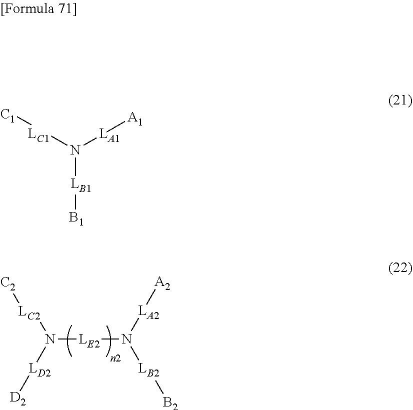

In the formulae (21) and (22):
L_{A1}, L_{B1}, L_{C1}, L_{A2}, L_{B2}, L_{C2}, and L_{D2} are each independently a single bond, a substituted or unsubstituted arylene group having 6 to 50 ring carbon atoms, or a substituted or unsubstituted divalent heterocyclic group having 5 to 50 ring atoms;
when L_{A1} and L_{B1} are each a single bond, A₁ and B₁ are mutually bonded to form a substituted or unsubstituted monocyclic ring, mutually bonded to form a substituted or unsubstituted fused ring, or not mutually bonded;
when L_{A1} and L_{C1} are each a single bond, A₁ and C₁ are mutually bonded to form a substituted or unsubstituted monocyclic ring, mutually bonded to form a substituted or unsubstituted fused ring, or not mutually bonded;
when L_{B1} and L_{C1} are each a single bond, B₁ and C₁ are mutually bonded to form a substituted or unsubstituted monocyclic ring, mutually bonded to form a substituted or unsubstituted fused ring, or not mutually bonded;
n2 is 1, 2, 3, or 4;
when n2 is 1, L_{E2} is a substituted or unsubstituted arylene group having 6 to 50 ring carbon atoms, or a substituted or unsubstituted divalent heterocyclic group having 5 to 50 ring atoms;
when n2 is 2, 3, or 4, a plurality of L_{E2} are mutually the same or different;
when n2 is 2, 3, or 4, a plurality of L_{E2} are mutually bonded to form a substituted or unsubstituted monocyclic ring, mutually bonded to form a substituted or unsubstituted fused ring, or not mutually bonded;
L_{E2} forming neither the monocyclic ring nor the fused ring is a substituted or unsubstituted arylene group having 6 to 50 ring carbon atoms, or a substituted or unsubstituted divalent heterocyclic group having 5 to 50 ring atoms;
A₁, B₁, C₁, A₂, B₂, C₂ and D₂ are each independently a substituted or unsubstituted aryl group having 6 to 50 ring carbon atoms, a substituted or unsubstituted heterocyclic group having 5 to 50 ring atoms, a group represented by —Si(R₉₂₁)(R₉₂₂)(R₉₂₃), or a group represented by —N(R₉₀₆)(R₉₀₇);
R₉₂₁, R₉₂₂, and R₉₂₃ are each independently a substituted or unsubstituted aryl group having 6 to 50 ring carbon atoms;
R₉₀₆ and R₉₀₇ are each independently a substituted or unsubstituted aryl group having 6 to 50 ring carbon atoms, a substituted or unsubstituted heterocyclic group having 5 to 50 ring atoms, or a substituted or unsubstituted alkyl group having 1 to 30 carbon atoms;
when a plurality of R₉₂₁ are present, the plurality of R₉₂₁ are mutually the same or different;
when a plurality of R₉₂₂ are present, the plurality of R₉₂₂ are mutually the same or different;
when a plurality of R₉₂₃ are present, the plurality of R₉₂₃ are mutually the same or different;
when a plurality of R₉₀₆ are present, the plurality of R₉₀₆ are mutually the same or different; and
when a plurality of R₉₀₇ are present, the plurality of R₉₀₇ are mutually the same or different.

In the formula (21):
when L_{A1} and L_{B1} are each a single bond, A₁ and B₁ may be mutually bonded to form a substituted or unsubstituted monocyclic ring, mutually bonded to form a substituted or unsubstituted fused ring, or not bonded;
when L_{A1} and L_{C1} are each a single bond, A₁ and C₁ may be mutually bonded to form a substituted or unsubstituted monocyclic ring, mutually bonded to form a substituted or unsubstituted fused ring, or not bonded; and
when L_{B1} and L_{C1} are each a single bond, B₁ and C₁ may be mutually bonded to form a substituted or unsubstituted monocyclic ring, mutually bonded to form a substituted or unsubstituted fused ring, or not bonded.

In the formula (22):
when L_{A2} and L_{B2} are each a single bond, A₂ and B₂ may be mutually bonded to form a substituted or unsubstituted monocyclic ring, mutually bonded to form a substituted or unsubstituted fused ring, or not bonded; and
when L_{C2} and L_{D2} are each a single bond, C₂ and D₂ may be mutually bonded to form a substituted or unsubstituted monocyclic ring, mutually bonded to form a substituted or unsubstituted fused ring, or not bonded.

The compound represented by the formula (21) is also preferably a compound represented by a formula (212) below.

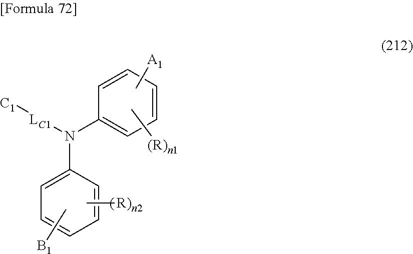

In the formula (212):
L_{C1}, A₁, B₁, and C₁ respectively represent the same as those defined in the formula (21);

n1 and n2 are each independently 0, 1, 2, 3 or 4;

when a plurality of R are present, the plurality of R are mutually the same or different;

when a plurality of R are present, at least one combination of adjacent two or more of the plurality of R are mutually bonded to form a substituted or unsubstituted monocyclic ring, mutually bonded to form a substituted or unsubstituted fused ring, or not mutually bonded; and

R forming neither the substituted or unsubstituted monocyclic ring nor the substituted or unsubstituted fused ring is a cyano group, a substituted or unsubstituted alkyl group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a substituted or unsubstituted aryl group having 6 to 50 ring carbon atoms, or a substituted or unsubstituted heterocyclic group having 5 to 50 ring atoms.

In the compound represented by the formula (21), at least one of A₁, B₁, or C₁ is preferably a group selected from the group consisting of groups represented by formulae (21a), (21b), (21c), (21d) and (21e) below.

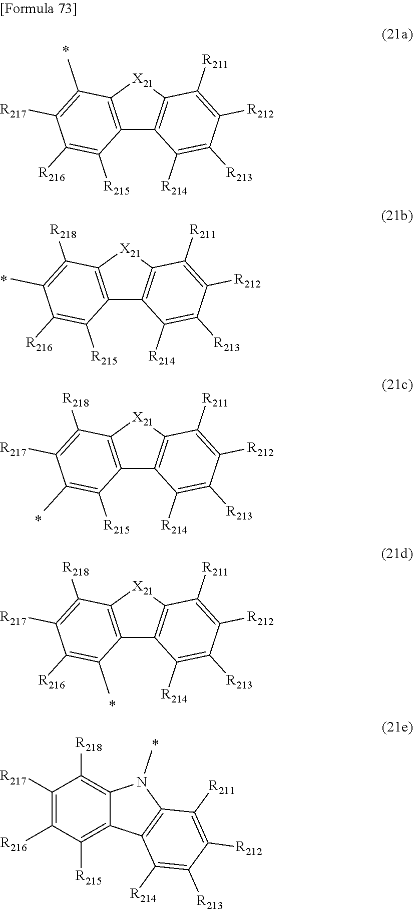

In the formulae (21a), (21b), (21c), (21d), and (21e):
X₂₁ is NR₂₁, CR₂₂R₂₃, an oxygen atom, or a sulfur atom;
when a plurality of X₂₁ are present, the plurality of X₂₁ are mutually the same or different;
when X₂₁ is CR₂₂R₂₃, a combination of R₂₂ and R₂₃ are mutually bonded to form a substituted or unsubstituted monocyclic ring, mutually bonded to form a substituted or unsubstituted fused ring, or not mutually bonded;
R₂₁, and R₂₂ and R₂₃ forming neither the substituted or unsubstituted monocyclic ring nor the substituted or unsubstituted fused ring are each independently a hydrogen atom, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a substituted or unsubstituted aryl group having 6 to 50 ring carbon atoms, or a substituted or unsubstituted heterocyclic group having 5 to 50 ring atoms;
at least one combination of adjacent two or more of R₂₁₁ to R₂₁₈ are mutually bonded to form a substituted or unsubstituted monocyclic ring, mutually bonded to form a substituted or unsubstituted fused ring, or not mutually bonded;
R₂₁₁ to R₂₁₈ forming neither the substituted or unsubstituted monocyclic ring nor the substituted or unsubstituted fused ring are each independently a hydrogen atom, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a substituted or unsubstituted aryl group having 6 to 50 ring carbon atoms, or a substituted or unsubstituted heterocyclic group having 5 to 50 ring atoms; and
* in the formulae (21a), (21b), (21c), (21d), and (21e) are each independently a bonding position to L_{A1}, L_{B1}, or L_{C1}.

A₁, B₁, and C₁ not being the group selected from the group consisting of the groups represented by the formulae (21a), (21b), (21c), (21d) and (21e) are preferably each independently a substituted or unsubstituted aryl group having 6 to 30 ring carbon atoms.

The compound represented by the formula (22) is also preferably a compound represented by a formula (A221) below.

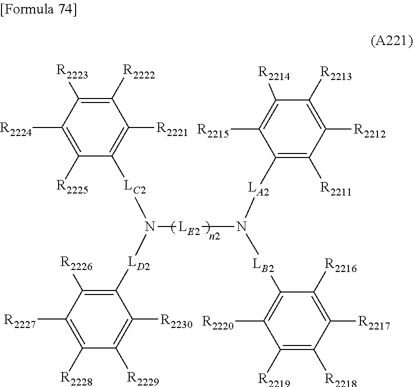

In the formula (A221):
L_{A2}, L_{B2}, L_{C2}, L_{D2} and L_{E2} are each independently a single bond, a substituted or unsubstituted arylene group having 6 to 50 ring carbon atoms, or a substituted or unsubstituted divalent heterocyclic group having 5 to 50 ring atoms;
n2 is 1, 2, 3, or 4;
when n2 is 2, 3, or 4, a plurality of L_{E2} are mutually the same or different;
at least one combination of adjacent two or more of R₂₂₁₁ to R₂₂₃₀ are mutually bonded to form a substituted or unsubstituted monocyclic ring, mutually bonded to form a substituted or unsubstituted fused ring, or not mutually bonded; and
R₂₂₁₁ to R₂₂₃₀ forming neither the substituted or unsubstituted monocyclic ring nor the substituted or unsubstituted fused ring are each independently a hydrogen atom, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —N(R₉₀₆)(R₉₀₇), a substituted or unsubstituted aryl group having 6 to 50 ring carbon atoms, or a substituted or unsubstituted heterocyclic group having 5 to 50 ring atoms.

In the hole transporting zone material of the organic EL device according to the exemplary embodiment, R₉₀₁, R₉₀₂, R₉₀₃, R₉₀₄, R₉₀₅, R₉₀₆ and R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;

when a plurality of R₉₀₁ are present, the plurality of R₉₀₁ are mutually the same or different;

when a plurality of R₉₀₂ are present, the plurality of R₉₀₂ are mutually the same or different;

when a plurality of R₉₀₃ are present, the plurality of R₉₀₃ are mutually the same or different;

when a plurality of R₉₀₄ are present, the plurality of R₉₀₄ are mutually the same or different;

when a plurality of R₉₀₅ are present, the plurality of R₉₀₅ are mutually the same or different;

when a plurality of R₉₀₆ are present, the plurality of R₉₀₆ are mutually the same or different; and

when a plurality of R₉₀₇ are present, the plurality of R₉₀₇ are mutually the same or different.

In the hole transporting zone material according to the exemplary embodiment, the groups specified to be “substituted or unsubstituted” are each preferably an “unsubstituted” group.

In the organic EL device according to the exemplary embodiment, the hole transporting zone material may be a compound that contains a substituted or unsubstituted 3-carbazolyl group in a molecule. In the organic EL device according to the exemplary embodiment, the hole transporting zone material may be a compound that does not contain a substituted or unsubstituted 3-carbazolyl group in a molecule.

In the organic EL device according to the exemplary embodiment, when the hole transporting zone includes the hole transporting layer, the compound represented by the formula (21) or the formula (22) is usable for the hole transporting layer. For instance, an aromatic amine derivative, carbazole derivative, and anthracene derivative are also usable. Specifically, an aromatic amine derivative or the like, such as 4-phenyl-4′-(9-phenylfluorene-9-yl)triphenylamine (abbreviation: BAFLP), is usable.

A substance exhibiting high hole transportability that is used for the hole transporting layer is, for instance, a substance having a hole mobility of 10⁻⁶ cm²/(V·s) or more. It should be noted that any other substance than the above may be used for the hole transporting layer as long as the substance exhibits a higher hole transportability than electron transportability.

The layer containing a highly hole-transportable substance may be a single layer or formed in a layered structure in which two or more layers containing the above substance are layered.

For instance, a blocking layer may be provided adjacent to at least one of a side of the emitting region close to the anode or a side of the emitting region close to the cathode. The blocking layer is preferably provided in contact with the emitting region to block at least any of holes, electrons, or excitons.

For instance, when the blocking layer is provided in contact with the side of the emitting region close to the cathode, the blocking layer permits transport of electrons and blocks holes from reaching a layer provided closer to the cathode (e.g., electron transporting layer) beyond the blocking layer. When the organic EL device includes the electron transporting layer, the blocking layer is preferably interposed between the emitting region and the electron transporting layer.

### Method of Producing Hole Transporting Zone Material

The hole transporting zone material can be produced by a known method. The hole transporting zone material can also be produced based on a known method through a known alternative reaction using a known material(s) tailored for the target compound.

### Specific Examples of Hole Transporting Zone Material

Specific examples of the hole transporting zone material include the following compounds. It should however be noted that the invention is not limited to the specific examples of the hole transporting zone material.

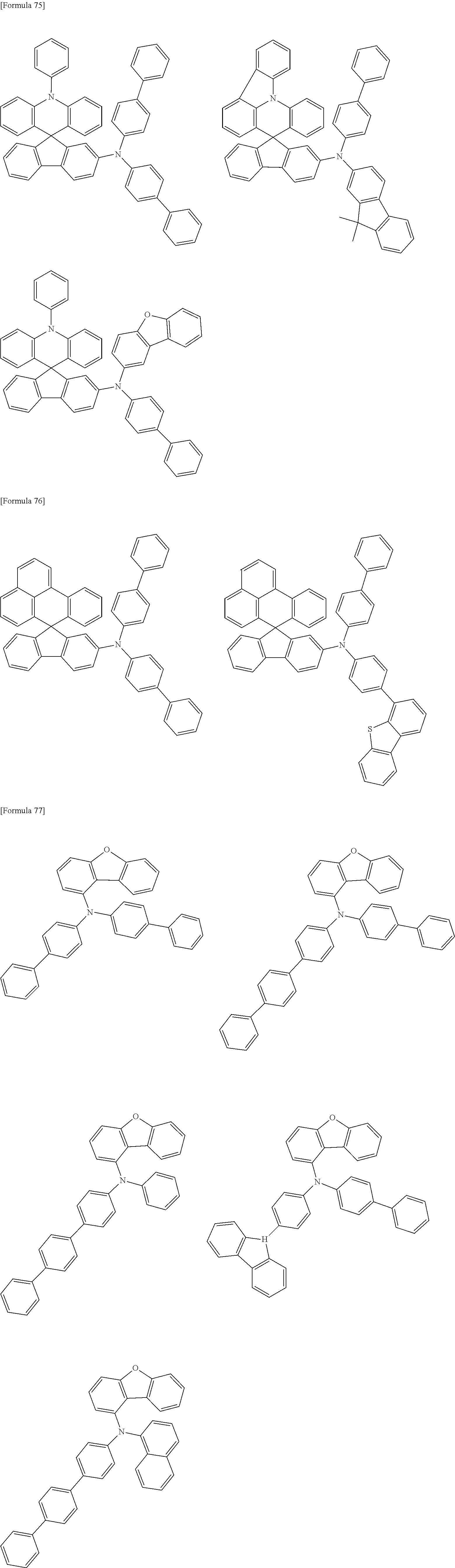

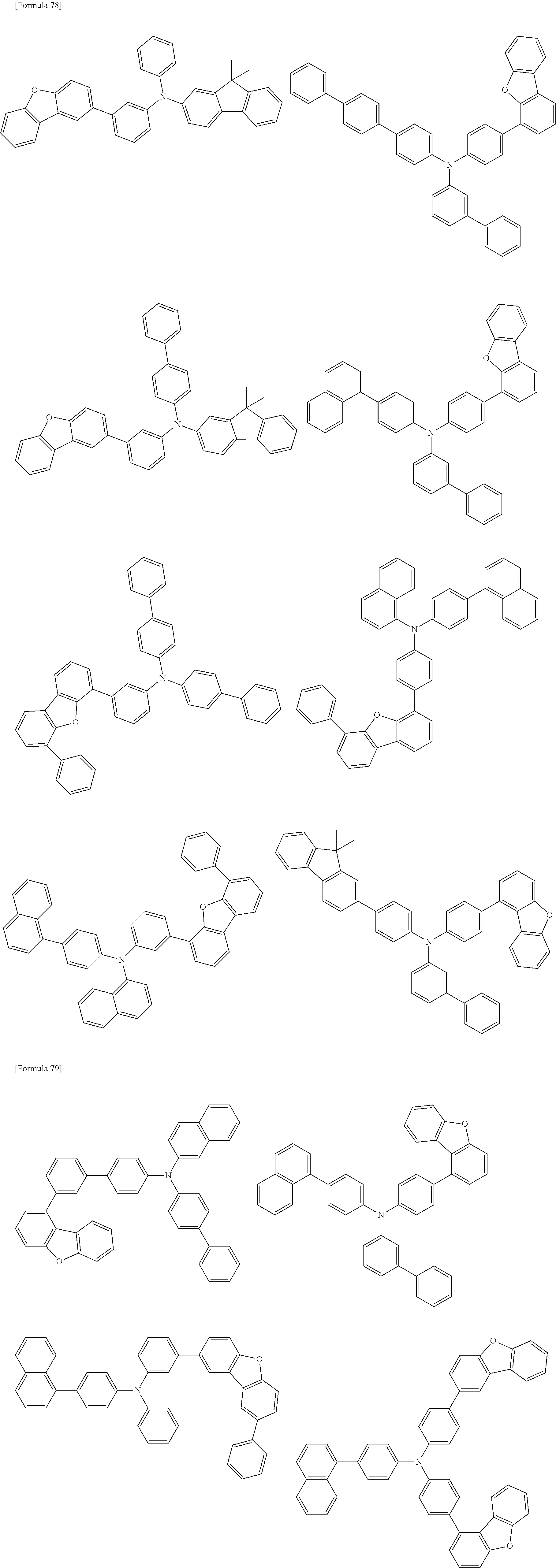

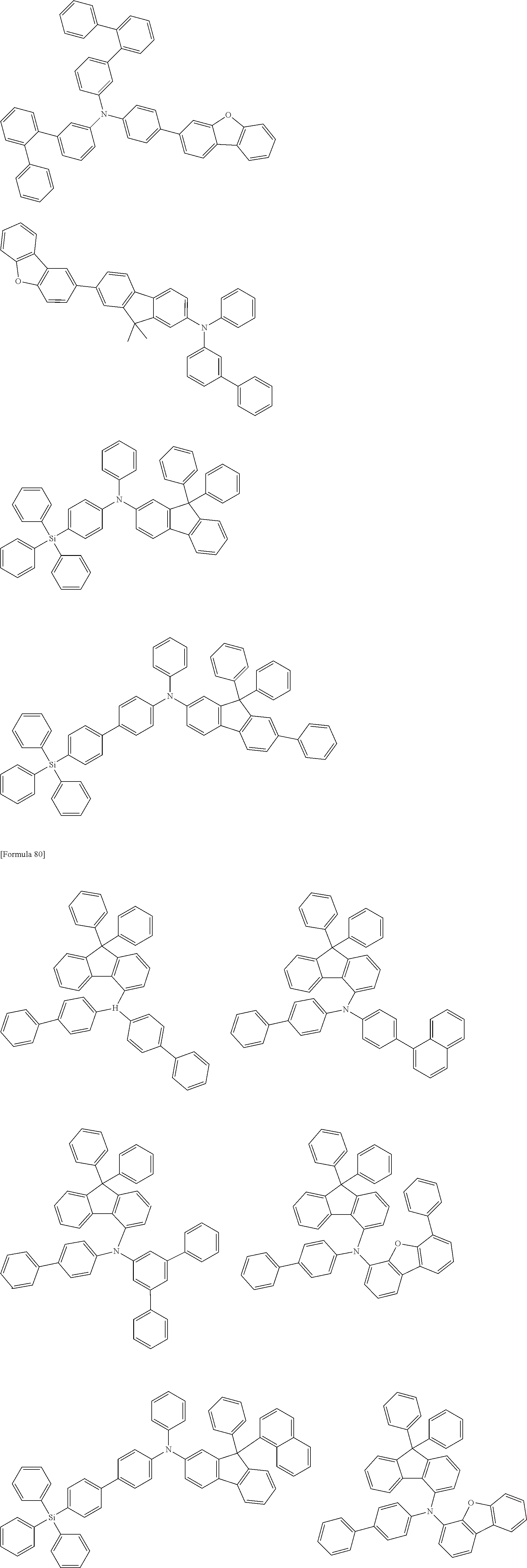

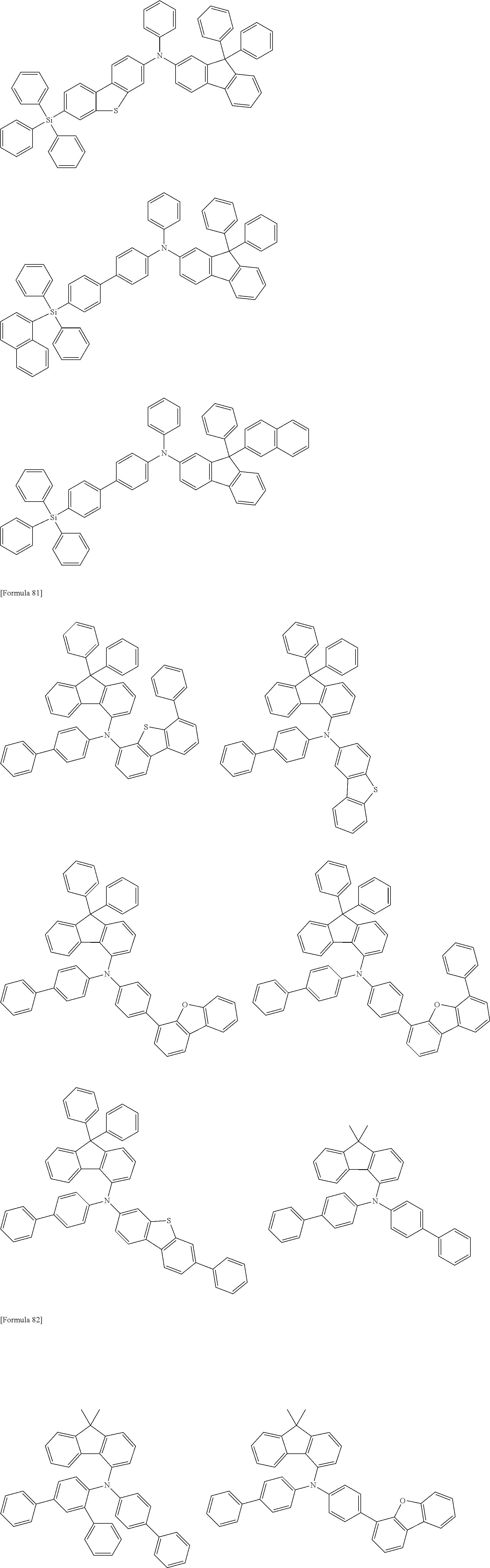

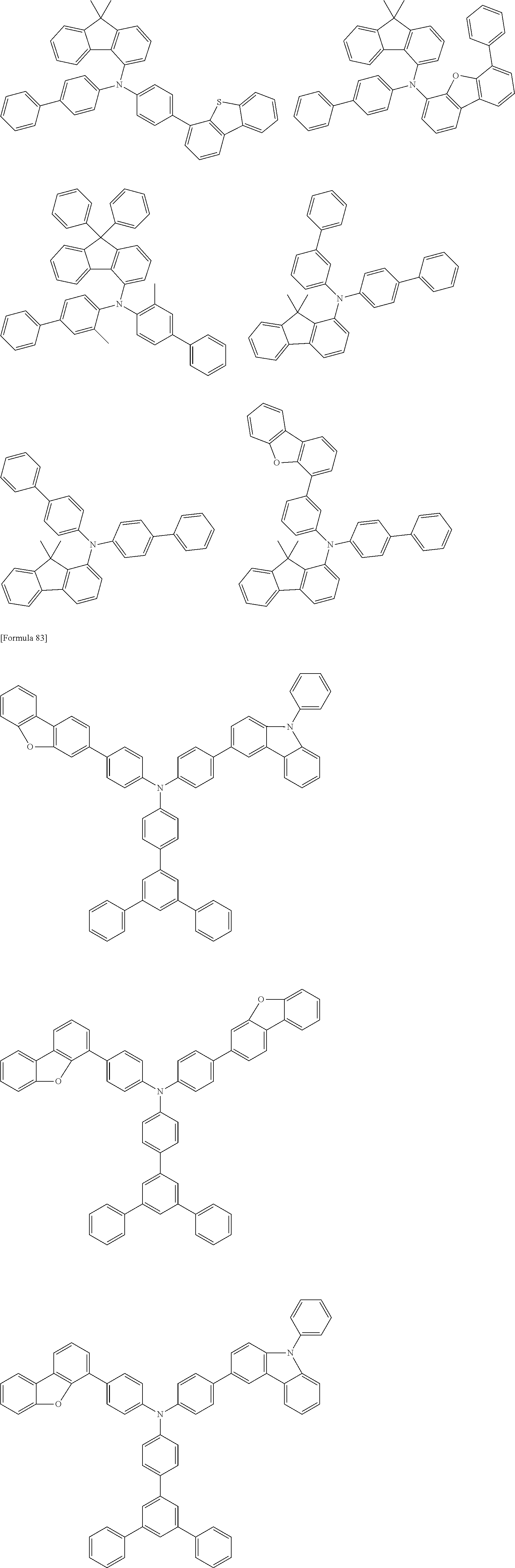

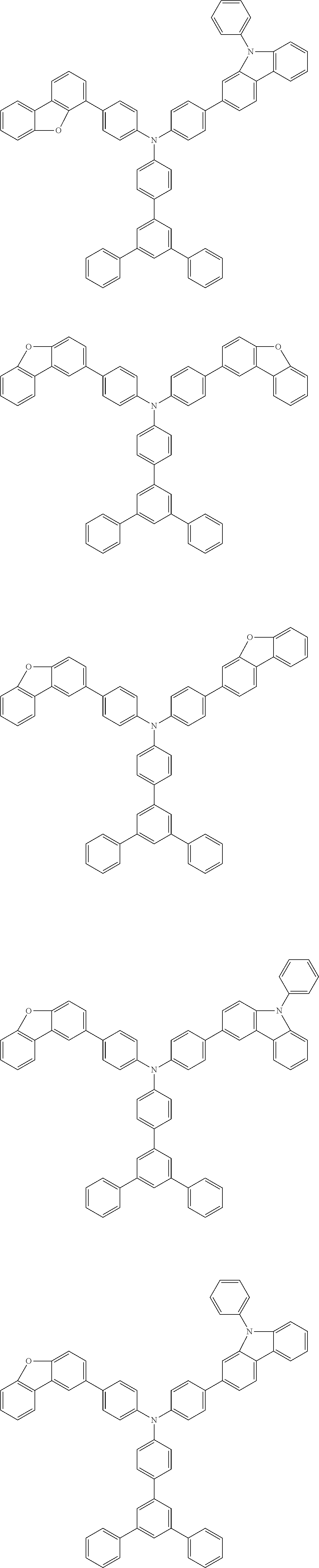

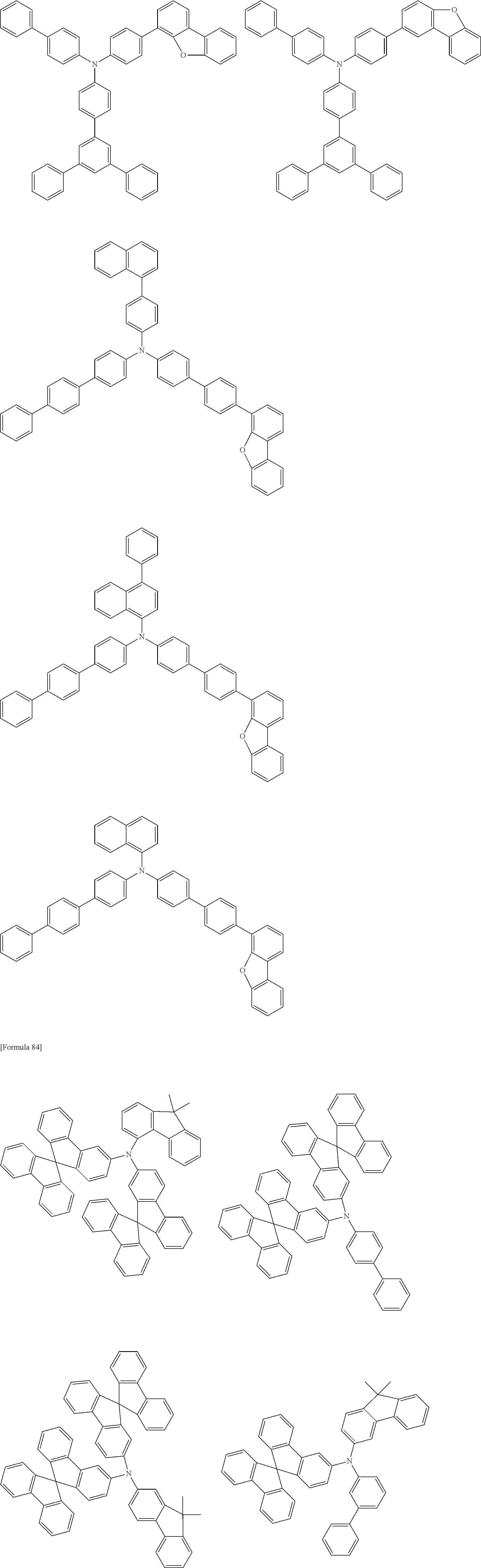

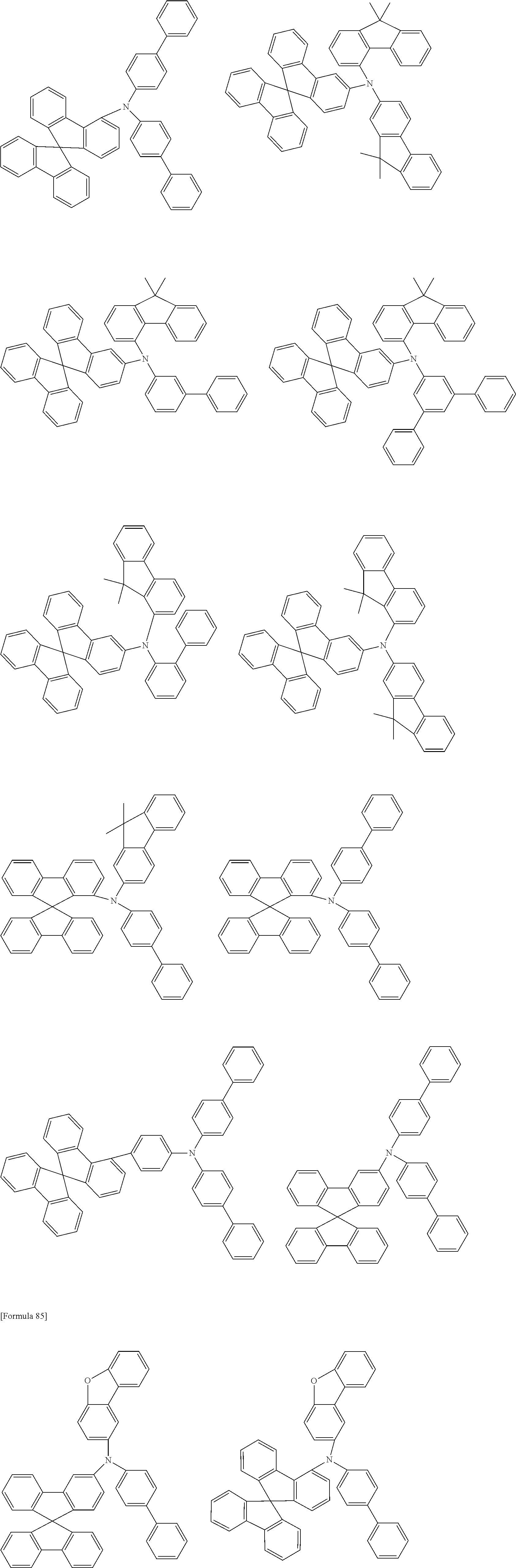

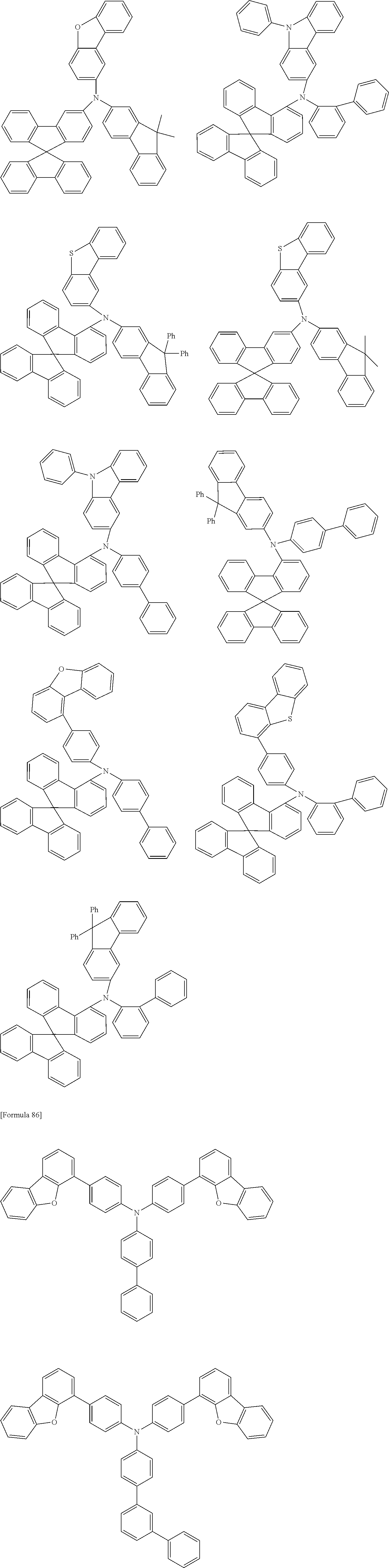

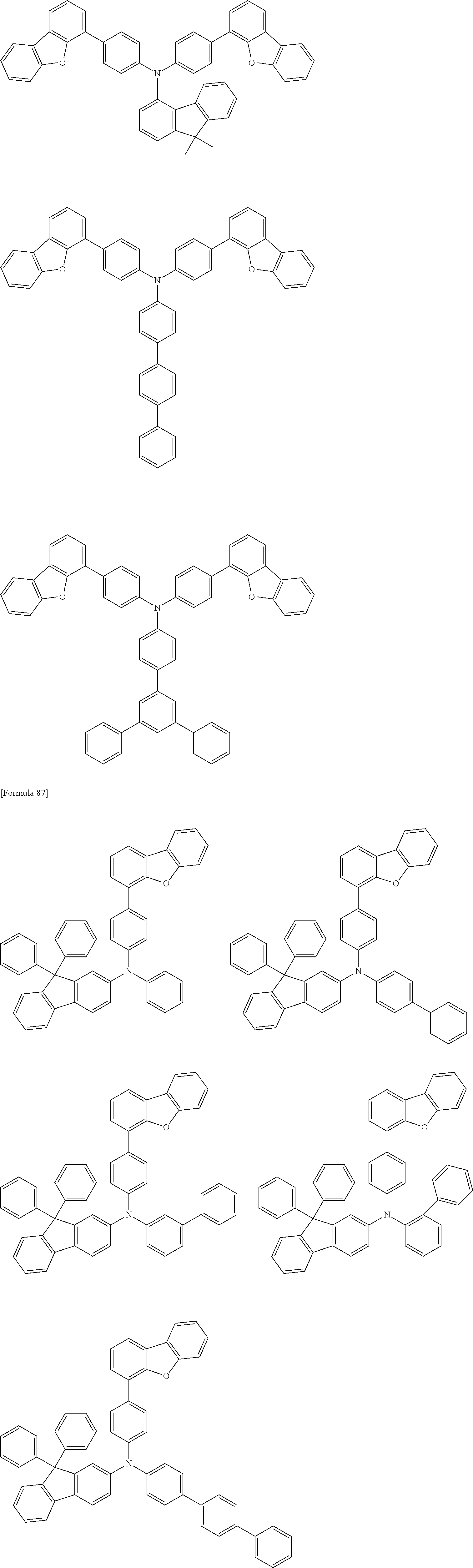

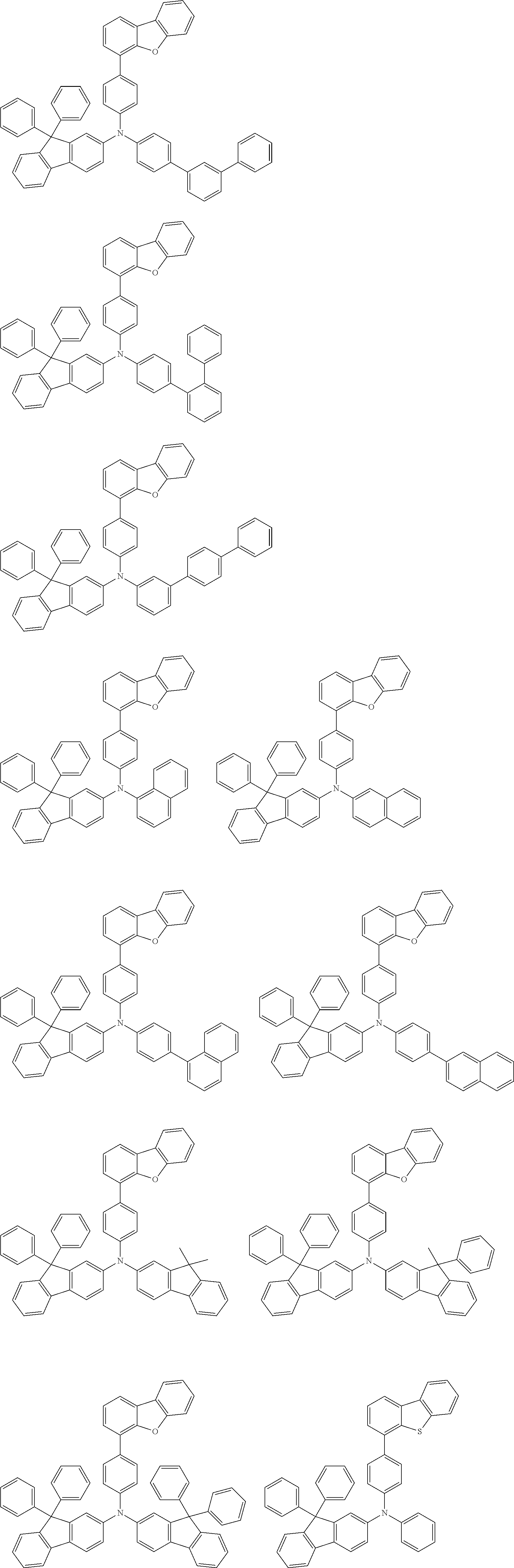

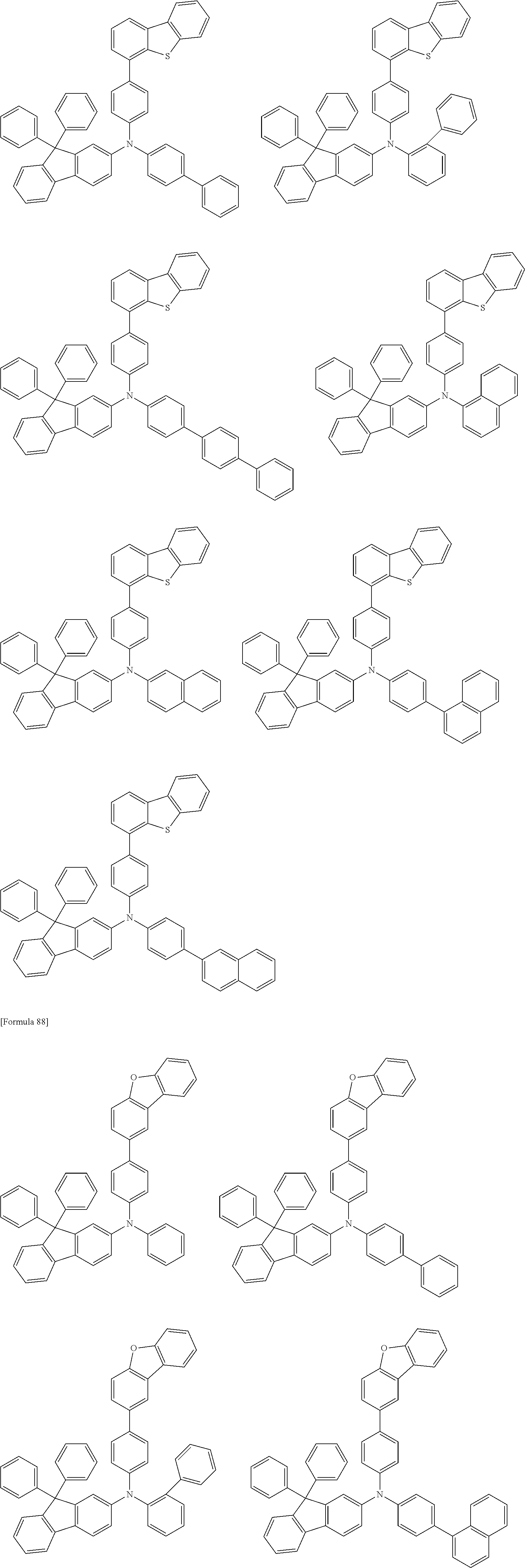

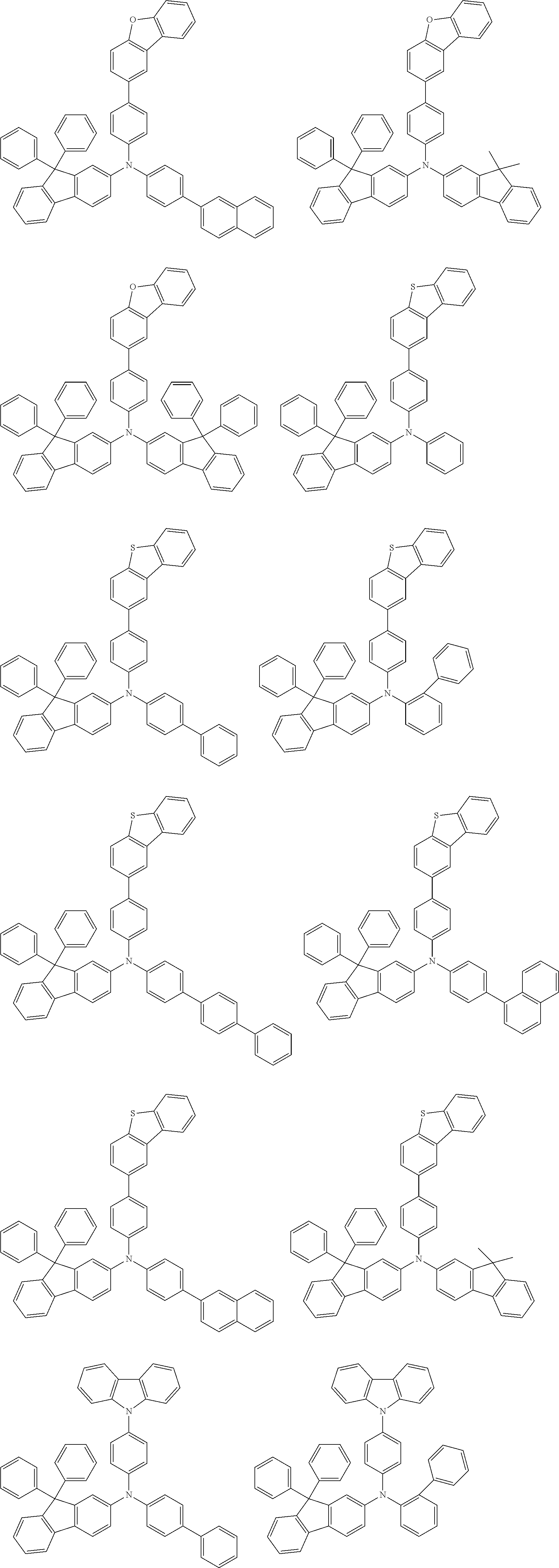

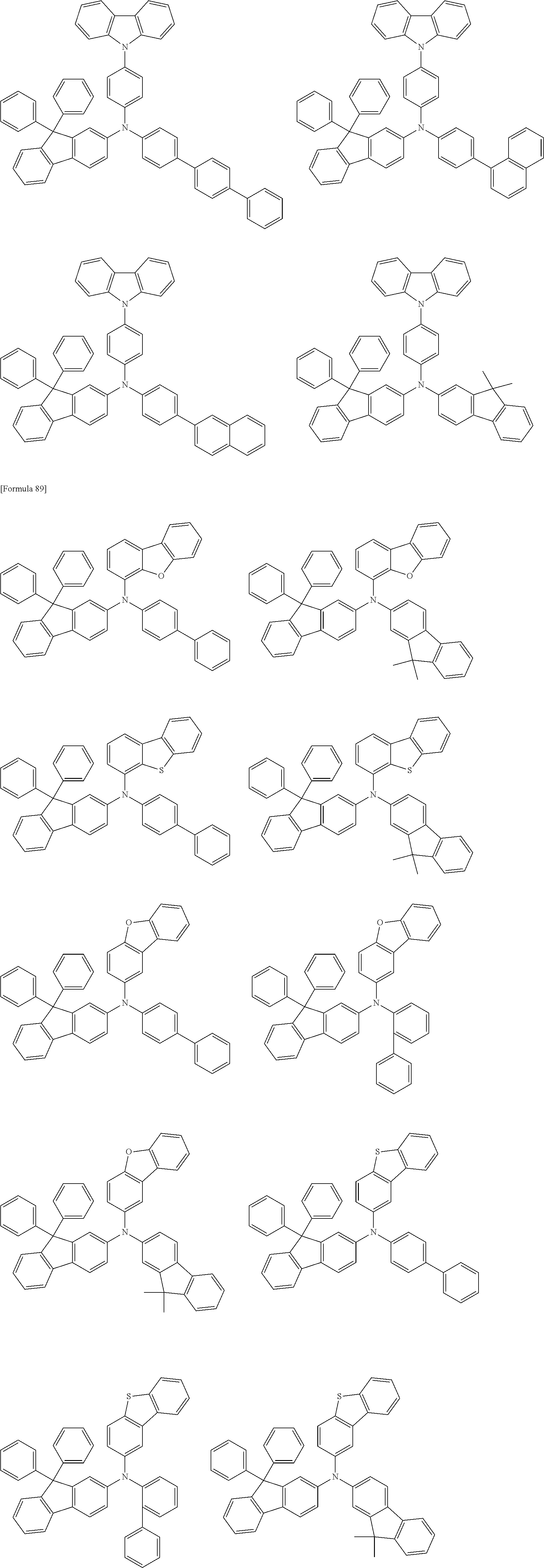

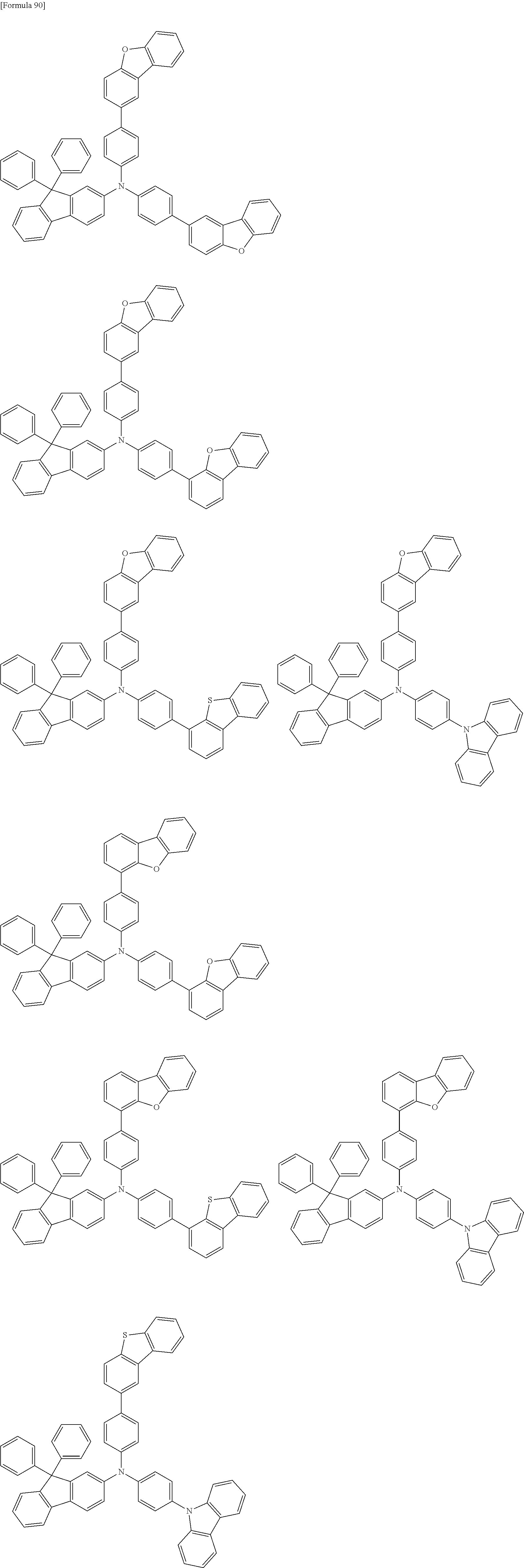

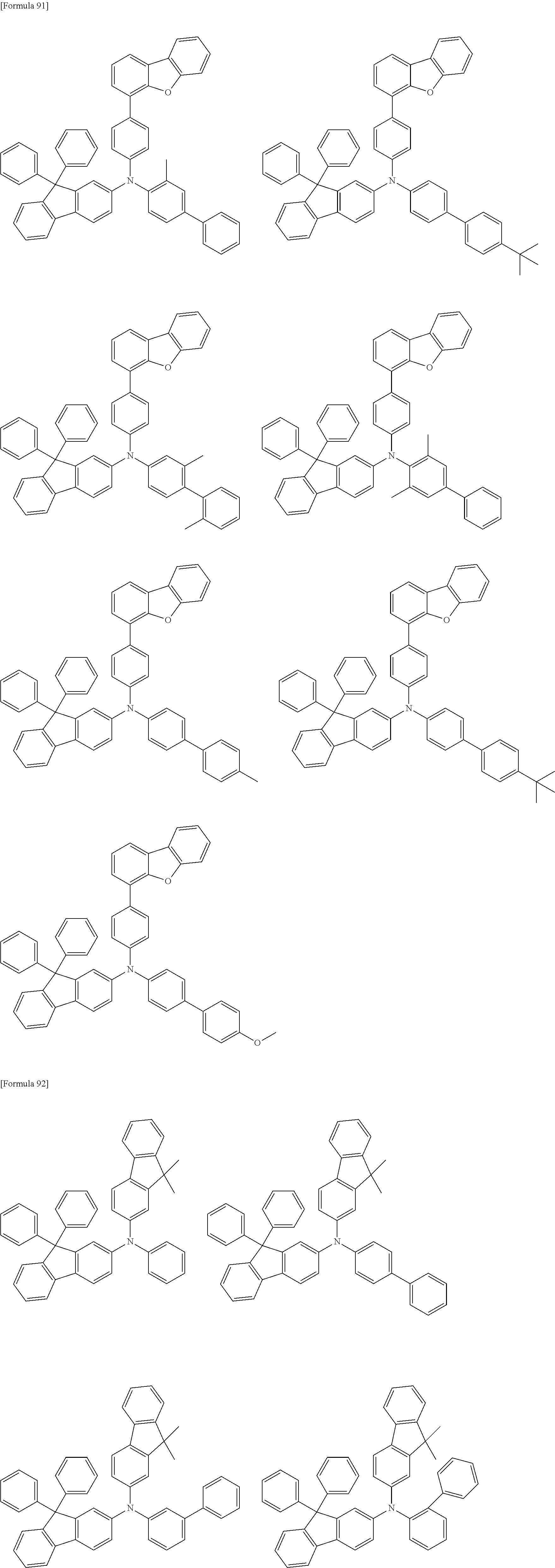

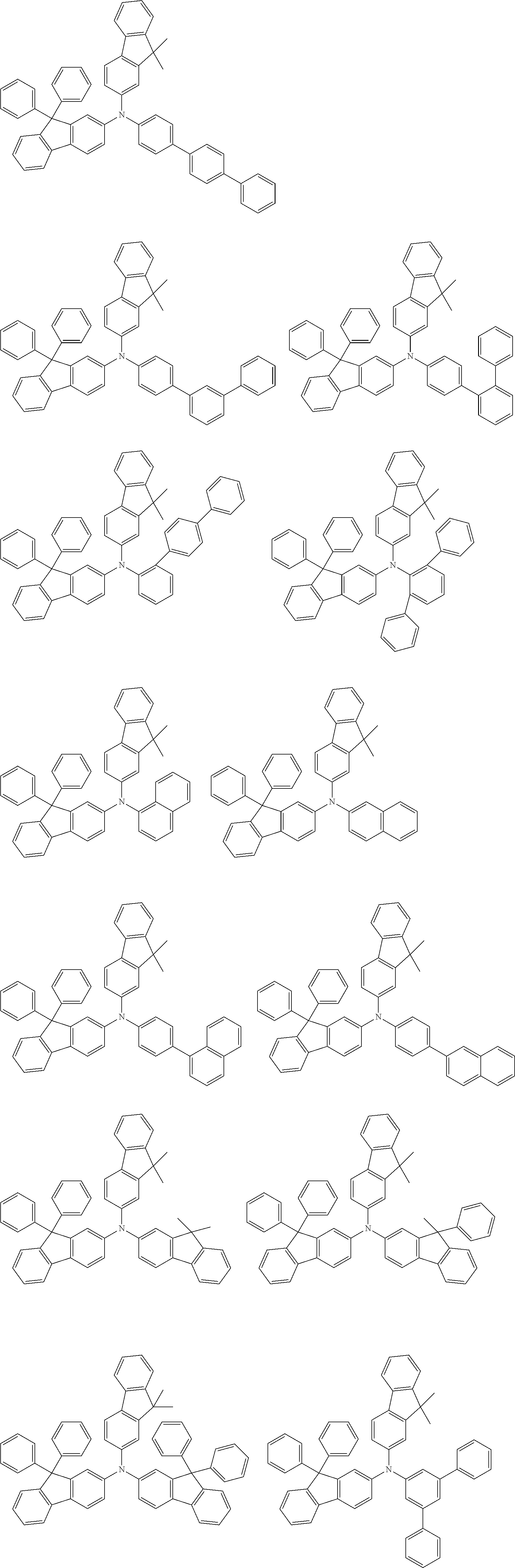

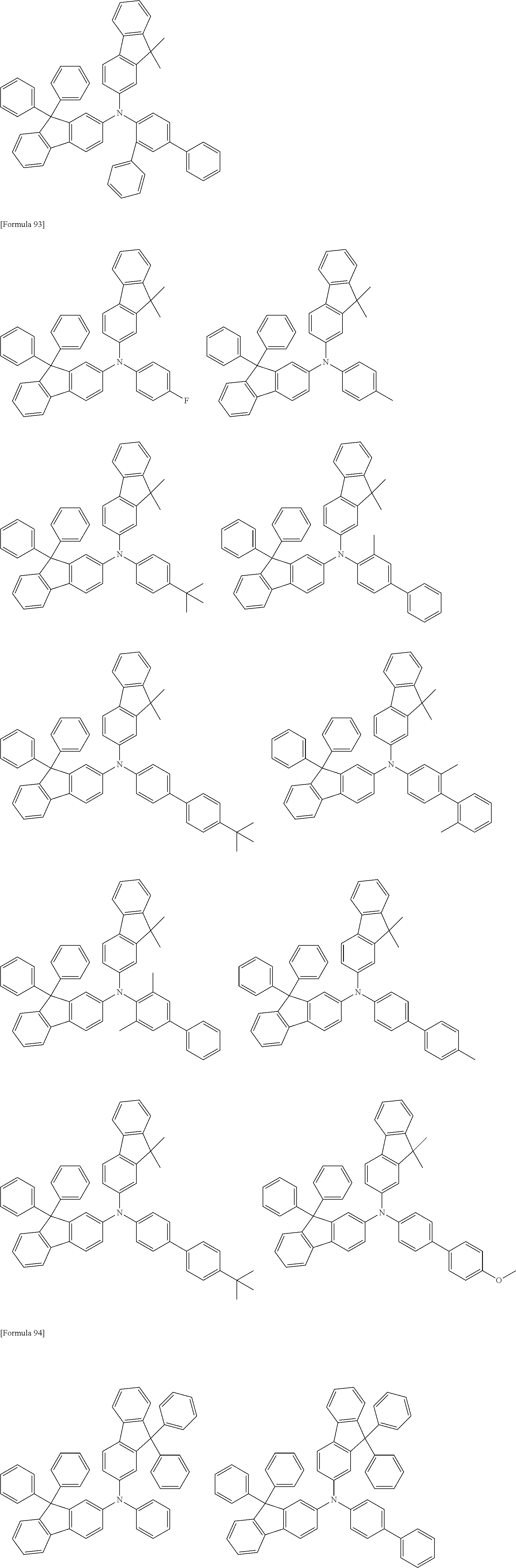

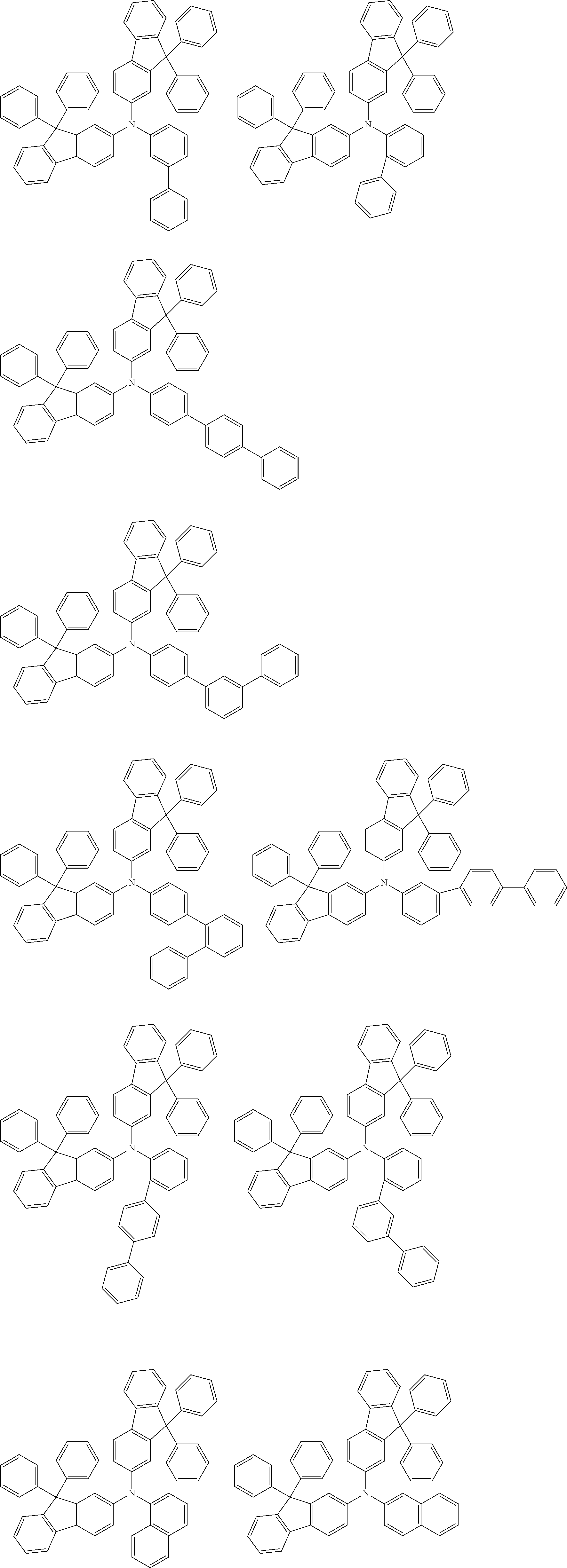

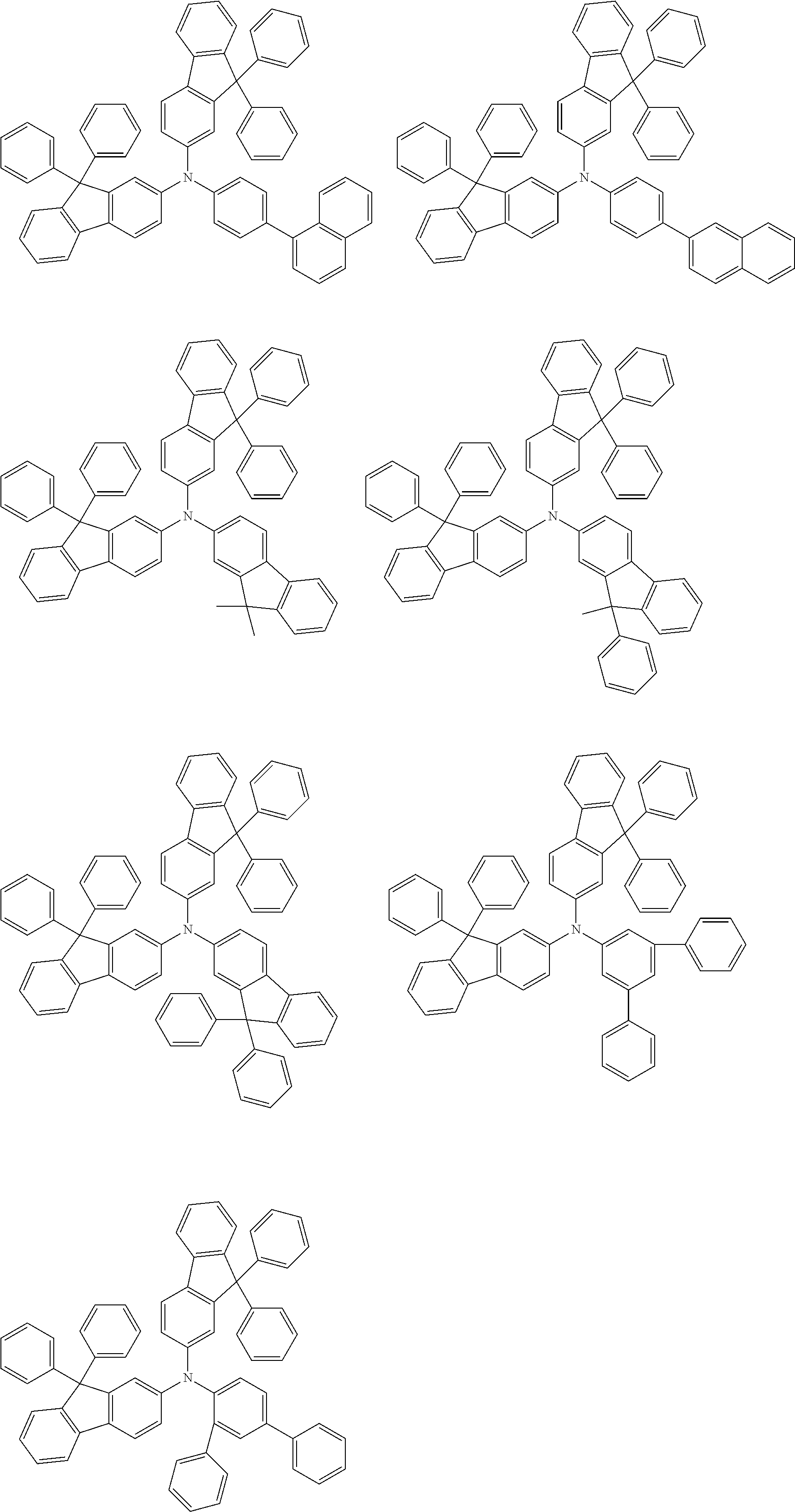

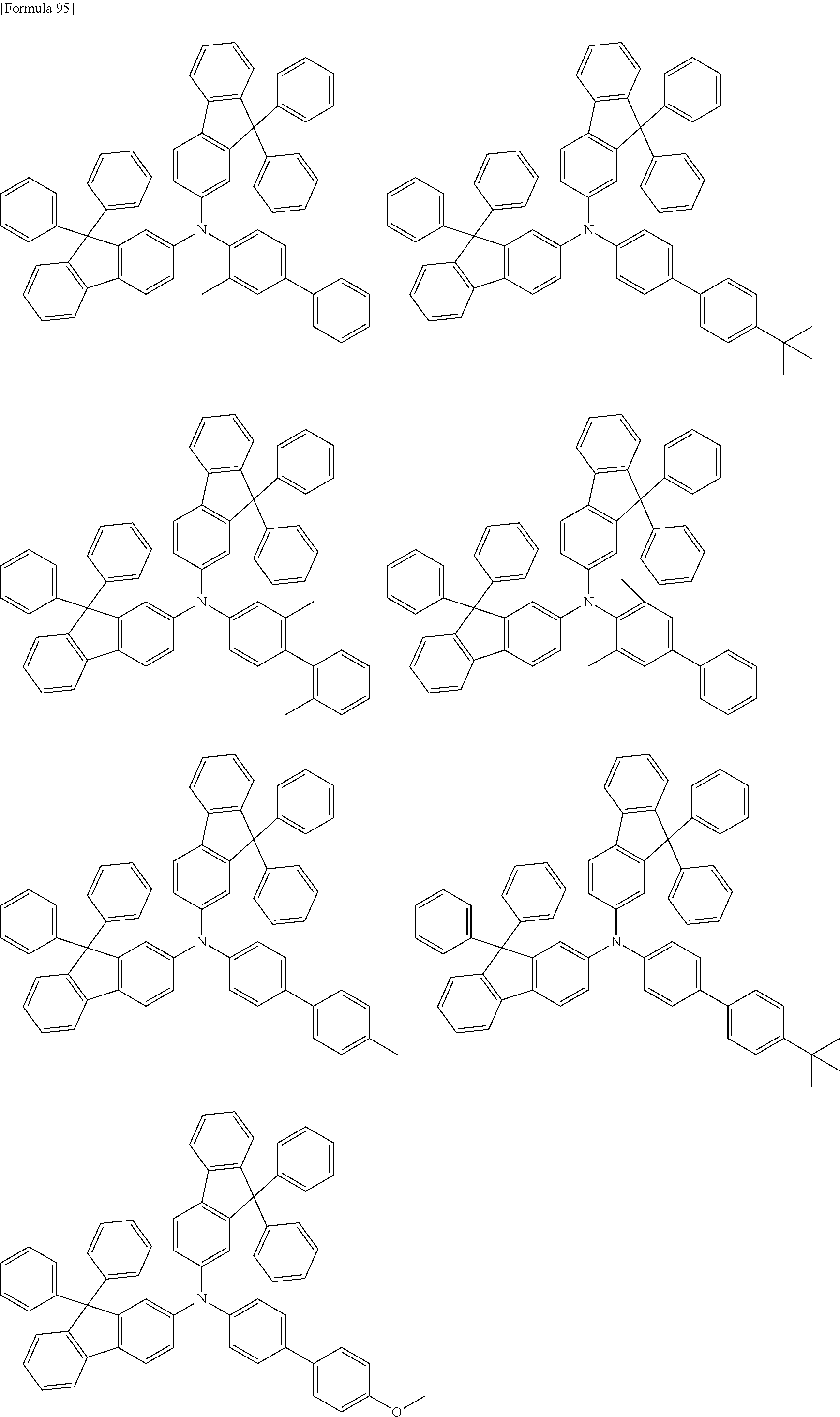

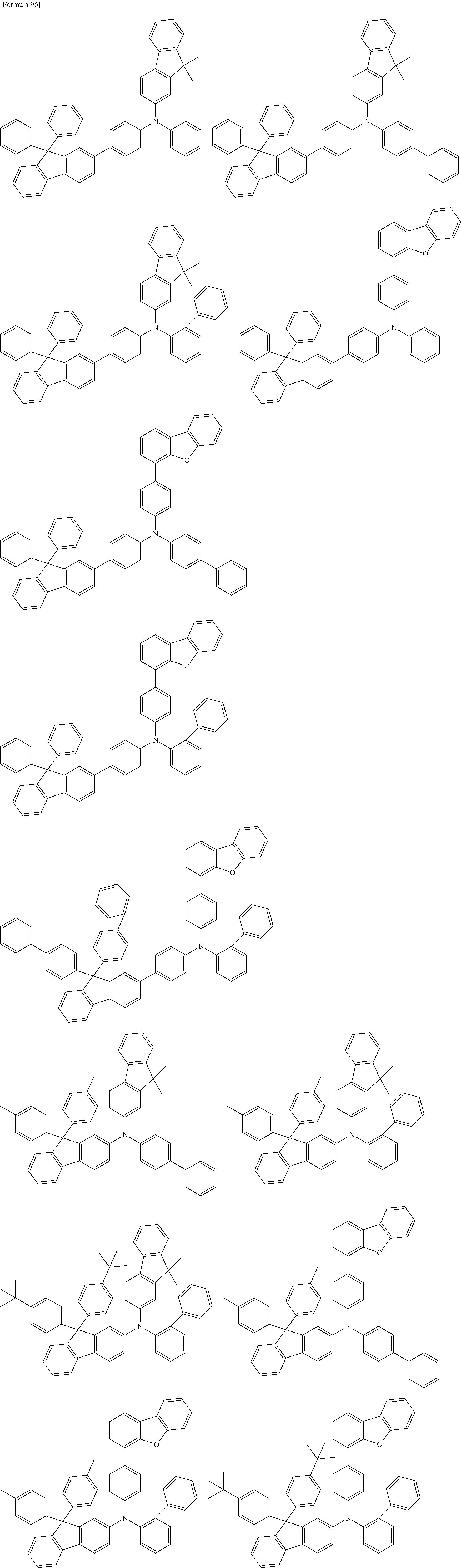

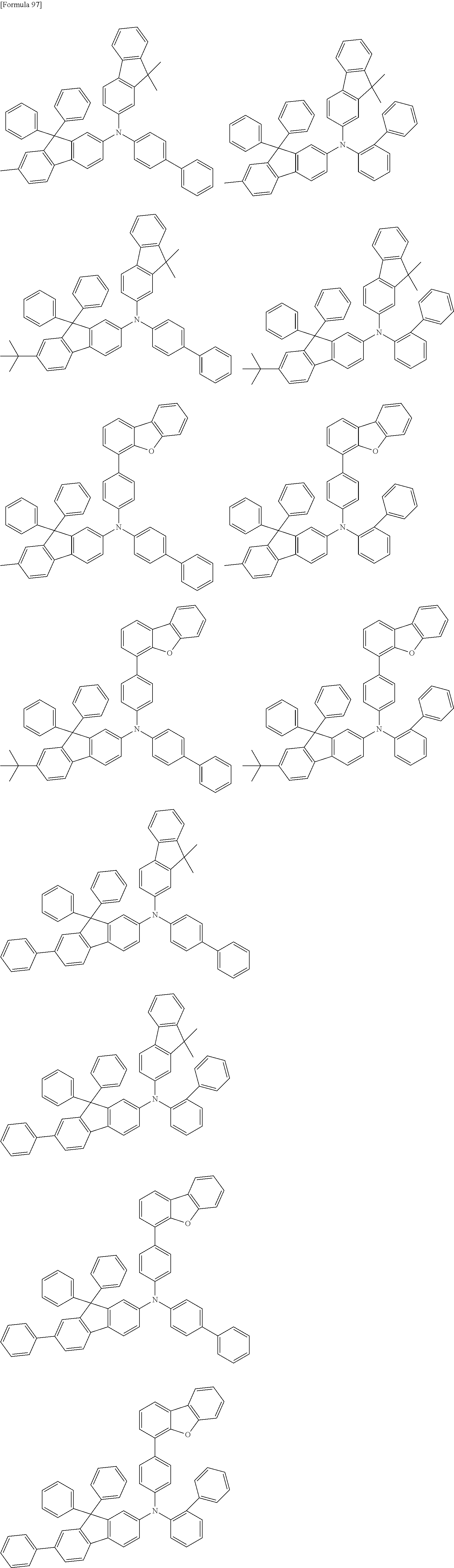

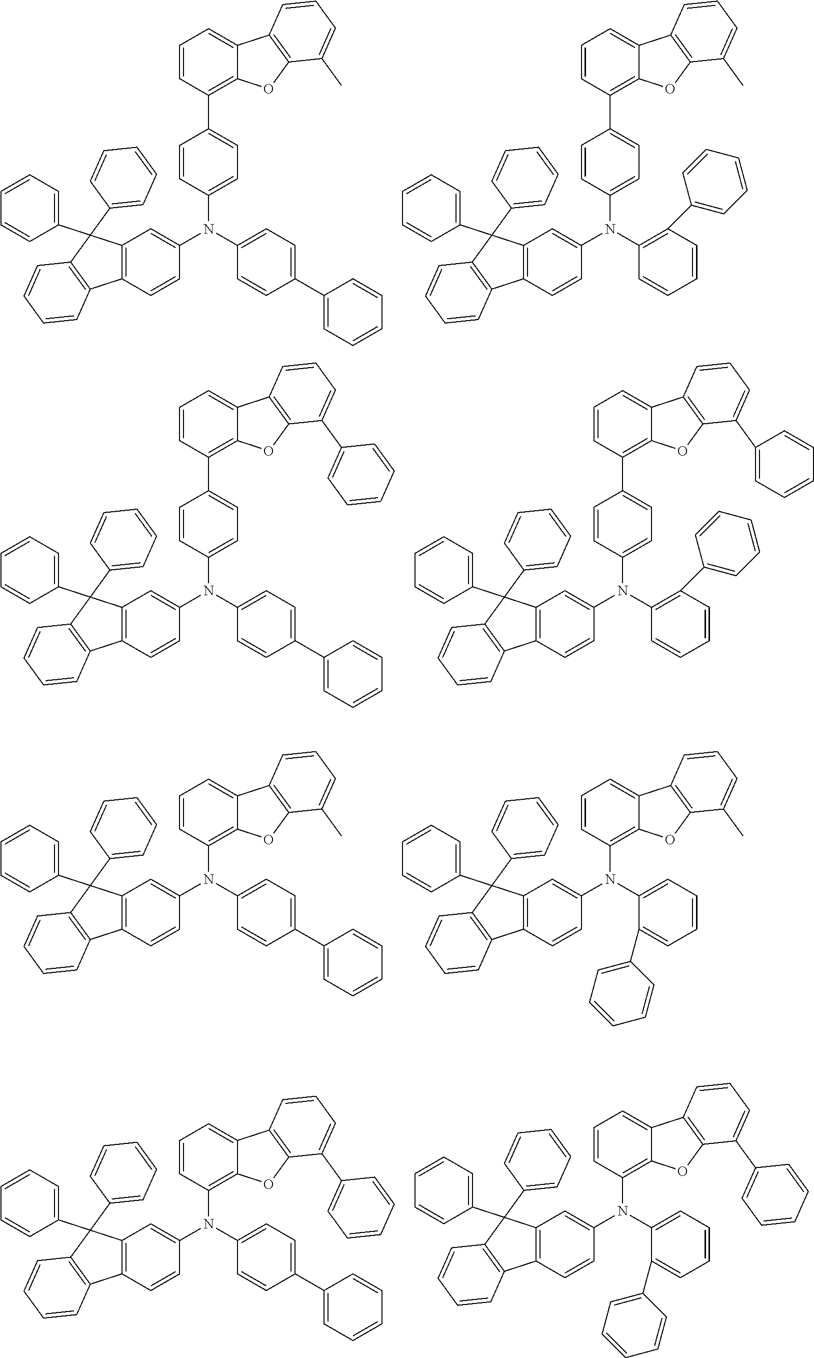

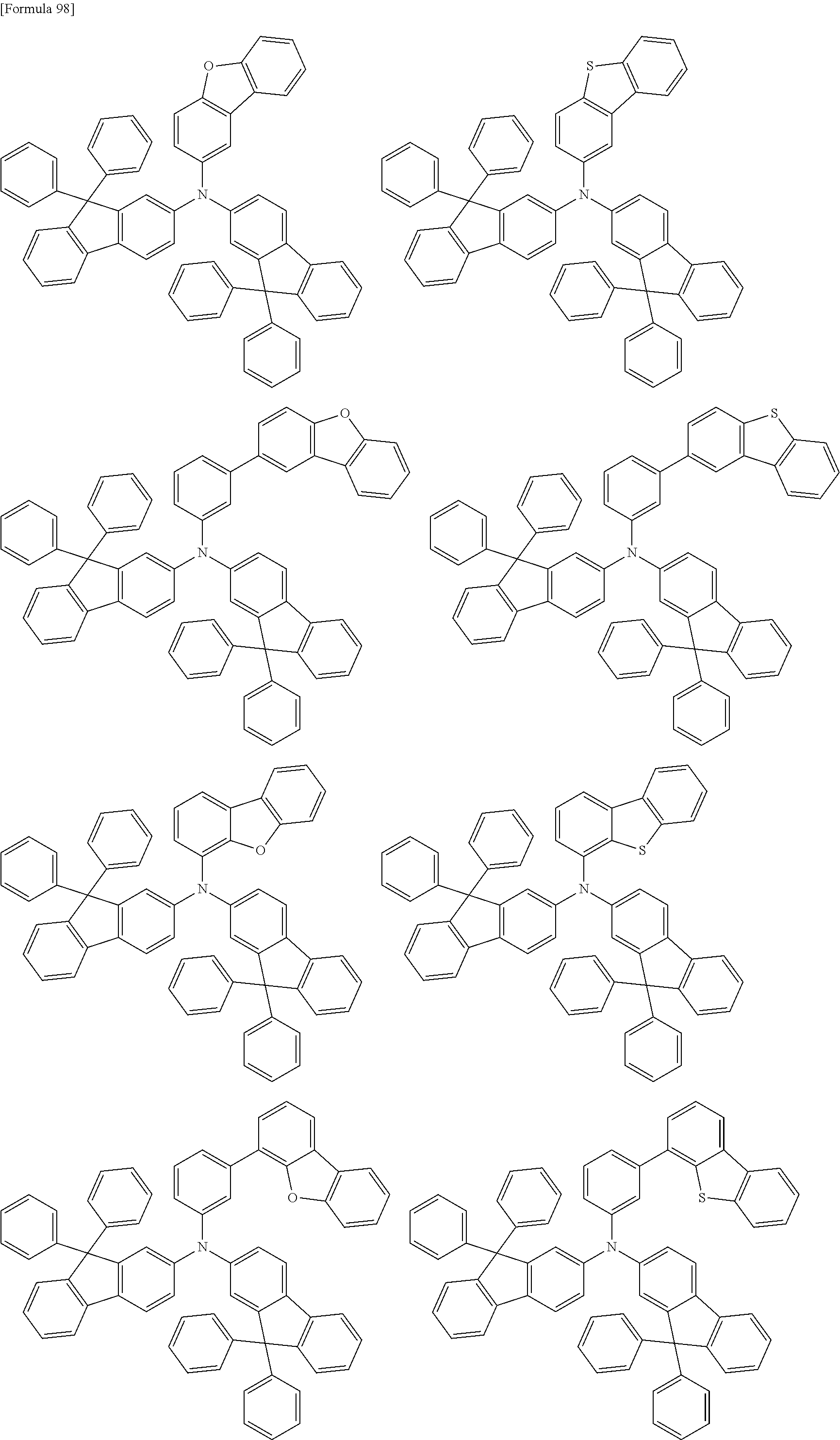

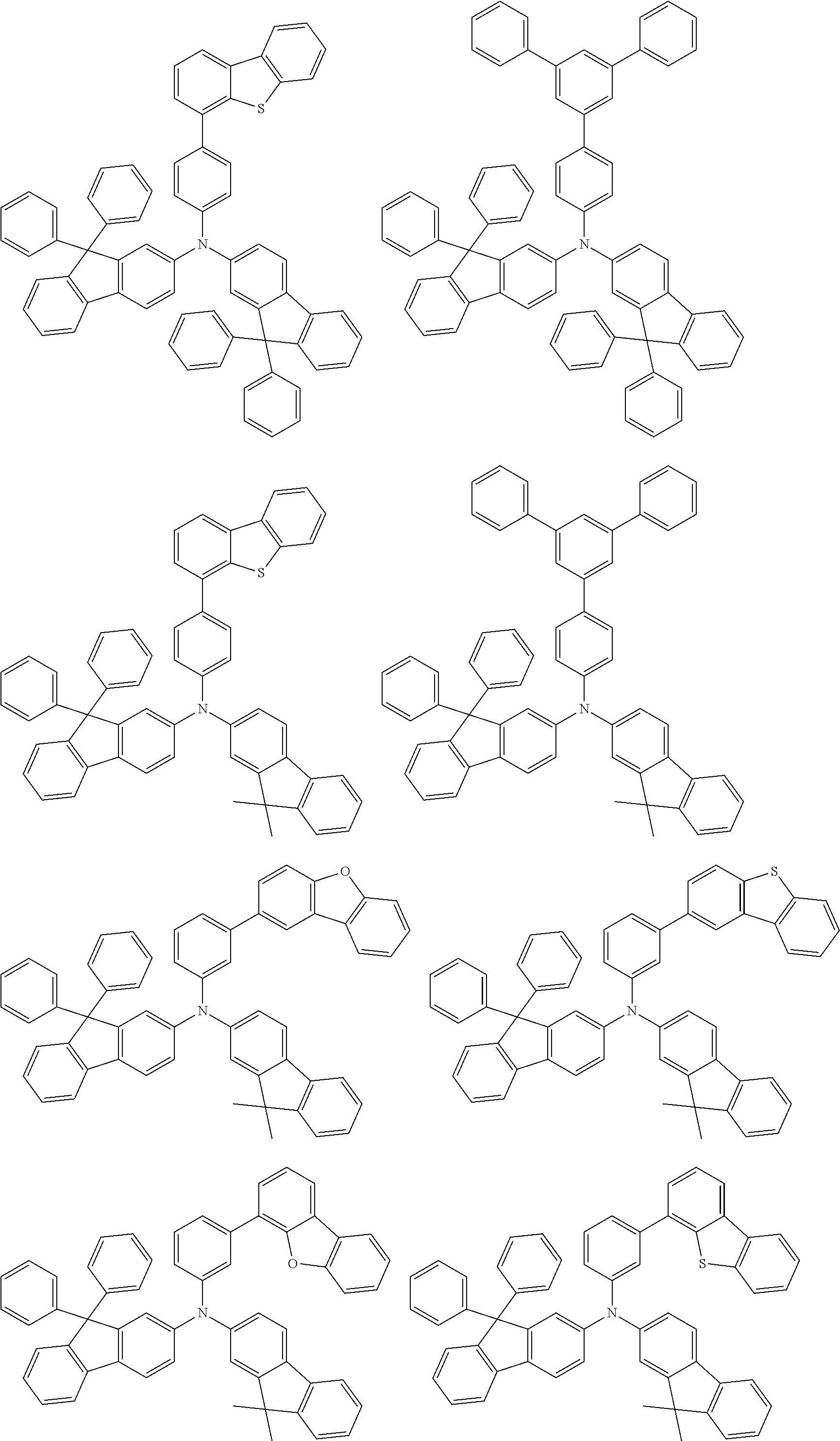

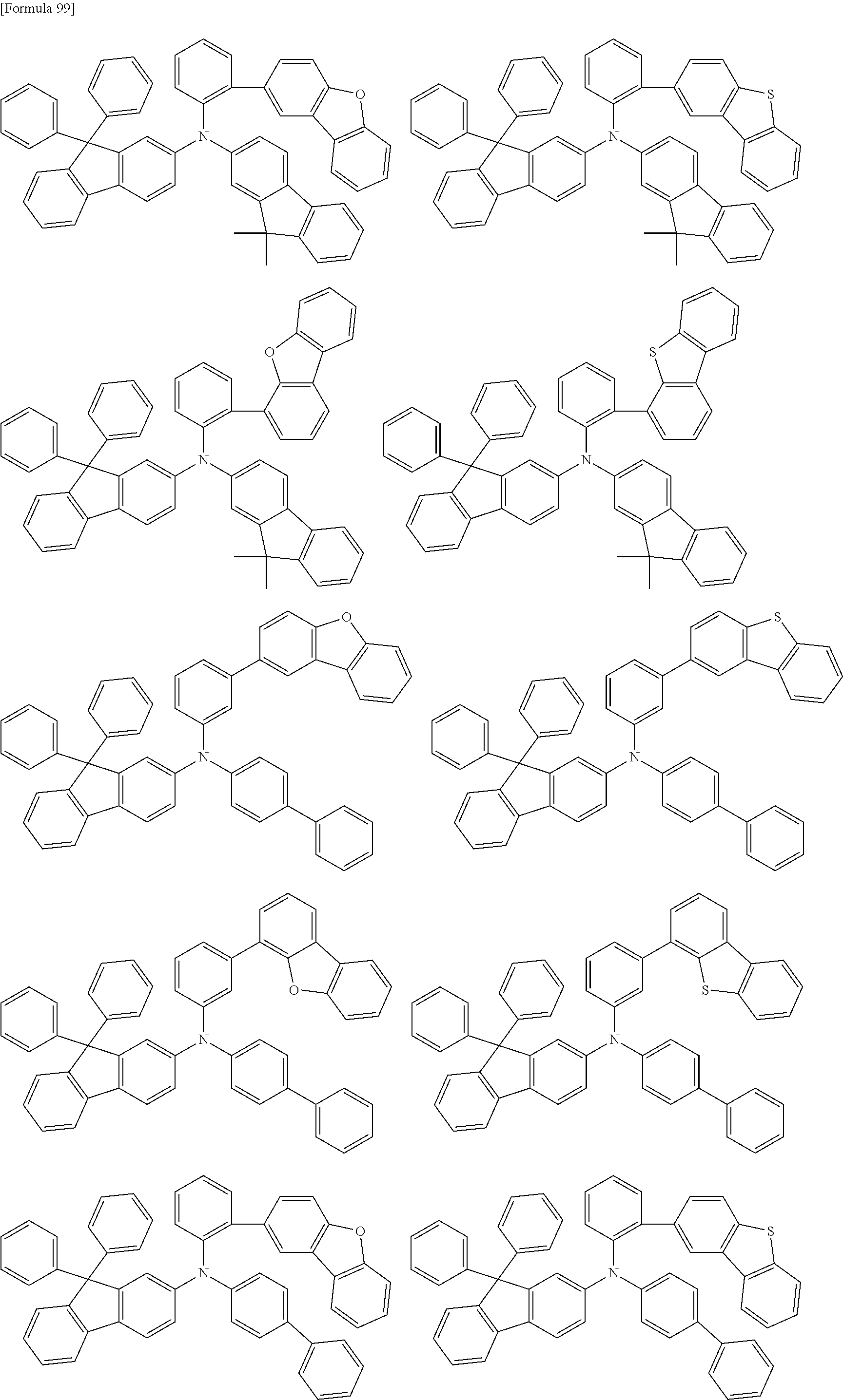

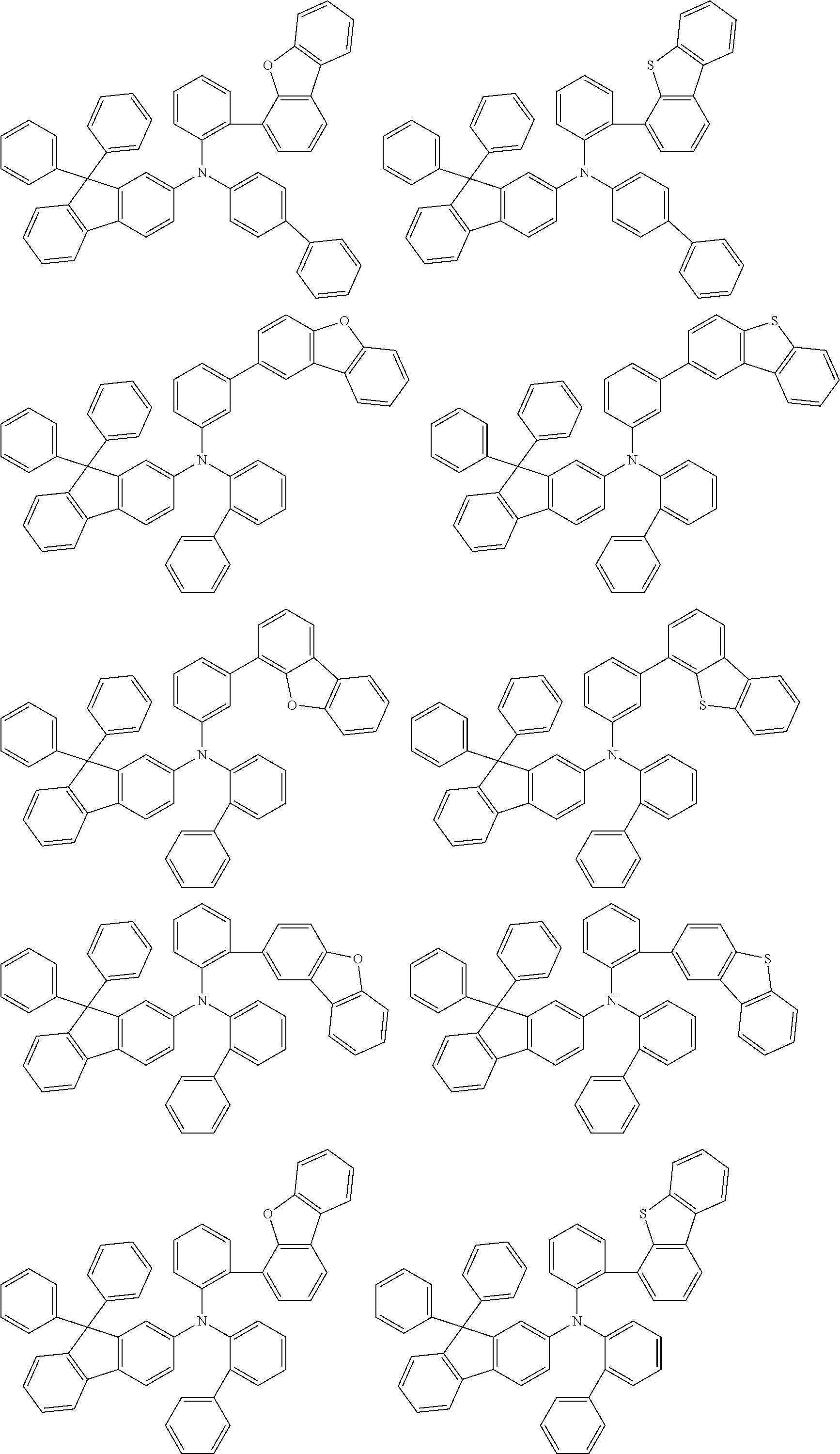

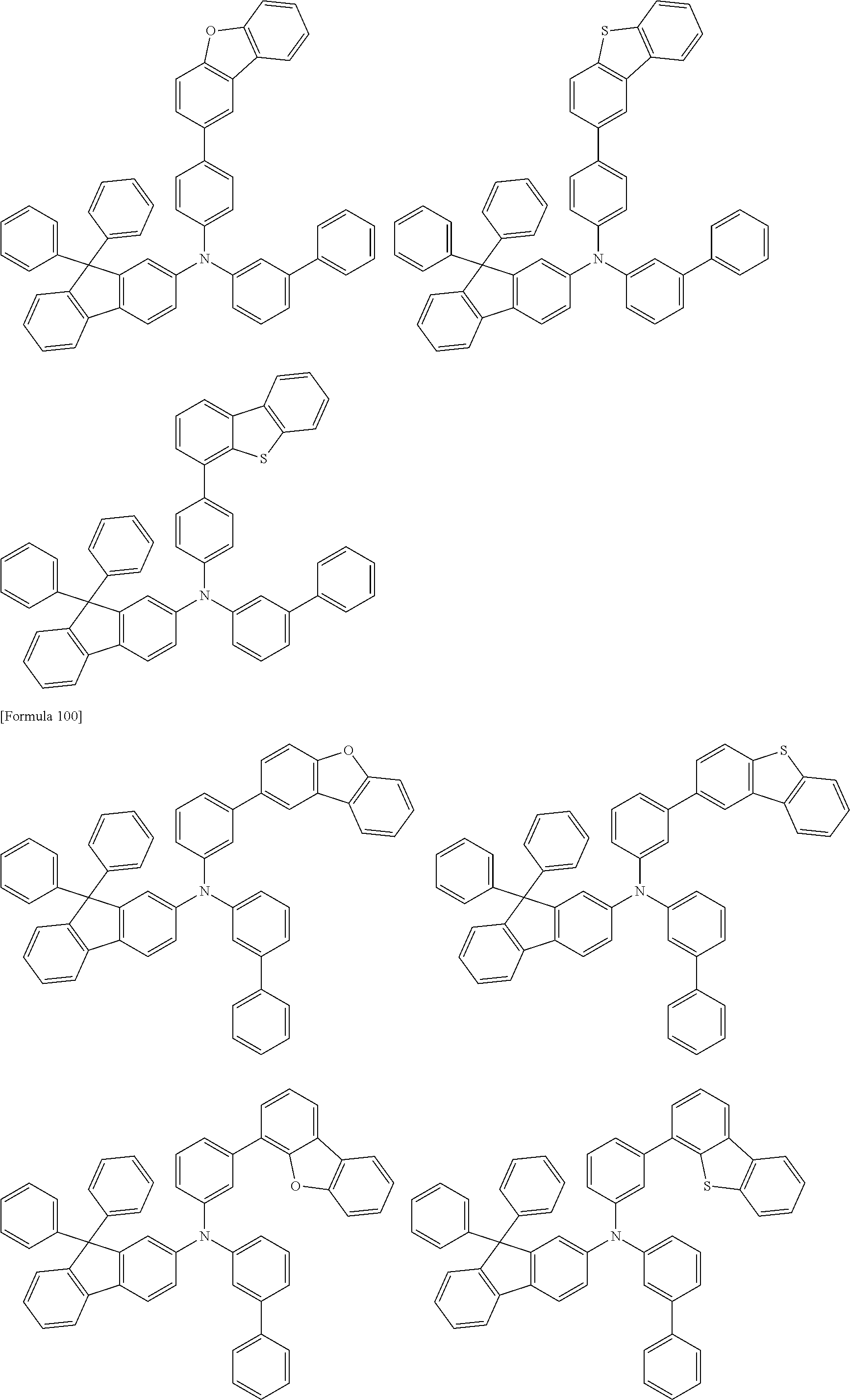

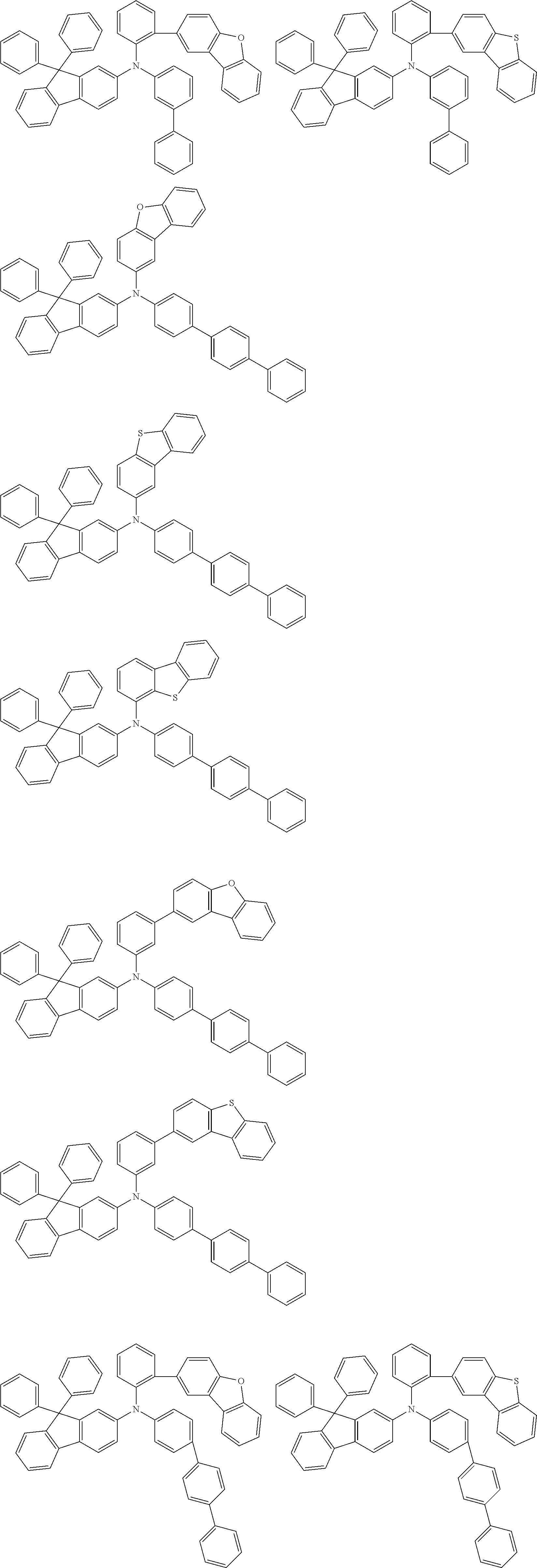

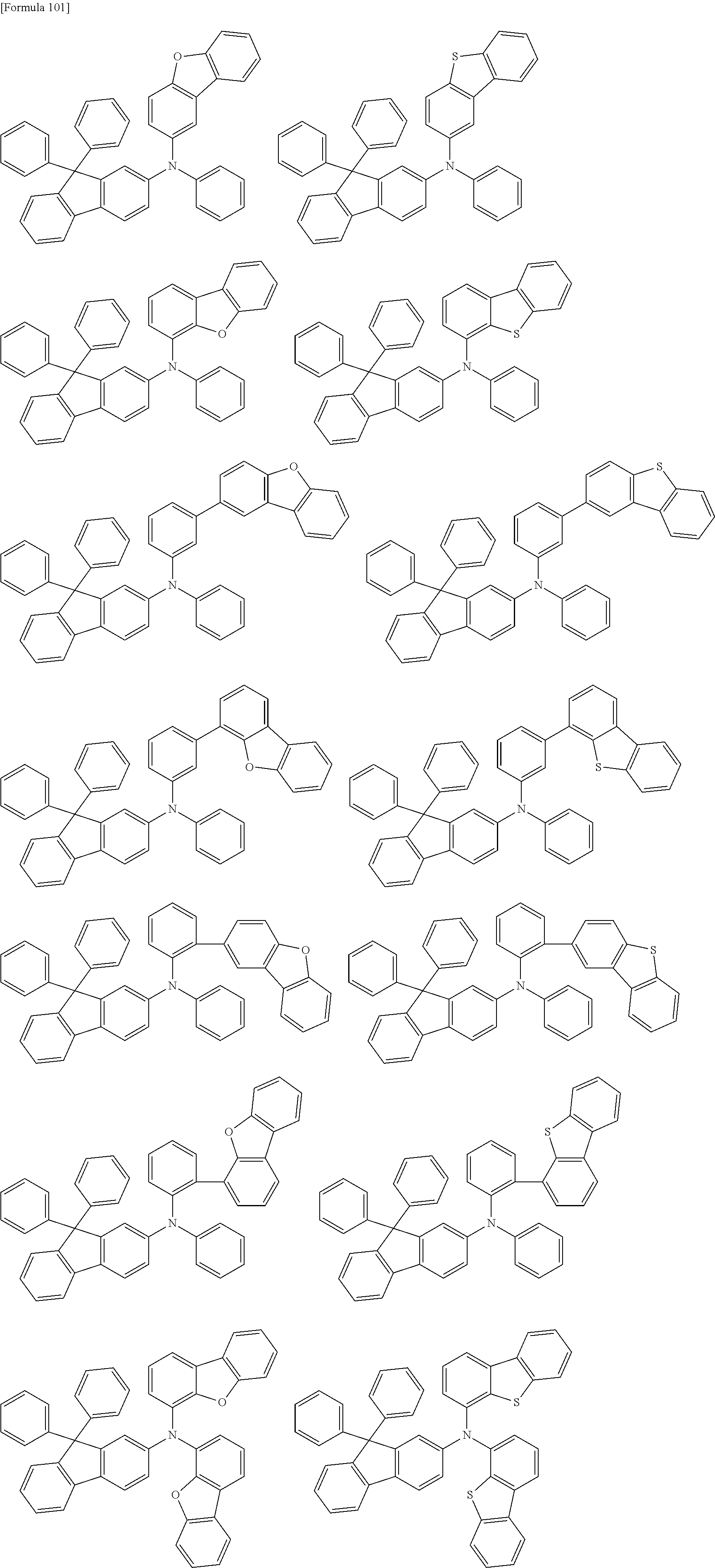

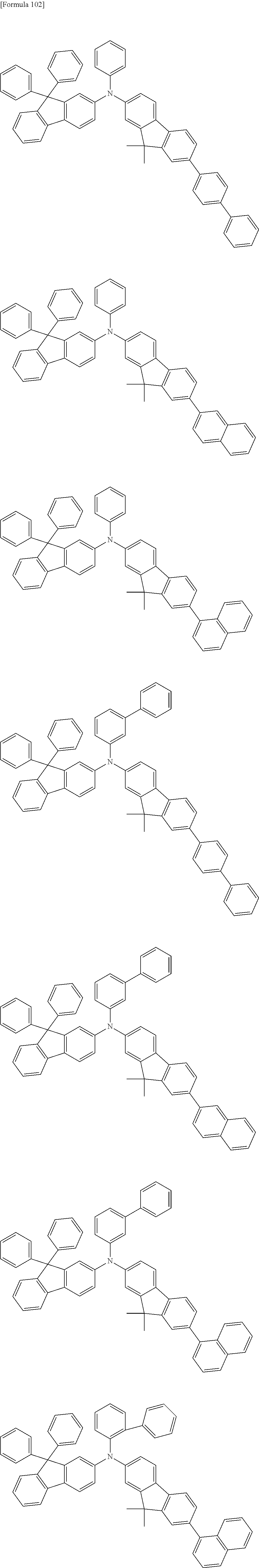

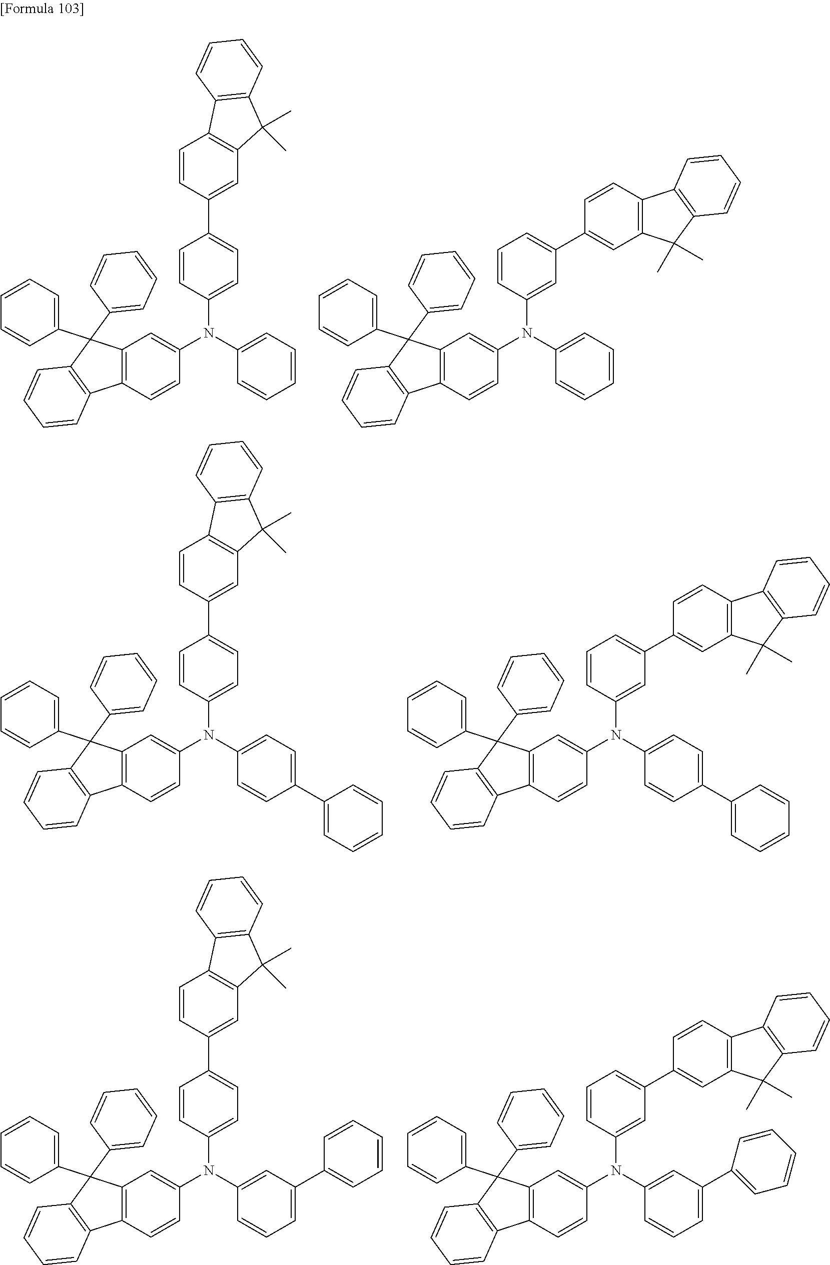

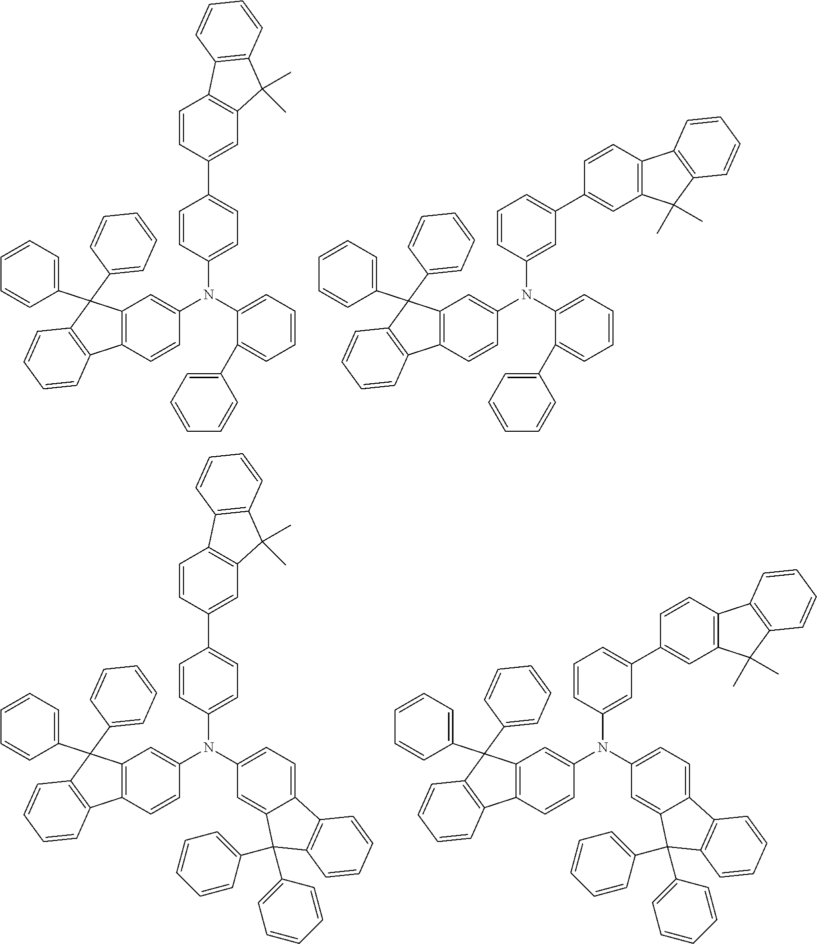

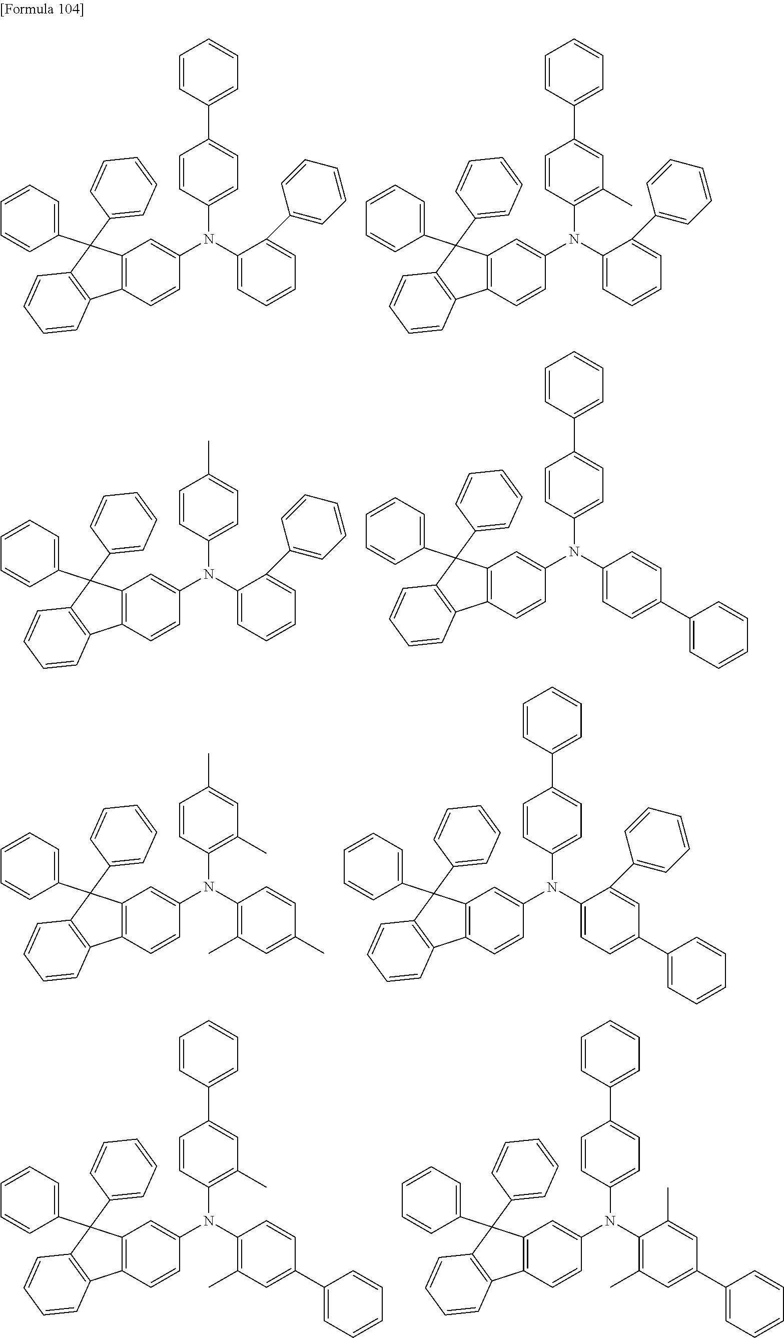

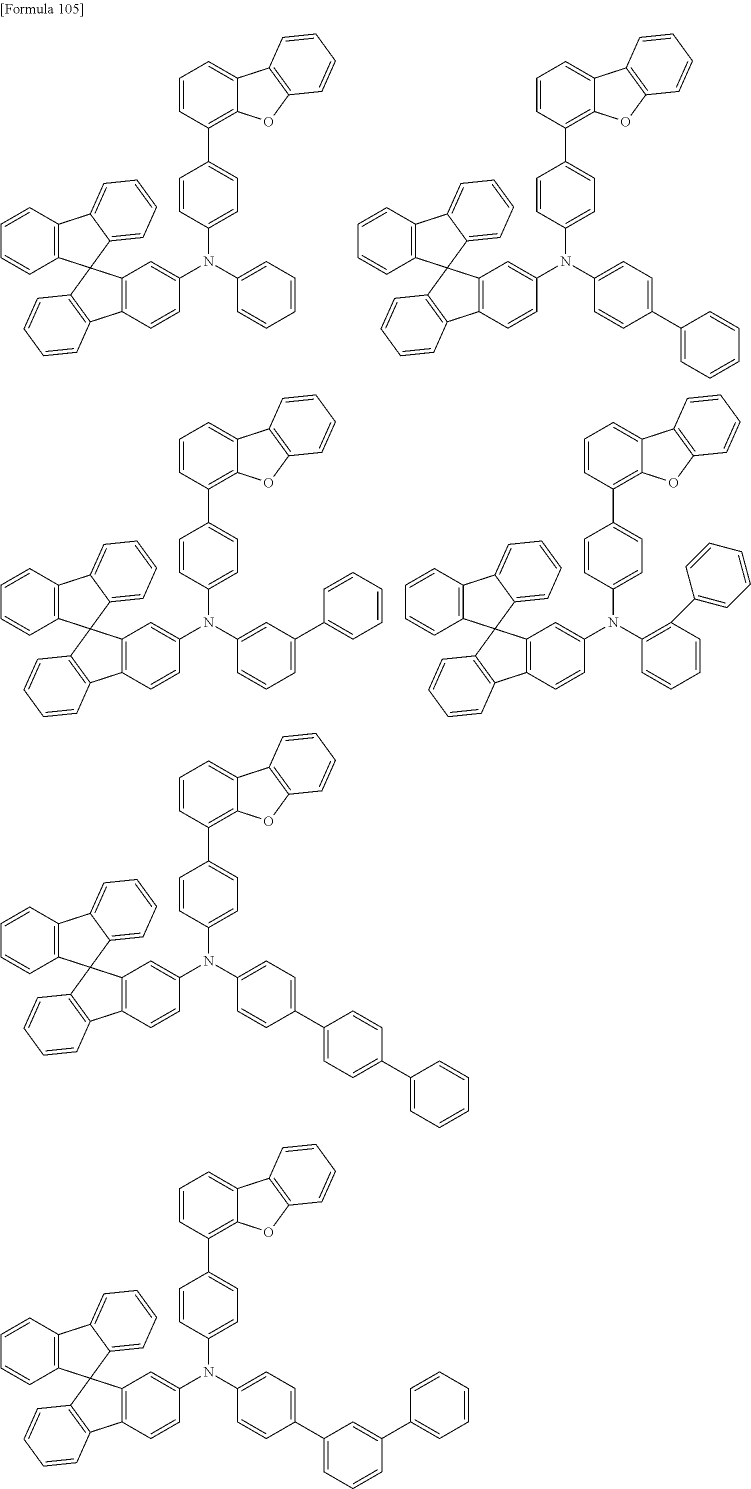

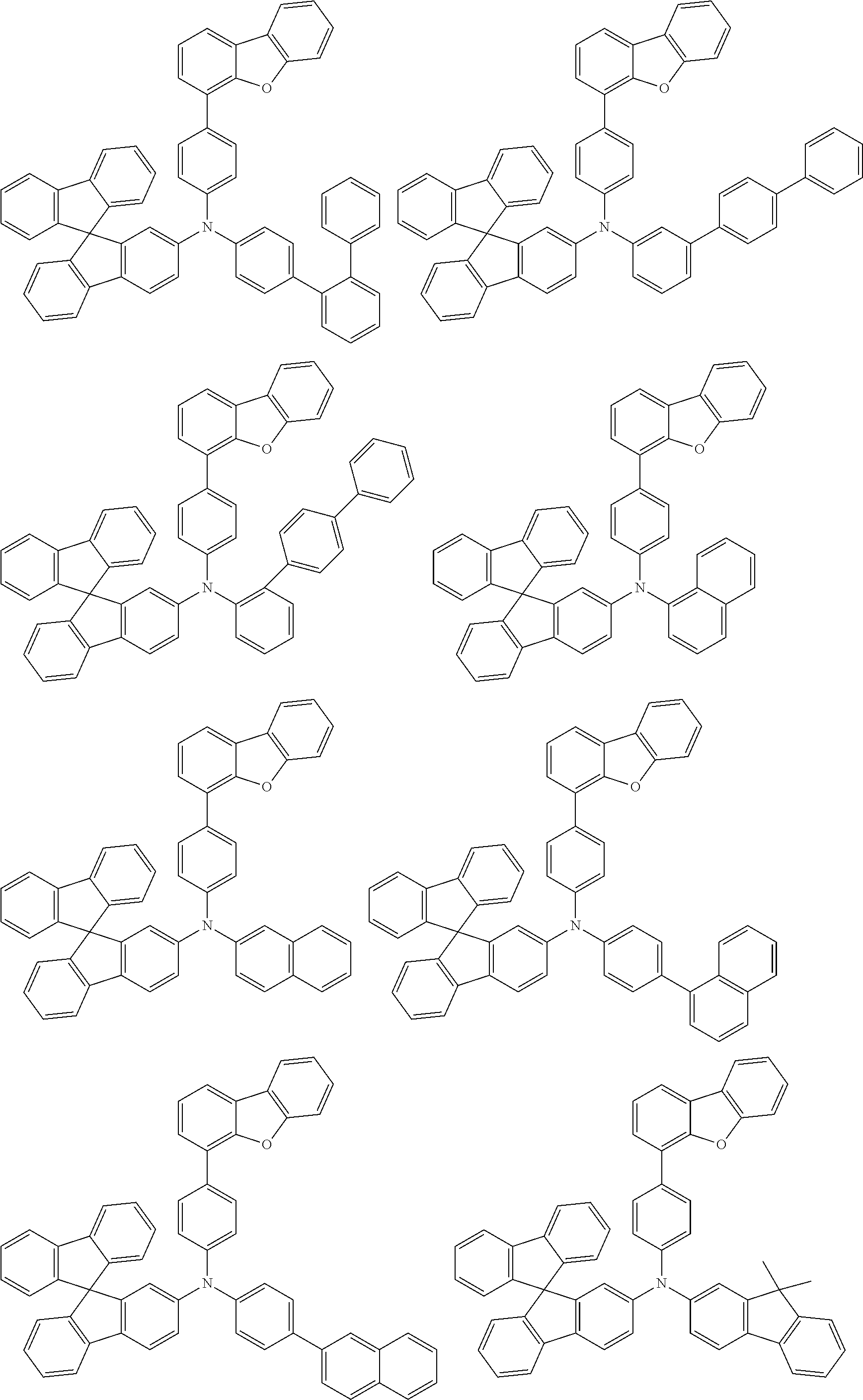

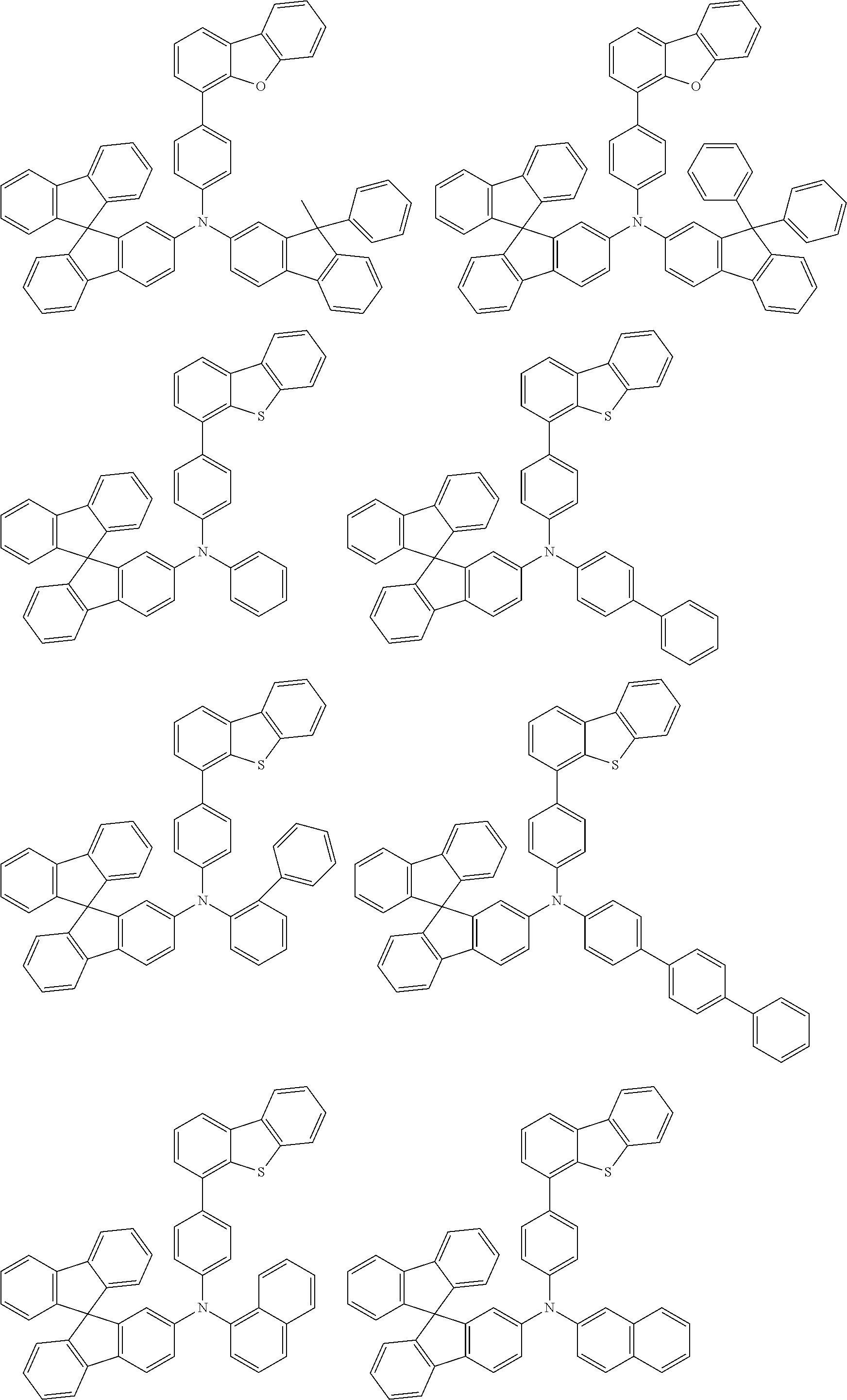

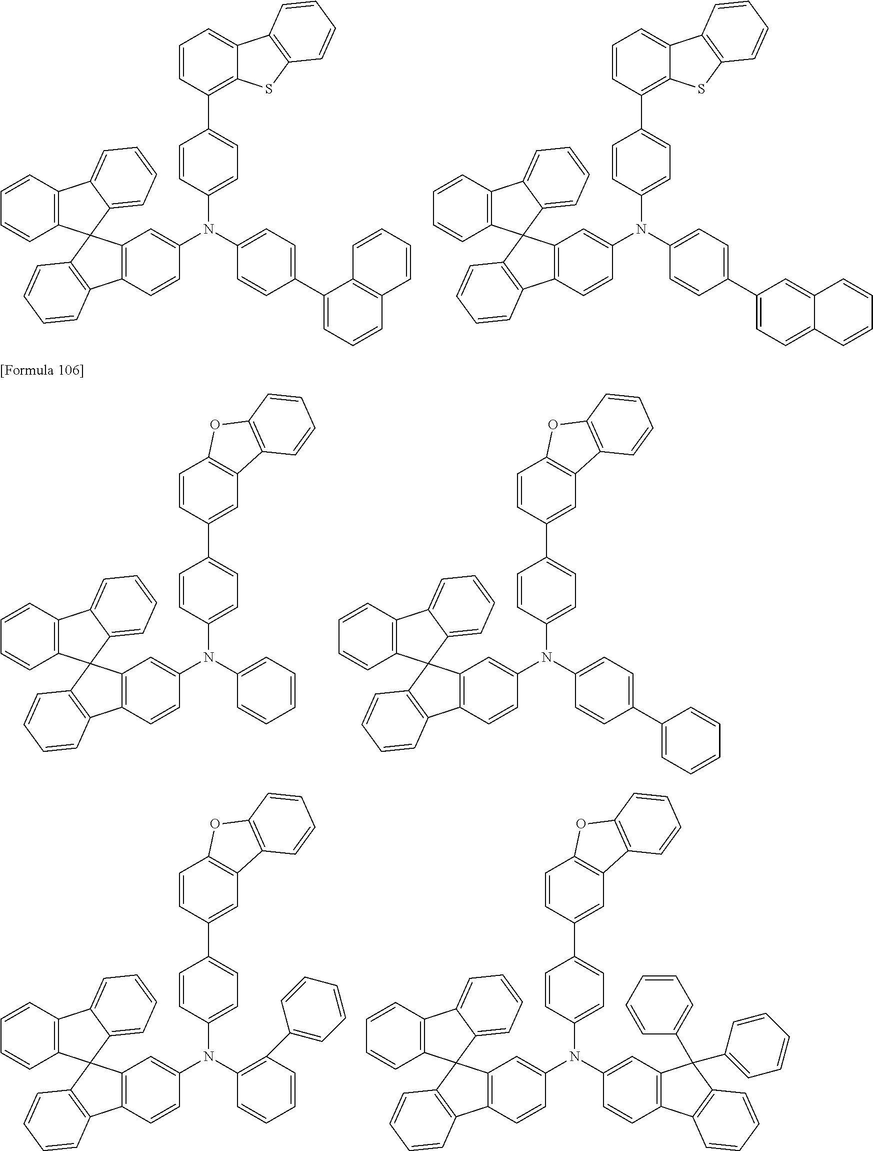

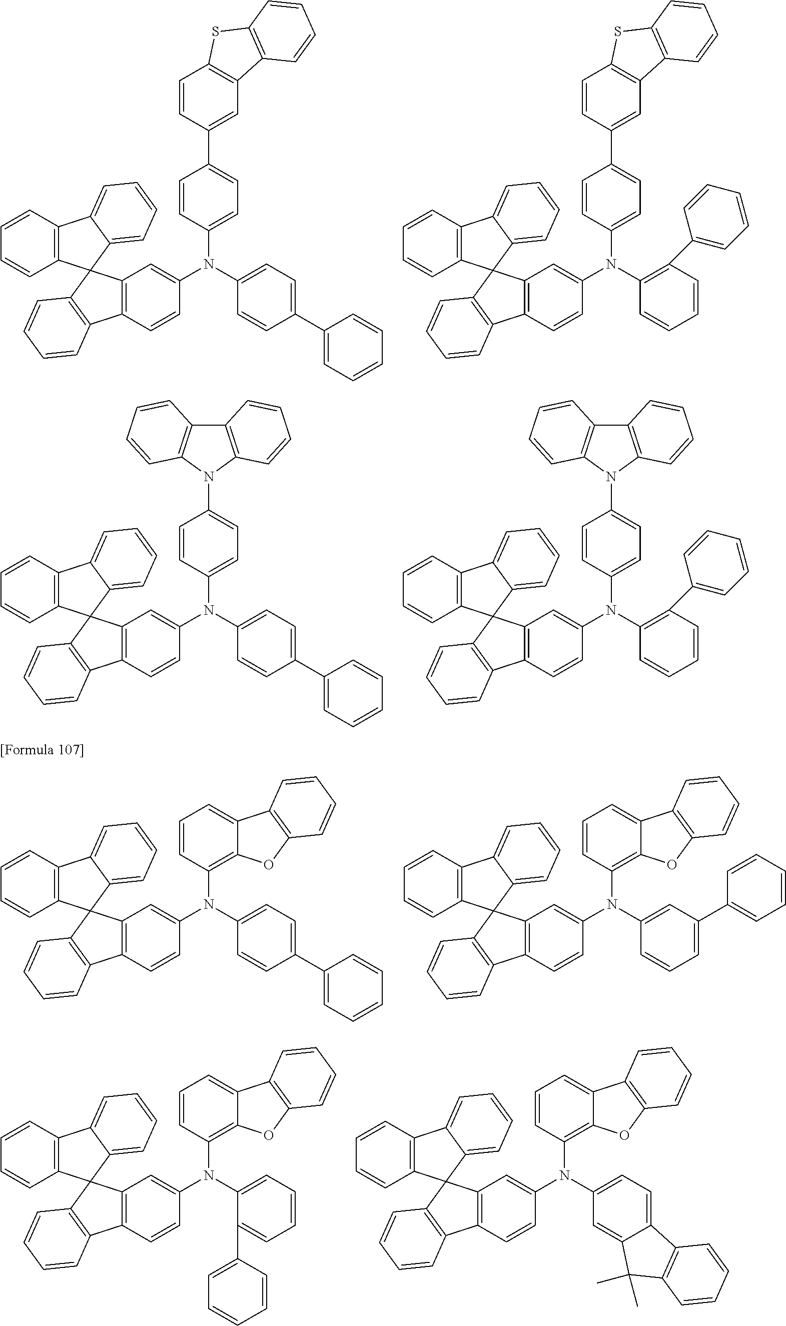

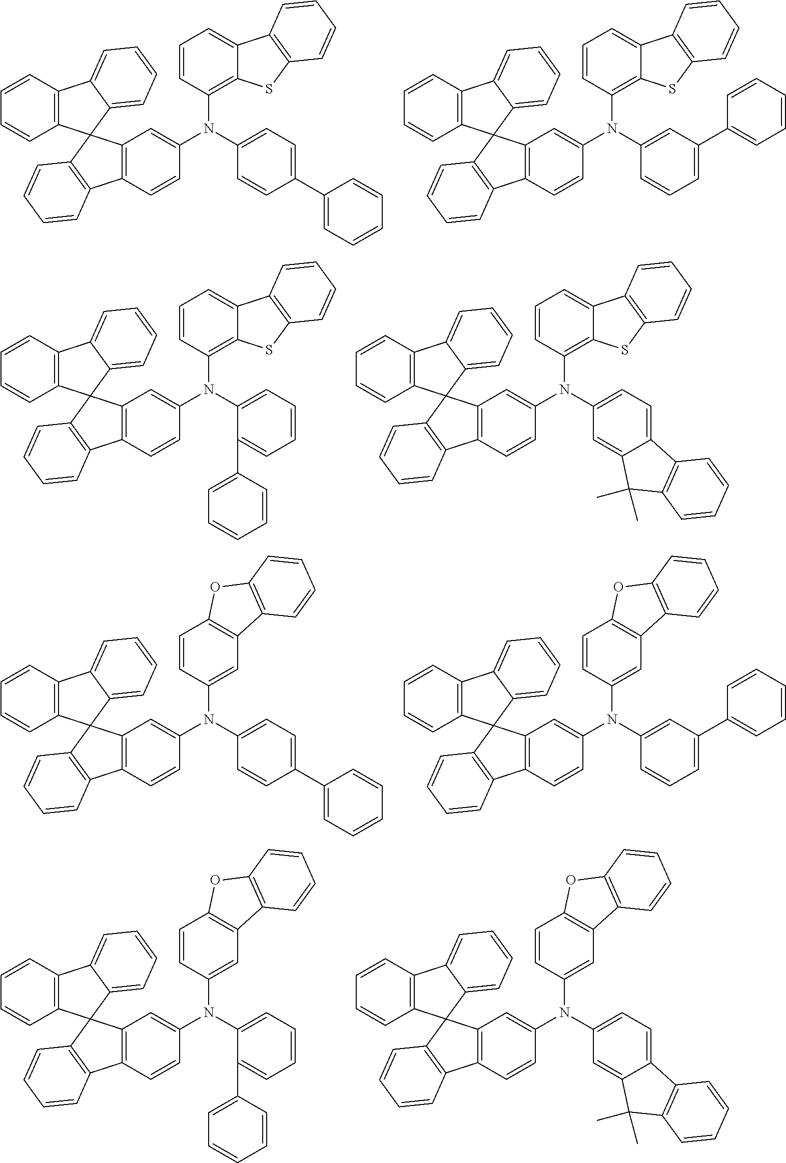

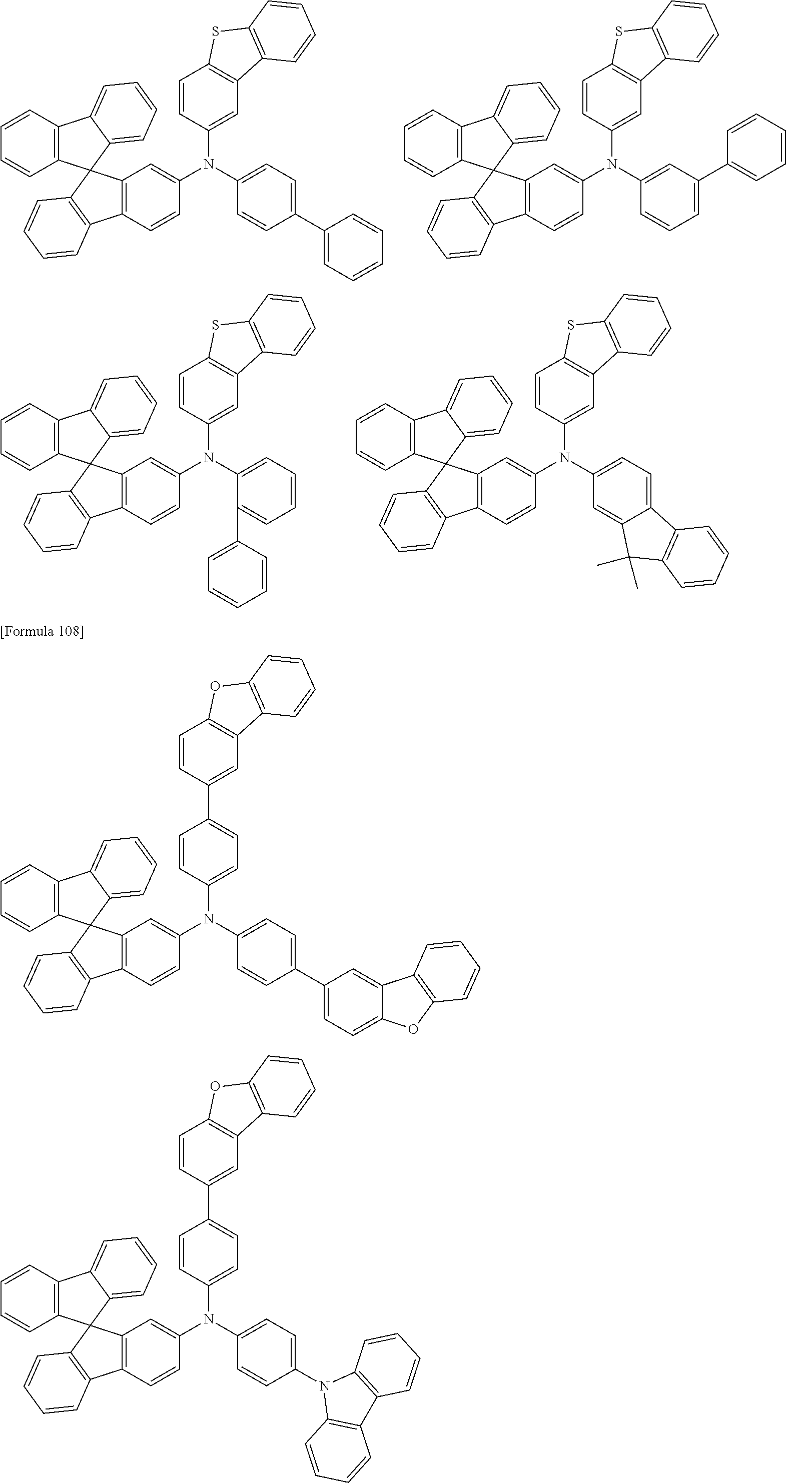

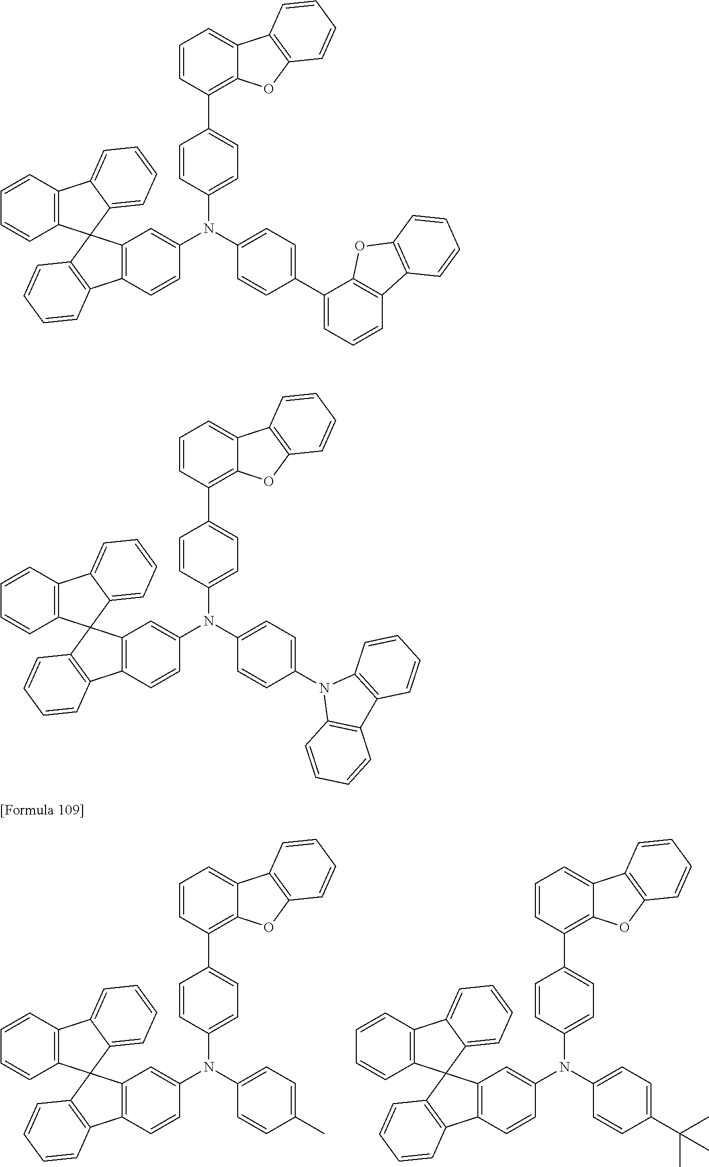 [SMILES: c1ccc2c(c1)-c1ccccc1C21c2ccccc2-c2ccc(N(c3ccc(-c4cccc5c4oc4ccccc45)cc3)c3ccc(-c4cccc5c4oc4ccccc45)cc3)cc21 ; c1ccc2c(c1)-c1ccccc1C21c2ccccc2-c2ccc(N(c3ccc(-c4cccc5c4oc4ccccc45)cc3)c3ccc(-n4c5ccccc5c5ccccc54)cc3)cc21 ; Cc1ccc(N(c2ccc(-c3cccc4c3oc3ccccc34)cc2)c2ccc3c(c2)C2(c4ccccc4-c4ccccc42)c2ccccc2-3)cc1 ; CC(C)(C)c1ccc(N(c2ccc(-c3cccc4c3oc3ccccc34)cc2)c2ccc3c(c2)C2(c4ccccc4-c4ccccc42)c2ccccc2-3)cc1]

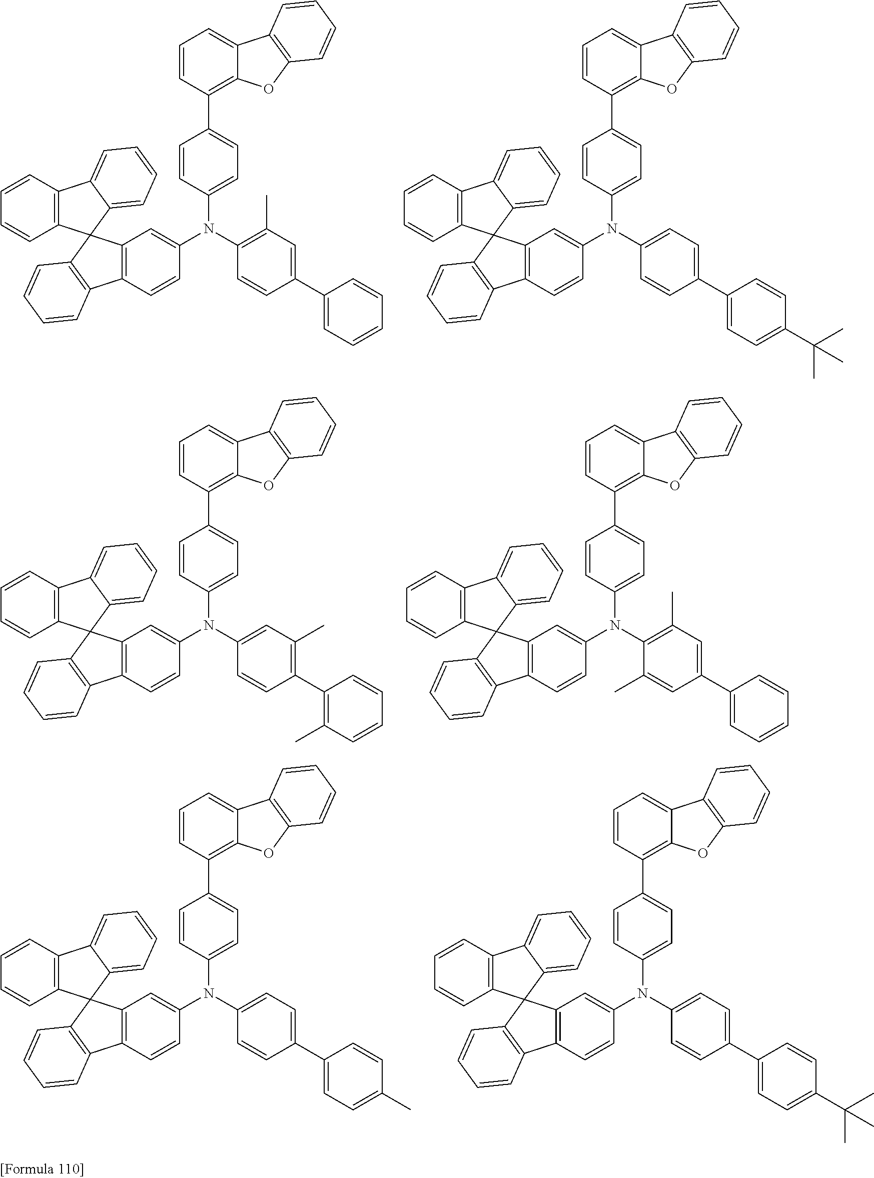

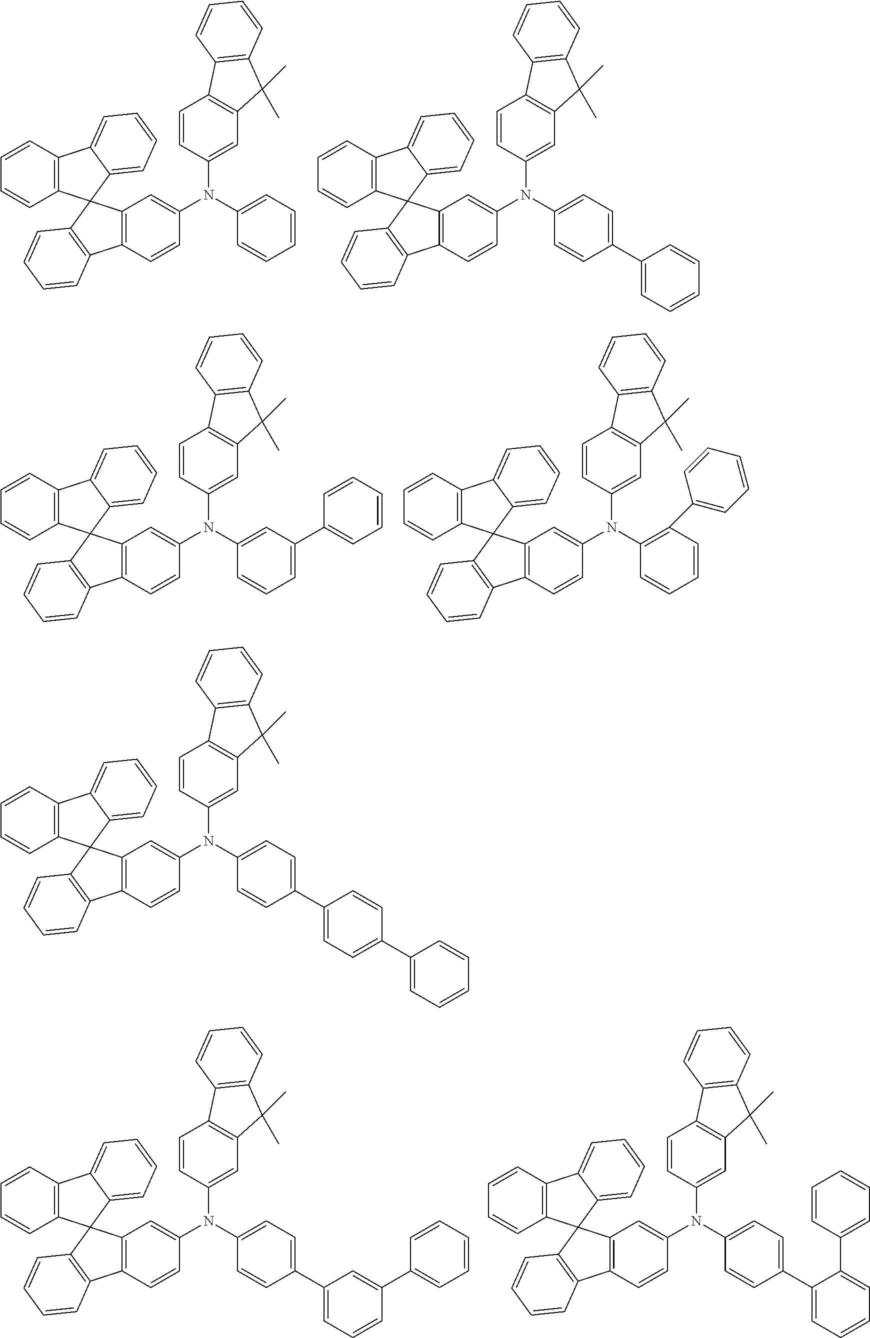

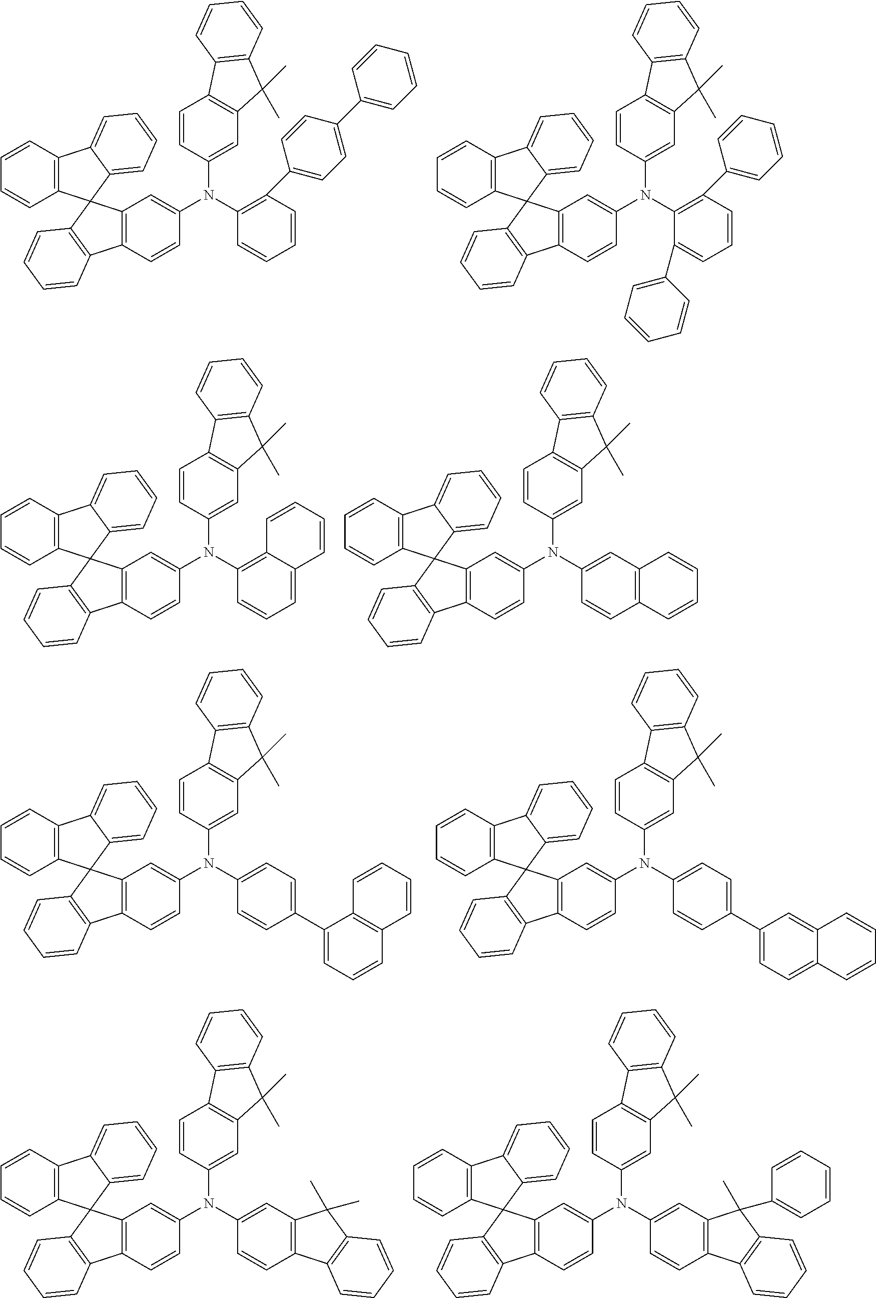

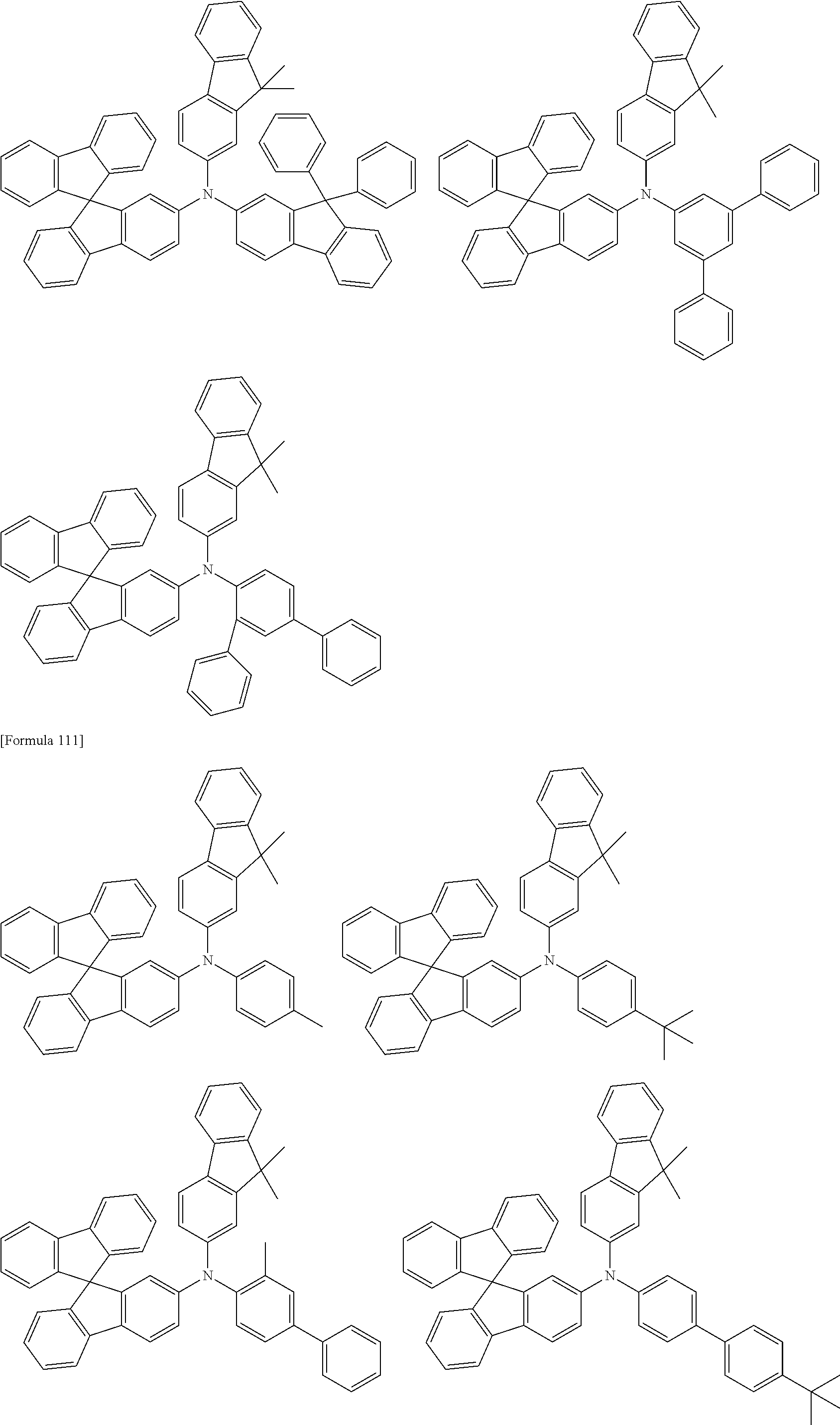

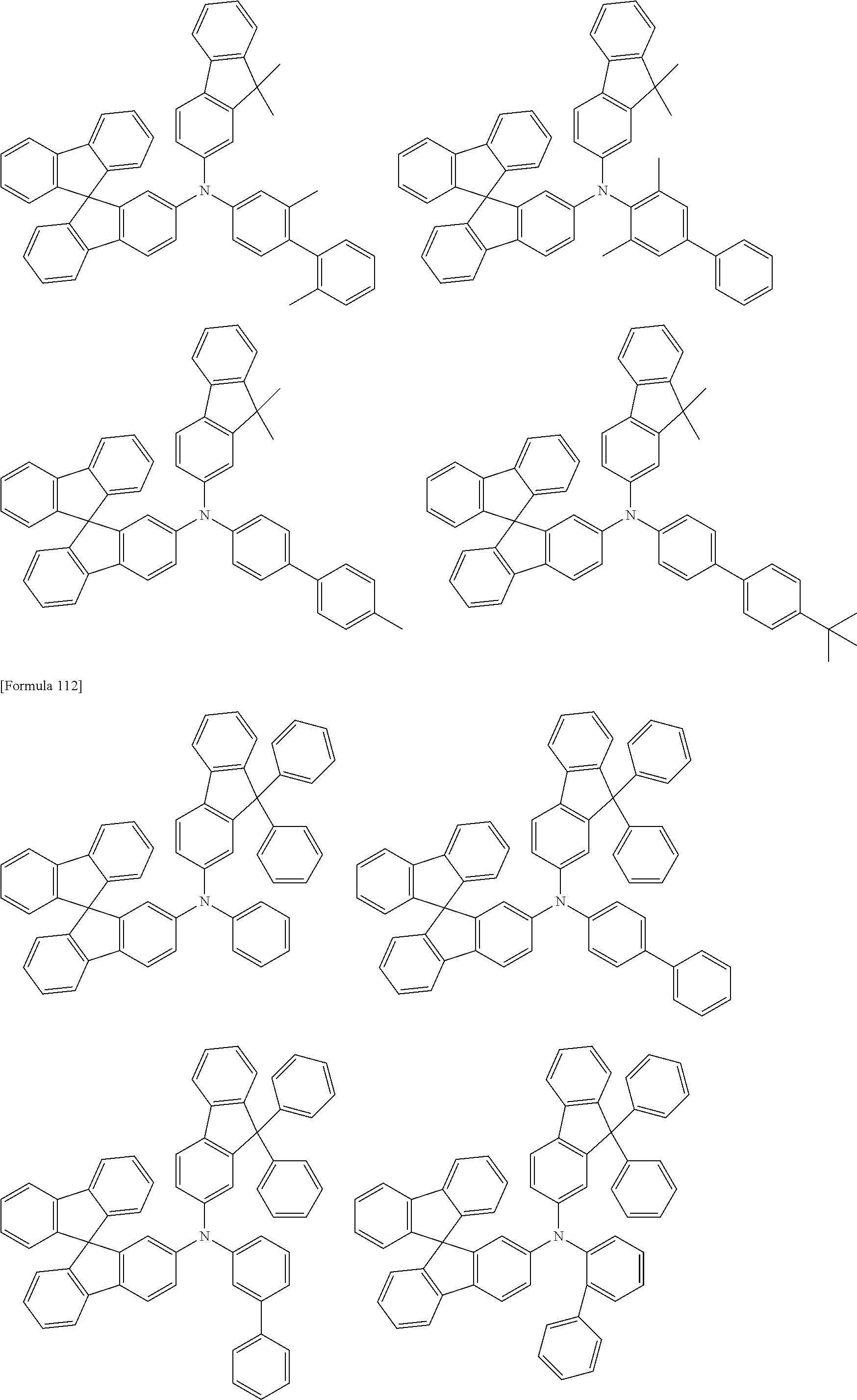

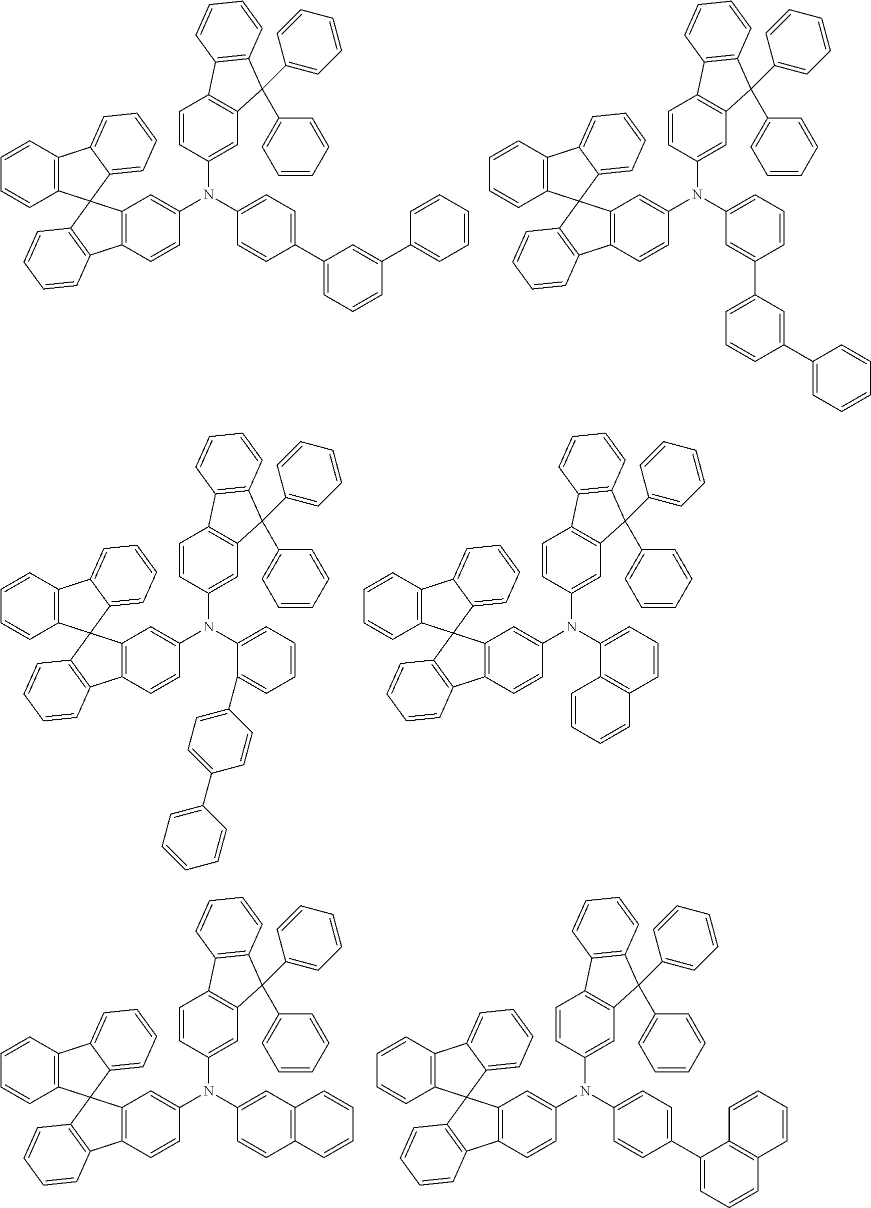

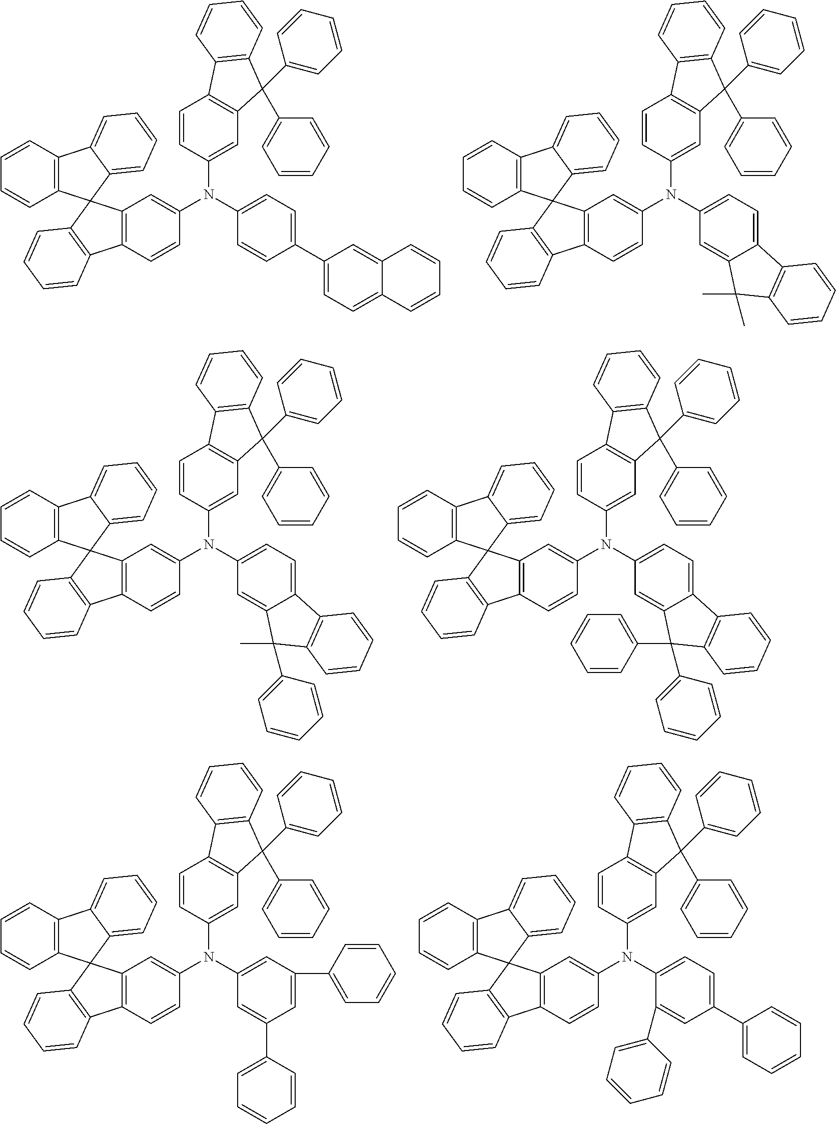

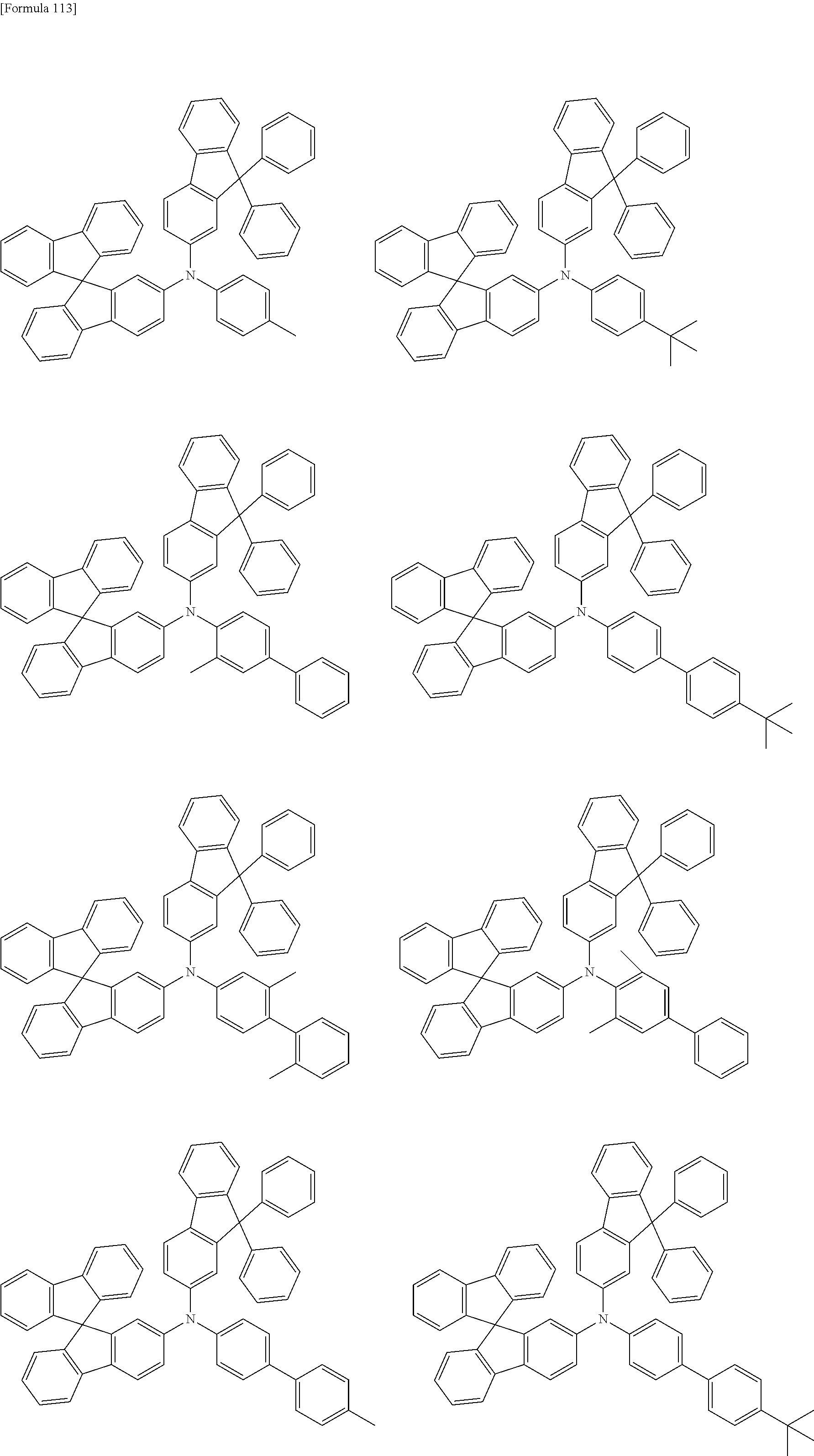

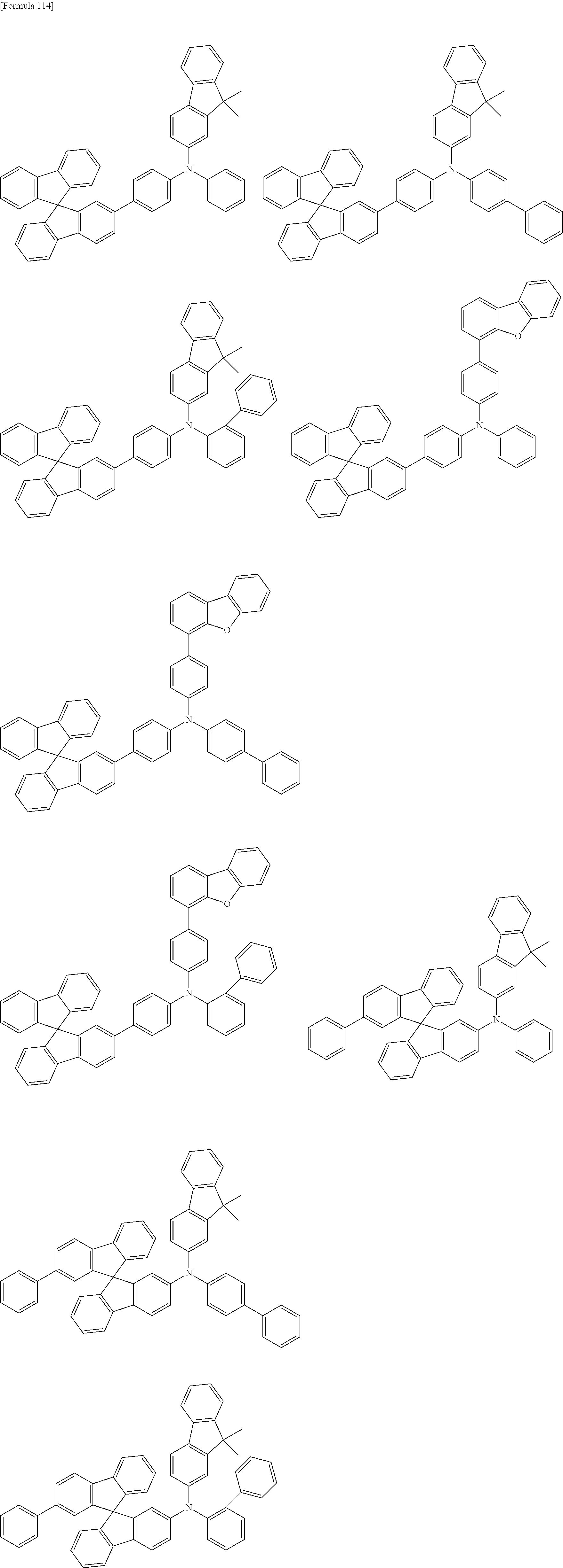

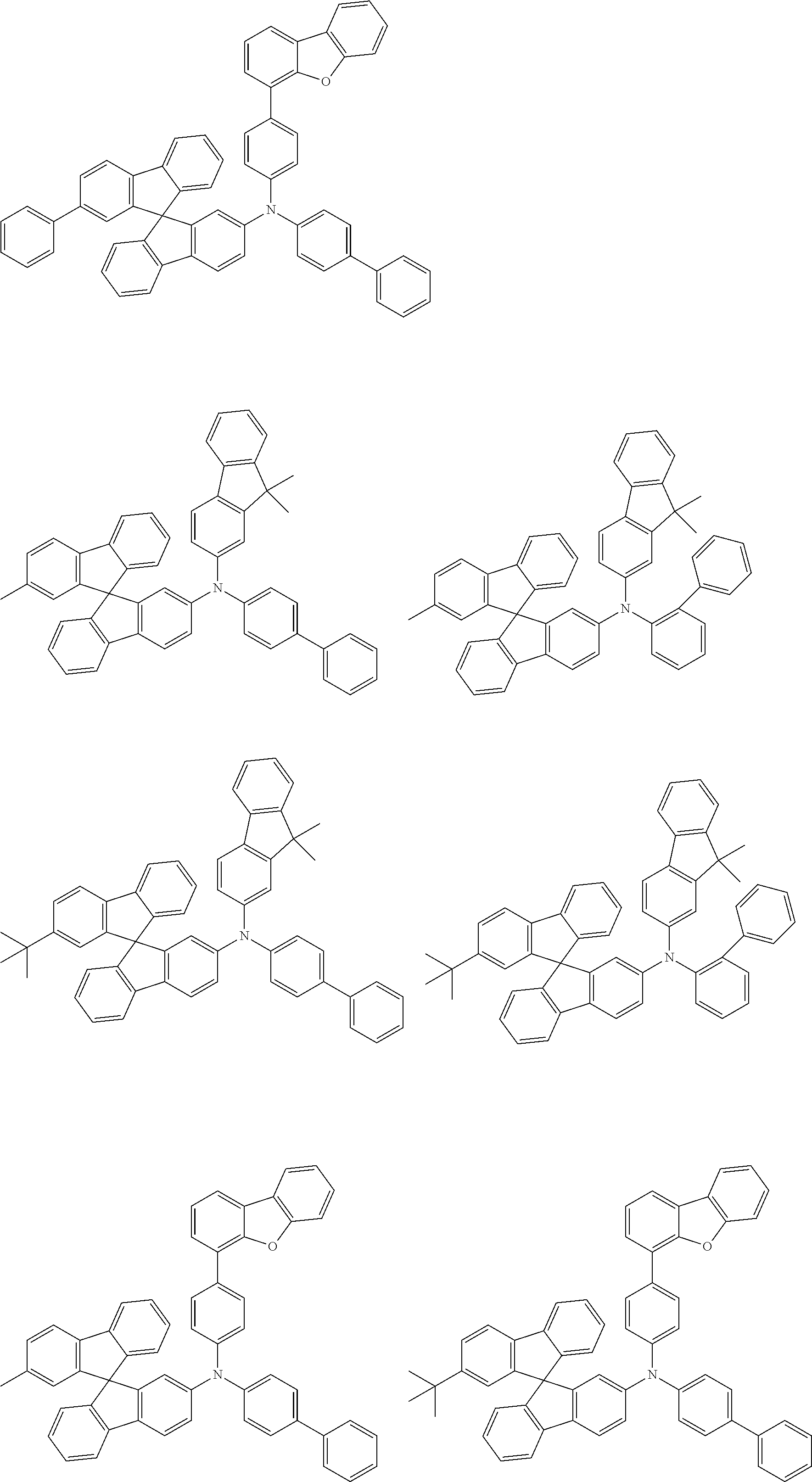

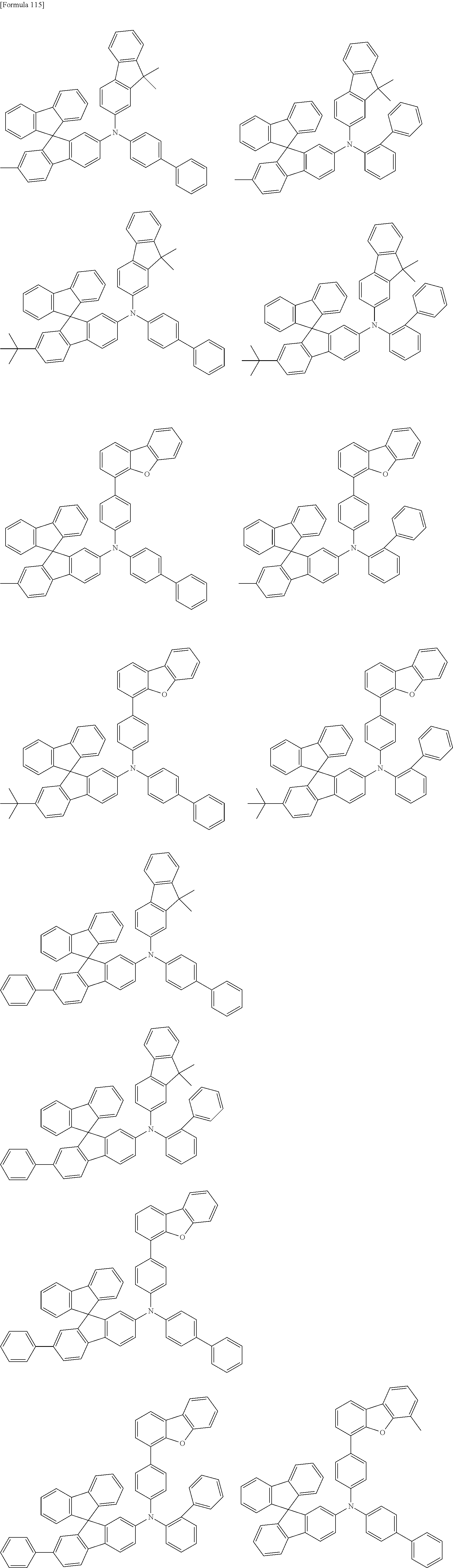

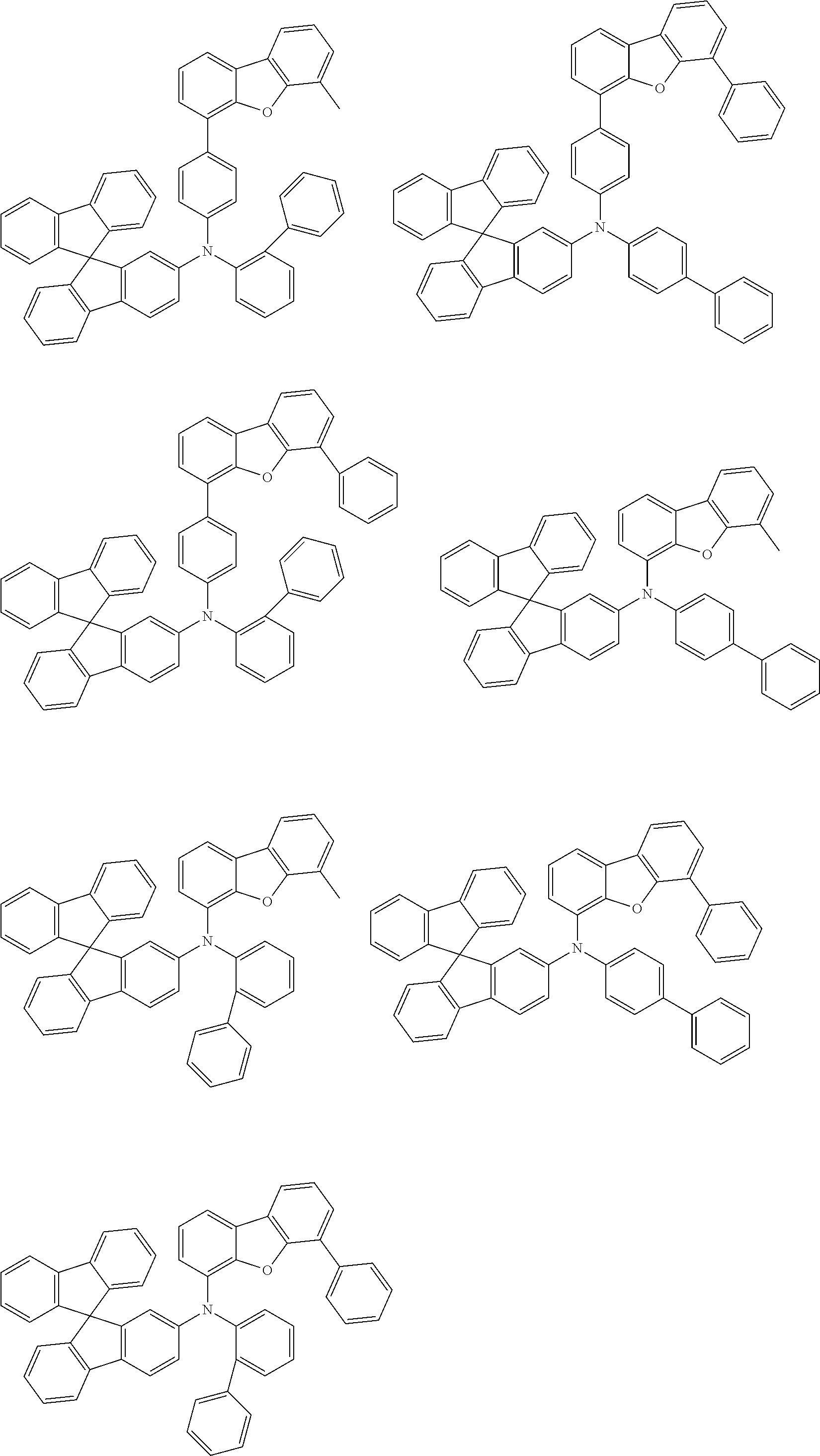

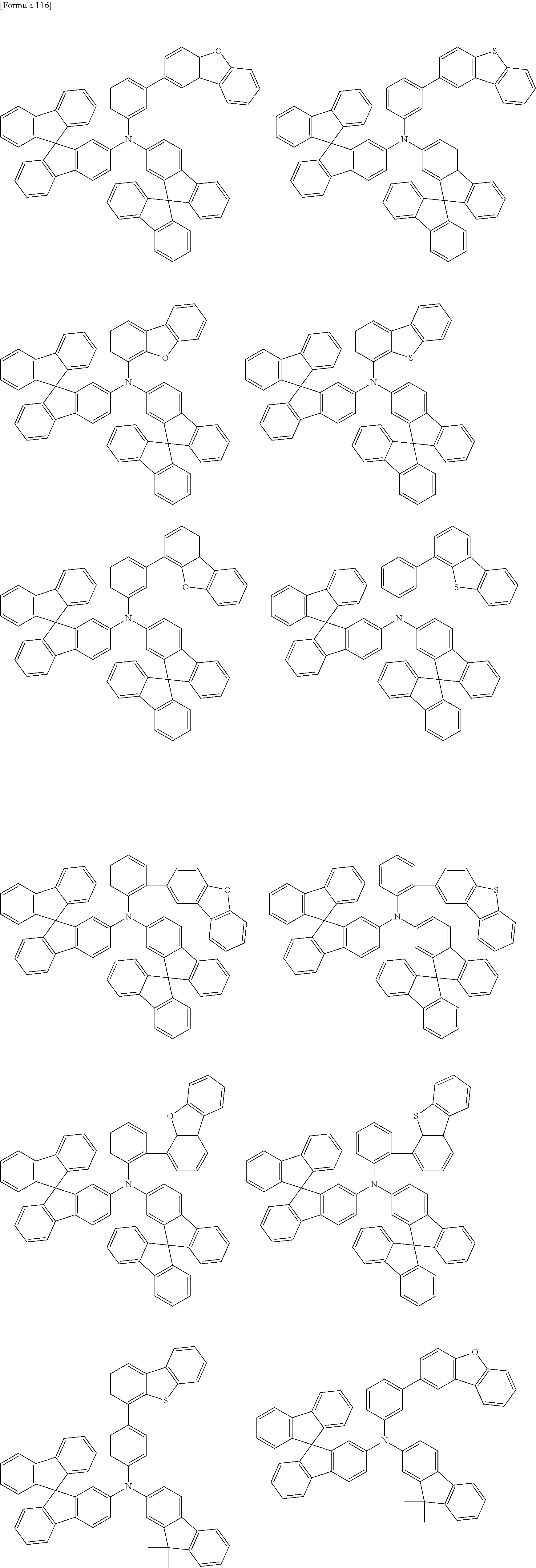

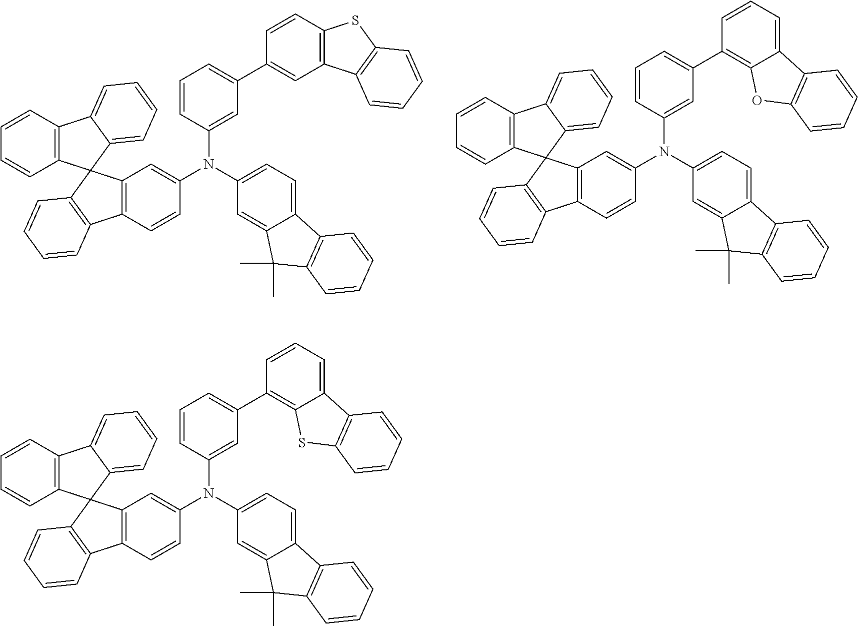 [SMILES: CC1(C)c2ccccc2-c2ccc(N(c3cccc(-c4ccc5sc6ccccc6c5c4)c3)c3ccc4c(c3)C3(c5ccccc5-c5ccccc53)c3ccccc3-4)cc21 ; CC1(C)c2ccccc2-c2ccc(N(c3cccc(-c4cccc5c4oc4ccccc45)c3)c3ccc4c(c3)C3(c5ccccc5-c5ccccc53)c3ccccc3-4)cc21 ; CC1(C)c2ccccc2-c2ccc(N(c3cccc(-c4cccc5c4sc4ccccc45)c3)c3ccc4c(c3)C3(c5ccccc5-c5ccccc53)c3ccccc3-4)cc21]

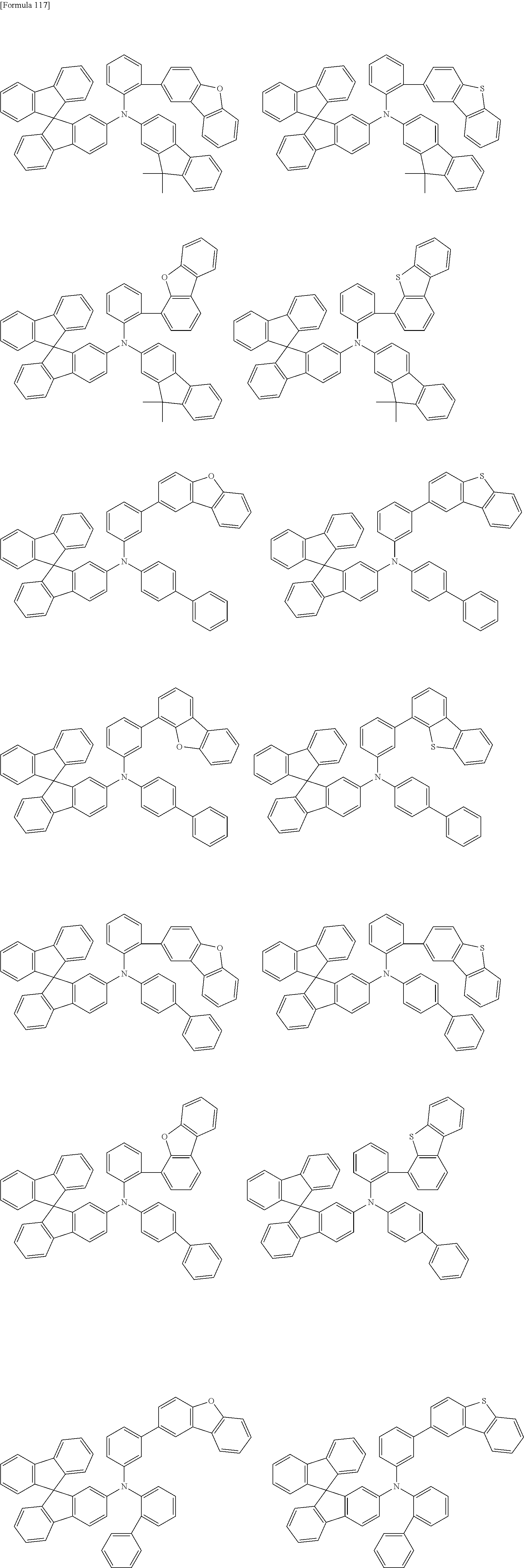

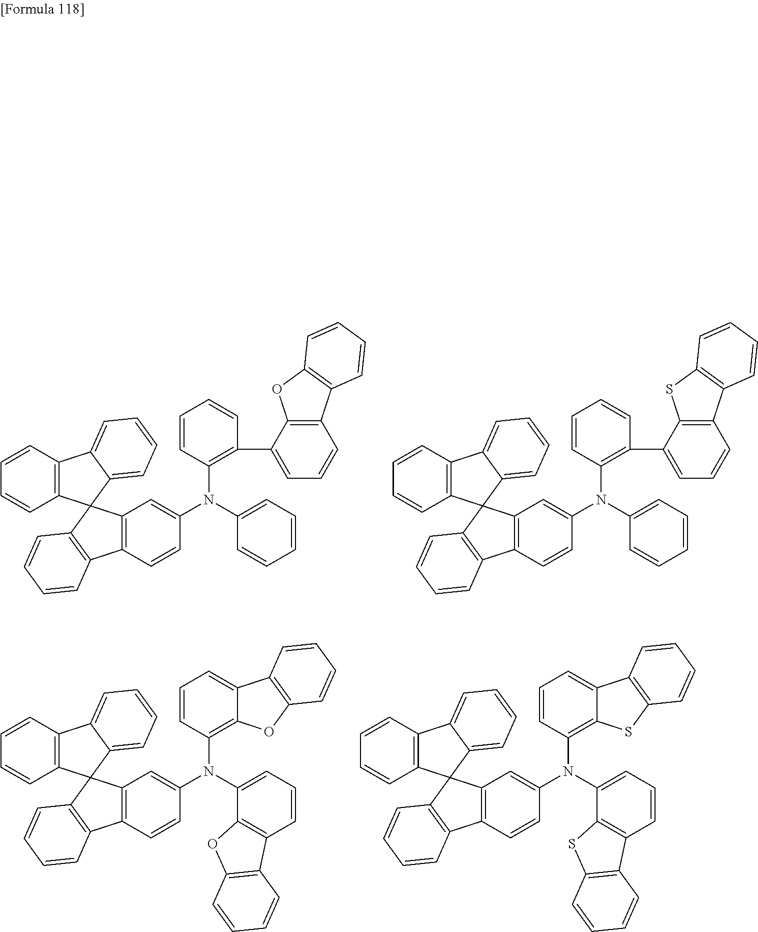 [SMILES: c1ccc(N(c2ccc3c(c2)C2(c4ccccc4-c4ccccc42)c2ccccc2-3)c2ccccc2-c2cccc3c2oc2ccccc23)cc1 ; c1ccc(N(c2ccc3c(c2)C2(c4ccccc4-c4ccccc42)c2ccccc2-3)c2ccccc2-c2cccc3c2sc2ccccc23)cc1 ; c1ccc2c(c1)-c1ccccc1C21c2ccccc2-c2ccc(N(c3cccc4c3oc3ccccc34)c3cccc4c3oc3ccccc34)cc21 ; c1ccc2c(c1)-c1ccccc1C21c2ccccc2-c2ccc(N(c3cccc4c3sc3ccccc34)c3cccc4c3sc3ccccc34)cc21]

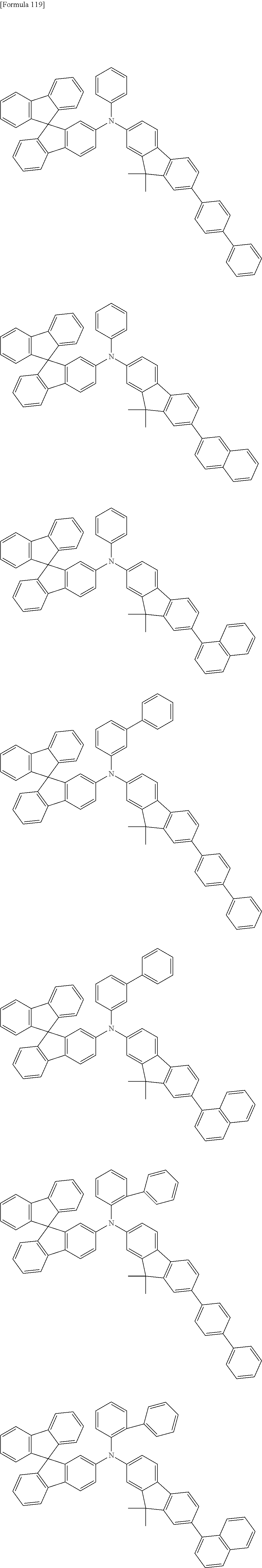

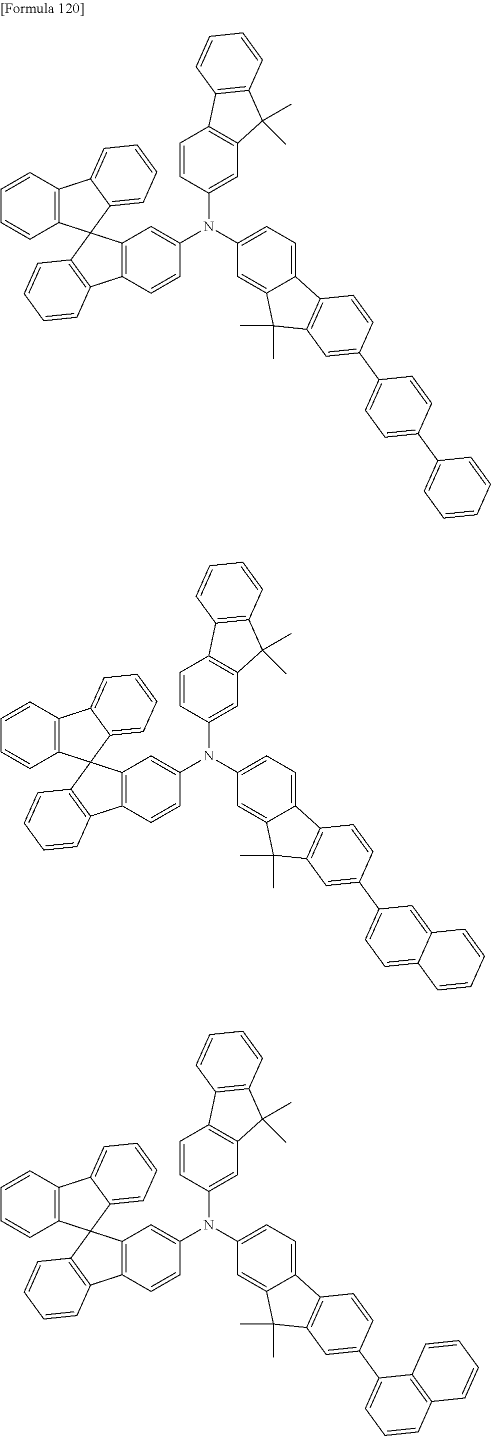 [SMILES: CC1(C)c2ccccc2-c2ccc(N(c3ccc4c(c3)C(C)(C)c3cc(-c5ccc(-c6ccccc6)cc5)ccc3-4)c3ccc4c(c3)C3(c5ccccc5-c5ccccc53)c3ccccc3-4)cc21 ; CC1(C)c2ccccc2-c2ccc(N(c3ccc4c(c3)C(C)(C)c3cc(-c5ccc6ccccc6c5)ccc3-4)c3ccc4c(c3)C3(c5ccccc5-c5ccccc53)c3ccccc3-4)cc21 ; CC1(C)c2ccccc2-c2ccc(N(c3ccc4c(c3)C(C)(C)c3cc(-c5cccc6ccccc56)ccc3-4)c3ccc4c(c3)C3(c5ccccc5-c5ccccc53)c3ccccc3-4)cc21]

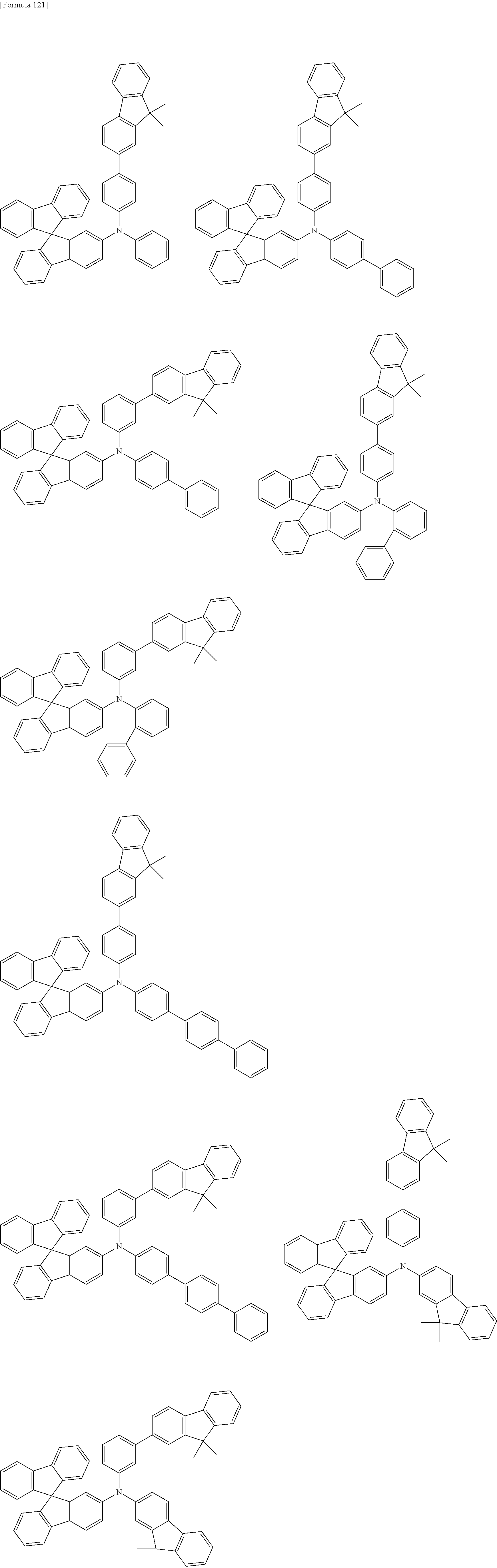

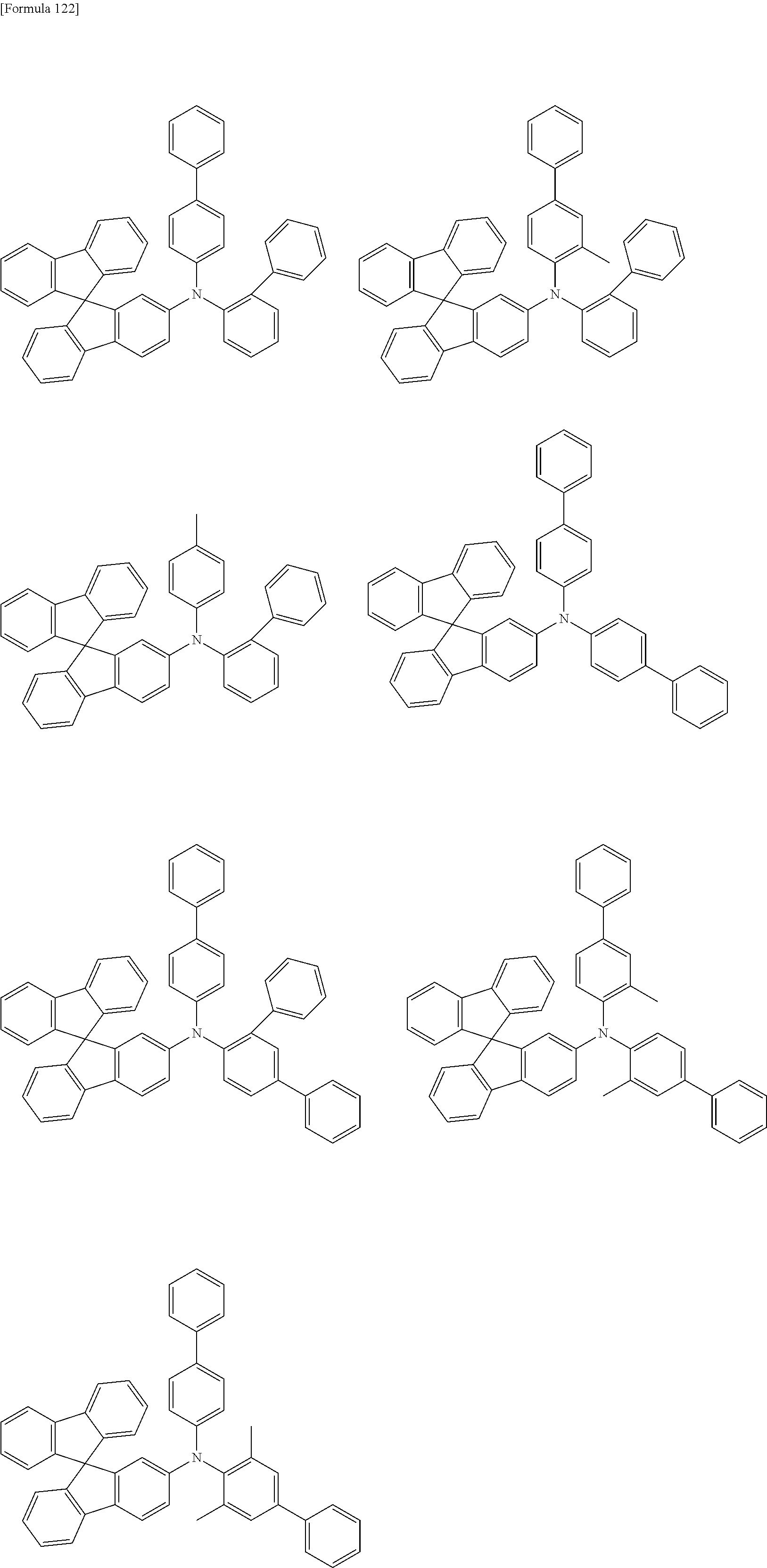

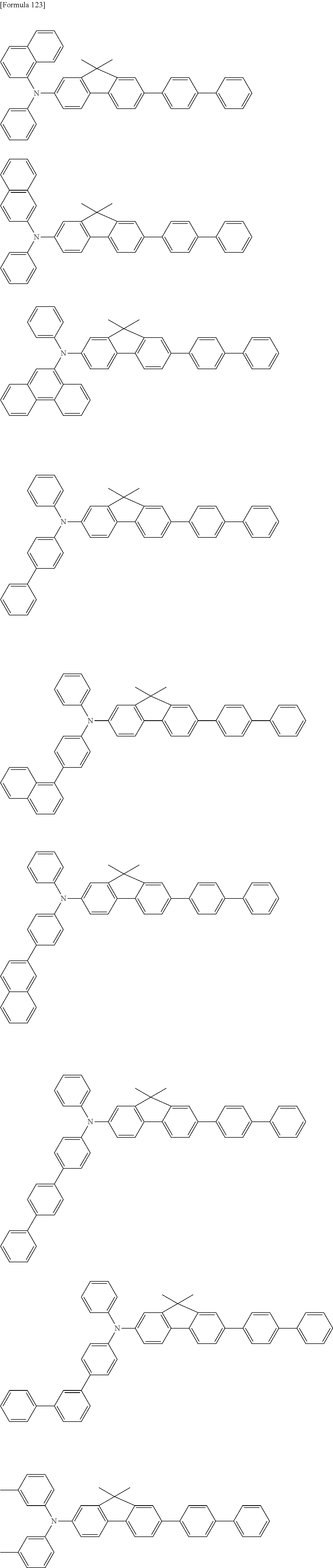

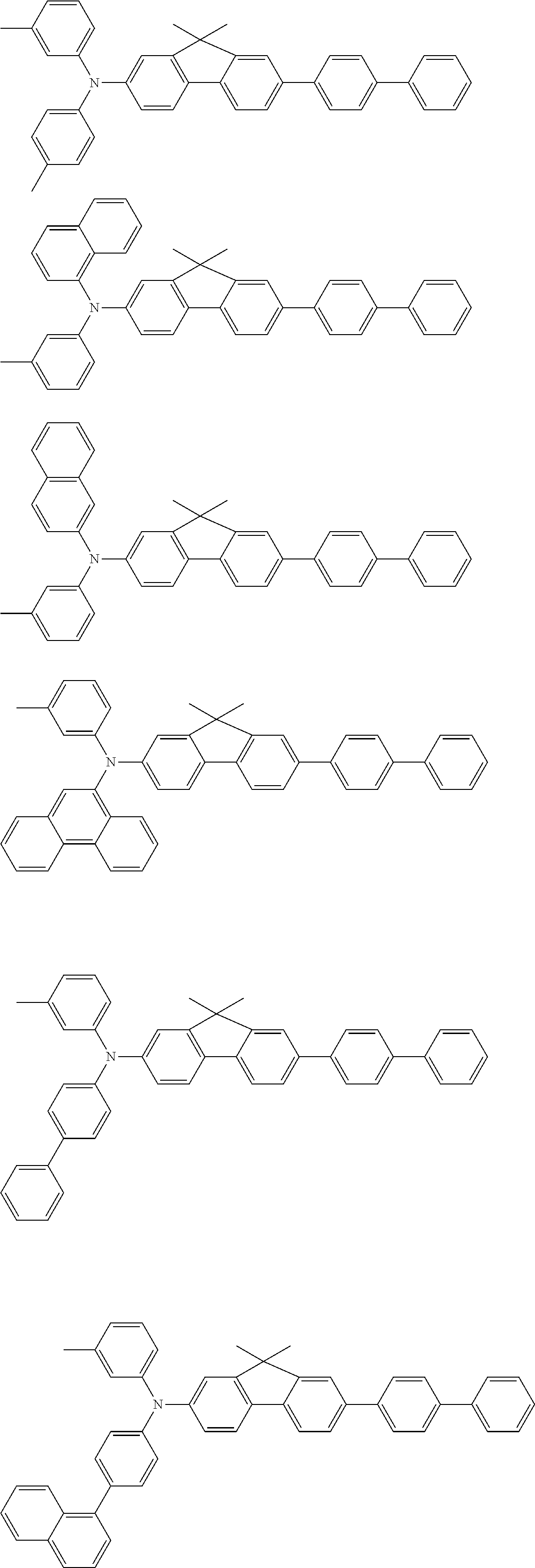

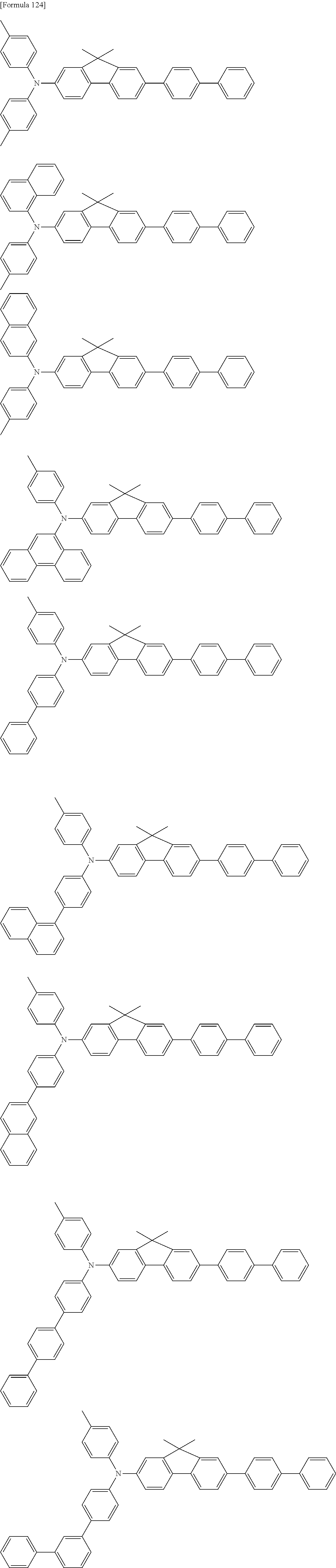

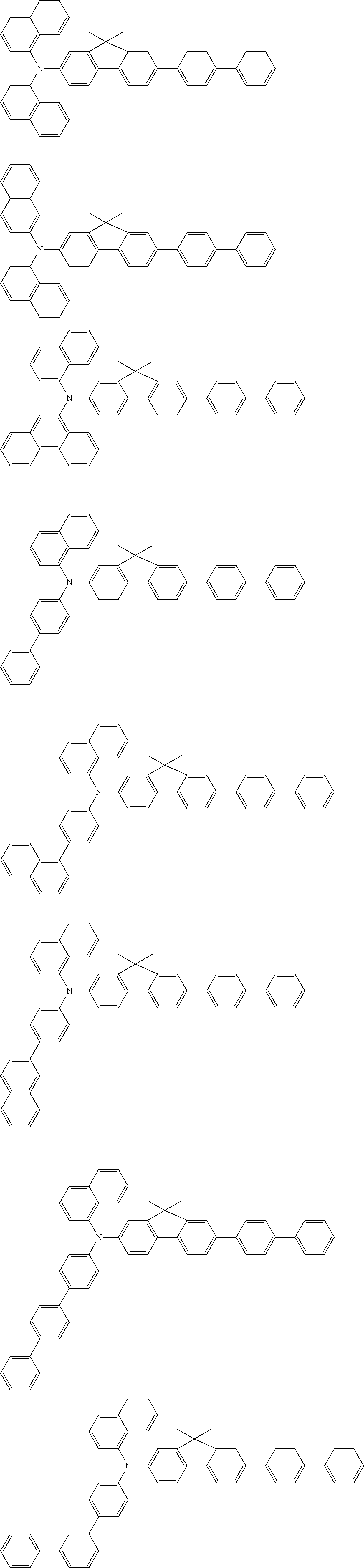

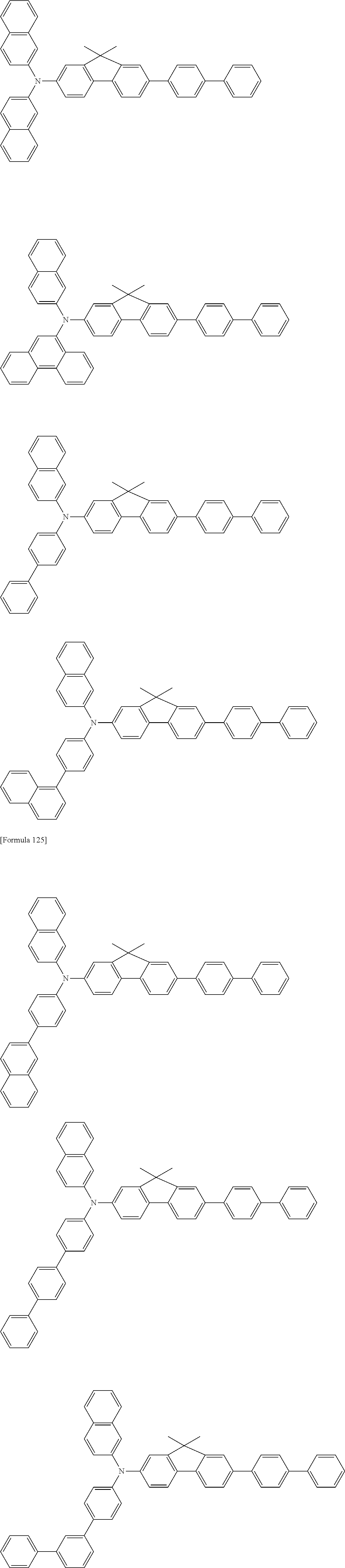

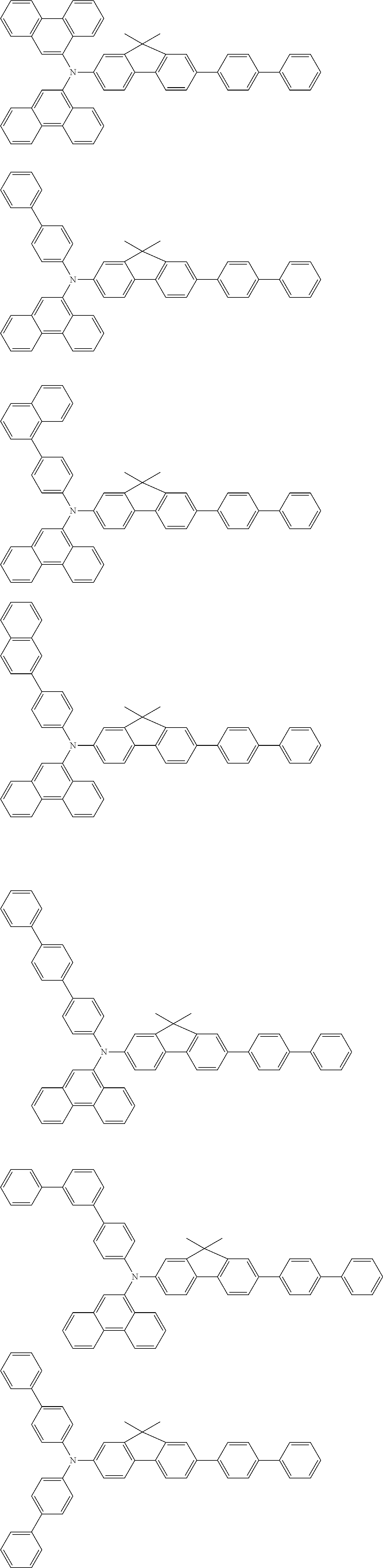

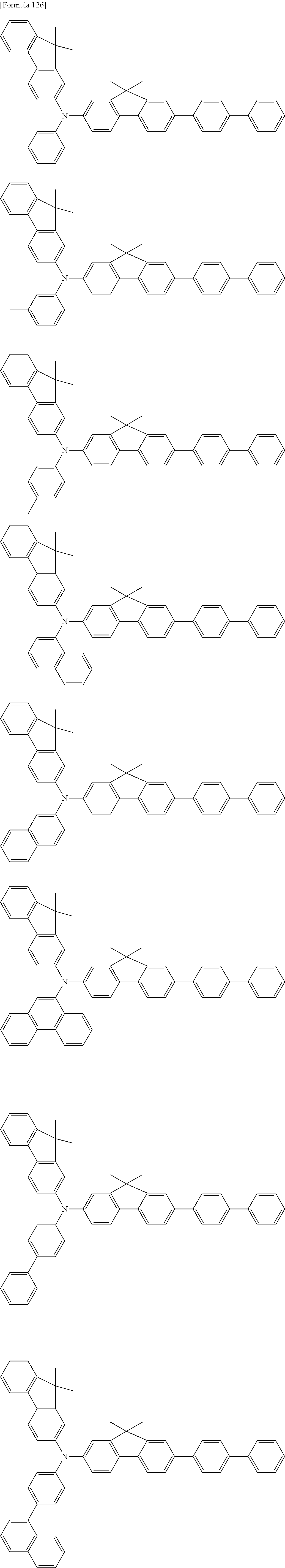

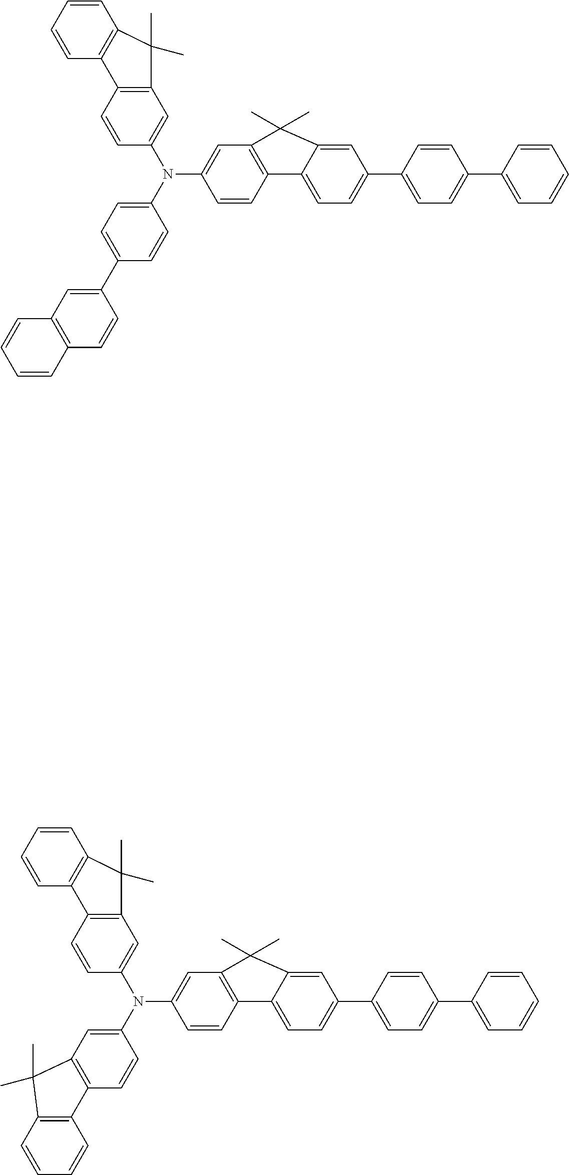 [SMILES: CC1(C)c2ccccc2-c2ccc(N(c3ccc(-c4ccc5ccccc5c4)cc3)c3ccc4c(c3)C(C)(C)c3cc(-c5ccc(-c6ccccc6)cc5)ccc3-4)cc21 ; CC1(C)c2ccccc2-c2ccc(N(c3ccc4c(c3)C(C)(C)c3ccccc3-4)c3ccc4c(c3)C(C)(C)c3cc(-c5ccc(-c6ccccc6)cc5)ccc3-4)cc21]

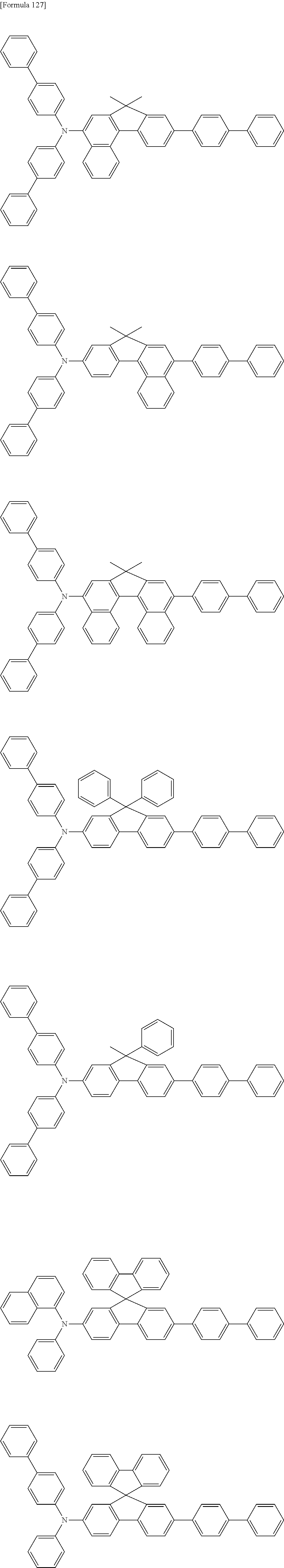

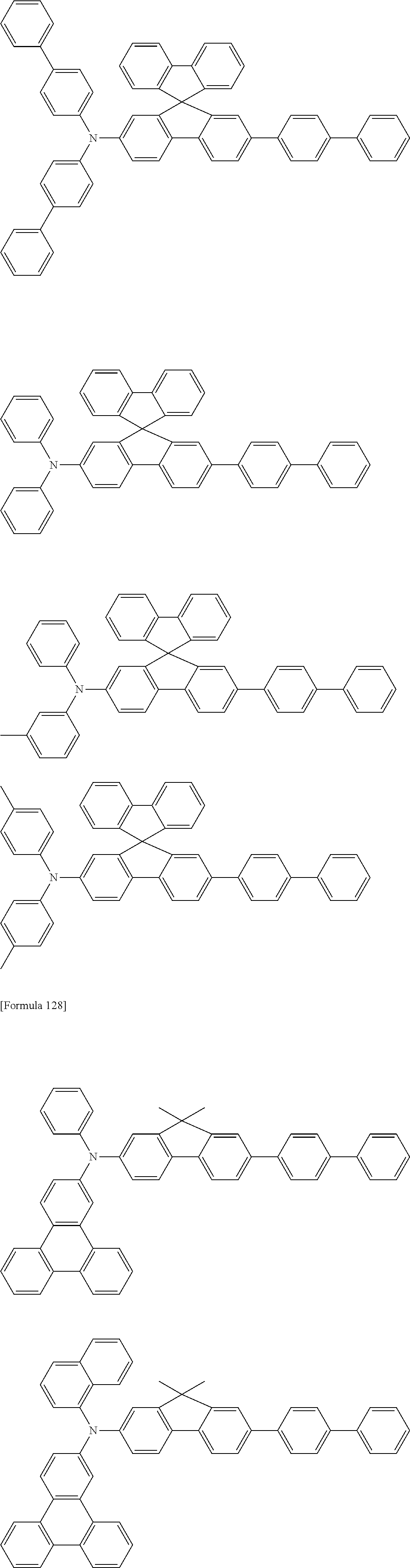

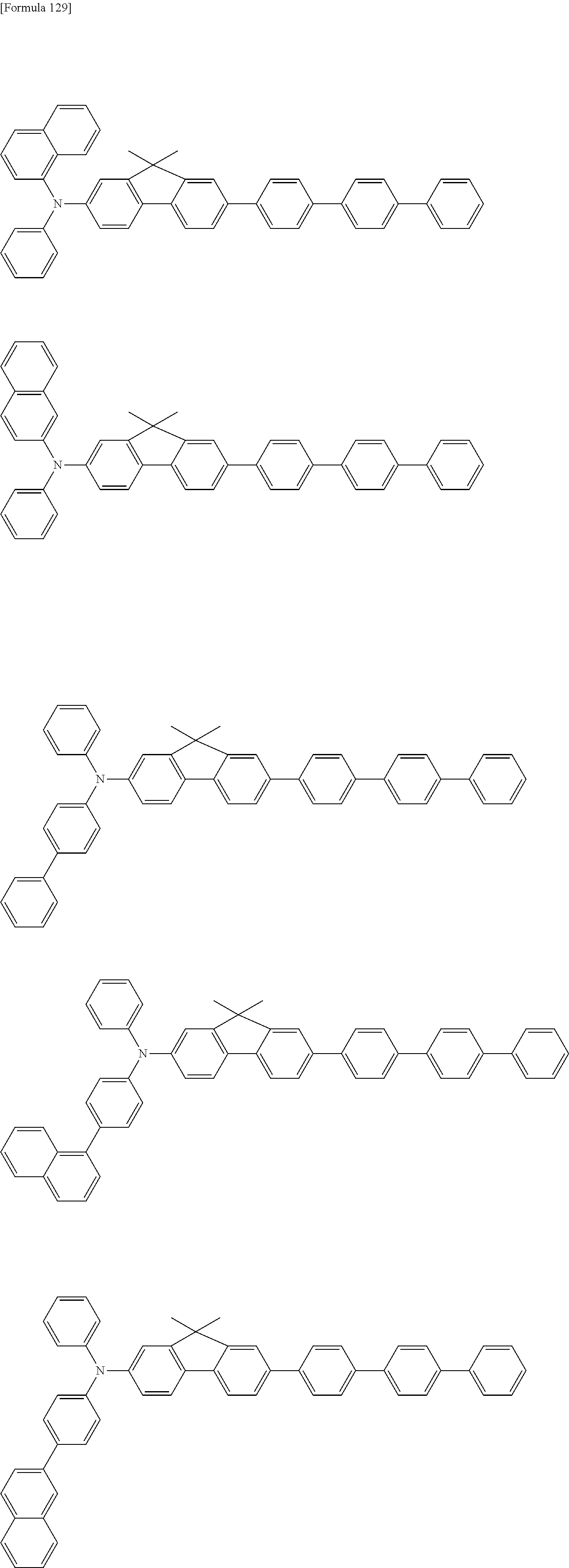 [SMILES: CC1(C)c2cc(-c3ccc(-c4ccc(-c5ccccc5)cc4)cc3)ccc2-c2ccc(N(c3ccccc3)c3cccc4ccccc34)cc21 ; CC1(C)c2cc(-c3ccc(-c4ccc(-c5ccccc5)cc4)cc3)ccc2-c2ccc(N(c3ccccc3)c3ccc4ccccc4c3)cc21 ; CC1(C)c2cc(-c3ccc(-c4ccc(-c5ccccc5)cc4)cc3)ccc2-c2ccc(N(c3ccccc3)c3ccc(-c4ccccc4)cc3)cc21 ; CC1(C)c2cc(-c3ccc(-c4ccc(-c5ccccc5)cc4)cc3)ccc2-c2ccc(N(c3ccccc3)c3ccc(-c4cccc5ccccc45)cc3)cc21 ; CC1(C)c2cc(-c3ccc(-c4ccc(-c5ccccc5)cc4)cc3)ccc2-c2ccc(N(c3ccccc3)c3ccc(-c4ccc5ccccc5c4)cc3)cc21]

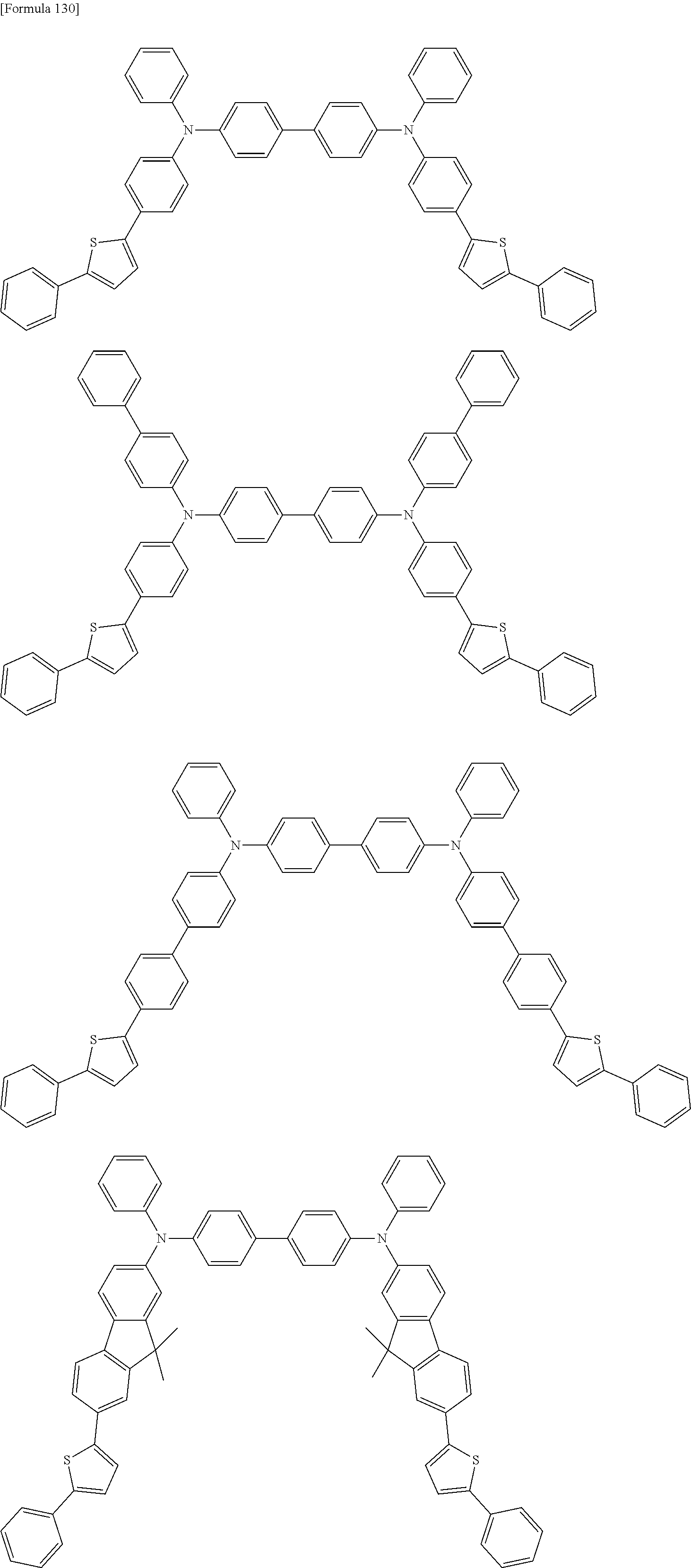

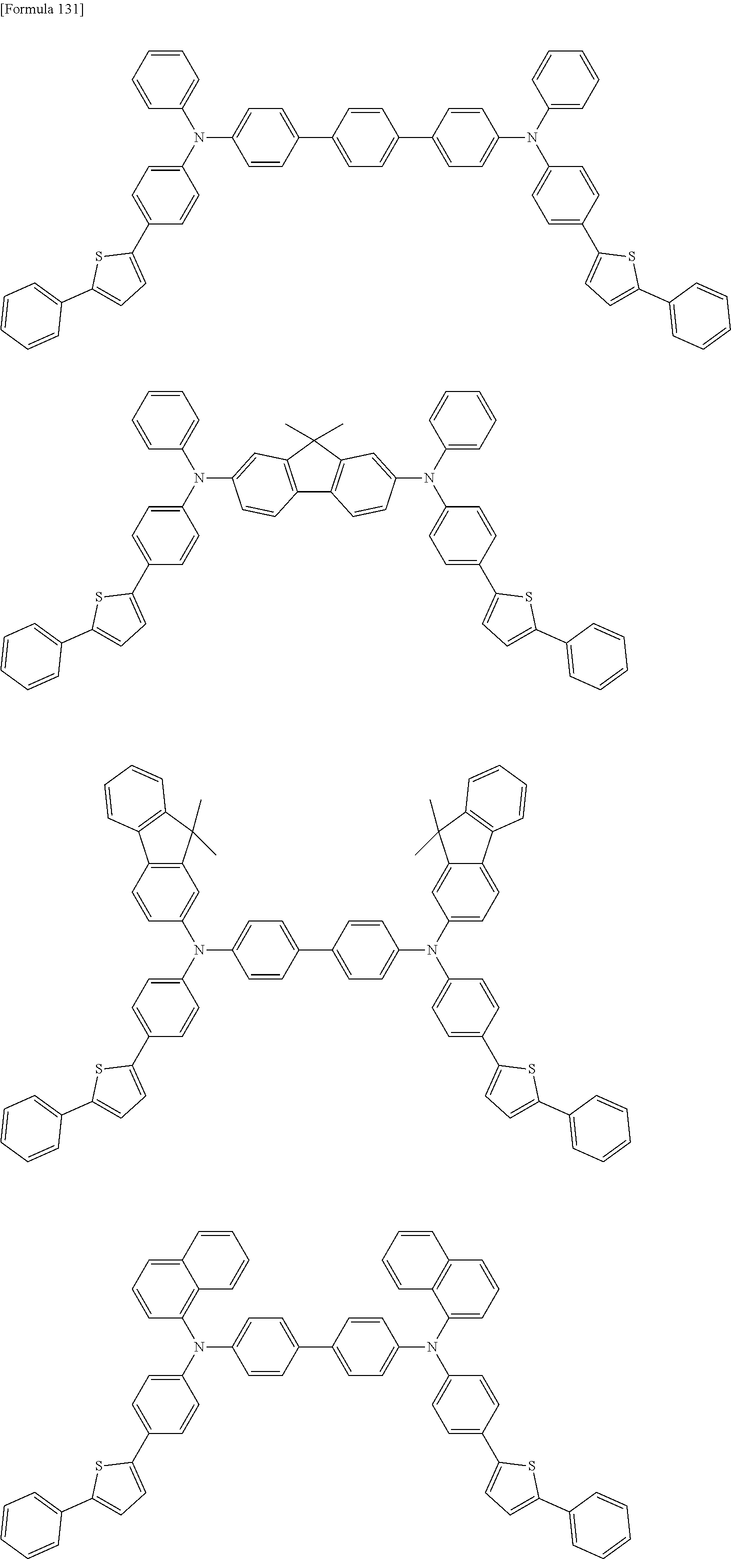 [SMILES: c1ccc(-c2ccc(-c3ccc(N(c4ccccc4)c4ccc(-c5ccc(-c6ccc(N(c7ccccc7)c7ccc(-c8ccc(-c9ccccc9)s8)cc7)cc6)cc5)cc4)cc3)s2)cc1 ; CC1(C)c2cc(N(c3ccccc3)c3ccc(-c4ccc(-c5ccccc5)s4)cc3)ccc2-c2ccc(N(c3ccccc3)c3ccc(-c4ccc(-c5ccccc5)s4)cc3)cc21 ; CC1(C)c2ccccc2-c2ccc(N(c3ccc(-c4ccc(N(c5ccc(-c6ccc(-c7ccccc7)s6)cc5)c5ccc6c(c5)C(C)(C)c5ccccc5-6)cc4)cc3)c3ccc(-c4ccc(-c5ccccc5)s4)cc3)cc21 ; c1ccc(-c2ccc(-c3ccc(N(c4ccc(-c5ccc(N(c6ccc(-c7ccc(-c8ccccc8)s7)cc6)c6cccc7ccccc67)cc5)cc4)c4cccc5ccccc45)cc3)s2)cc1]

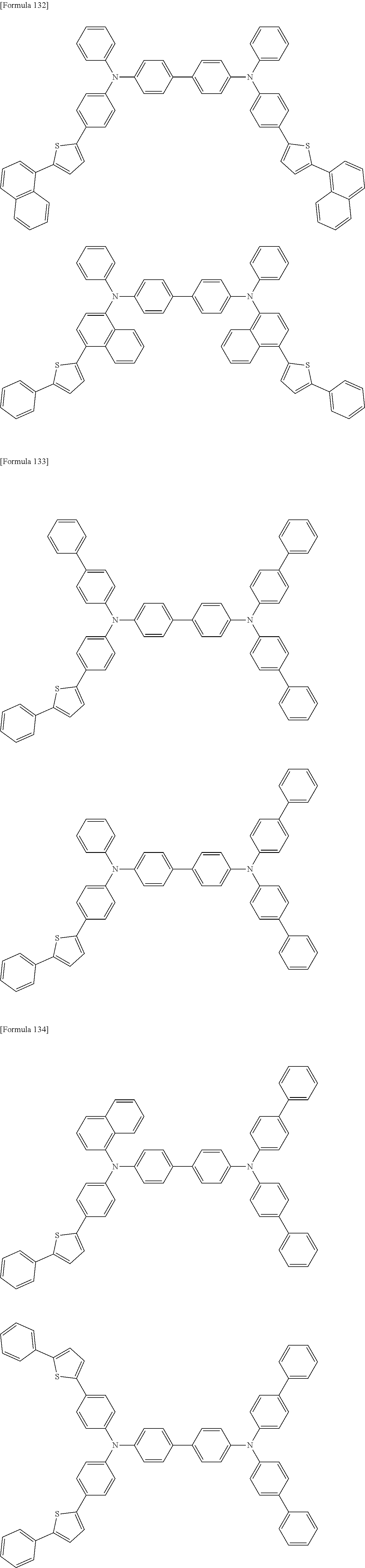

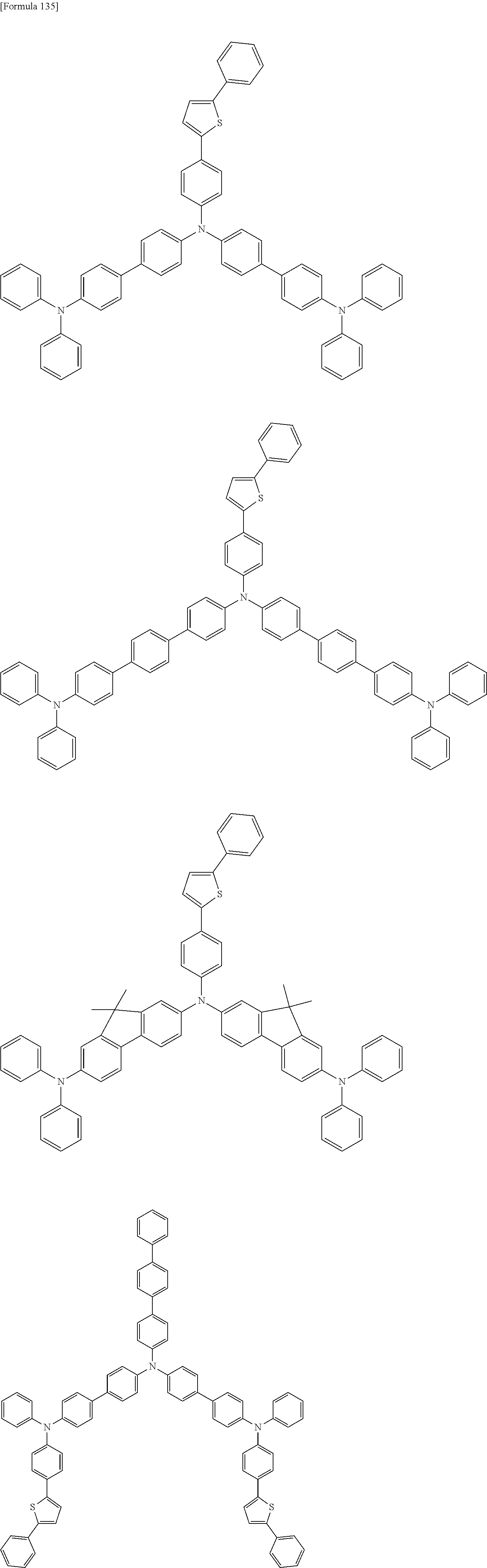

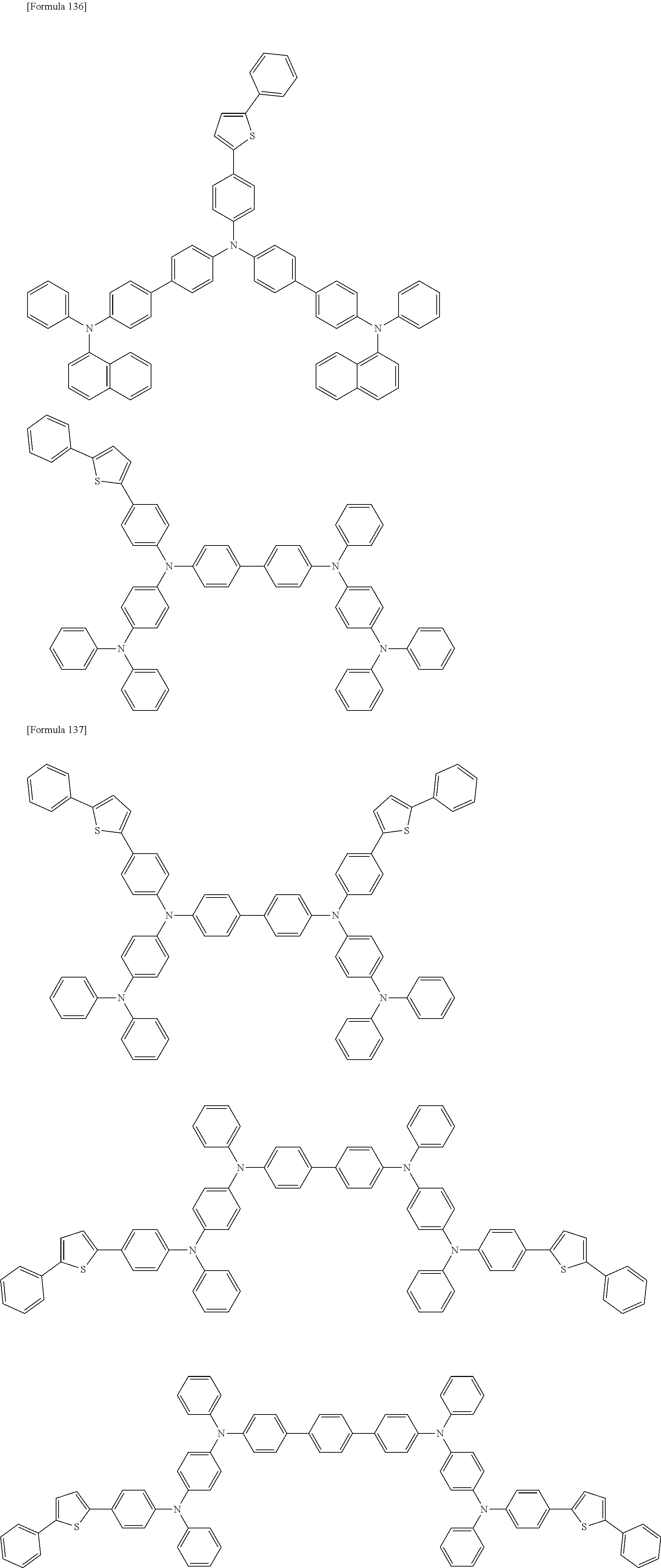

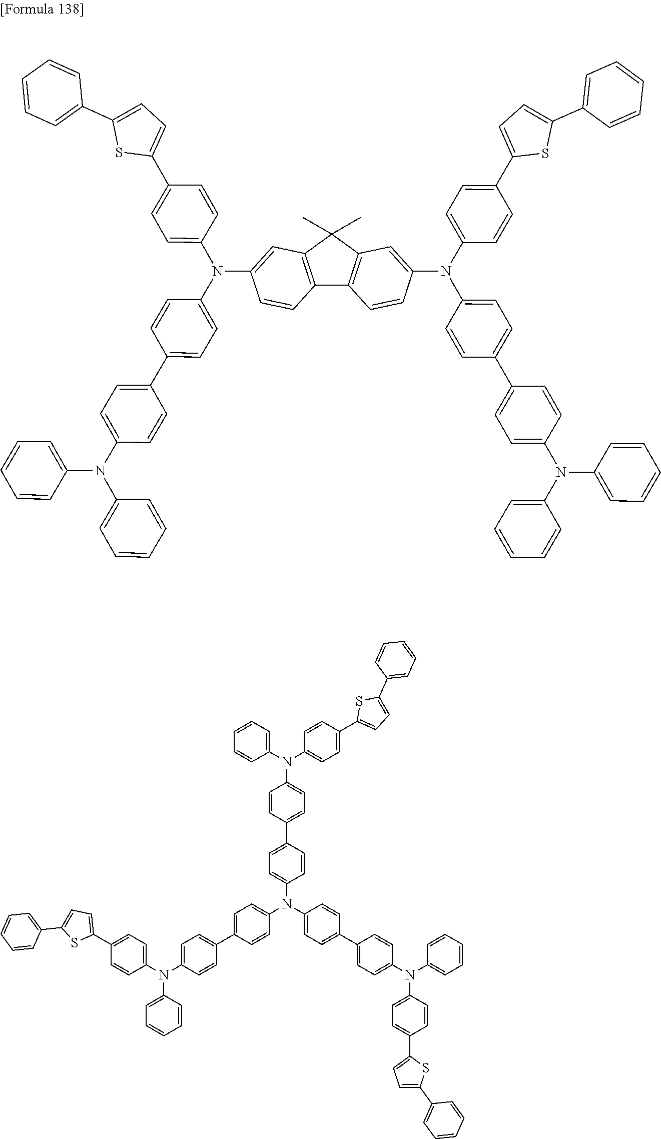 [SMILES: CC1(C)c2cc(N(c3ccc(-c4ccc(N(c5ccccc5)c5ccccc5)cc4)cc3)c3ccc(-c4ccc(-c5ccccc5)s4)cc3)ccc2-c2ccc(N(c3ccc(-c4ccc(N(c5ccccc5)c5ccccc5)cc4)cc3)c3ccc(-c4ccc(-c5ccccc5)s4)cc3)cc21 ; c1ccc(-c2ccc(-c3ccc(N(c4ccccc4)c4ccc(-c5ccc(N(c6ccc(-c7ccc(N(c8ccccc8)c8ccc(-c9ccc(-c%10ccccc%10)s9)cc8)cc7)cc6)c6ccc(-c7ccc(N(c8ccccc8)c8ccc(-c9ccc(-c%10ccccc%10)s9)cc8)cc7)cc6)cc5)cc4)cc3)s2)cc1]

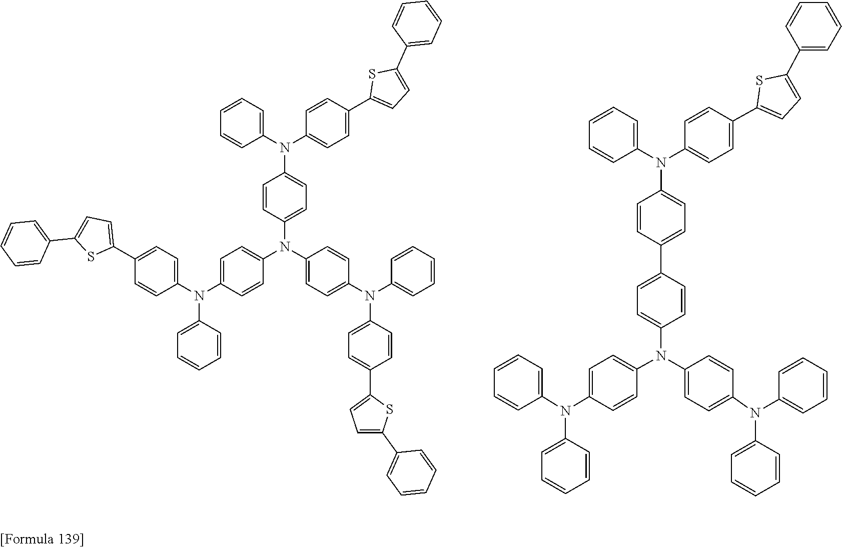 [SMILES: c1ccc(-c2ccc(-c3ccc(N(c4ccccc4)c4ccc(N(c5ccc(N(c6ccccc6)c6ccc(-c7ccc(-c8ccccc8)s7)cc6)cc5)c5ccc(N(c6ccccc6)c6ccc(-c7ccc(-c8ccccc8)s7)cc6)cc5)cc4)cc3)s2)cc1 ; c1ccc(-c2ccc(-c3ccc(N(c4ccccc4)c4ccc(-c5ccc(N(c6ccc(N(c7ccccc7)c7ccccc7)cc6)c6ccc(N(c7ccccc7)c7ccccc7)cc6)cc5)cc4)cc3)s2)cc1]

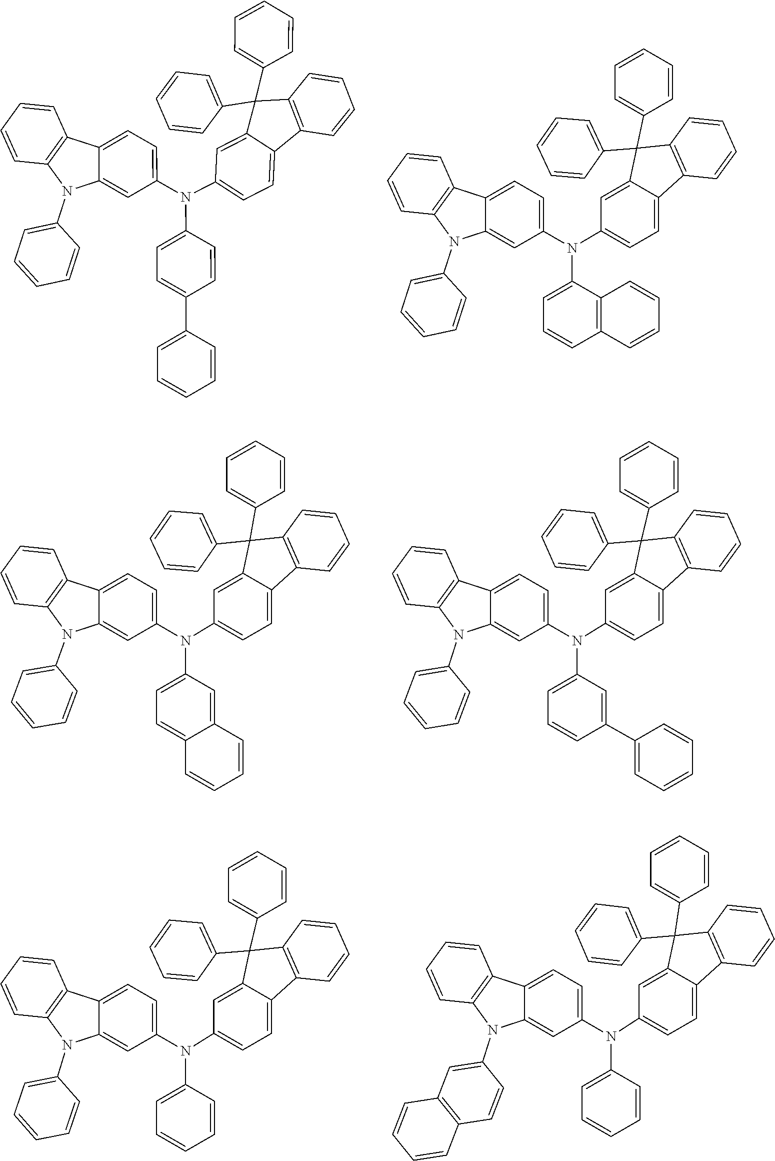

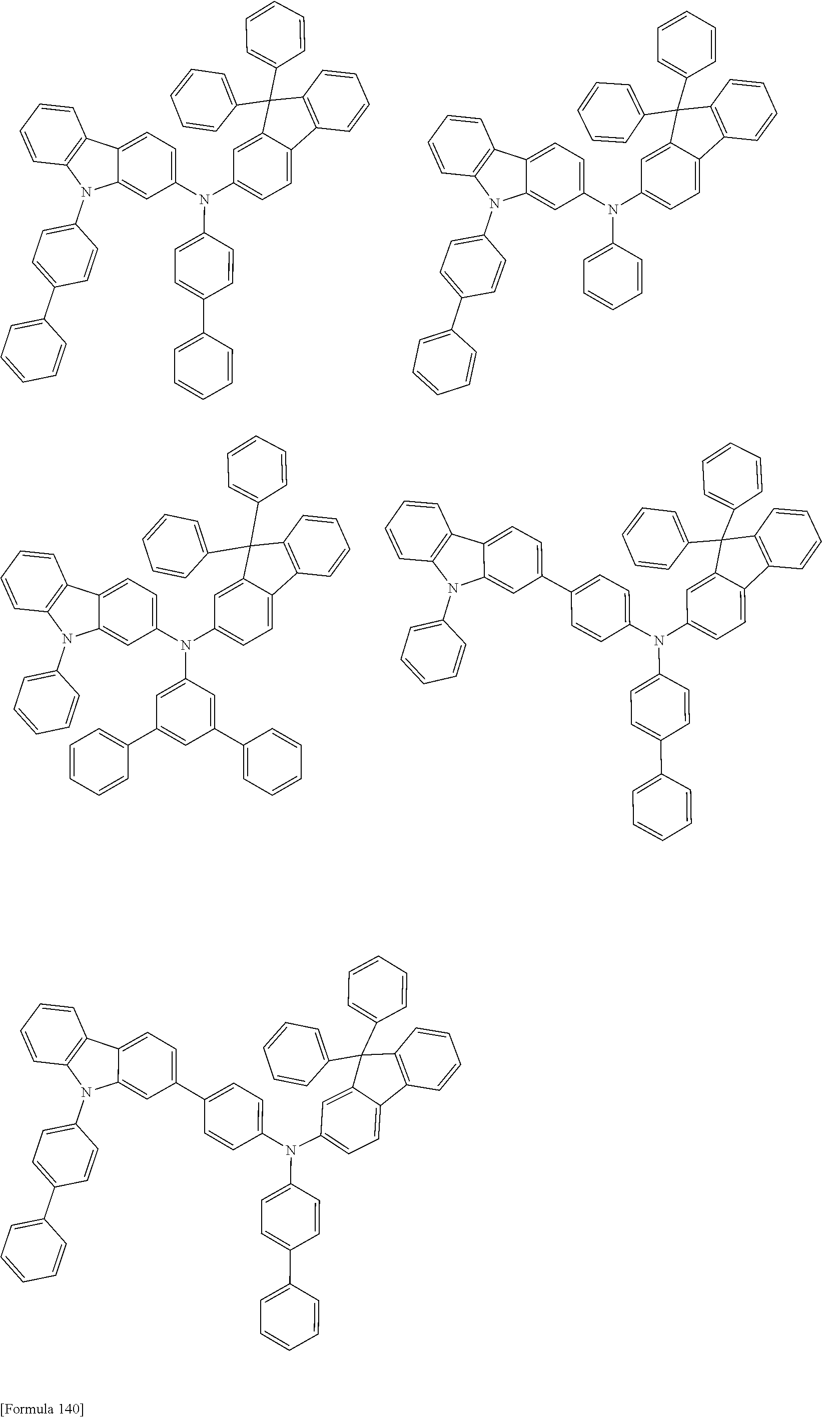

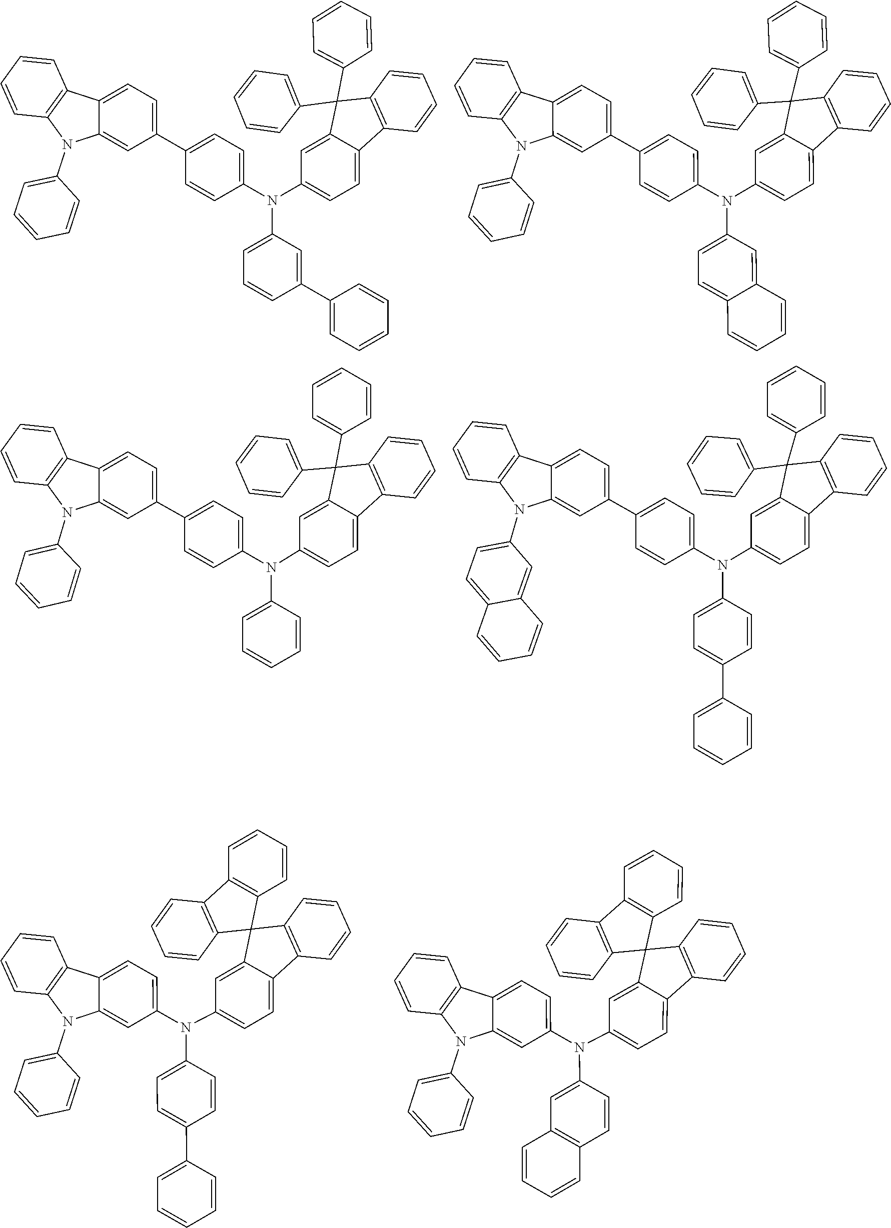

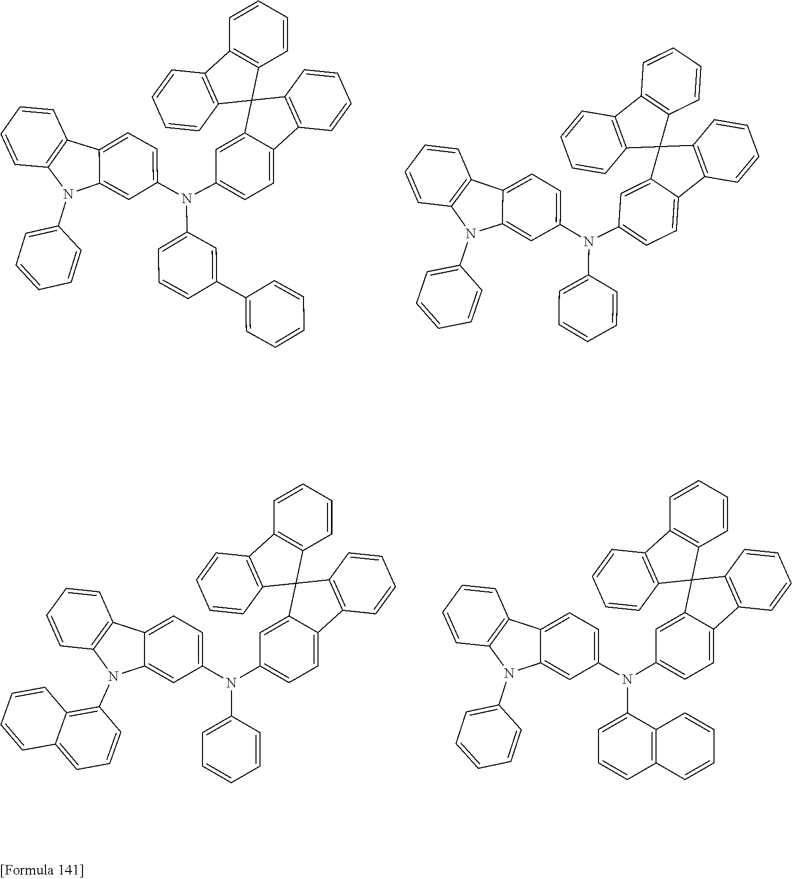 [SMILES: c1ccc(-c2cccc(N(c3ccc4c(c3)C3(c5ccccc5-c5ccccc53)c3ccccc3-4)c3ccc4c5ccccc5n(-c5ccccc5)c4c3)c2)cc1 ; c1ccc(N(c2ccc3c(c2)C2(c4ccccc4-c4ccccc42)c2ccccc2-3)c2ccc3c4ccccc4n(-c4ccccc4)c3c2)cc1 ; c1ccc(N(c2ccc3c(c2)C2(c4ccccc4-c4ccccc42)c2ccccc2-3)c2ccc3c4ccccc4n(-c4cccc5ccccc45)c3c2)cc1 ; c1ccc(-n2c3ccccc3c3ccc(N(c4ccc5c(c4)C4(c6ccccc6-c6ccccc64)c4ccccc4-5)c4cccc5ccccc45)cc32)cc1]

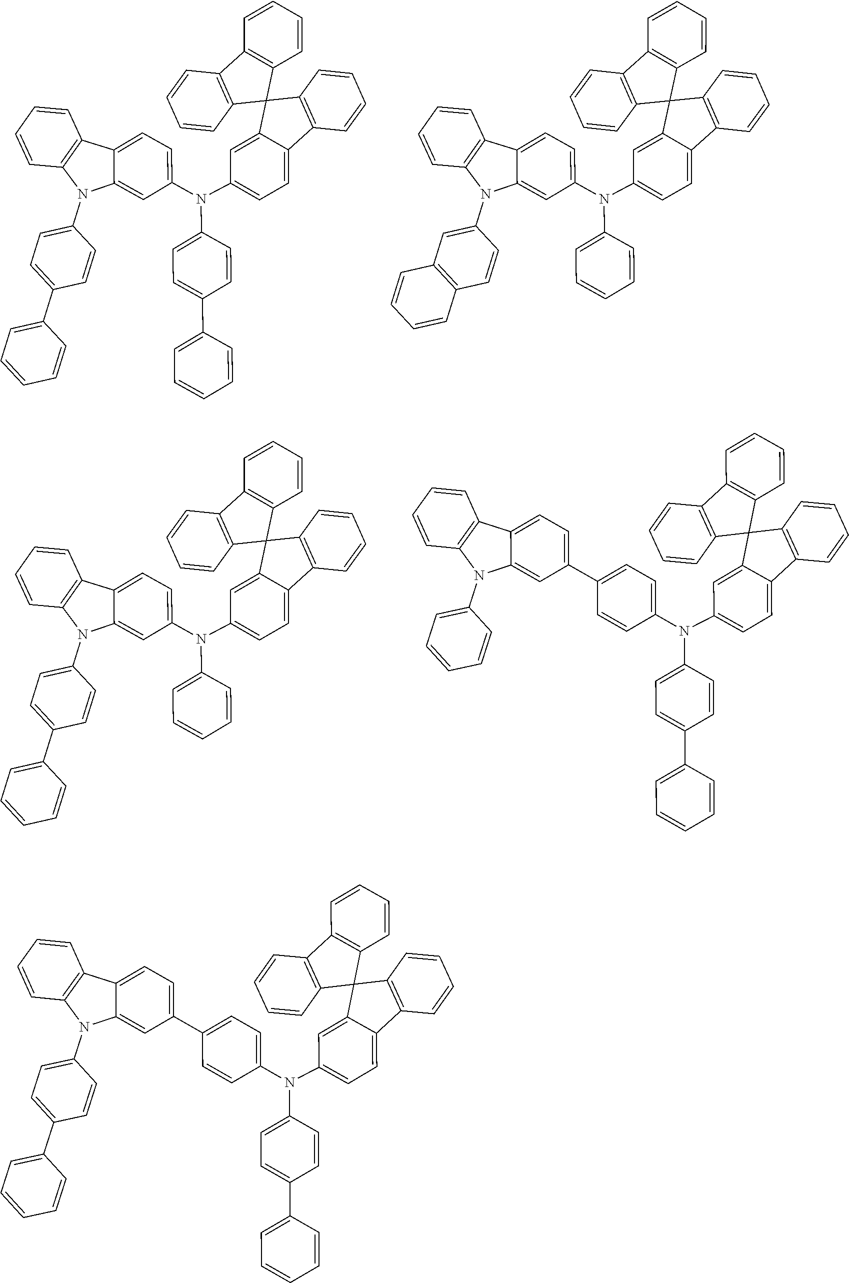

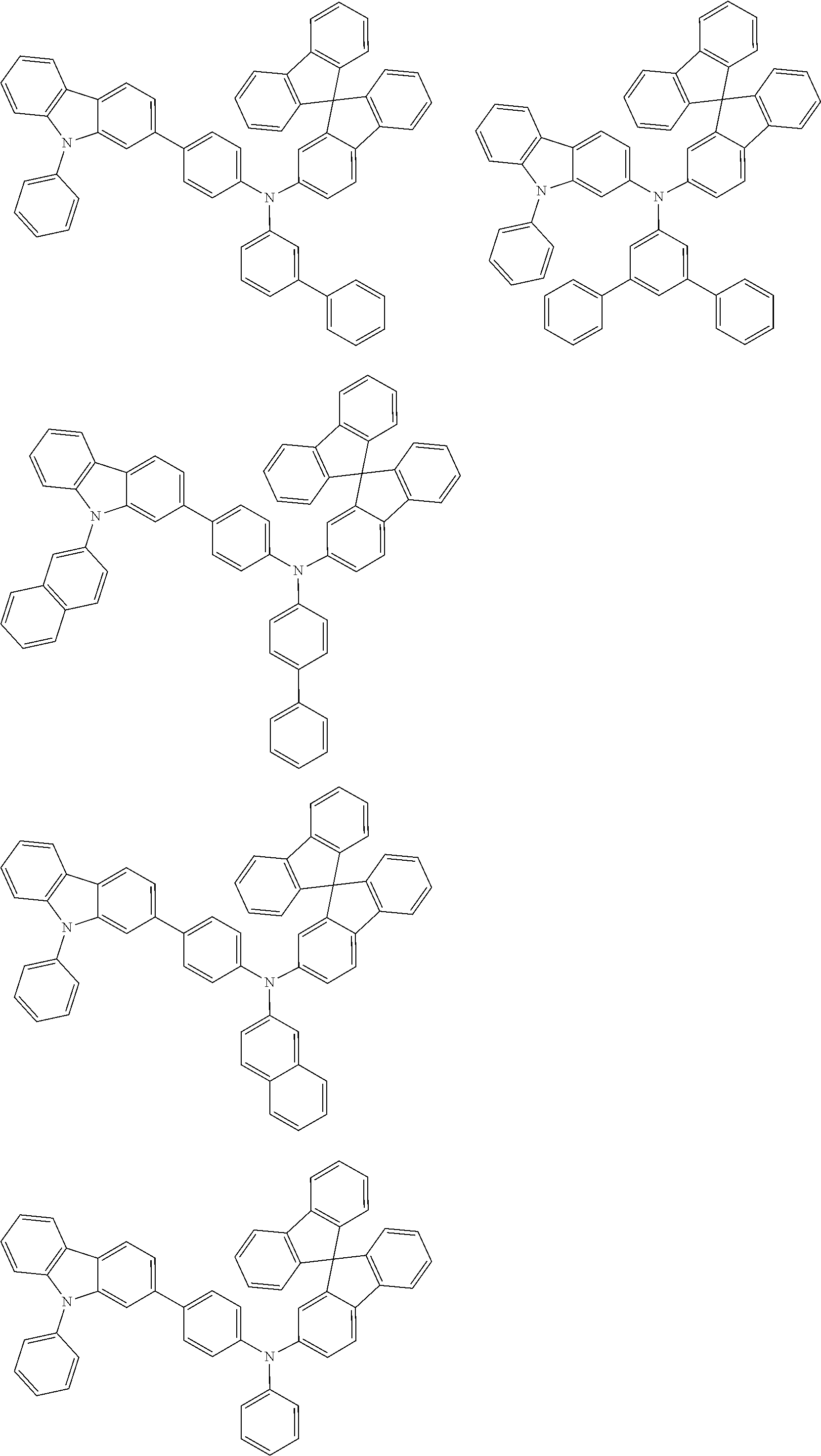

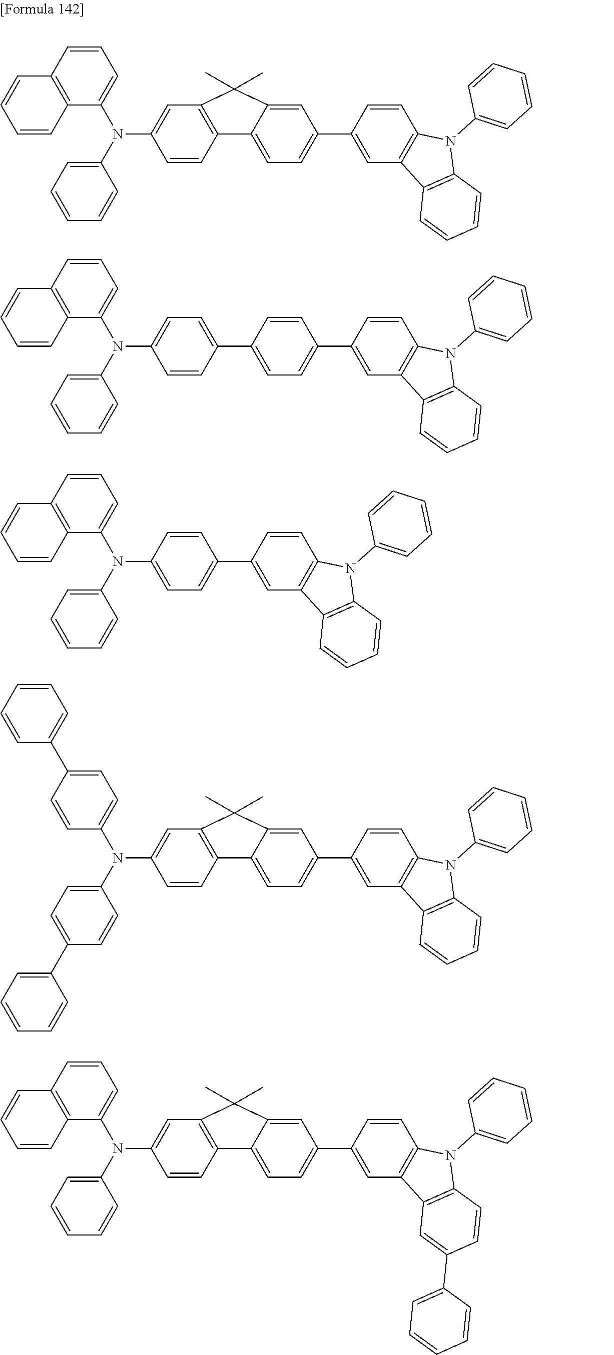

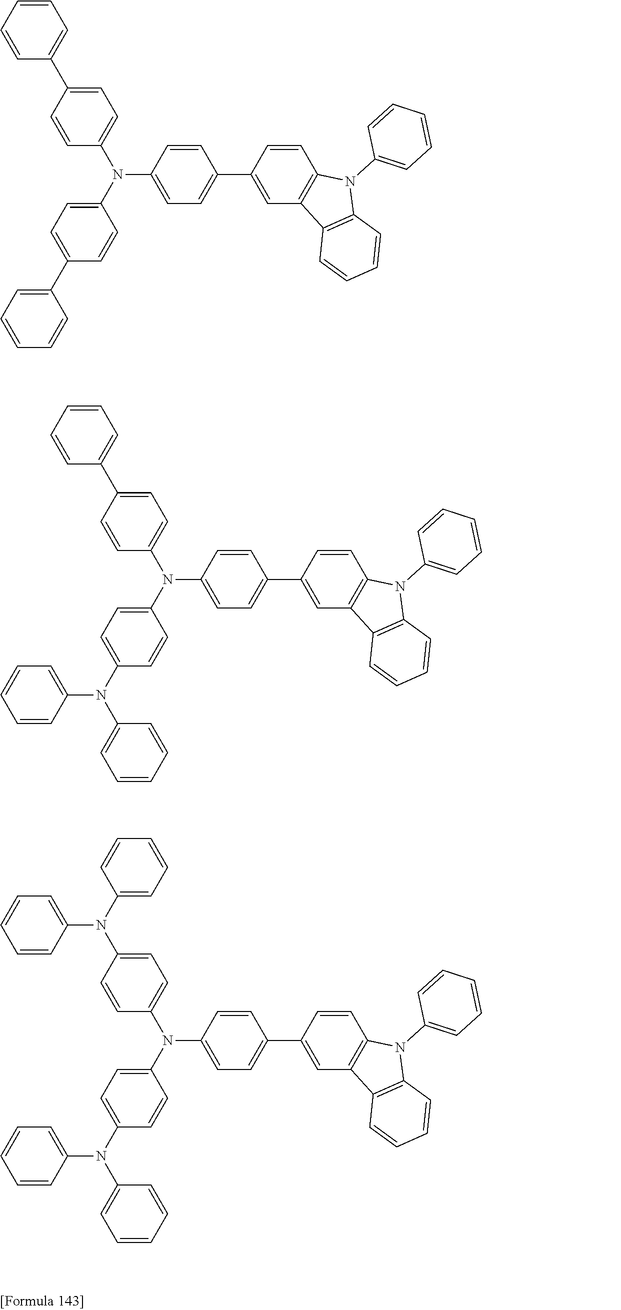 [SMILES: c1ccc(-c2ccc(N(c3ccc(-c4ccccc4)cc3)c3ccc(-c4ccc5c(c4)c4ccccc4n5-c4ccccc4)cc3)cc2)cc1 ; c1ccc(-c2ccc(N(c3ccc(-c4ccc5c(c4)c4ccccc4n5-c4ccccc4)cc3)c3ccc(N(c4ccccc4)c4ccccc4)cc3)cc2)cc1 ; c1ccc(N(c2ccccc2)c2ccc(N(c3ccc(-c4ccc5c(c4)c4ccccc4n5-c4ccccc4)cc3)c3ccc(N(c4ccccc4)c4ccccc4)cc3)cc2)cc1]

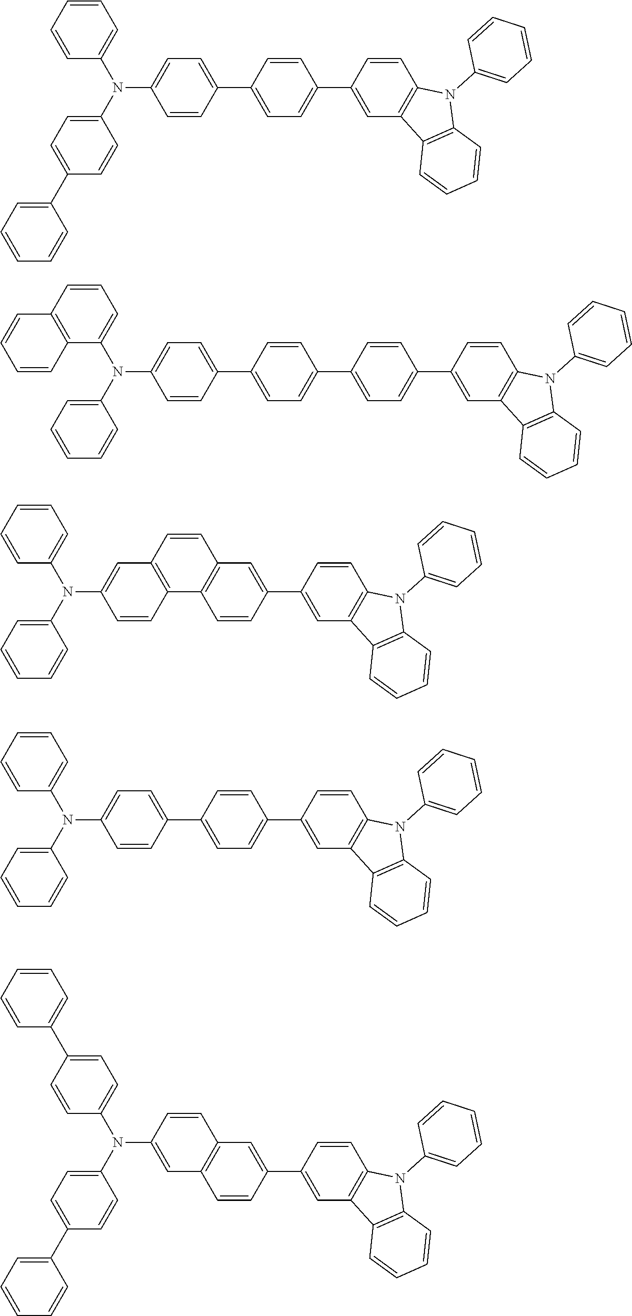

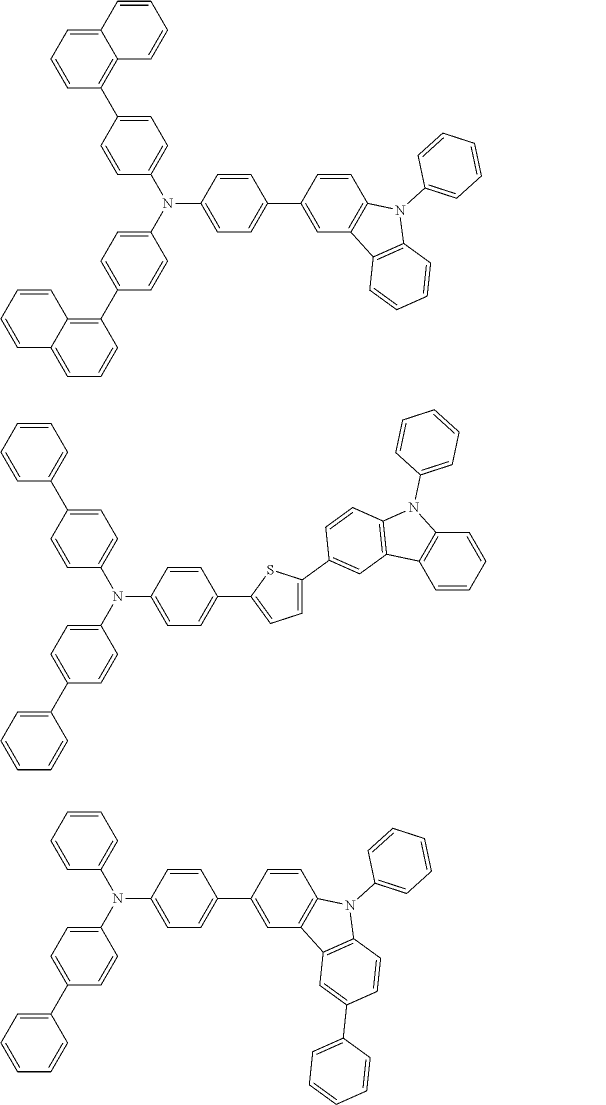

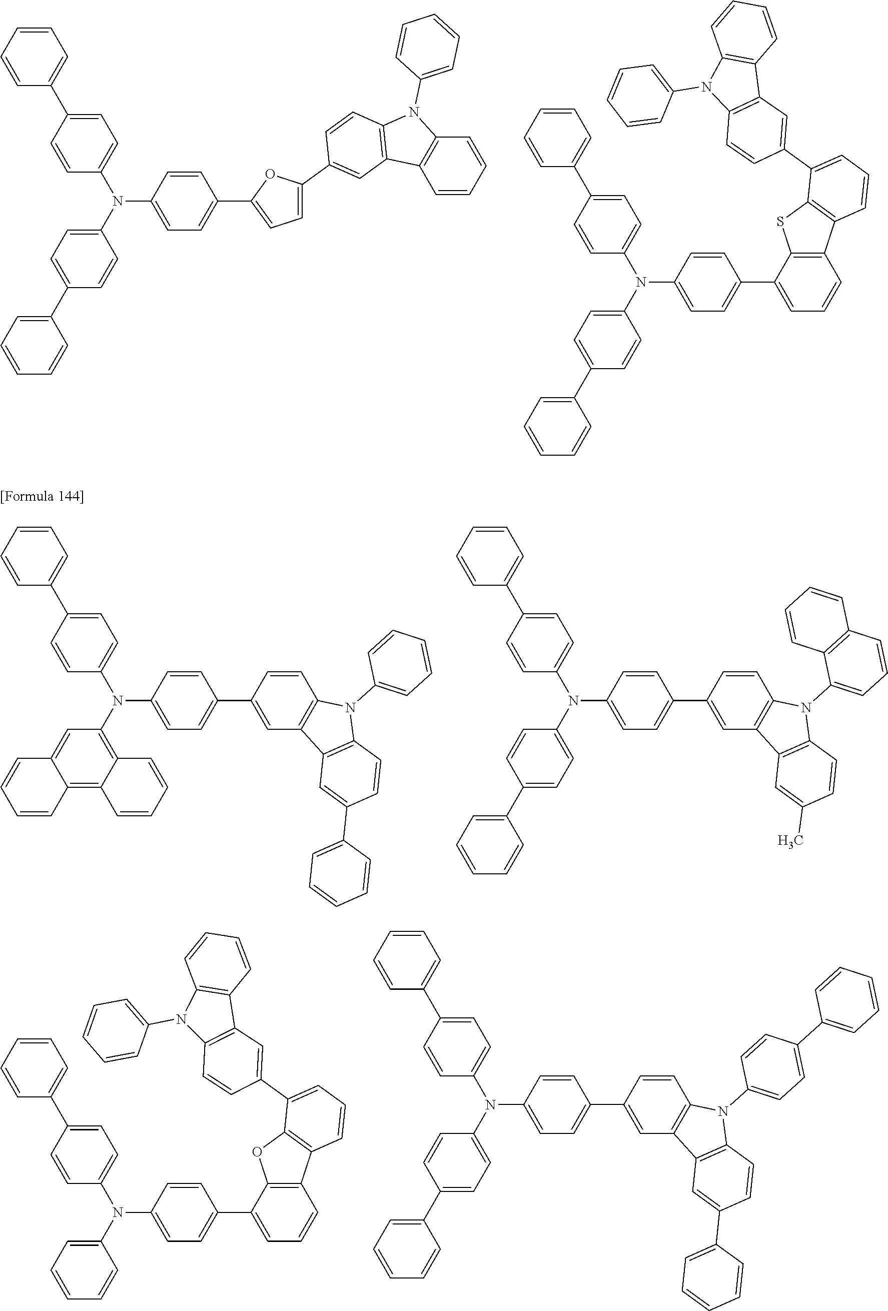

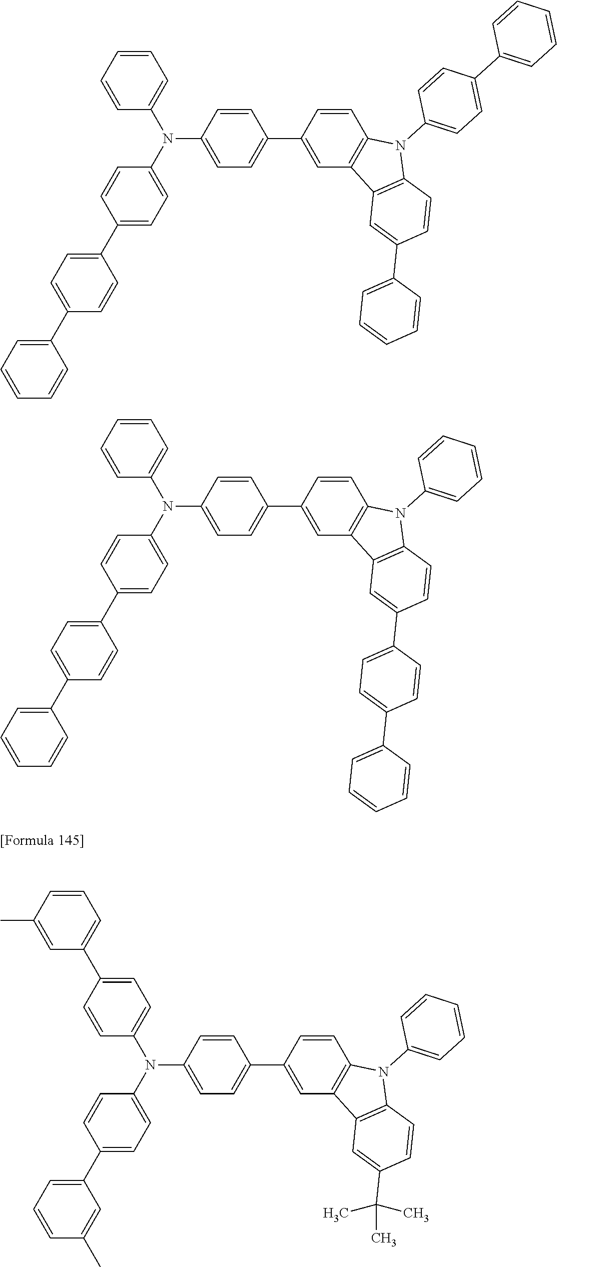 [SMILES: c1ccc(-c2ccc(-c3ccc(N(c4ccccc4)c4ccc(-c5ccc6c(c5)c5cc(-c7ccccc7)ccc5n6-c5ccc(-c6ccccc6)cc5)cc4)cc3)cc2)cc1 ; c1ccc(-c2ccc(-c3ccc(N(c4ccccc4)c4ccc(-c5ccc6c(c5)c5cc(-c7ccc(-c8ccccc8)cc7)ccc5n6-c5ccccc5)cc4)cc3)cc2)cc1 ; Cc1cccc(-c2ccc(N(c3ccc(-c4cccc(C)c4)cc3)c3ccc(-c4ccc5c(c4)c4cc(C(C)(C)C)ccc4n5-c4ccccc4)cc3)cc2)c1]

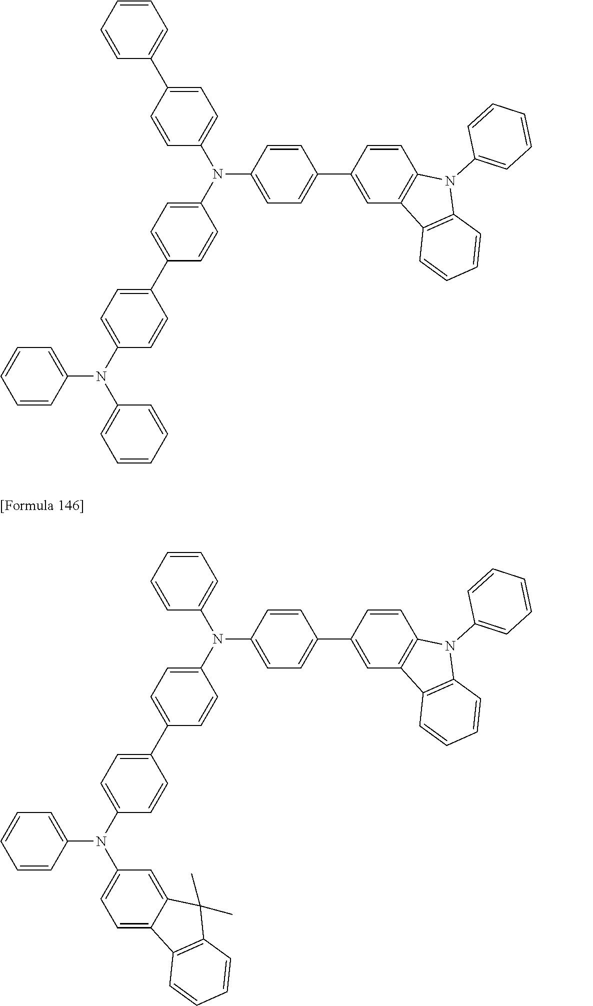 [SMILES: c1ccc(-c2ccc(N(c3ccc(-c4ccc(N(c5ccccc5)c5ccccc5)cc4)cc3)c3ccc(-c4ccc5c(c4)c4ccccc4n5-c4ccccc4)cc3)cc2)cc1 ; CC1(C)c2ccccc2-c2ccc(N(c3ccccc3)c3ccc(-c4ccc(N(c5ccccc5)c5ccc(-c6ccc7c(c6)c6ccccc6n7-c6ccccc6)cc5)cc4)cc3)cc21]

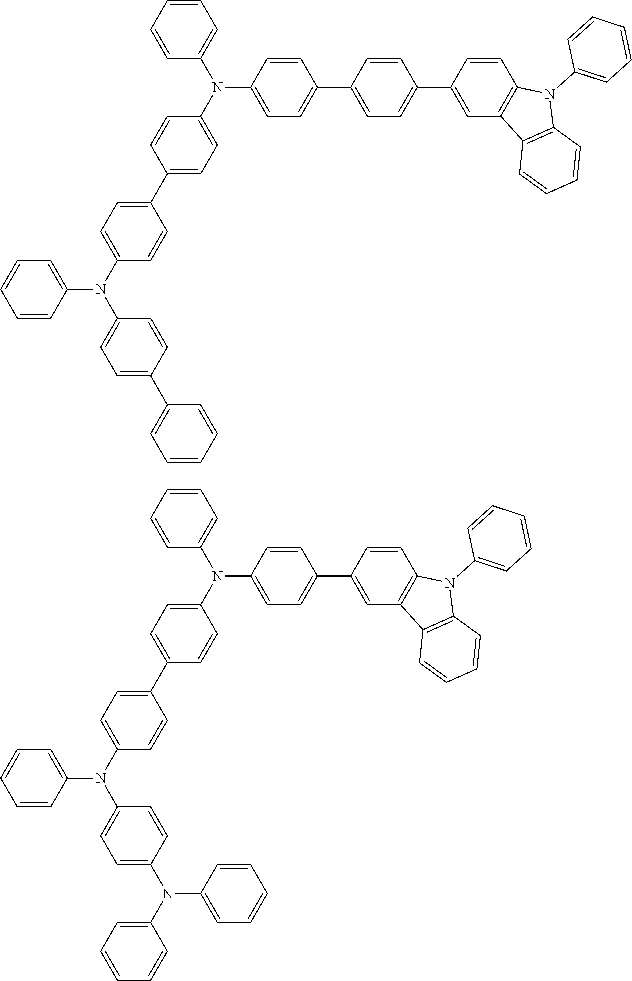

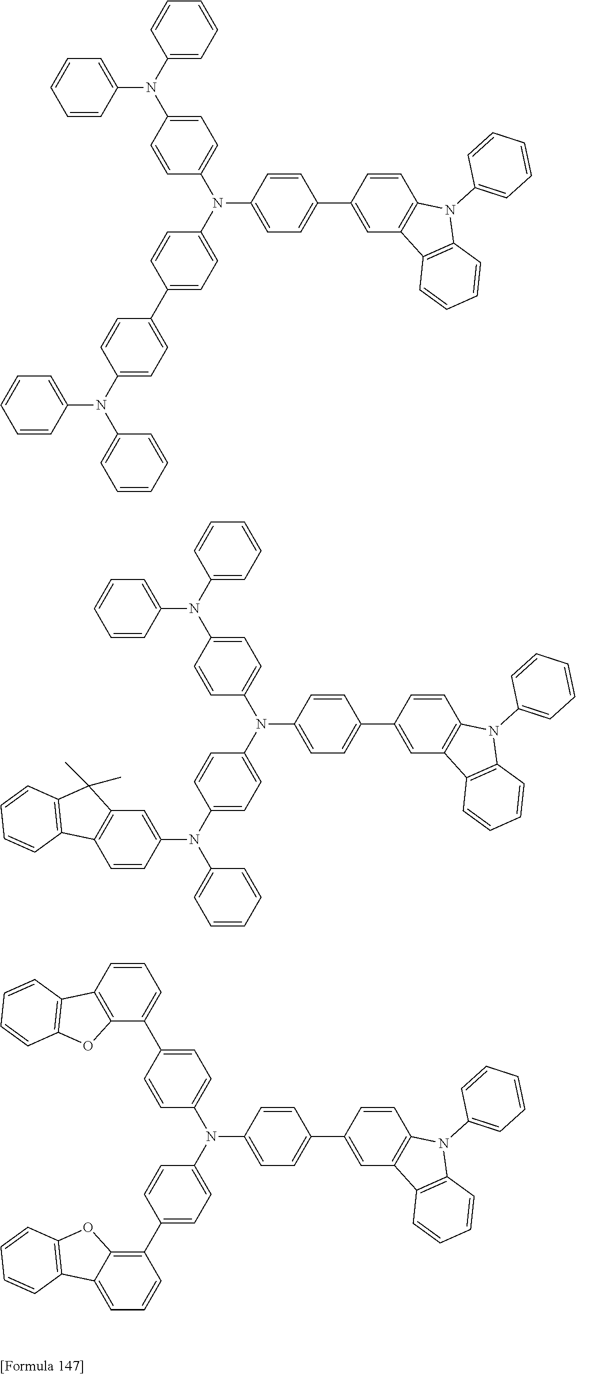 [SMILES: c1ccc(N(c2ccccc2)c2ccc(-c3ccc(N(c4ccc(-c5ccc6c(c5)c5ccccc5n6-c5ccccc5)cc4)c4ccc(N(c5ccccc5)c5ccccc5)cc4)cc3)cc2)cc1 ; CC1(C)c2ccccc2-c2ccc(N(c3ccccc3)c3ccc(N(c4ccc(-c5ccc6c(c5)c5ccccc5n6-c5ccccc5)cc4)c4ccc(N(c5ccccc5)c5ccccc5)cc4)cc3)cc21 ; c1ccc(-n2c3ccccc3c3cc(-c4ccc(N(c5ccc(-c6cccc7c6oc6ccccc67)cc5)c5ccc(-c6cccc7c6oc6ccccc67)cc5)cc4)ccc32)cc1]

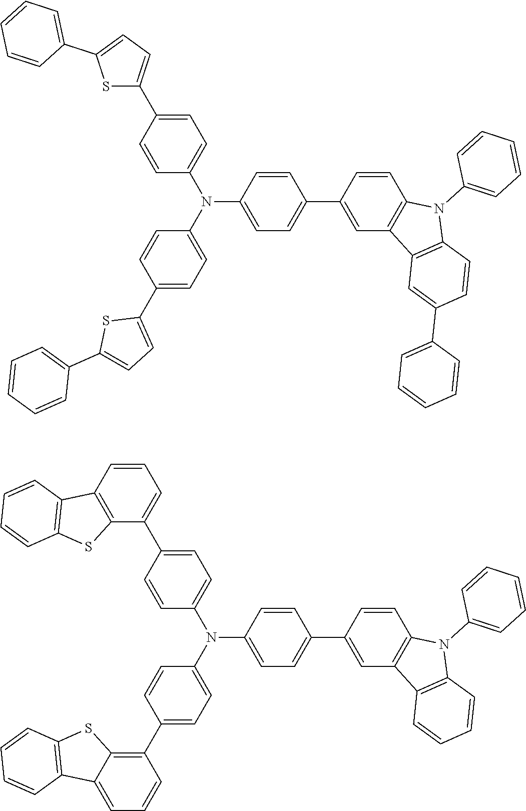 [SMILES: c1ccc(-c2ccc3c(c2)c2cc(-c4ccc(N(c5ccc(-c6ccc(-c7ccccc7)s6)cc5)c5ccc(-c6ccc(-c7ccccc7)s6)cc5)cc4)ccc2n3-c2ccccc2)cc1 ; c1ccc(-n2c3ccccc3c3cc(-c4ccc(N(c5ccc(-c6cccc7c6sc6ccccc67)cc5)c5ccc(-c6cccc7c6sc6ccccc67)cc5)cc4)ccc32)cc1]

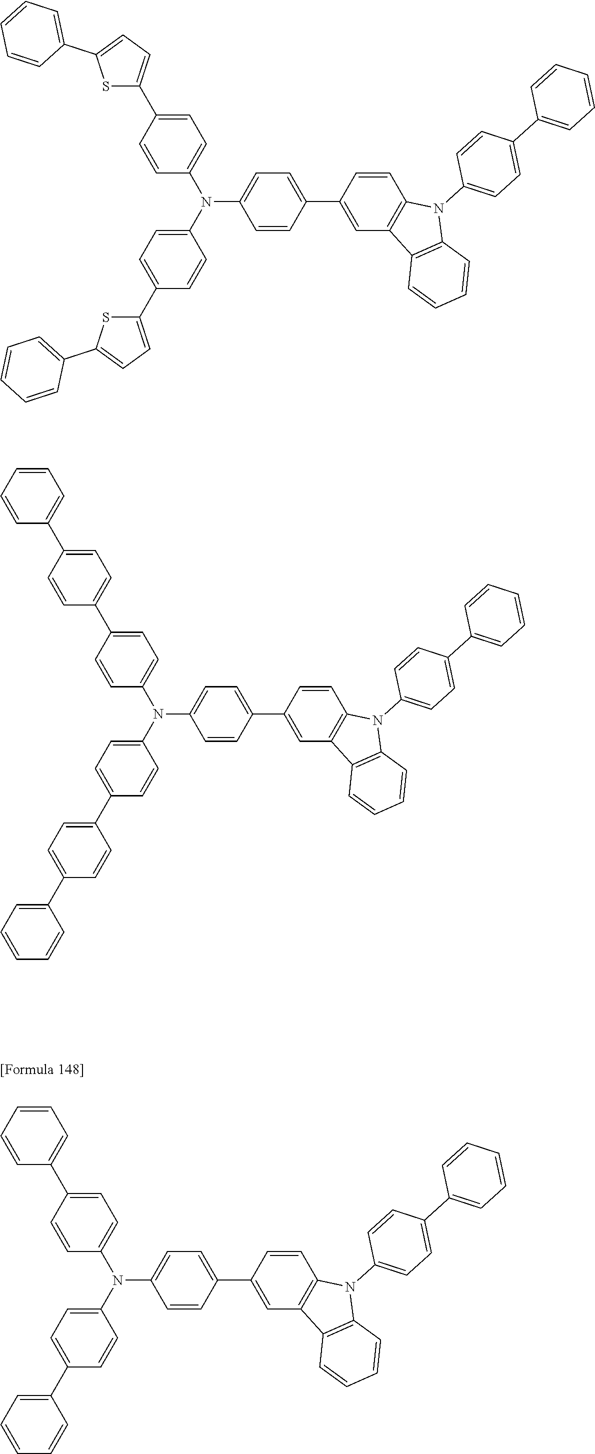 [SMILES: c1ccc(-c2ccc(-n3c4ccccc4c4cc(-c5ccc(N(c6ccc(-c7ccc(-c8ccccc8)s7)cc6)c6ccc(-c7ccc(-c8ccccc8)s7)cc6)cc5)ccc43)cc2)cc1 ; c1ccc(-c2ccc(-c3ccc(N(c4ccc(-c5ccc(-c6ccccc6)cc5)cc4)c4ccc(-c5ccc6c(c5)c5ccccc5n6-c5ccc(-c6ccccc6)cc5)cc4)cc3)cc2)cc1 ; c1ccc(-c2ccc(N(c3ccc(-c4ccccc4)cc3)c3ccc(-c4ccc5c(c4)c4ccccc4n5-c4ccc(-c5ccccc5)cc4)cc3)cc2)cc1]

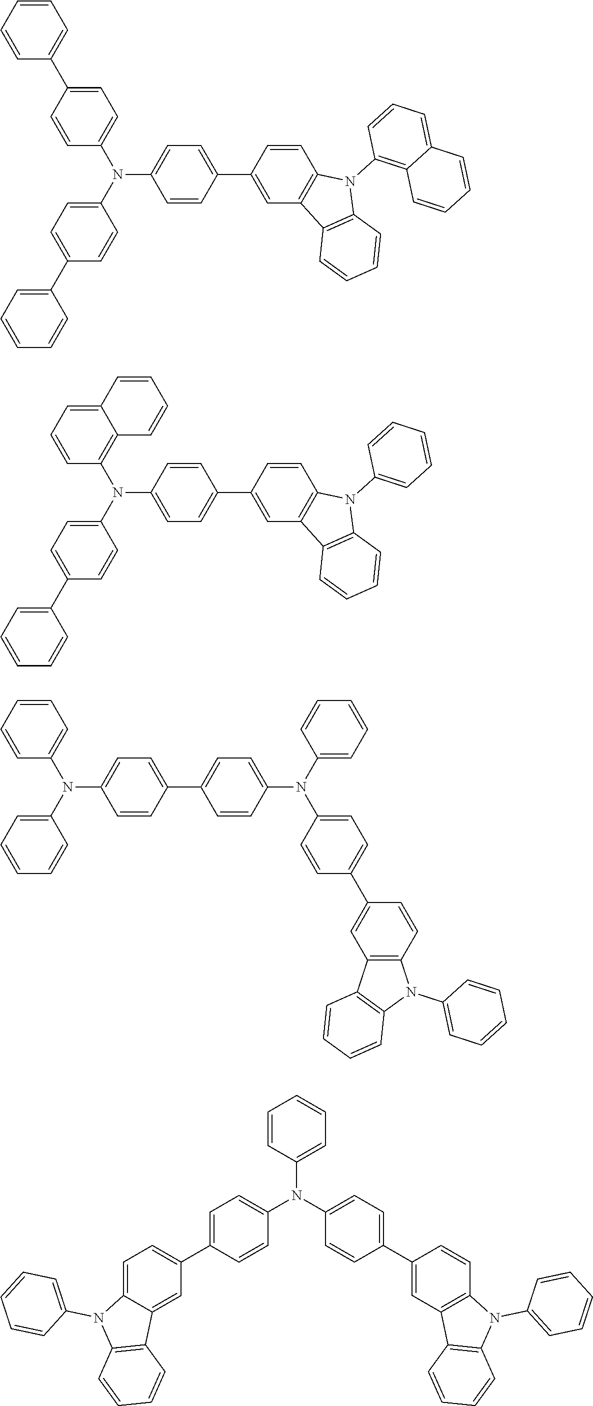

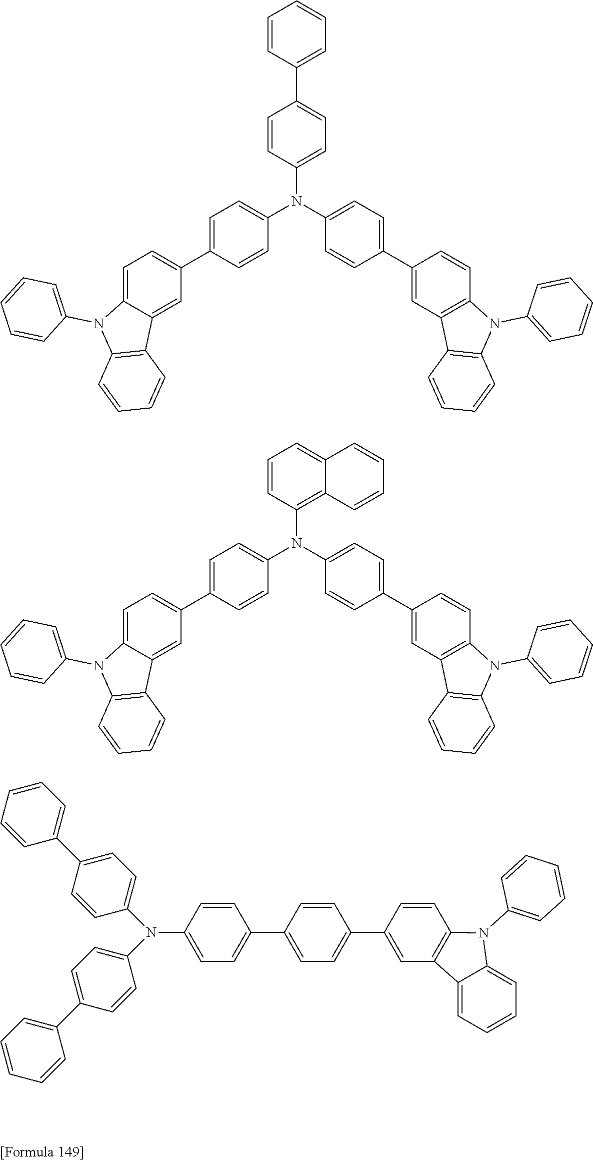 [SMILES: c1ccc(-c2ccc(N(c3ccc(-c4ccc5c(c4)c4ccccc4n5-c4ccccc4)cc3)c3ccc(-c4ccc5c(c4)c4ccccc4n5-c4ccccc4)cc3)cc2)cc1 ; c1ccc(-n2c3ccccc3c3cc(-c4ccc(N(c5ccc(-c6ccc7c(c6)c6ccccc6n7-c6ccccc6)cc5)c5cccc6ccccc56)cc4)ccc32)cc1 ; c1ccc(-c2ccc(N(c3ccc(-c4ccccc4)cc3)c3ccc(-c4ccc(-c5ccc6c(c5)c5ccccc5n6-c5ccccc5)cc4)cc3)cc2)cc1]

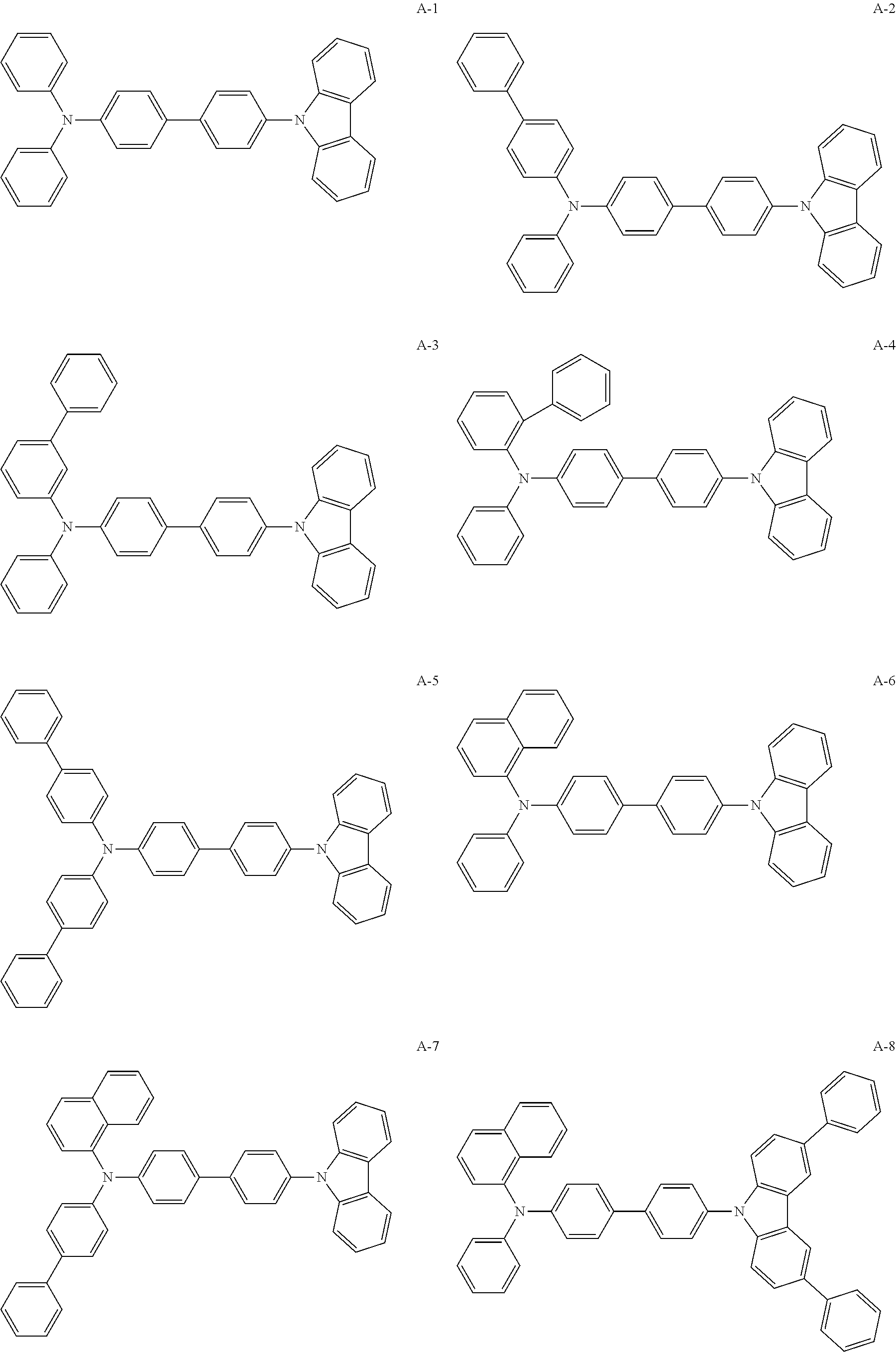

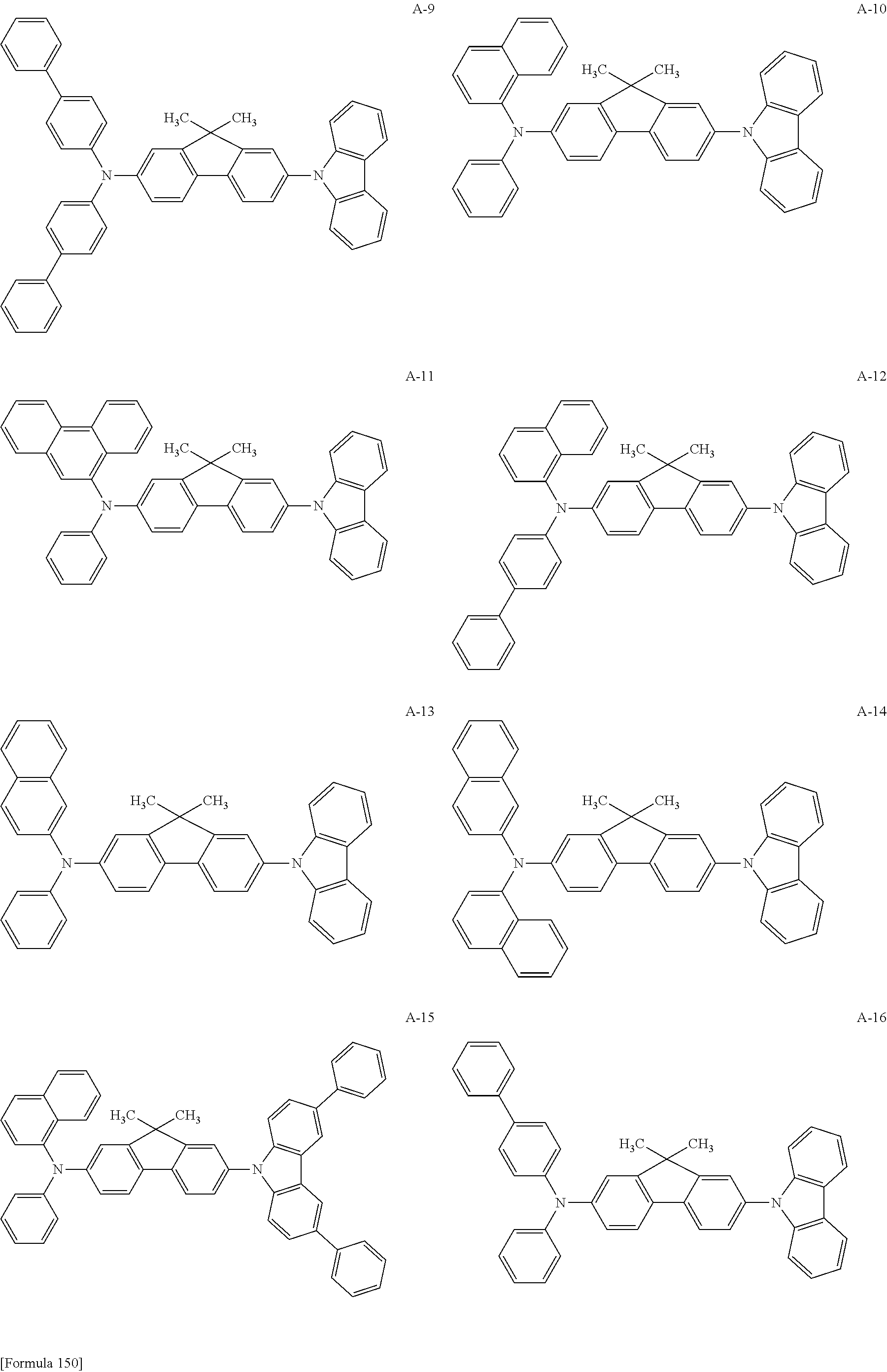

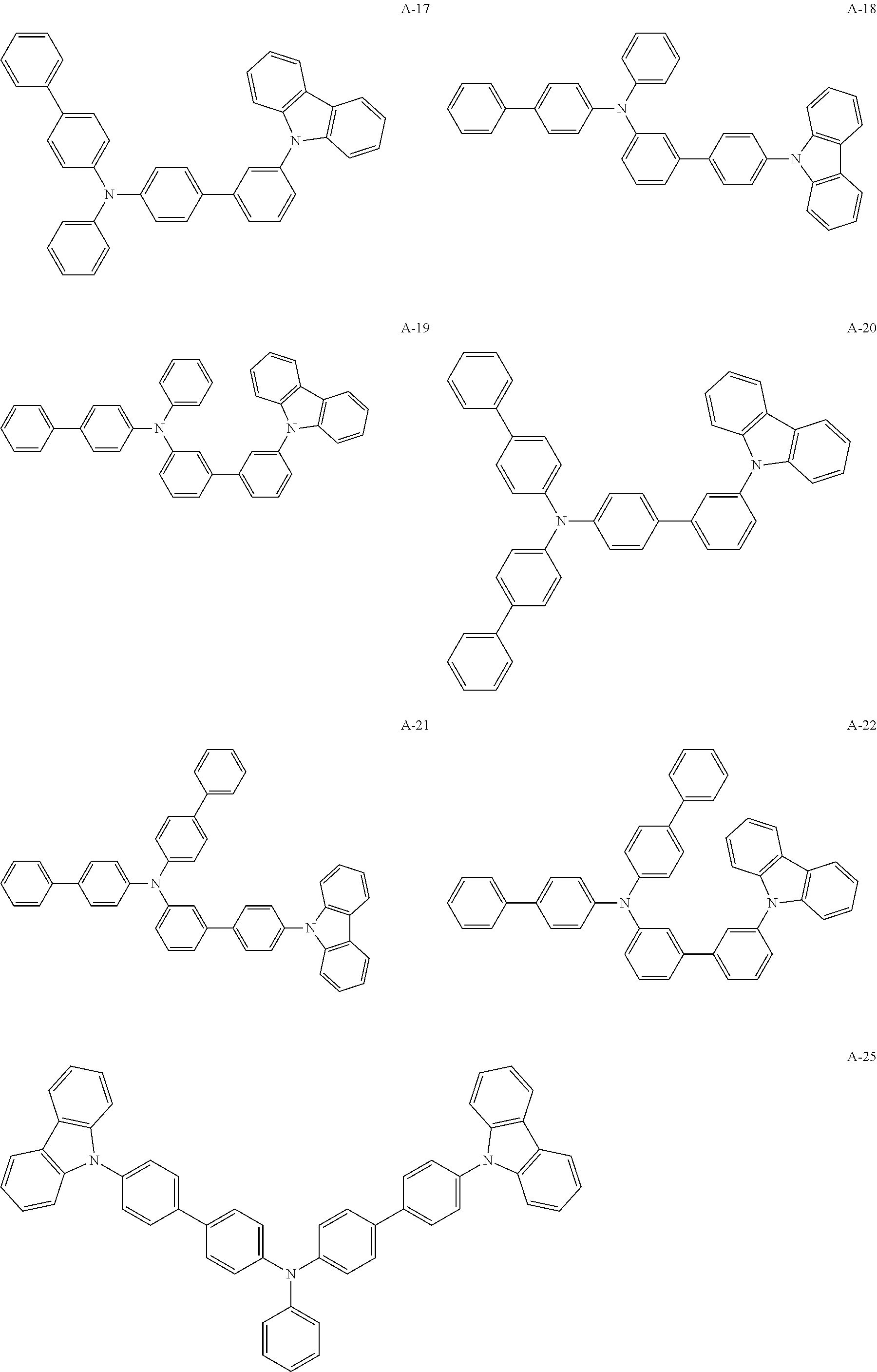

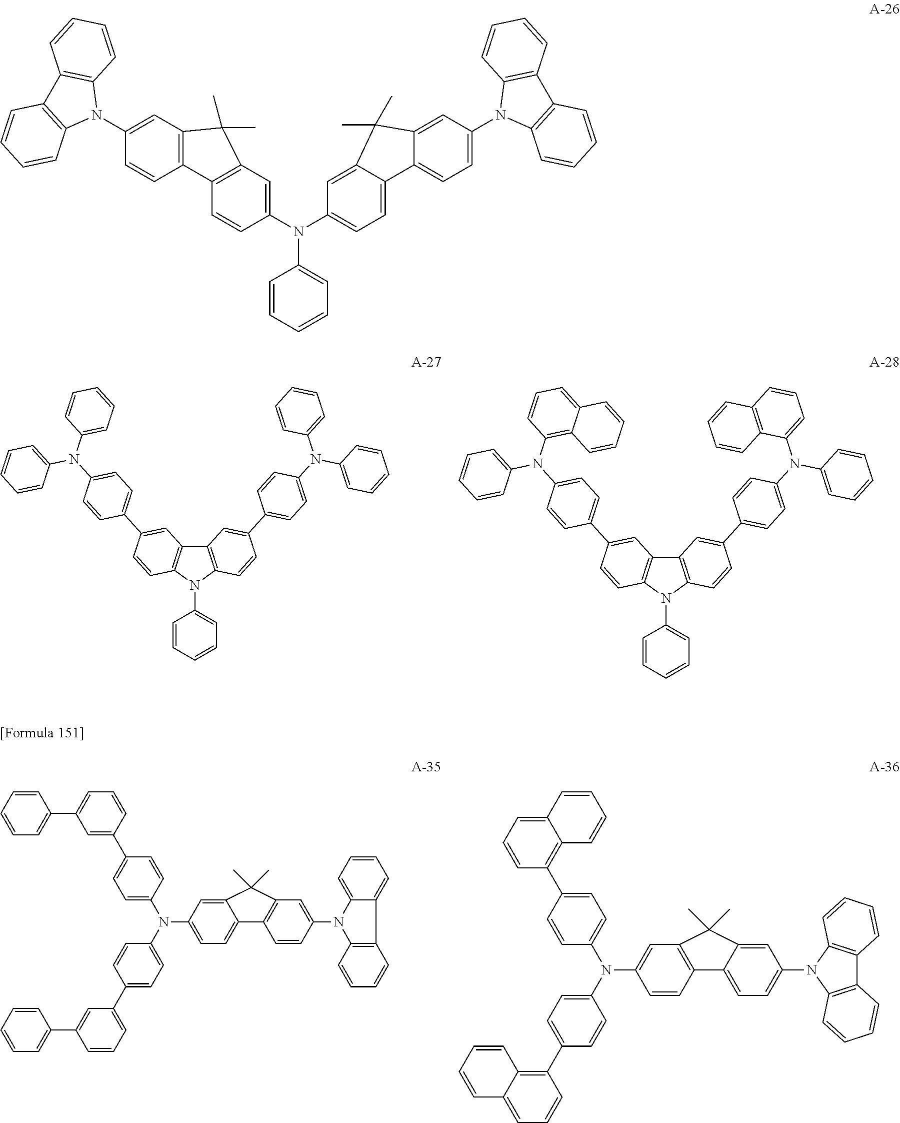

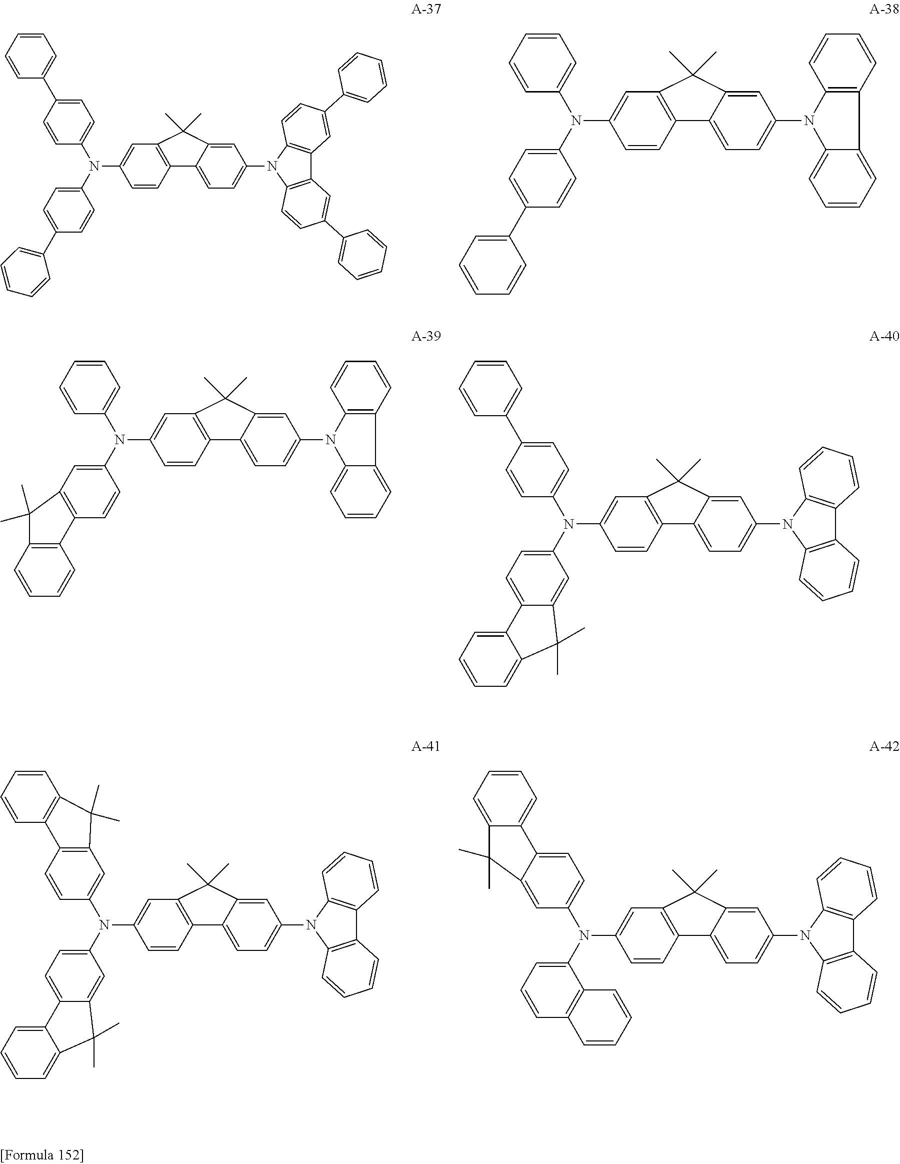

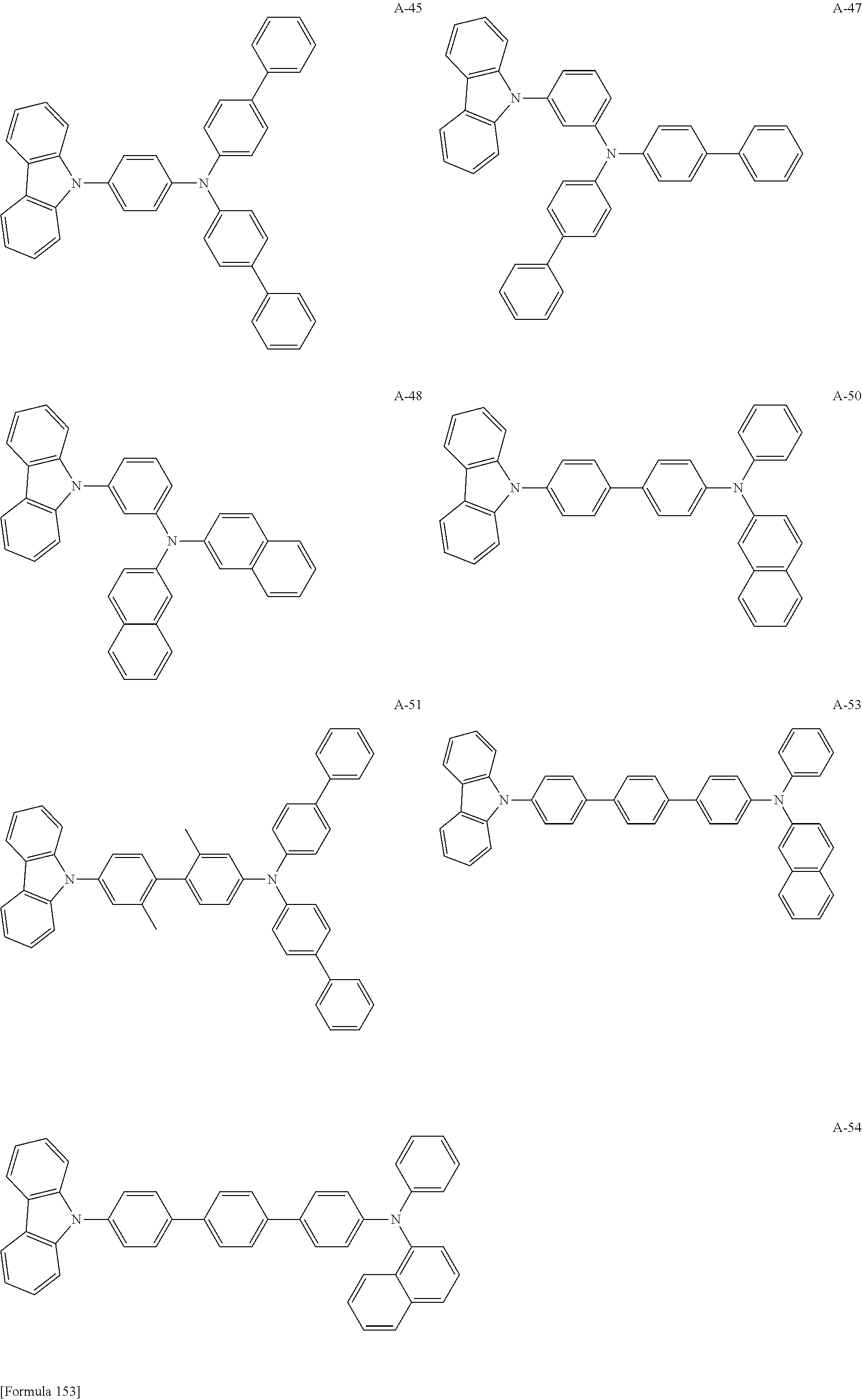

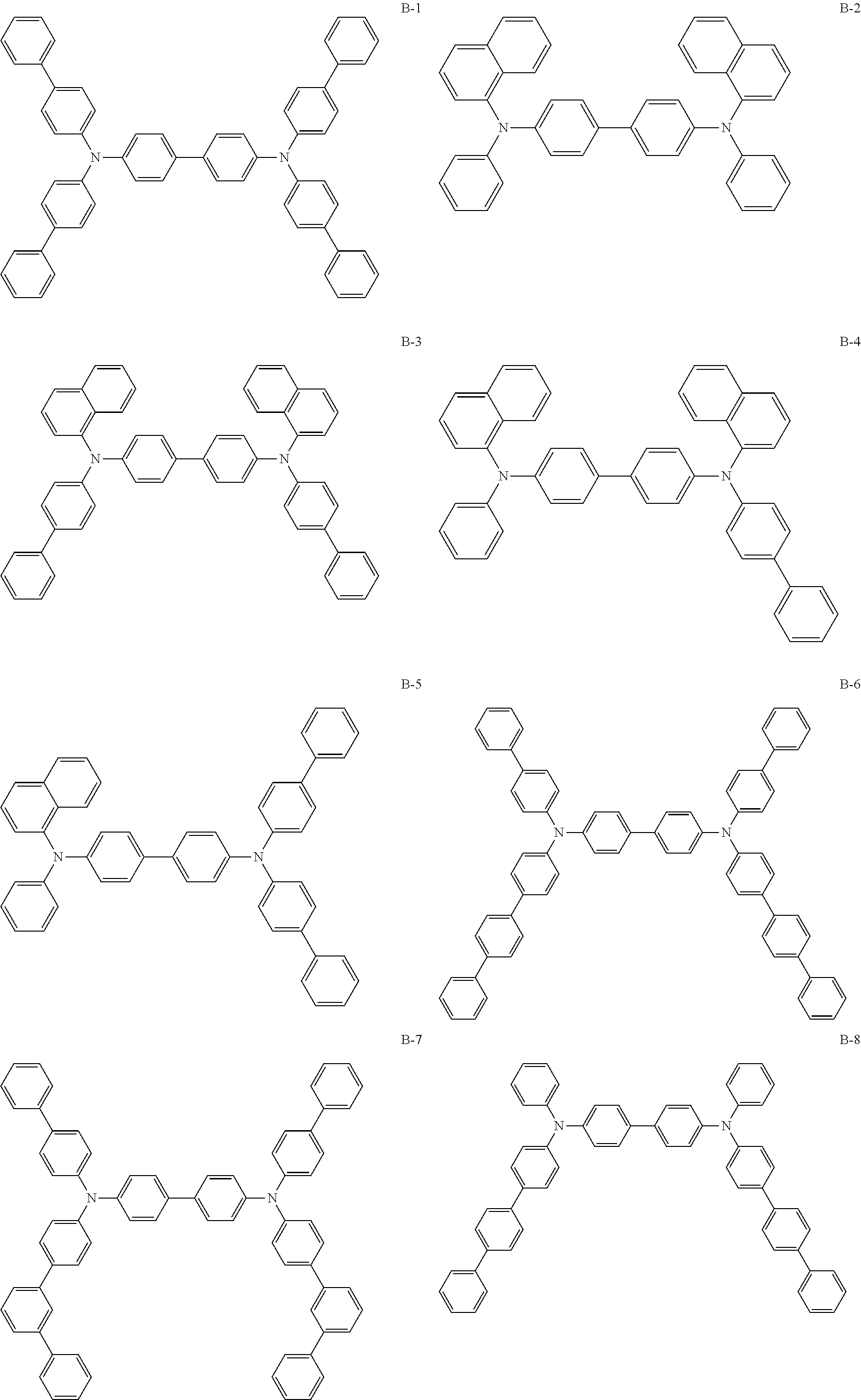

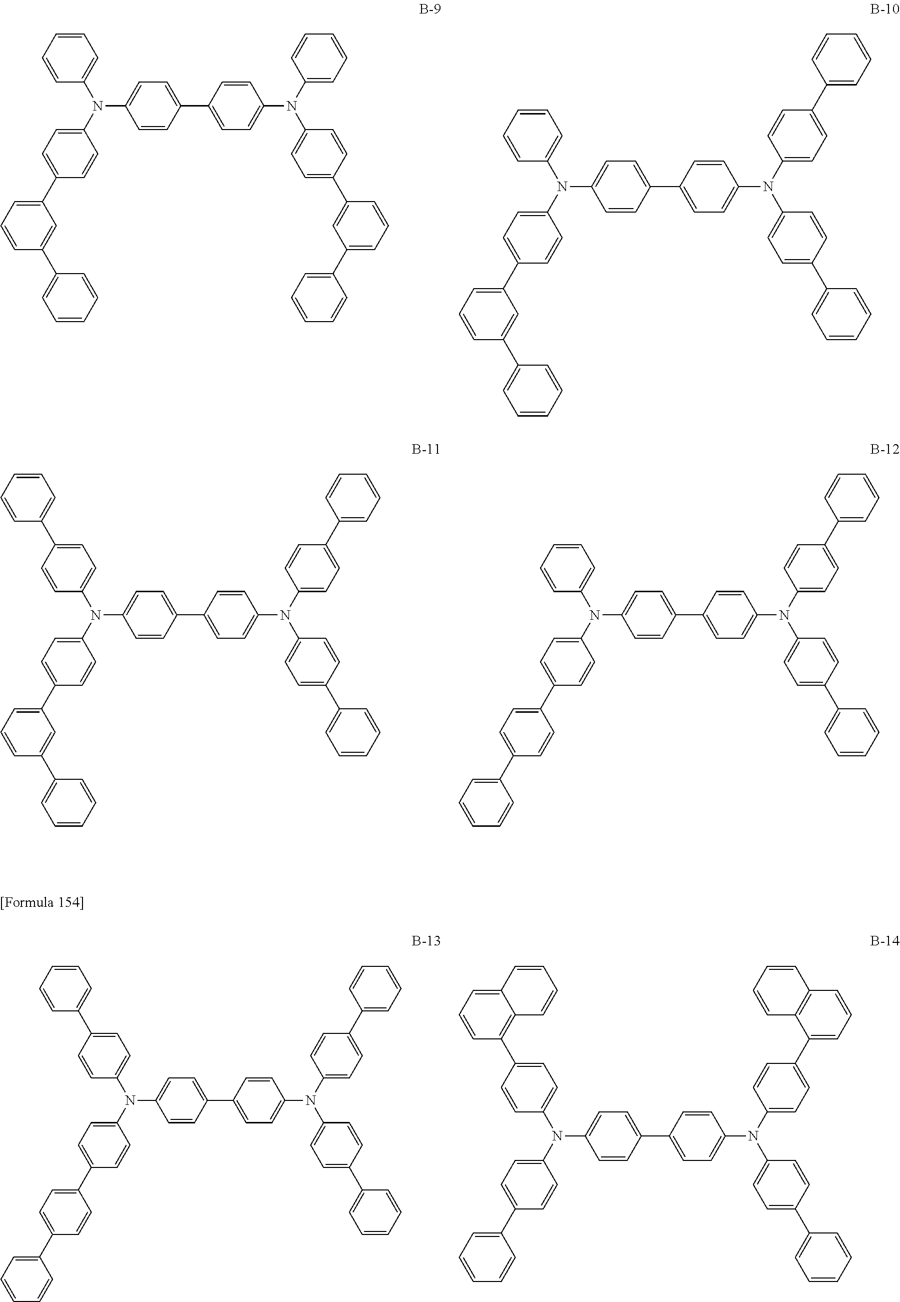

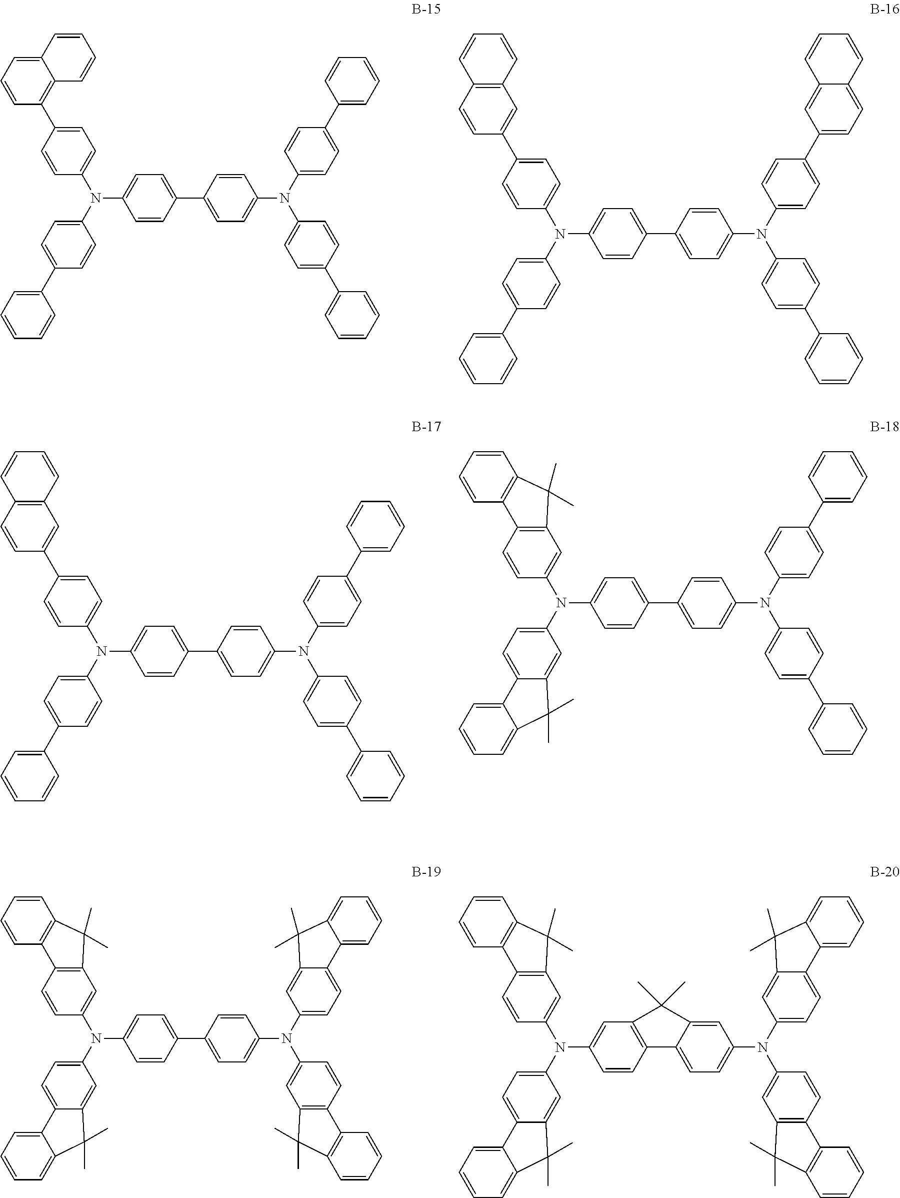

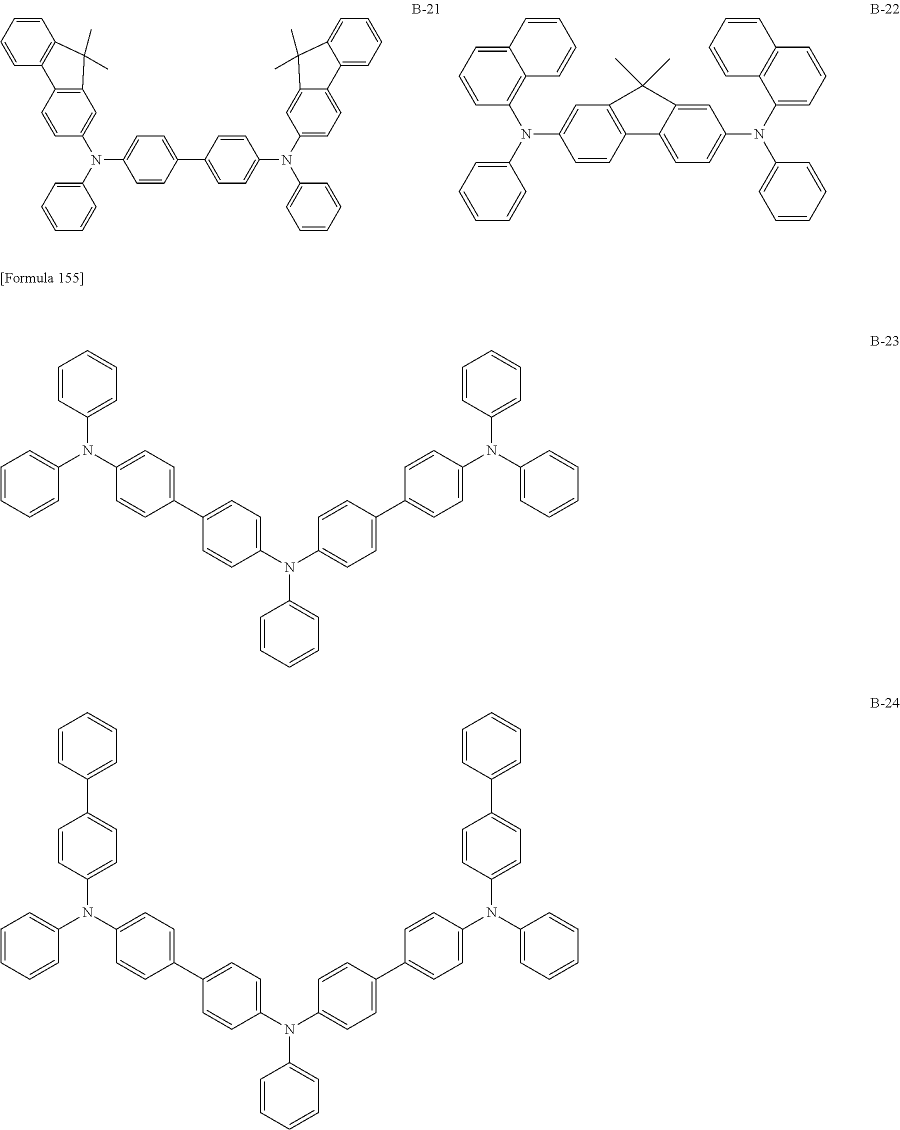 [SMILES: CC1(C)c2ccccc2-c2ccc(N(c3ccccc3)c3ccc(-c4ccc(N(c5ccccc5)c5ccc6c(c5)C(C)(C)c5ccccc5-6)cc4)cc3)cc21 ; CC1(C)c2cc(N(c3ccccc3)c3cccc4ccccc34)ccc2-c2ccc(N(c3ccccc3)c3cccc4ccccc34)cc21 ; c1ccc(N(c2ccccc2)c2ccc(-c3ccc(N(c4ccccc4)c4ccc(-c5ccc(N(c6ccccc6)c6ccccc6)cc5)cc4)cc3)cc2)cc1 ; c1ccc(-c2ccc(N(c3ccccc3)c3ccc(-c4ccc(N(c5ccccc5)c5ccc(-c6ccc(N(c7ccccc7)c7ccc(-c8ccccc8)cc7)cc6)cc5)cc4)cc3)cc2)cc1]

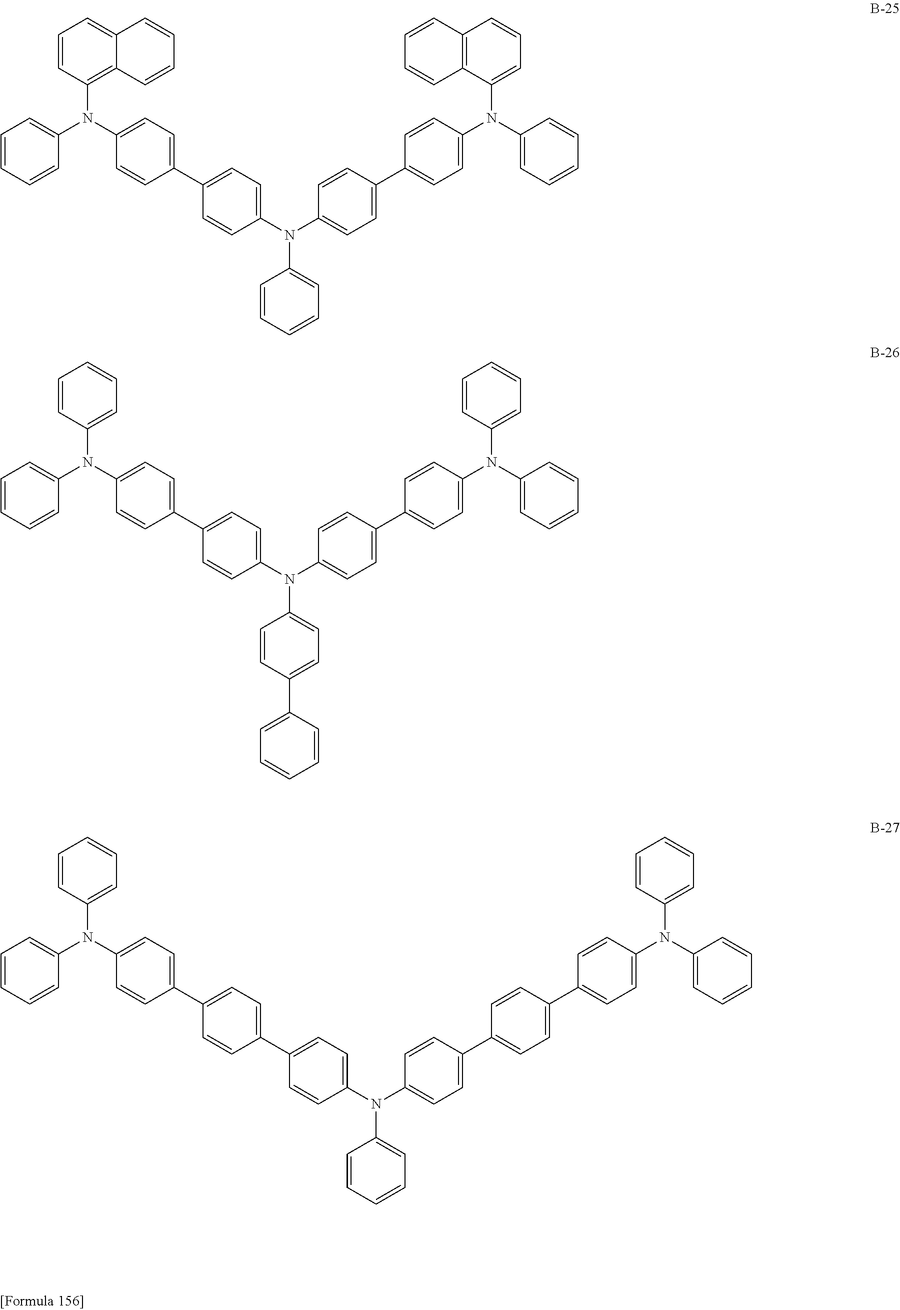 [SMILES: c1ccc(N(c2ccc(-c3ccc(N(c4ccccc4)c4cccc5ccccc45)cc3)cc2)c2ccc(-c3ccc(N(c4ccccc4)c4cccc5ccccc45)cc3)cc2)cc1 ; c1ccc(-c2ccc(N(c3ccc(-c4ccc(N(c5ccccc5)c5ccccc5)cc4)cc3)c3ccc(-c4ccc(N(c5ccccc5)c5ccccc5)cc4)cc3)cc2)cc1 ; c1ccc(N(c2ccccc2)c2ccc(-c3ccc(-c4ccc(N(c5ccccc5)c5ccc(-c6ccc(-c7ccc(N(c8ccccc8)c8ccccc8)cc7)cc6)cc5)cc4)cc3)cc2)cc1]

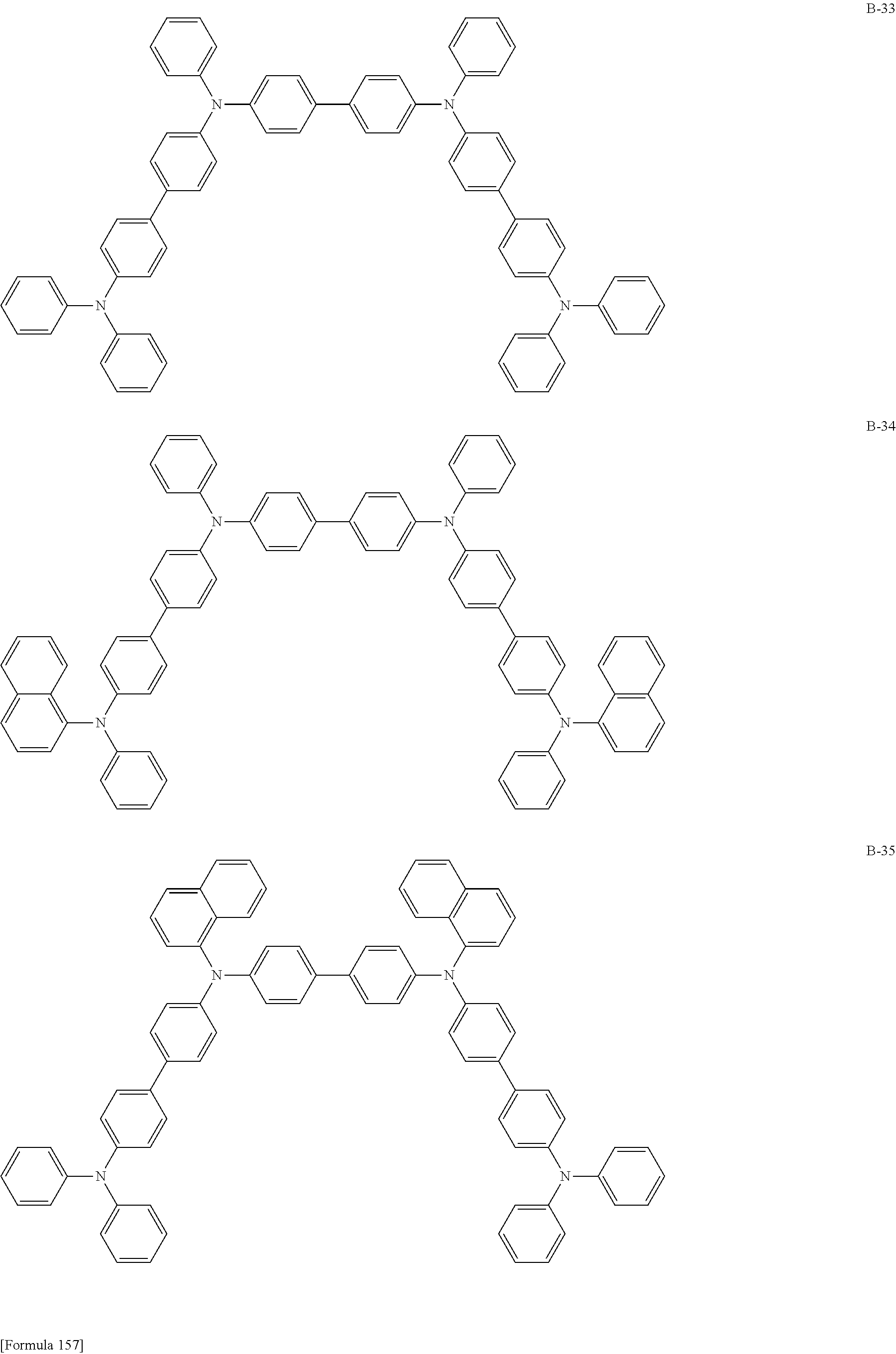 [SMILES: c1ccc(N(c2ccccc2)c2ccc(-c3ccc(N(c4ccccc4)c4ccc(-c5ccc(N(c6ccccc6)c6ccc(-c7ccc(N(c8ccccc8)c8ccccc8)cc7)cc6)cc5)cc4)cc3)cc2)cc1 ; c1ccc(N(c2ccc(-c3ccc(N(c4ccccc4)c4ccc(-c5ccc(N(c6ccccc6)c6cccc7ccccc67)cc5)cc4)cc3)cc2)c2ccc(-c3ccc(N(c4ccccc4)c4cccc5ccccc45)cc3)cc2)cc1 ; c1ccc(N(c2ccccc2)c2ccc(-c3ccc(N(c4ccc(-c5ccc(N(c6ccc(-c7ccc(N(c8ccccc8)c8ccccc8)cc7)cc6)c6cccc7ccccc67)cc5)cc4)c4cccc5ccccc45)cc3)cc2)cc1]

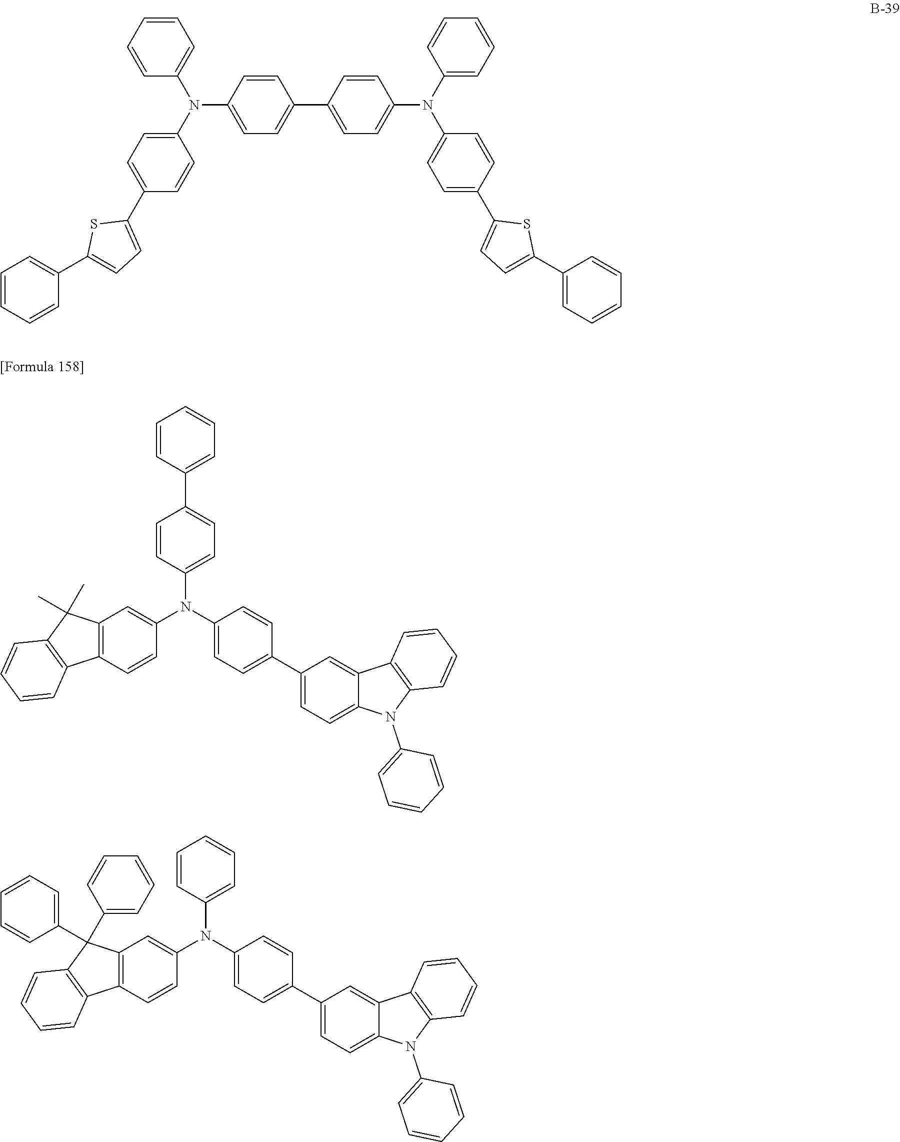 [SMILES: c1ccc(-c2ccc(-c3ccc(N(c4ccccc4)c4ccc(-c5ccc(N(c6ccccc6)c6ccc(-c7ccc(-c8ccccc8)s7)cc6)cc5)cc4)cc3)s2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc(-c3ccc4c(c3)c3ccccc3n4-c3ccccc3)cc2)c2ccc3c(c2)C(c2ccccc2)(c2ccccc2)c2ccccc2-3)cc1]

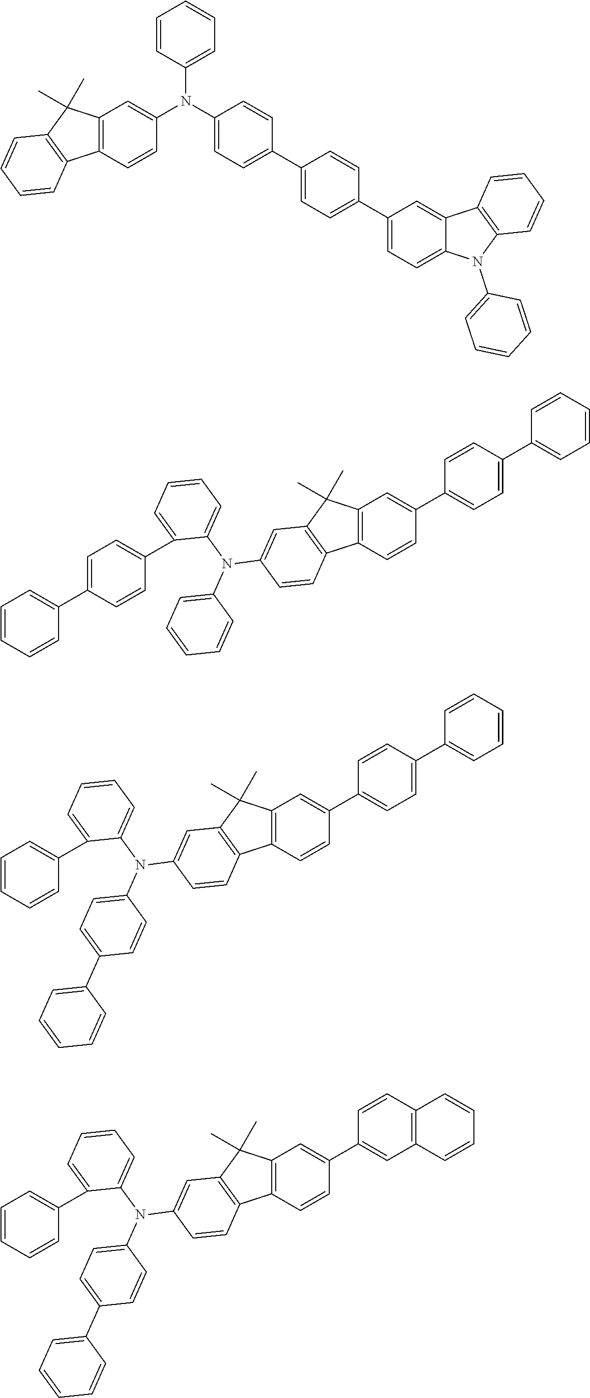 [SMILES: CC1(C)c2ccccc2-c2ccc(N(c3ccccc3)c3ccc(-c4ccc(-c5ccc6c(c5)c5ccccc5n6-c5ccccc5)cc4)cc3)cc21 ; CC1(C)c2cc(-c3ccc(-c4ccccc4)cc3)ccc2-c2ccc(N(c3ccccc3)c3ccccc3-c3ccc(-c4ccccc4)cc3)cc21 ; CC1(C)c2cc(-c3ccc(-c4ccccc4)cc3)ccc2-c2ccc(N(c3ccc(-c4ccccc4)cc3)c3ccccc3-c3ccccc3)cc21 ; CC1(C)c2cc(-c3ccc4ccccc4c3)ccc2-c2ccc(N(c3ccc(-c4ccccc4)cc3)c3ccccc3-c3ccccc3)cc21]

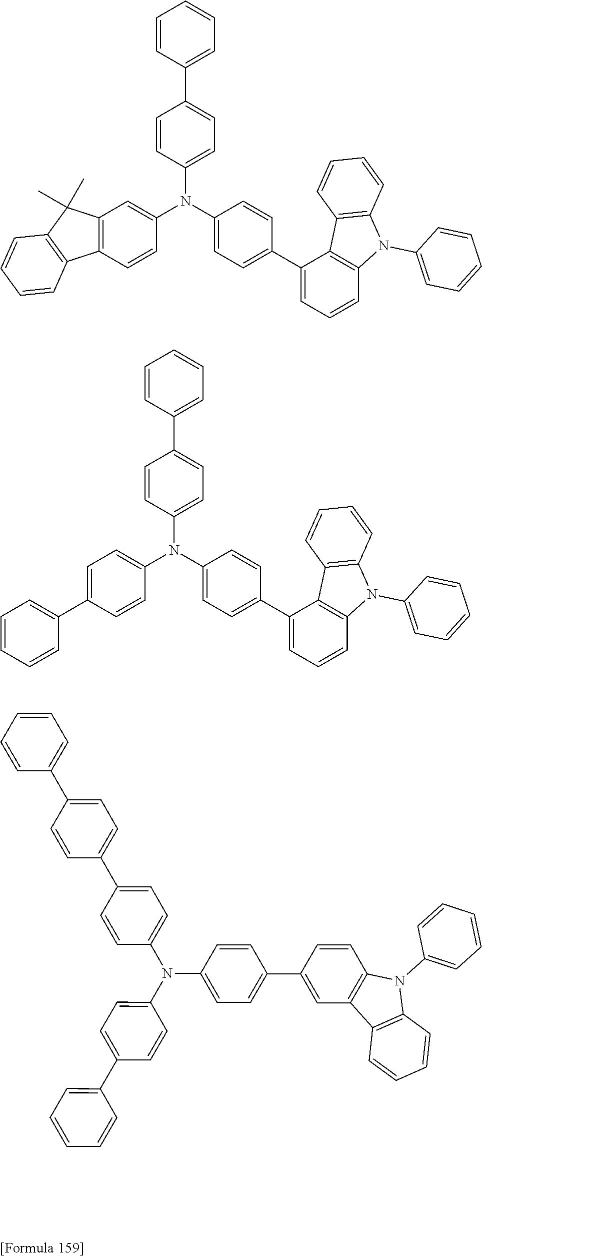 [SMILES: CC1(C)c2ccccc2-c2ccc(N(c3ccc(-c4ccccc4)cc3)c3ccc(-c4cccc5c4c4ccccc4n5-c4ccccc4)cc3)cc21 ; c1ccc(-c2ccc(N(c3ccc(-c4ccccc4)cc3)c3ccc(-c4cccc5c4c4ccccc4n5-c4ccccc4)cc3)cc2)cc1 ; c1ccc(-c2ccc(-c3ccc(N(c4ccc(-c5ccccc5)cc4)c4ccc(-c5ccc6c(c5)c5ccccc5n6-c5ccccc5)cc4)cc3)cc2)cc1]

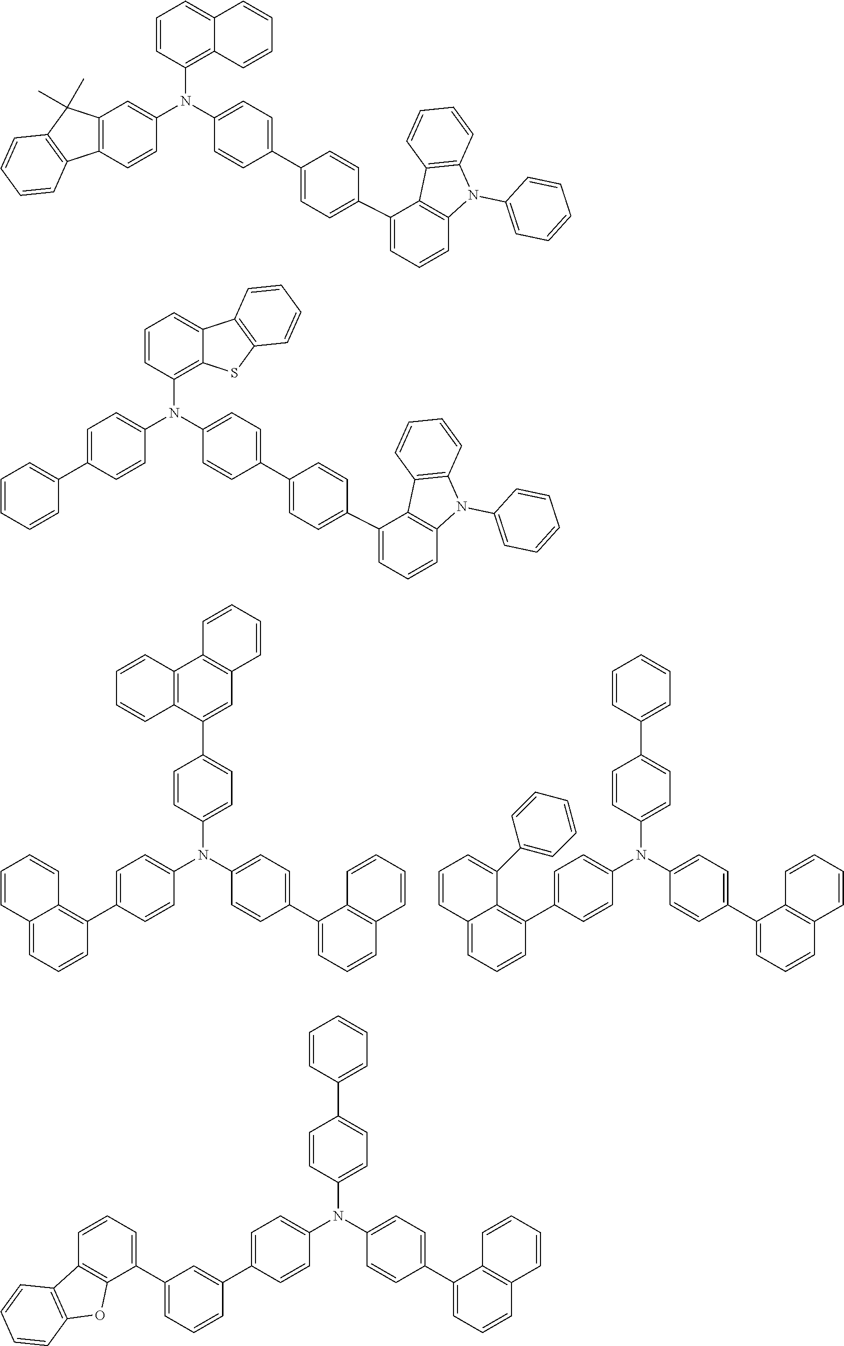

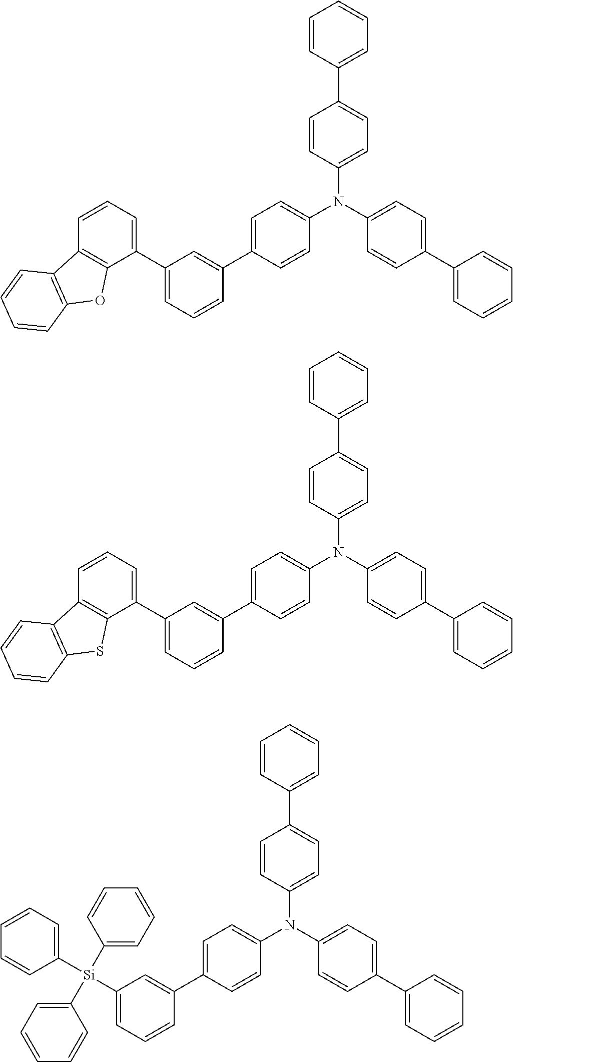 [SMILES: c1ccc(-c2ccc(N(c3ccc(-c4ccccc4)cc3)c3ccc(-c4cccc(-c5cccc6c5oc5ccccc56)c4)cc3)cc2)cc1 ; c1ccc(-c2ccc(N(c3ccc(-c4ccccc4)cc3)c3ccc(-c4cccc(-c5cccc6c5sc5ccccc56)c4)cc3)cc2)cc1 ; c1ccc(-c2ccc(N(c3ccc(-c4ccccc4)cc3)c3ccc(-c4cccc([Si](c5ccccc5)(c5ccccc5)c5ccccc5)c4)cc3)cc2)cc1]

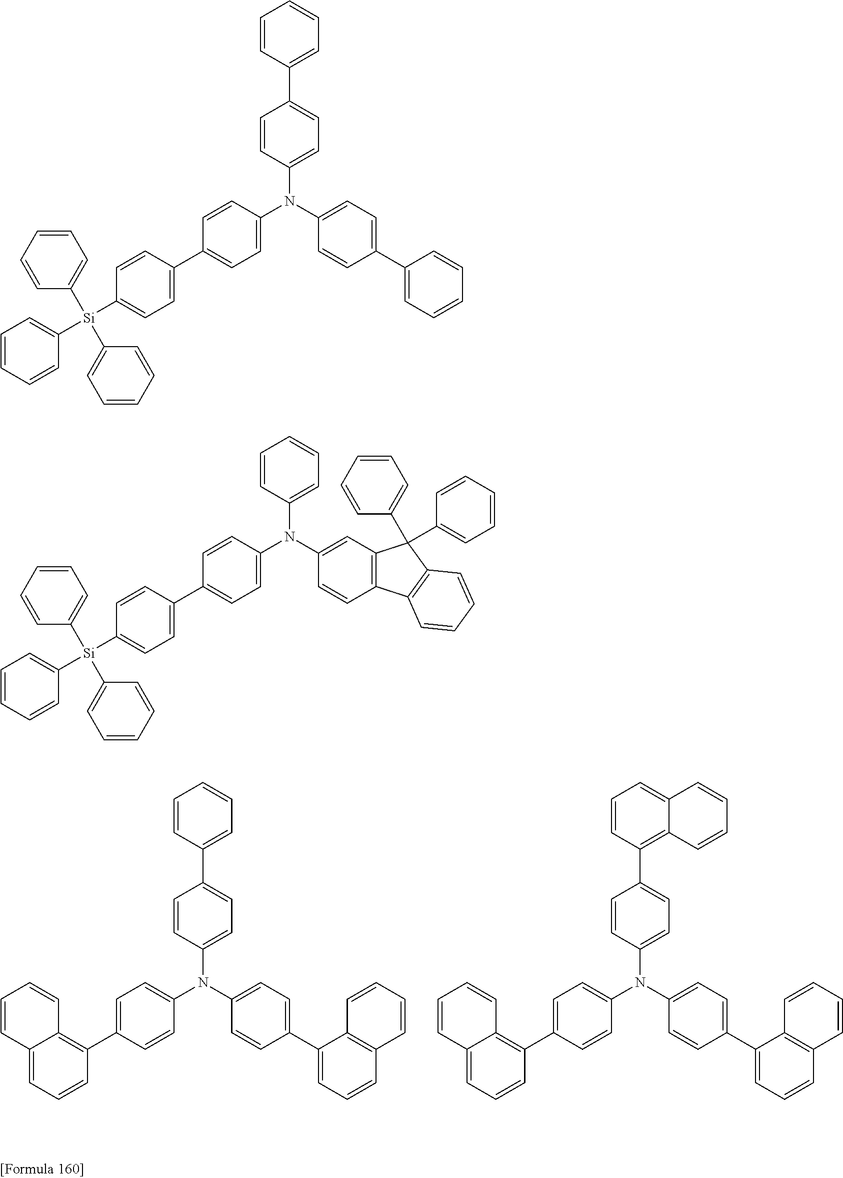

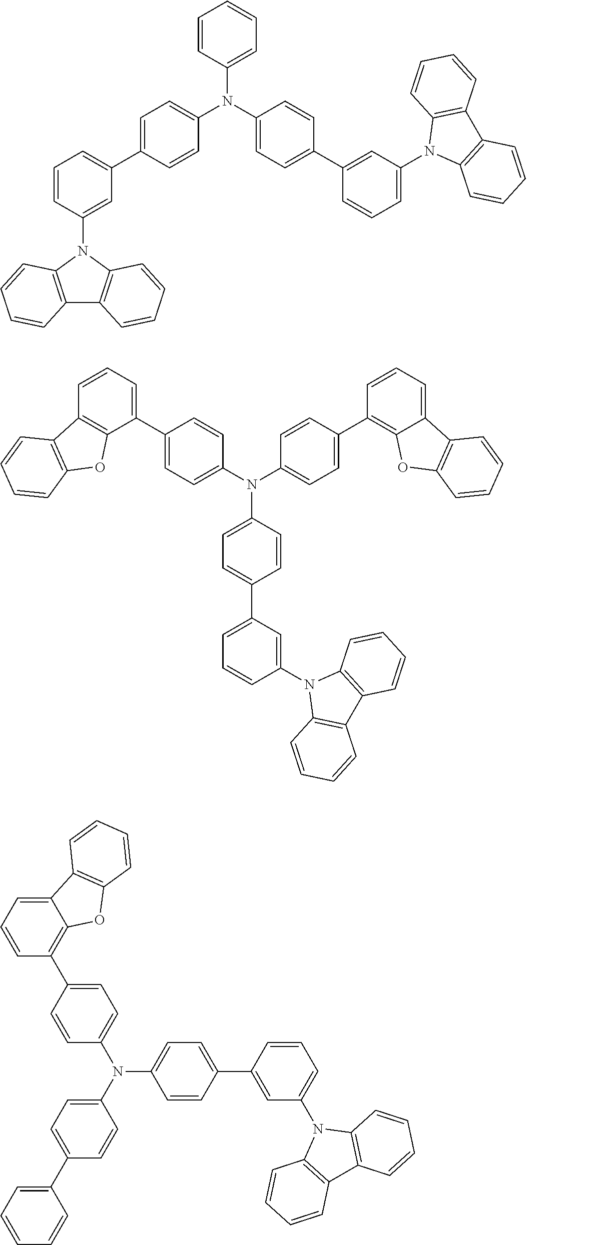

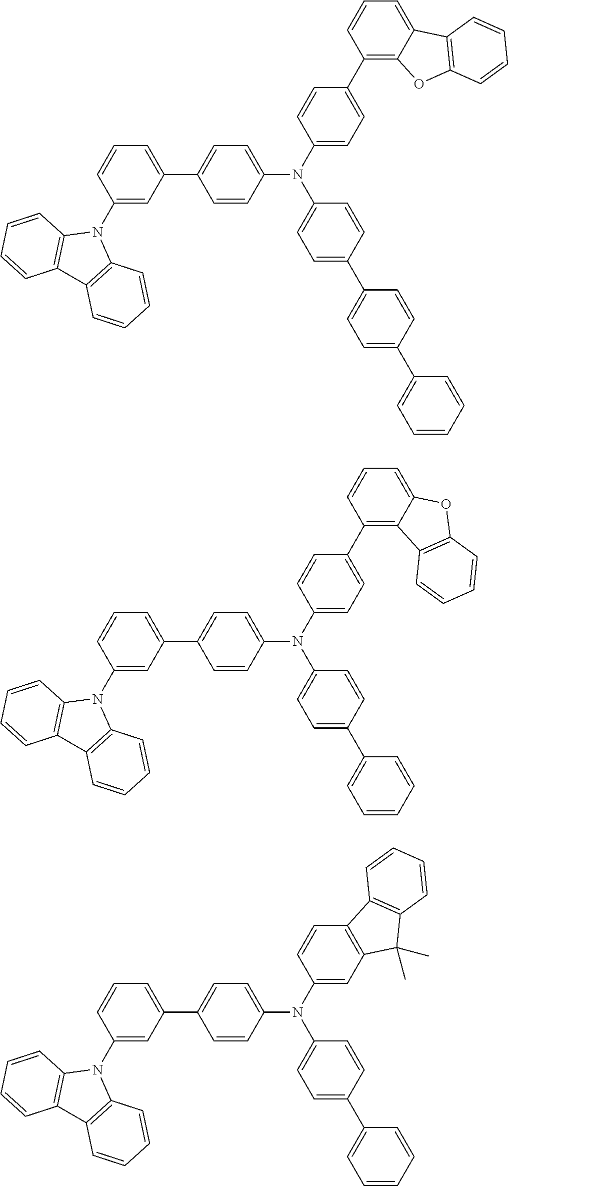

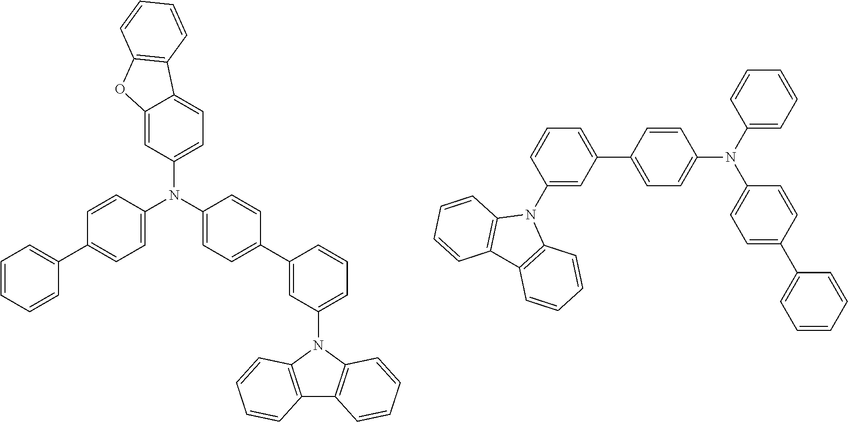 [SMILES: c1ccc(-c2ccc(N(c3ccc(-c4cccc(-n5c6ccccc6c6ccccc65)c4)cc3)c3ccc4c(c3)oc3ccccc34)cc2)cc1 ; c1ccc(-c2ccc(N(c3ccccc3)c3ccc(-c4cccc(-n5c6ccccc6c6ccccc65)c4)cc3)cc2)cc1]

In the organic EL device according to the exemplary embodiment, the triplet energy of the first host material T₁(H1) and the triplet energy of the second host material T₁(H2) preferably satisfy a relationship of a numerical formula (Numerical Formula 5) below.

T₁(H1)−T₁(H2)>0.03 eV (Numerical Formula 5)

Herein, the “host material” refers to, for instance, a material that accounts for “50 mass % or more of the layer”. That is, for instance, the first emitting layer contains 50 mass % or more of the first host material with respect to the total mass of the first emitting layer. For instance, the second emitting layer contains 50 mass % or more of the second host material with respect to the total mass of the second emitting layer.

### Emission Wavelength of Organic EL Device

The organic electroluminescence device according to the exemplary embodiment preferably emits, when being driven, light whose maximum peak wavelength is 500 nm or less.

The organic electroluminescence device according to the exemplary embodiment more preferably emits, when being driven, light whose maximum peak wavelength is in a range from 430 nm to 480 nm.

The maximum peak wavelength of the light emitted from the organic EL device when being driven is measured as follows. Voltage is applied to the organic EL device such that a current density becomes 10 mA/cm², where spectral radiance spectrum is measured by a spectroradiometer CS-2000 (produced by Konica Minolta, Inc.). A peak wavelength of an emission spectrum, at which the luminous intensity of the resultant spectral radiance spectrum is at the maximum, is measured and defined as a maximum peak wavelength (unit: nm).

### First Emitting Layer

The first emitting layer contains the first host material of which dipole is 0.4 D or more ((1.334256×10⁻³⁰° C.·m or more).

In order to facilitate the transfer of holes from the hole transporting zone to the emitting region, the dipole of the first host material is more preferably 0.5 D or more, still more preferably 0.6 D or more. The first host material having a large dipole value facilitates the transfer of carriers, which is preferable.

The first host material is a compound different from the second host material contained in the second emitting layer.

The first emitting layer contains the first emitting compound that emits light having a maximum peak wavelength of 500 nm or less. The first emitting compound preferably emits light having a maximum peak wavelength of 480 nm or less. The first emitting compound preferably emits light having a maximum peak wavelength of 430 nm or more.

The first emitting compound is preferably a fluorescent compound that emits fluorescence having a maximum peak wavelength of 500 nm or less. The first emitting compound preferably emits fluorescence having a maximum peak wavelength of 480 nm or less. The first emitting compound preferably emits fluorescence having a maximum peak wavelength of 430 nm or more.

In the organic EL device according to the exemplary embodiment, the first emitting compound is preferably a compound containing no azine ring structure in a molecule.

In the organic EL device according to the exemplary embodiment, the first emitting compound is preferably not a boron-containing complex, more preferably not a complex.

In the organic EL device according to the exemplary embodiment, the first emitting layer preferably does not contain a metal complex. In the organic EL device according to the exemplary embodiment, the first emitting layer also preferably does not contain a boron-containing complex.

In the organic EL device according to the exemplary embodiment, the first emitting layer preferably does not contain a phosphorescent material (dopant material).

In addition, the first emitting layer preferably does not contain a heavy-metal complex and a phosphorescent rare earth metal complex. Examples of the heavy-metal complex herein include iridium complex, osmium complex, and platinum complex.

A method of measuring the maximum peak wavelength of the compound is as follows. A toluene solution of a measurement target compound at a concentration of 5 μmol/L was prepared and put in a quartz cell. An emission spectrum (ordinate axis: luminous intensity, abscissa axis: wavelength) of the thus-obtained sample was measured at a normal temperature (300K). The emission spectrum can be measured using a spectrophotometer (apparatus name: F-7000) produced by Hitachi High-Tech Science Corporation. It should be noted that the apparatus for measuring the emission spectrum is not limited to the apparatus used herein.

A peak wavelength of the emission spectrum exhibiting the maximum luminous intensity is defined as the maximum peak wavelength. Herein, the maximum peak wavelength of fluorescence is occasionally referred to as a maximum fluorescence peak wavelength (FL-peak).

In an emission spectrum of the first emitting compound, where a peak exhibiting a maximum luminous intensity is defined as a maximum peak and a height of the maximum peak is defined as 1, heights of other peaks appearing in the emission spectrum are preferably less than 0.6. It should be noted that the peaks in the emission spectrum are defined as local maximum values.

Moreover, in the emission spectrum of the first emitting compound, the number of peaks is preferably less than three.

In the organic EL device according to the exemplary embodiment, the first emitting layer preferably emits light having a maximum peak wavelength of 500 nm or less when the device is driven.

The maximum peak wavelength of light emitted from the emitting layer when the device is driven can be measured by a method described below.

Maximum Peak Wavelength λp of Light Emitted from Emitting Layer when Device is Driven

For a maximum peak wavelength Δp₁ of light emitted from the first emitting layer when the organic EL device is driven, the organic EL device is produced by using the material of the first emitting layer for the first emitting layer and the second emitting layer, and voltage is applied to the organic EL device so that a current density becomes 10 mA/cm², where spectral radiance spectrum is measured by a spectroradiometer CS-2000 (produced by Konica Minolta, Inc.). The maximum peak wavelength λp₁ (unit: nm) is calculated from the obtained spectral radiance spectrum.

For a maximum peak wavelength Δp₂ of light emitted from the second emitting layer when the organic EL device is driven, the organic EL device is produced by using the material of the second emitting layer for the first emitting layer and the second emitting layer, and voltage is applied to the organic EL device so that a current density of the device is 10 mA/cm², where spectral radiance spectrum is measured by a spectroradiometer CS-2000 (produced by Konica Minolta, Inc.). The maximum peak wavelength Δp₂ (unit: nm) is calculated from the obtained spectral radiance spectrum.

In the organic EL device according to the exemplary embodiment, a singlet energy of the first host material S₁(H1) and a singlet energy of the first emitting compound S₁(D1) preferably satisfy a relationship of a numerical formula (Numerical Formula 20) below.

S₁(H1)>S₁(D1) (Numerical Formula 20)

The singlet energy S₁ means an energy difference between the lowest singlet state and the ground state.

When the first host material and the first emitting compound satisfy the relationship of the numerical formula (Numerical Formula 20), singlet excitons generated on the first host material easily energy-transfer from the first host material to the first emitting compound, thereby contributing to emission (preferably fluorescence) of the first emitting compound.

In the organic EL device according to the exemplary embodiment, the triplet energy of the first host material T₁(H1) and a triplet energy of the first emitting compound T₁(D1) preferably satisfy a relationship of a numerical formula (Numerical Formula 20A) below.

T₁(D1)>T₁(H1) (Numerical Formula 20A)

When the first host material and the first emitting compound satisfy the relationship of the numerical formula (Numerical Formula 20A), triplet excitons generated in the first emitting layer are transferred not onto the first emitting compound having higher triplet energy but onto the first host material, thereby being easily transferred to the second emitting layer.

The organic EL device according to the exemplary embodiment preferably satisfies a relationship of a numerical formula (Numerical Formula 20B) below.

T₁(D1)>T₁(H1)>T₁(H2) (Numerical Formula 20B)

### Triplet Energy T₁

A method of measuring triplet energy T₁ is exemplified by a method below.

A measurement target compound is dissolved in EPA (diethylether:isopentane:ethanol=5:5:2 in volume ratio) so as to fall within a range from 10⁻⁵ mol/L to 10⁻⁴ mol/L, and the obtained solution is encapsulated in a quartz cell to provide a measurement sample. A phosphorescence spectrum (ordinate axis: phosphorescent luminous intensity, abscissa axis: wavelength) of the measurement sample was measured at a low temperature (77K). A tangent was drawn to the rise of the phosphorescence spectrum close to the short-wavelength region. An energy amount was calculated by a conversion equation (F1) below on a basis of a wavelength value λ_{edge} [nm] at an intersection of the tangent and the abscissa axis. The calculated energy amount is defined as triplet energy T₁.

T₁ [eV]=1239.85/λ_{edge} Conversion Equation (F1):

The tangent to the rise of the phosphorescence spectrum close to the short-wavelength region is drawn as follows. While moving on a curve of the phosphorescence spectrum from the short-wavelength region to the local maximum value closest to the short-wavelength region among the local maximum values of the phosphorescence spectrum, a tangent is checked at each point on the curve toward the long-wavelength of the phosphorescence spectrum. An inclination of the tangent is increased along the rise of the curve (i.e., a value of the ordinate axis is increased). A tangent drawn at a point of the local maximum inclination (i.e., a tangent at an inflection point) is defined as the tangent to the rise of the phosphorescence spectrum close to the short-wavelength region.

A local maximum point where a peak intensity is 15% or less of the maximum peak intensity of the spectrum is not counted as the above-mentioned local maximum peak intensity closest to the short-wavelength region. The tangent drawn at a point that is closest to the local maximum peak intensity closest to the short-wavelength region and where the inclination of the curve is the local maximum is defined as a tangent to the rise of the phosphorescence spectrum close to the short-wavelength region.

For phosphorescence measurement, a spectrophotofluorometer body F-4500 (produced by Hitachi High-Technologies Corporation) is usable. The measurement apparatus is not limited to this arrangement. A combination of a cooling unit, a low temperature container, an excitation light source and a light-receiving unit may be used for measurement.

### Singlet Energy S₁

A method of measuring a singlet energy S₁ with use of a solution (occasionally referred to as a solution method) is exemplified by a method below.

A toluene solution of a measurement target compound at a concentration ranging from 10⁻⁵ mol/L to 10⁻⁴ mol/L is prepared and put in a quartz cell. An absorption spectrum (ordinate axis: absorption intensity, abscissa axis: wavelength) of the thus-obtained sample is measured at a normal temperature (300K). A tangent is drawn to the fall of the absorption spectrum close to the long-wavelength region, and a wavelength value λ_{edge} [nm] at an intersection of the tangent and the abscissa axis is assigned to a conversion equation (F2) below to calculate singlet energy.

S₁ [eV]=1239.85/λ_{edge} Conversion Equation (F2):

Any apparatus for measuring the absorption spectrum is usable. For instance, a spectrophotometer (U3310 produced by Hitachi, Ltd.) is usable.

The tangent to the fall of the absorption spectrum close to the long-wavelength region is drawn as follows. While moving on a curve of the absorption spectrum from the local maximum value closest to the long-wavelength region, among the local maximum values of the absorption spectrum, in a long-wavelength direction, a tangent at each point on the curve is checked. An inclination of the tangent is decreased and increased in a repeated manner as the curve falls (i.e., a value of the ordinate axis is decreased). A tangent drawn at a point where the inclination of the curve is the local minimum closest to the long-wavelength region (except when absorbance is 0.1 or less) is defined as the tangent to the fall of the absorption spectrum close to the long-wavelength region.

The local maximum absorbance of 0.2 or less is not counted as the above-mentioned local maximum absorbance closest to the long-wavelength region.

In the organic EL device according to the exemplary embodiment, the first emitting compound is preferably contained at 1.0 mass % or more in the first emitting layer. Specifically, the first emitting layer contains the first emitting compound preferably at 1.0 mass % or more, more preferably at exceeding 1.1 mass %, still more preferably at 1.2 mass % or more, and still further more preferably at 1.5 mass % or more, with respect to the total mass of the first emitting layer.

The first emitting layer contains the first emitting compound preferably at 10 mass % or less, more preferably at 7 mass % or less, and still more preferably at 5 mass % less, with respect to the total mass of the first emitting layer.

In the organic EL device according to the exemplary embodiment, the first emitting layer contains the first host material preferably at 60 mass % or more, more preferably at 70 mass % or more, still more preferably at 80 mass % or more, still further more preferably at 90 mass % or more, and yet still further more preferably at 95 mass % or more, with respect to the total mass of the first emitting layer.

The first emitting layer preferably contains the first host material at 99 mass % or less with respect to the total mass of the first emitting layer.

When the first emitting layer contains the first host material and the first emitting compound, the upper limit of the total of the content ratios of the first host material and the first emitting compound is 100 mass %.

The first emitting layer of the exemplary embodiment may further contain any other material than the first host material and the first emitting compound.

The first emitting layer may contain a single type of the first host material or may contain two or more types of the first host material. The first emitting layer may contain a single type of the first emitting compound or may contain two or more types of the first emitting compound.

In the organic EL device according to the exemplary embodiment, the film thickness of the first emitting layer is preferably 3 nm or more, more preferably 5 nm or more. A film thickness of 3 nm or more of the first emitting layer is sufficient for causing recombination of holes and electrons in the first emitting layer.

In the organic EL device according to the exemplary embodiment, the film thickness of the first emitting layer is preferably 15 nm or less, more preferably 10 nm or less. A film thickness of 15 nm or less of the first emitting layer is thin enough for transfer of triplet excitons to the second emitting layer.

In the organic EL device according to the exemplary embodiment, the film thickness of the first emitting layer is more preferably in a range from 3 nm to 15 nm.

In the organic EL device according to the exemplary embodiment, the first emitting layer may contain a compound represented by a formula (HT100) below.

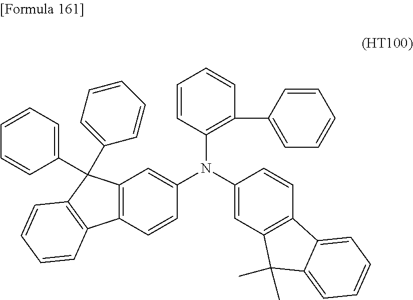 [SMILES: CC1(C)c2ccccc2-c2ccc(N(c3ccc4c(c3)C(c3ccccc3)(c3ccccc3)c3ccccc3-4)c3ccccc3-c3ccccc3)cc21]

In the organic EL device according to the exemplary embodiment, the first emitting layer may contain the hole transporting zone material according to the exemplary embodiment.

### Second Emitting Layer

The second emitting layer contains the second host material and the second emitting compound that emits light having a maximum peak wavelength of 500 nm or less. The second host material is a compound different from the first host material contained in the first emitting layer. The second emitting compound preferably emits light having a maximum peak wavelength of 480 nm or less. The second emitting compound preferably emits light having a maximum peak wavelength of 430 nm or more.

The second emitting compound contained in the second emitting layer is preferably a fluorescent compound that emits fluorescence having a maximum peak wavelength of 500 nm or less. The second emitting compound preferably emits fluorescence having a maximum peak wavelength of 480 nm or less. The second emitting compound preferably emits fluorescence having a maximum peak wavelength of 430 nm or more.

A method of measuring the maximum peak wavelength of the compound is as follows.

In the organic EL device according to the exemplary embodiment, the second emitting layer preferably emits light having a maximum peak wavelength of 500 nm or less when the device is driven.

In the organic EL device according to the exemplary embodiment, the full width at half maximum of a maximum peak of the second emitting compound is preferably in a range from 1 nm to 20 nm.

In the organic EL device according to the exemplary embodiment, a Stokes shift of the second emitting compound preferably exceeds 7 nm.

When the Stokes shift of the second emitting compound exceeds 7 nm, a decrease in luminous efficiency due to self-absorption is easily inhibited.

The self-absorption is a phenomenon in which emitted light is absorbed by the same compound to reduce luminous efficiency. The self-absorption is notably observed in a compound having a small Stokes shift (i.e., a large overlap between an absorption spectrum and a fluorescence spectrum). Accordingly, in order to reduce the self-absorption, it is preferable to use a compound having a large Stokes shift (i.e., a small overlap between the absorption spectrum and the fluorescence spectrum). The Stokes shift can be measured by a method described below.

A measurement target compound is dissolved in toluene at a concentration of 2.0×10⁻⁵ mol/L to prepare a measurement sample. The measurement sample is put into a quartz cell and is irradiated with continuous light falling within an ultraviolet-to-visible region at a room temperature (300K) to measure an absorption spectrum (ordinate axis: absorbance, abscissa axis: wavelength). A spectrophotometer U-3900/3900H produced by Hitachi High-Tech Science Corporation is usable for the absorption spectrum measurement. A measurement target compound is dissolved in toluene at a concentration of 4.9×10⁻⁶ mol/L to prepare a measurement sample. The measurement sample was put into a quartz cell and was irradiated with excited light at a room temperature (300K) to measure a fluorescence spectrum (ordinate axis: fluorescence intensity, abscissa axis: wavelength). A spectrophotofluorometer F-7000 produced by Hitachi High-Tech Science Corporation is usable for the fluorescence spectrum measurement.

A difference between an absorption local-maximum wavelength and a fluorescence local-maximum wavelength is calculated from the absorption spectrum and the fluorescence spectrum to obtain a Stokes shift (SS). A unit of the Stokes shift (SS) is denoted by nm.

In the organic EL device according to the exemplary embodiment, a triplet energy of the second emitting compound T₁(D₂) and the triplet energy of the second host material T₁(H2) preferably satisfy a relationship of a numerical formula (Numerical Formula 3A) below.

T₁(D₂)>T₁(H2) (Numerical Formula 3A)

In the organic EL device according to the exemplary embodiment, when the second emitting compound and the second host material satisfy the relationship of the numerical formula (Numerical Formula 3A), in transfer of triplet excitons generated in the first emitting layer to the second emitting layer, the triplet excitons energy-transfer not onto the second emitting compound having higher triplet energy but onto molecules of the second host material. In addition, triplet excitons generated by recombination of holes and electrons on the second host material do not transfer to the second emitting compound having higher triplet energy. Triplet excitons generated by recombination on molecules of the second emitting compound quickly energy-transfer to molecules of the second host material.

Triplet excitons in the second host material do not transfer to the second emitting compound but efficiently collide with one another on the second host material to generate singlet excitons by the TTF phenomenon.

In the organic EL device according to the exemplary embodiment, a singlet energy of the second host material S₁(H2) and a singlet energy of the second emitting compound S₁(D₂) preferably satisfy a relationship of a numerical formula (Numerical Formula 4) below.

S₁(H2)>S₁(D2) (Numerical Formula 4)

In the organic EL device according to the exemplary embodiment, when the second emitting compound and the second host material satisfy the relationship of the numerical formula (Numerical Formula 4), due to the singlet energy of the second emitting compound being smaller than the singlet energy of the second host material, singlet excitons generated by the TTF phenomenon energy-transfer from the second host material to the second emitting compound, thereby contributing to light emission (preferably fluorescence) of the second emitting compound.

In the organic EL device according to the exemplary embodiment, the second emitting compound is preferably a compound containing no azine ring structure in a molecule.

In the organic EL device according to the exemplary embodiment, the second emitting compound is preferably not a boron-containing complex, more preferably not a complex.

In the organic EL device according to the exemplary embodiment, the second emitting layer preferably does not contain a metal complex. In the organic EL device according to the exemplary embodiment, the second emitting layer also preferably does not contain a boron-containing complex.

In the organic EL device according to the exemplary embodiment, the second emitting layer preferably does not contain a phosphorescent material (dopant material).

Further, the second emitting layer preferably does not contain a heavy-metal complex and a phosphorescent rare earth metal complex. Examples of the heavy-metal complex herein include iridium complex, osmium complex, and platinum complex.

In the organic EL device according to the exemplary embodiment, the second emitting compound is preferably contained at 1.0 mass % or more in the second emitting layer. Specifically, the second emitting layer contains the second emitting compound preferably at 1.0 mass % or more, more preferably at exceeding 1.1 mass %, still more preferably at 1.2 mass % or more, and still further more preferably at 1.5 mass % or more, with respect to the total mass of the second emitting layer.

The second emitting layer contains the second emitting compound preferably at 10 mass % or less, more preferably at 7 mass % or less, and still more preferably at 5 mass % less with respect to the total mass of the second emitting layer.

The second emitting layer contains the second host material preferably at 60 mass % or more, more preferably at 70 mass % or more, still more preferably at 80 mass % or more, still further more preferably at 90 mass % or more, and yet still further more preferably at 95 mass % or more, with respect to the total mass of the second emitting layer.

The second emitting layer preferably contains the second host material at 99 mass % or less with respect to the total mass of the second emitting layer.

When the second emitting layer contains the second host material and the second emitting compound, the upper limit of the total of the content ratios of the second host material and the second emitting compound is 100 mass %.

The second emitting layer of the exemplary embodiment may further contain any other material than the second host material and the second emitting compound.

The second emitting layer may contain a single type of the second host material or may contain two or more types of the second host material. The second emitting layer may contain a single type of the second emitting compound or may contain two or more types of the second emitting compound.

In the organic EL device according to the exemplary embodiment, a film thickness of the second emitting layer is preferably 5 nm or more, more preferably 15 nm or more. When the film thickness of the second emitting layer is 5 nm or more, it is easy to inhibit triplet excitons having transferred from the first emitting layer to the second emitting layer from returning to the first emitting layer. Further, when the film thickness of the second emitting layer is 5 nm or more, triplet excitons can be sufficiently separated from the recombination portion in the first emitting layer.

In the organic EL device according to the exemplary embodiment, the film thickness of the second emitting layer is preferably 20 nm or less. When the film thickness of the second emitting layer is 20 nm or less, a density of the triplet excitons in the second emitting layer is improved to cause the TTF phenomenon more easily.

In the organic EL device according to the exemplary embodiment, the film thickness of the second emitting layer is preferably in a range from 5 nm to 20 nm.

In the organic EL device according to the exemplary embodiment, the triplet energy of the first host material T₁(H1) preferably satisfies a relationship of a numerical formula (Numerical Formula 12) below.

T₁(H1)>2.0 eV (Numerical Formula 12)

In the organic EL device according to the exemplary embodiment, the triplet energy of the first host material T₁(H1) preferably satisfies a relationship of a numerical formula (Numerical Formula 12A) below, or also preferably satisfies a relationship of a numerical formula (Numerical Formula 12B) below.

T₁(H1)>2.10 eV (Numerical Formula 12A)

T₁(H1)>2.15 eV (Numerical Formula 12B)

In the organic EL device according to the exemplary embodiment, when the triplet energy of the first host material T₁(H1) satisfies the relationship of the numerical formula (Numerical Formula 12A) or the numerical formula (Numerical Formula 12B), triplet excitons generated in the first emitting layer easily transfer to the second emitting layer, and also are easily inhibited from back-transferring from the second emitting layer to the first emitting layer. Consequently, singlet excitons are efficiently generated in the second emitting layer, thereby improving luminous efficiency.

In the organic EL device according to the exemplary embodiment, the triplet energy of the first host material T₁(H1) also preferably satisfies a relationship of a numerical formula (Numerical Formula 12C) below, or also preferably satisfies a relationship of a numerical formula (Numerical Formula 12D) below.

2.08 eV>T₁(H1)>1.87 eV (Numerical Formula 12C)

2.05 eV>T₁(H1)>1.90 eV (Numerical Formula 12D)

In the organic EL device according to the exemplary embodiment, when the triplet energy of the first host material T₁(H1) satisfies the relationship of the numerical formula (Numerical Formula 12C) or the numerical formula (Numerical Formula 12D), the energy of triplet excitons generated in the first emitting layer is reduced. The organic EL device of the exemplary embodiment can thus be expected to have a long lifetime.

In the organic EL device according to the exemplary embodiment, the triplet energy of the first emitting compound T₁(D1) also preferably satisfies a relationship of a numerical formula (Numerical Formula 14AX) below, a relationship of a numerical formula (Numerical Formula 14A) below, or a relationship of a numerical formula (Numerical Formula 14B) below.

2.70 eV>T₁(D1) (Numerical Formula 14AX)

2.60 eV>T₁(D1) (Numerical Formula 14A)

2.50 eV>T₁(D1) (Numerical Formula 14B)

The organic EL device has a long lifetime when the first emitting layer contains the first emitting compound that satisfies the relationship of the numerical formula (Numerical Formula 14AX), (Numerical Formula 14A), or (Numerical Formula 14B).

In the organic EL device according to the exemplary embodiment, the triplet energy of the second emitting compound T₁(D₂) also preferably satisfies a relationship of a numerical formula (Numerical Formula 14CX) below, a relationship of a numerical formula (Numerical Formula 14C) below, or a relationship of a numerical formula (Numerical Formula 14D) below.

2.70 eV>T₁(D₂) (Numerical Formula 14CX)

2.60 eV>T₁(D₂) (Numerical Formula 14C)

2.50 eV>T₁(D₂) (Numerical Formula 14D)

The organic EL device has a long lifetime when the second emitting layer contains the compound that satisfies the relationship of the numerical formula (Numerical Formula 14CX), (Numerical Formula 14C), or (Numerical Formula 14D).

In the organic EL device according to the exemplary embodiment, the triplet energy of the second host material T₁(H2) preferably satisfies a relationship of a numerical formula (Numerical Formula 13X) below, or also preferably satisfies a relationship of a numerical formula (Numerical Formula 13) below.

T₁(H2)≥1.8 eV (Numerical Formula 13X)

T₁(H2)≥1.9 eV (Numerical Formula 13)

### Additional Layers of Organic EL Device

In addition to the hole transporting zone, the first emitting layer and the second emitting layer, the organic EL device according to the exemplary embodiment may include one or more organic layers. Examples of the organic layer include at least one layer selected from the group consisting of an electron injecting layer, an electron transporting layer, a hole blocking layer, and an electron blocking layer.

In the organic EL device according to the exemplary embodiment, only the hole transporting zone, the first emitting layer, and the second emitting layer may be included as the organic layers. Alternatively, for instance, at least one layer selected from the group consisting of the electron injecting layer, the electron transporting layer, and the hole blocking layer may be further included as the organic layer.

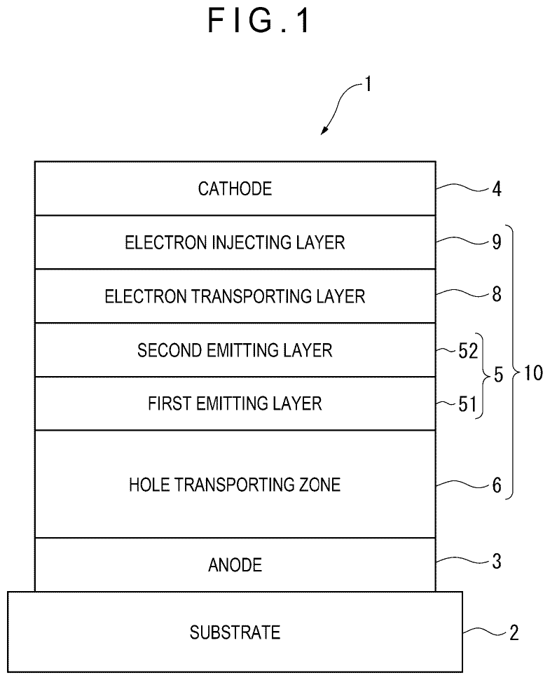

FIG. 1 schematically depicts an exemplary arrangement of the organic EL device of the exemplary embodiment.

An organic EL device 1 includes a substrate 2, an anode 3, a cathode 4, and organic layers 10 provided between the anode 3 and the cathode 4. The organic layers 10 include a hole transporting zone 6, a first emitting layer 51, a second emitting layer 52, an electron transporting layer 8, and an electron injecting layer 9 that are layered on the anode 3 in this order. An emitting region 5 includes the first emitting layer 51 and the second emitting layer 52.

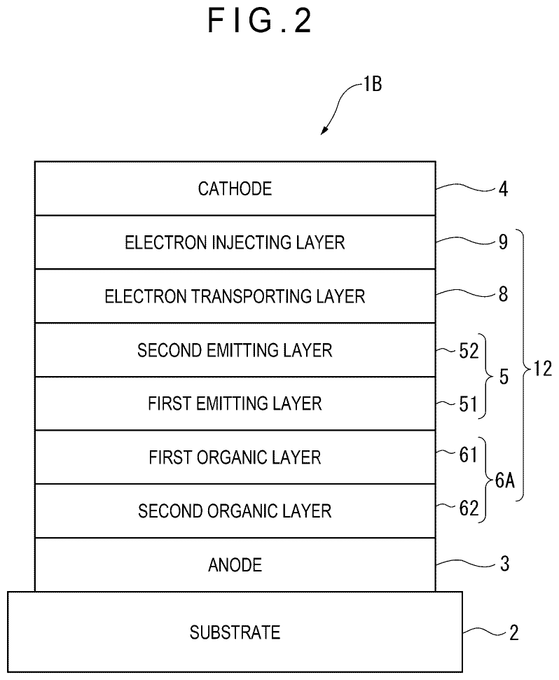

FIG. 2 schematically depicts another exemplary arrangement of the organic EL device according to the exemplary embodiment.

An organic EL device 1B includes the substrate 2, the anode 3, the cathode 4, and organic layers 12 provided between the anode 3 and the cathode 4. The organic layers 12 include a second organic layer 62, a first organic layer 61, the first emitting layer 51, the second emitting layer 52, the electron transporting layer 8, and the electron injecting layer 9 that are layered on the anode 3 in this order. In the organic EL device 1B, a hole transporting zone 6A includes the first organic layer 61 and the second organic layer 62.

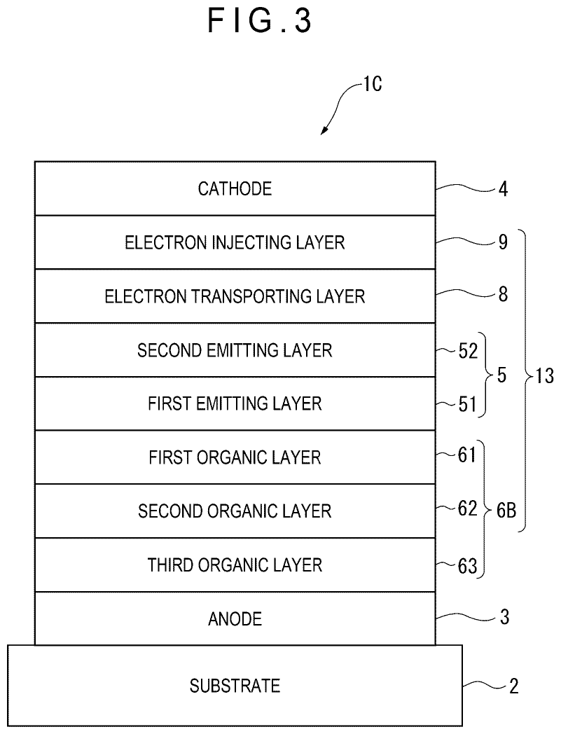

FIG. 3 schematically depicts still another exemplary arrangement of the organic EL device according to the exemplary embodiment.

An organic EL device 1C includes the substrate 2, the anode 3, the cathode 4, and organic layers 13 provided between the anode 3 and the cathode 4. The organic layers 13 include a third organic layer 63, the second organic layer 62, the first organic layer 61, the first emitting layer 51, the second emitting layer 52, the electron transporting layer 8, and the electron injecting layer 9 that are layered in this order on the anode 3. In the organic EL device 1C, a hole transporting zone 6B includes the first organic layer 61, the second organic layer 62, and the third organic layer 63.

Also in the organic EL devices illustrated in FIGS. 2 and 3, using a material with a large dipole (0.4 D or more) as the first host material contained in the first emitting layer facilitates the transfer of holes from the hole transporting zone to the emitting region. This makes it easy to achieve high efficiency even in a layer-saving arrangement of the hole transporting zone in which the supply amount of holes to the emitting region is likely to be insufficient.

The invention is not limited to the exemplary arrangements of the organic EL devices depicted in FIGS. 1 to 3.

In the organic EL device according to the exemplary embodiment, the first emitting layer and the second emitting layer may be in direct contact with each other.

Herein, a layer arrangement in which “the first emitting layer and the second emitting layer are in direct contact with each other” may include one of embodiments (LS1), (LS2), and (LS3) below.

(LS1) An embodiment in which a region containing both the first host material and the second host material is generated in a process of vapor-depositing the compound of the first emitting layer and vapor-depositing the compound of the second emitting layer, and is present on the interface between the first emitting layer and the second emitting layer.

(LS2) An embodiment in which in a case of containing an emitting compound in the first emitting layer and the second emitting layer, a region containing the first host material, the second host material and the emitting compound is generated in a process of vapor-depositing the compound of the first emitting layer and vapor-depositing the compound of the second emitting layer, and is present on the interface between the first emitting layer and the second emitting layer.

(LS3) An embodiment in which in a case of containing an emitting compound in the first emitting layer and the second emitting layer, a region containing the emitting compound, a region containing the first host material or a region containing the second host material is generated in a process of vapor-depositing the compound of the first emitting layer and vapor-depositing the compound of the second emitting layer, and is present on the interface between the first emitting layer and the second emitting layer.

The arrangement of the organic EL device will be further described below. It should be noted that the reference numerals are occasionally omitted below.

### Substrate

The substrate is used as a support for the organic EL device. For instance, glass, quartz, plastics and the like are usable for the substrate. A flexible substrate is also usable. The flexible substrate, which is a bendable substrate, is exemplified by a plastic substrate. Examples of a material for the flexible substrate include polycarbonate, polyarylate, polyethersulfone, polypropylene, polyester, polyvinyl fluoride, polyvinyl chloride, polyimide, and polyethylene naphthalate. Further, an inorganic vapor deposition film is also usable.

### Anode

Metal, an alloy, an electrically conductive compound, a mixture thereof, or the like having a large work function (specifically, 4.0 eV or more) is preferably used as the anode formed on the substrate. Specific examples of the material include indium tin oxide (ITO), indium oxide-tin oxide containing silicon or silicon oxide, indium oxide-zinc oxide, indium oxide containing tungsten oxide and zinc oxide, and graphene. In addition, gold (Au), platinum (Pt), nickel (Ni), tungsten (W), chrome (Cr), molybdenum (Mo), iron (Fe), cobalt (Co), copper (Cu), palladium (Pd), titanium (Ti), and nitrides of a metal material (e.g., titanium nitride) are usable.

The material is typically formed into a film by a sputtering method. For instance, the indium oxide-zinc oxide can be formed into a film by the sputtering method using a target in which zinc oxide in a range from 1 mass % to 10 mass % is added to indium oxide. Moreover, for instance, the indium oxide containing tungsten oxide and zinc oxide can be formed by the sputtering method using a target in which tungsten oxide in a range from 0.5 mass % to 5 mass % and zinc oxide in a range from 0.1 mass % to 1 mass % are added to indium oxide. In addition, the anode may be formed by a vacuum deposition method, a coating method, an inkjet method, a spin coating method or the like.

Among the EL layers formed on the anode, since the hole injecting layer adjacent to the anode is formed of a composite material into which holes are easily injectable irrespective of the work function of the anode, a material usable as an electrode material (e.g., metal, an alloy, an electroconductive compound, a mixture thereof, and the elements belonging to the group 1 or 2 of the periodic table) is also usable for the anode.

A material having a small work function such as elements belonging to Groups 1 and 2 in the periodic table of the elements, specifically, an alkali metal such as lithium (Li) and cesium (Cs), an alkaline earth metal such as magnesium (Mg), calcium (Ca) and strontium (Sr), alloys (e.g., MgAg and AlLi) including the alkali metal or the alkaline earth metal, a rare earth metal such as europium (Eu) and ytterbium (Yb), alloys including the rare earth metal are also usable for the anode. It should be noted that the vacuum deposition method and the sputtering method are usable for forming the anode using the alkali metal, alkaline earth metal and the alloy thereof. Further, when a silver paste is used for the anode, the coating method and the inkjet method are usable.

### Cathode

It is preferable to use metal, an alloy, an electroconductive compound, a mixture thereof, or the like having a small work function (specifically, 3.8 eV or less) for the cathode. Examples of the material for the cathode include elements belonging to Groups 1 and 2 in the periodic table of the elements, specifically, an alkali metal such as lithium (Li) and cesium (Cs), an alkaline earth metal such as magnesium (Mg), calcium (Ca) and strontium (Sr), alloys (e.g., MgAg and AlLi) including the alkali metal or the alkaline earth metal, a rare earth metal such as europium (Eu) and ytterbium (Yb), and alloys including the rare earth metal.

It should be noted that the vacuum deposition method and the sputtering method are usable for forming the cathode using the alkali metal, alkaline earth metal and the alloy thereof. Further, when a silver paste is used for the cathode, the coating method and the inkjet method are usable.

By providing the electron injecting layer, various conductive materials such as Al, Ag, ITO, graphene, and indium oxide-tin oxide containing silicon or silicon oxide may be used for forming the cathode regardless of the work function. The conductive materials can be formed into a film using the sputtering method, inkjet method, spin coating method, and the like.

### Electron Transporting Layer

In the organic EL device according to the exemplary embodiment, the electron transporting layer is preferably provided between the emitting layer and the cathode.

The electron transporting layer is a layer containing a highly electron-transportable substance. For the electron transporting layer, 1) a metal complex such as an aluminum complex, beryllium complex, and zinc complex, 2) a hetero aromatic compound such as imidazole derivative, benzimidazole derivative, azine derivative, carbazole derivative, and phenanthroline derivative, and 3) a high polymer compound are usable. Specifically, as a low-molecule organic compound, a metal complex such as Alq, tris(4-methyl-8-quinolinato)aluminum (abbreviation: Almq₃), bis(10-hydroxybenzo[h]quinolinato)beryllium (abbreviation: BeBq₂), BAlq, Znq, ZnPBO and ZnBTZ is usable. In addition to the metal complex, a heteroaromatic compound such as 2-(4-biphenylyl)-5-(4-tert-butylphenyl)-1,3,4-oxadiazole (abbreviation: PBD), 1,3-bis[5-(ptert-butylphenyl)-1,3,4-oxadiazole-2-yl]benzene (abbreviation: OXD-7), 3-(4-tert-butylphenyl)-4-phenyl-5-(4-biphenylyl)-1,2,4-triazole (abbreviation: TAZ), 3-(4-tert-butylphenyl)-4-(4-ethylphenyl)-5-(4-biphenylyl)-1,2,4-triazole (abbreviation: p-EtTAZ), bathophenanthroline (abbreviation: BPhen), bathocuproine (abbreviation: BCP), and 4,4′-bis(5-methylbenzoxazole-2-yl)stilbene (abbreviation: BzOs) is usable. In the exemplary embodiment, a benzoimidazole compound is suitably usable. The above-described substances mostly have an electron mobility of 10⁻⁶ cm²/Vs or more. It should be noted that any other substance than the above substance may be used for the electron transporting layer as long as the substance exhibits a higher electron transportability than the hole transportability. The electron transporting layer may be a single layer or a laminate of two or more layers formed of the above substance.

Further, a high polymer compound is usable for the electron transporting layer. For instance, poly[(9,9-dihexylfluorene-2,7-diyl)-co-(pyridine-3,5-diyl)] (abbreviation: PF-Py), and poly[(9,9-dioctylfluorene-2,7-diyl)-co-(2,2′-bipyridine-6,6′-diyl)] (abbreviation: PF-BPy) are usable.

### Electron Injecting Layer

The electron injecting layer is a layer containing a highly electron-injectable substance. Examples of a material for the electron injecting layer include an alkali metal, alkaline earth metal and a compound thereof, examples of which include lithium (Li), cesium (Cs), calcium (Ca), lithium fluoride (LiF), cesium fluoride (CsF), calcium fluoride (CaF₂), and lithium oxide (LiOx). In addition, the alkali metal, alkaline earth metal or the compound thereof may be added to the substance exhibiting the electron transportability in use. Specifically, for instance, magnesium (Mg) added to Alq may be used. In this case, the electrons can be more efficiently injected from the cathode.

Alternatively, the electron injecting layer may be provided by a composite material in a form of a mixture of the organic compound and the electron donor. Such a composite material exhibits excellent electron injectability and electron transportability since electrons are generated in the organic compound by the electron donor. In this case, the organic compound is preferably a material excellent in transporting the generated electrons. Specifically, the above examples (e.g., the metal complex and the hetero aromatic compound) of the substance forming the electron transporting layer are usable. As the electron donor, any substance exhibiting electron donating property to the organic compound is usable. Specifically, the electron donor is preferably alkali metal, alkaline earth metal and rare earth metal such as lithium, cesium, magnesium, calcium, erbium and ytterbium. The electron donor is also preferably alkali metal oxide and alkaline earth metal oxide such as lithium oxide, calcium oxide, and barium oxide. Moreover, a Lewis base such as magnesium oxide is usable. Further, the organic compound such as tetrathiafulvalene (abbreviation: TTF) is usable.

### Layer Formation Method(s)

A method of forming each layer of the organic EL device in the exemplary embodiment is subject to no limitation except for the above particular description. However, known methods of dry film-forming such as vacuum deposition, sputtering, plasma or ion plating and wet film-forming such as spin coating, dipping, flow coating or ink-jet are applicable.

### Film Thickness

The film thickness of each of the organic layers of the organic EL device in the exemplary embodiment is not limited unless otherwise specified in the above. In general, the thickness preferably ranges from several nanometers to 1 μm because an excessively small film thickness is likely to cause defects (e.g. pin holes) and an excessively large thickness leads to the necessity of applying high voltage and consequent reduction in efficiency.

### First Host Material

In the organic EL device according to the exemplary embodiment, the first host material is not particularly limited as long as the first host material is a compound of which dipole is 0.4 D or more.

The compound with a dipole of 0.4 D or more can be obtained by adjusting a type of polar group in the compound, a site where the polar group is introduced, or the like.

Examples of the polar group include a dibenzofuran ring, benzoxanthene ring, naphthobenzofuran ring, dinaphthobenzofuran ring, dibenzothiophene ring, benzothioxanthene ring, naphthobenzothiophene ring, and dinaphthobenzothiophene ring. The dipole of compounds having these polar groups is likely to be large. However, the dipole of compounds having the above polar groups may not be large in some cases. For instance, a compound having two or more polar groups may have a small dipole owing to dipole cancellation depending on the site where each polar group is introduced, the two or more polar groups being selected among the dibenzofuran ring, benzoxanthene ring, naphthobenzofuran ring, dinaphthobenzofuran ring, dibenzothiophene ring, benzothioxanthene ring, naphthobenzothiophene ring, and dinaphthobenzothiophene ring.

For instance, of compounds represented by (1000B), a formula (16X), a formula (17X-1), a formula (17X-2), a formula (17X-3), and a formula (18) below, a compound with a dipole of 0.4 D or more can be selected and used as the first host material.

### Compound Represented by Formula (1000B)

In the organic EL device according to the exemplary embodiment, the first host material is also preferably a compound represented by a formula (14X) below.

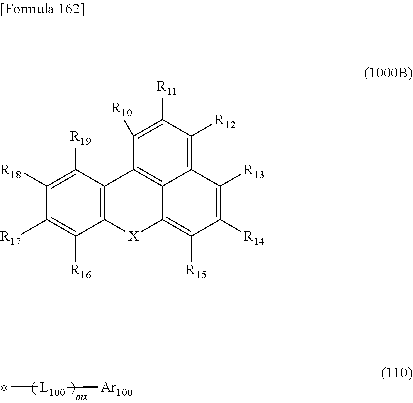

In the formula (1000B):
X is an oxygen atom or a sulfur atom;
at least one combination of adjacent two or more of R₁₀ to R₁₉ are mutually bonded to form a substituted or unsubstituted monocyclic ring, mutually bonded to form a substituted or unsubstituted fused ring, or not mutually bonded;
R₁₀ to R₁₉ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₈₀₁, a group represented by —COOR₈₀₂, a halogen atom, a nitro group, a substituted or unsubstituted aryl group having 6 to 50 ring carbon atoms, a substituted or unsubstituted heterocyclic group having 5 to 50 ring atoms, or a group represented by the formula (110);
at least one of R₁₀ to R₁₉ is a group represented by the formula (110);
when a plurality of groups represented by the formula (110) are present, the plurality of groups represented by the formula (110) are mutually the same or different;
L₁₀₀ is a single bond, a substituted or unsubstituted arylene group having 6 to 50 ring carbon atoms, or a substituted or unsubstituted divalent heterocyclic group having 5 to 50 ring atoms;
mx is 1, 2, or 3;
when two or more L₁₀₀ are present, the two or more L₁₀₀ are mutually the same or different;
Ar₁₀₀ is a substituted or unsubstituted aryl group including three or more rings, or a substituted or unsubstituted heterocyclic group including two or more aromatic rings and one or more heterocycles;
Ar₁₀₀ includes no anthracene ring;
when two or more Ar₁₀₀ are present, the two or more Ar₁₀₀ are mutually the same or different; and
* in the formula (110) represents a bonding position;
in the first host material represented by the formula (1000B), R₉₀₁, R₉₀₂, R₉₀₃, R₉₀₄, R₉₀₅, R₉₀₆, R₉₀₇, R₈₀₁, and R₈₀₂ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different;
when a plurality of R₉₀₇ are present, the plurality of R₉₀₇ are mutually the same or different;
when a plurality of R₈₀₁ are present, the plurality of R₈₀₁ are mutually the same or different; and
when a plurality of R₈₀₂ are present, the plurality of R₈₀₂ are mutually the same or different.

In the formula (1000B), X is preferably an oxygen atom.

The compound represented by the formula (1000B) is preferably a compound represented by a formula (100) below and having at least one group represented by the formula (110).

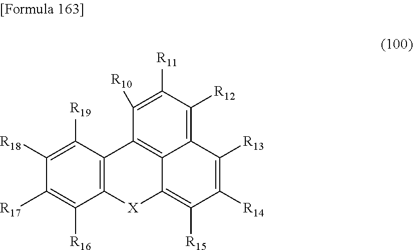

In the formula (100): R₁₀ to R₁₉ each independently represent the same as R₁₀ to R₁₉ in the formula (1000B); and Ar₁₀₀, L₁₀₀ and mx respectively represent the same as Ar₁₀₀, L₁₀₀ and mx in the formula (110).

The compound represented by the formula (1000B) is also preferably a compound represented by a formula (101) or a formula (102) below.

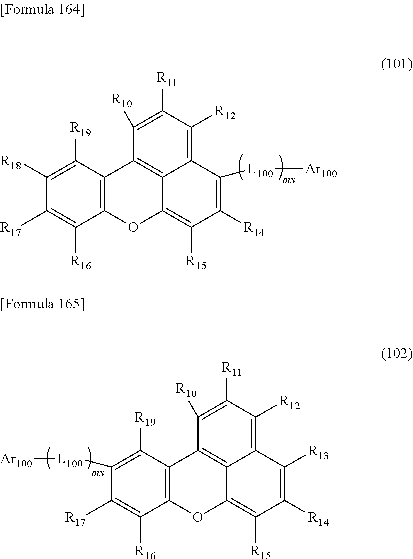

In the formulae (101) and (102): R₁₀ to R₁₉ each independently represent the same as R₁₀ to R₁₉ in the formula (1000B); and Ar₁₀₀, L₁₀₀ and mx respectively represent the same as Ar₁₀₀, L₁₀₀ and mx in the formula (110).

In the formula (1000B), R₁₀ to R₁₉ not being the group represented by the formula (110) are preferably each independently a hydrogen atom, a substituted or unsubstituted alkyl group having 1 to 50 carbon atoms, a substituted or unsubstituted cycloalkyl group having 3 to 50 ring carbon atoms, or a substituted or unsubstituted aryl group having 6 to 50 ring carbon atoms.

In the formula (1000B), R₁₀ to R₁₉ not being the group represented by the formula (110) are each preferably a hydrogen atom.

In the formula (1000B), L₁₀₀ is preferably a single bond, or an arylene group including at most three substituted or unsubstituted benzene rings.

In the formula (1000B), L₁₀₀ is preferably not a substituted or unsubstituted anthrylene group.

In the formula (1000B), L₁₀₀ is also preferably a single bond.

In the formula (1000B), the group represented by -(L₁₀₀)ₘₓ- in the formula (110) is also preferably a group represented by one of formulae (111) to (120) below.

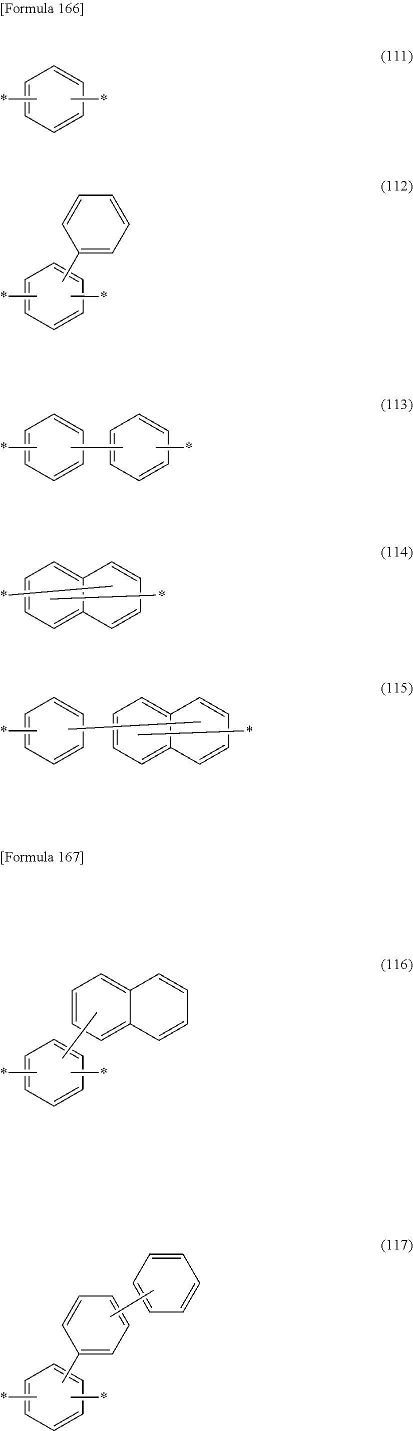

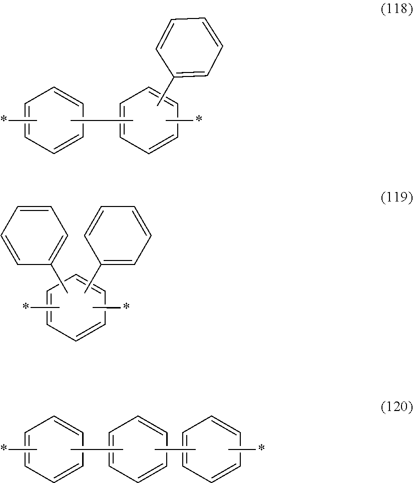

* in the formulae (111) to (120) each represent a bonding position.

The group represented by -(L₁₀₀)ₘₓ- in the formula (110) is preferably a group represented by the formula (111) or (112).

In the formula (1000B), Ar₁₀₀ is preferably an aryl group in which at least four substituted or unsubstituted benzene rings are fused.

In the formula (1000B), Ar₁₀₀ is preferably an aryl group in which four substituted or unsubstituted benzene rings are fused or an aryl group in which five substituted or unsubstituted benzene rings are fused.

In the formula (1000B), Ar₁₀₀ is preferably a group represented by a formula (1100), (1200), (1300), (1400), (1500), (1600), (1700), or (1800) below.

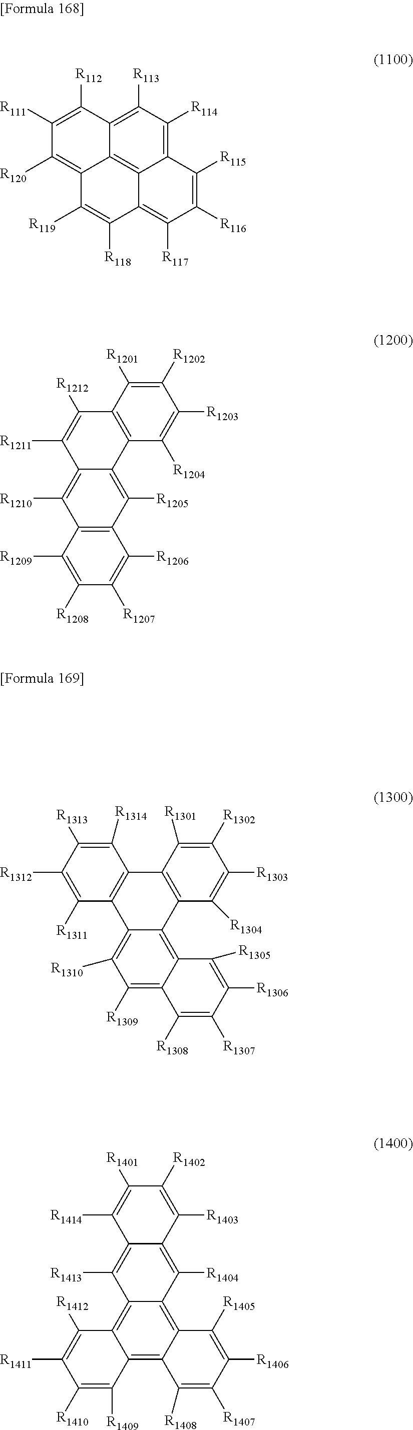

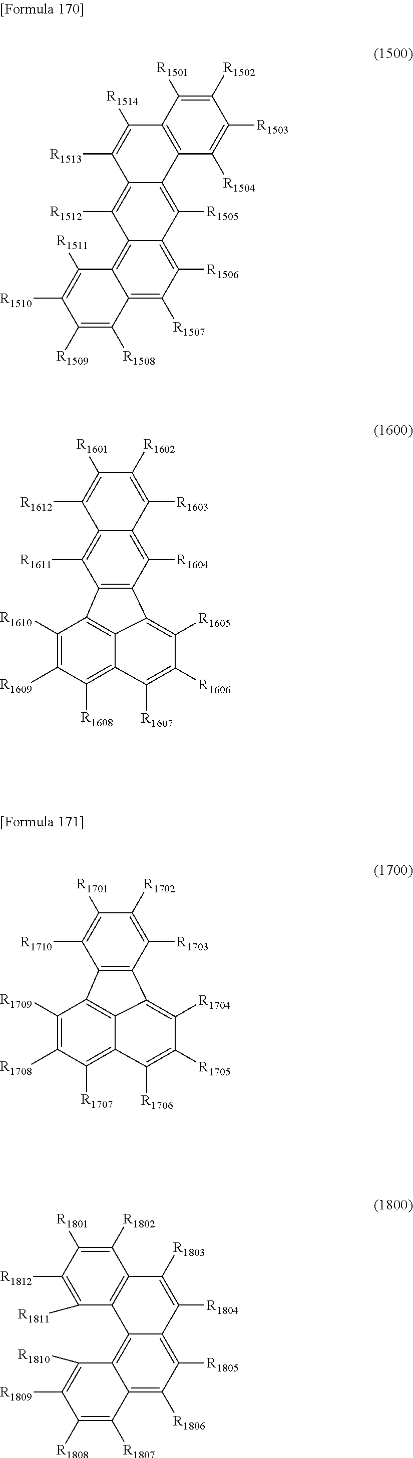

In the formula (1100), one of R₁₁₁ to R₁₂₀ is a bond.

In the formula (1200), one of R₁₂₀₁ to R₁₂₁₂ is a bond.

In the formula (1300), one of R₁₃₀₁ to R₁₃₁₄ is a bond.

In the formula (1400), one of R₁₄₀₁ to R₁₄₁₄ is a bond.

In the formula (1500), one of R₁₅₀₁ to R₁₅₁₄ is a bond.

In the formula (1600), one of R₁₈₀₁ to R₁₆₁₂ is a bond.

In the formula (1700), one of R₁₇₀₁ to R₁₇₁₀ is a bond.

In the formula (1800), one of R₁₈₀₁ to R₁₈₁₂ is a bond.

R₁₁₁ to R₁₂₀ not being a bond, R₁₂₀₁ to R₁₂₁₂ not being a bond, R₁₃₀₁ to R₁₃₁₄ not being a bond, R₁₄₀₁ to R₁₄₁₄ not being a bond, R₁₅₀₁ to R₁₅₁₄ not being a bond, R₁₆₀₁ to R₁₆₁₂ not being a bond, R₁₇₀₁ to R₁₇₁₀ not being a bond, and R₁₈₀₁ to R₁₈₁₂ not being a bond are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₈₀₁, a group represented by —COOR₈₀₂, a halogen atom, a nitro group, a substituted or unsubstituted aryl group having 6 to 50 ring carbon atoms, or a substituted or unsubstituted heterocyclic group having 5 to 50 ring atoms.

The group represented by the formula (1100) in which R₁₁₁ is a bond is a group represented by a formula (1112) below. The group represented by the formula (1100) in which R₁₂₀ is a bond is a group represented by a formula (1113) below. The group represented by the formula (1100) in which R₁₁₉ is a bond is a group represented by a formula (1114) below.

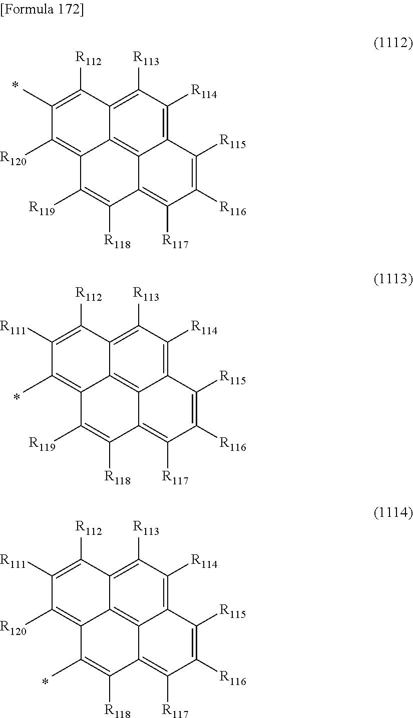

In the formulae (1112), (1113), and (1114):
R₁₁₁ to R₁₂₀ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₈₀₁, a group represented by —COOR₈₀₂, a halogen atom, a nitro group, a substituted or unsubstituted aryl group having 6 to 50 ring carbon atoms, or a substituted or unsubstituted heterocyclic group having 5 to 50 ring atoms; and
* in the formulae (1112) to (1114) each represent a bonding position.

In the formulae (1100), (1200), (1300), (1400), (1500), (1600), (1700) and (1800), R₁₁₁ to R₁₂₀ not being a bond, R₁₂₀₁ to R₁₂₁₂ not being a bond, R₁₃₀₁ to R₁₃₁₄ not being a bond, R₁₄₀₁ to R₁₄₁₄ not being a bond, R₁₅₀₁ to R₁₅₁₄ not being a bond, R₁₆₀₁ to R₁₆₁₂ not being a bond, R₁₇₀₁ to R₁₇₁₀ not being a bond, and R₁₈₀₁ to R₁₈₁₂ not being a bond are preferably each independently a hydrogen atom, a substituted or unsubstituted alkyl group having 1 to 50 carbon atoms, a substituted or unsubstituted cycloalkyl group having 3 to 50 ring carbon atoms, or a substituted or unsubstituted aryl group having 6 to 50 ring carbon atoms.

In the formulae (1100), (1200), (1300), (1400), (1500), (1600), (1700) and (1800), R₁₁₁ to R₁₂₀ not being a bond, R₁₂₀₁ to R₁₂₁₂ not being a bond, R₁₃₀₁ to R₁₃₁₄ not being a bond, R₁₄₀₁ to R₁₄₁₄ not being a bond, R₁₅₀₁ to R₁₅₁₄ not being a bond, R₁₆₀₁ to R₁₆₁₂ not being a bond, R₁₇₀₁ to R₁₇₁₀ not being a bond, and R₁₈₀₁ to R₁₈₁₂ not being a bond are each preferably a hydrogen atom.

The compound represented by the formula (1000B) preferably includes only one benzoxanthene ring in a molecule.

The compounds represented by the formulae (100), (101) and (102) in which a benzoxanthene ring is substituted by a benzothioxanthene ring are also preferable.

### Compound Represented by Formula (17X-1)

In the organic EL device according to the exemplary embodiment, the first host material is also preferably a compound represented by a formula (17X-1) below.

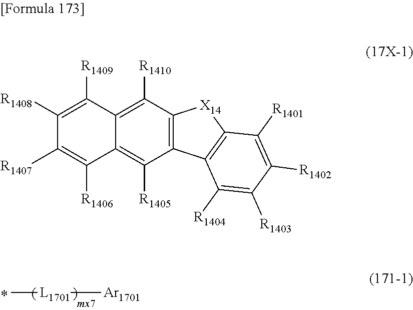

In the formula (17X-1):
X₁₄ is an oxygen atom or a sulfur atom;
at least one combination of adjacent two or more of R₁₄₀₁ to R₁₄₀₄ are mutually bonded to form a substituted or unsubstituted monocyclic ring, mutually bonded to form a substituted or unsubstituted fused ring, or not mutually bonded;
at least one combination of adjacent two or more of R₁₄₀₅ to R₁₄₁₀ are mutually bonded to form a substituted or unsubstituted monocyclic ring, mutually bonded to form a substituted or unsubstituted fused ring, or not mutually bonded;
at least one of R₁₄₀₁ to R₁₄₁₀ is a group represented by the formula (171-1);
R₁₄₀₁ to R₁₄₁₀ forming neither the monocyclic ring nor the fused ring and not being the group represented by the formula (171-1) are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by the formula (171-1);
at least one of R₁₄₀₁ to R₁₄₁₀ is a group represented by the formula (171-1);
when a plurality of groups represented by the formula (171-1) are present, the plurality of groups represented by the formula (171-1) are mutually the same or different;
L₁₇₀₁ is a single bond, a substituted or unsubstituted arylene group having 6 to 50 ring carbon atoms, or a substituted or unsubstituted divalent heterocyclic group having 5 to 50 ring atoms;
Ar₁₇₀₁ is a substituted or unsubstituted aryl group having 6 to 50 ring carbon atoms, or a substituted or unsubstituted heterocyclic group having 5 to 50 ring atoms;
mx7 is 0, 1, 2, 3, 4, or 5;
when two or more L₁₇₀₁ are present, the two or more L₁₇₀₁ are mutually the same or different;
when two or more Ar₁₇₀₁ are present, the two or more Ar₁₇₀₁ are mutually the same or different;
R₉₀₁ to R₉₀₅, R₈₀₁, and R₈₀₂ each independently represent the same as R₉₀₁ to R₉₀₅, R₈₀₁, and R₈₀₂ in the formula (1000B); and
* in the formula (171-1) represents a bonding position to a ring represented by the formula (17X-1).

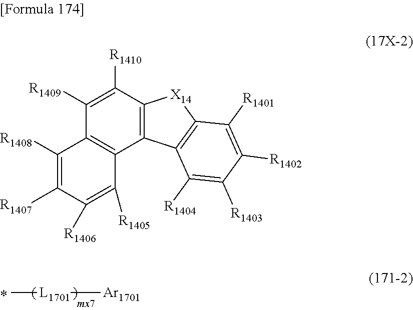

In the formula (17X-2), R₁₄₀₁ to R₁₄₁₀ and X₁₄ each independently represent the same as R₁₄₀₁ to R₁₄₁₀ and X₁₄ in the formula (17X-1);

the group represented by the formula (171-2) represents the same as a group represented by the formula (171-1); and L₁₇₀₁, Ar₁₇₀₁ and mx7 in the formula (171-2) each independently represent the same as L₁₇₀₁, Ar₁₇₀₁ and mx7 in the formula (171-1);

when a plurality of groups represented by the formula (171-2) are present, the plurality of groups represented by the formula (171-2) are mutually the same or different; and

* in the formula (171-2) represents a bonding position to a ring represented by the formula (17X-2).

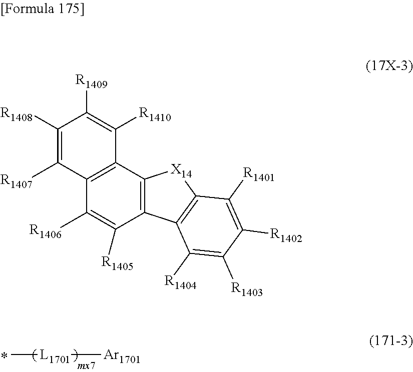

In the formula (17X-3), R₁₄₀₁ to R₁₄₁₀ and X₁₄ each independently represent the same as R₁₄₀₁ to R₁₄₁₀ and X₁₄ in the formula (17X-1);

the group represented by the formula (171-3) represents the same as a group represented by the formula (171-1); and L₁₇₀₁, Ar₁₇₀₁ and mx7 in the formula (171-3) each independently represent the same as L₁₇₀₁, Ar₁₇₀₁ and mx7 in the formula (171-1);

when a plurality of groups represented by the formula (171-3) are present, the plurality of groups represented by the formula (171-3) are mutually the same or different; and

* in the formula (171-3) represents a bonding position to a ring represented by the formula (17X-3).

In the formulae (17X-1), (17X-2) and (17X-3), X₁₄ is preferably an oxygen atom.

### Compound Represented by Formula (18)

In the organic EL device according to the exemplary embodiment, the first host material is also preferably a compound represented by the formula (18) below.

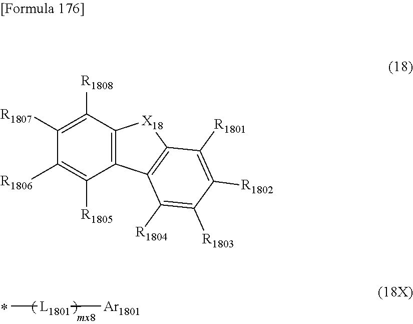

In the formula (18):
X₁₈ is an oxygen atom or a sulfur atom;
at least one combination of adjacent two or more of R₁₈₀₁ to R₁₈₀₄ are mutually bonded to form a substituted or unsubstituted monocyclic ring, mutually bonded to form a substituted or unsubstituted fused ring, or not mutually bonded;
at least one combination of adjacent two or more of R₁₈₀₅ to R₁₈₀₈ are mutually bonded to form a substituted or unsubstituted monocyclic ring, mutually bonded to form a substituted or unsubstituted fused ring, or not mutually bonded;
at least one of R₁₈₀₁ to R₁₈₀₈ is a group represented by the formula (18X);
R₁₈₀₁ to R₁₈₀₈ forming neither the monocyclic ring nor the fused ring and not being the group represented by the formula (18X) are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by the formula (18X);
at least one of R₁₈₀₁ to R₁₈₀₈ is a group represented by the formula (18X);
when a plurality of groups represented by the formula (18X) are present, the plurality of groups represented by the formula (18X) are mutually the same or different;
L₁₈₀₁ is a single bond, a substituted or unsubstituted arylene group having 6 to 50 ring carbon atoms, or a substituted or unsubstituted divalent heterocyclic group having 5 to 50 ring atoms;
Ar₁₈₀₁ is a substituted or unsubstituted aryl group having 6 to 50 ring carbon atoms, or a substituted or unsubstituted heterocyclic group having 5 to 50 ring atoms;
mx8 is 0, 1, 2, 3, 4, or 5;
when two or more L₁₈₀₁ are present, the two or more L₁₈₀₁ are mutually the same or different;
when two or more Ar₁₈₀₁ are present, the two or more Ar₁₈₀₁ are mutually the same or different;
R₉₀₁ to R₉₀₅, R₈₀₁, and R₈₀₂ each independently represent the same as R₉₀₁ to R₉₀₅, R₈₀₁, and R₈₀₂ in the formula (1000B); and
* in the formula (18X) represents a bonding position to a ring represented by the formula (18).

In the formula (18), X₁₈ is preferably an oxygen atom.

In the first host material, the groups specified to be “substituted or unsubstituted” are each preferably an unsubstituted group.

### Method for Producing First Host Material

The first host material can be produced by a known method. The first host material can also be produced based on a known method through a known alternative reaction using a known material(s) tailored for the target compound.

### Specific Examples of First Host Material

Specific examples of the first host material include compounds below. It should however be noted that the invention is not limited to the specific examples of the compounds.

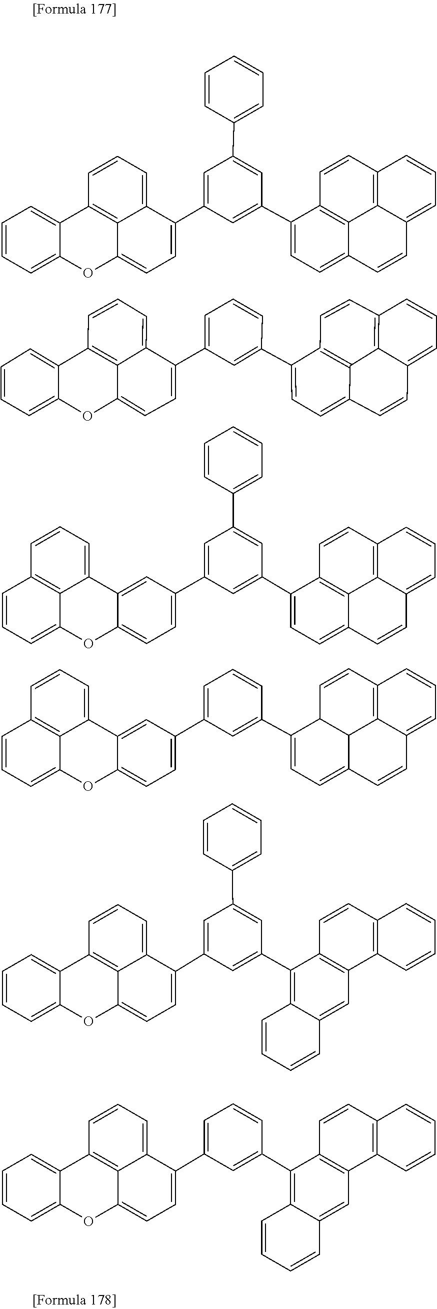

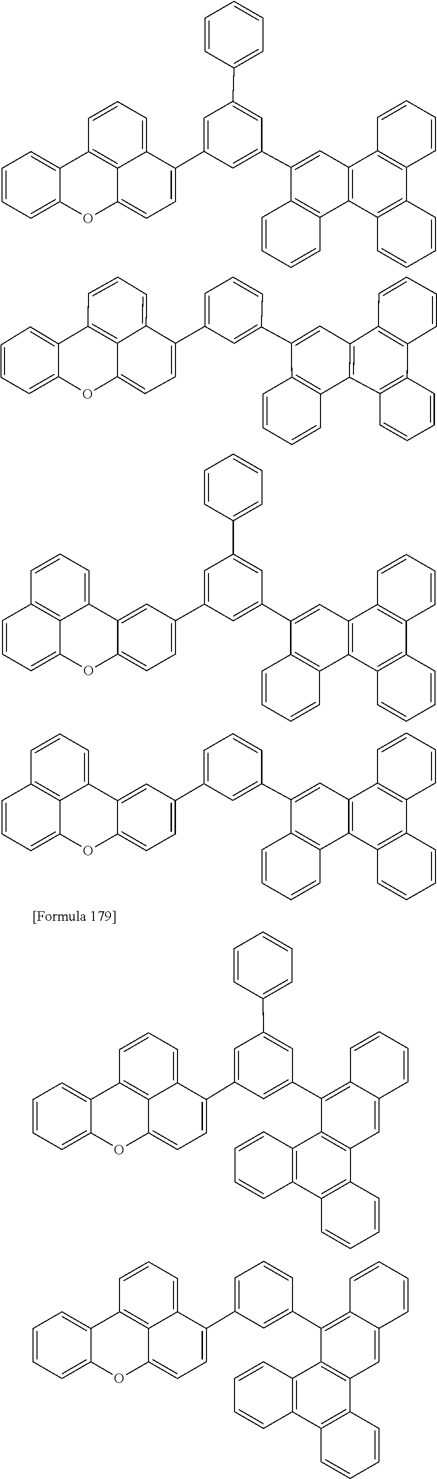

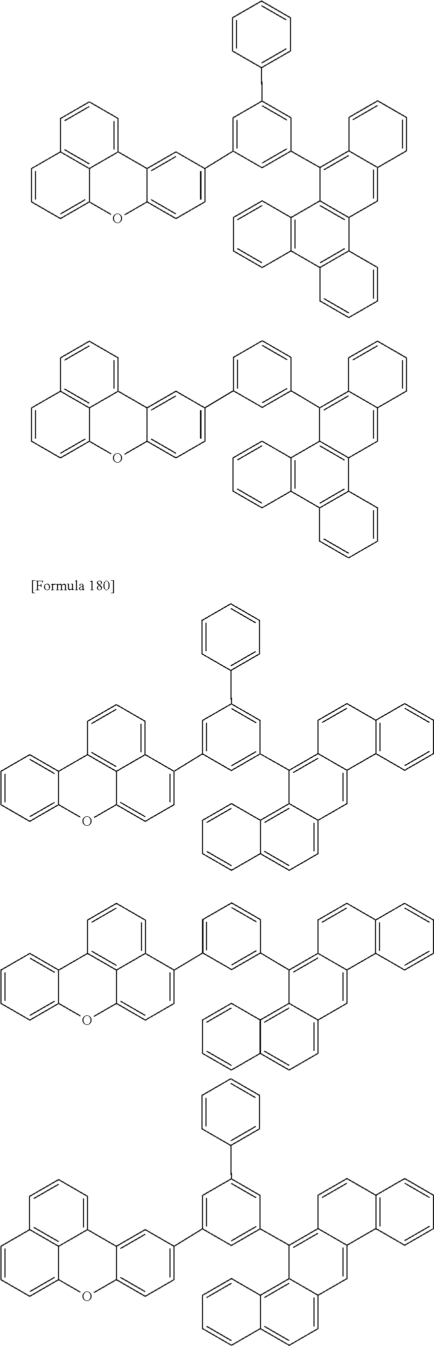

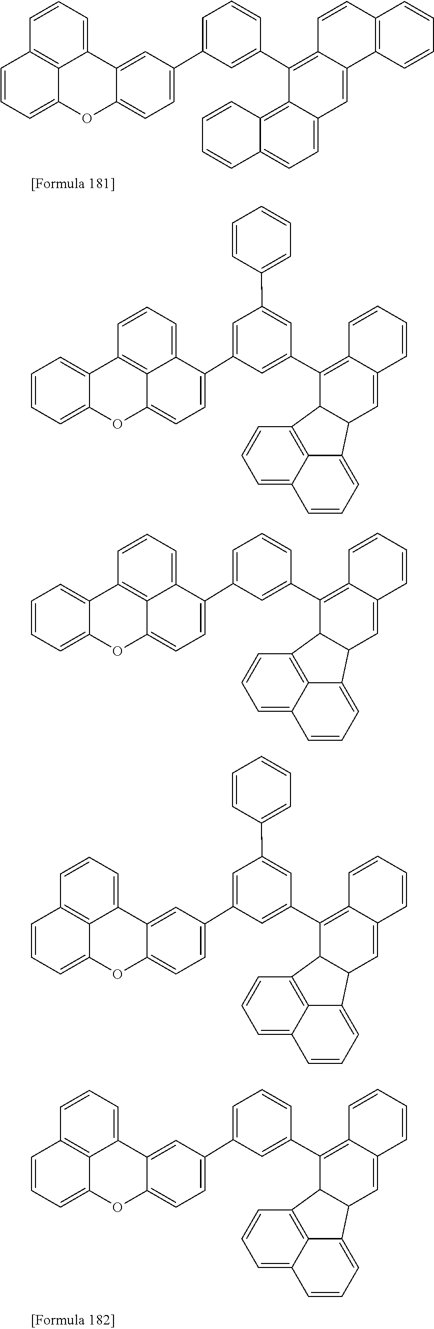

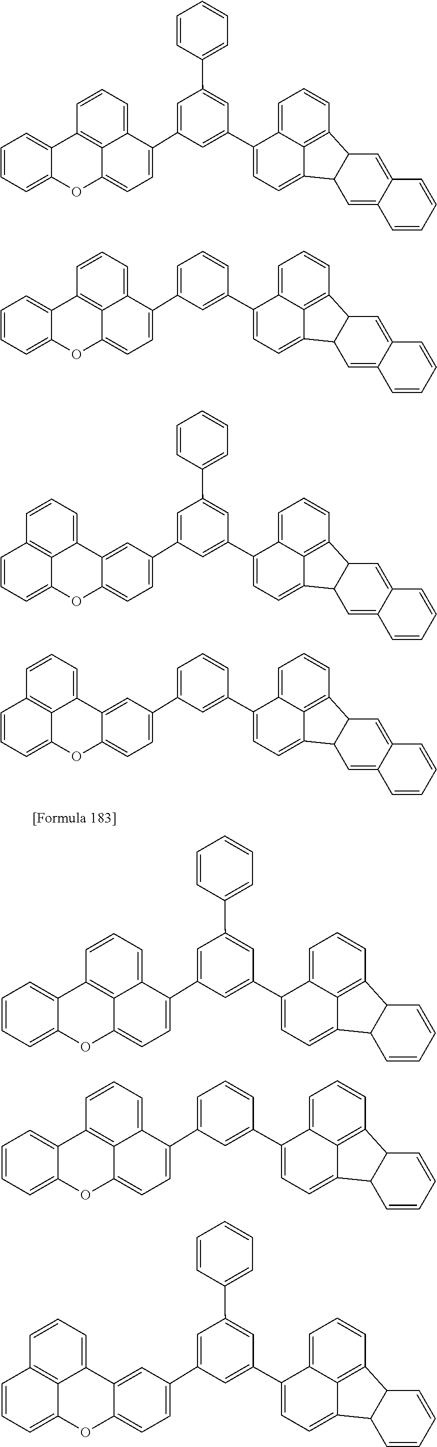

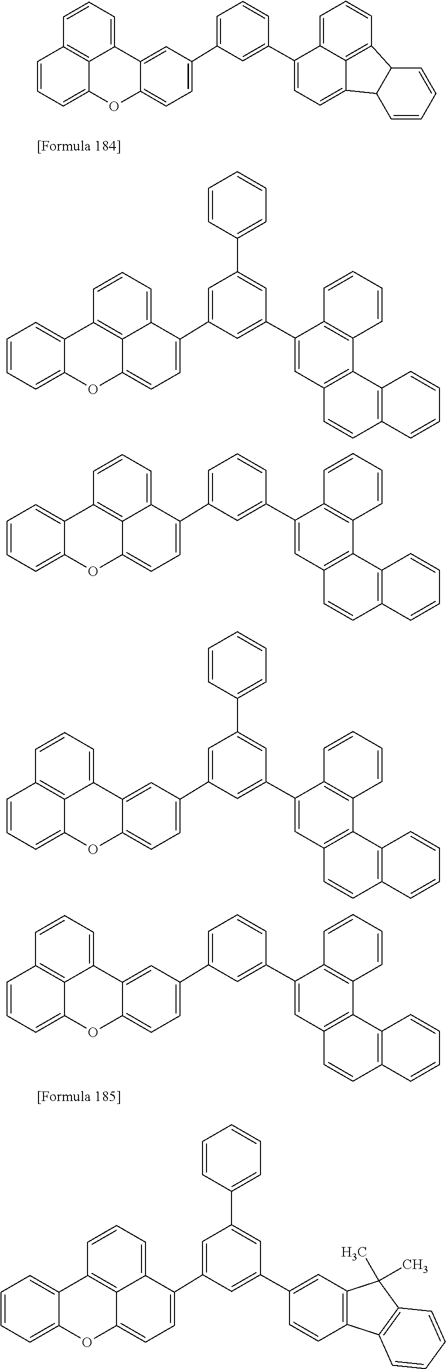

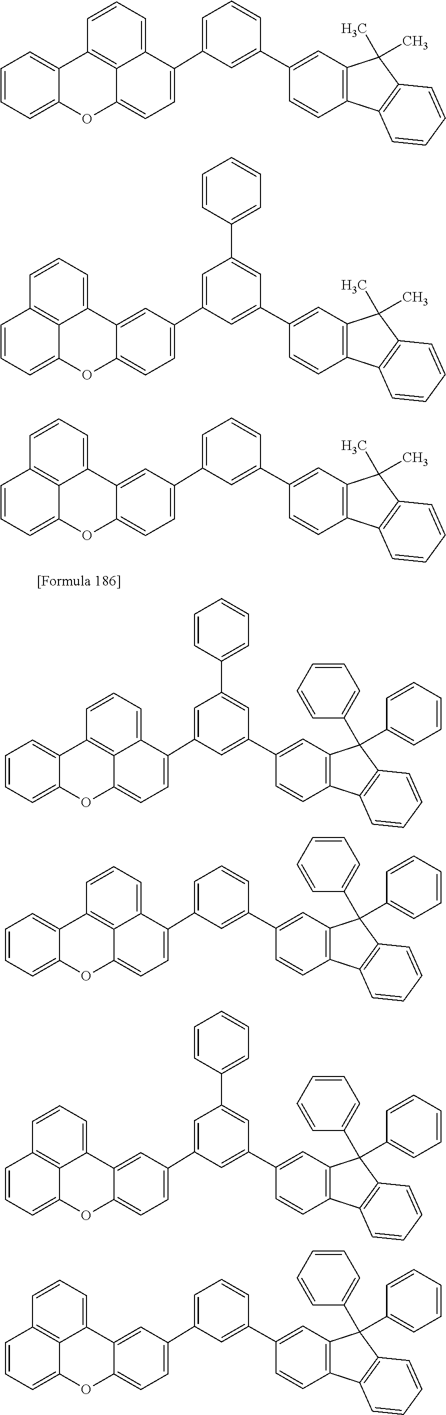

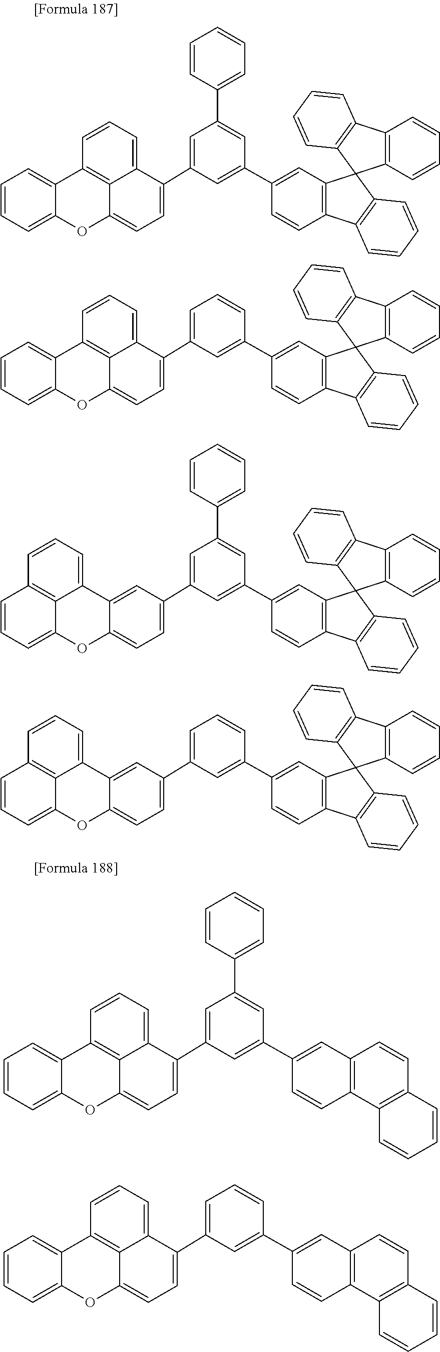

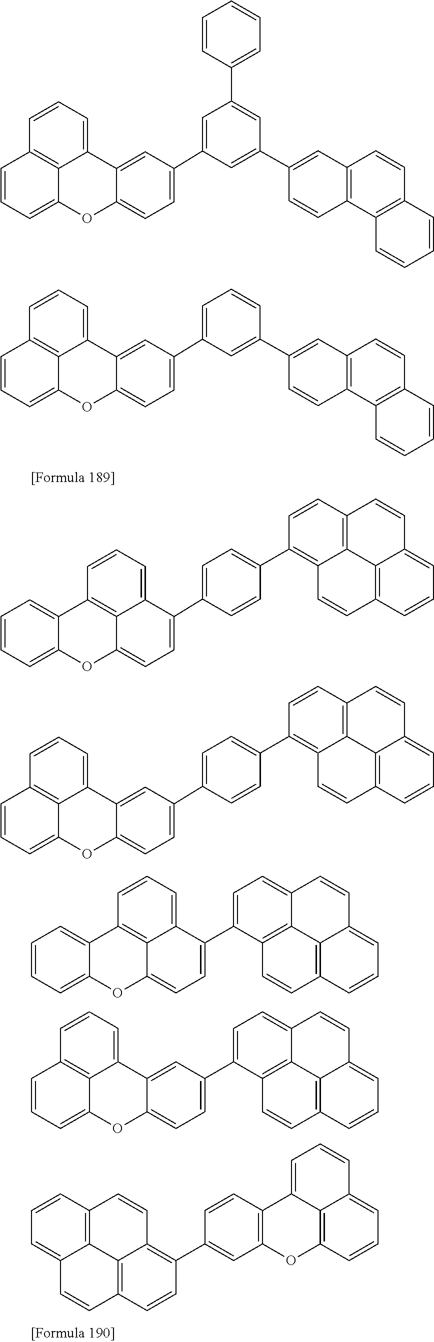

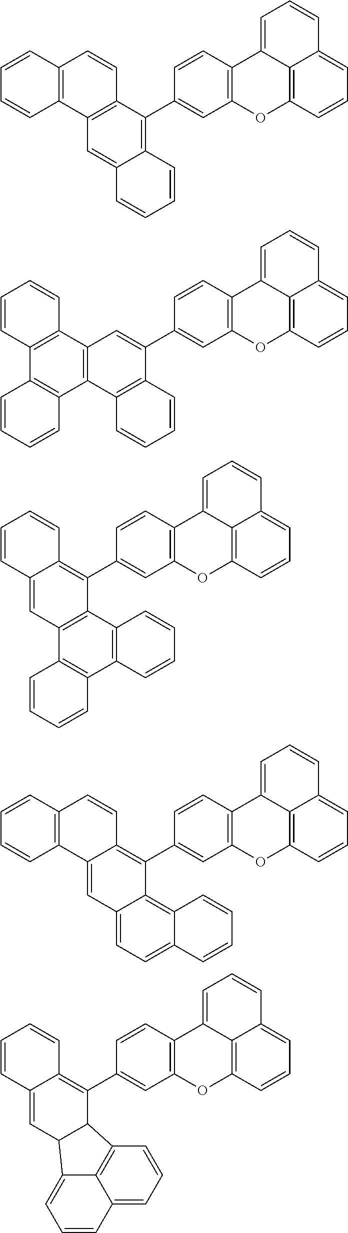

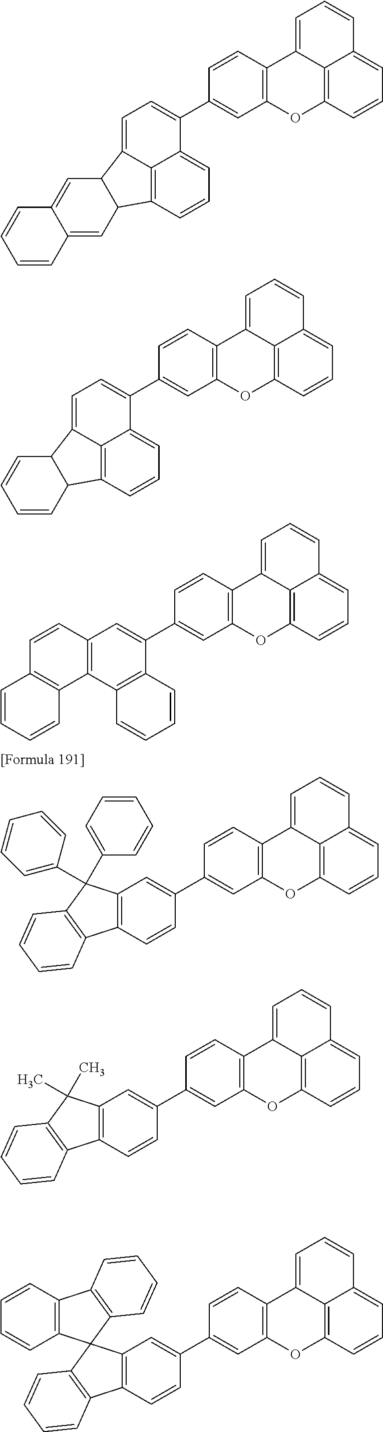 [SMILES: C1=c2ccccc2=CC2c3ccc(-c4ccc5c(c4)Oc4cccc6cccc-5c46)c4cccc(c34)C12 ; C1=CC2c3cccc4c(-c5ccc6c(c5)Oc5cccc7cccc-6c57)ccc(c34)C2C=C1 ; c1cc2c3c(cccc3c1)-c1ccc(-c3cc4ccc5ccccc5c4c4ccccc34)cc1O2 ; c1ccc(C2(c3ccccc3)c3ccccc3-c3ccc(-c4ccc5c(c4)Oc4cccc6cccc-5c46)cc32)cc1 ; CC1(C)c2ccccc2-c2ccc(-c3ccc4c(c3)Oc3cccc5cccc-4c35)cc21 ; c1ccc2c(c1)-c1ccccc1C21c2ccccc2-c2ccc(-c3ccc4c(c3)Oc3cccc5cccc-4c35)cc21]

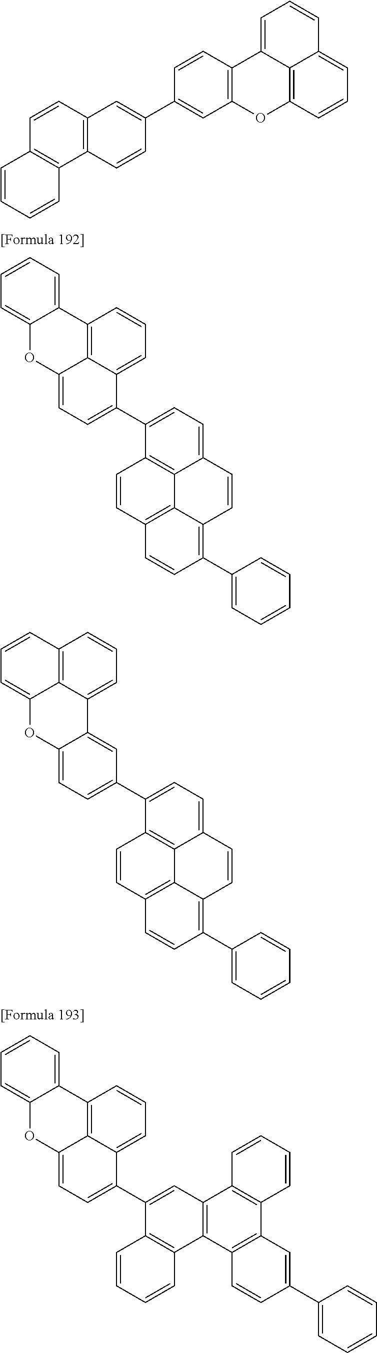

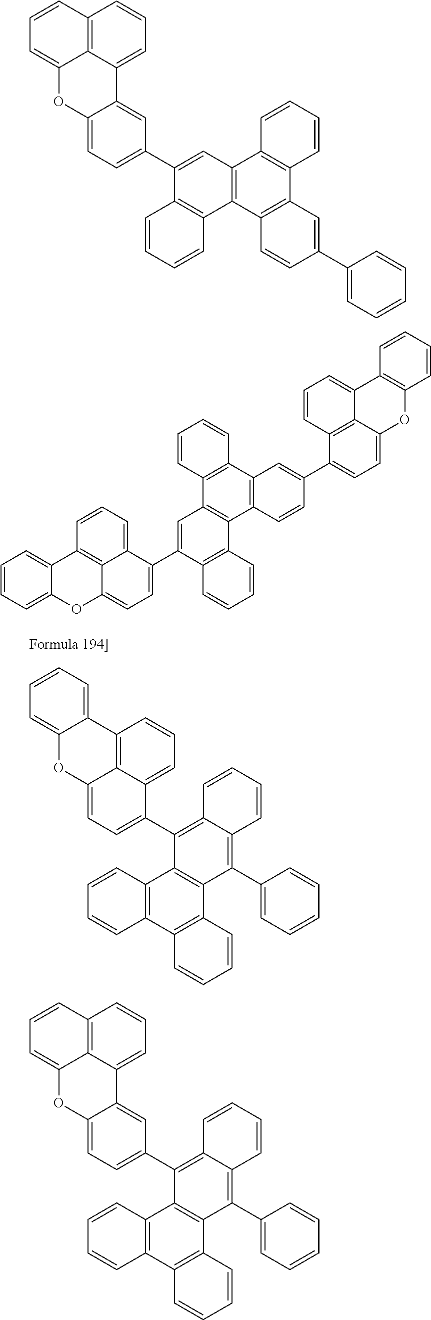

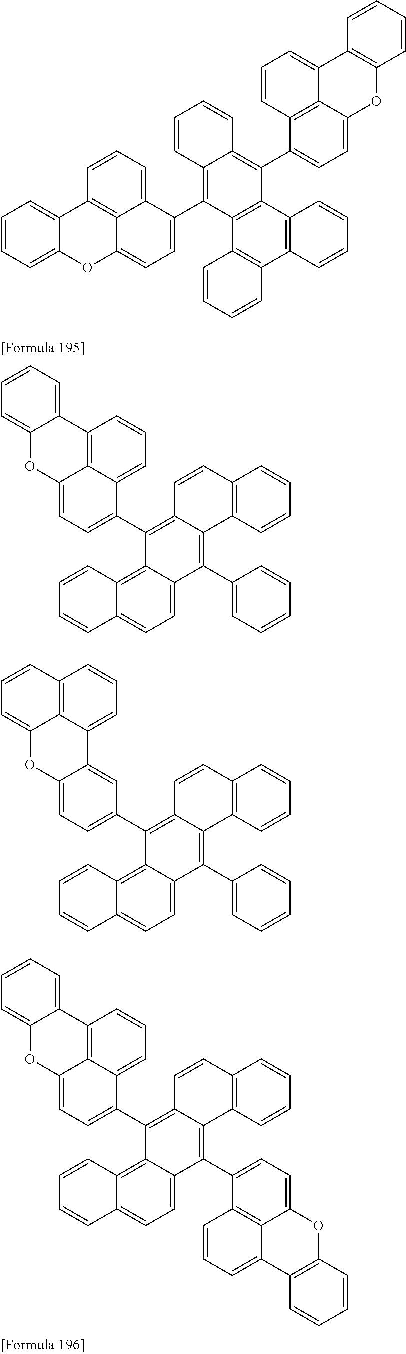

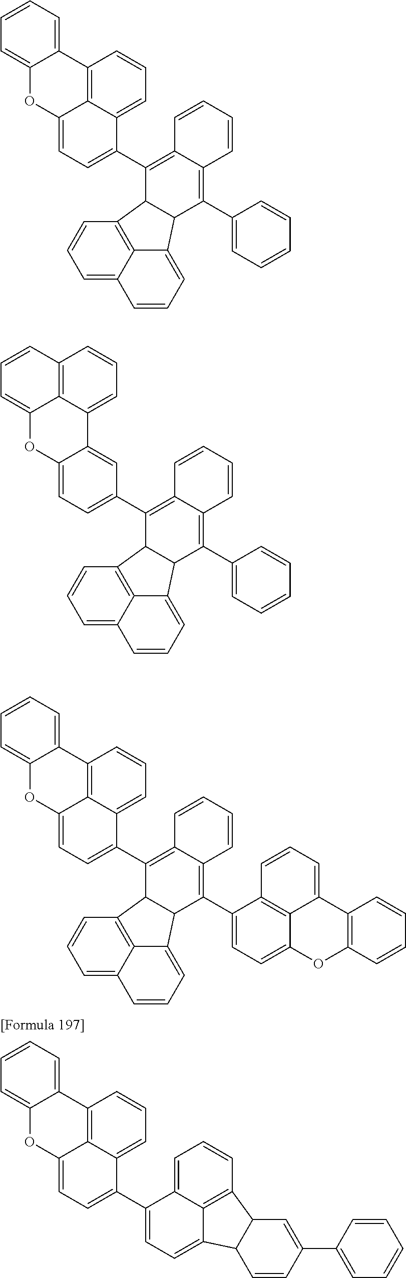 [SMILES: c1ccc(C2=c3ccccc3=C(c3ccc4c5c(cccc35)-c3ccccc3O4)C3c4cccc5cccc(c45)C23)cc1 ; c1ccc(C2=c3ccccc3=C(c3ccc4c(c3)-c3cccc5cccc(c35)O4)C3c4cccc5cccc(c45)C23)cc1 ; c1ccc2c(c1)Oc1ccc(C3=c4ccccc4=C(c4ccc5c6c(cccc46)-c4ccccc4O5)C4c5cccc6cccc(c56)C34)c3cccc-2c13 ; C1=CC2c3ccc(-c4ccc5c6c(cccc46)-c4ccccc4O5)c4cccc(c34)C2C=C1c1ccccc1]

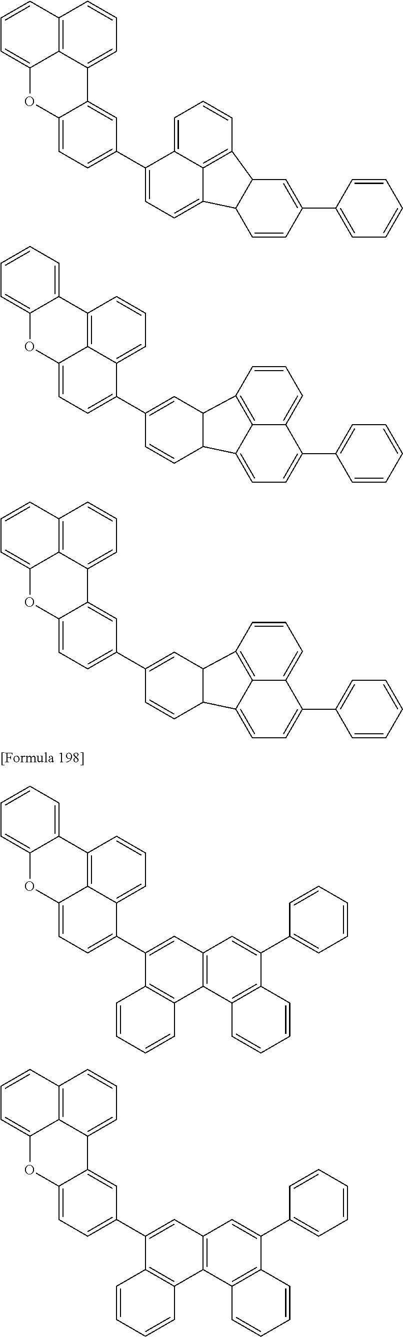

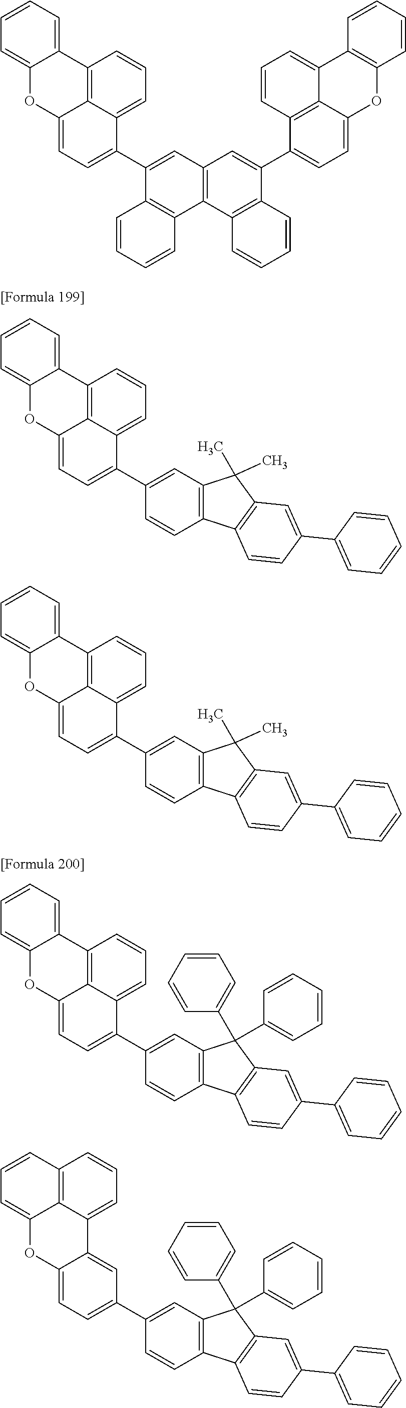 [SMILES: c1ccc2c(c1)Oc1ccc(-c3cc4cc(-c5ccc6c7c(cccc57)-c5ccccc5O6)c5ccccc5c4c4ccccc34)c3cccc-2c13 ; CC1(C)c2cc(-c3ccccc3)ccc2-c2ccc(-c3ccc4c5c(cccc35)-c3ccccc3O4)cc21 ; CC1(C)c2cc(-c3ccccc3)ccc2-c2ccc(-c3ccc4c5c(cccc35)-c3ccccc3O4)cc21 ; c1ccc(-c2ccc3c(c2)C(c2ccccc2)(c2ccccc2)c2cc(-c4ccc5c6c(cccc46)-c4ccccc4O5)ccc2-3)cc1 ; c1ccc(-c2ccc3c(c2)C(c2ccccc2)(c2ccccc2)c2cc(-c4ccc5c(c4)-c4cccc6cccc(c46)O5)ccc2-3)cc1]

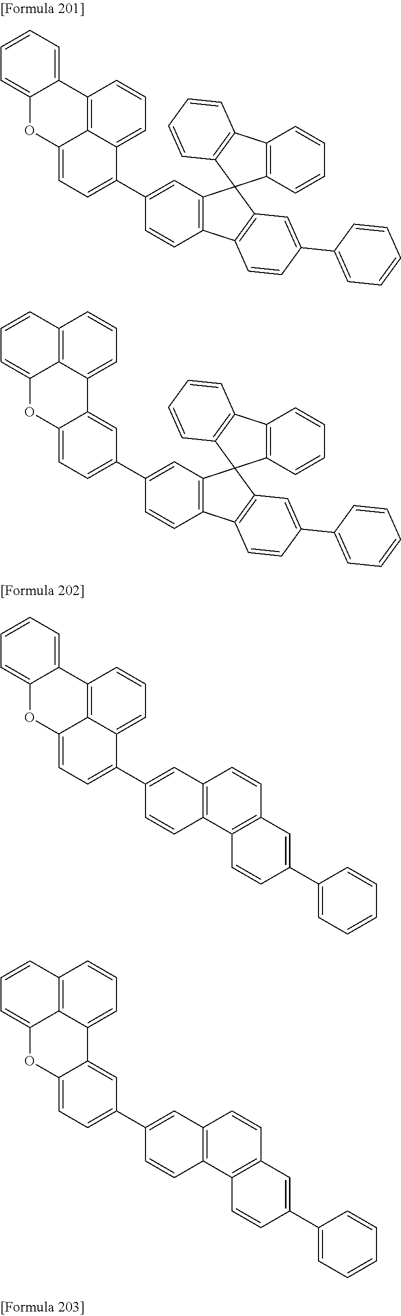 [SMILES: c1ccc(-c2ccc3c(c2)C2(c4ccccc4-c4ccccc42)c2cc(-c4ccc5c6c(cccc46)-c4ccccc4O5)ccc2-3)cc1 ; c1ccc(-c2ccc3c(c2)C2(c4ccccc4-c4ccccc42)c2cc(-c4ccc5c(c4)-c4cccc6cccc(c46)O5)ccc2-3)cc1 ; c1ccc(-c2ccc3c(ccc4cc(-c5ccc6c7c(cccc57)-c5ccccc5O6)ccc43)c2)cc1 ; c1ccc(-c2ccc3c(ccc4cc(-c5ccc6c(c5)-c5cccc7cccc(c57)O6)ccc43)c2)cc1]

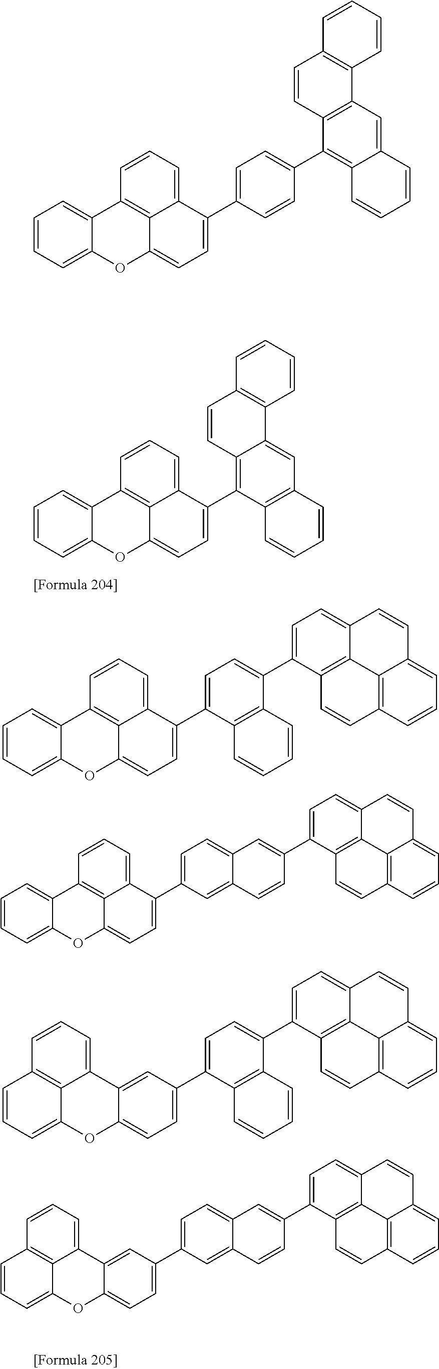 [SMILES: c1ccc2c(c1)Oc1ccc(-c3ccc(-c4c5ccccc5cc5c4ccc4ccccc45)cc3)c3cccc-2c13 ; c1ccc2c(c1)Oc1ccc(-c3c4ccccc4cc4c3ccc3ccccc34)c3cccc-2c13 ; c1ccc2c(c1)Oc1ccc(-c3ccc(-c4ccc5ccc6cccc7ccc4c5c67)c4ccccc34)c3cccc-2c13 ; c1ccc2c(c1)Oc1ccc(-c3ccc4cc(-c5ccc6ccc7cccc8ccc5c6c78)ccc4c3)c3cccc-2c13 ; c1cc2c3c(cccc3c1)-c1cc(-c3ccc(-c4ccc5ccc6cccc7ccc4c5c67)c4ccccc34)ccc1O2 ; c1cc2c3c(cccc3c1)-c1cc(-c3ccc4cc(-c5ccc6ccc7cccc8ccc5c6c78)ccc4c3)ccc1O2]

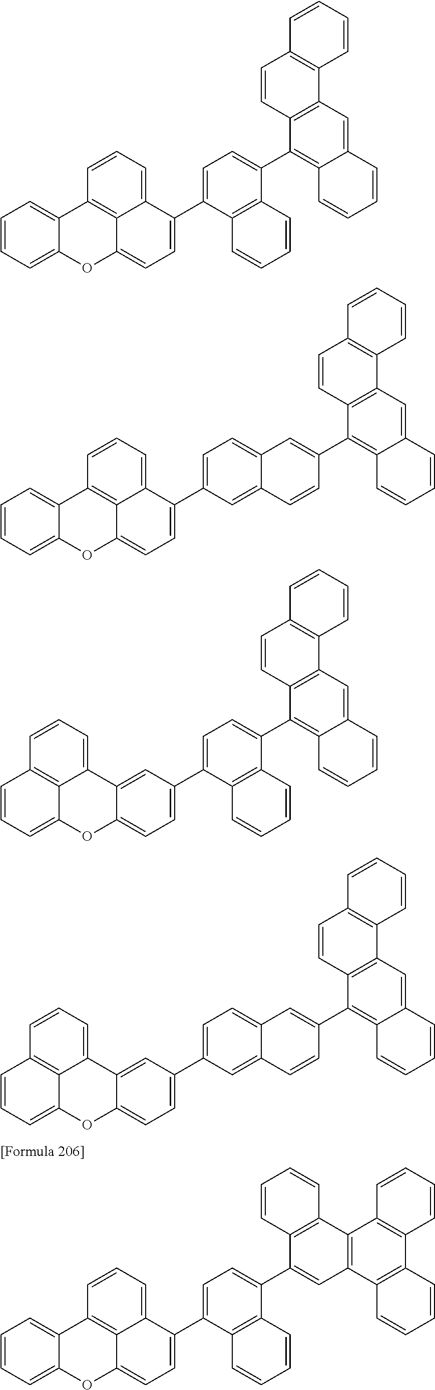 [SMILES: c1ccc2c(c1)Oc1ccc(-c3ccc(-c4c5ccccc5cc5c4ccc4ccccc45)c4ccccc34)c3cccc-2c13 ; c1ccc2c(c1)Oc1ccc(-c3ccc4cc(-c5c6ccccc6cc6c5ccc5ccccc56)ccc4c3)c3cccc-2c13 ; c1ccc2c(-c3ccc(-c4ccc5c(c4)-c4cccc6cccc(c46)O5)c4ccccc34)c3ccc4ccccc4c3cc2c1 ; c1ccc2c(-c3ccc4cc(-c5ccc6c(c5)-c5cccc7cccc(c57)O6)ccc4c3)c3ccc4ccccc4c3cc2c1 ; c1ccc2c(c1)Oc1ccc(-c3ccc(-c4cc5c6ccccc6c6ccccc6c5c5ccccc45)c4ccccc34)c3cccc-2c13]

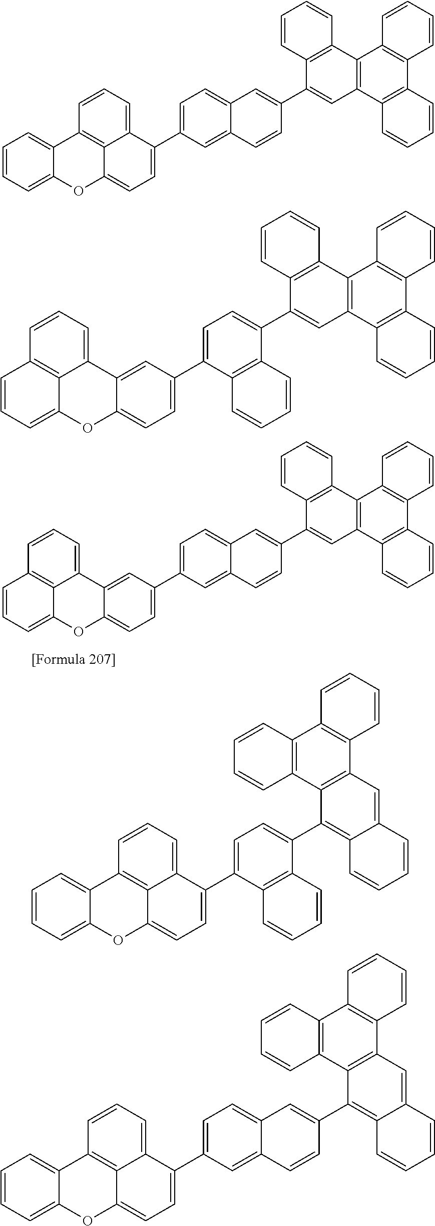

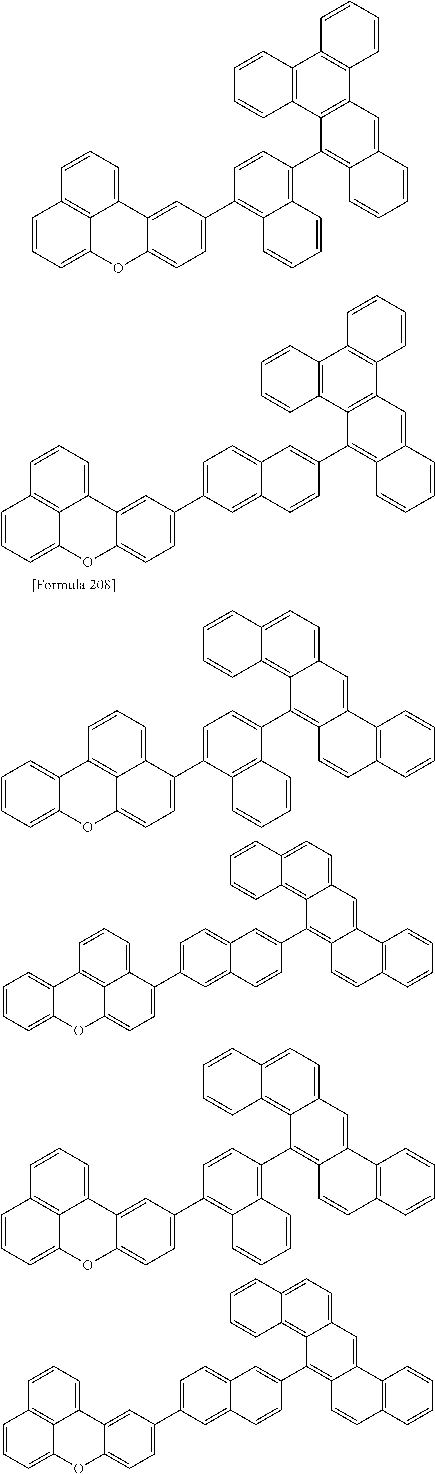

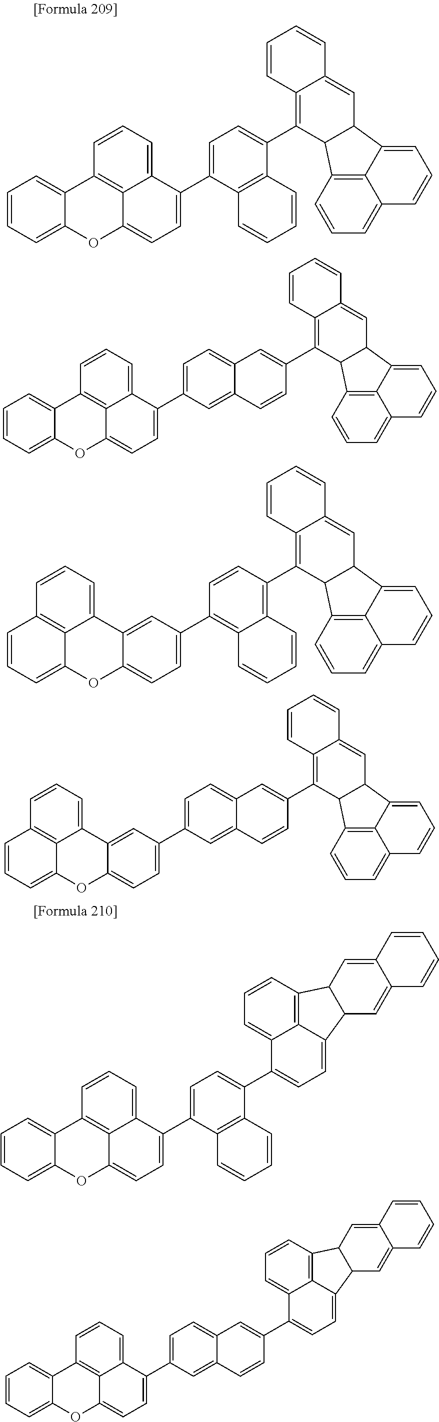

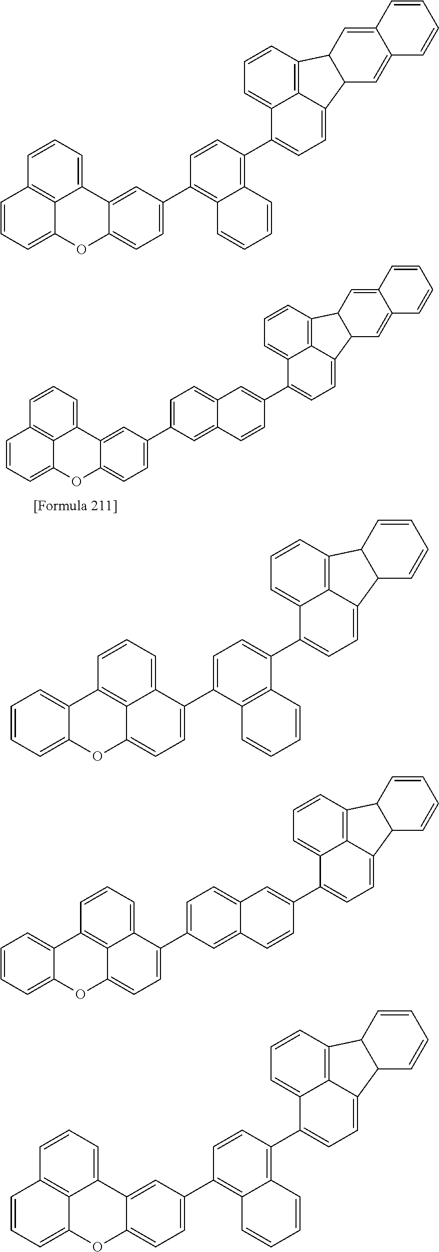 [SMILES: C1=c2ccccc2=CC2c3ccc(-c4ccc(-c5ccc6c(c5)-c5cccc7cccc(c57)O6)c5ccccc45)c4cccc(c34)C12 ; C1=c2ccccc2=CC2c3ccc(-c4ccc5cc(-c6ccc7c(c6)-c6cccc8cccc(c68)O7)ccc5c4)c4cccc(c34)C12 ; C1=CC2c3cccc4c(-c5ccc(-c6ccc7c8c(cccc68)-c6ccccc6O7)c6ccccc56)ccc(c34)C2C=C1 ; C1=CC2c3cccc4c(-c5ccc6cc(-c7ccc8c9c(cccc79)-c7ccccc7O8)ccc6c5)ccc(c34)C2C=C1 ; C1=CC2c3cccc4c(-c5ccc(-c6ccc7c(c6)-c6cccc8cccc(c68)O7)c6ccccc56)ccc(c34)C2C=C1]

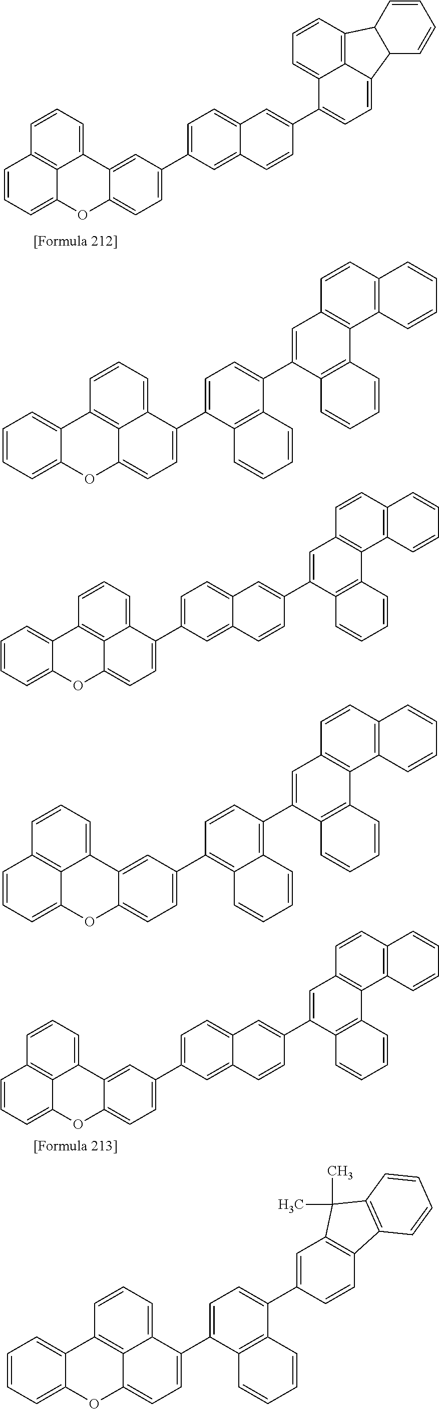 [SMILES: C1=CC2c3cccc4c(-c5ccc6cc(-c7ccc8c(c7)-c7cccc9cccc(c79)O8)ccc6c5)ccc(c34)C2C=C1 ; c1ccc2c(c1)Oc1ccc(-c3ccc(-c4cc5ccc6ccccc6c5c5ccccc45)c4ccccc34)c3cccc-2c13 ; c1ccc2c(c1)Oc1ccc(-c3ccc4cc(-c5cc6ccc7ccccc7c6c6ccccc56)ccc4c3)c3cccc-2c13 ; c1cc2c3c(cccc3c1)-c1cc(-c3ccc(-c4cc5ccc6ccccc6c5c5ccccc45)c4ccccc34)ccc1O2 ; c1cc2c3c(cccc3c1)-c1cc(-c3ccc4cc(-c5cc6ccc7ccccc7c6c6ccccc56)ccc4c3)ccc1O2 ; CC1(C)c2ccccc2-c2ccc(-c3ccc(-c4ccc5c6c(cccc46)-c4ccccc4O5)c4ccccc34)cc21]

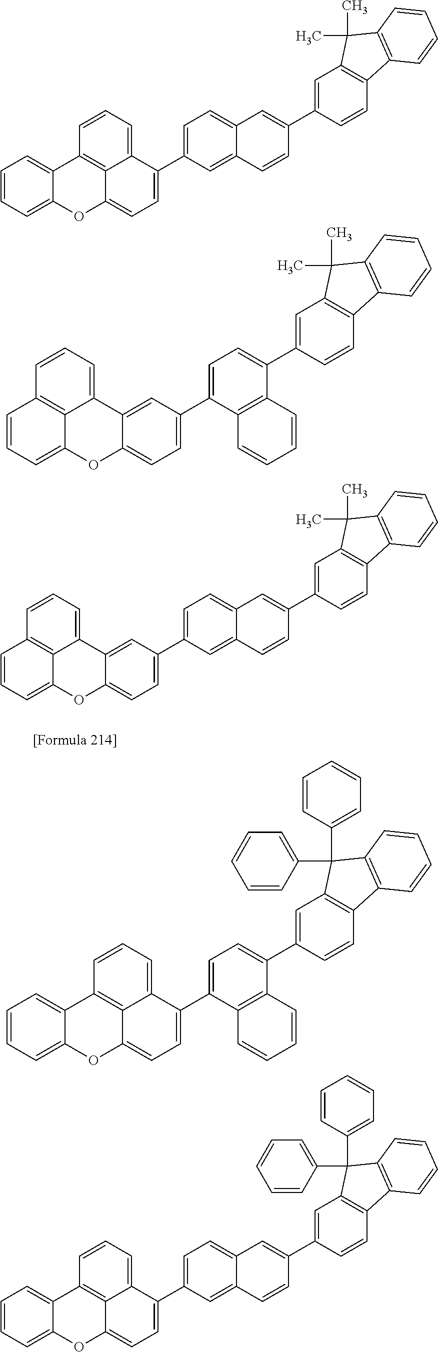 [SMILES: CC1(C)c2ccccc2-c2ccc(-c3ccc4cc(-c5ccc6c7c(cccc57)-c5ccccc5O6)ccc4c3)cc21 ; CC1(C)c2ccccc2-c2ccc(-c3ccc(-c4ccc5c(c4)-c4cccc6cccc(c46)O5)c4ccccc34)cc21 ; CC1(C)c2ccccc2-c2ccc(-c3ccc4cc(-c5ccc6c(c5)-c5cccc7cccc(c57)O6)ccc4c3)cc21 ; c1ccc(C2(c3ccccc3)c3ccccc3-c3ccc(-c4ccc(-c5ccc6c7c(cccc57)-c5ccccc5O6)c5ccccc45)cc32)cc1 ; c1ccc(C2(c3ccccc3)c3ccccc3-c3ccc(-c4ccc5cc(-c6ccc7c8c(cccc68)-c6ccccc6O7)ccc5c4)cc32)cc1]

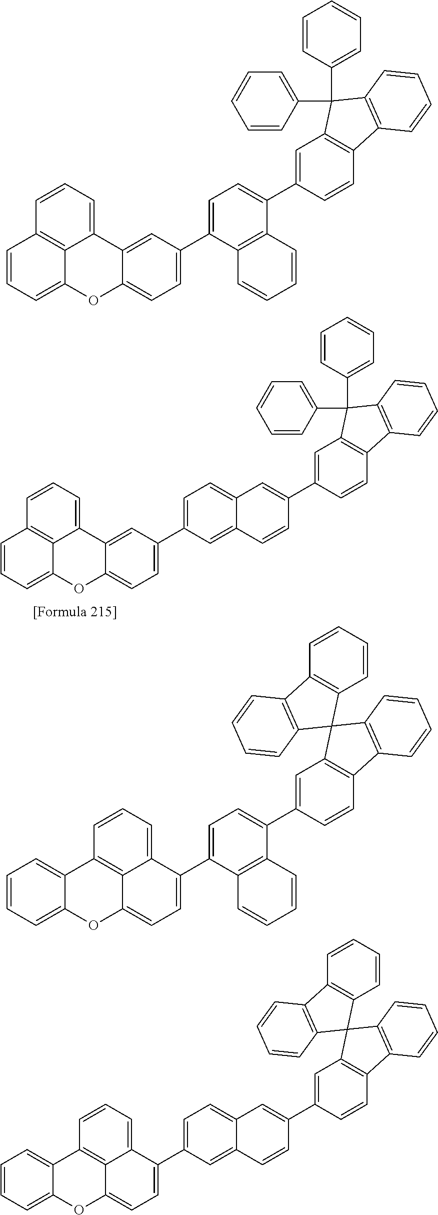 [SMILES: c1ccc(C2(c3ccccc3)c3ccccc3-c3ccc(-c4ccc(-c5ccc6c(c5)-c5cccc7cccc(c57)O6)c5ccccc45)cc32)cc1 ; c1ccc(C2(c3ccccc3)c3ccccc3-c3ccc(-c4ccc5cc(-c6ccc7c(c6)-c6cccc8cccc(c68)O7)ccc5c4)cc32)cc1 ; c1ccc2c(c1)Oc1ccc(-c3ccc(-c4ccc5c(c4)C4(c6ccccc6-c6ccccc64)c4ccccc4-5)c4ccccc34)c3cccc-2c13 ; c1ccc2c(c1)Oc1ccc(-c3ccc4cc(-c5ccc6c(c5)C5(c7ccccc7-c7ccccc75)c5ccccc5-6)ccc4c3)c3cccc-2c13]

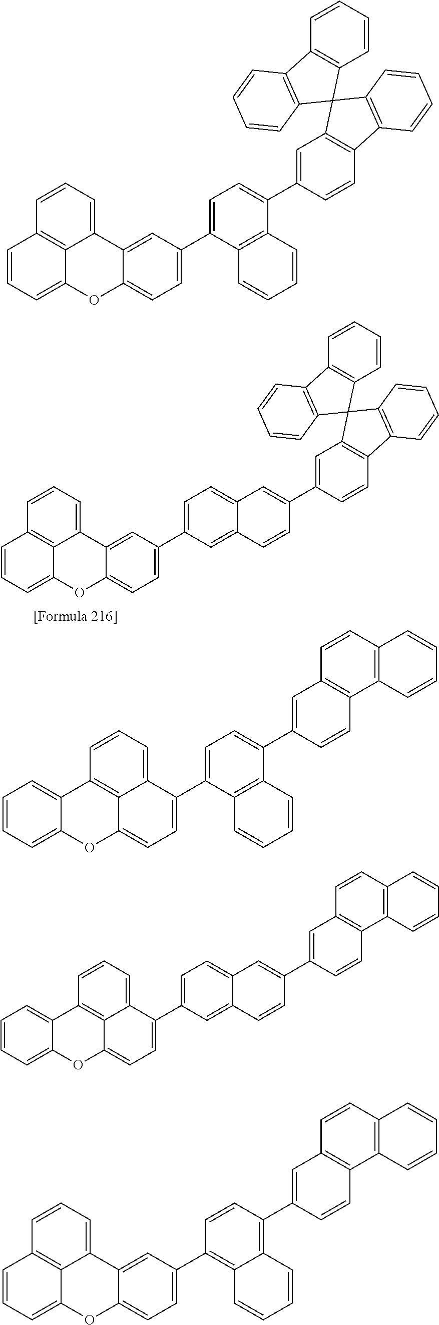 [SMILES: c1ccc2c(c1)-c1ccccc1C21c2ccccc2-c2ccc(-c3ccc(-c4ccc5c(c4)-c4cccc6cccc(c46)O5)c4ccccc34)cc21 ; c1ccc2c(c1)-c1ccccc1C21c2ccccc2-c2ccc(-c3ccc4cc(-c5ccc6c(c5)-c5cccc7cccc(c57)O6)ccc4c3)cc21 ; c1ccc2c(c1)Oc1ccc(-c3ccc(-c4ccc5c(ccc6ccccc65)c4)c4ccccc34)c3cccc-2c13 ; c1ccc2c(c1)Oc1ccc(-c3ccc4cc(-c5ccc6c(ccc7ccccc76)c5)ccc4c3)c3cccc-2c13 ; c1cc2c3c(cccc3c1)-c1cc(-c3ccc(-c4ccc5c(ccc6ccccc65)c4)c4ccccc34)ccc1O2]

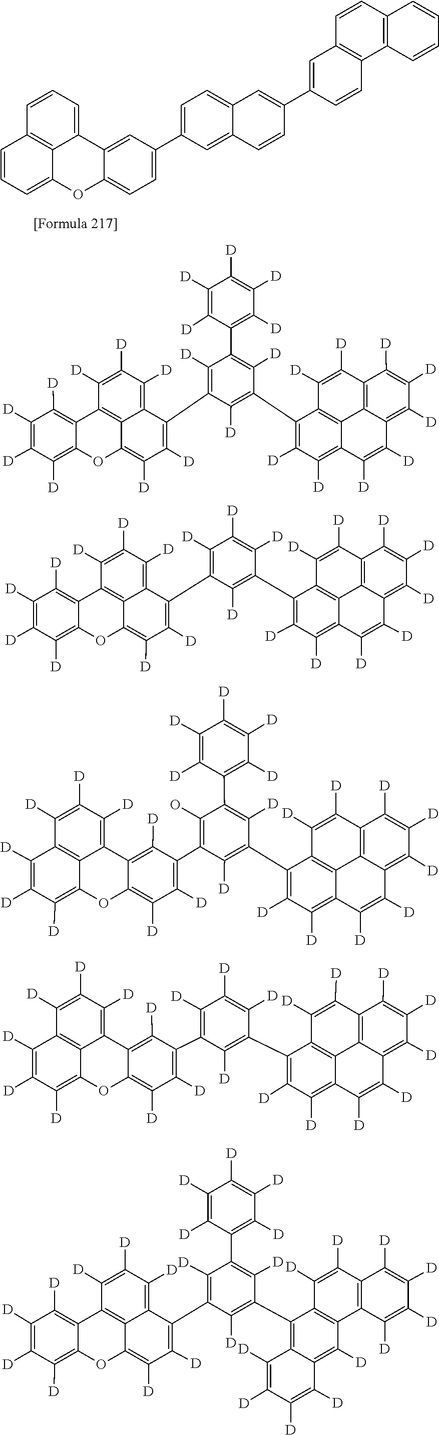

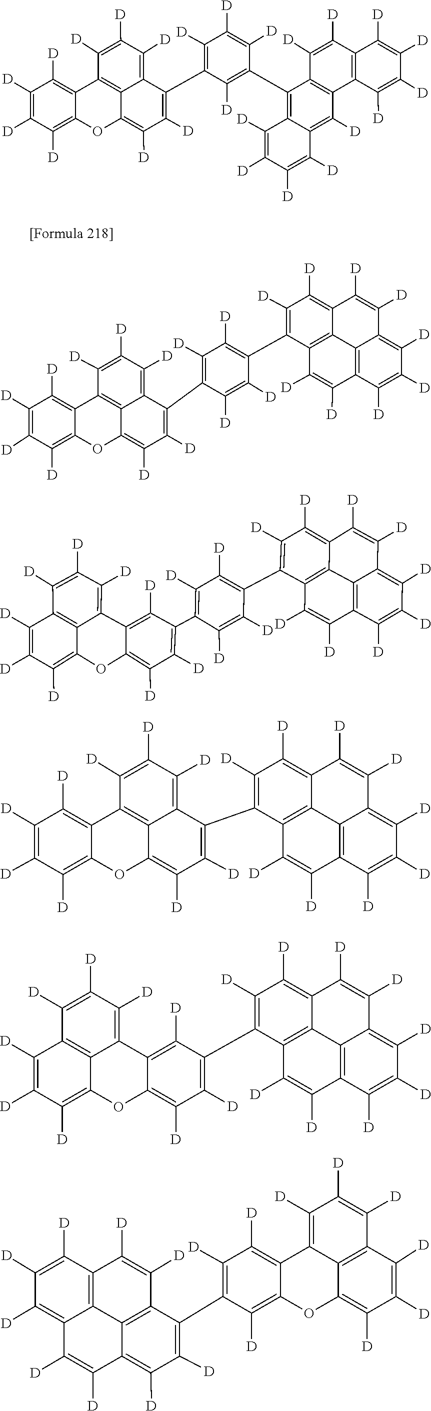

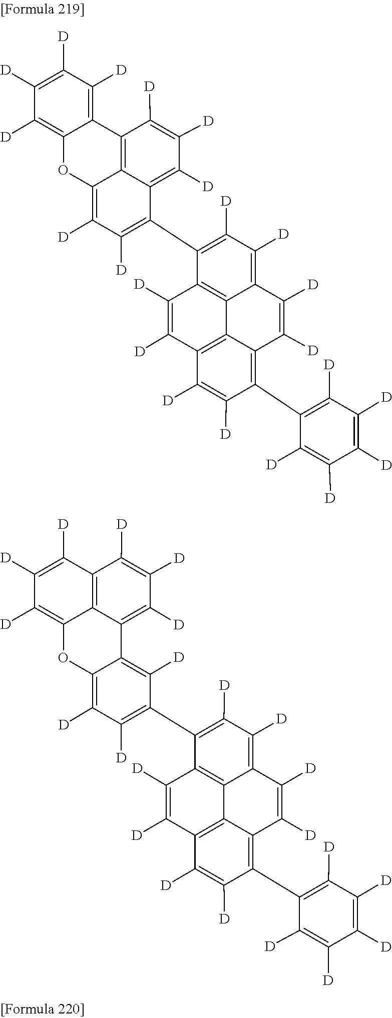 [SMILES: [2H]c1c([2H])c([2H])c(-c2c([2H])c([2H])c3c([2H])c([2H])c4c(-c5c([2H])c([2H])c6c7c(c([2H])c([2H])c([2H])c57)-c5c([2H])c([2H])c([2H])c([2H])c5O6)c([2H])c([2H])c5c([2H])c([2H])c2c3c54)c([2H])c1[2H] ; [2H]c1c([2H])c([2H])c(-c2c([2H])c([2H])c3c([2H])c([2H])c4c(-c5c([2H])c([2H])c6c(c5[2H])-c5c([2H])c([2H])c([2H])c7c([2H])c([2H])c([2H])c(c57)O6)c([2H])c([2H])c5c([2H])c([2H])c2c3c54)c([2H])c1[2H]]

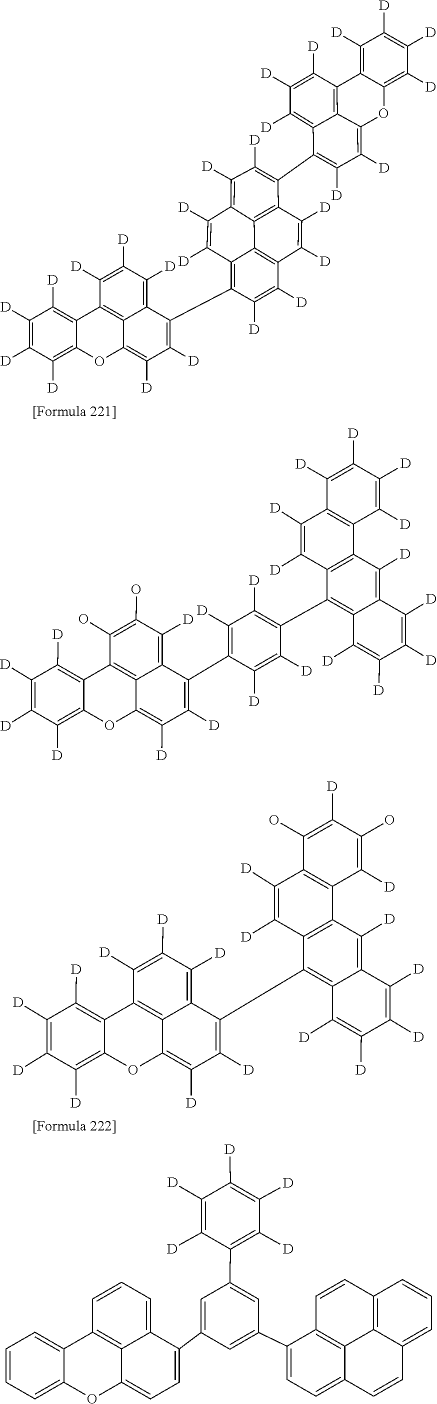

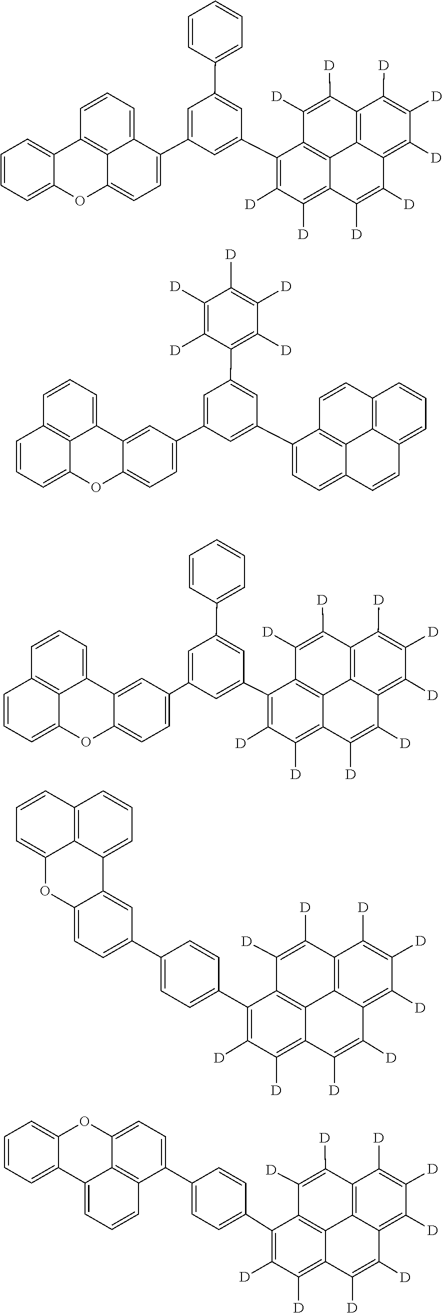

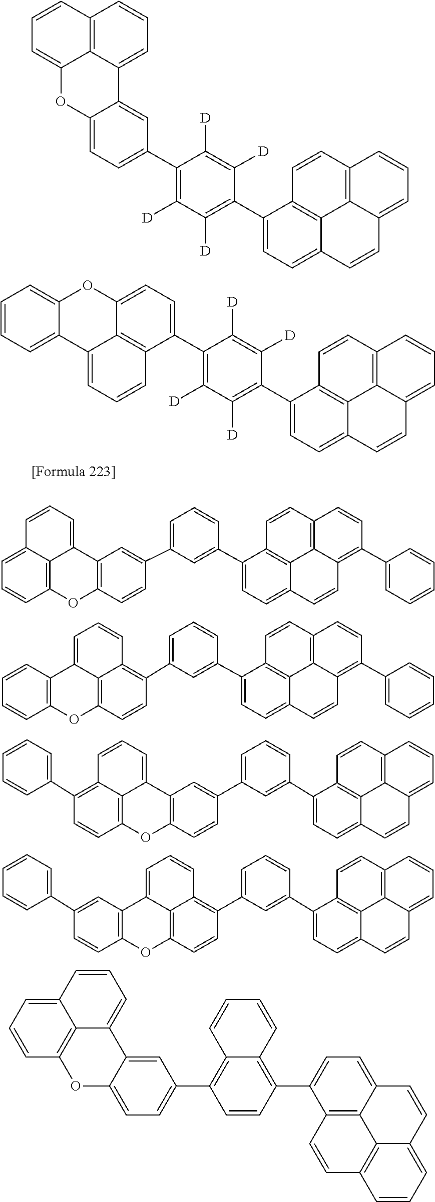

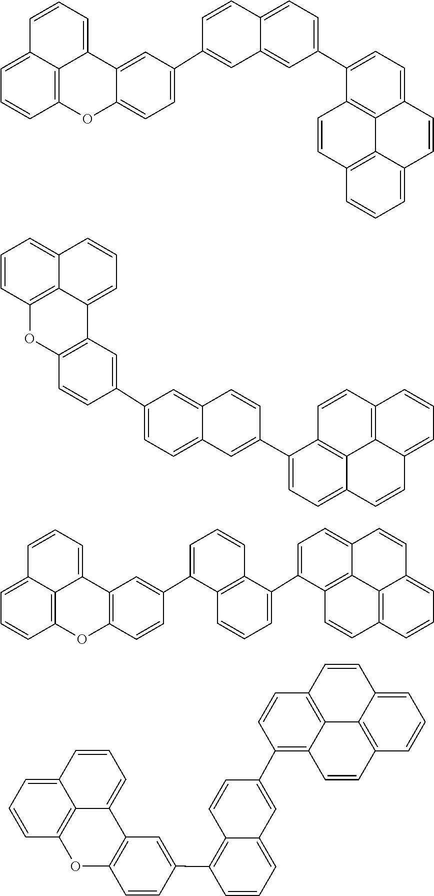

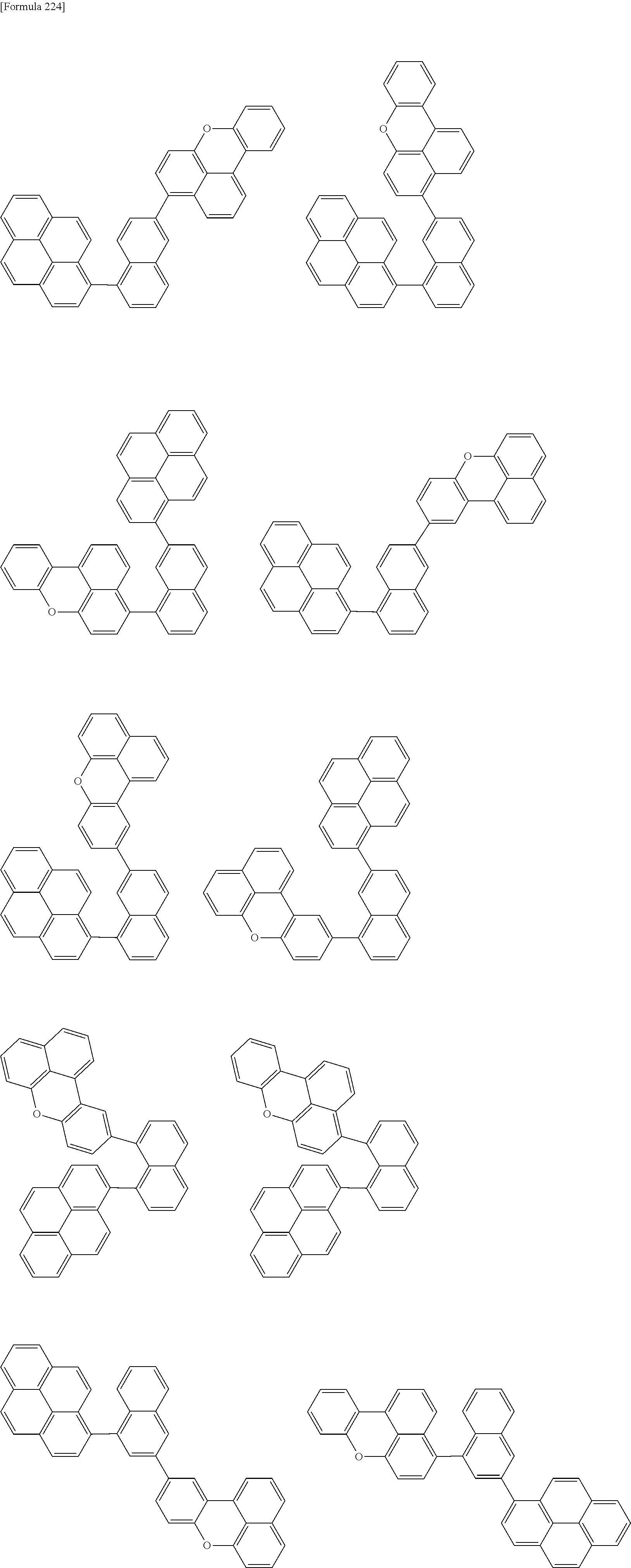

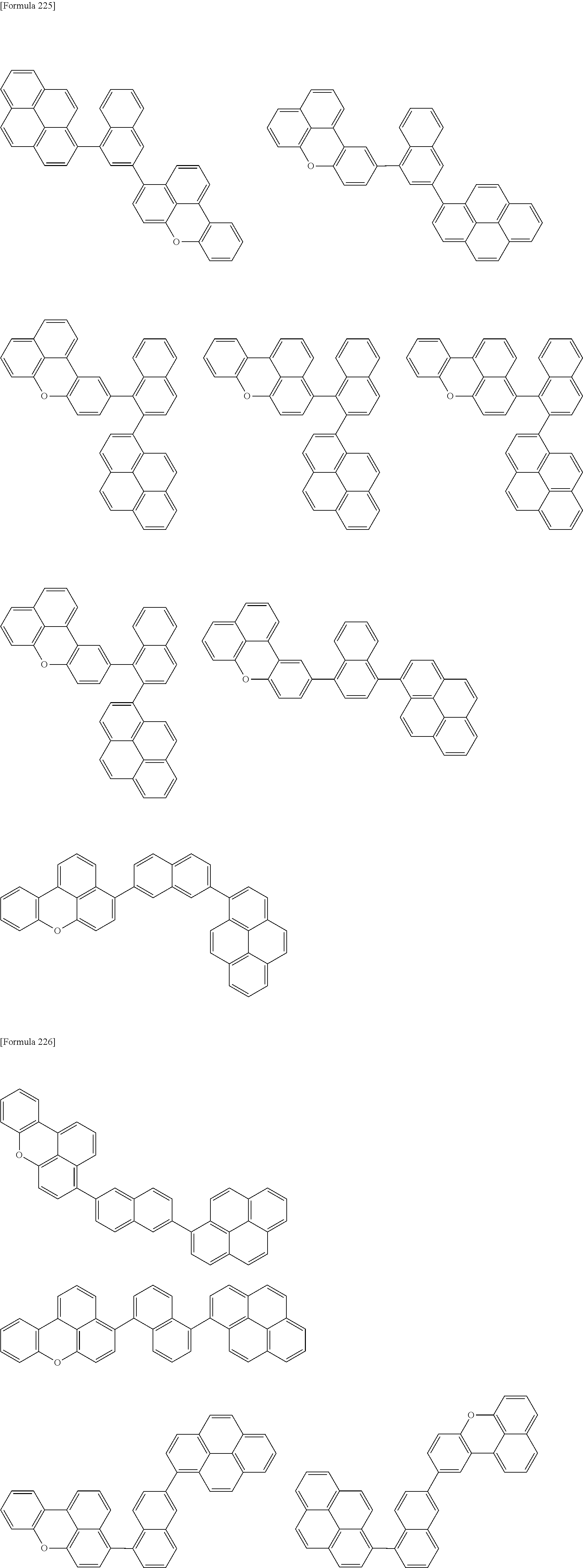

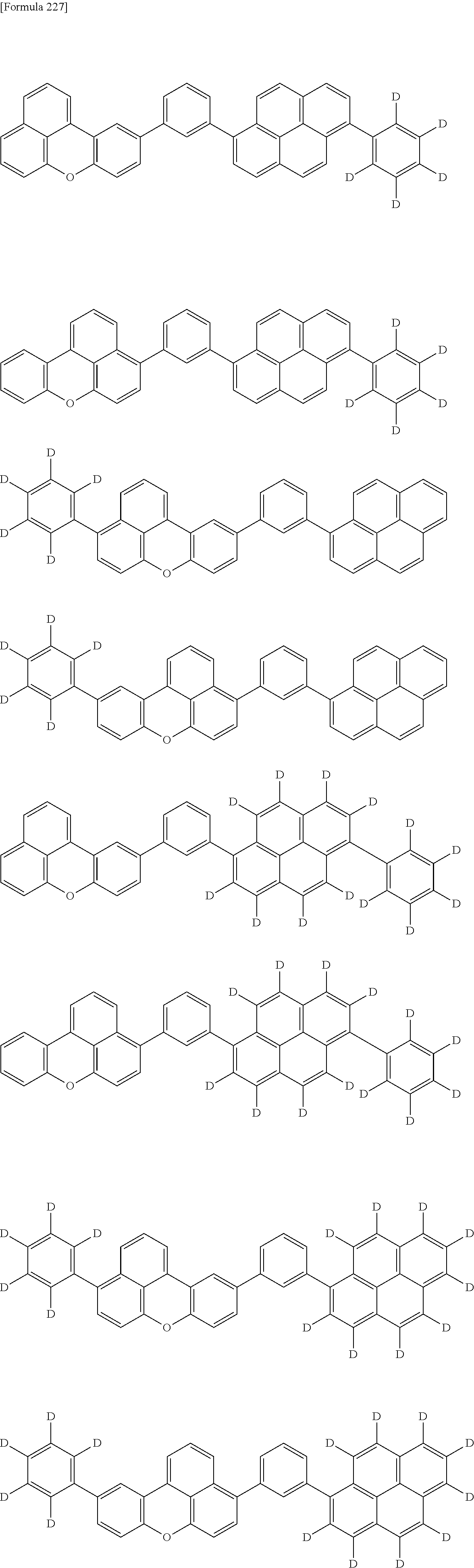

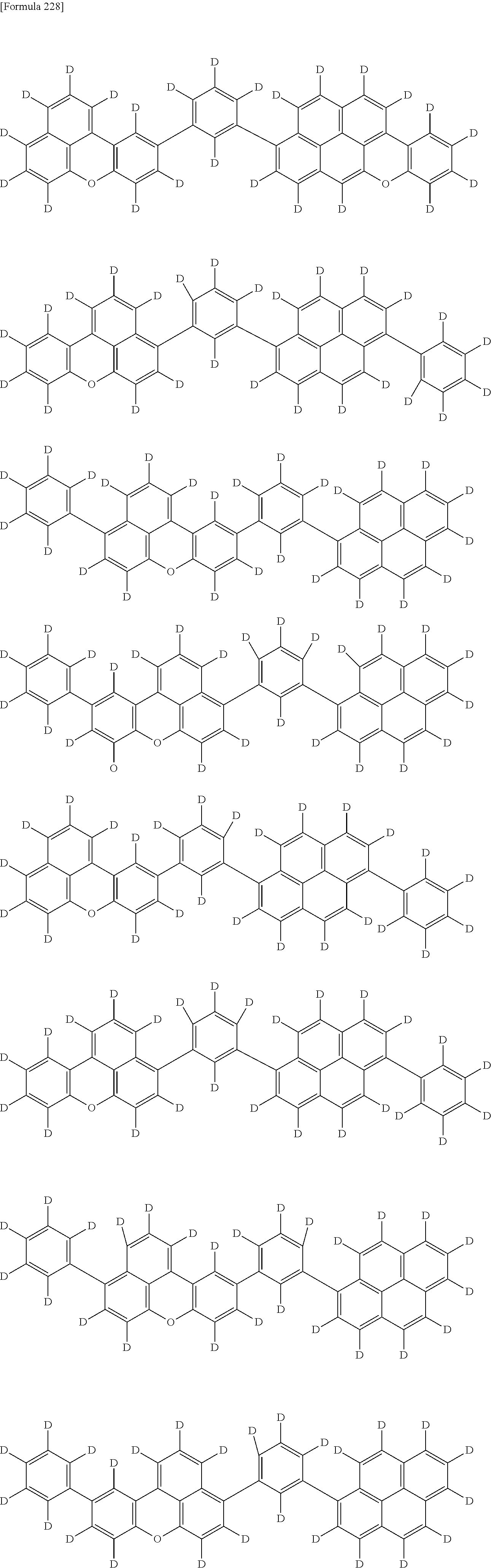

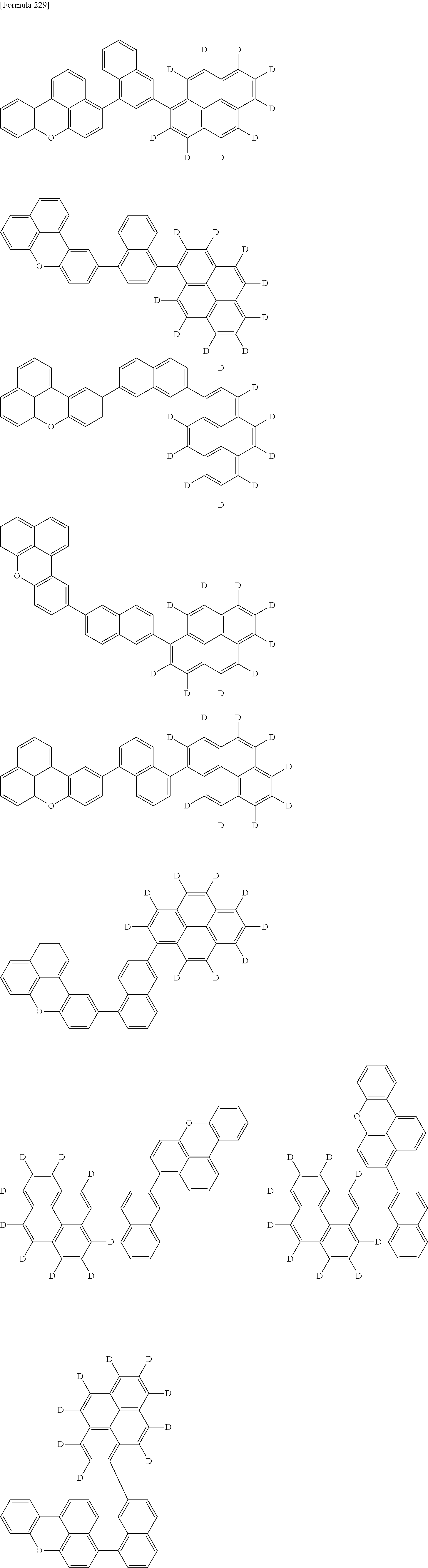

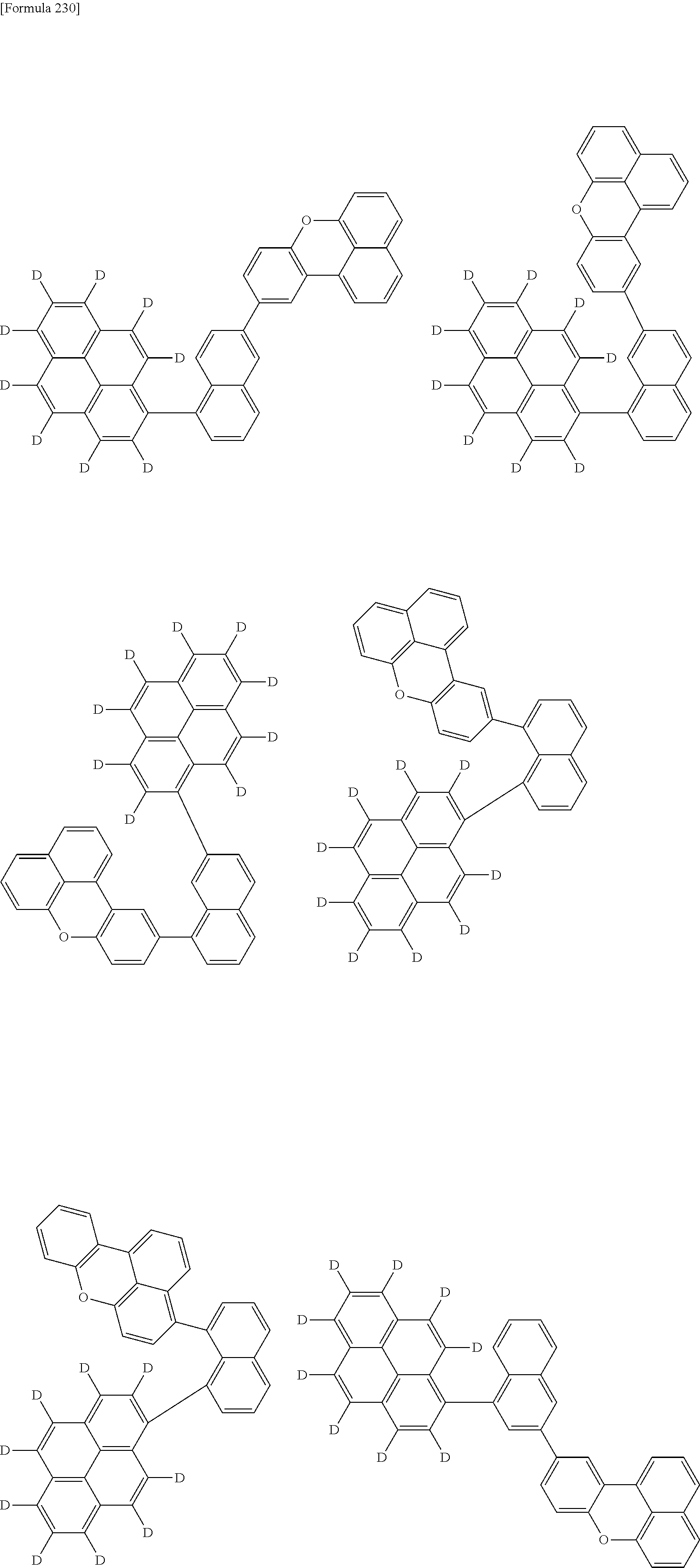

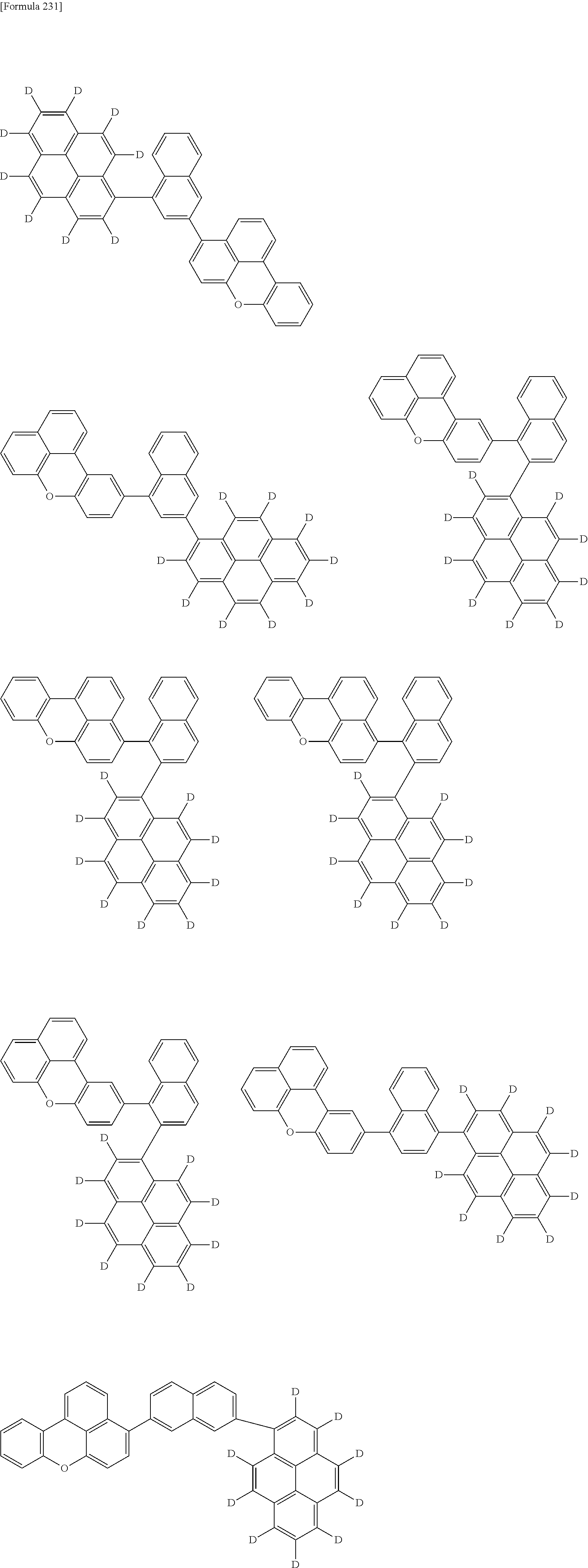

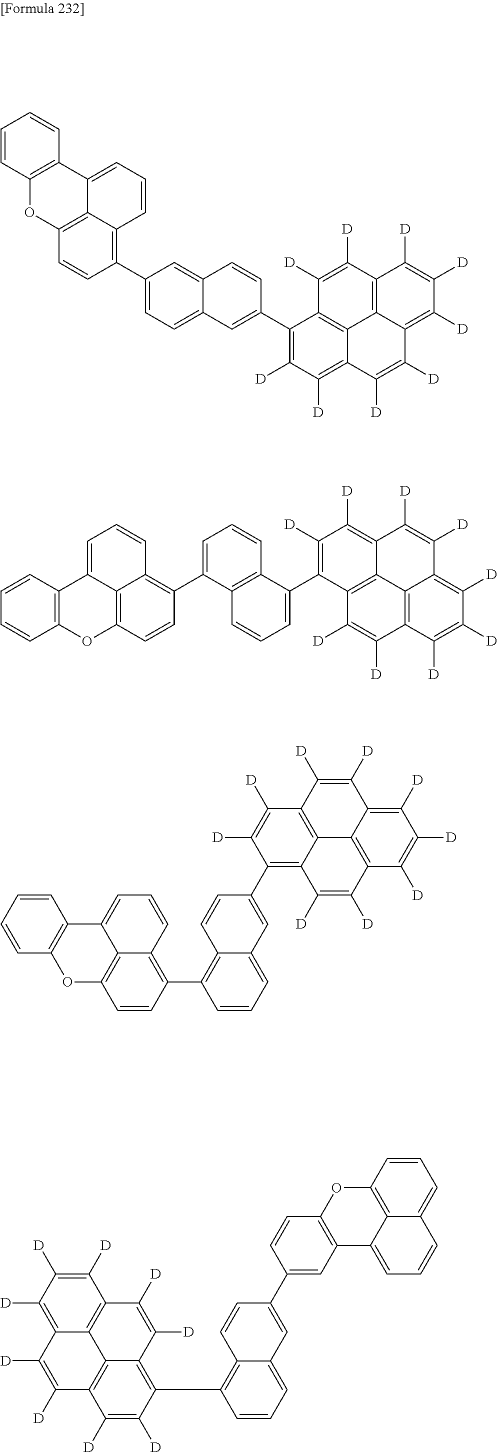

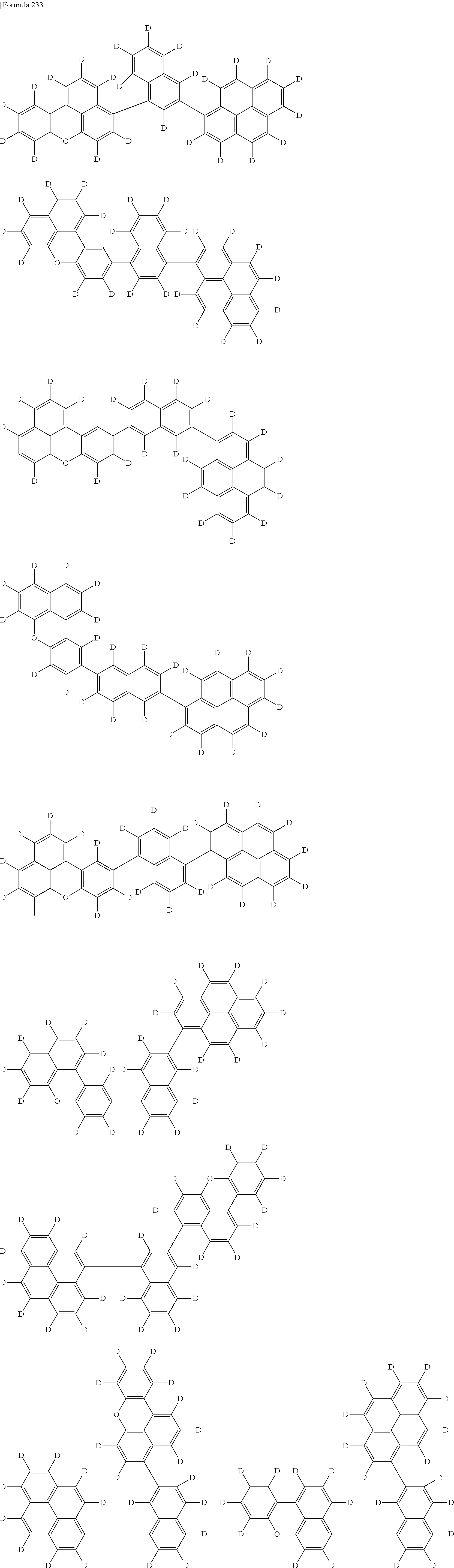

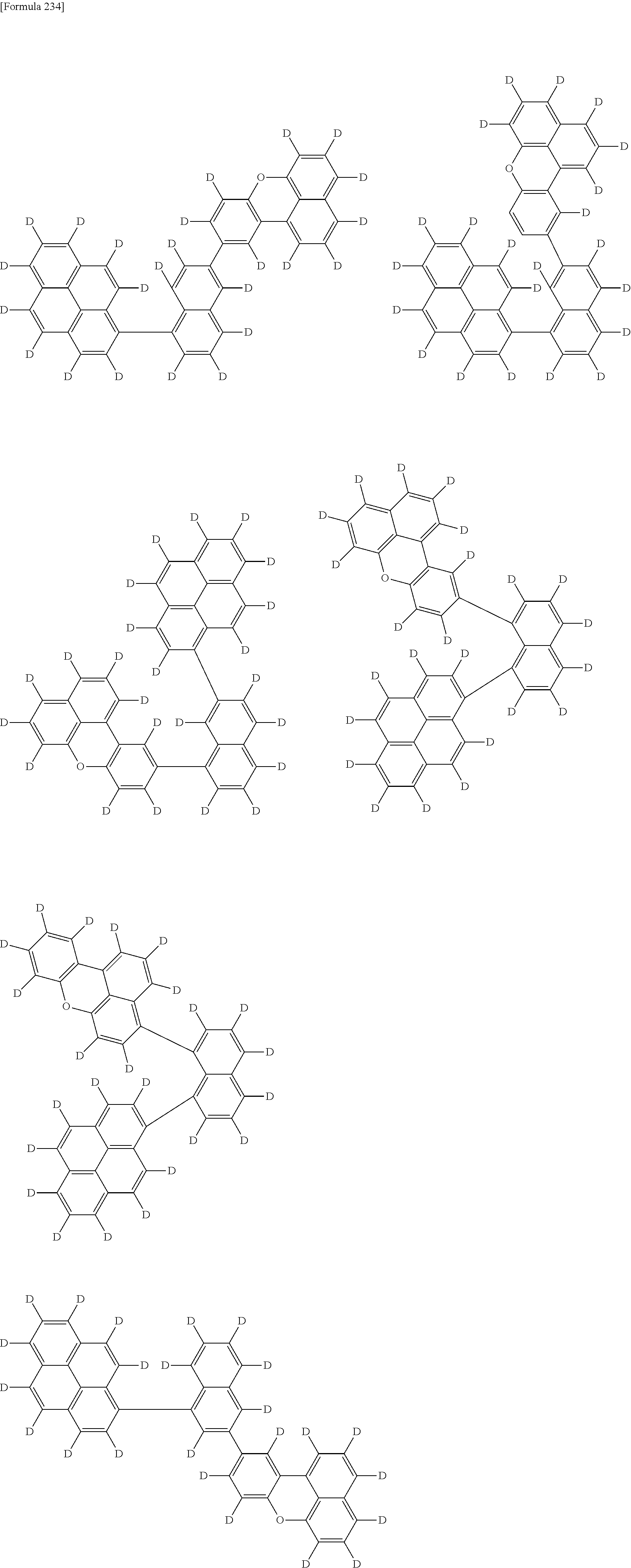

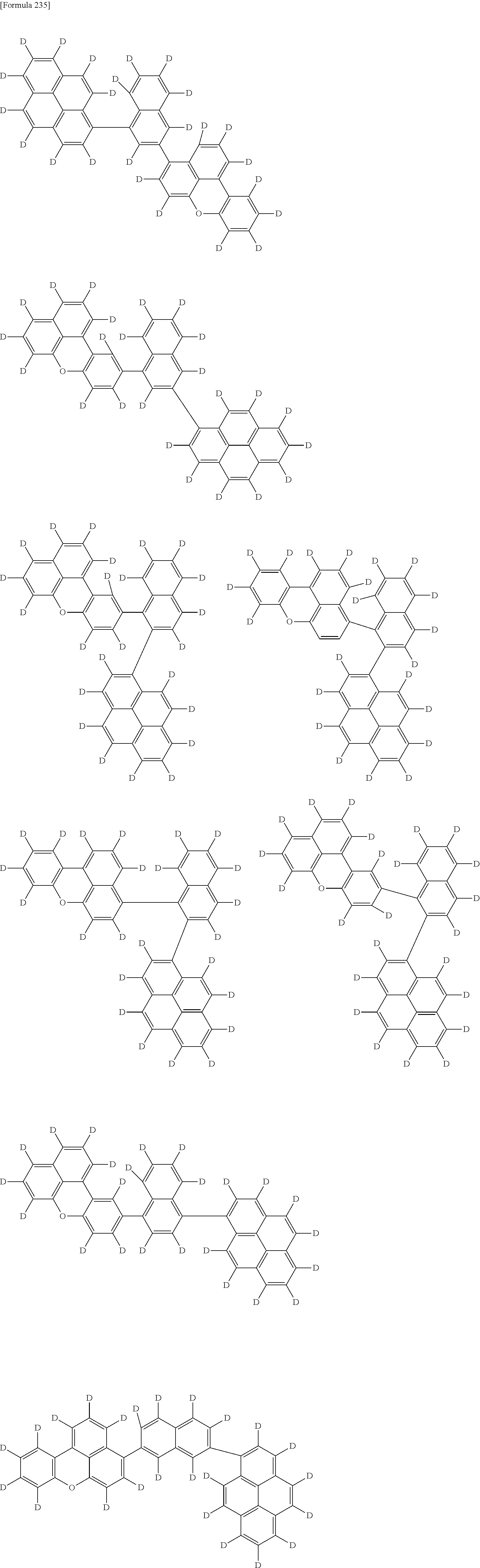

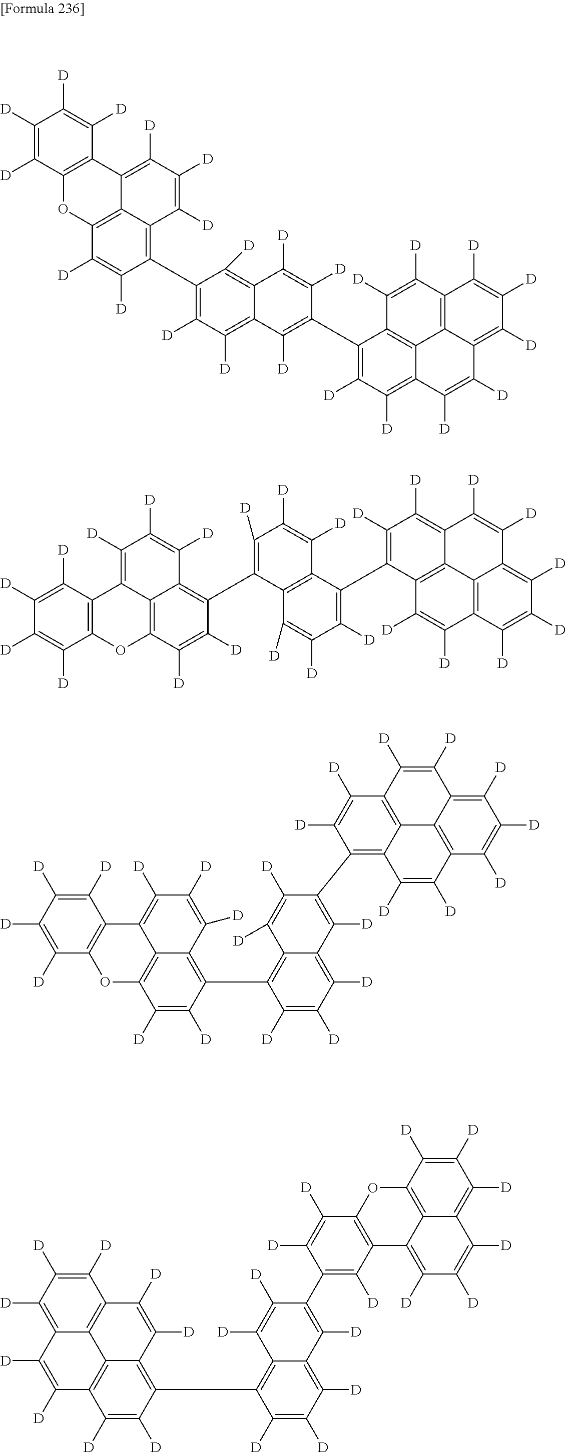

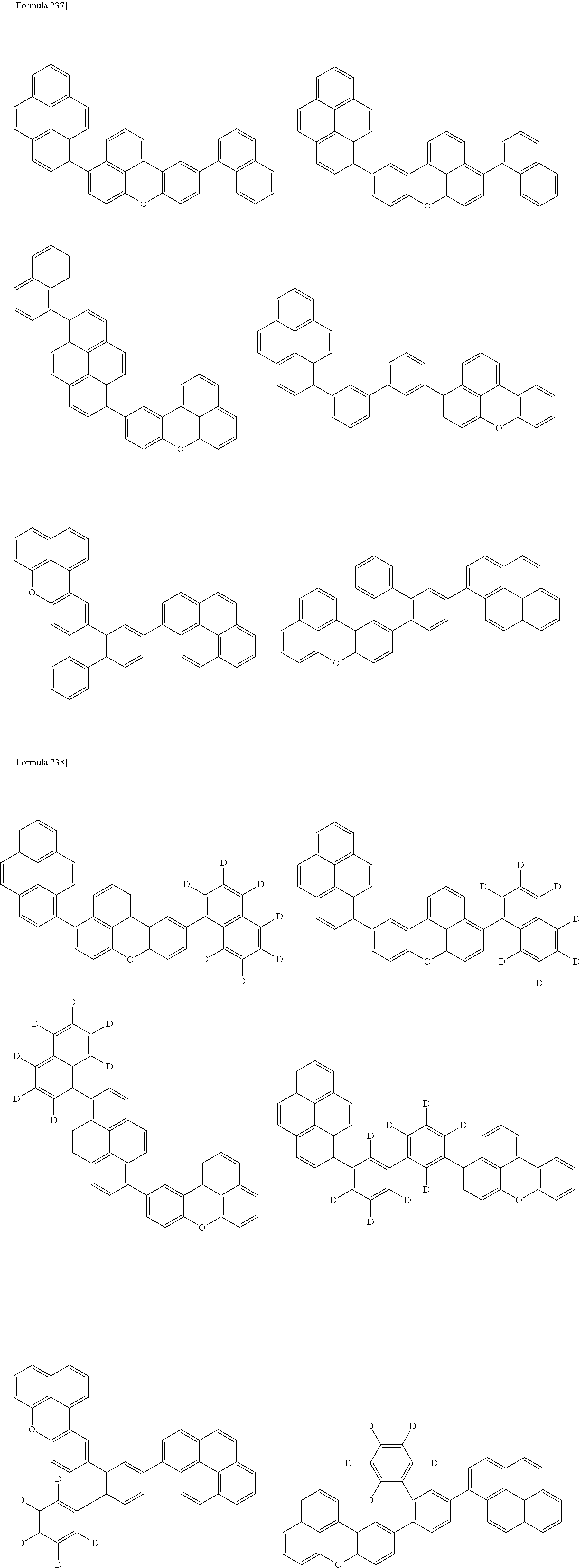

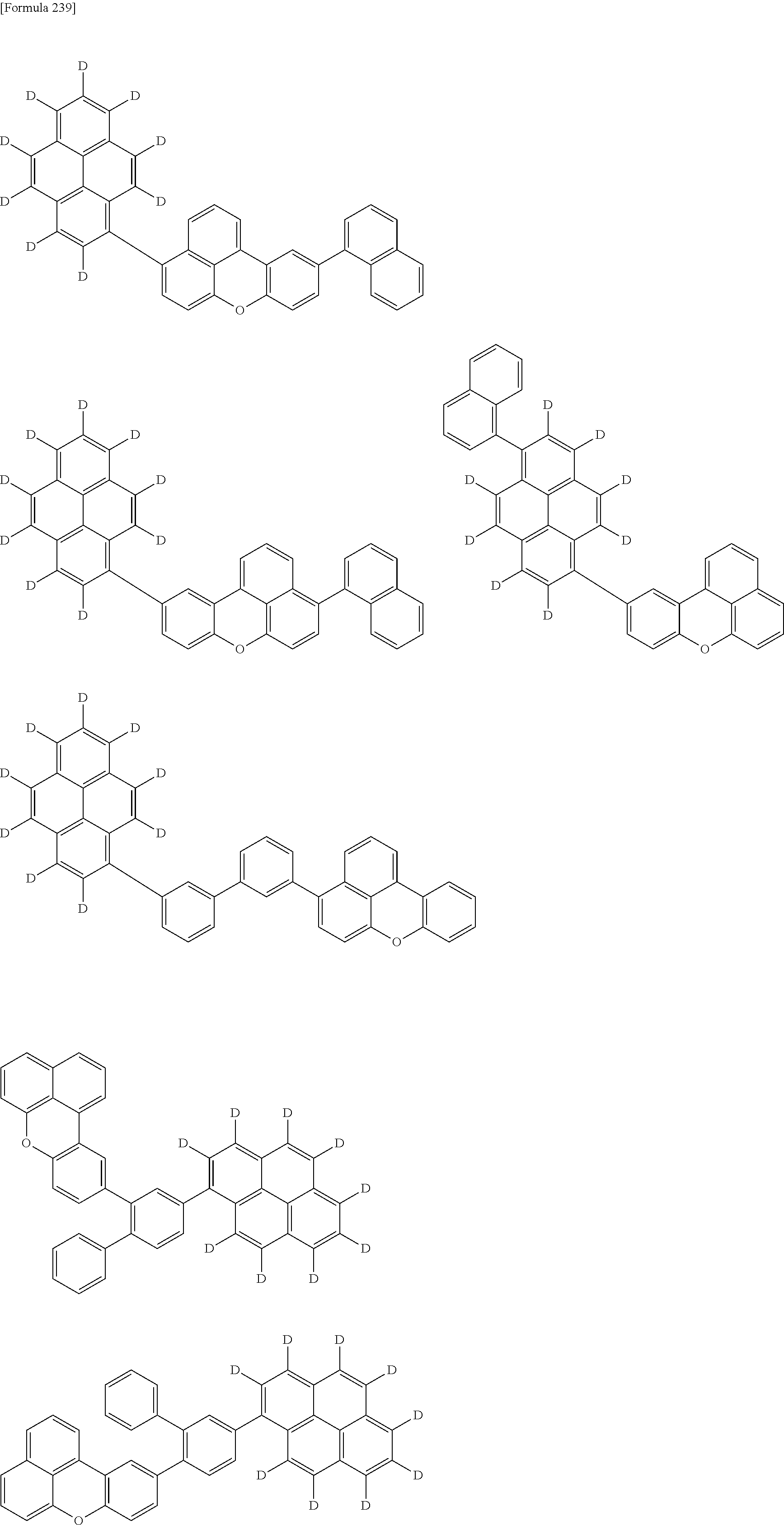

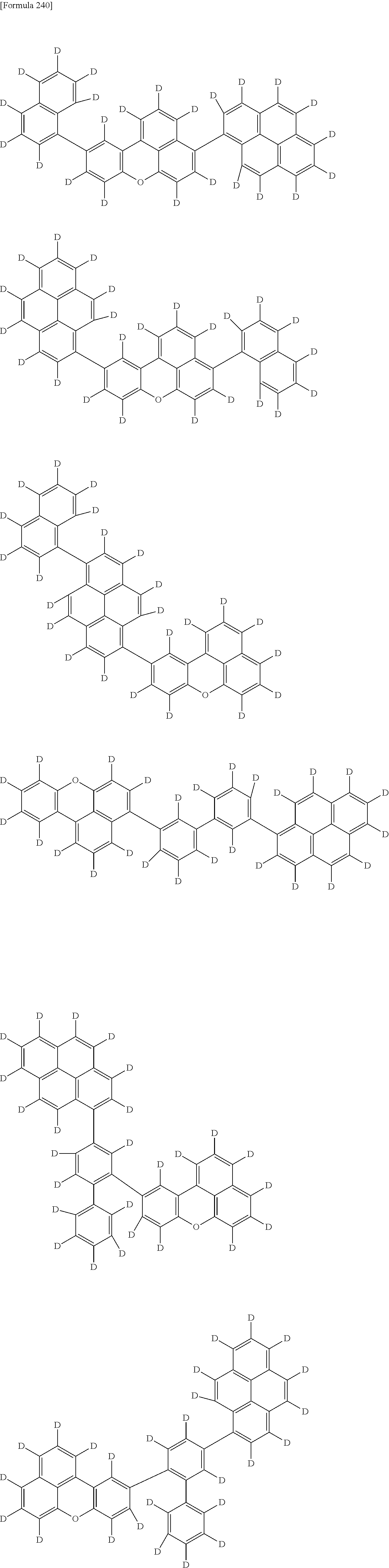

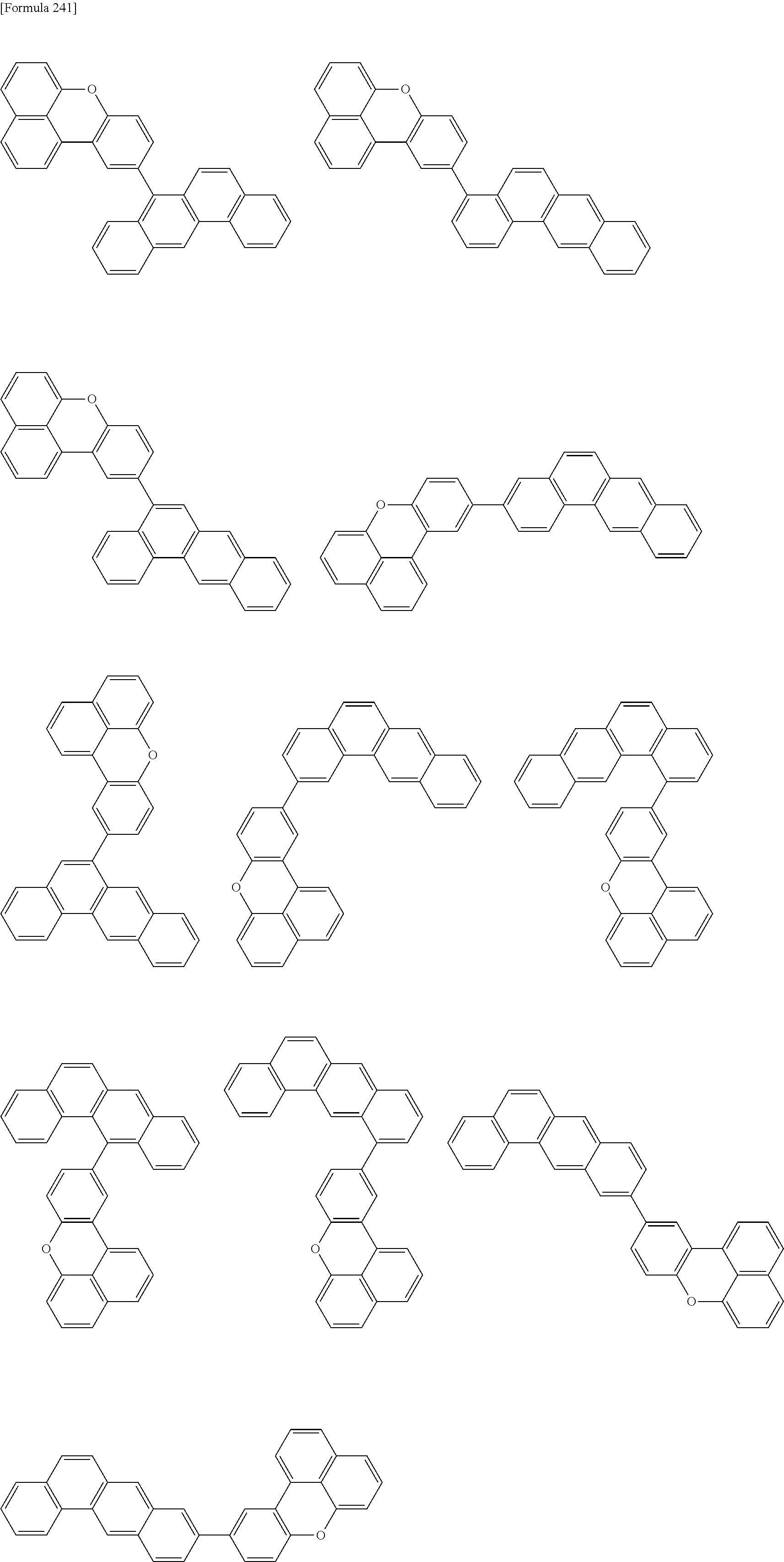

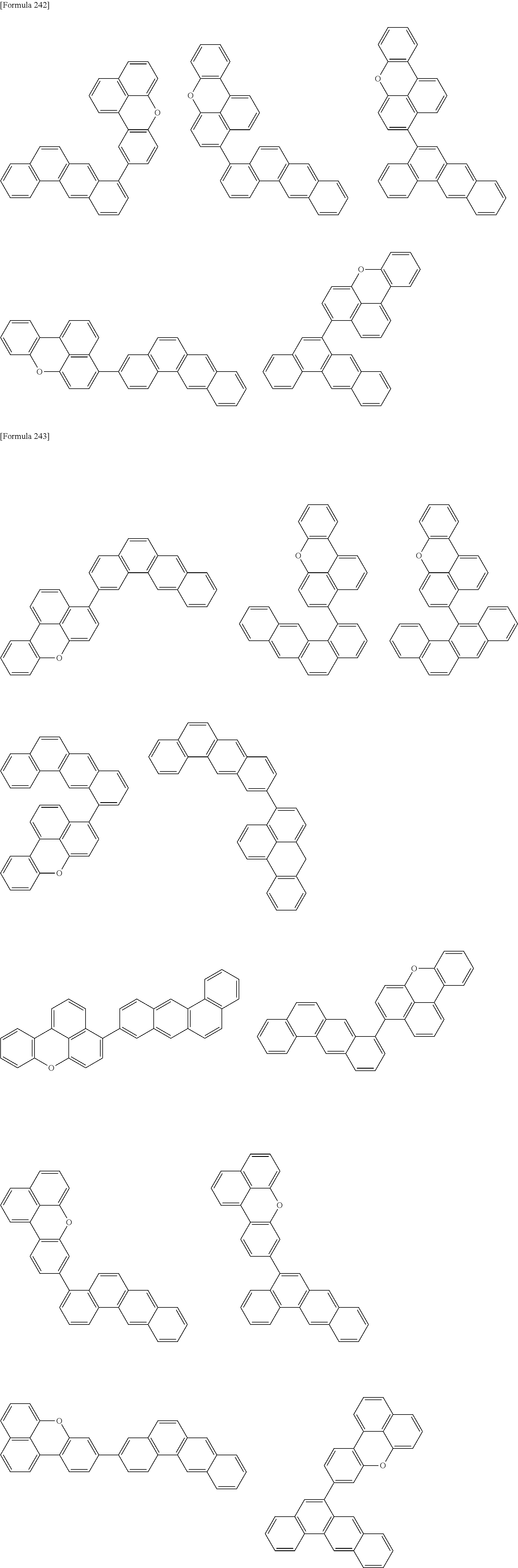

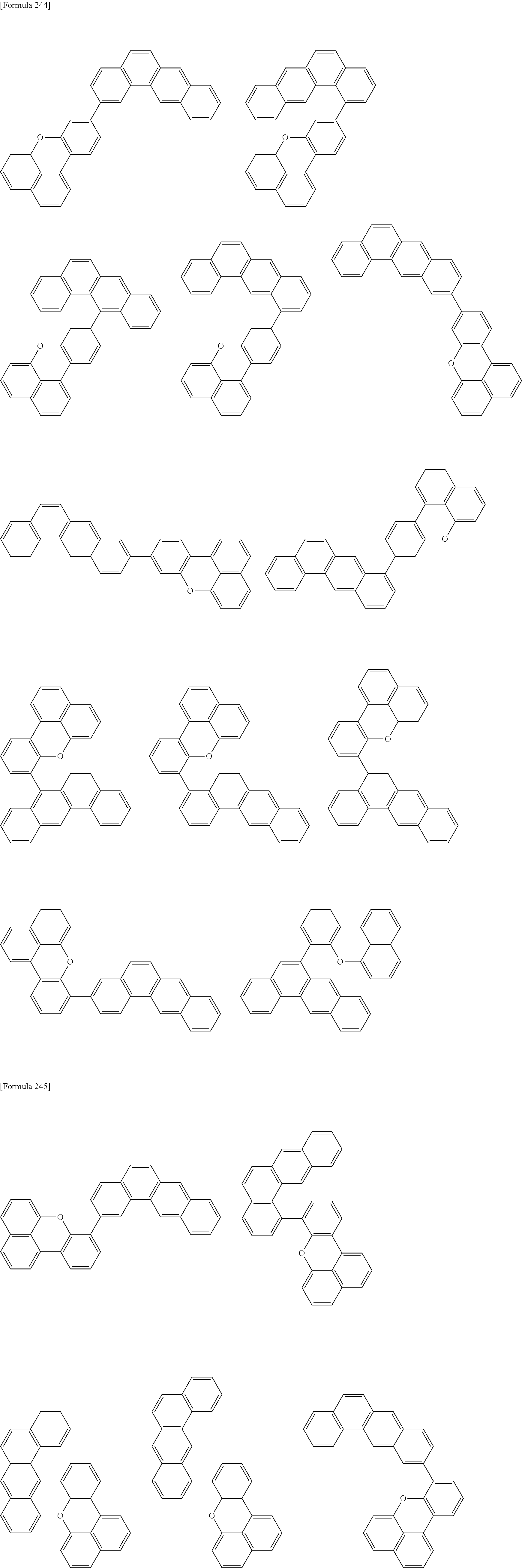

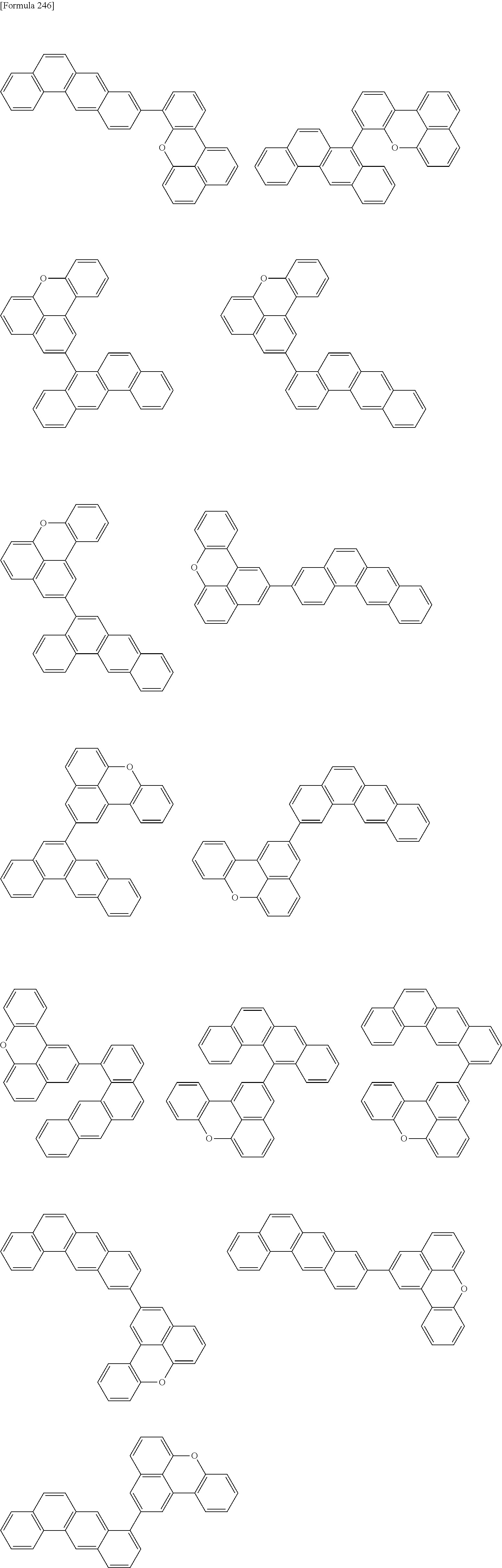

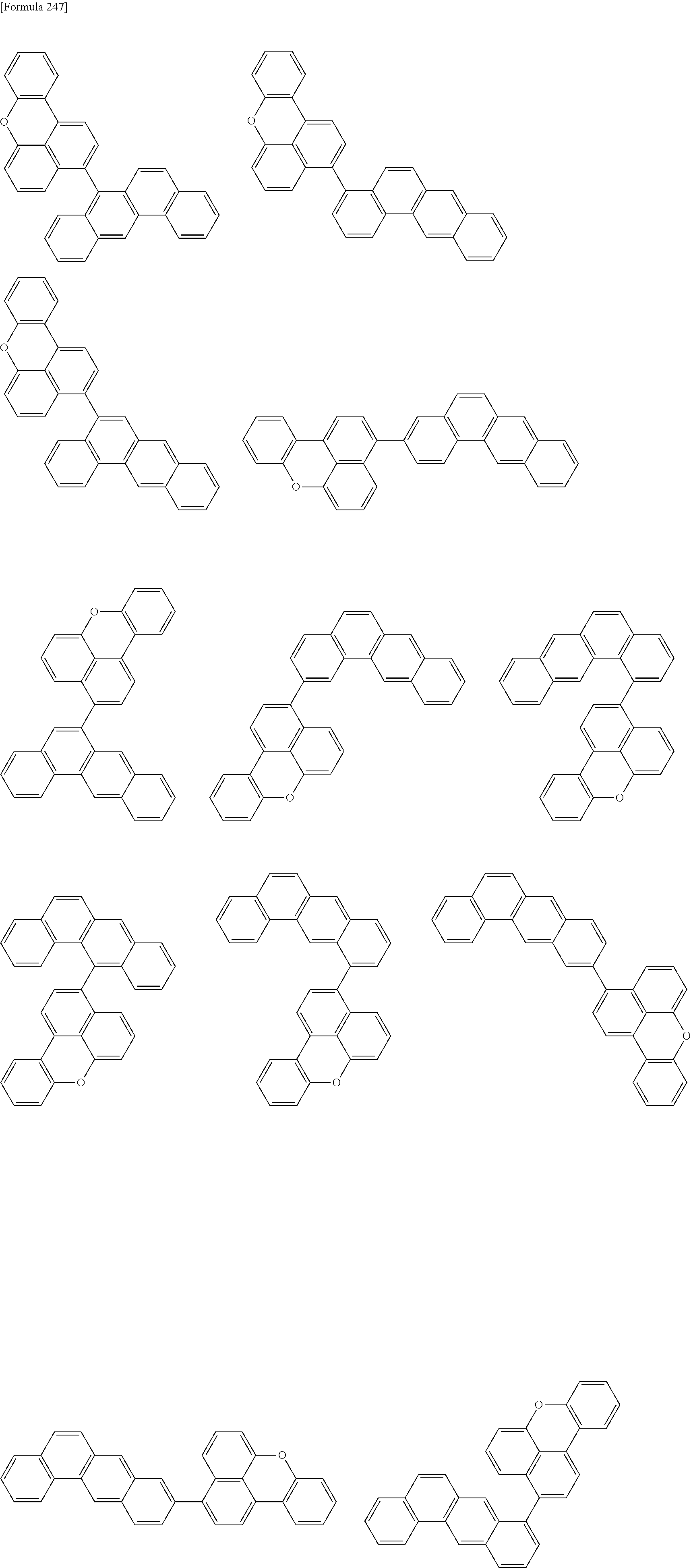

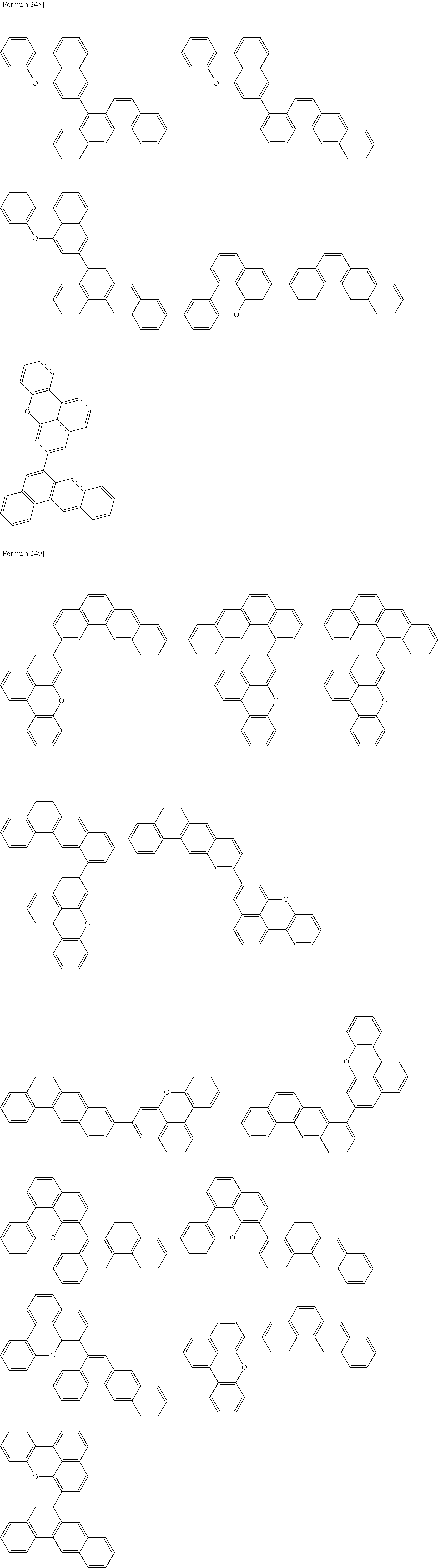

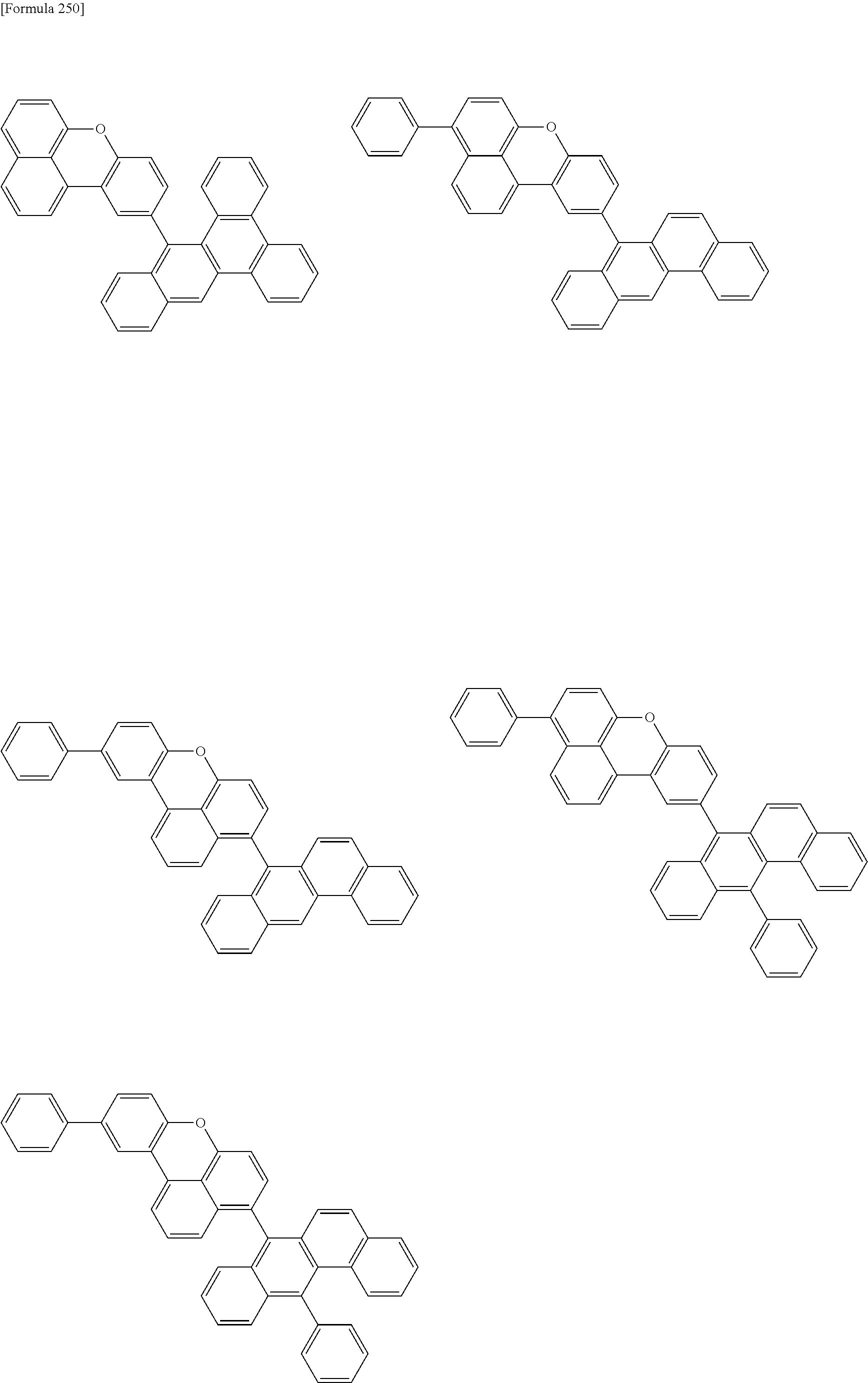 [SMILES: c1ccc2c(-c3ccc4c(c3)-c3cccc5cccc(c35)O4)c3c4ccccc4c4ccccc4c3cc2c1 ; c1ccc(-c2ccc3c4c(cccc24)-c2cc(-c4c5ccccc5cc5c4ccc4ccccc45)ccc2O3)cc1 ; c1ccc(-c2ccc3c(c2)-c2cccc4c(-c5c6ccccc6cc6c5ccc5ccccc56)ccc(c24)O3)cc1 ; c1ccc(-c2ccc3c4c(cccc24)-c2cc(-c4c5ccccc5c(-c5ccccc5)c5c4ccc4ccccc45)ccc2O3)cc1 ; c1ccc(-c2ccc3c(c2)-c2cccc4c(-c5c6ccccc6c(-c6ccccc6)c6c5ccc5ccccc56)ccc(c24)O3)cc1]

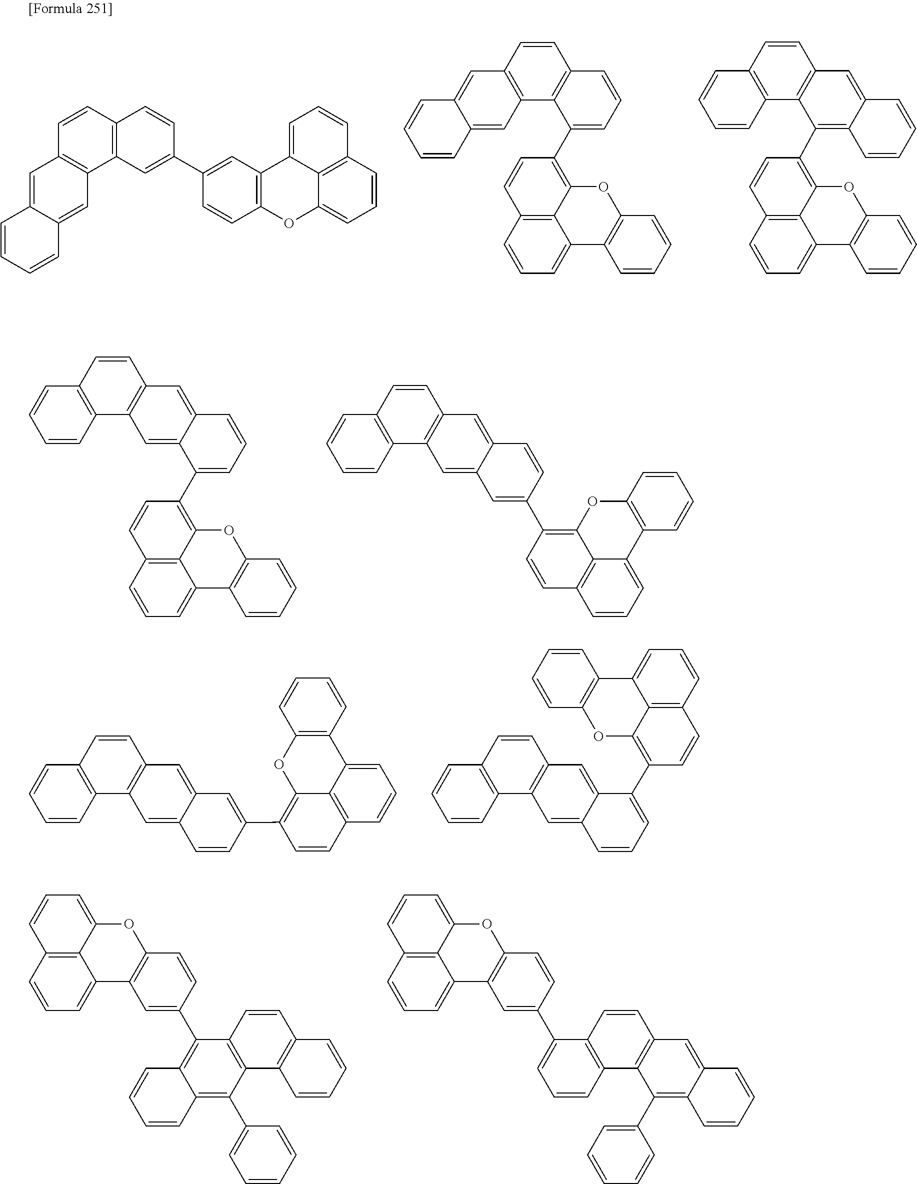

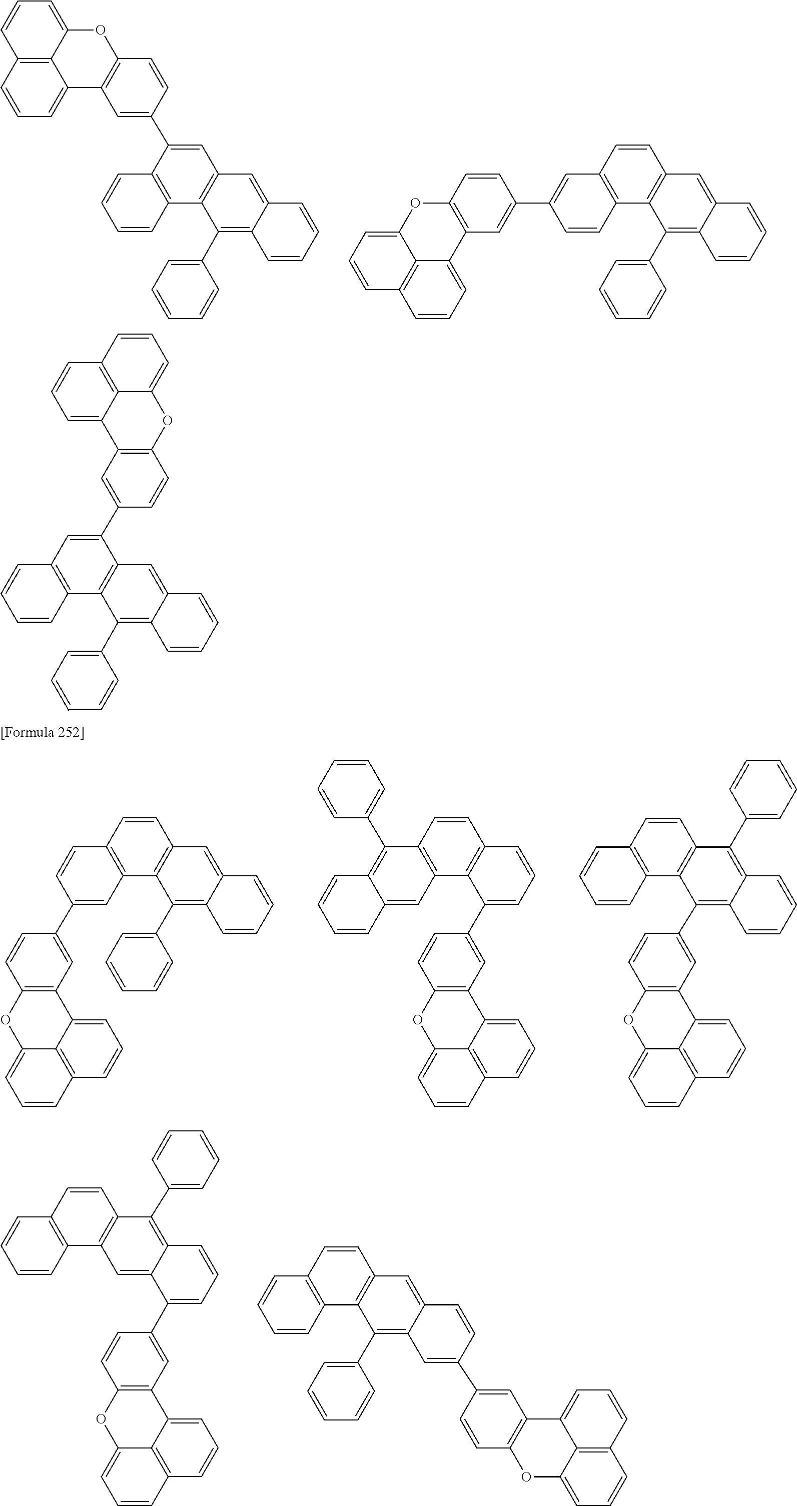

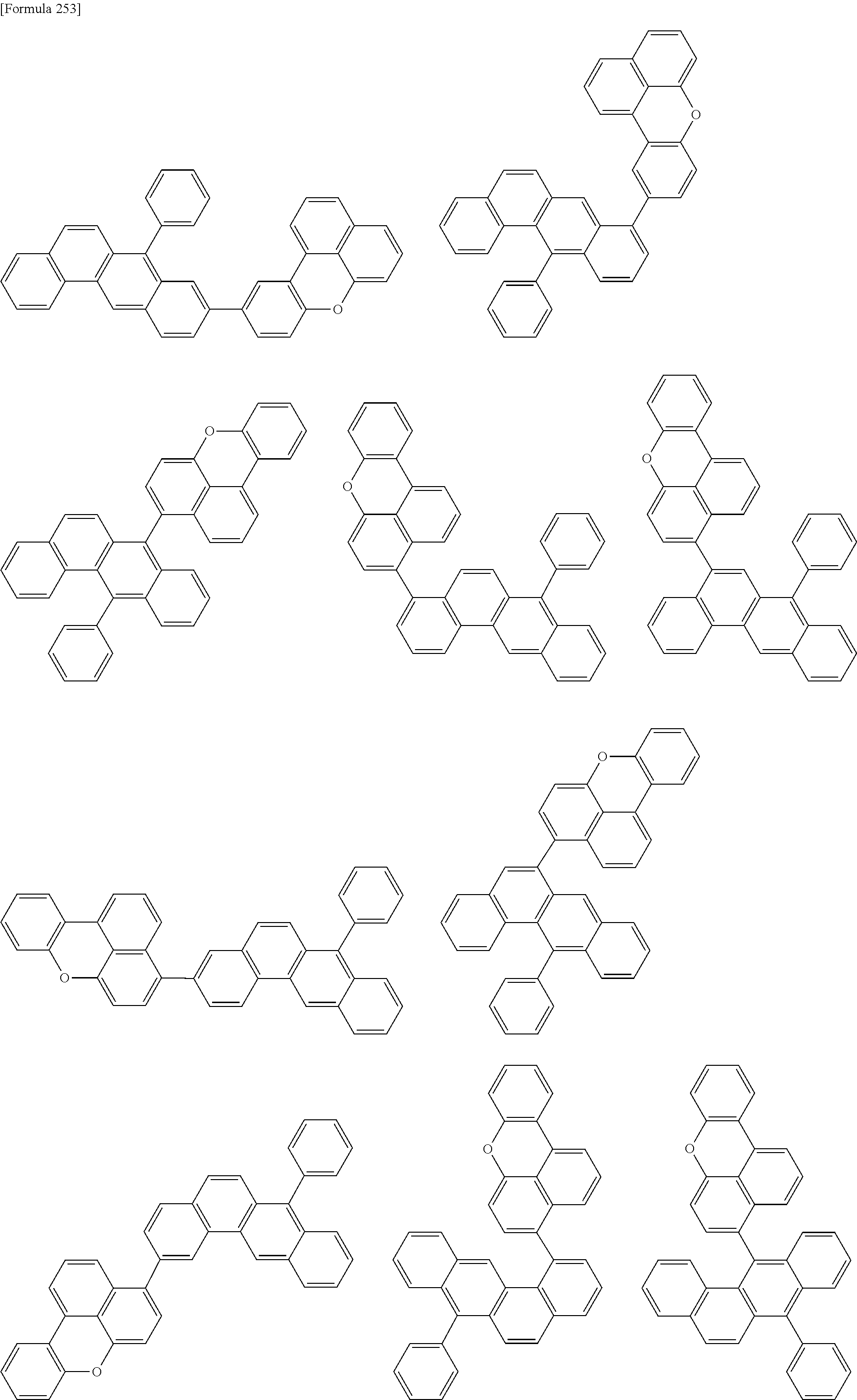

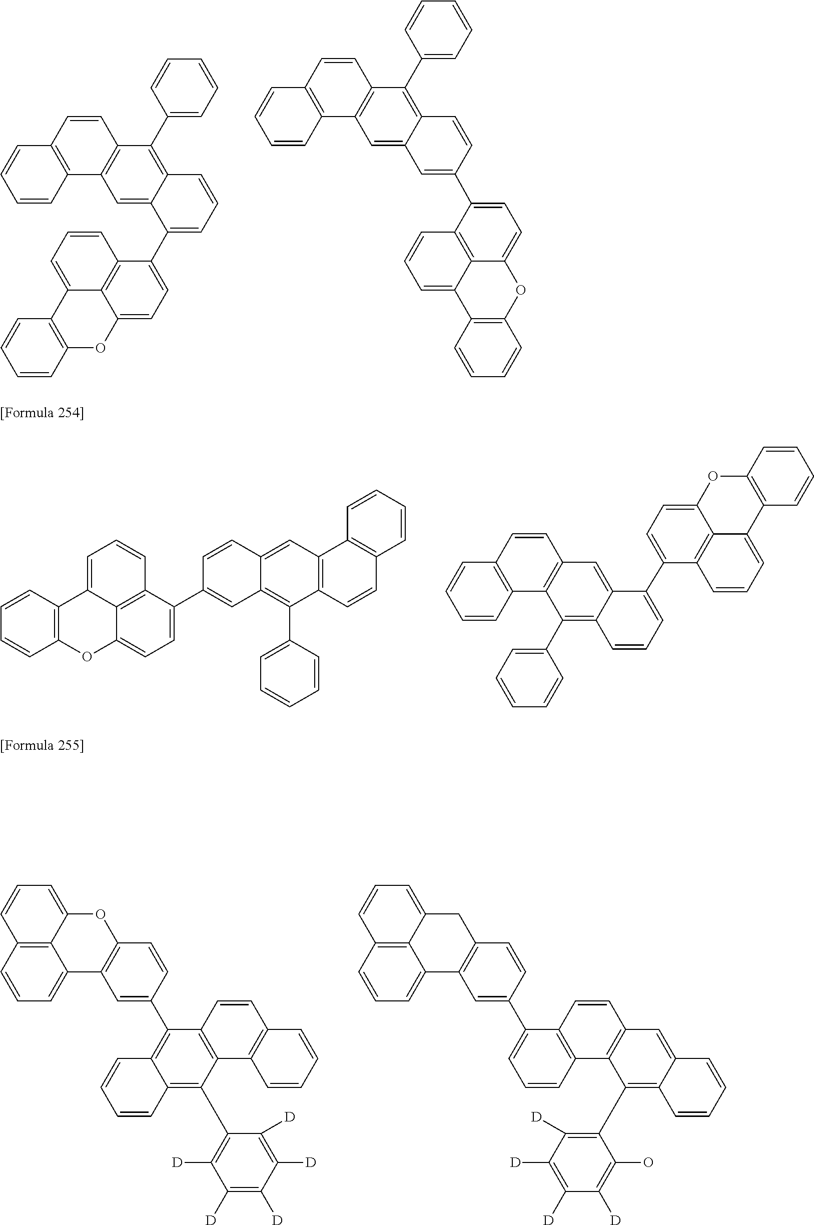

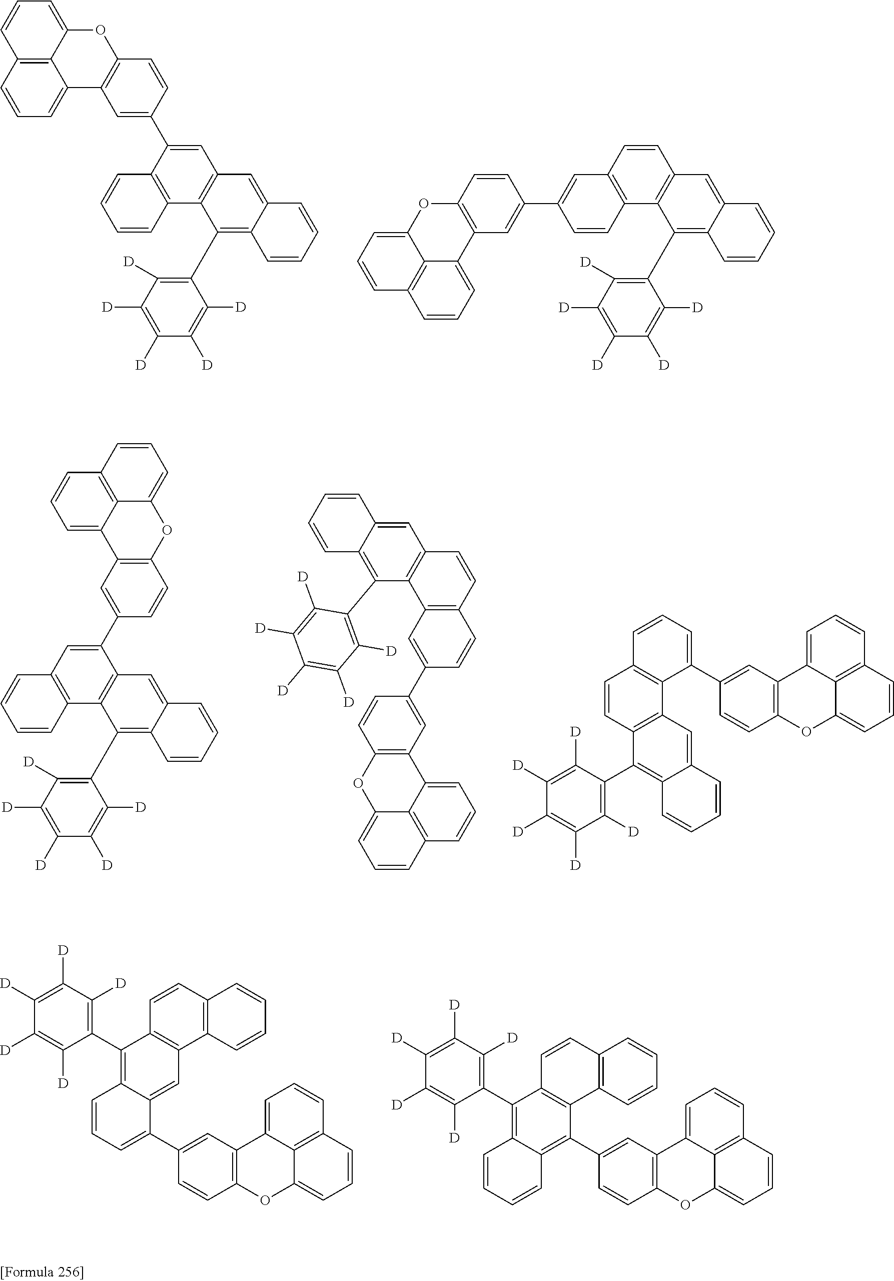

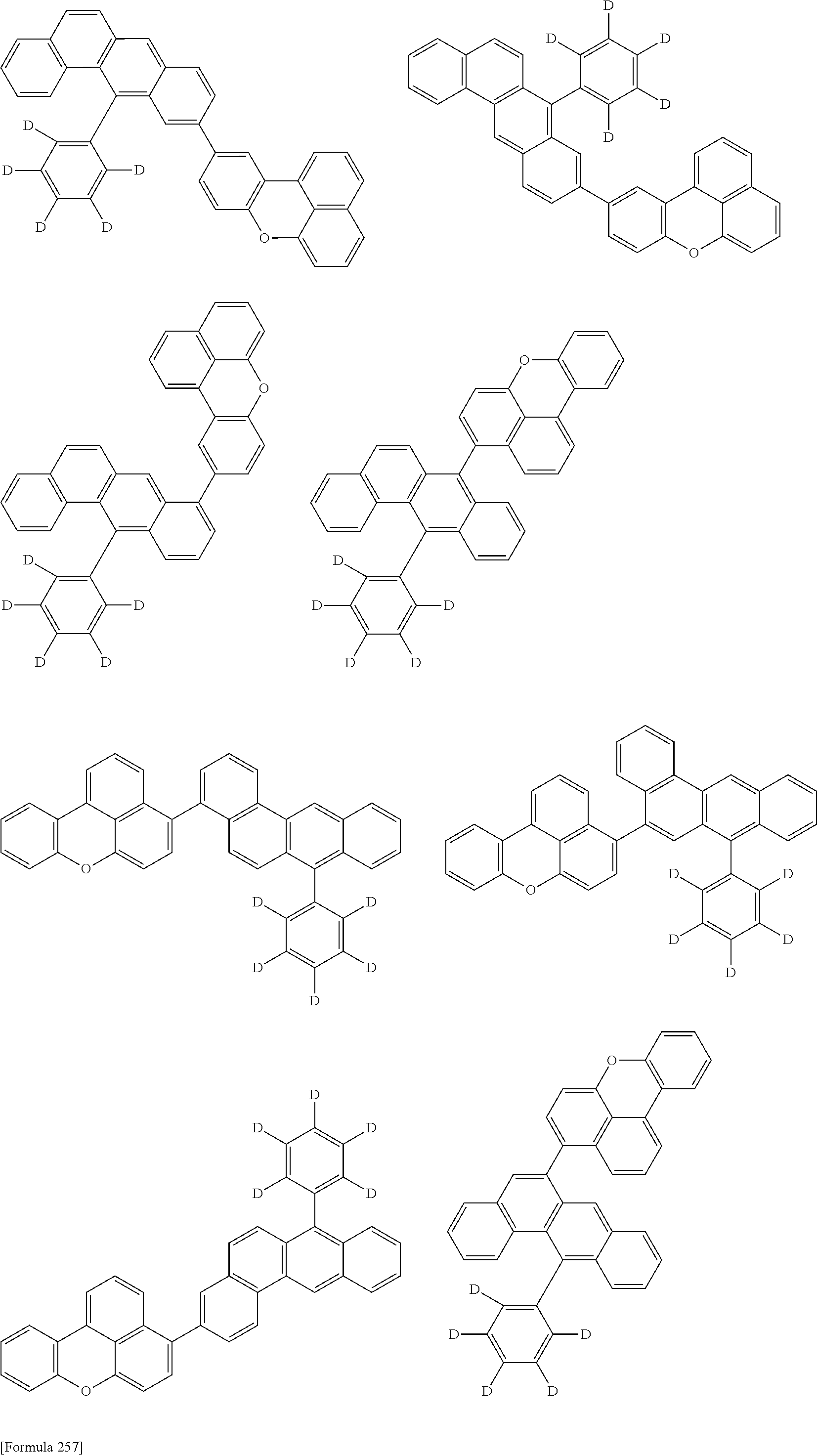

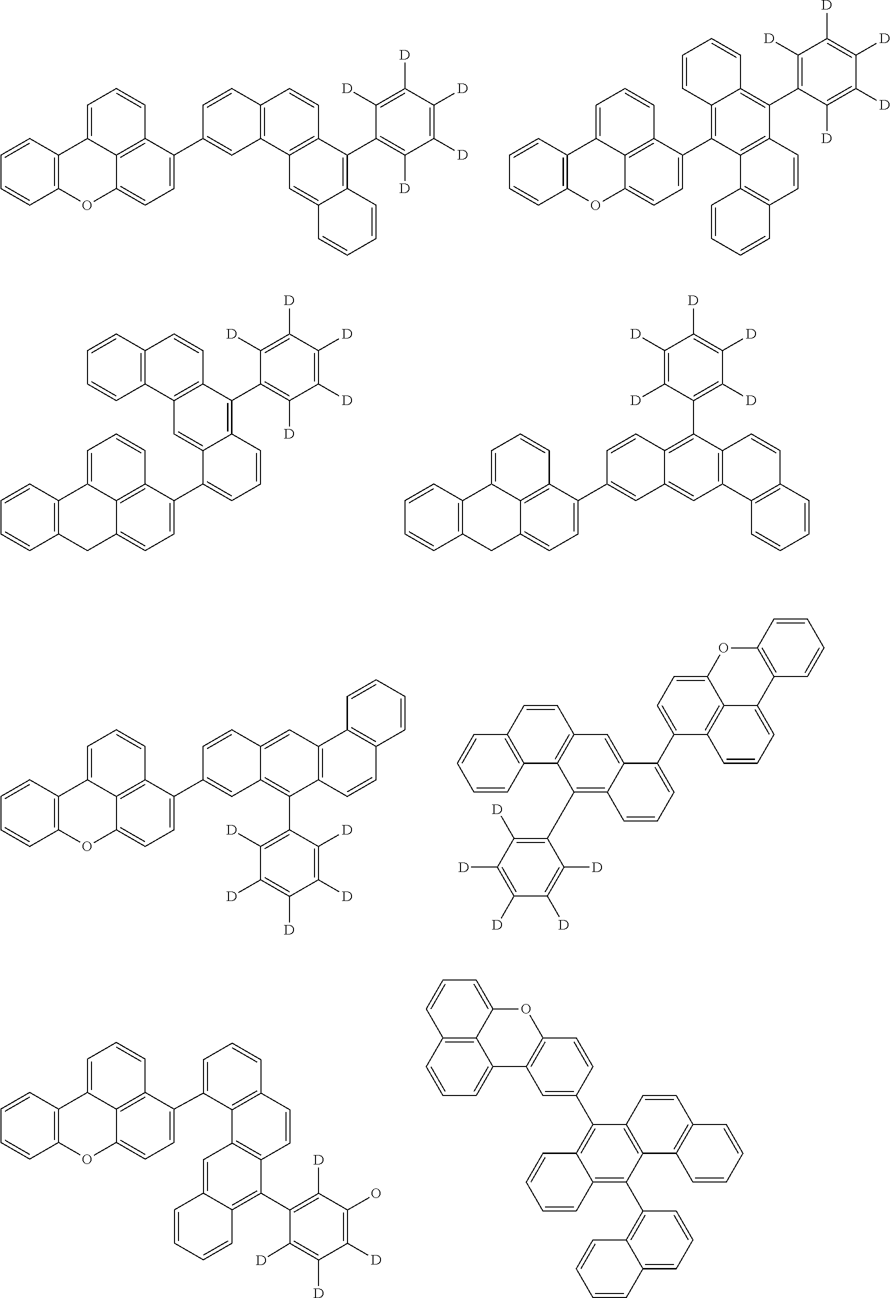

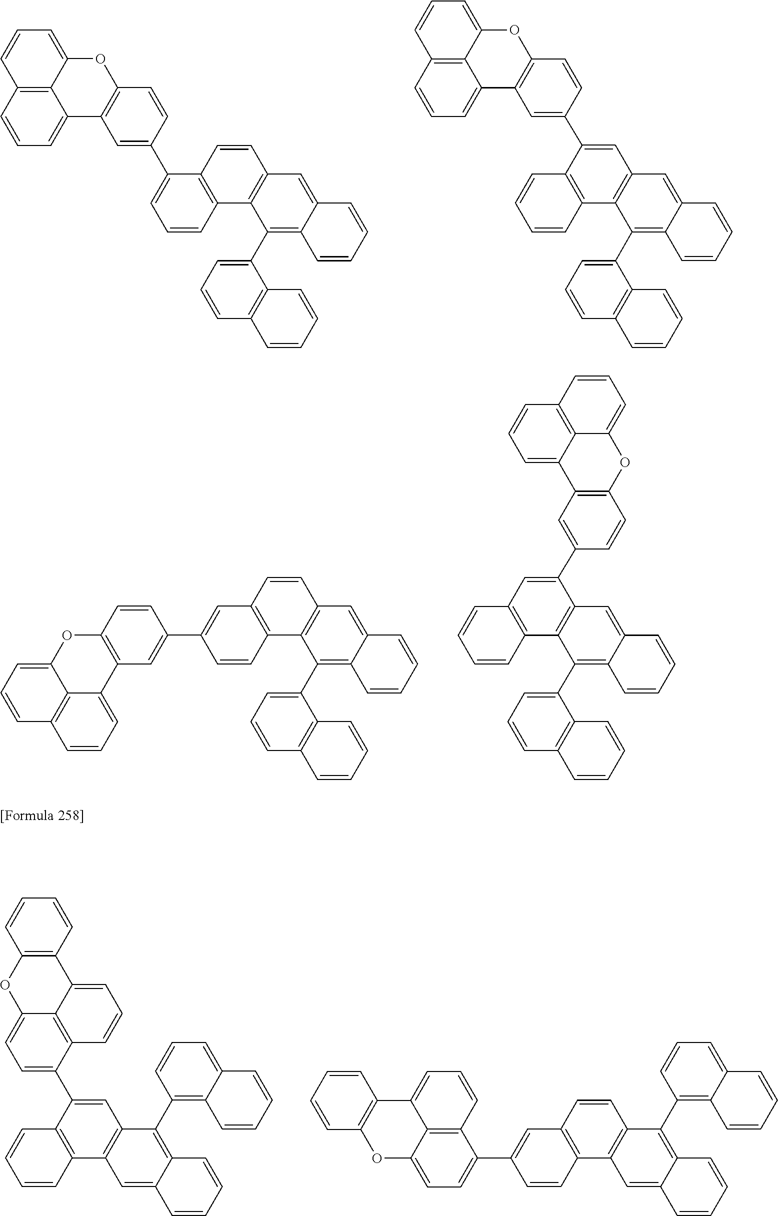

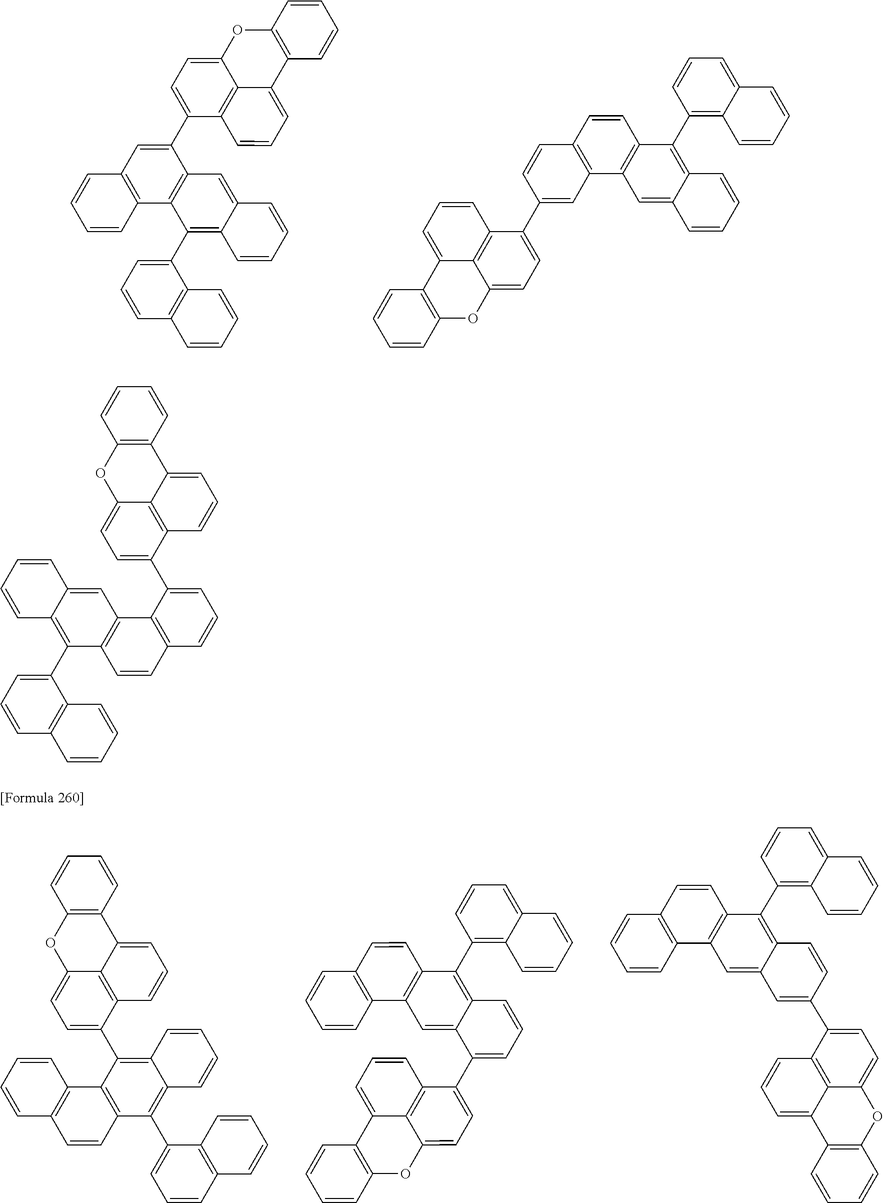

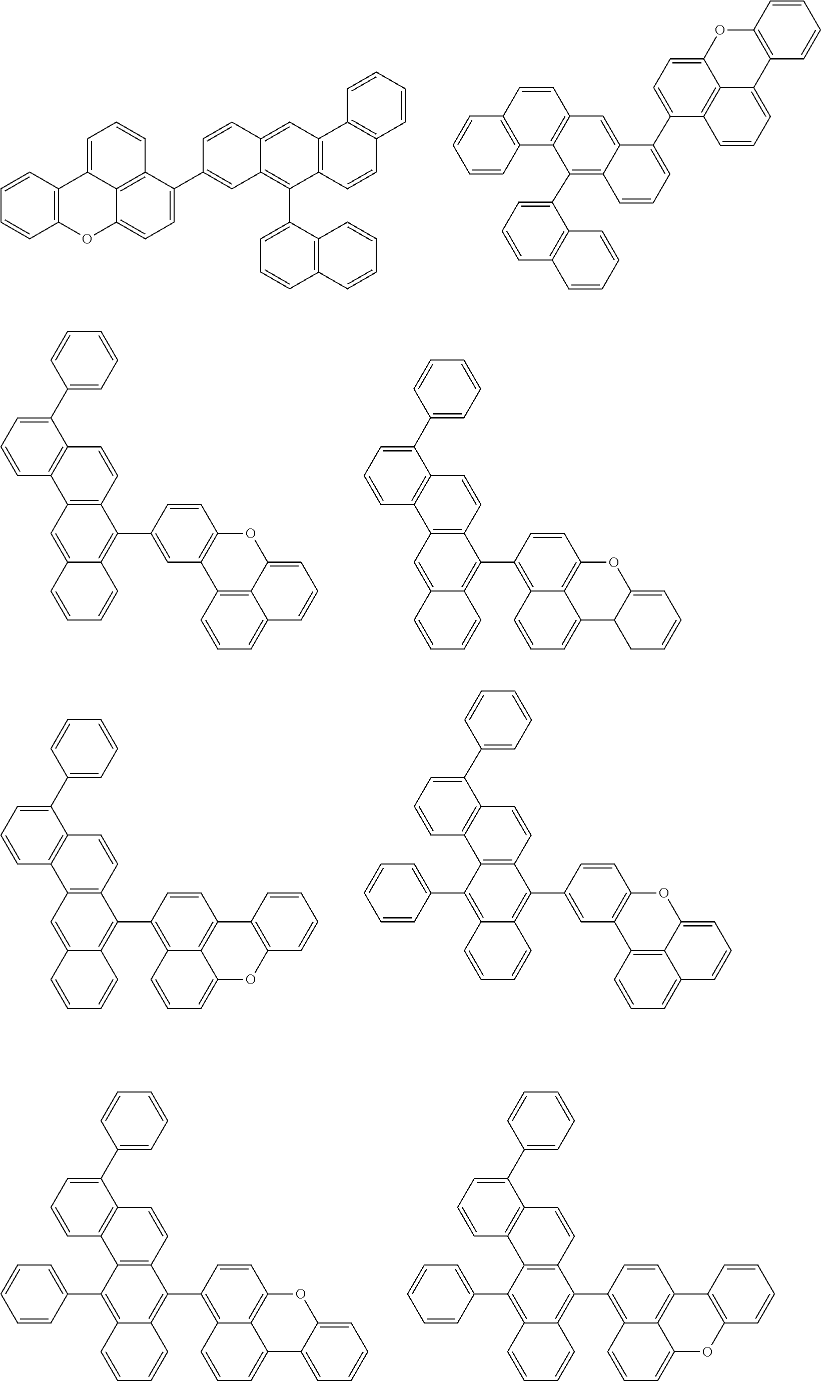

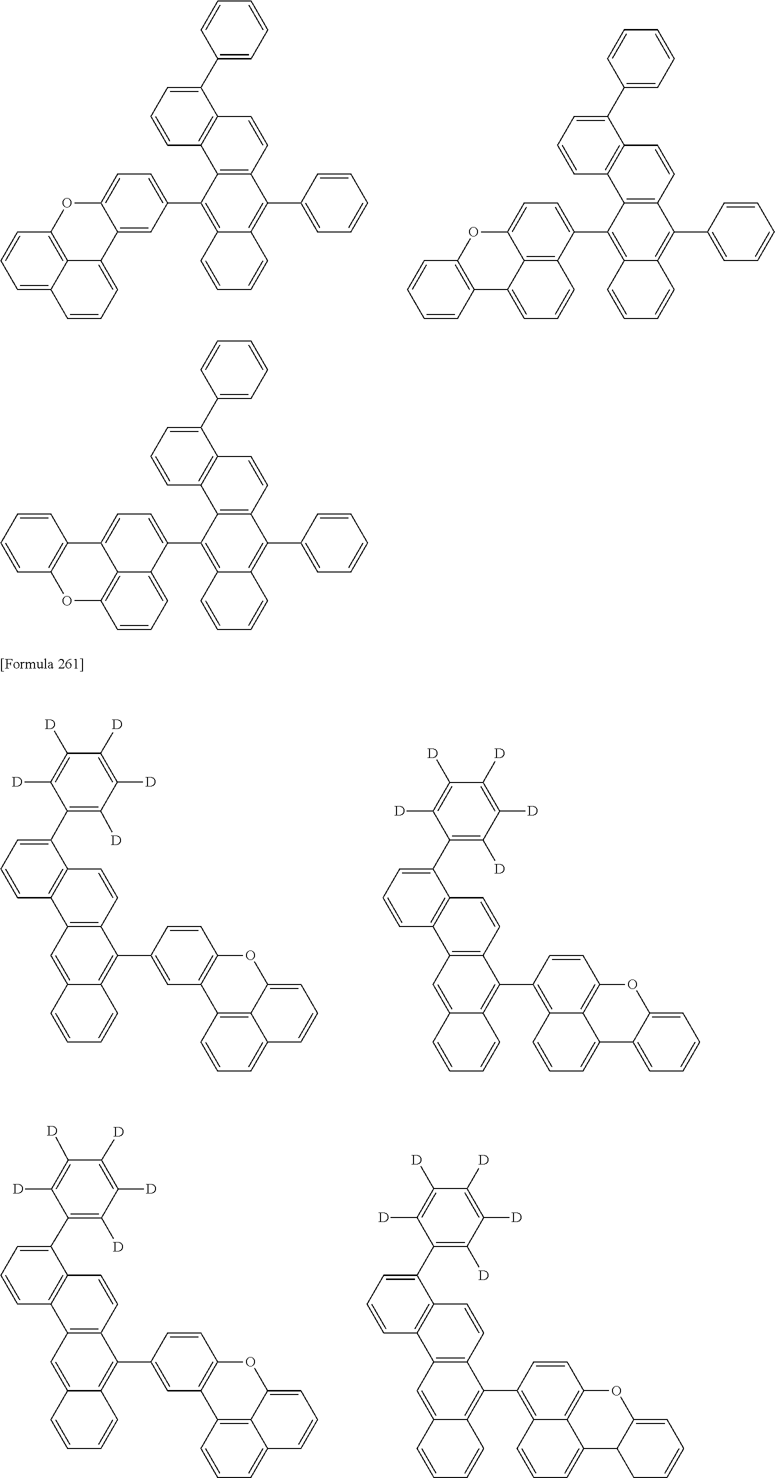

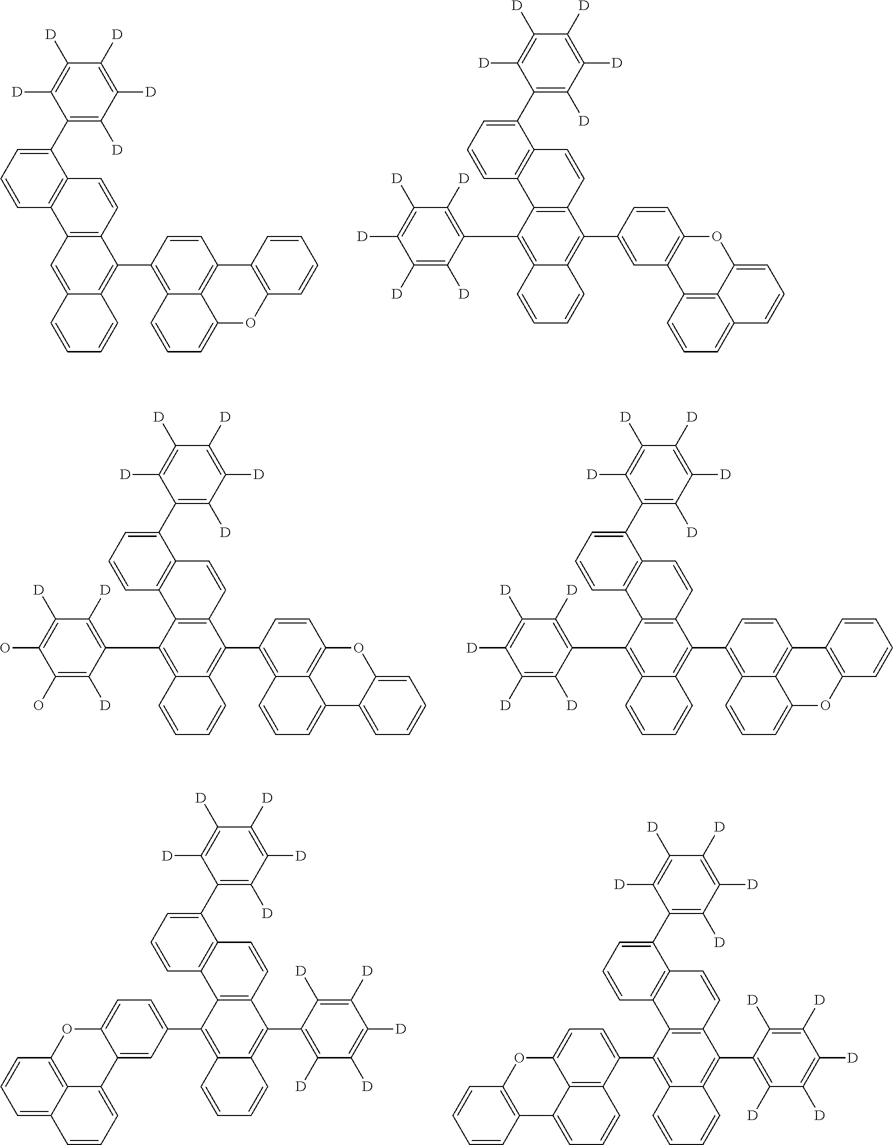

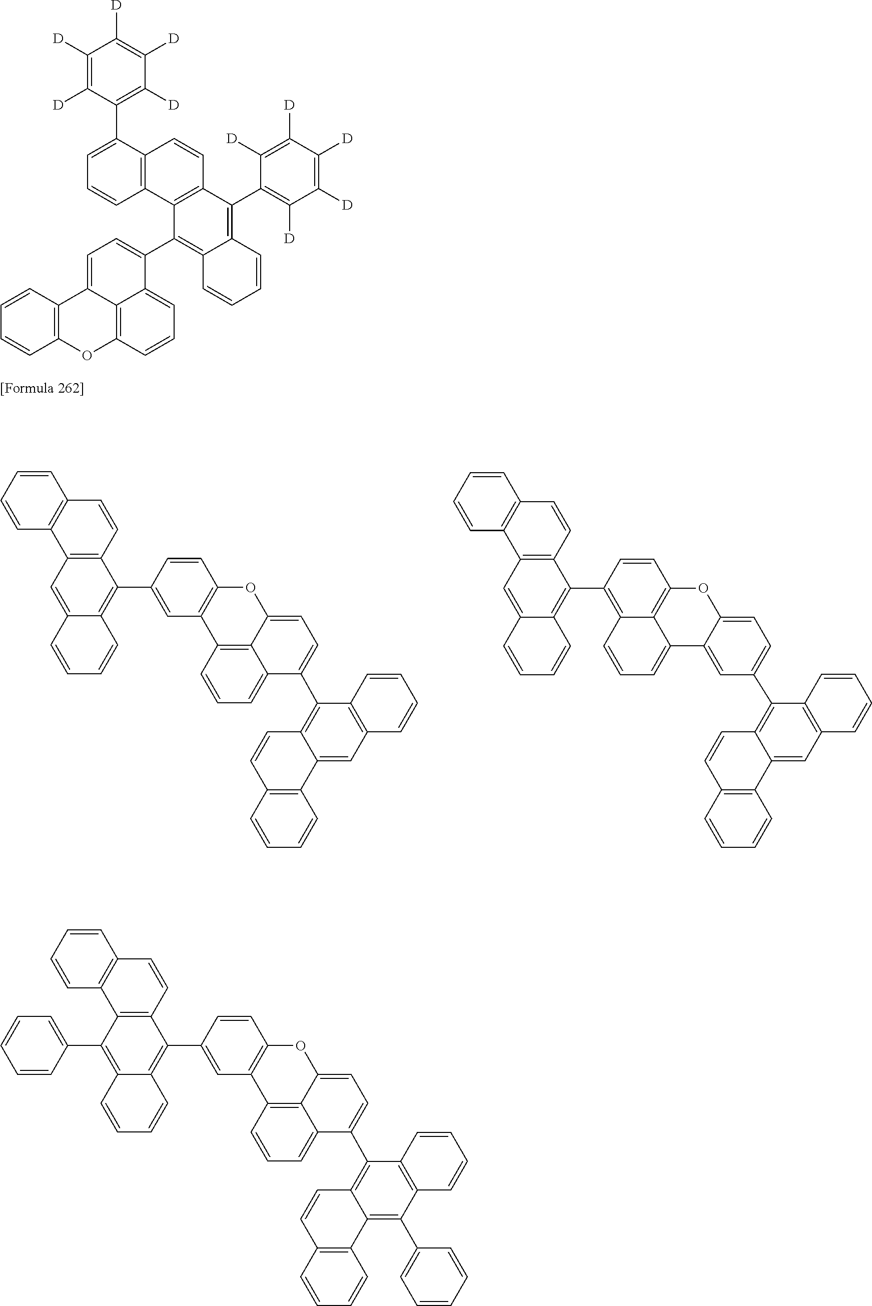 [SMILES: [2H]c1c([2H])c([2H])c(-c2cccc3c2ccc2c(-c4c([2H])c([2H])c([2H])c([2H])c4[2H])c4ccccc4c(-c4ccc5c6c(cccc46)Oc4ccccc4-5)c23)c([2H])c1[2H] ; c1ccc2c(-c3ccc4c(c3)-c3cccc5c(-c6c7ccccc7cc7c6ccc6ccccc67)ccc(c35)O4)c3ccc4ccccc4c3cc2c1 ; c1ccc2c(-c3ccc4c(c3)-c3cccc5c(-c6c7ccccc7cc7c6ccc6ccccc67)ccc(c35)O4)c3ccc4ccccc4c3cc2c1 ; c1ccc(-c2c3ccccc3c(-c3ccc4c(c3)-c3cccc5c(-c6c7ccccc7c(-c7ccccc7)c7c6ccc6ccccc67)ccc(c35)O4)c3ccc4ccccc4c23)cc1]

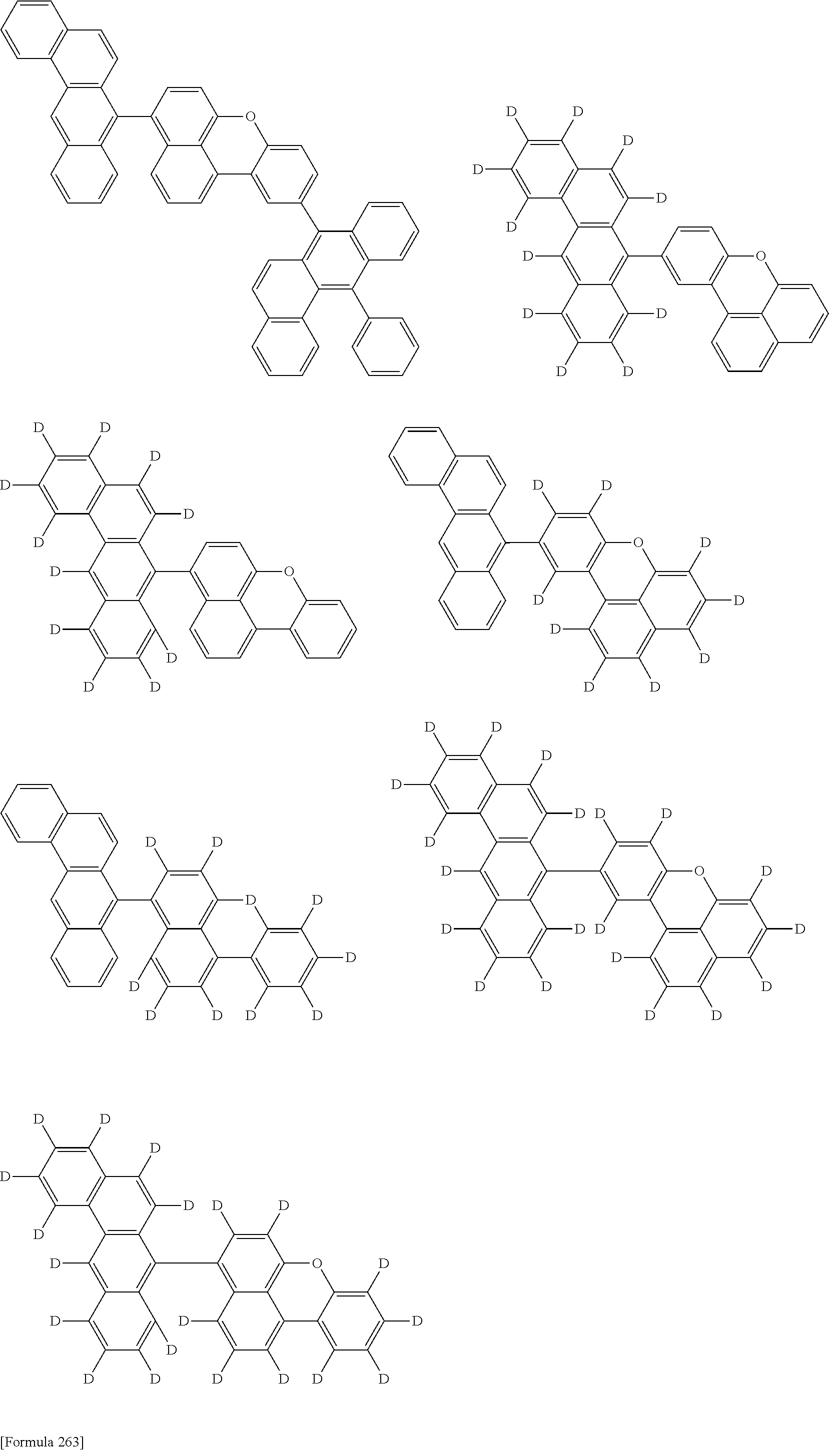

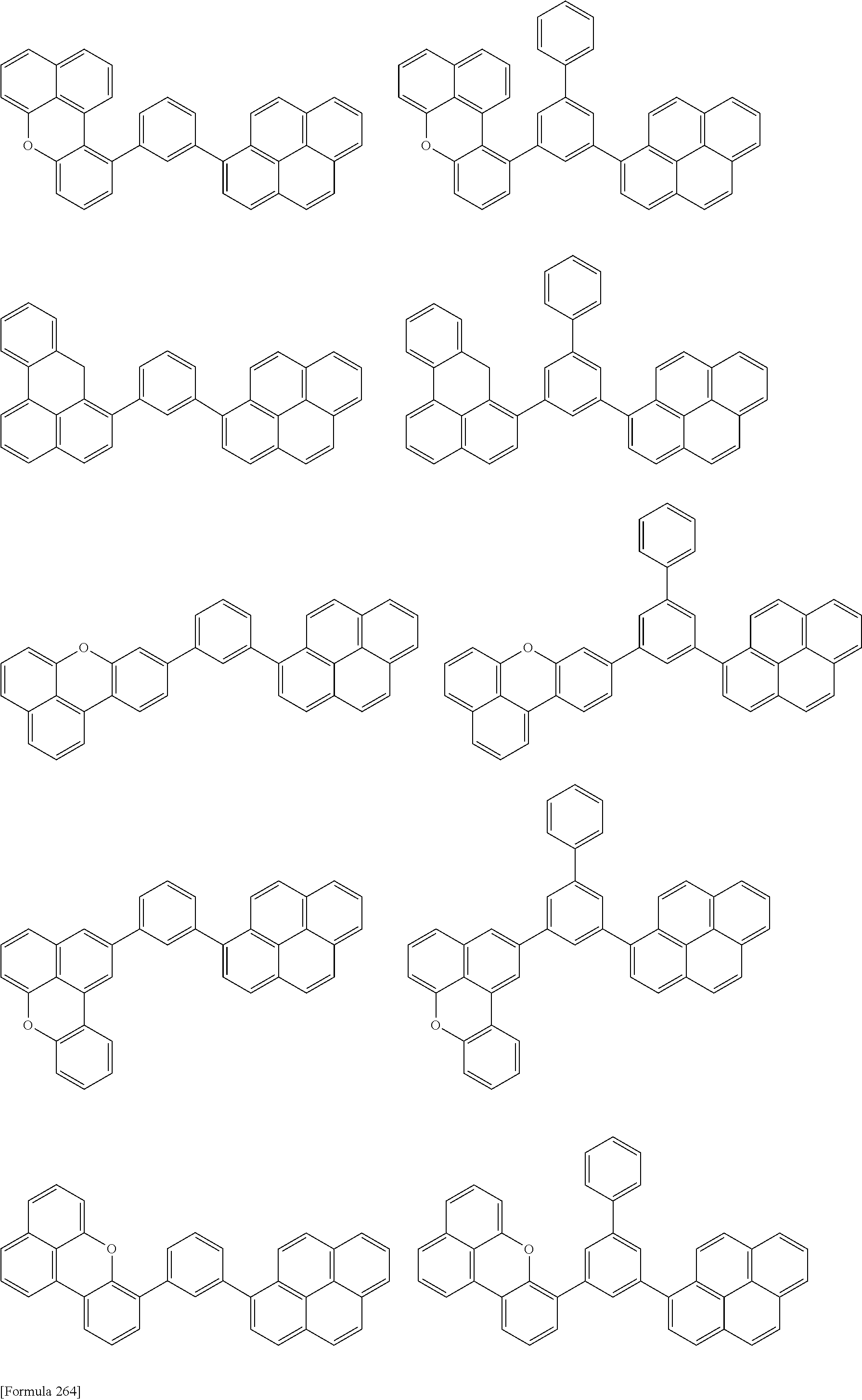

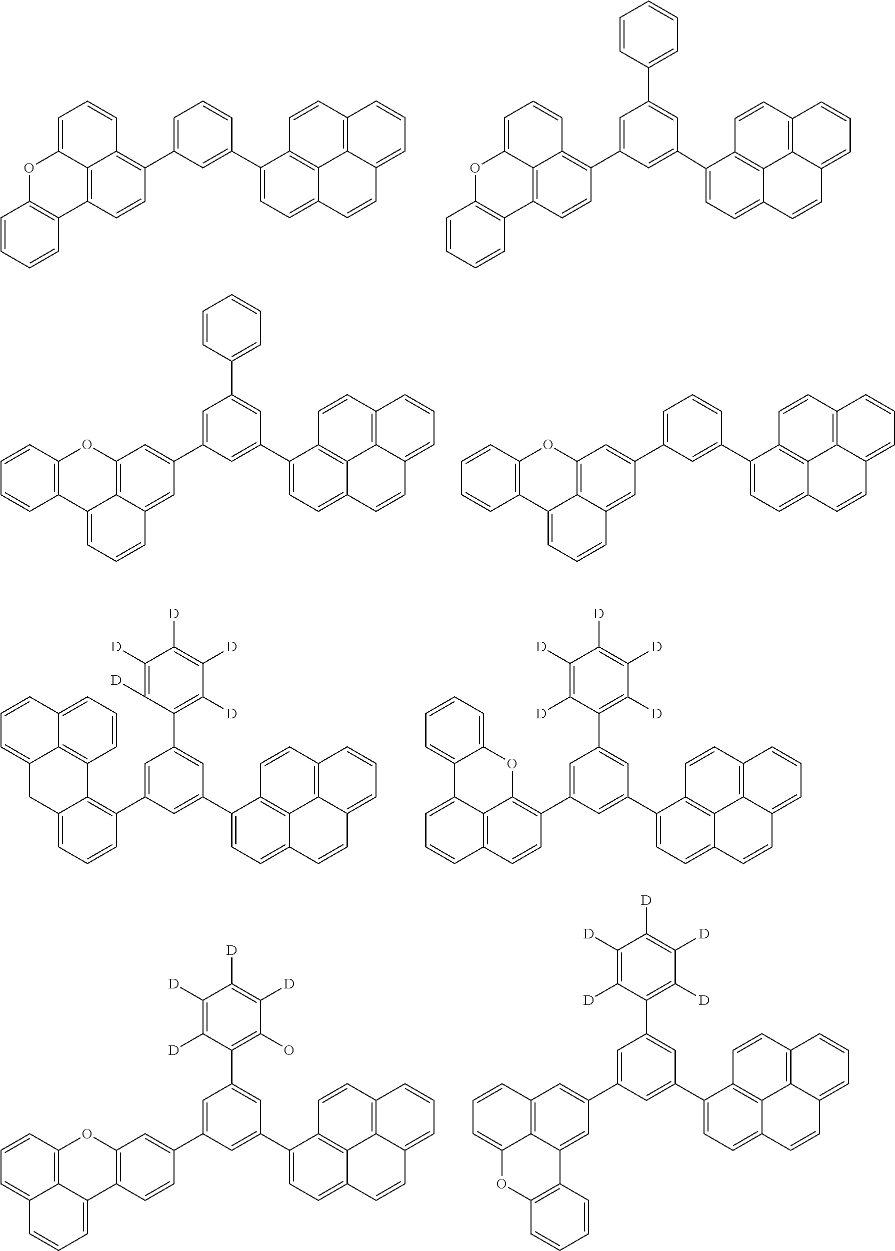

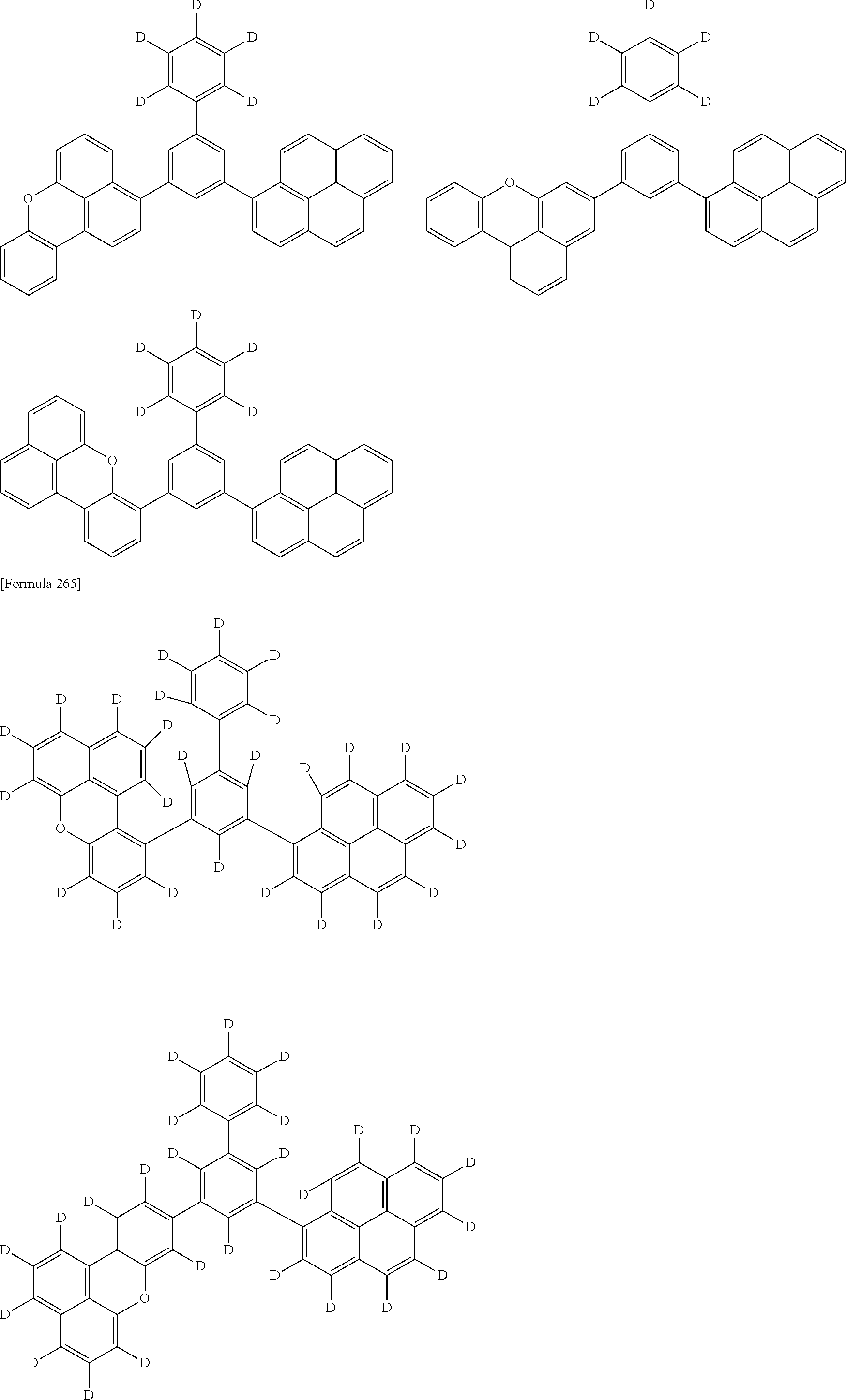

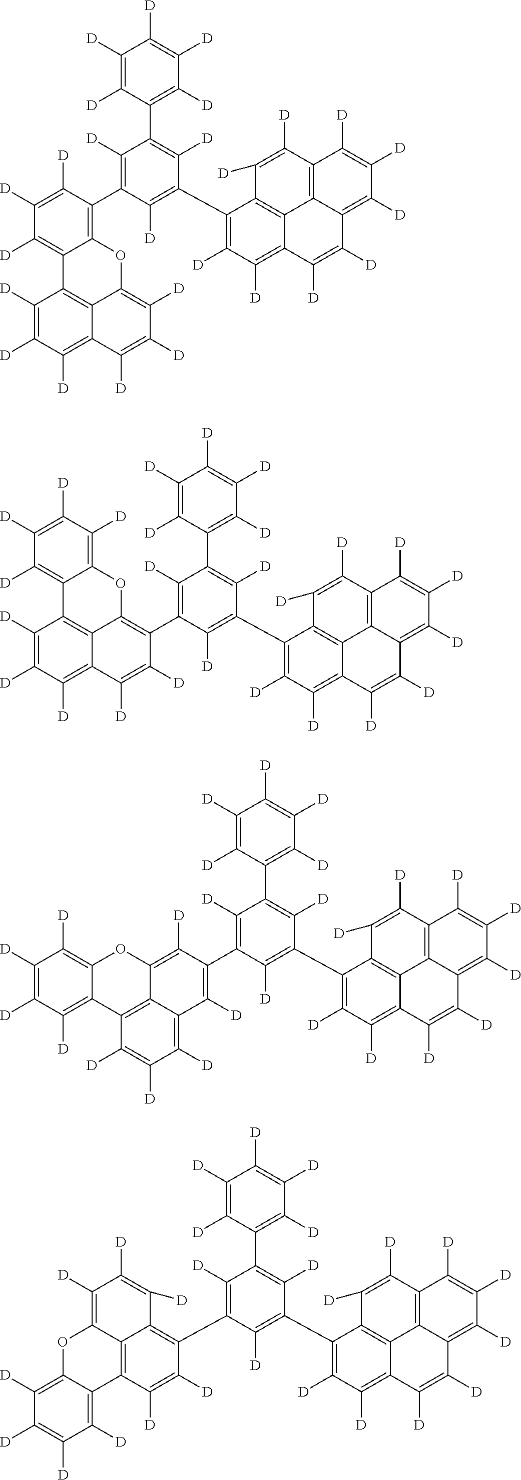

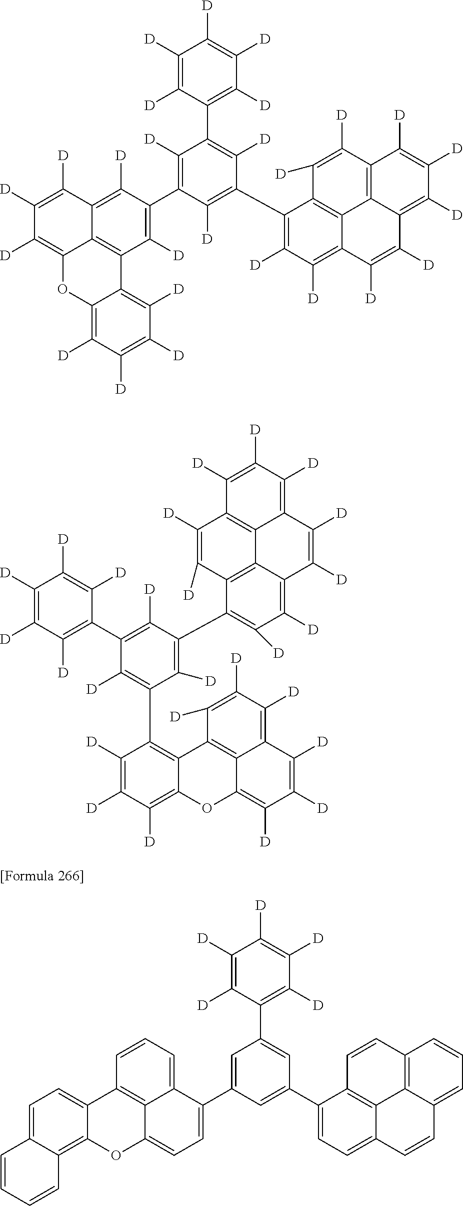

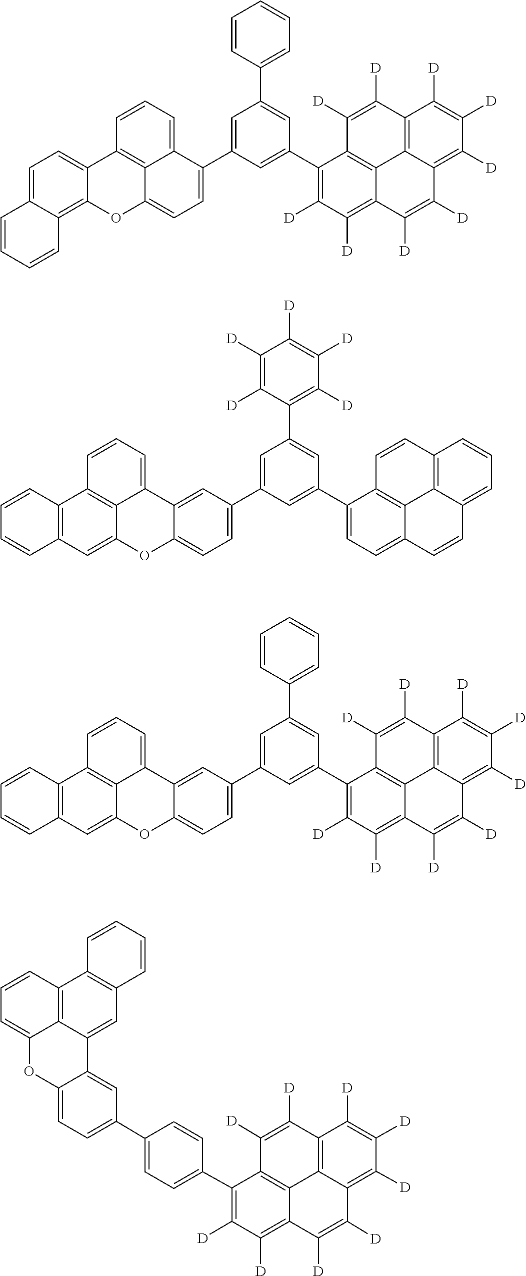

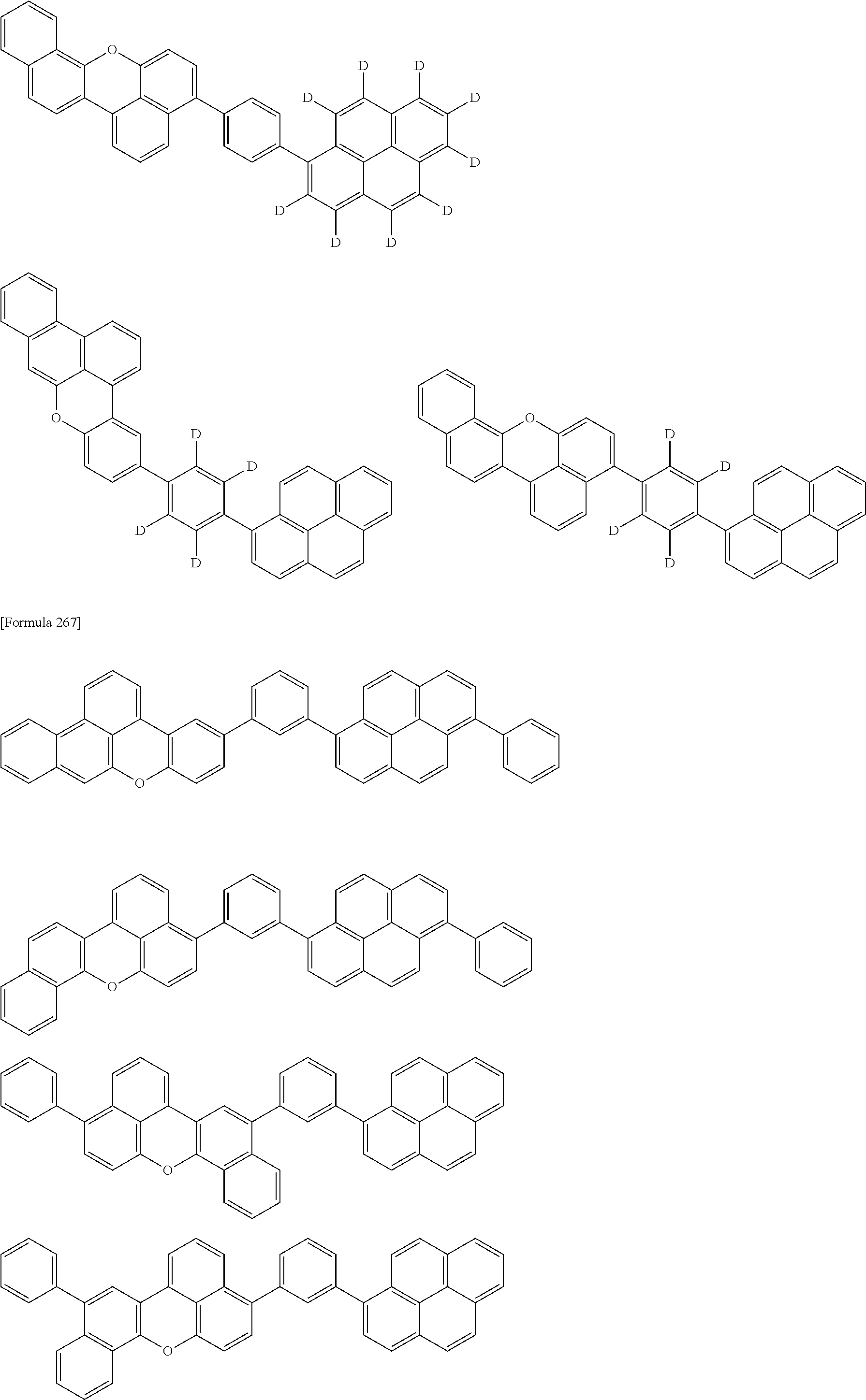

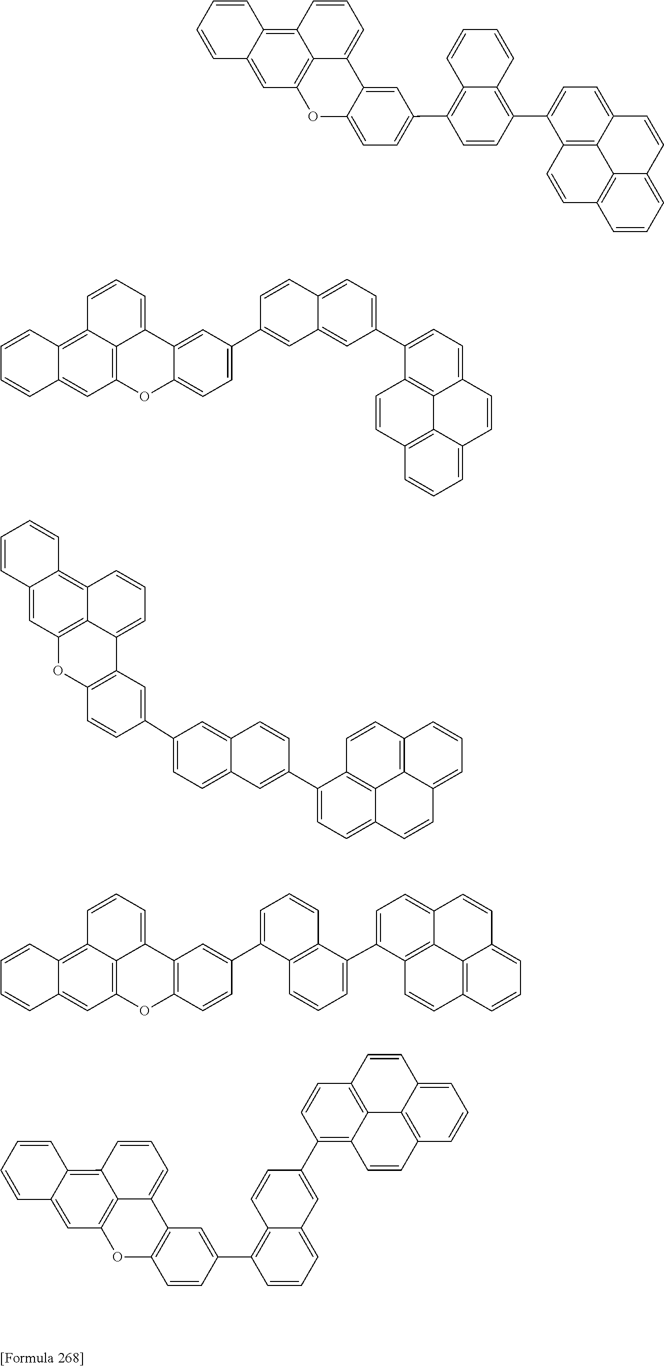 [SMILES: c1ccc2c(c1)cc1c3c(cccc32)-c2cc(-c3ccc(-c4ccc5ccc6cccc7ccc4c5c67)c4ccccc34)ccc2O1 ; c1ccc2c(c1)cc1c3c(cccc32)-c2cc(-c3ccc4ccc(-c5ccc6ccc7cccc8ccc5c6c78)cc4c3)ccc2O1 ; c1ccc2c(c1)cc1c3c(cccc32)-c2cc(-c3ccc4cc(-c5ccc6ccc7cccc8ccc5c6c78)ccc4c3)ccc2O1 ; c1ccc2c(c1)cc1c3c(cccc32)-c2cc(-c3cccc4c(-c5ccc6ccc7cccc8ccc5c6c78)cccc34)ccc2O1 ; c1cc(-c2ccc3c(c2)-c2cccc4c2c(cc2ccccc24)O3)c2ccc(-c3ccc4ccc5cccc6ccc3c4c56)cc2c1]

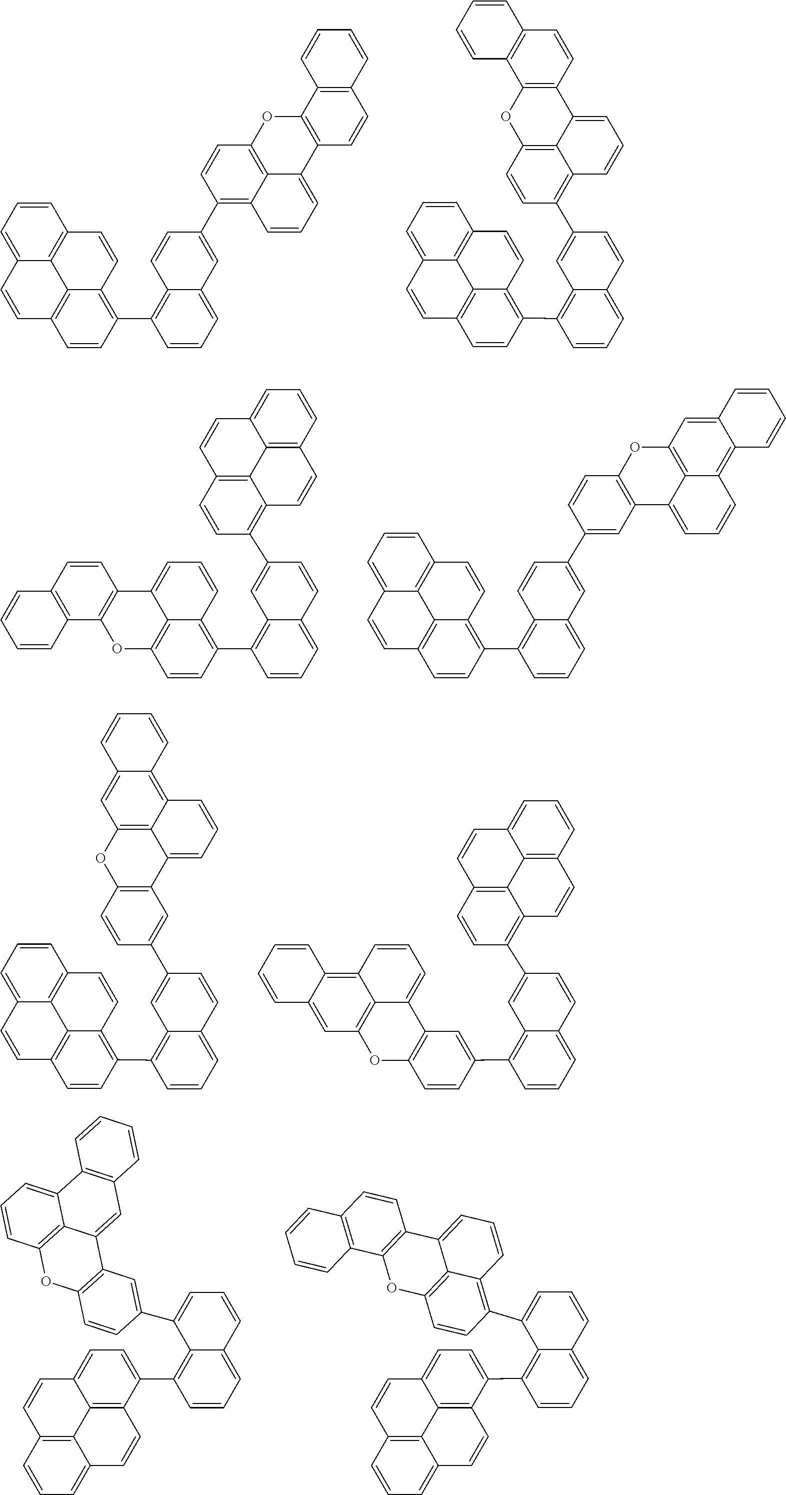

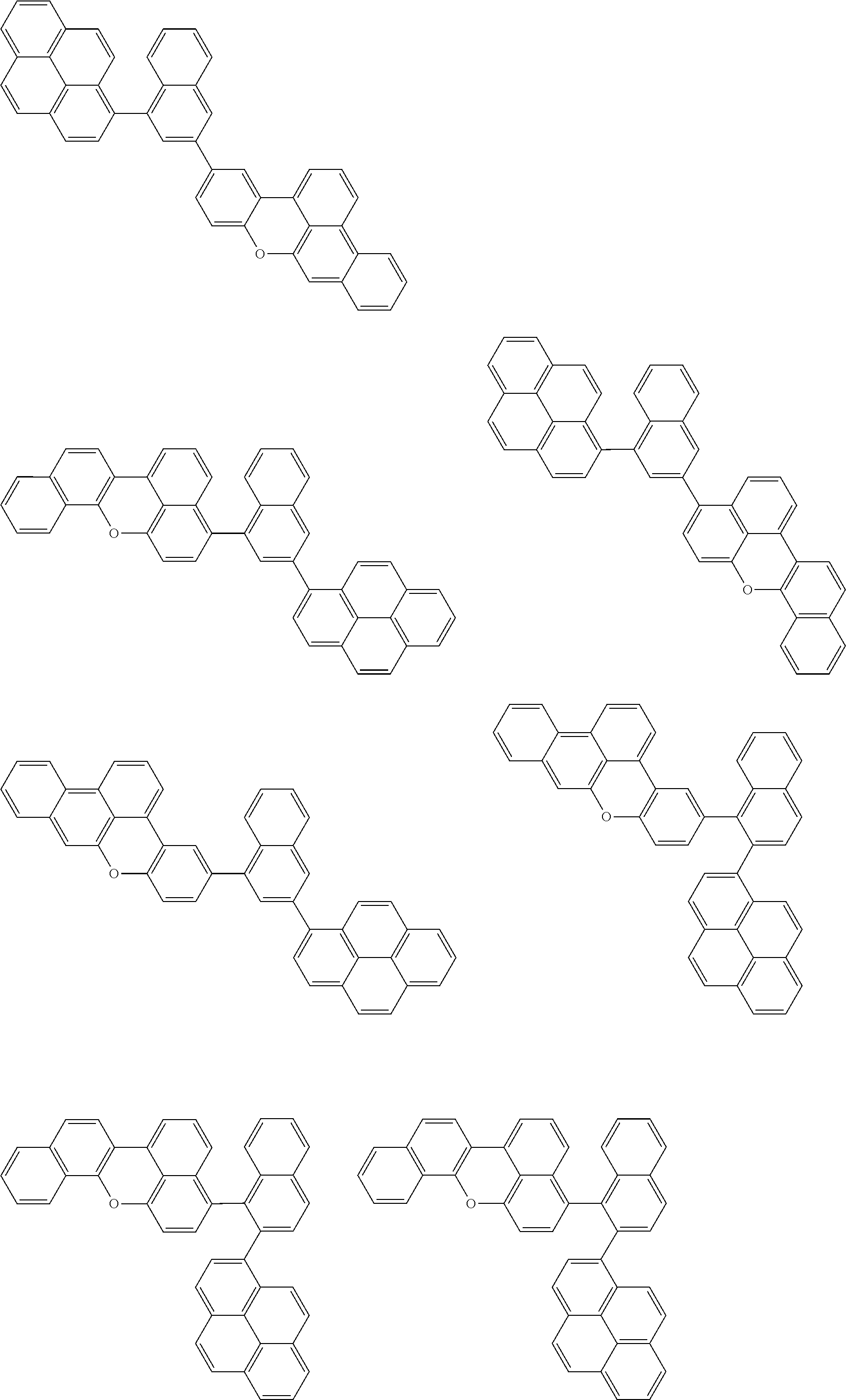

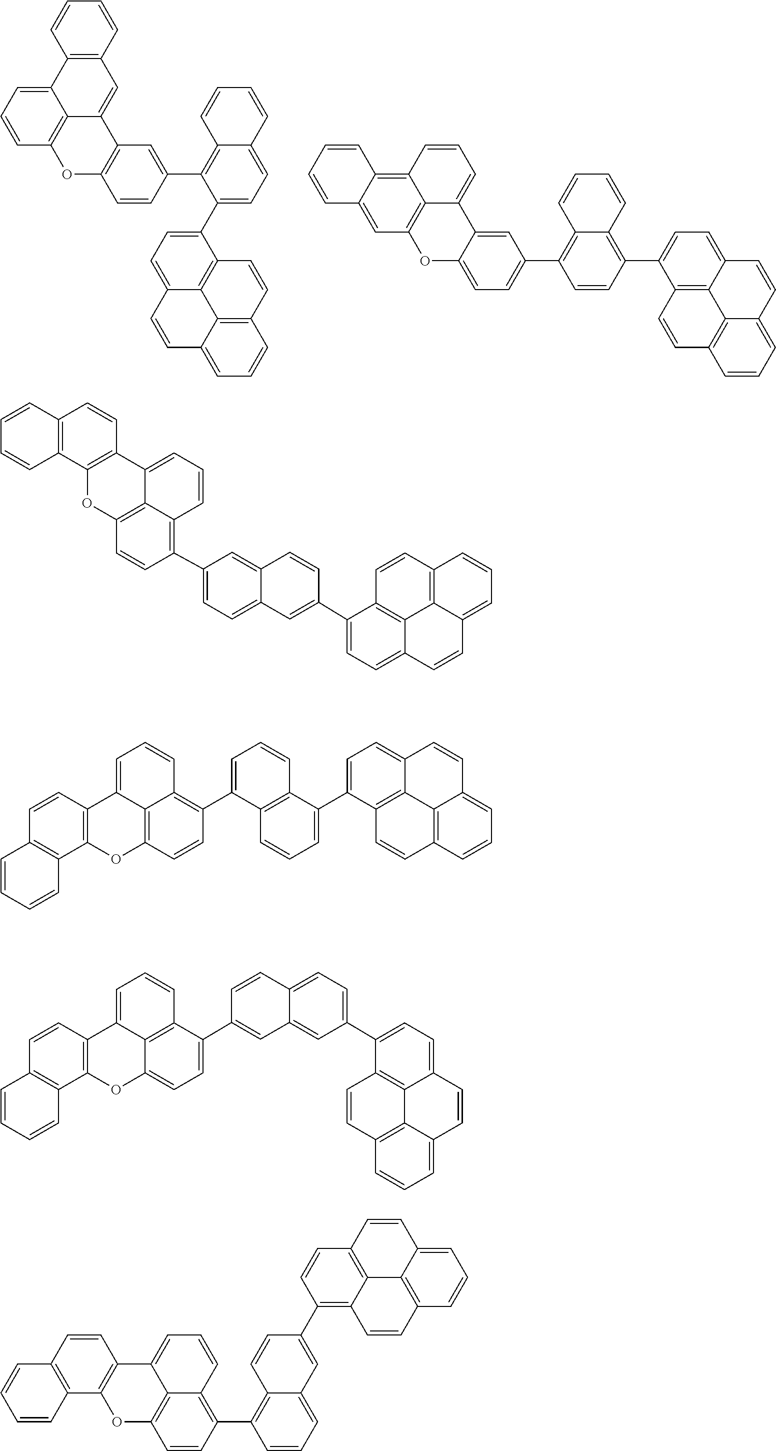

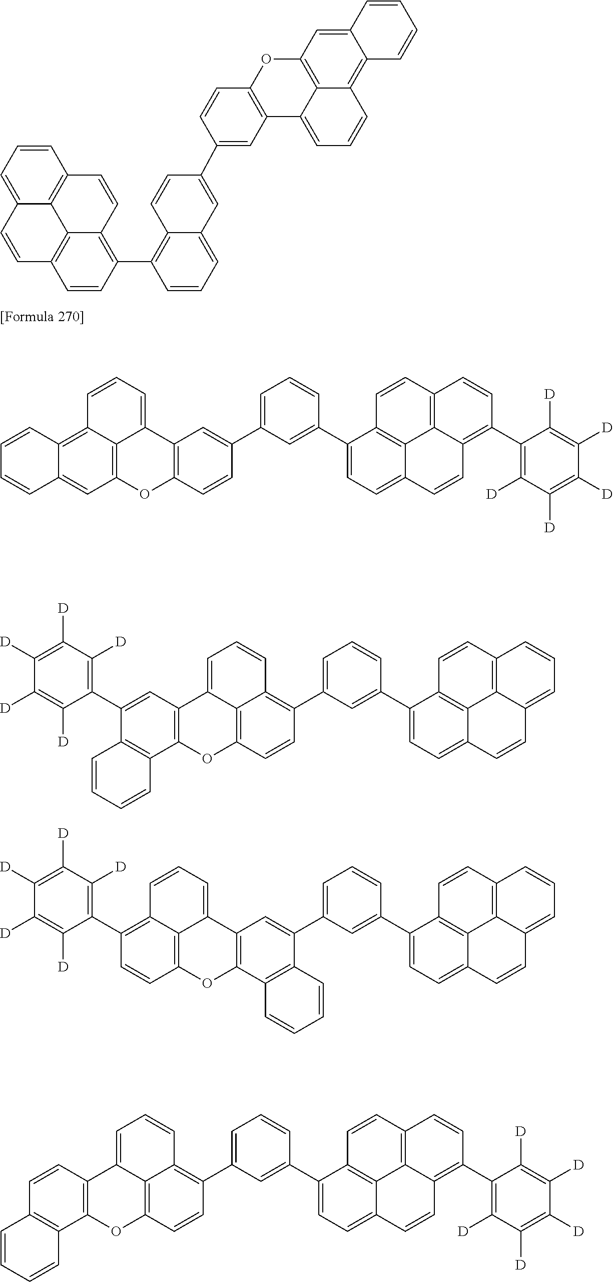

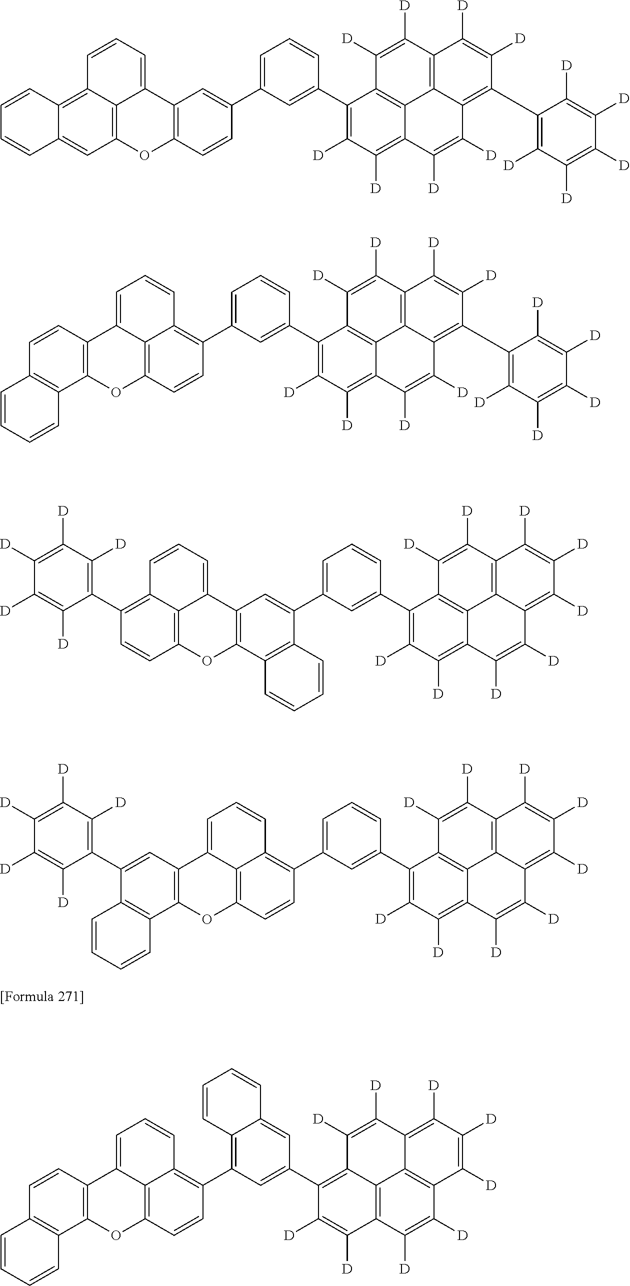

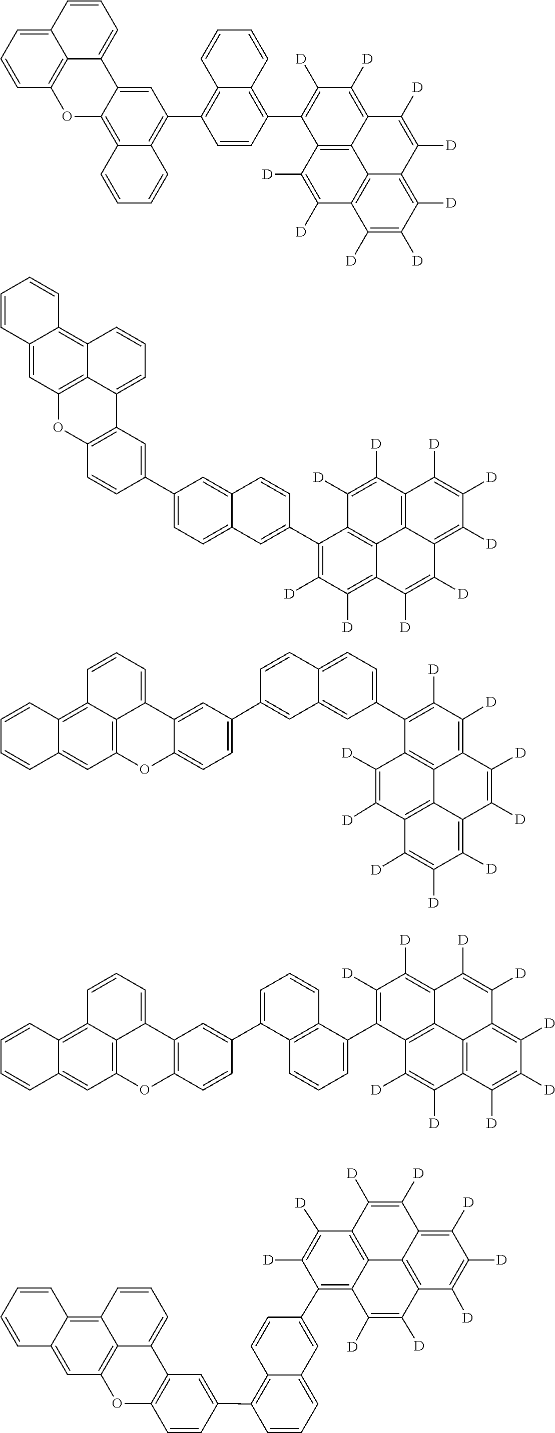

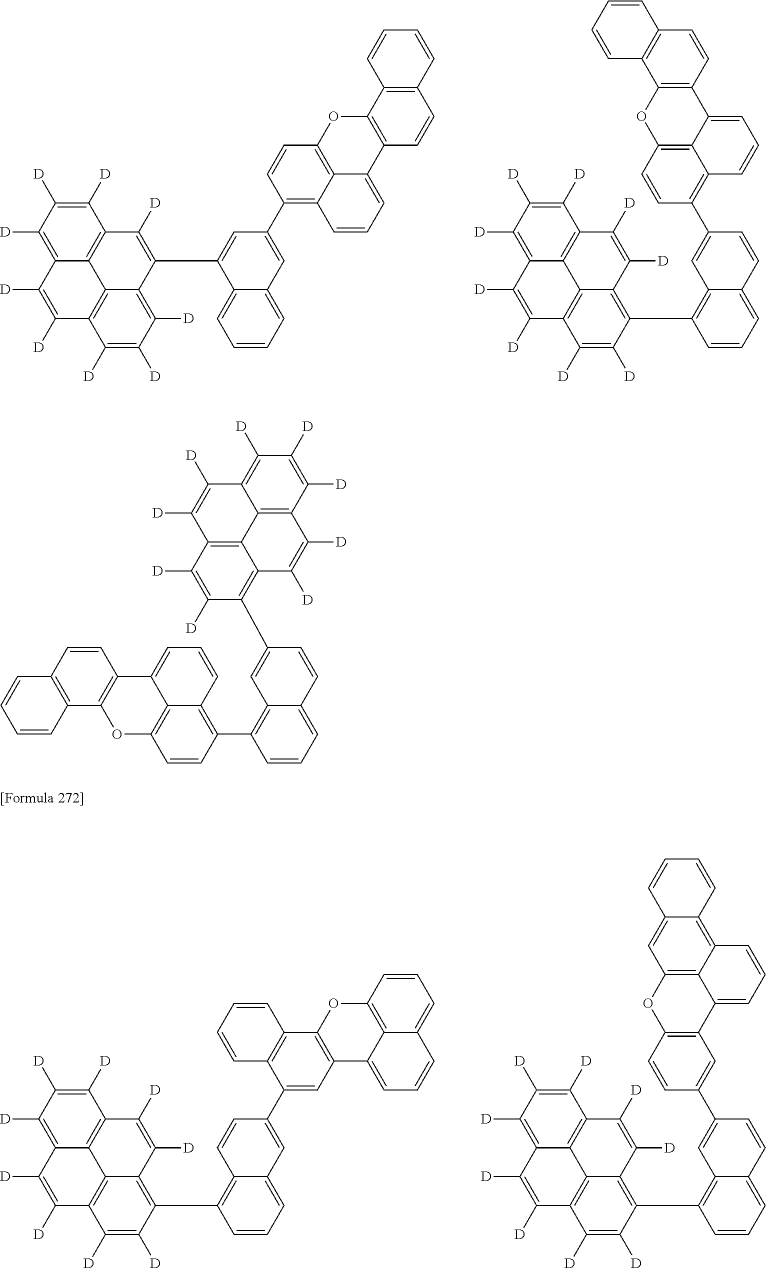

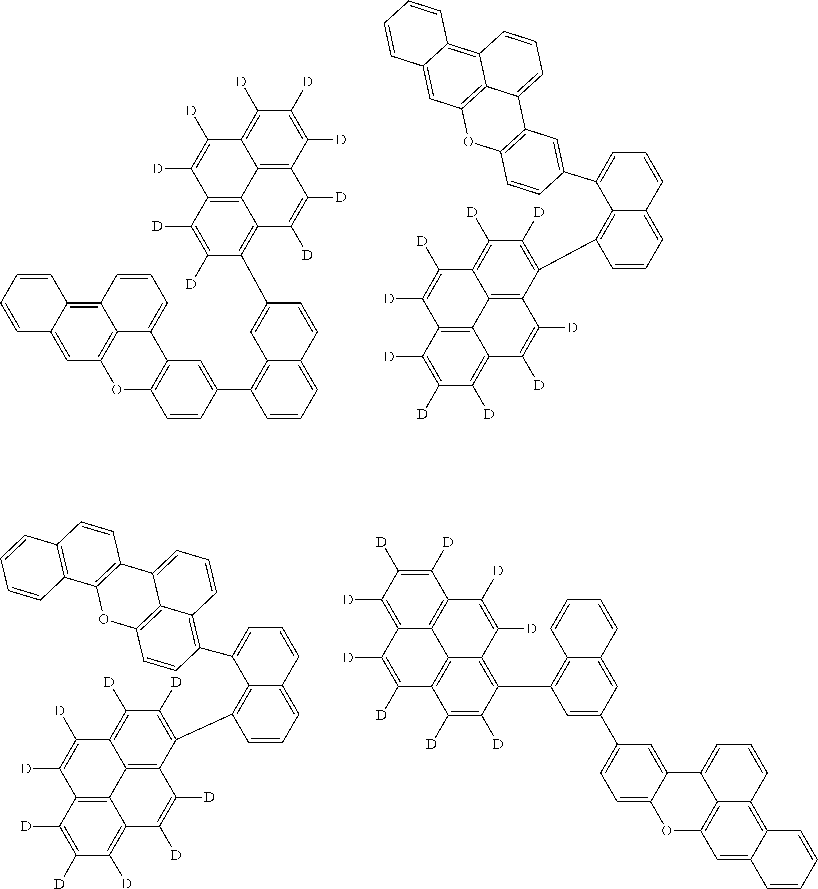

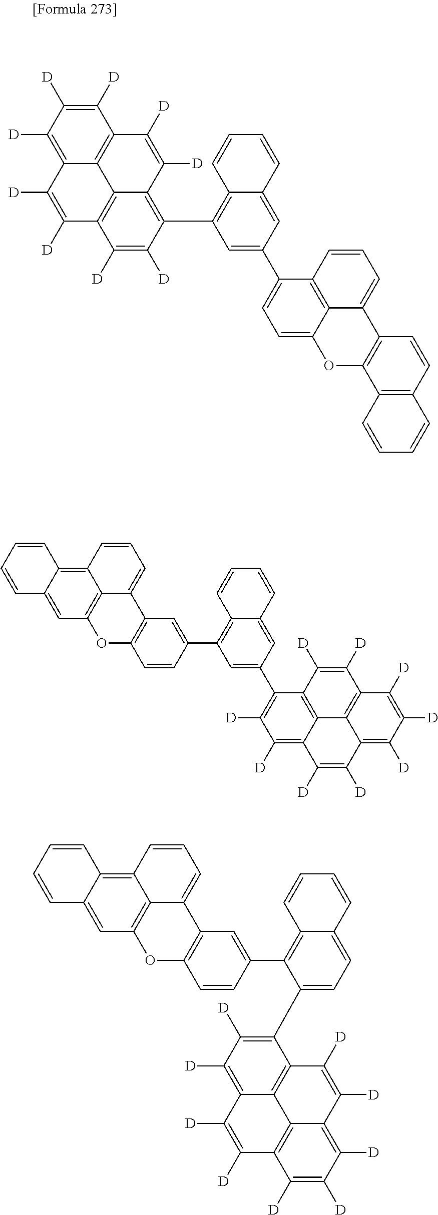 [SMILES: [2H]c1c([2H])c2c([2H])c([2H])c3c([2H])c([2H])c(-c4cc(-c5ccc6c7c(cccc57)-c5ccc7ccccc7c5O6)cc5ccccc45)c4c([2H])c([2H])c(c1[2H])c2c34 ; [2H]c1c([2H])c2c([2H])c([2H])c3c([2H])c([2H])c(-c4cc(-c5ccc6c(c5)-c5cccc7c5c(cc5ccccc57)O6)c5ccccc5c4)c4c([2H])c([2H])c(c1[2H])c2c34 ; [2H]c1c([2H])c2c([2H])c([2H])c3c([2H])c([2H])c(-c4ccc5ccccc5c4-c4ccc5c(c4)-c4cccc6c4c(cc4ccccc46)O5)c4c([2H])c([2H])c(c1[2H])c2c34]

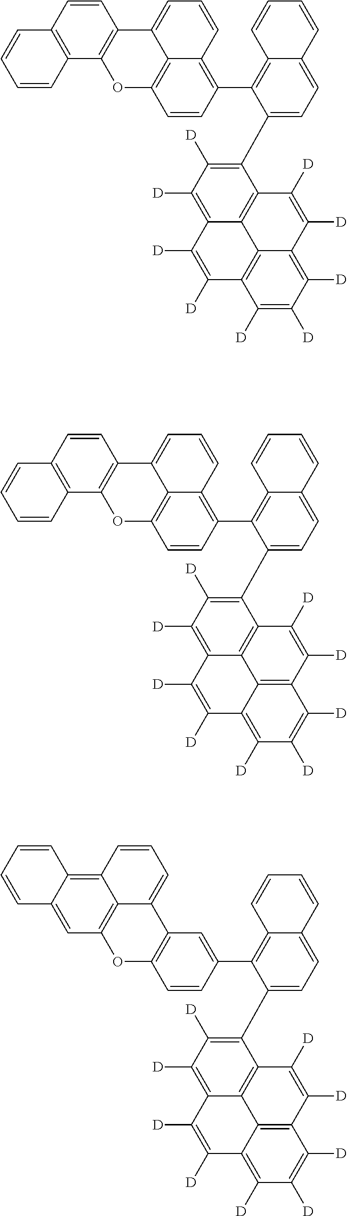 [SMILES: [2H]c1c([2H])c2c([2H])c([2H])c3c([2H])c([2H])c(-c4ccc5ccccc5c4-c4ccc5c6c(cccc46)-c4ccc6ccccc6c4O5)c4c([2H])c([2H])c(c1[2H])c2c34 ; [2H]c1c([2H])c2c([2H])c([2H])c3c([2H])c([2H])c(-c4ccc5ccccc5c4-c4ccc5c6c(cccc46)-c4ccc6ccccc6c4O5)c4c([2H])c([2H])c(c1[2H])c2c34 ; [2H]c1c([2H])c2c([2H])c([2H])c3c([2H])c([2H])c(-c4ccc5ccccc5c4-c4ccc5c(c4)-c4cccc6c4c(cc4ccccc46)O5)c4c([2H])c([2H])c(c1[2H])c2c34]

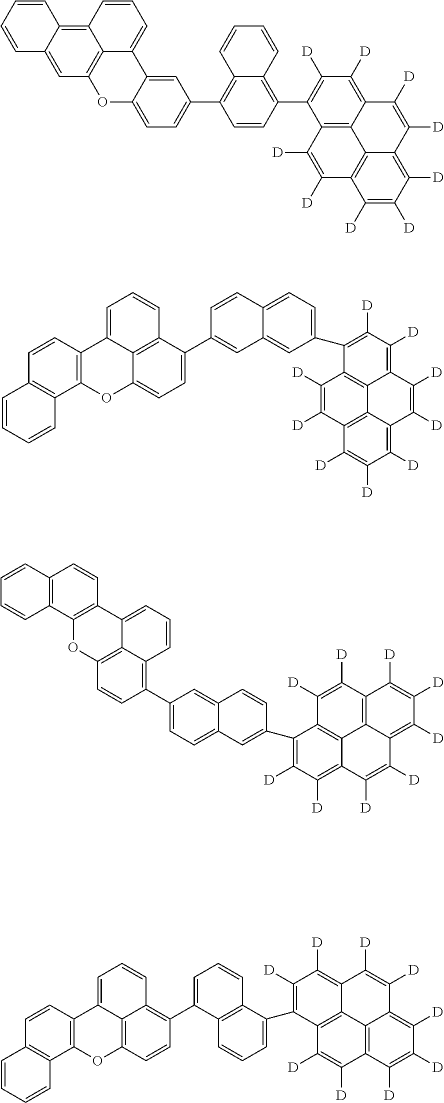

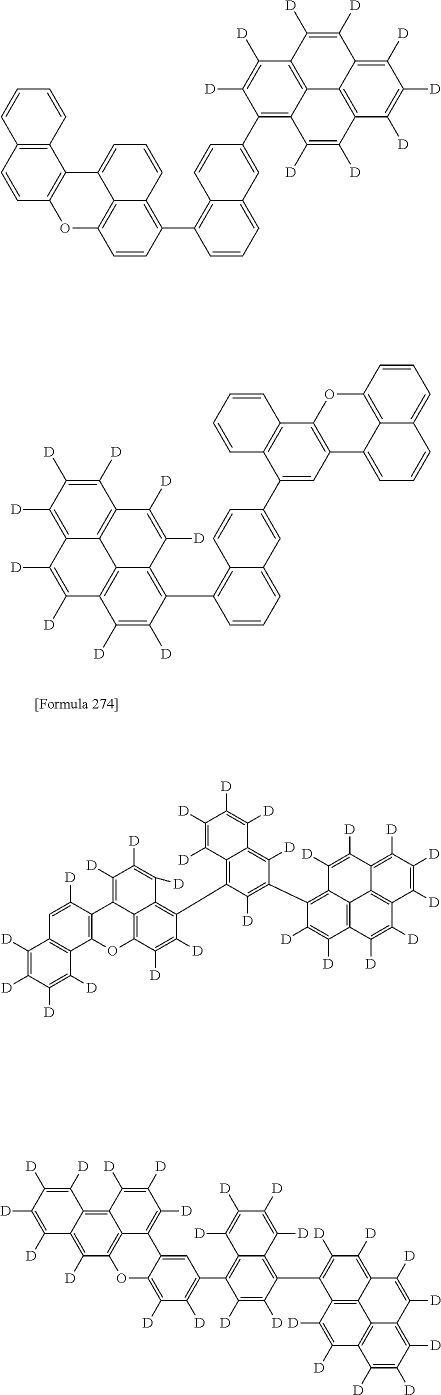

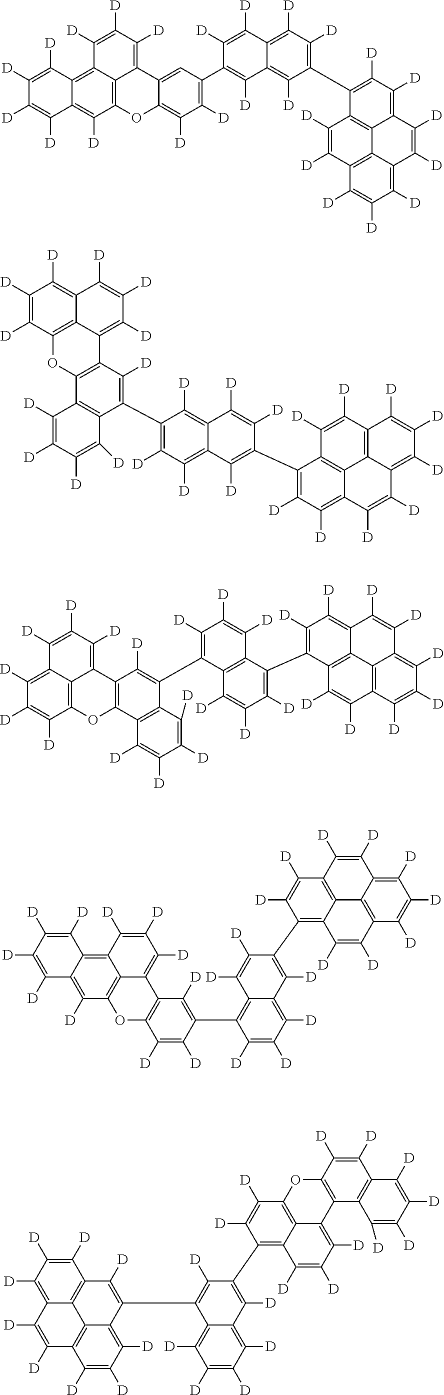

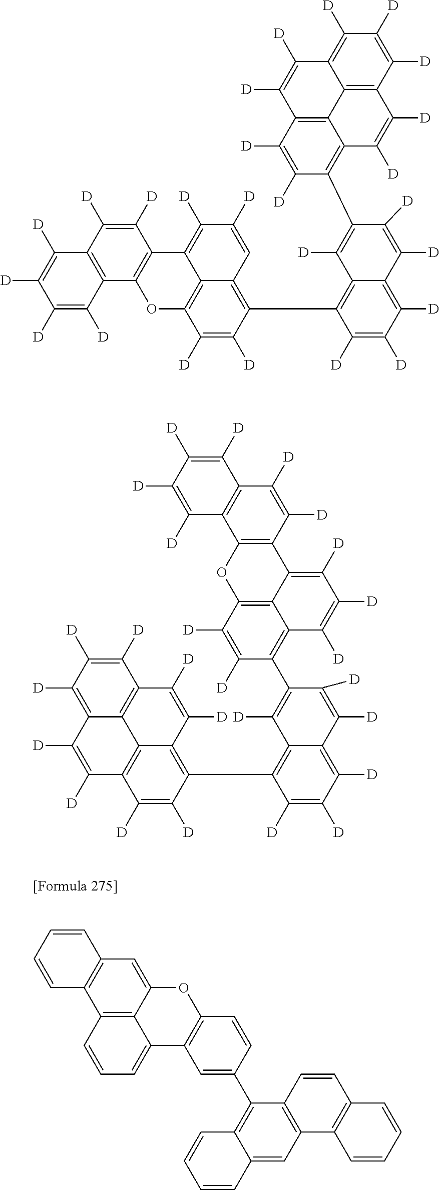

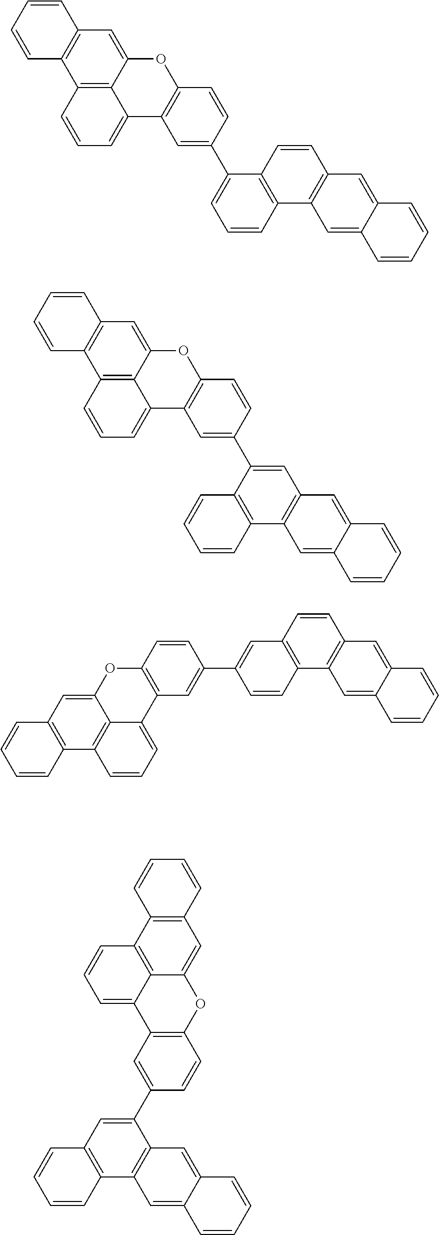

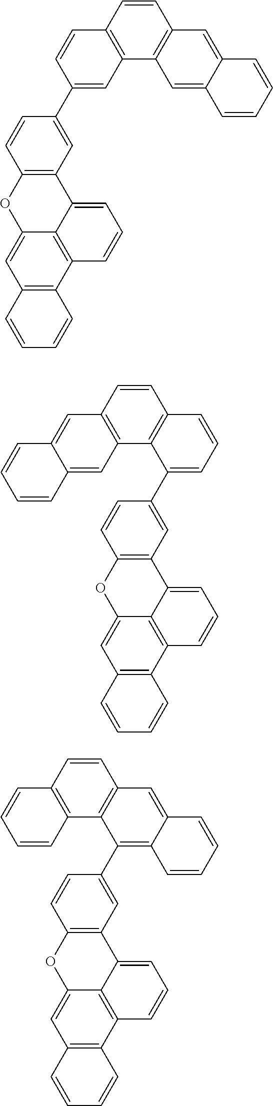

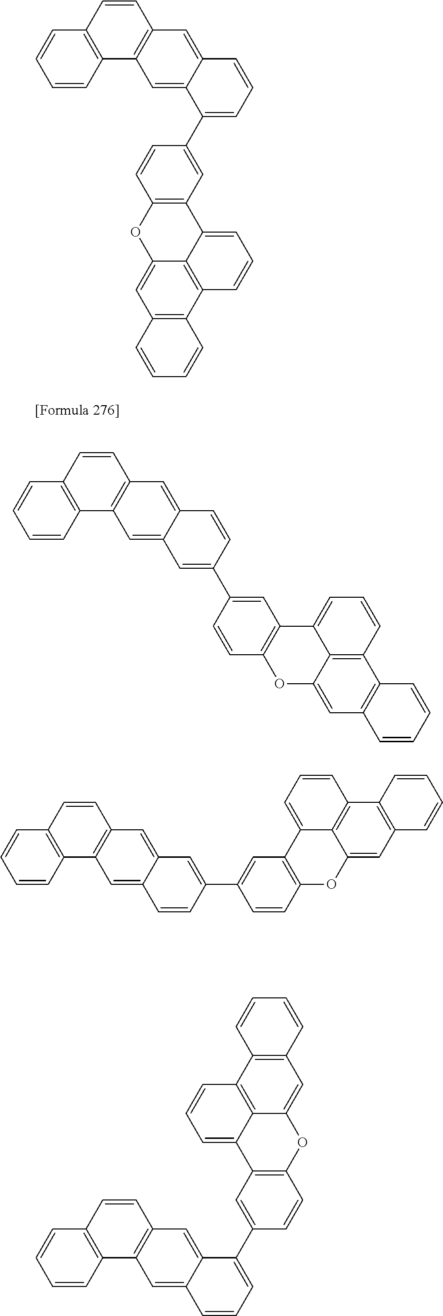

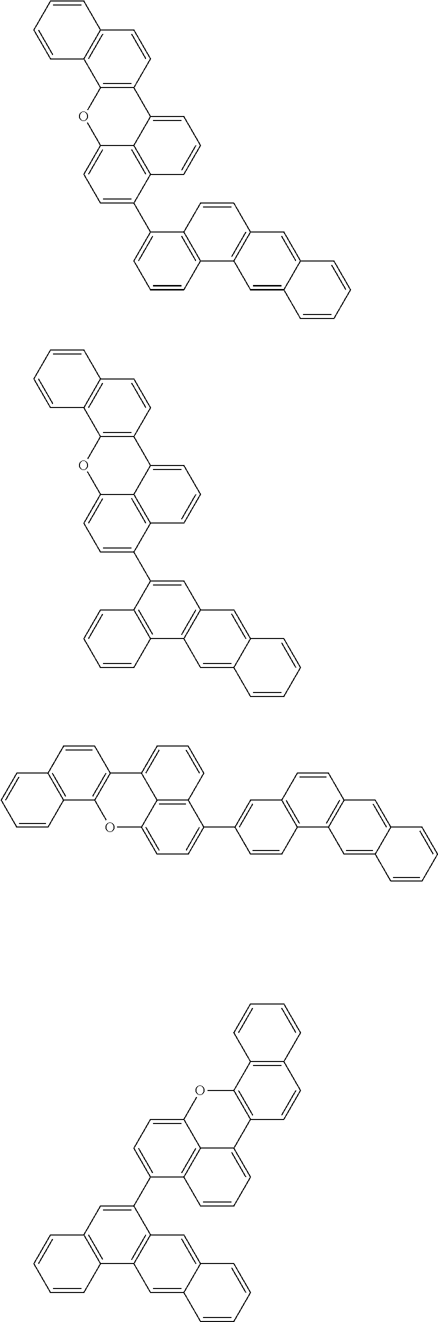 [SMILES: c1ccc2cc3c(ccc4c(-c5ccc6c7c(cccc57)-c5ccc7ccccc7c5O6)cccc43)cc2c1 ; c1ccc2cc3c(cc(-c4ccc5c6c(cccc46)-c4ccc6ccccc6c4O5)c4ccccc43)cc2c1 ; c1ccc2cc3c(ccc4cc(-c5ccc6c7c(cccc57)-c5ccc7ccccc7c5O6)ccc43)cc2c1 ; c1ccc2cc3c(cc2c1)c(-c1ccc2c4c(cccc14)-c1ccc4ccccc4c1O2)cc1ccccc13]

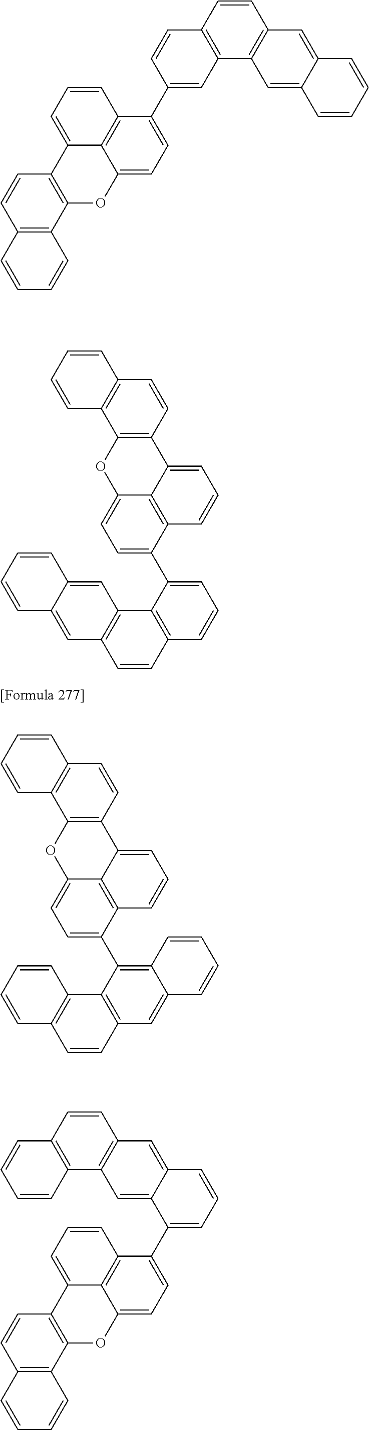 [SMILES: c1ccc2cc3c(ccc4ccc(-c5ccc6c7c(cccc57)-c5ccc7ccccc7c5O6)cc43)cc2c1 ; c1ccc2cc3c(ccc4cccc(-c5ccc6c7c(cccc57)-c5ccc7ccccc7c5O6)c43)cc2c1 ; c1ccc2c3c(ccc2c1)-c1cccc2c(-c4c5ccccc5cc5ccc6ccccc6c45)ccc(c12)O3 ; c1cc(-c2ccc3c4c(cccc24)-c2ccc4ccccc4c2O3)c2cc3c(ccc4ccccc43)cc2c1]

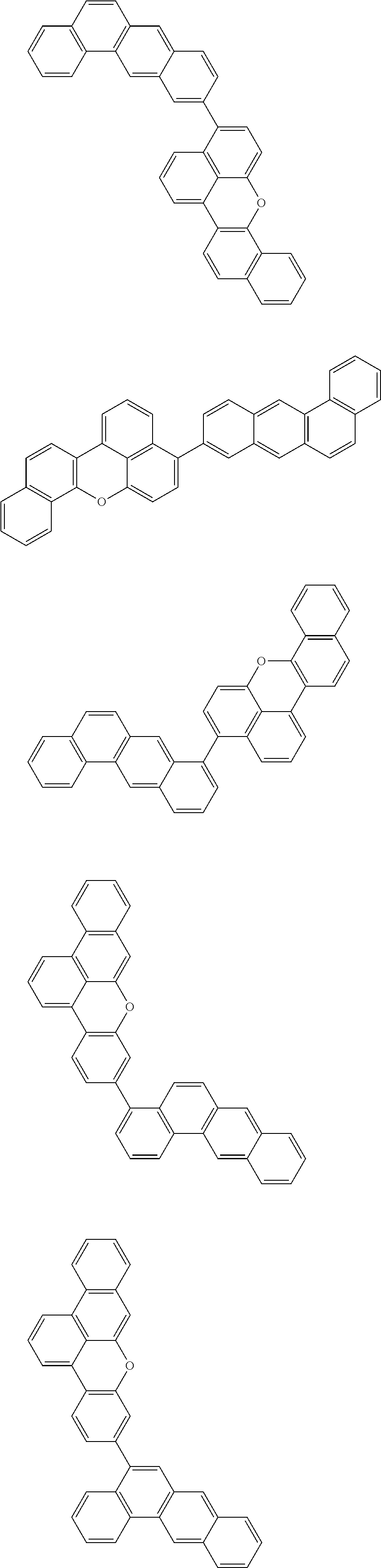 [SMILES: c1ccc2c3c(ccc2c1)-c1cccc2c(-c4ccc5cc6ccc7ccccc7c6cc5c4)ccc(c12)O3 ; c1ccc2c3c(ccc2c1)-c1cccc2c(-c4ccc5cc6c(ccc7ccccc76)cc5c4)ccc(c12)O3 ; c1cc(-c2ccc3c4c(cccc24)-c2ccc4ccccc4c2O3)c2cc3ccc4ccccc4c3cc2c1 ; c1ccc2cc3c(ccc4c(-c5ccc6c(c5)Oc5cc7ccccc7c7cccc-6c57)cccc43)cc2c1 ; c1ccc2cc3c(cc(-c4ccc5c(c4)Oc4cc6ccccc6c6cccc-5c46)c4ccccc43)cc2c1]

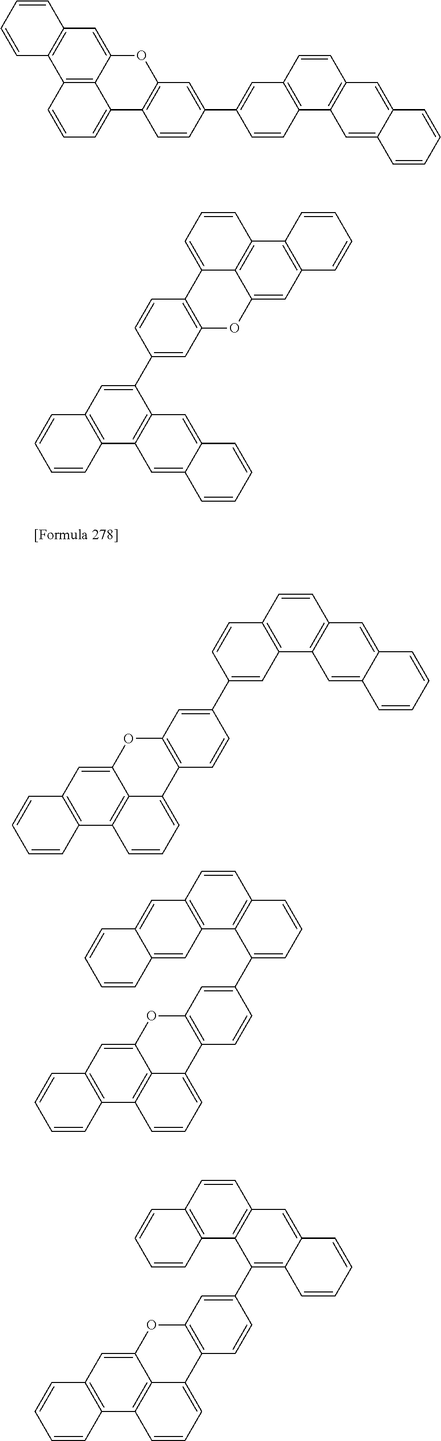

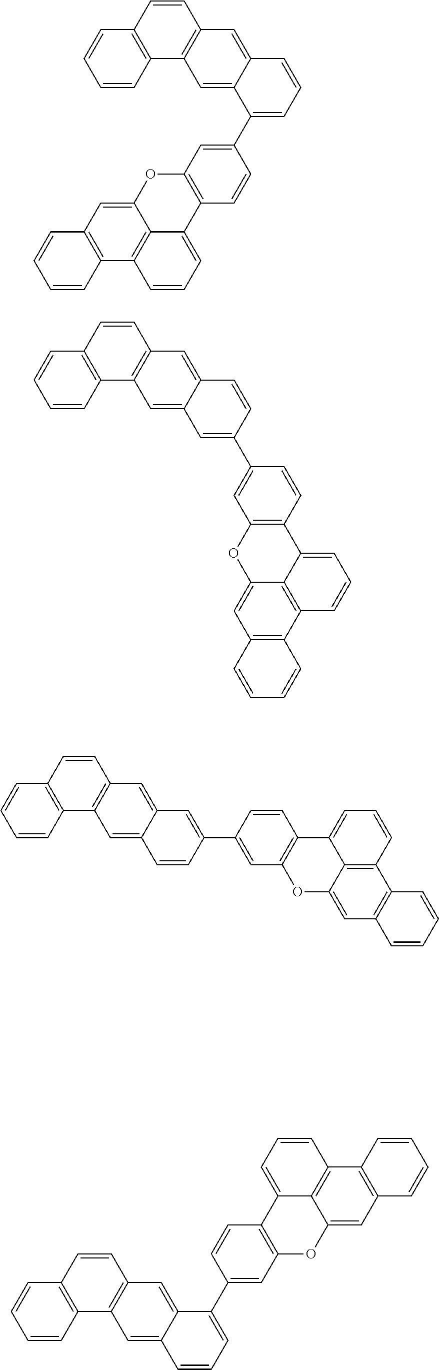

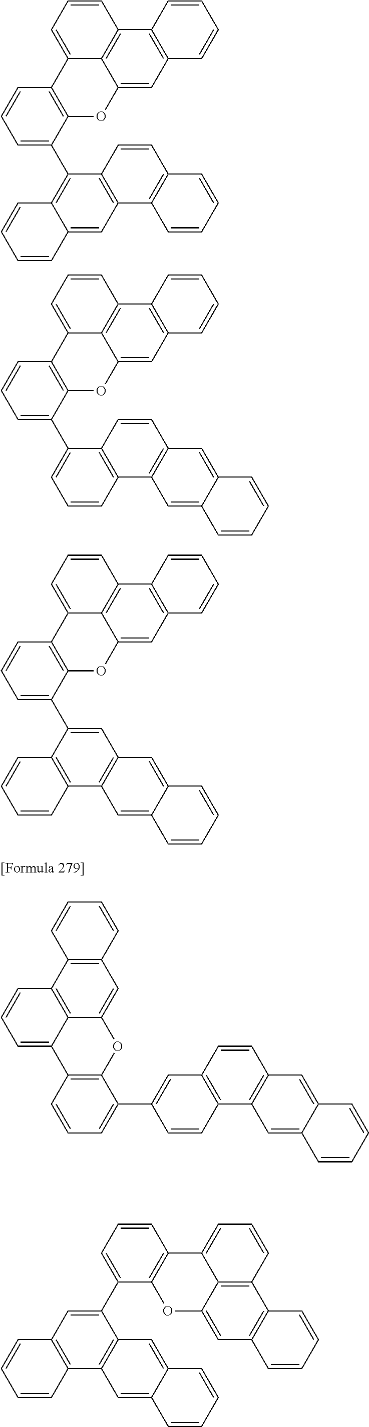

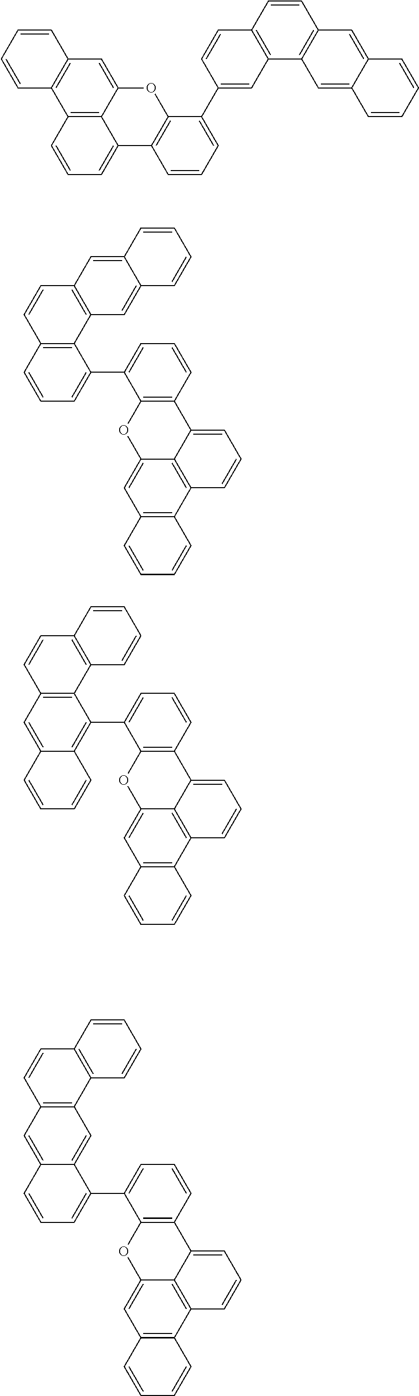

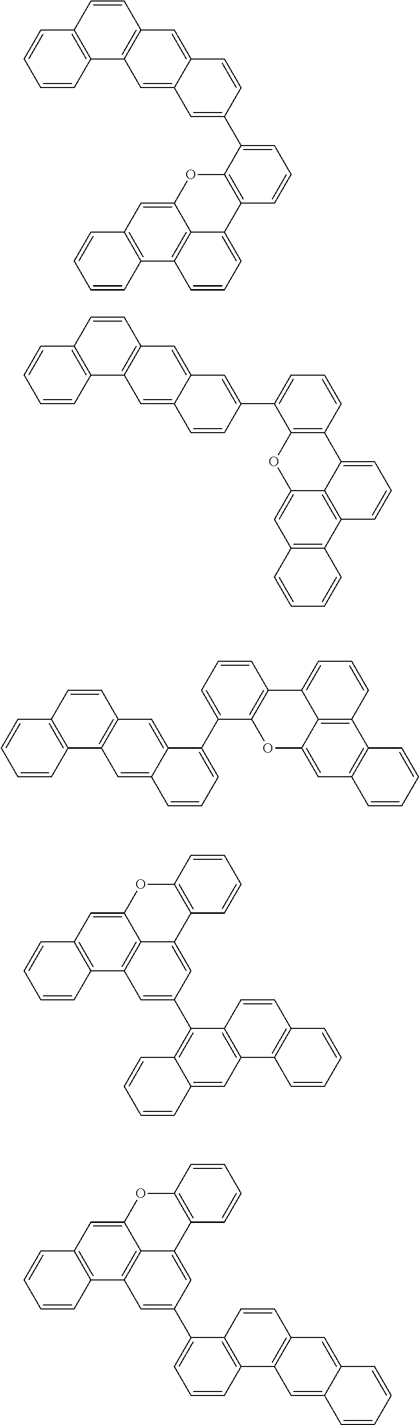

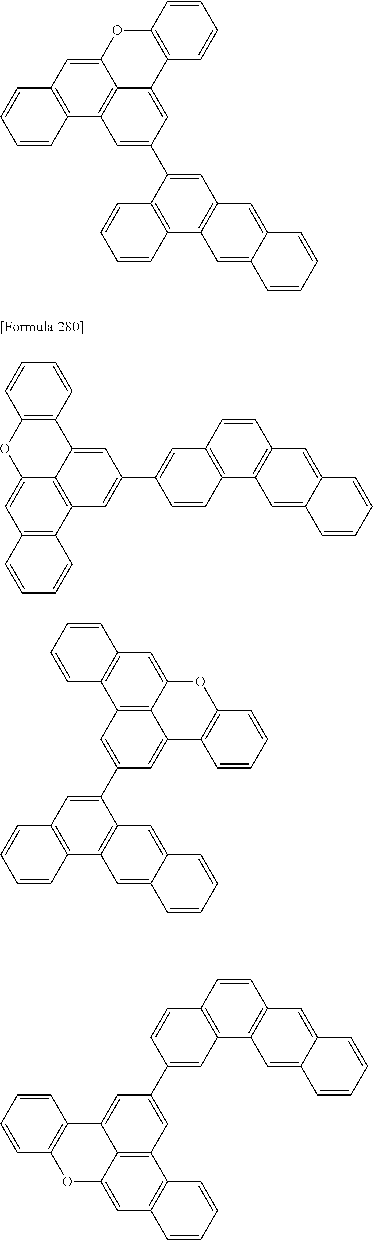

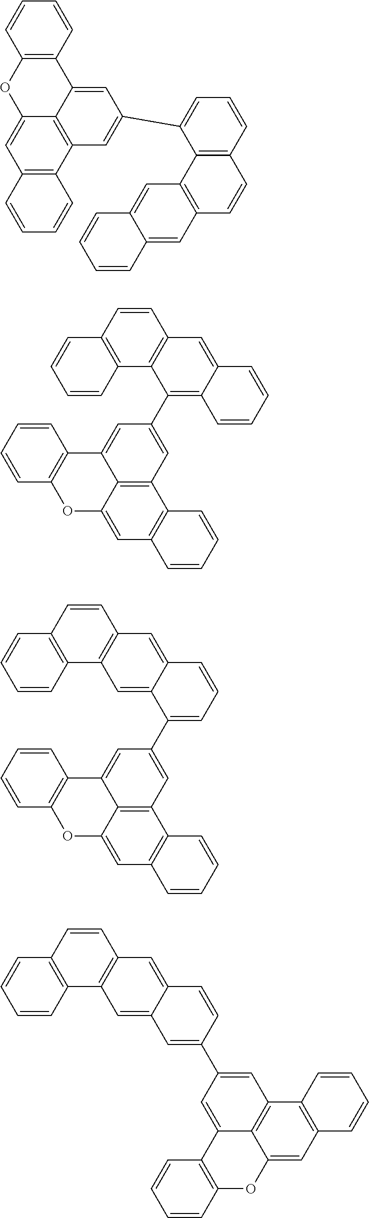

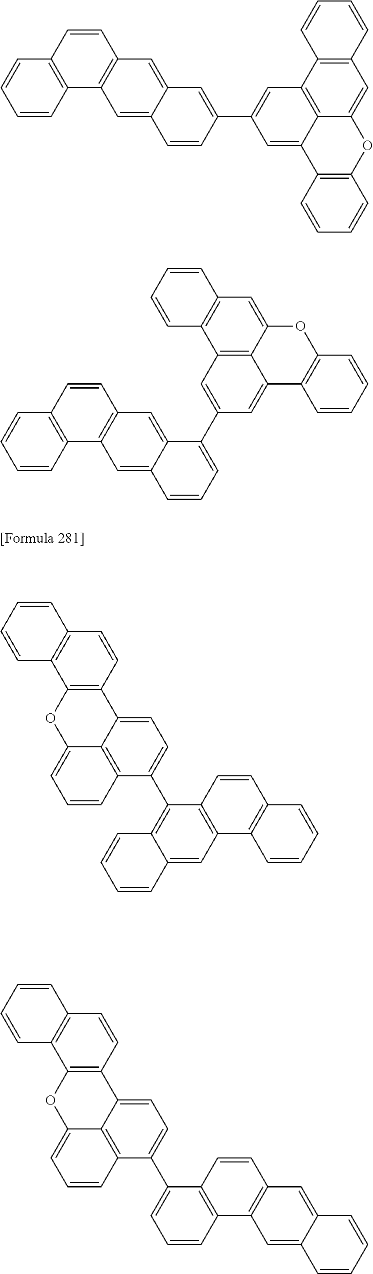 [SMILES: c1ccc2c(c1)Oc1cc3ccccc3c3cc(-c4ccc5cc6c(ccc7ccccc76)cc5c4)cc-2c13 ; c1ccc2c(c1)Oc1cc3ccccc3c3cc(-c4cccc5cc6c(ccc7ccccc76)cc45)cc-2c13 ; c1ccc2c3c(ccc2c1)-c1ccc(-c2c4ccccc4cc4c2ccc2ccccc24)c2cccc(c12)O3 ; c1ccc2cc3c(ccc4c(-c5ccc6c7c(cccc57)Oc5c-6ccc6ccccc56)cccc43)cc2c1]

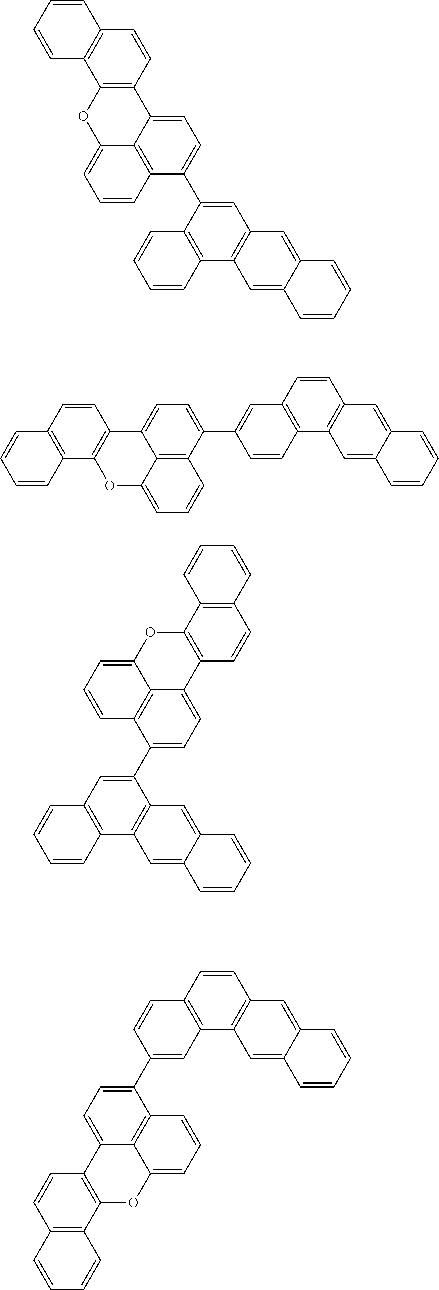

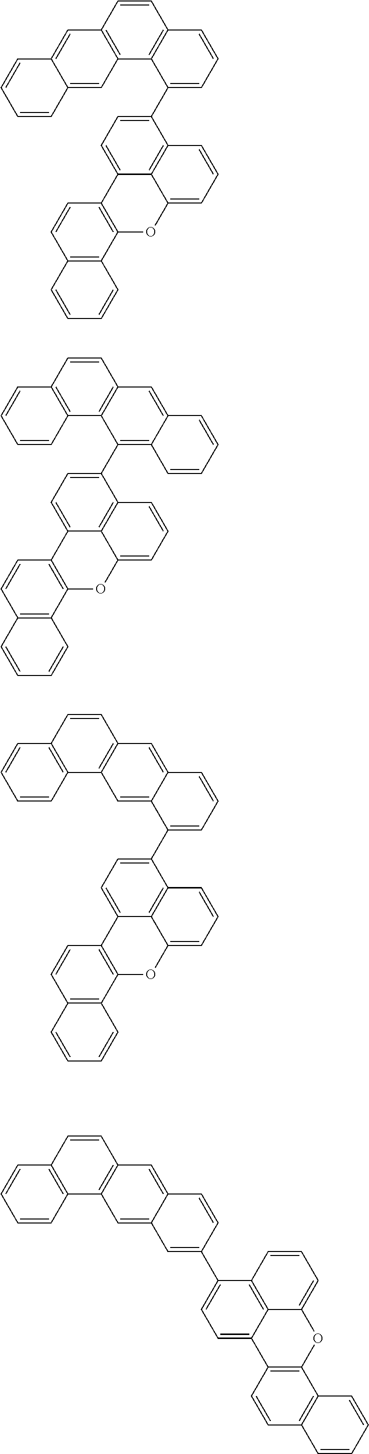

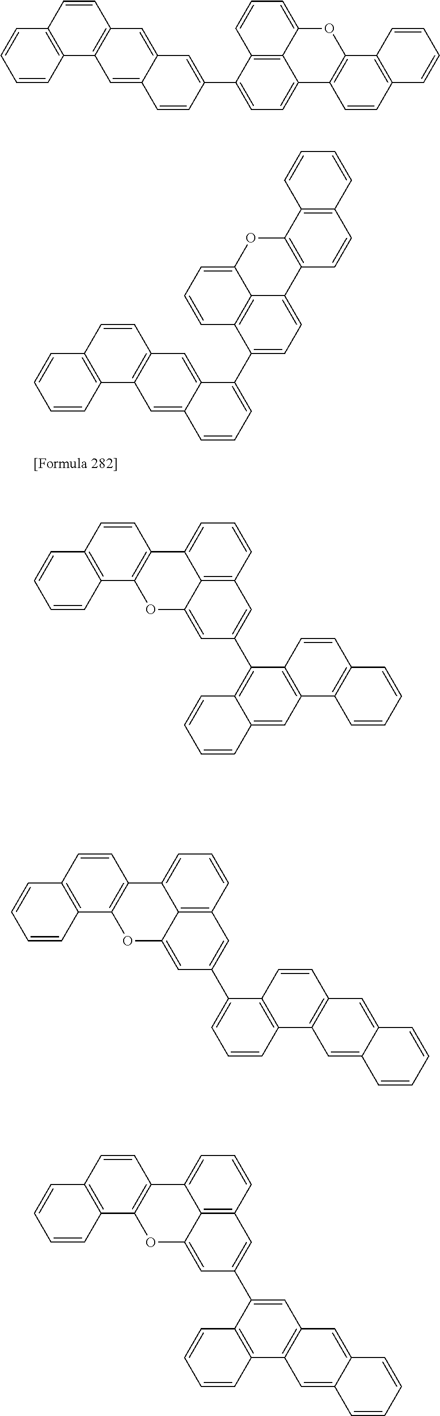

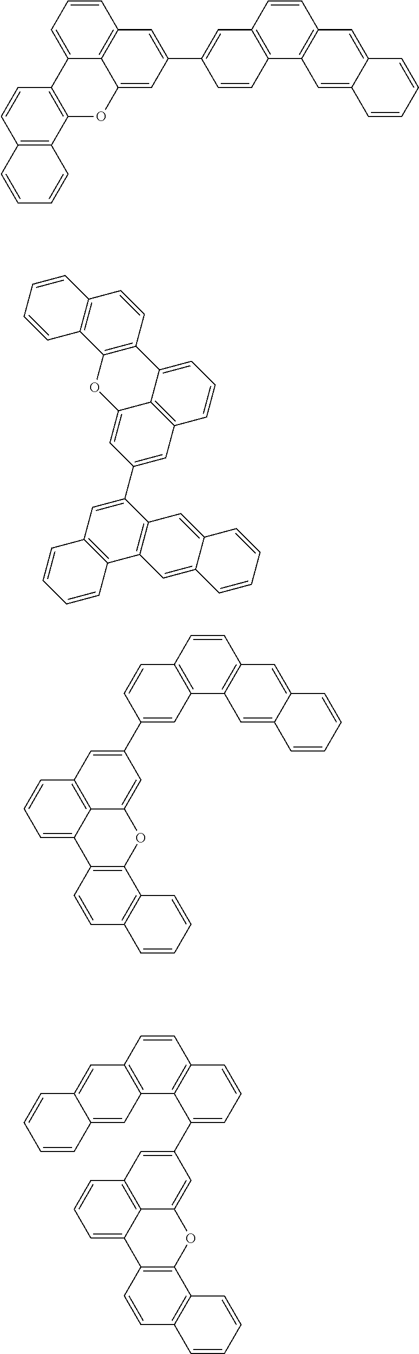

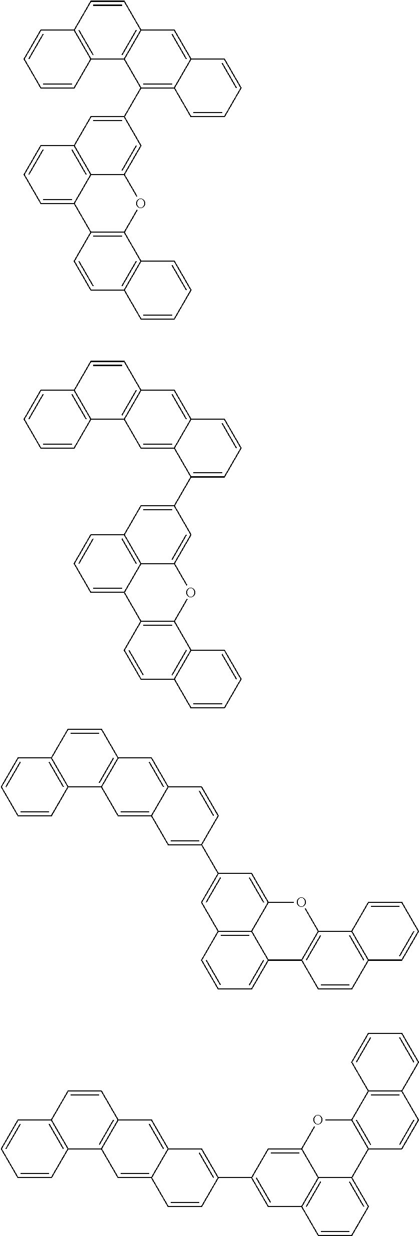

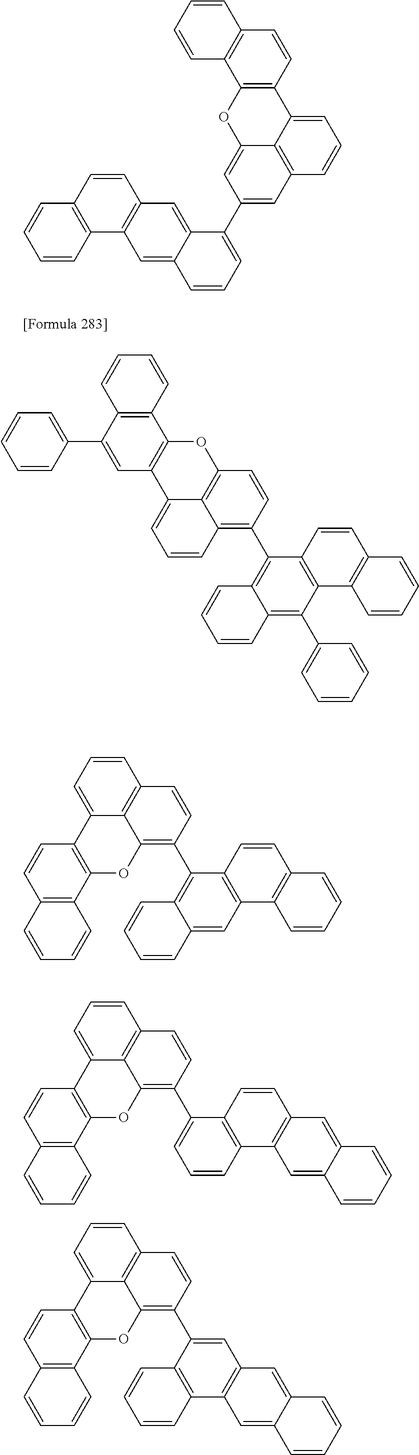

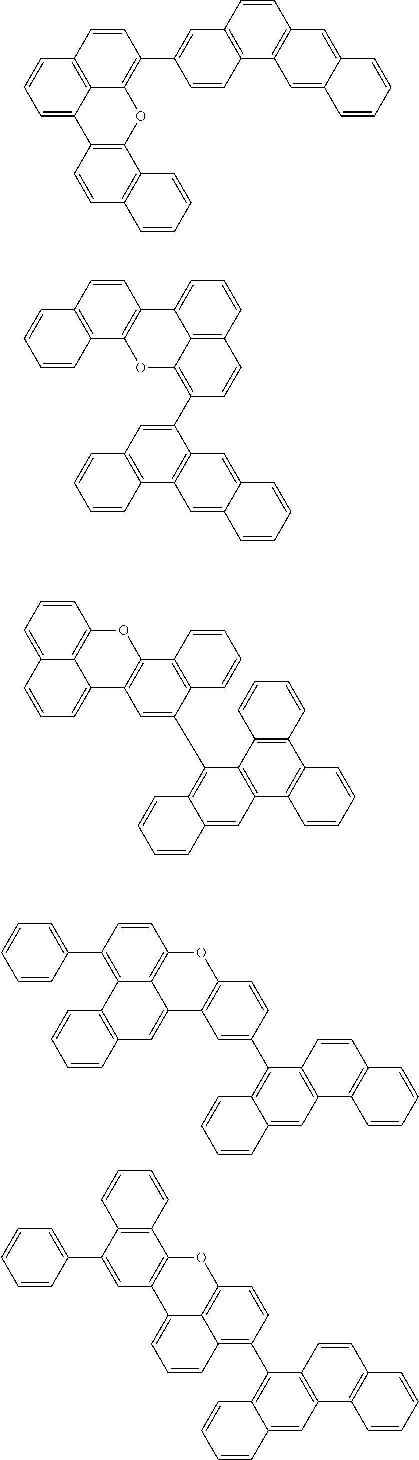 [SMILES: c1ccc2cc3c(ccc4cc(-c5ccc6cccc7c6c5Oc5c-7ccc6ccccc56)ccc43)cc2c1 ; c1ccc2cc3c(cc2c1)c(-c1ccc2cccc4c2c1Oc1c-4ccc2ccccc12)cc1ccccc13 ; c1ccc2c(-c3cc4c(c5ccccc35)Oc3cccc5cccc-4c35)c3c4ccccc4c4ccccc4c3cc2c1 ; c1ccc(-c2ccc3c4c(cc5ccccc5c24)-c2cc(-c4c5ccccc5cc5c4ccc4ccccc45)ccc2O3)cc1 ; c1ccc(-c2cc3c(c4ccccc24)Oc2ccc(-c4c5ccccc5cc5c4ccc4ccccc45)c4cccc-3c24)cc1]

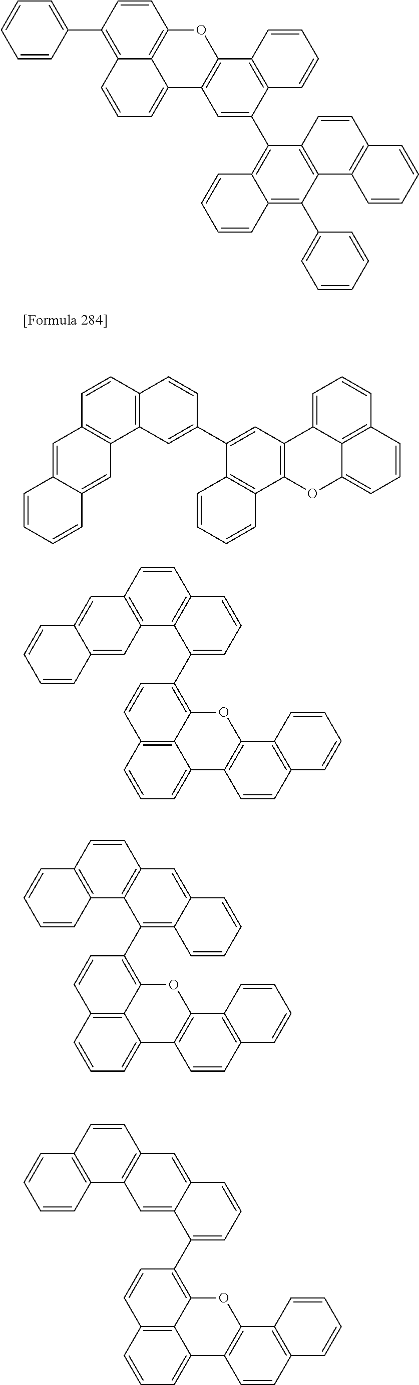

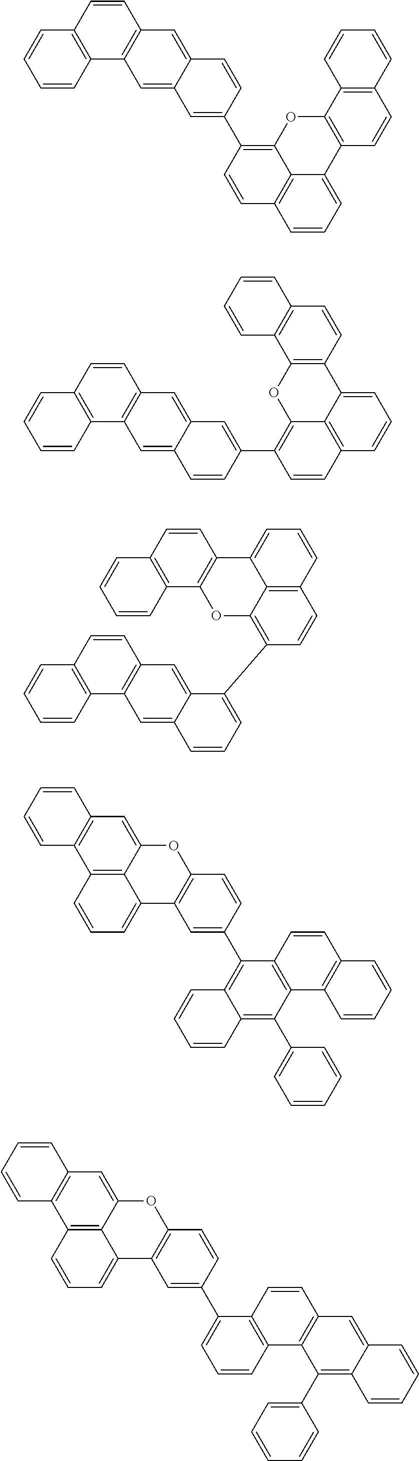 [SMILES: c1ccc2c3c(ccc2c1)-c1cccc2ccc(-c4ccc5cc6ccc7ccccc7c6cc5c4)c(c12)O3 ; c1ccc2c3c(ccc2c1)-c1cccc2ccc(-c4ccc5cc6c(ccc7ccccc76)cc5c4)c(c12)O3 ; c1cc(-c2ccc3cccc4c3c2Oc2c-4ccc3ccccc23)c2cc3ccc4ccccc4c3cc2c1 ; c1ccc(-c2c3ccccc3c(-c3ccc4c(c3)-c3cccc5c3c(cc3ccccc35)O4)c3ccc4ccccc4c23)cc1 ; c1ccc(-c2c3ccccc3cc3ccc4c(-c5ccc6c(c5)-c5cccc7c5c(cc5ccccc57)O6)cccc4c23)cc1]

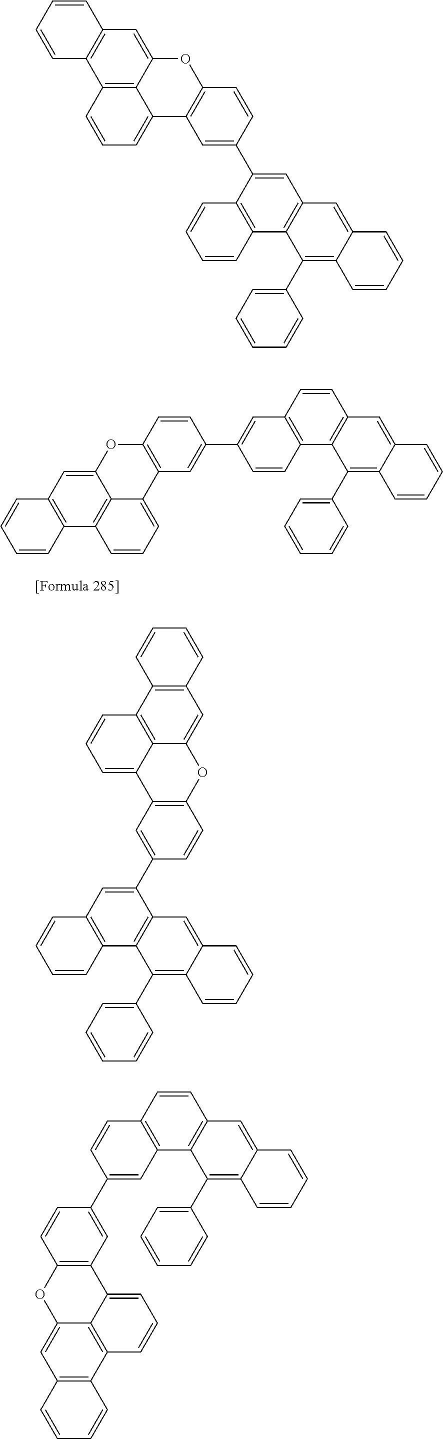

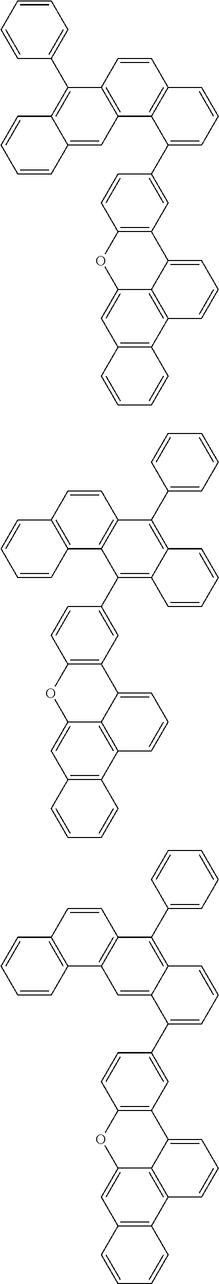

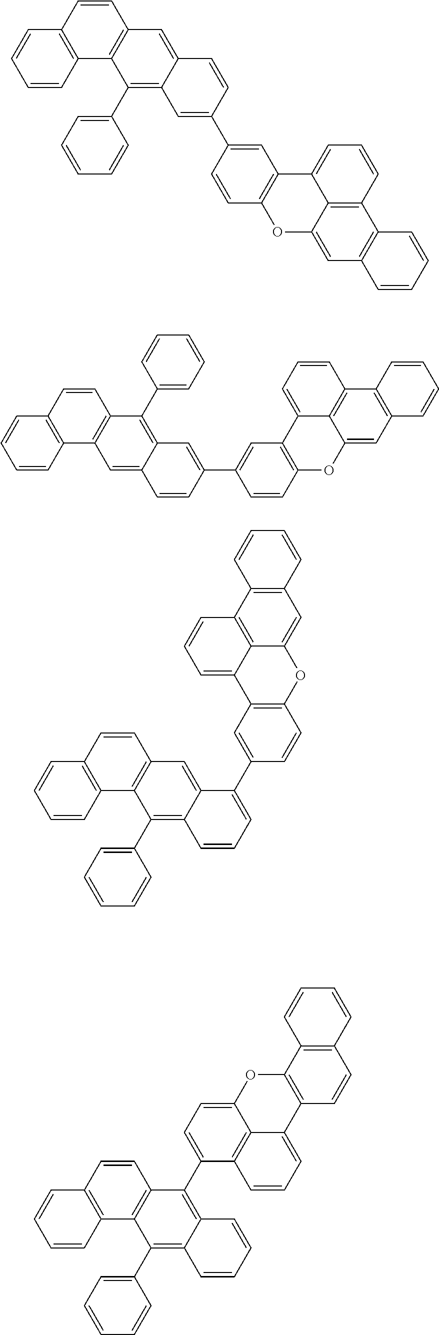

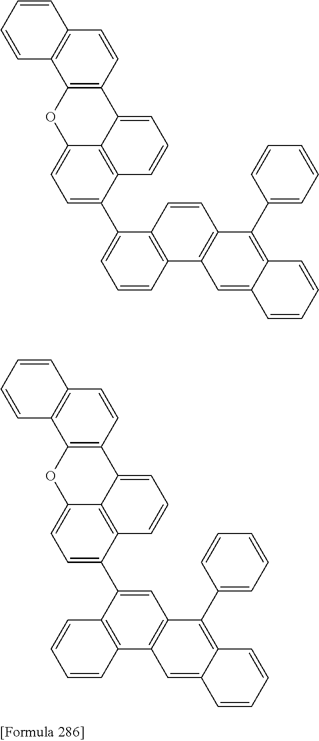 [SMILES: c1ccc(-c2c3ccccc3cc3c2ccc2c(-c4ccc5c6c(cccc46)-c4ccc6ccccc6c4O5)cccc23)cc1 ; c1ccc(-c2c3ccccc3cc3c2cc(-c2ccc4c5c(cccc25)-c2ccc5ccccc5c2O4)c2ccccc23)cc1]

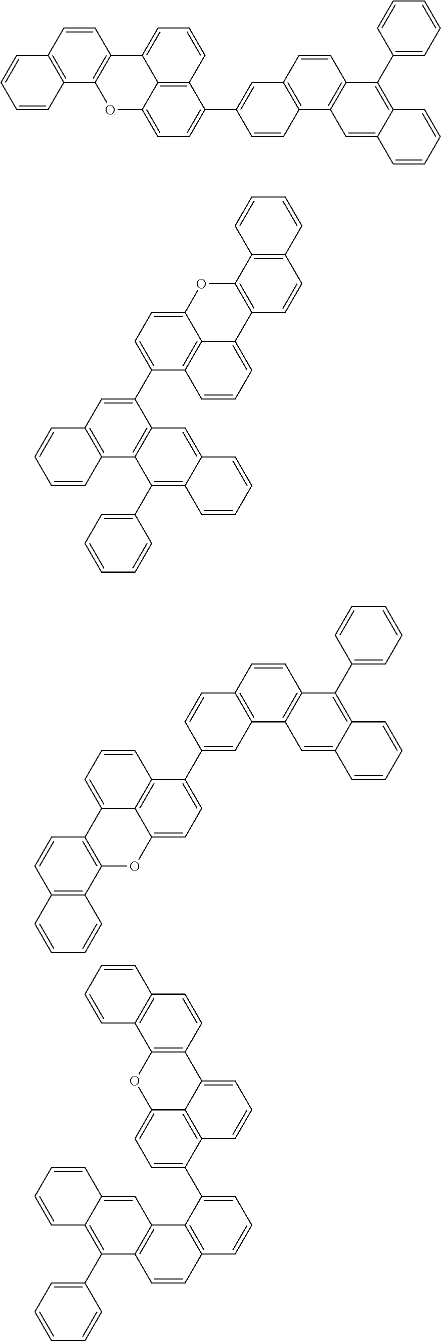

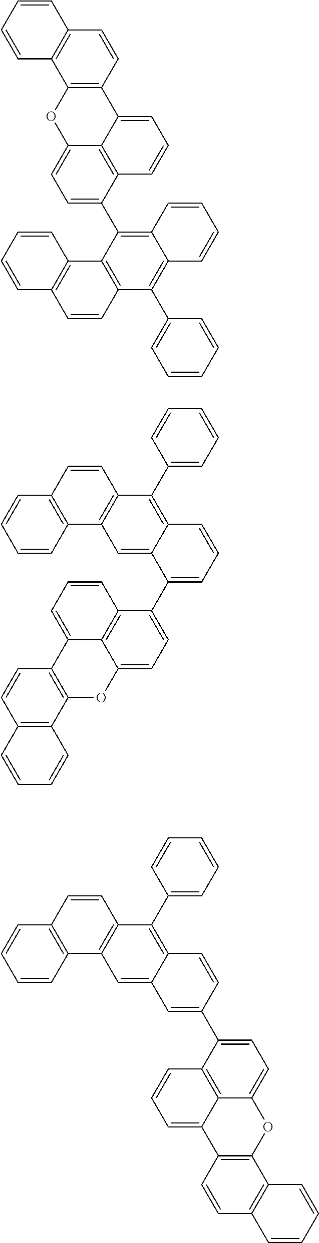

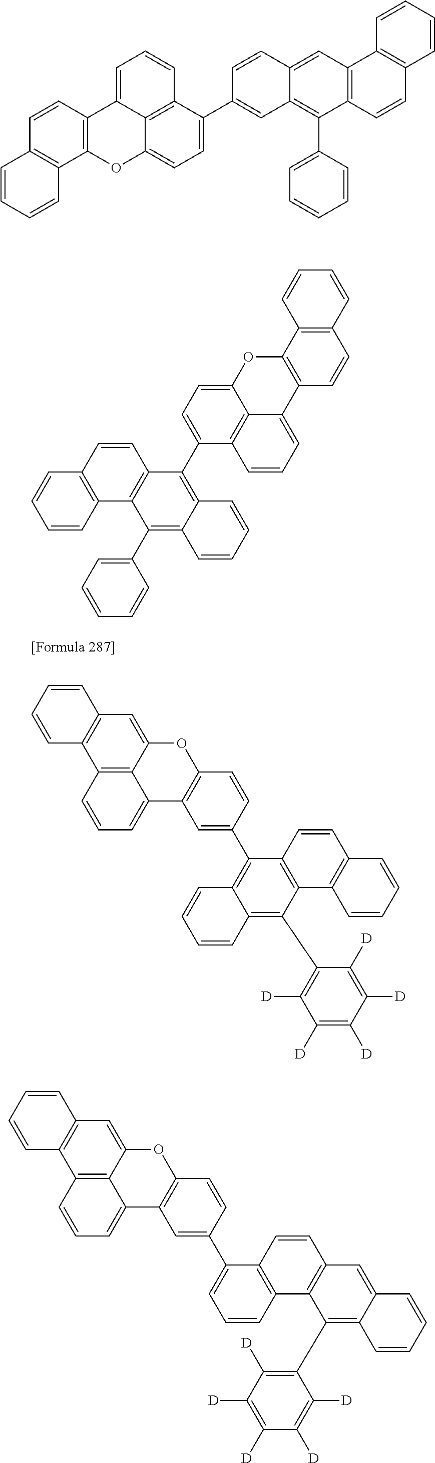 [SMILES: c1ccc(-c2c3cc(-c4ccc5c6c(cccc46)-c4ccc6ccccc6c4O5)ccc3cc3c2ccc2ccccc23)cc1 ; c1ccc(-c2c3ccccc3c(-c3ccc4c5c(cccc35)-c3ccc5ccccc5c3O4)c3ccc4ccccc4c23)cc1 ; [2H]c1c([2H])c([2H])c(-c2c3ccccc3c(-c3ccc4c(c3)-c3cccc5c3c(cc3ccccc35)O4)c3ccc4ccccc4c23)c([2H])c1[2H] ; [2H]c1c([2H])c([2H])c(-c2c3ccccc3cc3ccc4c(-c5ccc6c(c5)-c5cccc7c5c(cc5ccccc57)O6)cccc4c23)c([2H])c1[2H]]

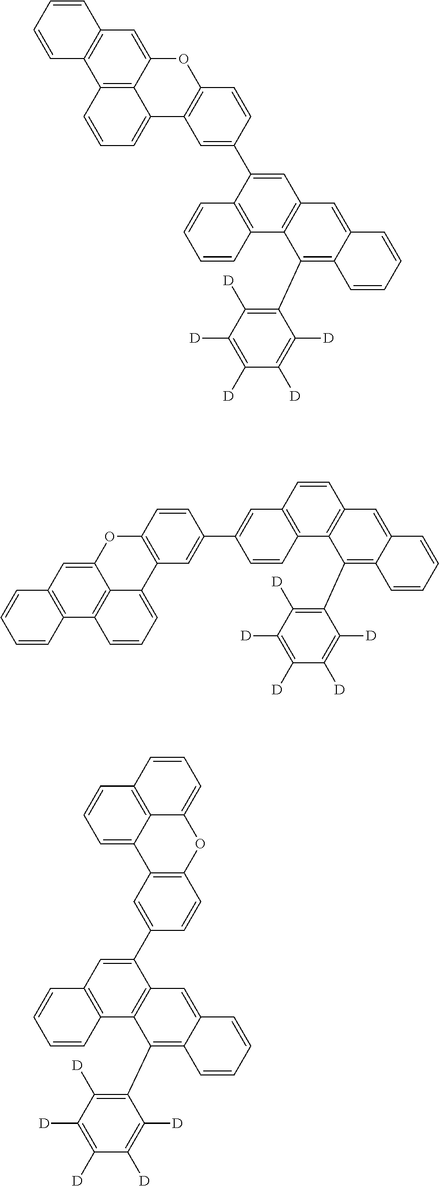 [SMILES: [2H]c1c([2H])c([2H])c(-c2c3ccccc3cc3cc(-c4ccc5c(c4)-c4cccc6c4c(cc4ccccc46)O5)c4ccccc4c23)c([2H])c1[2H] ; [2H]c1c([2H])c([2H])c(-c2c3ccccc3cc3ccc4cc(-c5ccc6c(c5)-c5cccc7c5c(cc5ccccc57)O6)ccc4c23)c([2H])c1[2H] ; [2H]c1c([2H])c([2H])c(-c2c3ccccc3cc3c(-c4ccc5c(c4)-c4cccc6cccc(c46)O5)cc4ccccc4c23)c([2H])c1[2H]]

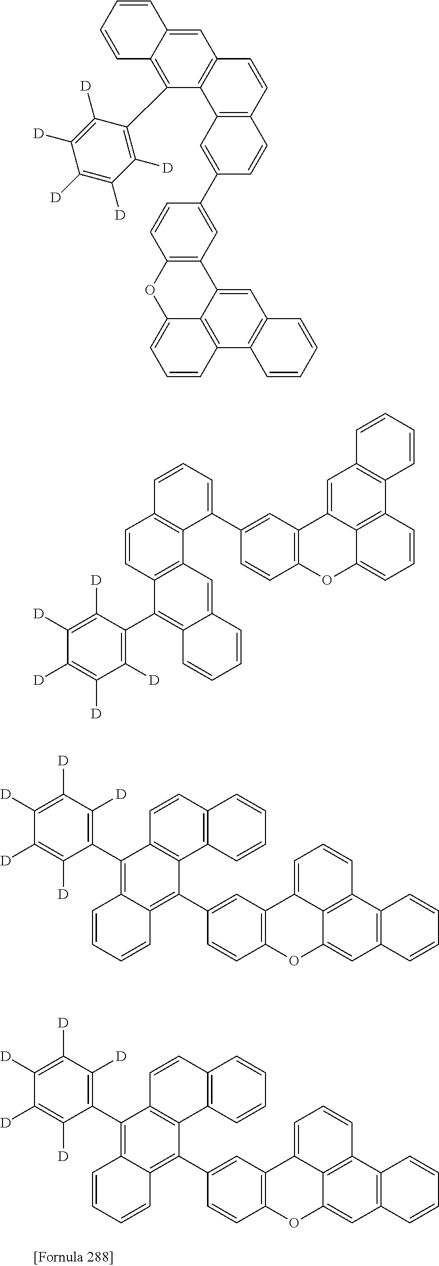 [SMILES: [2H]c1c([2H])c([2H])c(-c2c3ccccc3cc3ccc4ccc(-c5ccc6c(c5)-c5cc7ccccc7c7cccc(c57)O6)cc4c23)c([2H])c1[2H] ; [2H]c1c([2H])c([2H])c(-c2c3ccccc3cc3c2ccc2cccc(-c4ccc5c(c4)-c4cc6ccccc6c6cccc(c46)O5)c23)c([2H])c1[2H] ; [2H]c1c([2H])c([2H])c(-c2c3ccccc3c(-c3ccc4c(c3)-c3cccc5c3c(cc3ccccc35)O4)c3c2ccc2ccccc23)c([2H])c1[2H] ; [2H]c1c([2H])c([2H])c(-c2c3ccccc3c(-c3ccc4c(c3)-c3cccc5c3c(cc3ccccc35)O4)c3c2ccc2ccccc23)c([2H])c1[2H]]

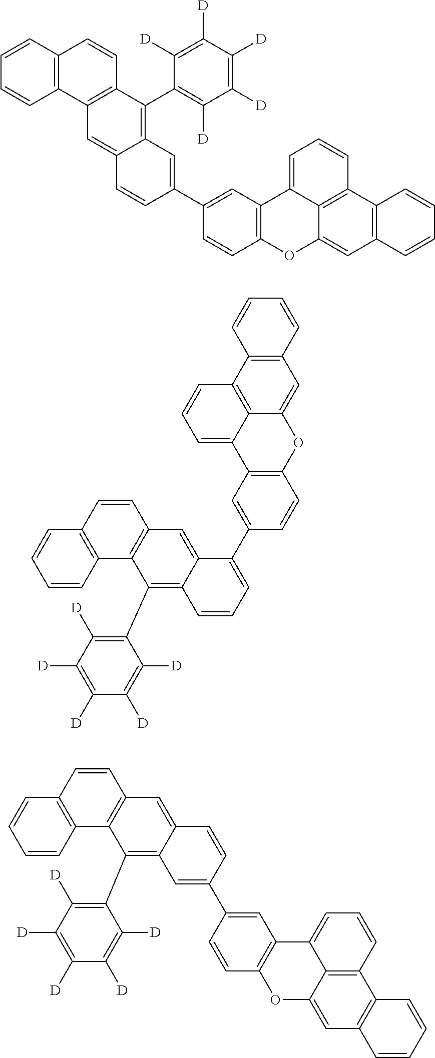

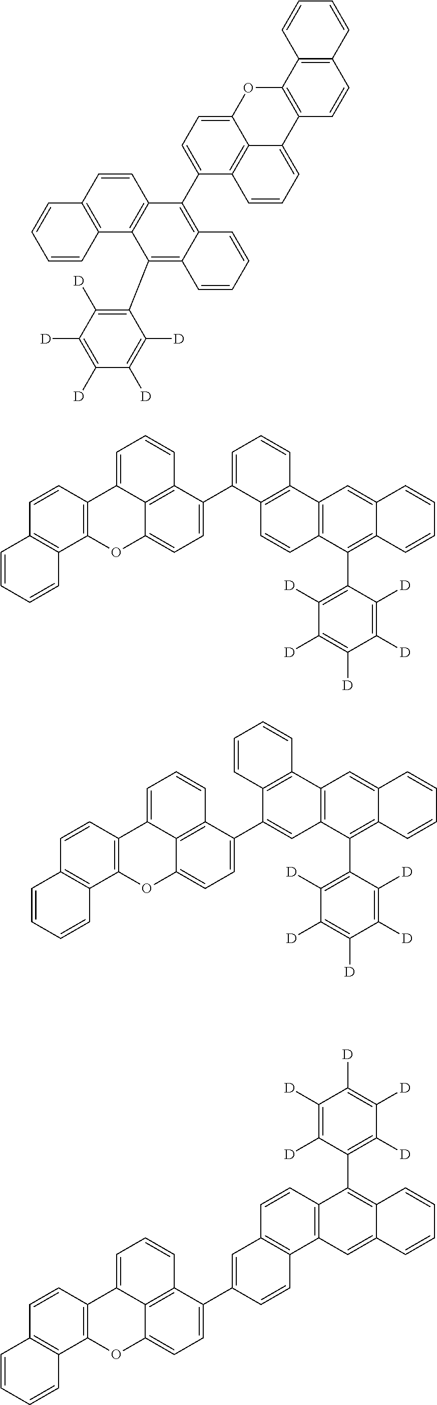

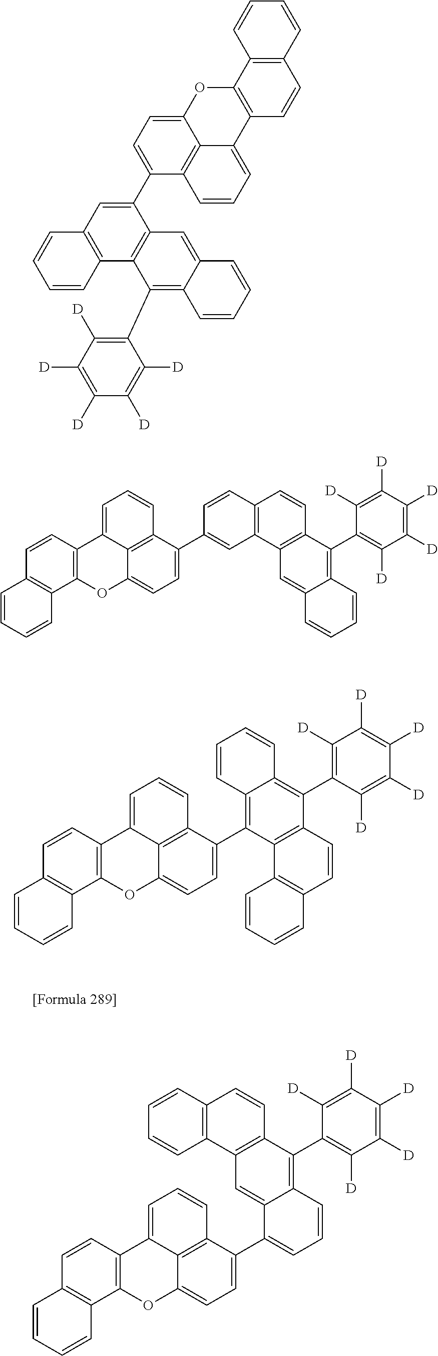 [SMILES: [2H]c1c([2H])c([2H])c(-c2c3ccccc3cc3c(-c4ccc5c6c(cccc46)-c4ccc6ccccc6c4O5)cc4ccccc4c23)c([2H])c1[2H] ; [2H]c1c([2H])c([2H])c(-c2c3ccccc3cc3c2ccc2ccc(-c4ccc5c6c(cccc46)-c4ccc6ccccc6c4O5)cc23)c([2H])c1[2H] ; [2H]c1c([2H])c([2H])c(-c2c3ccccc3c(-c3ccc4c5c(cccc35)-c3ccc5ccccc5c3O4)c3c2ccc2ccccc23)c([2H])c1[2H] ; [2H]c1c([2H])c([2H])c(-c2c3cccc(-c4ccc5c6c(cccc46)-c4ccc6ccccc6c4O5)c3cc3c2ccc2ccccc23)c([2H])c1[2H]]

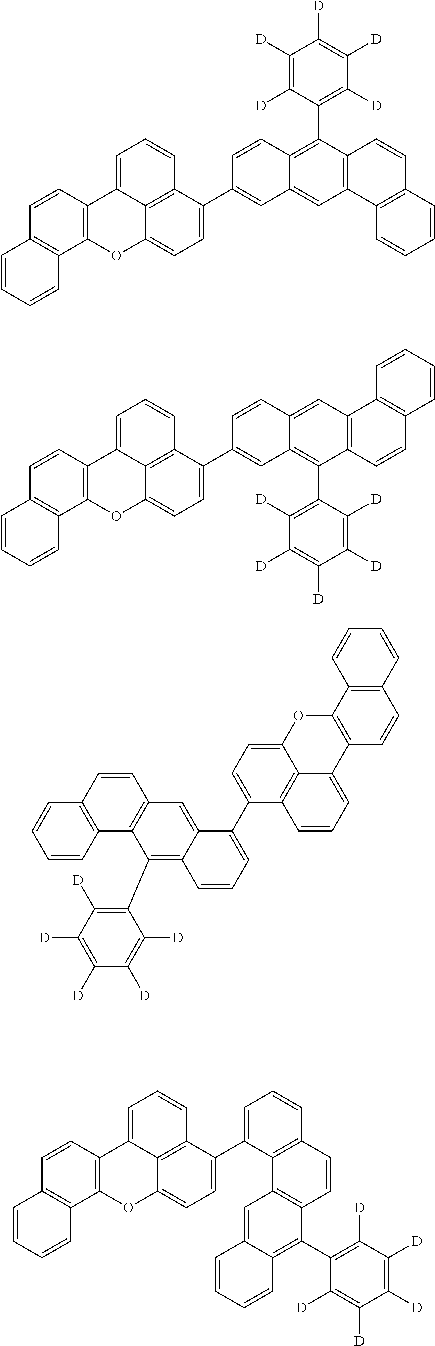

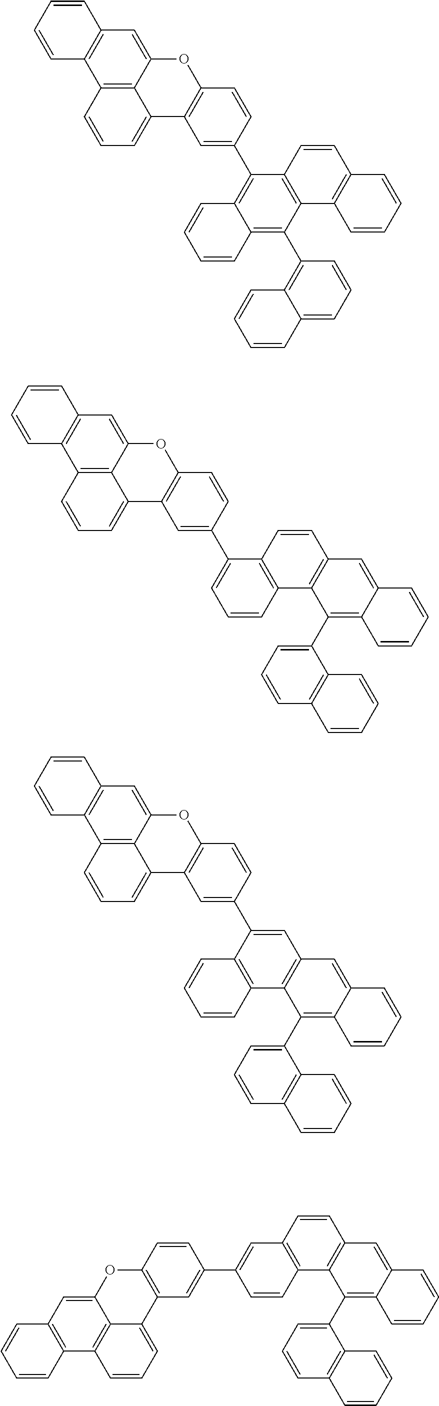 [SMILES: c1ccc2c(-c3c4ccccc4c(-c4ccc5c(c4)-c4cccc6c4c(cc4ccccc46)O5)c4ccc5ccccc5c34)cccc2c1 ; c1ccc2c(-c3c4ccccc4cc4ccc5c(-c6ccc7c(c6)-c6cccc8c6c(cc6ccccc68)O7)cccc5c34)cccc2c1 ; c1ccc2c(-c3c4ccccc4cc4cc(-c5ccc6c(c5)-c5cccc7c5c(cc5ccccc57)O6)c5ccccc5c34)cccc2c1 ; c1ccc2c(-c3c4ccccc4cc4ccc5cc(-c6ccc7c(c6)-c6cccc8c6c(cc6ccccc68)O7)ccc5c34)cccc2c1]

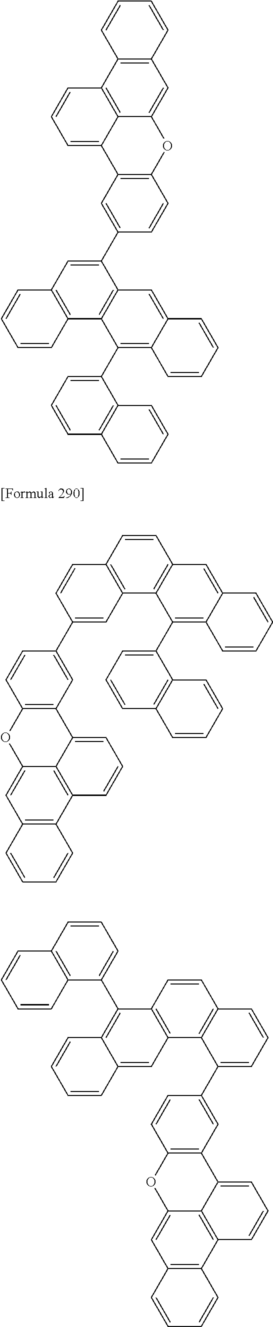

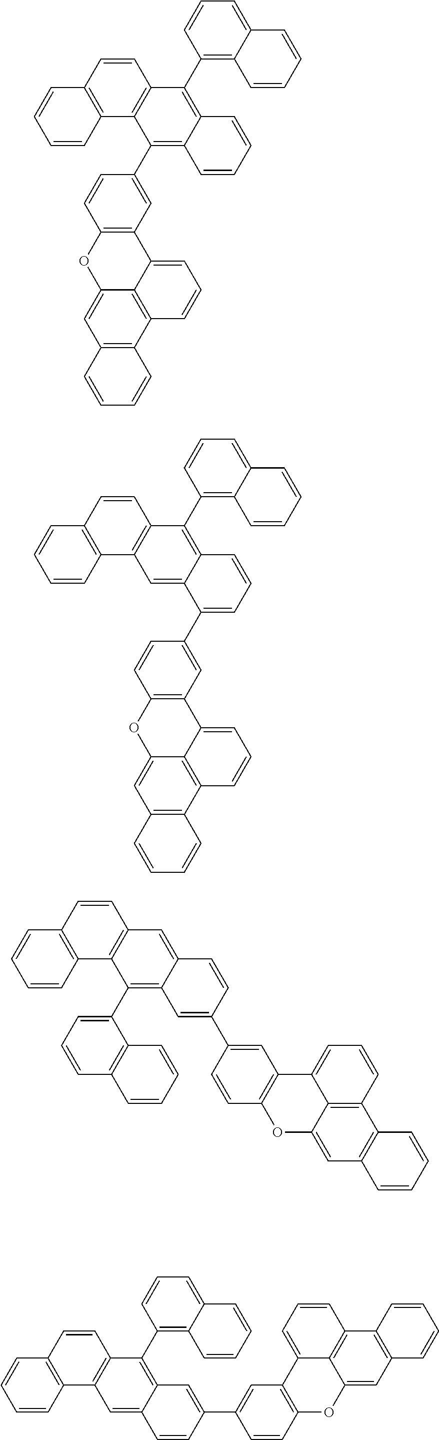 [SMILES: c1ccc2c(-c3c4ccccc4c(-c4ccc5c(c4)-c4cccc6c4c(cc4ccccc46)O5)c4c3ccc3ccccc34)cccc2c1 ; c1ccc2c(-c3c4cccc(-c5ccc6c(c5)-c5cccc7c5c(cc5ccccc57)O6)c4cc4c3ccc3ccccc34)cccc2c1 ; c1ccc2c(-c3c4cc(-c5ccc6c(c5)-c5cccc7c5c(cc5ccccc57)O6)ccc4cc4ccc5ccccc5c34)cccc2c1 ; c1ccc2c(-c3c4cc(-c5ccc6c(c5)-c5cccc7c5c(cc5ccccc57)O6)ccc4cc4c3ccc3ccccc34)cccc2c1]

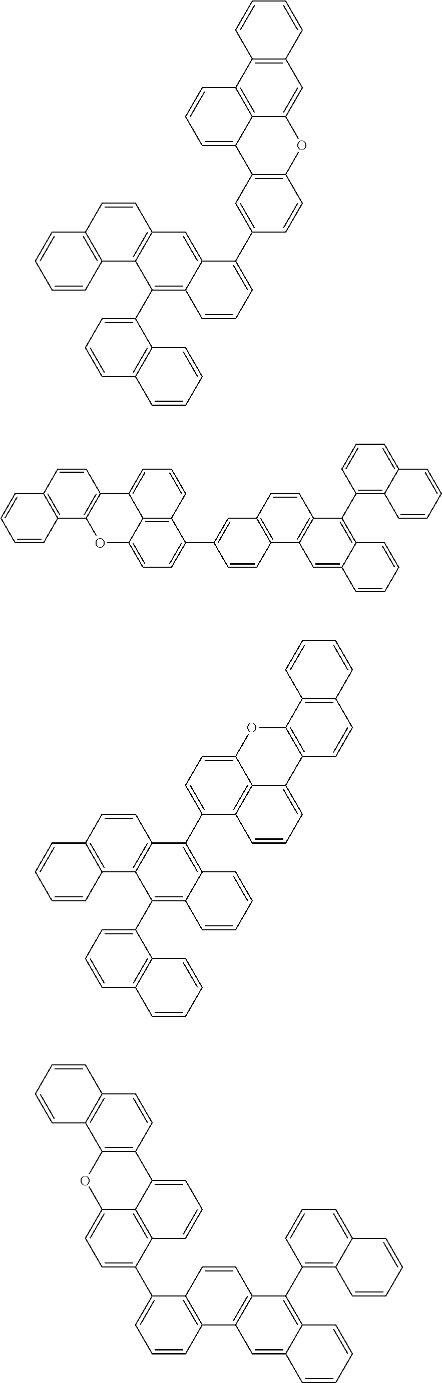 [SMILES: c1ccc2c(-c3c4cccc(-c5ccc6c(c5)-c5cccc7c5c(cc5ccccc57)O6)c4cc4ccc5ccccc5c34)cccc2c1 ; c1ccc2c(-c3c4ccccc4cc4c3ccc3cc(-c5ccc6c7c(cccc57)-c5ccc7ccccc7c5O6)ccc34)cccc2c1 ; c1ccc2c(-c3c4ccccc4c(-c4ccc5c6c(cccc46)-c4ccc6ccccc6c4O5)c4ccc5ccccc5c34)cccc2c1 ; c1ccc2c(-c3c4ccccc4cc4c3ccc3c(-c5ccc6c7c(cccc57)-c5ccc7ccccc7c5O6)cccc34)cccc2c1]

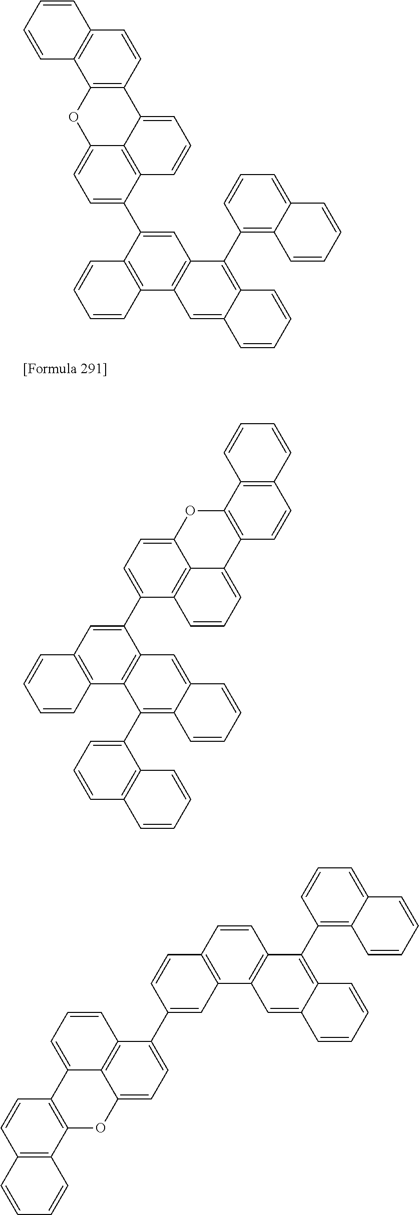 [SMILES: c1ccc2c(-c3c4ccccc4cc4c3cc(-c3ccc5c6c(cccc36)-c3ccc6ccccc6c3O5)c3ccccc34)cccc2c1 ; c1ccc2c(-c3c4ccccc4cc4c(-c5ccc6c7c(cccc57)-c5ccc7ccccc7c5O6)cc5ccccc5c34)cccc2c1 ; c1ccc2c(-c3c4ccccc4cc4c3ccc3ccc(-c5ccc6c7c(cccc57)-c5ccc7ccccc7c5O6)cc34)cccc2c1]

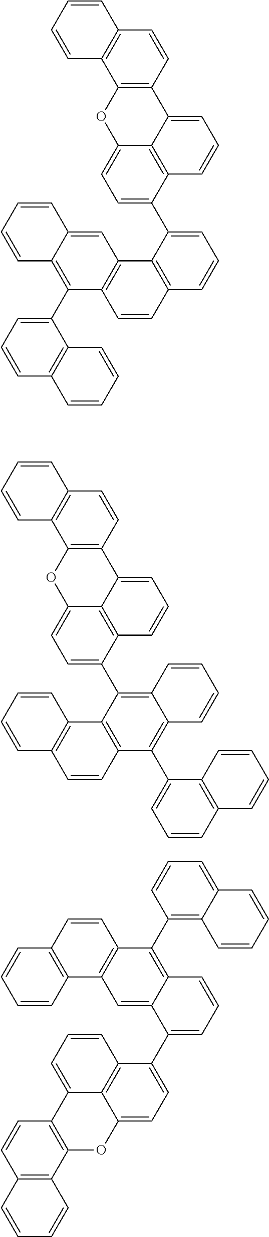

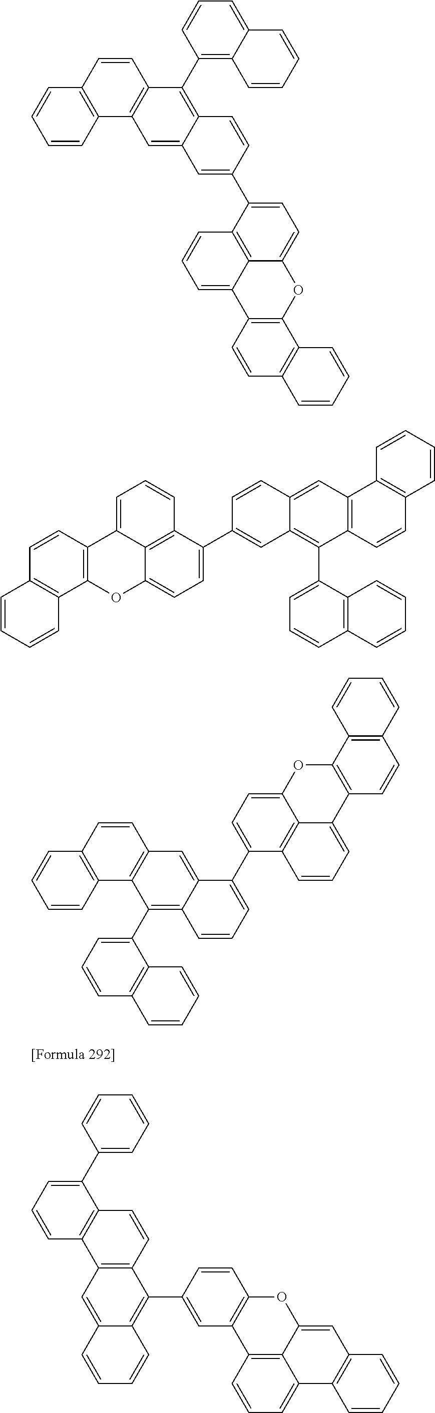

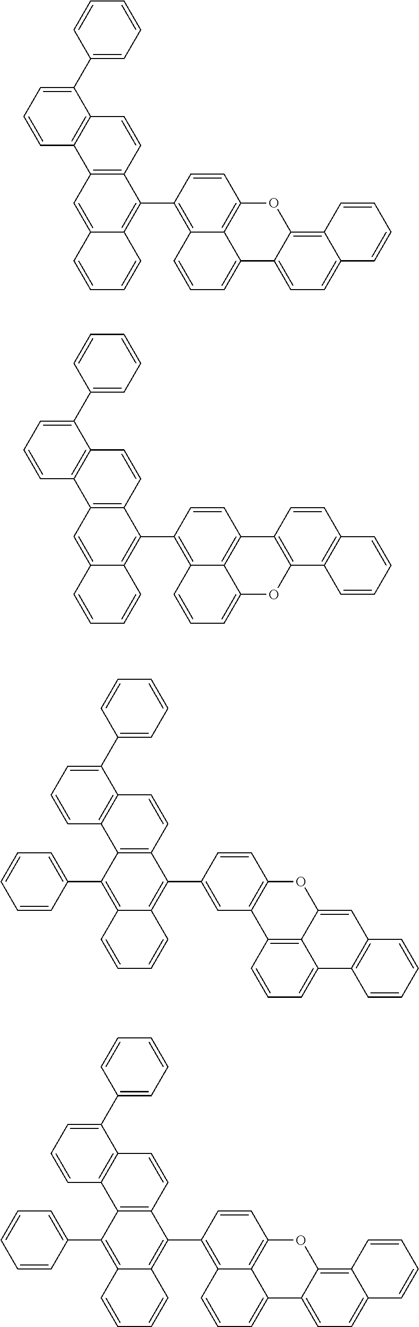

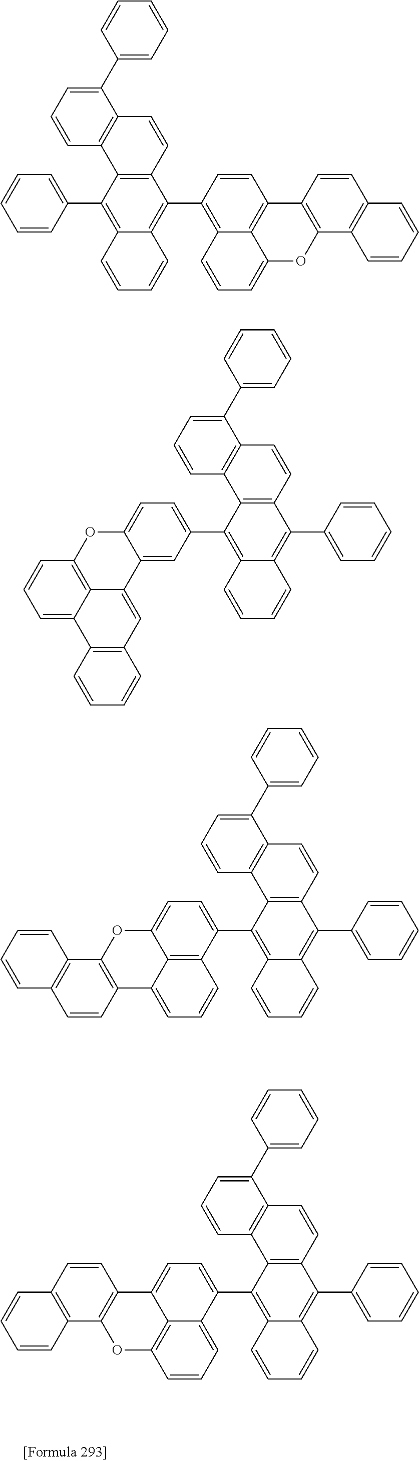

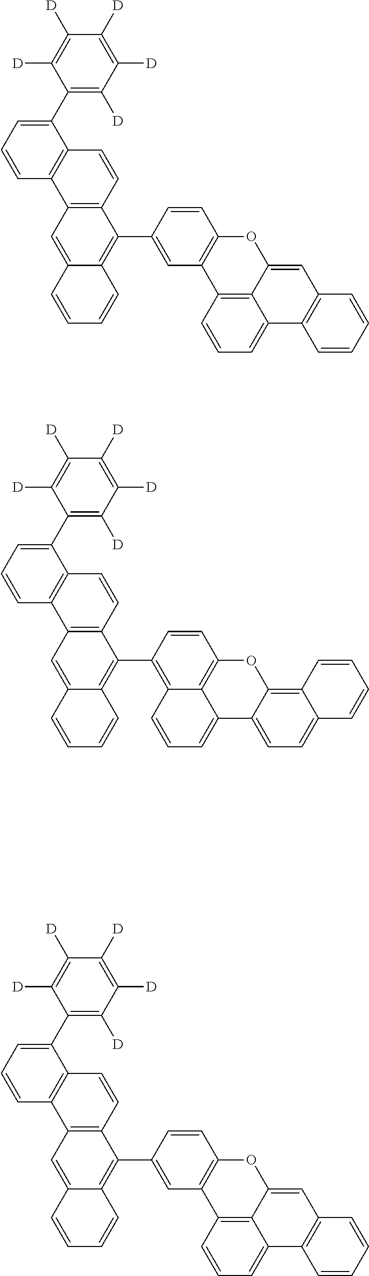 [SMILES: [2H]c1c([2H])c([2H])c(-c2cccc3c2ccc2c(-c4ccc5c(c4)-c4cccc6c4c(cc4ccccc46)O5)c4ccccc4cc23)c([2H])c1[2H] ; [2H]c1c([2H])c([2H])c(-c2cccc3c2ccc2c(-c4ccc5c6c(cccc46)-c4ccc6ccccc6c4O5)c4ccccc4cc23)c([2H])c1[2H] ; [2H]c1c([2H])c([2H])c(-c2cccc3c2ccc2c(-c4ccc5c(c4)-c4cccc6c4c(cc4ccccc46)O5)c4ccccc4cc23)c([2H])c1[2H]]

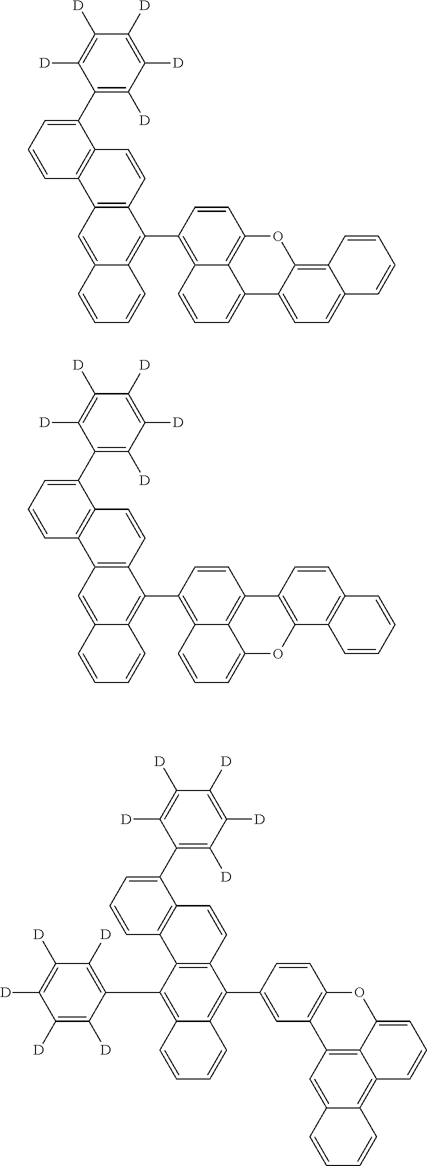

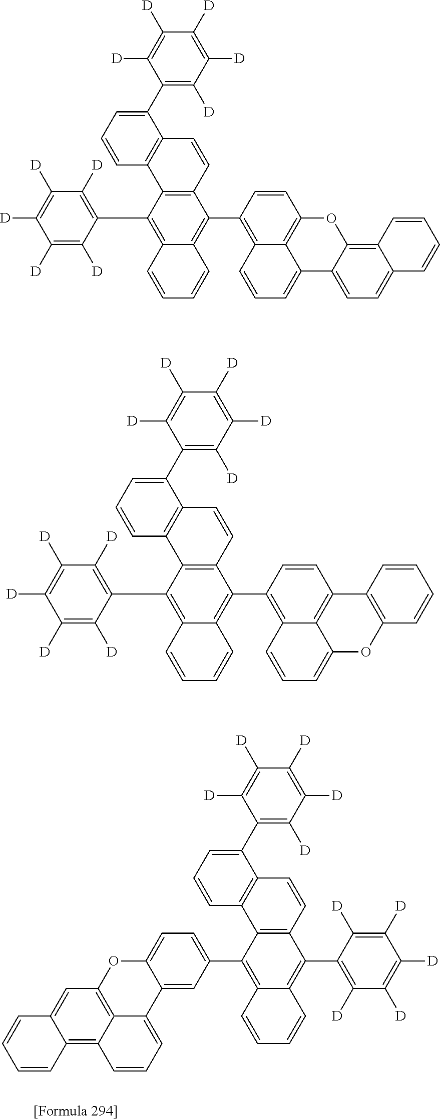 [SMILES: [2H]c1c([2H])c([2H])c(-c2cccc3c2ccc2c(-c4ccc5c6c(cccc46)-c4ccc6ccccc6c4O5)c4ccccc4c(-c4c([2H])c([2H])c([2H])c([2H])c4[2H])c23)c([2H])c1[2H] ; [2H]c1c([2H])c([2H])c(-c2cccc3c2ccc2c(-c4ccc5c6c(cccc46)Oc4ccccc4-5)c4ccccc4c(-c4c([2H])c([2H])c([2H])c([2H])c4[2H])c23)c([2H])c1[2H] ; [2H]c1c([2H])c([2H])c(-c2cccc3c2ccc2c(-c4c([2H])c([2H])c([2H])c([2H])c4[2H])c4ccccc4c(-c4ccc5c(c4)-c4cccc6c4c(cc4ccccc46)O5)c23)c([2H])c1[2H]]

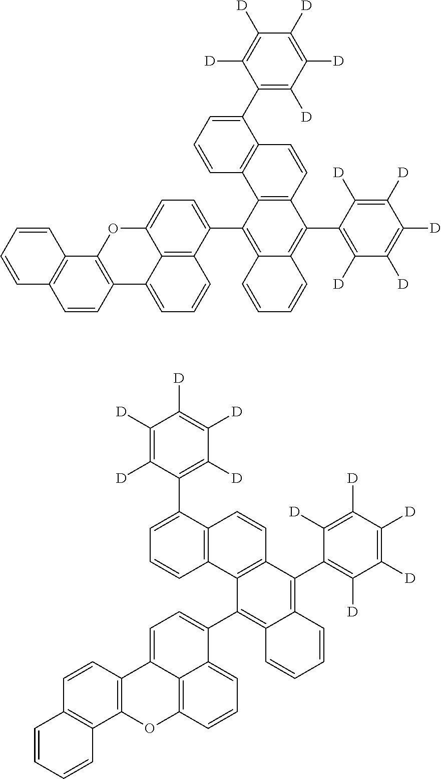 [SMILES: [2H]c1c([2H])c([2H])c(-c2cccc3c2ccc2c(-c4c([2H])c([2H])c([2H])c([2H])c4[2H])c4ccccc4c(-c4ccc5c6c(cccc46)-c4ccc6ccccc6c4O5)c23)c([2H])c1[2H] ; [2H]c1c([2H])c([2H])c(-c2cccc3c2ccc2c(-c4c([2H])c([2H])c([2H])c([2H])c4[2H])c4ccccc4c(-c4ccc5c6c(cccc46)Oc4c-5ccc5ccccc45)c23)c([2H])c1[2H]]

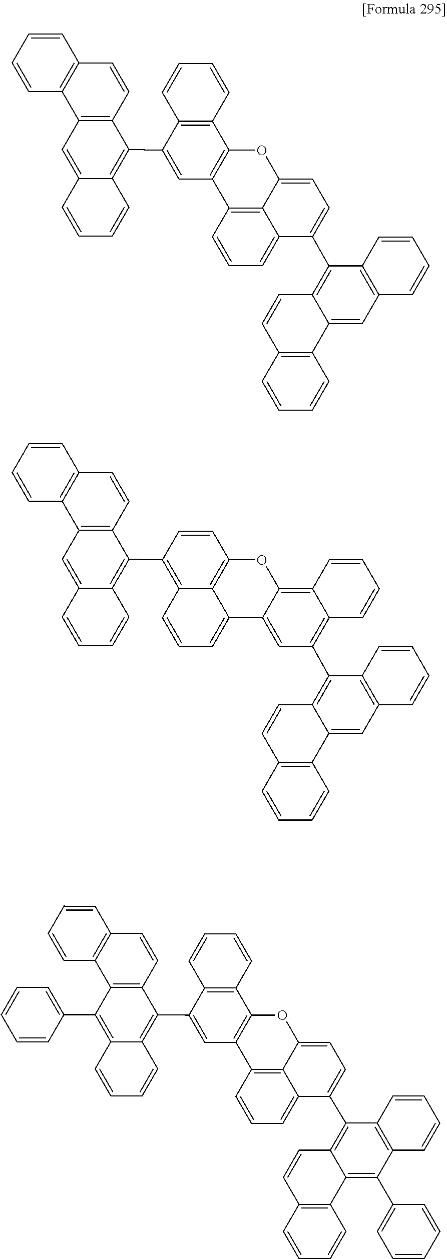 [SMILES: c1ccc2c(-c3cc4c(c5ccccc35)Oc3ccc(-c5c6ccccc6cc6c5ccc5ccccc56)c5cccc-4c35)c3ccc4ccccc4c3cc2c1 ; c1ccc2c(-c3cc4c(c5ccccc35)Oc3ccc(-c5c6ccccc6cc6c5ccc5ccccc56)c5cccc-4c35)c3ccc4ccccc4c3cc2c1 ; Cc1ccc2c(ccc3c(-c4cc5c(c6ccccc46)Oc4ccc(-c6c7ccccc7c(-c7ccccc7)c7c6ccc6ccccc67)c6cccc-5c46)c4ccccc4c(-c4ccccc4)c32)c1]

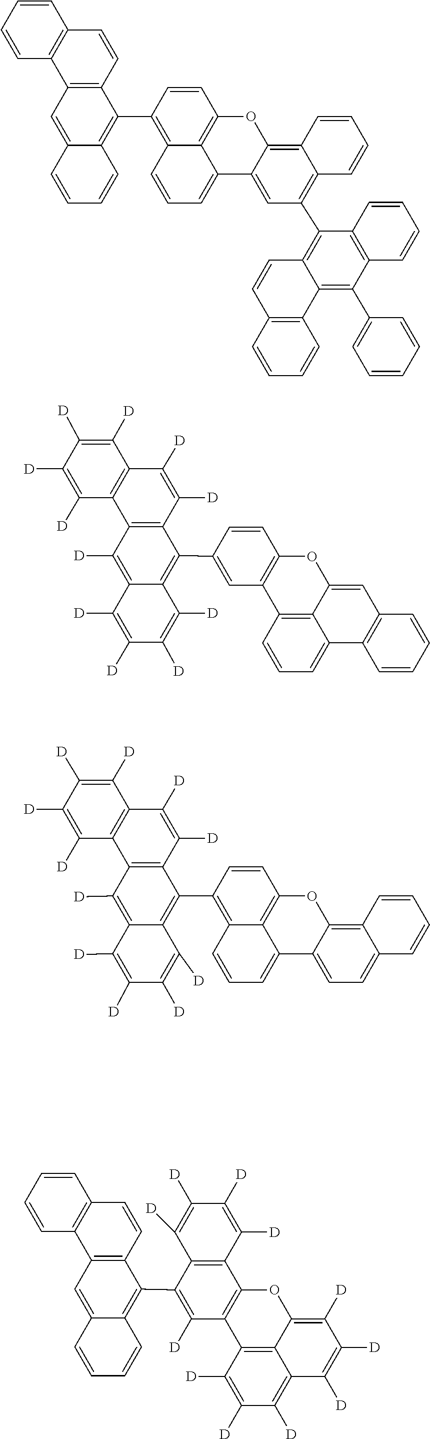 [SMILES: c1ccc(-c2c3ccccc3c(-c3cc4c(c5ccccc35)Oc3ccc(-c5c6ccccc6cc6c5ccc5ccccc56)c5cccc-4c35)c3ccc4ccccc4c23)cc1 ; [2H]c1c([2H])c([2H])c2c([2H])c3c(c([2H])c([2H])c4c([2H])c([2H])c([2H])c([2H])c43)c(-c3ccc4c(c3)-c3cccc5c3c(cc3ccccc35)O4)c2c1[2H] ; [2H]c1c([2H])c([2H])c2c([2H])c3c(c([2H])c([2H])c4c([2H])c([2H])c([2H])c([2H])c43)c(-c3ccc4c5c(cccc35)-c3ccc5ccccc5c3O4)c2c1[2H] ; [2H]c1c([2H])c2c3c(c([2H])c([2H])c([2H])c3c1[2H])-c1c([2H])c(-c3c4ccccc4cc4c3ccc3ccccc34)c3c([2H])c([2H])c([2H])c([2H])c3c1O2]

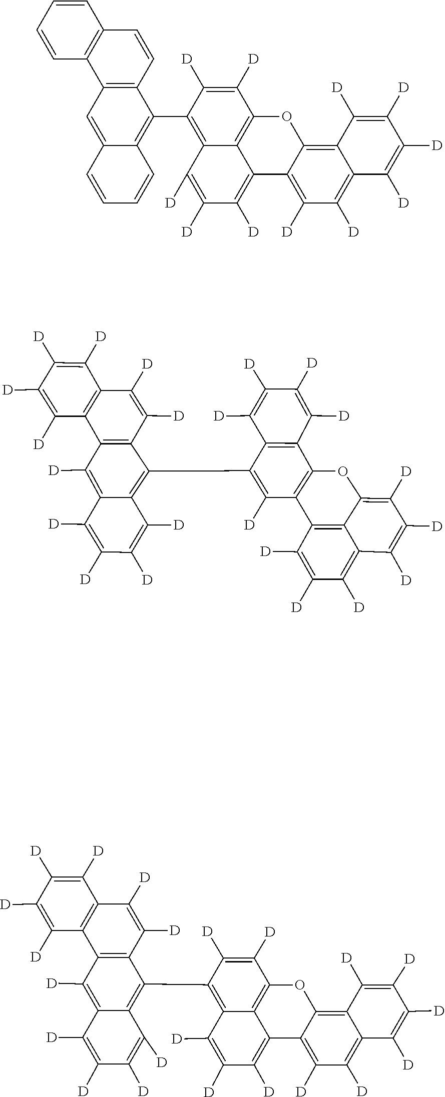

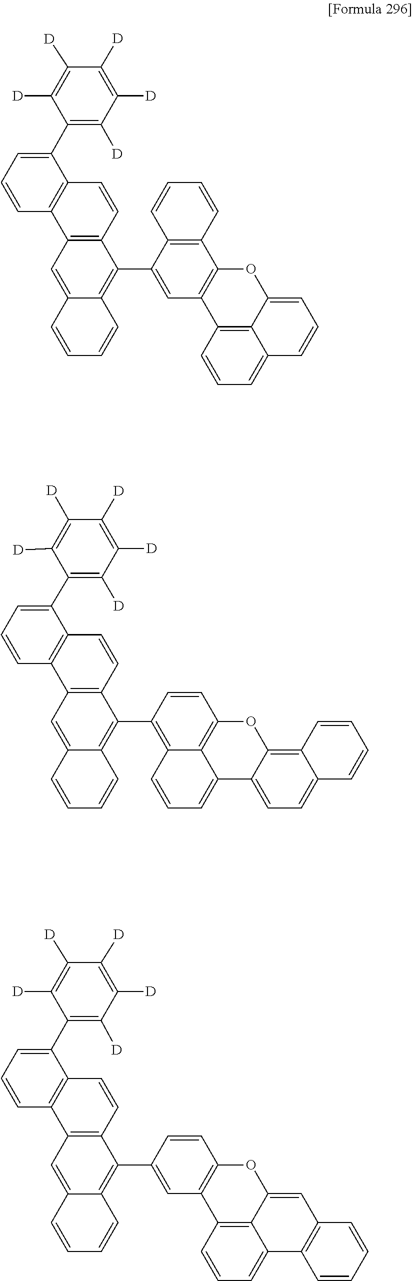 [SMILES: [2H]c1c([2H])c([2H])c(-c2cccc3c2ccc2c(-c4cc5c(c6ccccc46)Oc4cccc6cccc-5c46)c4ccccc4cc23)c([2H])c1[2H] ; [2H]c1c([2H])c([2H])c(-c2cccc3c2ccc2c(-c4ccc5c6c(cccc46)-c4ccc6ccccc6c4O5)c4ccccc4cc23)c([2H])c1[2H] ; [2H]c1c([2H])c([2H])c(-c2cccc3c2ccc2c(-c4ccc5c(c4)-c4cccc6c4c(cc4ccccc46)O5)c4ccccc4cc23)c([2H])c1[2H]]

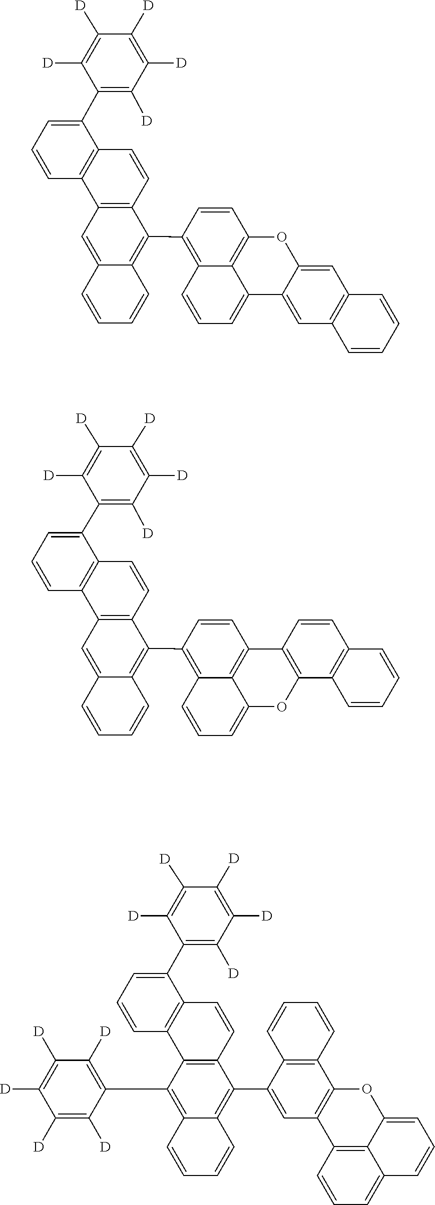 [SMILES: [2H]c1c([2H])c([2H])c(-c2cccc3c2ccc2c(-c4ccc5c6c(cccc46)-c4cc6ccccc6cc4O5)c4ccccc4cc23)c([2H])c1[2H] ; [2H]c1c([2H])c([2H])c(-c2cccc3c2ccc2c(-c4ccc5c6c(cccc46)Oc4c-5ccc5ccccc45)c4ccccc4cc23)c([2H])c1[2H] ; [2H]c1c([2H])c([2H])c(-c2cccc3c2ccc2c(-c4cc5c(c6ccccc46)Oc4cccc6cccc-5c46)c4ccccc4c(-c4c([2H])c([2H])c([2H])c([2H])c4[2H])c23)c([2H])c1[2H]]

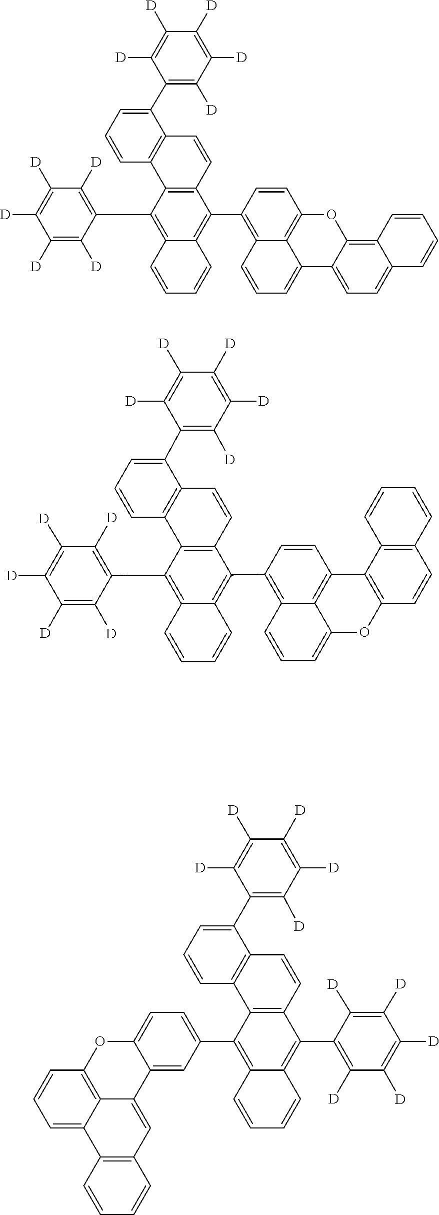 [SMILES: [2H]c1c([2H])c([2H])c(-c2cccc3c2ccc2c(-c4ccc5c6c(cccc46)-c4ccc6ccccc6c4O5)c4ccccc4c(-c4c([2H])c([2H])c([2H])c([2H])c4[2H])c23)c([2H])c1[2H] ; [2H]c1c([2H])c([2H])c(-c2cccc3c2ccc2c(-c4ccc5c6c(cccc46)Oc4ccc6ccccc6c4-5)c4ccccc4c(-c4c([2H])c([2H])c([2H])c([2H])c4[2H])c23)c([2H])c1[2H] ; [2H]c1c([2H])c([2H])c(-c2cccc3c2ccc2c(-c4c([2H])c([2H])c([2H])c([2H])c4[2H])c4ccccc4c(-c4ccc5c(c4)-c4cc6ccccc6c6cccc(c46)O5)c23)c([2H])c1[2H]]

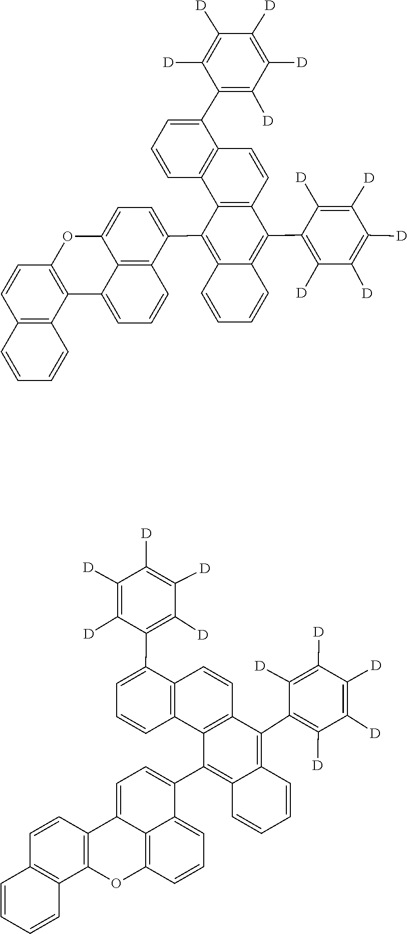 [SMILES: [2H]c1c([2H])c([2H])c(-c2cccc3c2ccc2c(-c4c([2H])c([2H])c([2H])c([2H])c4[2H])c4ccccc4c(-c4ccc5c6c(cccc46)-c4c(ccc6ccccc46)O5)c23)c([2H])c1[2H] ; [2H]c1c([2H])c([2H])c(-c2cccc3c2ccc2c(-c4c([2H])c([2H])c([2H])c([2H])c4[2H])c4ccccc4c(-c4ccc5c6c(cccc46)Oc4c-5ccc5ccccc45)c23)c([2H])c1[2H]]

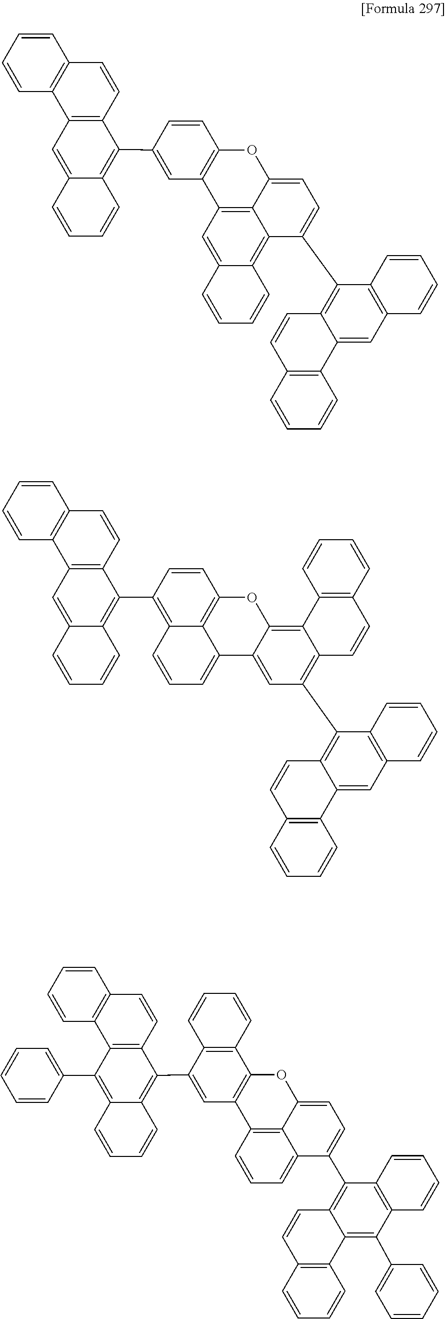 [SMILES: c1ccc2c(-c3ccc4c(c3)-c3cc5ccccc5c5c(-c6c7ccccc7cc7c6ccc6ccccc67)ccc(c35)O4)c3ccc4ccccc4c3cc2c1 ; c1ccc2c(-c3ccc4c5c(cccc35)-c3cc(-c5c6ccccc6cc6c5ccc5ccccc56)c5ccc6ccccc6c5c3O4)c3ccc4ccccc4c3cc2c1 ; c1ccc(-c2c3ccccc3c(-c3cc4c(c5ccccc35)Oc3ccc(-c5c6ccccc6c(-c6ccccc6)c6c5ccc5ccccc56)c5cccc-4c35)c3ccc4ccccc4c23)cc1]

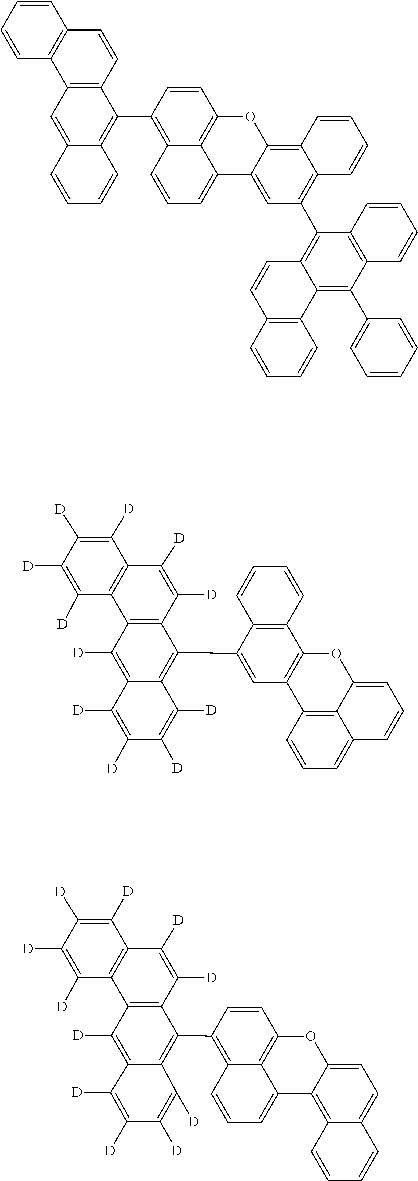 [SMILES: c1ccc(-c2c3ccccc3c(-c3cc4c(c5ccccc35)Oc3ccc(-c5c6ccccc6cc6c5ccc5ccccc56)c5cccc-4c35)c3ccc4ccccc4c23)cc1 ; [2H]c1c([2H])c([2H])c2c([2H])c3c(c([2H])c([2H])c4c([2H])c([2H])c([2H])c([2H])c43)c(-c3cc4c(c5ccccc35)Oc3cccc5cccc-4c35)c2c1[2H] ; [2H]c1c([2H])c([2H])c2c([2H])c3c(c([2H])c([2H])c4c([2H])c([2H])c([2H])c([2H])c43)c(-c3ccc4c5c(cccc35)-c3c(ccc5ccccc35)O4)c2c1[2H]]

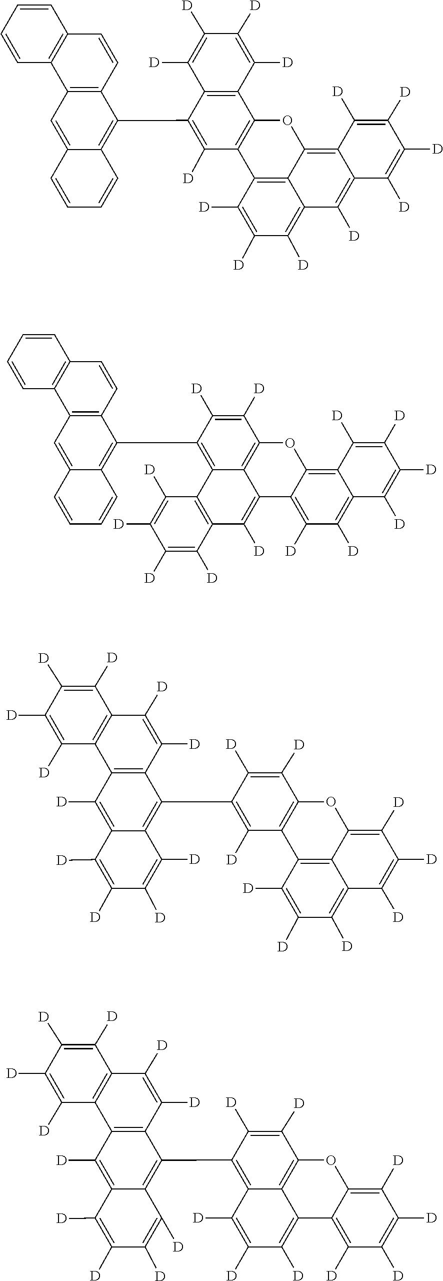

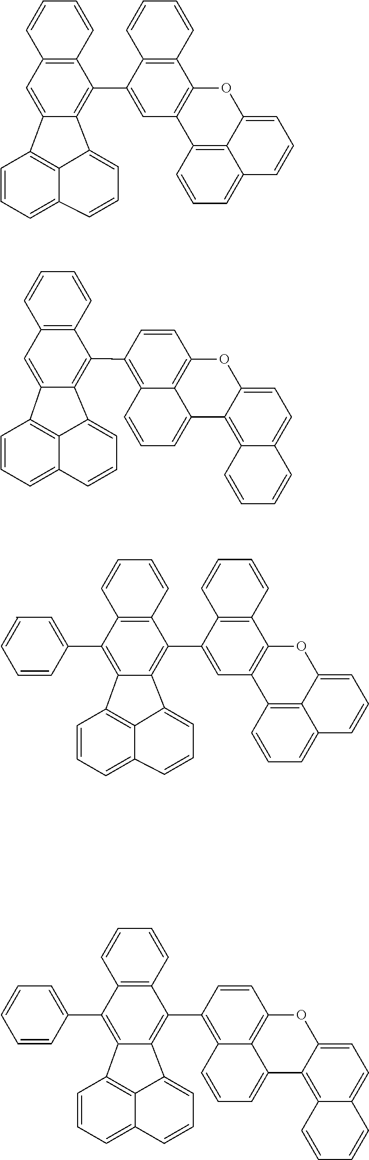 [SMILES: c1ccc2c(-c3cc4c(c5ccccc35)Oc3cccc5cccc-4c35)c3c(cc2c1)-c1cccc2cccc-3c12 ; c1ccc2c3c(ccc2c1)Oc1ccc(-c2c4c(cc5ccccc25)-c2cccc5cccc-4c25)c2cccc-3c12 ; Cc1cccc(-c2c3c(c(-c4cc5c(c6ccccc46)Oc4cccc6cccc-5c46)c4ccccc24)-c2cccc4cccc-3c24)c1 ; c1ccc(-c2c3c(c(-c4ccc5c6c(cccc46)-c4c(ccc6ccccc46)O5)c4ccccc24)-c2cccc4cccc-3c24)cc1]

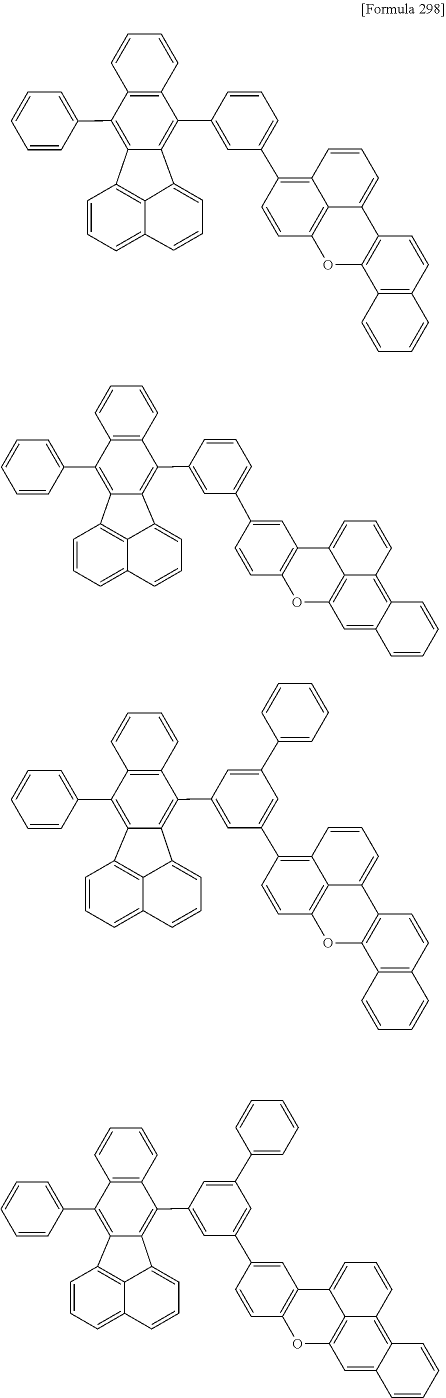 [SMILES: c1ccc(-c2c3c(c(-c4cccc(-c5ccc6c7c(cccc57)-c5ccc7ccccc7c5O6)c4)c4ccccc24)-c2cccc4cccc-3c24)cc1 ; c1ccc(-c2c3c(c(-c4cccc(-c5ccc6c(c5)-c5cccc7c5c(cc5ccccc57)O6)c4)c4ccccc24)-c2cccc4cccc-3c24)cc1 ; c1ccc(-c2cc(-c3c4c(c(-c5ccccc5)c5ccccc35)-c3cccc5cccc-4c35)cc(-c3ccc4c5c(cccc35)-c3ccc5ccccc5c3O4)c2)cc1 ; c1ccc(-c2cc(-c3ccc4c(c3)-c3cccc5c3c(cc3ccccc35)O4)cc(-c3c4c(c(-c5ccccc5)c5ccccc35)-c3cccc5cccc-4c35)c2)cc1]

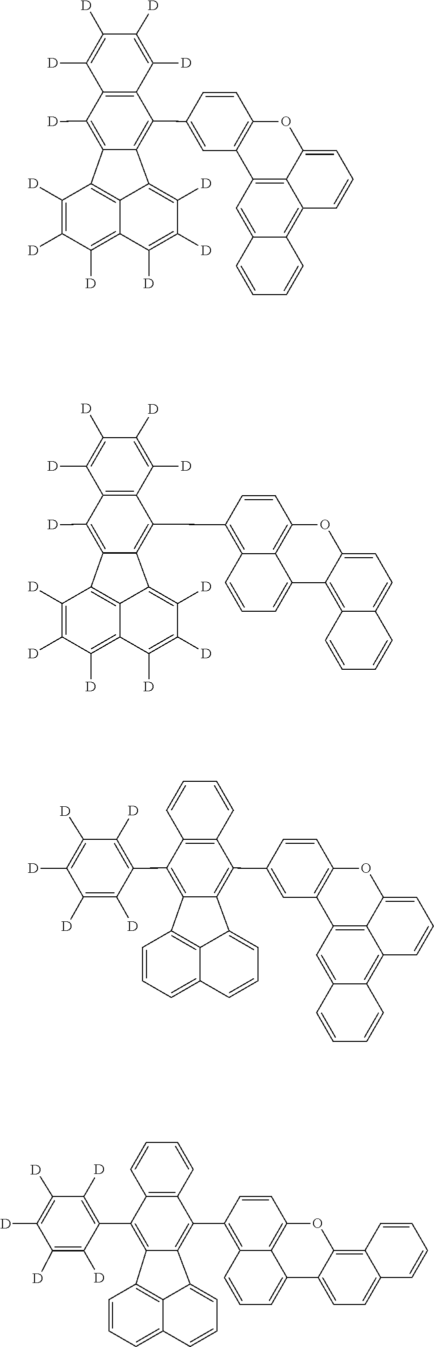 [SMILES: [2H]c1c([2H])c([2H])c2c(-c3ccc4c(c3)-c3cc5ccccc5c5cccc(c35)O4)c3c(c([2H])c2c1[2H])-c1c([2H])c([2H])c([2H])c2c([2H])c([2H])c([2H])c-3c12 ; [2H]c1c([2H])c([2H])c2c(-c3ccc4c5c(cccc35)-c3c(ccc5ccccc35)O4)c3c(c([2H])c2c1[2H])-c1c([2H])c([2H])c([2H])c2c([2H])c([2H])c([2H])c-3c12 ; [2H]c1c([2H])c([2H])c(-c2c3c(c(-c4ccc5c(c4)-c4cc6ccccc6c6cccc(c46)O5)c4ccccc24)-c2cccc4cccc-3c24)c([2H])c1[2H] ; [2H]c1c([2H])c([2H])c(-c2c3c(c(-c4ccc5c6c(cccc46)-c4ccc6ccccc6c4O5)c4ccccc24)-c2cccc4cccc-3c24)c([2H])c1[2H]]

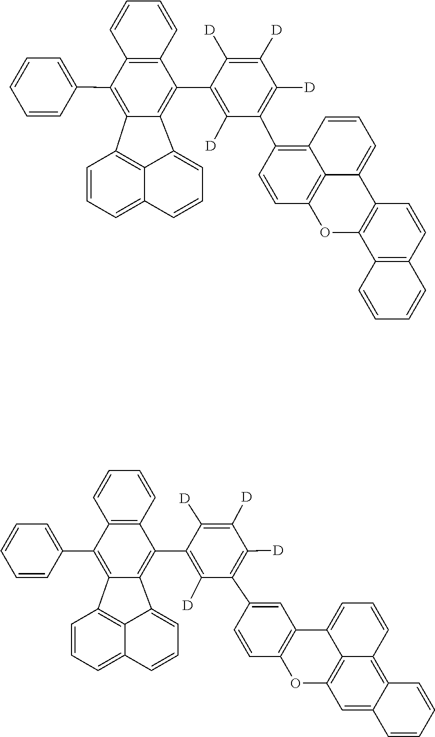 [SMILES: [2H]c1c([2H])c(-c2c3c(c(-c4ccccc4)c4ccccc24)-c2cccc4cccc-3c24)c([2H])c(-c2ccc3c4c(cccc24)-c2ccc4ccccc4c2O3)c1[2H] ; [2H]c1c([2H])c(-c2ccc3c(c2)-c2cccc4c2c(cc2ccccc24)O3)c([2H])c(-c2c3c(c(-c4ccccc4)c4ccccc24)-c2cccc4cccc-3c24)c1[2H]]

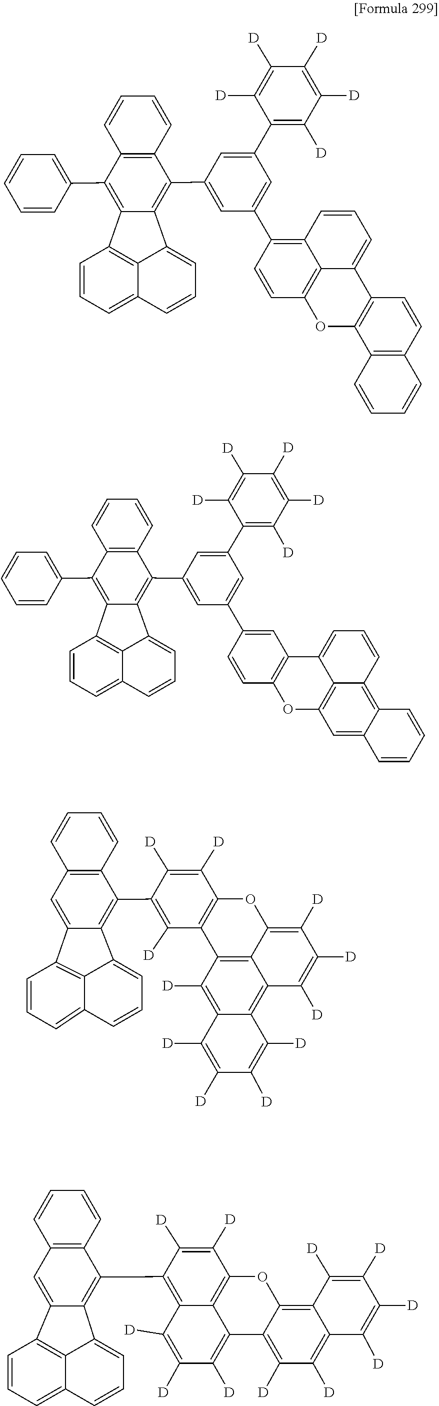

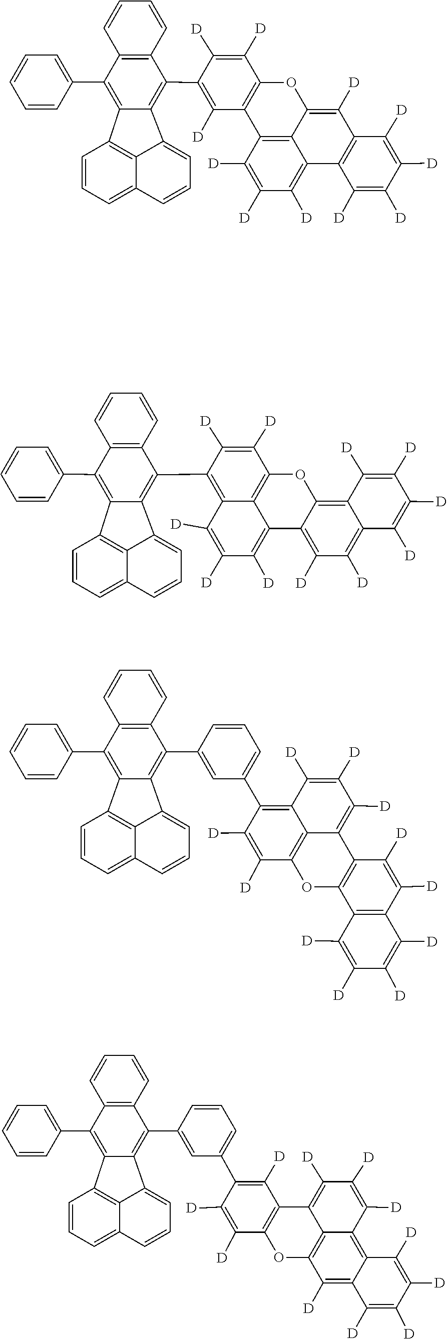

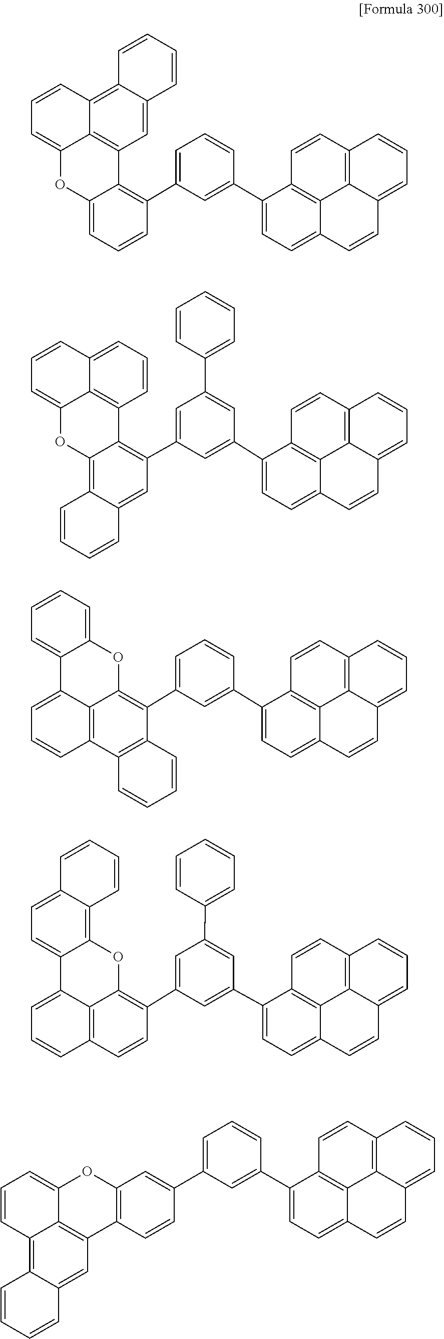

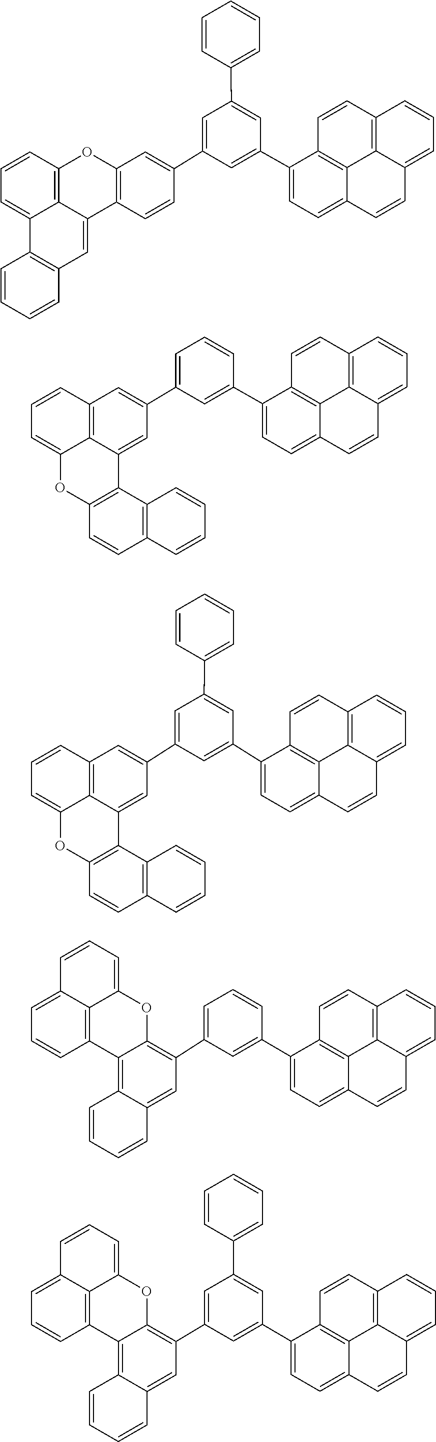

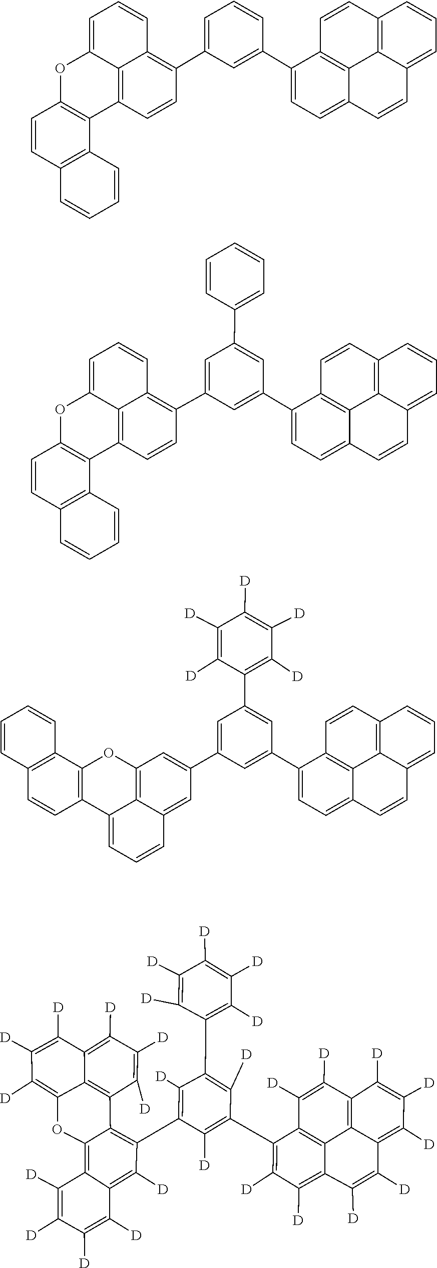

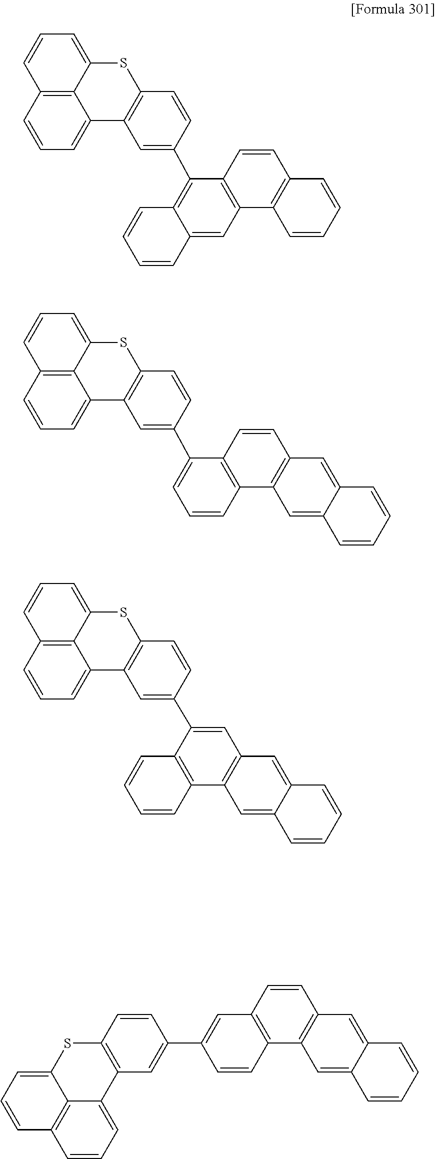 [SMILES: c1ccc2c(-c3ccc4c(c3)-c3cccc5cccc(c35)S4)c3ccc4ccccc4c3cc2c1 ; c1ccc2cc3c(ccc4c(-c5ccc6c(c5)-c5cccc7cccc(c57)S6)cccc43)cc2c1 ; c1ccc2cc3c(cc(-c4ccc5c(c4)-c4cccc6cccc(c46)S5)c4ccccc43)cc2c1 ; c1ccc2cc3c(ccc4cc(-c5ccc6c(c5)-c5cccc7cccc(c57)S6)ccc43)cc2c1]

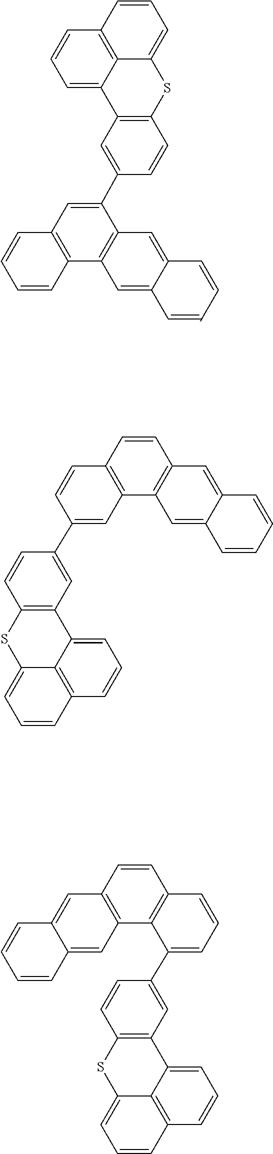 [SMILES: Cc1ccc2cc3c(-c4ccc5c(c4)-c4cccc6cccc(c46)S5)cc4ccccc4c3cc2c1 ; c1ccc2cc3c(ccc4ccc(-c5ccc6c(c5)-c5cccc7cccc(c57)S6)cc43)cc2c1 ; c1ccc2cc3c(ccc4cccc(-c5ccc6c(c5)-c5cccc7cccc(c57)S6)c43)cc2c1]

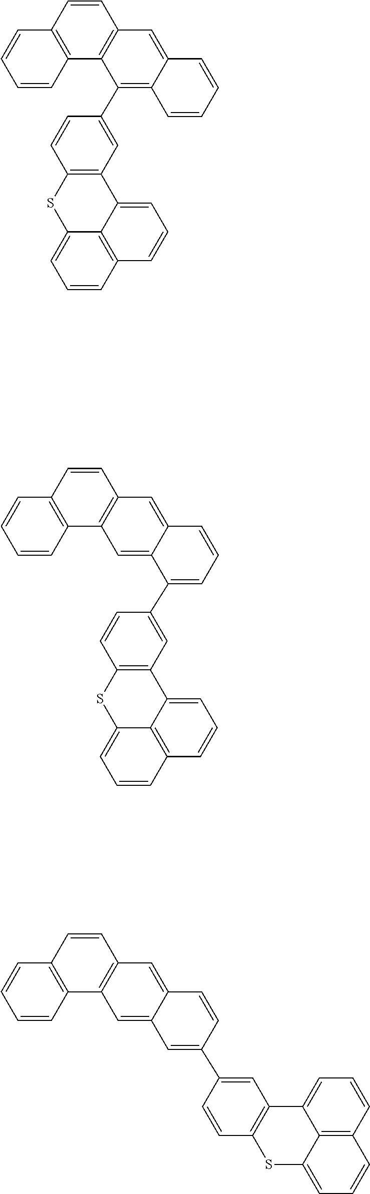 [SMILES: c1ccc2c(-c3ccc4c(c3)-c3cccc5cccc(c35)S4)c3c(ccc4ccccc43)cc2c1 ; c1cc(-c2ccc3c(c2)-c2cccc4cccc(c24)S3)c2cc3c(ccc4ccccc43)cc2c1 ; c1cc2c3c(cccc3c1)-c1cc(-c3ccc4cc5ccc6ccccc6c5cc4c3)ccc1S2]

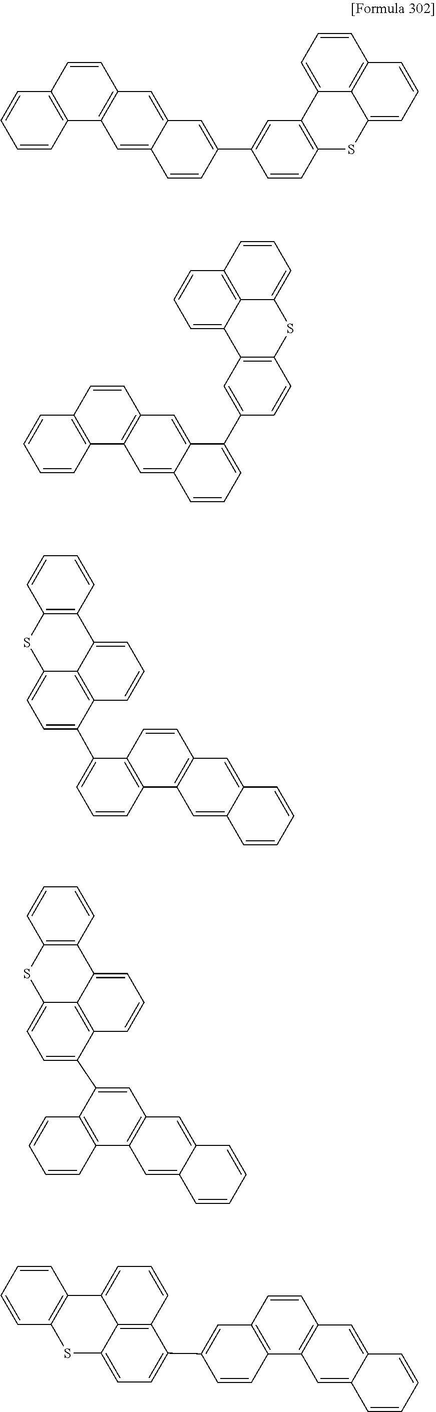 [SMILES: c1cc2c3c(cccc3c1)-c1cc(-c3ccc4cc5c(ccc6ccccc65)cc4c3)ccc1S2 ; c1cc(-c2ccc3c(c2)-c2cccc4cccc(c24)S3)c2cc3ccc4ccccc4c3cc2c1 ; c1ccc2c(c1)Sc1ccc(-c3cccc4c3ccc3cc5ccccc5cc34)c3cccc-2c13 ; c1ccc2c(c1)Sc1ccc(-c3cc4cc5ccccc5cc4c4ccccc34)c3cccc-2c13 ; c1ccc2c(c1)Sc1ccc(-c3ccc4c(ccc5cc6ccccc6cc54)c3)c3cccc-2c13]

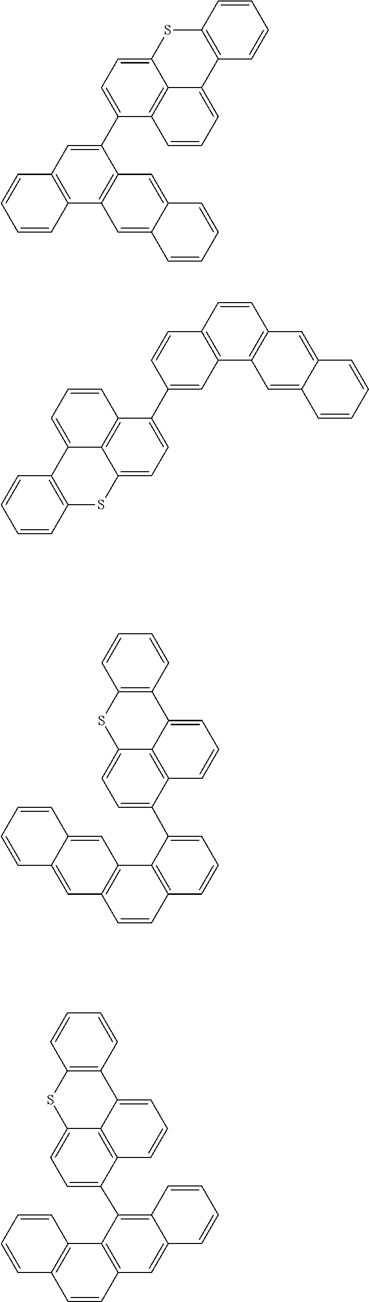

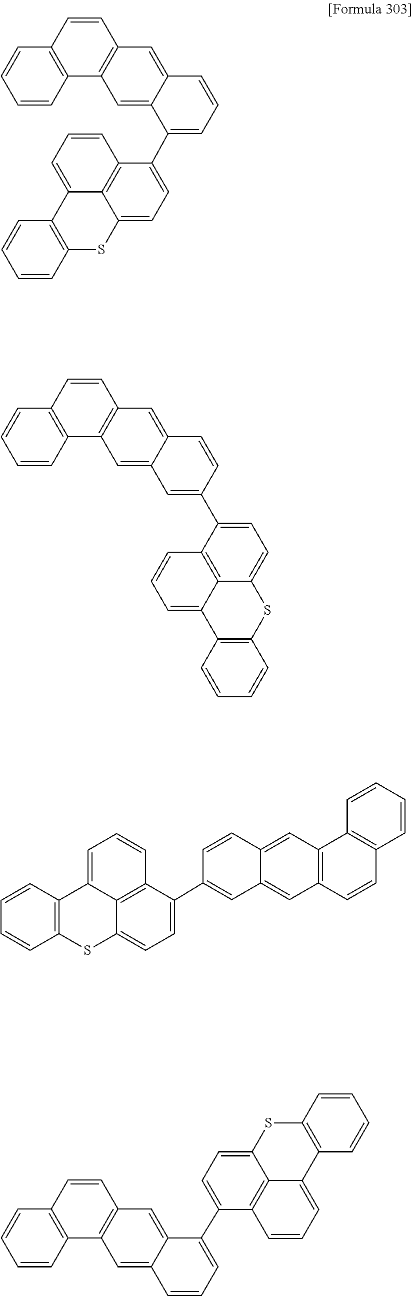 [SMILES: c1ccc2c(c1)Sc1ccc(-c3cccc4cc5ccc6ccccc6c5cc34)c3cccc-2c13 ; c1ccc2c(c1)Sc1ccc(-c3ccc4cc5ccc6ccccc6c5cc4c3)c3cccc-2c13 ; c1ccc2c(c1)Sc1ccc(-c3ccc4cc5c(ccc6ccccc65)cc4c3)c3cccc-2c13 ; c1ccc2c(c1)Sc1ccc(-c3cccc4cc5c(ccc6ccccc65)cc34)c3cccc-2c13]

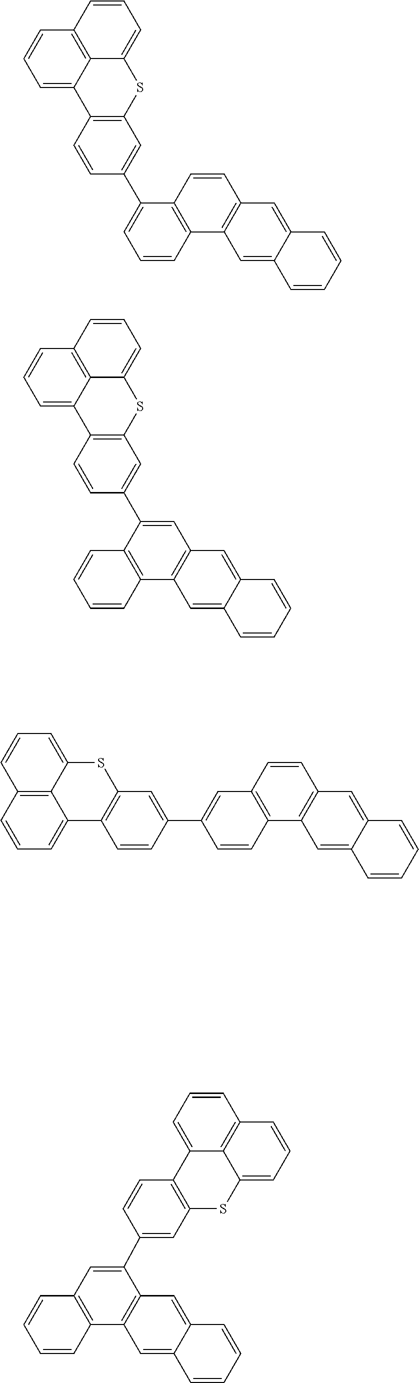 [SMILES: c1ccc2cc3c(ccc4c(-c5ccc6c(c5)Sc5cccc7cccc-6c57)cccc43)cc2c1 ; c1ccc2cc3c(cc(-c4ccc5c(c4)Sc4cccc6cccc-5c46)c4ccccc43)cc2c1 ; c1ccc2cc3c(ccc4cc(-c5ccc6c(c5)Sc5cccc7cccc-6c57)ccc43)cc2c1 ; c1ccc2cc3c(cc2c1)c(-c1ccc2c(c1)Sc1cccc4cccc-2c14)cc1ccccc13]

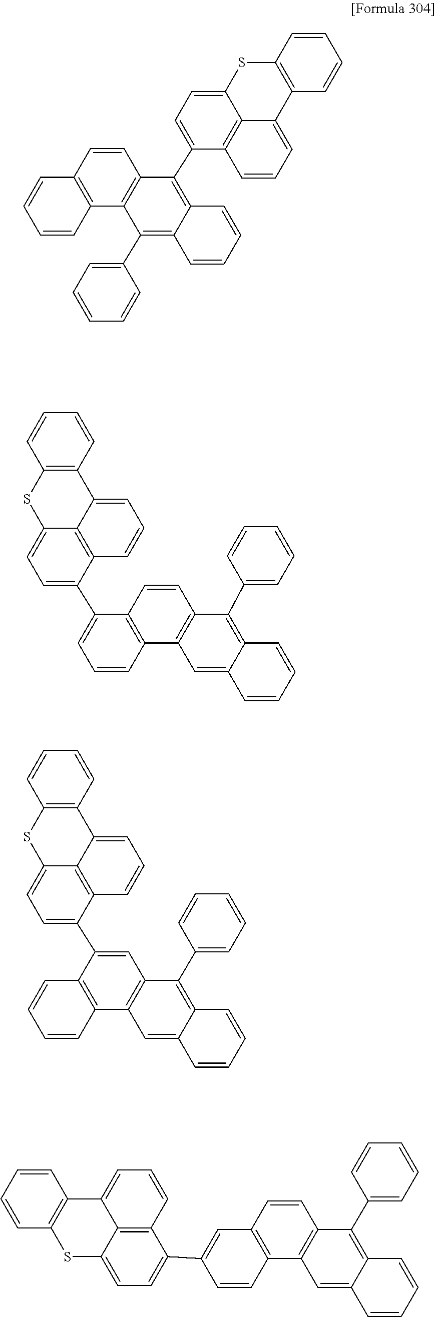 [SMILES: c1ccc(-c2c3ccccc3c(-c3ccc4c5c(cccc35)-c3ccccc3S4)c3ccc4ccccc4c23)cc1 ; c1ccc(-c2c3ccccc3cc3c2ccc2c(-c4ccc5c6c(cccc46)-c4ccccc4S5)cccc23)cc1 ; c1ccc(-c2c3ccccc3cc3c2cc(-c2ccc4c5c(cccc25)-c2ccccc2S4)c2ccccc23)cc1 ; c1ccc(-c2c3ccccc3cc3c2ccc2cc(-c4ccc5c6c(cccc46)-c4ccccc4S5)ccc23)cc1]

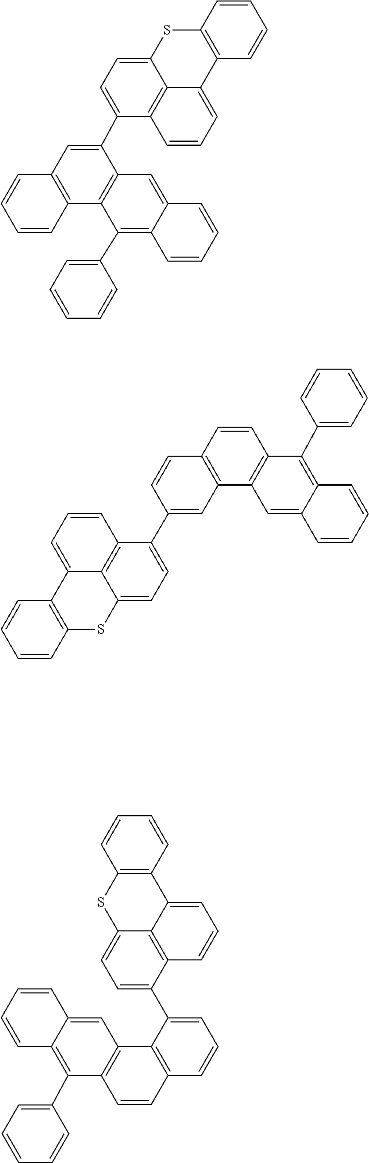 [SMILES: c1ccc(-c2c3ccccc3cc3c(-c4ccc5c6c(cccc46)-c4ccccc4S5)cc4ccccc4c23)cc1 ; c1ccc(-c2c3ccccc3cc3c2ccc2ccc(-c4ccc5c6c(cccc46)-c4ccccc4S5)cc23)cc1 ; c1ccc(-c2c3ccccc3cc3c2ccc2cccc(-c4ccc5c6c(cccc46)-c4ccccc4S5)c23)cc1]

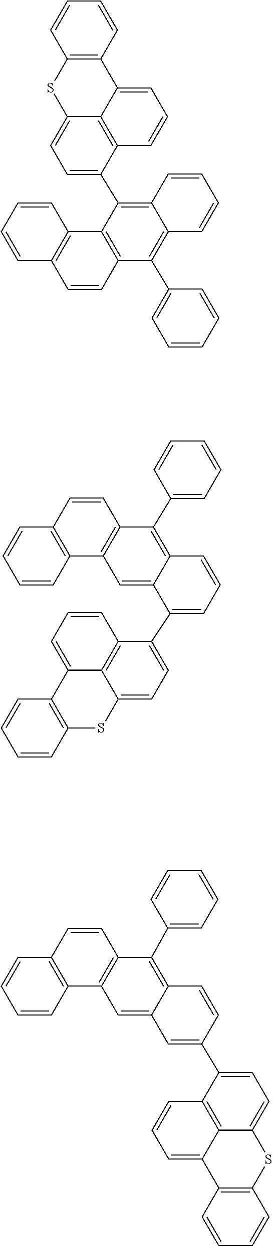 [SMILES: c1ccc(-c2c3ccccc3c(-c3ccc4c5c(cccc35)-c3ccccc3S4)c3c2ccc2ccccc23)cc1 ; c1ccc(-c2c3cccc(-c4ccc5c6c(cccc46)-c4ccccc4S5)c3cc3c2ccc2ccccc23)cc1 ; c1ccc(-c2c3ccc(-c4ccc5c6c(cccc46)-c4ccccc4S5)cc3cc3c2ccc2ccccc23)cc1]

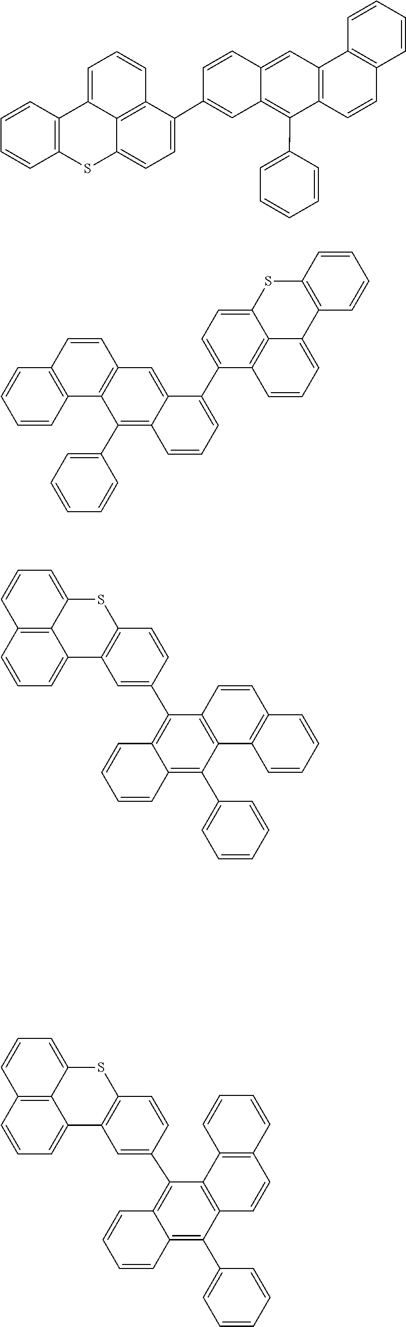

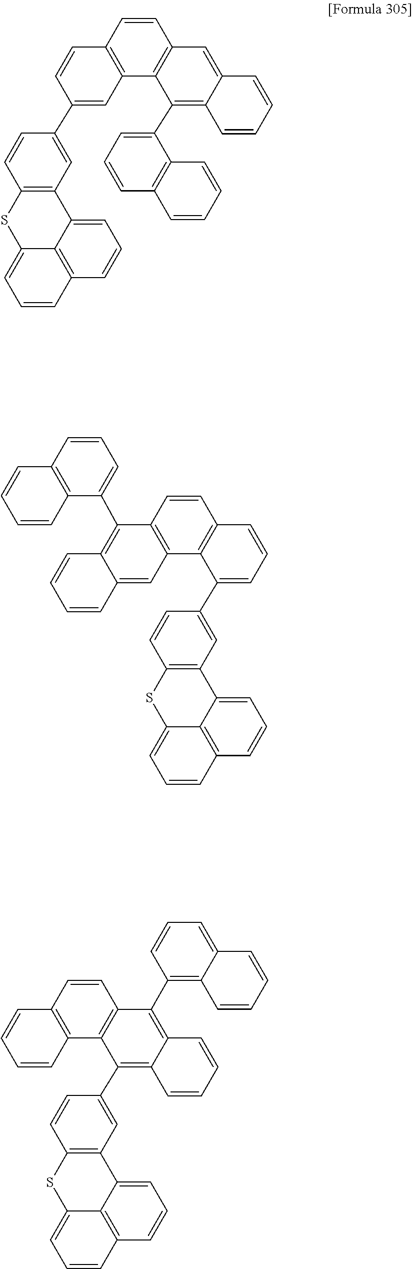 [SMILES: c1ccc2c(-c3c4ccccc4cc4ccc5ccc(-c6ccc7c(c6)-c6cccc8cccc(c68)S7)cc5c34)cccc2c1 ; c1ccc2c(-c3c4ccccc4cc4c3ccc3cccc(-c5ccc6c(c5)-c5cccc7cccc(c57)S6)c34)cccc2c1 ; c1ccc2c(-c3c4ccccc4c(-c4ccc5c(c4)-c4cccc6cccc(c46)S5)c4c3ccc3ccccc34)cccc2c1]

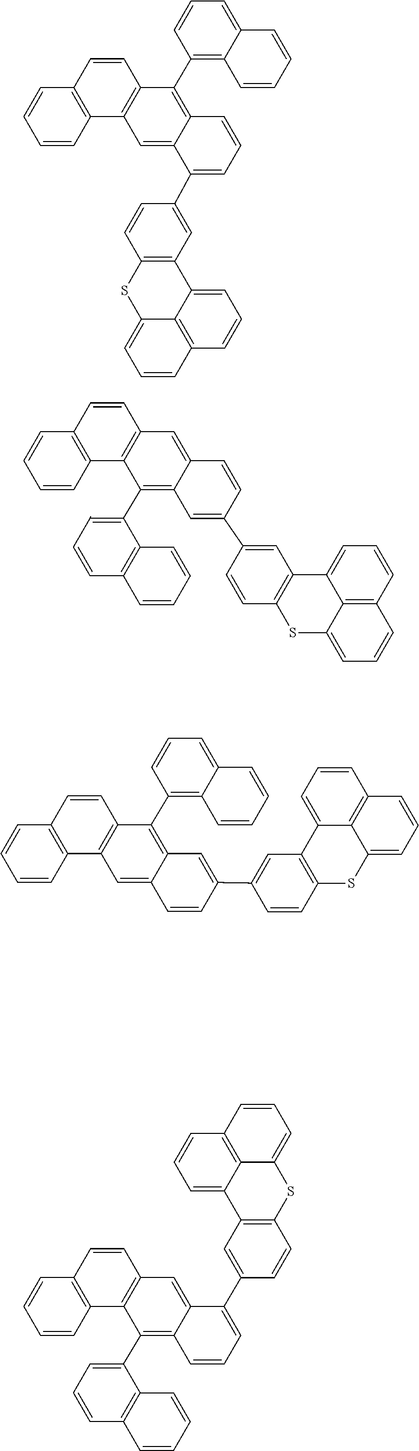

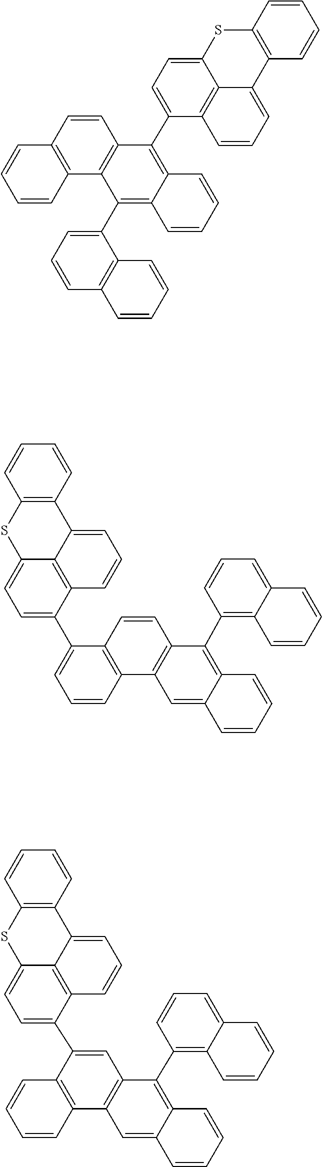 [SMILES: c1ccc2c(c1)Sc1ccc(-c3c4ccccc4c(-c4cccc5ccccc45)c4c3ccc3ccccc34)c3cccc-2c13 ; c1ccc2c(c1)Sc1ccc(-c3cccc4c3ccc3c(-c5cccc6ccccc56)c5ccccc5cc34)c3cccc-2c13 ; c1ccc2c(c1)Sc1ccc(-c3cc4c(-c5cccc6ccccc56)c5ccccc5cc4c4ccccc34)c3cccc-2c13]

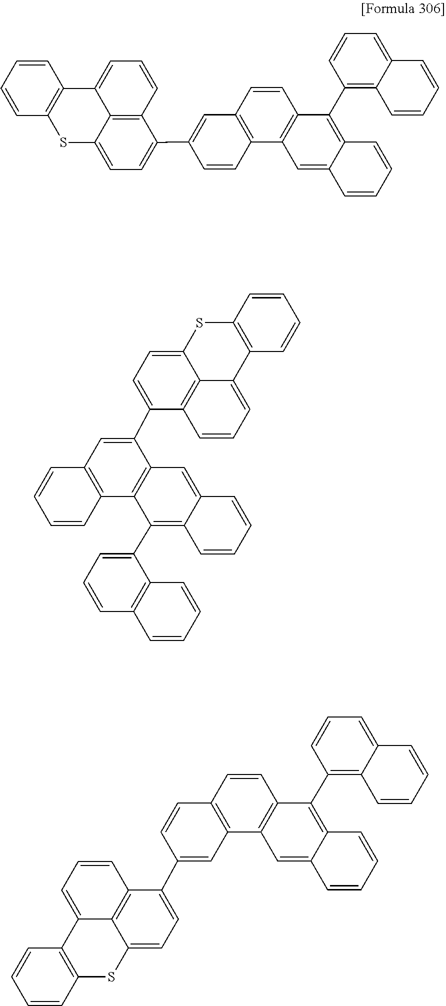 [SMILES: c1ccc2c(c1)Sc1ccc(-c3ccc4c(ccc5c(-c6cccc7ccccc67)c6ccccc6cc54)c3)c3cccc-2c13 ; c1ccc2c(c1)Sc1ccc(-c3cc4ccccc4c4c(-c5cccc6ccccc56)c5ccccc5cc34)c3cccc-2c13 ; c1ccc2c(c1)Sc1ccc(-c3ccc4ccc5c(-c6cccc7ccccc67)c6ccccc6cc5c4c3)c3cccc-2c13]

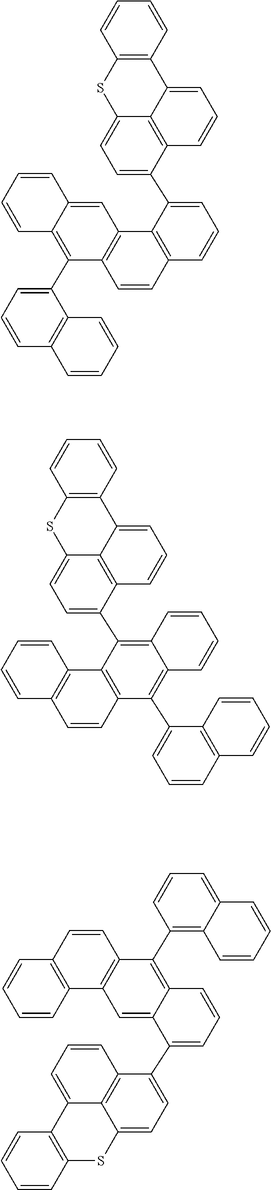 [SMILES: c1ccc2c(c1)Sc1ccc(-c3cccc4ccc5c(-c6cccc7ccccc67)c6ccccc6cc5c34)c3cccc-2c13 ; c1ccc2c(c1)Sc1ccc(-c3c4ccccc4c(-c4cccc5ccccc45)c4ccc5ccccc5c34)c3cccc-2c13 ; c1ccc2c(c1)Sc1ccc(-c3cccc4c(-c5cccc6ccccc56)c5ccc6ccccc6c5cc34)c3cccc-2c13]

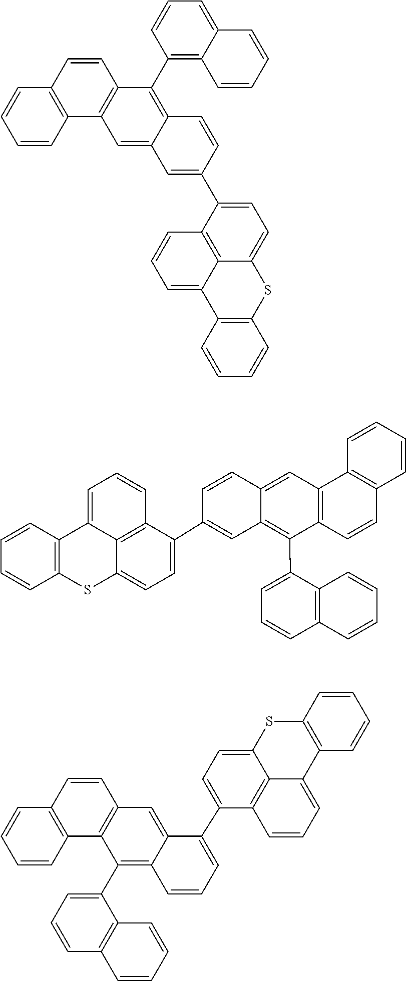 [SMILES: c1ccc2c(c1)Sc1ccc(-c3ccc4c(-c5cccc6ccccc56)c5ccc6ccccc6c5cc4c3)c3cccc-2c13 ; c1ccc2c(c1)Sc1ccc(-c3ccc4cc5c(ccc6ccccc65)c(-c5cccc6ccccc56)c4c3)c3cccc-2c13 ; c1ccc2c(c1)Sc1ccc(-c3cccc4c(-c5cccc6ccccc56)c5c(ccc6ccccc65)cc34)c3cccc-2c13]

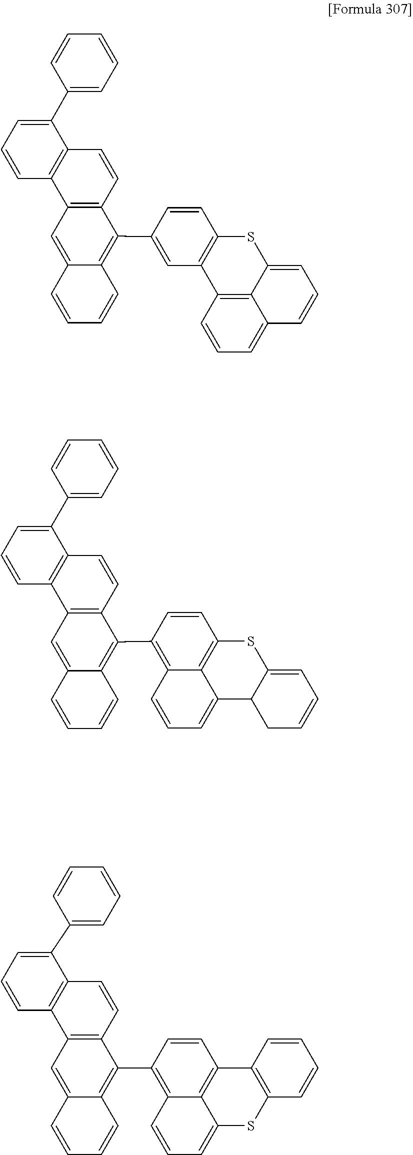 [SMILES: c1ccc(-c2cccc3c2ccc2c(-c4ccc5c(c4)-c4cccc6cccc(c46)S5)c4ccccc4cc23)cc1 ; C1=CCC2C(=C1)Sc1ccc(-c3c4ccccc4cc4c3ccc3c(-c5ccccc5)cccc34)c3cccc2c13 ; c1ccc(-c2cccc3c2ccc2c(-c4ccc5c6c(cccc46)Sc4ccccc4-5)c4ccccc4cc23)cc1]

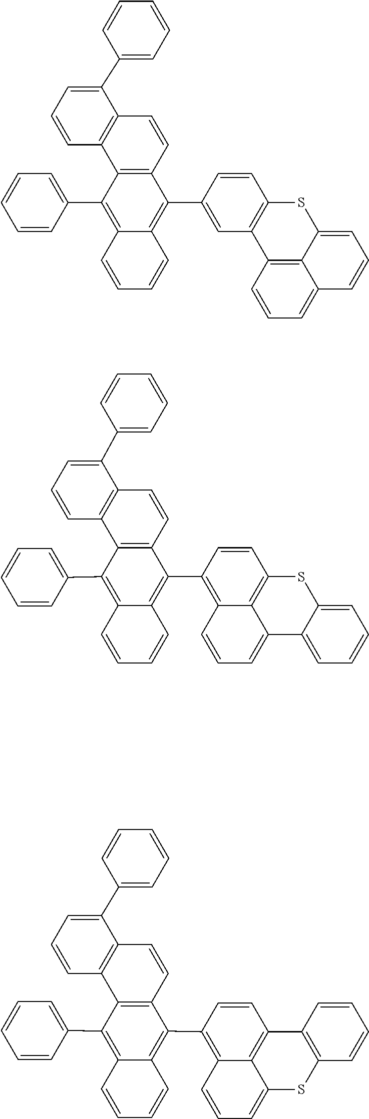 [SMILES: c1ccc(-c2cccc3c2ccc2c(-c4ccc5c(c4)-c4cccc6cccc(c46)S5)c4ccccc4c(-c4ccccc4)c23)cc1 ; c1ccc(-c2cccc3c2ccc2c(-c4ccc5c6c(cccc46)-c4ccccc4S5)c4ccccc4c(-c4ccccc4)c23)cc1 ; c1ccc(-c2cccc3c2ccc2c(-c4ccc5c6c(cccc46)Sc4ccccc4-5)c4ccccc4c(-c4ccccc4)c23)cc1]

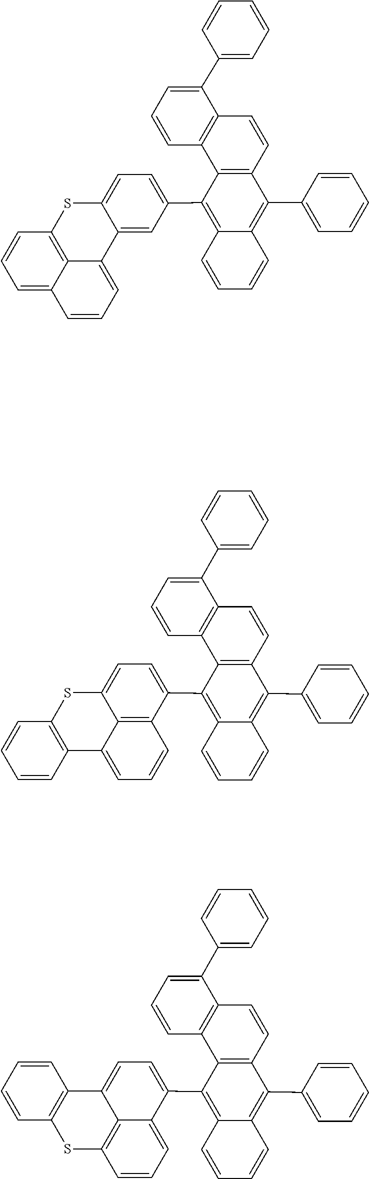 [SMILES: c1ccc(-c2cccc3c2ccc2c(-c4ccccc4)c4ccccc4c(-c4ccc5c(c4)-c4cccc6cccc(c46)S5)c23)cc1 ; c1ccc(-c2cccc3c2ccc2c(-c4ccccc4)c4ccccc4c(-c4ccc5c6c(cccc46)-c4ccccc4S5)c23)cc1 ; c1ccc(-c2cccc3c2ccc2c(-c4ccccc4)c4ccccc4c(-c4ccc5c6c(cccc46)Sc4ccccc4-5)c23)cc1]

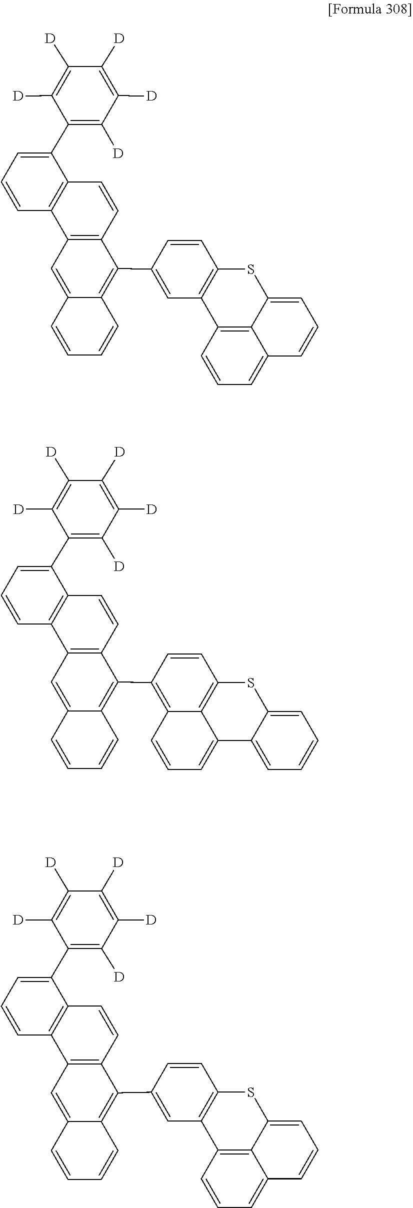 [SMILES: [2H]c1c([2H])c([2H])c(-c2cccc3c2ccc2c(-c4ccc5c(c4)-c4cccc6cccc(c46)S5)c4ccccc4cc23)c([2H])c1[2H] ; [2H]c1c([2H])c([2H])c(-c2cccc3c2ccc2c(-c4ccc5c6c(cccc46)-c4ccccc4S5)c4ccccc4cc23)c([2H])c1[2H] ; [2H]c1c([2H])c([2H])c(-c2cccc3c2ccc2c(-c4ccc5c(c4)-c4cccc6cccc(c46)S5)c4ccccc4cc23)c([2H])c1[2H]]

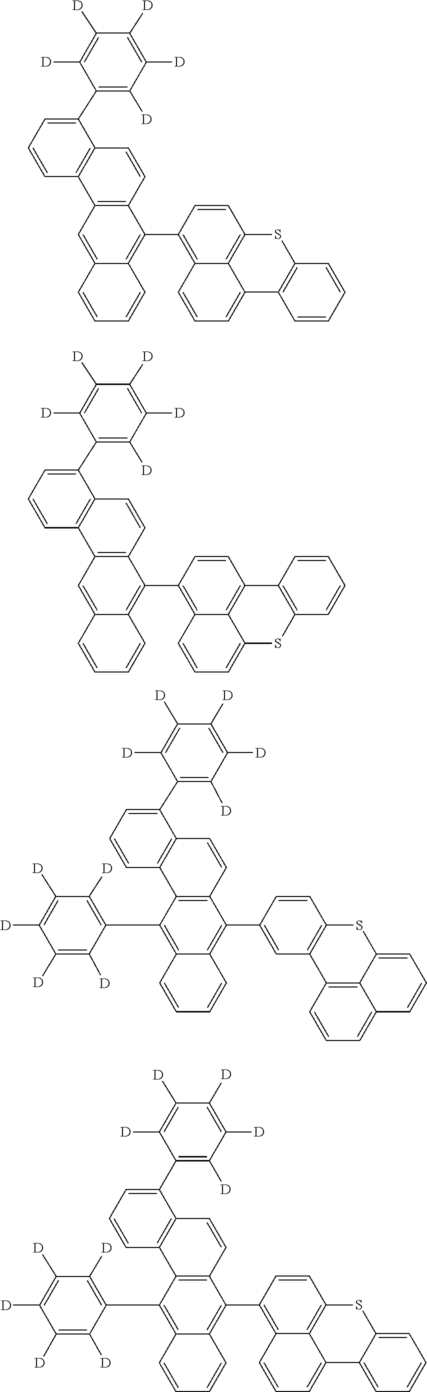

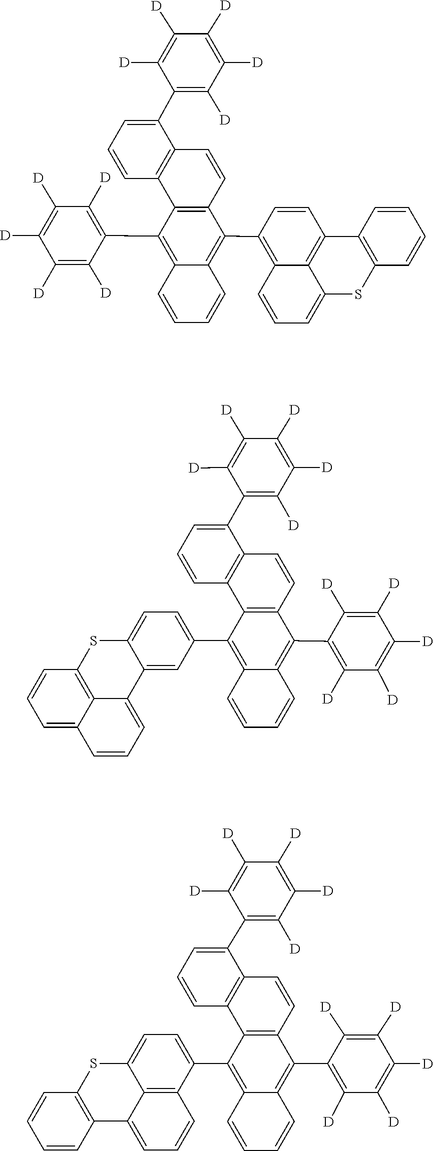 [SMILES: [2H]c1c([2H])c([2H])c(-c2cccc3c2ccc2c(-c4ccc5c6c(cccc46)Sc4ccccc4-5)c4ccccc4c(-c4c([2H])c([2H])c([2H])c([2H])c4[2H])c23)c([2H])c1[2H] ; [2H]c1c([2H])c([2H])c(-c2cccc3c2ccc2c(-c4c([2H])c([2H])c([2H])c([2H])c4[2H])c4ccccc4c(-c4ccc5c(c4)-c4cccc6cccc(c46)S5)c23)c([2H])c1[2H] ; [2H]c1c([2H])c([2H])c(-c2cccc3c2ccc2c(-c4c([2H])c([2H])c([2H])c([2H])c4[2H])c4ccccc4c(-c4ccc5c6c(cccc46)-c4ccccc4S5)c23)c([2H])c1[2H]]

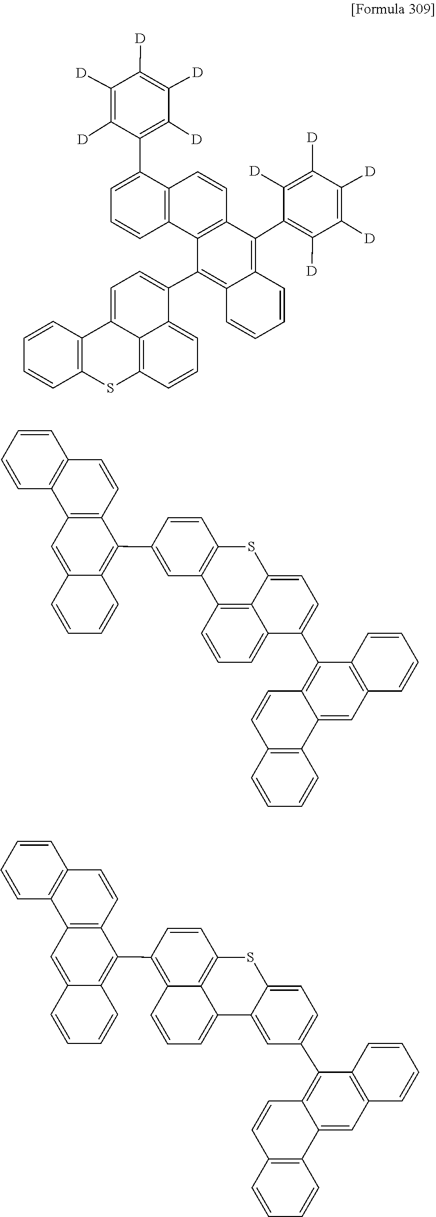

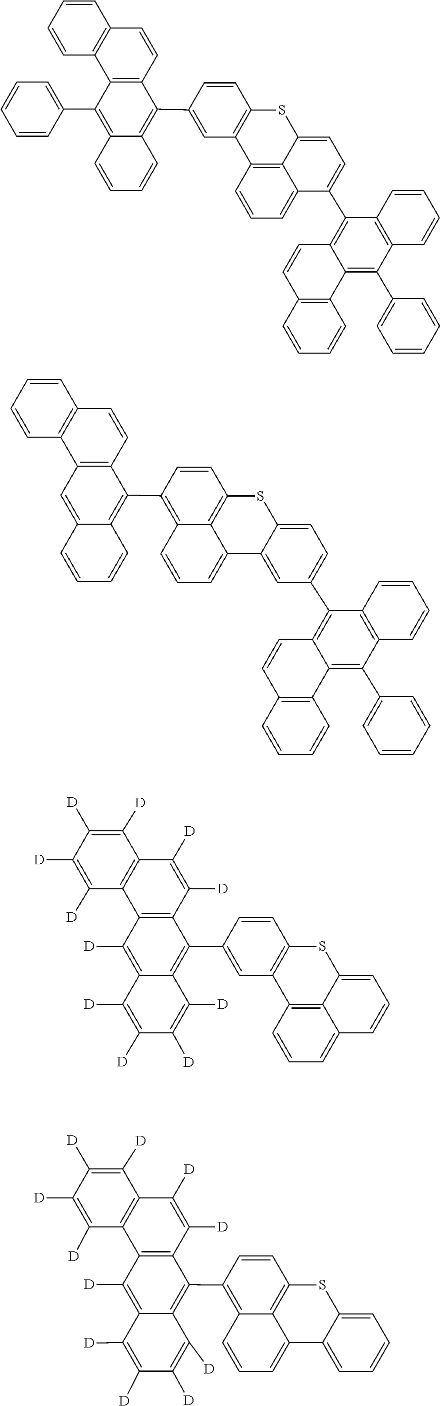 [SMILES: c1ccc(-c2c3ccccc3c(-c3ccc4c(c3)-c3cccc5c(-c6c7ccccc7c(-c7ccccc7)c7c6ccc6ccccc67)ccc(c35)S4)c3ccc4ccccc4c23)cc1 ; c1ccc(-c2c3ccccc3c(-c3ccc4c(c3)-c3cccc5c(-c6c7ccccc7cc7c6ccc6ccccc67)ccc(c35)S4)c3ccc4ccccc4c23)cc1 ; [2H]c1c([2H])c([2H])c2c([2H])c3c(c([2H])c([2H])c4c([2H])c([2H])c([2H])c([2H])c43)c(-c3ccc4c(c3)-c3cccc5cccc(c35)S4)c2c1[2H] ; [2H]c1c([2H])c([2H])c2c([2H])c3c(c([2H])c([2H])c4c([2H])c([2H])c([2H])c([2H])c43)c(-c3ccc4c5c(cccc35)-c3ccccc3S4)c2c1[2H]]

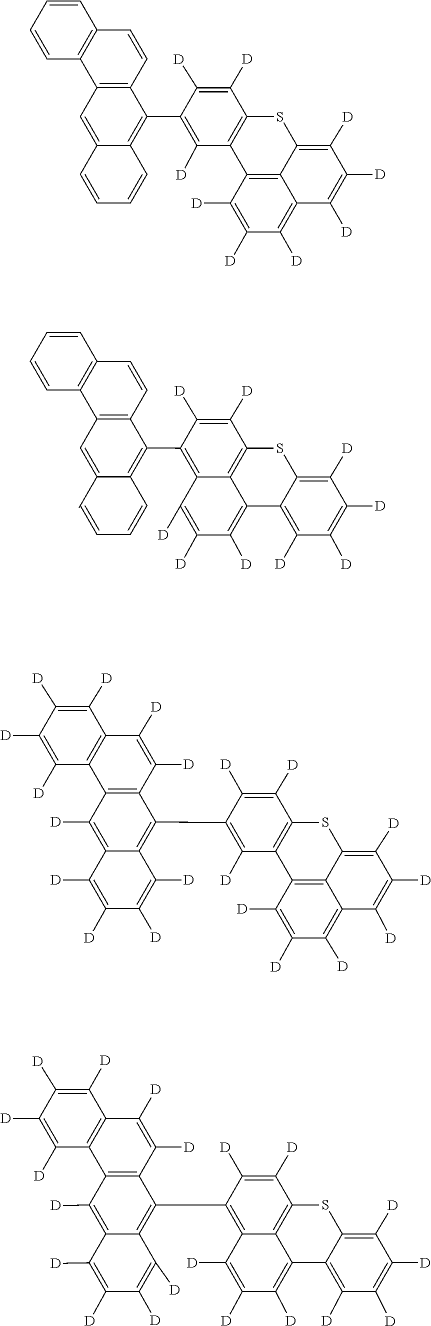

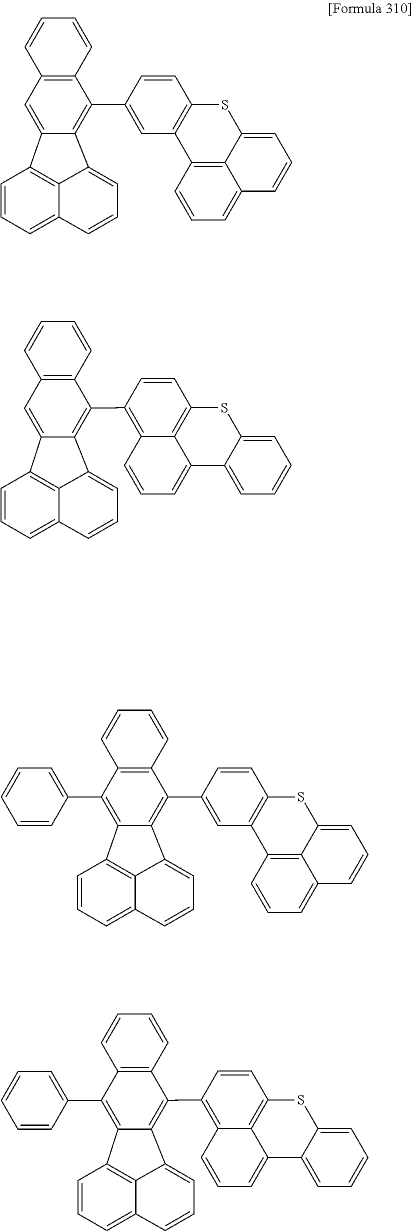 [SMILES: c1ccc2c(-c3ccc4c(c3)-c3cccc5cccc(c35)S4)c3c(cc2c1)-c1cccc2cccc-3c12 ; c1ccc2c(c1)Sc1ccc(-c3c4c(cc5ccccc35)-c3cccc5cccc-4c35)c3cccc-2c13 ; c1ccc(-c2c3c(c(-c4ccc5c(c4)-c4cccc6cccc(c46)S5)c4ccccc24)-c2cccc4cccc-3c24)cc1 ; c1ccc(-c2c3c(c(-c4ccc5c6c(cccc46)-c4ccccc4S5)c4ccccc24)-c2cccc4cccc-3c24)cc1]

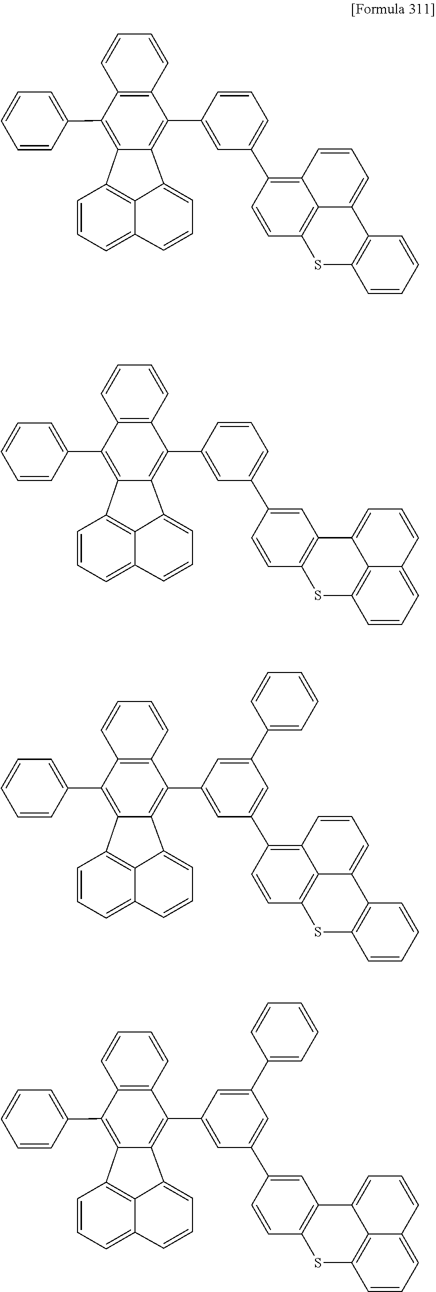 [SMILES: c1ccc(-c2c3c(c(-c4cccc(-c5ccc6c7c(cccc57)-c5ccccc5S6)c4)c4ccccc24)-c2cccc4cccc-3c24)cc1 ; c1ccc(-c2c3c(c(-c4cccc(-c5ccc6c(c5)-c5cccc7cccc(c57)S6)c4)c4ccccc24)-c2cccc4cccc-3c24)cc1 ; c1ccc(-c2cc(-c3c4c(c(-c5ccccc5)c5ccccc35)-c3cccc5cccc-4c35)cc(-c3ccc4c5c(cccc35)-c3ccccc3S4)c2)cc1 ; c1ccc(-c2cc(-c3ccc4c(c3)-c3cccc5cccc(c35)S4)cc(-c3c4c(c(-c5ccccc5)c5ccccc35)-c3cccc5cccc-4c35)c2)cc1]

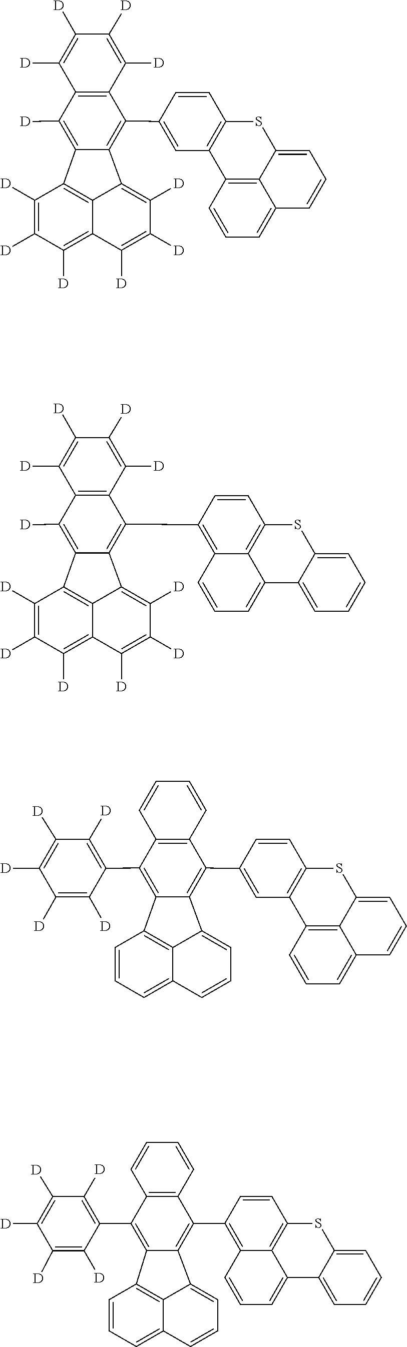 [SMILES: [2H]c1c([2H])c([2H])c2c(-c3ccc4c(c3)-c3cccc5cccc(c35)S4)c3c(c([2H])c2c1[2H])-c1c([2H])c([2H])c([2H])c2c([2H])c([2H])c([2H])c-3c12 ; [2H]c1c([2H])c([2H])c2c(-c3ccc4c5c(cccc35)-c3ccccc3S4)c3c(c([2H])c2c1[2H])-c1c([2H])c([2H])c([2H])c2c([2H])c([2H])c([2H])c-3c12 ; [2H]c1c([2H])c([2H])c(-c2c3c(c(-c4ccc5c(c4)-c4cccc6cccc(c46)S5)c4ccccc24)-c2cccc4cccc-3c24)c([2H])c1[2H] ; [2H]c1c([2H])c([2H])c(-c2c3c(c(-c4ccc5c6c(cccc46)-c4ccccc4S5)c4ccccc24)-c2cccc4cccc-3c24)c([2H])c1[2H]]

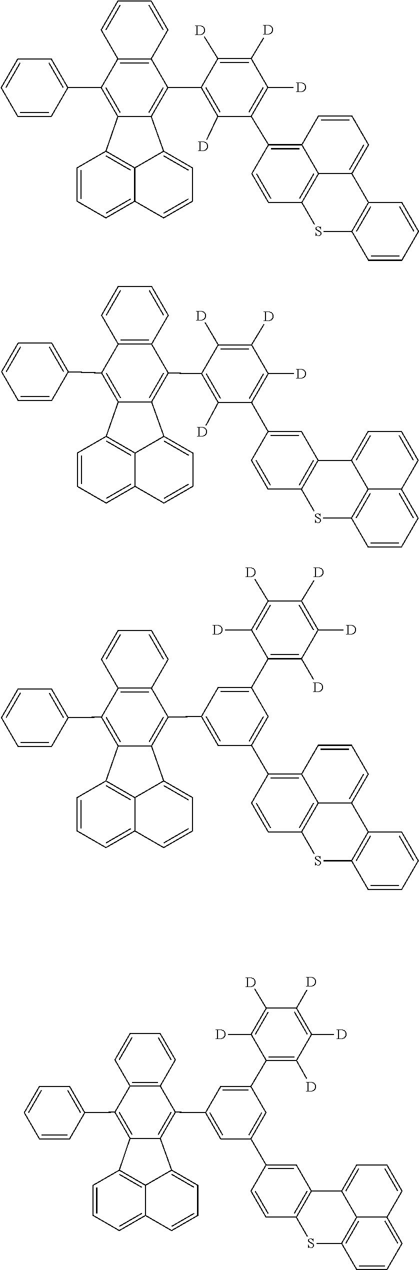 [SMILES: [2H]c1c([2H])c(-c2c3c(c(-c4ccccc4)c4ccccc24)-c2cccc4cccc-3c24)c([2H])c(-c2ccc3c4c(cccc24)-c2ccccc2S3)c1[2H] ; [2H]c1c([2H])c(-c2ccc3c(c2)-c2cccc4cccc(c24)S3)c([2H])c(-c2c3c(c(-c4ccccc4)c4ccccc24)-c2cccc4cccc-3c24)c1[2H] ; [2H]c1c([2H])c([2H])c(-c2cc(-c3c4c(c(-c5ccccc5)c5ccccc35)-c3cccc5cccc-4c35)cc(-c3ccc4c5c(cccc35)-c3ccccc3S4)c2)c([2H])c1[2H] ; [2H]c1c([2H])c([2H])c(-c2cc(-c3ccc4c(c3)-c3cccc5cccc(c35)S4)cc(-c3c4c(c(-c5ccccc5)c5ccccc35)-c3cccc5cccc-4c35)c2)c([2H])c1[2H]]

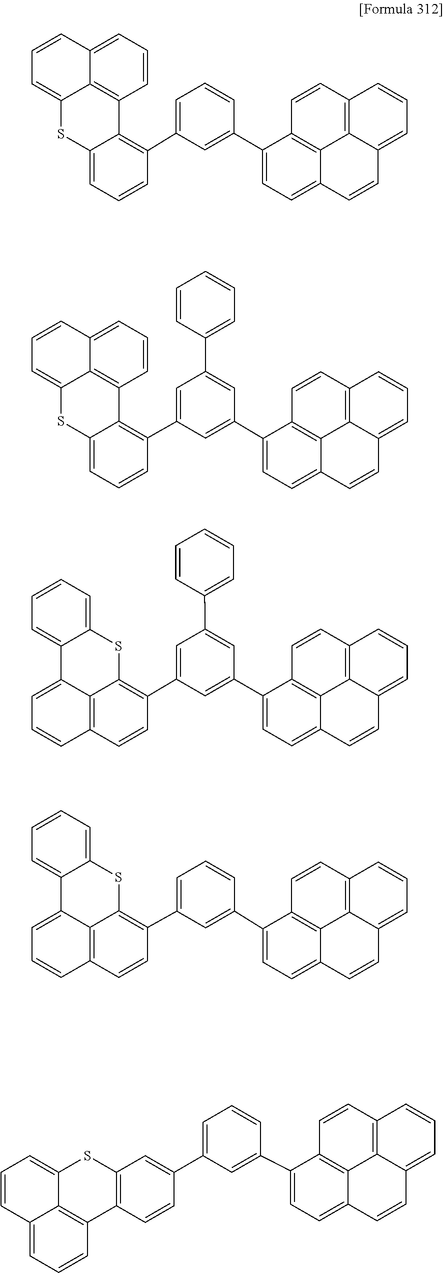 [SMILES: c1cc(-c2cccc3c2-c2cccc4cccc(c24)S3)cc(-c2ccc3ccc4cccc5ccc2c3c45)c1 ; c1ccc(-c2cc(-c3cccc4c3-c3cccc5cccc(c35)S4)cc(-c3ccc4ccc5cccc6ccc3c4c56)c2)cc1 ; c1ccc(-c2cc(-c3ccc4cccc5c4c3Sc3ccccc3-5)cc(-c3ccc4ccc5cccc6ccc3c4c56)c2)cc1 ; c1cc(-c2ccc3cccc4c3c2Sc2ccccc2-4)cc(-c2ccc3ccc4cccc5ccc2c3c45)c1 ; c1cc(-c2ccc3c(c2)Sc2cccc4cccc-3c24)cc(-c2ccc3ccc4cccc5ccc2c3c45)c1]

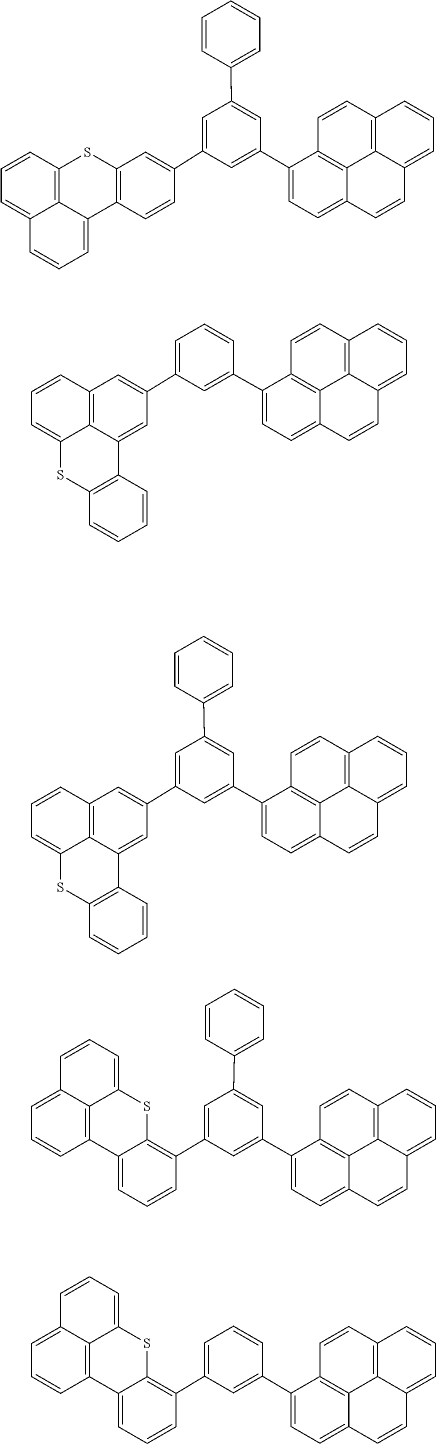 [SMILES: c1ccc(-c2cc(-c3ccc4c(c3)Sc3cccc5cccc-4c35)cc(-c3ccc4ccc5cccc6ccc3c4c56)c2)cc1 ; c1cc(-c2cc3c4c(cccc4c2)Sc2ccccc2-3)cc(-c2ccc3ccc4cccc5ccc2c3c45)c1 ; c1ccc(-c2cc(-c3cc4c5c(cccc5c3)Sc3ccccc3-4)cc(-c3ccc4ccc5cccc6ccc3c4c56)c2)cc1 ; c1ccc(-c2cc(-c3cccc4c3Sc3cccc5cccc-4c35)cc(-c3ccc4ccc5cccc6ccc3c4c56)c2)cc1 ; c1cc(-c2cccc3c2Sc2cccc4cccc-3c24)cc(-c2ccc3ccc4cccc5ccc2c3c45)c1]

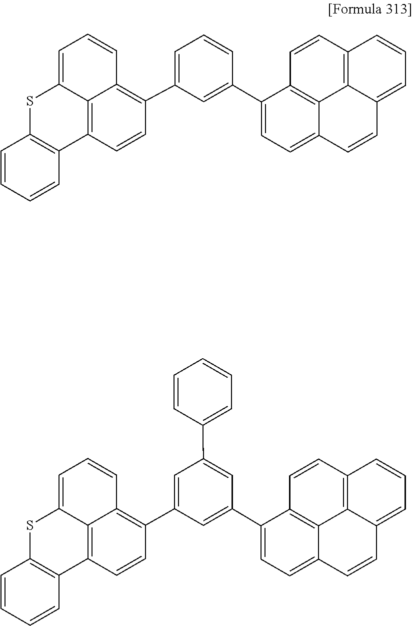 [SMILES: c1cc(-c2ccc3c4c(cccc24)Sc2ccccc2-3)cc(-c2ccc3ccc4cccc5ccc2c3c45)c1 ; c1ccc(-c2cc(-c3ccc4c5c(cccc35)Sc3ccccc3-4)cc(-c3ccc4ccc5cccc6ccc3c4c56)c2)cc1]

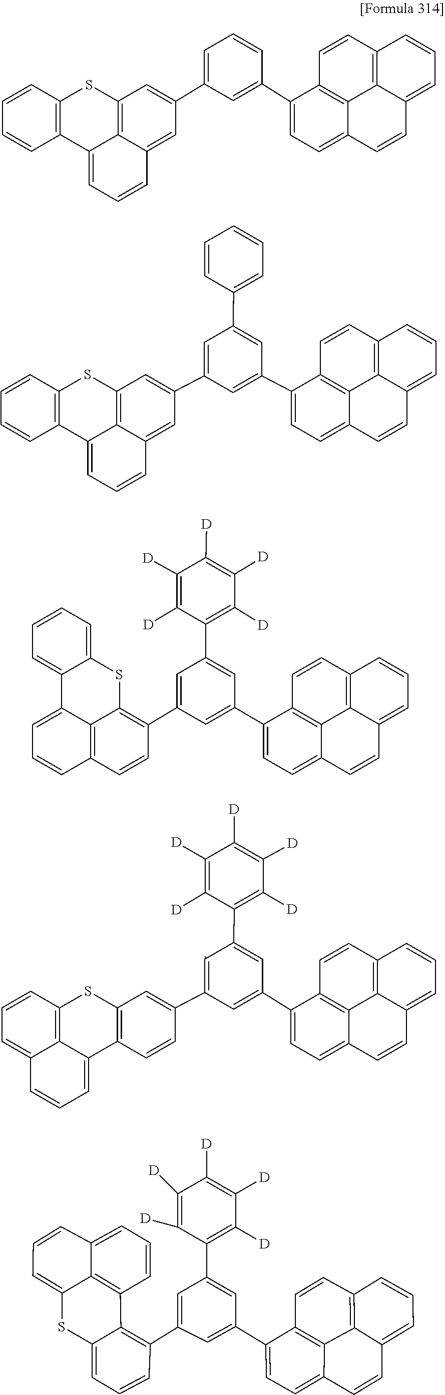 [SMILES: c1cc(-c2cc3c4c(cccc4c2)-c2ccccc2S3)cc(-c2ccc3ccc4cccc5ccc2c3c45)c1 ; c1ccc(-c2cc(-c3cc4c5c(cccc5c3)-c3ccccc3S4)cc(-c3ccc4ccc5cccc6ccc3c4c56)c2)cc1 ; [2H]c1c([2H])c([2H])c(-c2cc(-c3ccc4cccc5c4c3Sc3ccccc3-5)cc(-c3ccc4ccc5cccc6ccc3c4c56)c2)c([2H])c1[2H] ; [2H]c1c([2H])c([2H])c(-c2cc(-c3ccc4ccc5cccc6ccc3c4c56)cc(-c3ccc4c(c3)Sc3cccc5cccc-4c35)c2C)c([2H])c1[2H] ; [2H]c1c([2H])c([2H])c(-c2cc(-c3cccc4c3-c3cccc5cccc(c35)S4)cc(-c3ccc4ccc5cccc6ccc3c4c56)c2)c([2H])c1[2H]]

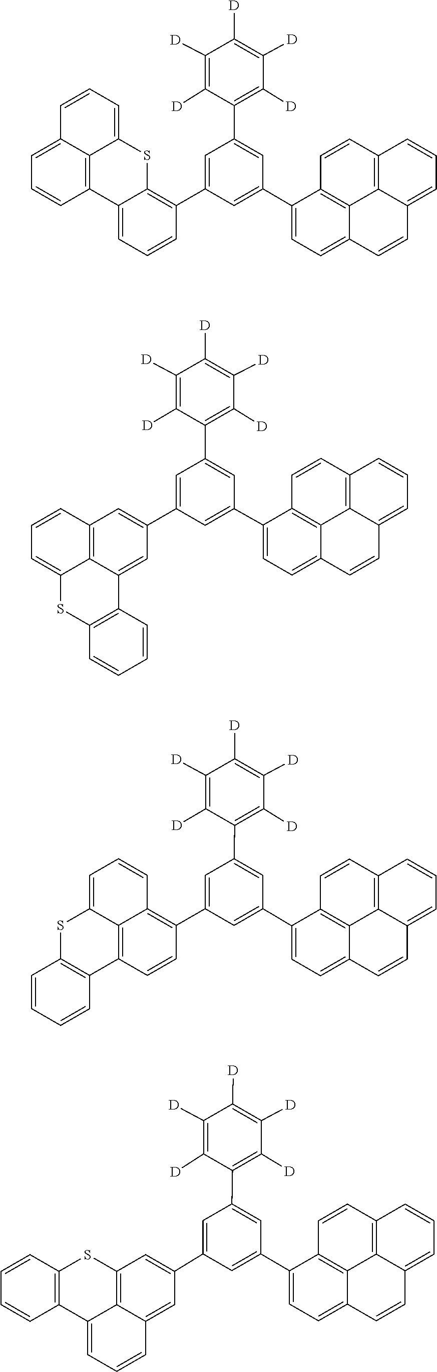 [SMILES: [2H]c1c([2H])c([2H])c(-c2cc(-c3cccc4c3Sc3cccc5cccc-4c35)cc(-c3ccc4ccc5cccc6ccc3c4c56)c2)c([2H])c1[2H] ; [2H]c1c([2H])c([2H])c(-c2cc(-c3cc4c5c(cccc5c3)Sc3ccccc3-4)cc(-c3ccc4ccc5cccc6ccc3c4c56)c2)c([2H])c1[2H] ; [2H]c1c([2H])c([2H])c(-c2cc(-c3ccc4c5c(cccc35)Sc3ccccc3-4)cc(-c3ccc4ccc5cccc6ccc3c4c56)c2)c([2H])c1[2H] ; [2H]c1c([2H])c([2H])c(-c2cc(-c3cc4c5c(cccc5c3)-c3ccccc3S4)cc(-c3ccc4ccc5cccc6ccc3c4c56)c2)c([2H])c1[2H]]

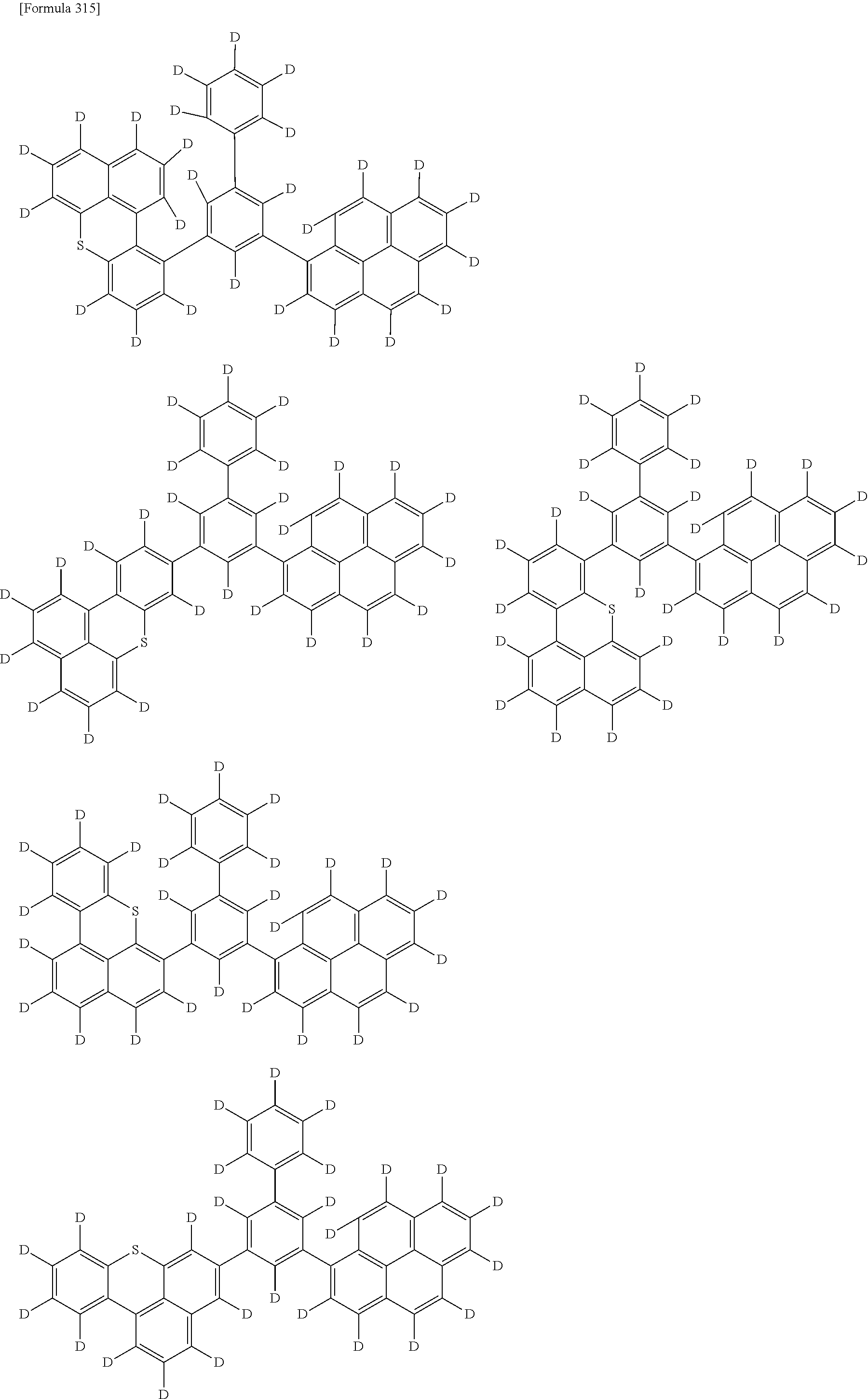

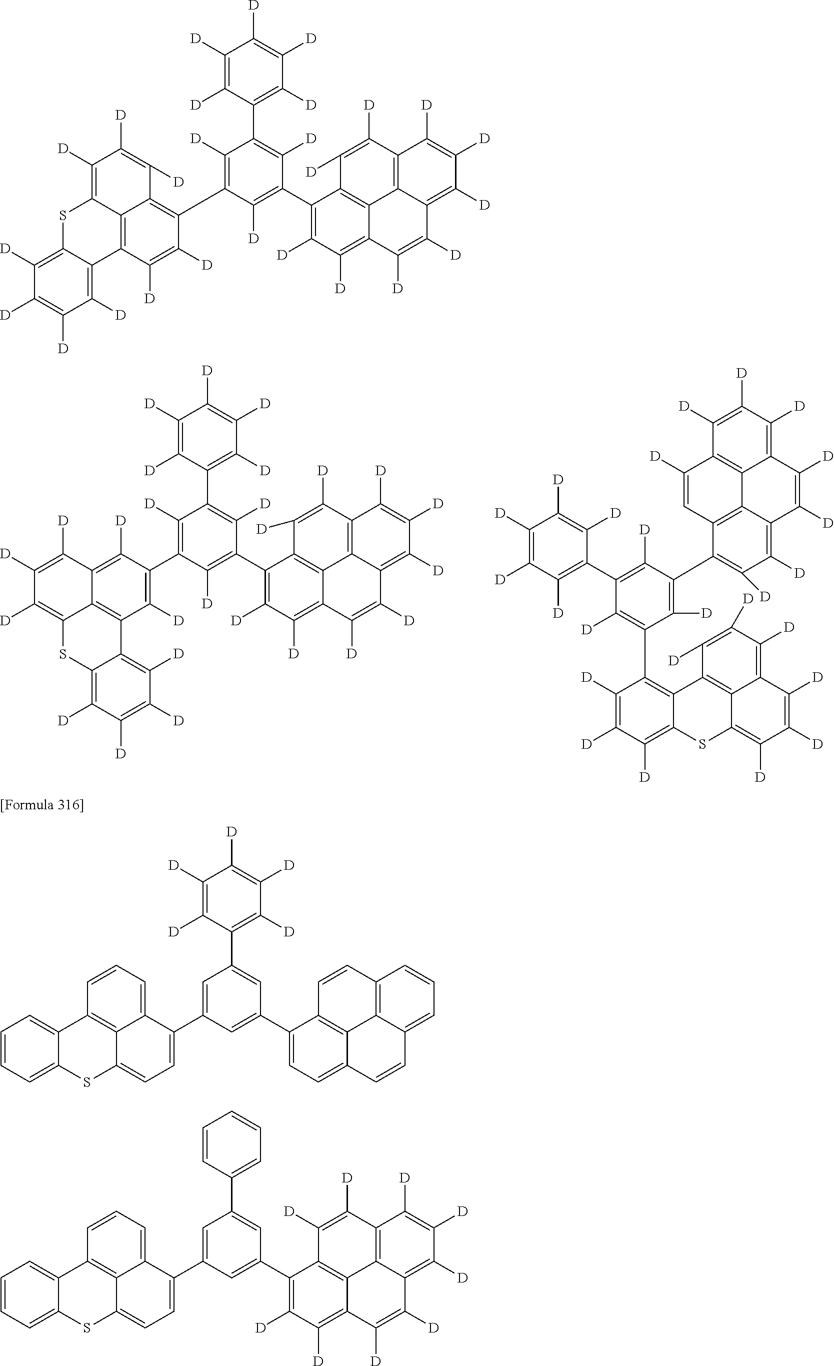

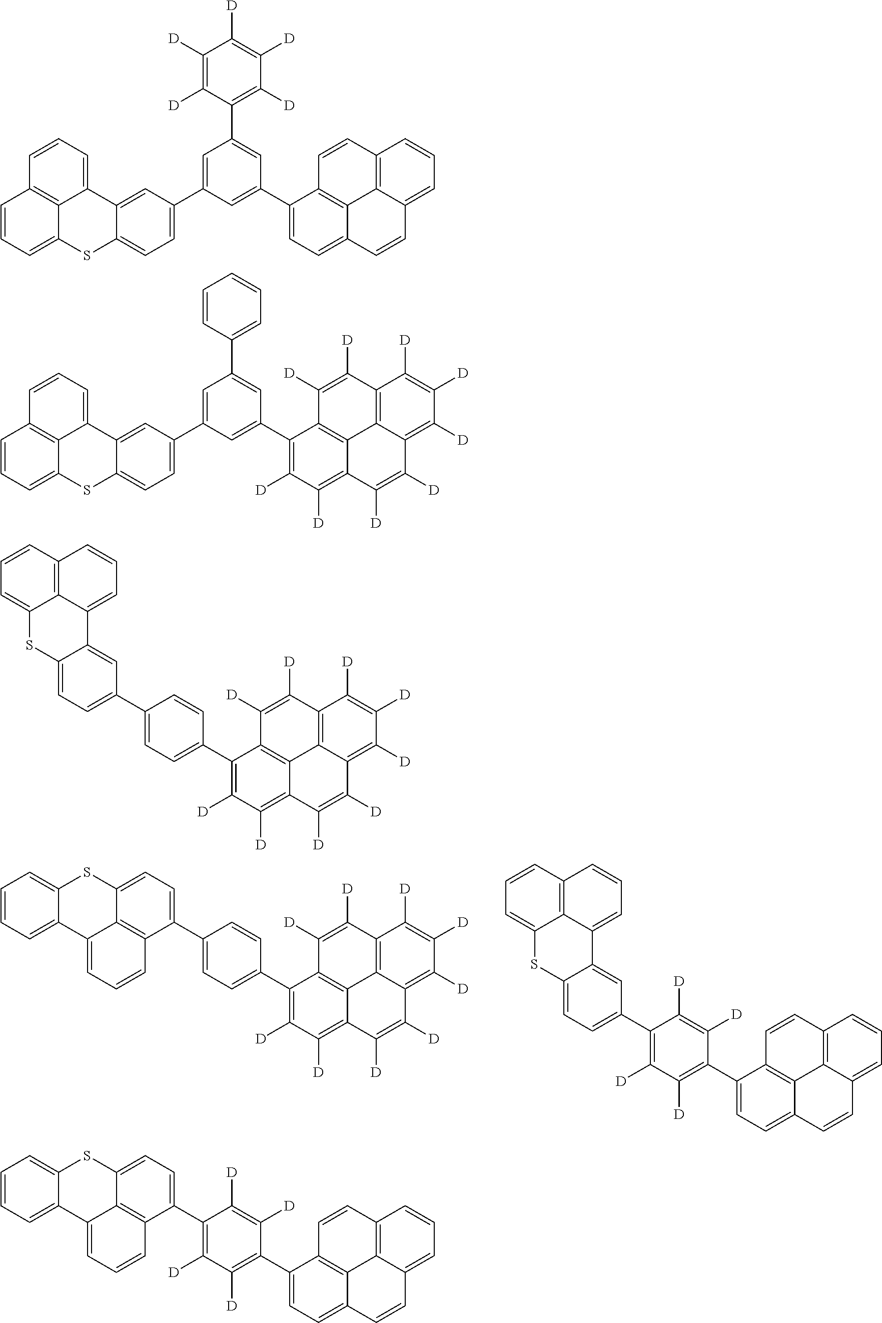

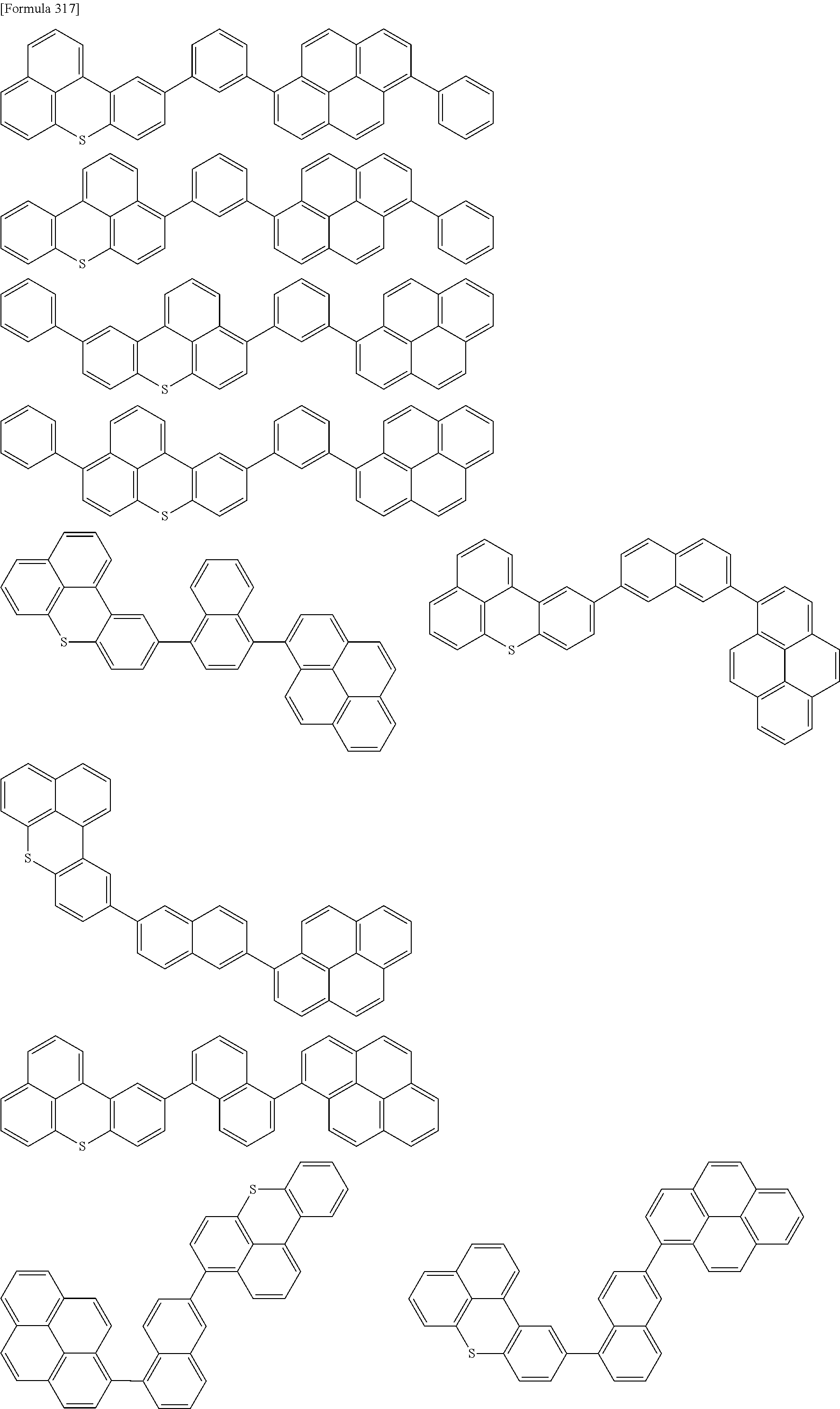

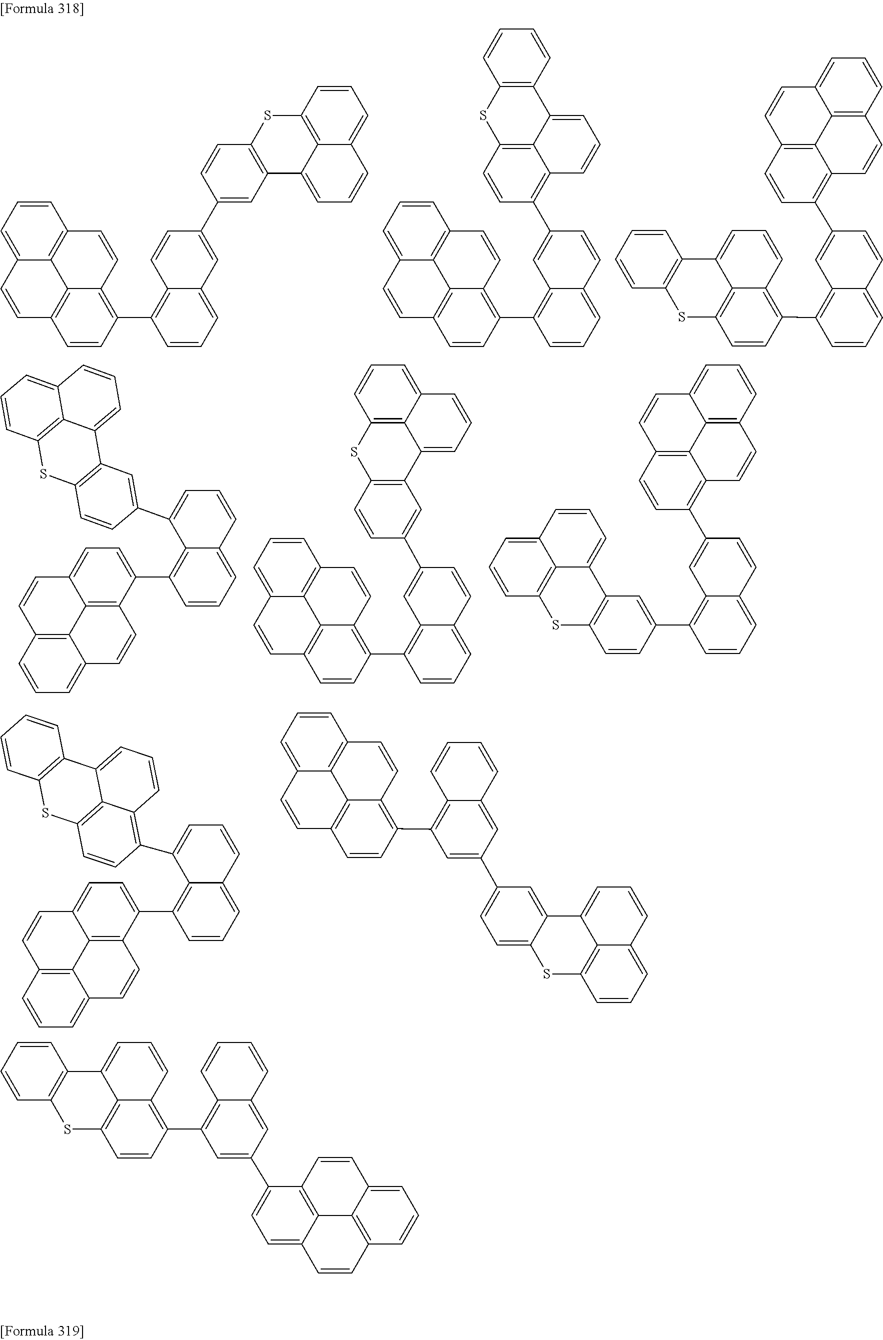

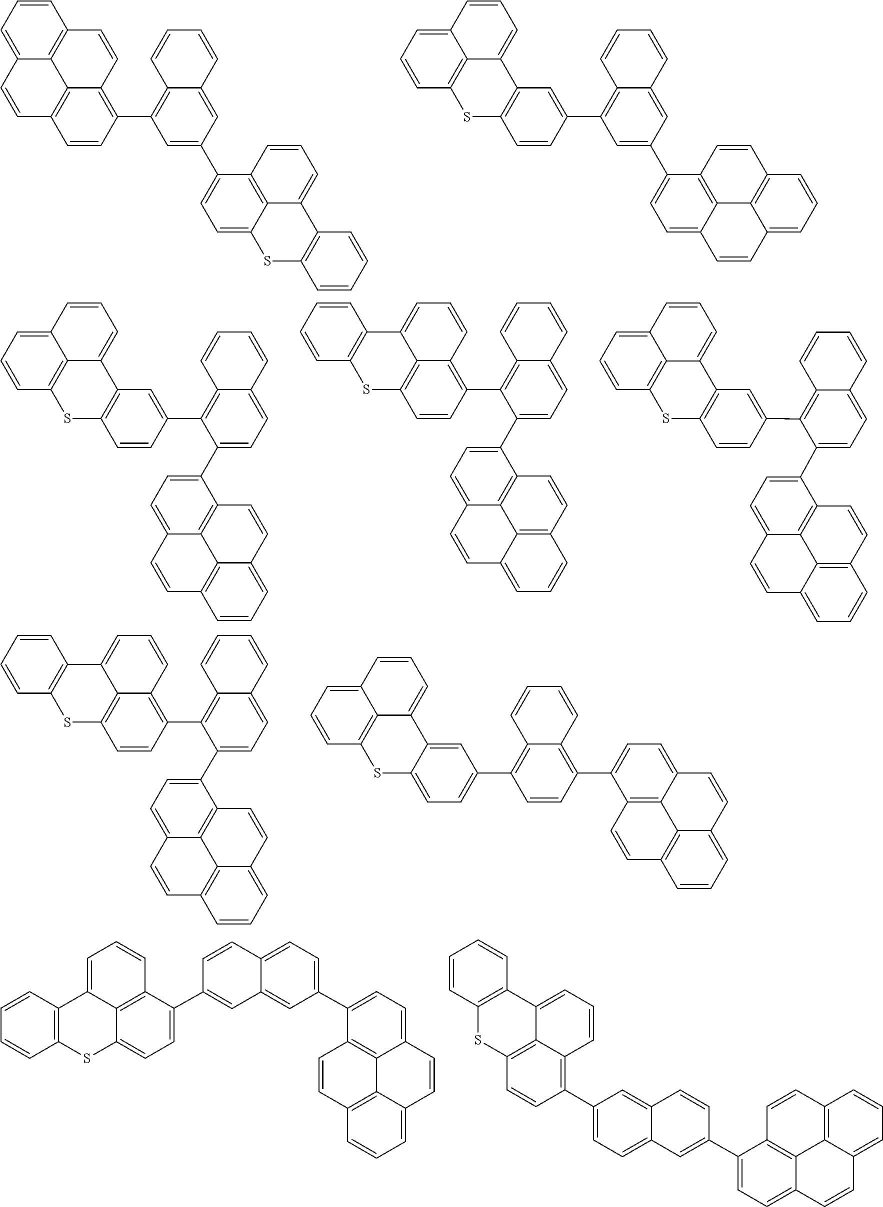

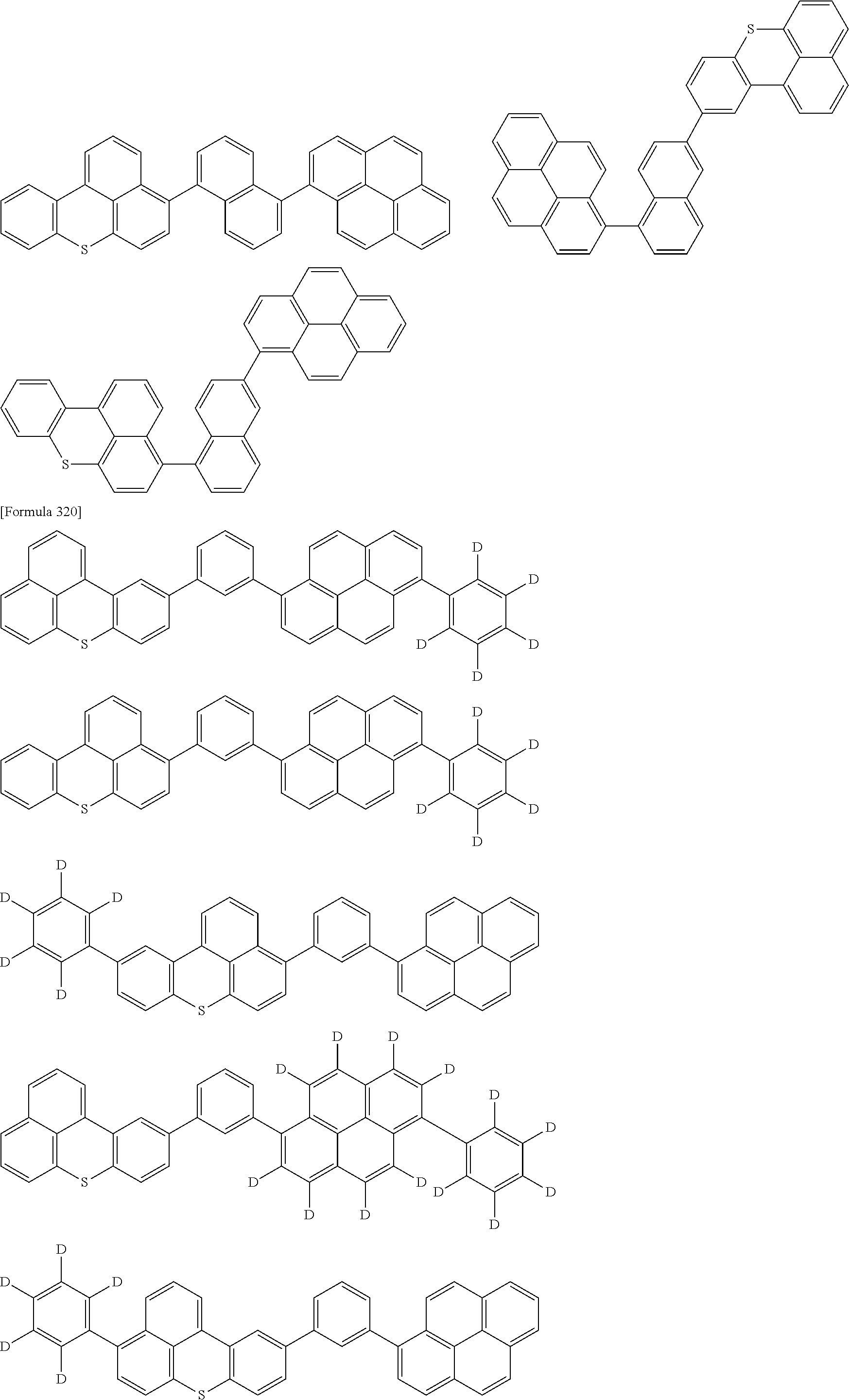

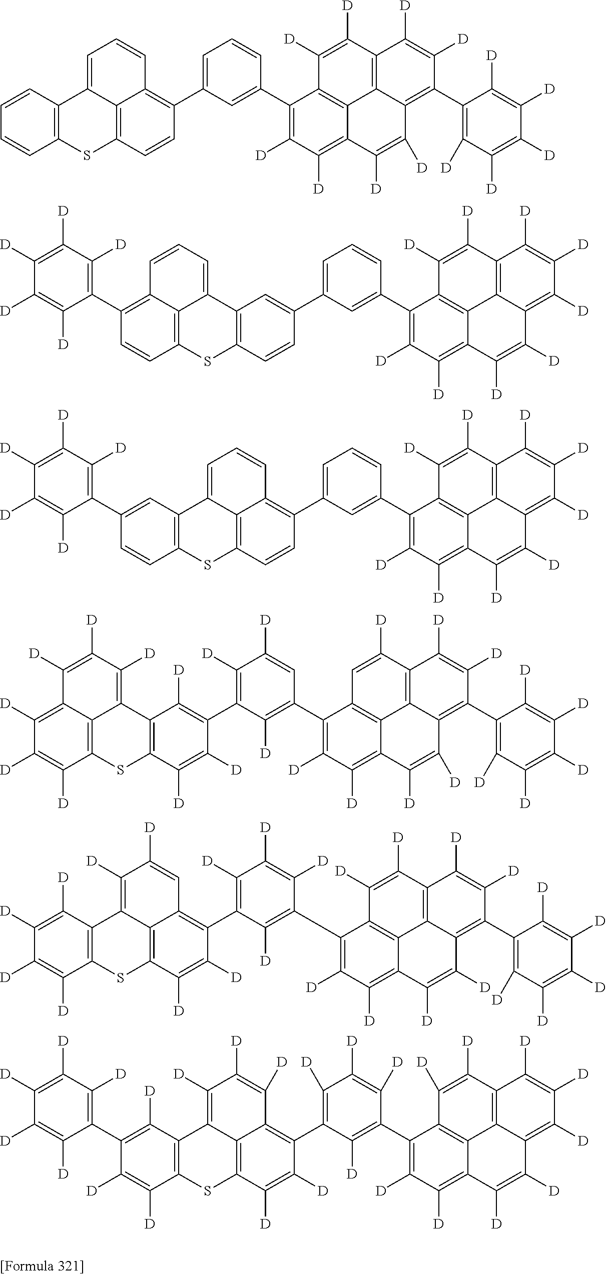

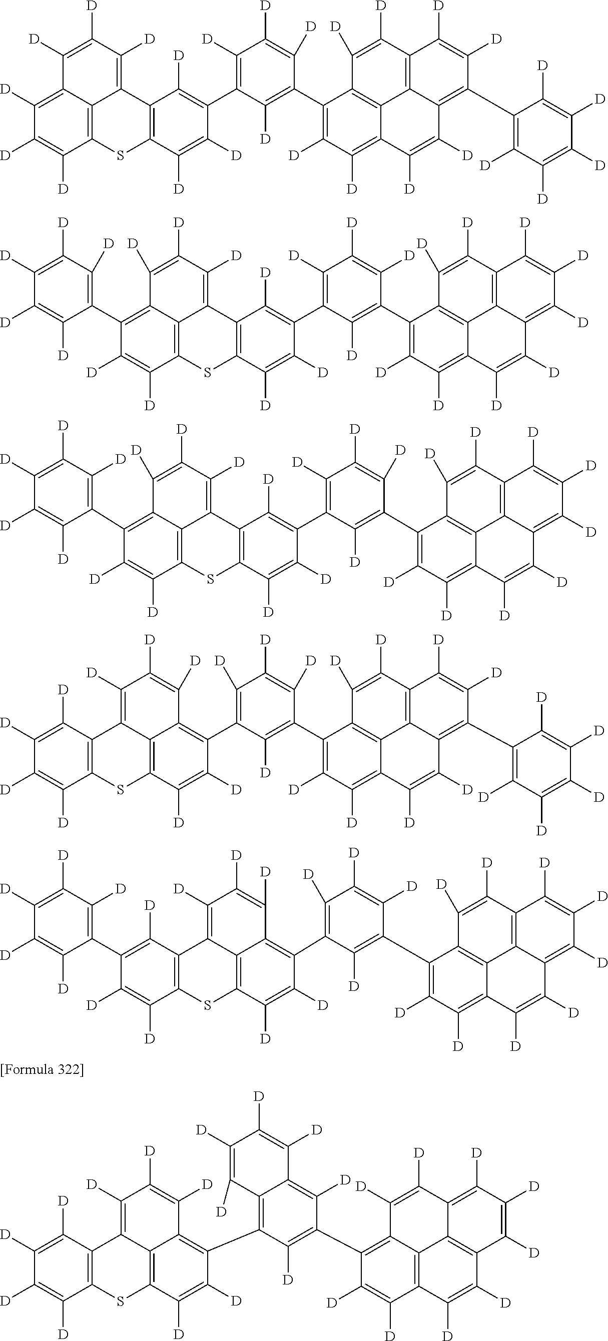

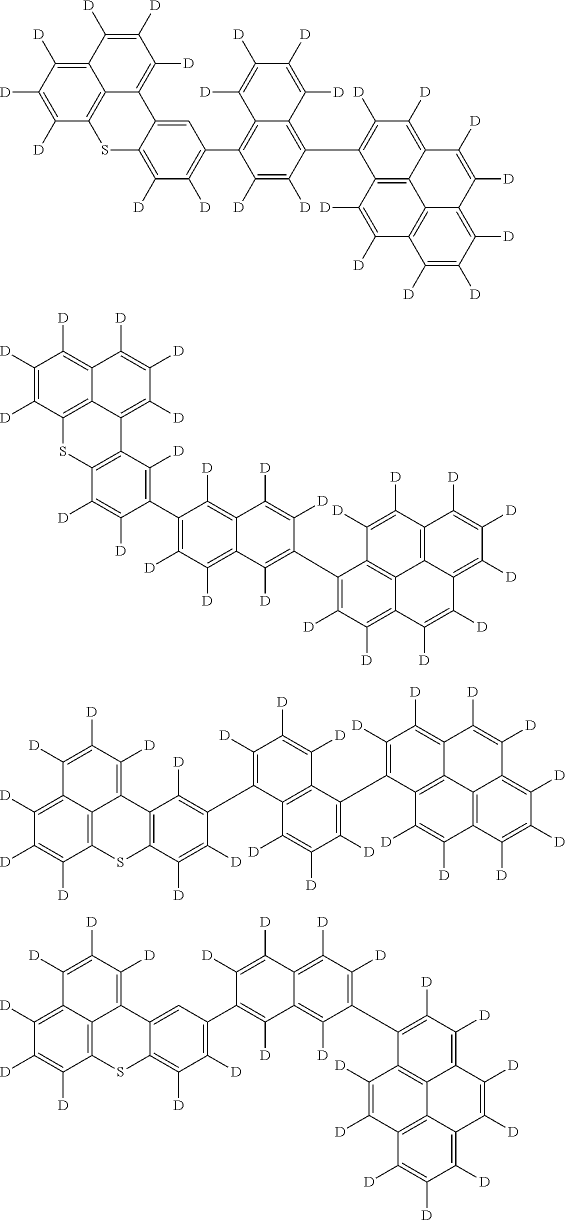

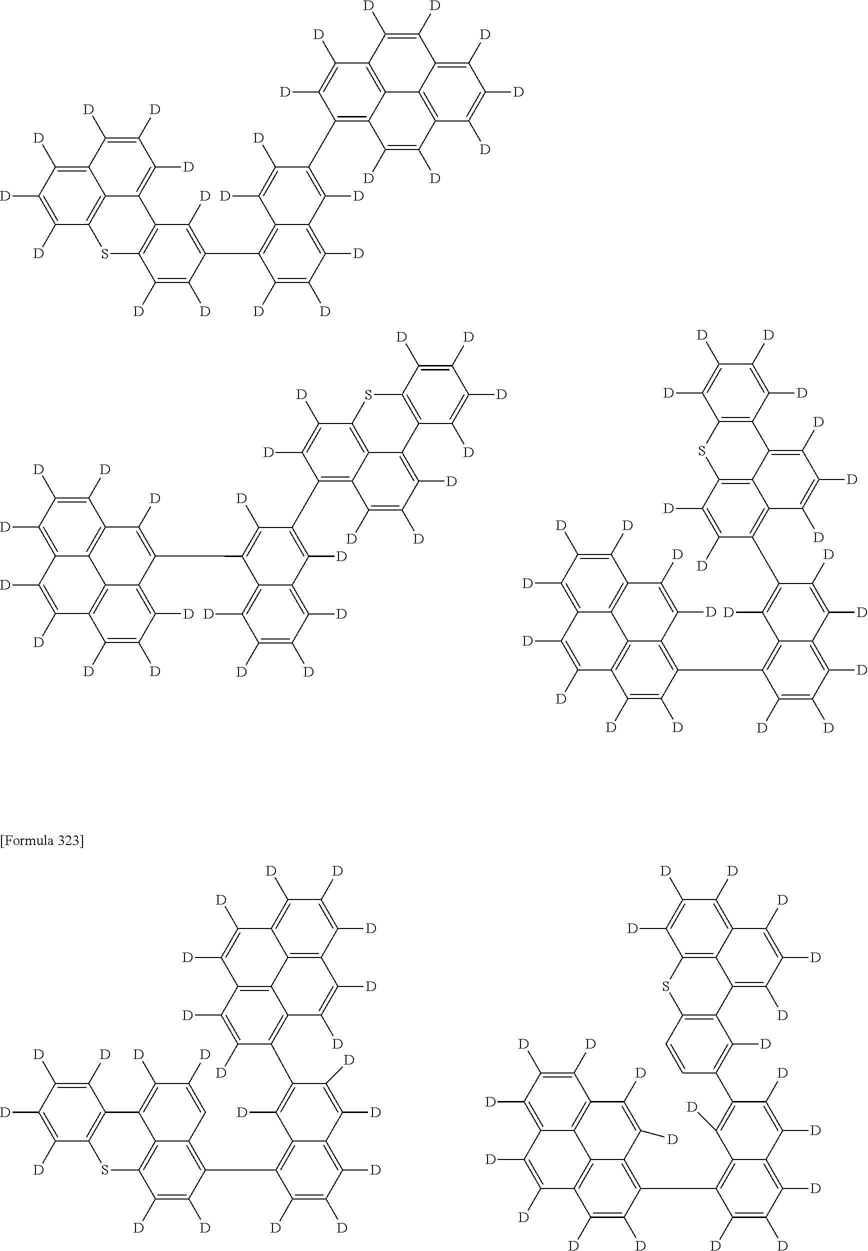

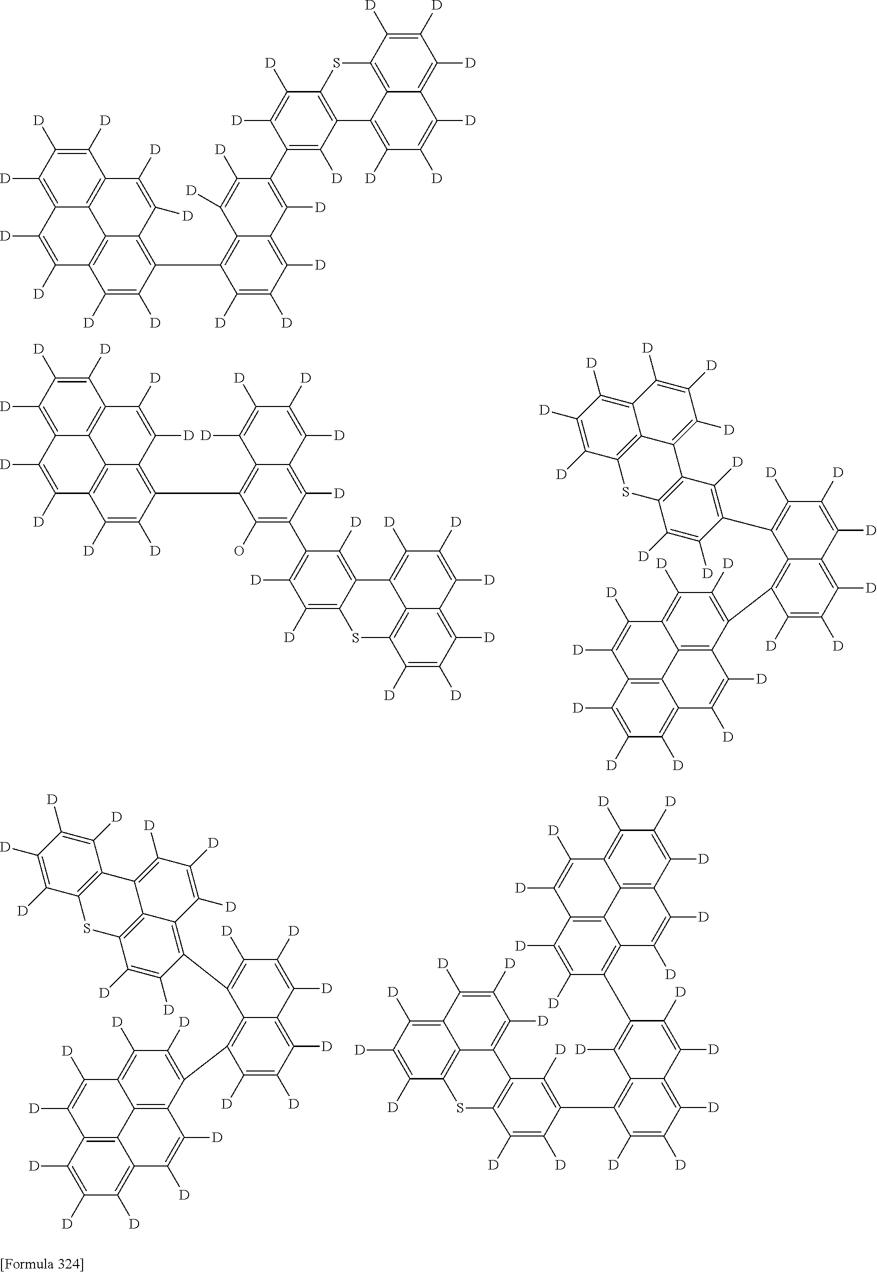

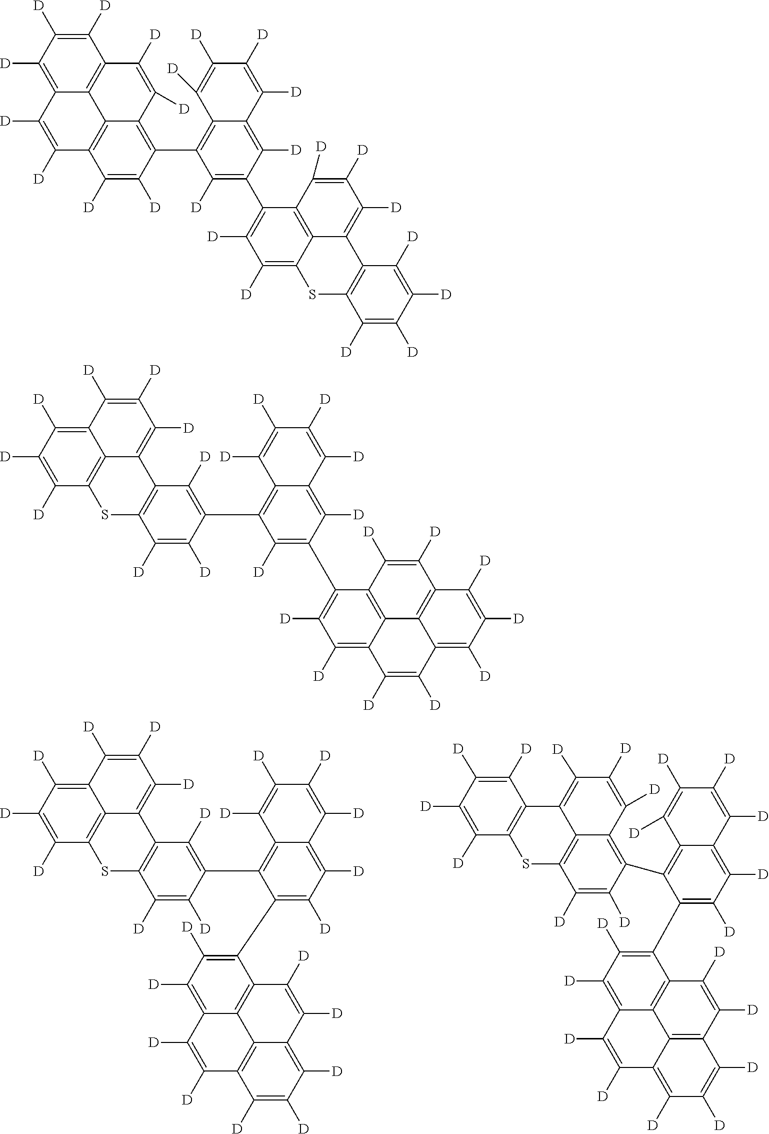

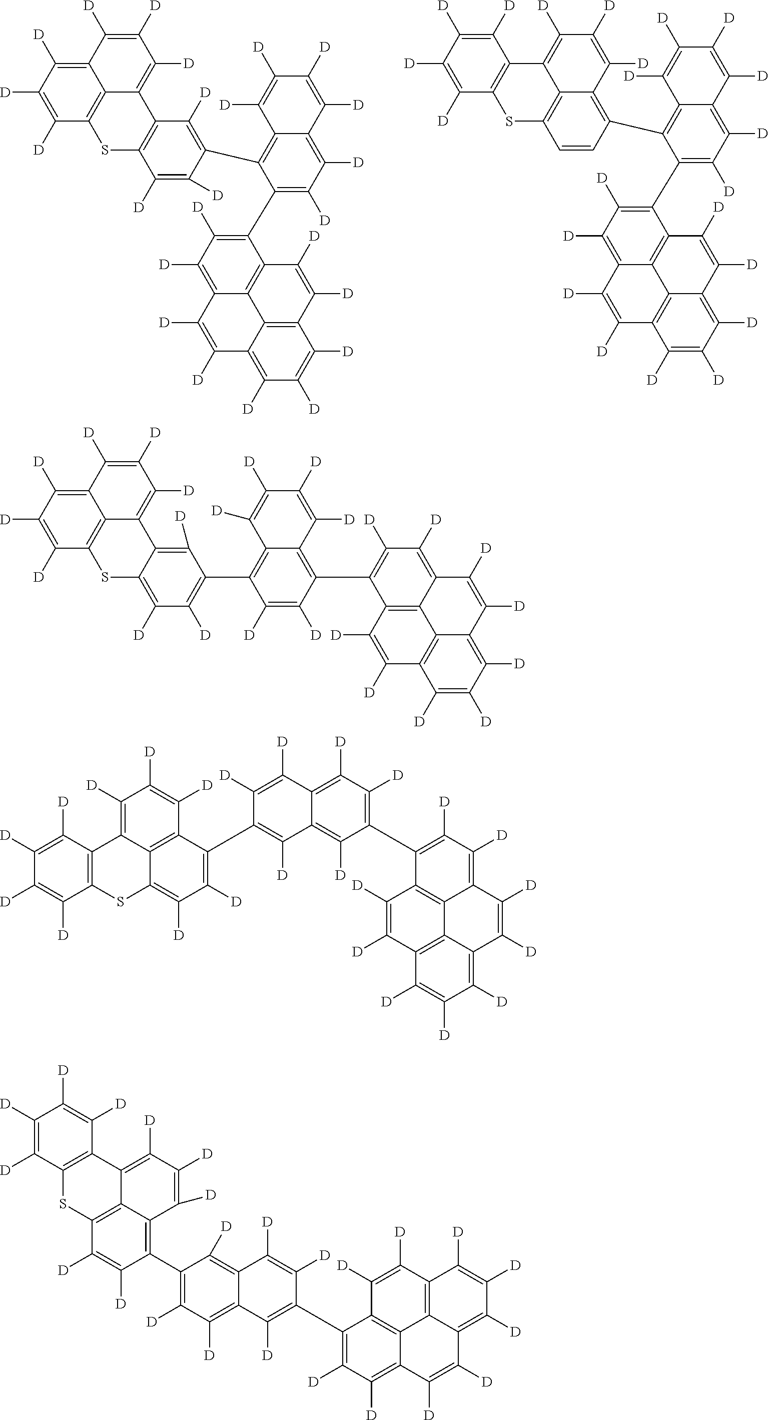

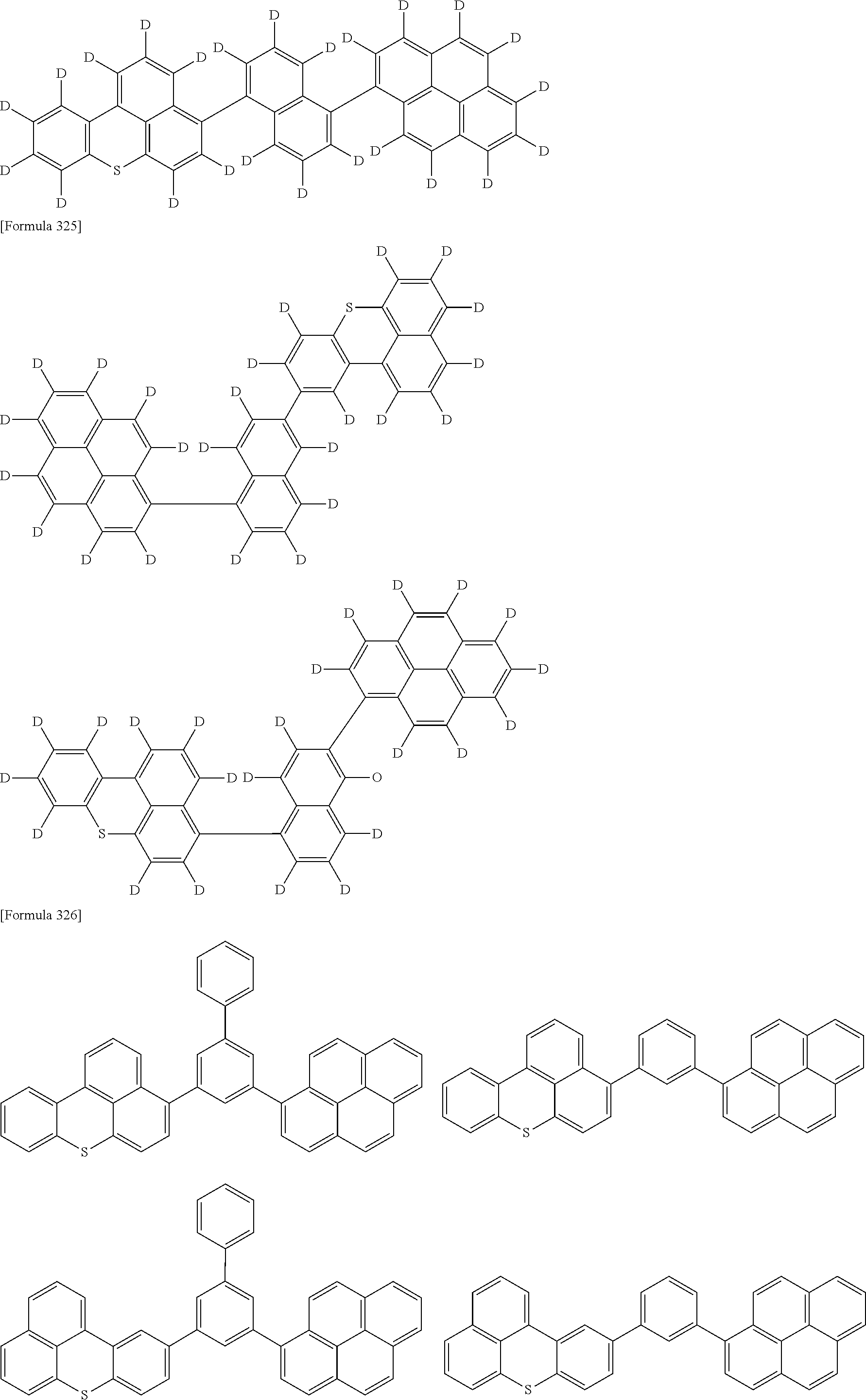

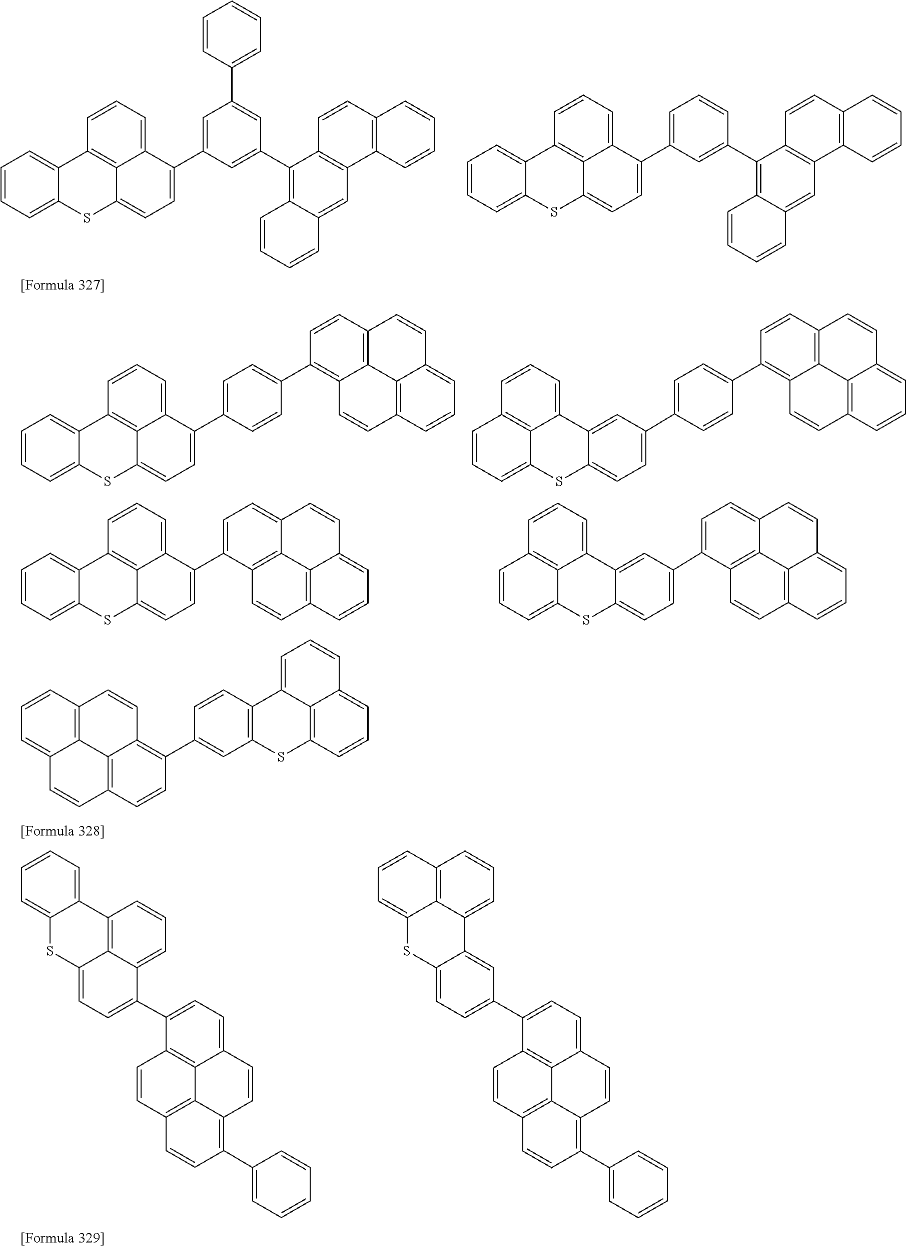

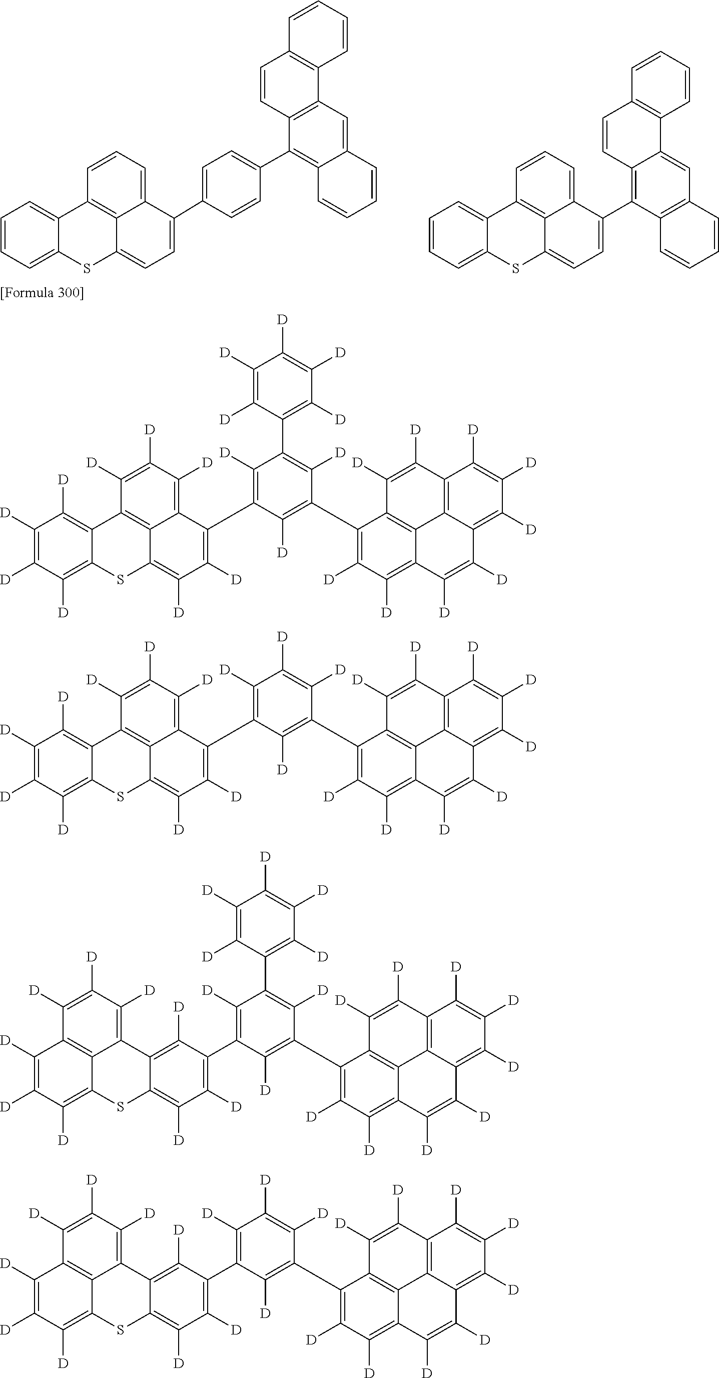

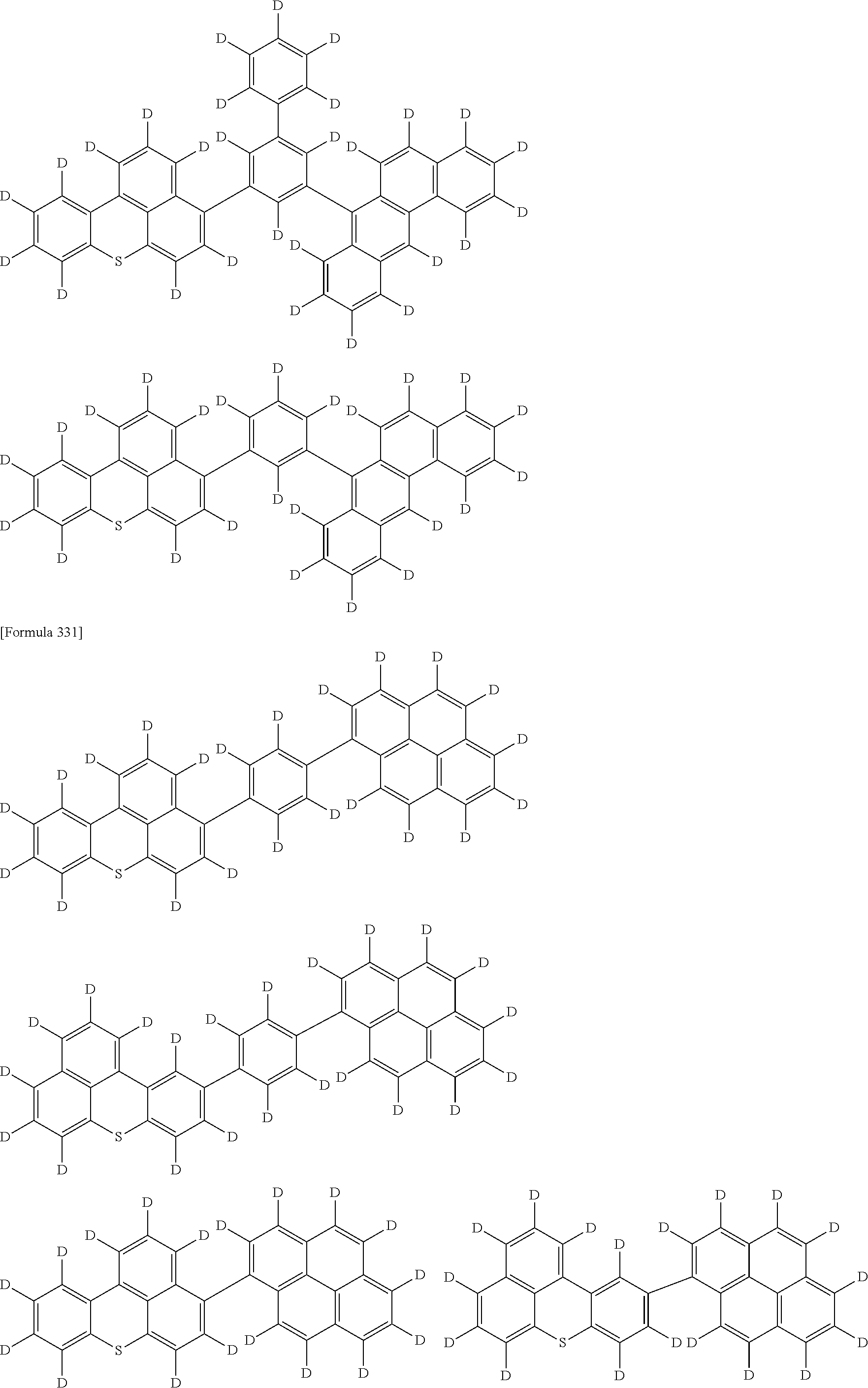

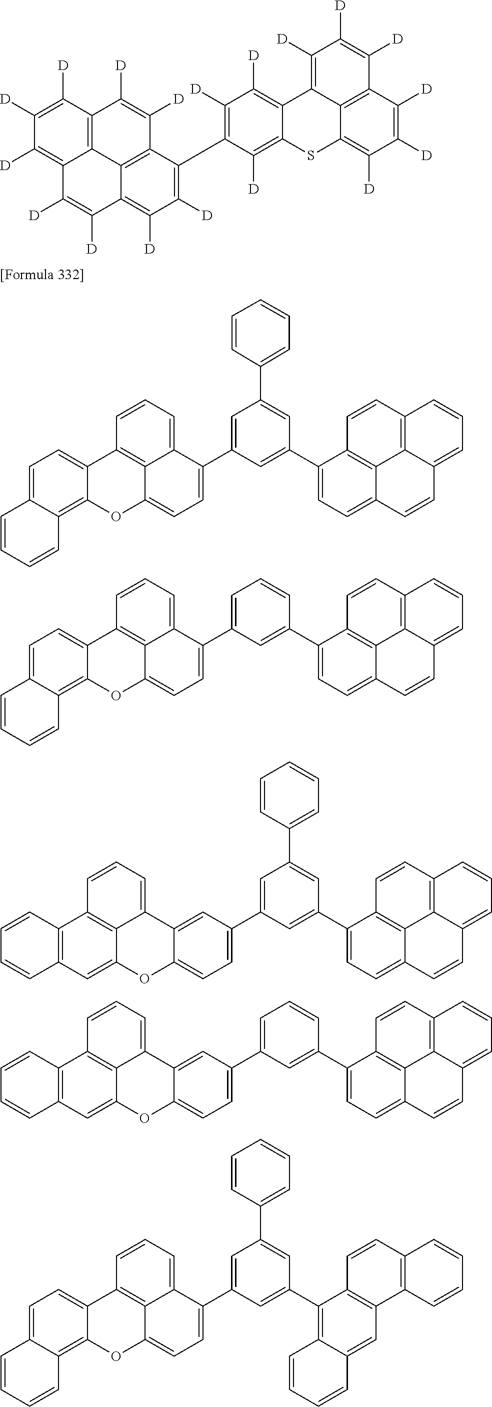

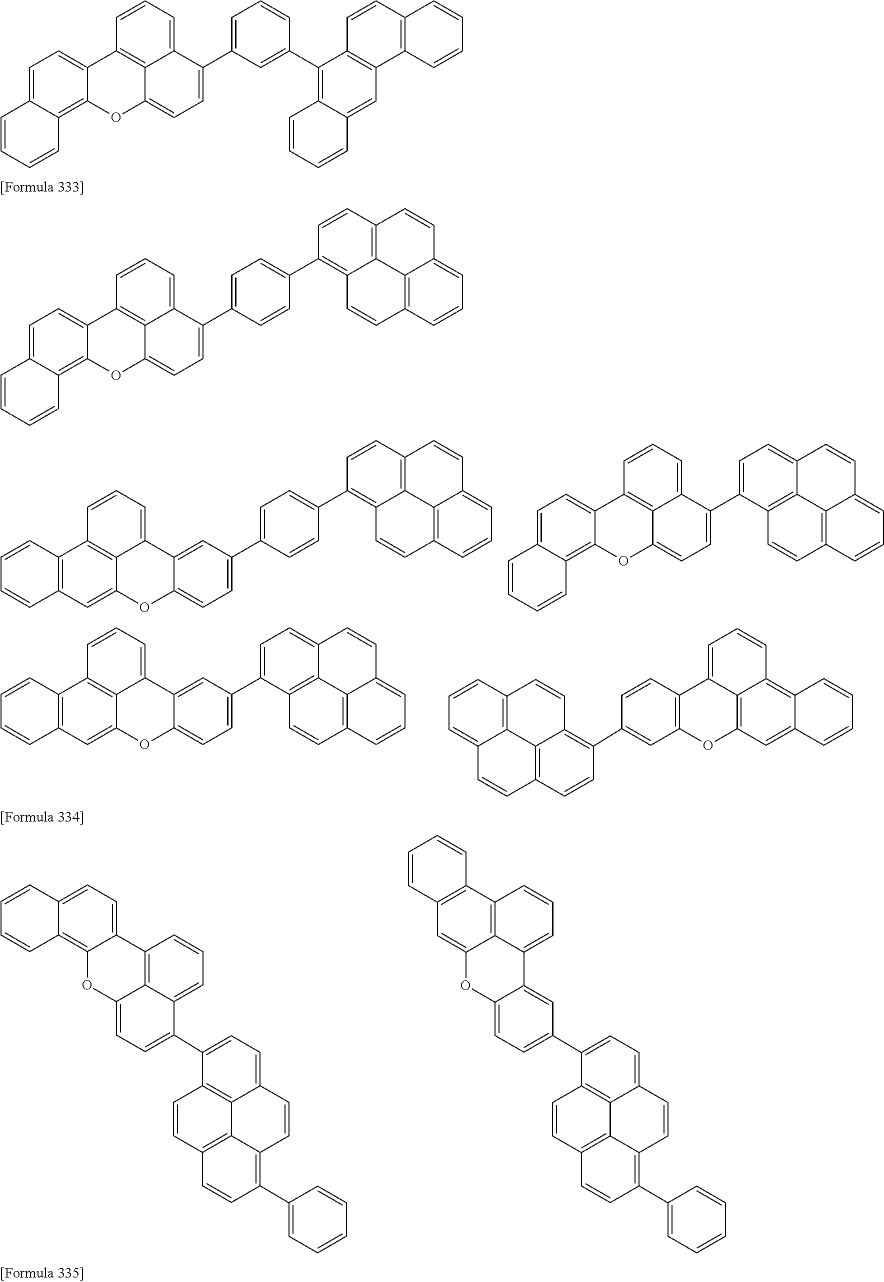

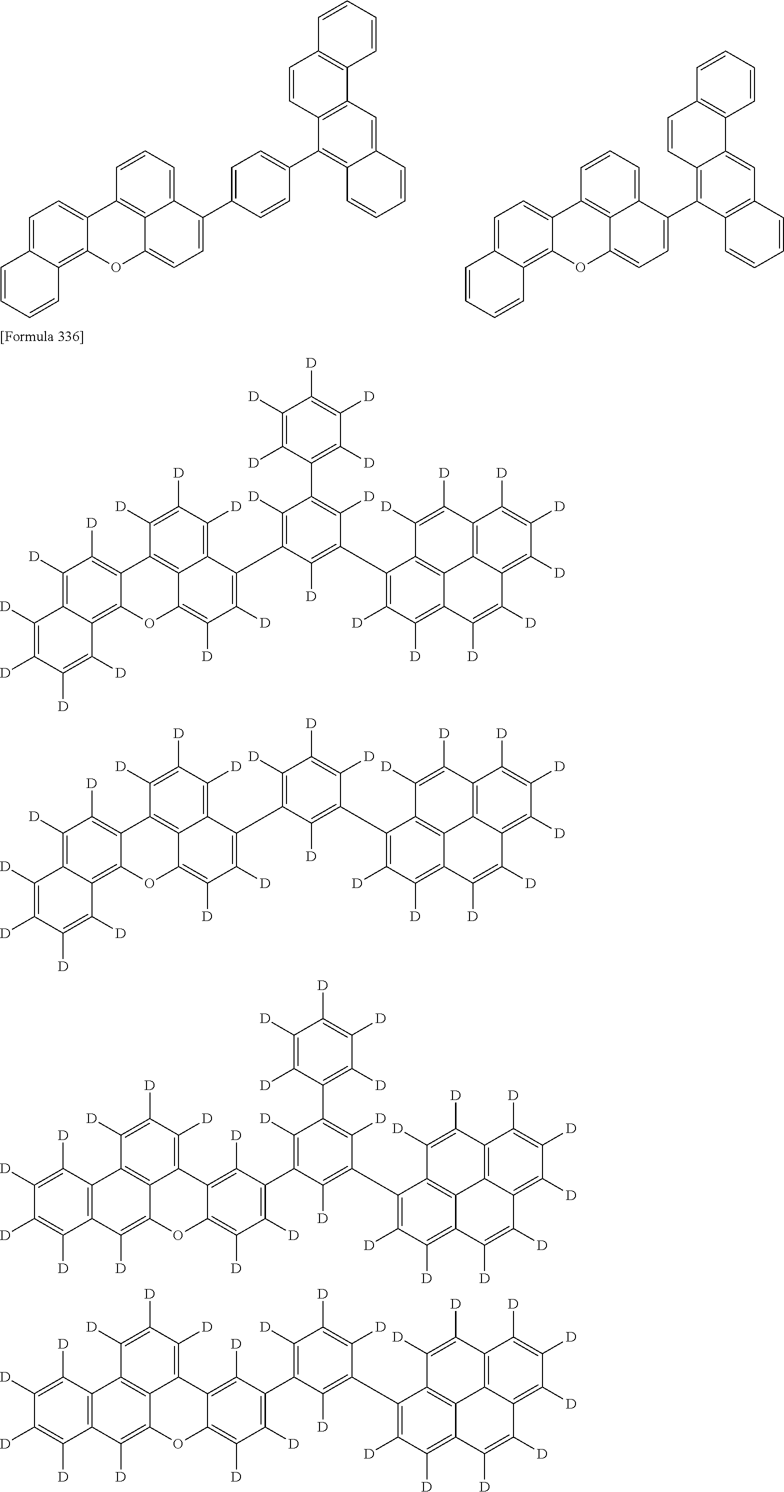

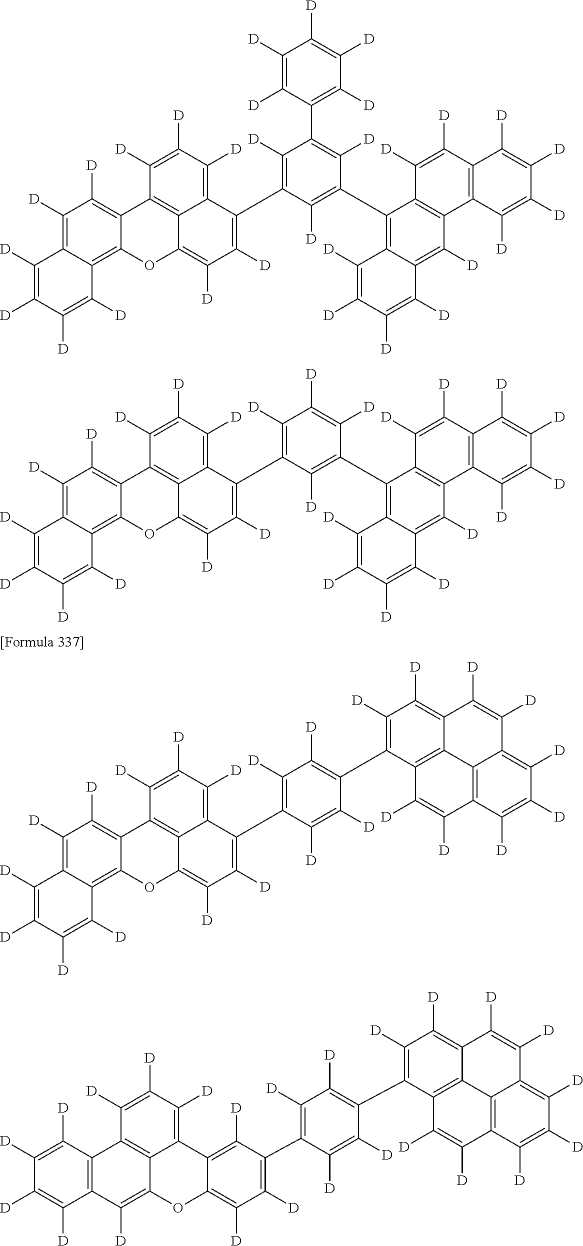

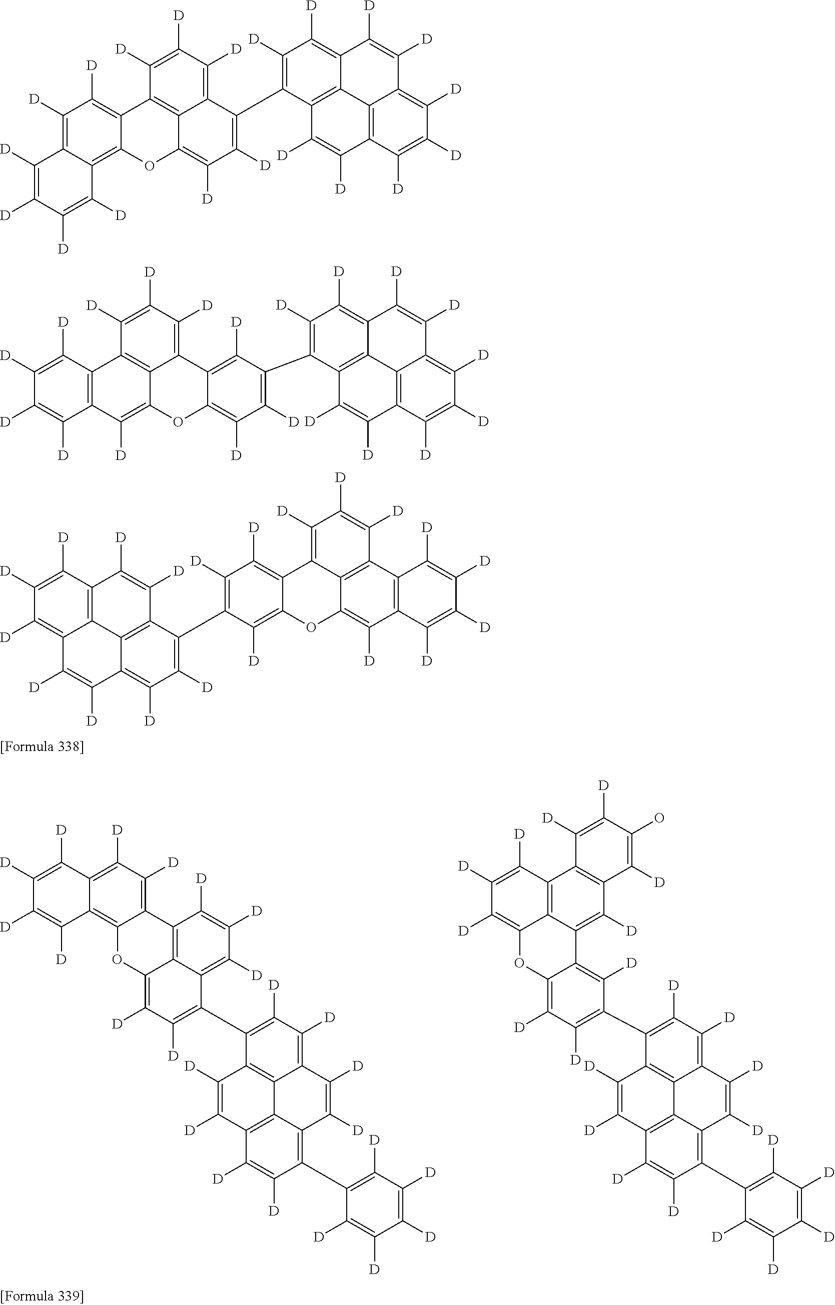

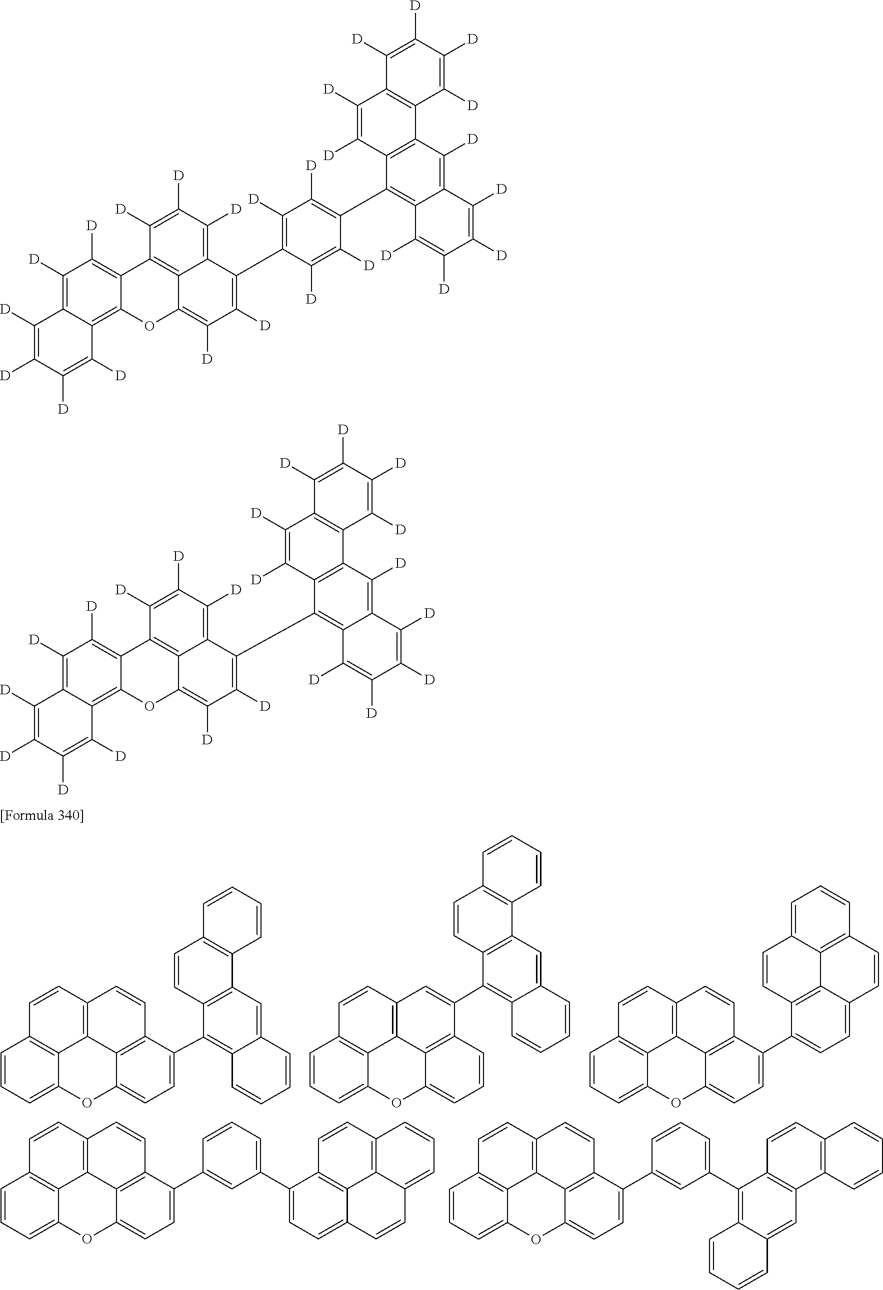

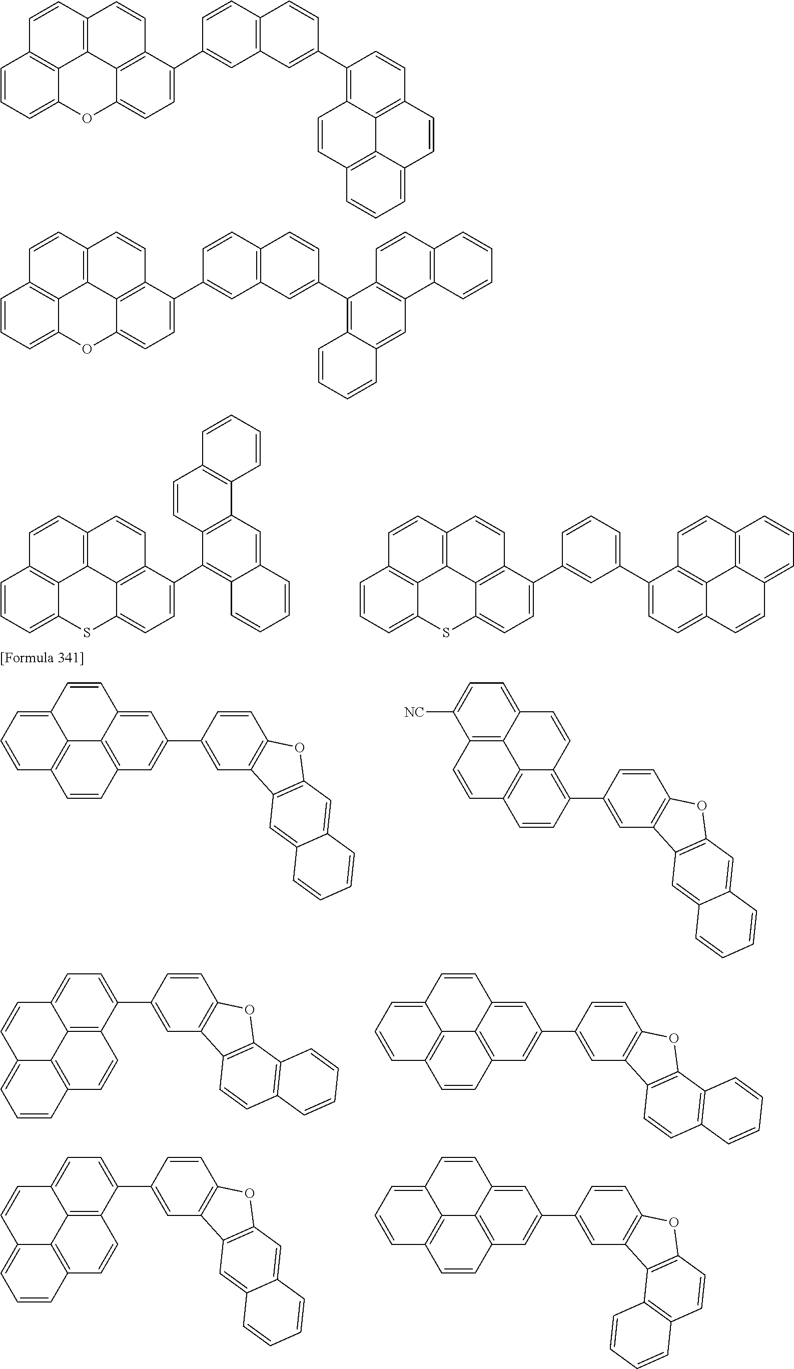

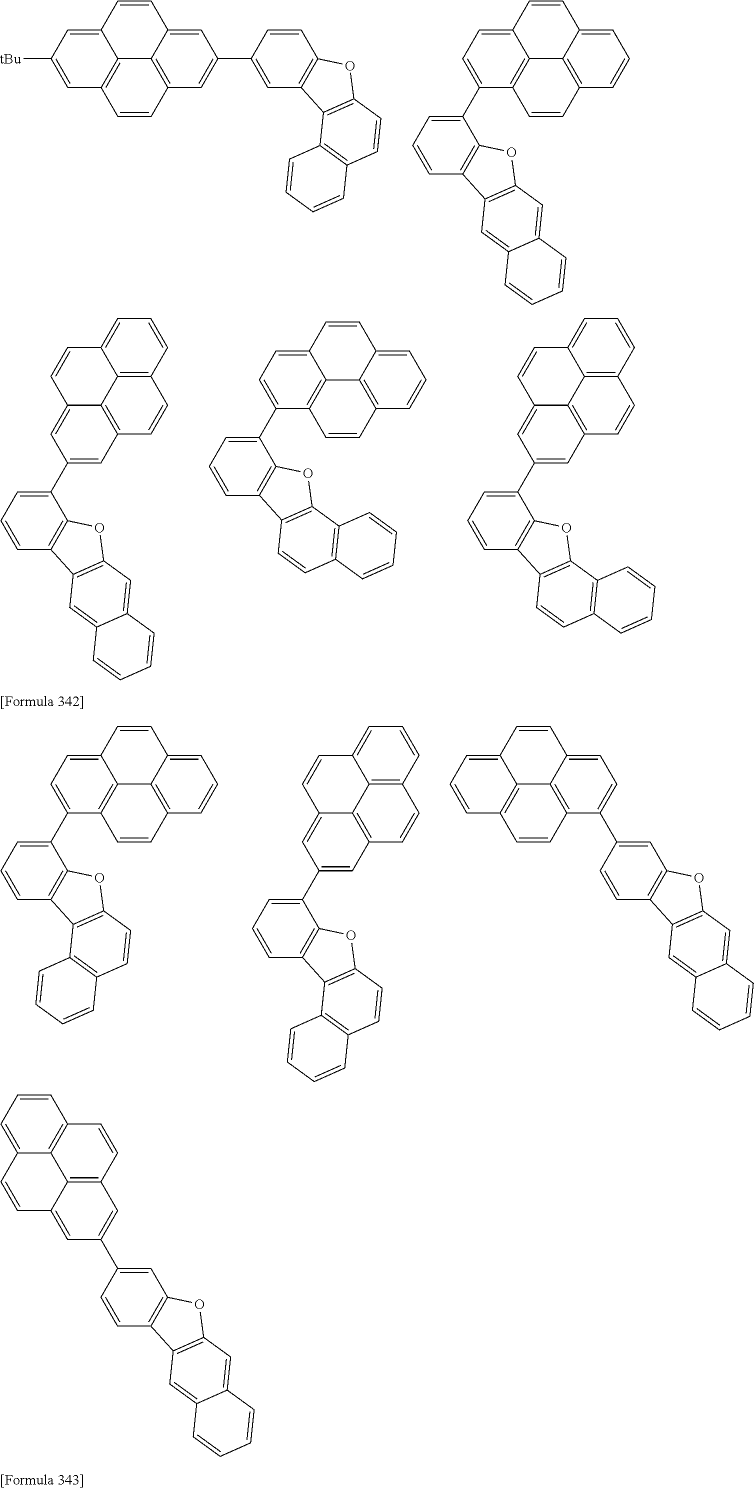

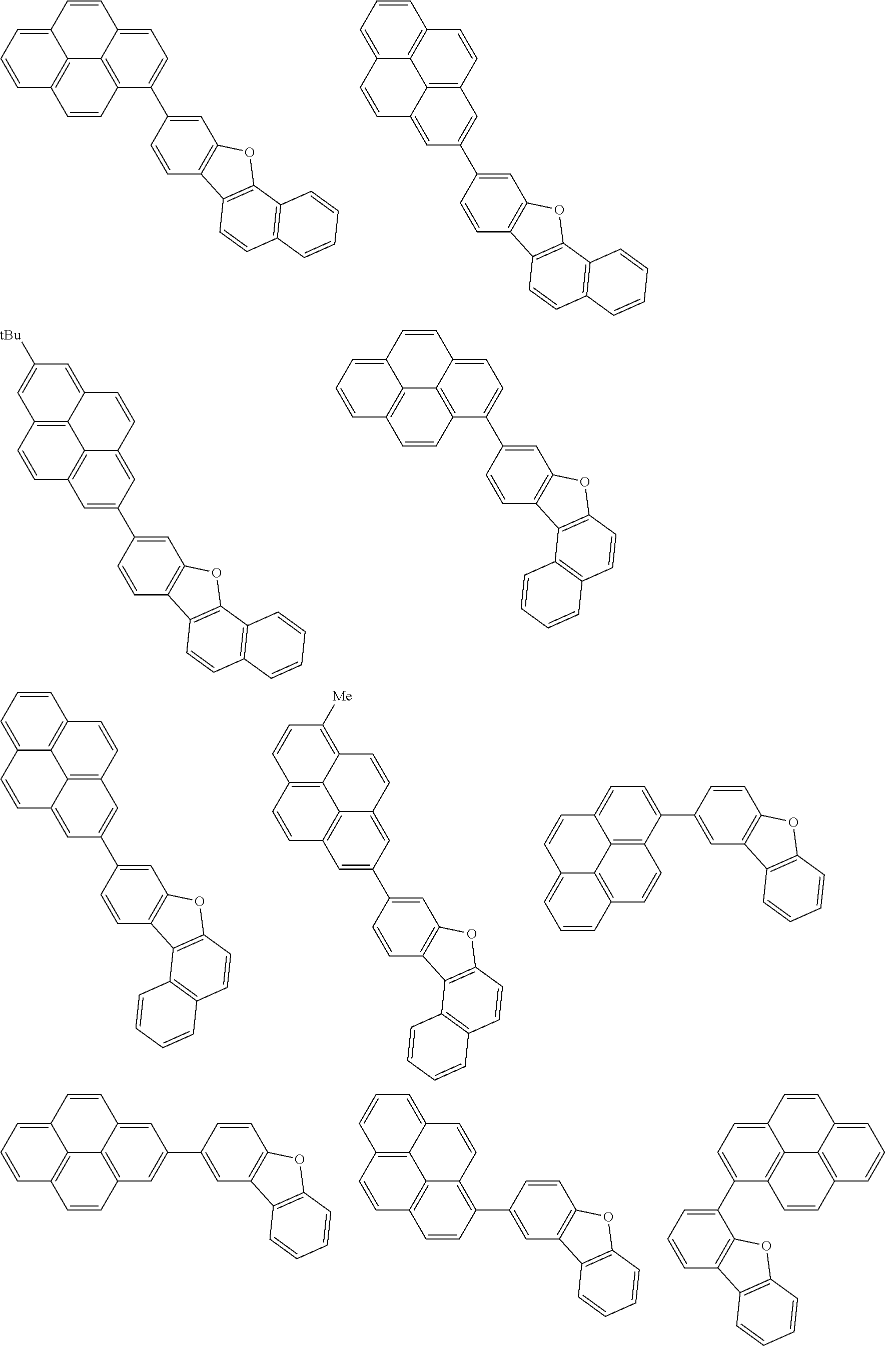

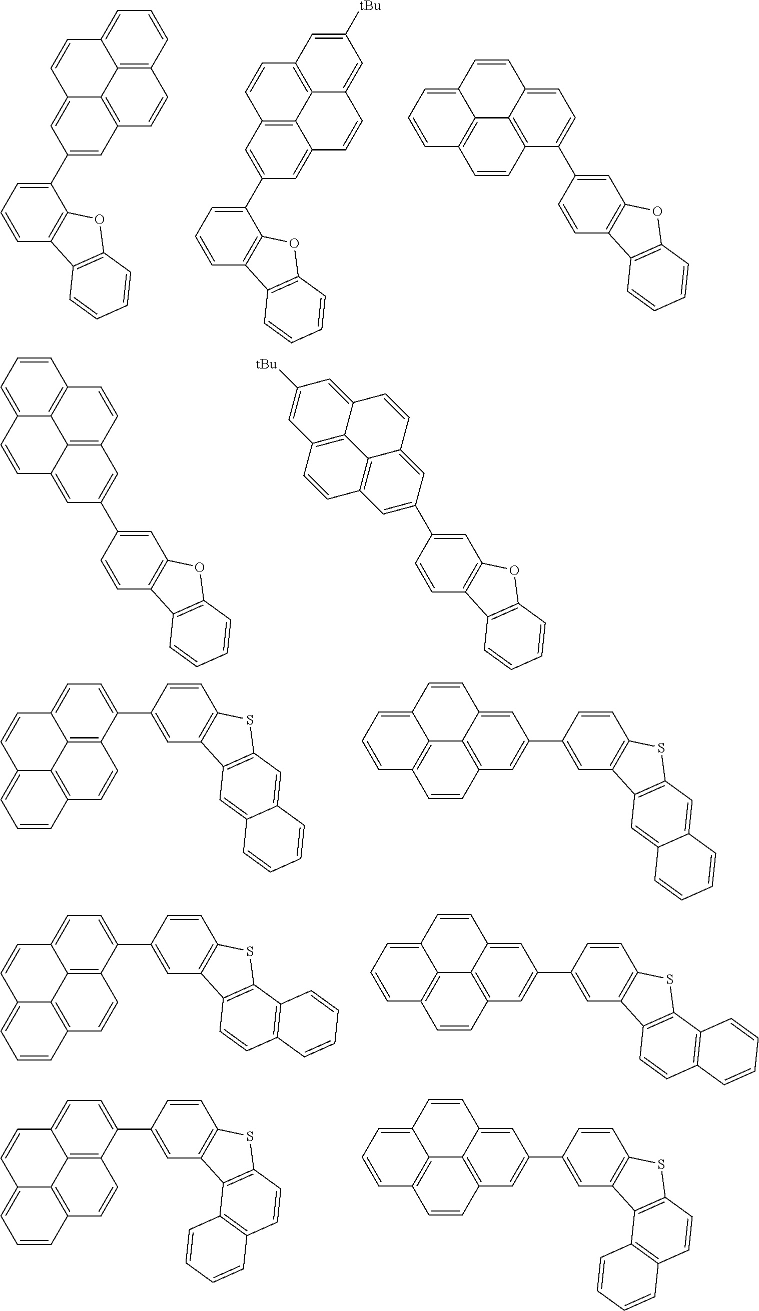

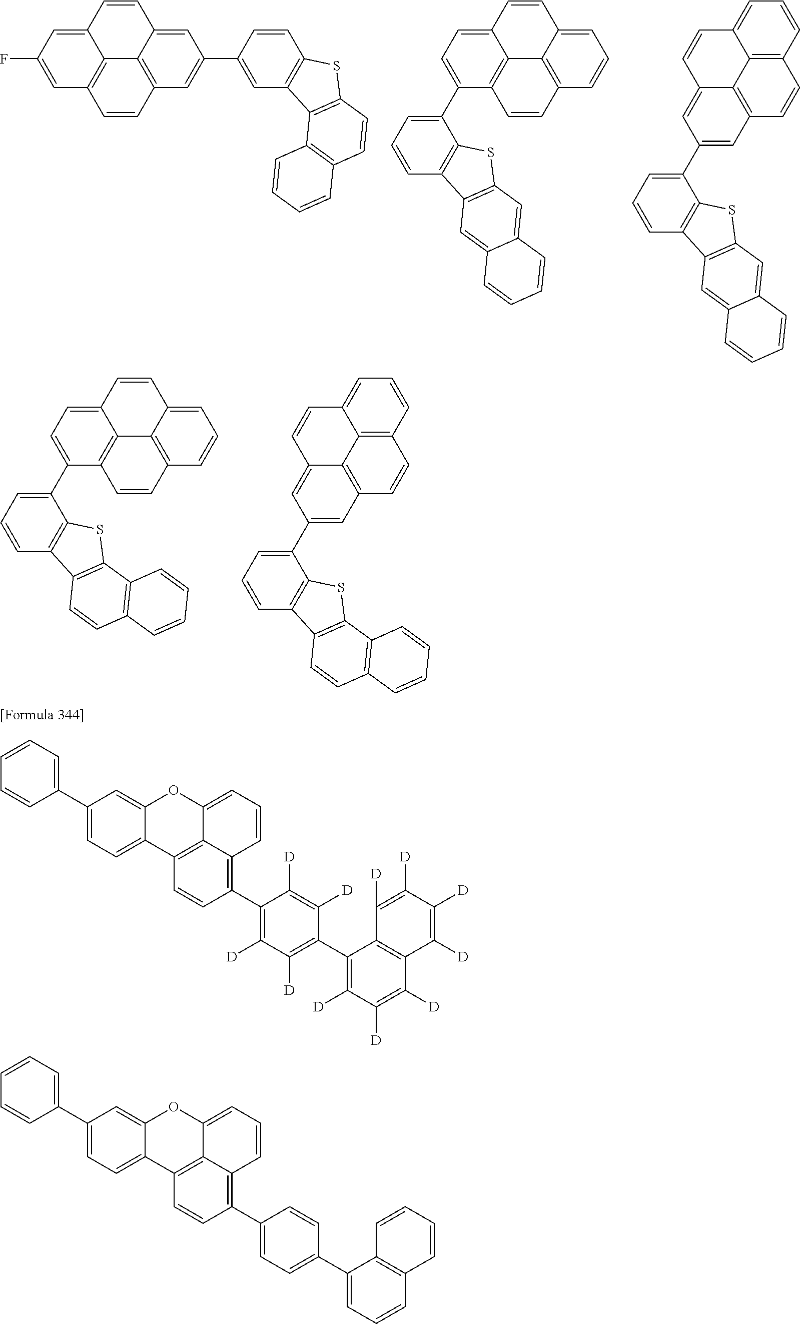

### Second Host Material

In the organic EL device according to the exemplary embodiment, the second host material, which is not particularly limited, is exemplified by a compound represented by a formula (2) below.

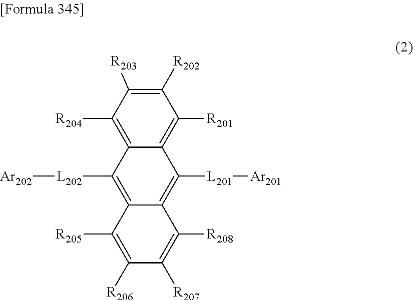

In the formula (2):
R₂₀₁ to R₂₀₈ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms;
L₂₀₁ and L₂₀₂ are each independently a single bond, a substituted or unsubstituted arylene group having 6 to 50 ring carbon atoms, or a substituted or unsubstituted divalent heterocyclic group having 5 to 50 ring atoms; and
Ar₂₀₁ and Ar₂₀₂ are each independently a substituted or unsubstituted aryl group having 6 to 50 ring carbon atoms, or a substituted or unsubstituted heterocyclic group having 5 to 50 ring atoms.

In the second host material according to the exemplary embodiment, R₉₀₁, R₉₀₂, R₉₀₃, R₉₀₄, R₉₀₅, R₉₀₆, R₉₀₇, R₈₀₁, and R₈₀₂ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;

when a plurality of R₉₀₁ are present, the plurality of R₉₀₁ are mutually the same or different;

when a plurality of R₉₀₂ are present, the plurality of R₉₀₂ are mutually the same or different;

when a plurality of R₉₀₃ are present, the plurality of R₉₀₃ are mutually the same or different;

when a plurality of R₉₀₄ are present, the plurality of R₉₀₄ are mutually the same or different;

when a plurality of R₉₀₅ are present, the plurality of R₉₀₅ are mutually the same or different;

when a plurality of R₉₀₆ are present, the plurality of R₉₀₆ are mutually the same or different;

when a plurality of R₉₀₇ are present, the plurality of R₉₀₇ are mutually the same or different;

when a plurality of R₈₀₁ are present, the plurality of R₈₀₁ are mutually the same or different; and

when a plurality of R₈₀₂ are present, the plurality of R₈₀₂ are mutually the same or different.

In the organic EL device according to the exemplary embodiment, it is preferable that:
R₂₀₁ to R₂₀₈ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₈₀₁, a group represented by —COOR₈₀₂, a halogen atom, a cyano group, or a nitro group;
L₂₀₁ and L₂₀₂ are each independently a single bond, a substituted or unsubstituted arylene group having 6 to 50 ring carbon atoms, or a substituted or unsubstituted divalent heterocyclic group having 5 to 50 ring atoms; and
Ar₂₀₁ and Ar₂₀₂ are each independently a substituted or unsubstituted aryl group having 6 to 50 ring carbon atoms, or a substituted or unsubstituted heterocyclic group having 5 to 50 ring atoms.

In the organic EL device according to the exemplary embodiment, it is preferable that:
L₂₀₁ and L₂₀₂ are each independently a single bond, or a substituted or unsubstituted arylene group having 6 to 50 ring carbon atoms; and
Ar₂₀₁ and Ar₂₀₂ are each independently a substituted or unsubstituted aryl group having 6 to 50 ring carbon atoms.

In the organic EL device according to the exemplary embodiment, it is preferable that: Ar₂₀₁ and Ar₂₀₂ are each independently a phenyl group, naphthyl group, phenanthryl group, biphenyl group, terphenyl group, diphenylfluorenyl group, dimethylfluorenyl group, benzodiphenylfluorenyl group, benzodimethylfluorenyl group, dibenzofuranyl group, dibenzothienyl group, naphthobenzofuranyl group, or naphthobenzothienyl group.

In the organic EL device according to the exemplary embodiment, the second host material represented by the formula (2) is preferably a compound represented by a formula (201), a formula (202), a formula (203), a formula (204), a formula (205), a formula (206), a formula (207), a formula (208), or a formula (209) below.

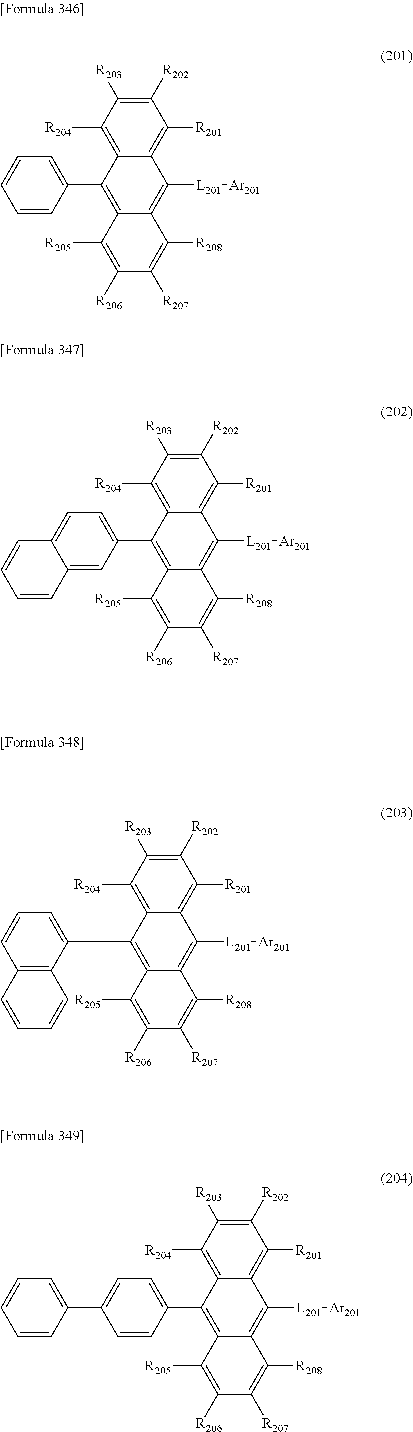

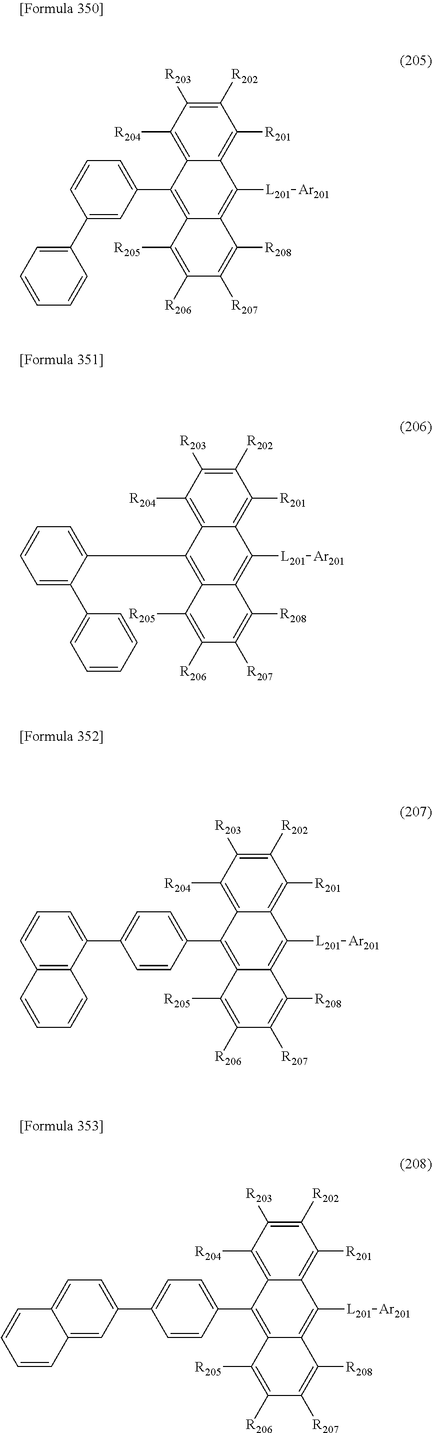

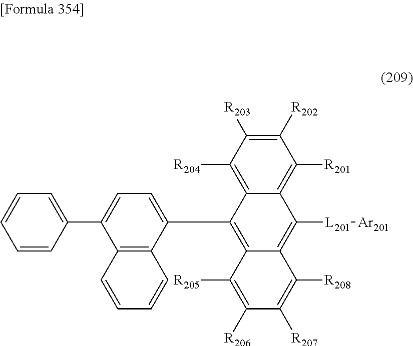

In the formulae (201) to (209):
L₂₀₁ and Ar₂₀₁ represent the same as L₂₀₁ and Ar₂₀₁ in the formula (2); and
R₂₀₁ to R₂₀₈ each independently represent the same as R₂₀₁ to R₂₀₈ in the formula (2).

The second host material represented by the formula (2) is also preferably a compound represented by a formula (221), a formula (222), a formula (223), a formula (224), a formula (225), a formula (226), a formula (227), a formula (228), or a formula (229) below.

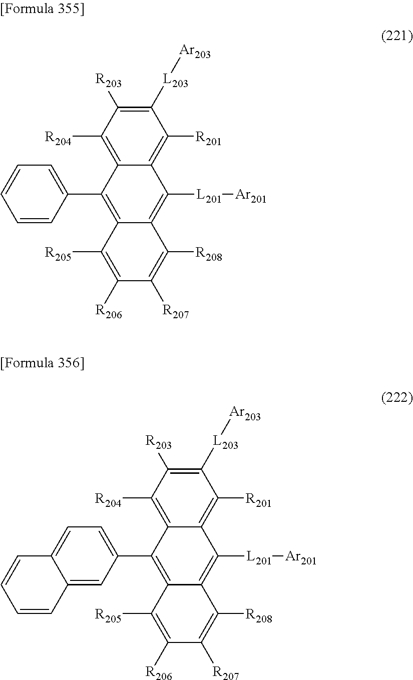

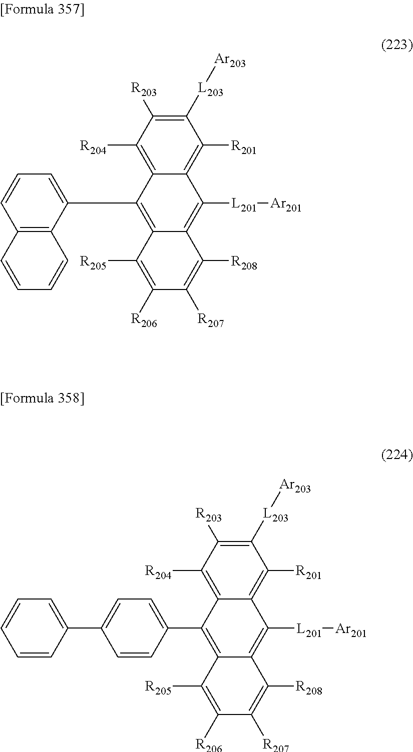

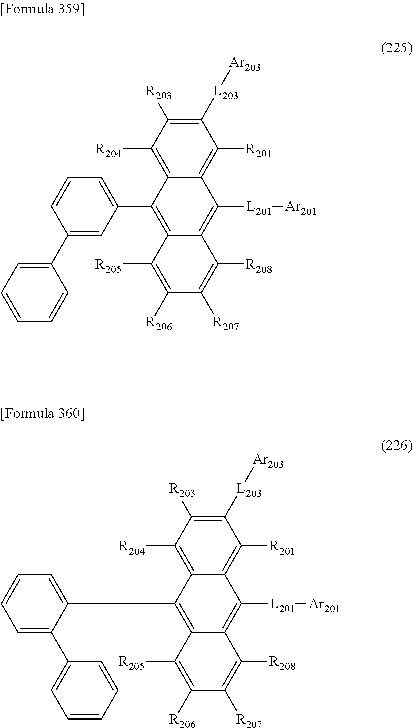

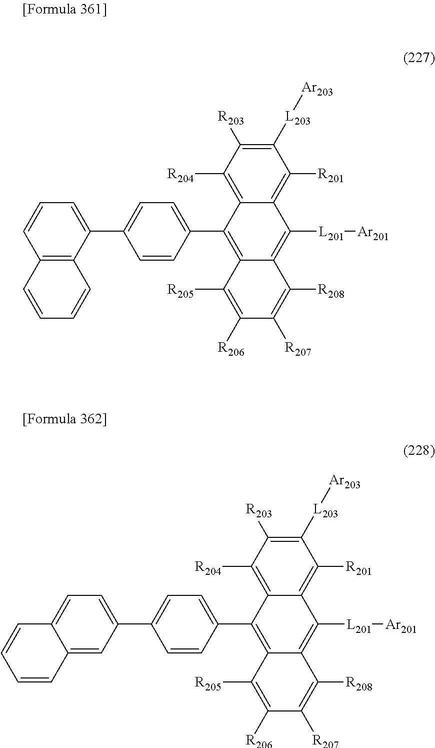

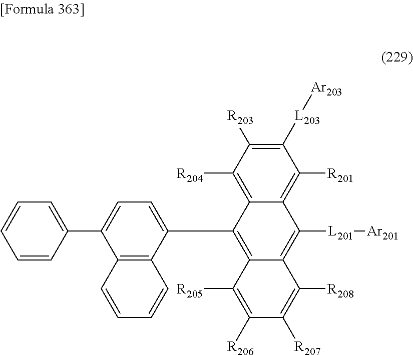

In the formulae (221), (222), (223), (224), (225), (226), (227), (228), and (229):
R₂₀₁ and R₂₀₃ to R₂₀₈ each independently represent the same as R₂₀₁ and R₂₀₃ to R₂₀₈ in the formula (2);

L₂₀₁ and Ar₂₀₁ respectively represent the same as L₂₀₁ and Ar₂₀₁ in the formula (2);
L₂₀₃ represents the same as L₂₀₁ in the formula (2);
L₂₀₃ and L₂₀₁ are mutually the same or different;
Ar₂₀₃ represents the same as Ar₂₀₁ in the formula (2); and
Ar₂₀₃ and Ar₂₀₁ are mutually the same or different.

The second host material represented by the formula (2) is also preferably a compound represented by a formula (241), a formula (242), a formula (243), a formula (244), a formula (245), a formula (246), a formula (247), a formula (248), or a formula (249) below.

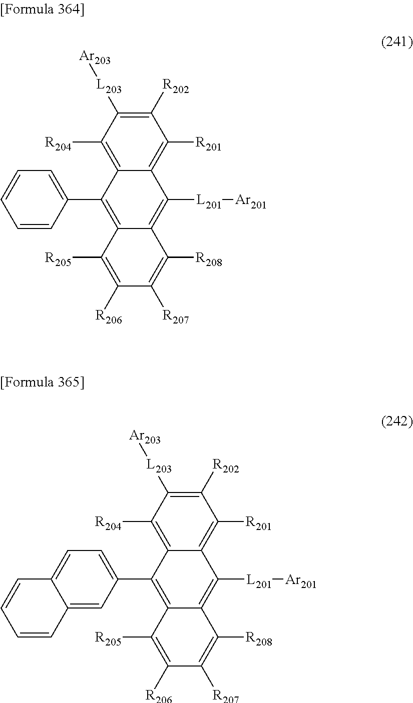

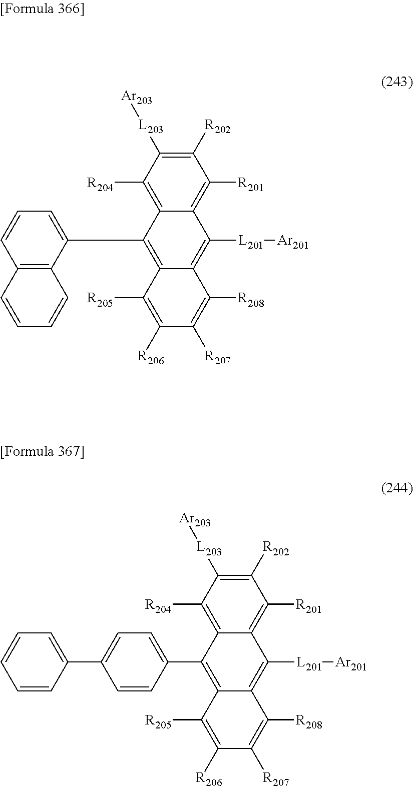

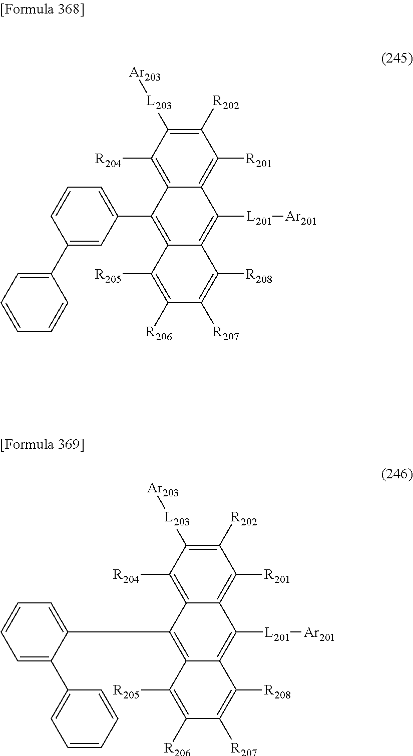

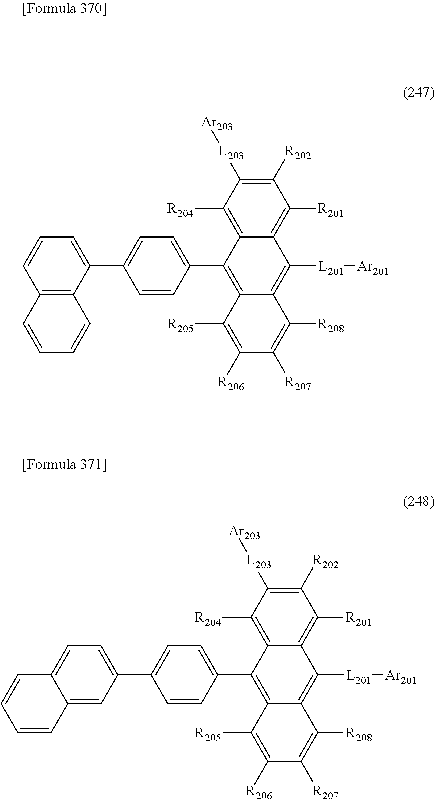

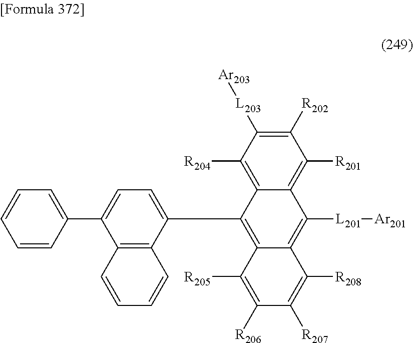

In the formulae (241), (242), (243), (244), (245), (246), (247), (248), and (249):
R₂₀₁, R₂₀₂ and R₂₀₄ to R₂₀₈ each independently represent the same as R₂₀₁, R₂₀₂ and R₂₀₄ to R₂₀₈ in the formula (2);
L₂₀₁ and Ar₂₀₁ respectively represent the same as L₂₀₁ and Ar₂₀₁ in the formula (2);
L₂₀₃ represents the same as L₂₀₁ in the formula (2);
L₂₀₃ and L₂₀₁ are mutually the same or different;
Ar₂₀₃ represents the same as Ar₂₀₁ in the formula (2); and
Ar₂₀₃ and Ar₂₀₁ are mutually the same or different.

In the second host material represented by the formula (2), R₂₀₁ to R₂₀₈ are preferably each independently a hydrogen atom, a substituted or unsubstituted alkyl group having 1 to 50 carbon atoms, a substituted or unsubstituted cycloalkyl group having 3 to 50 ring carbon atoms, or a group represented by —Si(R₉₀₁)(R₉₀₂)(R₉₀₃).

L₂₀₁ is preferably a single bond, or an unsubstituted arylene group having 6 to 22 ring carbon atoms; and

Ar₂₀₁ is preferably a substituted or unsubstituted aryl group having 6 to 22 ring carbon atoms.

In the organic EL device according to the exemplary embodiment, R₂₀₁ to R₂₀₈ that are substituents of an anthracene skeleton in the second host material represented by the formula (2) are each preferably a hydrogen atom in terms of preventing inhibition of intermolecular interaction and inhibiting decrease in electron mobility. However, R₂₀₁ to R₂₀₈ may each be a substituted or unsubstituted aryl group having 6 to 50 ring carbon atoms or a substituted or unsubstituted heterocyclic group having 5 to 50 ring atoms.

Assuming that R₂₀₁ to R₂₀₈ are each a bulky substituent such as an alkyl group and a cycloalkyl group, intermolecular interaction may be inhibited. It should be noted that substituents, namely, a haloalkyl group, alkenyl group, alkynyl group, group represented by —Si(R₉₀₁)(R₉₀₂)(R₉₀₃), group represented by —O—(R₉₀₄), group represented by —S—(R₉₀₅), group represented by —N(R₉₀₆)(R₉₀₇), aralkyl group, group represented by —C(═O)R₈₀₁, group represented by —COOR₈₀₂, halogen atom, cyano group, and nitro group are likely to be bulky, and an alkyl group and cycloalkyl group are likely to be further bulky.

In the second host material represented by the formula (2), R₂₀₁ to R₂₀₈, which are the substituents on the anthracene skeleton, are each preferably not a bulky substituent and preferably not an alkyl group and cycloalkyl group. More preferably, R₂₀₁ to R₂₀₈ are each not an alkyl group, cycloalkyl group, haloalkyl group, alkenyl group, alkynyl group, group represented by —Si(R₉₀₁)(R₉₀₂)(R₉₀₃), group represented by —O—(R₉₀₄), group represented by —S—(R₉₀₅), group represented by —N(R₉₀₆)(R₉₀₇), aralkyl group, group represented by —C(═O)R₈₀₁, group represented by —COOR₈₀₂, halogen atom, cyano group, and nitro group.

In the organic EL device according to the exemplary embodiment, also preferably, R₂₀₁ to R₂₀₈ in the second host material represented by the formula (2) are each independently a hydrogen atom, a substituted or unsubstituted alkyl group having 1 to 50 carbon atoms, a substituted or unsubstituted cycloalkyl group having 3 to 50 ring carbon atoms, or a group represented by —Si(R₉₀₁)(R₉₀₂)(R₉₀₃).

In the organic EL device according to the exemplary embodiment, R₂₀₁ to R₂₀₈ in the second host material represented by the formula (2) are each preferably a hydrogen atom.

In the second host material, examples of the substituent for the “substituted or unsubstituted” group on R₂₀₁ to R₂₀₈ also preferably do not include the above-described substituent that is likely to be bulky, especially a substituted or unsubstituted alkyl group and a substituted or unsubstituted cycloalkyl group. When examples of the substituent for the “substituted or unsubstituted” group on R₂₀₁ to R₂₀₈ do not include a substituted or unsubstituted alkyl group and a substituted or unsubstituted cycloalkyl group, the inhibition of intermolecular interaction to be caused by the presence of a bulky substituent such as an alkyl group and a cycloalkyl group can be prevented, thereby preventing a decrease in the electron mobility. Moreover, when the second host material described above is used in the second emitting layer, a decrease in a recombination ability between holes and electrons in the first emitting layer and a decrease in the luminous efficiency can be inhibited.

Further preferably, R₂₀₁ to R₂₀₈ that are the substituents on the anthracene skeleton are not bulky substituents and R₂₀₁ to R₂₀₈ as substituents are unsubstituted. Assuming that R₂₀₁ to R₂₀₈ that are the substituents on the anthracene skeleton are not bulky substituents and substituents are bonded to R₂₀₁ to R₂₀₈ that are not bulky substituents, the substituents bonded to R₂₀₁ to R₂₀₈ are preferably not bulky substituents; and the substituents bonded to R₂₀₁ to R₂₀₈ serving as substituents are preferably not an alkyl group and cycloalkyl group, more preferably not an alkyl group, cycloalkyl group, haloalkyl group, alkenyl group, alkynyl group, group represented by —Si(R₉₀₁)(R₉₀₂)(R₉₀₃), group represented by —O—(R₉₀₄), group represented by —S—(R₉₀₅), group represented by —N(R₉₀₆)(R₉₀₇), aralkyl group, group represented by —C(═O)R₈₀₁, group represented by —COOR₈₀₂, halogen atom, cyano group, and nitro group.

In the second host material, the groups specified to be “substituted or unsubstituted” are each preferably an unsubstituted group.

### Method for Producing Second Host Material

The second host material can be produced by a known method. The second host material can also be produced based on a known method through a known alternative reaction using a known material(s) tailored for the target compound.

### Specific Example of Second Host Material

Specific examples of the second host material include compounds below. However, the invention is by no means limited to the specific examples of the second host material.

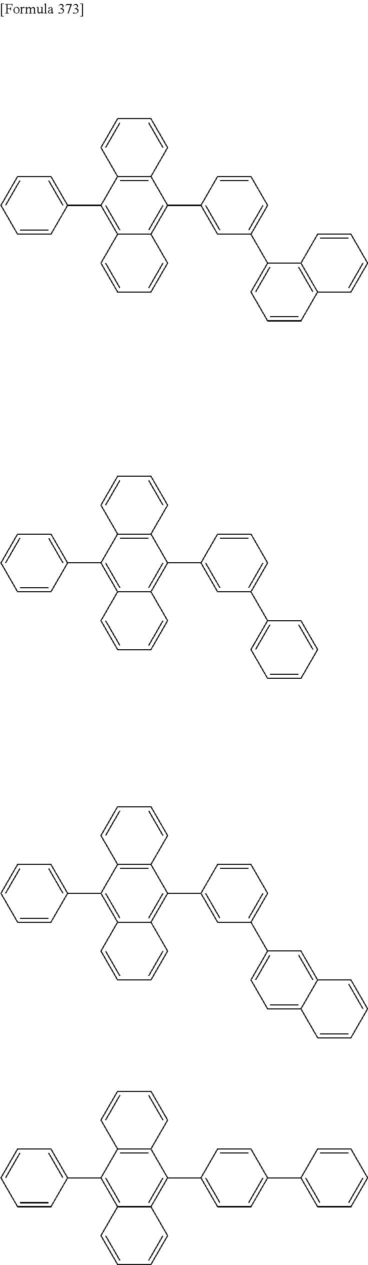

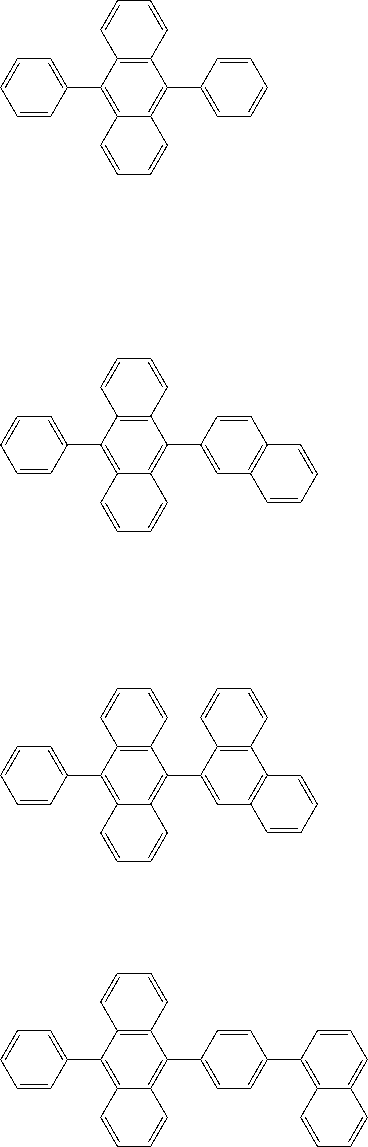

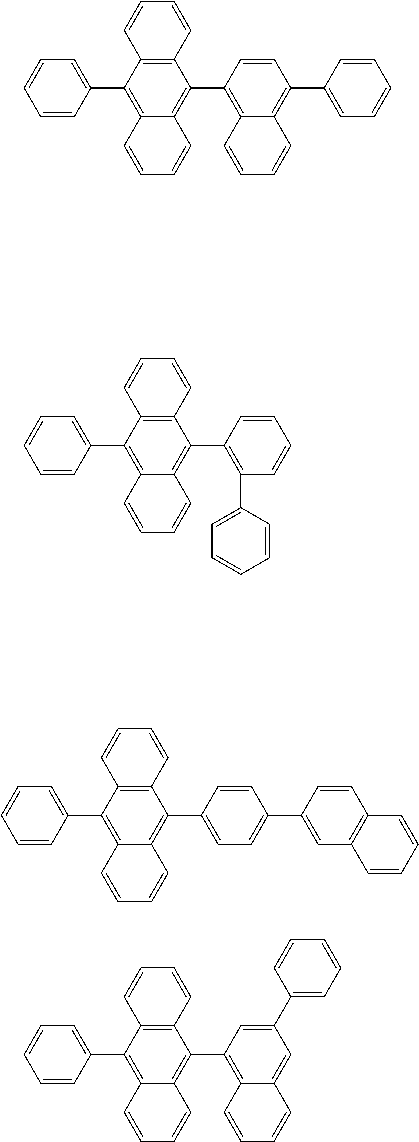

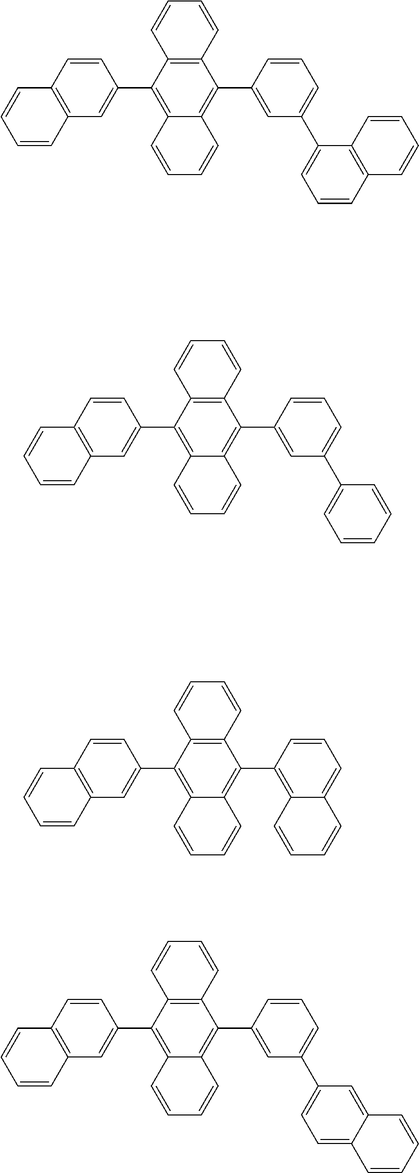

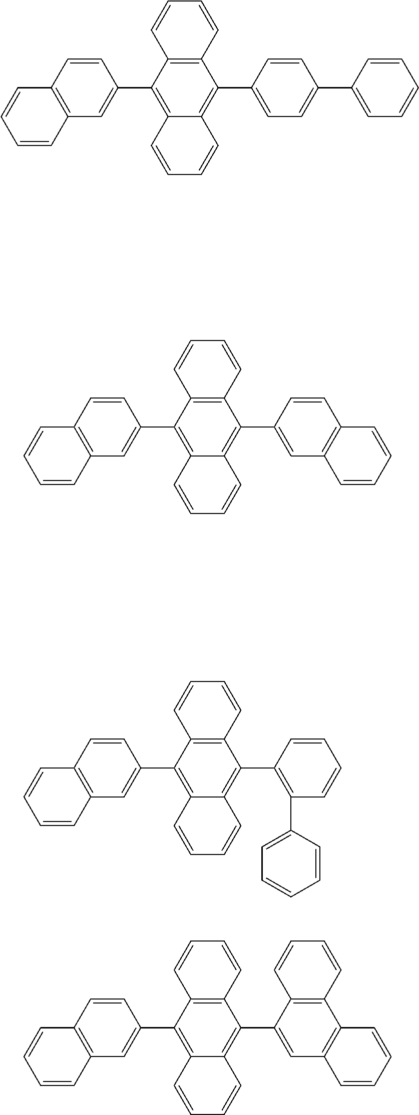

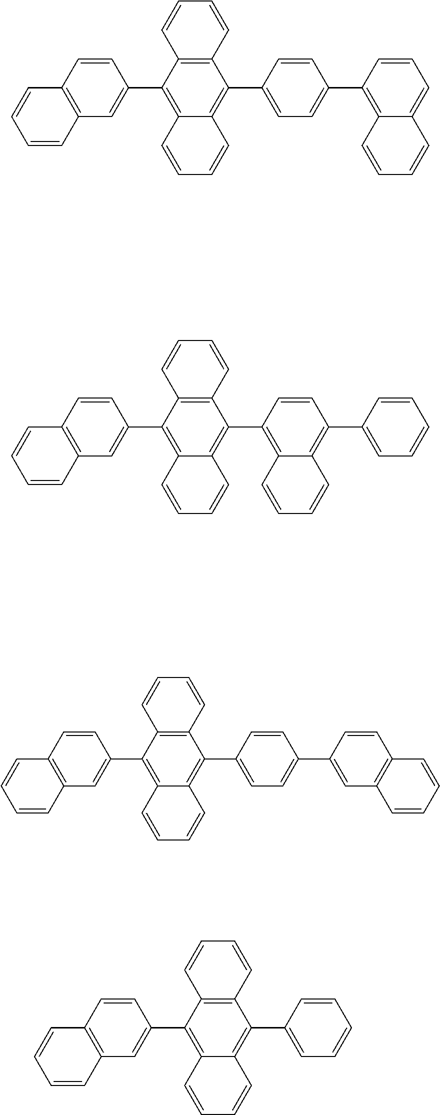

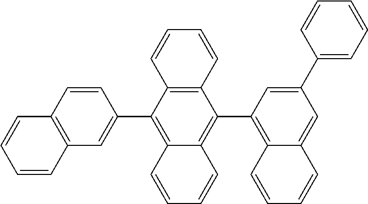 [SMILES: c1ccc(-c2cc(-c3c4ccccc4c(-c4ccc5ccccc5c4)c4ccccc34)c3ccccc3c2)cc1]

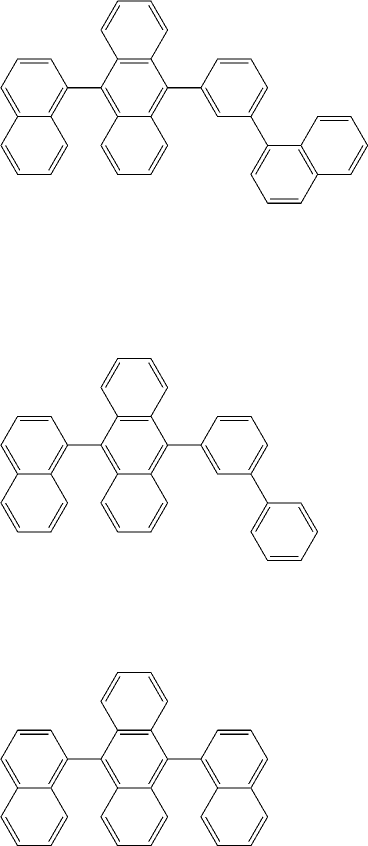

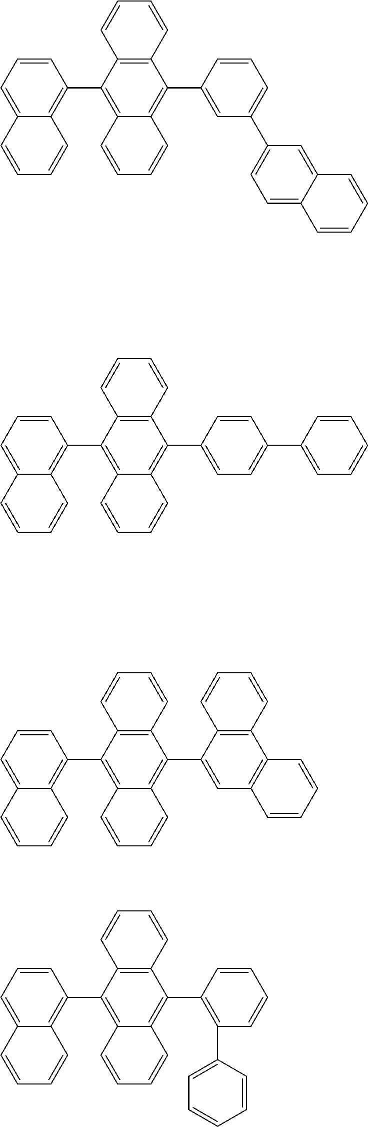

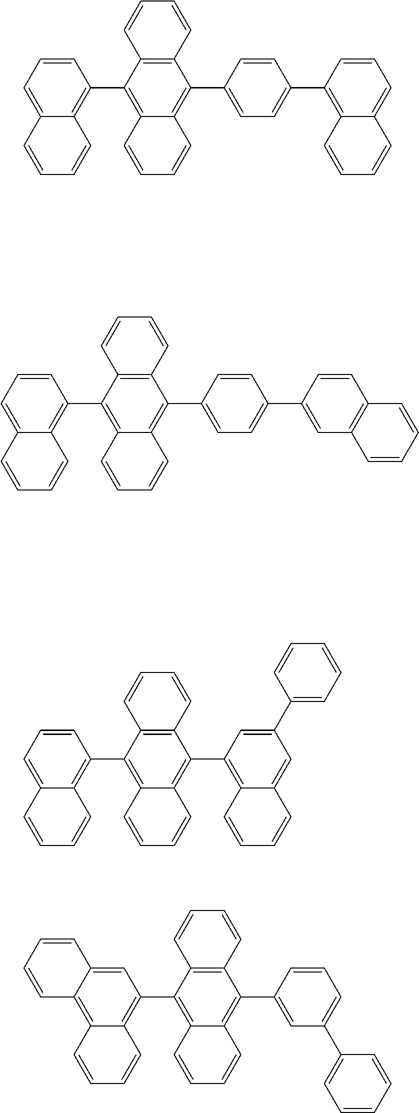

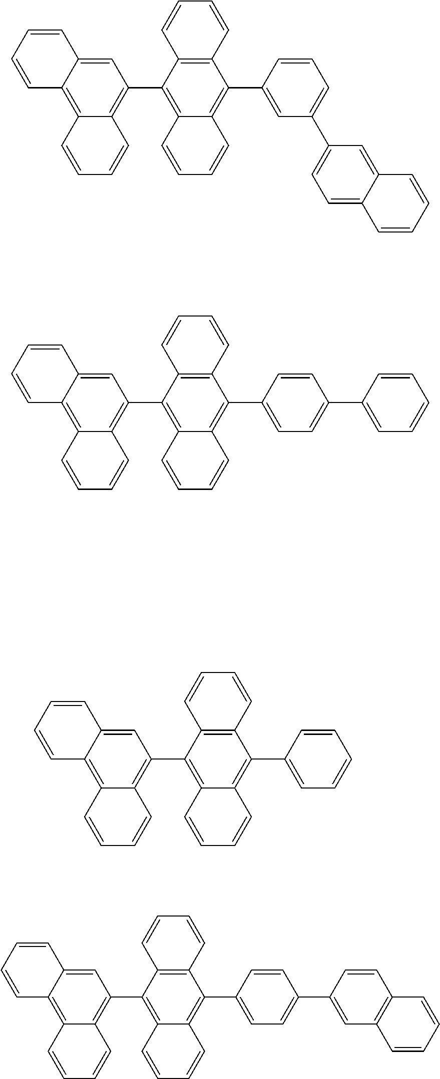

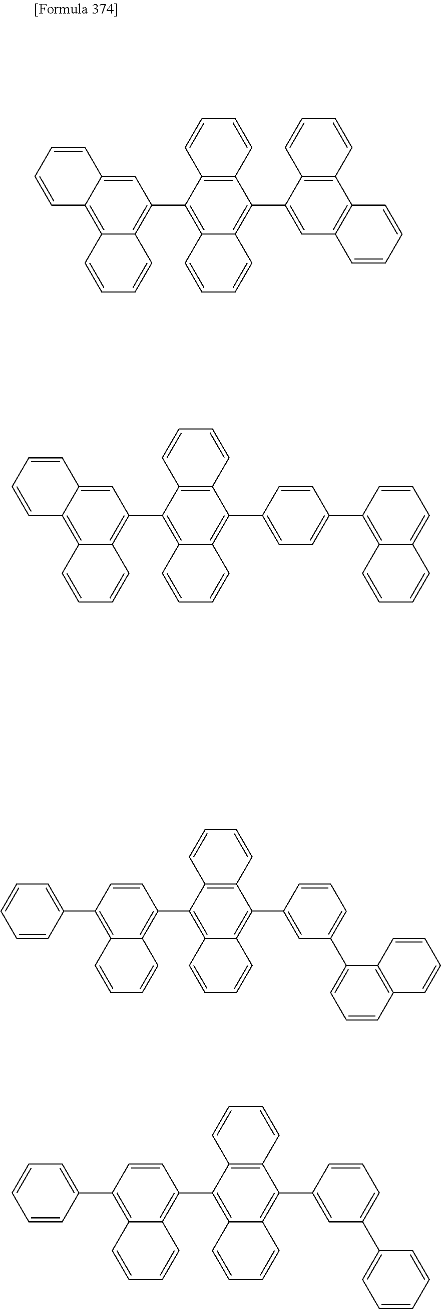

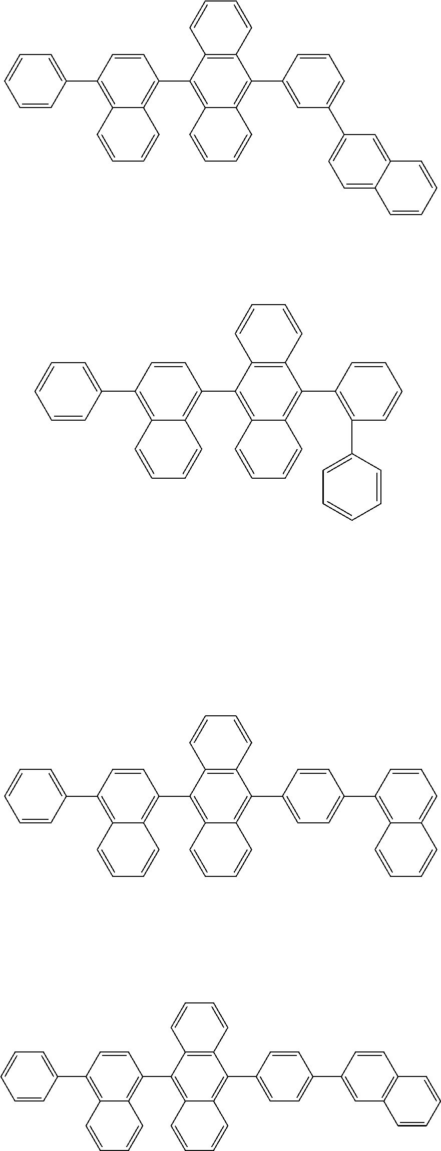

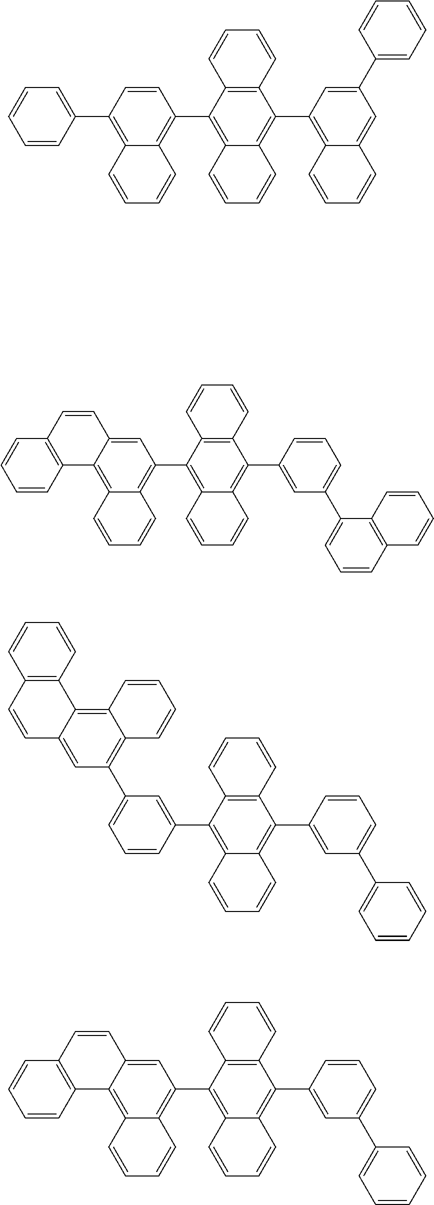

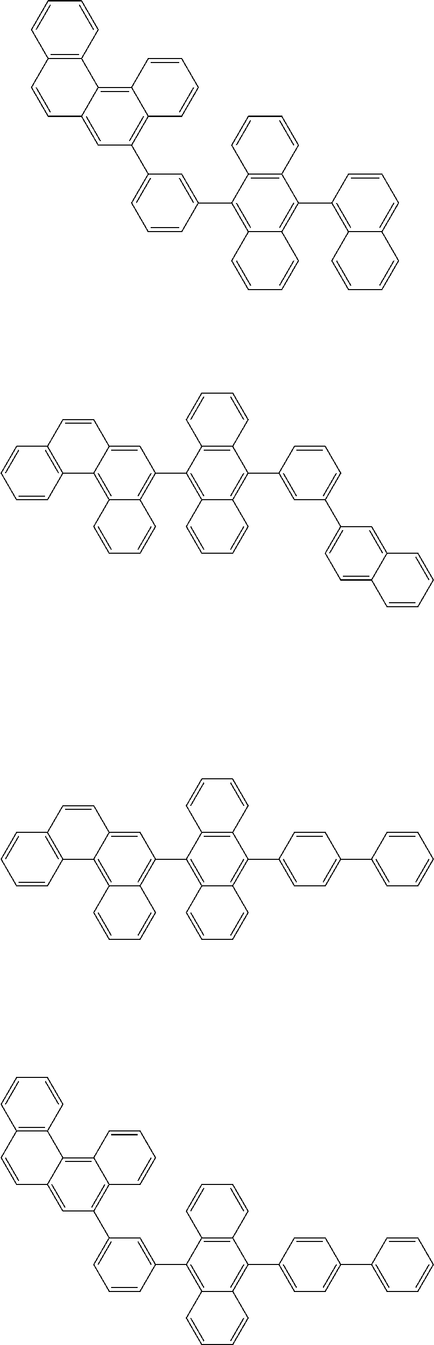

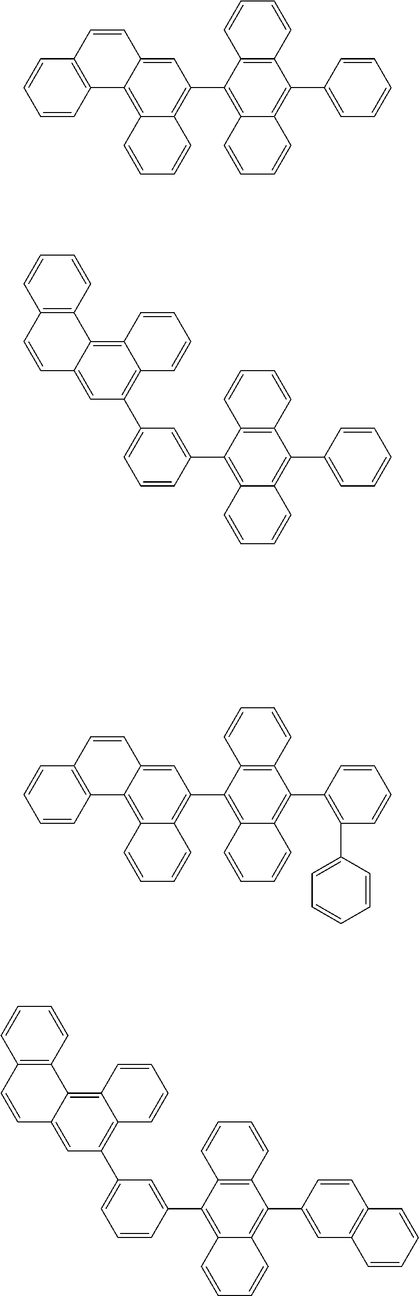

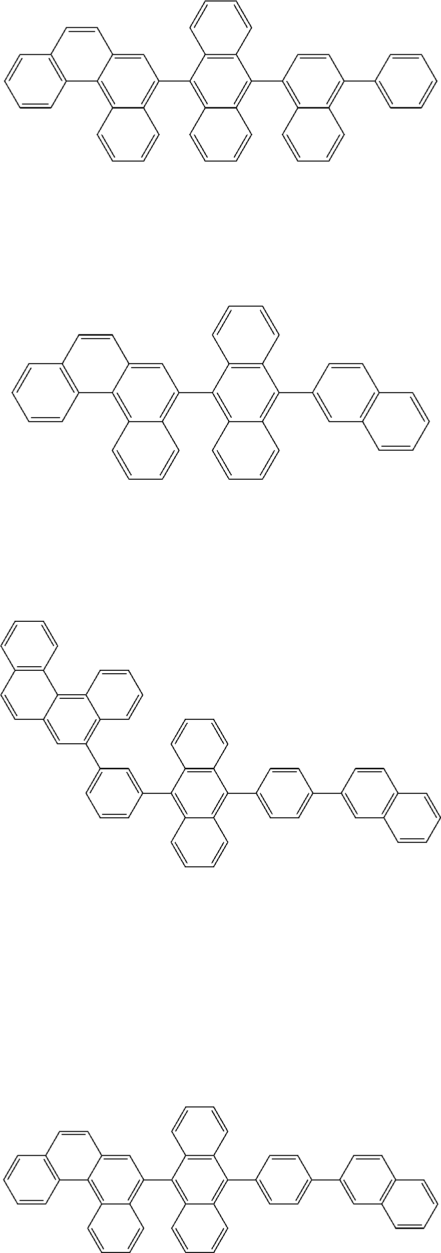

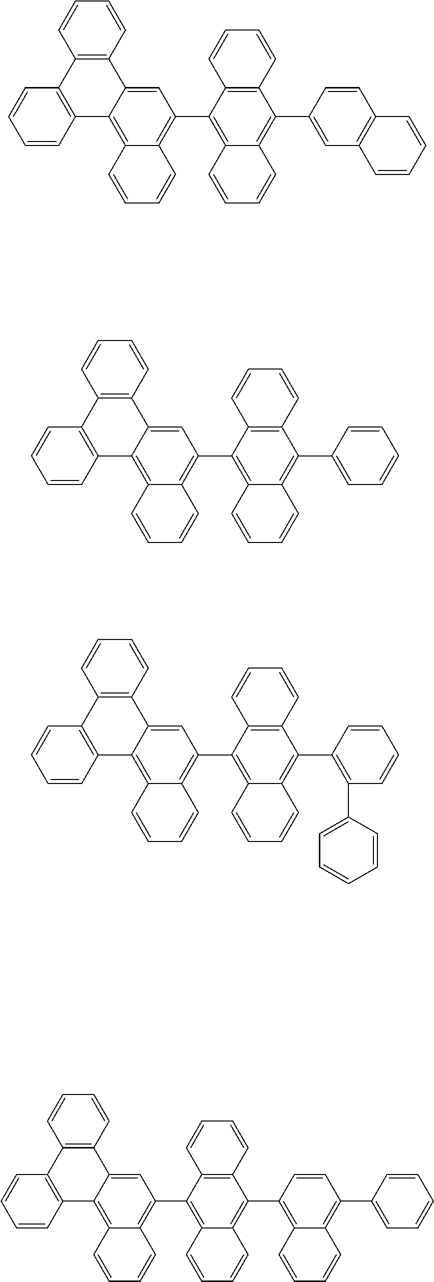

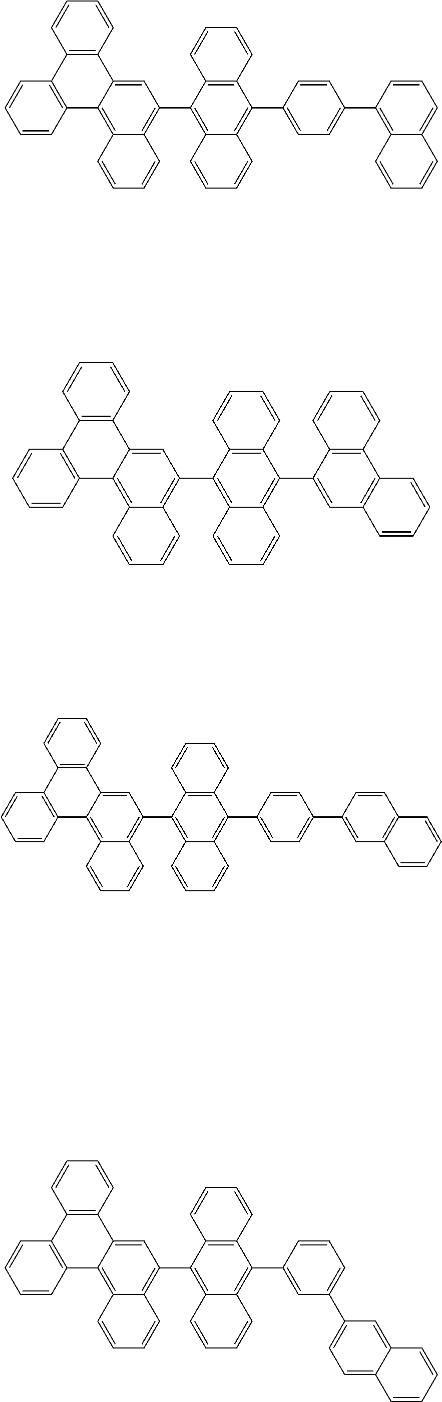

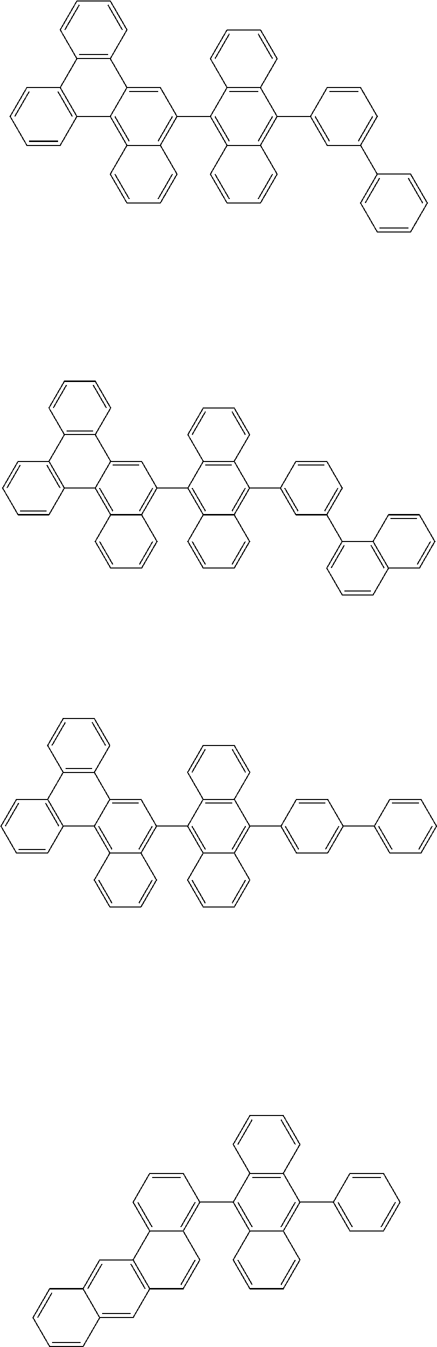

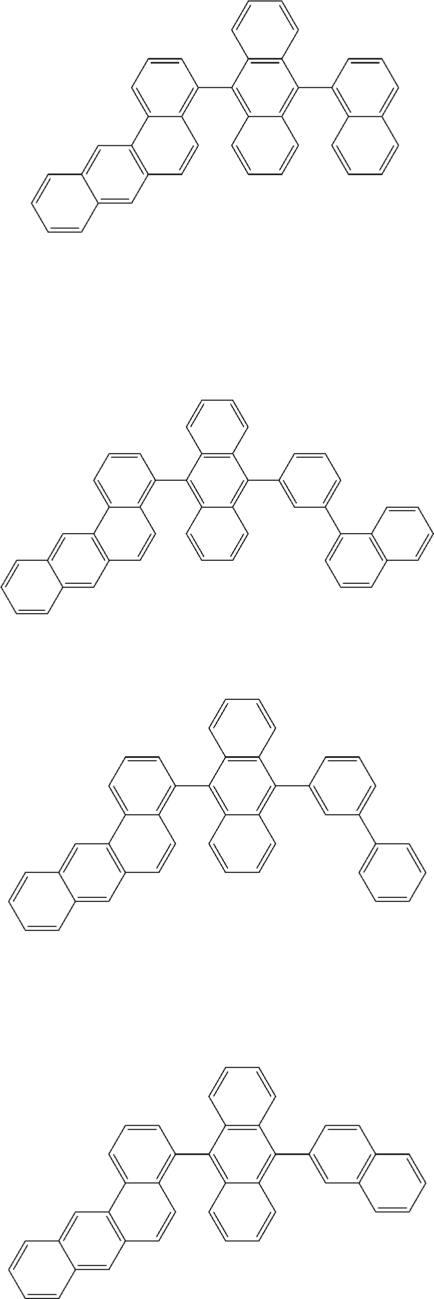

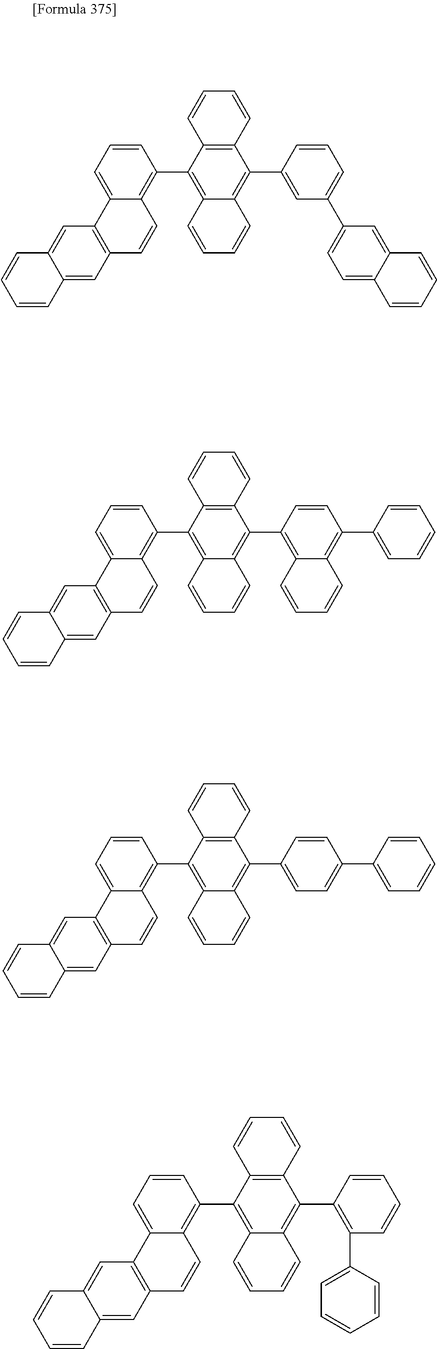

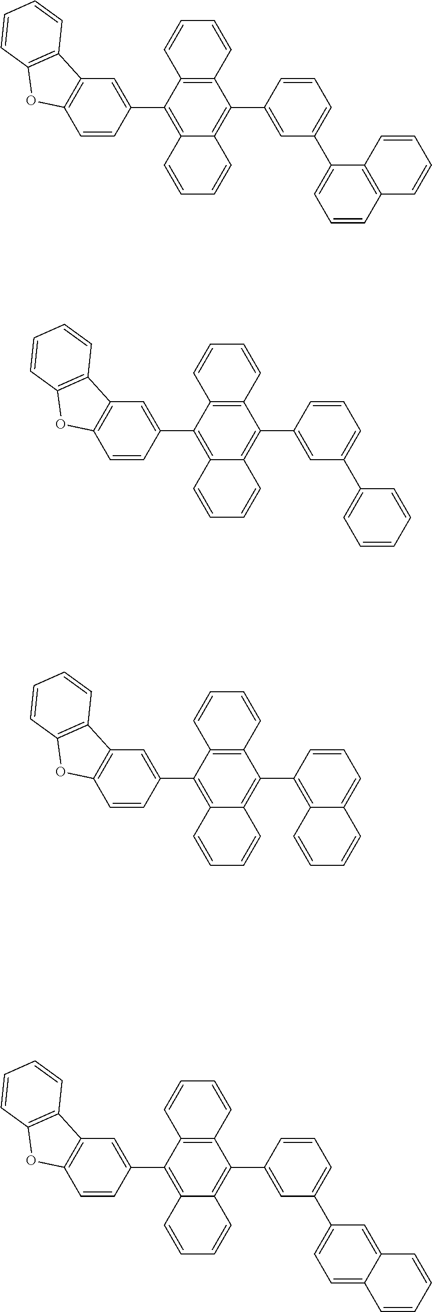 [SMILES: c1cc(-c2cccc3ccccc23)cc(-c2c3ccccc3c(-c3ccc4oc5ccccc5c4c3)c3ccccc23)c1 ; c1ccc(-c2cccc(-c3c4ccccc4c(-c4ccc5oc6ccccc6c5c4)c4ccccc34)c2)cc1 ; c1ccc2c(-c3c4ccccc4c(-c4ccc5oc6ccccc6c5c4)c4ccccc34)cccc2c1 ; c1cc(-c2ccc3ccccc3c2)cc(-c2c3ccccc3c(-c3ccc4oc5ccccc5c4c3)c3ccccc23)c1]

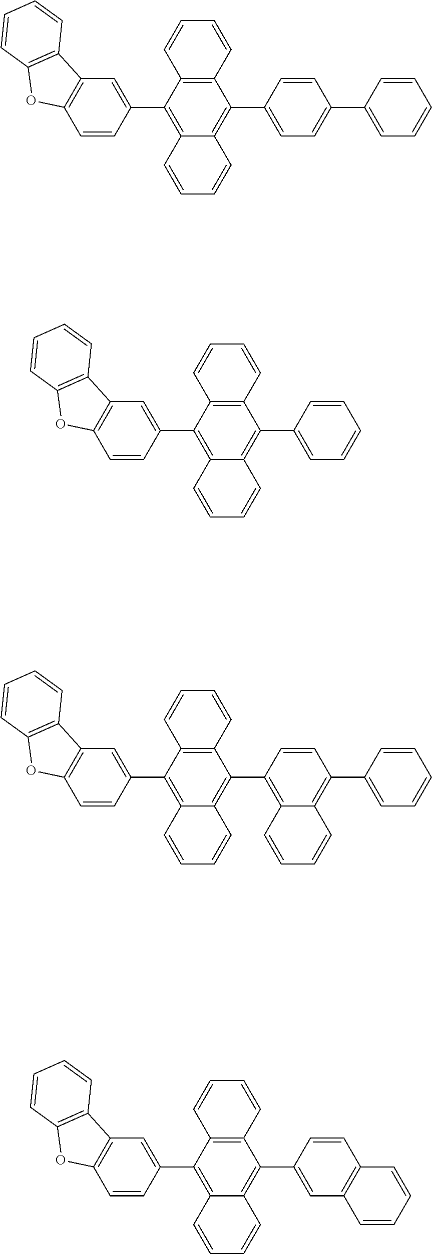 [SMILES: c1ccc(-c2ccc(-c3c4ccccc4c(-c4ccc5oc6ccccc6c5c4)c4ccccc34)cc2)cc1 ; c1ccc(-c2c3ccccc3c(-c3ccc4oc5ccccc5c4c3)c3ccccc23)cc1 ; c1ccc(-c2ccc(-c3c4ccccc4c(-c4ccc5oc6ccccc6c5c4)c4ccccc34)c3ccccc23)cc1 ; c1ccc2cc(-c3c4ccccc4c(-c4ccc5oc6ccccc6c5c4)c4ccccc34)ccc2c1]

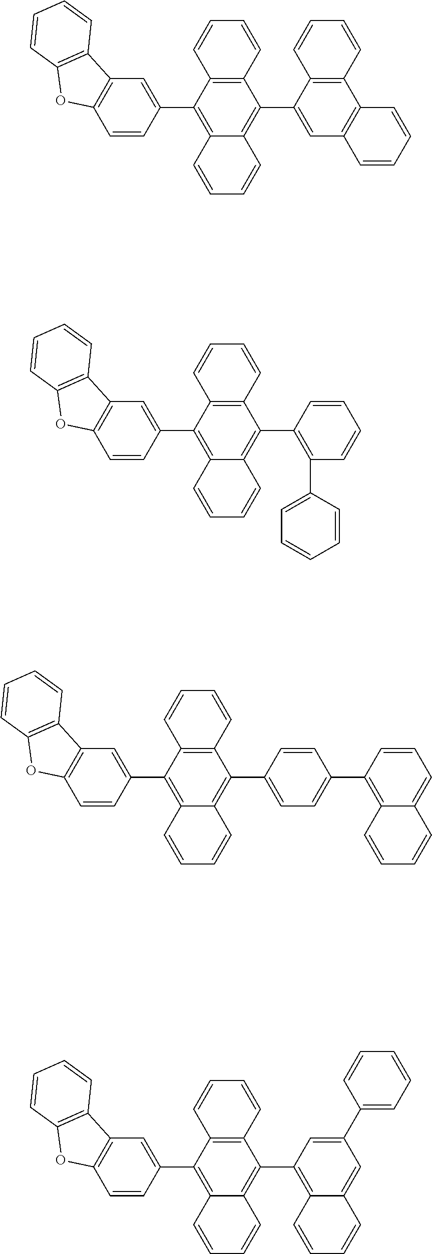 [SMILES: c1ccc2c(c1)cc(-c1c3ccccc3c(-c3ccc4oc5ccccc5c4c3)c3ccccc13)c1ccccc12 ; c1ccc(-c2ccccc2-c2c3ccccc3c(-c3ccc4oc5ccccc5c4c3)c3ccccc23)cc1 ; c1ccc2c(-c3ccc(-c4c5ccccc5c(-c5ccc6oc7ccccc7c6c5)c5ccccc45)cc3)cccc2c1 ; c1ccc(-c2cc(-c3c4ccccc4c(-c4ccc5oc6ccccc6c5c4)c4ccccc34)c3ccccc3c2)cc1]

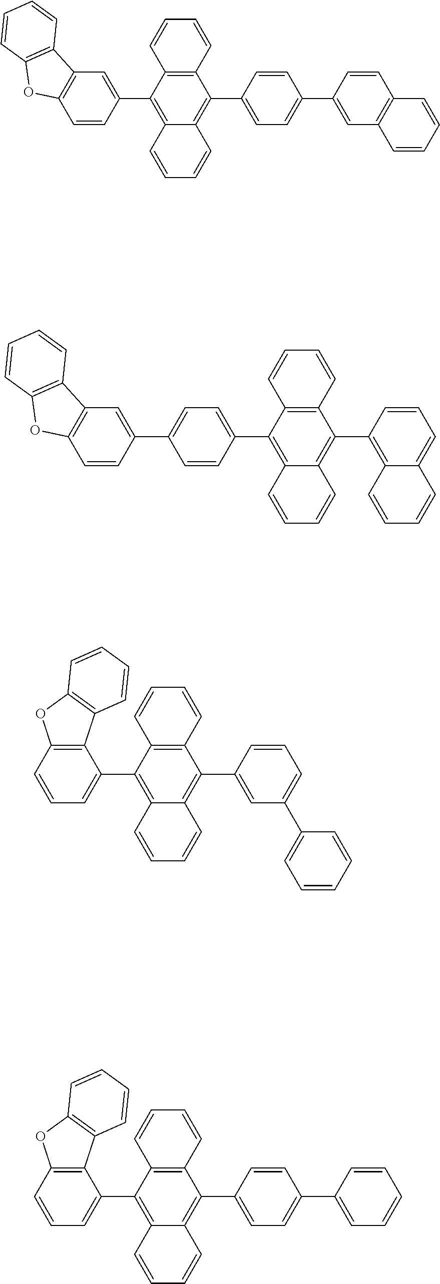 [SMILES: c1ccc2cc(-c3ccc(-c4c5ccccc5c(-c5ccc6oc7ccccc7c6c5)c5ccccc45)cc3)ccc2c1 ; c1ccc2c(-c3c4ccccc4c(-c4ccc(-c5ccc6oc7ccccc7c6c5)cc4)c4ccccc34)cccc2c1 ; c1ccc(-c2cccc(-c3c4ccccc4c(-c4cccc5oc6ccccc6c45)c4ccccc34)c2)cc1 ; c1ccc(-c2ccc(-c3c4ccccc4c(-c4cccc5oc6ccccc6c45)c4ccccc34)cc2)cc1]

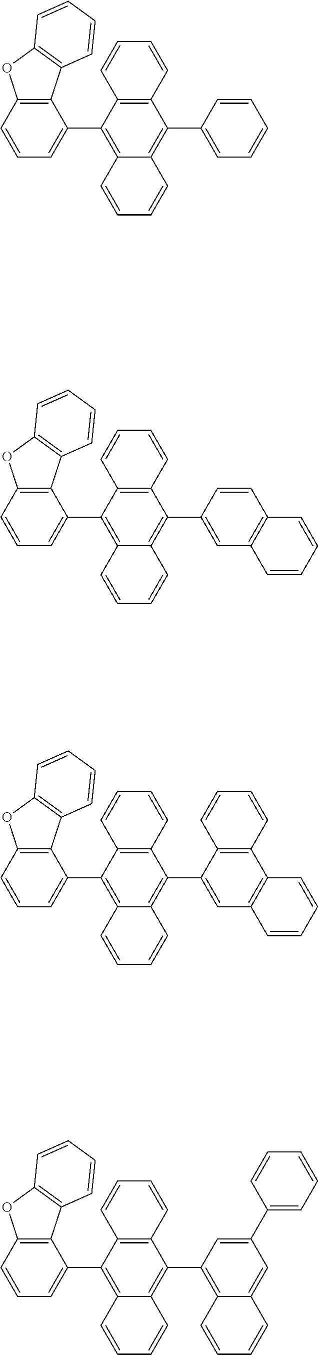 [SMILES: c1ccc(-c2c3ccccc3c(-c3cccc4oc5ccccc5c34)c3ccccc23)cc1 ; c1ccc2cc(-c3c4ccccc4c(-c4cccc5oc6ccccc6c45)c4ccccc34)ccc2c1 ; c1ccc2c(c1)cc(-c1c3ccccc3c(-c3cccc4oc5ccccc5c34)c3ccccc13)c1ccccc12 ; c1ccc(-c2cc(-c3c4ccccc4c(-c4cccc5oc6ccccc6c45)c4ccccc34)c3ccccc3c2)cc1]

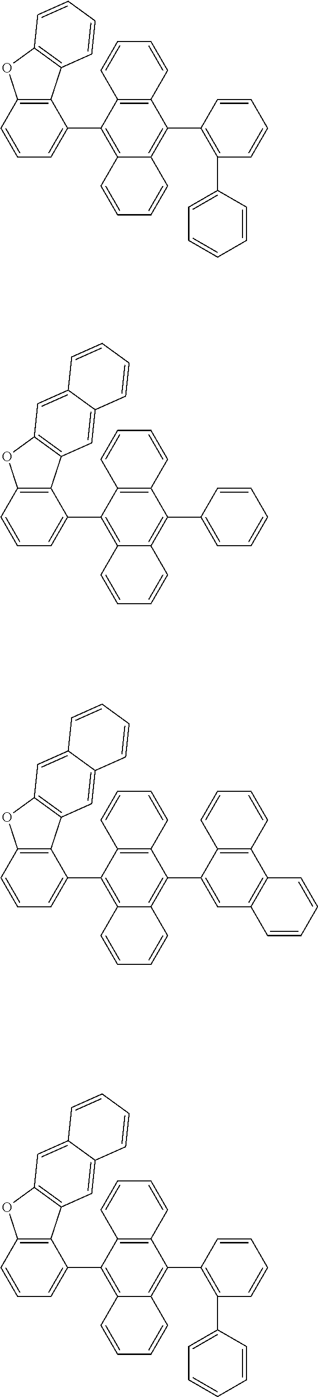 [SMILES: c1ccc(-c2ccccc2-c2c3ccccc3c(-c3cccc4oc5ccccc5c34)c3ccccc23)cc1 ; c1ccc(-c2c3ccccc3c(-c3cccc4oc5cc6ccccc6cc5c34)c3ccccc23)cc1 ; c1ccc2cc3c(cc2c1)oc1cccc(-c2c4ccccc4c(-c4cc5ccccc5c5ccccc45)c4ccccc24)c13 ; c1ccc(-c2ccccc2-c2c3ccccc3c(-c3cccc4oc5cc6ccccc6cc5c34)c3ccccc23)cc1]

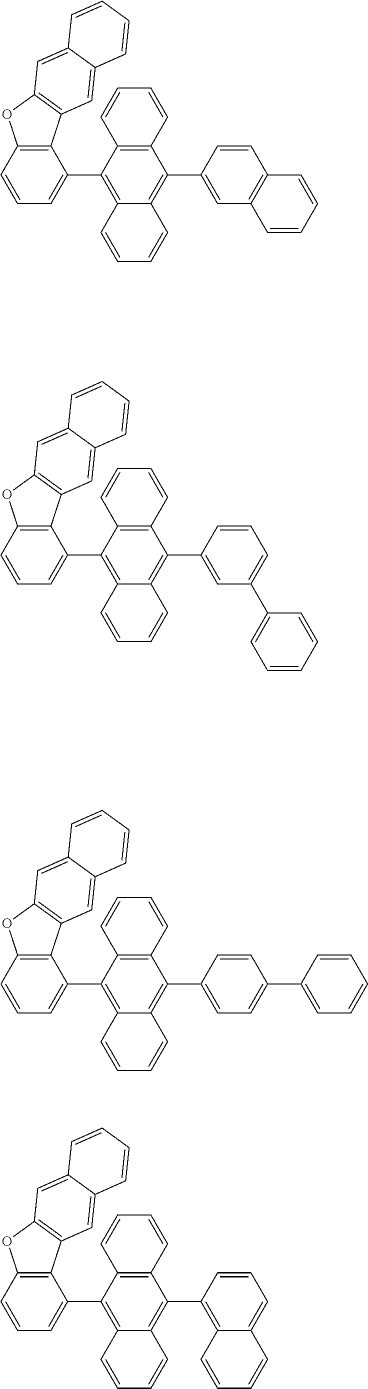 [SMILES: c1ccc2cc(-c3c4ccccc4c(-c4cccc5oc6cc7ccccc7cc6c45)c4ccccc34)ccc2c1 ; c1ccc(-c2cccc(-c3c4ccccc4c(-c4cccc5oc6cc7ccccc7cc6c45)c4ccccc34)c2)cc1 ; c1ccc(-c2ccc(-c3c4ccccc4c(-c4cccc5oc6cc7ccccc7cc6c45)c4ccccc34)cc2)cc1 ; c1ccc2cc3c(cc2c1)oc1cccc(-c2c4ccccc4c(-c4cccc5ccccc45)c4ccccc24)c13]

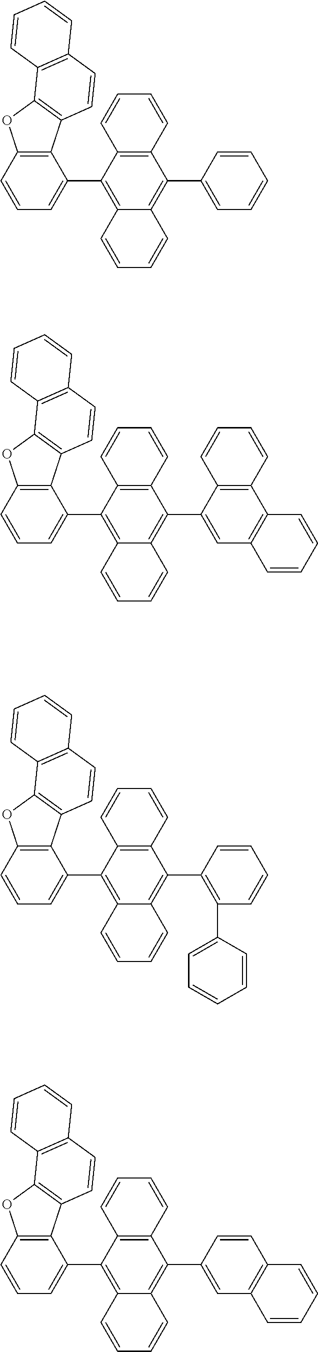 [SMILES: c1ccc(-c2c3ccccc3c(-c3cccc4oc5c6ccccc6ccc5c34)c3ccccc23)cc1 ; c1ccc2c(c1)cc(-c1c3ccccc3c(-c3cccc4oc5c6ccccc6ccc5c34)c3ccccc13)c1ccccc12 ; c1ccc(-c2ccccc2-c2c3ccccc3c(-c3cccc4oc5c6ccccc6ccc5c34)c3ccccc23)cc1 ; c1ccc2cc(-c3c4ccccc4c(-c4cccc5oc6c7ccccc7ccc6c45)c4ccccc34)ccc2c1]

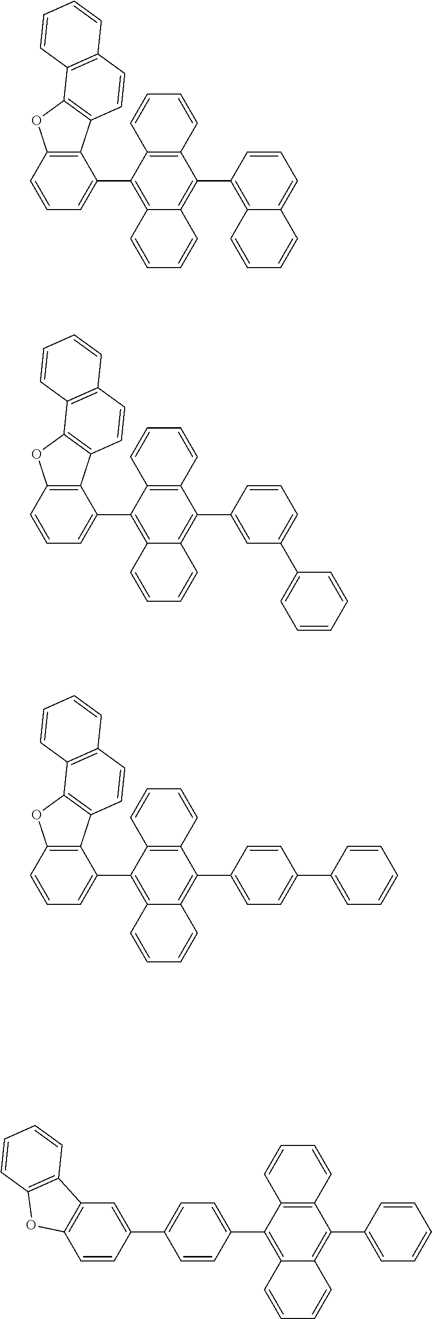 [SMILES: c1ccc2c(-c3c4ccccc4c(-c4cccc5oc6c7ccccc7ccc6c45)c4ccccc34)cccc2c1 ; c1ccc(-c2cccc(-c3c4ccccc4c(-c4cccc5oc6c7ccccc7ccc6c45)c4ccccc34)c2)cc1 ; c1ccc(-c2ccc(-c3c4ccccc4c(-c4cccc5oc6c7ccccc7ccc6c45)c4ccccc34)cc2)cc1 ; c1ccc(-c2c3ccccc3c(-c3ccc(-c4ccc5oc6ccccc6c5c4)cc3)c3ccccc23)cc1]

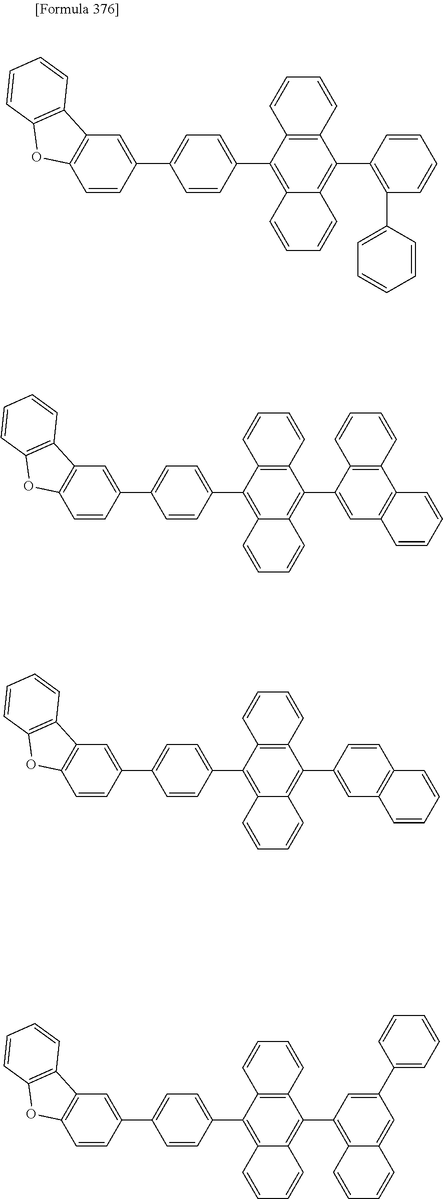 [SMILES: c1ccc(-c2ccccc2-c2c3ccccc3c(-c3ccc(-c4ccc5oc6ccccc6c5c4)cc3)c3ccccc23)cc1 ; c1ccc2c(c1)cc(-c1c3ccccc3c(-c3ccc(-c4ccc5oc6ccccc6c5c4)cc3)c3ccccc13)c1ccccc12 ; c1ccc2cc(-c3c4ccccc4c(-c4ccc(-c5ccc6oc7ccccc7c6c5)cc4)c4ccccc34)ccc2c1 ; c1ccc(-c2cc(-c3c4ccccc4c(-c4ccc(-c5ccc6oc7ccccc7c6c5)cc4)c4ccccc34)c3ccccc3c2)cc1]

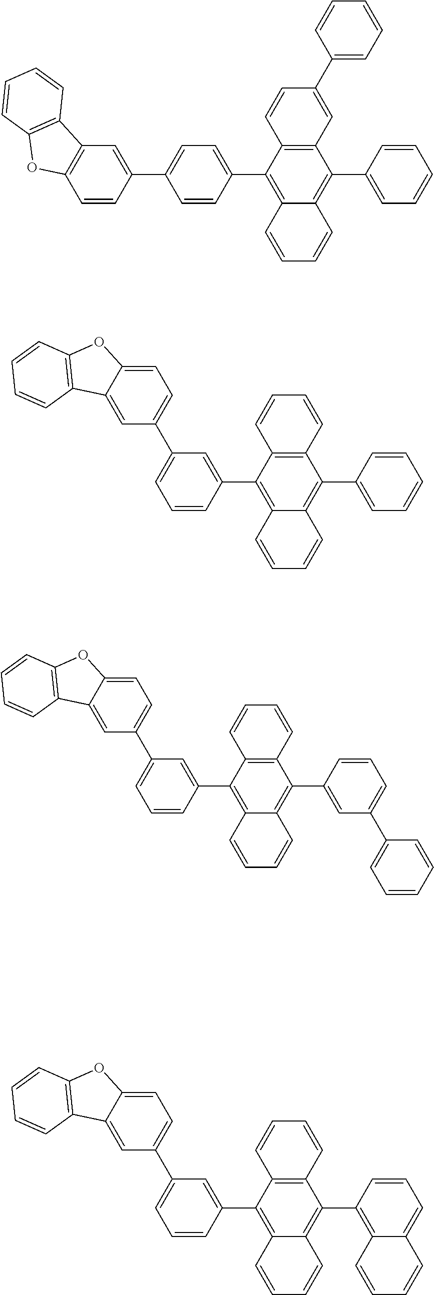 [SMILES: c1ccc(-c2ccc3c(-c4ccc(-c5ccc6oc7ccccc7c6c5)cc4)c4ccccc4c(-c4ccccc4)c3c2)cc1 ; c1ccc(-c2c3ccccc3c(-c3cccc(-c4ccc5oc6ccccc6c5c4)c3)c3ccccc23)cc1 ; c1ccc(-c2cccc(-c3c4ccccc4c(-c4cccc(-c5ccc6oc7ccccc7c6c5)c4)c4ccccc34)c2)cc1 ; c1cc(-c2ccc3oc4ccccc4c3c2)cc(-c2c3ccccc3c(-c3cccc4ccccc34)c3ccccc23)c1]

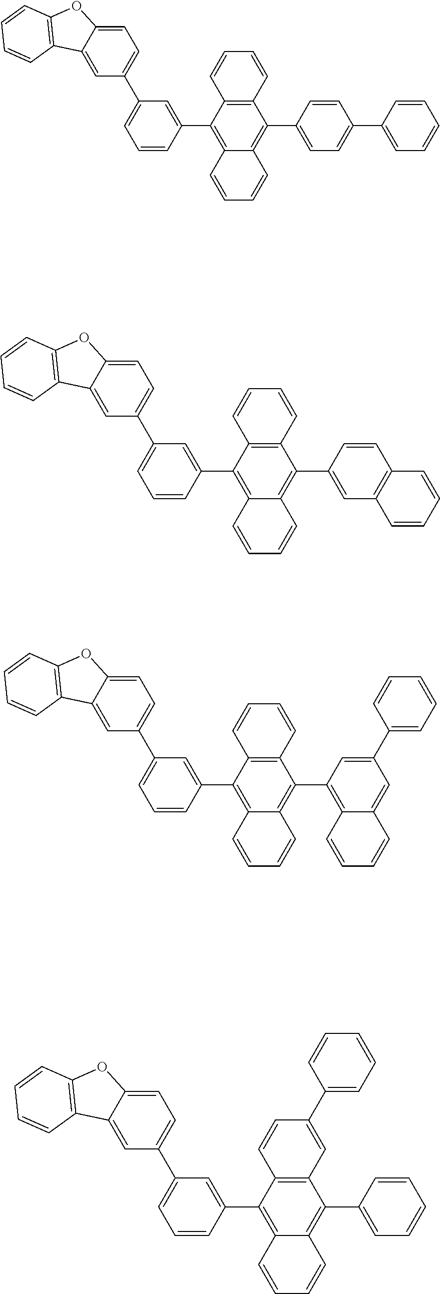 [SMILES: c1ccc(-c2ccc(-c3c4ccccc4c(-c4cccc(-c5ccc6oc7ccccc7c6c5)c4)c4ccccc34)cc2)cc1 ; c1cc(-c2ccc3oc4ccccc4c3c2)cc(-c2c3ccccc3c(-c3ccc4ccccc4c3)c3ccccc23)c1 ; c1ccc(-c2cc(-c3c4ccccc4c(-c4cccc(-c5ccc6oc7ccccc7c6c5)c4)c4ccccc34)c3ccccc3c2)cc1 ; c1ccc(-c2ccc3c(-c4cccc(-c5ccc6oc7ccccc7c6c5)c4)c4ccccc4c(-c4ccccc4)c3c2)cc1]

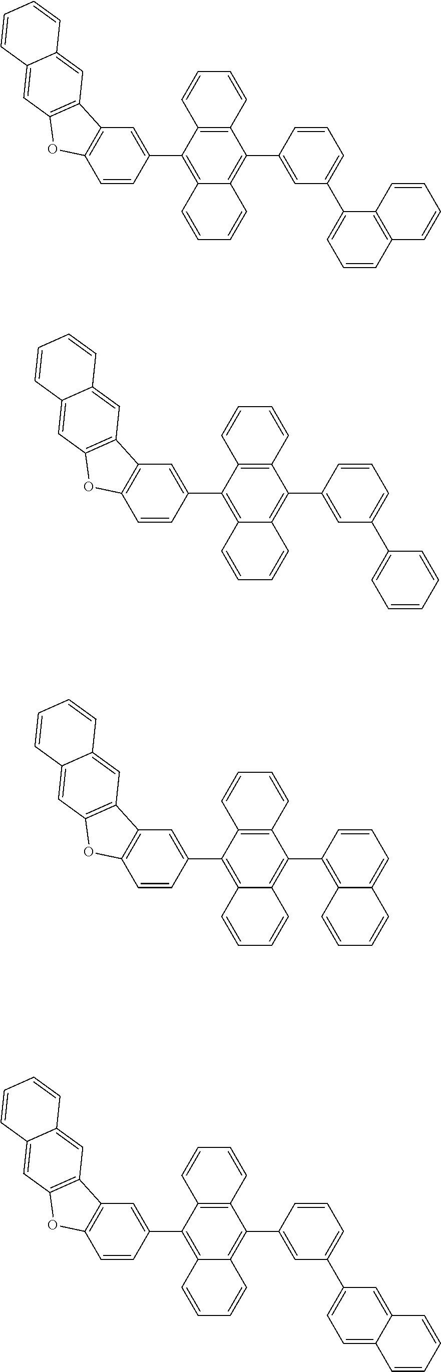 [SMILES: c1cc(-c2cccc3ccccc23)cc(-c2c3ccccc3c(-c3ccc4oc5cc6ccccc6cc5c4c3)c3ccccc23)c1 ; c1ccc(-c2cccc(-c3c4ccccc4c(-c4ccc5oc6cc7ccccc7cc6c5c4)c4ccccc34)c2)cc1 ; c1ccc2cc3c(cc2c1)oc1ccc(-c2c4ccccc4c(-c4cccc5ccccc45)c4ccccc24)cc13 ; c1cc(-c2ccc3ccccc3c2)cc(-c2c3ccccc3c(-c3ccc4oc5cc6ccccc6cc5c4c3)c3ccccc23)c1]

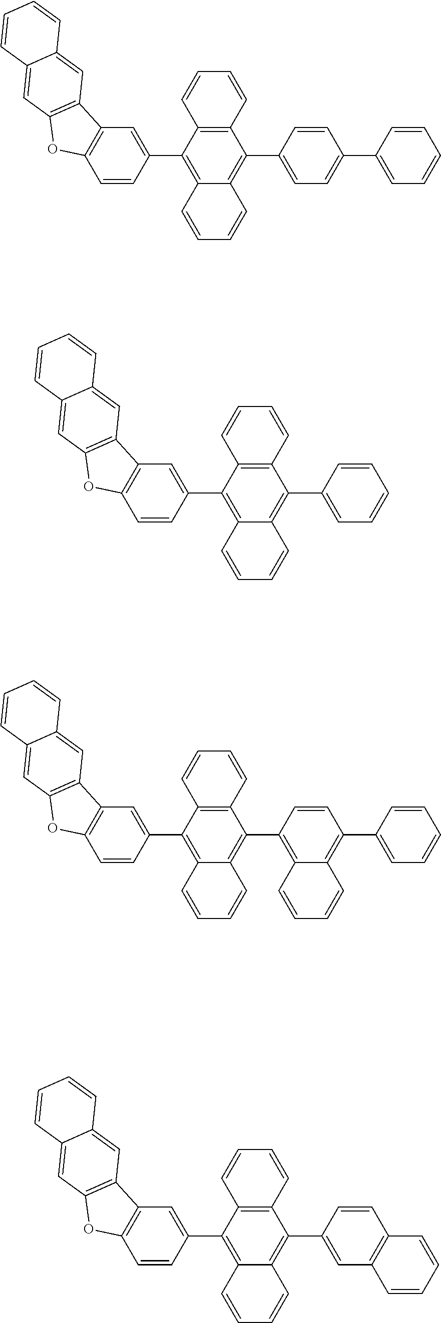 [SMILES: c1ccc(-c2ccc(-c3c4ccccc4c(-c4ccc5oc6cc7ccccc7cc6c5c4)c4ccccc34)cc2)cc1 ; c1ccc(-c2c3ccccc3c(-c3ccc4oc5cc6ccccc6cc5c4c3)c3ccccc23)cc1 ; c1ccc(-c2ccc(-c3c4ccccc4c(-c4ccc5oc6cc7ccccc7cc6c5c4)c4ccccc34)c3ccccc23)cc1 ; c1ccc2cc(-c3c4ccccc4c(-c4ccc5oc6cc7ccccc7cc6c5c4)c4ccccc34)ccc2c1]

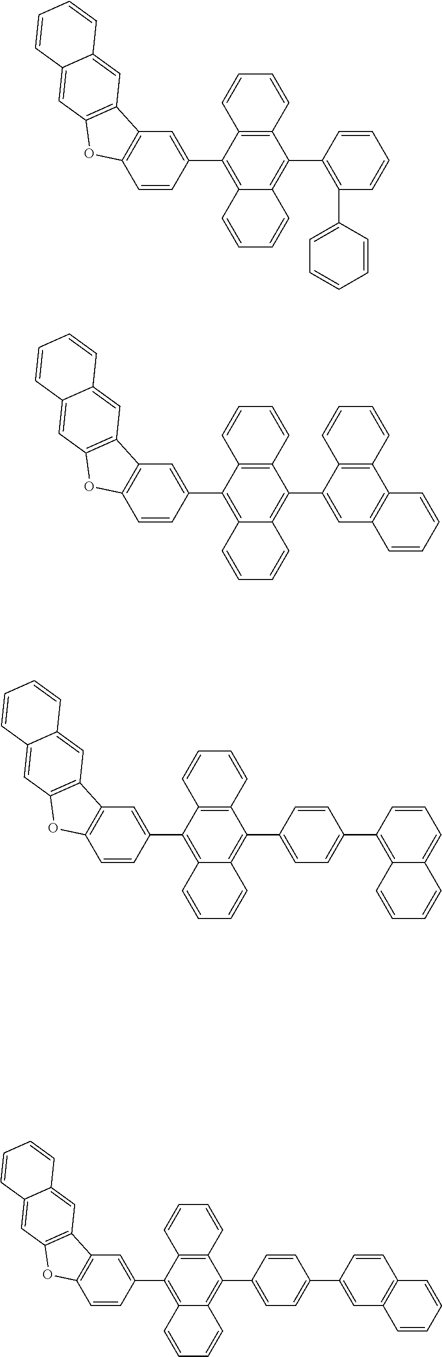 [SMILES: c1ccc(-c2ccccc2-c2c3ccccc3c(-c3ccc4oc5cc6ccccc6cc5c4c3)c3ccccc23)cc1 ; c1ccc2cc3c(cc2c1)oc1ccc(-c2c4ccccc4c(-c4cc5ccccc5c5ccccc45)c4ccccc24)cc13 ; c1ccc2cc3c(cc2c1)oc1ccc(-c2c4ccccc4c(-c4ccc(-c5cccc6ccccc56)cc4)c4ccccc24)cc13 ; c1ccc2cc(-c3ccc(-c4c5ccccc5c(-c5ccc6oc7cc8ccccc8cc7c6c5)c5ccccc45)cc3)ccc2c1]

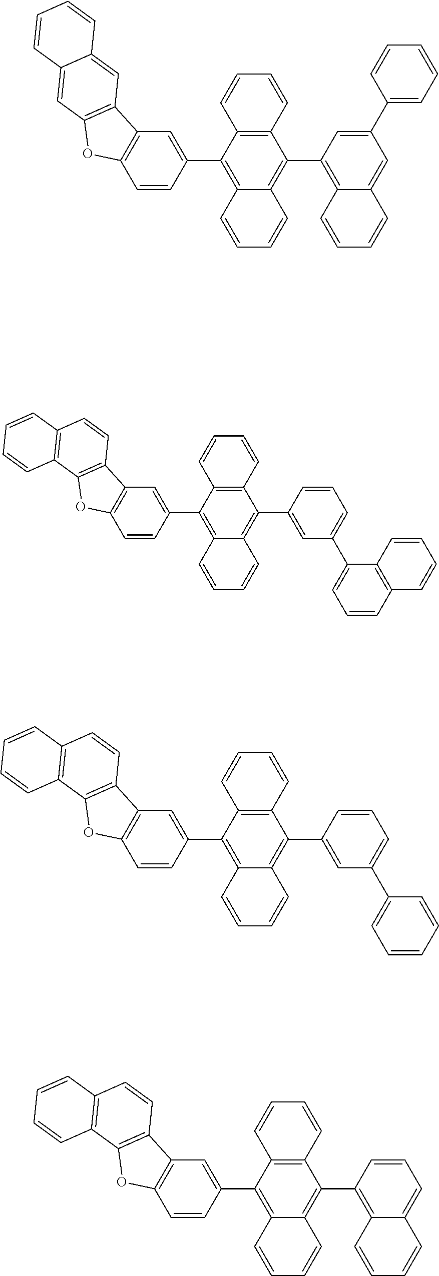 [SMILES: c1ccc(-c2cc(-c3c4ccccc4c(-c4ccc5oc6cc7ccccc7cc6c5c4)c4ccccc34)c3ccccc3c2)cc1 ; c1cc(-c2cccc3ccccc23)cc(-c2c3ccccc3c(-c3ccc4oc5c6ccccc6ccc5c4c3)c3ccccc23)c1 ; c1ccc(-c2cccc(-c3c4ccccc4c(-c4ccc5oc6c7ccccc7ccc6c5c4)c4ccccc34)c2)cc1 ; c1ccc2c(-c3c4ccccc4c(-c4ccc5oc6c7ccccc7ccc6c5c4)c4ccccc34)cccc2c1]

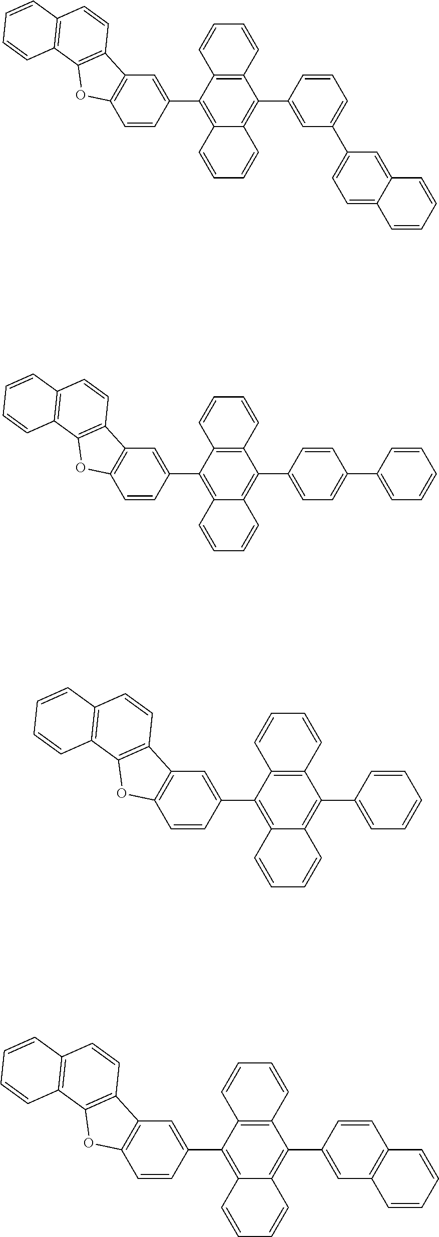 [SMILES: c1cc(-c2ccc3ccccc3c2)cc(-c2c3ccccc3c(-c3ccc4oc5c6ccccc6ccc5c4c3)c3ccccc23)c1 ; c1ccc(-c2ccc(-c3c4ccccc4c(-c4ccc5oc6c7ccccc7ccc6c5c4)c4ccccc34)cc2)cc1 ; c1ccc(-c2c3ccccc3c(-c3ccc4oc5c6ccccc6ccc5c4c3)c3ccccc23)cc1 ; c1ccc2cc(-c3c4ccccc4c(-c4ccc5oc6c7ccccc7ccc6c5c4)c4ccccc34)ccc2c1]

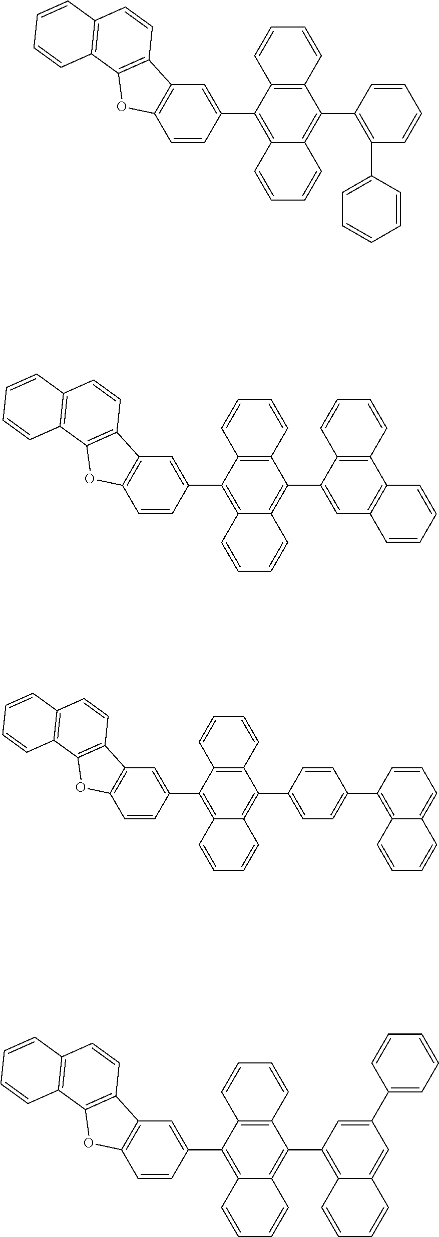 [SMILES: c1ccc(-c2ccccc2-c2c3ccccc3c(-c3ccc4oc5c6ccccc6ccc5c4c3)c3ccccc23)cc1 ; c1ccc2c(c1)cc(-c1c3ccccc3c(-c3ccc4oc5c6ccccc6ccc5c4c3)c3ccccc13)c1ccccc12 ; c1ccc2c(-c3ccc(-c4c5ccccc5c(-c5ccc6oc7c8ccccc8ccc7c6c5)c5ccccc45)cc3)cccc2c1 ; c1ccc(-c2cc(-c3c4ccccc4c(-c4ccc5oc6c7ccccc7ccc6c5c4)c4ccccc34)c3ccccc3c2)cc1]

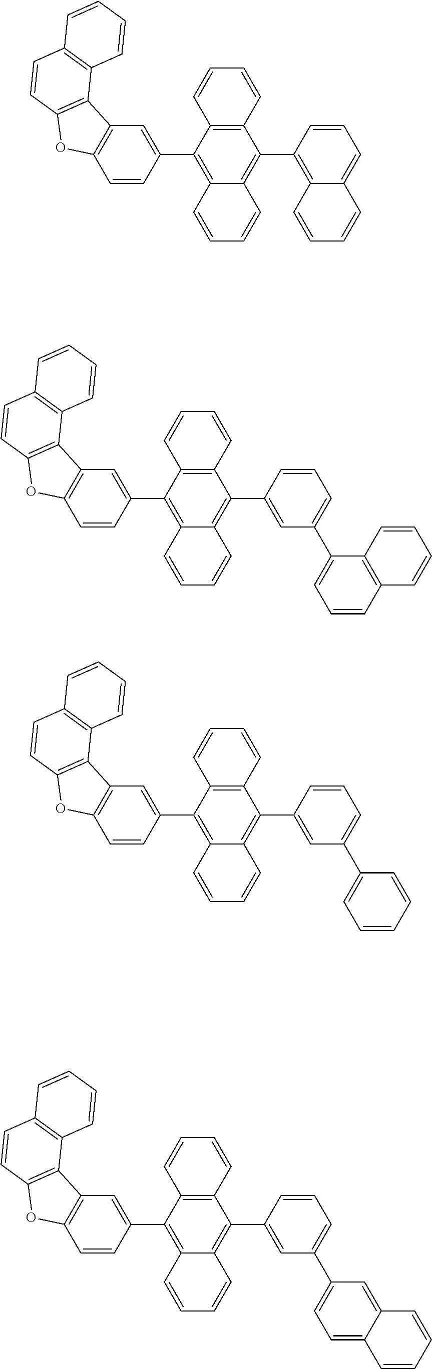 [SMILES: c1ccc2c(-c3c4ccccc4c(-c4ccc5oc6ccc7ccccc7c6c5c4)c4ccccc34)cccc2c1 ; c1cc(-c2cccc3ccccc23)cc(-c2c3ccccc3c(-c3ccc4oc5ccc6ccccc6c5c4c3)c3ccccc23)c1 ; c1ccc(-c2cccc(-c3c4ccccc4c(-c4ccc5oc6ccc7ccccc7c6c5c4)c4ccccc34)c2)cc1 ; c1cc(-c2ccc3ccccc3c2)cc(-c2c3ccccc3c(-c3ccc4oc5ccc6ccccc6c5c4c3)c3ccccc23)c1]

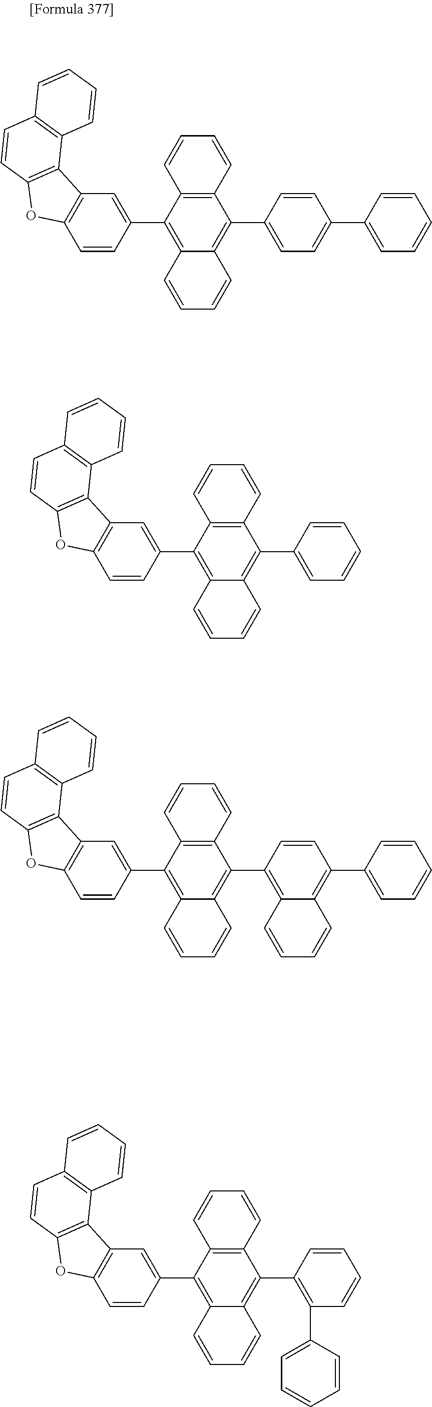 [SMILES: c1ccc(-c2ccc(-c3c4ccccc4c(-c4ccc5oc6ccc7ccccc7c6c5c4)c4ccccc34)cc2)cc1 ; c1ccc(-c2c3ccccc3c(-c3ccc4oc5ccc6ccccc6c5c4c3)c3ccccc23)cc1 ; c1ccc(-c2ccc(-c3c4ccccc4c(-c4ccc5oc6ccc7ccccc7c6c5c4)c4ccccc34)c3ccccc23)cc1 ; c1ccc(-c2ccccc2-c2c3ccccc3c(-c3ccc4oc5ccc6ccccc6c5c4c3)c3ccccc23)cc1]

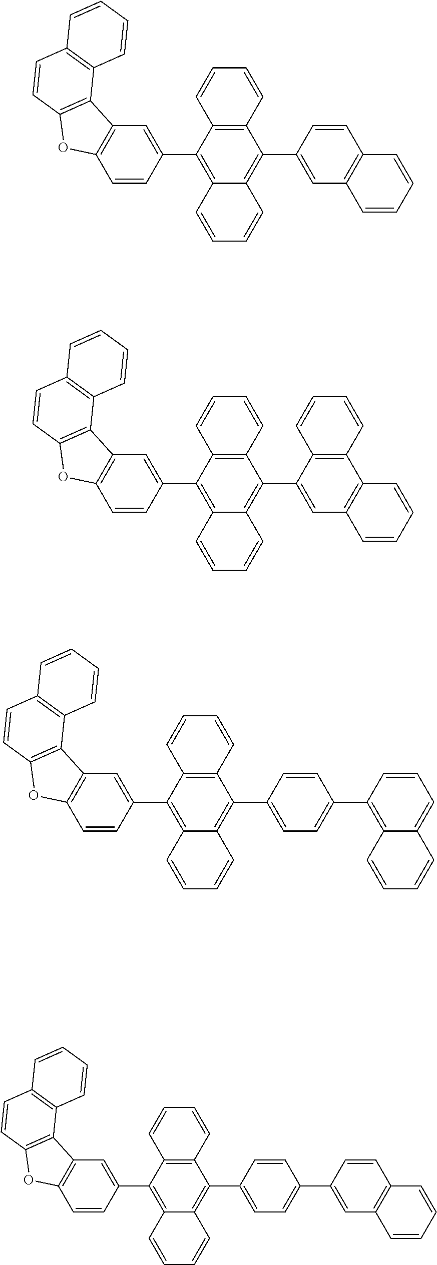 [SMILES: c1ccc2cc(-c3c4ccccc4c(-c4ccc5oc6ccc7ccccc7c6c5c4)c4ccccc34)ccc2c1 ; c1ccc2c(c1)cc(-c1c3ccccc3c(-c3ccc4oc5ccc6ccccc6c5c4c3)c3ccccc13)c1ccccc12 ; c1ccc2c(-c3ccc(-c4c5ccccc5c(-c5ccc6oc7ccc8ccccc8c7c6c5)c5ccccc45)cc3)cccc2c1 ; c1ccc2cc(-c3ccc(-c4c5ccccc5c(-c5ccc6oc7ccc8ccccc8c7c6c5)c5ccccc45)cc3)ccc2c1]

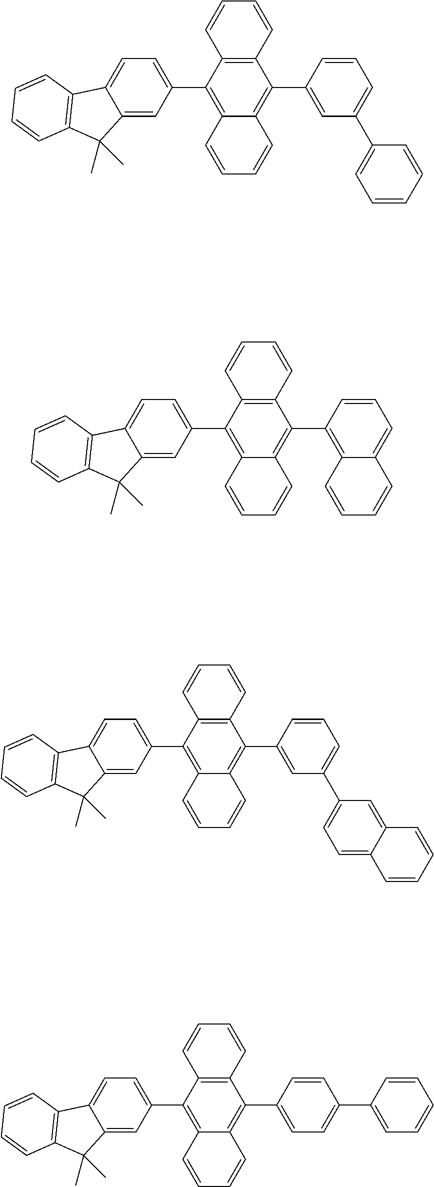

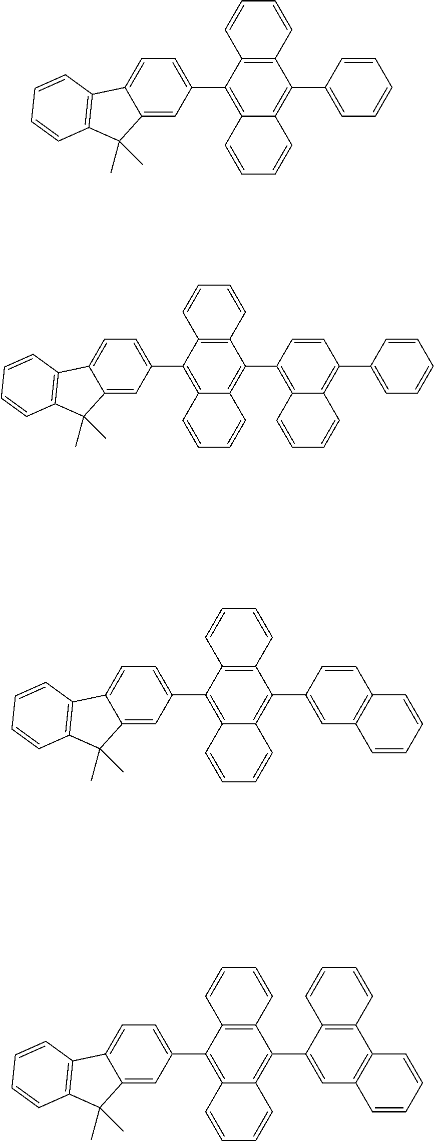

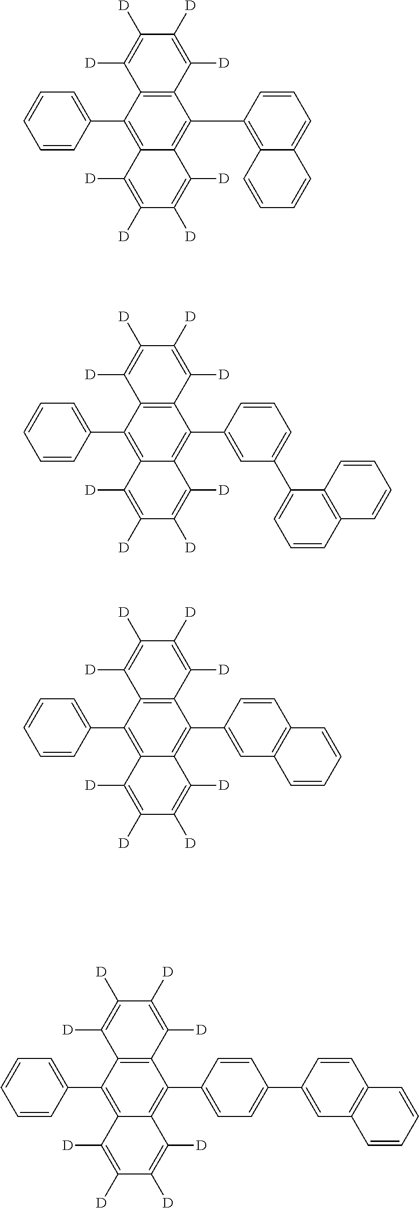 [SMILES: [2H]c1c([2H])c([2H])c2c(-c3cccc4ccccc34)c3c([2H])c([2H])c([2H])c([2H])c3c(-c3ccccc3)c2c1[2H] ; [2H]c1c([2H])c([2H])c2c(-c3cccc(-c4cccc5ccccc45)c3)c3c([2H])c([2H])c([2H])c([2H])c3c(-c3ccccc3)c2c1[2H] ; [2H]c1c([2H])c([2H])c2c(-c3ccc4ccccc4c3)c3c([2H])c([2H])c([2H])c([2H])c3c(-c3ccccc3)c2c1[2H] ; [2H]c1c([2H])c([2H])c2c(-c3ccc(-c4ccc5ccccc5c4)cc3)c3c([2H])c([2H])c([2H])c([2H])c3c(-c3ccccc3)c2c1[2H]]

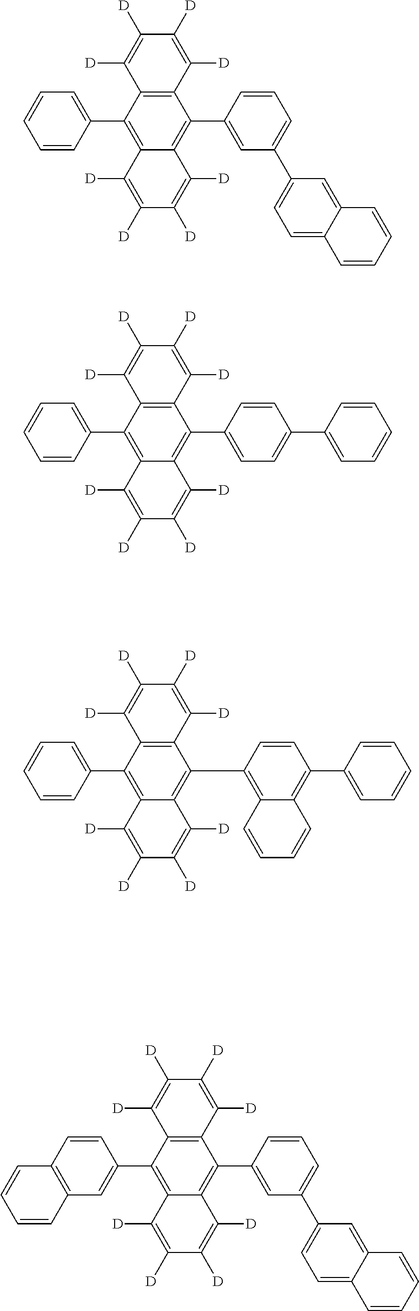 [SMILES: [2H]c1c([2H])c([2H])c2c(-c3cccc(-c4ccc5ccccc5c4)c3)c3c([2H])c([2H])c([2H])c([2H])c3c(-c3ccccc3)c2c1[2H] ; [2H]c1c([2H])c([2H])c2c(-c3ccc(-c4ccccc4)cc3)c3c([2H])c([2H])c([2H])c([2H])c3c(-c3ccccc3)c2c1[2H] ; [2H]c1c([2H])c([2H])c2c(-c3ccc(-c4ccccc4)c4ccccc34)c3c([2H])c([2H])c([2H])c([2H])c3c(-c3ccccc3)c2c1[2H] ; [2H]c1c([2H])c([2H])c2c(-c3ccc4ccccc4c3)c3c([2H])c([2H])c([2H])c([2H])c3c(-c3cccc(-c4ccc5ccccc5c4)c3)c2c1[2H]]

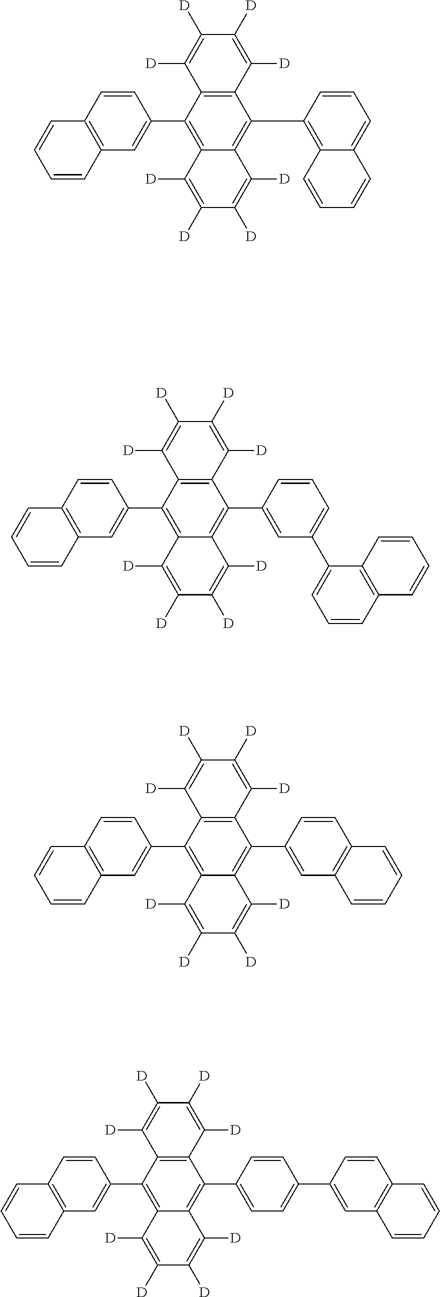 [SMILES: [2H]c1c([2H])c([2H])c2c(-c3cccc4ccccc34)c3c([2H])c([2H])c([2H])c([2H])c3c(-c3ccc4ccccc4c3)c2c1[2H] ; [2H]c1c([2H])c([2H])c2c(-c3ccc4ccccc4c3)c3c([2H])c([2H])c([2H])c([2H])c3c(-c3cccc(-c4cccc5ccccc45)c3)c2c1[2H] ; [2H]c1c([2H])c([2H])c2c(-c3ccc4ccccc4c3)c3c([2H])c([2H])c([2H])c([2H])c3c(-c3ccc4ccccc4c3)c2c1[2H] ; [2H]c1c([2H])c([2H])c2c(-c3ccc4ccccc4c3)c3c([2H])c([2H])c([2H])c([2H])c3c(-c3ccc(-c4ccc5ccccc5c4)cc3)c2c1[2H]]

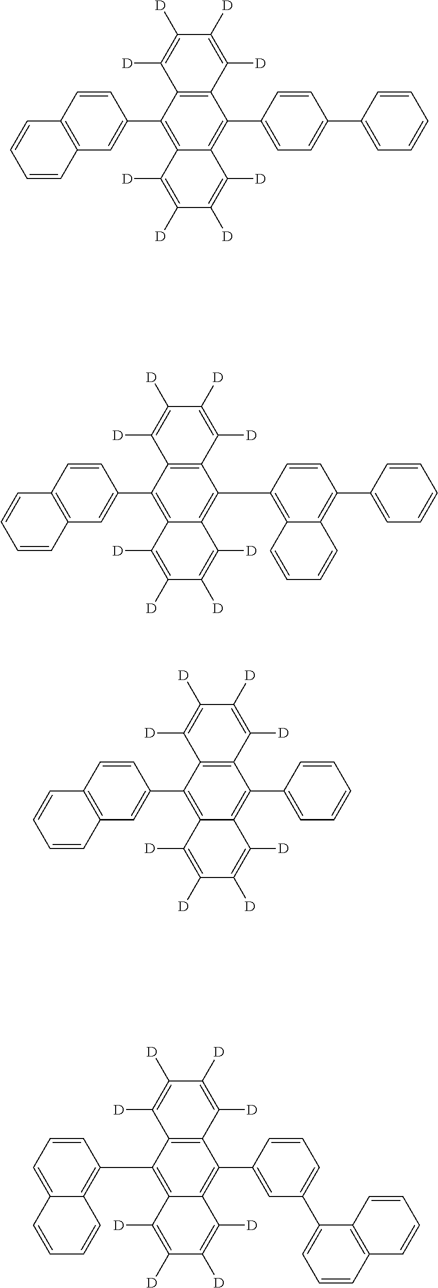 [SMILES: [2H]c1c([2H])c([2H])c2c(-c3ccc4ccccc4c3)c3c([2H])c([2H])c([2H])c([2H])c3c(-c3ccc(-c4ccccc4)cc3)c2c1[2H] ; [2H]c1c([2H])c([2H])c2c(-c3ccc(-c4ccccc4)c4ccccc34)c3c([2H])c([2H])c([2H])c([2H])c3c(-c3ccc4ccccc4c3)c2c1[2H] ; [2H]c1c([2H])c([2H])c2c(-c3ccc4ccccc4c3)c3c([2H])c([2H])c([2H])c([2H])c3c(-c3ccccc3)c2c1[2H] ; [2H]c1c([2H])c([2H])c2c(-c3cccc4ccccc34)c3c([2H])c([2H])c([2H])c([2H])c3c(-c3cccc(-c4cccc5ccccc45)c3)c2c1[2H]]

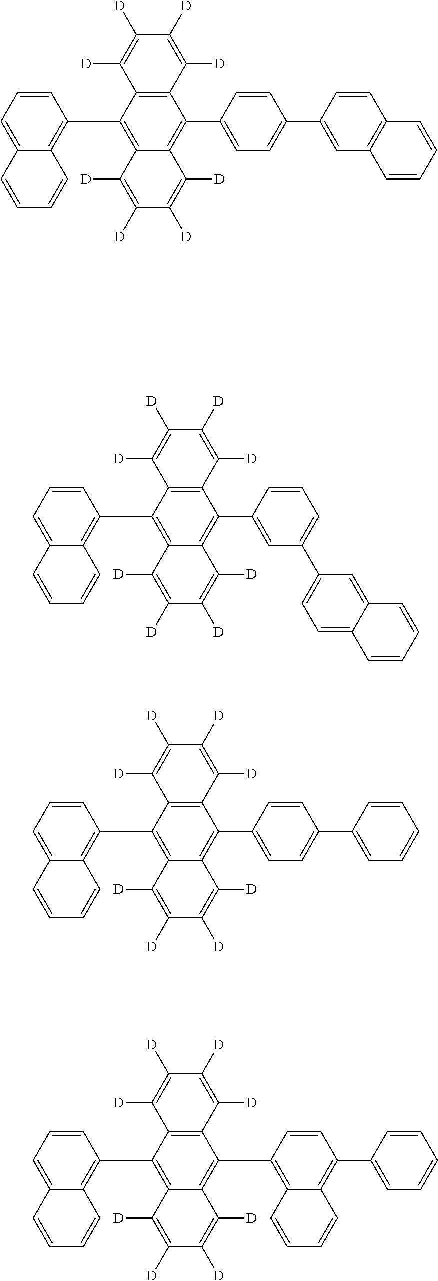 [SMILES: [2H]c1c([2H])c([2H])c2c(-c3cccc4ccccc34)c3c([2H])c([2H])c([2H])c([2H])c3c(-c3ccc(-c4ccc5ccccc5c4)cc3)c2c1[2H] ; [2H]c1c([2H])c([2H])c2c(-c3cccc4ccccc34)c3c([2H])c([2H])c([2H])c([2H])c3c(-c3cccc(-c4ccc5ccccc5c4)c3)c2c1[2H] ; [2H]c1c([2H])c([2H])c2c(-c3cccc4ccccc34)c3c([2H])c([2H])c([2H])c([2H])c3c(-c3ccc(-c4ccccc4)cc3)c2c1[2H] ; [2H]c1c([2H])c([2H])c2c(-c3ccc(-c4ccccc4)c4ccccc34)c3c([2H])c([2H])c([2H])c([2H])c3c(-c3cccc4ccccc34)c2c1[2H]]

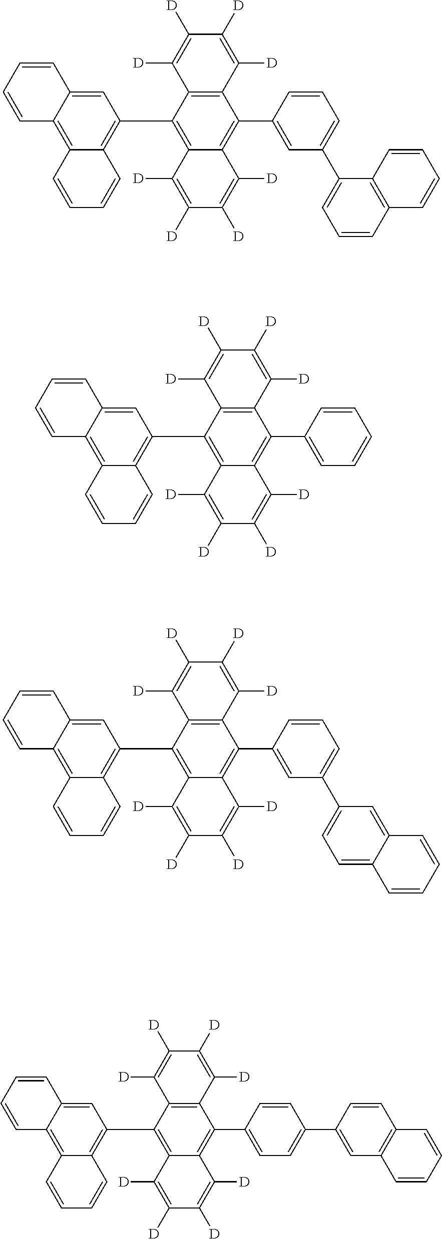 [SMILES: [2H]c1c([2H])c([2H])c2c(-c3cc4ccccc4c4ccccc34)c3c([2H])c([2H])c([2H])c([2H])c3c(-c3cccc(-c4cccc5ccccc45)c3)c2c1[2H] ; [2H]c1c([2H])c([2H])c2c(-c3cc4ccccc4c4ccccc34)c3c([2H])c([2H])c([2H])c([2H])c3c(-c3ccccc3)c2c1[2H] ; [2H]c1c([2H])c([2H])c2c(-c3cc4ccccc4c4ccccc34)c3c([2H])c([2H])c([2H])c([2H])c3c(-c3cccc(-c4ccc5ccccc5c4)c3)c2c1[2H] ; [2H]c1c([2H])c([2H])c2c(-c3cc4ccccc4c4ccccc34)c3c([2H])c([2H])c([2H])c([2H])c3c(-c3ccc(-c4ccc5ccccc5c4)cc3)c2c1[2H]]

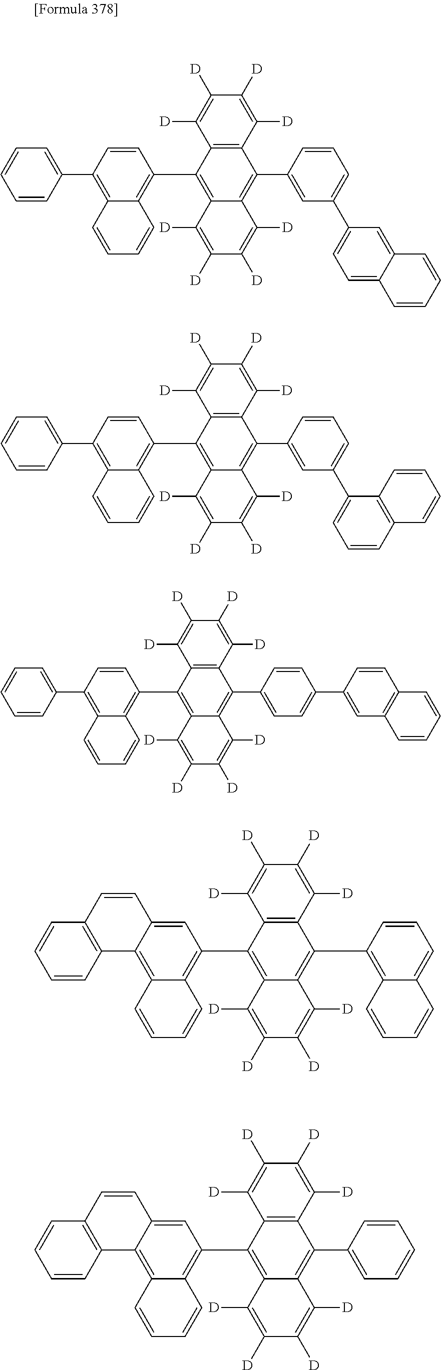

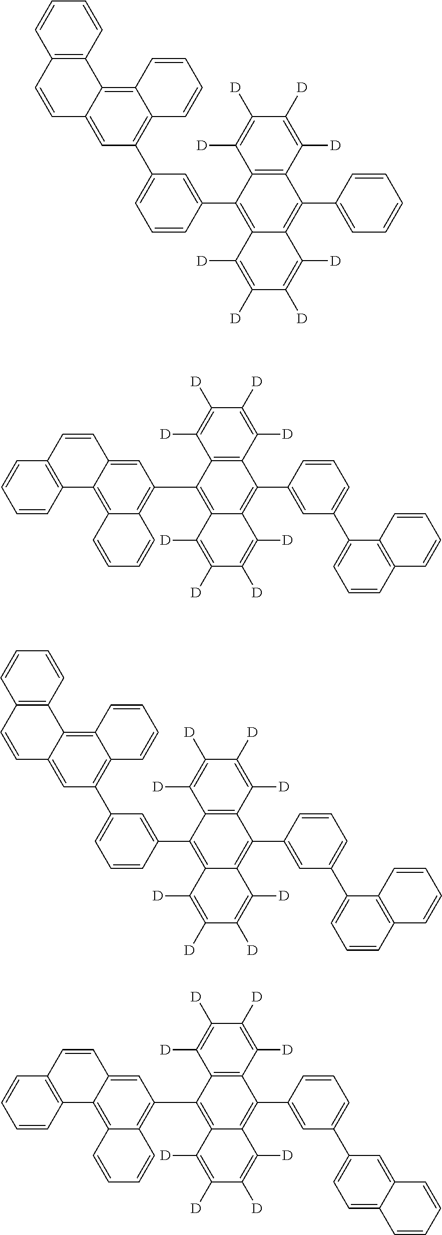 [SMILES: [2H]c1c([2H])c([2H])c2c(-c3cccc(-c4cc5ccc6ccccc6c5c5ccccc45)c3)c3c([2H])c([2H])c([2H])c([2H])c3c(-c3ccccc3)c2c1[2H] ; [2H]c1c([2H])c([2H])c2c(-c3cc4ccc5ccccc5c4c4ccccc34)c3c([2H])c([2H])c([2H])c([2H])c3c(-c3cccc(-c4cccc5ccccc45)c3)c2c1[2H] ; [2H]c1c([2H])c([2H])c2c(-c3cccc(-c4cc5ccc6ccccc6c5c5ccccc45)c3)c3c([2H])c([2H])c([2H])c([2H])c3c(-c3cccc(-c4cccc5ccccc45)c3)c2c1[2H] ; [2H]c1c([2H])c([2H])c2c(-c3cc4ccc5ccccc5c4c4ccccc34)c3c([2H])c([2H])c([2H])c([2H])c3c(-c3cccc(-c4ccc5ccccc5c4)c3)c2c1[2H]]

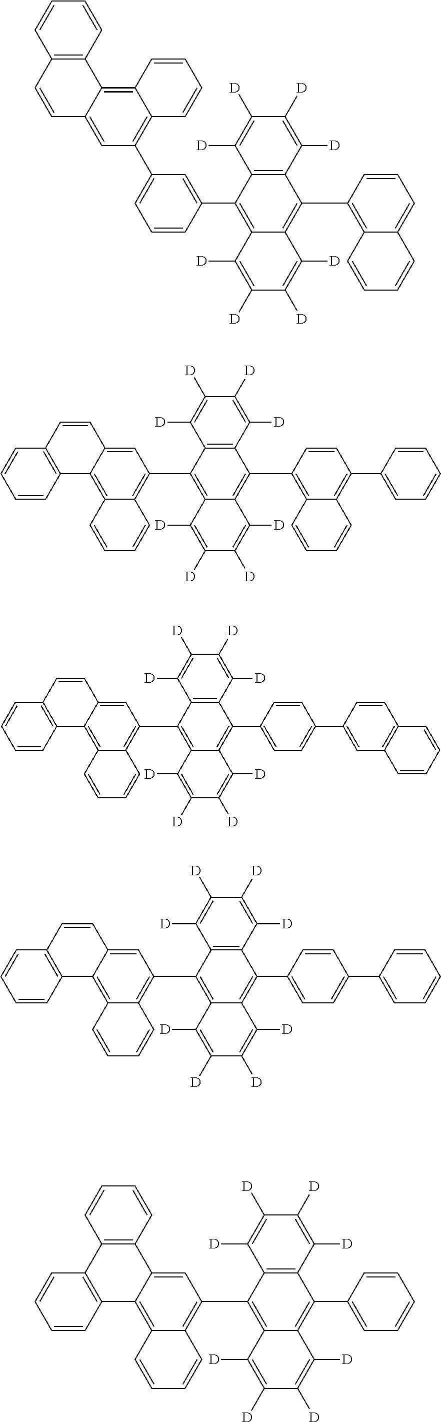

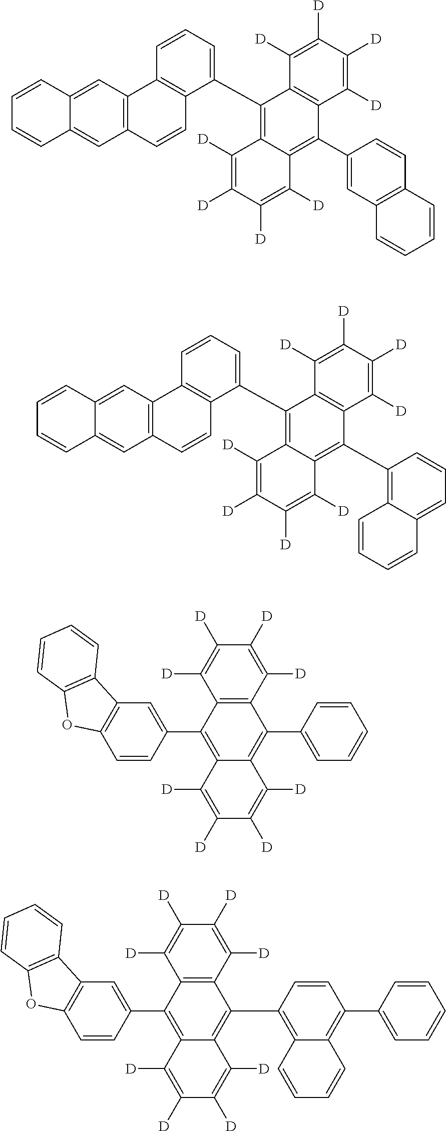 [SMILES: [2H]c1c([2H])c([2H])c2c(-c3cccc4c3ccc3cc5ccccc5cc34)c3c([2H])c([2H])c([2H])c([2H])c3c(-c3ccc4ccccc4c3)c2c1[2H] ; [2H]c1c([2H])c([2H])c2c(-c3cccc4c3ccc3cc5ccccc5cc34)c3c([2H])c([2H])c([2H])c([2H])c3c(-c3cccc4ccccc34)c2c1[2H] ; [2H]c1c([2H])c([2H])c2c(-c3ccc4oc5ccccc5c4c3)c3c([2H])c([2H])c([2H])c([2H])c3c(-c3ccccc3)c2c1[2H] ; [2H]c1c([2H])c([2H])c2c(-c3ccc(-c4ccccc4)c4ccccc34)c3c([2H])c([2H])c([2H])c([2H])c3c(-c3ccc4oc5ccccc5c4c3)c2c1[2H]]

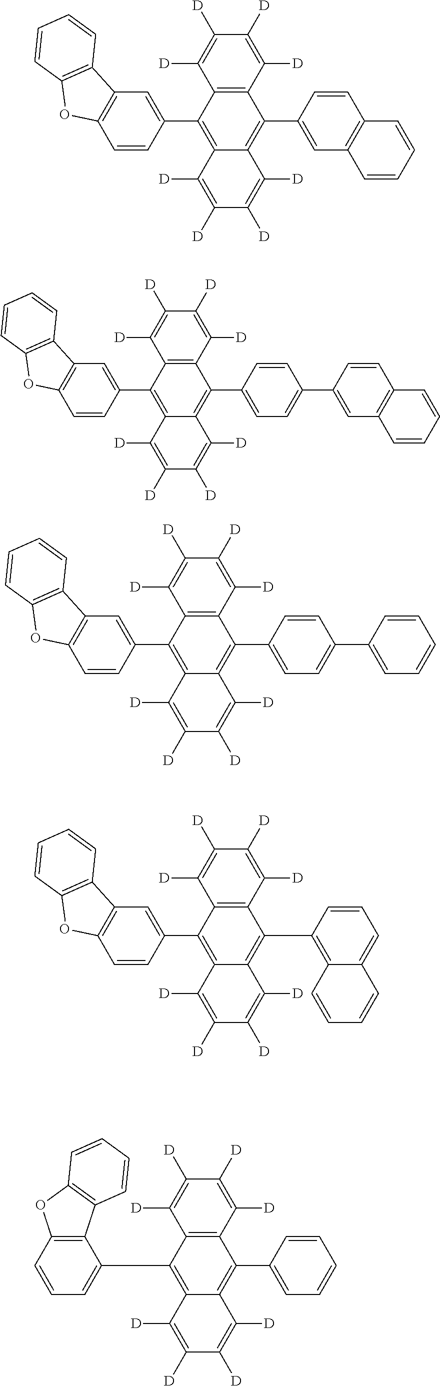

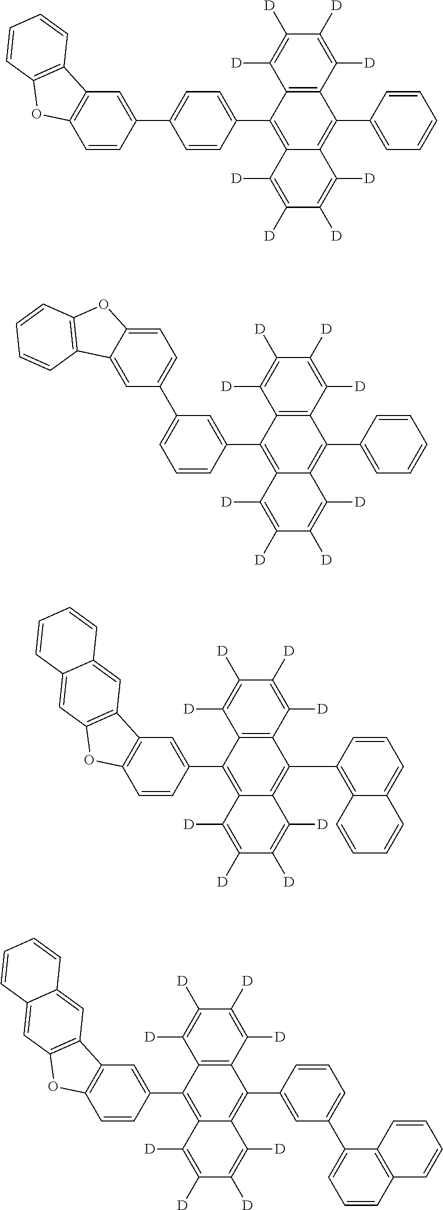 [SMILES: [2H]c1c([2H])c([2H])c2c(-c3ccc(-c4ccc5oc6ccccc6c5c4)cc3)c3c([2H])c([2H])c([2H])c([2H])c3c(-c3ccccc3)c2c1[2H] ; [2H]c1c([2H])c([2H])c2c(-c3cccc(-c4ccc5oc6ccccc6c5c4)c3)c3c([2H])c([2H])c([2H])c([2H])c3c(-c3ccccc3)c2c1[2H] ; [2H]c1c([2H])c([2H])c2c(-c3cccc4ccccc34)c3c([2H])c([2H])c([2H])c([2H])c3c(-c3ccc4oc5cc6ccccc6cc5c4c3)c2c1[2H] ; [2H]c1c([2H])c([2H])c2c(-c3ccc4oc5cc6ccccc6cc5c4c3)c3c([2H])c([2H])c([2H])c([2H])c3c(-c3cccc(-c4cccc5ccccc45)c3)c2c1[2H]]

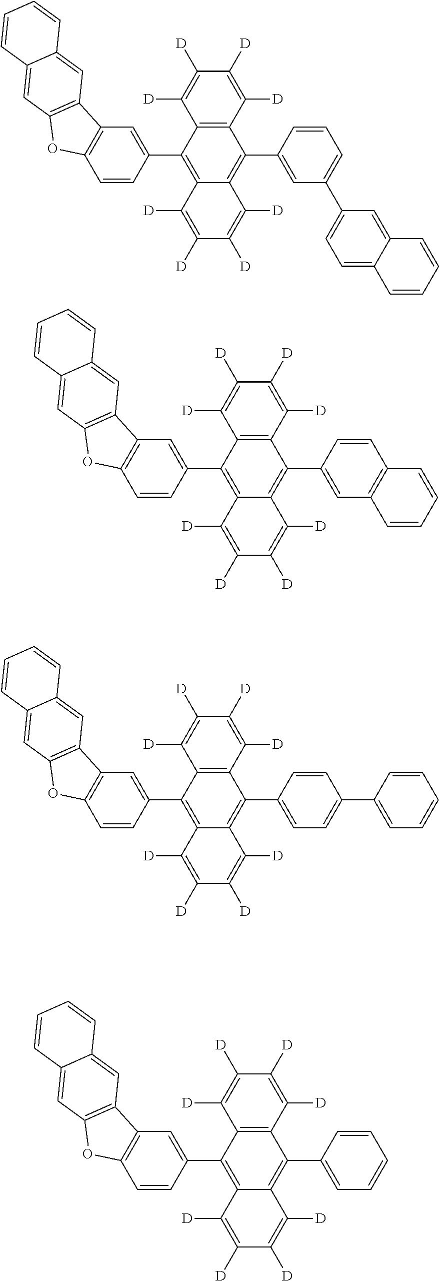 [SMILES: [2H]c1c([2H])c([2H])c2c(-c3ccc4oc5cc6ccccc6cc5c4c3)c3c([2H])c([2H])c([2H])c([2H])c3c(-c3cccc(-c4ccc5ccccc5c4)c3)c2c1[2H] ; [2H]c1c([2H])c([2H])c2c(-c3ccc4oc5cc6ccccc6cc5c4c3)c3c([2H])c([2H])c([2H])c([2H])c3c(-c3ccc4ccccc4c3)c2c1[2H] ; [2H]c1c([2H])c([2H])c2c(-c3ccc4oc5cc6ccccc6cc5c4c3)c3c([2H])c([2H])c([2H])c([2H])c3c(-c3ccc(-c4ccccc4)cc3)c2c1[2H] ; [2H]c1c([2H])c([2H])c2c(-c3ccc4oc5cc6ccccc6cc5c4c3)c3c([2H])c([2H])c([2H])c([2H])c3c(-c3ccccc3)c2c1[2H]]

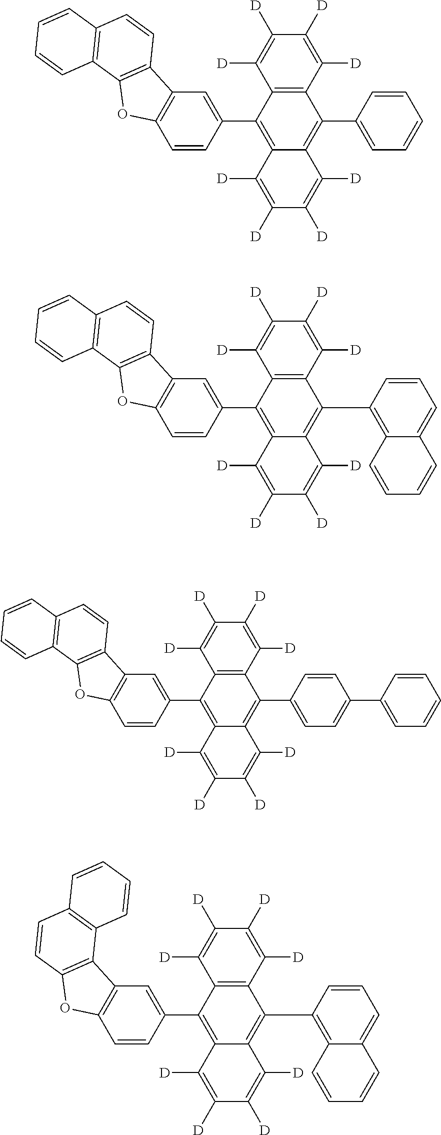 [SMILES: [2H]c1c([2H])c([2H])c2c(-c3ccc4oc5c6ccccc6ccc5c4c3)c3c([2H])c([2H])c([2H])c([2H])c3c(-c3ccccc3)c2c1[2H] ; [2H]c1c([2H])c([2H])c2c(-c3cccc4ccccc34)c3c([2H])c([2H])c([2H])c([2H])c3c(-c3ccc4oc5c6ccccc6ccc5c4c3)c2c1[2H] ; [2H]c1c([2H])c([2H])c2c(-c3ccc4oc5c6ccccc6ccc5c4c3)c3c([2H])c([2H])c([2H])c([2H])c3c(-c3ccc(-c4ccccc4)cc3)c2c1[2H] ; [2H]c1c([2H])c([2H])c2c(-c3cccc4ccccc34)c3c([2H])c([2H])c([2H])c([2H])c3c(-c3ccc4oc5ccc6ccccc6c5c4c3)c2c1[2H]]

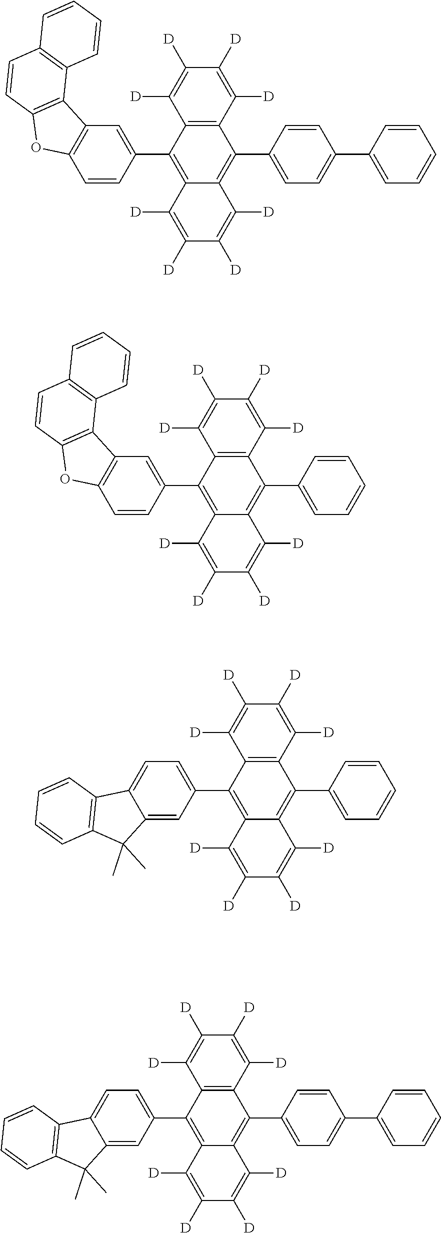 [SMILES: [2H]c1c([2H])c([2H])c2c(-c3ccc4oc5ccc6ccccc6c5c4c3)c3c([2H])c([2H])c([2H])c([2H])c3c(-c3ccc(-c4ccccc4)cc3)c2c1[2H] ; [2H]c1c([2H])c([2H])c2c(-c3ccc4oc5ccc6ccccc6c5c4c3)c3c([2H])c([2H])c([2H])c([2H])c3c(-c3ccccc3)c2c1[2H] ; [2H]c1c([2H])c([2H])c2c(-c3ccc4c(c3)C(C)(C)c3ccccc3-4)c3c([2H])c([2H])c([2H])c([2H])c3c(-c3ccccc3)c2c1[2H] ; [2H]c1c([2H])c([2H])c2c(-c3ccc4c(c3)C(C)(C)c3ccccc3-4)c3c([2H])c([2H])c([2H])c([2H])c3c(-c3ccc(-c4ccccc4)cc3)c2c1[2H]]

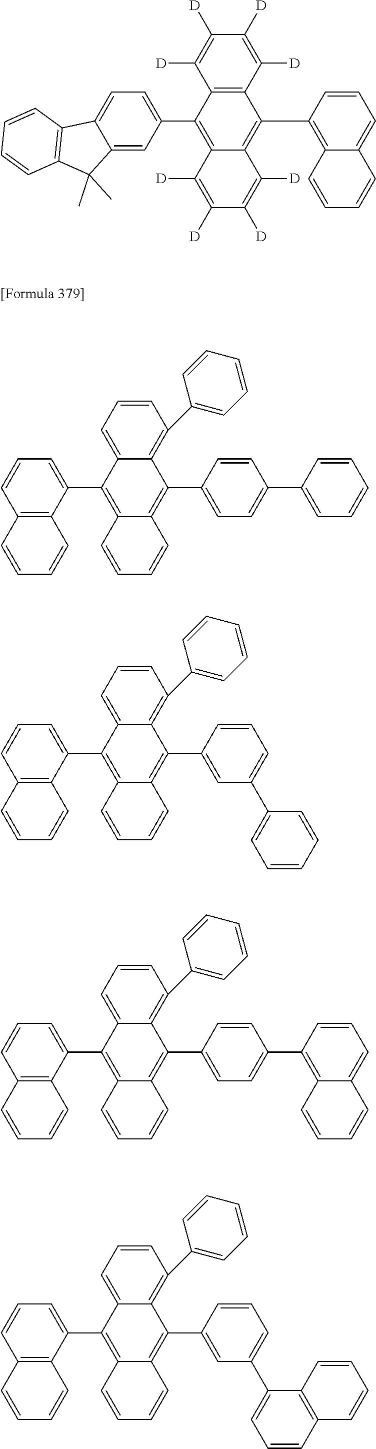

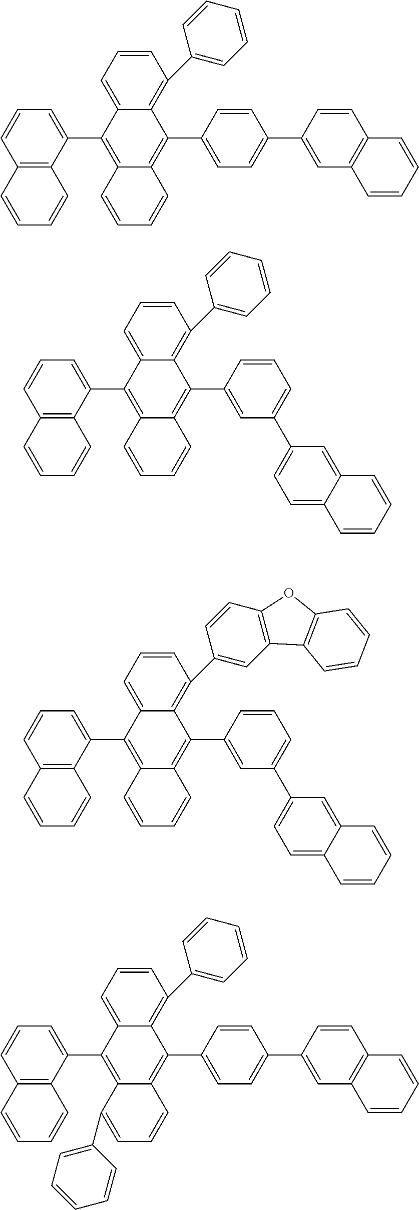

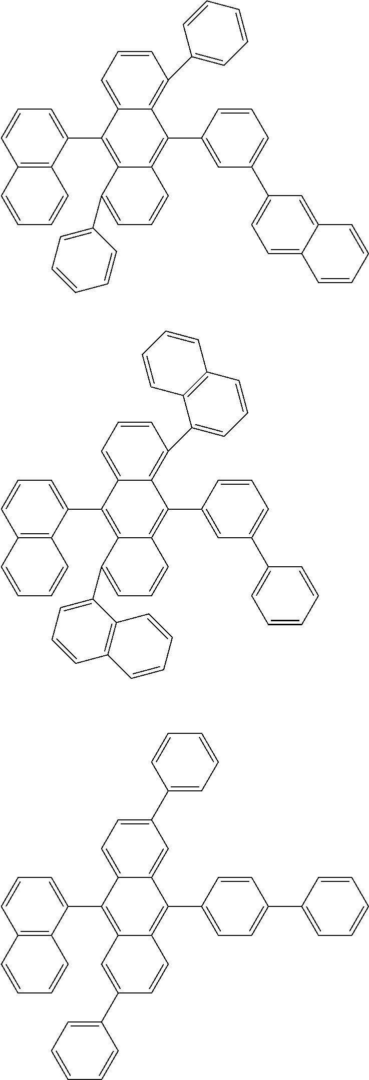

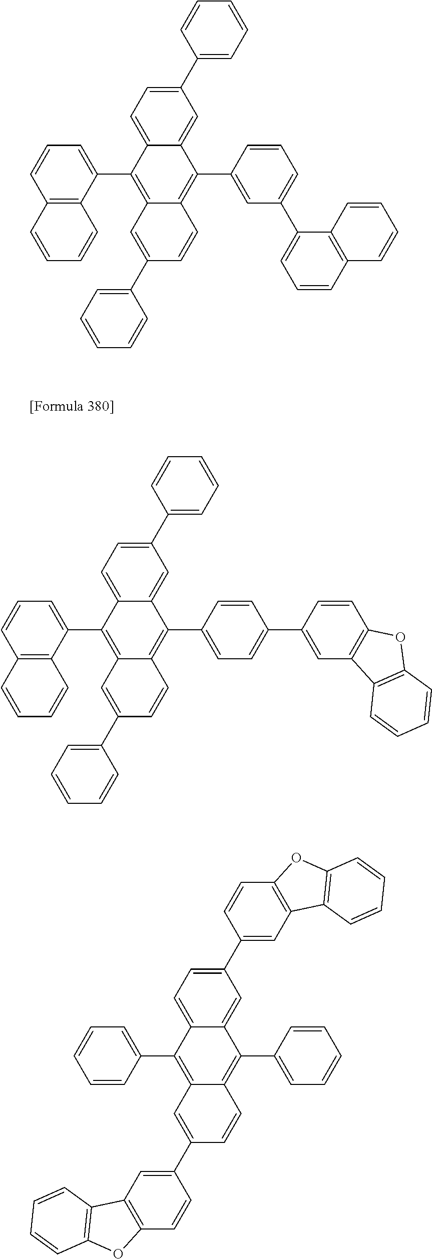

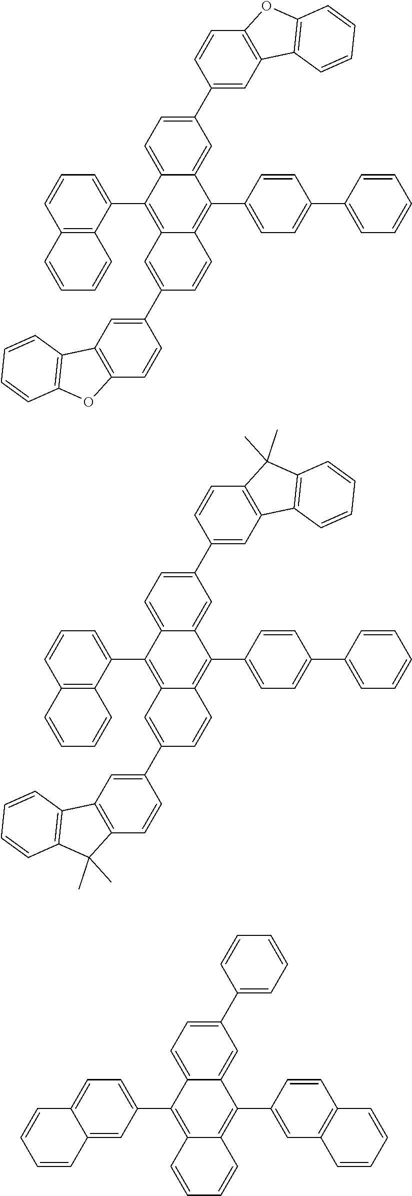

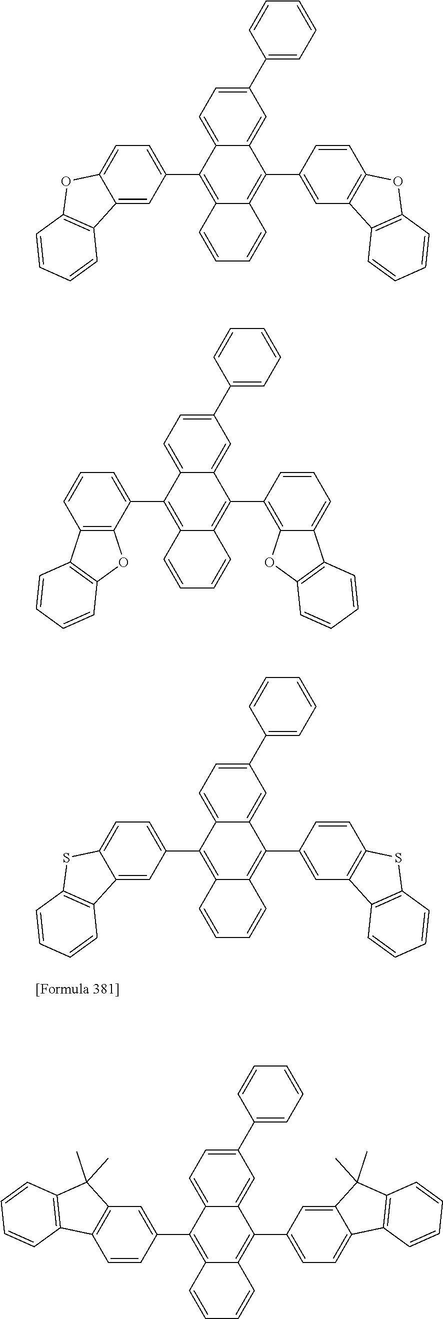

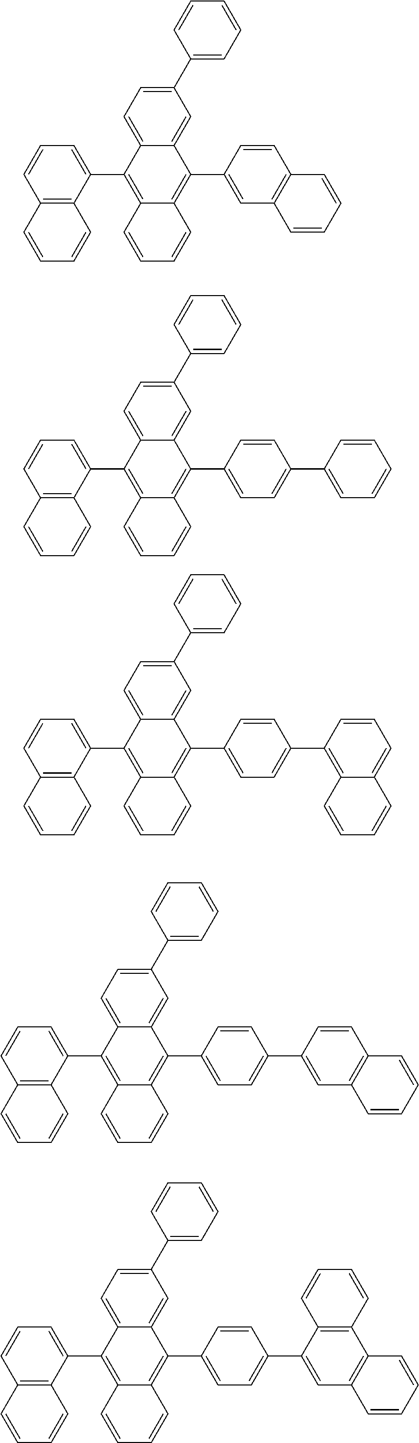

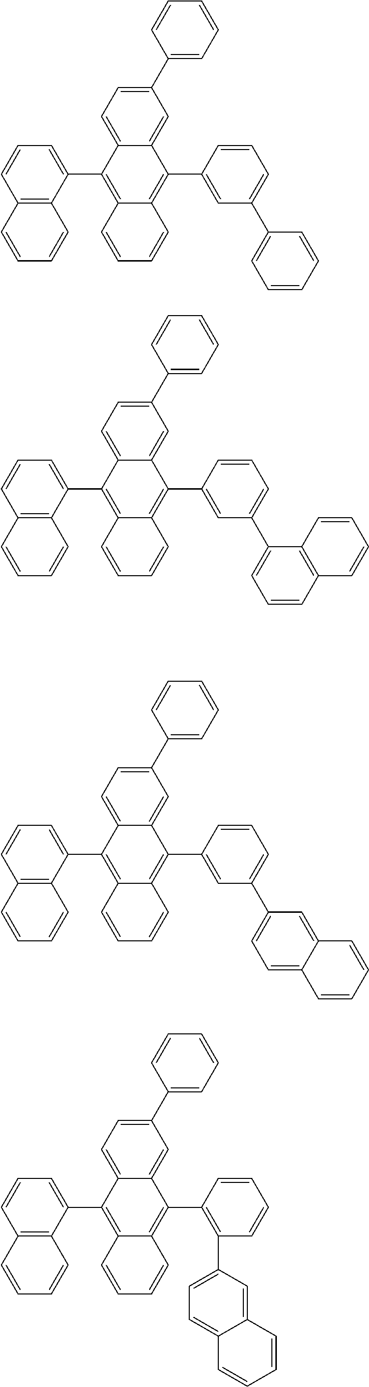

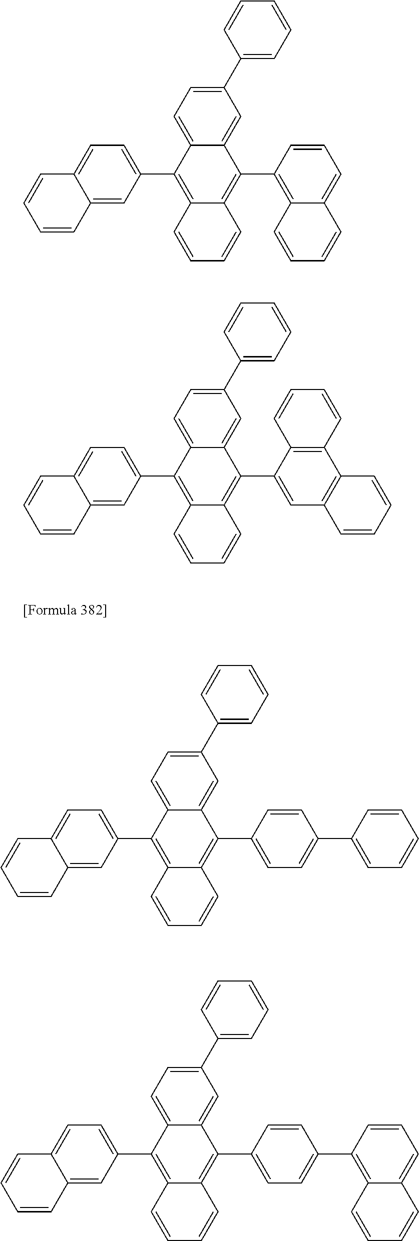

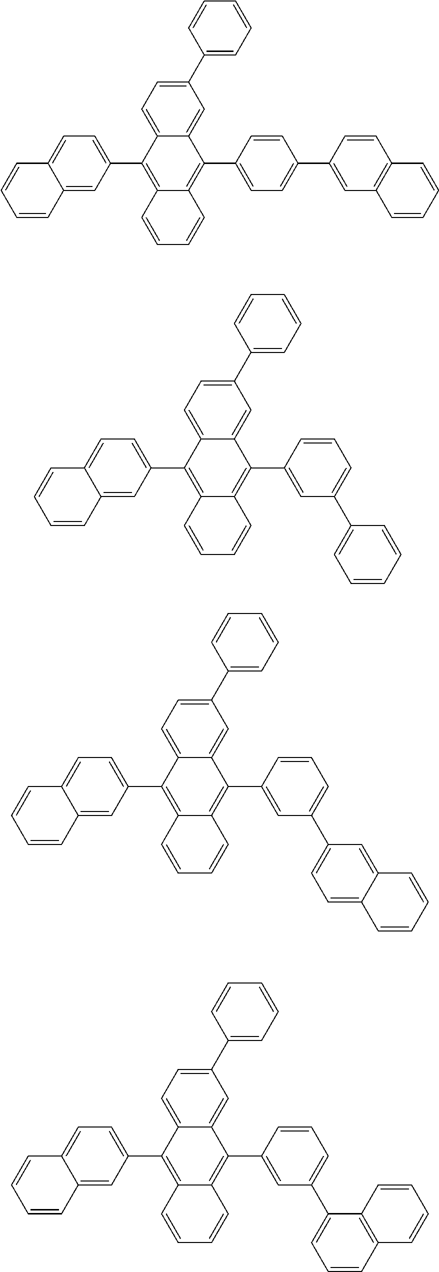

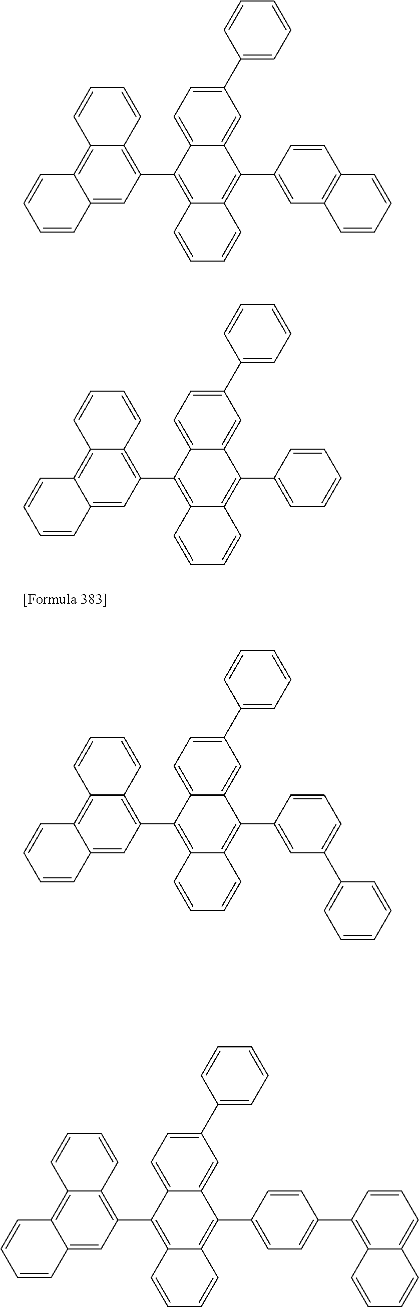

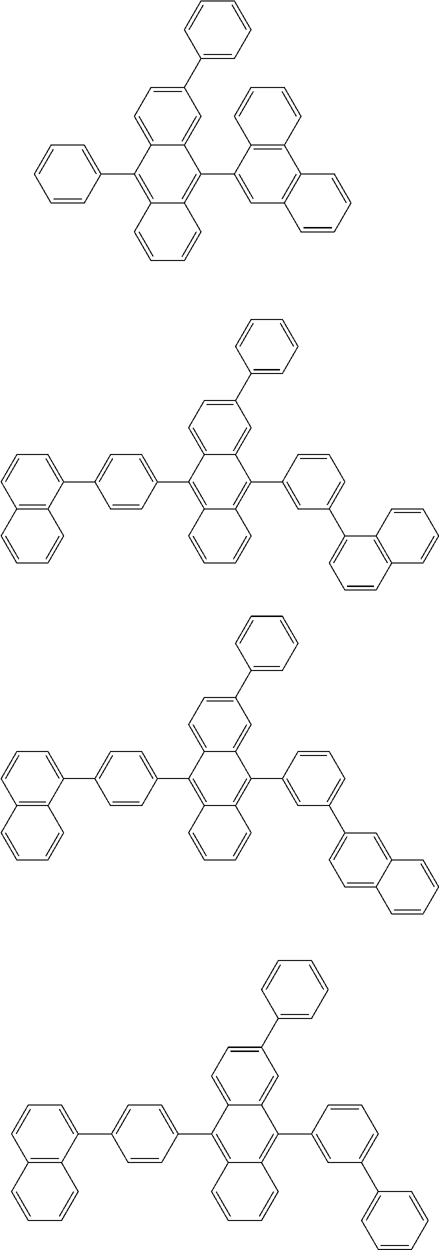

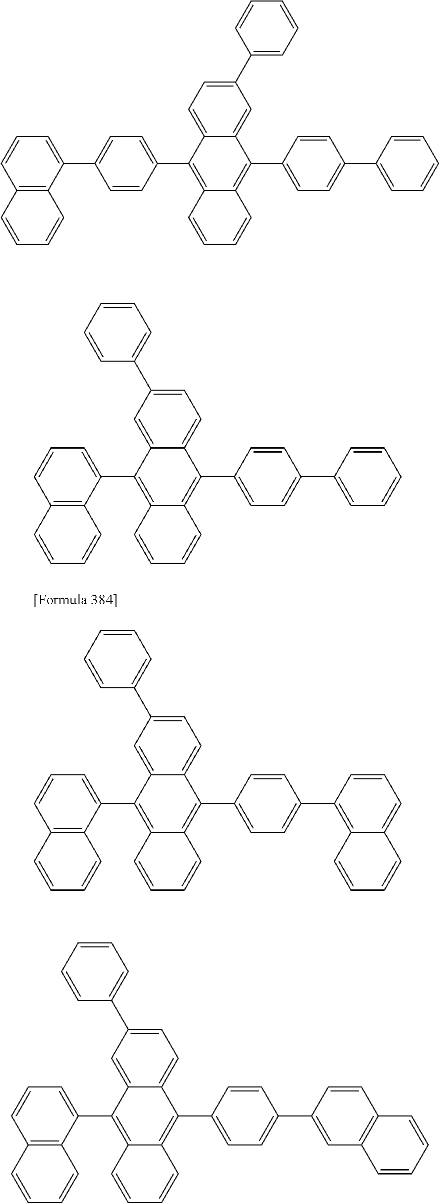

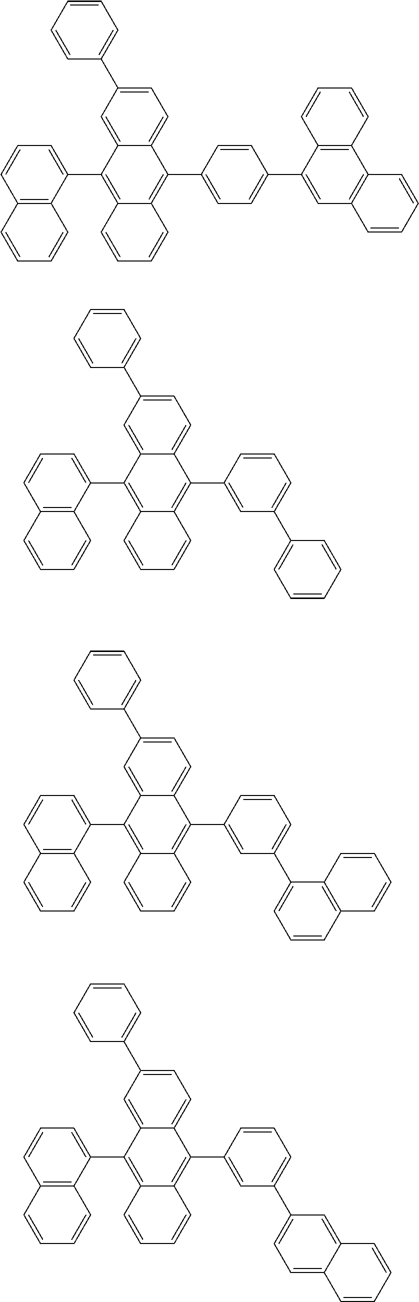

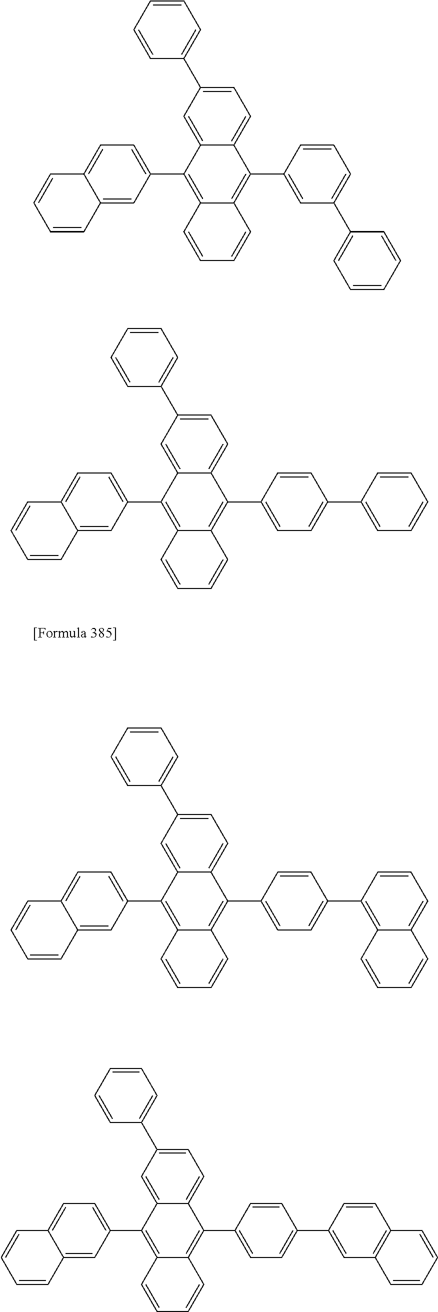

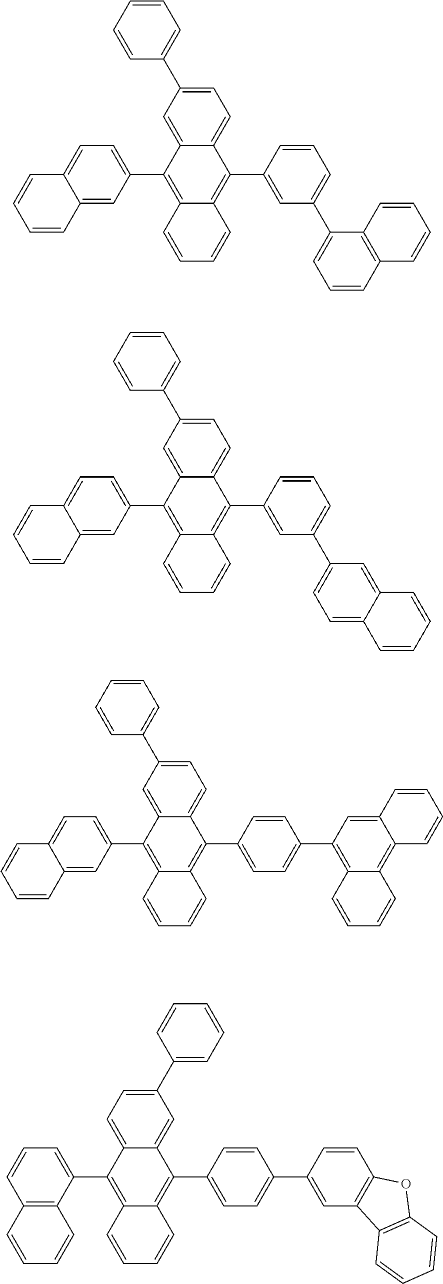

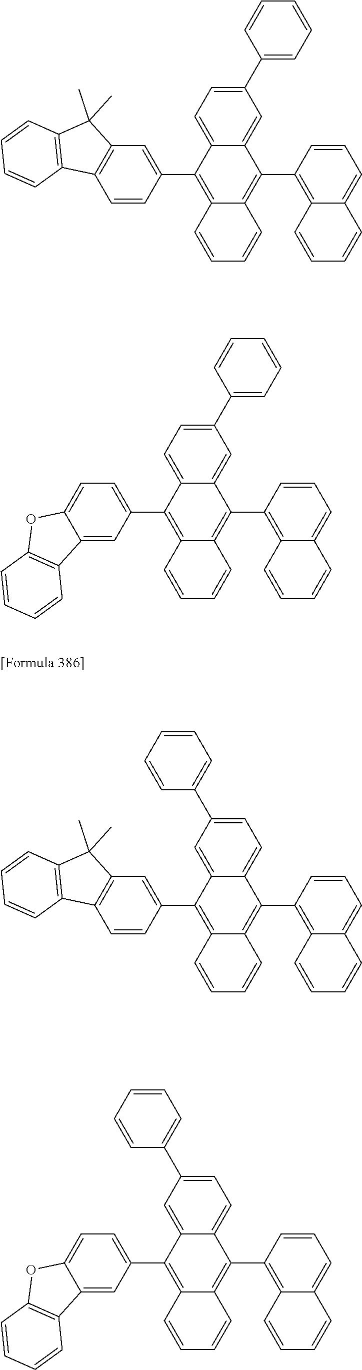

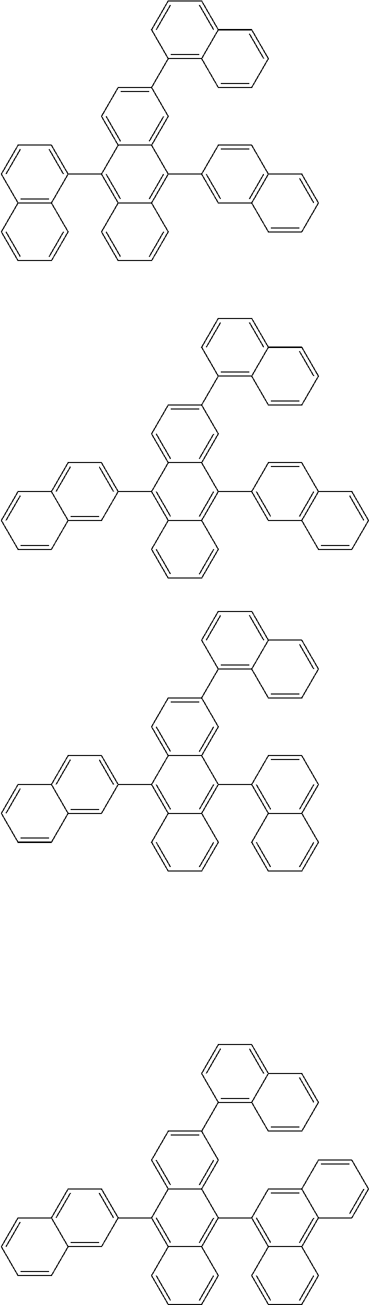

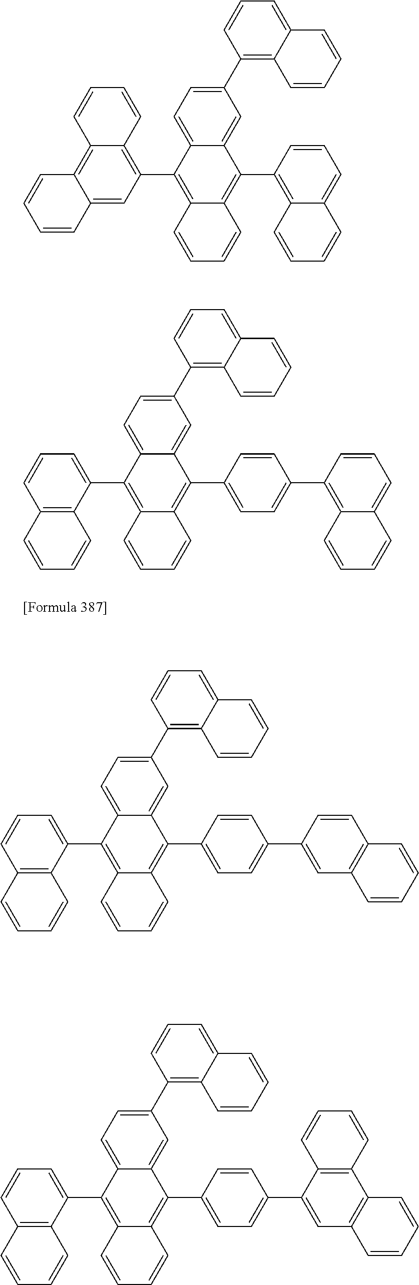

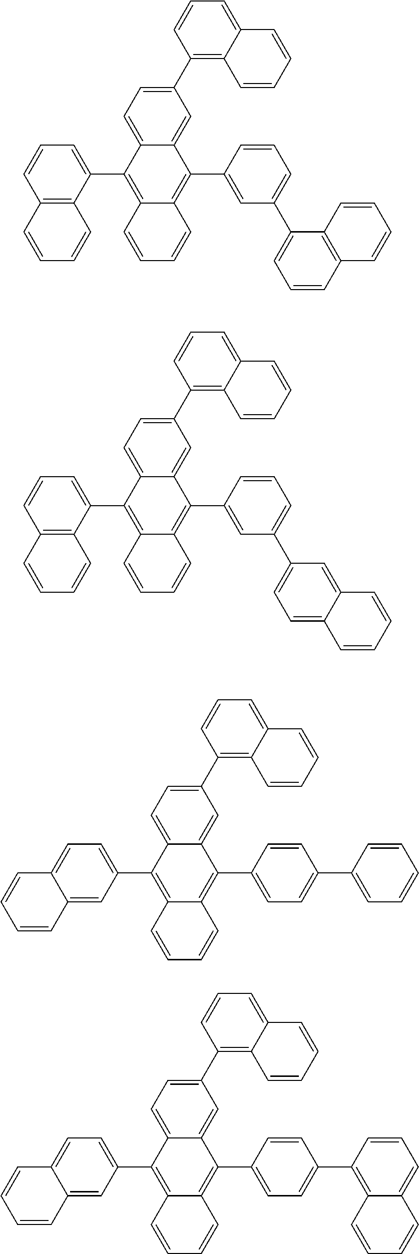

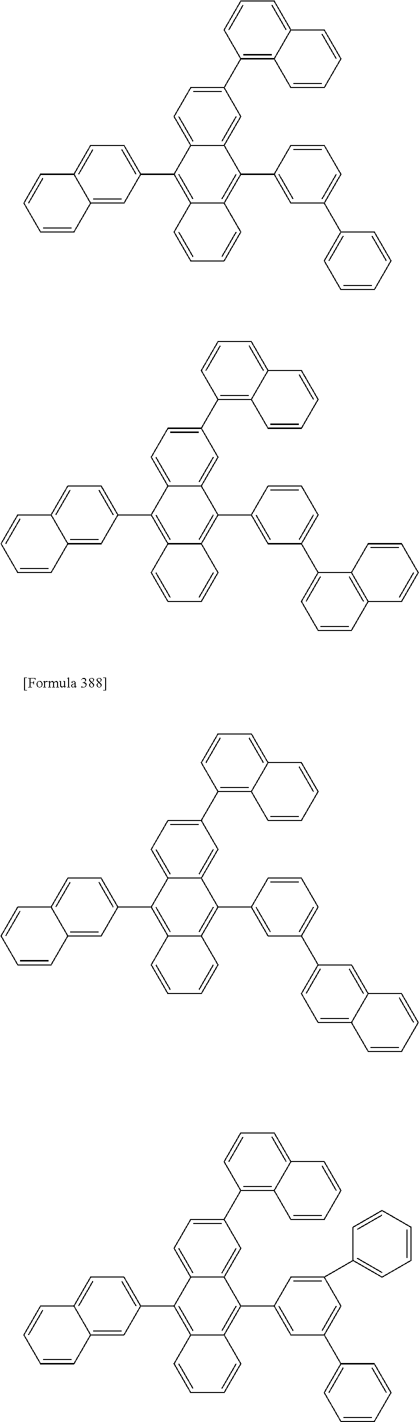

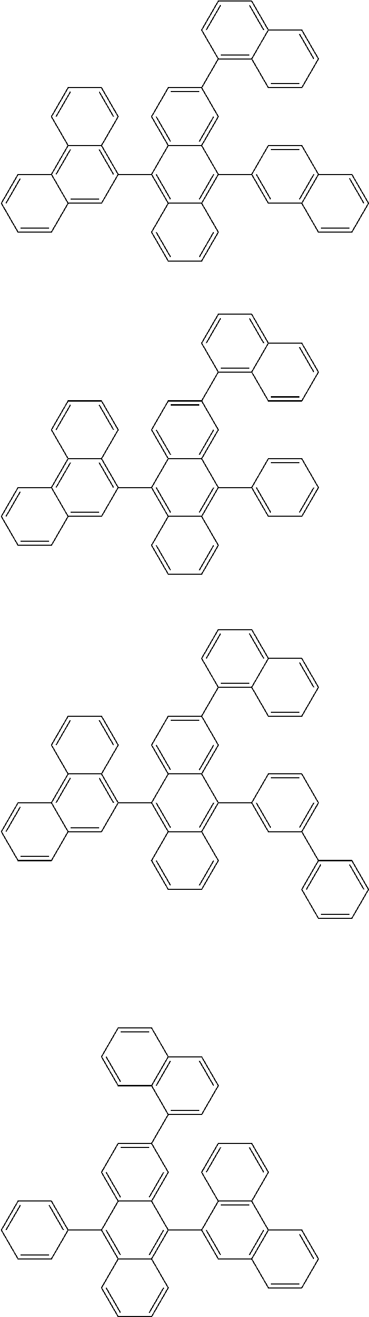

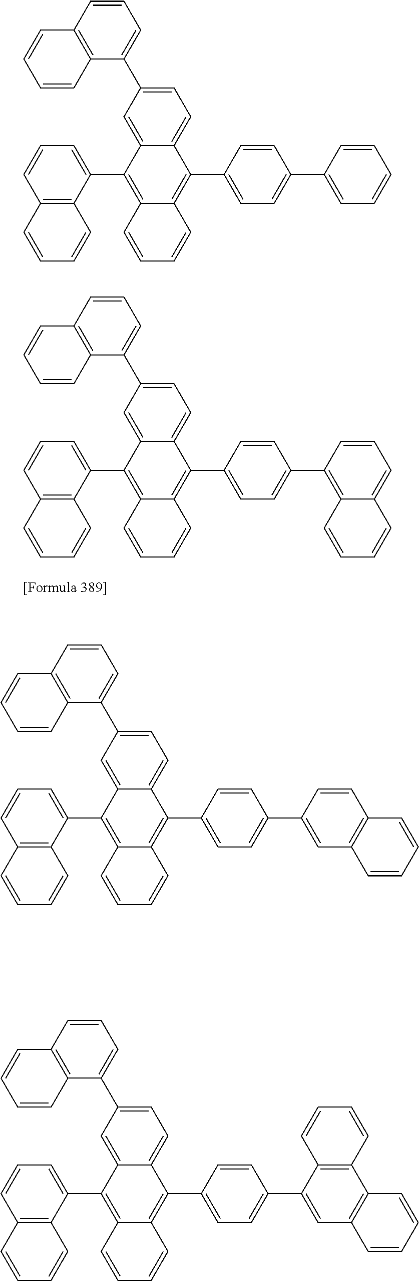

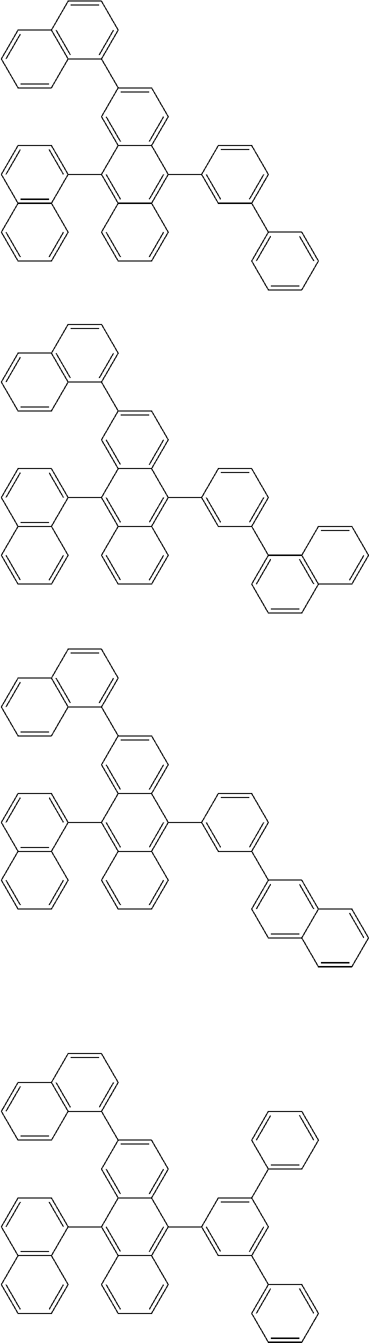

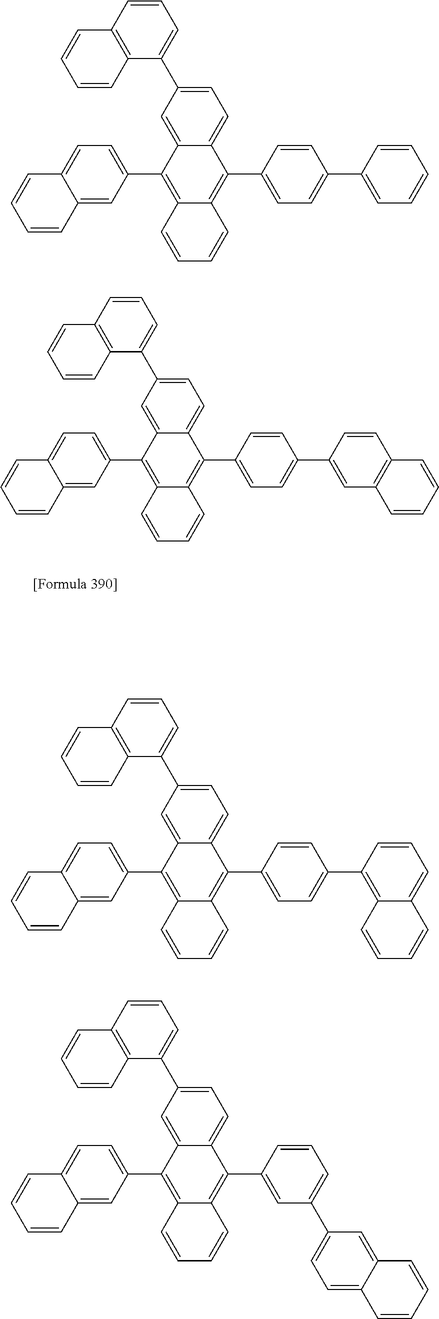

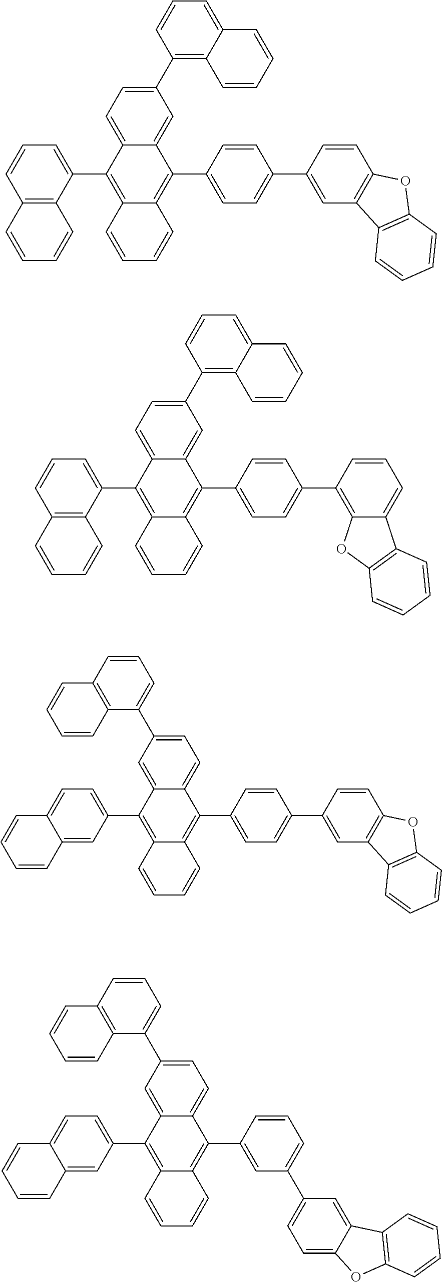 [SMILES: c1ccc2c(-c3ccc4c(-c5cccc6ccccc56)c5ccccc5c(-c5ccc(-c6ccc7oc8ccccc8c7c6)cc5)c4c3)cccc2c1 ; c1ccc2c(-c3ccc4c(-c5cccc6ccccc56)c5ccccc5c(-c5ccc(-c6cccc7c6oc6ccccc67)cc5)c4c3)cccc2c1 ; c1ccc2cc(-c3c4ccccc4c(-c4ccc(-c5ccc6oc7ccccc7c6c5)cc4)c4ccc(-c5cccc6ccccc56)cc34)ccc2c1 ; c1cc(-c2ccc3oc4ccccc4c3c2)cc(-c2c3ccccc3c(-c3ccc4ccccc4c3)c3cc(-c4cccc5ccccc45)ccc23)c1]

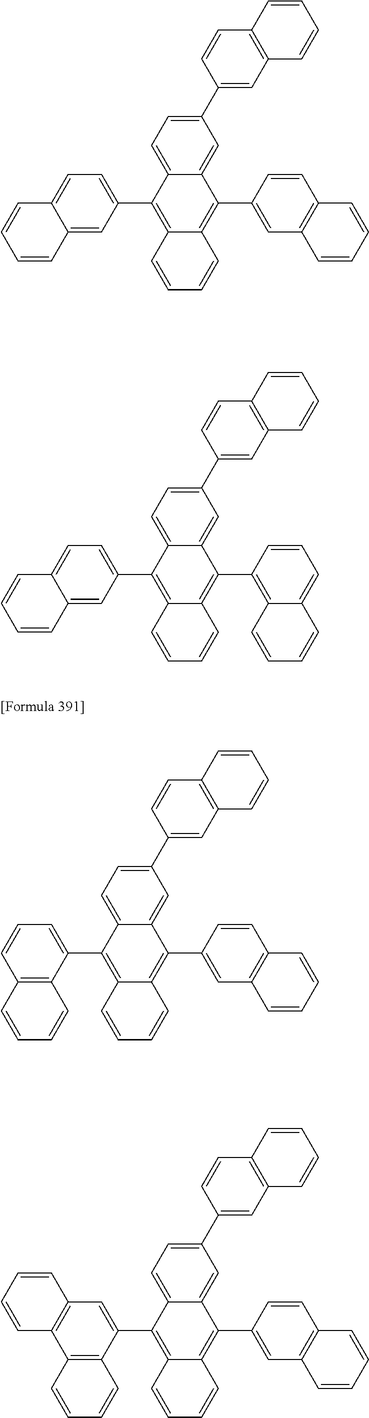

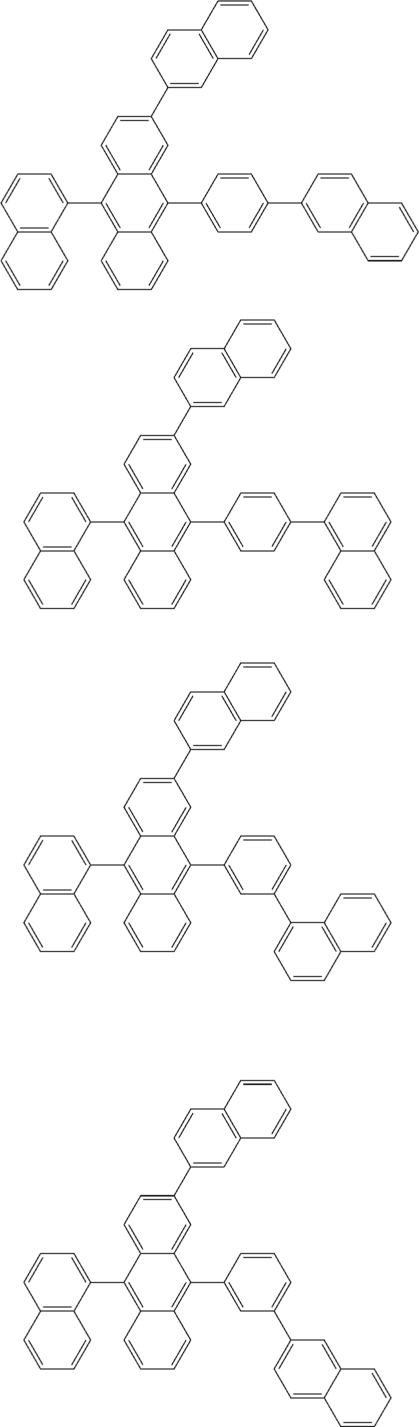

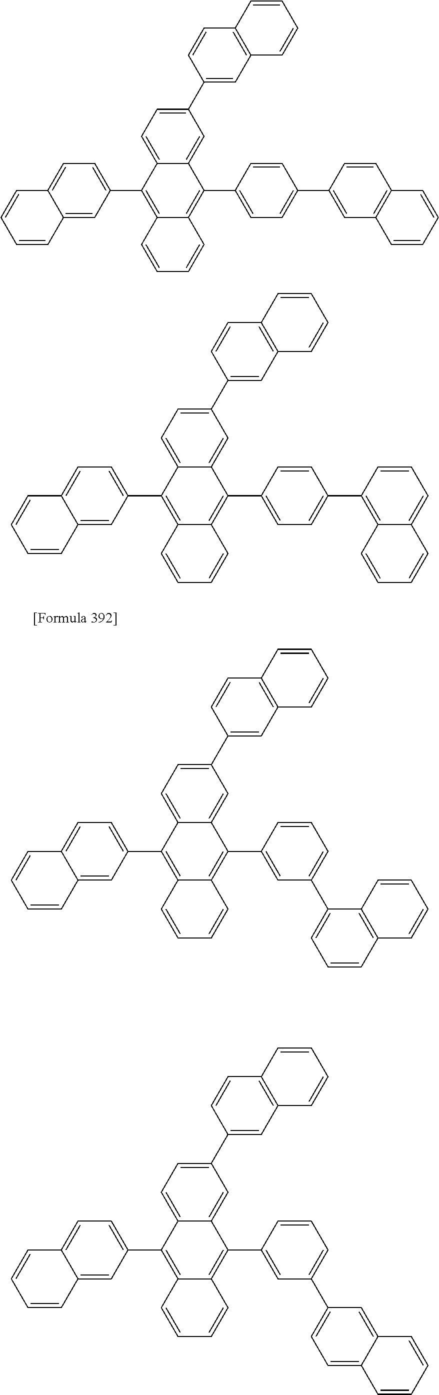

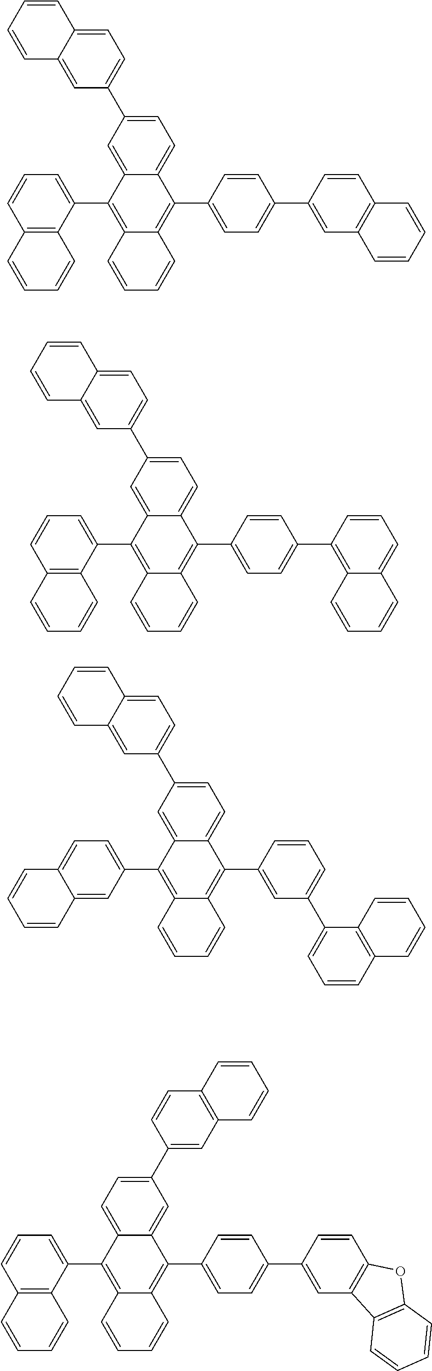

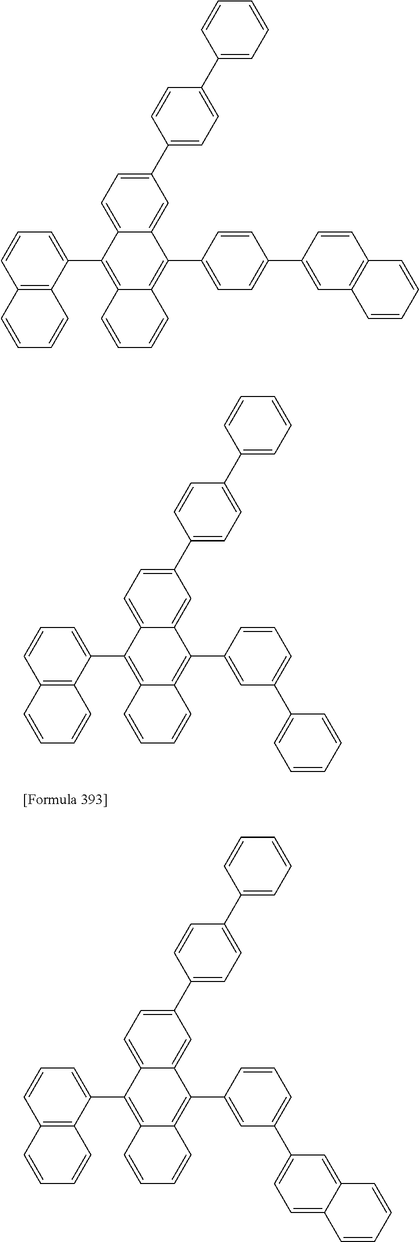

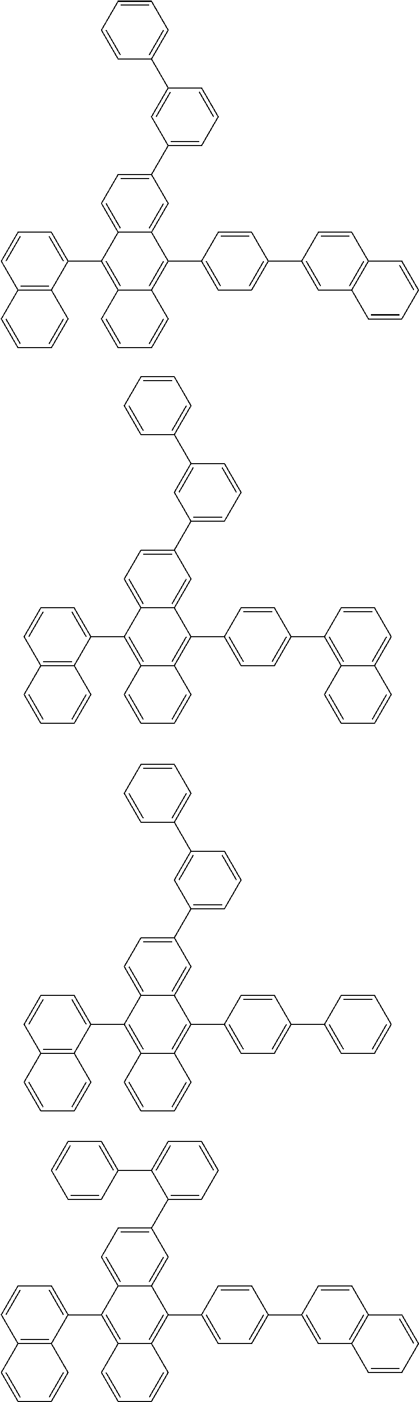

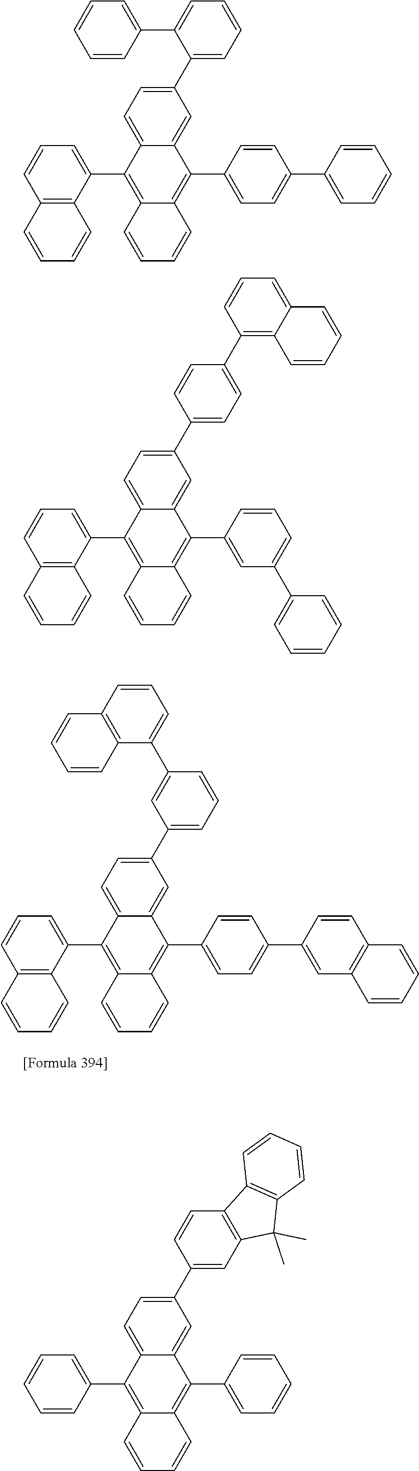

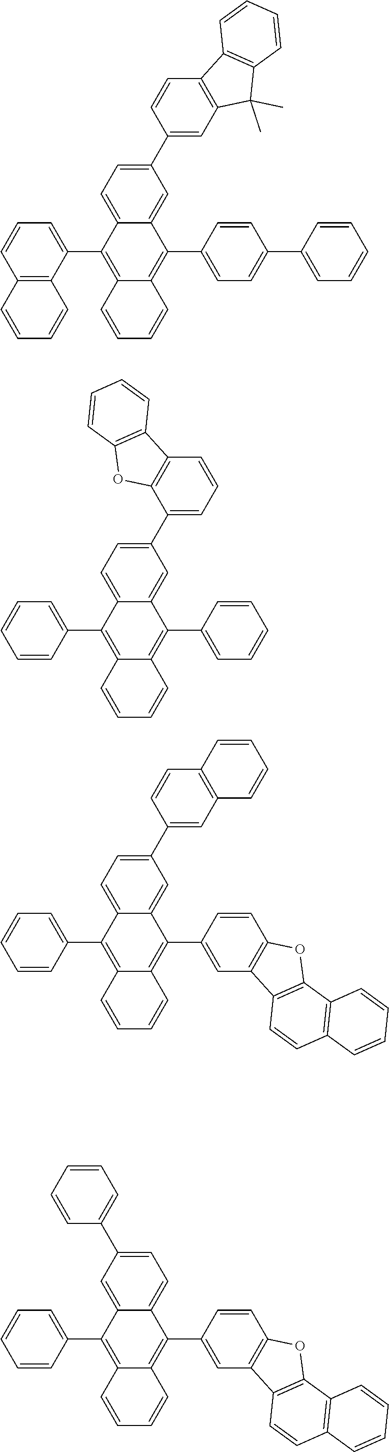

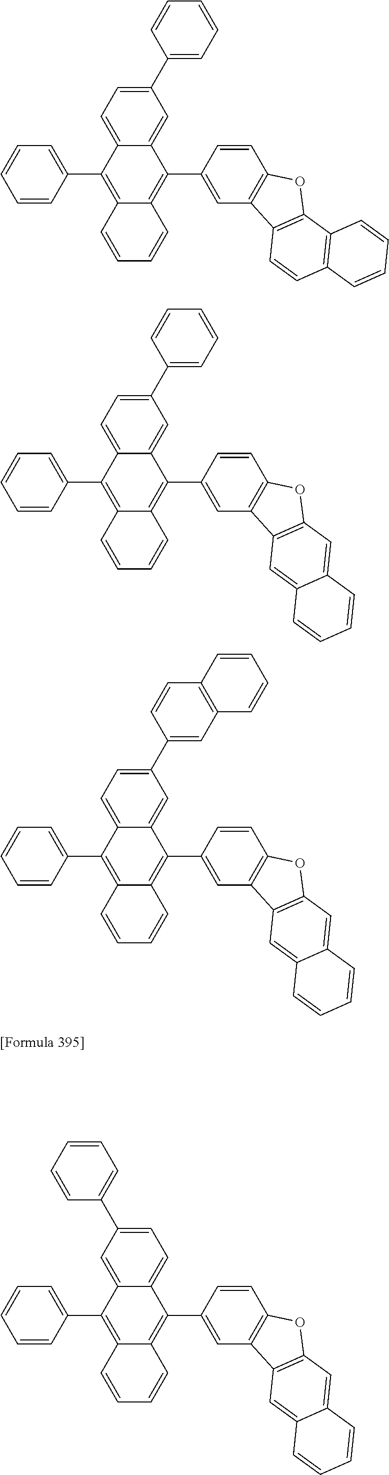 [SMILES: c1ccc(-c2ccc3c(-c4ccccc4)c4ccccc4c(-c4ccc5oc6c7ccccc7ccc6c5c4)c3c2)cc1 ; c1ccc(-c2ccc3c(-c4ccccc4)c4ccccc4c(-c4ccc5oc6cc7ccccc7cc6c5c4)c3c2)cc1 ; c1ccc(-c2c3ccccc3c(-c3ccc4oc5cc6ccccc6cc5c4c3)c3cc(-c4ccc5ccccc5c4)ccc23)cc1 ; c1ccc(-c2ccc3c(-c4ccc5oc6cc7ccccc7cc6c5c4)c4ccccc4c(-c4ccccc4)c3c2)cc1]

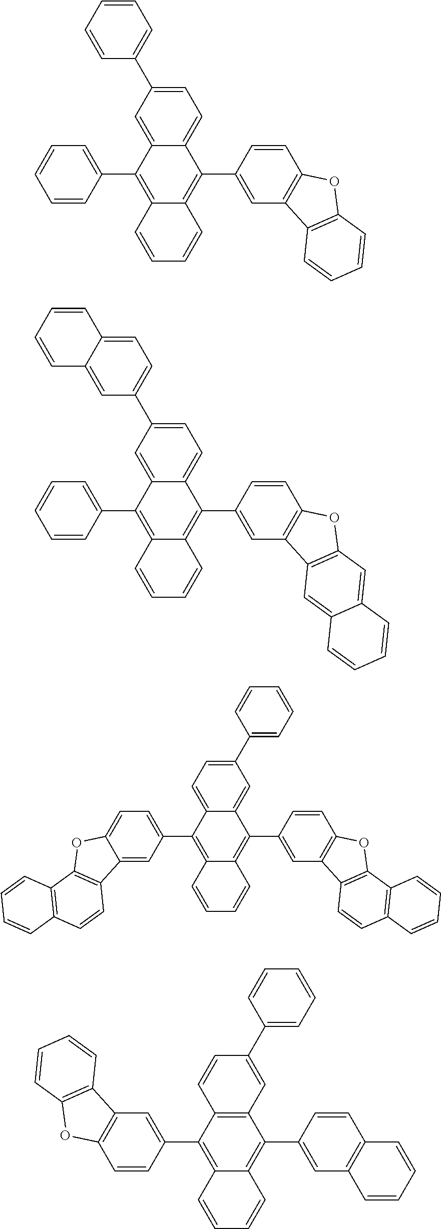 [SMILES: c1ccc(-c2ccc3c(-c4ccc5oc6ccccc6c5c4)c4ccccc4c(-c4ccccc4)c3c2)cc1 ; c1ccc(-c2c3ccccc3c(-c3ccc4oc5cc6ccccc6cc5c4c3)c3ccc(-c4ccc5ccccc5c4)cc23)cc1 ; c1ccc(-c2ccc3c(-c4ccc5oc6c7ccccc7ccc6c5c4)c4ccccc4c(-c4ccc5oc6c7ccccc7ccc6c5c4)c3c2)cc1 ; c1ccc(-c2ccc3c(-c4ccc5oc6ccccc6c5c4)c4ccccc4c(-c4ccc5ccccc5c4)c3c2)cc1]

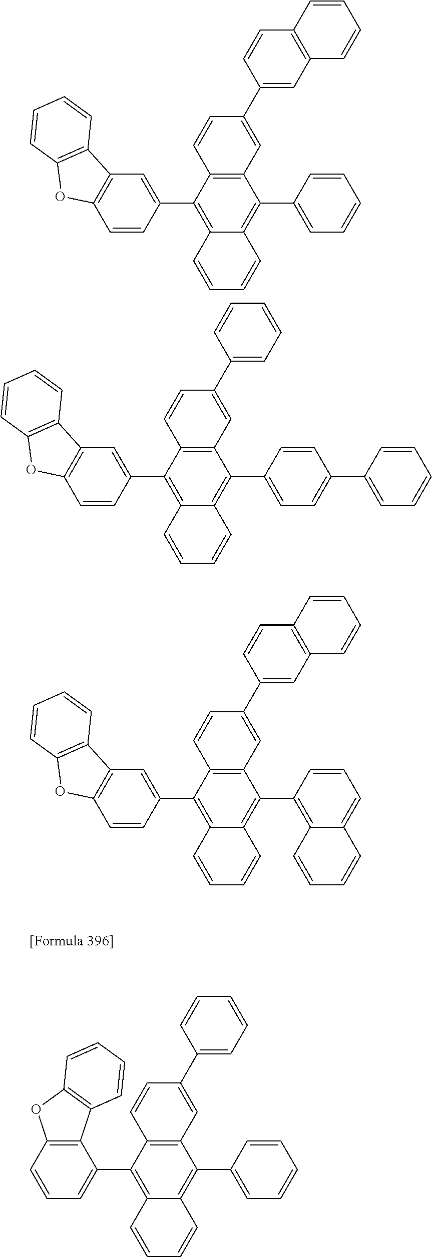

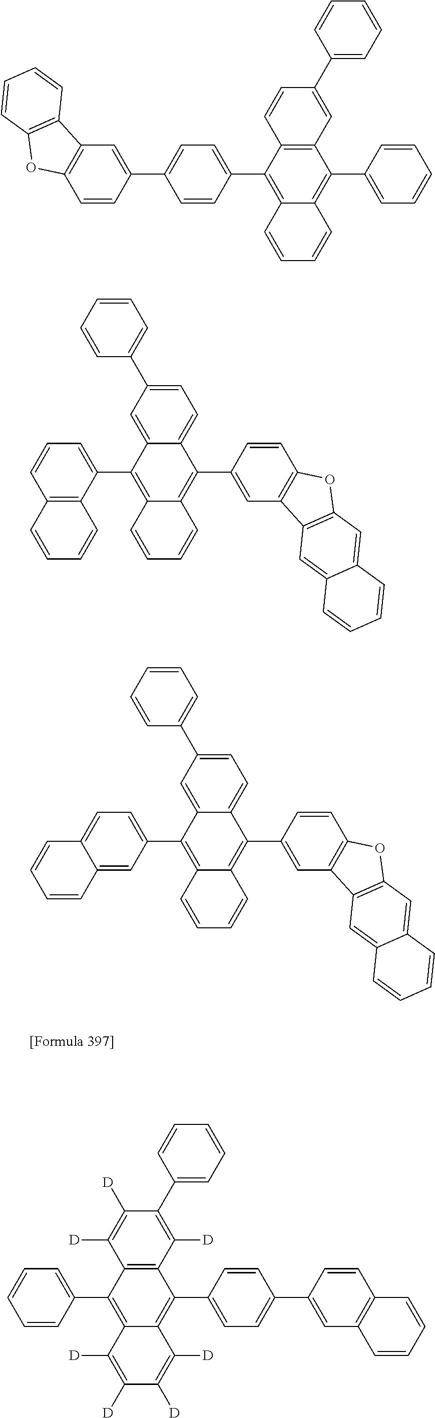 [SMILES: c1ccc(-c2ccc3c(-c4ccc(-c5ccc6oc7ccccc7c6c5)cc4)c4ccccc4c(-c4ccccc4)c3c2)cc1 ; c1ccc(-c2ccc3c(-c4ccc5oc6cc7ccccc7cc6c5c4)c4ccccc4c(-c4cccc5ccccc45)c3c2)cc1 ; c1ccc(-c2ccc3c(-c4ccc5oc6cc7ccccc7cc6c5c4)c4ccccc4c(-c4ccc5ccccc5c4)c3c2)cc1 ; [2H]c1c([2H])c([2H])c2c(-c3ccc(-c4ccc5ccccc5c4)cc3)c3c([2H])c(-c4ccccc4)c([2H])c([2H])c3c(-c3ccccc3)c2c1[2H]]

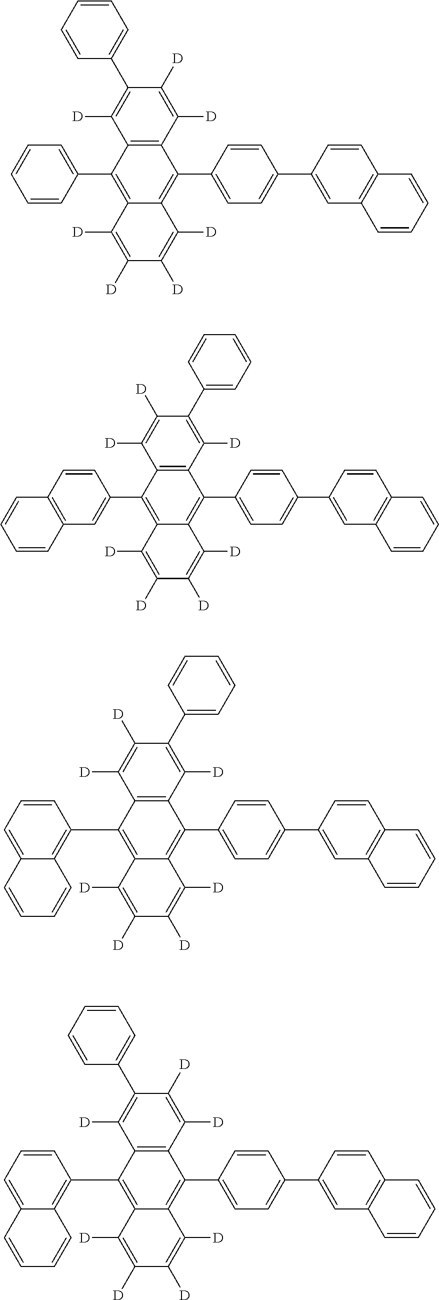 [SMILES: [2H]c1c([2H])c([2H])c2c(-c3ccccc3)c3c([2H])c(-c4ccccc4)c([2H])c([2H])c3c(-c3ccc(-c4ccc5ccccc5c4)cc3)c2c1[2H] ; [2H]c1c([2H])c([2H])c2c(-c3ccc(-c4ccc5ccccc5c4)cc3)c3c([2H])c(-c4ccccc4)c([2H])c([2H])c3c(-c3ccc4ccccc4c3)c2c1[2H] ; [2H]c1c([2H])c([2H])c2c(-c3cccc4ccccc34)c3c([2H])c([2H])c(-c4ccccc4)c([2H])c3c(-c3ccc(-c4ccc5ccccc5c4)cc3)c2c1[2H] ; [2H]c1c([2H])c([2H])c2c(-c3cccc4ccccc34)c3c([2H])c(-c4ccccc4)c([2H])c([2H])c3c(-c3ccc(-c4ccc5ccccc5c4)cc3)c2c1[2H]]

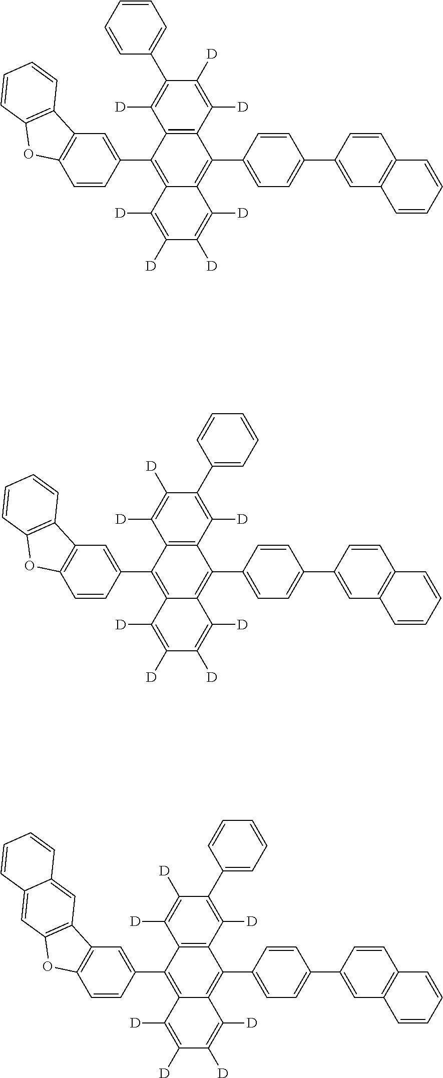 [SMILES: [2H]c1c([2H])c([2H])c2c(-c3ccc4oc5ccccc5c4c3)c3c([2H])c(-c4ccccc4)c([2H])c([2H])c3c(-c3ccc(-c4ccc5ccccc5c4)cc3)c2c1[2H] ; [2H]c1c([2H])c([2H])c2c(-c3ccc(-c4ccc5ccccc5c4)cc3)c3c([2H])c(-c4ccccc4)c([2H])c([2H])c3c(-c3ccc4oc5ccccc5c4c3)c2c1[2H] ; [2H]c1c([2H])c([2H])c2c(-c3ccc(-c4ccc5ccccc5c4)cc3)c3c([2H])c(-c4ccccc4)c([2H])c([2H])c3c(-c3ccc4oc5cc6ccccc6cc5c4c3)c2c1[2H]]

### First Emitting Compound and Second Emitting Compound

In the organic EL device according to the exemplary embodiment, the first emitting compound and the second emitting compound are exemplified by a third compound and a fourth compound below.

The third compound and the fourth compound are each independently at least one compound selected from the group consisting of a compound represented by a formula (4), a compound represented by a formula (5), a compound represented by a formula (41), and a compound represented by a formula (6) below.

### Compound Represented by Formula (4)

The compound represented by the formula (4) will be described.

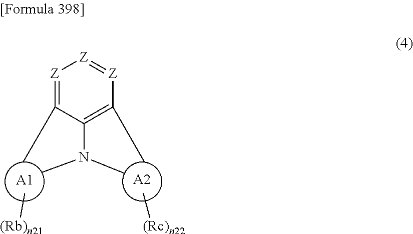

In the formula (4):
each Z is independently CRa or a nitrogen atom;
a ring A1 and a ring A2 are each independently a substituted or unsubstituted aromatic hydrocarbon ring having 6 to 50 ring carbon atoms, or a substituted or unsubstituted heterocycle having 5 to 50 ring atoms;
when a plurality of Ra are present, at least one combination of adjacent two or more of the plurality of Ra are mutually bonded to form a substituted or unsubstituted monocyclic ring, mutually bonded to form a substituted or unsubstituted fused ring, or not mutually bonded;
n21 and n22 are each independently 0, 1, 2, 3, or 4;
when a plurality of Rb are present, at least one combination of adjacent two or more of the plurality of Rb are mutually bonded to form a substituted or unsubstituted monocyclic ring, mutually bonded to form a substituted or unsubstituted fused ring, or not mutually bonded;
when a plurality of Rc are present, at least one combination of adjacent two or more of the plurality of Rc are mutually bonded to form a substituted or unsubstituted monocyclic ring, mutually bonded to form a substituted or unsubstituted fused ring, or not mutually bonded; and
Ra, Rb and Rc forming neither the monocyclic ring nor the fused ring are each independently a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms.

The “aromatic hydrocarbon ring” for the ring A1 and the ring A2 has the same structure as a compound formed by introducing a hydrogen atom to the “aryl group” described above.

Ring atoms of the “aromatic hydrocarbon ring” for the ring A1 and the ring A2 include two carbon atoms on a fused bicyclic structure at the center of the formula (4).

Specific examples of the “substituted or unsubstituted aromatic hydrocarbon ring having 6 to 50 ring carbon atoms” include a compound formed by introducing a hydrogen atom to the “aryl group” described in the specific example group G1.

The “heterocycle” for the ring A1 and the ring A2 has the same structure as a compound formed by introducing a hydrogen atom to the “heterocyclic group” described above.

Ring atoms of the “heterocycle” for the ring A1 and the ring A2 include two carbon atoms on a fused bicyclic structure at the center of the formula (4).

Specific examples of the “substituted or unsubstituted heterocycle having 5 to 50 ring atoms” include a compound formed by introducing a hydrogen atom to the “heterocyclic group” described in the specific example group G2.

Rb is bonded to any one of carbon atoms forming the aromatic hydrocarbon ring as the ring A1 or any one of atoms forming the heterocycle as the ring A1.

Rc is bonded to any one of carbon atoms forming the aromatic hydrocarbon ring as the ring A2 or any one of atoms forming the heterocycle as the ring A2.

At least one of Ra, Rb, or Rc is preferably a group represented by a formula (4a) below. More preferably, at least two of Ra, Rb, and Rc are each a group represented by the formula (4a).

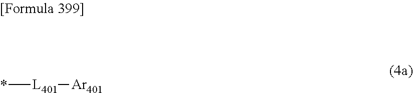

In the formula (4a):
L₄₀₁ is a single bond, a substituted or unsubstituted arylene group having 6 to 30 ring carbon atoms, or a substituted or unsubstituted divalent heterocyclic group having 5 to 30 ring atoms; and
Ar₄₀₁ is a substituted or unsubstituted aryl group having 6 to 50 ring carbon atoms, a substituted or unsubstituted heterocyclic group having 5 to 50 ring atoms, or a group represented by a formula (4b) below.

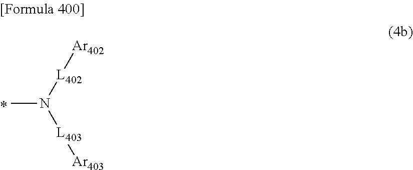

In the formula (4b):
L₄₀₂ and L₄₀₃ are each independently a single bond, a substituted or unsubstituted arylene group having 6 to 30 ring carbon atoms, or a substituted or unsubstituted divalent heterocyclic group having 5 to 30 ring atoms;
a combination of Ar₄₀₂ and Ar₄₀₃ are mutually bonded to form a substituted or unsubstituted monocyclic ring, mutually bonded to form a substituted or unsubstituted fused ring, or not mutually bonded; and
Ar₄₀₂ and Ar₄₀₃ forming neither the monocyclic ring nor the fused ring are each independently a substituted or unsubstituted aryl group having 6 to 50 ring carbon atoms, or a substituted or unsubstituted heterocyclic group having 5 to 50 ring atoms.

In an exemplary embodiment, the compound represented by the formula (4) is represented by a formula (42) below.

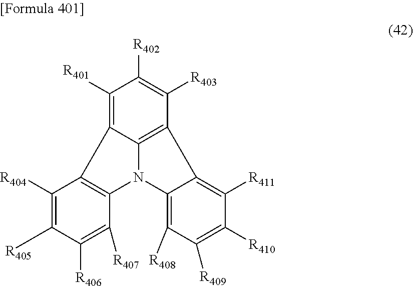

In the formula (42):
at least one combination of adjacent two or more of R₄₀₁ to R₄₁₁ are mutually bonded to form a substituted or unsubstituted monocyclic ring, mutually bonded to form a substituted or unsubstituted fused ring, or not mutually bonded; and
R₄₀₁ to R₄₁₁ forming neither the monocyclic ring nor the fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms.

At least one of R₄₀₁ to R₄₁₁ is preferably a group represented by the formula (4a). More preferably, at least two of R₄₀₁ to R₄₁₁ are each a group represented by the formula (4a).

R₄₀₄ and R₄₁₁ are each preferably a group represented by the formula (4a).

In an exemplary embodiment, the compound represented by the formula (4) is a compound formed by bonding a structure represented by a formula (4-1) or a formula (4-2) below to the ring A1.

Further, in an exemplary embodiment, the compound represented by the formula (42) is a compound formed by bonding a structure represented by the formula (4-1) or the formula (4-2) to a ring bonded to R₄₀₄ to R₄₀₇.

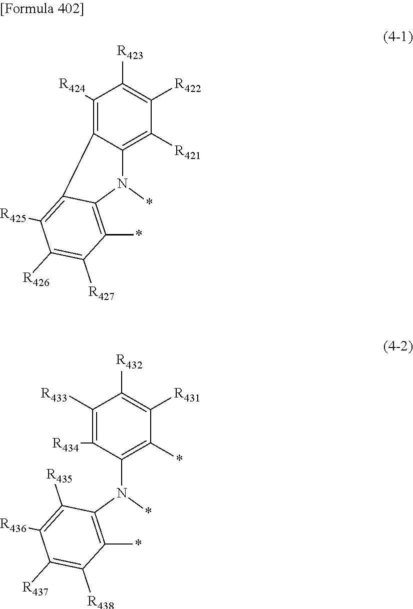

In the formula (4-1), two * are each independently bonded to a ring-forming carbon atom of the aromatic hydrocarbon ring or a ring atom of the heterocycle as the A1 ring in the formula (4) or bonded to one of R₄₀₄ to R₄₀₇ in the formula (42);

in the formula (4-2), three * are each independently bonded to a ring-forming carbon atom of the aromatic hydrocarbon ring or a ring atom of the heterocycle as the A1 ring in the formula (4) or bonded to one of R₄₀₄ to R₄₀₇ in the formula (42);

at least one combination of adjacent two or more of R₄₂₁ to R₄₂₇ are mutually bonded to form a substituted or unsubstituted monocyclic ring, mutually bonded to form a substituted or unsubstituted fused ring, or not mutually bonded;

at least one combination of adjacent two or more of R₄₃₁ to R₄₃₈ are mutually bonded to form a substituted or unsubstituted monocyclic ring, mutually bonded to form a substituted or unsubstituted fused ring, or not mutually bonded; and

R₄₂₁ to R₄₂₇ and R₄₃₁ to R₄₃₈ forming neither the monocyclic ring nor the fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms.

In an exemplary embodiment, the compound represented by the formula (4) is a compound represented by a formula (41-3), (41-4), or (41-5) below.

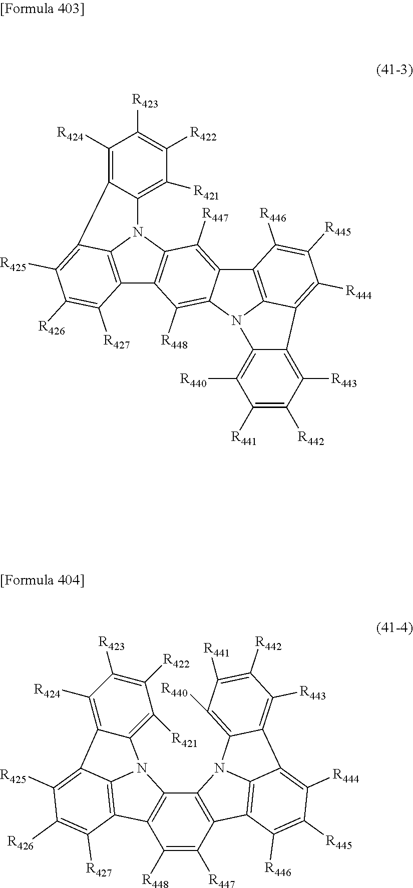

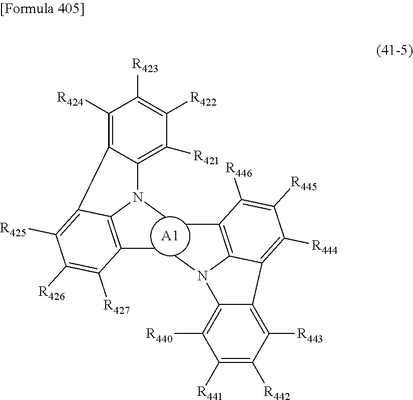

In the formulae (41-3), (41-4), and (41-5):
a ring A1 is as defined in the formula (4);
R₄₂₁ to R₄₂₇ each independently represent the same as R₄₂₁ to R₄₂₇ in the formula (4-1); and
R₄₄₀ to R₄₄₈ each independently represent the same as R₄₀₁ to R₄₁₁ in the formula (42).

In an exemplary embodiment, a substituted or unsubstituted aromatic hydrocarbon ring having 6 to 50 ring carbon atoms as the ring A1 in the formula (41-5) is a substituted or unsubstituted naphthalene group, or a substituted or unsubstituted fluorene ring.

In an exemplary embodiment, a substituted or unsubstituted heterocycle having 5 to 50 ring atoms as the ring A1 in the formula (41-5) is a substituted or unsubstituted dibenzofuran ring, a substituted or unsubstituted carbazole ring, or a substituted or unsubstituted dibenzothiophene ring.

In an exemplary embodiment, the compound represented by the formula (4) or the formula (42) is selected from the group consisting of compounds represented by formulae (461) to (467) below.

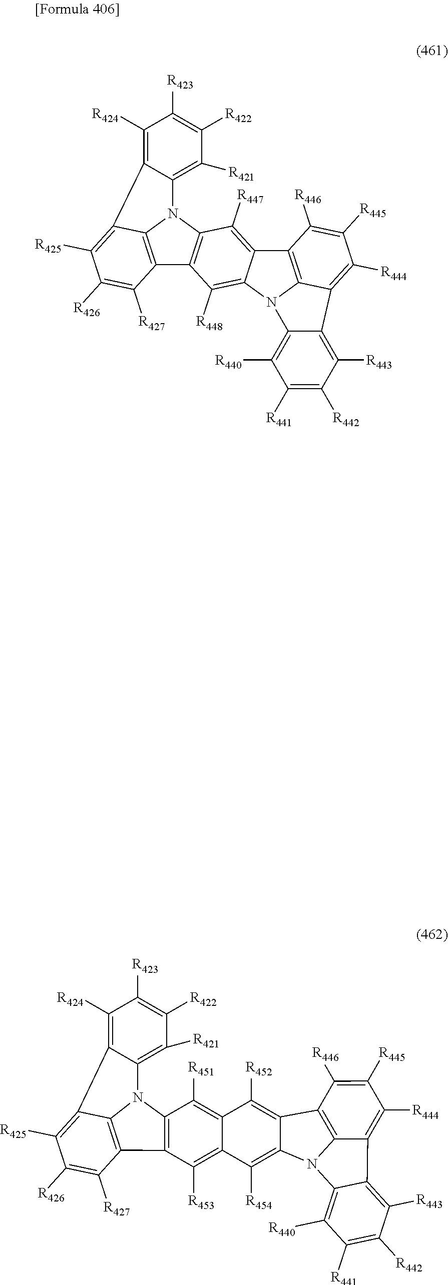

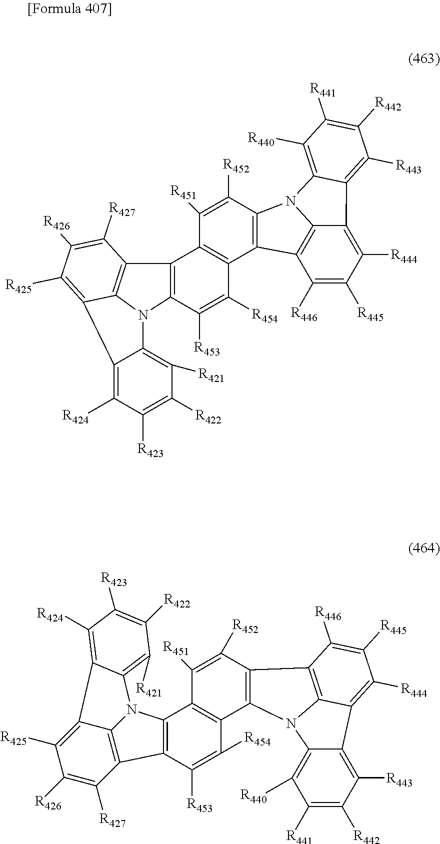

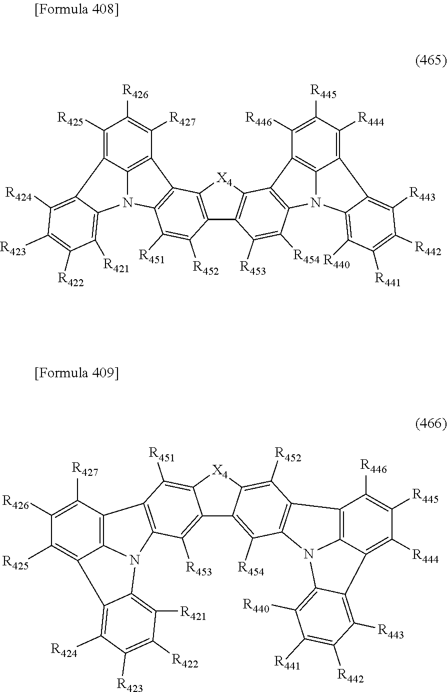

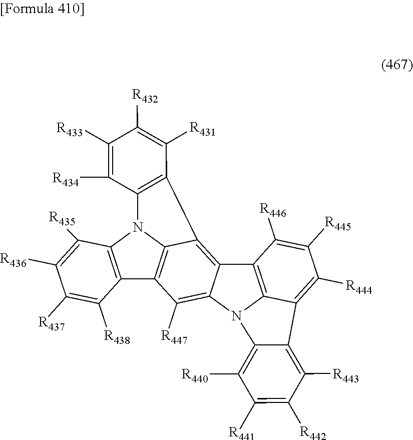

In the formulae (461), (462), (463), (464), (465), (466) and (467):
R₄₂₁ to R₄₂₇ each independently represent the same as R₄₂₁ to R₄₂₇ in the formula (4-1);
R₄₃₁ to R₄₃₈ each independently represent the same as R₄₃₁ to R₄₃₈ in the formula (4-2);
R₄₄₀ to R₄₄₈ and R₄₅₁ to R₄₅₄ each independently represent the same as R₄₀₁ to R₄₁₁ in the formula (42);
X₄ is an oxygen atom, NR₈₀₁, or C(R₈₀₂)(R₈₀₃);
R₈₀₁, R₈₀₂ and R₈₀₃ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms; preferably, a substituted or unsubstituted alkyl group having 1 to 50 carbon atoms, or a substituted or unsubstituted aryl group having 6 to 50 ring carbon atoms;
when a plurality of R₈₀₁ are present, the plurality of R₈₀₁ are mutually the same or different;
when a plurality of R₈₀₂ are present, the plurality of R₈₀₂ are mutually the same or different; and
when a plurality of R₈₀₃ are present, the plurality of R₈₀₃ are mutually the same or different.

In an exemplary embodiment, in a compound represented by the formula (42), at least one combination of adjacent two or more of R₄₀₁ to R₄₁₁ are mutually bonded to form a substituted or unsubstituted monocyclic ring or are mutually bonded to form a substituted or unsubstituted fused ring. The compound represented by the formula (42) in the exemplary embodiment is described in detail as a compound represented by a formula (45) below.

### Compound Represented by Formula (45)

The compound represented by the formula (45) will be described.

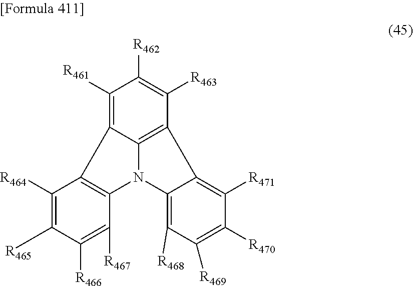

In the formula (45):

two or more of combinations selected from the group consisting of a combination of R₄₆₁ and R₄₆₂, a combination of R₄₆₂ and R₄₆₃, a combination of R₄₆₄ and R₄₆₅, a combination of R₄₆₅ and R₄₆₆, a combination of R₄₆₆ and R₄₆₇, a combination of R₄₆₈ and R₄₆₉, a combination of R₄₆₉ and R₄₇₀, and a combination of R₄₇₀ and R₄₇₁ are mutually bonded to form a substituted or unsubstituted monocyclic ring or a substituted or unsubstituted fused ring.

Here, the combination of R₄₆₁ and R₄₆₂ and the combination of R₄₆₂ and R₄₆₃; the combination of R₄₆₄ and R₄₆₅ and the combination of R₄₆₅ and R₄₆₆; the combination of R₄₆₅ and R₄₆₆ and the combination of R₄₆₆ and R₄₆₇; the combination of R₄₆₈ and R₄₆₉ and the combination of R₄₆₉ and R₄₇₀; and the combination of R₄₆₉ and R₄₇₀ and the combination of R₄₇₀ and R₄₇₁ do not simultaneously form a ring;

the two or more rings formed by R₄₆₁ to R₄₇₁ are mutually the same or different; and

R₄₆₁ to R₄₇₁ forming neither the monocyclic ring nor the fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms.

In the formula (45), Rₙ and Rₙ₊₁ (n being an integer selected from 461, 462, 464 to 466, and 468 to 470) are mutually bonded to form a substituted or unsubstituted monocyclic ring or fused ring together with two ring-forming carbon atoms bonded to Rₙ and Rₙ₊₁. The ring is preferably formed of atoms selected from the group consisting of a carbon atom, an oxygen atom, a sulfur atom, and a nitrogen atom, and is preferably made of 3 to 7, more preferably 5 or 6 atoms.

The number of the above cyclic structures in the compound represented by the formula (45) is, for instance, 2, 3, or 4. The two or more of the cyclic structures may be present on the same benzene ring on the basic skeleton represented by the formula (45) or may be present on different benzene rings. For instance, when three cyclic structures are present, each of the cyclic structures may be present on the corresponding one of the three benzene rings of the formula (45).

Examples of the above cyclic structures in the compound represented by the formula (45) include structures represented by formulae (451) to (460) below.

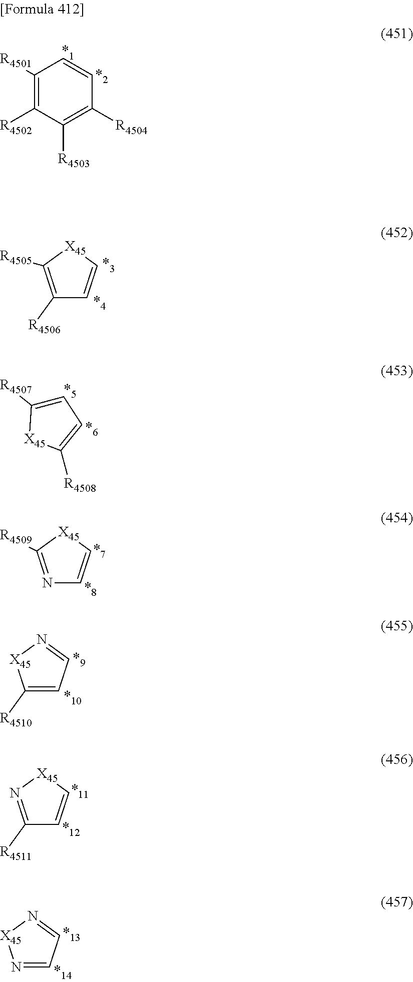

In the formulae (451) to (457):
each combination of *1 and *2, *3 and *4, *5 and *6, *7 and *8, *9 and *10, *11 and *12, and *13 and *14 represent the two ring-forming carbon atoms bonded to Rₙ and Rₙ₊₁;
the ring-forming carbon atom bonded to Rn may be any one of the two ring-forming carbon atoms represented by *1 and *2, *3 and *4, *5 and *6, *7 and *8, *9 and *10, *11 and *12, and *13 and *14;
X₄₅ is C(R₄₅₁₂)(R₄₅₁₃), NR₄₅₁₄, an oxygen atom, or a sulfur atom;

at least one combination of adjacent two or more of R₄₅₀₁ to R₄₅₀₆ and R₄₅₁₂ to R₄₅₁₃ are mutually bonded to form a substituted or unsubstituted monocyclic ring, mutually bonded to form a substituted or unsubstituted fused ring, or not mutually bonded; and
R₄₅₀₁ to R₄₅₁₄ forming neither the monocyclic ring nor the fused ring each independently represent the same as R₄₆₁ to R₄₇₁ in the formula (45).

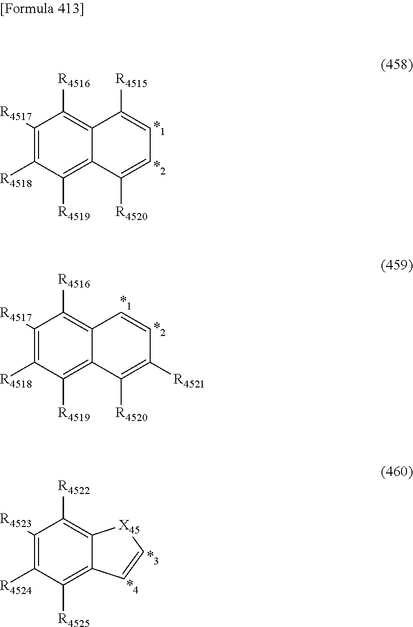

In the formulae (458) to (460):
each combination of *1 and *2, and *3 and *4 represent the two ring-forming carbon atoms bonded to Rₙ and Rₙ₊₁;
the ring-forming carbon atom bonded to Rn may be any one of the two ring-forming carbon atoms represented by *1 and *2, or *3 and *4;
X₄₅ is C(R₄₅₁₂)(R₄₅₁₃), NR₄₅₁₄, an oxygen atom, or a sulfur atom;
at least one combination of adjacent two or more of R₄₅₁₂ to R₄₅₁₃ and R₄₅₁₅ to R₄₅₂₅ are mutually bonded to form a substituted or unsubstituted monocyclic ring, mutually bonded to form a substituted or unsubstituted fused ring, or not mutually bonded; and
R₄₅₁₂ to R₄₅₁₃, R₄₅₁₅ to R₄₅₂₁ and R₄₅₂₂ to R₄₅₂₅ forming neither the monocyclic ring nor the fused ring, and R₄₅₁₄ each independently represent the same as R₄₆₁ to
R₄₇₁ in the formula (45).

In the formula (45), it is preferable that at least one of R₄₆₂, R₄₆₄, R₄₆₅, R₄₇₀ or R₄₇₁ (preferably, at least one of R₄₆₂, R₄₆₅ or R₄₇₀, more preferably R₄₆₂) is a group forming no cyclic structure.

(i) In the formula (45), a substituent, if present, for a cyclic structure formed by Rₙ and Rₙ₊₁, (ii) in the formula (45), R₄₆₁ to R₄₇₁ forming no cyclic structure, and (iii) R₄₅₀₁ to R₄₅₁₄, R₄₅₁₅ to R₄₅₂₅ in the formulae (451) to (460) are preferably each independently a group selected from the group consisting of a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —N(R₉₀₆)(R₉₀₇), a substituted or unsubstituted aryl group having 6 to 50 ring carbon atoms, a substituted or unsubstituted heterocyclic group having 5 to 50 ring atoms, or groups represented by formulae (461) to (464).

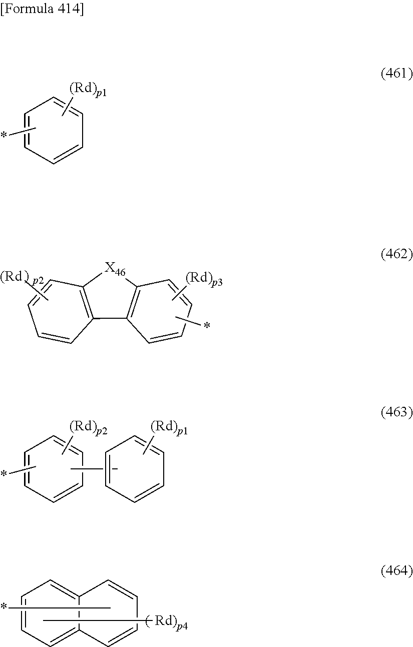

In the formulae (461) to (464):
R_{d} are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, preferably, a substituted or unsubstituted aryl group having 6 to 50 ring carbon atoms, or a substituted or unsubstituted heterocyclic group having 5 to 50 ring atoms;
X₄₆ is C(R₈₀₁)(R₈₀₂), NR₈₀₃, an oxygen atom, or a sulfur atom;
R₈₀₁, R₈₀₂ and R₈₀₃ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
a substituted or unsubstituted alkyl group having 1 to 50 carbon atoms, or a substituted or unsubstituted aryl group having 6 to 50 ring carbon atoms;
when a plurality of R₈₀₁ are present, the plurality of R₈₀₁ are mutually the same or different;
when a plurality of R₈₀₂ are present, the plurality of R₈₀₂ are mutually the same or different;
when a plurality of R₈₀₃ are present, the plurality of R₈₀₃ are mutually the same or different;
p1 is 5;
p2 is 4;
p3 is 3;
p4 is 7; and
* in the formulae (461) to (464) each independently represent a bonding position to a cyclic structure.

In the third compound and the fourth compound, R₉₀₁ to R₉₀₇ are as defined above.

In an exemplary embodiment, the compound represented by the formula (45) is represented by any one of formulae (45-1) to (45-6) below.

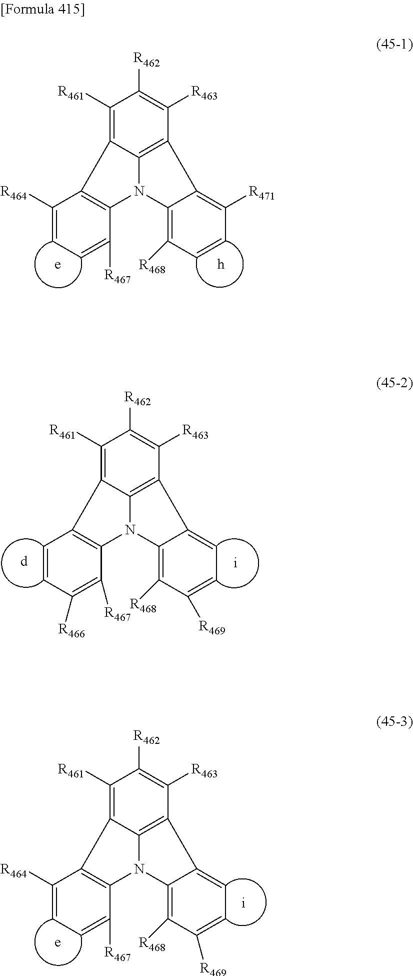

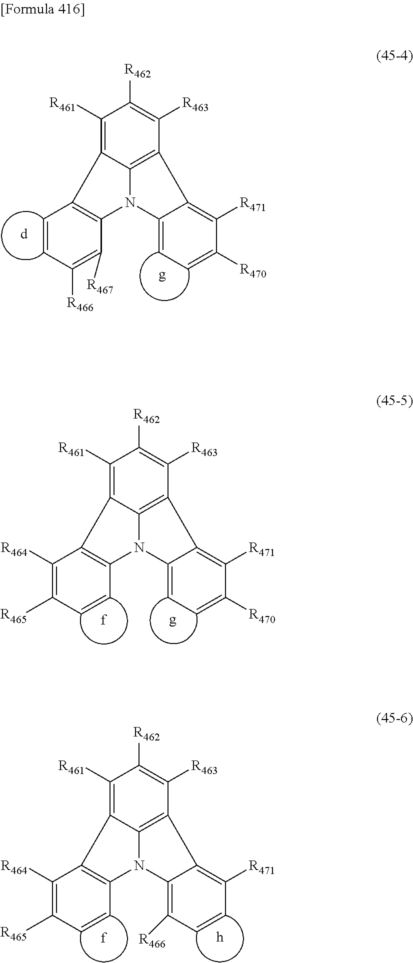

In the formulae (45-1) to (45-6):
rings d to i are each independently a substituted or unsubstituted monocyclic ring or a substituted or unsubstituted fused ring; and
R₄₆₁ to R₄₇₁ each independently represent the same as R₄₆₁ to R₄₇₁ in the formula (45).

In an exemplary embodiment, the compound represented by the formula (45) is represented by any one of formulae (45-7) to (45-12) below.

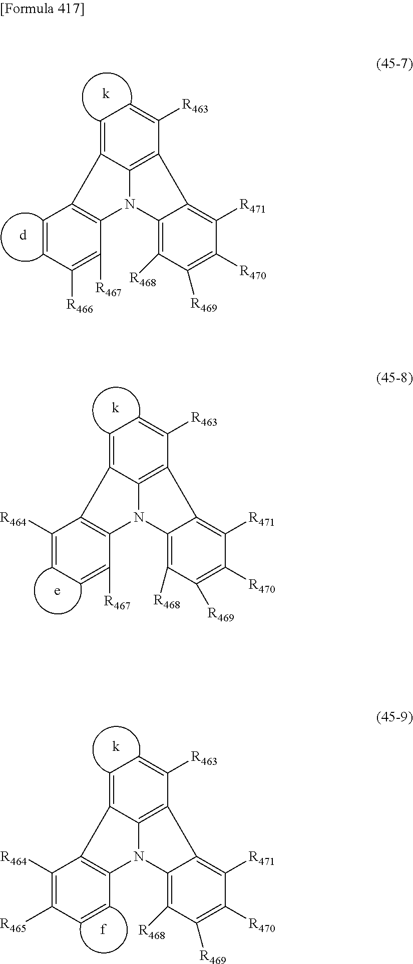

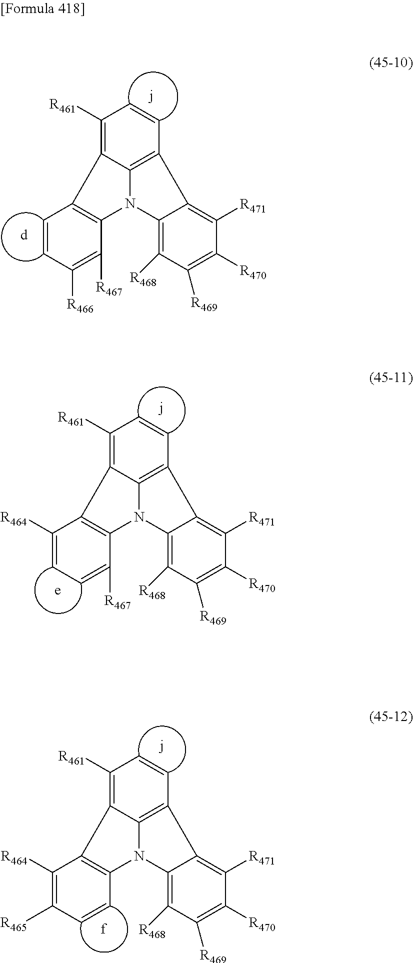

In the formulae (45-7) to (45-12):
rings d to f, k, and j are each independently a substituted or unsubstituted monocyclic ring or a substituted or unsubstituted fused ring; and
R₄₆₁ to R₄₇₁ each independently represent the same as R₄₆₁ to R₄₇₁ in the formula (45).

### Compound Represented by Formula (5)

The compound represented by the formula (5) will be described. The compound represented by the formula (5) corresponds to a compound represented by the formula (41-3) described above.

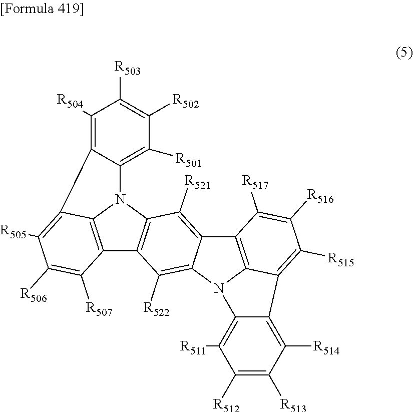

In the formula (5):
at least one combination of adjacent two or more of R₅₀₁ to R₅₀₇ and R₅₁₁ to R₅₁₇ are mutually bonded to form a substituted or unsubstituted monocyclic ring, mutually bonded to form a substituted or unsubstituted fused ring, or not mutually bonded;
R₅₀₁ to R₅₀₇ and R₅₁₁ to R₅₁₇ forming neither the monocyclic ring nor the fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms; and
R₅₂₁ and R₅₂₂ are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms.

“A combination of adjacent two or more of R₅₀₁ to R₅₀₇ and R₅₁₁ to R₅₁₇” refers to, for instance, a combination of R₅₀₁ and R₅₀₂, a combination of R₅₀₂ and R₅₀₃, a combination of R₅₀₃ and R₅₀₄, a combination of R₅₀₅ and R₅₀₆, a combination of R₅₀₆ and R₅₀₇, and a combination of R₅₀₁, R₅₀₂, and R₅₀₃.

In an exemplary embodiment, at least one, preferably two, of R₅₀₁ to R₅₀₇ or R₅₁₁ to R₅₁₇ are each a group represented by —N(R₉₀₆)(R₉₀₇).

In an exemplary embodiment, R₅₀₁ to R₅₀₇ and R₅₁₁ to R₅₁₇ are each independently a hydrogen atom, a substituted or unsubstituted aryl group having 6 to 50 ring carbon atoms, or a substituted or unsubstituted heterocyclic group having 5 to 50 ring atoms.

In an exemplary embodiment, the compound represented by the formula (5) is a compound represented by a formula (52) below.

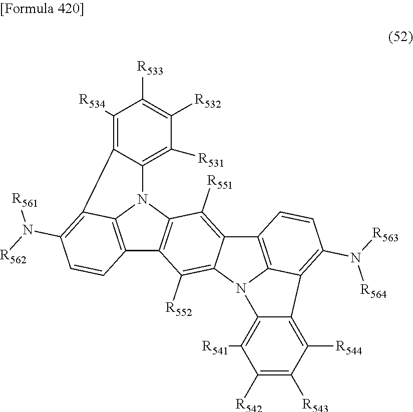

In the formula (52):
at least one combination of adjacent two or more of R₅₃₁ to R₅₃₄ and R₅₄₁ to R₅₄₄ are mutually bonded to form a substituted or unsubstituted monocyclic ring, mutually bonded to form a substituted or unsubstituted fused ring, or not mutually bonded;
R₅₃₁ to R₅₃₄ and R₅₄₁ to R₅₄₄ forming neither the monocyclic ring nor the fused ring, R₅₅₁, and R₅₅₂ are each independently a hydrogen atom, a substituted or unsubstituted aryl group having 6 to 50 ring carbon atoms, or a substituted or unsubstituted heterocyclic group having 5 to 50 ring atoms; and
R₅₆₁ to R₅₆₄ are each independently a substituted or unsubstituted aryl group having 6 to 50 ring carbon atoms, or a substituted or unsubstituted heterocyclic group having 5 to 50 ring atoms.

In an exemplary embodiment, the compound represented by the formula (5) is a compound represented by a formula (53) below.

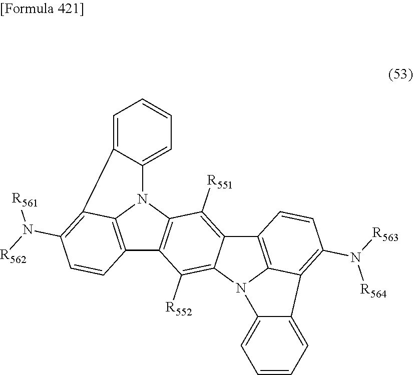

In the formula (53), R₅₅₁, R₅₅₂ and R₅₆₁ to R₅₆₄ each independently represent the same as R₅₅₁, R₅₅₂ and R₅₆₁ to R₅₆₄ in the formula (52).

In an exemplary embodiment, R₅₆₁ to R₅₆₄ in the formulae (52) and (53) are each independently a substituted or unsubstituted aryl group having 6 to 50 ring carbon atoms (preferably a phenyl group).

In an exemplary embodiment, R₅₂₁ and R₅₂₂ in the formula (5) and R₅₅₁ and R₅₅₂ in the formulae (52) and (53) are hydrogen atoms.

In an exemplary embodiment, the substituent for the “substituted or unsubstituted” group in the formulae (5), (52) and (53) is a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

### Compound Represented by Formula (41)

The first emitting compound and the second emitting compound are preferably each independently a compound represented by the formula (41) below.

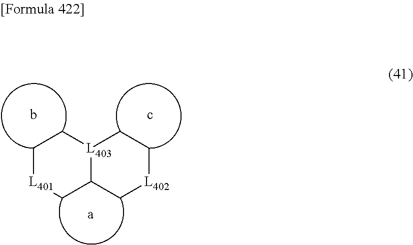

In the formula (41):
a ring a, a ring b, and a ring c are each independently a substituted or unsubstituted aromatic hydrocarbon ring having 6 to 50 ring carbon atoms, or a substituted or unsubstituted heterocycle having 5 to 50 ring atoms;
L₄₀₁ and L₄₀₂ are each independently O, S, Se, NR₄₀₁, C(R₄₀₂)(R₄₀₃), or Si(R₄₀₄)(R₄₀₅);
L₄₀₃ is B, P, or P═O;
R₄₀₁ to R₄₀₅ are each independently bonded with the ring a, ring b, or ring c to form a substituted or unsubstituted monocyclic ring, bonded with the ring a, ring b, or ring c to form a substituted or unsubstituted fused ring, or not bonded with the ring a, ring b, or ring c;
R₄₀₂ and R₄₀₃ are mutually bonded to form a substituted or unsubstituted monocyclic ring, mutually bonded to form a substituted or unsubstituted fused ring, or not mutually bonded;
R₄₀₄ and R₄₀₅ are mutually bonded to form a substituted or unsubstituted monocyclic ring, mutually bonded to form a substituted or unsubstituted fused ring, or not mutually bonded;
R₄₀₁ to R₄₀₅ forming neither the substituted or unsubstituted monocyclic ring nor the substituted or unsubstituted fused ring are each independently a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₄₀₁ are present, the plurality of R₄₀₁ are mutually the same or different;
when a plurality of R₄₀₂ are present, the plurality of R₄₀₂ are mutually the same or different;
when a plurality of R₄₀₃ are present, the plurality of R₄₀₃ are mutually the same or different;
when a plurality of R₄₀₄ are present, the plurality of R₄₀₄ are mutually the same or different; and
when a plurality of R₄₀₅ are present, the plurality of R₄₀₅ are mutually the same or different.

In an exemplary embodiment, the substituent for the “substituted or unsubstituted” group in the formula (41) is selected from the group consisting of an unsubstituted alkyl group having 1 to 50 carbon atoms, an unsubstituted haloalkyl group having 1 to 50 carbon atoms, an unsubstituted alkenyl group having 2 to 50 carbon atoms, an unsubstituted alkynyl group having 2 to 50 carbon atoms, an unsubstituted cycloalkyl group having 3 to 50 ring carbon atoms, an unsubstituted alkoxy group having 1 to 50 carbon atoms, an unsubstituted alkylthio group having 1 to 50 carbon atoms, an unsubstituted aryloxy group having 6 to 50 ring carbon atoms, an unsubstituted arylthio group having 6 to 50 ring carbon atoms, an unsubstituted aralkyl group having 7 to 50 carbon atoms, —Si(R₄₁)(R₄₂)(R₄₃), —C(═O)R₄₄, —COOR₄₅, —S(═O)₂R₄₆, —P(═O)(R₄₇)(R₄₈), —Ge(R₄₉)(R₅₀)(R₅₁), —N(R₅₂)(R₅₃), (where: R₄₁ to R₅₃ are each independently a hydrogen atom, an unsubstituted alkyl group having 1 to 50 ring carbon atoms, an unsubstituted aryl group having 6 to 50 ring carbon atoms, or an unsubstituted heterocyclic group having 5 to 50 ring atoms, (when two or more R₄₁ are present, the two or more R₄₁ are mutually the same or different; when two or more R₄₂ are present, the two or more R₄₂ are mutually the same or different; when two or more R₄₃ are present, the two or more R₄₃ are mutually the same or different; when two or more R₄₄ are present, the two or more R₄₄ are mutually the same or different; when two or more R₄₅ are present, the two or more R₄₅ are mutually the same or different; when two or more R₄₆ are present, the two or more R₄₆ are mutually the same or different; when two or more R₄₇ are present, the two or more R₄₇ are mutually the same or different; when two or more R₄₈ are present, the two or more R₄₈ are mutually the same or different; when two or more R₄₉ are present, the two or more R₄₉ are mutually the same or different; when two or more R₅₀ are present, the two or more R₅₀ are mutually the same or different; when two or more R₅₁ are present, the two or more R₅₁ are mutually the same or different; when two or more R₅₂ are present, the two or more R₅₂ are mutually the same or different; and when two or more R₅₃ are present, the two or more R₅₃ are mutually the same or different), a hydroxy group, a halogen atom, a cyano group, a nitro group, an aryl group having 6 to 50 ring carbon atoms, and a monovalent heterocyclic group having 5 to 50 ring atoms.

In an exemplary embodiment, the substituent for the “substituted or unsubstituted” group in the formula (41) is selected from the group consisting of an unsubstituted alkyl group having 1 to 18 carbon atoms, an unsubstituted aryl group having 6 to 18 ring carbon atoms, and an unsubstituted heterocyclic group having 5 to 18 ring atoms.

### Compound Represented by Formula (6)

The compound represented by the formula (6) will be described.

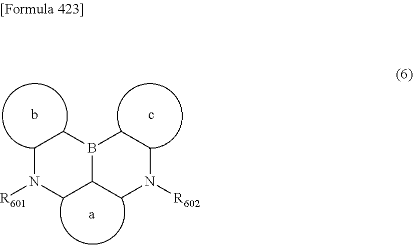

In the formula (6):
a ring a, a ring b, and a ring c are each independently a substituted or unsubstituted aromatic hydrocarbon ring having 6 to 50 ring carbon atoms, or a substituted or unsubstituted heterocycle having 5 to 50 ring atoms;
R₆₀₁ and R₆₀₂ are each independently bonded with the ring a, ring b or ring c to form a substituted or unsubstituted heterocycle, or not bonded therewith to form no substituted or unsubstituted heterocycle; and
R₆₀₁ and R₆₀₂ not forming the substituted or unsubstituted heterocycle are each independently a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

The ring a, ring b and ring c are each a ring (a substituted or unsubstituted aromatic hydrocarbon ring having 6 to 50 ring carbon atoms, or a substituted or unsubstituted heterocycle having 5 to 50 ring atoms) fused with a fused bicyclic structure formed of a boron atom and two nitrogen atoms at the center of the formula (6).

The “aromatic hydrocarbon ring” for the rings a, b, and c has the same structure as a compound formed by introducing a hydrogen atom to the “aryl group” described above.

Ring atoms of the “aromatic hydrocarbon ring” for the ring a include three carbon atoms on the fused bicyclic structure at the center of the formula (6).

Ring atoms of the “aromatic hydrocarbon ring” for the rings b and c include two carbon atoms on the fused bicyclic structure at the center of the formula (6).

Specific examples of the “substituted or unsubstituted aromatic hydrocarbon ring having 6 to 50 ring carbon atoms” include a compound formed by introducing a hydrogen atom to the “aryl group” described in the specific example group G1.

The “heterocycle” for the rings a, b, and c has the same structure as a compound formed by introducing a hydrogen atom to the “heterocyclic group” described above.

Ring atoms of the “heterocycle” for the ring a include three carbon atoms on the fused bicyclic structure at the center of the formula (6). Ring atoms of the “heterocycle” for the rings b and c include two carbon atoms on the fused bicyclic structure at the center of the formula (6). Specific examples of the “substituted or unsubstituted heterocycle having 5 to 50 ring atoms” include a compound formed by introducing a hydrogen atom to the “heterocyclic group” described in the specific example group G2.

R₆₀₁ and R₆₀₂ may be each independently bonded with the ring a, ring b, or ring c to form a substituted or unsubstituted heterocycle. The “heterocycle” in this arrangement includes a nitrogen atom on the fused bicyclic structure at the center of the formula (6). The heterocycle in the above arrangement optionally includes a hetero atom other than the nitrogen atom. R₆₀₁ and R₆₀₂ being bonded with the ring a, ring b, or ring c specifically means that atoms forming R₆₀₁ and R₆₀₂ are bonded with atoms forming the ring a, ring b, or ring c. For instance, R₆₀₁ may be bonded with the ring a to form a bicyclic (or tri-or-more cyclic) fused nitrogen-containing heterocycle, in which the ring including R₆₀₁ and the ring a are fused. Specific examples of the nitrogen-containing heterocycle include a compound corresponding to the nitrogen-containing bi(or-more)cyclic fused heterocyclic group in the specific example group G2.

The same applies to R₆₀₁ bonded with the ring b, R₆₀₂ bonded with the ring a, and R₆₀₂ bonded with the ring c.

In an exemplary embodiment, the ring a, ring b and ring c in the formula (6) are each independently a substituted or unsubstituted aromatic hydrocarbon ring having 6 to 50 ring carbon atoms.

In an exemplary embodiment, the ring a, ring b and ring c in the formula (6) are each independently a substituted or unsubstituted benzene ring or a substituted or unsubstituted naphthalene ring.

In an exemplary embodiment, R₆₀₁ and R₆₀₂ in the formula (6) are each independently a substituted or unsubstituted aryl group having 6 to 50 ring carbon atoms, or a substituted or unsubstituted heterocyclic group having 5 to 50 ring atoms; preferably, a substituted or unsubstituted aryl group having 6 to 50 ring carbon atoms.

In an exemplary embodiment, the compound represented by the formula (6) is a compound represented by a formula (62) below.

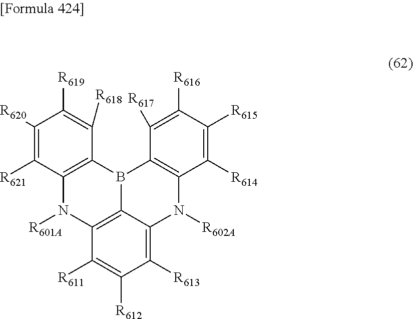

In the formula (62):
R_{601A} is bonded with at least one of R₆₁₁ or R₆₂₁ to form a substituted or unsubstituted heterocycle, or not bonded therewith to form no substituted or unsubstituted heterocycle;
R_{602A} is bonded with at least one of R₆₁₃ or R₆₁₄ to form a substituted or unsubstituted heterocycle, or not bonded therewith to form no substituted or unsubstituted heterocycle;
R_{601A} and R_{602A} not forming the substituted or unsubstituted heterocycle are each independently a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
at least one combination of adjacent two or more of R₆₁₁ to R₆₂₁ are mutually bonded to form a substituted or unsubstituted monocyclic ring, mutually bonded to form a substituted or unsubstituted fused ring, or not mutually bonded; and
R₆₁₁ to R₆₂₁ not forming the substituted or unsubstituted heterocycle, not forming the monocyclic ring, and not forming the fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms.

R_{601A} and R_{602A} in the formula (62) are groups corresponding to R₆₀₁ and R₆₀₂ in the formula (6), respectively.

For instance, R_{601A} and R₆₁₁ are optionally bonded with each other to form a bicyclic (or tri-or-more cyclic) fused nitrogen-containing heterocycle, in which the ring including R_{601A} and R₆₁₁ and a benzene ring corresponding to the ring a are fused. Specific examples of the nitrogen-containing heterocycle include a compound corresponding to the nitrogen-containing bi(or-more)cyclic fused heterocyclic group in the specific example group G2. The same applies to R_{601A} bonded with R₆₂₁, R_{602A} bonded with R₆₁₃, and R_{602A} bonded with R₆₁₄.

At least one combination of adjacent two or more of R₆₁₁ to R₆₂₁ are mutually bonded to form a substituted or unsubstituted monocyclic ring, or mutually bonded to form a substituted or unsubstituted fused ring.

For instance, R₆₁₁ and R₆₁₂ are optionally mutually bonded to form a structure in which a benzene ring, indole ring, pyrrole ring, benzofuran ring, benzothiophene ring or the like is fused to the six-membered ring bonded with R₆₁₁ and R₆₁₂, the resultant fused ring forming a naphthalene ring, carbazole ring, indole ring, dibenzofuran ring, or dibenzothiophene ring, respectively.

In an exemplary embodiment: R₆₁₁ to R₆₂₁ not contributing to ring formation are each independently a hydrogen atom, a substituted or unsubstituted alkyl group having 1 to 50 carbon atoms, a substituted or unsubstituted aryl group having 6 to 50 ring carbon atoms, or a substituted or unsubstituted heterocyclic group having 5 to 50 ring atoms.

In an exemplary embodiment: R₆₁₁ to R₆₂₁ not contributing to ring formation are each independently a hydrogen atom, a substituted or unsubstituted aryl group having 6 to 50 ring carbon atoms, or a substituted or unsubstituted heterocyclic group having 5 to 50 ring atoms.

In an exemplary embodiment: R₆₁₁ to R₆₂₁ not contributing to ring formation are each independently a hydrogen atom, or a substituted or unsubstituted alkyl group having 1 to 50 carbon atoms.

In an exemplary embodiment: R₆₁₁ to R₆₂₁ not contributing to ring formation are each independently a hydrogen atom, or a substituted or unsubstituted alkyl group having 1 to 50 carbon atoms; and

at least one of R₆₁₁ to R₆₂₁ is a substituted or unsubstituted alkyl group having 1 to 50 carbon atoms.

In an exemplary embodiment, the compound represented by the formula (62) is a compound represented by a formula (63) below.

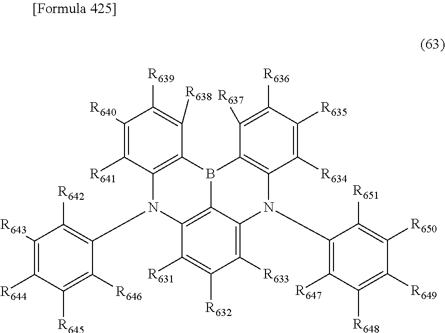

In the formula (63):
R₆₃₁ is bonded with R₆₄₆ to form a substituted or unsubstituted heterocycle, or not bonded therewith to form no substituted or unsubstituted heterocycle;
R₆₃₃ is bonded with R₆₄₇ to form a substituted or unsubstituted heterocycle, or not bonded therewith to form no substituted or unsubstituted heterocycle;
R₆₃₄ is bonded with R₆₅₁ to form a substituted or unsubstituted heterocycle, or not bonded therewith to form no substituted or unsubstituted heterocycle;
R₆₄₁ is bonded with R₆₄₂ to form a substituted or unsubstituted heterocycle, or not bonded therewith to form no substituted or unsubstituted heterocycle;
at least one combination of adjacent two or more of R₆₃₁ to R₆₅₁ are mutually bonded to form a substituted or unsubstituted monocyclic ring, mutually bonded to form a substituted or unsubstituted fused ring, or not mutually bonded; and
R₆₃₁ to R₆₅₁ not forming the substituted or unsubstituted heterocycle, not forming the monocyclic ring, and not forming the fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms.

R₆₃₁ is optionally bonded with R₆₄₆ to form a substituted or unsubstituted heterocycle. For instance, R₆₃₁ and R₆₄₆ are optionally bonded with each other to form a tri-or-more cyclic fused nitrogen-containing heterocycle, in which a benzene ring bonded with R₆₄₆, a ring including a nitrogen atom, and a benzene ring corresponding to the ring a are fused. Specific examples of the nitrogen-containing heterocycle include a compound corresponding to a nitrogen-containing tri(-or-more)cyclic fused heterocyclic group in the specific example group G2. The same applies to R₆₃₃ bonded with R₆₄₇, R₆₃₄ bonded with R₆₅₁, and R₆₄₁ bonded with R₆₄₂.

In an exemplary embodiment: R₆₃₁ to R₆₅₁ not contributing to ring formation are each independently a hydrogen atom, a substituted or unsubstituted alkyl group having 1 to 50 carbon atoms, a substituted or unsubstituted aryl group having 6 to 50 ring carbon atoms, or a substituted or unsubstituted heterocyclic group having 5 to 50 ring atoms.

In an exemplary embodiment, R₆₃₁ to R₆₅₁ not contributing to ring formation are each independently a hydrogen atom, a substituted or unsubstituted aryl group having 6 to 50 ring carbon atoms, or a substituted or unsubstituted heterocyclic group having 5 to 50 ring atoms.

In an exemplary embodiment, R₆₃₁ to R₆₅₁ not contributing to ring formation are each independently a hydrogen atom, or a substituted or unsubstituted alkyl group having 1 to 50 carbon atoms.

In an exemplary embodiment, R₆₃₁ to R₆₅₁ not contributing to ring formation are each independently a hydrogen atom, or a substituted or unsubstituted alkyl group having 1 to 50 carbon atoms, and at least one of R₆₃₁ to R₆₅₁ is a substituted or unsubstituted alkyl group having 1 to 50 carbon atoms.

In an exemplary embodiment, the compound represented by the formula (63) is a compound represented by a formula (63A) below.

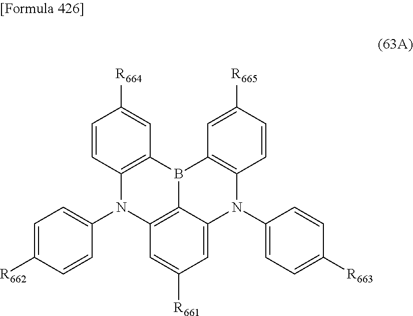

In the formula (63A):
R₆₆₁ is a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, or a substituted or unsubstituted aryl group having 6 to 50 ring carbon atoms; and
R₆₆₂ to R₆₆₅ are each independently a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, or a substituted or unsubstituted aryl group having 6 to 50 ring carbon atoms.

In an exemplary embodiment, R₆₆₁ to R₆₆₅ are each independently a substituted or unsubstituted alkyl group having 1 to 50 carbon atoms, or a substituted or unsubstituted aryl group having 6 to 50 ring carbon atoms.

In an exemplary embodiment, R₆₆₁ to R₆₆₅ are each independently a substituted or unsubstituted alkyl group having 1 to 50 carbon atoms. In an exemplary embodiment, the compound represented by the formula (63) is a compound represented by a formula (63B) below.

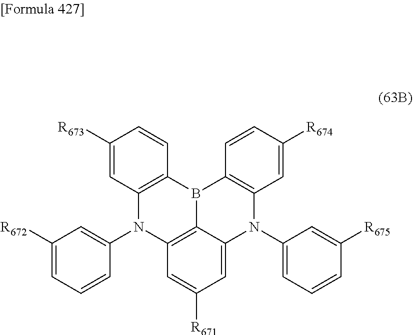

In the formula (63B):
R₆₇₁ and R₆₇₂ are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —N(R₉₀₆)(R₉₀₇), or a substituted or unsubstituted aryl group having 6 to 50 ring carbon atoms; and
R₆₇₃ to R₆₇₅ are each independently a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —N(R₉₀₆)(R₉₀₇), or a substituted or unsubstituted aryl group having 6 to 50 ring carbon atoms.

In an exemplary embodiment, the compound represented by the formula (63) is a compound represented by a formula (63B′) below.

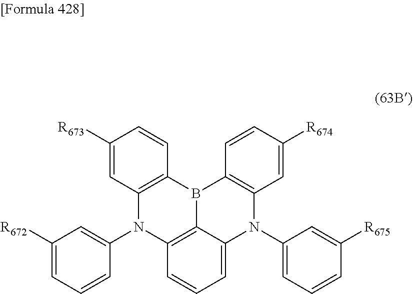

In the formula (63B′), R₆₇₂ to R₆₇₅ each independently represent the same as R₆₇₂ to R₆₇₅ in the formula (63B).

In an exemplary embodiment, at least one of R₆₇₁ to R₆₇₅ is a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —N(R₉₀₆)(R₉₀₇), or a substituted or unsubstituted aryl group having 6 to 50 ring carbon atoms.

In an exemplary embodiment:
R₆₇₂ is a hydrogen atom, a substituted or unsubstituted alkyl group having 1 to 50 carbon atoms, a group represented by —N(R₉₀₆)(R₉₀₇), or a substituted or unsubstituted aryl group having 6 to 50 ring carbon atoms; and
R₆₇₁ and R₆₇₃ to R₆₇₅ are each independently a substituted or unsubstituted alkyl group having 1 to 50 carbon atoms, a group represented by —N(R₉₀₆)(R₉₀₇), or a substituted or unsubstituted aryl group having 6 to 50 ring carbon atoms.

In an exemplary embodiment, the compound represented by the formula (63) is a compound represented by a formula (63C) below.

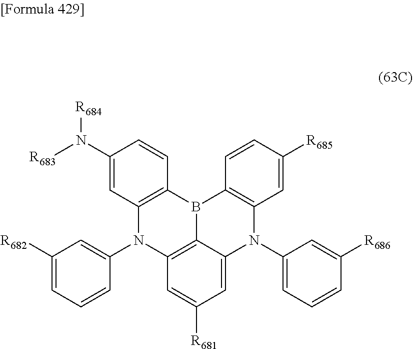

In the formula (63C):
R₆₈₁ and R₆₈₂ are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, or a substituted or unsubstituted aryl group having 6 to 50 ring carbon atoms; and
R₆₈₃ to R₆₈₆ are each independently a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, or a substituted or unsubstituted aryl group having 6 to 50 ring carbon atoms.

In an exemplary embodiment, the compound represented by the formula (63) is a compound represented by a formula (63C′) below.

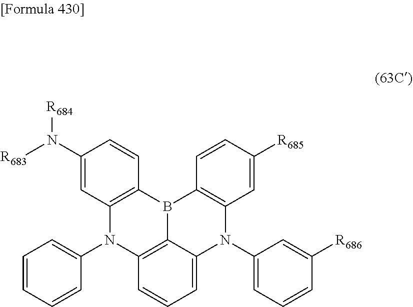

In the formula (63C′), R₆₈₃ to R₆₈₆ each independently represent the same as R₆₈₃ to R₆₈₆ in the formula (63C).

In an exemplary embodiment, R₆₈₁ to R₆₈₆ are each independently a substituted or unsubstituted alkyl group having 1 to 50 carbon atoms, or a substituted or unsubstituted aryl group having 6 to 50 ring carbon atoms.

In an exemplary embodiment, R₆₈₁ to R₆₈₆ are each independently a substituted or unsubstituted aryl group having 6 to 50 ring carbon atoms.

The compound represented by the formula (6) is producible by initially bonding the ring a, ring b and ring c with linking groups (a group including N—R₆₀₁ and a group including N—R₆₀₂) to form an intermediate (first reaction), and bonding the ring a, ring b and ring c with a linking group (a group including a boron atom) to form a final product (second reaction). In the first reaction, an amination reaction (e.g. Buchwald-Hartwig reaction) is applicable. In the second reaction, Tandem Hetero-Friedel-Crafts Reactions or the like is applicable.

In an exemplary embodiment, the compound represented by the formula (6) is a compound represented by a formula (42-2) below.

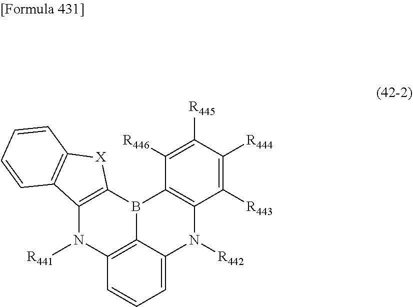

In the formula (42-2):
R₄₄₁ and R₄₄₂ are each independently a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
R₄₄₃ to R₄₄₆ are each independently a hydrogen atom or a substituent R; each substituent R is independently a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, —Si(R₉₀₁)(R₉₀₂)(R₉₀₃), —O—(R₉₀₄), —S—(R₉₀₅), —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms;
X is O or S;
R₉₀₁ to R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms; and
when a plurality of R₉₀₁ are present, the plurality of R₉₀₁ are mutually the same or different; when a plurality of R₉₀₂ are present, the plurality of R₉₀₂ are mutually the same or different; when a plurality of R₉₀₃ are present, the plurality of R₉₀₃ are mutually the same or different; when a plurality of R₉₀₄ are present, the plurality of R₉₀₄ are mutually the same or different; when a plurality of R₉₀₅ are present, the plurality of R₉₀₅ are mutually the same or different; when a plurality of R₉₀₆ are present, the plurality of R₉₀₆ are mutually the same or different; and when a plurality of R₉₀₇ are present, the plurality of R₉₀₇ are mutually the same or different.

In an exemplary embodiment, the substituent for the “substituted or unsubstituted” group in the formula (42-2) is selected from the group consisting of an unsubstituted alkyl group having 1 to 50 carbon atoms, an unsubstituted haloalkyl group having 1 to 50 carbon atoms, an unsubstituted alkenyl group having 2 to 50 carbon atoms, an unsubstituted alkynyl group having 2 to 50 carbon atoms, an unsubstituted cycloalkyl group having 3 to 50 ring carbon atoms, an unsubstituted alkoxy group having 1 to 50 carbon atoms, an unsubstituted alkylthio group having 1 to 50 carbon atoms, an unsubstituted aryloxy group having 6 to 50 ring carbon atoms, an unsubstituted arylthio group having 6 to 50 ring carbon atoms, an unsubstituted aralkyl group having 7 to 50 carbon atoms, —Si(R₄₁)(R₄₂)(R₄₃), —C(═O)R₄₄, —COOR₄₅, —S(═O)₂R₄₆, —P(═O)(R₄₇)(R₄₈), —Ge(R₄₉)(R₅₀)(R₅₁), —N(R₅₂)(R₅₃), (where: R₄₁ to R₅₃ are each independently a hydrogen atom, an unsubstituted alkyl group having 1 to 50 ring carbon atoms, an unsubstituted aryl group having 6 to 50 ring carbon atoms, or an unsubstituted heterocyclic group having 5 to 50 ring atoms; <<nret>> when two or more R₄₁ are present, the two or more R₄₁ are mutually the same or different; when two or more R₄₂ are present, the two or more R₄₂ are mutually the same or different; when two or more R₄₃ are present, the two or more R₄₃ are mutually the same or different; when two or more R₄₄ are present, the two or more R₄₄ are mutually the same or different; when two or more R₄₅ are present, the two or more R₄₅ are mutually the same or different; when two or more R₄₆ are present, the two or more R₄₆ are mutually the same or different; when two or more R₄₇ are present, the two or more R₄₇ are mutually the same or different; when two or more R₄₈ are present, the two or more R₄₈ are mutually the same or different; when two or more R₄₉ are present, the two or more R₄₉ are mutually the same or different; when two or more R₅₀ are present, the two or more R₅₀ are mutually the same or different; when two or more R₅₁ are present, the two or more R₅₁ are mutually the same or different; when two or more R₅₂ are present, the two or more R₅₂ are mutually the same or different; and when two or more R₅₃ are present, the two or more R₅₃ are mutually the same or different) a hydroxy group, a halogen atom, a cyano group, a nitro group, an aryl group having 6 to 50 ring carbon atoms, and a heterocyclic group having 5 to 50 ring atoms.

In an exemplary embodiment, the emitting layer contains, as at least one of the third emitting compound or the fourth emitting compound, at least one compound selected from the group consisting of a compound represented by the formula (4), a compound represented by the formula (5), a compound represented by the formula (41), and a compound represented by a formula (63a) below.

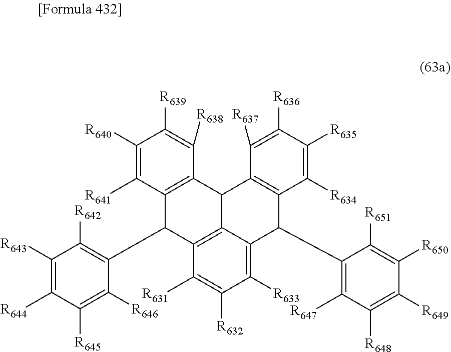

In the formula (63a):
R₆₃₁ is bonded with R₆₄₆ to form a substituted or unsubstituted heterocycle, or not bonded therewith to form no substituted or unsubstituted heterocycle;
R₆₃₃ is bonded with R₆₄₇ to form a substituted or unsubstituted heterocycle, or not bonded therewith to form no substituted or unsubstituted heterocycle;
R₆₃₄ is bonded with R₆₅₁ to form a substituted or unsubstituted heterocycle, or not bonded therewith to form no substituted or unsubstituted heterocycle;
R₆₄₁ is bonded with R₆₄₂ to form a substituted or unsubstituted heterocycle, or not bonded therewith to form no substituted or unsubstituted heterocycle;
at least one combination of adjacent two or more of R₆₃₁ to R₆₅₁ are mutually bonded to form a substituted or unsubstituted monocyclic ring, mutually bonded to form a substituted or unsubstituted fused ring, or not mutually bonded;
R₆₃₁ to R₆₅₁ not forming the substituted or unsubstituted heterocycle, not forming the monocyclic ring, and not forming the fused ring are each independently a hydrogen atom, a halogen atom, a cyano group, a nitro group, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aryl group having 6 to 50 ring carbon atoms, or a substituted or unsubstituted heterocyclic group having 5 to 50 ring atoms; and
at least one of R₆₃₁ to R₆₅₁ not forming the substituted or unsubstituted heterocycle, not forming the monocyclic ring, and not forming the fused ring is a halogen atom, a cyano group, a nitro group, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms.

In an exemplary embodiment, the compound represented by the formula (4) is a compound represented by the formula (41-3), the formula (41-4), or the formula (41-5), the ring A1 in the formula (41-5) being a substituted or unsubstituted fused aromatic hydrocarbon ring having 10 to 50 ring carbon atoms, or a substituted or unsubstituted fused heterocycle having 8 to 50 ring atoms.

In an exemplary embodiment, the substituted or unsubstituted fused aromatic hydrocarbon ring having 10 to 50 ring carbon atoms in the formulae (41-3), (41-4) and (41-5) is a substituted or unsubstituted naphthalene ring, a substituted or unsubstituted anthracene ring, or a substituted or unsubstituted fluorene ring; and the substituted or unsubstituted fused heterocycle having 8 to 50 ring atoms is a substituted or unsubstituted dibenzofuran ring, a substituted or unsubstituted carbazole ring, or a substituted or unsubstituted dibenzothiophene ring.

In an exemplary embodiment, the substituted or unsubstituted fused aromatic hydrocarbon ring having 10 to 50 ring carbon atoms in the formula (41-3), (41-4) or (41-5) is a substituted or unsubstituted naphthalene group, or a substituted or unsubstituted fluorene ring; and

the substituted or unsubstituted fused heterocycle having 8 to 50 ring atoms is a substituted or unsubstituted dibenzofuran ring, a substituted or unsubstituted carbazole ring, or a substituted or unsubstituted dibenzothiophene ring.

In an exemplary embodiment, the compound represented by the formula (4) is selected from the group consisting of a compound represented by a formula (461) below, a compound represented by a formula (462) below, a compound represented by a formula (463) below, a compound represented by a formula (464) below, a compound represented by a formula (465) below, a compound represented by a formula (466) below, and a compound represented by a formula (467) below.

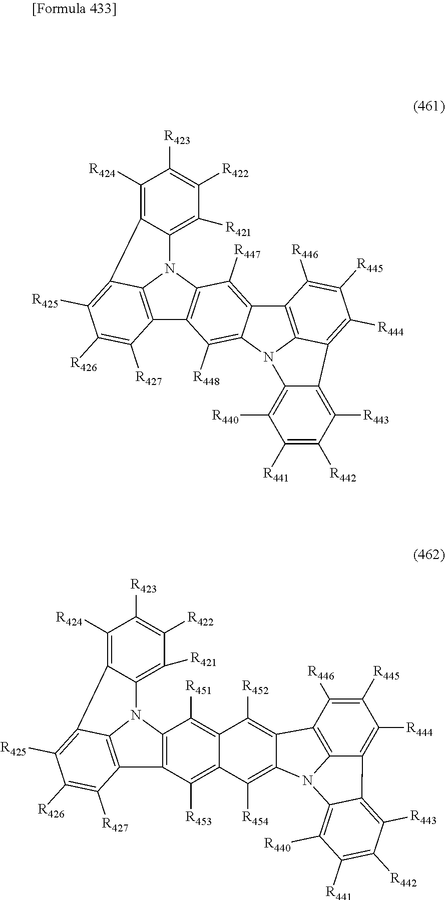

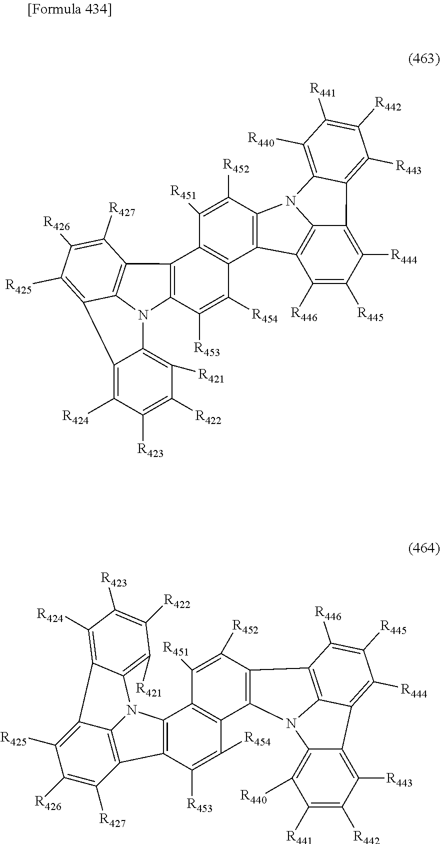

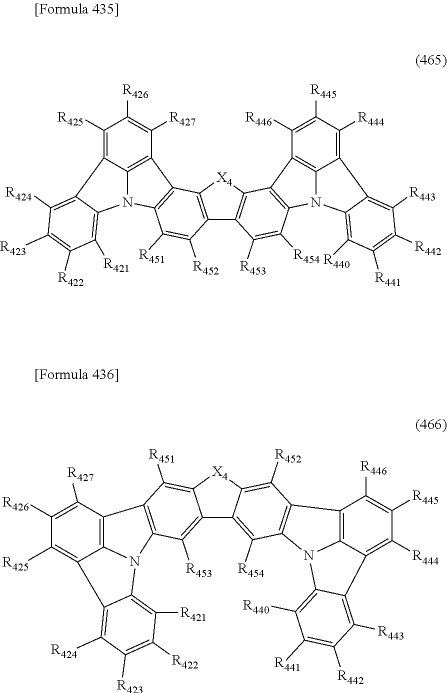

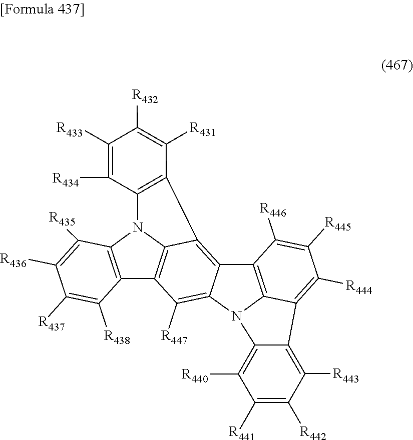

In the formulae (461) to (467):
at least one combination of adjacent two or more of R₄₂₁ to R₄₂₇, R₄₃₁ to R₄₃₆, R₄₄₀ to R₄₄₈, and R₄₅₁ to R₄₅₄ are mutually bonded to form a substituted or unsubstituted monocyclic ring, mutually bonded to form a substituted or unsubstituted fused ring, or not mutually bonded;
R₄₃₇, R₄₃₈, and R₄₂₁ to R₄₂₇, R₄₃₁ to R₄₃₆, R₄₄₀ to R₄₄₈, and R₄₅₁ to R₄₅₄ forming neither the monocyclic ring nor the fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms;
X₄ is an oxygen atom, NR₈₀₁, or C(R₈₀₂)(R₈₀₃);
R₈₀₁, R₈₀₂ and R₈₀₃ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
a substituted or unsubstituted alkyl group having 1 to 50 carbon atoms, or a substituted or unsubstituted aryl group having 6 to 50 ring carbon atoms;
when a plurality of R₈₀₁ are present, the plurality of R₈₀₁ are mutually the same or different;
when a plurality of R₈₀₂ are present, the plurality of R₈₀₂ are mutually the same or different; and
when a plurality of R₈₀₃ are present, the plurality of R₈₀₃ are mutually the same or different.

In an exemplary embodiment, R₄₂₁ to R₄₂₇ and R₄₄₀ to R₄₄₈ are each independently a hydrogen atom, a substituted or unsubstituted aryl group having 6 to 50 ring carbon atoms, or a substituted or unsubstituted heterocyclic group having 5 to 50 ring atoms.

In an exemplary embodiment, R₄₂₁ to R₄₂₇ and R₄₄₀ to R₄₄₇ are each independently selected from the group consisting of a hydrogen atom, a substituted or unsubstituted aryl group having 6 to 18 ring carbon atoms, and a substituted or unsubstituted heterocyclic group having 5 to 18 ring atoms.

In an exemplary embodiment, the compound represented by the formula (41-3) is a compound represented by a formula (41-3-1) below.

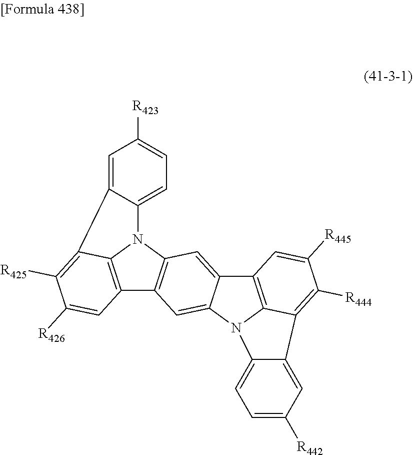

In the formula (41-3-1), R₄₂₃, R₄₂₅, R₄₂₆, R₄₄₂, R₄₄₄ and R₄₄₅ each independently represent the same as R₄₂₃, R₄₂₅, R₄₂₆, R₄₄₂, R₄₄₄ and R₄₄₅ in the formula (41-3).

In an exemplary embodiment, the compound represented by the formula (41-3) is a compound represented by a formula (41-3-2) below.

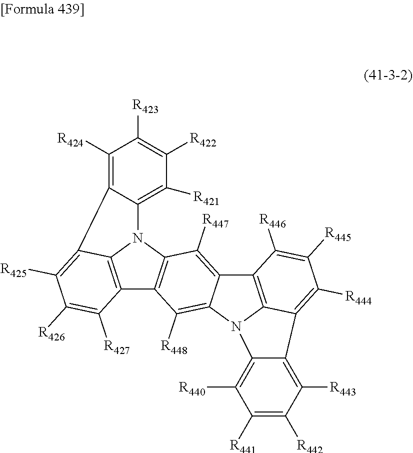

In the formula (41-3-2), R₄₂₁ to R₄₂₇ and R₄₄₀ to R₄₄₈ each independently represent the same as R₄₂₁ to R₄₂₇ and R₄₄₀ to R₄₄₈ in the formula (41-3); and at least one of R₄₂₁ to R₄₂₇ or R₄₄₀ to R₄₄₆ is a group represented by —N(R₉₀₆)(R₉₀₇).

In an exemplary embodiment, two of R₄₂₁ to R₄₂₇ and R₄₄₀ to R₄₄₆ in the formula (41-3-2) are each a group represented by —N(R₉₀₆)(R₉₀₇).

In an exemplary embodiment, the compound represented by the formula (41-3-2) is a compound represented by a formula (41-3-3) below.

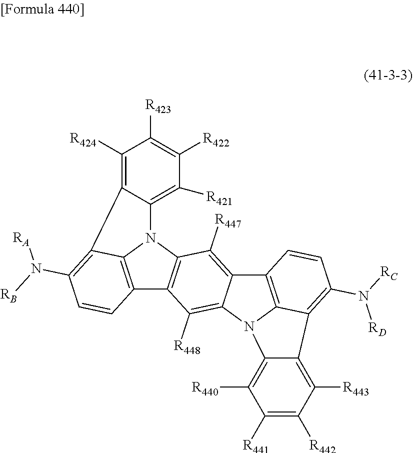

In the formula (41-3-3), R₄₂₁ to R₄₂₄, R₄₄₀ to R₄₄₃, R₄₄₇ and R₄₄₈ each independently represent the same as R₄₂₁ to R₄₂₄, R₄₄₀ to R₄₄₃, R₄₄₇ and R₄₄₈ in the formula (41-3); and

R_{A}, R_{B}, R_{C} and R_{D} are each independently a substituted or unsubstituted aryl group having 6 to 18 ring carbon atoms, or a substituted or unsubstituted heterocyclic group having 5 to 18 ring atoms.

In an exemplary embodiment, the compound represented by the formula (41-3-3) is a compound represented by a formula (41-3-4) below.

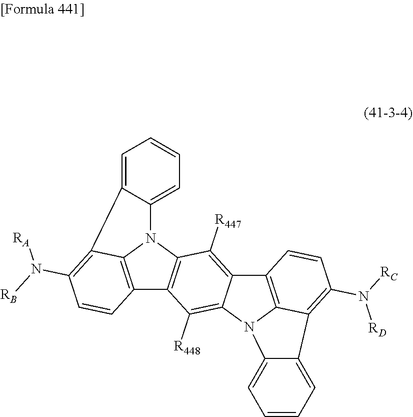

In the formula (41-3-4), R₄₄₇, R₄₄₈, R^{A}, R^{B}, R^{C} and R^{D} each independently represent the same as R₄₄₇, R₄₄₈, R^{A}, R^{B}, R^{C} and R^{D} in the formula (41-3-3).

In an exemplary embodiment, R^{A}, R^{B}, R^{C} and R^{D} are each independently a substituted or unsubstituted aryl group having 6 to 18 ring carbon atoms.

In an exemplary embodiment, R^{A}. R^{B}. R^{C} and R^{D} are each independently a substituted or unsubstituted phenyl group.

In an exemplary embodiment, R₄₄₇ to R₄₄₈ are each a hydrogen atom.

In an exemplary embodiment, the substituent for “the substituted or unsubstituted” group in each of the formulae is an unsubstituted alkyl group having 1 to 50 carbon atoms, an unsubstituted alkenyl group having 2 to 50 carbon atoms, an unsubstituted alkynyl group having 2 to 50 carbon atoms, an unsubstituted cycloalkyl group having 3 to 50 ring carbon atoms, —Si(R₉₀₁ₐ)(R₉₀₂ₐ)(R₉₀₃ₐ), —O—(R₉₀₄ₐ), —S—(R₉₀₅ₐ), —N(R₉₀₆ₐ)(R₉₀₇ₐ), a halogen atom, a cyano group, a nitro group, an unsubstituted aryl group having 6 to 50 ring carbon atoms, or, an unsubstituted heterocyclic group having 5 to 50 ring atoms;

R₉₀₁ₐ to R₉₀₇ₐ are each independently a hydrogen atom, an unsubstituted alkyl group having 1 to 50 carbon atoms, an unsubstituted aryl group having 6 to 50 ring carbon atoms, or, an unsubstituted heterocyclic group having 5 to 50 ring atoms;

when two or more R₉₀₁ₐ are present, the two or more R₉₀₁ₐ are mutually the same or different;

when two or more R₉₀₂ₐ are present, the two or more R₉₀₂ₐ are mutually the same or different;

when two or more R₉₀₃ₐ are present, the two or more R₉₀₃ₐ are mutually the same or different;

when two or more R₉₀₄ₐ are present, the two or more R₉₀₄ₐ are mutually the same or different;

when two or more R₉₀₅ₐ are present, the two or more R₉₀₅ₐ are mutually the same or different;

when two or more R₉₀₆ₐ are present, the two or more R₉₀₆ₐ are mutually the same or different; and

when two or more R₉₀₇ₐ are present, the two or more R₉₀₇ₐ are mutually the same or different.

In an exemplary embodiment, the substituent for “the substituted or unsubstituted” group in each of the formulae is an unsubstituted alkyl group having 1 to 50 carbon atoms, an unsubstituted aryl group having 6 to 50 ring carbon atoms, or, an unsubstituted heterocyclic group having 5 to 50 ring atoms.

In an exemplary embodiment, the substituent for “the substituted or unsubstituted” group in each of the formulae is an unsubstituted alkyl group having 1 to 18 carbon atoms, an unsubstituted aryl group having 6 to 18 ring carbon atoms, or, an unsubstituted heterocyclic group having 5 to 18 ring atoms.

### Specific Examples of Third Compound and Fourth Compound

Specific examples of the third compound and the fourth compound include compounds below. It should however be noted that the invention is not limited to the specific examples of the third compound and the fourth compound.

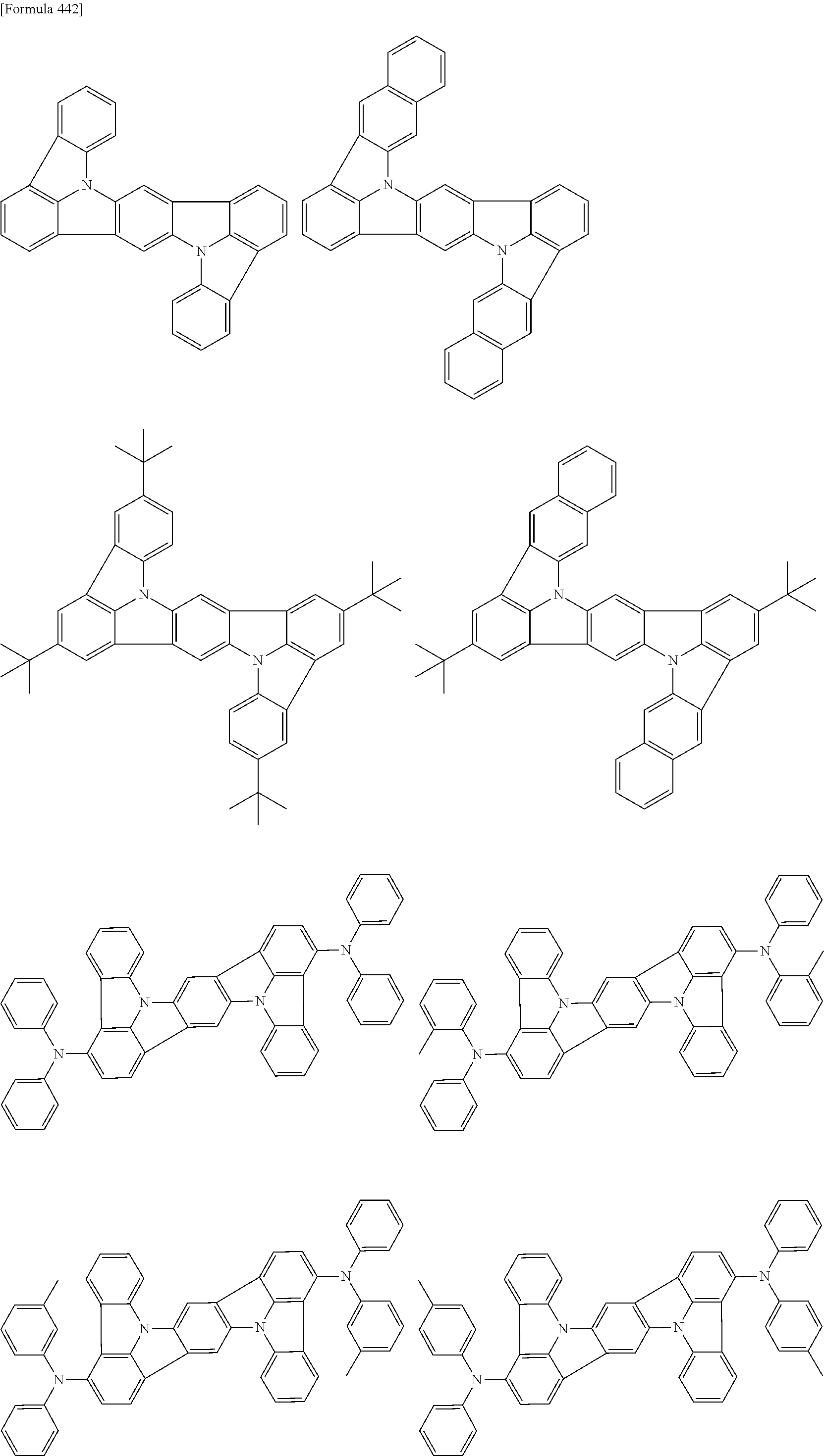

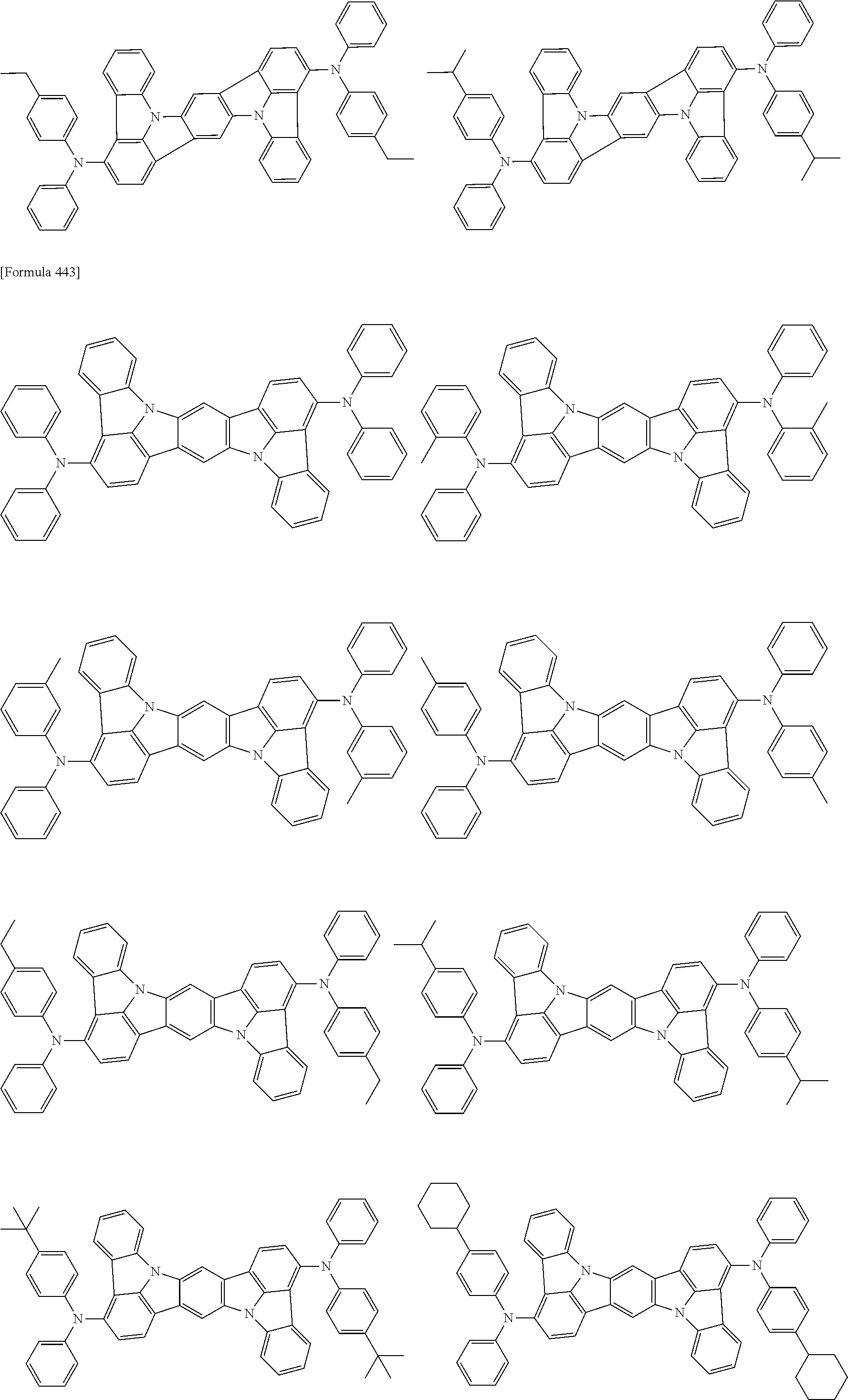

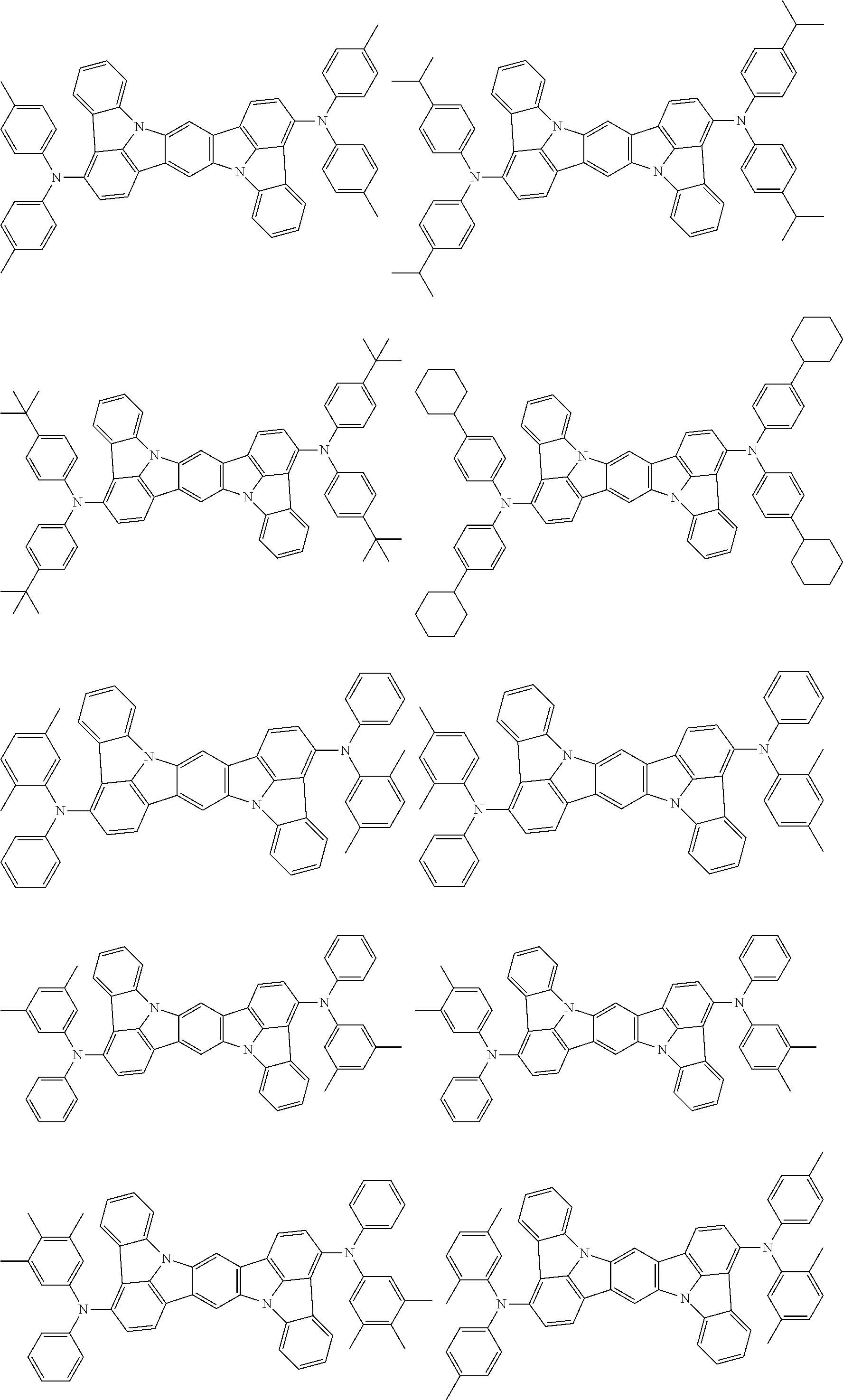

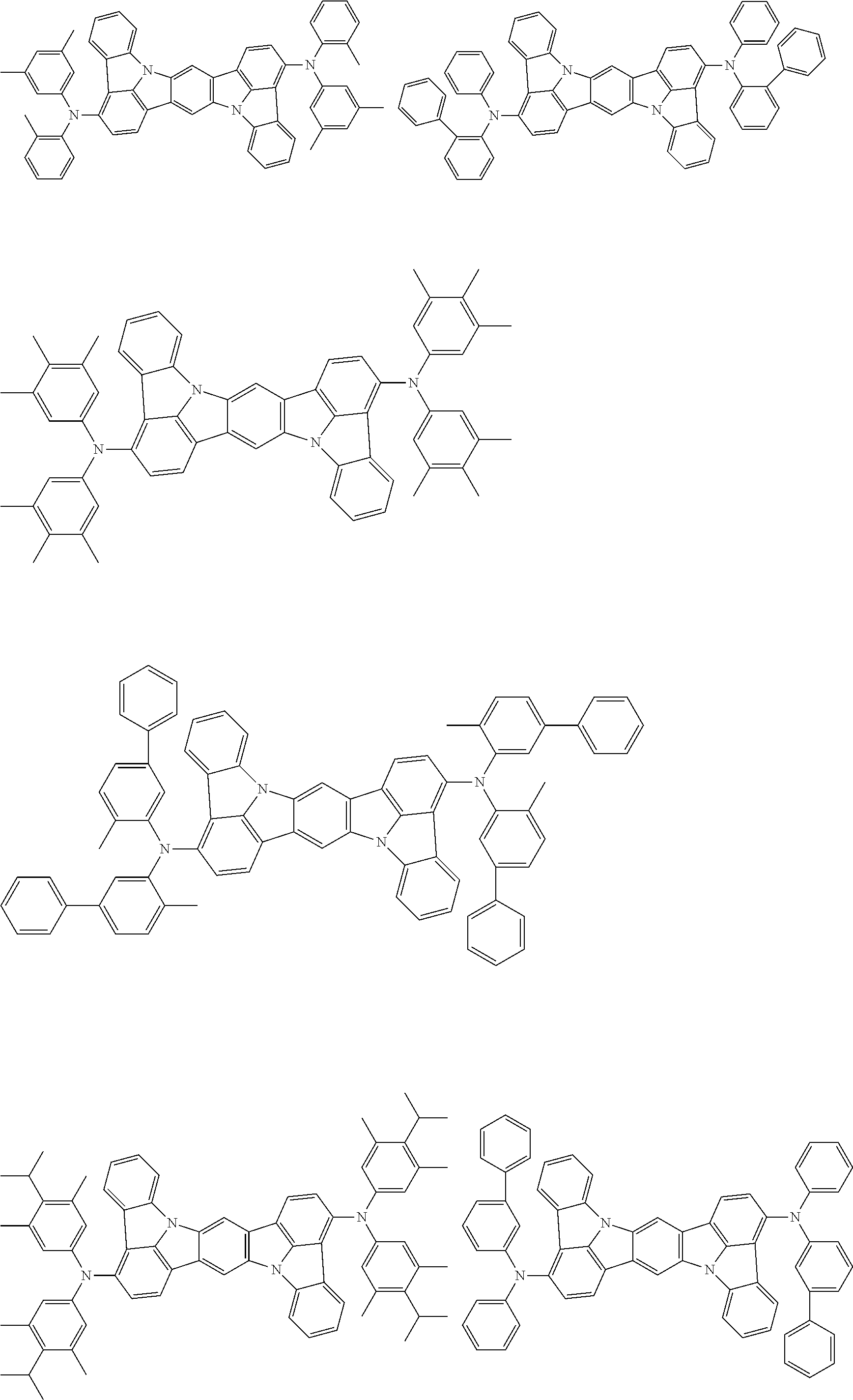

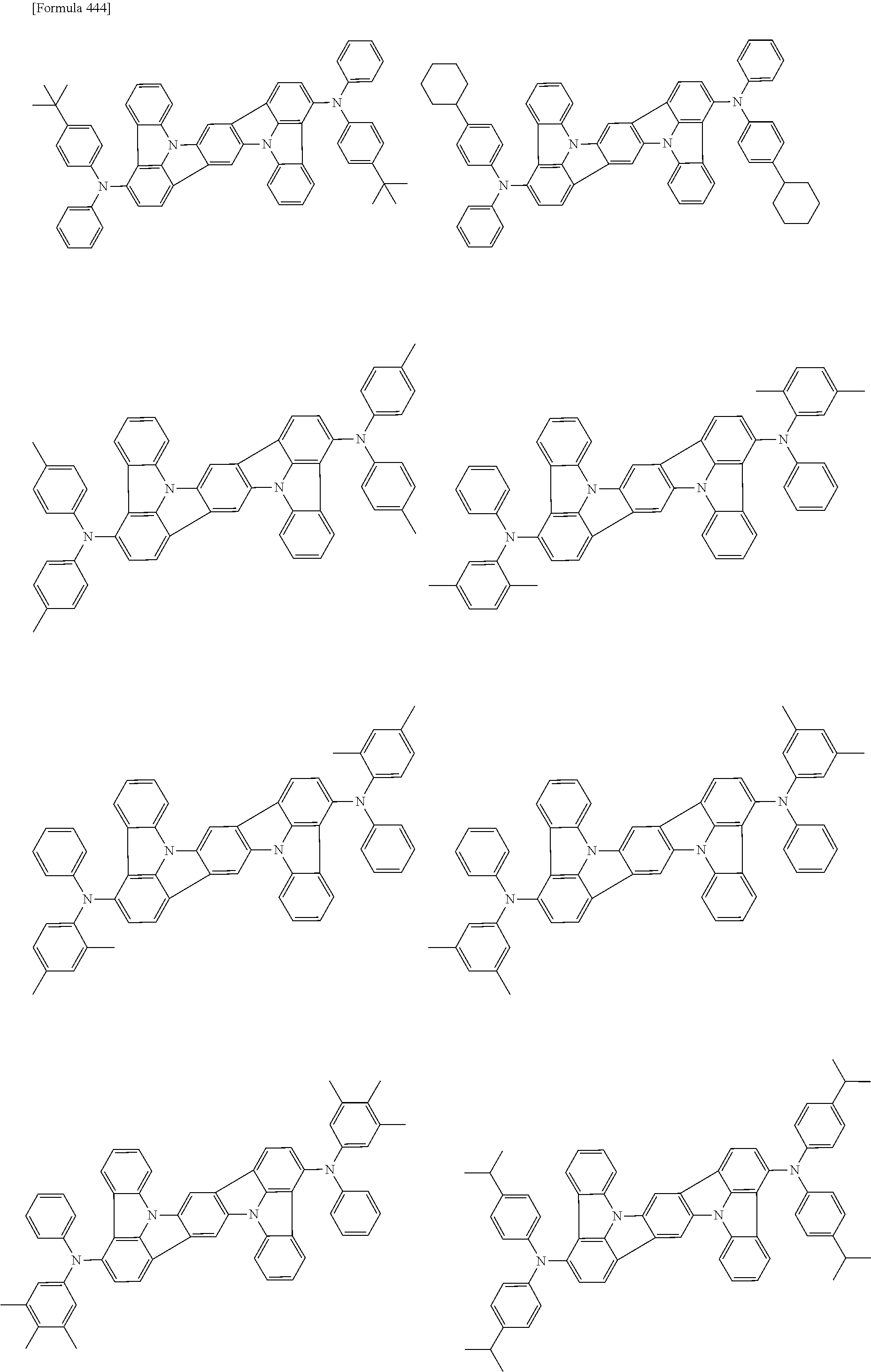

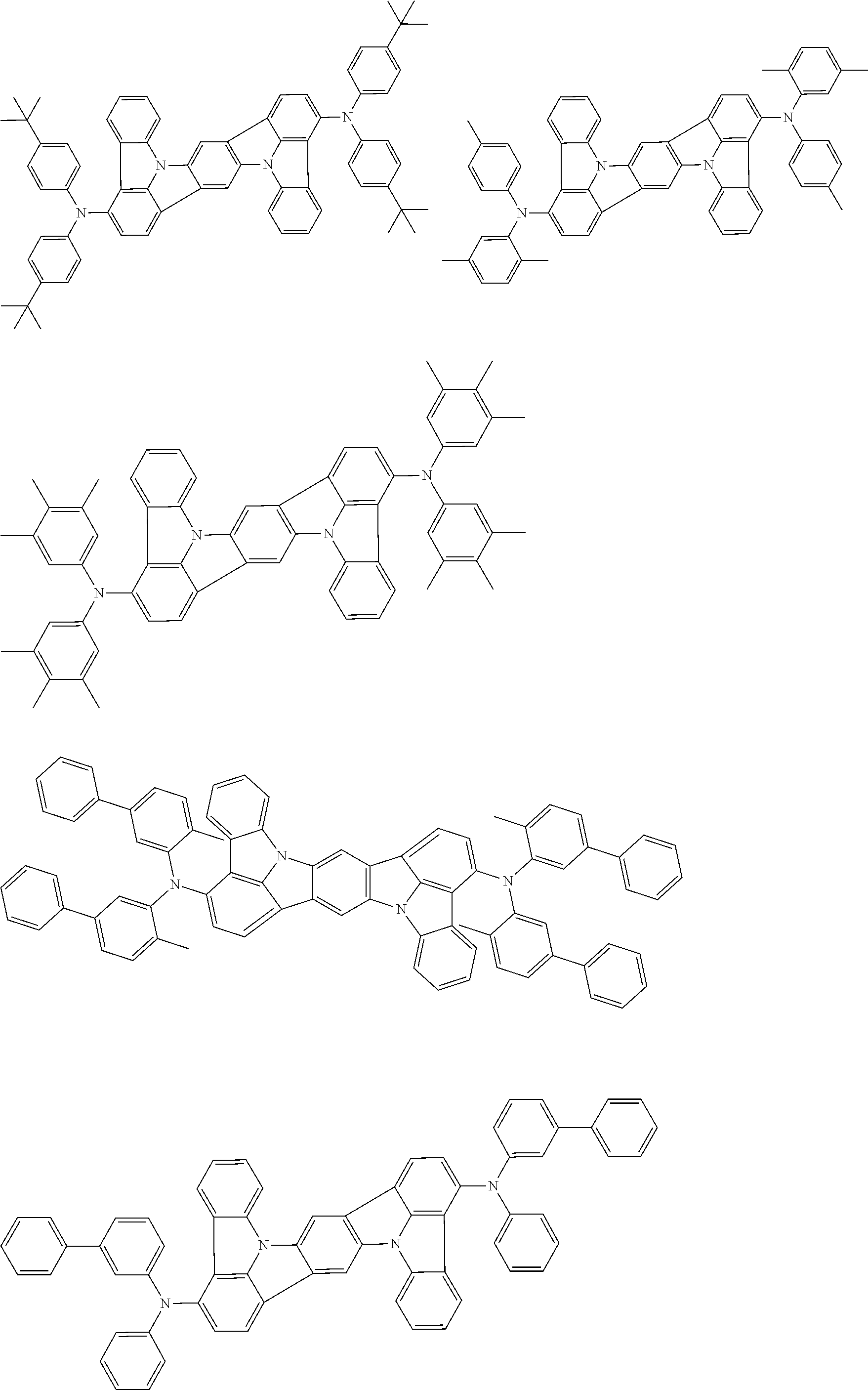

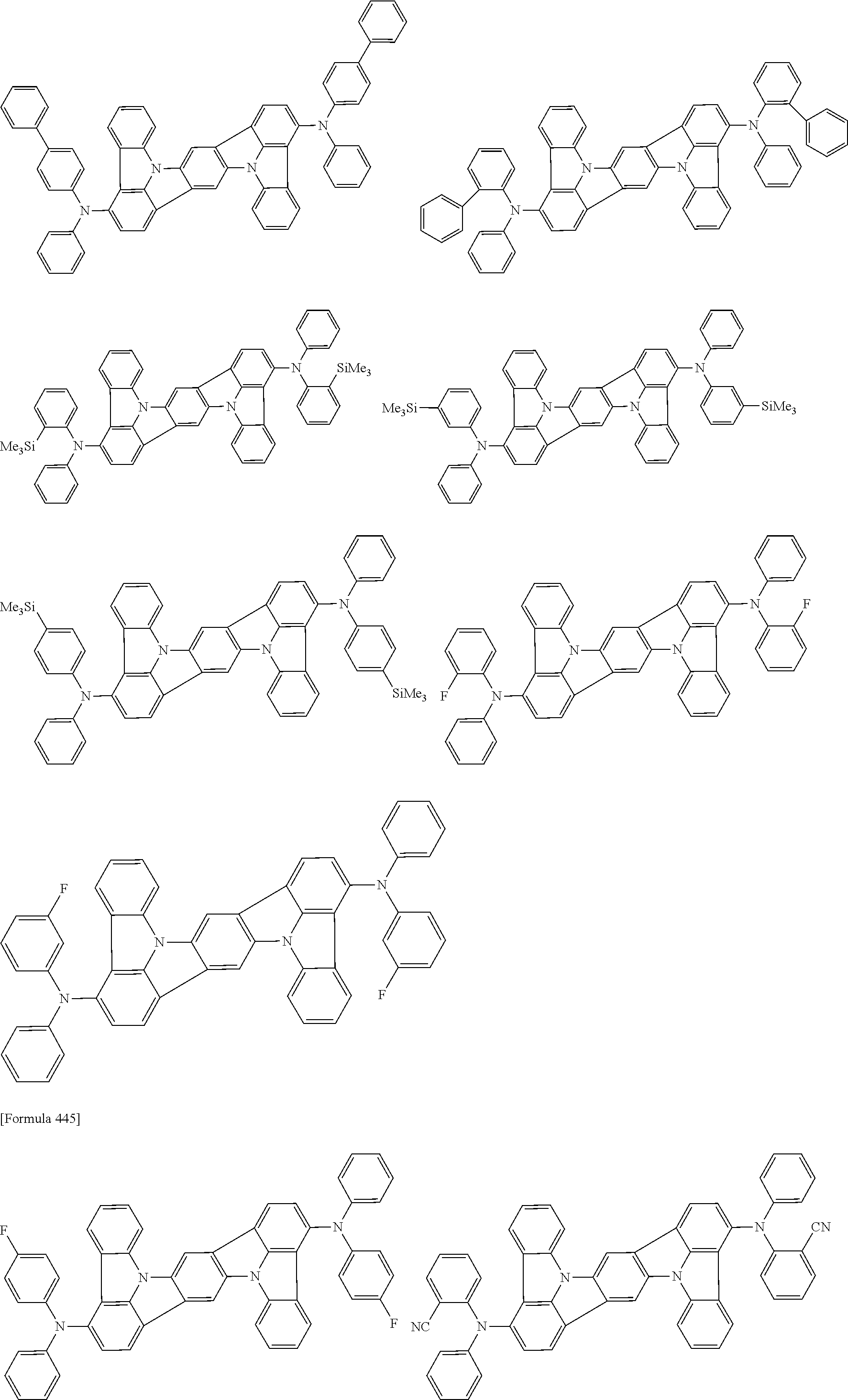

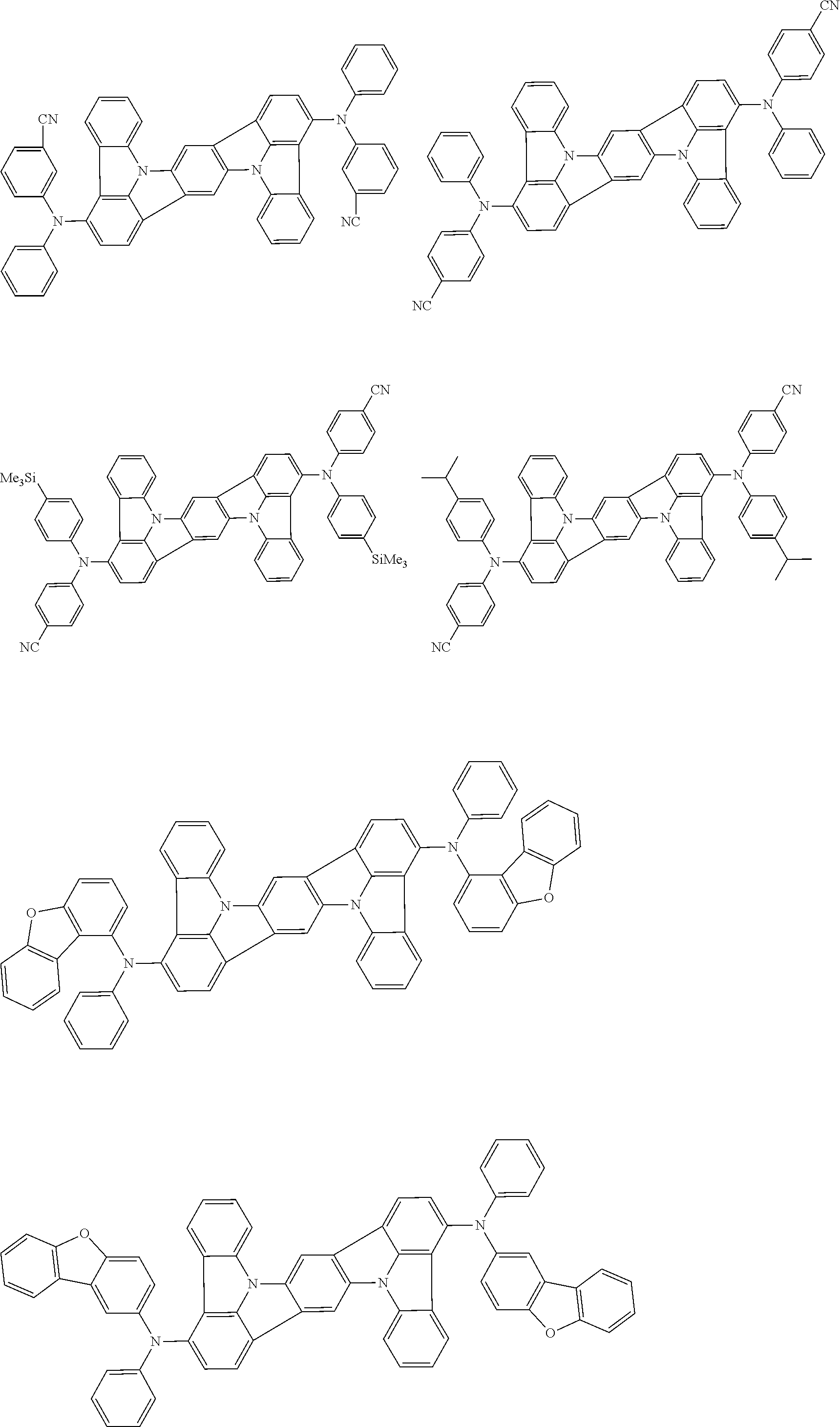

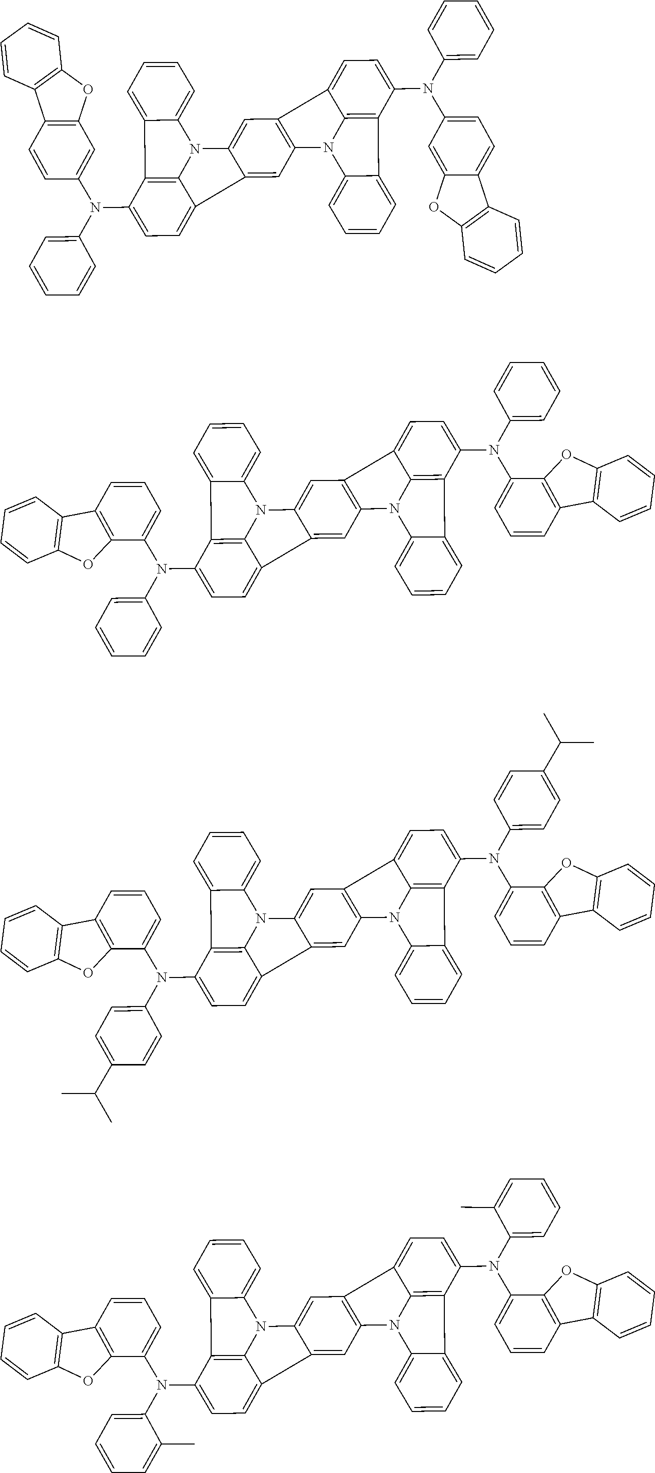 [SMILES: c1ccc(N(c2ccc3c(c2)oc2ccccc23)c2ccc3c4cc5c(cc4n4c6ccccc6c2c34)c2ccc(N(c3ccccc3)c3ccc4c(c3)oc3ccccc34)c3c4ccccc4n5c23)cc1 ; c1ccc(N(c2cccc3c2oc2ccccc23)c2ccc3c4cc5c(cc4n4c6ccccc6c2c34)c2ccc(N(c3ccccc3)c3cccc4c3oc3ccccc34)c3c4ccccc4n5c23)cc1 ; CC(C)c1ccc(N(c2cccc3c2oc2ccccc23)c2ccc3c4cc5c(cc4n4c6ccccc6c2c34)c2ccc(N(c3ccc(C(C)C)cc3)c3cccc4c3oc3ccccc34)c3c4ccccc4n5c23)cc1 ; Cc1ccccc1N(c1cccc2c1oc1ccccc12)c1ccc2c3cc4c(cc3n3c5ccccc5c1c23)c1ccc(N(c2ccccc2C)c2cccc3c2oc2ccccc23)c2c3ccccc3n4c12]

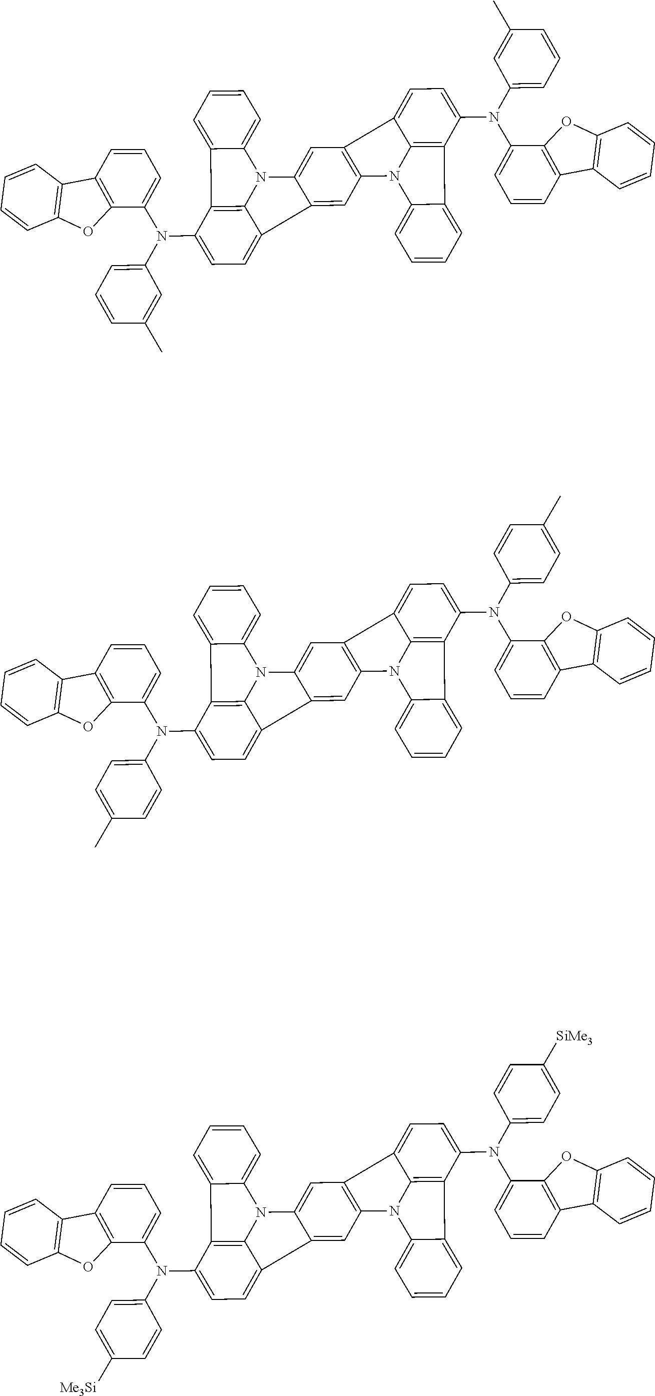 [SMILES: Cc1cccc(N(c2cccc3c2oc2ccccc23)c2ccc3c4cc5c(cc4n4c6ccccc6c2c34)c2ccc(N(c3cccc(C)c3)c3cccc4c3oc3ccccc34)c3c4ccccc4n5c23)c1 ; Cc1ccc(N(c2cccc3c2oc2ccccc23)c2ccc3c4cc5c(cc4n4c6ccccc6c2c34)c2ccc(N(c3ccc(C)cc3)c3cccc4c3oc3ccccc34)c3c4ccccc4n5c23)cc1 ; C[Si](C)(C)c1ccc(N(c2cccc3c2oc2ccccc23)c2ccc3c4cc5c(cc4n4c6ccccc6c2c34)c2ccc(N(c3ccc([Si](C)(C)C)cc3)c3cccc4c3oc3ccccc34)c3c4ccccc4n5c23)cc1]

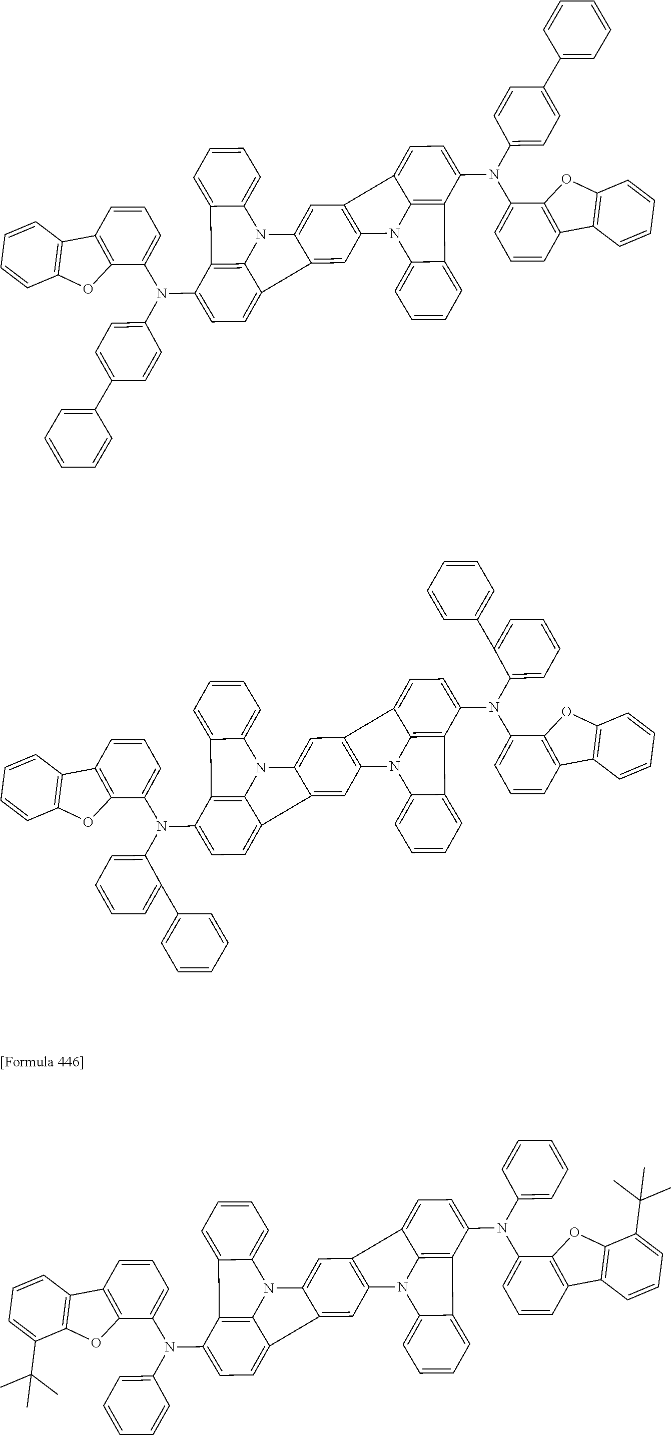 [SMILES: c1ccc(-c2ccc(N(c3cccc4c3oc3ccccc34)c3ccc4c5cc6c(cc5n5c7ccccc7c3c45)c3ccc(N(c4ccc(-c5ccccc5)cc4)c4cccc5c4oc4ccccc45)c4c5ccccc5n6c34)cc2)cc1 ; c1ccc(-c2ccccc2N(c2cccc3c2oc2ccccc23)c2ccc3c4cc5c(cc4n4c6ccccc6c2c34)c2ccc(N(c3ccccc3-c3ccccc3)c3cccc4c3oc3ccccc34)c3c4ccccc4n5c23)cc1 ; CC(C)(C)c1cccc2c1oc1c(N(c3ccccc3)c3ccc4c5cc6c(cc5n5c7ccccc7c3c45)c3ccc(N(c4ccccc4)c4cccc5c4oc4c(C(C)(C)C)cccc45)c4c5ccccc5n6c34)cccc12]

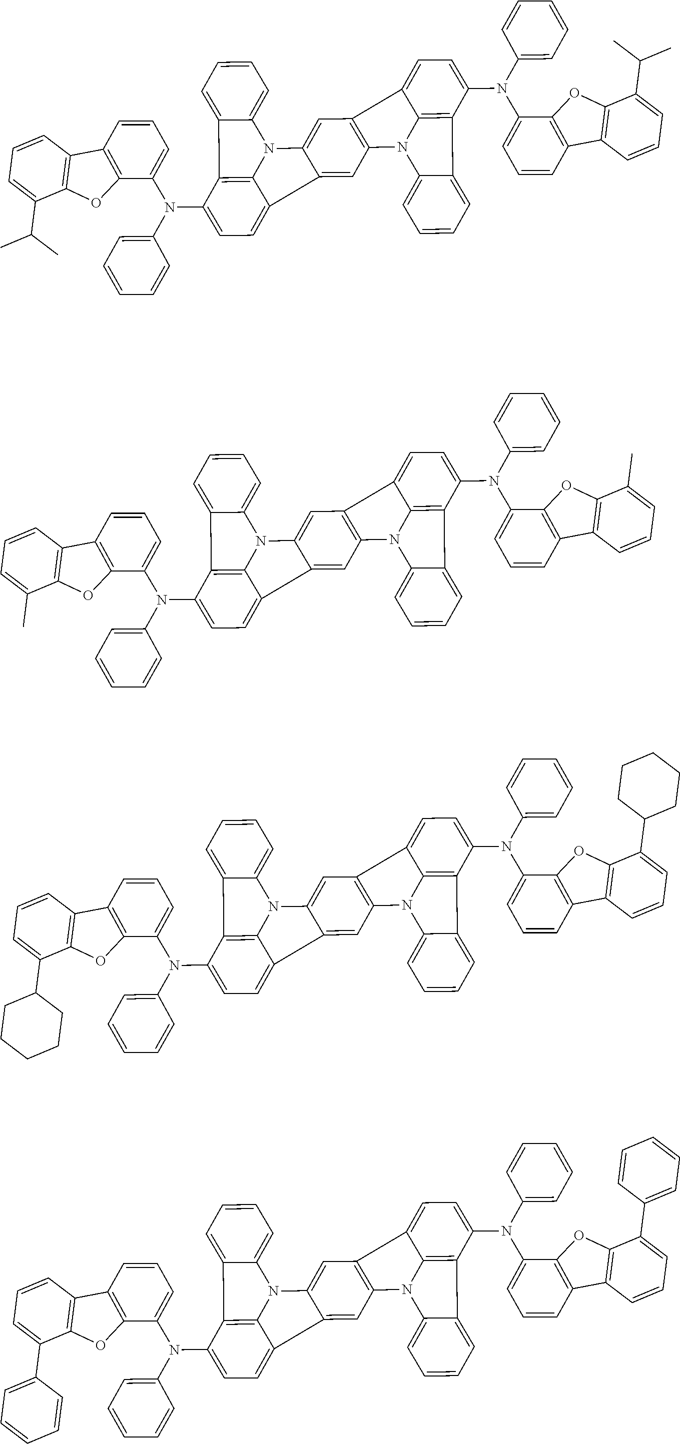

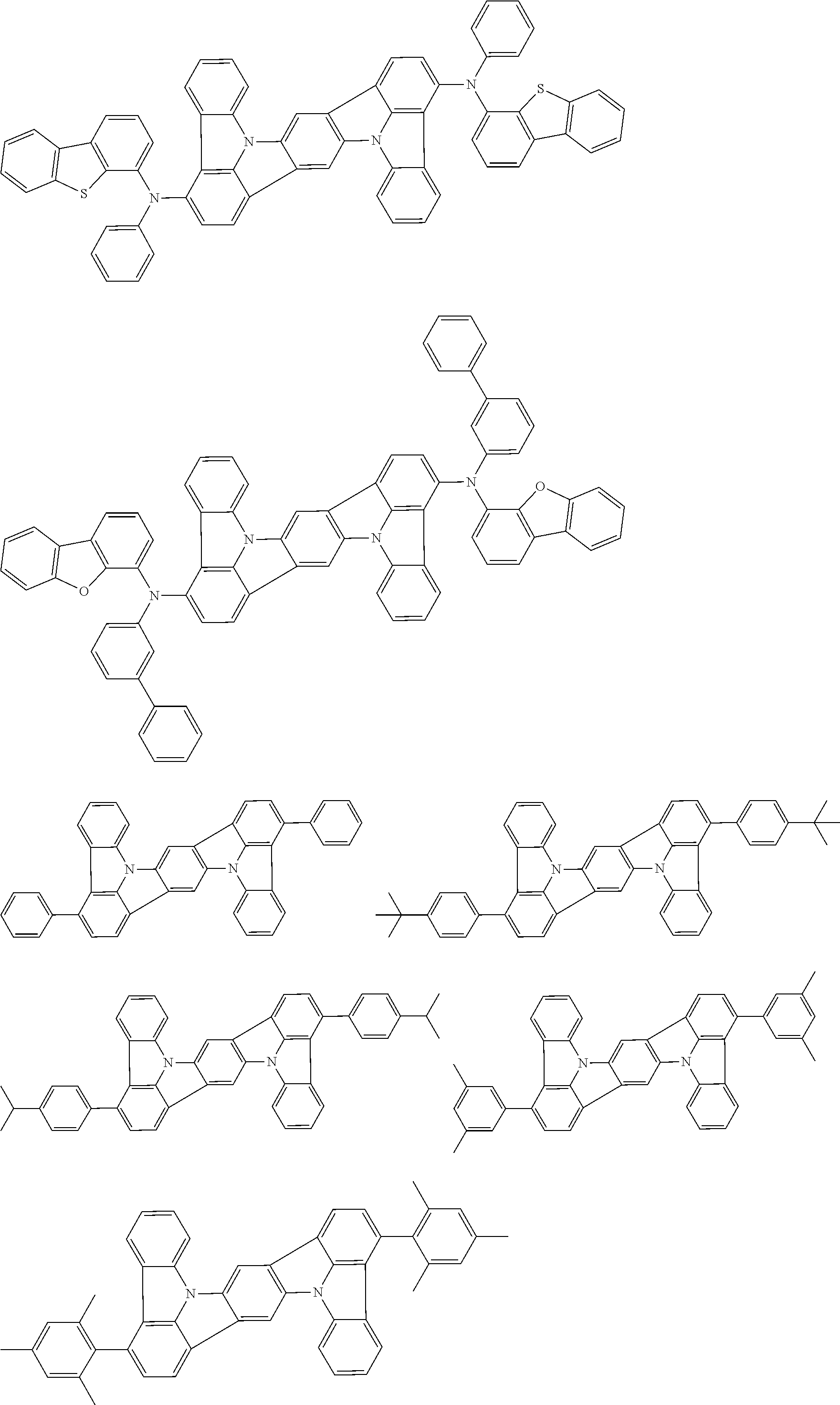

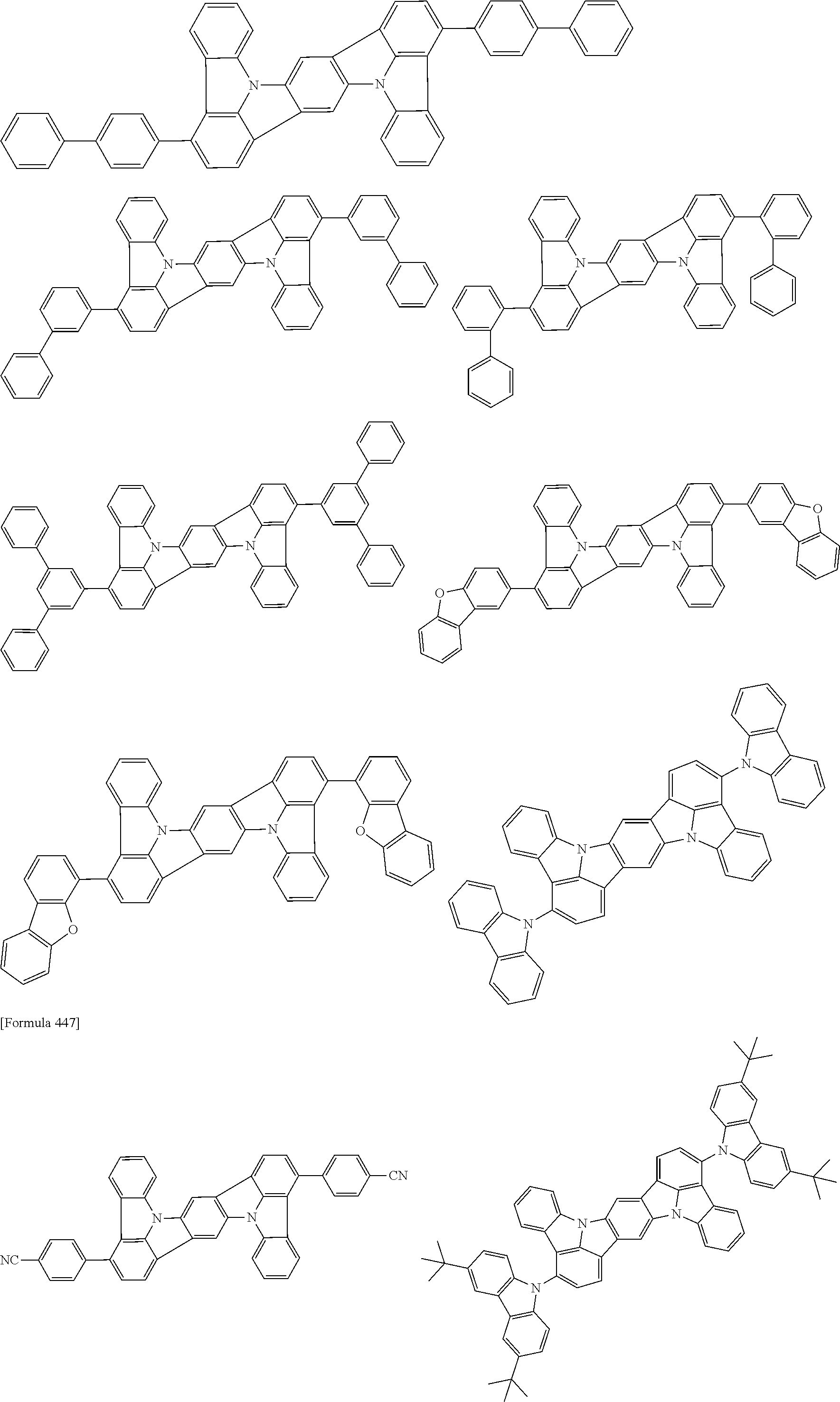

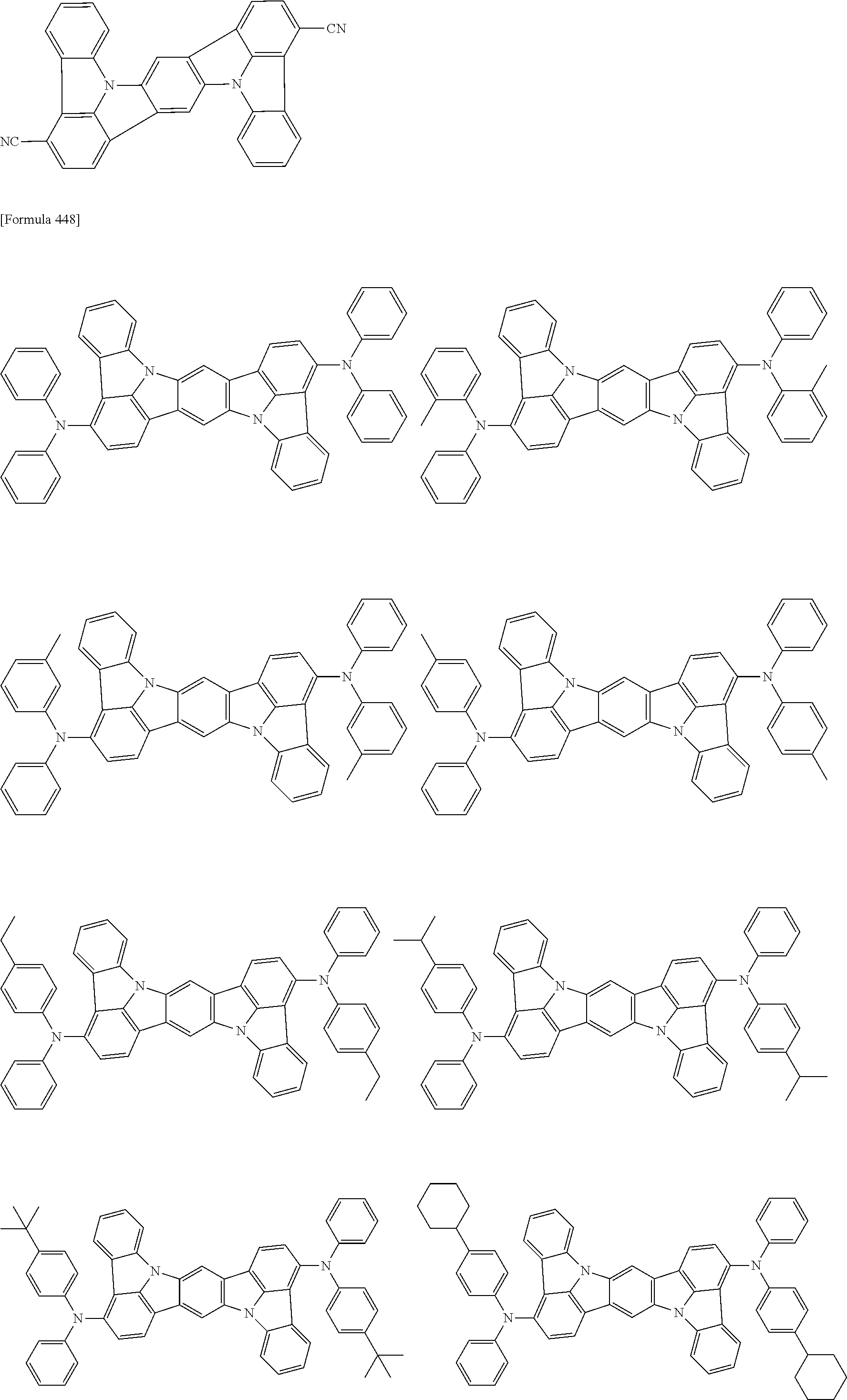

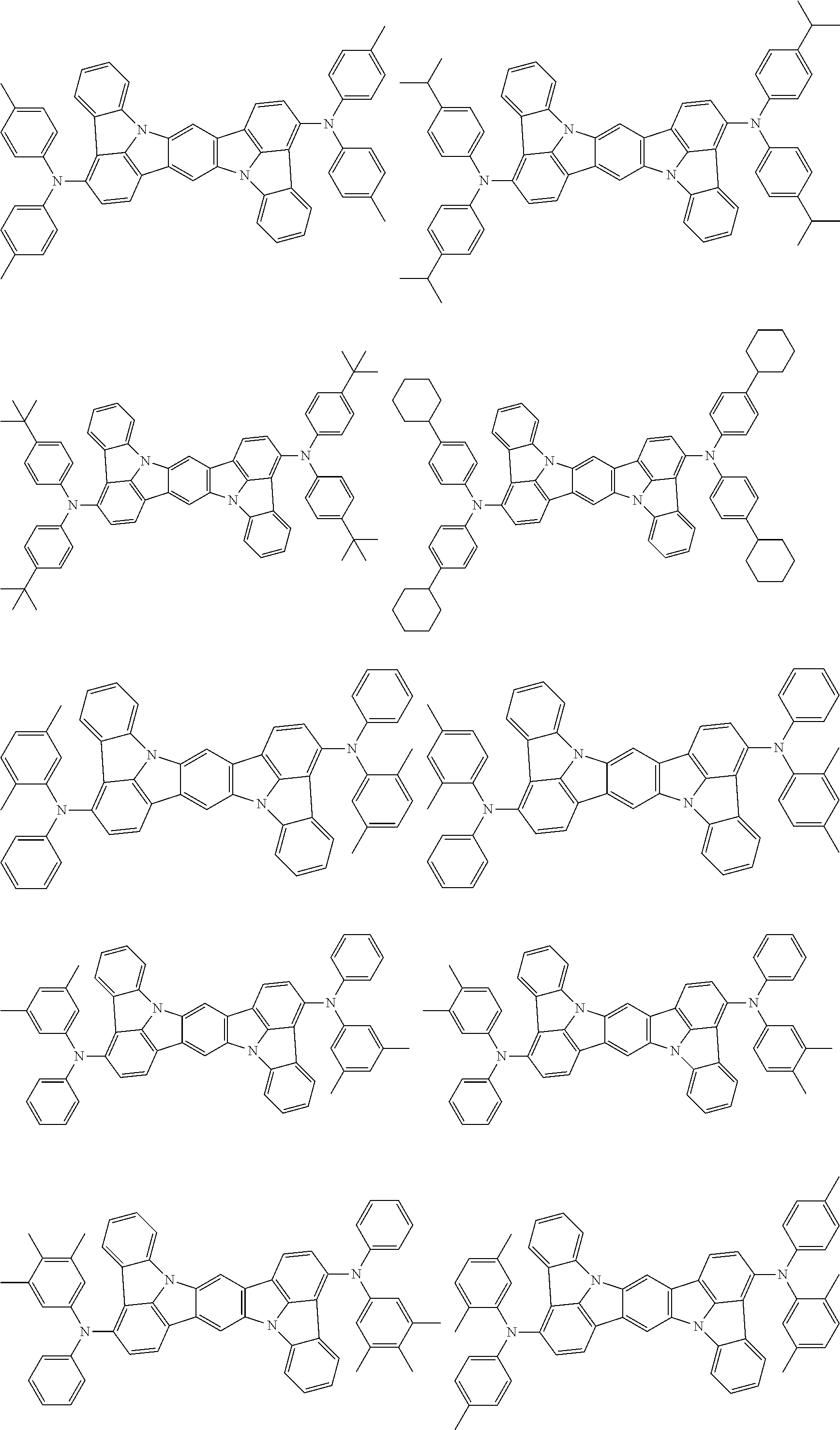

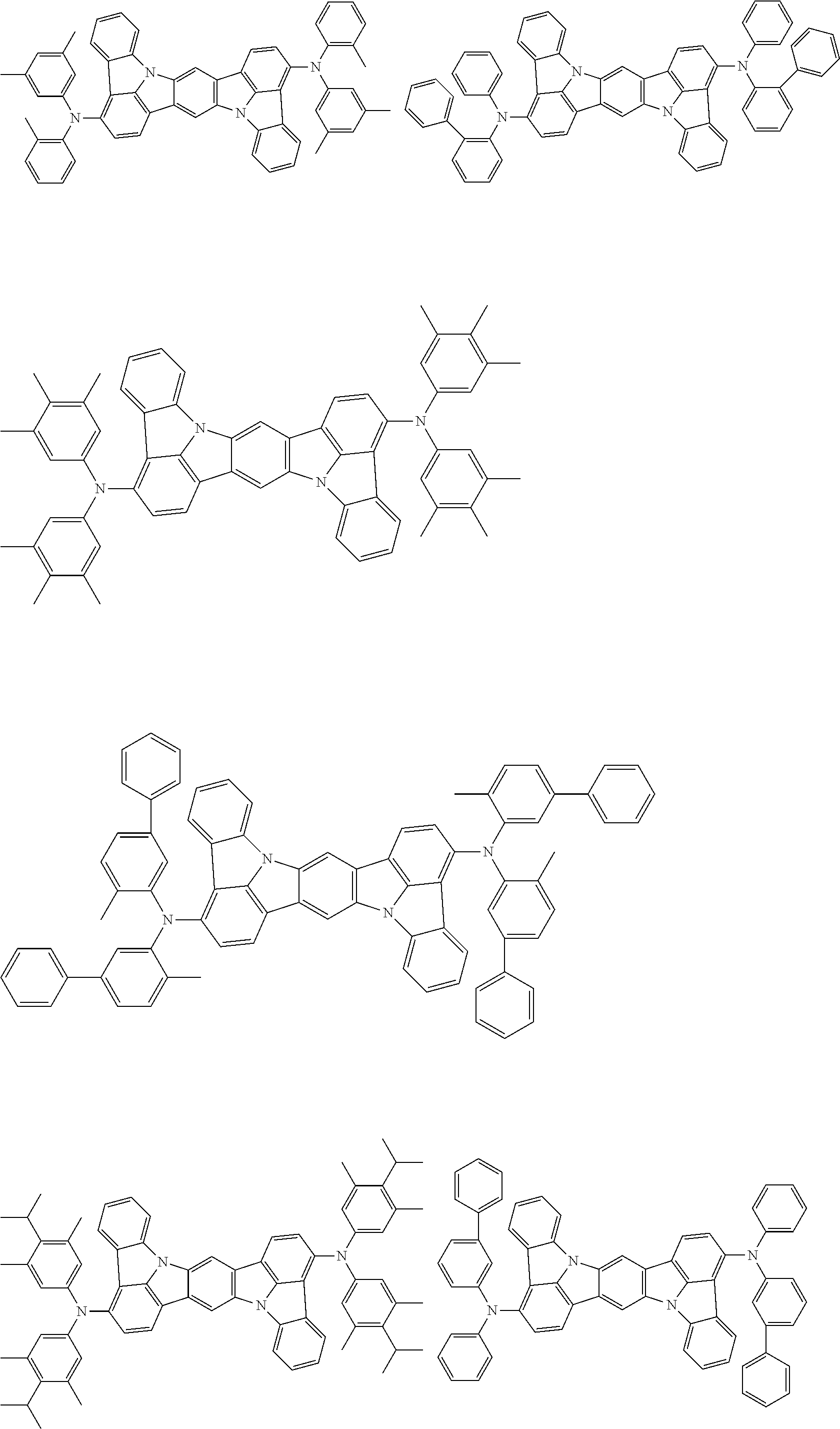

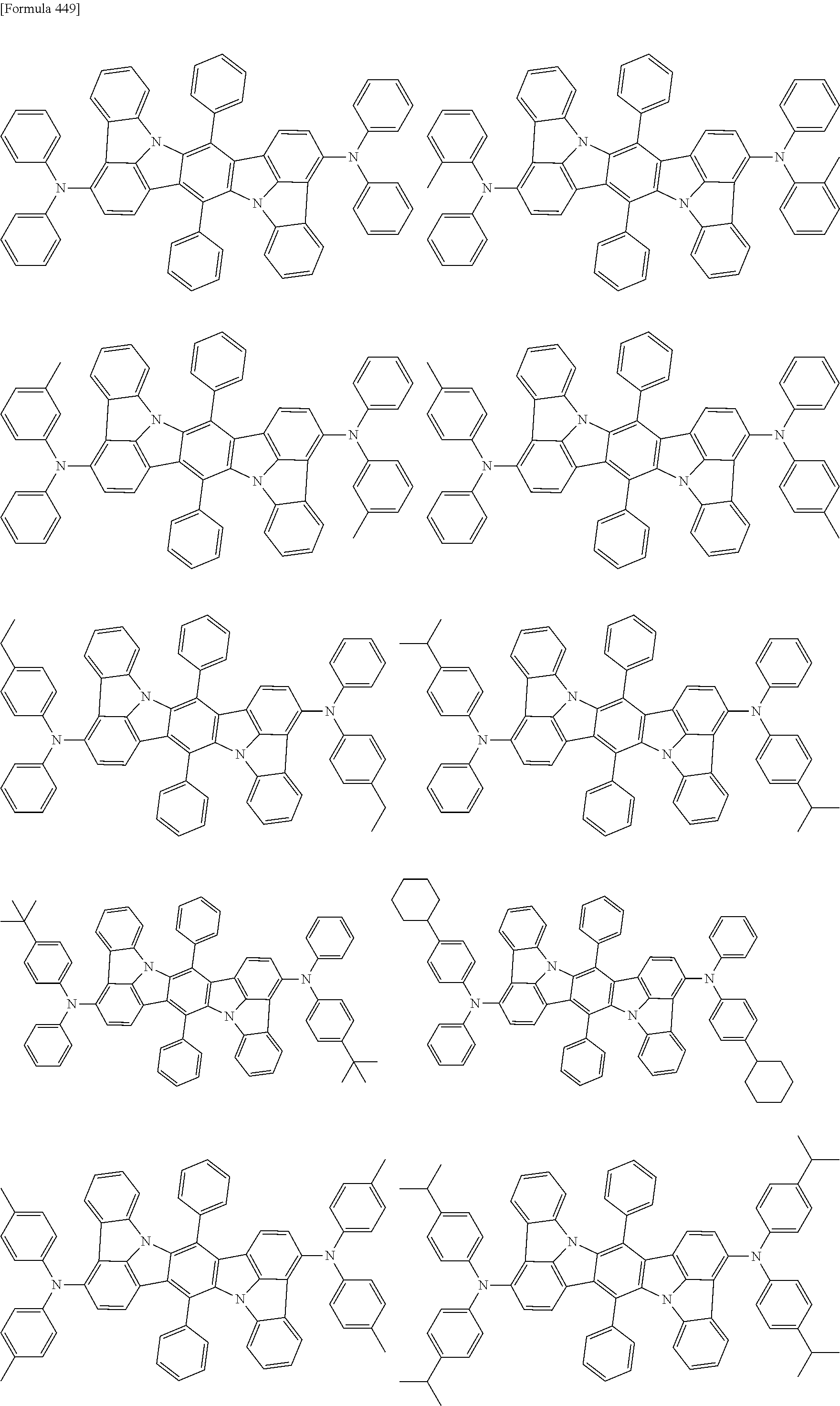

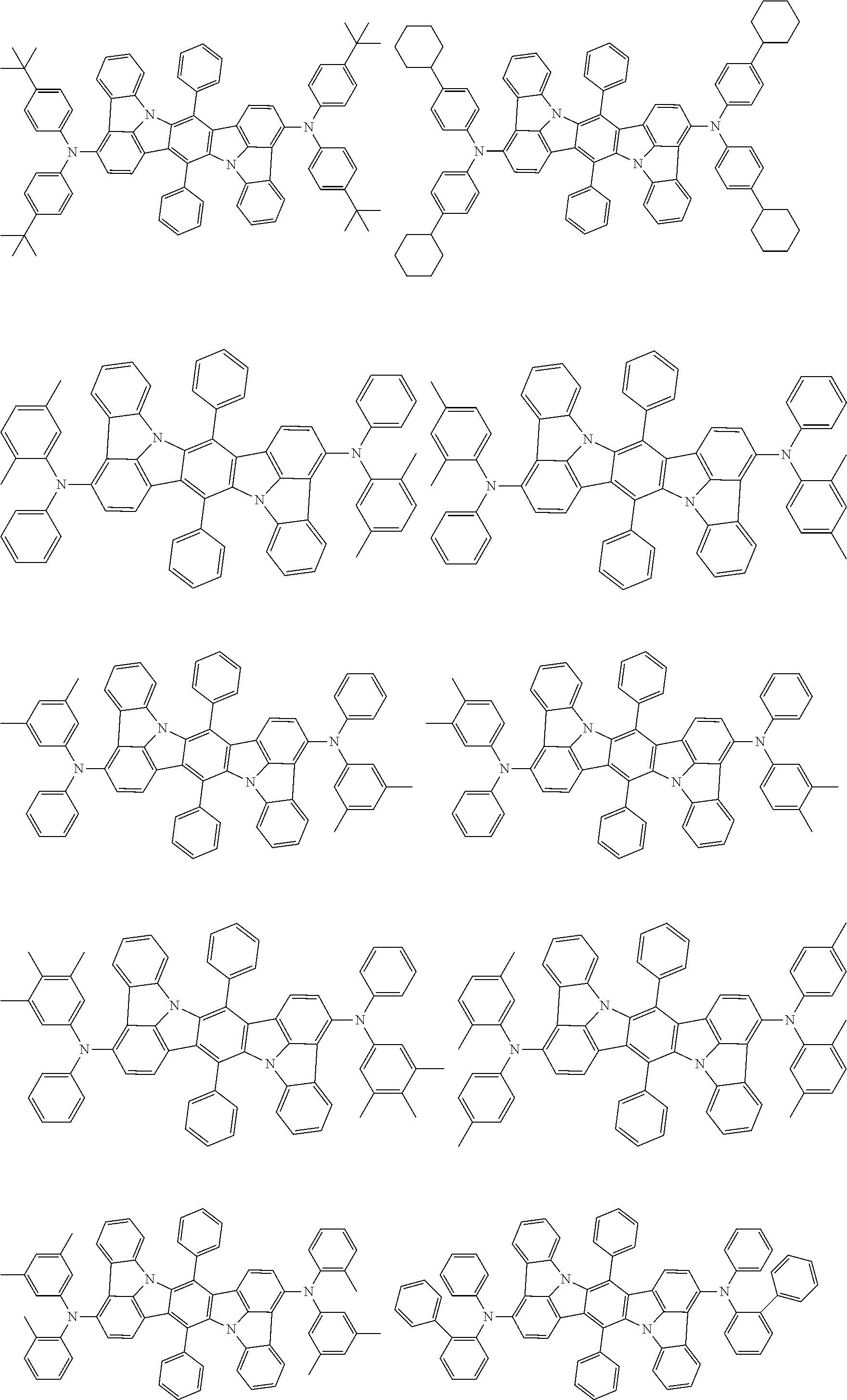

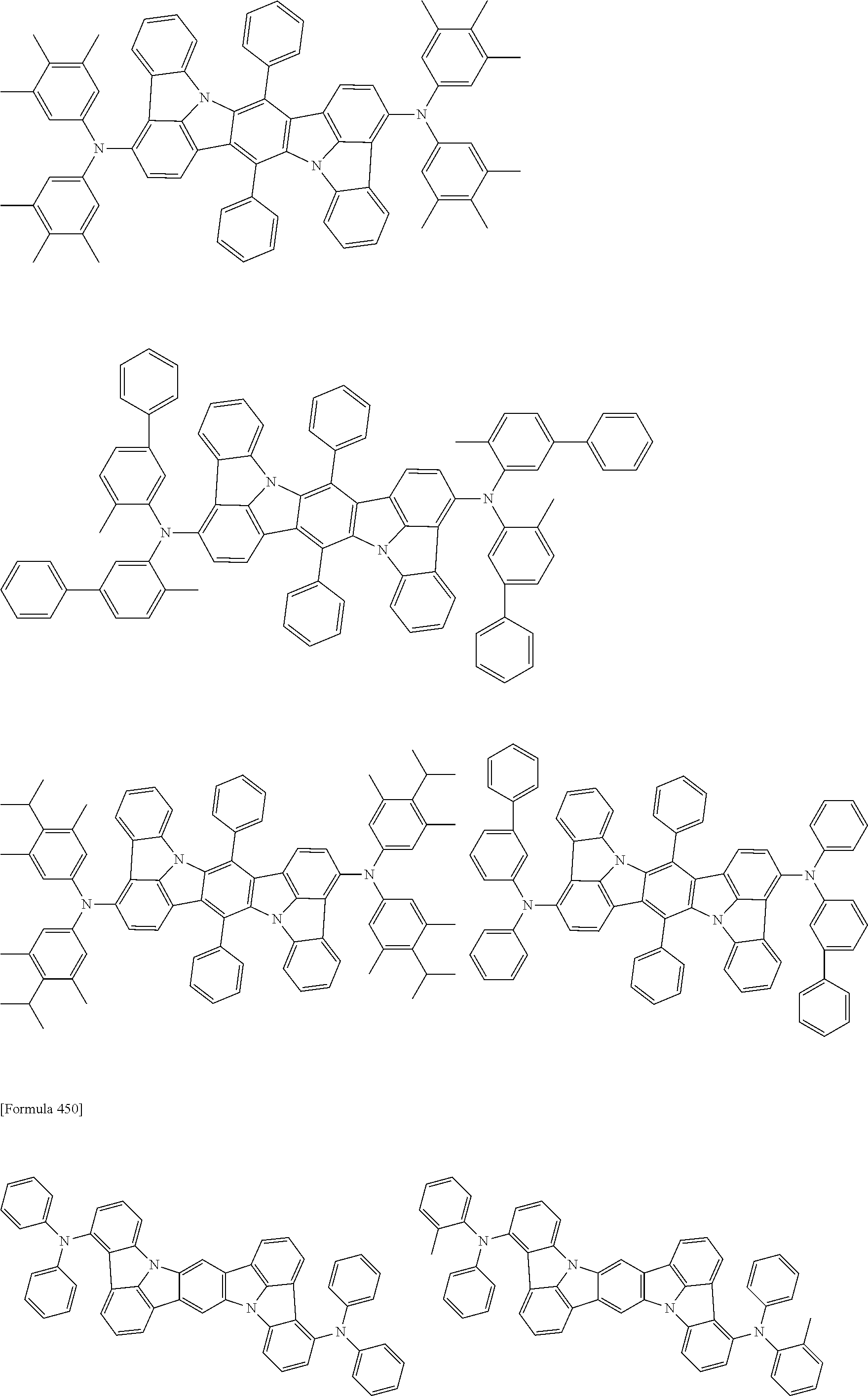

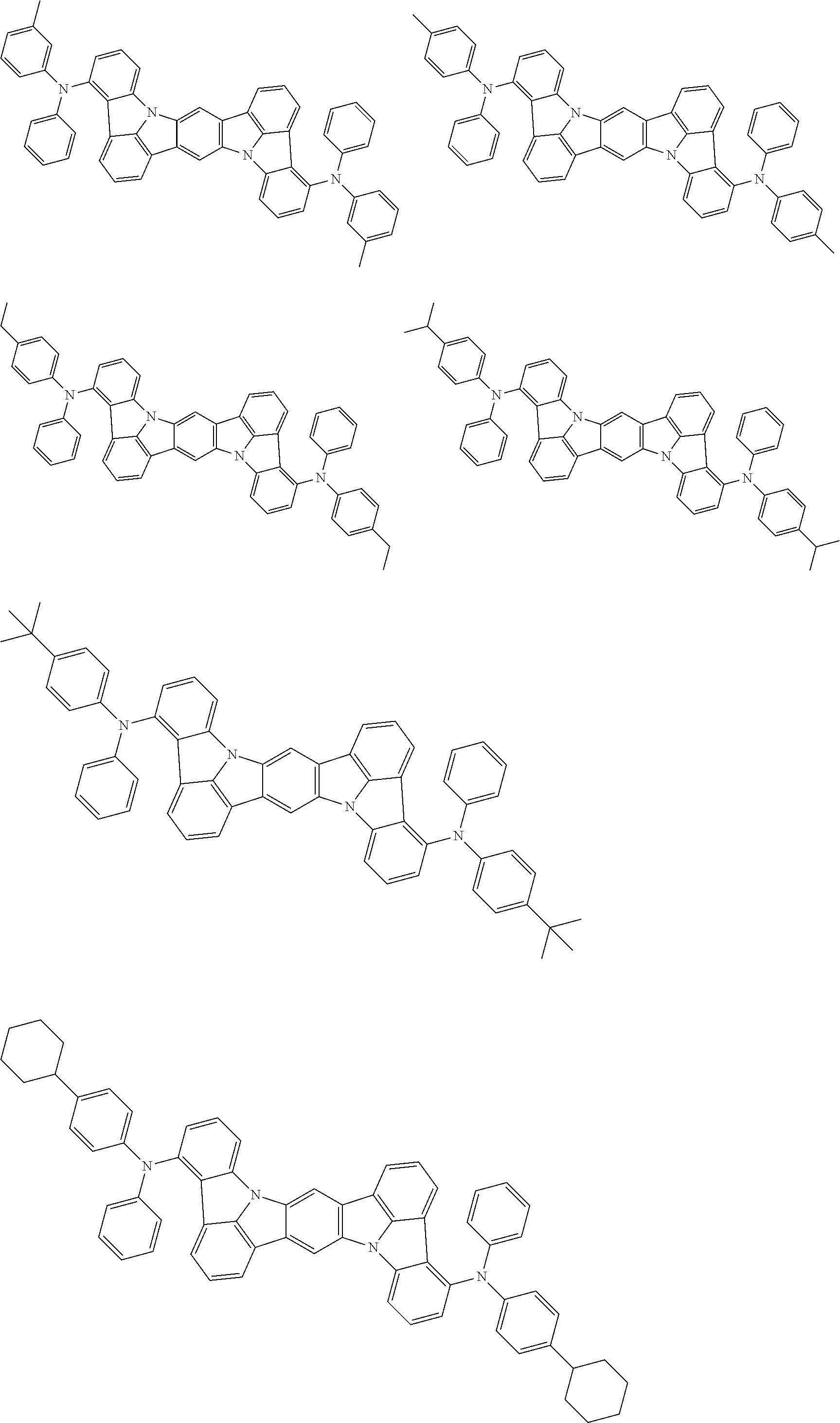

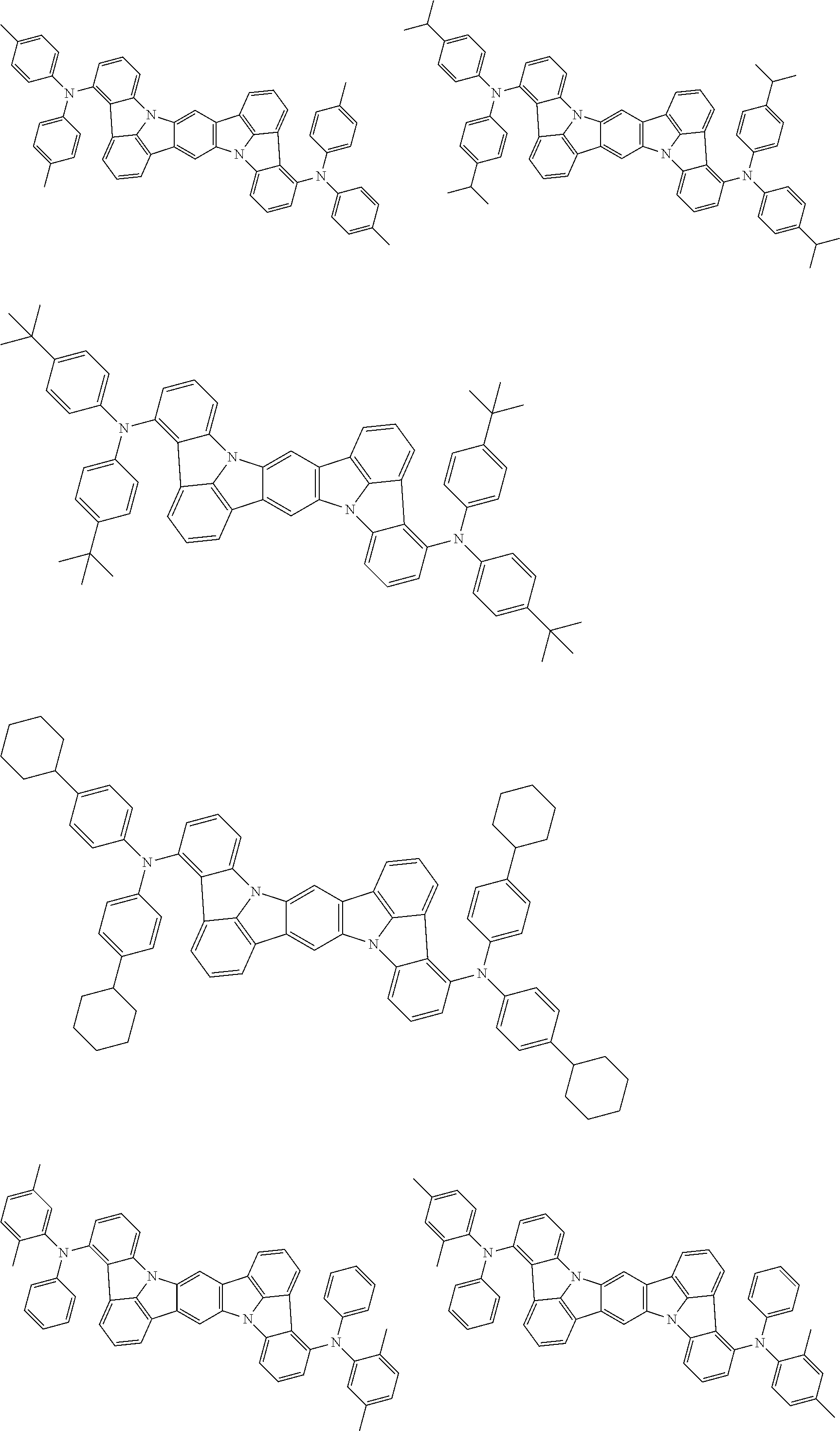

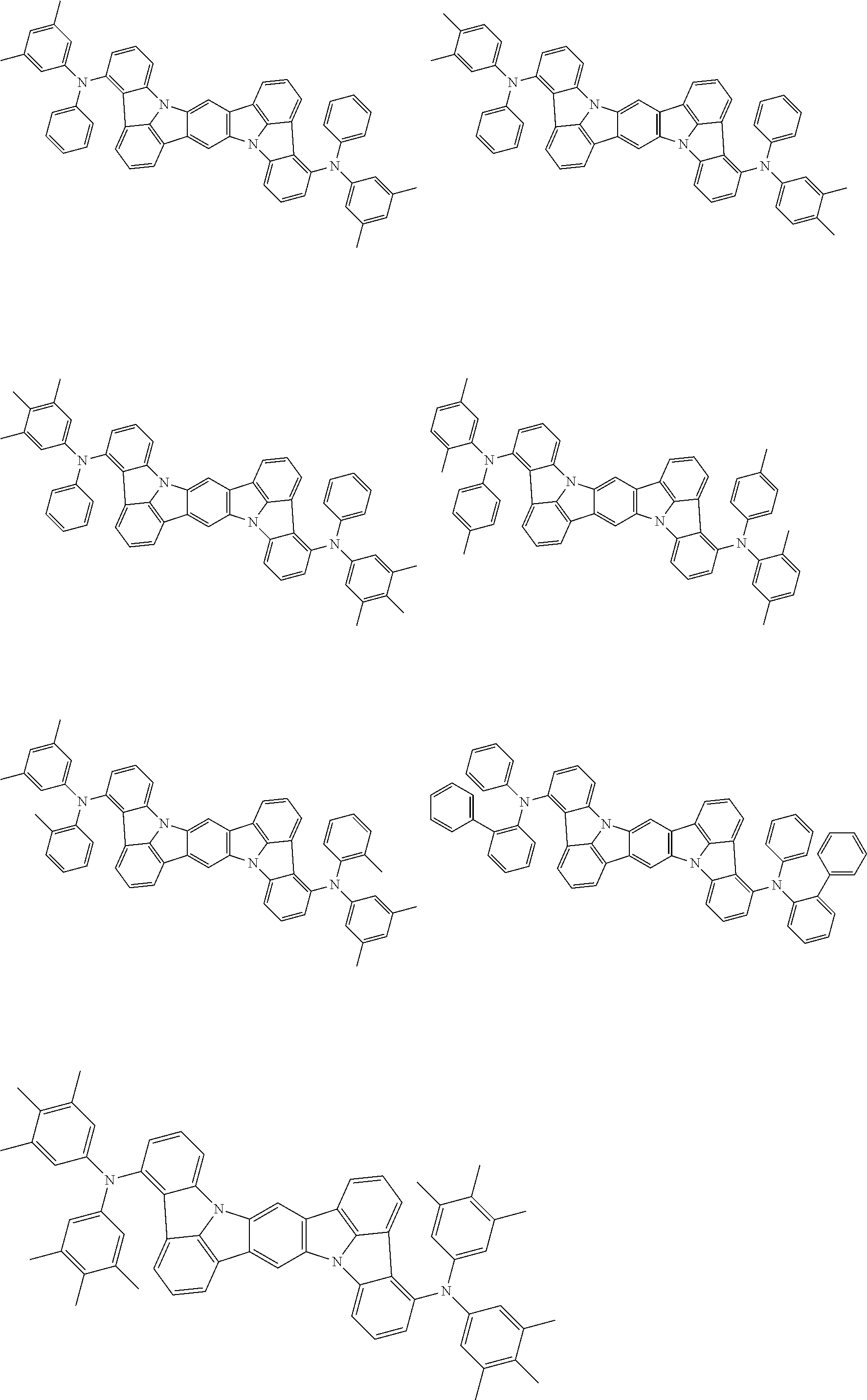

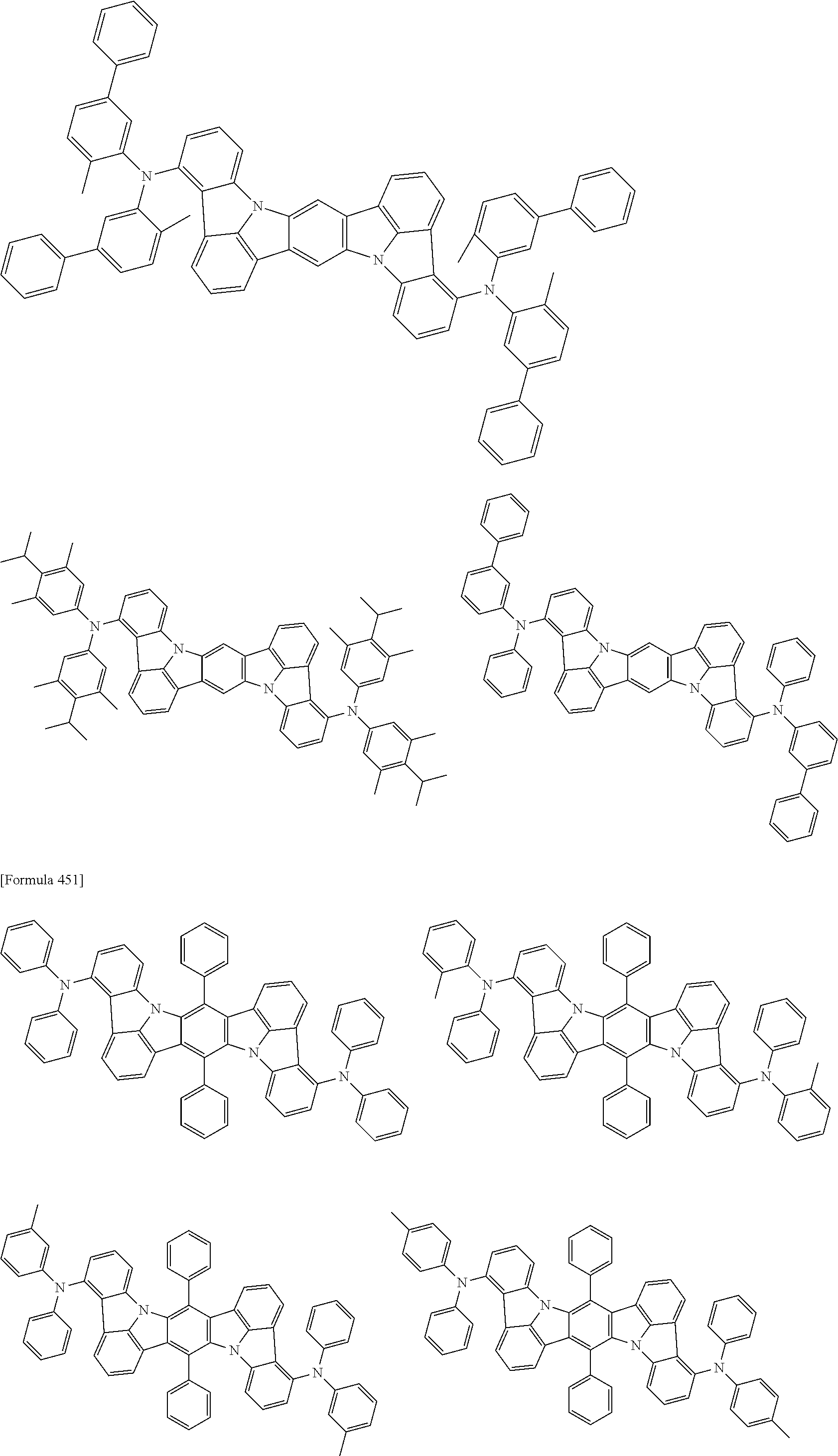

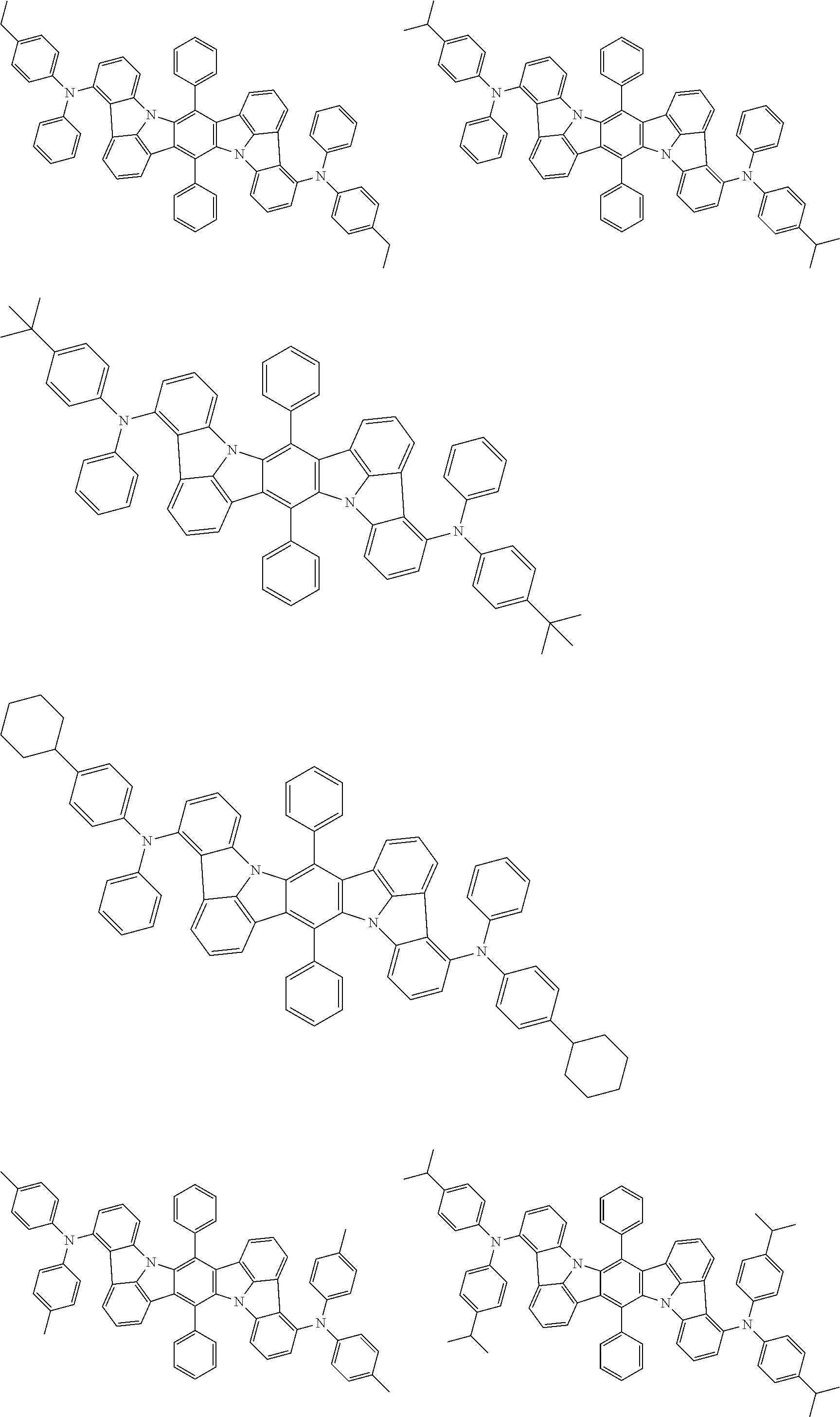

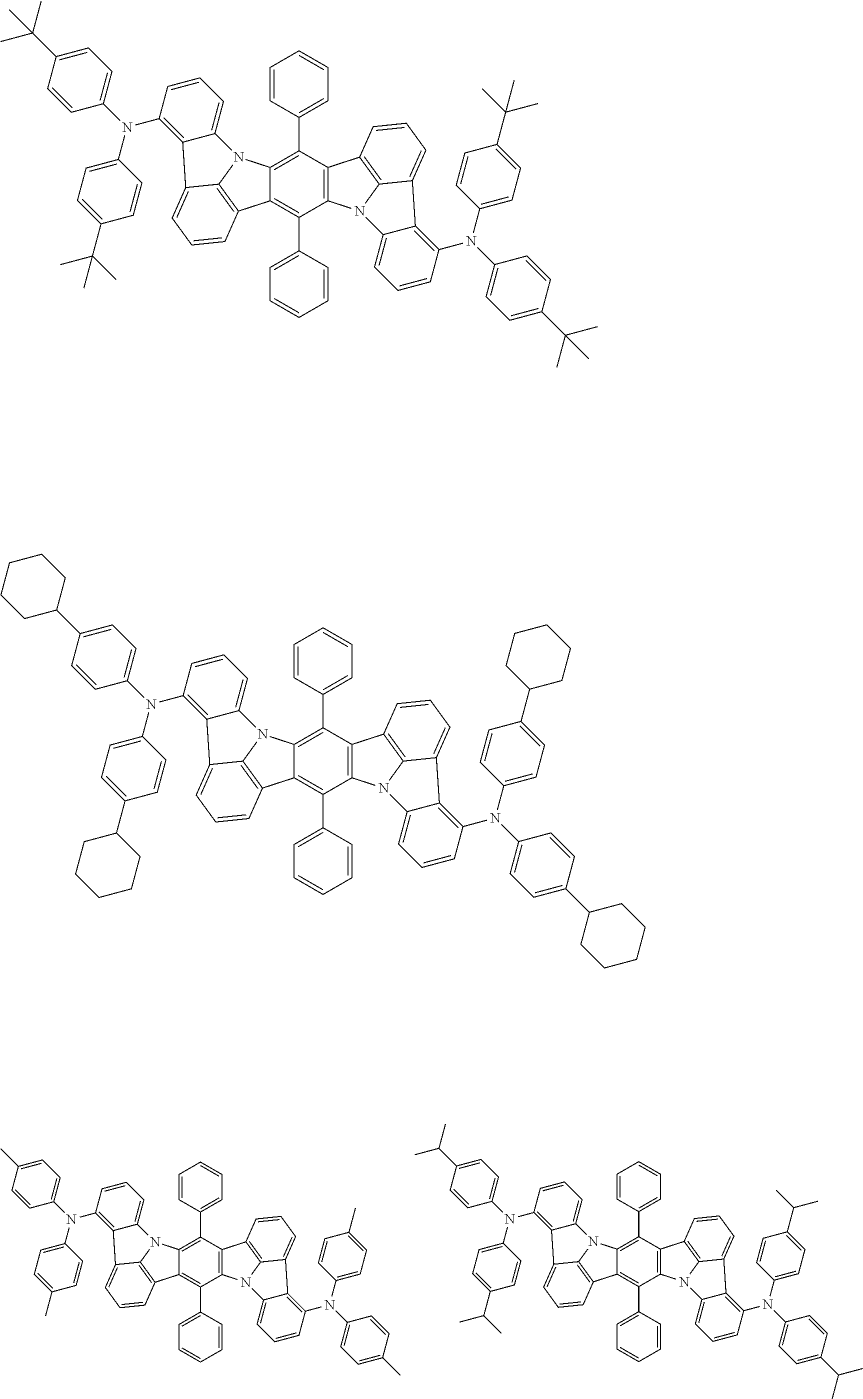

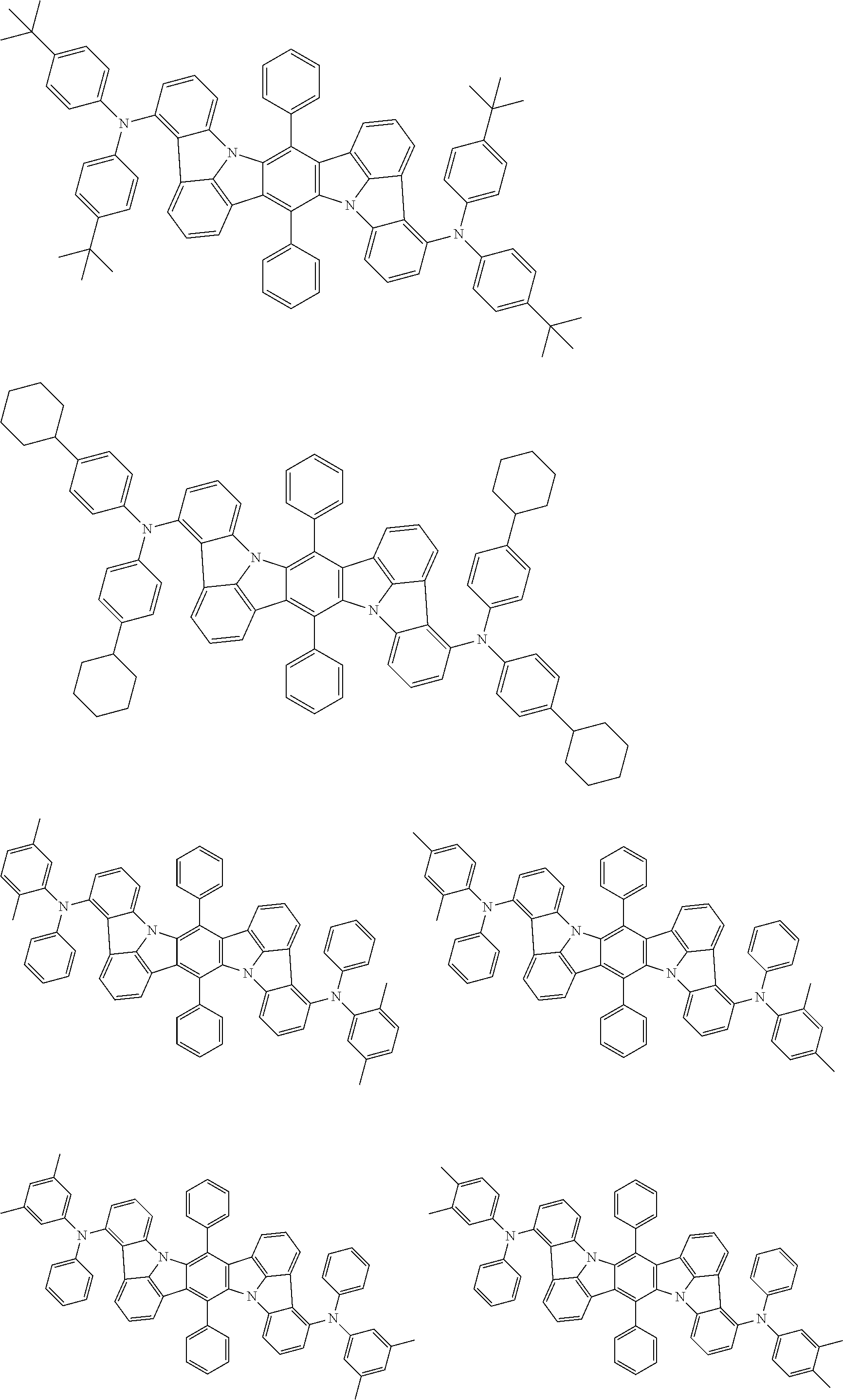

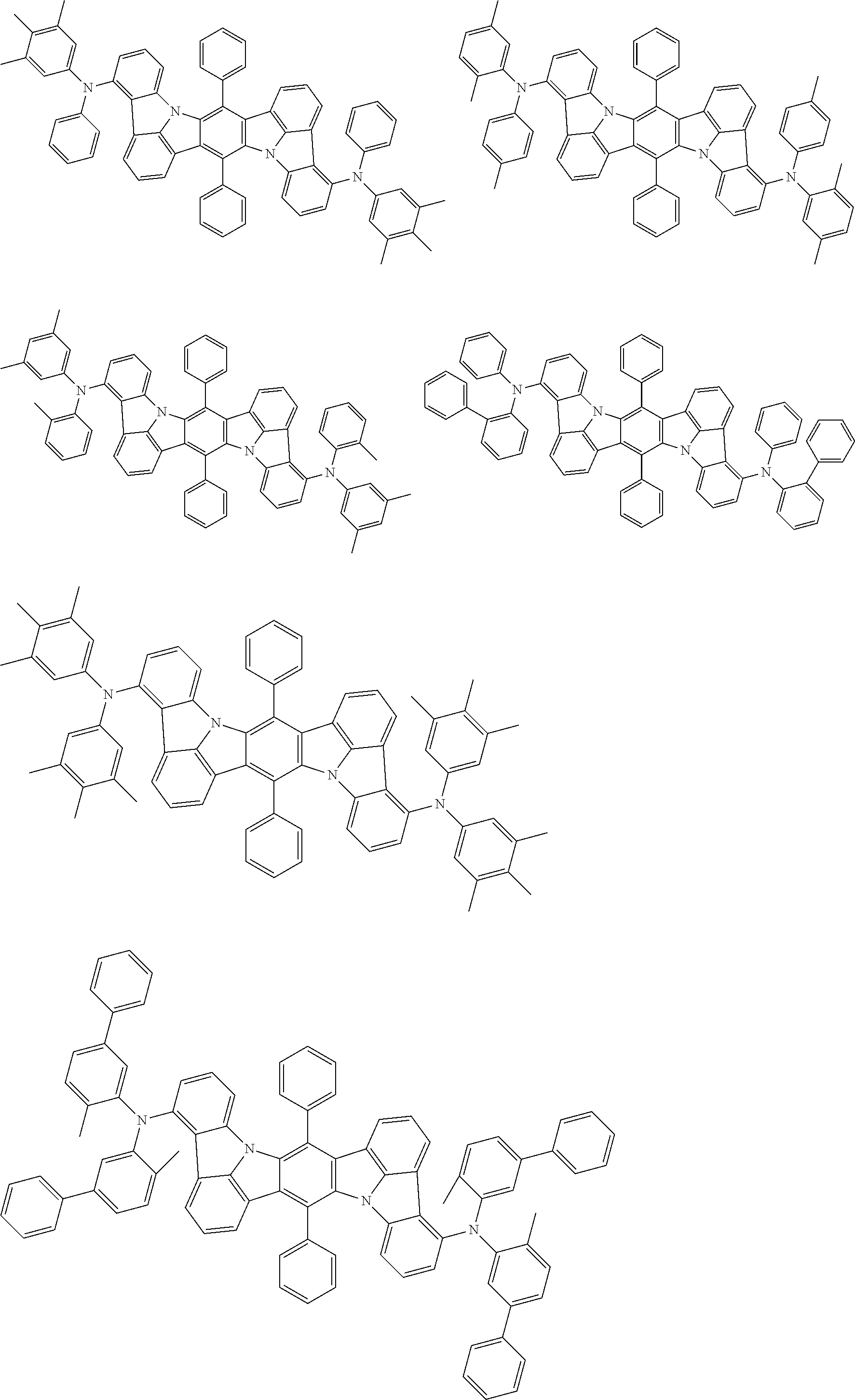

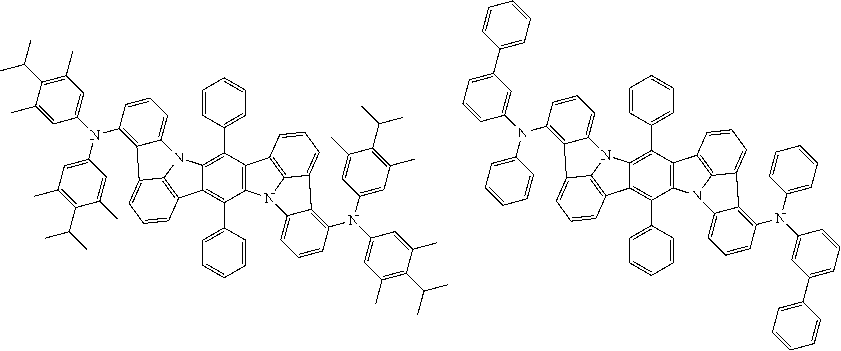 [SMILES: Cc1cc(N(c2cc(C)c(C(C)C)c(C)c2)c2cccc3c2c2cccc4c5c(-c6ccccc6)c6c(c(-c7ccccc7)c5n3c24)c2cccc3c4c(N(c5cc(C)c(C(C)C)c(C)c5)c5cc(C)c(C(C)C)c(C)c5)cccc4n6c32)cc(C)c1C(C)C ; c1ccc(-c2cccc(N(c3ccccc3)c3cccc4c3c3cccc5c6c(-c7ccccc7)c7c(c(-c8ccccc8)c6n4c35)c3cccc4c5c(N(c6ccccc6)c6cccc(-c8ccccc8)c6)cccc5n7c43)c2)cc1]

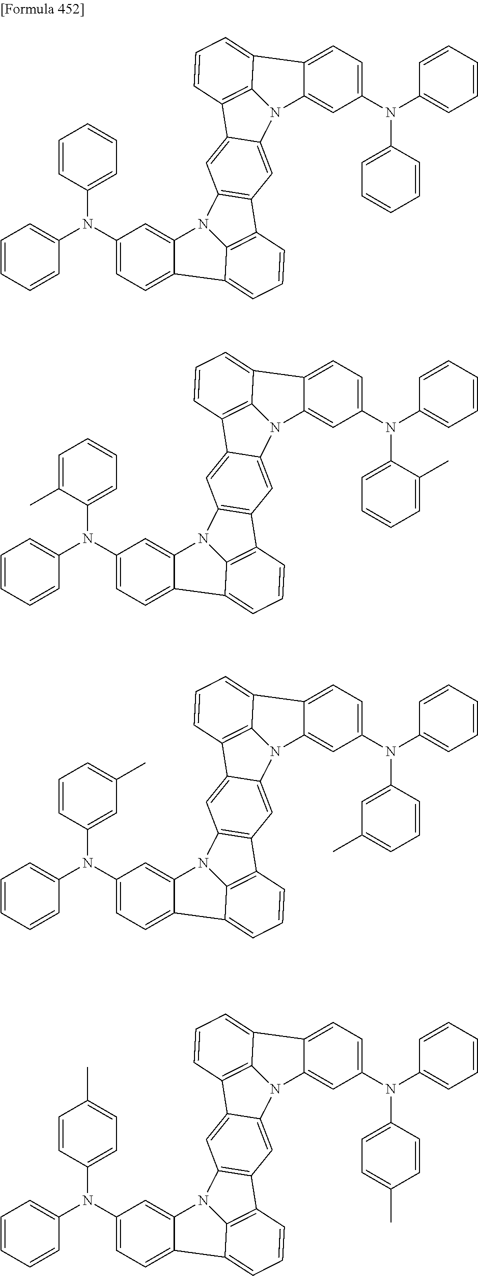 [SMILES: c1ccc(N(c2ccccc2)c2ccc3c4cccc5c6cc7c(cc6n(c3c2)c45)c2cccc3c4ccc(N(c5ccccc5)c5ccccc5)cc4n7c32)cc1 ; Cc1ccccc1N(c1ccccc1)c1ccc2c3cccc4c5cc6c(cc5n(c2c1)c34)c1cccc2c3ccc(N(c4ccccc4)c4ccccc4C)cc3n6c21 ; Cc1cccc(N(c2ccccc2)c2ccc3c4cccc5c6cc7c(cc6n(c3c2)c45)c2cccc3c4ccc(N(c5ccccc5)c5cccc(C)c5)cc4n7c32)c1 ; Cc1ccc(N(c2ccccc2)c2ccc3c4cccc5c6cc7c(cc6n(c3c2)c45)c2cccc3c4ccc(N(c5ccccc5)c5ccc(C)cc5)cc4n7c32)cc1]

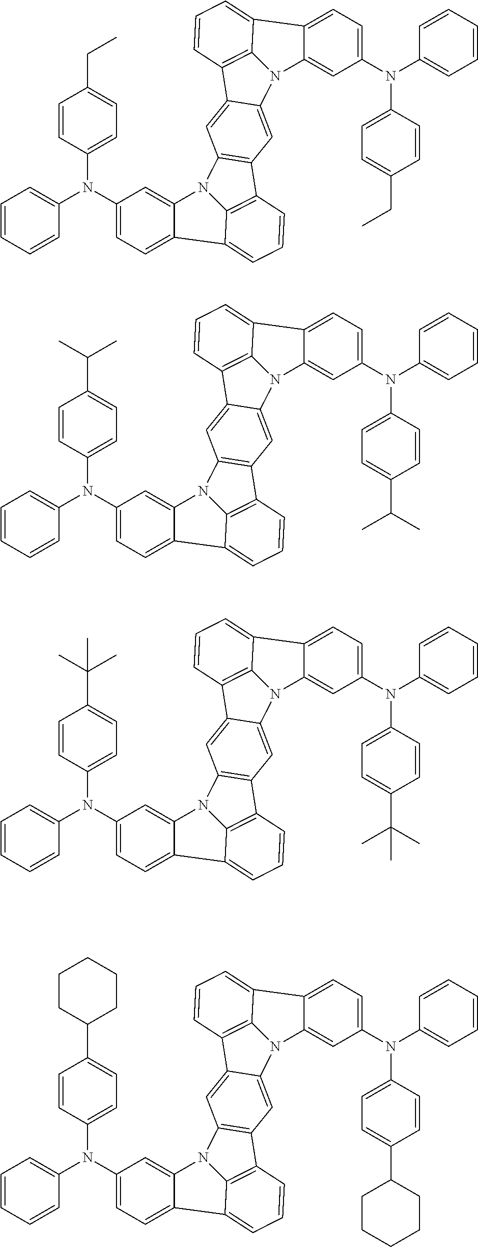 [SMILES: CCc1ccc(N(c2ccccc2)c2ccc3c4cccc5c6cc7c(cc6n(c3c2)c45)c2cccc3c4ccc(N(c5ccccc5)c5ccc(CC)cc5)cc4n7c32)cc1 ; CC(C)c1ccc(N(c2ccccc2)c2ccc3c4cccc5c6cc7c(cc6n(c3c2)c45)c2cccc3c4ccc(N(c5ccccc5)c5ccc(C(C)C)cc5)cc4n7c32)cc1 ; CC(C)(C)c1ccc(N(c2ccccc2)c2ccc3c4cccc5c6cc7c(cc6n(c3c2)c45)c2cccc3c4ccc(N(c5ccccc5)c5ccc(C(C)(C)C)cc5)cc4n7c32)cc1 ; c1ccc(N(c2ccc(C3CCCCC3)cc2)c2ccc3c4cccc5c6cc7c(cc6n(c3c2)c45)c2cccc3c4ccc(N(c5ccccc5)c5ccc(C6CCCCC6)cc5)cc4n7c32)cc1]

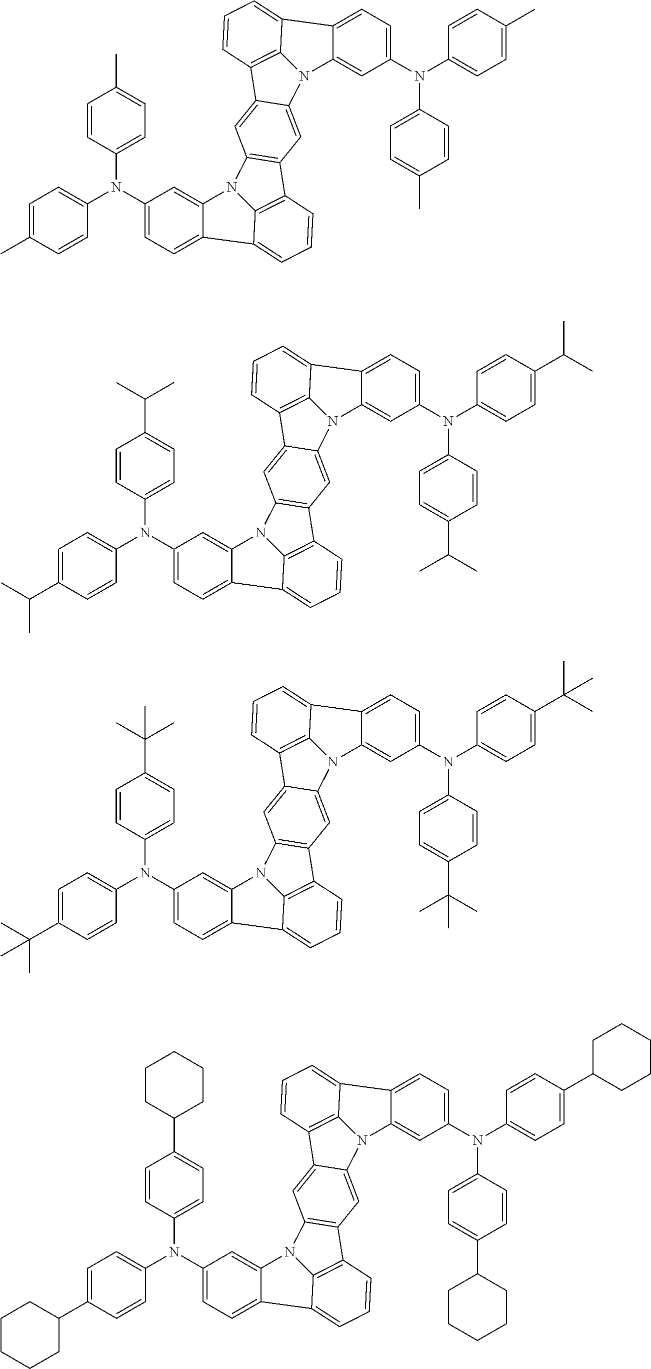

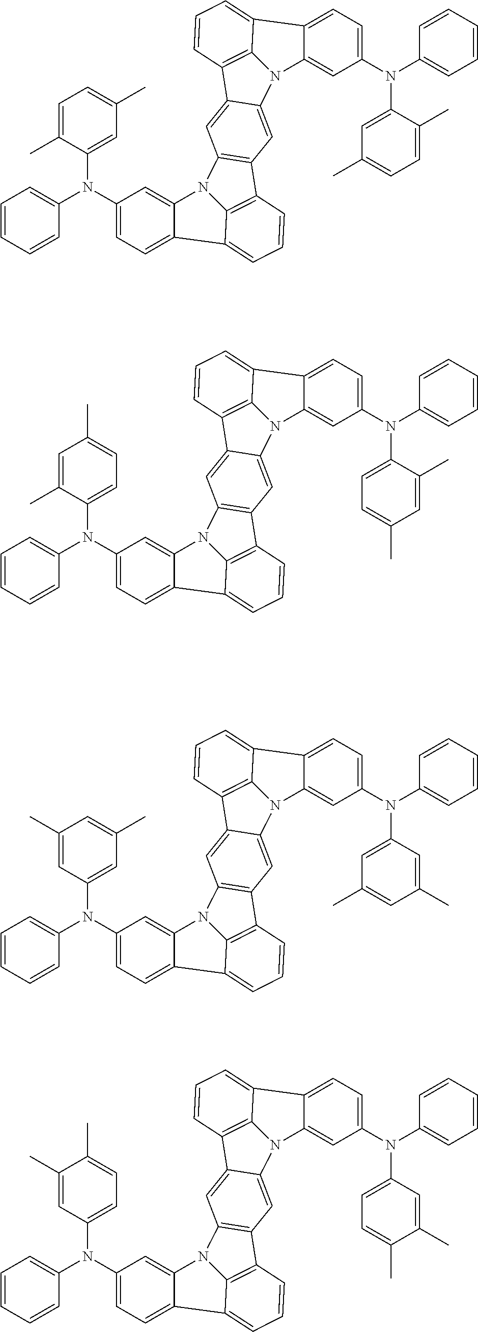 [SMILES: Cc1ccc(C)c(N(c2ccccc2)c2ccc3c4cccc5c6cc7c(cc6n(c3c2)c45)c2cccc3c4ccc(N(c5ccccc5)c5cc(C)ccc5C)cc4n7c32)c1 ; Cc1ccc(N(c2ccccc2)c2ccc3c4cccc5c6cc7c(cc6n(c3c2)c45)c2cccc3c4ccc(N(c5ccccc5)c5ccc(C)cc5C)cc4n7c32)c(C)c1 ; Cc1cc(C)cc(N(c2ccccc2)c2ccc3c4cccc5c6cc7c(cc6n(c3c2)c45)c2cccc3c4ccc(N(c5ccccc5)c5cc(C)cc(C)c5)cc4n7c32)c1 ; Cc1ccc(N(c2ccccc2)c2ccc3c4cccc5c6cc7c(cc6n(c3c2)c45)c2cccc3c4ccc(N(c5ccccc5)c5ccc(C)c(C)c5)cc4n7c32)cc1C]

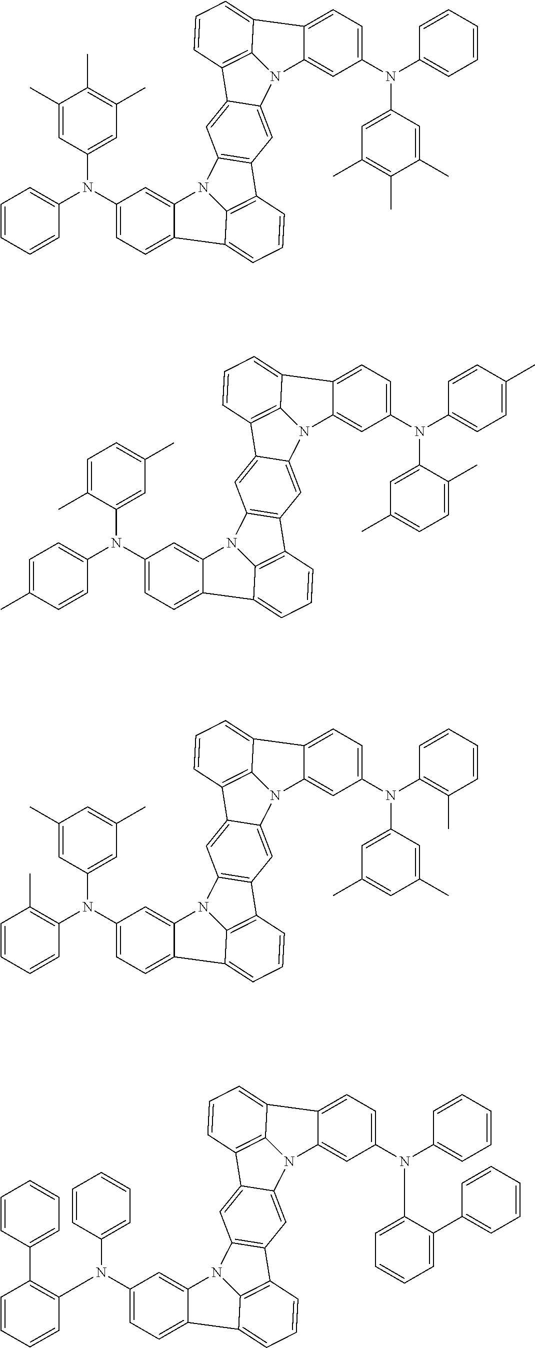

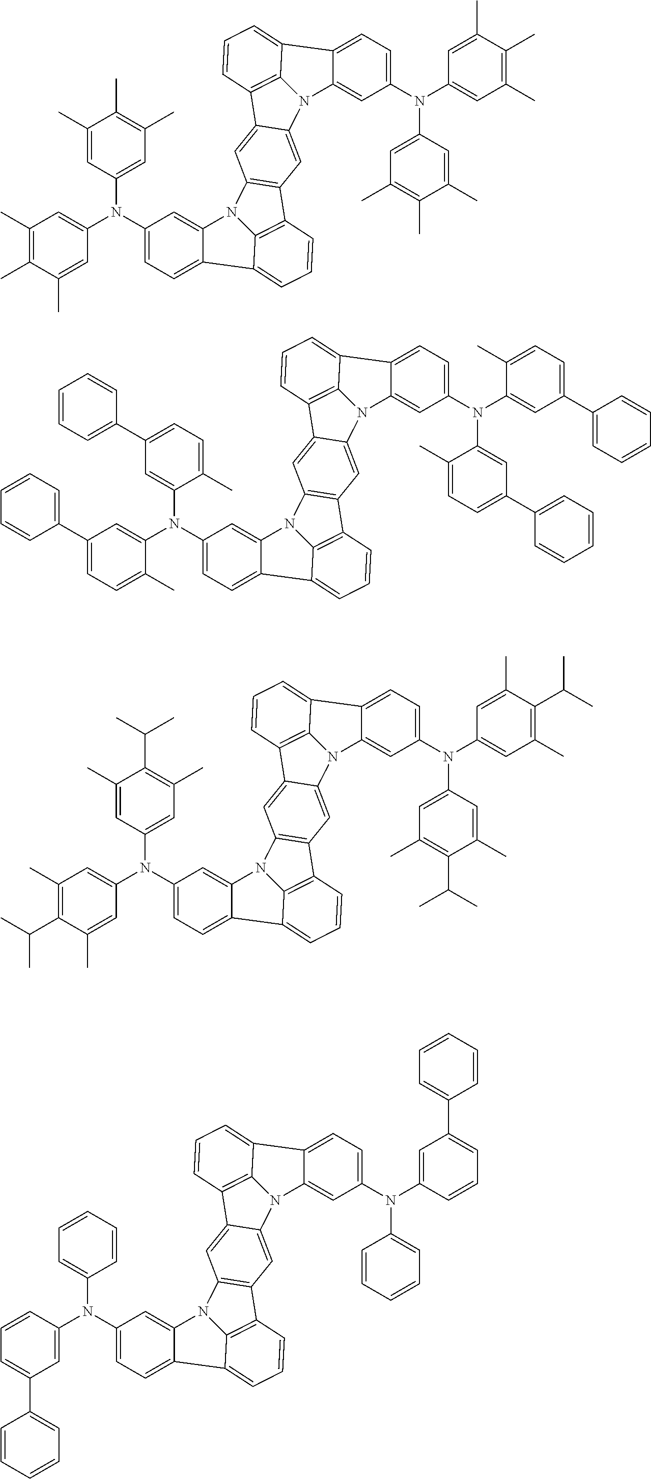

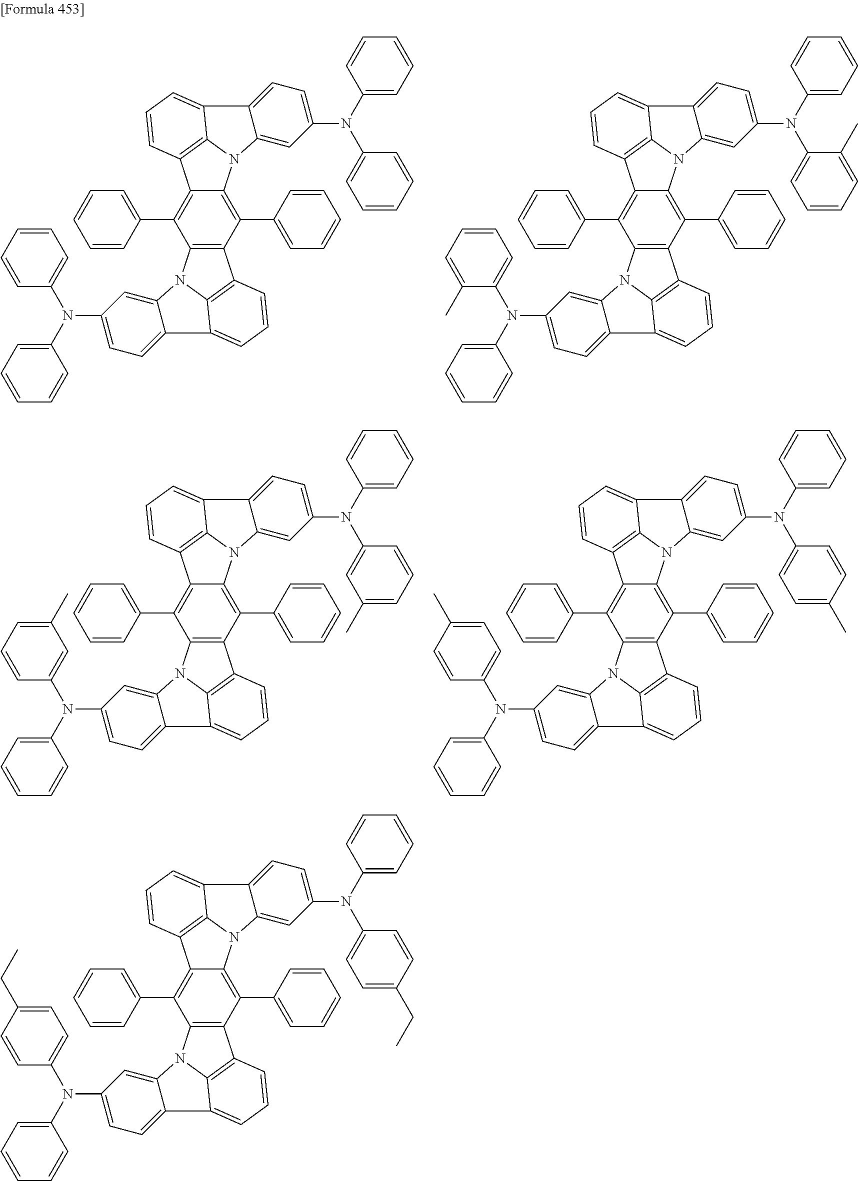

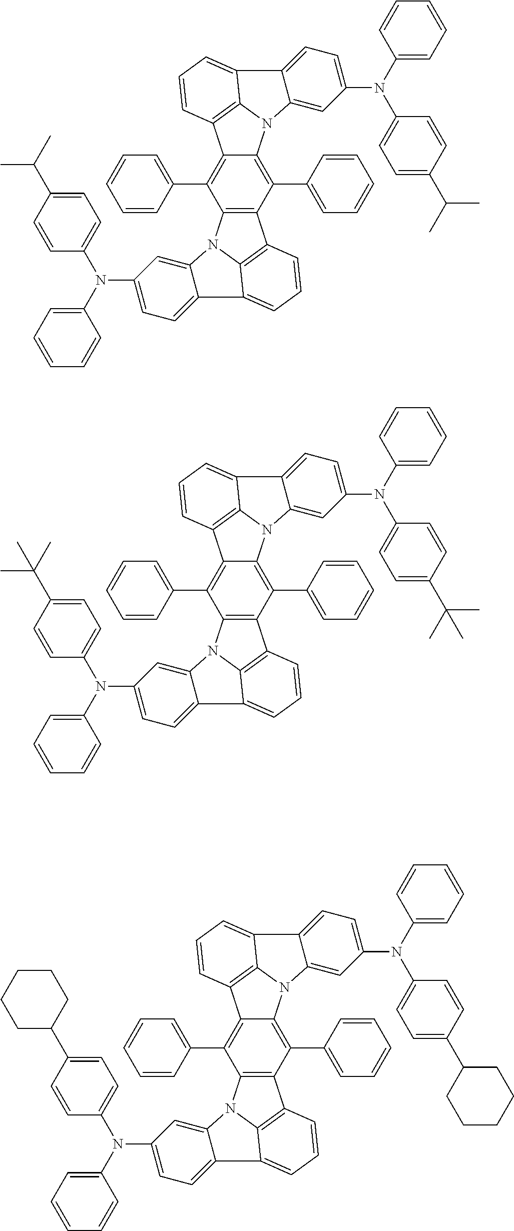

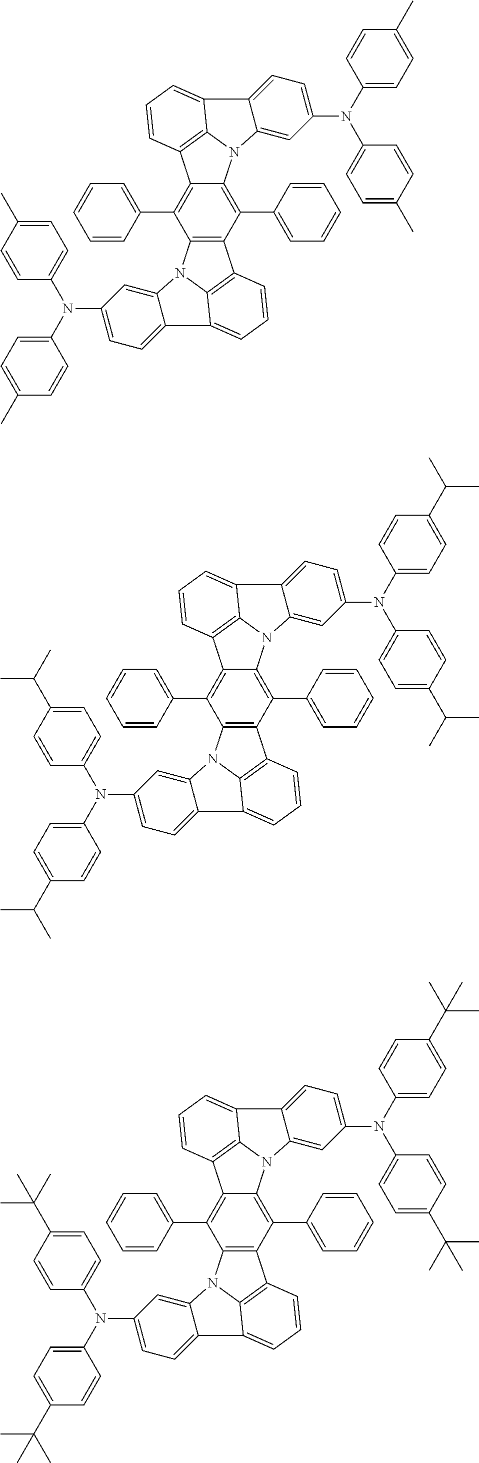

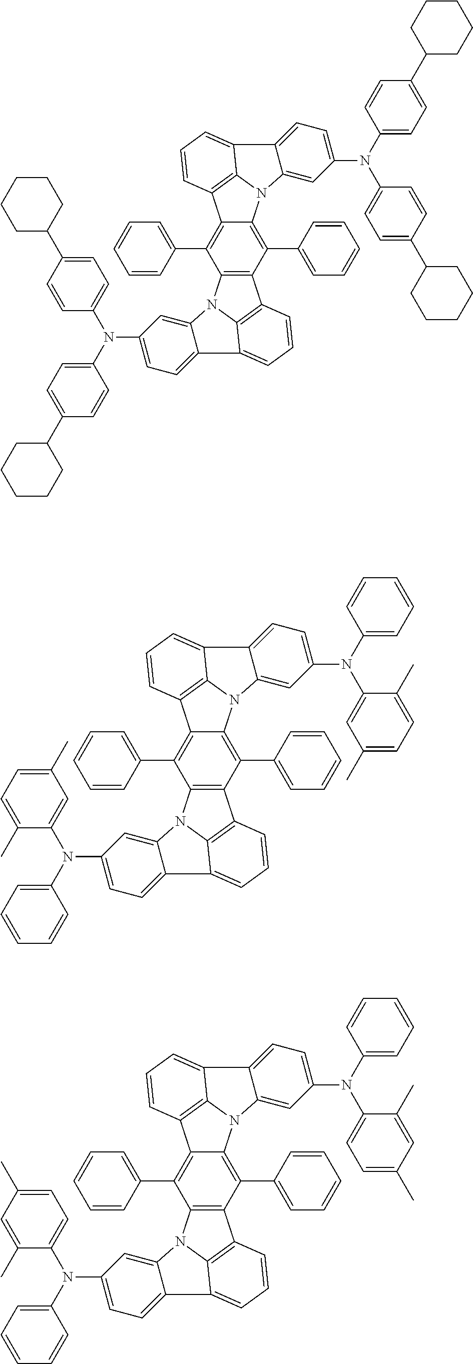 [SMILES: c1ccc(-c2c3c4cccc5c6ccc(N(c7ccc(C8CCCCC8)cc7)c7ccc(C8CCCCC8)cc7)cc6n(c3c(-c3ccccc3)c3c6cccc7c8ccc(N(c9ccc(C%10CCCCC%10)cc9)c9ccc(C%10CCCCC%10)cc9)cc8n(c23)c76)c54)cc1 ; Cc1ccc(C)c(N(c2ccccc2)c2ccc3c4cccc5c6c(-c7ccccc7)c7c(c(-c8ccccc8)c6n(c3c2)c45)c2cccc3c4ccc(N(c5ccccc5)c5cc(C)ccc5C)cc4n7c32)c1 ; Cc1ccc(N(c2ccccc2)c2ccc3c4cccc5c6c(-c7ccccc7)c7c(c(-c8ccccc8)c6n(c3c2)c45)c2cccc3c4ccc(N(c5ccccc5)c5ccc(C)cc5C)cc4n7c32)c(C)c1]

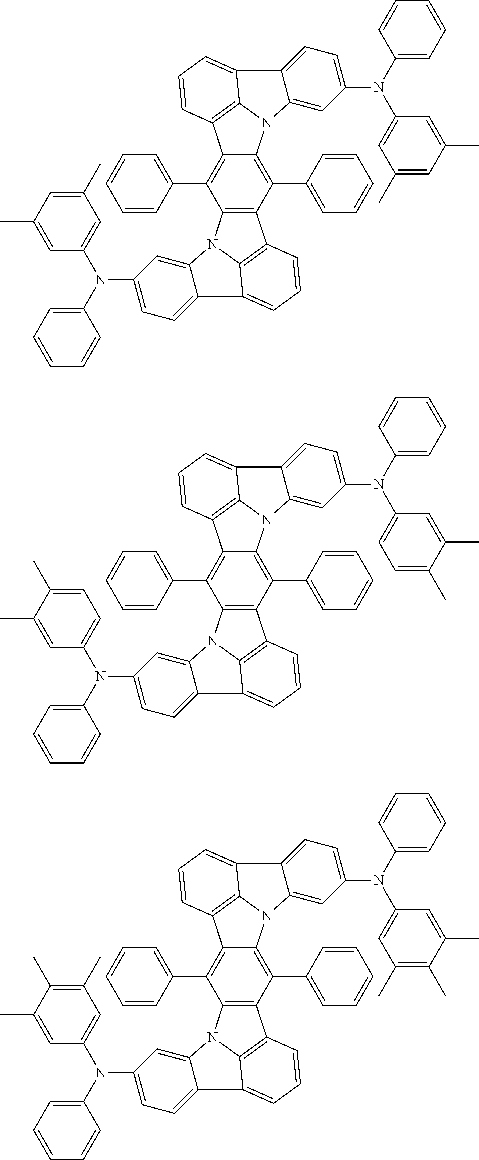

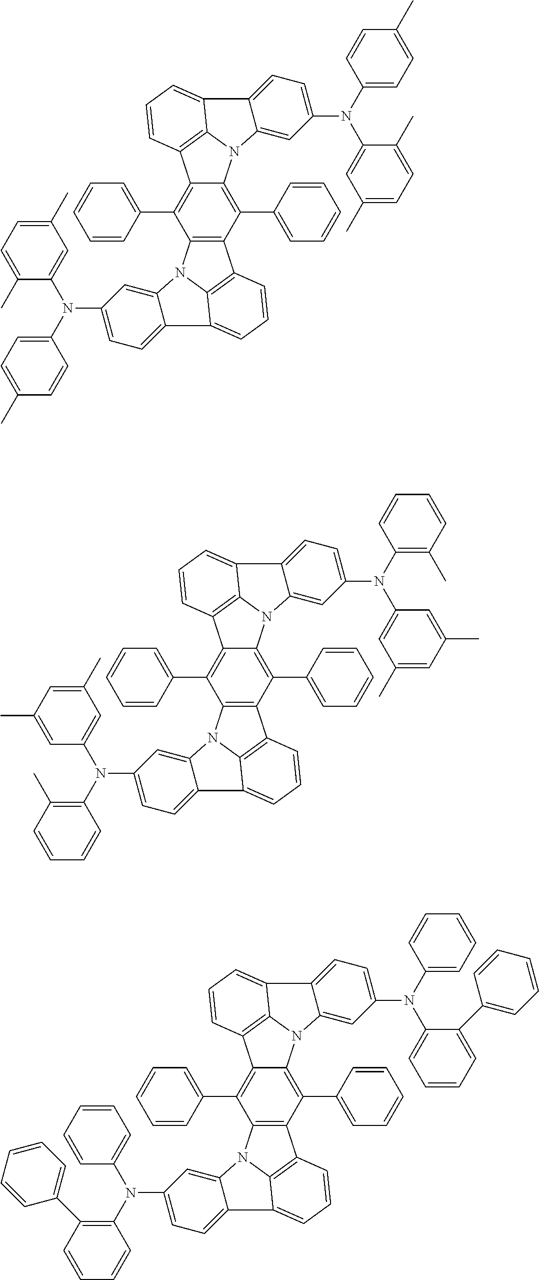

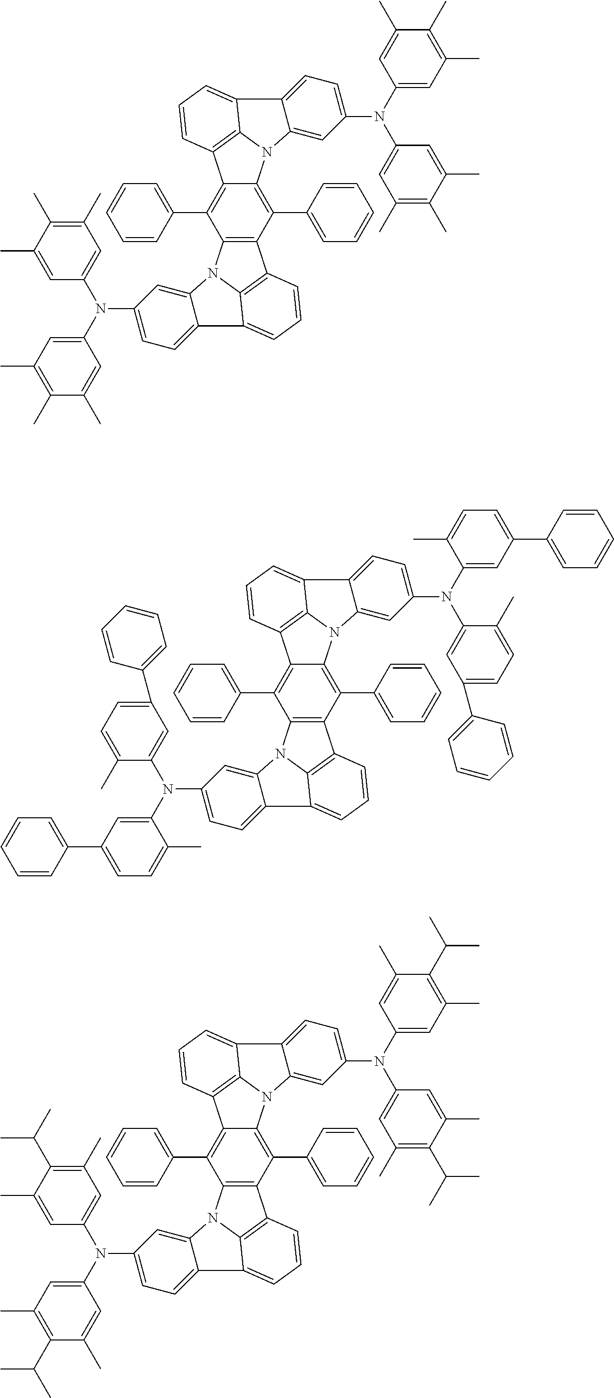

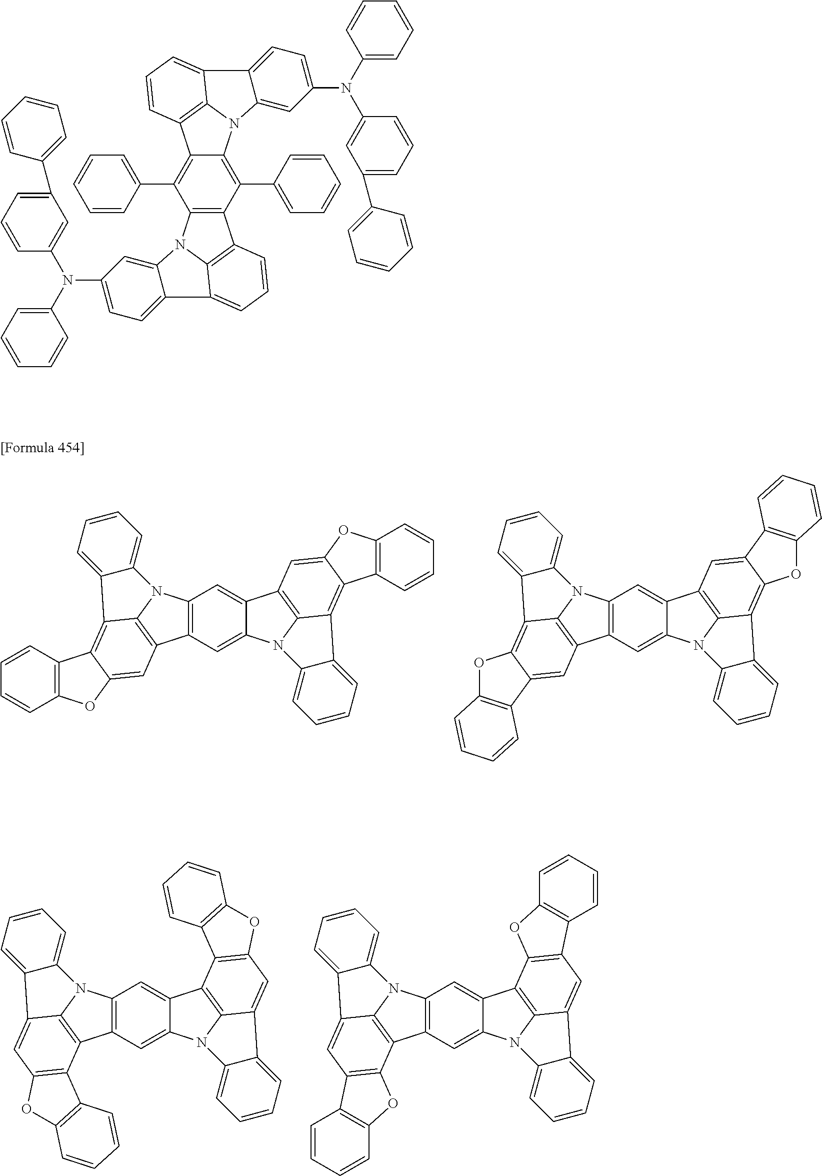

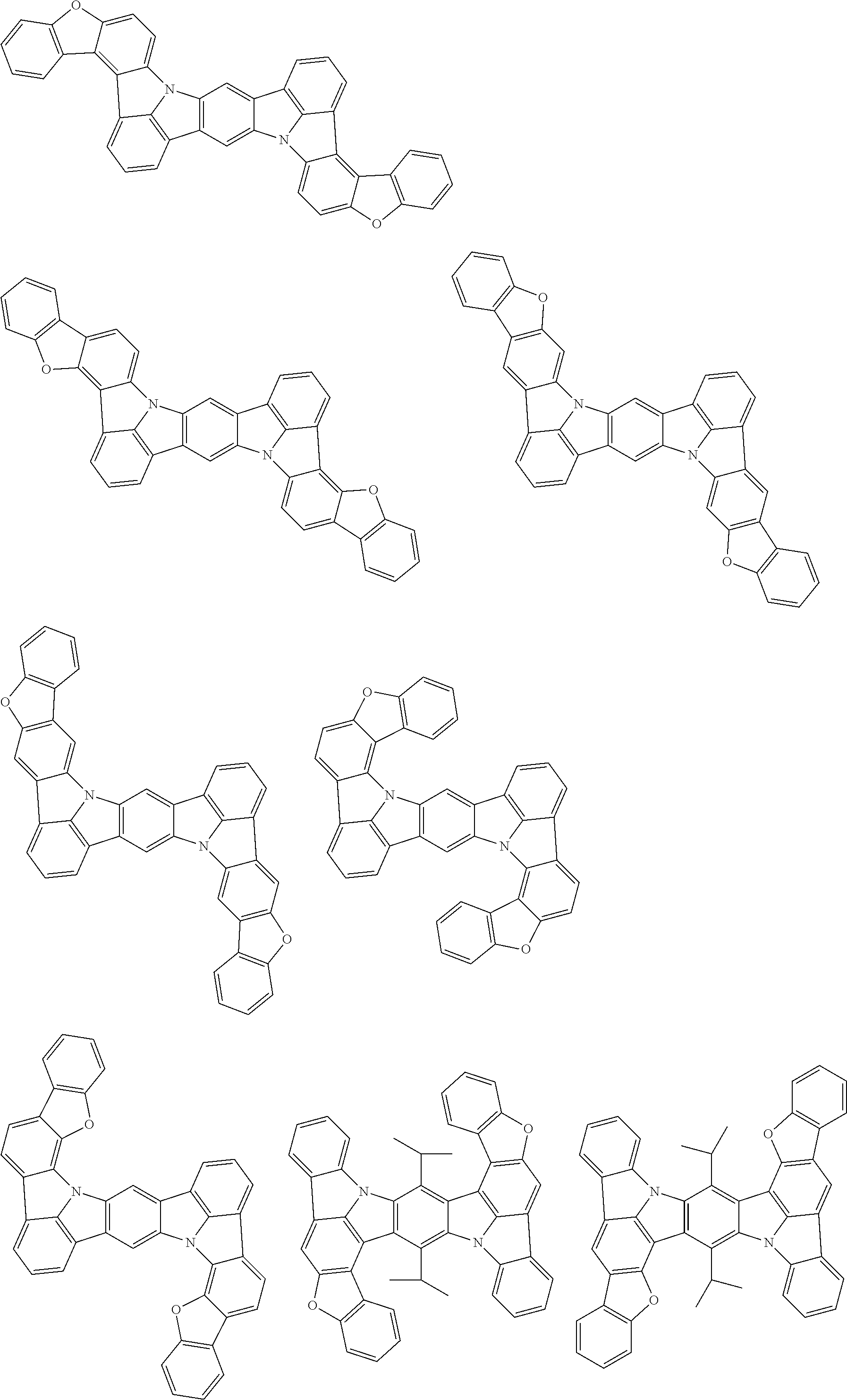

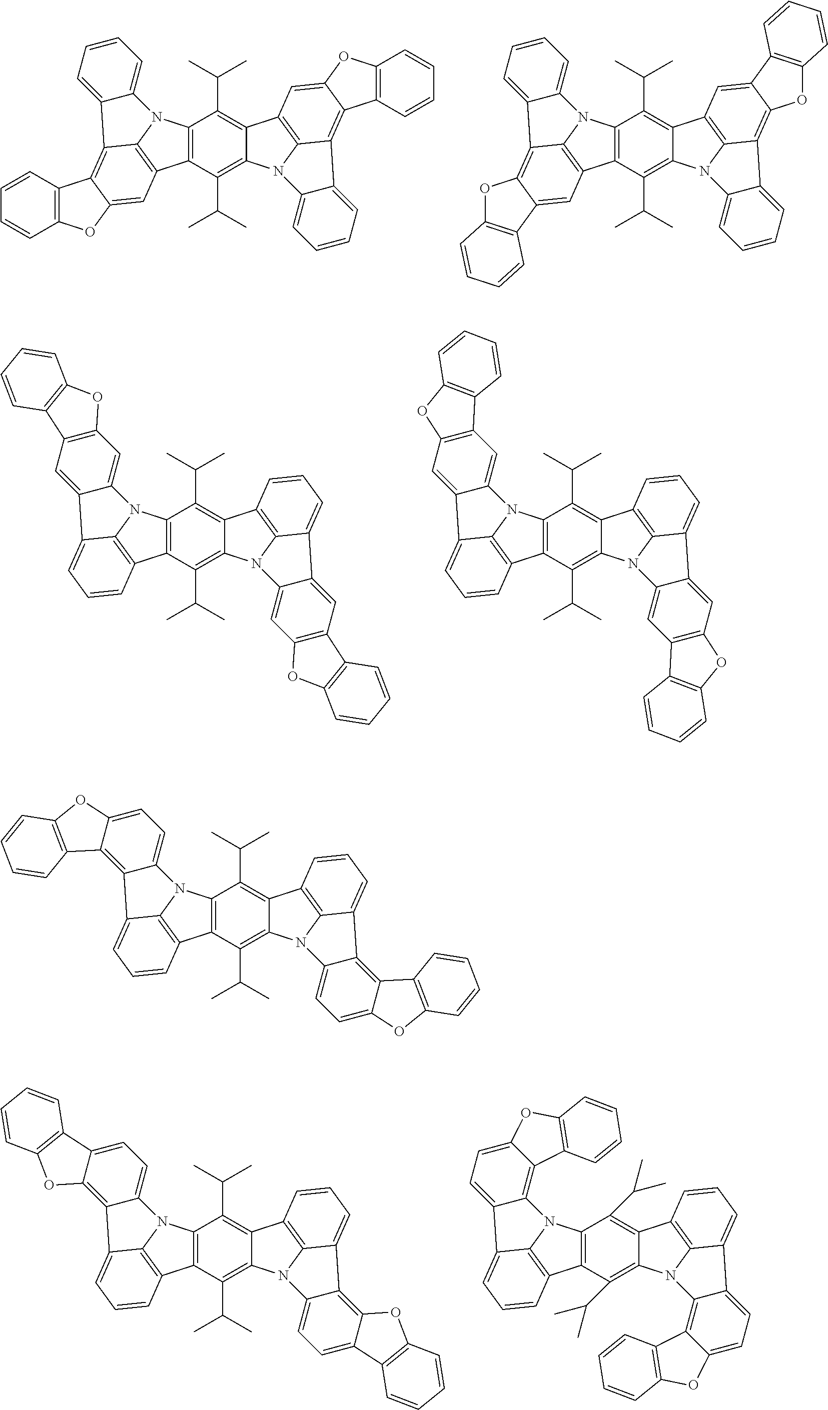

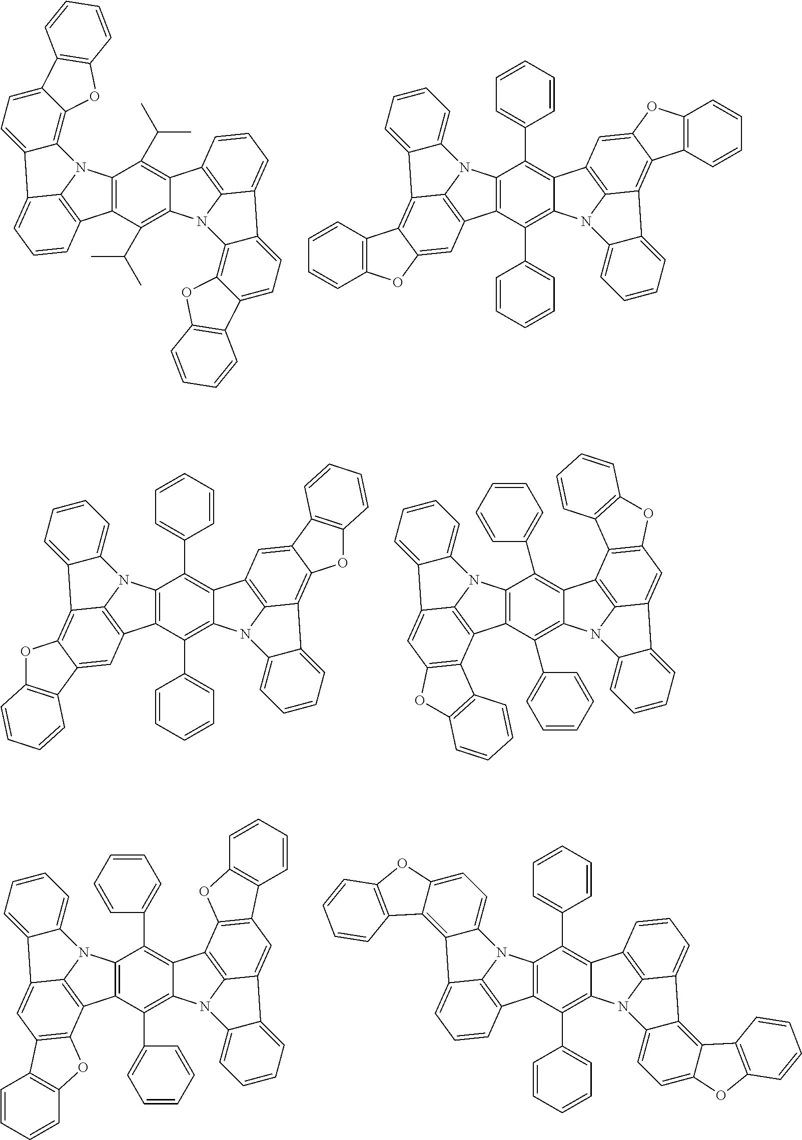

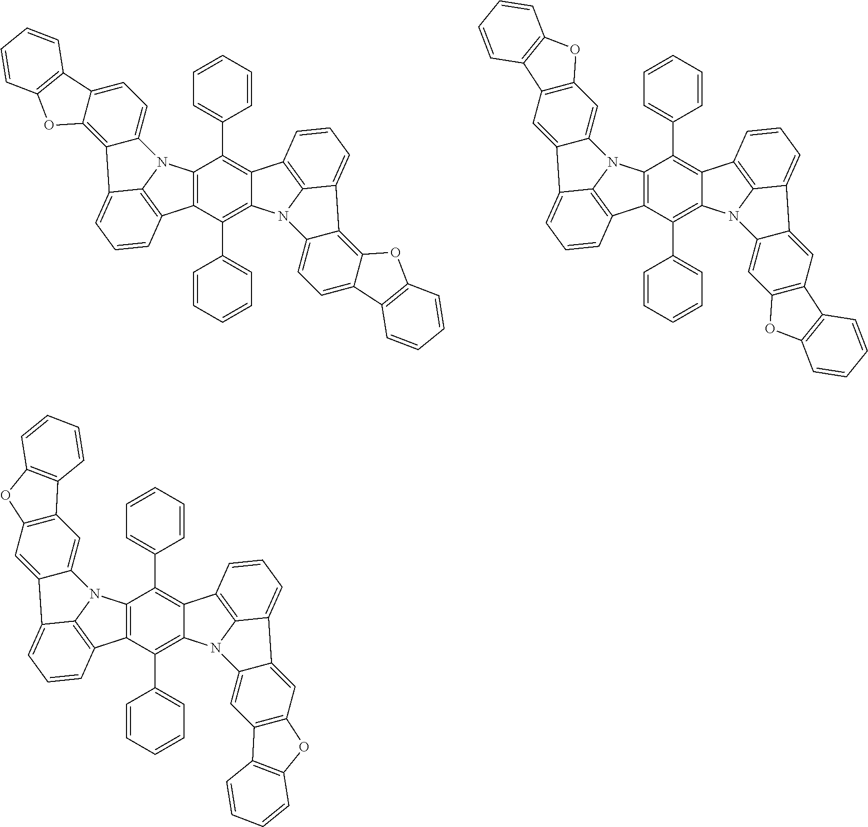 [SMILES: c1ccc(-c2c3c4cccc5c6c7oc8ccccc8c7ccc6n(c3c(-c3ccccc3)c3c6cccc7c8c9oc%10ccccc%10c9ccc8n(c23)c67)c45)cc1 ; c1ccc(-c2c3c4cccc5c6cc7c(cc6n(c3c(-c3ccccc3)c3c6cccc8c9cc%10c(cc9n(c23)c86)oc2ccccc2%10)c54)oc2ccccc27)cc1 ; c1ccc(-c2c3c4cccc5c6cc7oc8ccccc8c7cc6n(c3c(-c3ccccc3)c3c6cccc7c8cc9oc%10ccccc%10c9cc8n(c23)c76)c54)cc1]

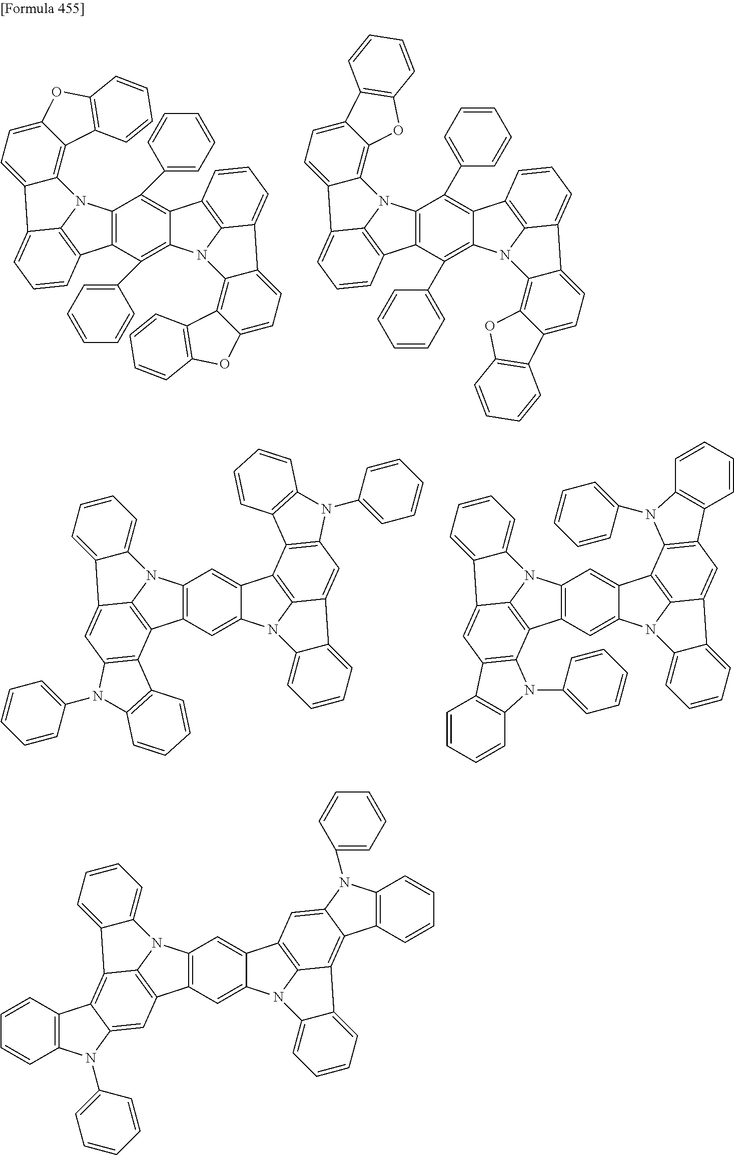

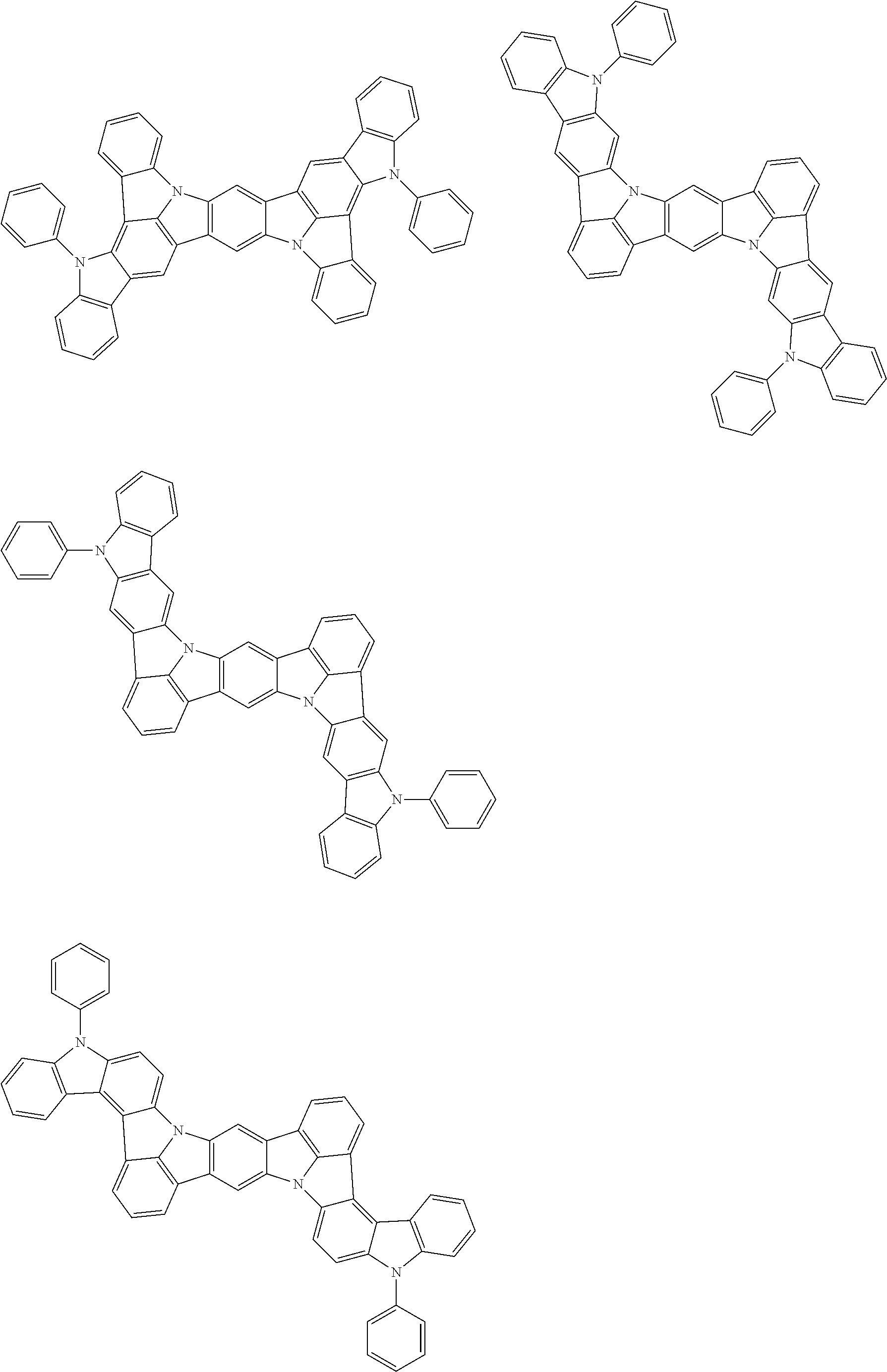 [SMILES: c1ccc(-n2c3ccccc3c3cc4c5cc6c(cc5n5c7ccccc7c(c32)c45)c2cc3c4ccccc4n(-c4ccccc4)c3c3c4ccccc4n6c23)cc1 ; c1ccc(-n2c3ccccc3c3cc4c5cccc6c7cc8c(cc7n(c4cc32)c65)c2cccc3c4cc5c6ccccc6n(-c6ccccc6)c5cc4n8c23)cc1 ; c1ccc(-n2c3ccccc3c3cc4c(cc32)c2cccc3c5cc6c(cc5n4c23)c2cccc3c4cc5c(cc4n6c32)c2ccccc2n5-c2ccccc2)cc1 ; c1ccc(-n2c3ccccc3c3c4c5cccc6c7cc8c(cc7n(c4ccc32)c65)c2cccc3c4c5c6ccccc6n(-c6ccccc6)c5ccc4n8c23)cc1]

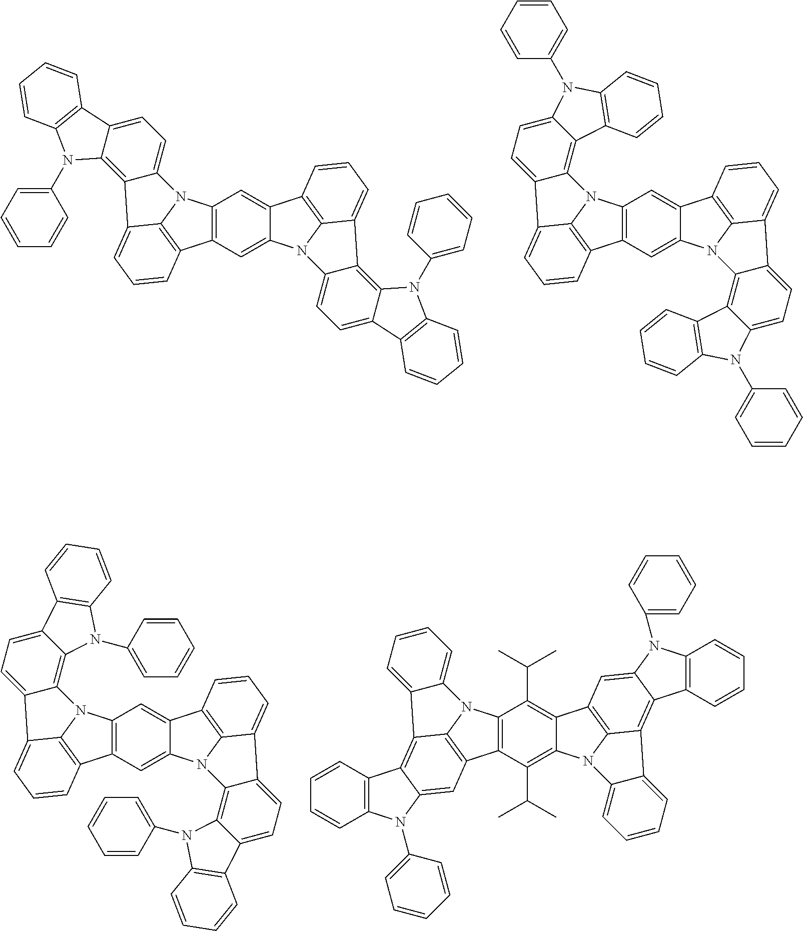

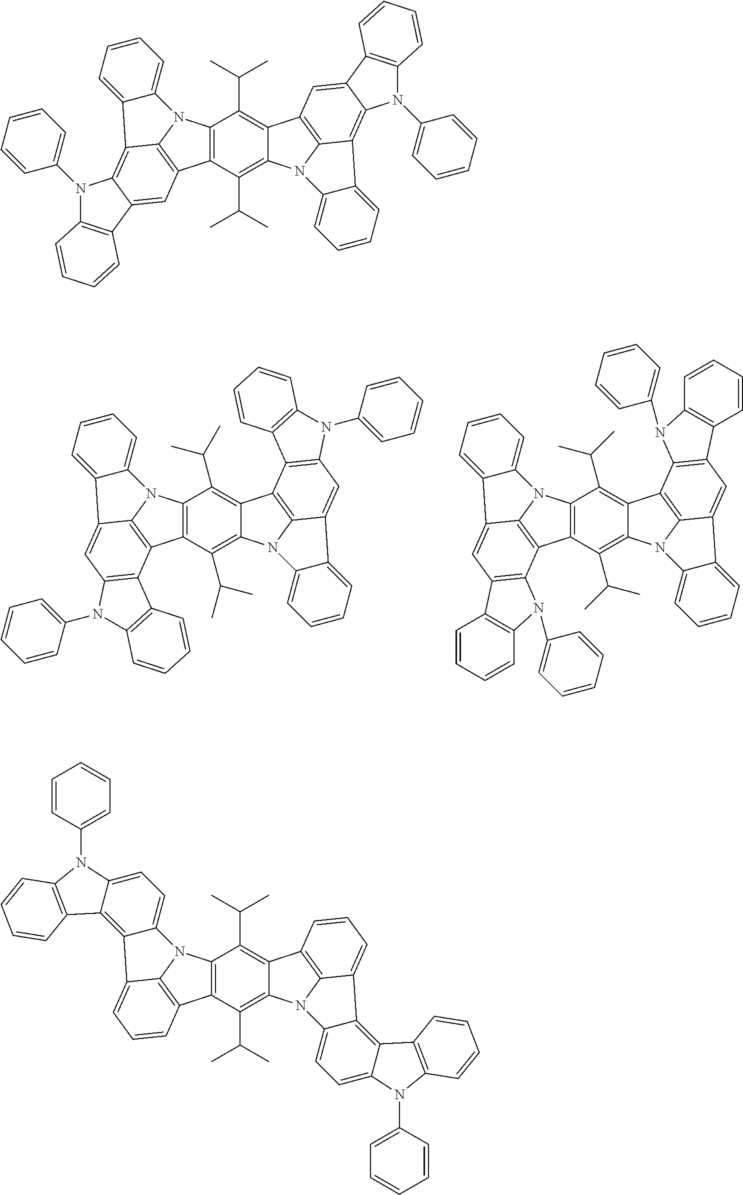 [SMILES: CC(C)c1c2c3cc4c5ccccc5n(-c5ccccc5)c4c4c5ccccc5n(c2c(C(C)C)c2c5cc6c7ccccc7n(-c7ccccc7)c6c6c7ccccc7n(c12)c56)c34 ; CC(C)c1c2c3c4c5ccccc5n(-c5ccccc5)c4cc4c5ccccc5n(c2c(C(C)C)c2c5c6c7ccccc7n(-c7ccccc7)c6cc6c7ccccc7n(c12)c65)c43 ; CC(C)c1c2c3c4c(cc5c6ccccc6n(c2c(C(C)C)c2c6c7c(cc8c9ccccc9n(c12)c86)c1ccccc1n7-c1ccccc1)c53)c1ccccc1n4-c1ccccc1 ; CC(C)c1c2c3cccc4c5c6c7ccccc7n(-c7ccccc7)c6ccc5n(c2c(C(C)C)c2c5cccc6c7c8c9ccccc9n(-c9ccccc9)c8ccc7n(c12)c56)c34]

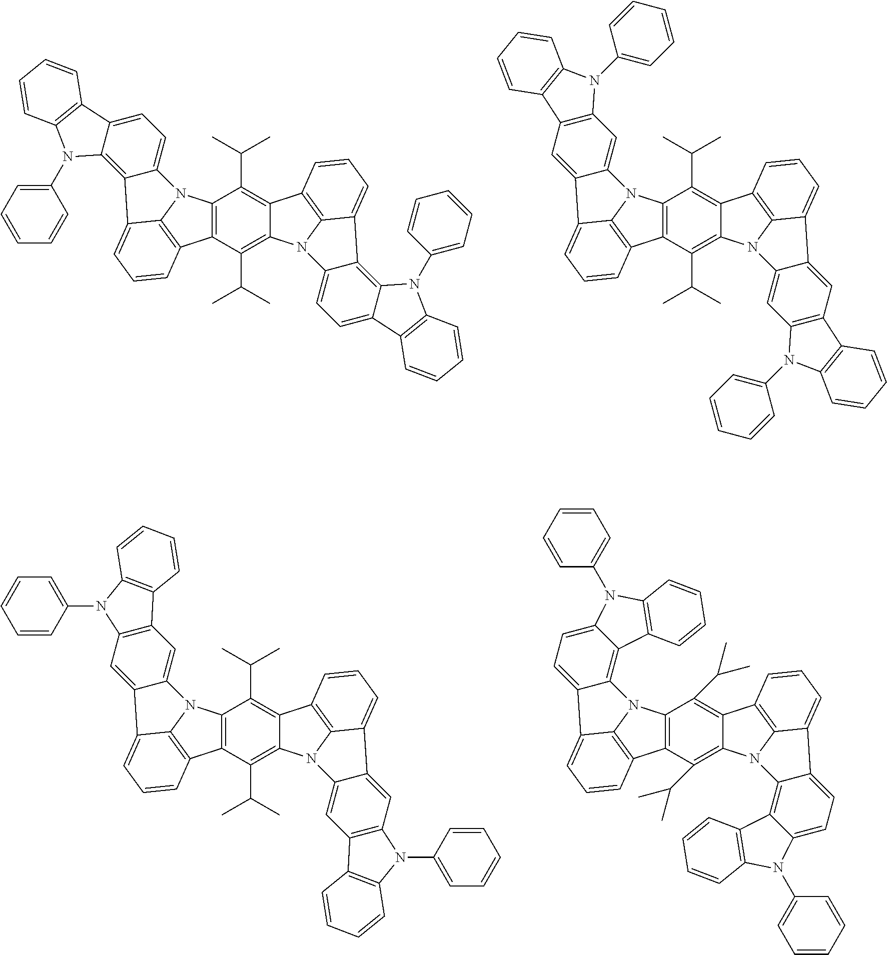 [SMILES: CC(C)c1c2c3cccc4c5c6c(ccc5n(c2c(C(C)C)c2c5cccc7c8c9c(ccc8n(c12)c57)c1ccccc1n9-c1ccccc1)c34)c1ccccc1n6-c1ccccc1 ; CC(C)c1c2c3cccc4c5cc6c7ccccc7n(-c7ccccc7)c6cc5n(c2c(C(C)C)c2c5cccc6c7cc8c9ccccc9n(-c9ccccc9)c8cc7n(c12)c65)c43 ; CC(C)c1c2c3cccc4c5cc6c(cc5n(c2c(C(C)C)c2c5cccc7c8cc9c(cc8n(c12)c75)c1ccccc1n9-c1ccccc1)c43)c1ccccc1n6-c1ccccc1 ; CC(C)c1c2c3cccc4c5ccc6c(c7ccccc7n6-c6ccccc6)c5n(c2c(C(C)C)c2c5cccc6c7ccc8c(c9ccccc9n8-c8ccccc8)c7n(c12)c65)c43]

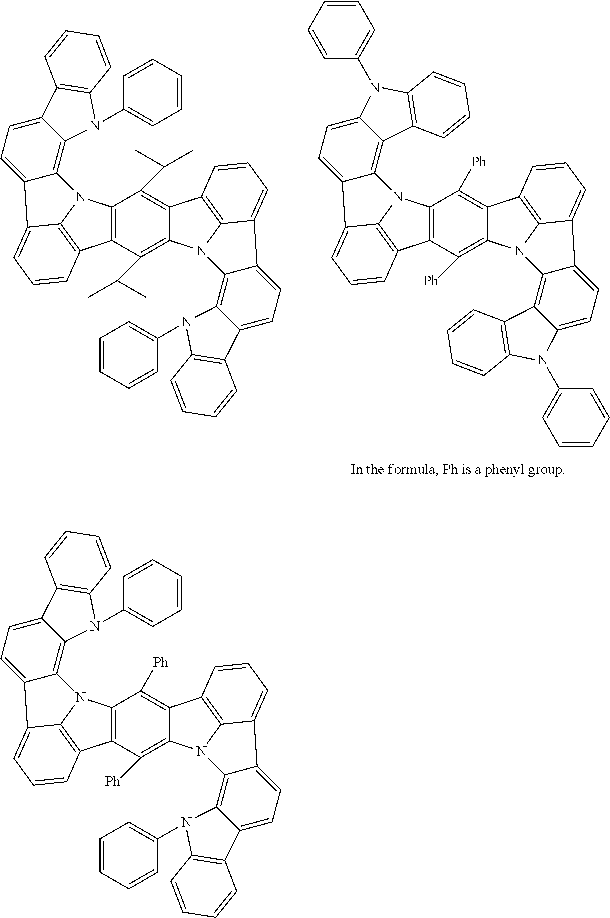 [SMILES: CC(C)c1c2c3cccc4c5ccc6c7ccccc7n(-c7ccccc7)c6c5n(c2c(C(C)C)c2c5cccc6c7ccc8c9ccccc9n(-c9ccccc9)c8c7n(c12)c65)c43 ; c1ccc(-c2c3c4cccc5c6ccc7c(c8ccccc8n7-c7ccccc7)c6n(c3c(-c3ccccc3)c3c6cccc7c8ccc9c(c%10ccccc%10n9-c9ccccc9)c8n(c23)c76)c54)cc1 ; c1ccc(-c2c3c4cccc5c6ccc7c8ccccc8n(-c8ccccc8)c7c6n(c3c(-c3ccccc3)c3c6cccc7c8ccc9c%10ccccc%10n(-c%10ccccc%10)c9c8n(c23)c76)c54)cc1]

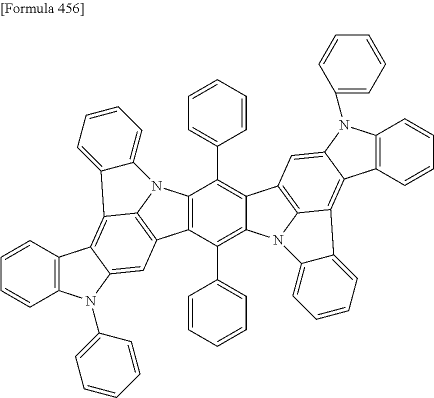 [SMILES: c1ccc(-c2c3c4cc5c(c6ccccc6n5-c5ccccc5)c5c6ccccc6n(c3c(-c3ccccc3)c3c6cc7c(c8ccccc8n7-c7ccccc7)c7c8ccccc8n(c23)c67)c45)cc1]

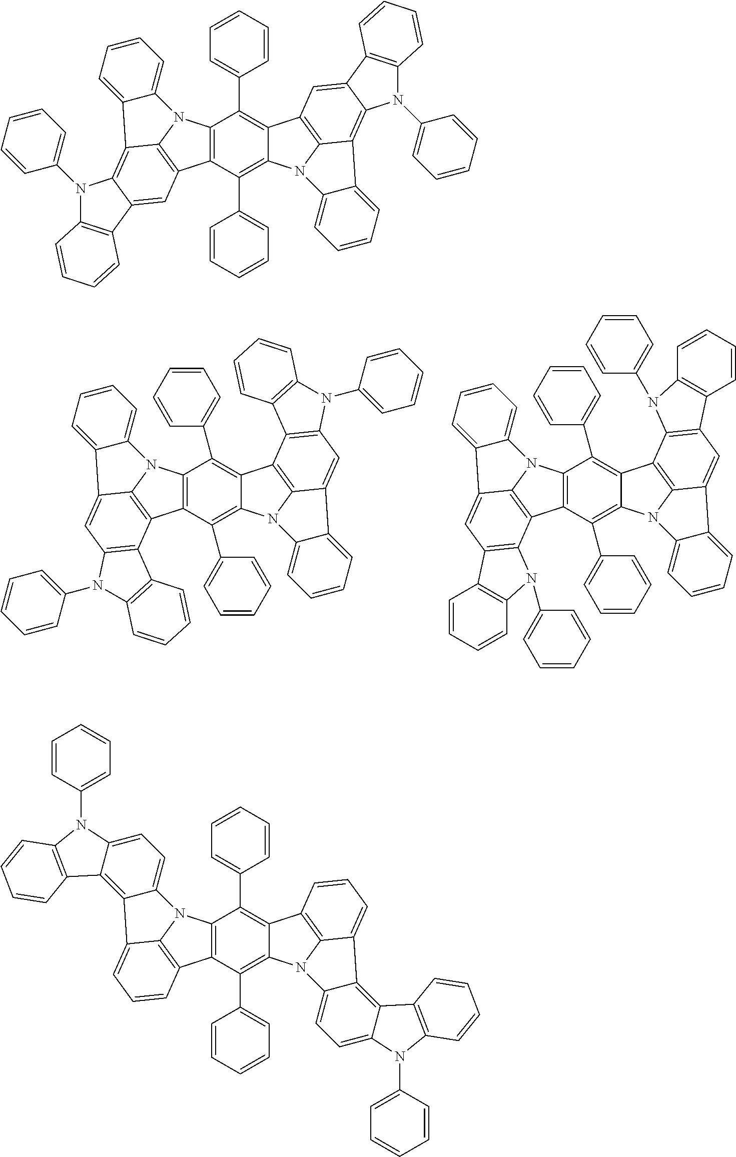

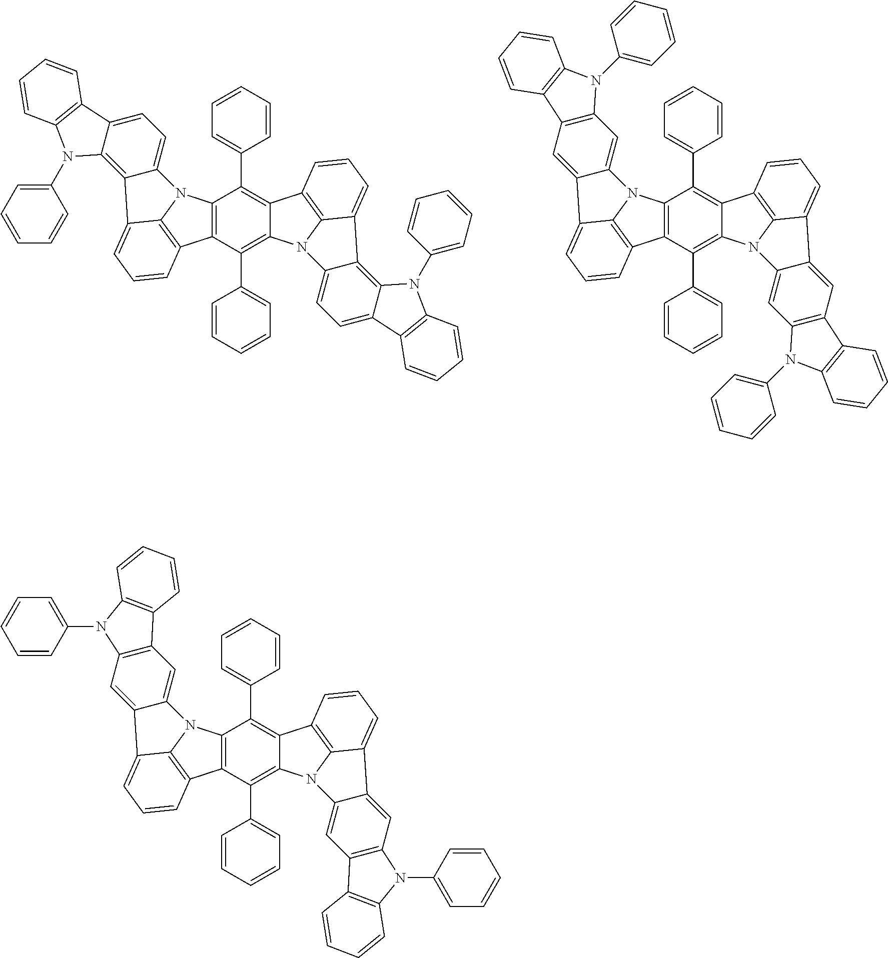 [SMILES: c1ccc(-c2c3c4cccc5c6c7c(ccc6n(c3c(-c3ccccc3)c3c6cccc8c9c%10c(ccc9n(c23)c68)c2ccccc2n%10-c2ccccc2)c45)c2ccccc2n7-c2ccccc2)cc1 ; c1ccc(-c2c3c4cccc5c6cc7c8ccccc8n(-c8ccccc8)c7cc6n(c3c(-c3ccccc3)c3c6cccc7c8cc9c%10ccccc%10n(-c%10ccccc%10)c9cc8n(c23)c76)c54)cc1 ; c1ccc(-c2c3c4cccc5c6cc7c(cc6n(c3c(-c3ccccc3)c3c6cccc8c9cc%10c(cc9n(c23)c86)c2ccccc2n%10-c2ccccc2)c54)c2ccccc2n7-c2ccccc2)cc1]

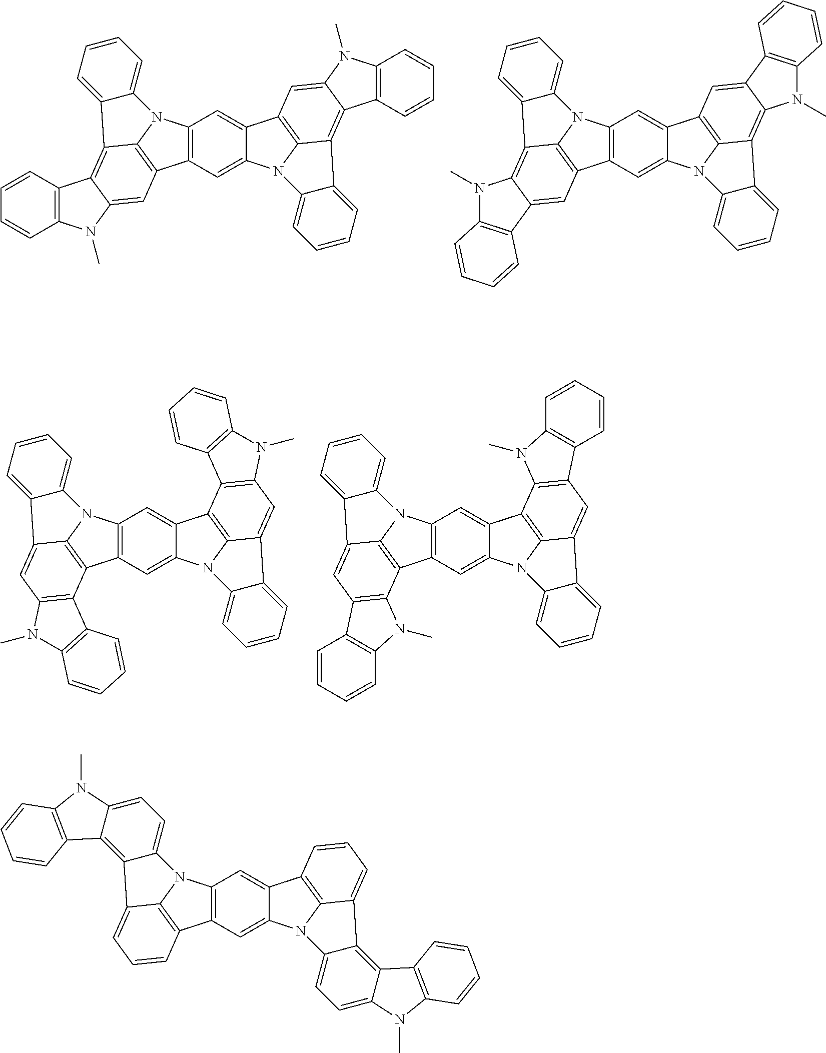

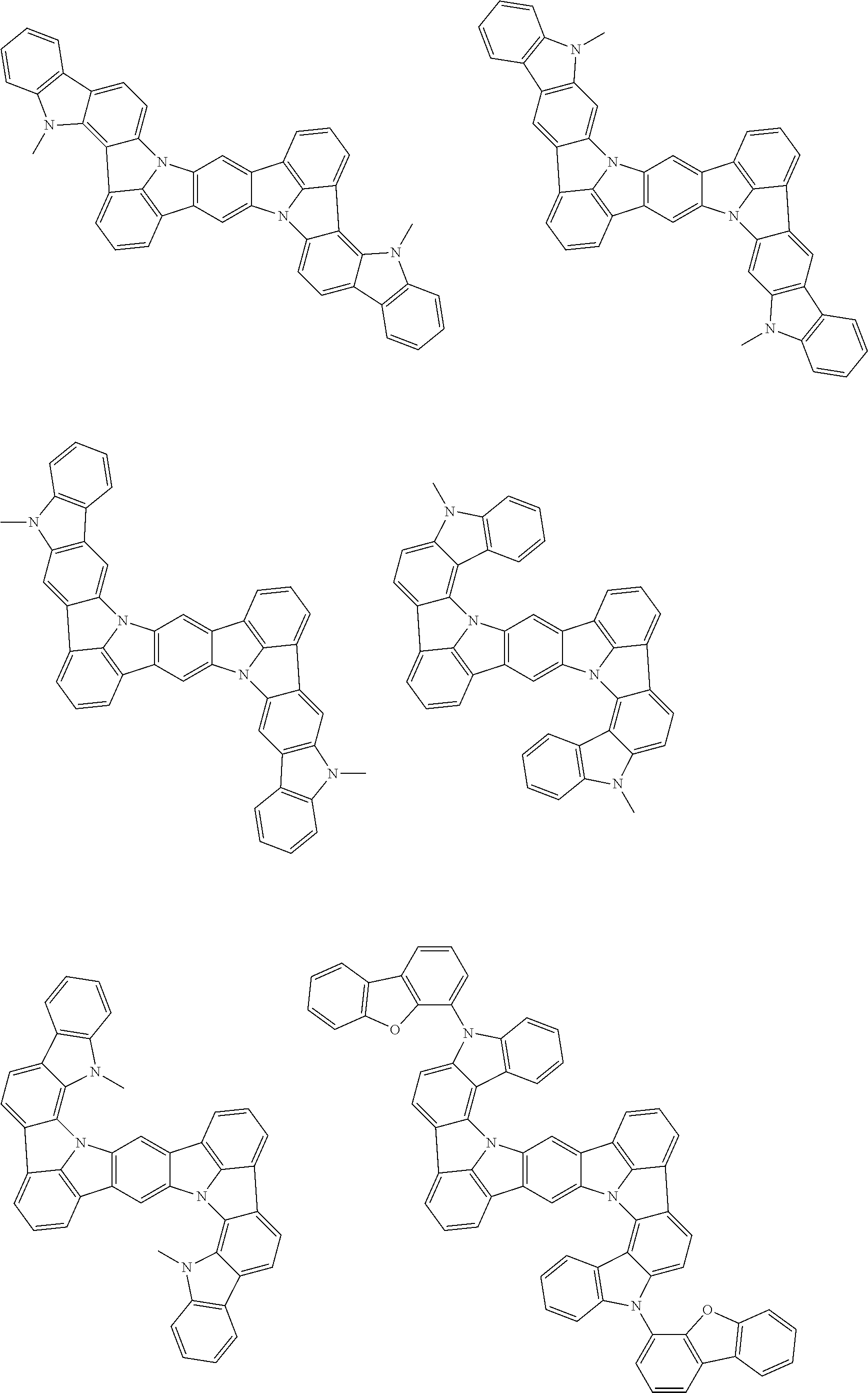

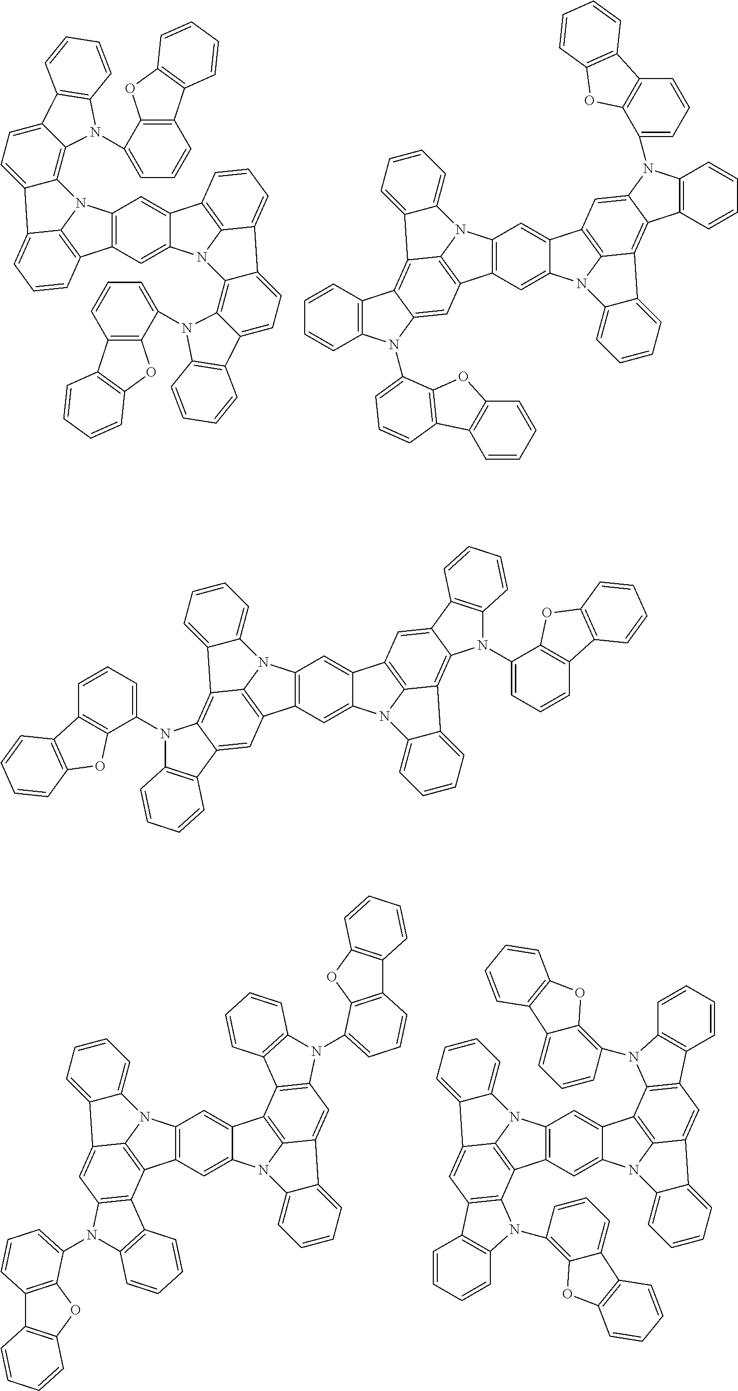

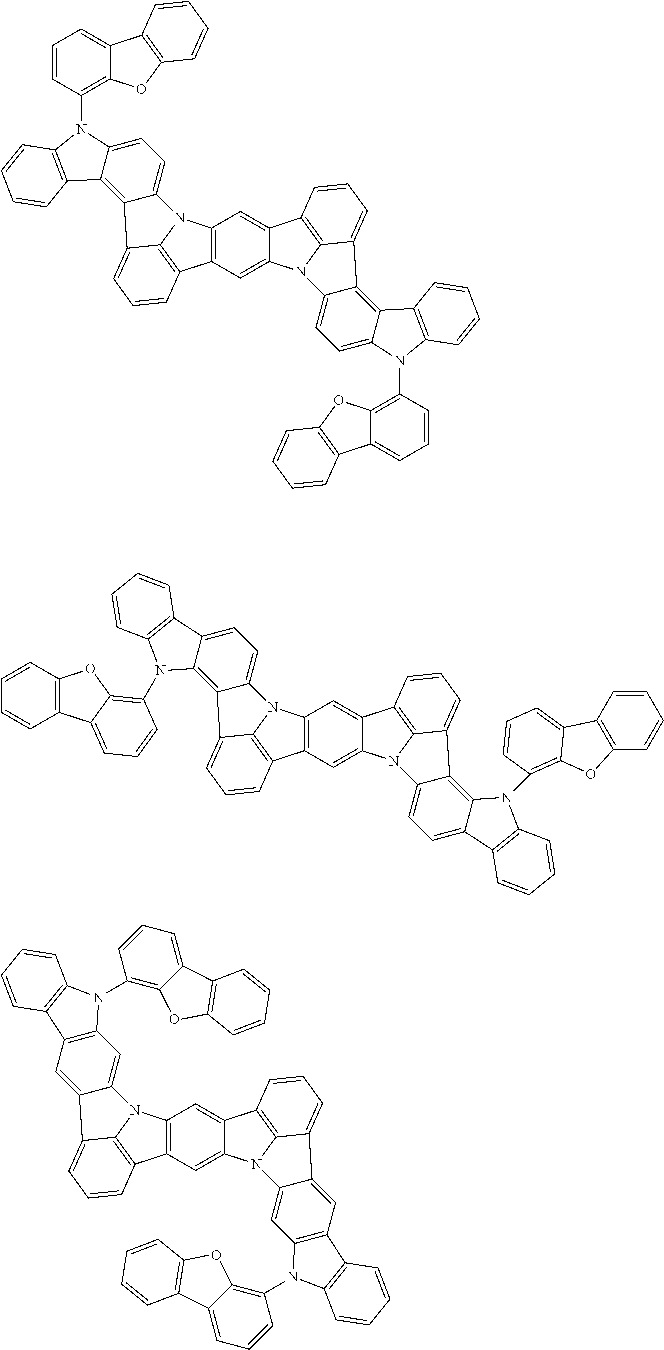 [SMILES: c1ccc2c(c1)oc1c(-n3c4ccccc4c4c5c6cccc7c8cc9c(cc8n(c5ccc43)c76)c3cccc4c5c6c7ccccc7n(-c7cccc8c7oc7ccccc78)c6ccc5n9c34)cccc12 ; c1ccc2c(c1)oc1c(-n3c4ccccc4c4ccc5c(c6cccc7c8cc9c(cc8n5c76)c5cccc6c7c8c(ccc7n9c56)c5ccccc5n8-c5cccc6c5oc5ccccc56)c43)cccc12 ; c1ccc2c(c1)oc1c(-n3c4ccccc4c4cc5c6cccc7c8cc9c(cc8n(c5cc43)c76)c3cccc4c5cc6c7ccccc7n(-c7cccc8c7oc7ccccc78)c6cc5n9c34)cccc12]

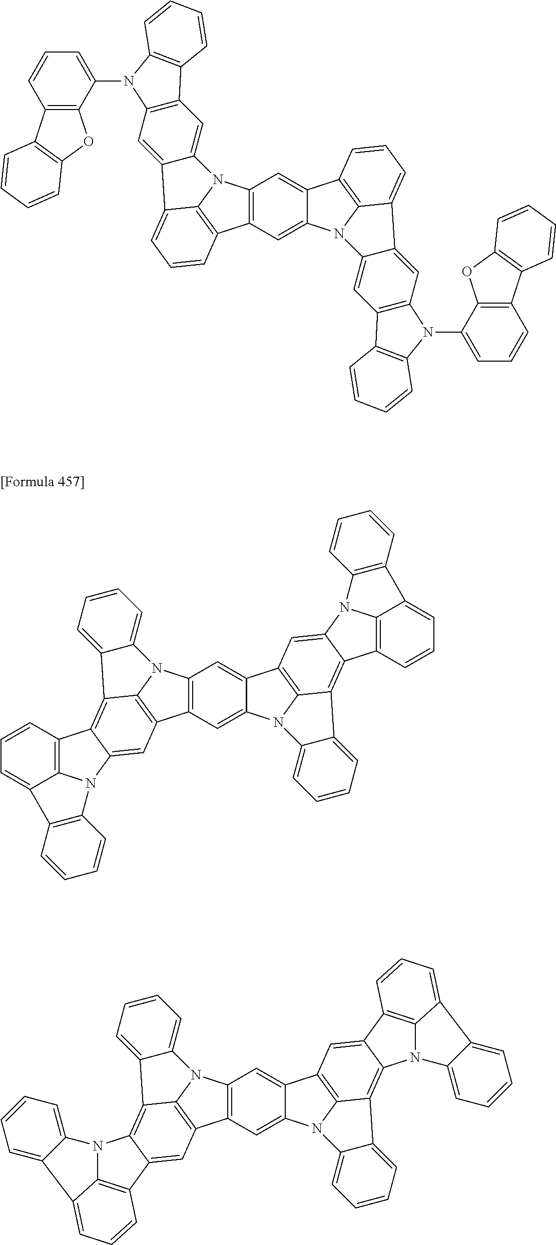 [SMILES: c1ccc2c(c1)oc1c(-n3c4ccccc4c4cc5c(cc43)c3cccc4c6cc7c(cc6n5c34)c3cccc4c5cc6c(cc5n7c43)c3ccccc3n6-c3cccc4c3oc3ccccc34)cccc12 ; c1ccc2c(c1)c1cccc3c4c5c6ccccc6n6c7cc8c9cc%10c(c%11cccc%12c%13ccccc%13n%10c%12%11)c%10c%11ccccc%11n(c8cc7c(cc4n2c13)c56)c9%10 ; c1ccc2c(c1)c1c3c(cc4c5cccc6c7ccccc7n(c65)c41)c1cc4c(cc1n23)c1cc2c3cccc5c6ccccc6n(c53)c2c2c3ccccc3n4c12]

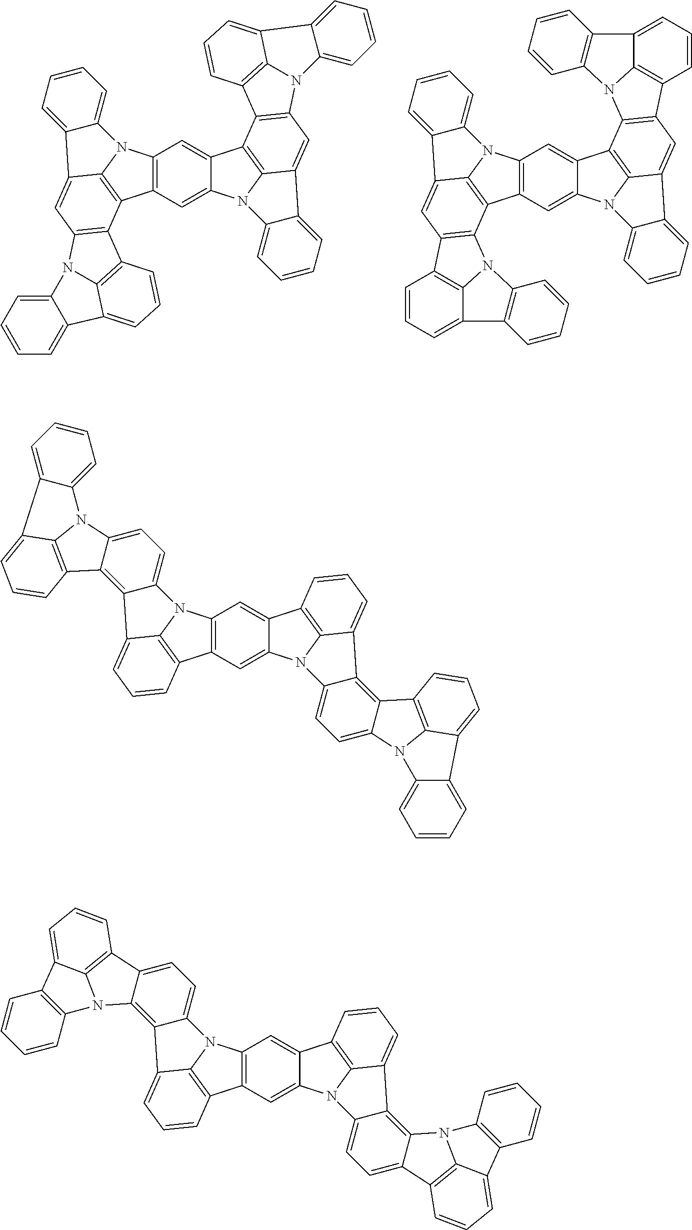 [SMILES: c1ccc2c(c1)c1cccc3c4c5c6cc7c(cc6n6c8ccccc8c(cc4n2c13)c56)c1c2c3cccc4c5ccccc5n(c2cc2c5ccccc5n7c21)c43 ; c1ccc2c(c1)c1cc3c4cccc5c6ccccc6n(c54)c3c3c4cc5c(cc4n2c13)c1c2c(cc3c4cccc6c7ccccc7n(c64)c31)c1ccccc1n52 ; c1ccc2c(c1)c1cccc3c4c5c6cccc7c8cc9c(cc8n(c5ccc4n2c13)c76)c1cccc2c3c4c5cccc6c7ccccc7n(c4ccc3n9c12)c65 ; c1ccc2c(c1)c1cccc3c4ccc5c(c6cccc7c8cc9c(cc8n5c76)c5cccc6c7c(ccc8c%10cccc%11c%12ccccc%12n(c%11%10)c87)n9c56)c4n2c13]

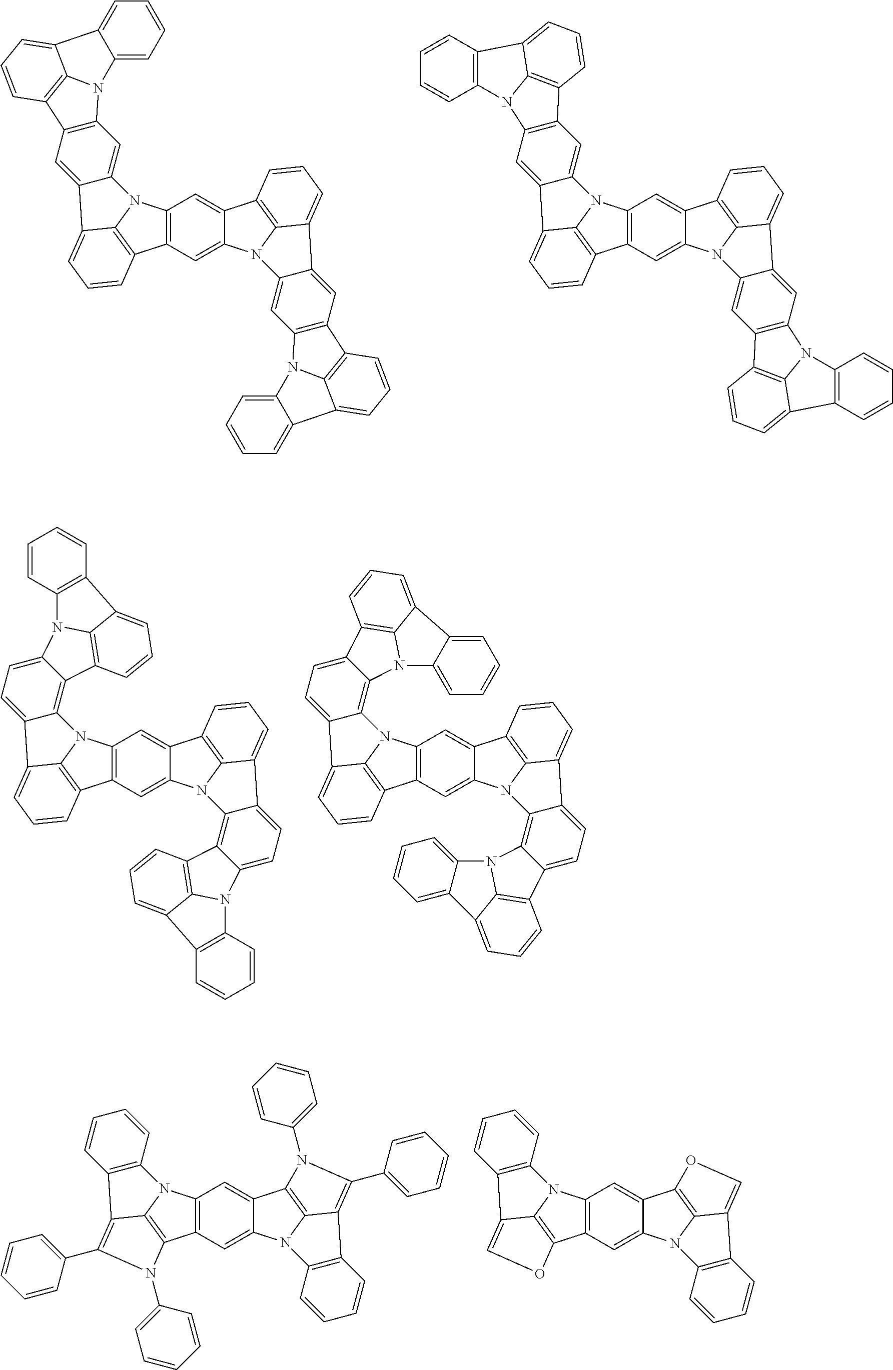

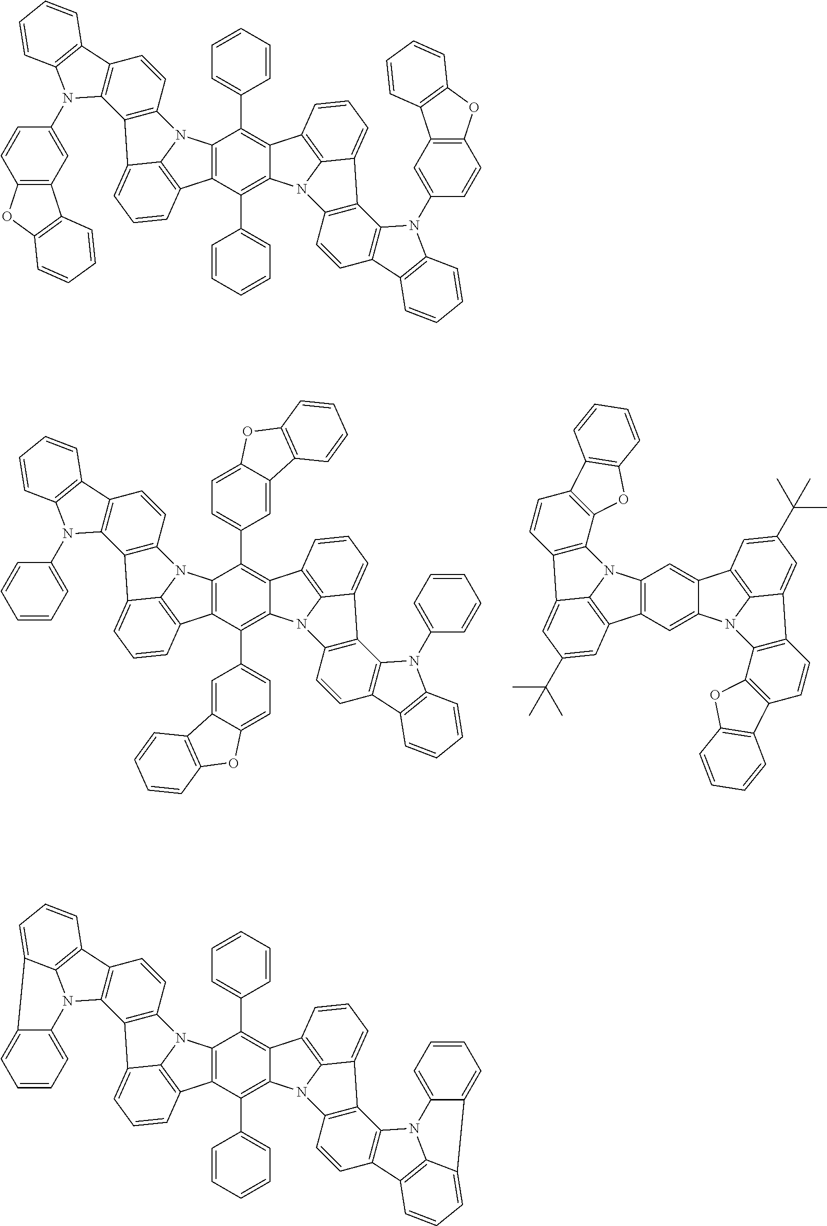

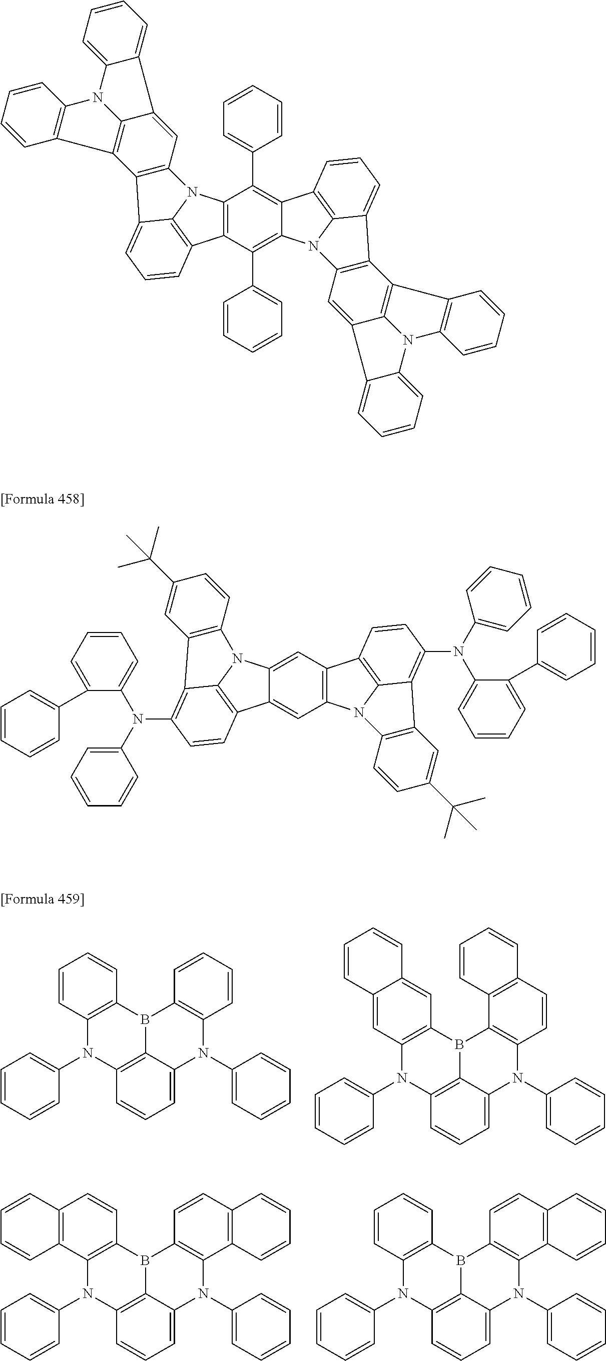

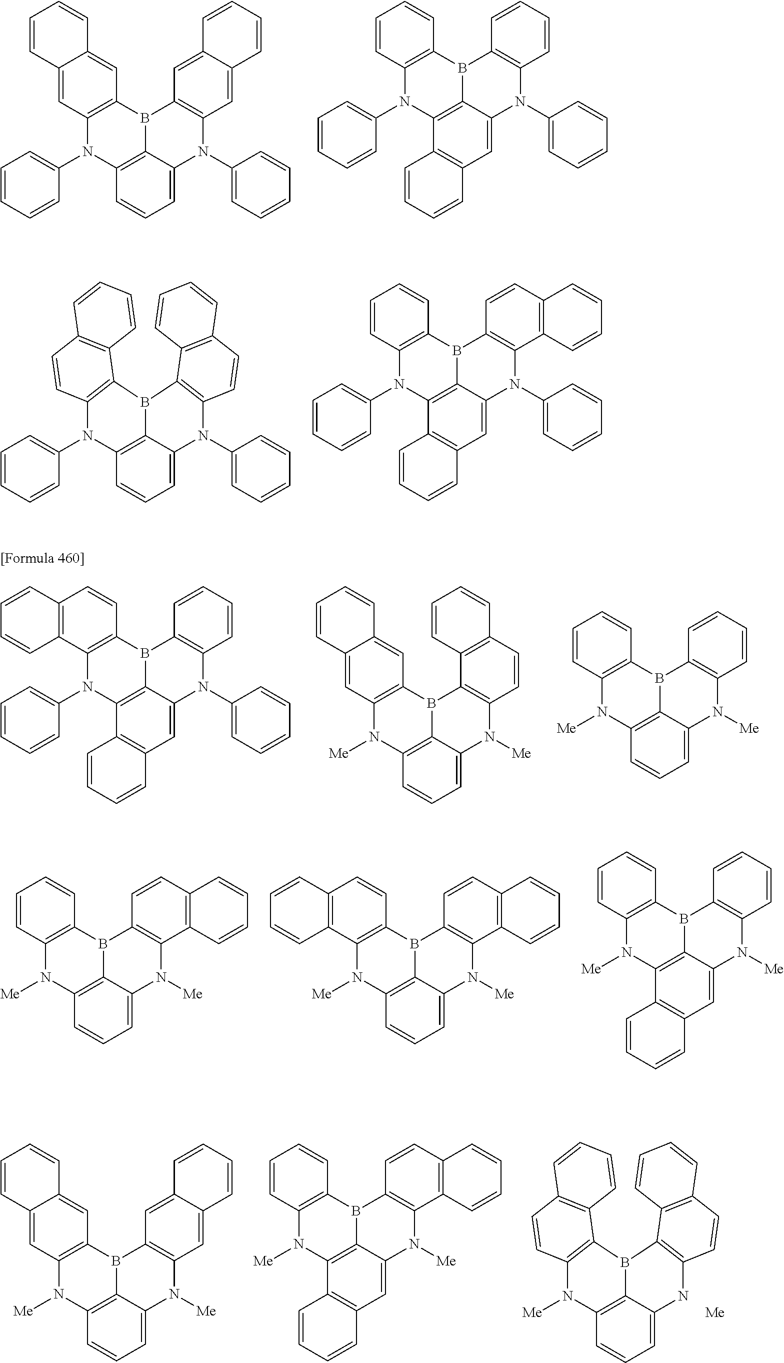

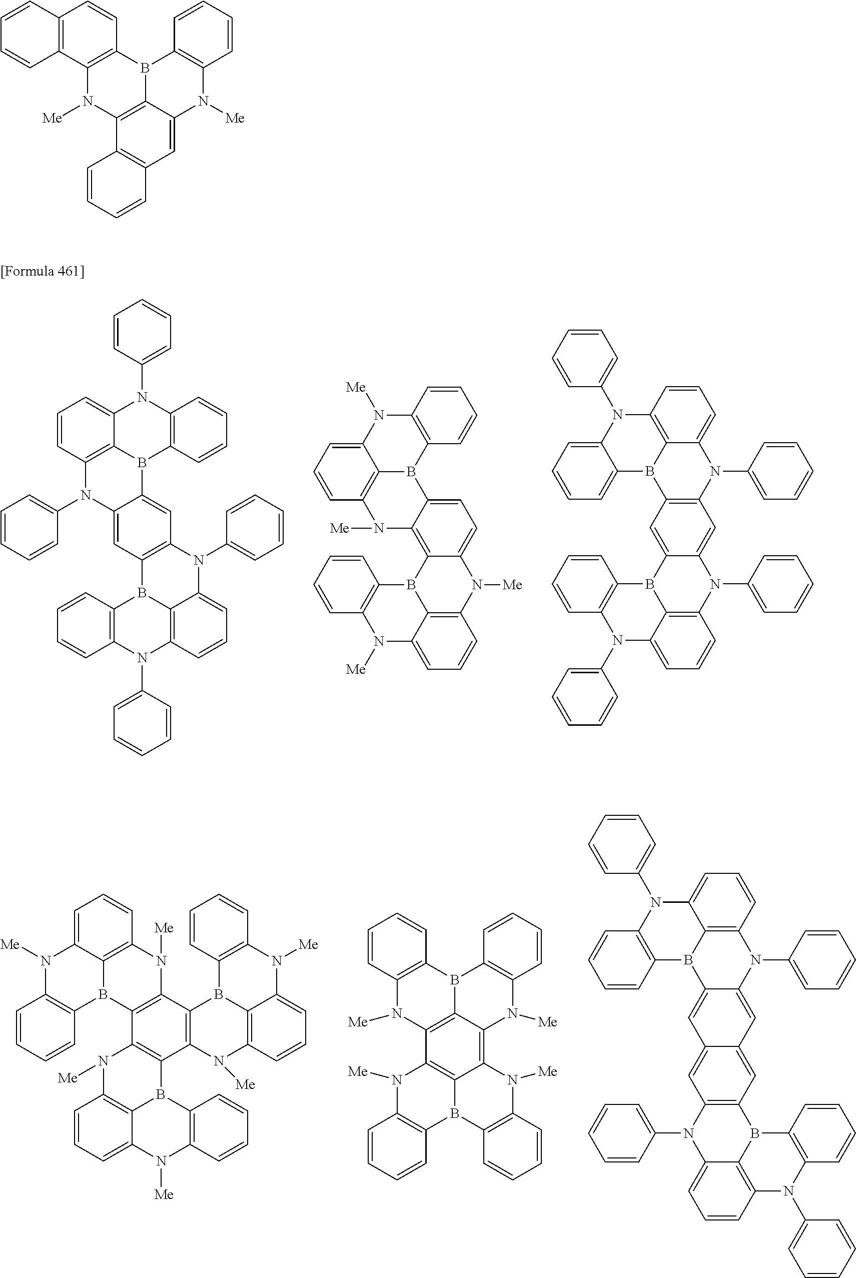

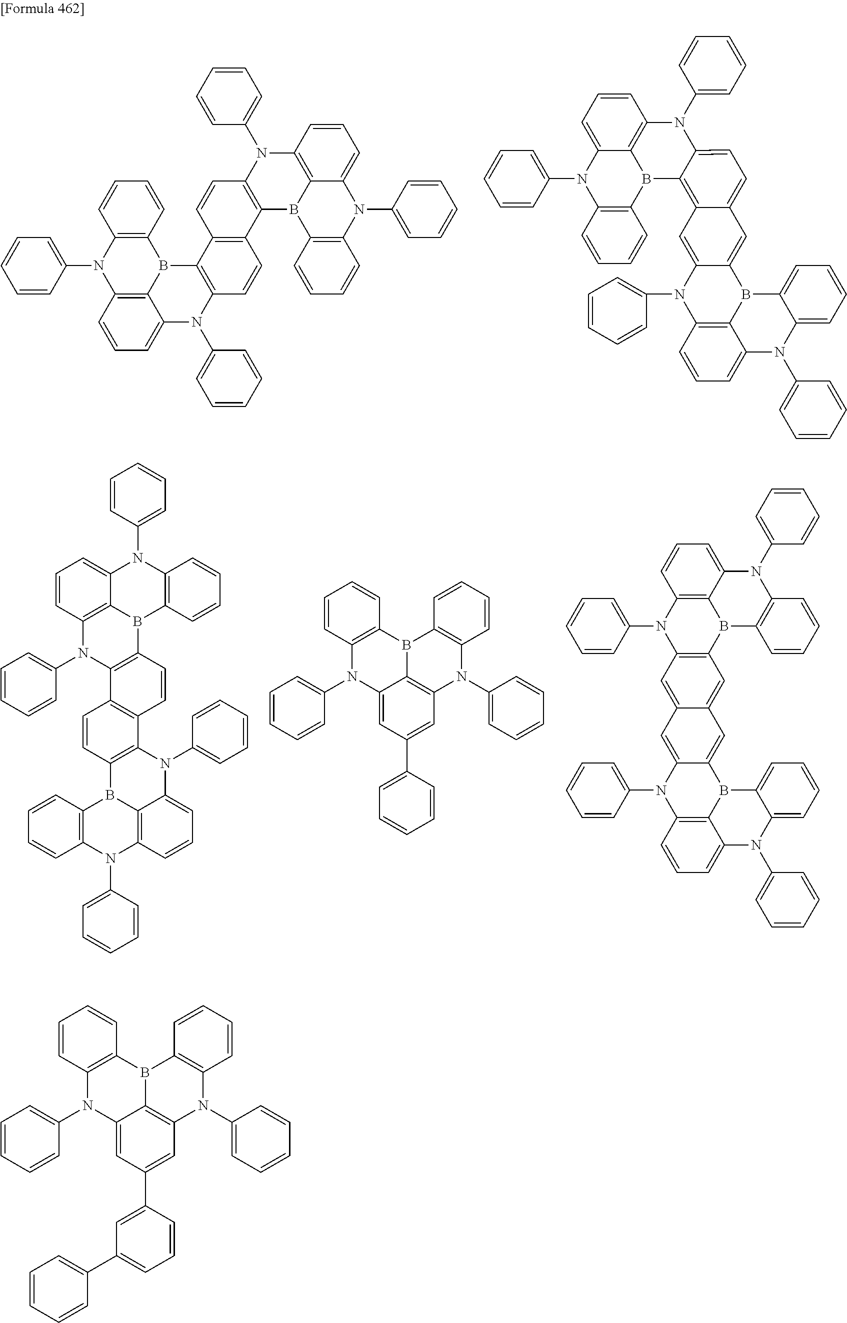

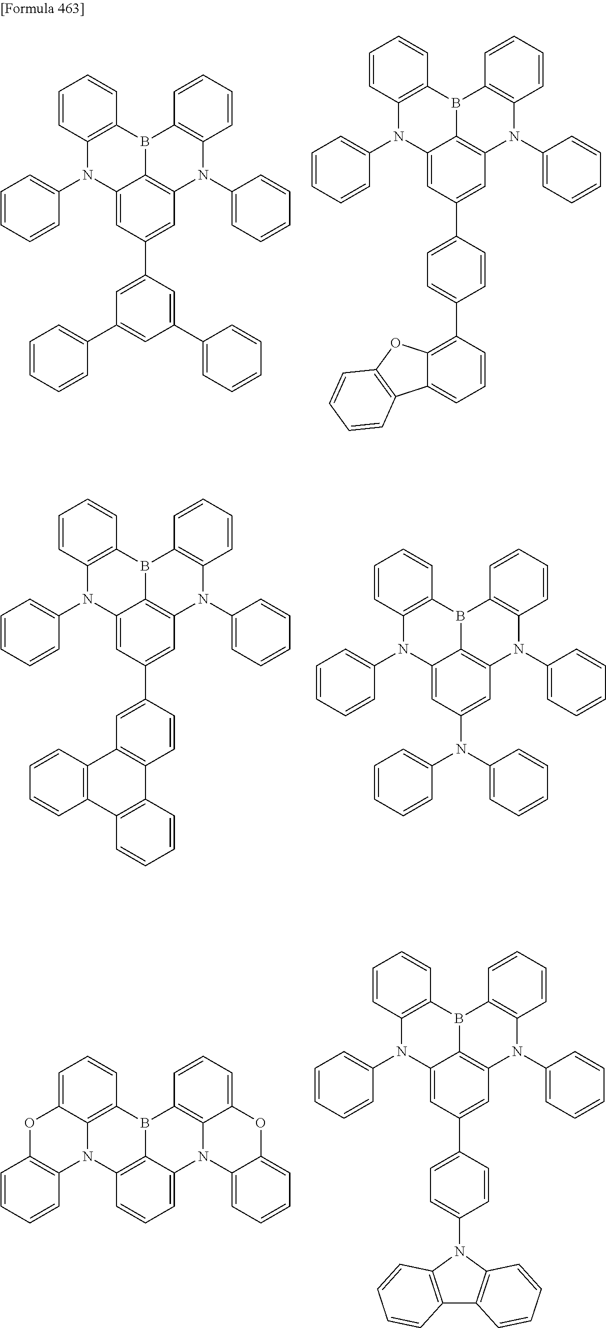

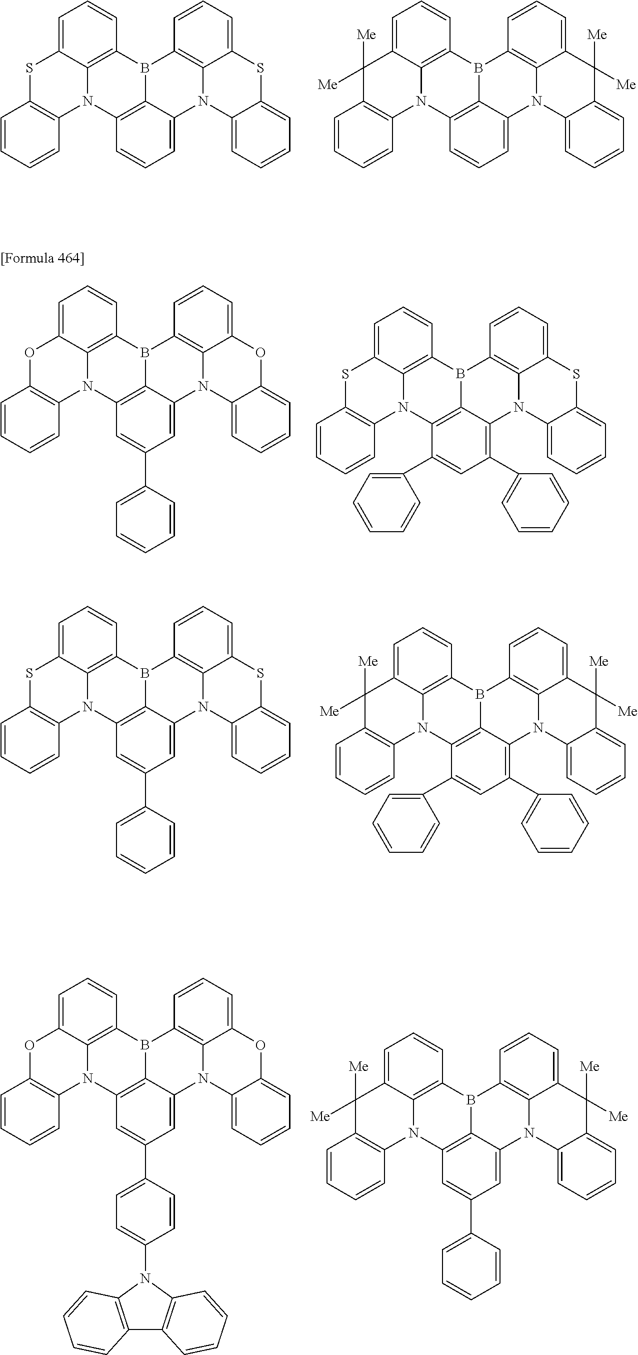

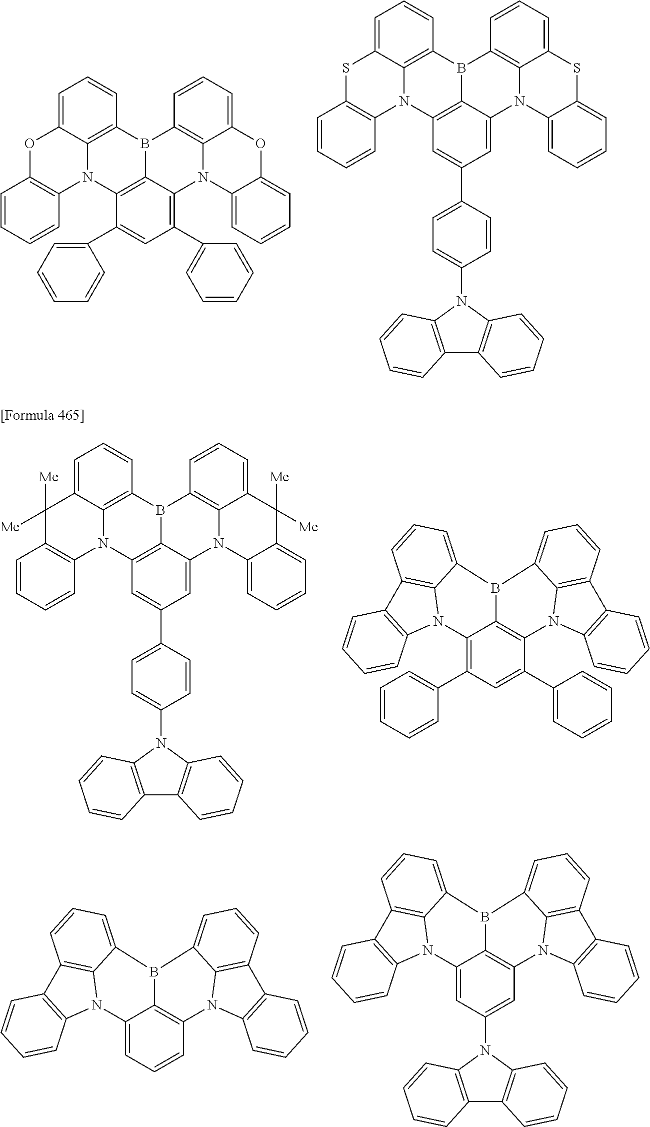

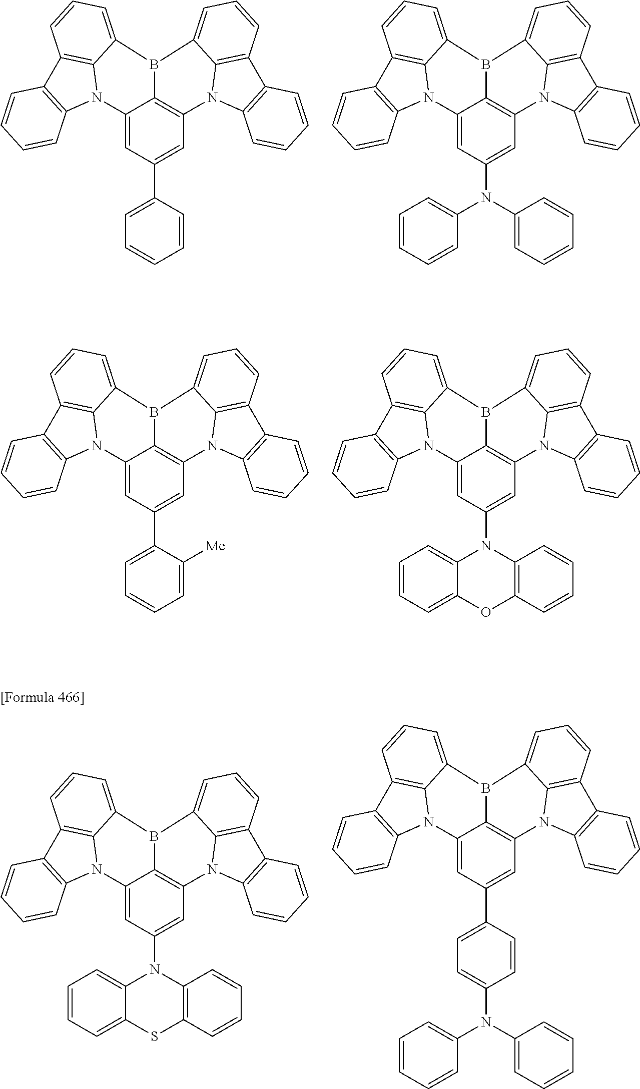

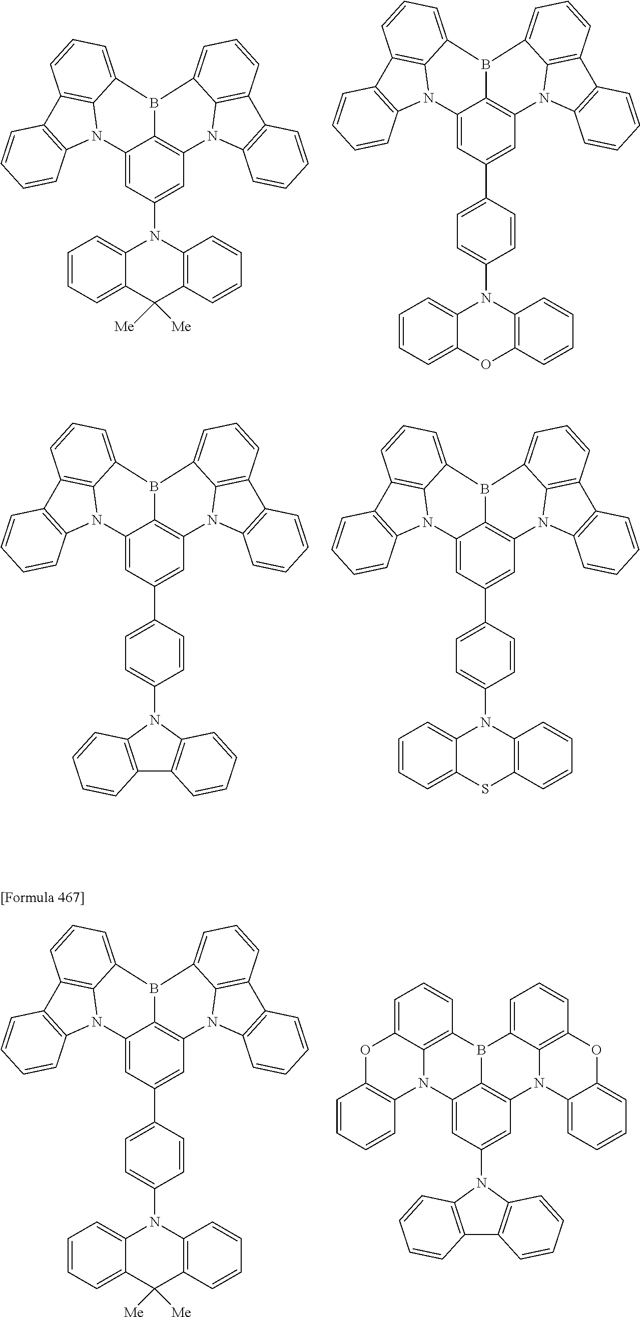

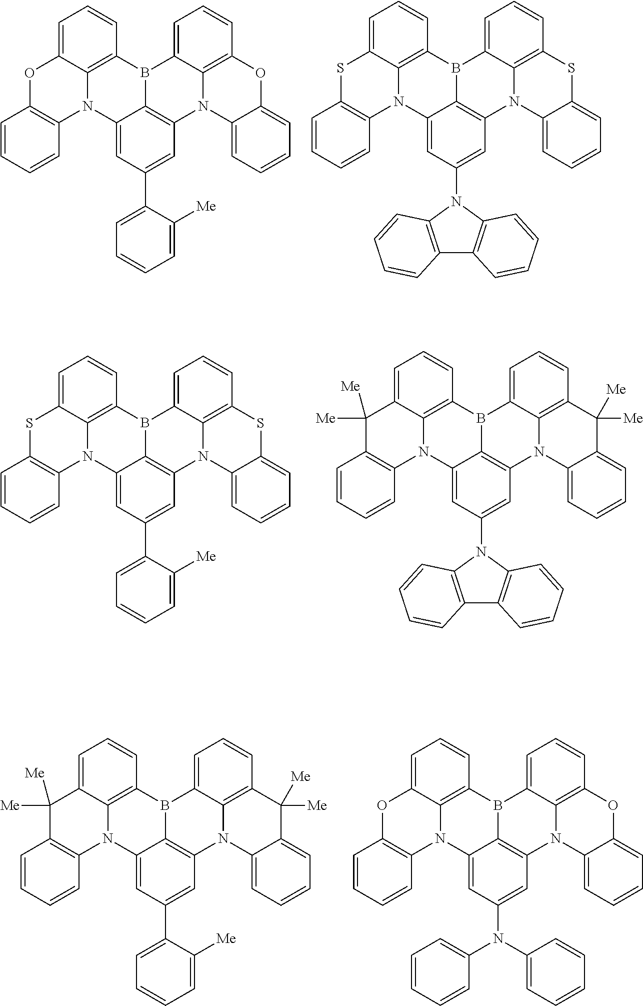

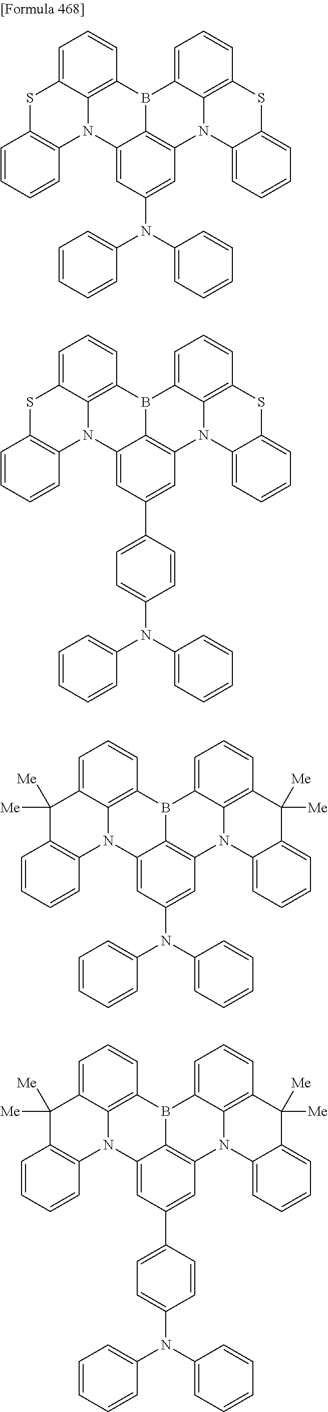

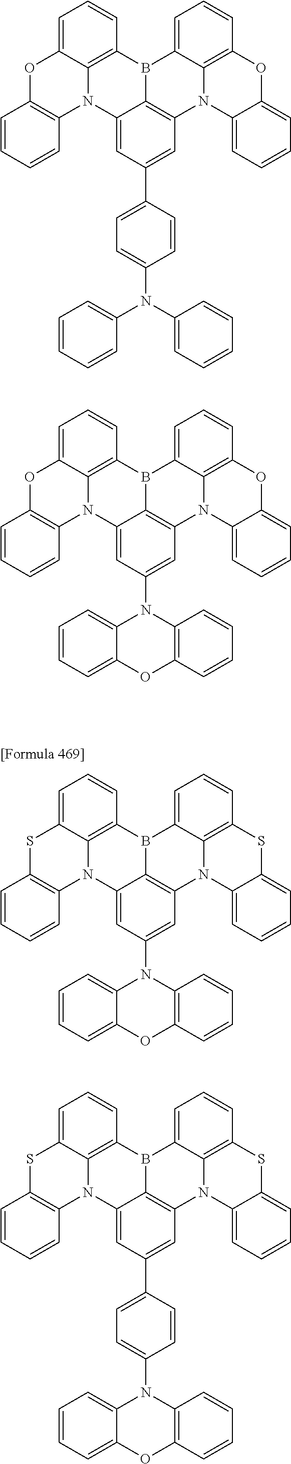

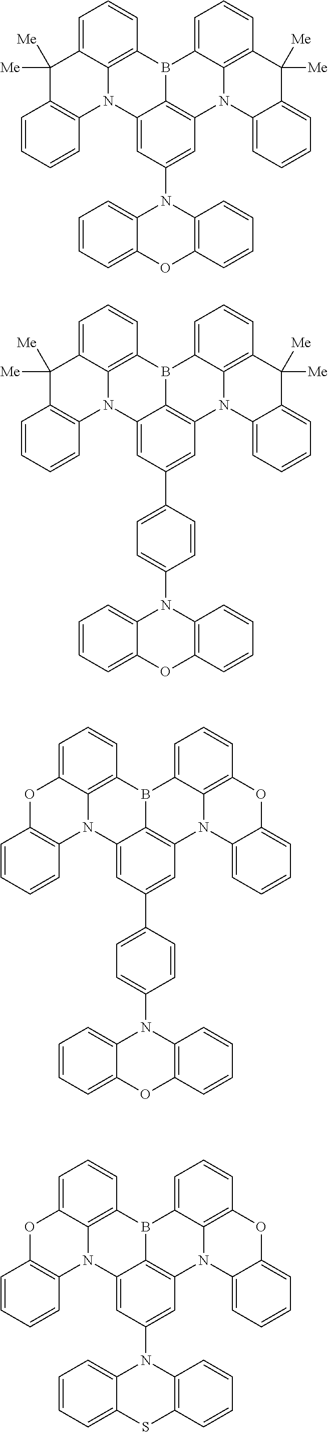

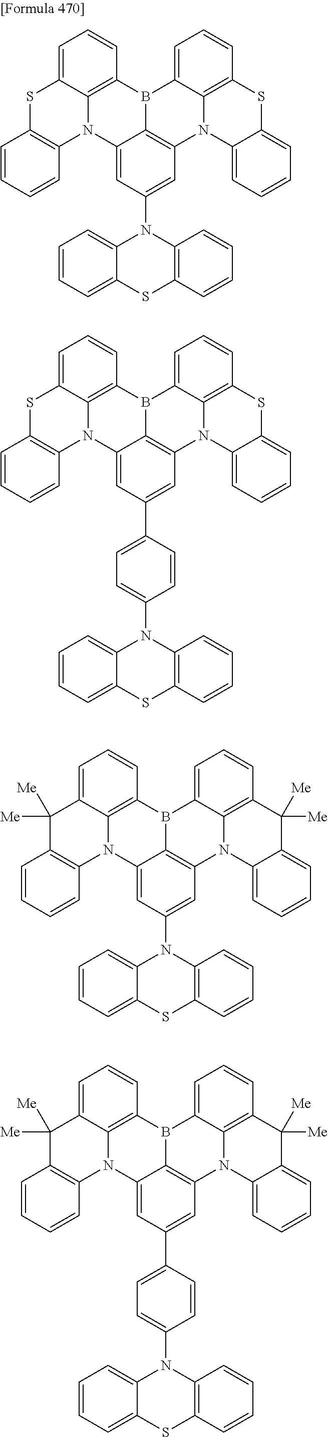

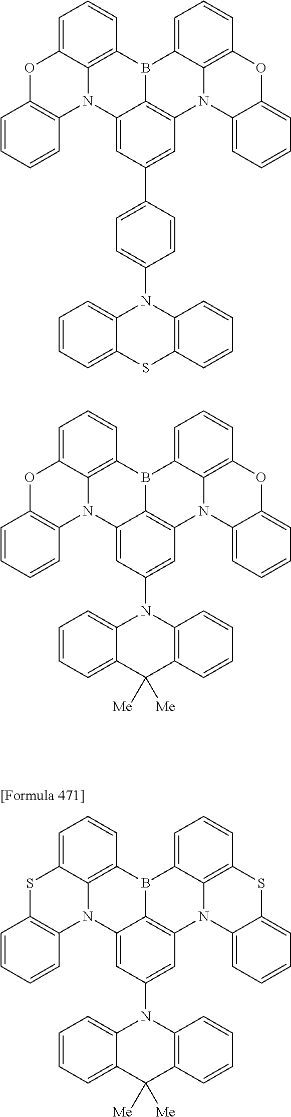

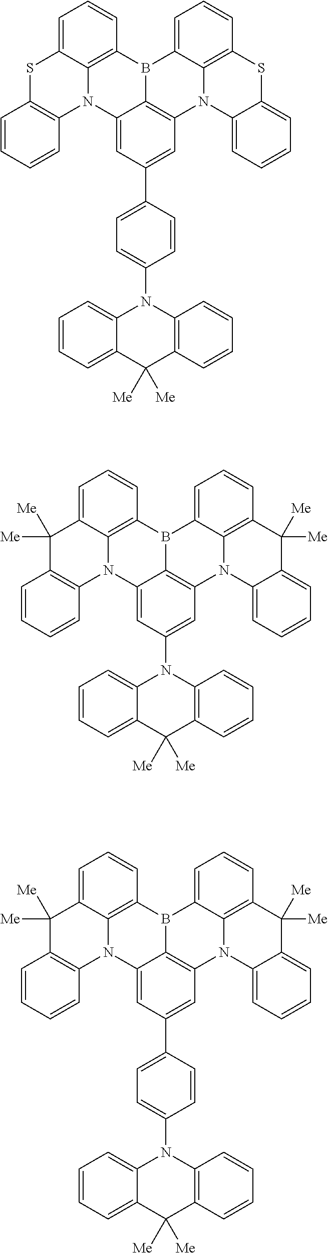 [SMILES: CC1(C)c2ccccc2N(c2ccc(-c3cc4c5c(c3)N3c6ccccc6Sc6cccc(c63)B5c3cccc5c3N4c3ccccc3S5)cc2)c2ccccc21 ; CC1(C)c2ccccc2N(c2cc3c4c(c2)N2c5ccccc5C(C)(C)c5cccc(c52)B4c2cccc4c2N3c2ccccc2C4(C)C)c2ccccc21 ; CC1(C)c2ccccc2N(c2ccc(-c3cc4c5c(c3)N3c6ccccc6C(C)(C)c6cccc(c63)B5c3cccc5c3N4c3ccccc3C5(C)C)cc2)c2ccccc21]

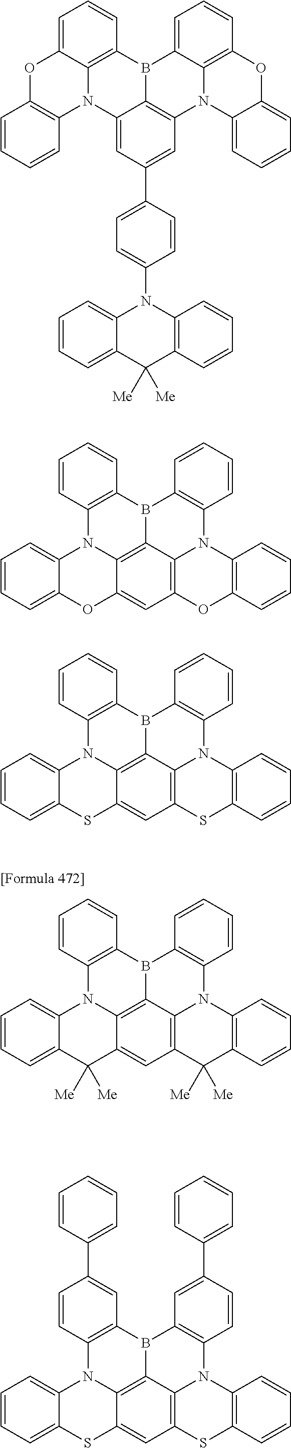

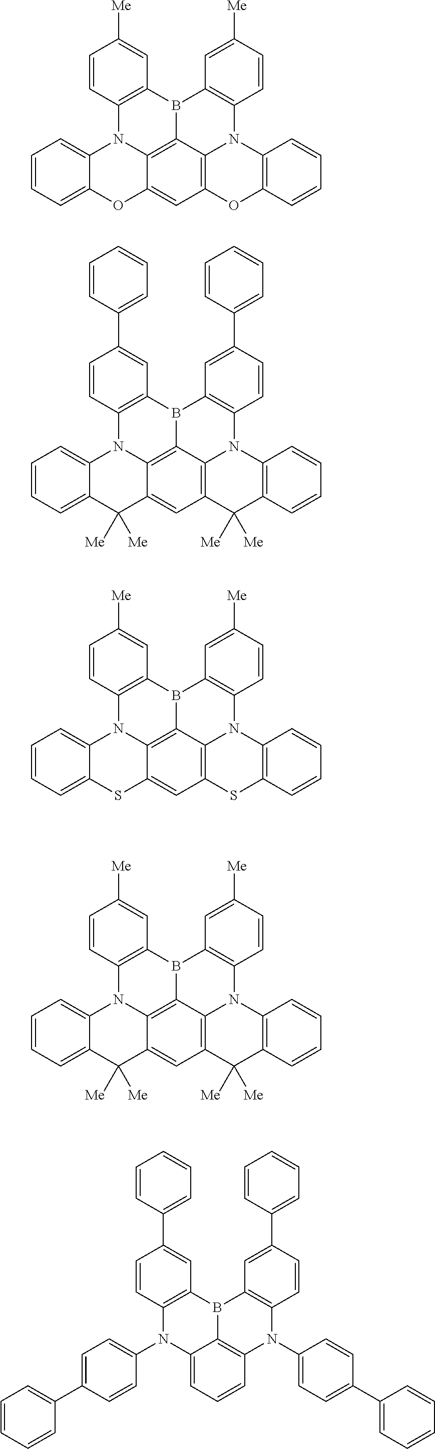

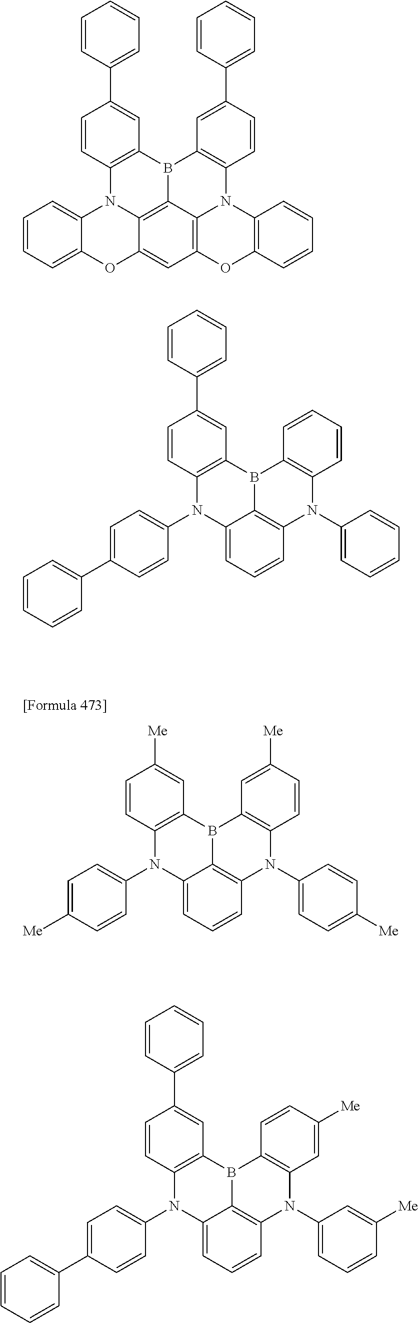 [SMILES: c1ccc(-c2ccc3c(c2)B2c4cc(-c5ccccc5)ccc4-n4c5ccccc5oc5cc6oc7ccccc7n-3c6c2c54)cc1 ; c1ccc(-c2ccc(N3c4ccc(-c5ccccc5)cc4B4c5ccccc5N(c5ccccc5)c5cccc3c54)cc2)cc1 ; Cc1ccc(N2c3ccc(C)cc3B3c4cc(C)ccc4N(c4ccc(C)cc4)c4cccc2c43)cc1 ; Cc1cccc(N2c3cc(C)ccc3B3c4cc(-c5ccccc5)ccc4N(c4ccc(-c5ccccc5)cc4)c4cccc2c43)c1]

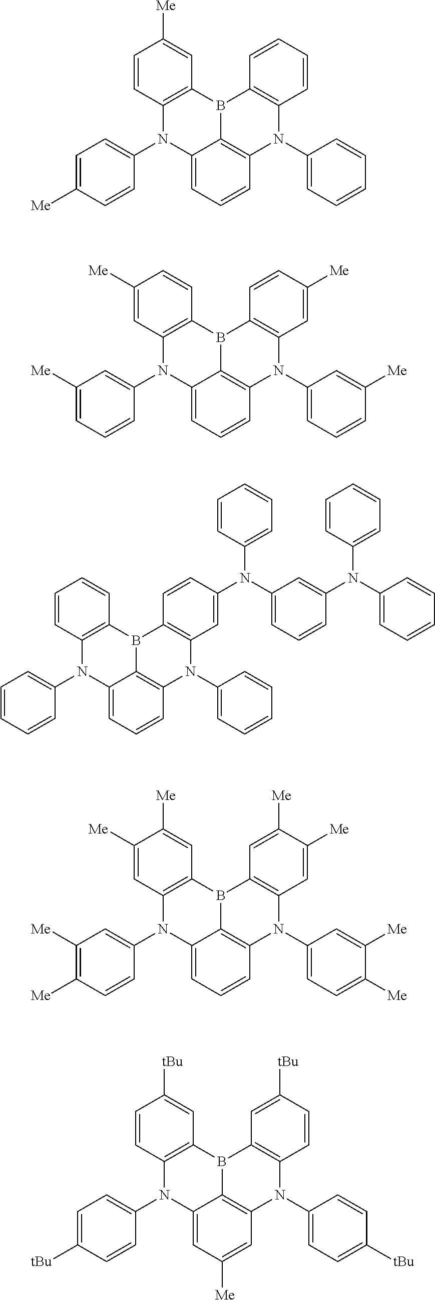 [SMILES: Cc1ccc(N2c3ccc(C)cc3B3c4ccccc4N(c4ccccc4)c4cccc2c43)cc1 ; Cc1cccc(N2c3cc(C)ccc3B3c4ccc(C)cc4N(c4cccc(C)c4)c4cccc2c43)c1 ; c1ccc(N(c2ccccc2)c2cccc(N(c3ccccc3)c3ccc4c(c3)N(c3ccccc3)c3cccc5c3B4c3ccccc3N5c3ccccc3)c2)cc1 ; Cc1ccc(N2c3cc(C)c(C)cc3B3c4cc(C)c(C)cc4N(c4ccc(C)c(C)c4)c4cccc2c43)cc1C ; Cc1cc2c3c(c1)N(c1ccc(C(C)(C)C)cc1)c1ccc(C(C)(C)C)cc1B3c1cc(C(C)(C)C)ccc1N2c1ccc(C(C)(C)C)cc1]

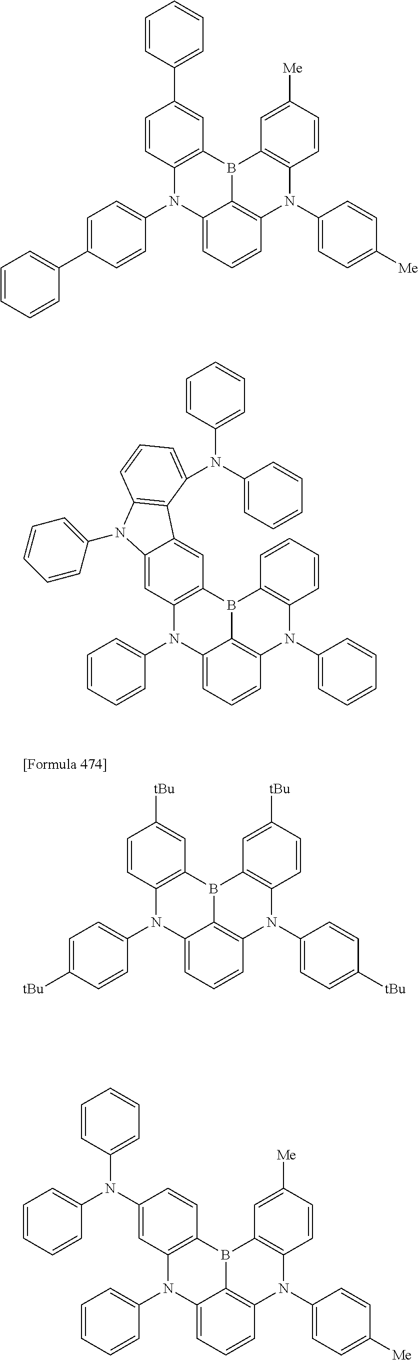 [SMILES: Cc1ccc(N2c3ccc(C)cc3B3c4cc(-c5ccccc5)ccc4N(c4ccc(-c5ccccc5)cc4)c4cccc2c43)cc1 ; c1ccc(N2c3ccccc3B3c4cc5c6c(N(c7ccccc7)c7ccccc7)cccc6n(-c6ccccc6)c5cc4N(c4ccccc4)c4cccc2c43)cc1 ; CC(C)(C)c1ccc(N2c3ccc(C(C)(C)C)cc3B3c4cc(C(C)(C)C)ccc4N(c4ccc(C(C)(C)C)cc4)c4cccc2c43)cc1 ; Cc1ccc(N2c3ccc(C)cc3B3c4ccc(N(c5ccccc5)c5ccccc5)cc4N(c4ccccc4)c4cccc2c43)cc1]

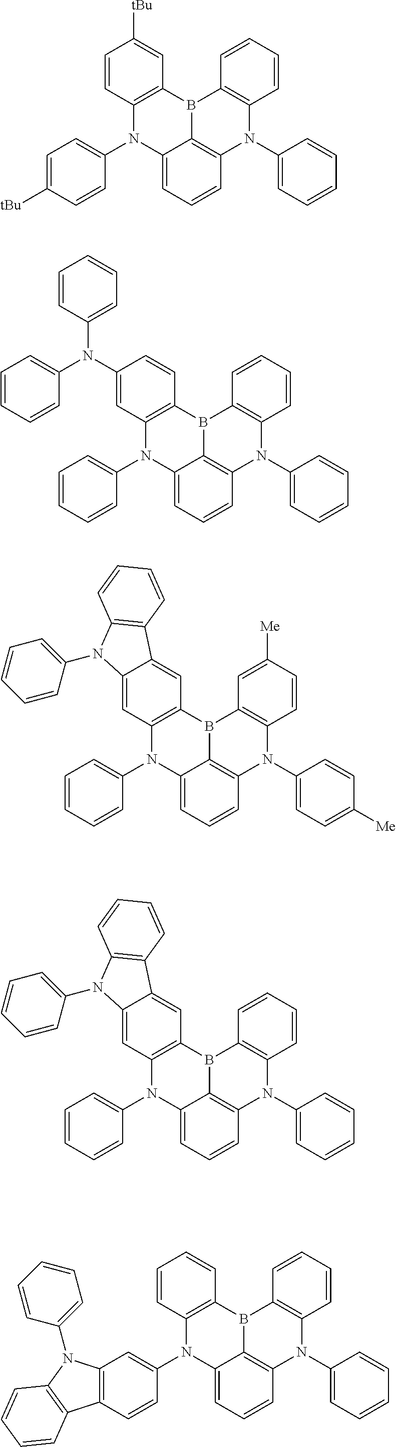 [SMILES: CC(C)(C)c1ccc(N2c3ccc(C(C)(C)C)cc3B3c4ccccc4N(c4ccccc4)c4cccc2c43)cc1 ; c1ccc(N(c2ccccc2)c2ccc3c(c2)N(c2ccccc2)c2cccc4c2B3c2ccccc2N4c2ccccc2)cc1 ; Cc1ccc(N2c3ccc(C)cc3B3c4cc5c6ccccc6n(-c6ccccc6)c5cc4N(c4ccccc4)c4cccc2c43)cc1 ; c1ccc(N2c3ccccc3B3c4cc5c6ccccc6n(-c6ccccc6)c5cc4N(c4ccccc4)c4cccc2c43)cc1 ; c1ccc(N2c3ccccc3B3c4ccccc4N(c4ccc5c6ccccc6n(-c6ccccc6)c5c4)c4cccc2c43)cc1]

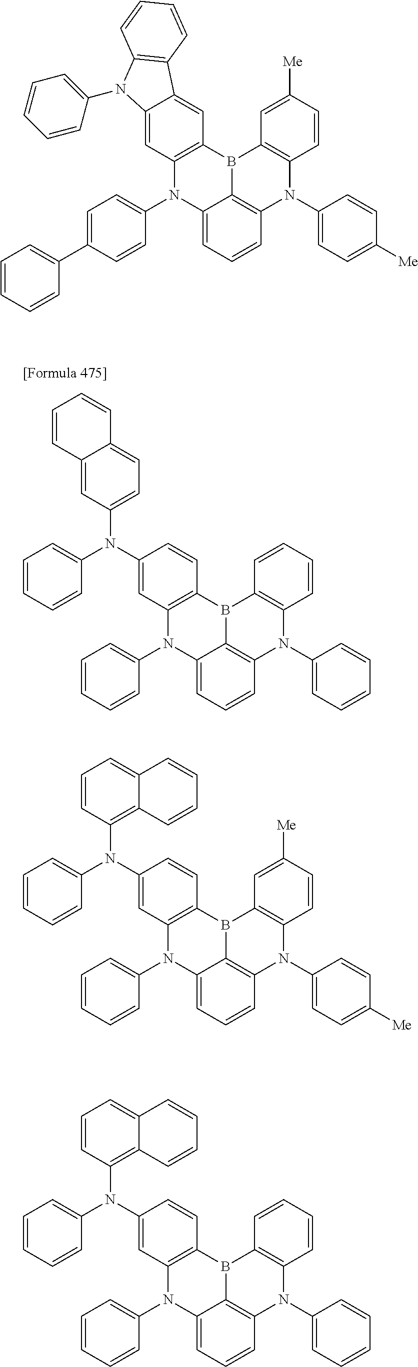 [SMILES: Cc1ccc(N2c3ccc(C)cc3B3c4cc5c6ccccc6n(-c6ccccc6)c5cc4N(c4ccc(-c5ccccc5)cc4)c4cccc2c43)cc1 ; c1ccc(N(c2ccc3c(c2)N(c2ccccc2)c2cccc4c2B3c2ccccc2N4c2ccccc2)c2ccc3ccccc3c2)cc1 ; Cc1ccc(N2c3ccc(C)cc3B3c4ccc(N(c5ccccc5)c5cccc6ccccc56)cc4N(c4ccccc4)c4cccc2c43)cc1 ; c1ccc(N2c3ccccc3B3c4ccc(N(c5ccccc5)c5cccc6ccccc56)cc4N(c4ccccc4)c4cccc2c43)cc1]

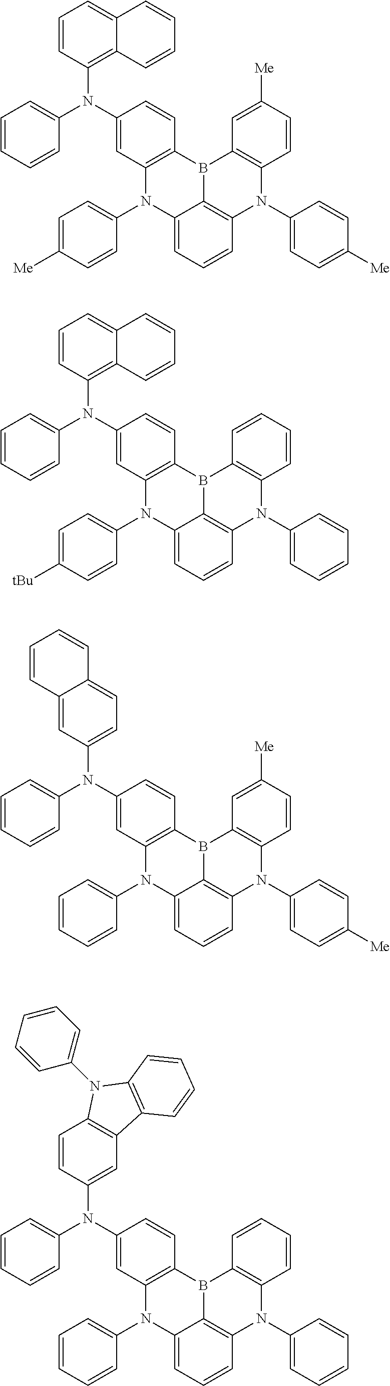

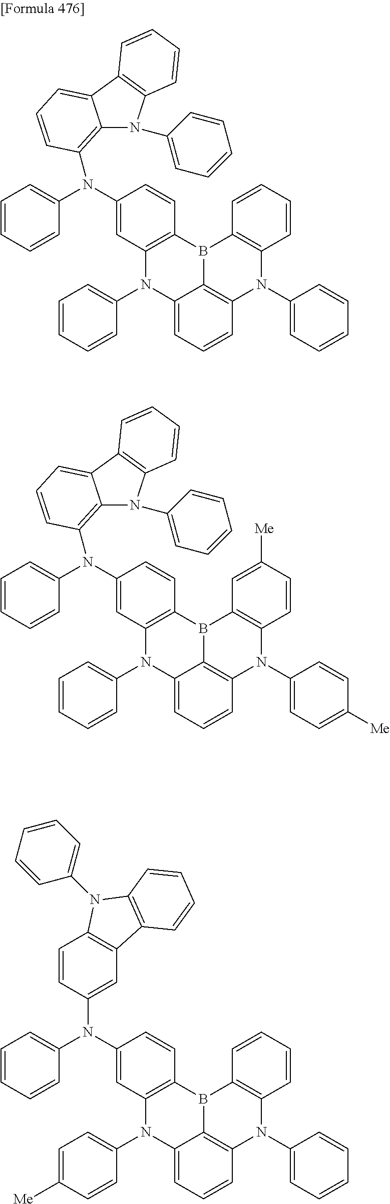 [SMILES: c1ccc(N2c3ccccc3B3c4ccc(N(c5ccccc5)c5cccc6c7ccccc7n(-c7ccccc7)c56)cc4N(c4ccccc4)c4cccc2c43)cc1 ; Cc1ccc(N2c3ccc(C)cc3B3c4ccc(N(c5ccccc5)c5cccc6c7ccccc7n(-c7ccccc7)c56)cc4N(c4ccccc4)c4cccc2c43)cc1 ; Cc1ccc(N2c3cc(N(c4ccccc4)c4ccc5c(c4)c4ccccc4n5-c4ccccc4)ccc3B3c4ccccc4N(c4ccccc4)c4cccc2c43)cc1]

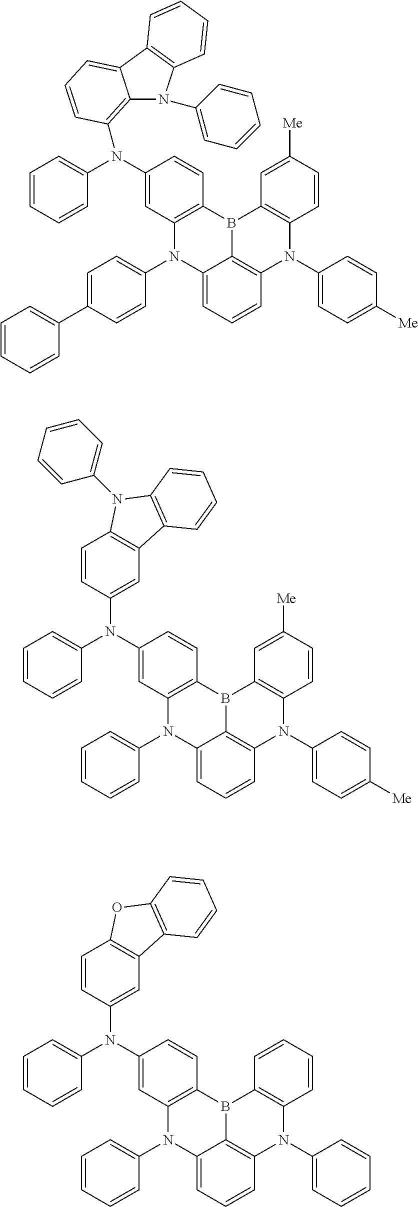 [SMILES: Cc1ccc(N2c3ccc(C)cc3B3c4ccc(N(c5ccccc5)c5cccc6c7ccccc7n(-c7ccccc7)c56)cc4N(c4ccc(-c5ccccc5)cc4)c4cccc2c43)cc1 ; Cc1ccc(N2c3ccc(C)cc3B3c4ccc(N(c5ccccc5)c5ccc6c(c5)c5ccccc5n6-c5ccccc5)cc4N(c4ccccc4)c4cccc2c43)cc1 ; c1ccc(N(c2ccc3c(c2)N(c2ccccc2)c2cccc4c2B3c2ccccc2N4c2ccccc2)c2ccc3oc4ccccc4c3c2)cc1]

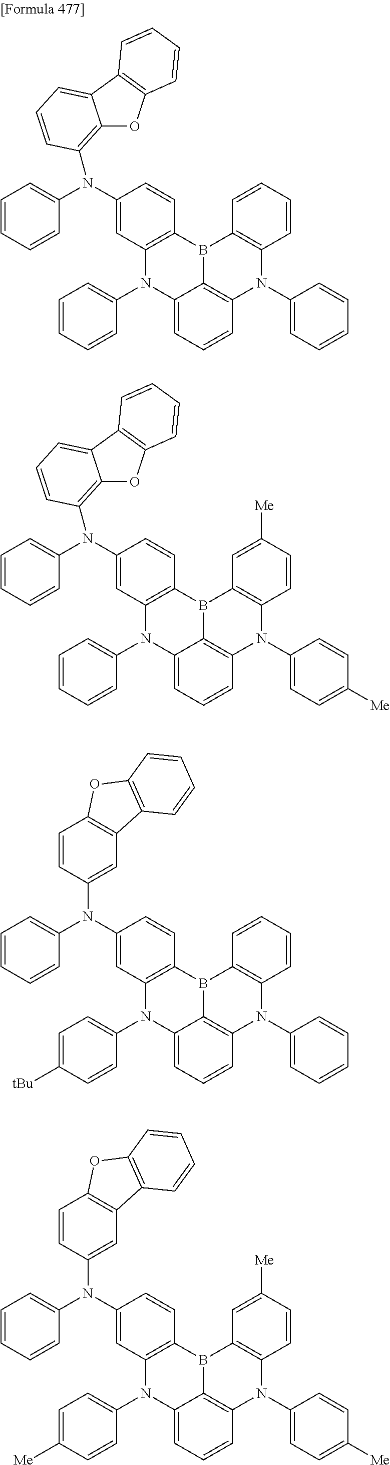 [SMILES: c1ccc(N2c3ccccc3B3c4ccc(N(c5ccccc5)c5cccc6c5oc5ccccc56)cc4N(c4ccccc4)c4cccc2c43)cc1 ; Cc1ccc(N2c3ccc(C)cc3B3c4ccc(N(c5ccccc5)c5cccc6c5oc5ccccc56)cc4N(c4ccccc4)c4cccc2c43)cc1 ; CC(C)(C)c1ccc(N2c3cc(N(c4ccccc4)c4ccc5oc6ccccc6c5c4)ccc3B3c4ccccc4N(c4ccccc4)c4cccc2c43)cc1 ; Cc1ccc(N2c3ccc(C)cc3B3c4ccc(N(c5ccccc5)c5ccc6oc7ccccc7c6c5)cc4N(c4ccc(C)cc4)c4cccc2c43)cc1]

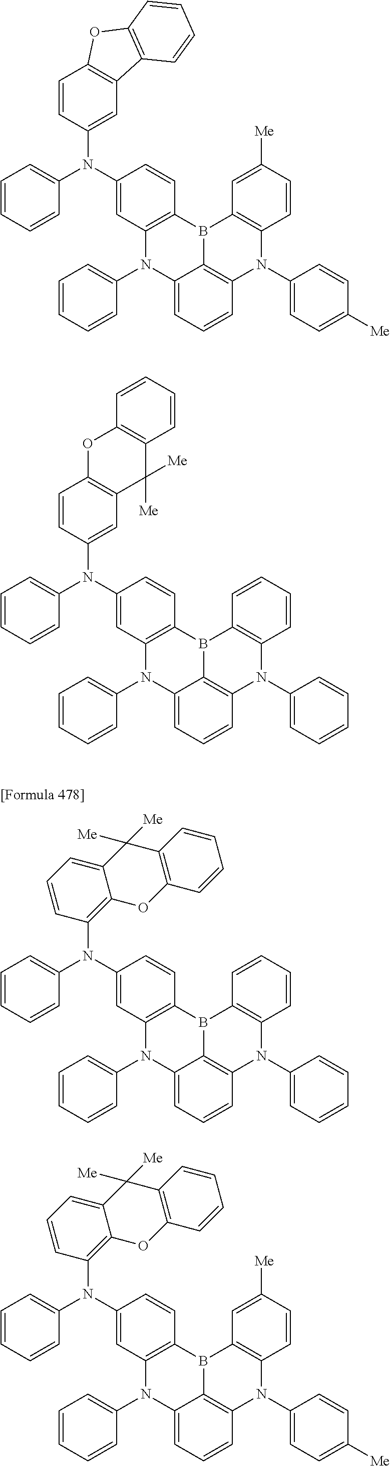 [SMILES: Cc1ccc(N2c3ccc(C)cc3B3c4ccc(N(c5ccccc5)c5ccc6oc7ccccc7c6c5)cc4N(c4ccccc4)c4cccc2c43)cc1 ; CC1(C)c2ccccc2Oc2ccc(N(c3ccccc3)c3ccc4c(c3)N(c3ccccc3)c3cccc5c3B4c3ccccc3N5c3ccccc3)cc21 ; CC1(C)c2ccccc2Oc2c(N(c3ccccc3)c3ccc4c(c3)N(c3ccccc3)c3cccc5c3B4c3ccccc3N5c3ccccc3)cccc21 ; Cc1ccc(N2c3ccc(C)cc3B3c4ccc(N(c5ccccc5)c5cccc6c5Oc5ccccc5C6(C)C)cc4N(c4ccccc4)c4cccc2c43)cc1]

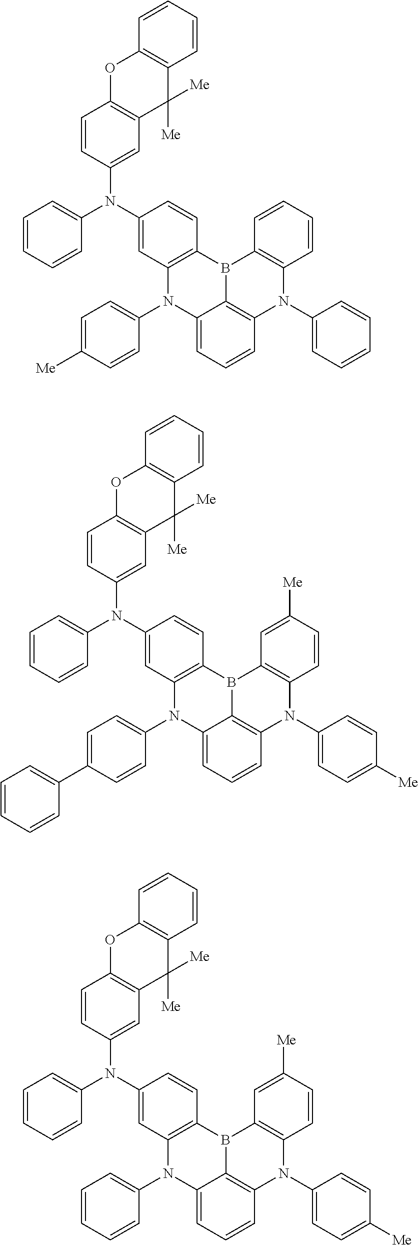 [SMILES: Cc1ccc(N2c3cc(N(c4ccccc4)c4ccc5c(c4)C(C)(C)c4ccccc4O5)ccc3B3c4ccccc4N(c4ccccc4)c4cccc2c43)cc1 ; Cc1ccc(N2c3ccc(C)cc3B3c4ccc(N(c5ccccc5)c5ccc6c(c5)C(C)(C)c5ccccc5O6)cc4N(c4ccc(-c5ccccc5)cc4)c4cccc2c43)cc1 ; Cc1ccc(N2c3ccc(C)cc3B3c4ccc(N(c5ccccc5)c5ccc6c(c5)C(C)(C)c5ccccc5O6)cc4N(c4ccccc4)c4cccc2c43)cc1]

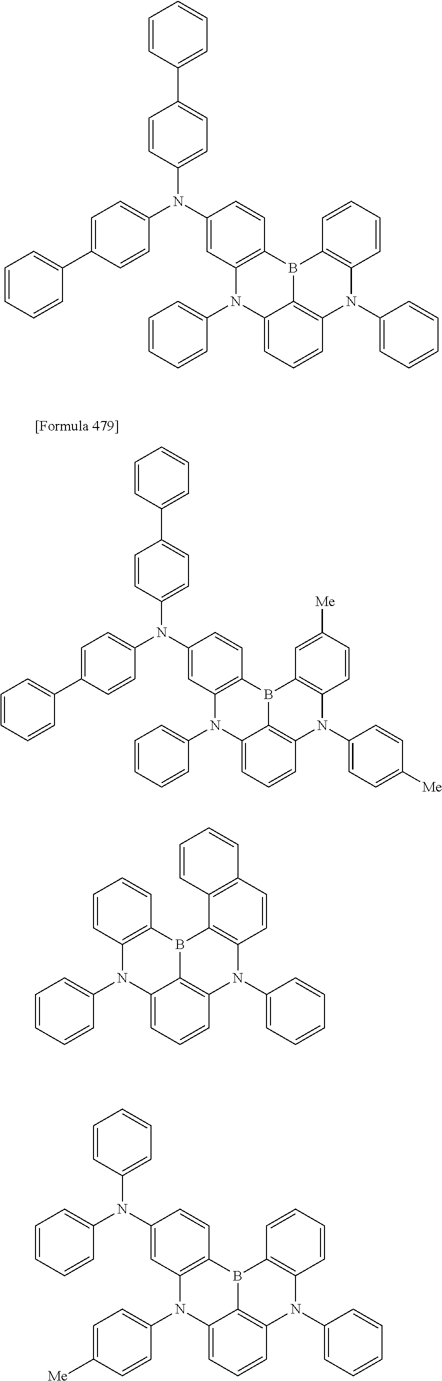 [SMILES: c1ccc(-c2ccc(N(c3ccc(-c4ccccc4)cc3)c3ccc4c(c3)N(c3ccccc3)c3cccc5c3B4c3ccccc3N5c3ccccc3)cc2)cc1 ; Cc1ccc(N2c3ccc(C)cc3B3c4ccc(N(c5ccc(-c6ccccc6)cc5)c5ccc(-c6ccccc6)cc5)cc4N(c4ccccc4)c4cccc2c43)cc1 ; c1ccc(N2c3ccccc3B3c4c2cccc4N(c2ccccc2)c2ccc4ccccc4c23)cc1 ; Cc1ccc(N2c3cc(N(c4ccccc4)c4ccccc4)ccc3B3c4ccccc4N(c4ccccc4)c4cccc2c43)cc1]

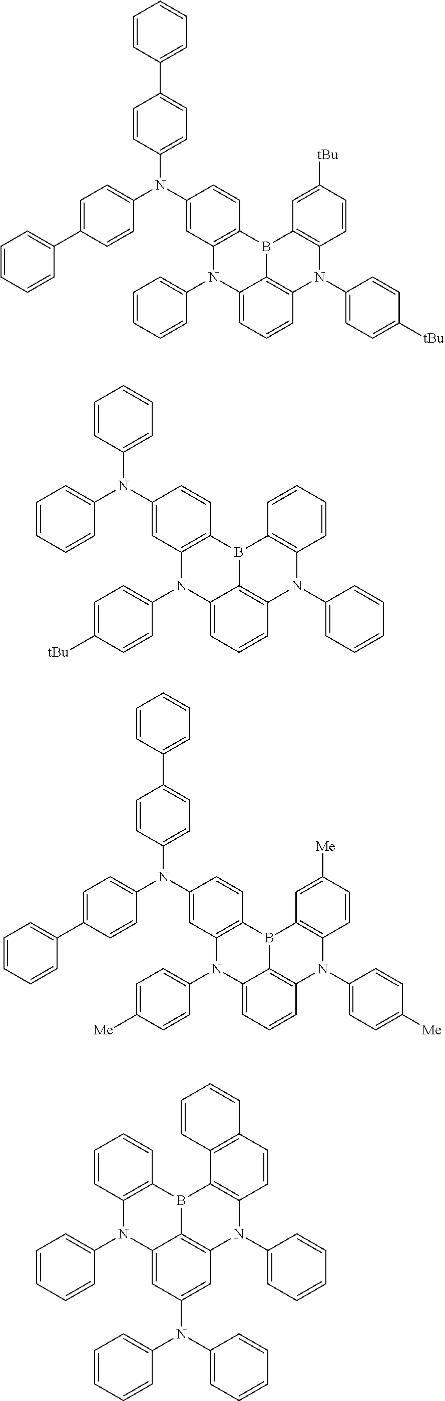 [SMILES: CC(C)(C)c1ccc(N2c3ccc(C(C)(C)C)cc3B3c4ccc(N(c5ccc(-c6ccccc6)cc5)c5ccc(-c6ccccc6)cc5)cc4N(c4ccccc4)c4cccc2c43)cc1 ; CC(C)(C)c1ccc(N2c3cc(N(c4ccccc4)c4ccccc4)ccc3B3c4ccccc4N(c4ccccc4)c4cccc2c43)cc1 ; Cc1ccc(N2c3ccc(C)cc3B3c4ccc(N(c5ccc(-c6ccccc6)cc5)c5ccc(-c6ccccc6)cc5)cc4N(c4ccc(C)cc4)c4cccc2c43)cc1 ; c1ccc(N(c2ccccc2)c2cc3c4c(c2)N(c2ccccc2)c2ccc5ccccc5c2B4c2ccccc2N3c2ccccc2)cc1]

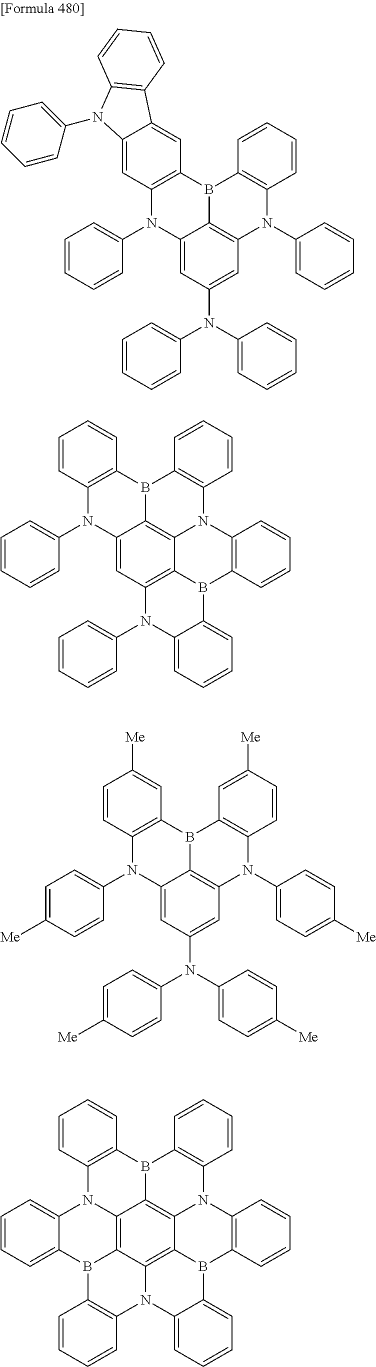 [SMILES: c1ccc(N(c2ccccc2)c2cc3c4c(c2)N(c2ccccc2)c2cc5c(cc2B4c2ccccc2N3c2ccccc2)c2ccccc2n5-c2ccccc2)cc1 ; c1ccc(N2c3ccccc3B3c4ccccc4N4c5ccccc5B5c6ccccc6N(c6ccccc6)c6cc2c3c4c65)cc1 ; Cc1ccc(N(c2ccc(C)cc2)c2cc3c4c(c2)N(c2ccc(C)cc2)c2ccc(C)cc2B4c2cc(C)ccc2N3c2ccc(C)cc2)cc1 ; c1ccc2c(c1)B1c3ccccc3N3c4ccccc4B4c5ccccc5N5c6ccccc6B6c7ccccc7N2c2c1c3c4c5c26]

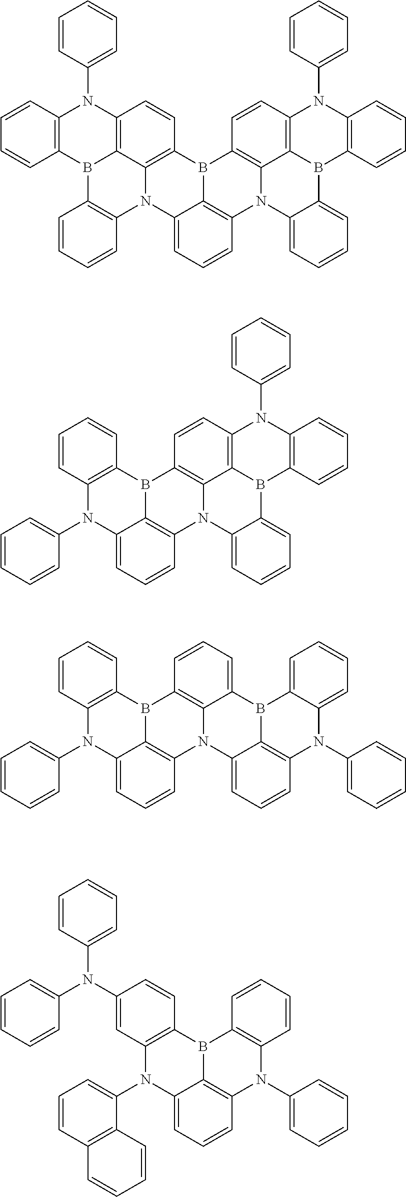 [SMILES: c1ccc(N2c3ccccc3B3c4ccccc4N4c5cccc6c5B(c5ccc2c3c54)c2ccc3c4c2N6c2ccccc2B4c2ccccc2N3c2ccccc2)cc1 ; c1ccc(N2c3ccccc3B3c4ccc5c6c4N(c4ccccc4B6c4ccccc4N5c4ccccc4)c4cccc2c43)cc1 ; c1ccc(N2c3ccccc3B3c4cccc5c4N(c4cccc2c43)c2cccc3c2B5c2ccccc2N3c2ccccc2)cc1 ; c1ccc(N(c2ccccc2)c2ccc3c(c2)N(c2cccc4ccccc24)c2cccc4c2B3c2ccccc2N4c2ccccc2)cc1]

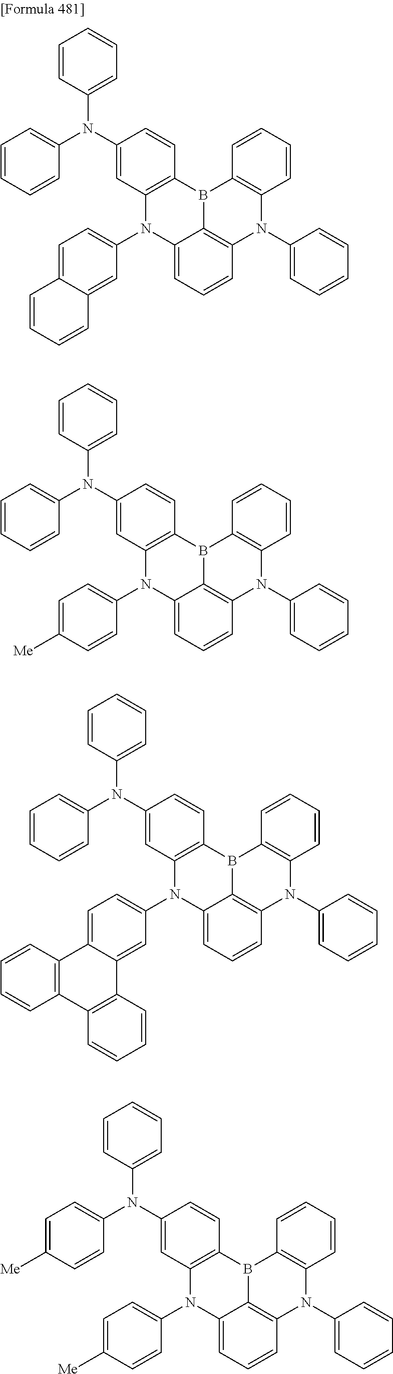

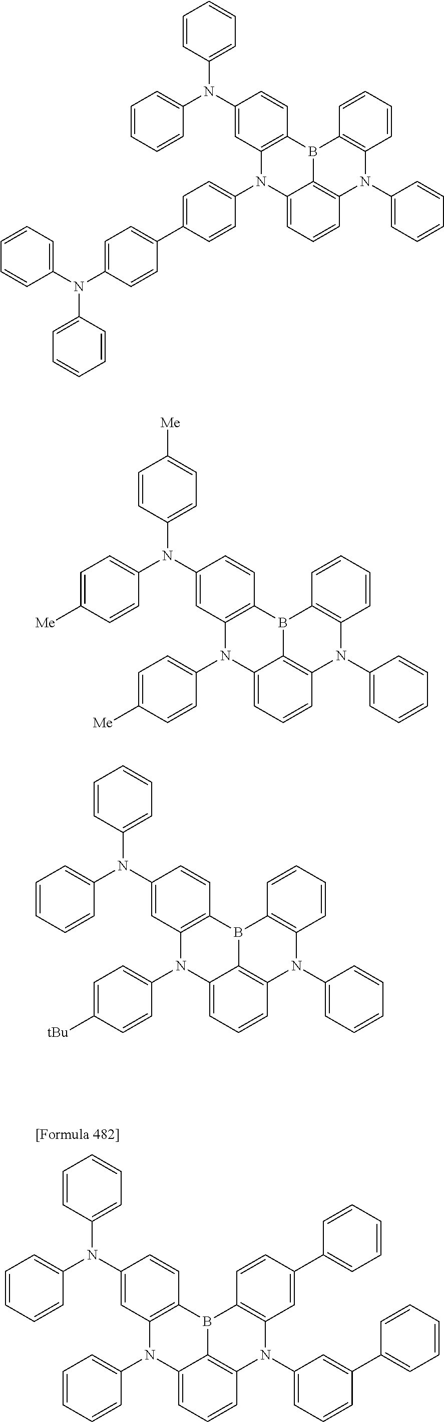

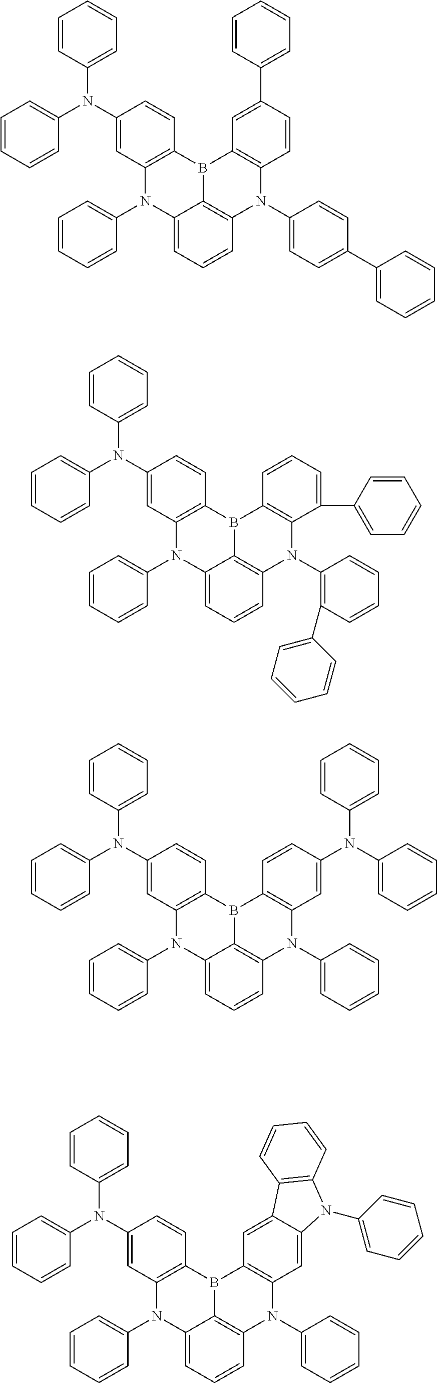 [SMILES: c1ccc(-c2ccc(N3c4ccc(-c5ccccc5)cc4B4c5ccc(N(c6ccccc6)c6ccccc6)cc5N(c5ccccc5)c5cccc3c54)cc2)cc1 ; c1ccc(-c2ccccc2N2c3cccc4c3B(c3ccc(N(c5ccccc5)c5ccccc5)cc3N4c3ccccc3)c3cccc(-c4ccccc4)c32)cc1 ; c1ccc(N(c2ccccc2)c2ccc3c(c2)N(c2ccccc2)c2cccc4c2B3c2ccc(N(c3ccccc3)c3ccccc3)cc2N4c2ccccc2)cc1 ; c1ccc(N(c2ccccc2)c2ccc3c(c2)N(c2ccccc2)c2cccc4c2B3c2cc3c5ccccc5n(-c5ccccc5)c3cc2N4c2ccccc2)cc1]

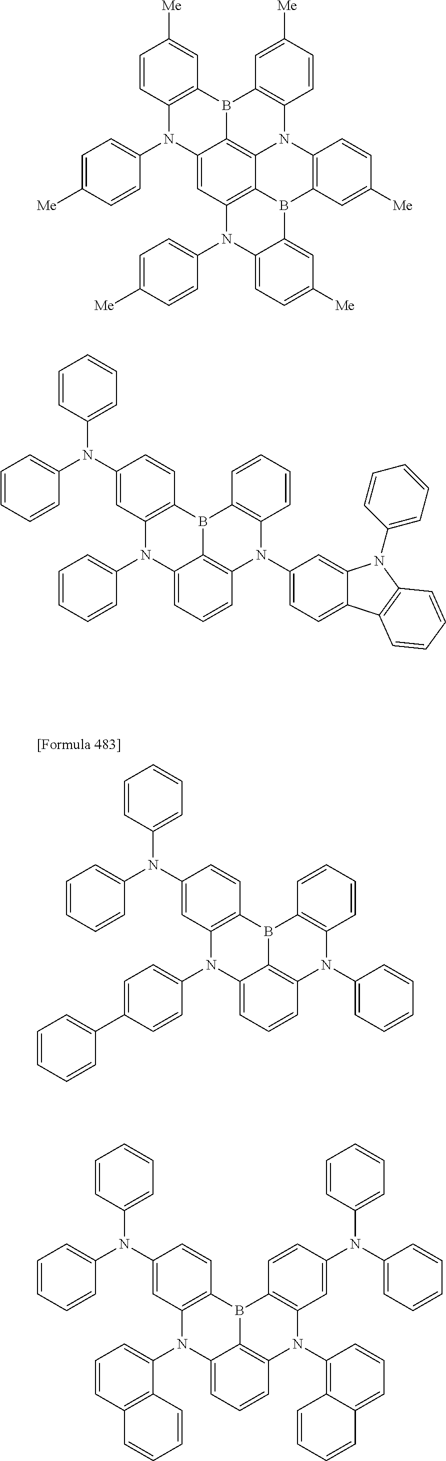 [SMILES: Cc1ccc(N2c3ccc(C)cc3B3c4cc(C)ccc4N4c5ccc(C)cc5B5c6cc(C)ccc6N(c6ccc(C)cc6)c6cc2c3c4c65)cc1 ; c1ccc(N(c2ccccc2)c2ccc3c(c2)N(c2ccccc2)c2cccc4c2B3c2ccccc2N4c2ccc3c4ccccc4n(-c4ccccc4)c3c2)cc1 ; c1ccc(-c2ccc(N3c4cc(N(c5ccccc5)c5ccccc5)ccc4B4c5ccccc5N(c5ccccc5)c5cccc3c54)cc2)cc1 ; c1ccc(N(c2ccccc2)c2ccc3c(c2)N(c2cccc4ccccc24)c2cccc4c2B3c2ccc(N(c3ccccc3)c3ccccc3)cc2N4c2cccc3ccccc23)cc1]

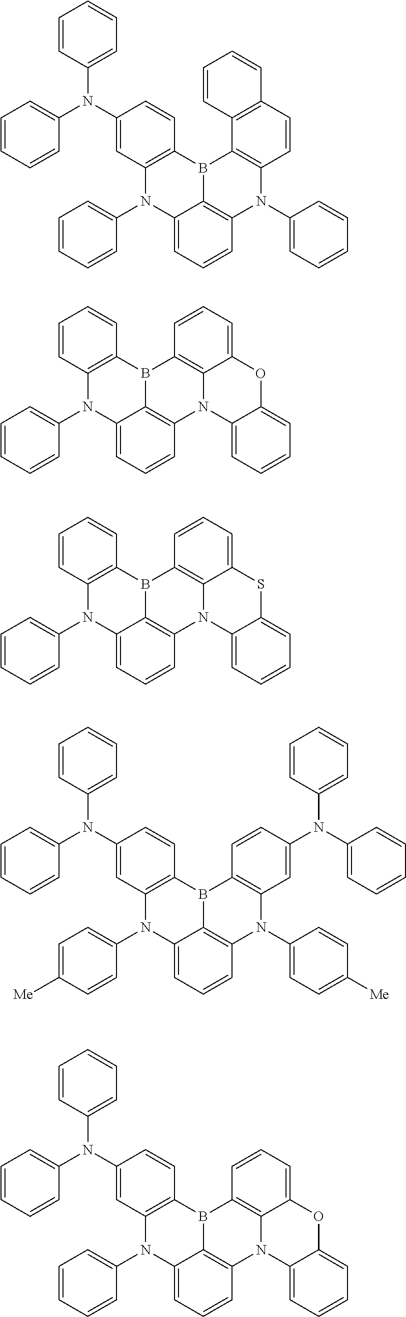

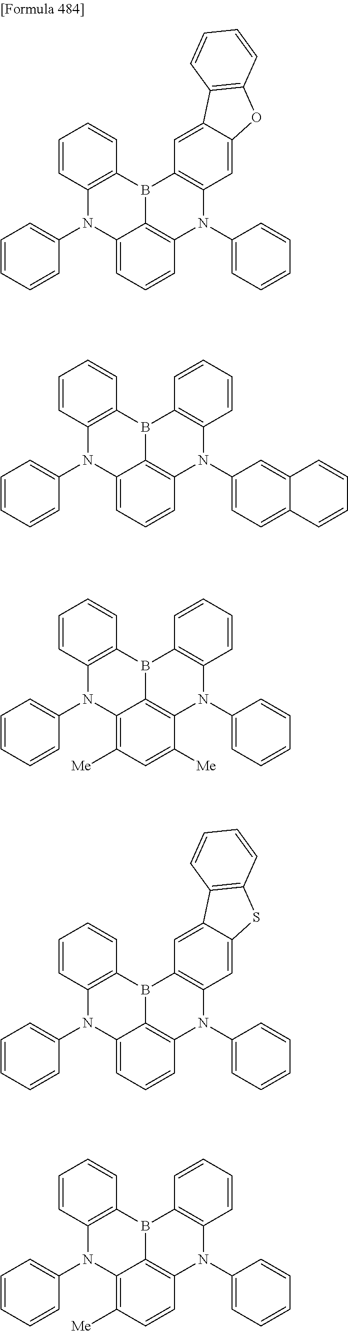 [SMILES: c1ccc(N2c3ccccc3B3c4cc5c(cc4N(c4ccccc4)c4cccc2c43)oc2ccccc25)cc1 ; c1ccc(N2c3ccccc3B3c4ccccc4N(c4ccc5ccccc5c4)c4cccc2c43)cc1 ; Cc1cc(C)c2c3c1N(c1ccccc1)c1ccccc1B3c1ccccc1N2c1ccccc1 ; c1ccc(N2c3ccccc3B3c4cc5c(cc4N(c4ccccc4)c4cccc2c43)sc2ccccc25)cc1 ; Cc1ccc2c3c1N(c1ccccc1)c1ccccc1B3c1ccccc1N2c1ccccc1]

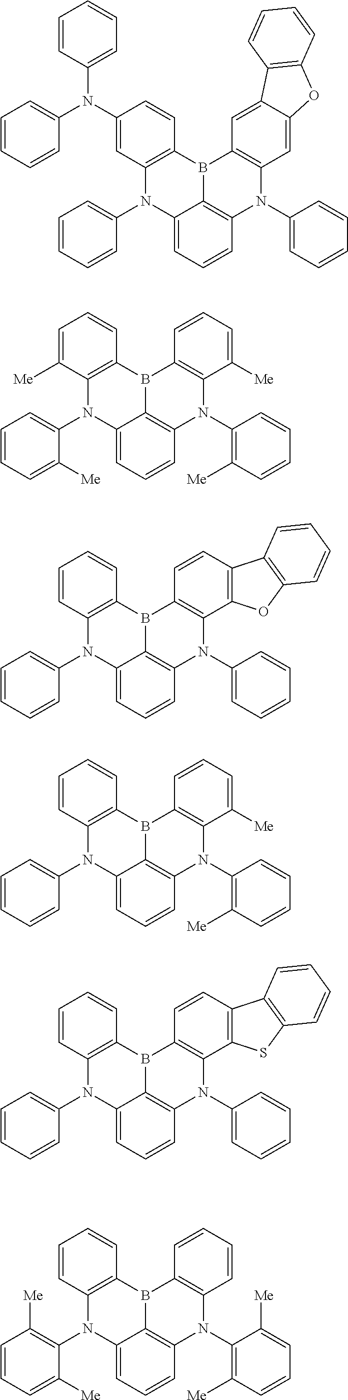

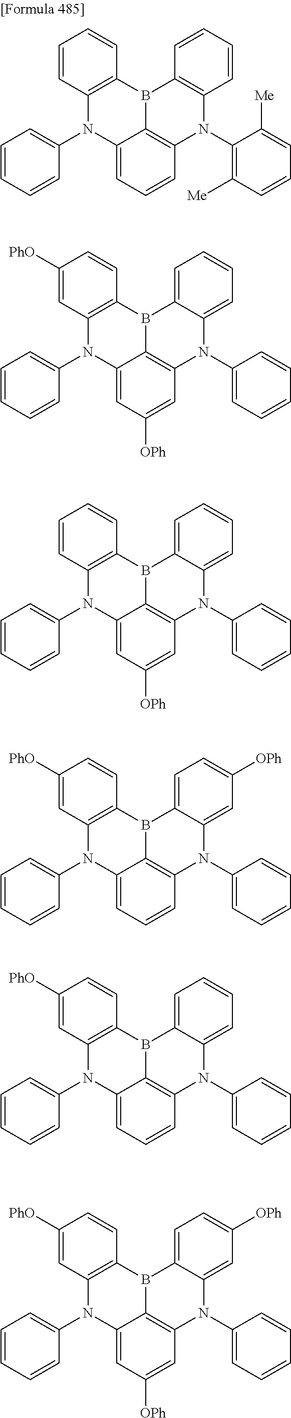 [SMILES: Cc1cccc(C)c1N1c2ccccc2B2c3ccccc3N(c3ccccc3)c3cccc1c32 ; c1ccc(Oc2ccc3c(c2)N(c2ccccc2)c2cc(Oc4ccccc4)cc4c2B3c2ccccc2N4c2ccccc2)cc1 ; c1ccc(Oc2cc3c4c(c2)N(c2ccccc2)c2ccccc2B4c2ccccc2N3c2ccccc2)cc1 ; c1ccc(Oc2ccc3c(c2)N(c2ccccc2)c2cccc4c2B3c2ccc(Oc3ccccc3)cc2N4c2ccccc2)cc1 ; c1ccc(Oc2ccc3c(c2)N(c2ccccc2)c2cccc4c2B3c2ccccc2N4c2ccccc2)cc1 ; c1ccc(Oc2ccc3c(c2)N(c2ccccc2)c2cc(Oc4ccccc4)cc4c2B3c2ccc(Oc3ccccc3)cc2N4c2ccccc2)cc1]

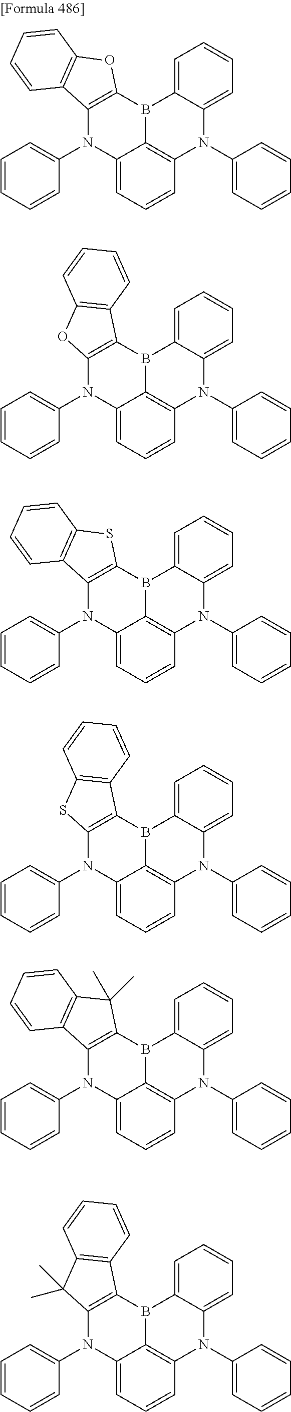

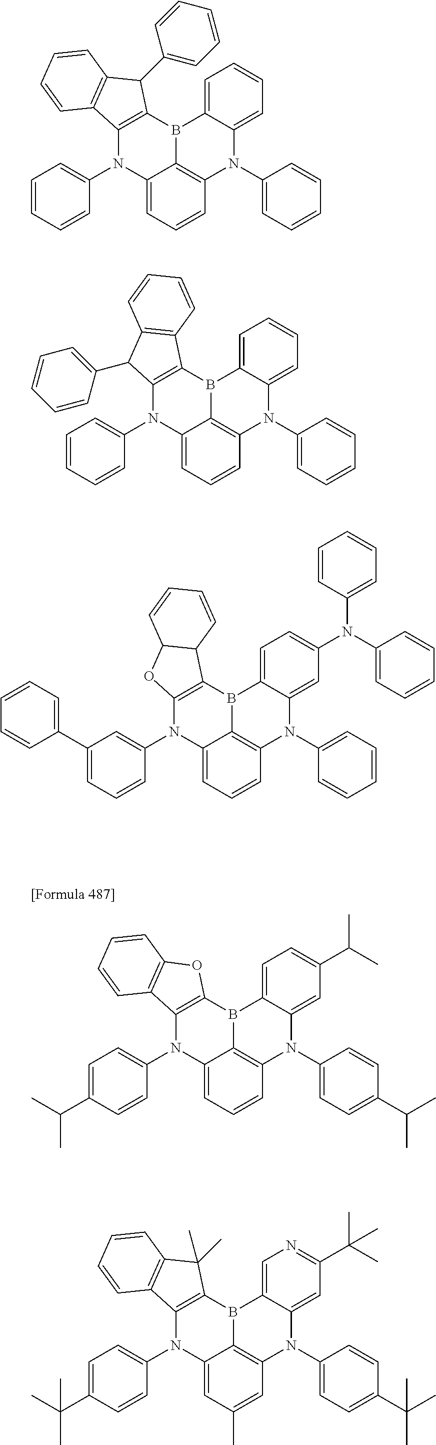

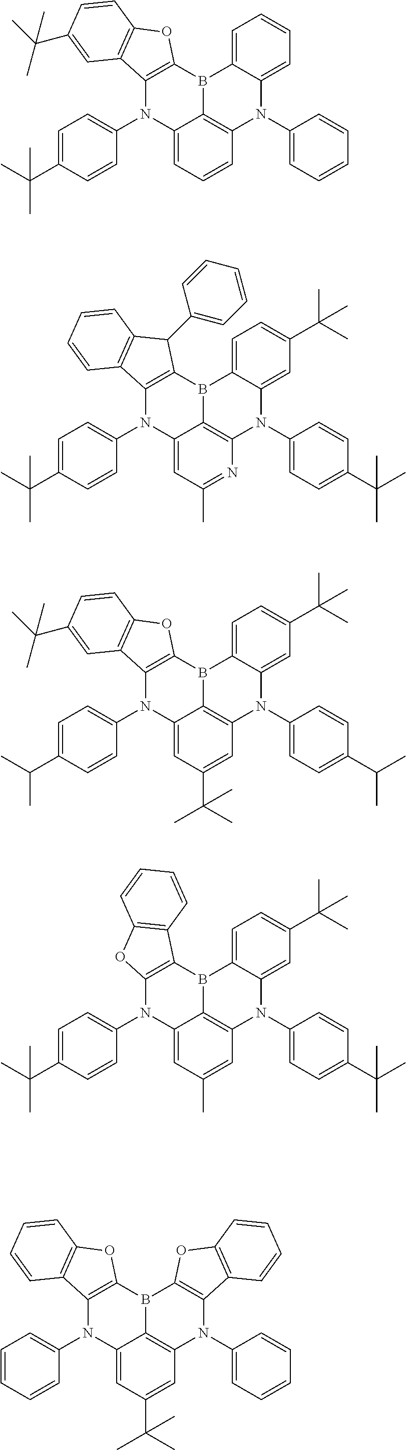

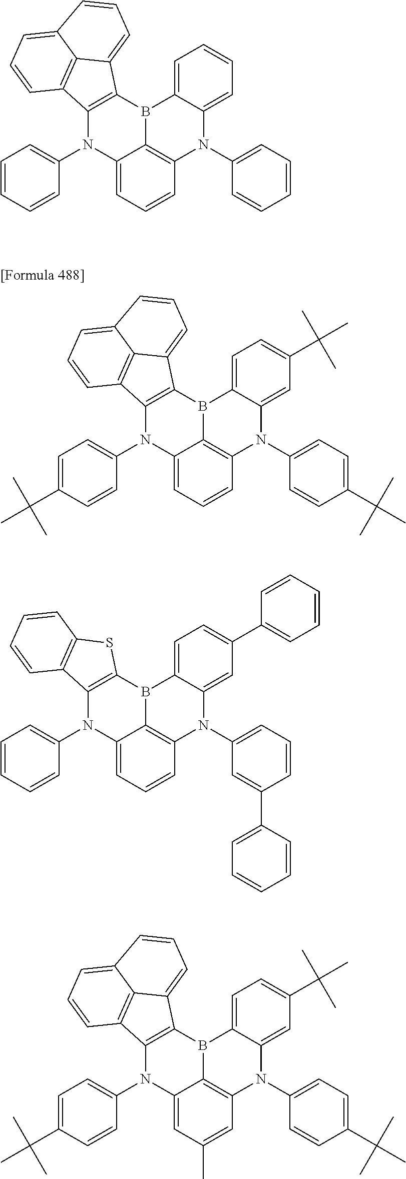

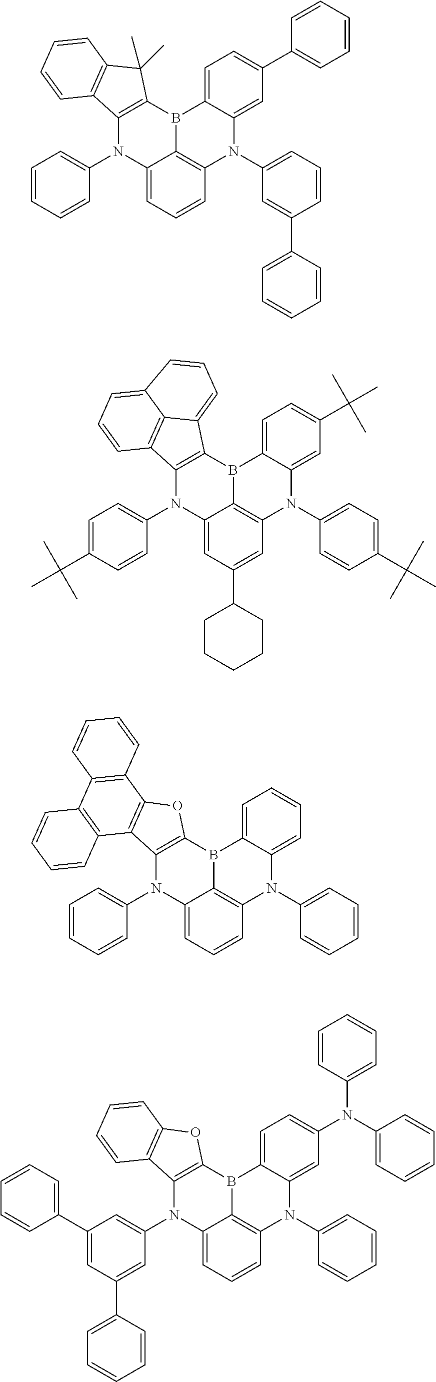 [SMILES: CC1(C)C2=C(c3ccccc31)N(c1ccccc1)c1cccc3c1B2c1ccc(-c2ccccc2)cc1N3c1cccc(-c2ccccc2)c1 ; CC(C)(C)c1ccc(N2C3=C(B4c5ccc(C(C)(C)C)cc5N(c5ccc(C(C)(C)C)cc5)c5cc(C6CCCCC6)cc2c54)c2cccc4cccc3c24)cc1 ; c1ccc(N2c3ccccc3B3c4oc5c6ccccc6c6ccccc6c5c4N(c4ccccc4)c4cccc2c43)cc1 ; c1ccc(-c2cc(-c3ccccc3)cc(N3c4cccc5c4B(c4ccc(N(c6ccccc6)c6ccccc6)cc4N5c4ccccc4)c4oc5ccccc5c43)c2)cc1]

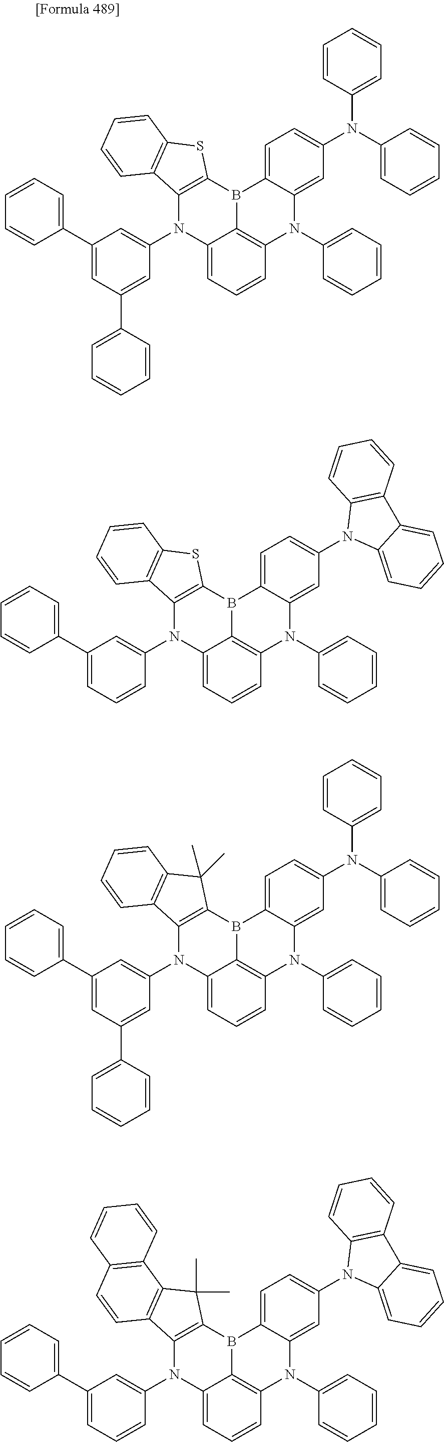 [SMILES: c1ccc(-c2cc(-c3ccccc3)cc(N3c4cccc5c4B(c4ccc(N(c6ccccc6)c6ccccc6)cc4N5c4ccccc4)c4sc5ccccc5c43)c2)cc1 ; c1ccc(-c2cccc(N3c4cccc5c4B(c4ccc(-n6c7ccccc7c7ccccc76)cc4N5c4ccccc4)c4sc5ccccc5c43)c2)cc1 ; CC1(C)C2=C(c3ccccc31)N(c1cc(-c3ccccc3)cc(-c3ccccc3)c1)c1cccc3c1B2c1ccc(N(c2ccccc2)c2ccccc2)cc1N3c1ccccc1 ; CC1(C)C2=C(c3ccc4ccccc4c31)N(c1cccc(-c3ccccc3)c1)c1cccc3c1B2c1ccc(-n2c4ccccc4c4ccccc42)cc1N3c1ccccc1]

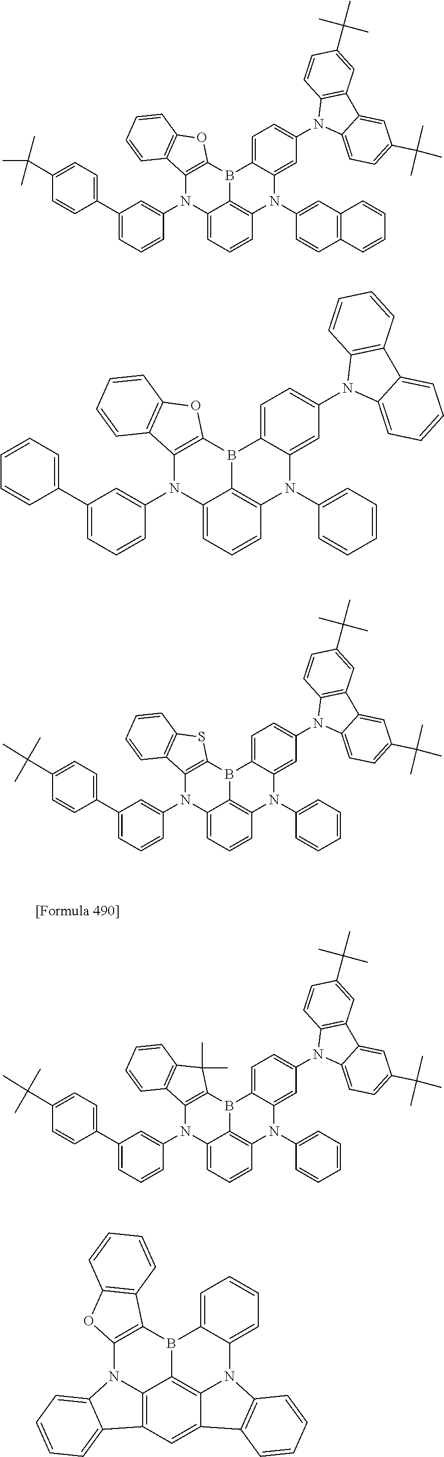

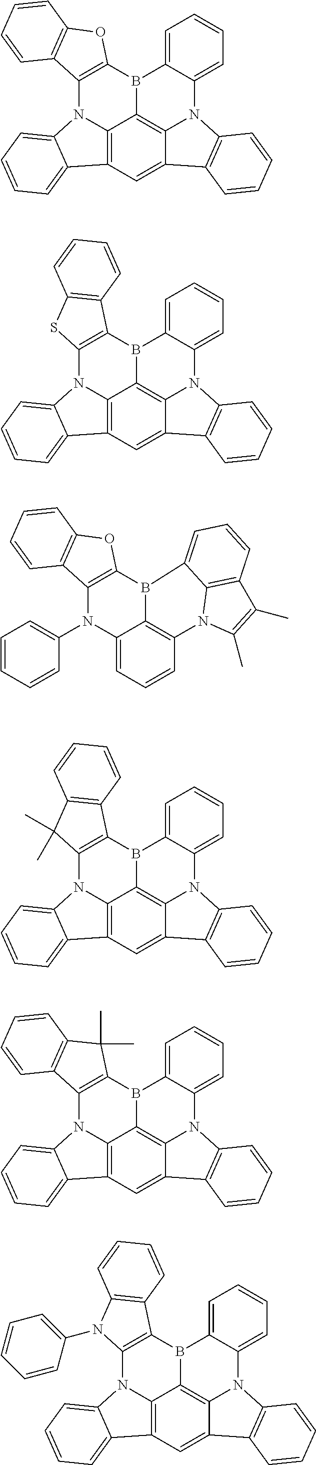

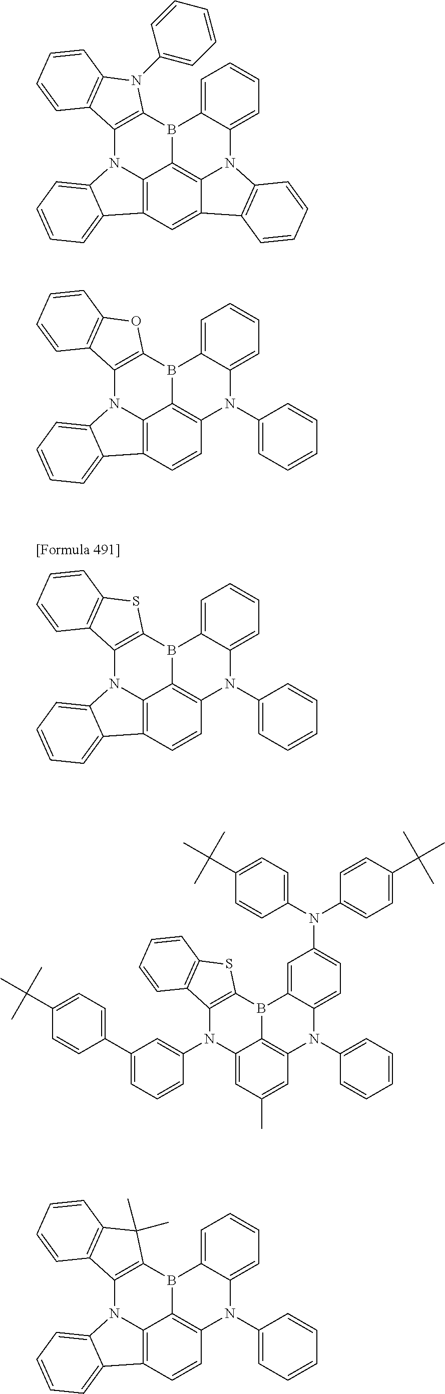 [SMILES: c1ccc(-n2c3c(c4ccccc42)-n2c4ccccc4c4cc5c6ccccc6n6c5c(c42)B3c2ccccc2-6)cc1 ; c1ccc(N2c3ccccc3B3c4oc5ccccc5c4-n4c5ccccc5c5ccc2c3c54)cc1 ; c1ccc(N2c3ccccc3B3c4sc5ccccc5c4-n4c5ccccc5c5ccc2c3c54)cc1 ; Cc1cc2c3c(c1)N(c1cccc(-c4ccc(C(C)(C)C)cc4)c1)c1c(sc4ccccc14)B3c1cc(N(c3ccc(C(C)(C)C)cc3)c3ccc(C(C)(C)C)cc3)ccc1N2c1ccccc1 ; CC1(C)C2=C(c3ccccc31)n1c3ccccc3c3ccc4c(c31)B2c1ccccc1N4c1ccccc1]

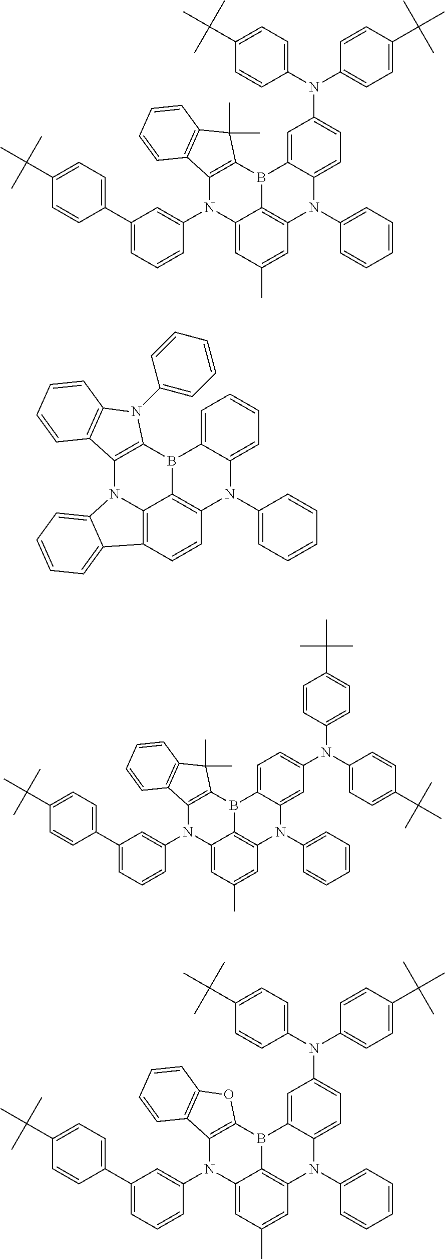

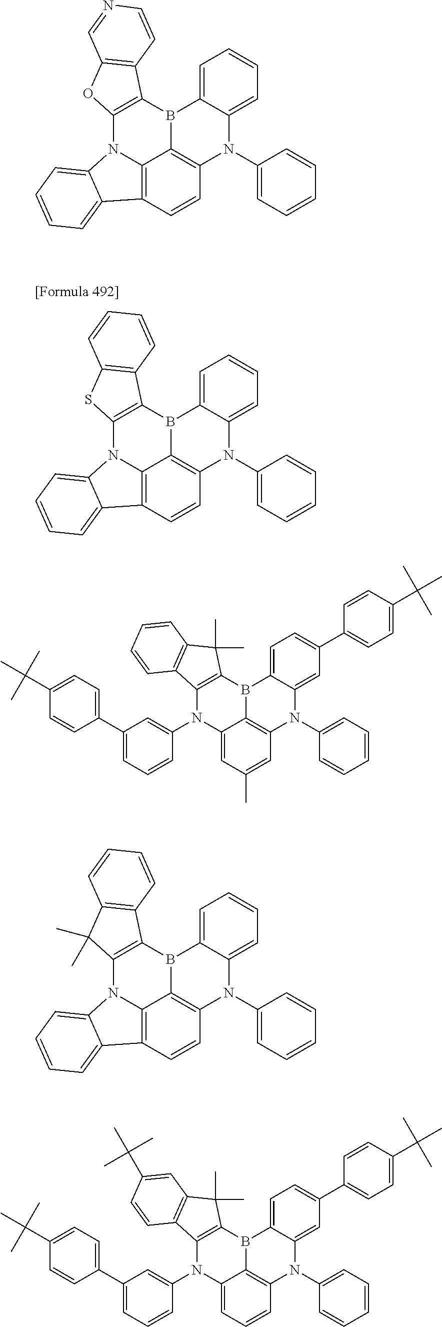

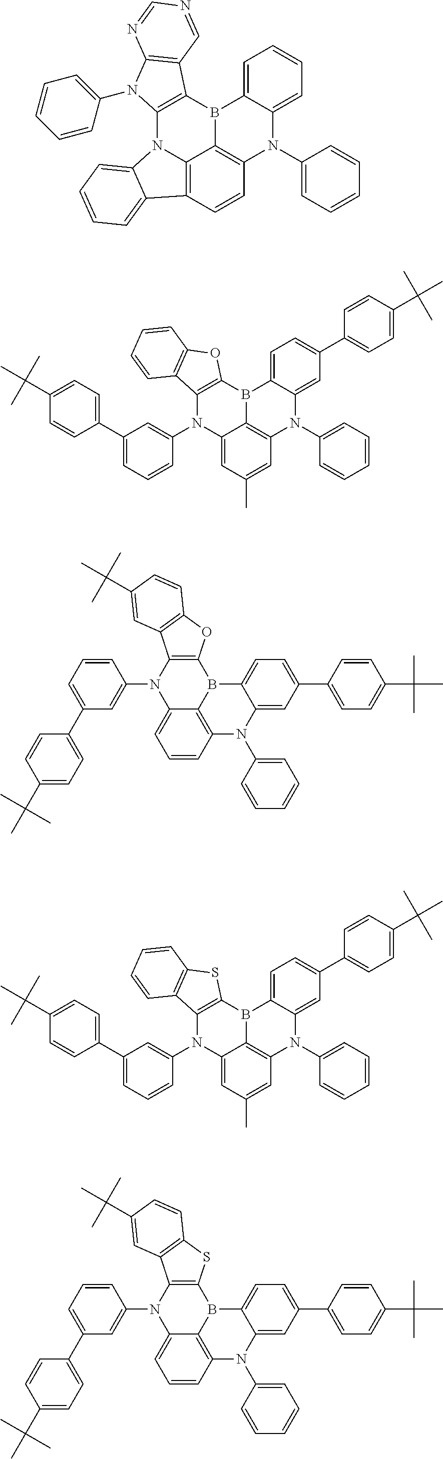

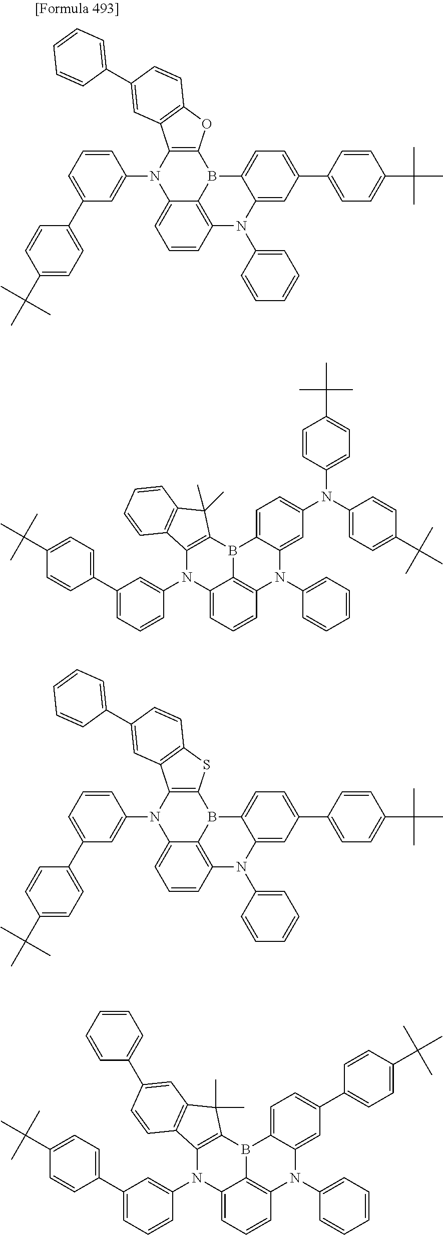

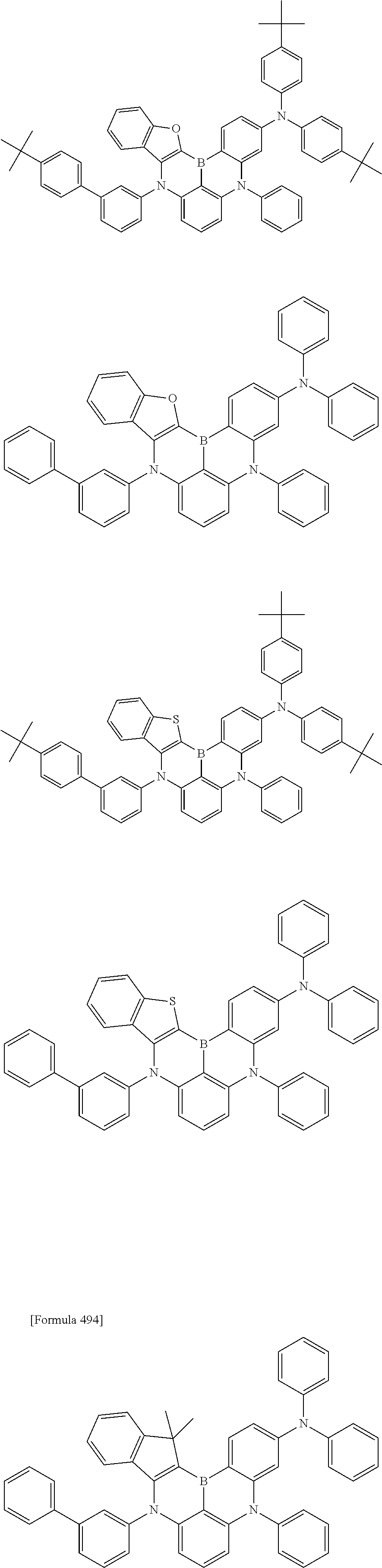

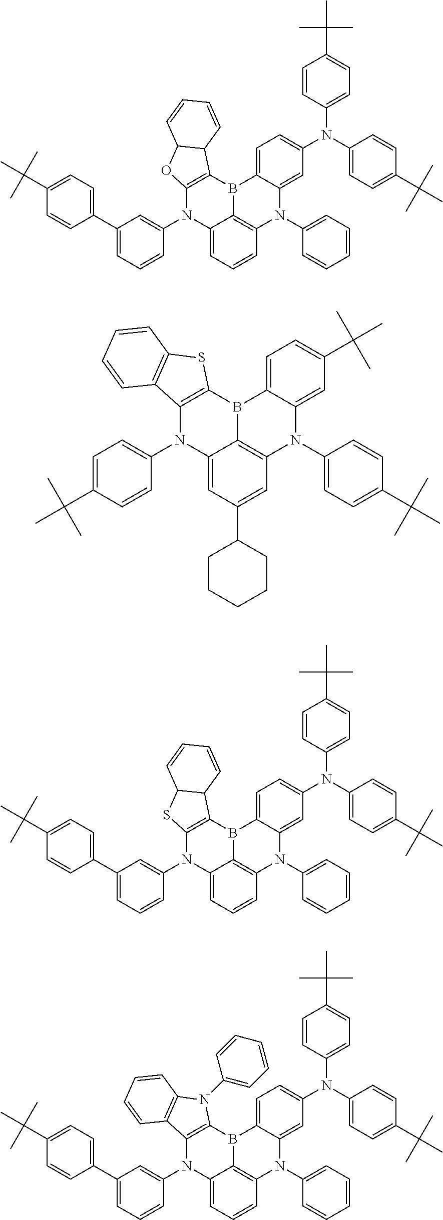

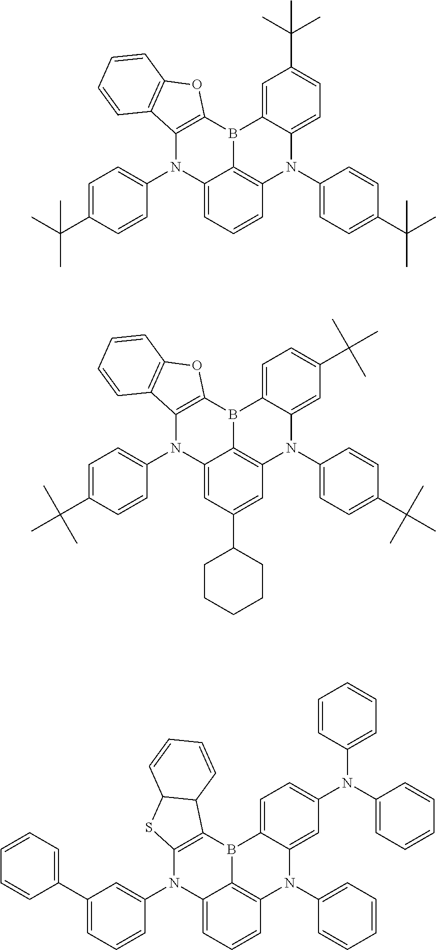

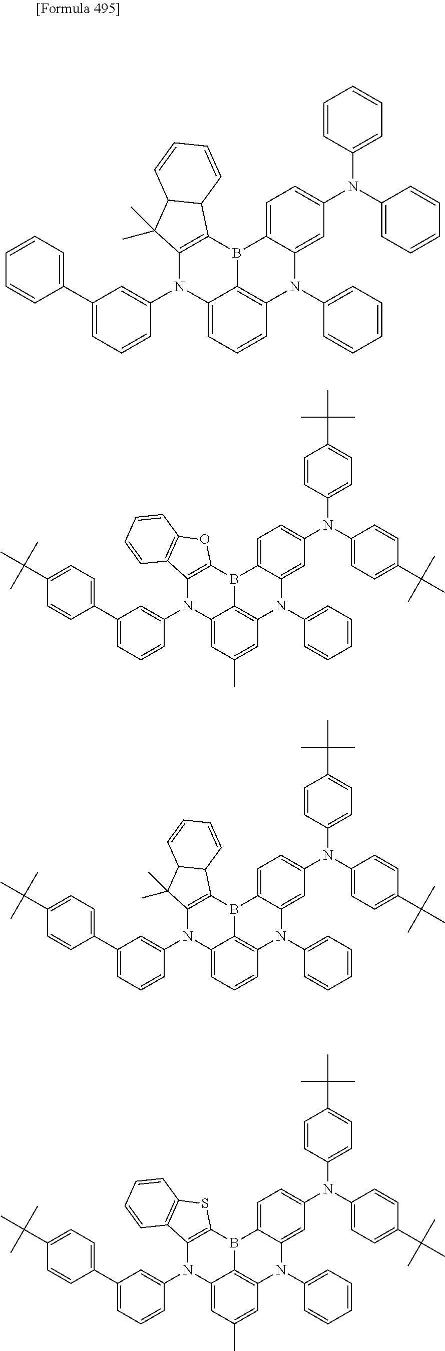

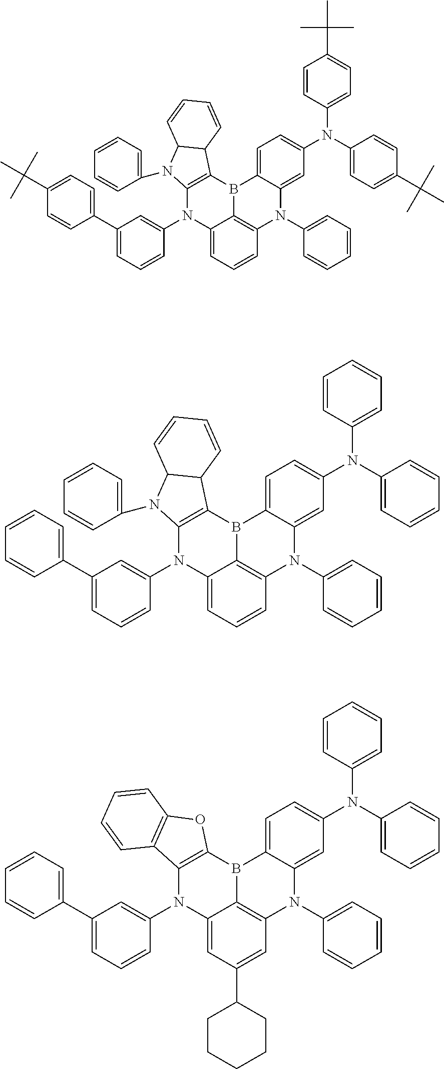 [SMILES: CC(C)(C)c1ccc(-c2cccc(N3C4=C(B5c6ccc(N(c7ccc(C(C)(C)C)cc7)c7ccc(C(C)(C)C)cc7)cc6N(c6ccccc6)c6cccc3c65)C3C=CC=CC3N4c3ccccc3)c2)cc1 ; C1=CC2C3=C(N(c4cccc(-c5ccccc5)c4)c4cccc5c4B3c3ccc(N(c4ccccc4)c4ccccc4)cc3N5c3ccccc3)N(c3ccccc3)C2C=C1 ; c1ccc(-c2cccc(N3c4cc(C5CCCCC5)cc5c4B(c4ccc(N(c6ccccc6)c6ccccc6)cc4N5c4ccccc4)c4oc5ccccc5c43)c2)cc1]

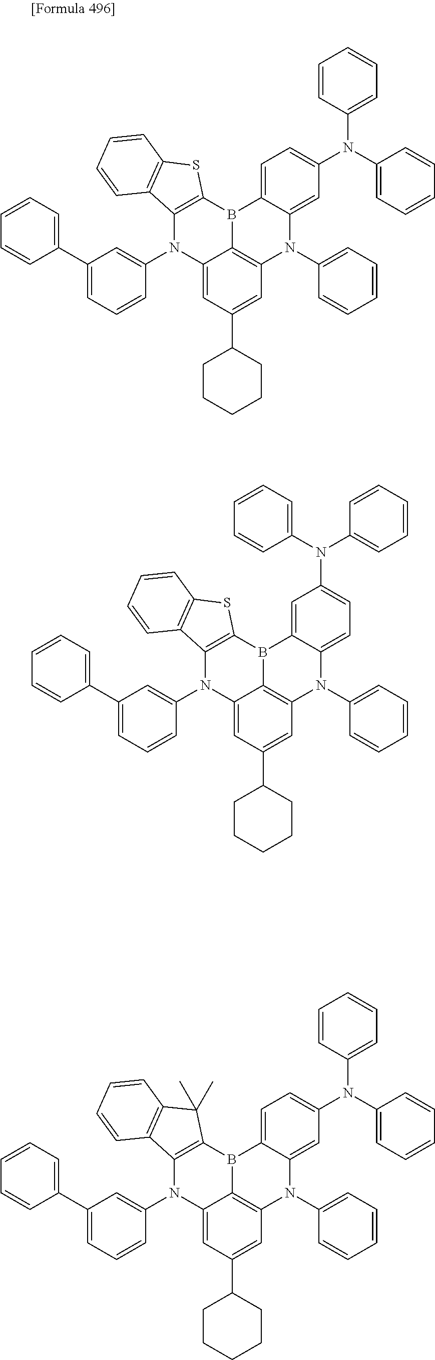 [SMILES: c1ccc(-c2cccc(N3c4cc(C5CCCCC5)cc5c4B(c4ccc(N(c6ccccc6)c6ccccc6)cc4N5c4ccccc4)c4sc5ccccc5c43)c2)cc1 ; c1ccc(-c2cccc(N3c4cc(C5CCCCC5)cc5c4B(c4cc(N(c6ccccc6)c6ccccc6)ccc4N5c4ccccc4)c4sc5ccccc5c43)c2)cc1 ; CC1(C)C2=C(c3ccccc31)N(c1cccc(-c3ccccc3)c1)c1cc(C3CCCCC3)cc3c1B2c1ccc(N(c2ccccc2)c2ccccc2)cc1N3c1ccccc1]

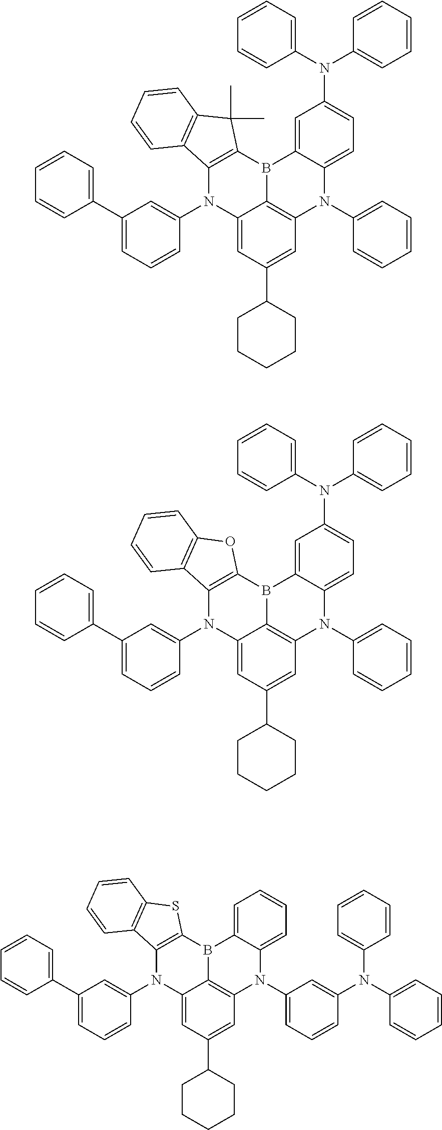 [SMILES: CC1(C)C2=C(c3ccccc31)N(c1cccc(-c3ccccc3)c1)c1cc(C3CCCCC3)cc3c1B2c1cc(N(c2ccccc2)c2ccccc2)ccc1N3c1ccccc1 ; c1ccc(-c2cccc(N3c4cc(C5CCCCC5)cc5c4B(c4cc(N(c6ccccc6)c6ccccc6)ccc4N5c4ccccc4)c4oc5ccccc5c43)c2)cc1 ; c1ccc(-c2cccc(N3c4cc(C5CCCCC5)cc5c4B(c4ccccc4N5c4cccc(N(c5ccccc5)c5ccccc5)c4)c4sc5ccccc5c43)c2)cc1]

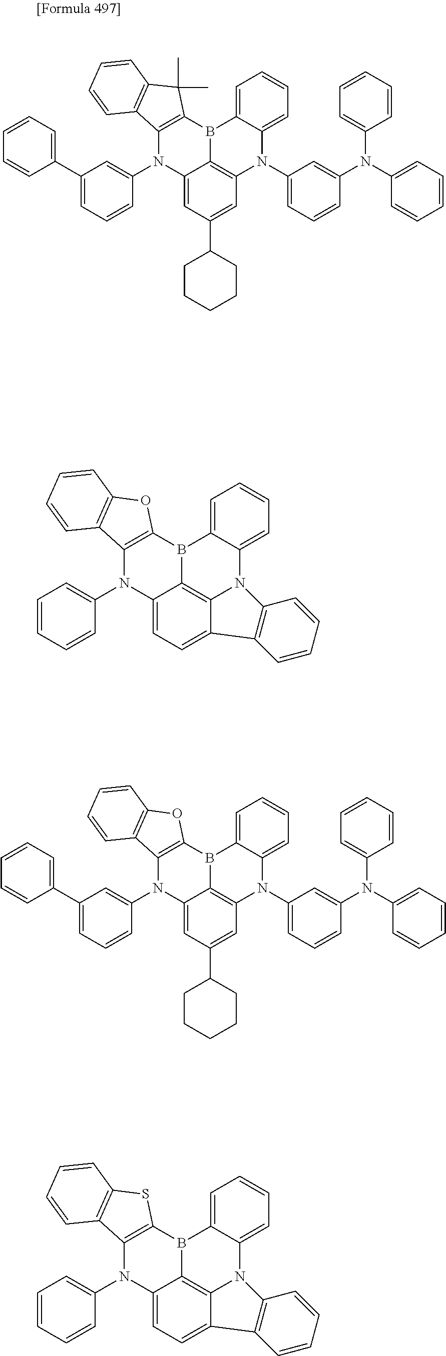 [SMILES: CC1(C)C2=C(c3ccccc31)N(c1cccc(-c3ccccc3)c1)c1cc(C3CCCCC3)cc3c1B2c1ccccc1N3c1cccc(N(c2ccccc2)c2ccccc2)c1 ; c1ccc(N2c3ccc4c5ccccc5n5c4c3B(c3ccccc3-5)c3oc4ccccc4c32)cc1 ; c1ccc(-c2cccc(N3c4cc(C5CCCCC5)cc5c4B(c4ccccc4N5c4cccc(N(c5ccccc5)c5ccccc5)c4)c4oc5ccccc5c43)c2)cc1 ; c1ccc(N2c3ccc4c5ccccc5n5c4c3B(c3ccccc3-5)c3sc4ccccc4c32)cc1]

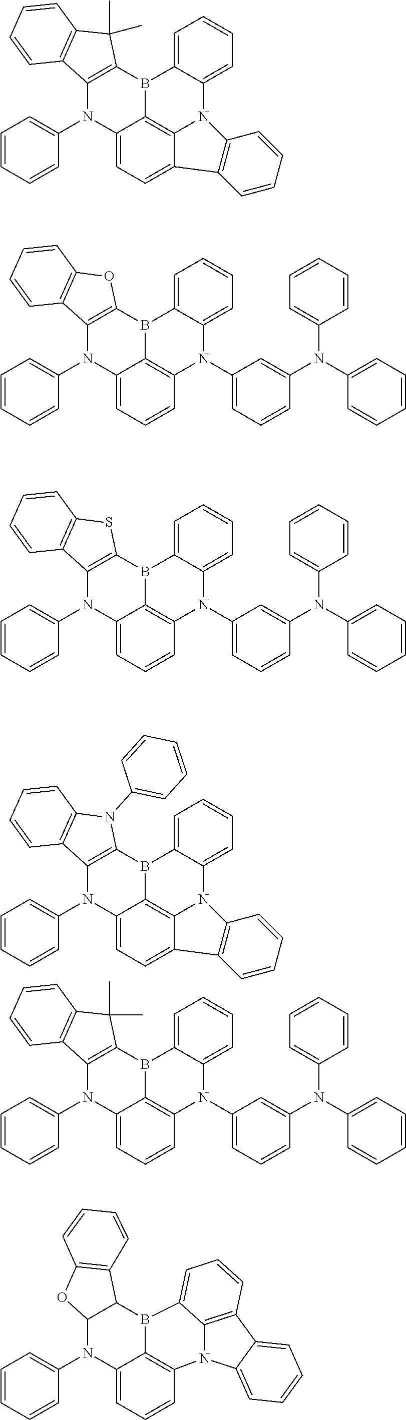

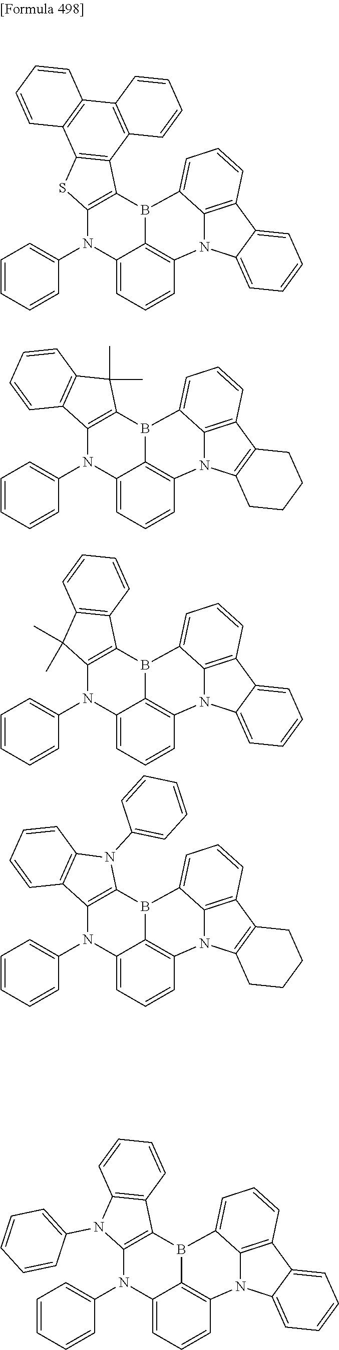

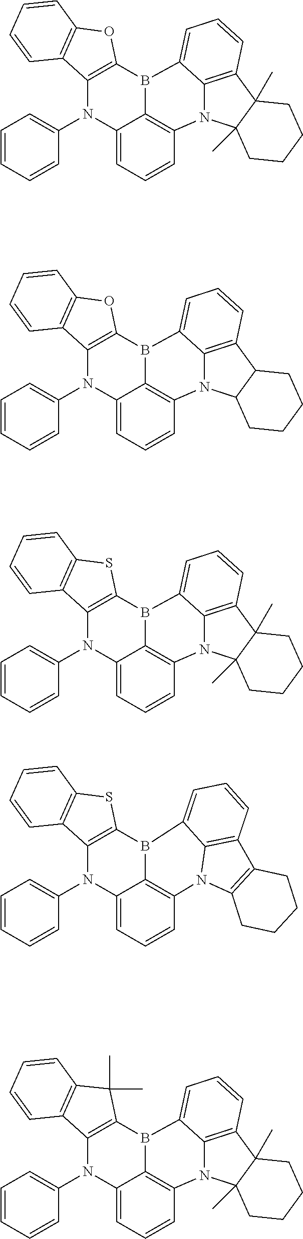 [SMILES: CC12CCCCC1(C)N1c3cccc4c3B(c3cccc2c31)c1oc2ccccc2c1N4c1ccccc1 ; c1ccc(N2c3cccc4c3B(c3cccc5c3N4C3CCCCC53)c3oc4ccccc4c32)cc1 ; CC12CCCCC1(C)N1c3cccc4c3B(c3cccc2c31)c1sc2ccccc2c1N4c1ccccc1 ; c1ccc(N2c3cccc4c3B(c3sc5ccccc5c32)c2cccc3c5c(n-4c23)CCCC5)cc1 ; CC1(C)C2=C(c3ccccc31)N(c1ccccc1)c1cccc3c1B2c1cccc2c1N3C1(C)CCCCC21C]

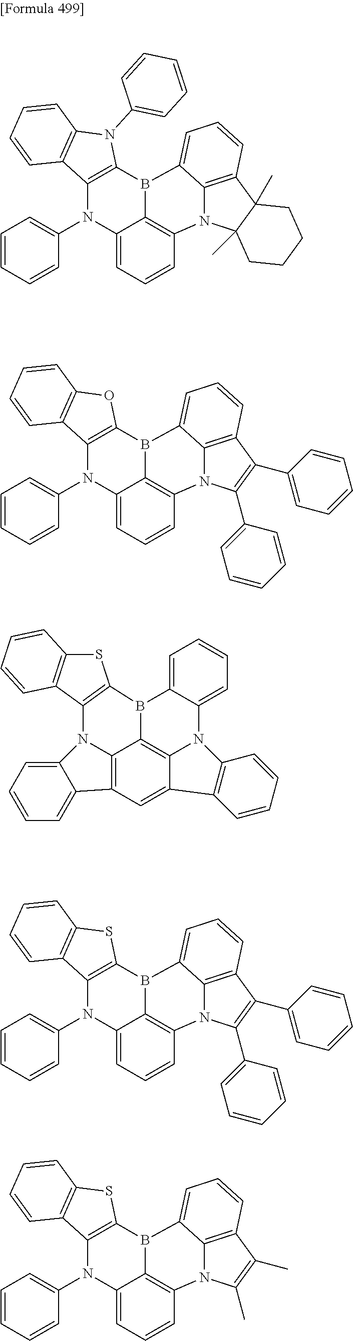 [SMILES: CC12CCCCC1(C)N1c3cccc4c3B(c3cccc2c31)c1c(c2ccccc2n1-c1ccccc1)N4c1ccccc1 ; c1ccc(-c2c(-c3ccccc3)n3c4c(cccc24)B2c4oc5ccccc5c4N(c4ccccc4)c4cccc-3c42)cc1 ; c1ccc2c(c1)B1c3sc4ccccc4c3-n3c4ccccc4c4cc5c6ccccc6n-2c5c1c43 ; c1ccc(-c2c(-c3ccccc3)n3c4c(cccc24)B2c4sc5ccccc5c4N(c4ccccc4)c4cccc-3c42)cc1 ; Cc1c(C)n2c3c(cccc13)B1c3sc4ccccc4c3N(c3ccccc3)c3cccc-2c31]

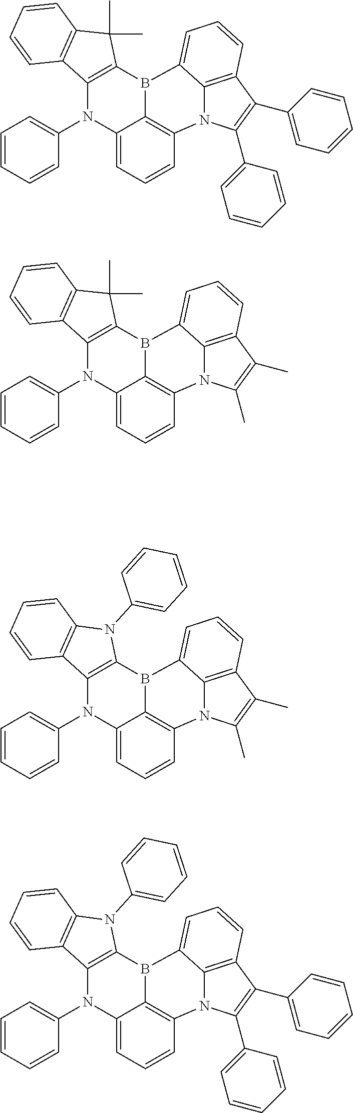 [SMILES: CC1(C)C2=C(c3ccccc31)N(c1ccccc1)c1cccc3c1B2c1cccc2c(-c4ccccc4)c(-c4ccccc4)n-3c12 ; Cc1c(C)n2c3c(cccc13)B1C3=C(c4ccccc4C3(C)C)N(c3ccccc3)c3cccc-2c31 ; Cc1c(C)n2c3c(cccc13)B1c3c(cccc3-2)N(c2ccccc2)c2c1n(-c1ccccc1)c1ccccc21 ; c1ccc(-c2c(-c3ccccc3)n3c4c(cccc24)B2c4c(cccc4-3)N(c3ccccc3)c3c2n(-c2ccccc2)c2ccccc32)cc1]

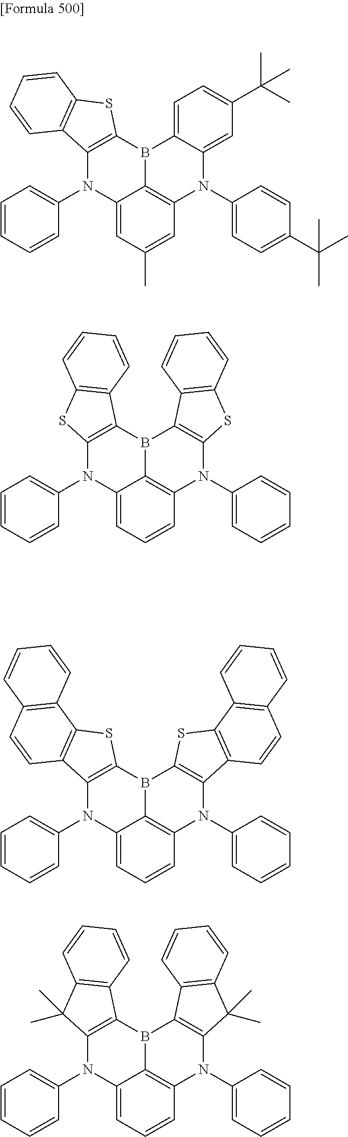 [SMILES: Cc1cc2c3c(c1)N(c1ccccc1)c1c(sc4ccccc14)B3c1ccc(C(C)(C)C)cc1N2c1ccc(C(C)(C)C)cc1 ; c1ccc(N2c3cccc4c3B(c3c2sc2ccccc32)c2c(sc3ccccc23)N4c2ccccc2)cc1 ; c1ccc(N2c3cccc4c3B(c3sc5c(ccc6ccccc65)c32)c2sc3c(ccc5ccccc53)c2N4c2ccccc2)cc1 ; CC1(C)C2=C(B3C4=C(N(c5ccccc5)c5cccc(c53)N2c2ccccc2)C(C)(C)c2ccccc24)c2ccccc21]

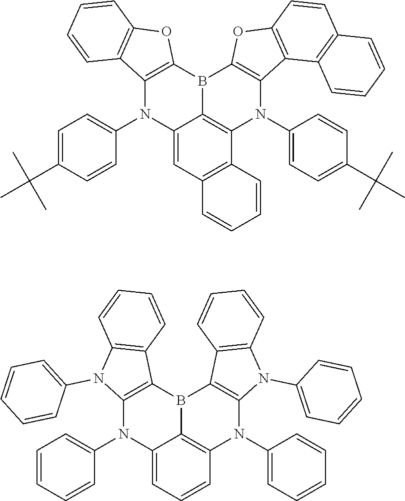 [SMILES: CC(C)(C)c1ccc(N2c3cc4ccccc4c4c3B(c3oc5ccccc5c32)c2oc3ccc5ccccc5c3c2N4c2ccc(C(C)(C)C)cc2)cc1 ; c1ccc(N2c3cccc4c3B(c3c2n(-c2ccccc2)c2ccccc32)c2c(n(-c3ccccc3)c3ccccc23)N4c2ccccc2)cc1]

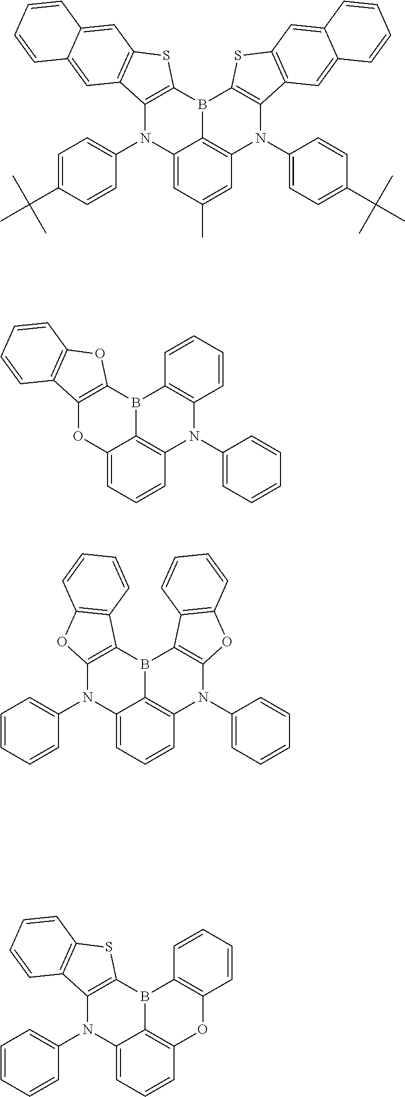 [SMILES: Cc1cc2c3c(c1)N(c1ccc(C(C)(C)C)cc1)c1c(sc4cc5ccccc5cc14)B3c1sc3cc4ccccc4cc3c1N2c1ccc(C(C)(C)C)cc1 ; c1ccc(N2c3ccccc3B3c4oc5ccccc5c4Oc4cccc2c43)cc1 ; c1ccc(N2c3cccc4c3B(c3c2oc2ccccc32)c2c(oc3ccccc23)N4c2ccccc2)cc1 ; c1ccc(N2c3cccc4c3B(c3ccccc3O4)c3sc4ccccc4c32)cc1]

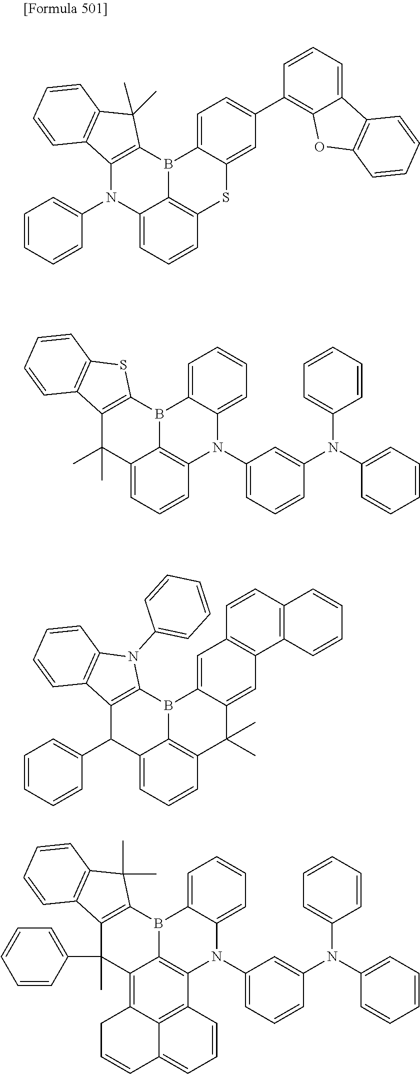

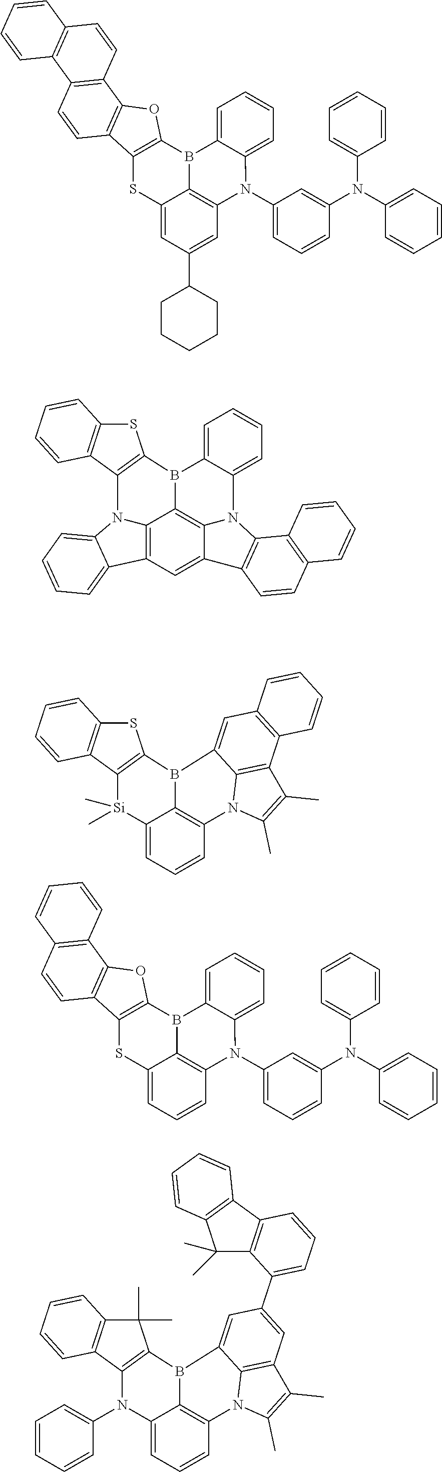

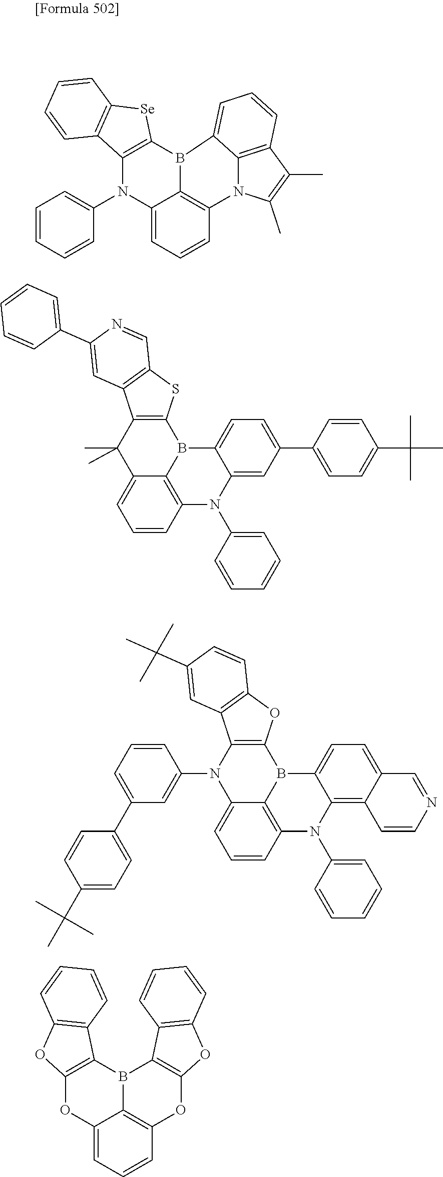

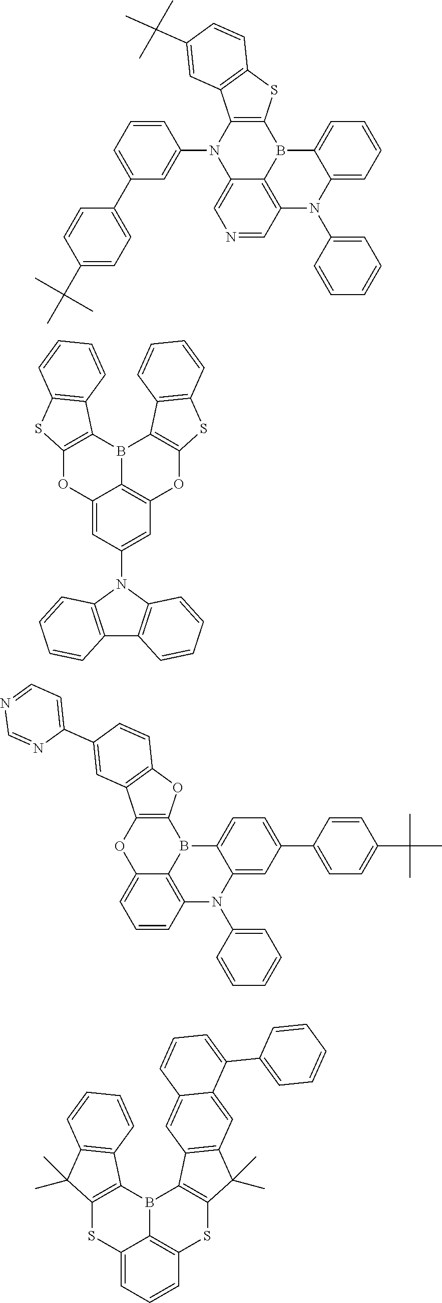

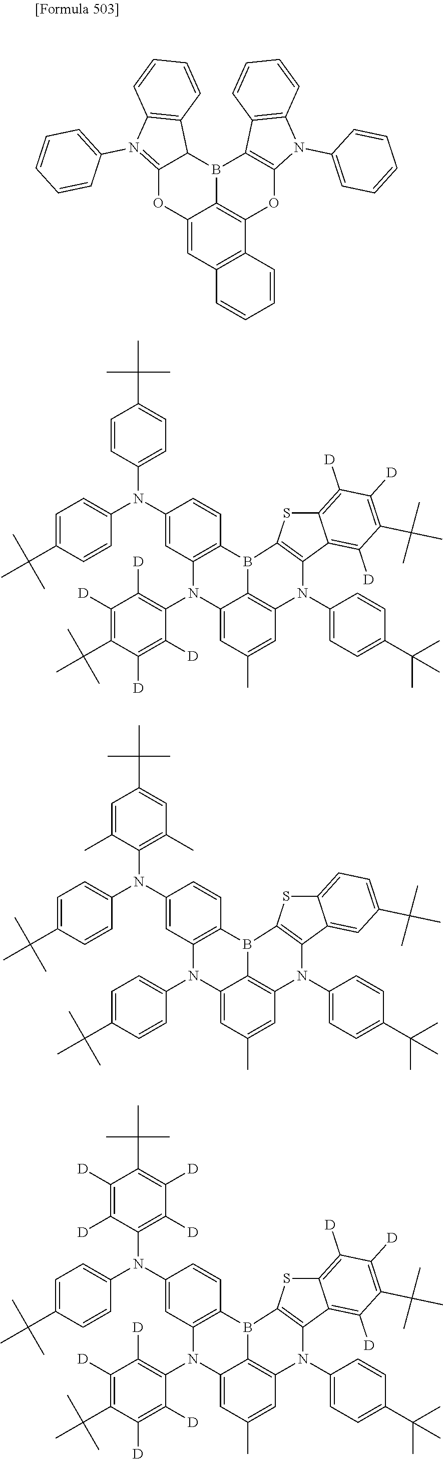

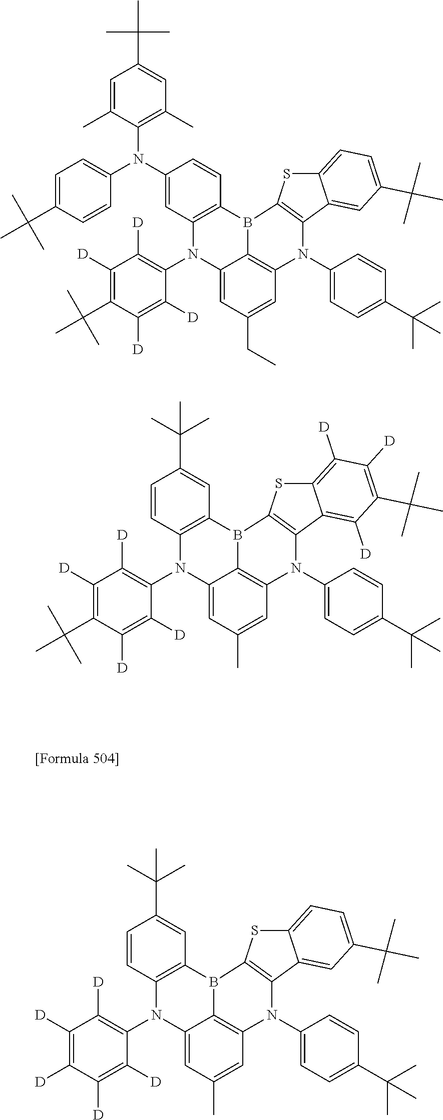

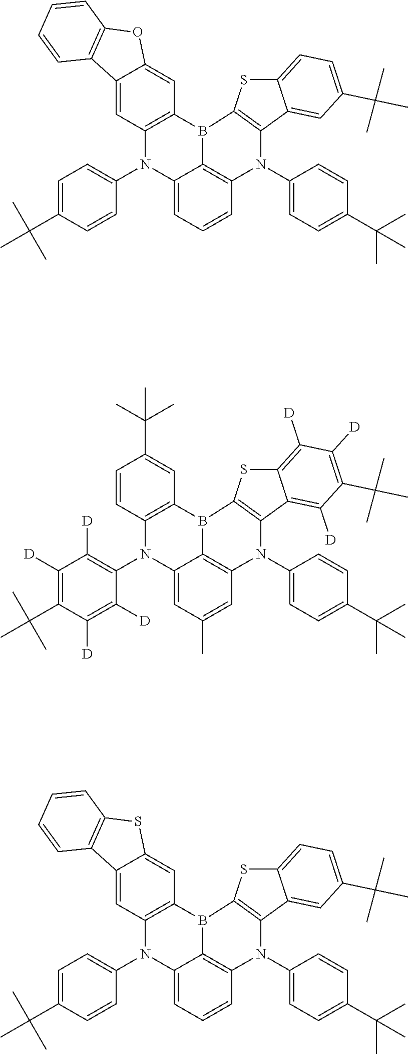

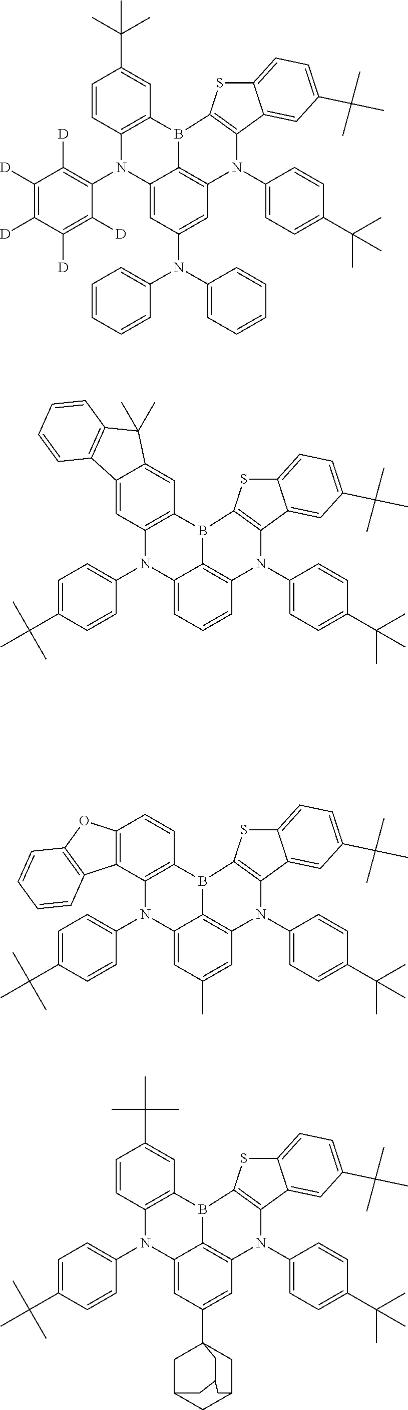

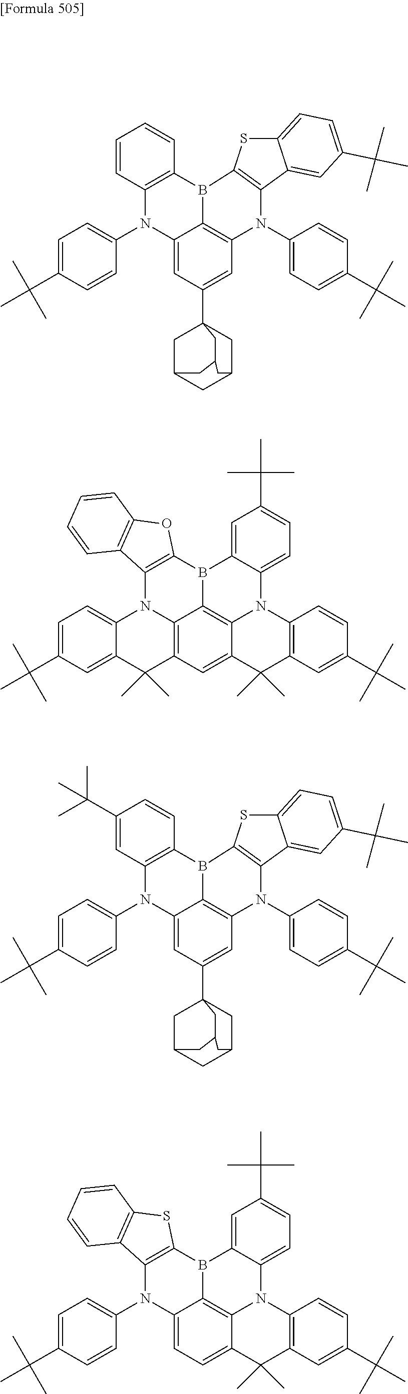

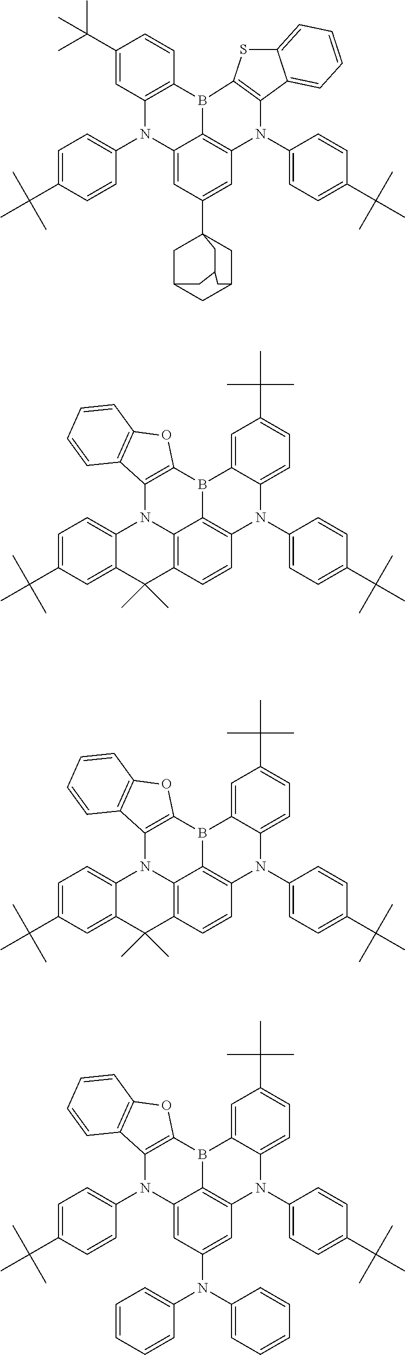

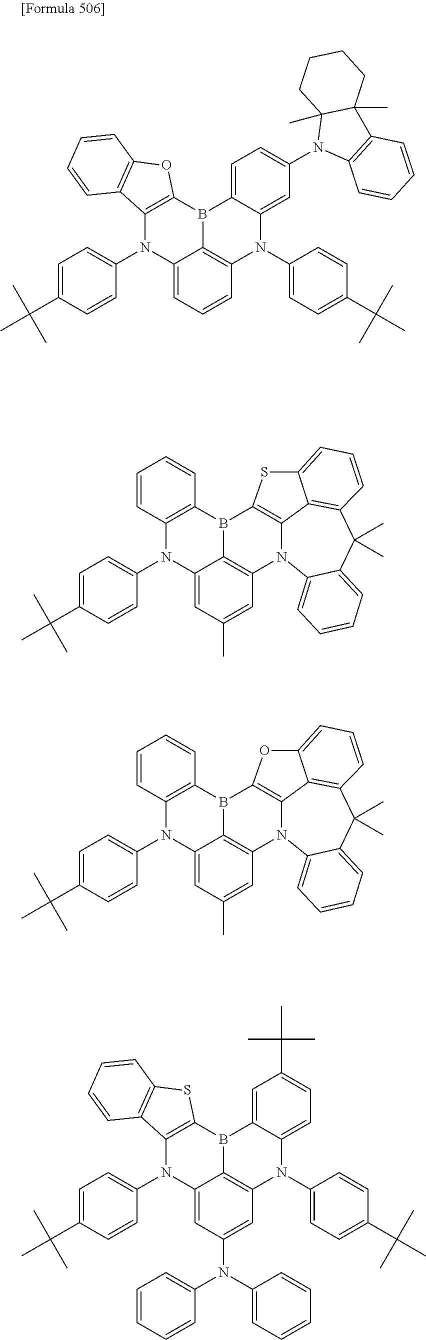

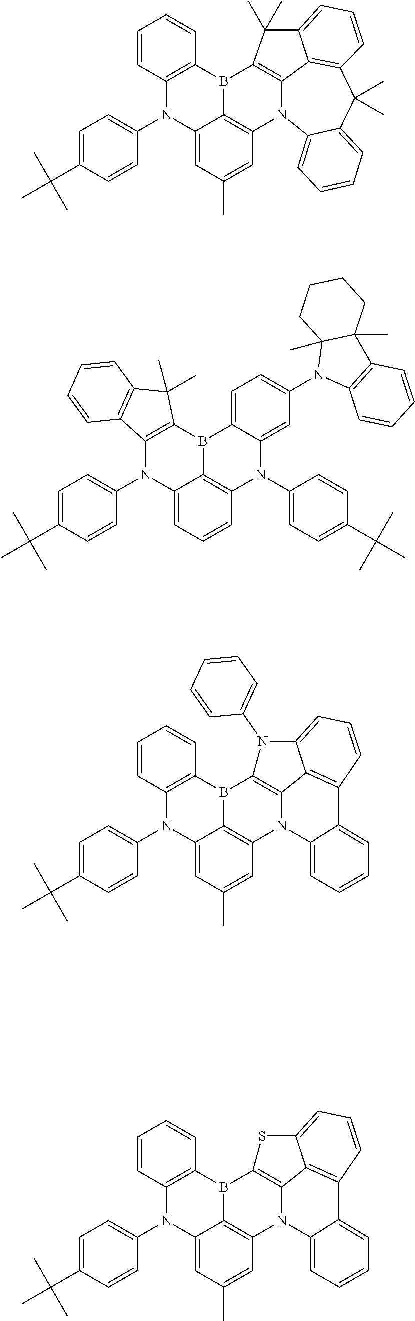

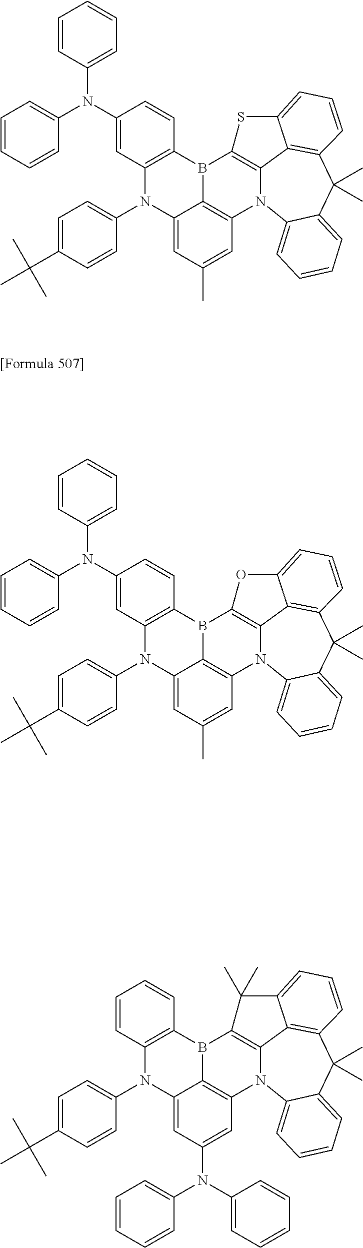

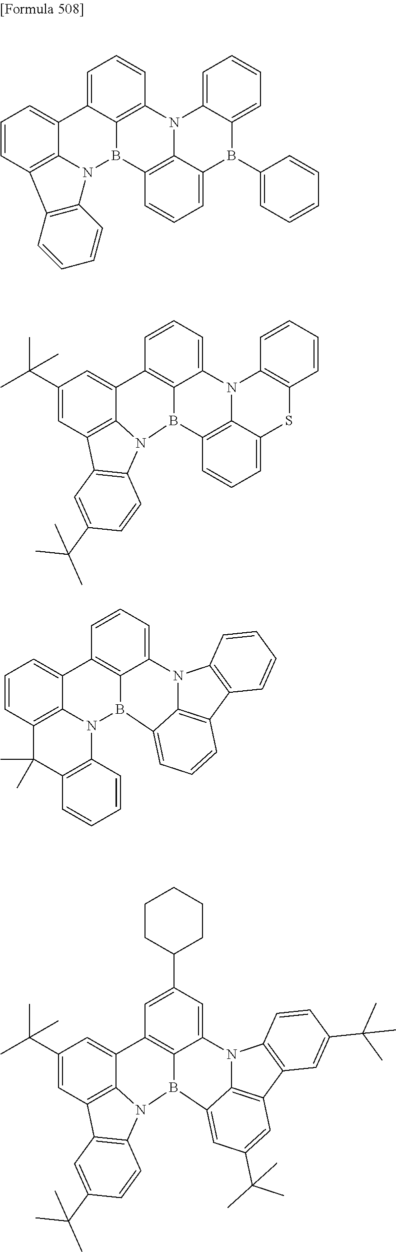

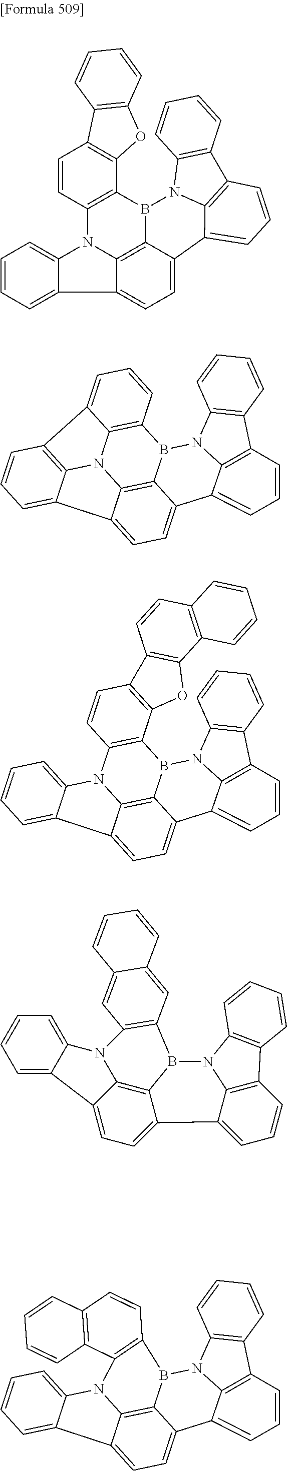 [SMILES: c1ccc2c(c1)oc1c3c(ccc12)-n1c2ccccc2c2ccc4c(c21)B3n1c2ccccc2c2cccc-4c21 ; c1ccc2c(c1)c1cccc3c1n2B1c2cccc4c5cccc6c7ccc-3c1c7n(c24)c56 ; c1ccc2c(c1)ccc1c3ccc4c(c3oc21)B1c2c(ccc3c5ccccc5n-4c23)-c2cccc3c4ccccc4n1c23 ; c1ccc2cc3c(cc2c1)B1c2c(ccc4c5ccccc5n-3c24)-c2cccc3c4ccccc4n1c23 ; c1ccc2c3c(ccc2c1)B1c2c(ccc4c5ccccc5n-3c24)-c2cccc3c4ccccc4n1c23]

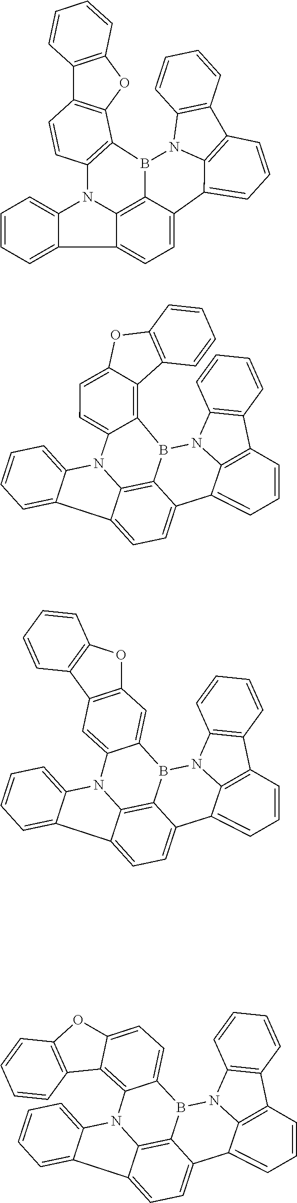 [SMILES: c1ccc2c(c1)oc1c3c(ccc12)-n1c2ccccc2c2ccc4c(c21)B3n1c2ccccc2c2cccc-4c21 ; c1ccc2c(c1)oc1ccc3c(c12)B1c2c(ccc4c5ccccc5n-3c24)-c2cccc3c4ccccc4n1c23 ; c1ccc2c(c1)oc1cc3c(cc12)-n1c2ccccc2c2ccc4c(c21)B3n1c2ccccc2c2cccc-4c21 ; c1ccc2c(c1)oc1ccc3c(c12)-n1c2ccccc2c2ccc4c(c21)B3n1c2ccccc2c2cccc-4c21]

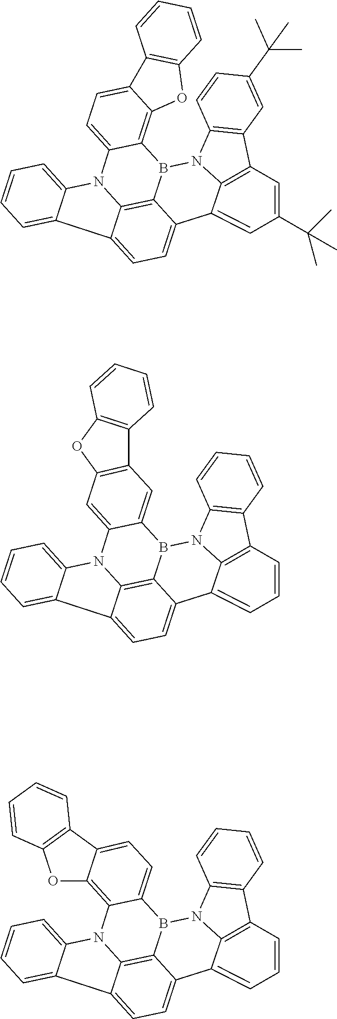 [SMILES: CC(C)(C)c1ccc2c(c1)c1cc(C(C)(C)C)cc3c1n2B1c2c(ccc4c2oc2ccccc24)-n2c4ccccc4c4ccc-3c1c42 ; c1ccc2c(c1)oc1cc3c(cc12)B1c2c(ccc4c5ccccc5n-3c24)-c2cccc3c4ccccc4n1c23 ; c1ccc2c(c1)oc1c3c(ccc12)B1c2c(ccc4c5ccccc5n-3c24)-c2cccc3c4ccccc4n1c23]

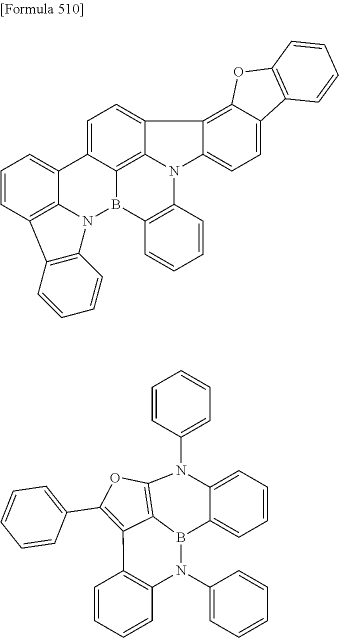 [SMILES: c1ccc2c(c1)B1c3c(ccc4c5c6oc7ccccc7c6ccc5n-2c34)-c2cccc3c4ccccc4n1c23 ; c1ccc(-c2oc3c4c2-c2ccccc2N(c2ccccc2)B4c2ccccc2N3c2ccccc2)cc1]

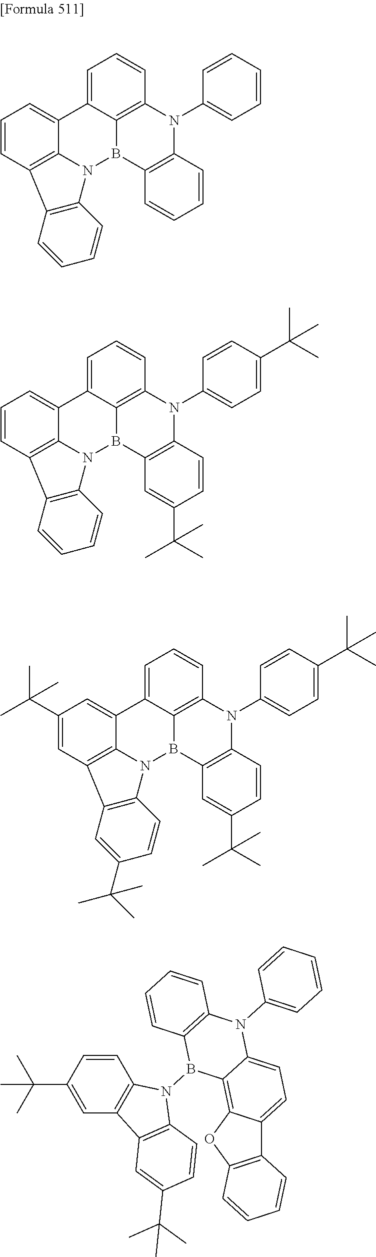

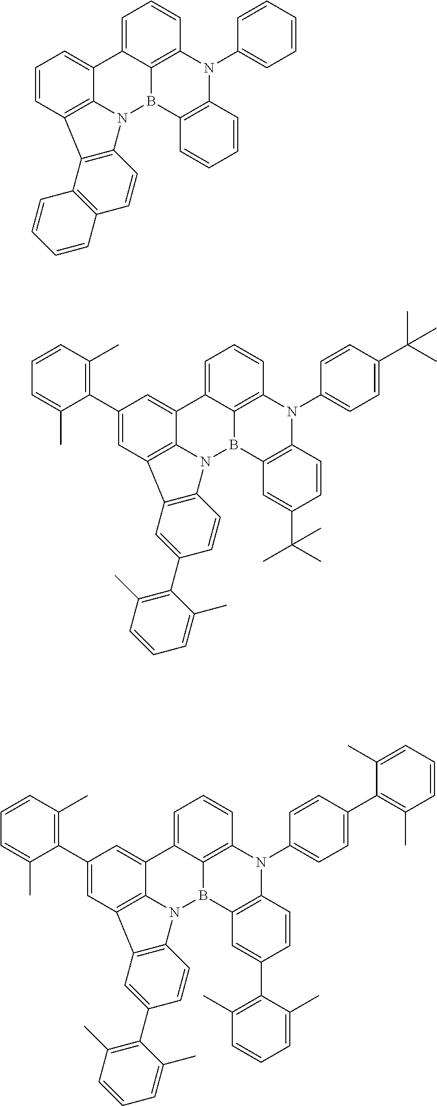 [SMILES: c1ccc(N2c3ccccc3B3c4c(cccc42)-c2cccc4c5c6ccccc6ccc5n3c24)cc1 ; Cc1cccc(C)c1-c1ccc2c(c1)c1cc(-c3c(C)cccc3C)cc3c1n2B1c2cc(C(C)(C)C)ccc2N(c2ccc(C(C)(C)C)cc2)c2cccc-3c21 ; Cc1cccc(C)c1-c1ccc(N2c3ccc(-c4c(C)cccc4C)cc3B3c4c(cccc42)-c2cc(-c4c(C)cccc4C)cc4c5cc(-c6c(C)cccc6C)ccc5n3c24)cc1]

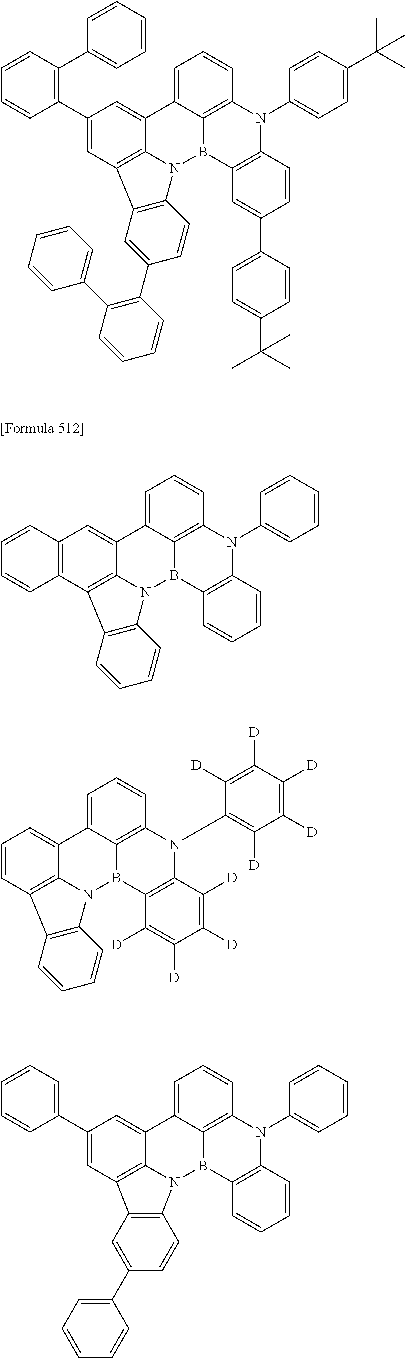 [SMILES: CC(C)(C)c1ccc(-c2ccc3c(c2)B2c4c(cccc4N3c3ccc(C(C)(C)C)cc3)-c3cc(-c4ccccc4-c4ccccc4)cc4c5cc(-c6ccccc6-c6ccccc6)ccc5n2c34)cc1 ; c1ccc(N2c3ccccc3B3c4c(cccc42)-c2cc4ccccc4c4c5ccccc5n3c24)cc1 ; [2H]c1c([2H])c([2H])c(N2c3cccc4c3B(c3c([2H])c([2H])c([2H])c([2H])c32)n2c3ccccc3c3cccc-4c32)c([2H])c1[2H] ; c1ccc(-c2ccc3c(c2)c2cc(-c4ccccc4)cc4c2n3B2c3ccccc3N(c3ccccc3)c3cccc-4c32)cc1]

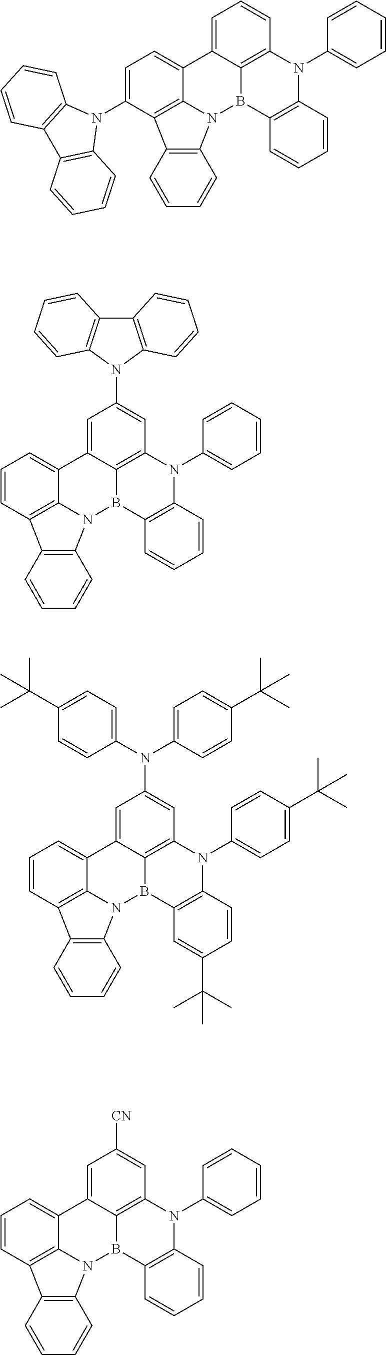 [SMILES: c1ccc(N2c3ccccc3B3c4c(cccc42)-c2ccc(-n4c5ccccc5c5ccccc54)c4c5ccccc5n3c24)cc1 ; c1ccc(N2c3ccccc3B3c4c(cc(-n5c6ccccc6c6ccccc65)cc42)-c2cccc4c5ccccc5n3c24)cc1 ; CC(C)(C)c1ccc(N(c2ccc(C(C)(C)C)cc2)c2cc3c4c(c2)N(c2ccc(C(C)(C)C)cc2)c2ccc(C(C)(C)C)cc2B4n2c4ccccc4c4cccc-3c42)cc1 ; N#Cc1cc2c3c(c1)N(c1ccccc1)c1ccccc1B3n1c3ccccc3c3cccc-2c31]

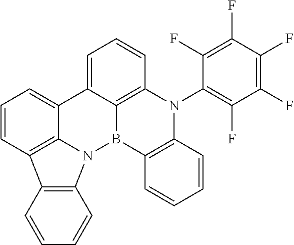 [SMILES: Fc1c(F)c(F)c(N2c3ccccc3B3c4c(cccc42)-c2cccc4c5ccccc5n3c24)c(F)c1F]

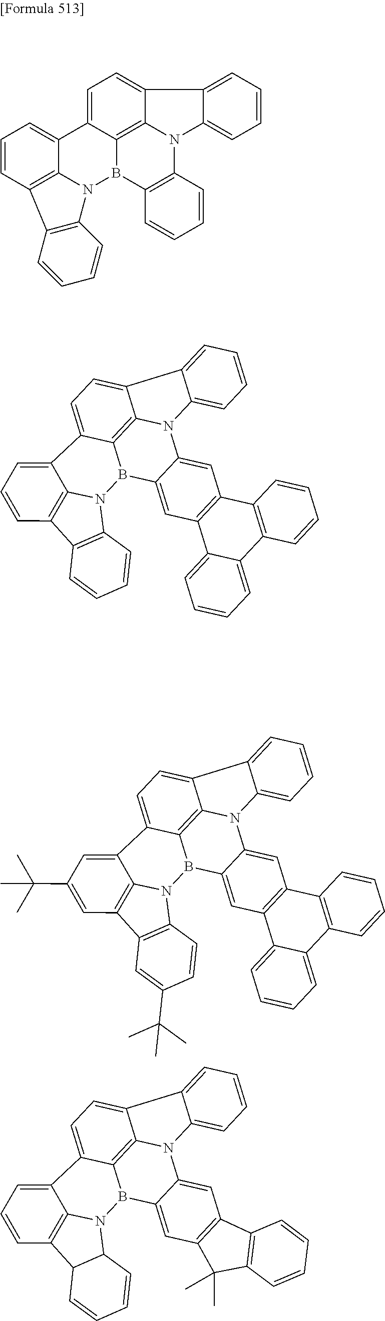

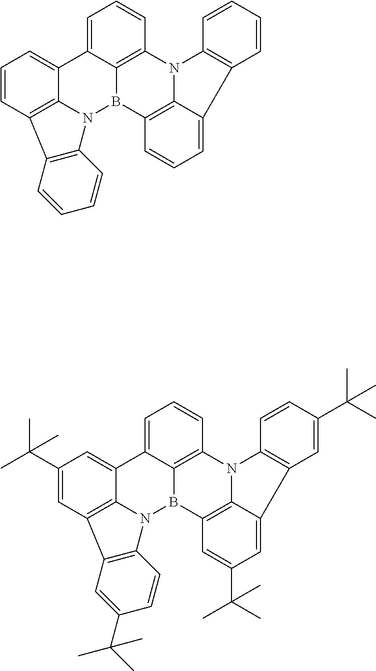 [SMILES: c1cc2c3c(c1)-n1c4ccccc4c4cccc(c41)B3n1c3ccccc3c3cccc-2c31 ; CC(C)(C)c1ccc2c(c1)c1cc(C(C)(C)C)cc3c1n2B1c2c-3cccc2-n2c3ccc(C(C)(C)C)cc3c3cc(C(C)(C)C)cc1c32]

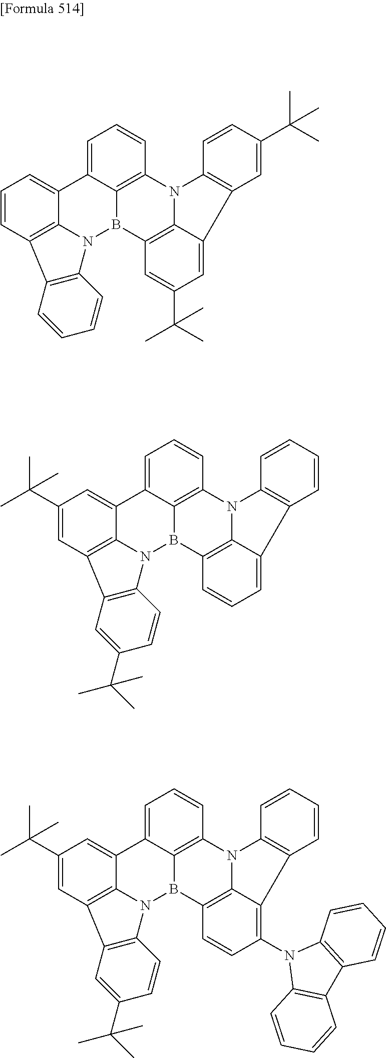

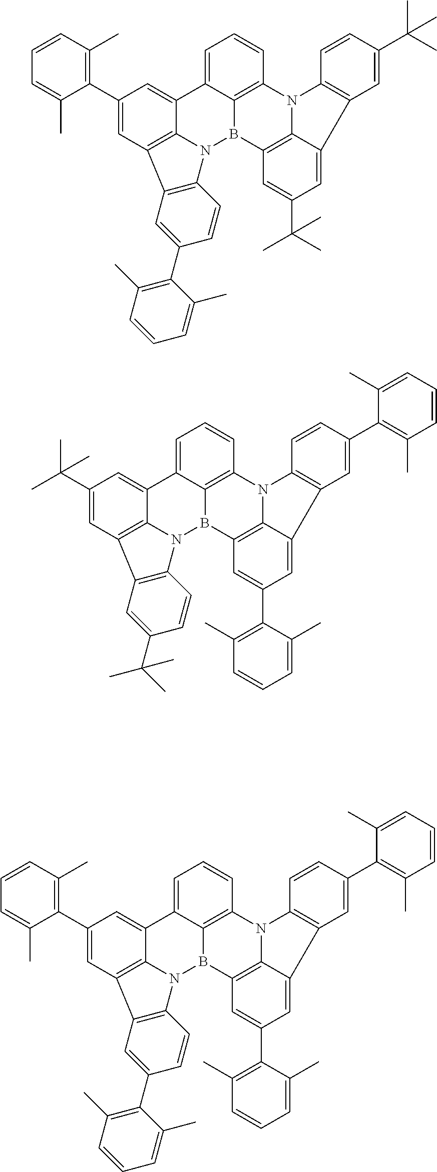

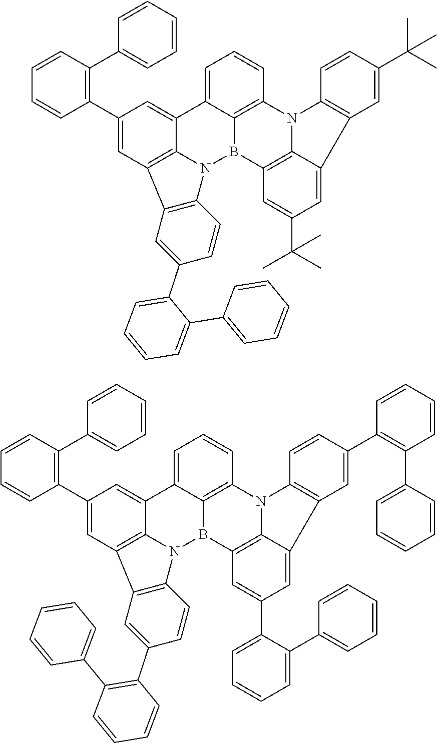

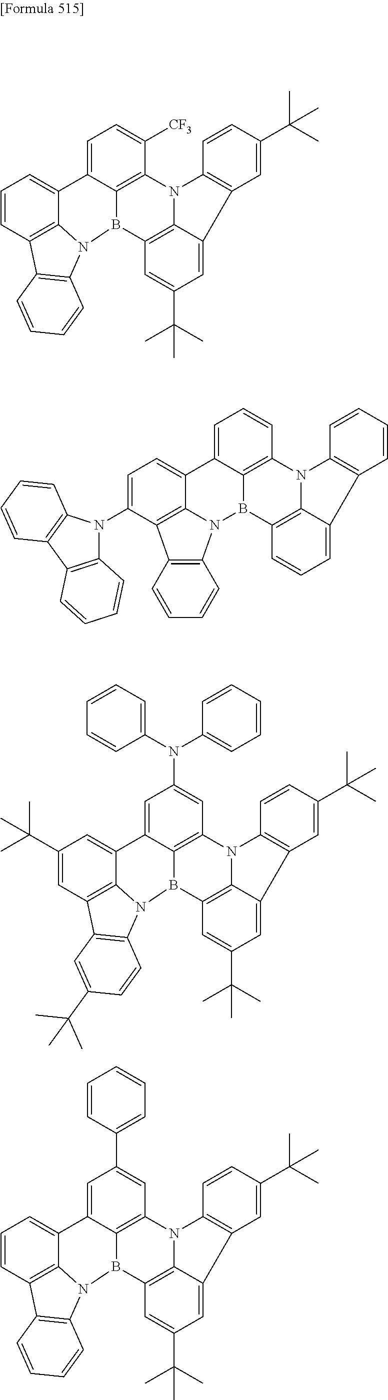

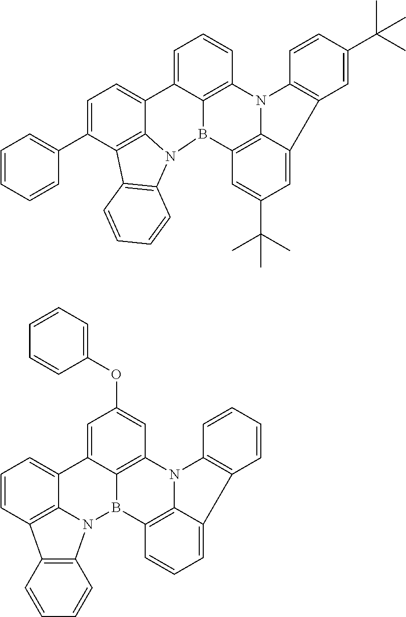 [SMILES: CC(C)(C)c1ccc2c(c1)c1cc(C(C)(C)C)cc3c1n2-c1cccc2c1B3n1c3ccccc3c3c(-c4ccccc4)ccc-2c31 ; c1ccc(Oc2cc3c4c(c2)-n2c5ccccc5c5cccc(c52)B4n2c4ccccc4c4cccc-3c42)cc1]

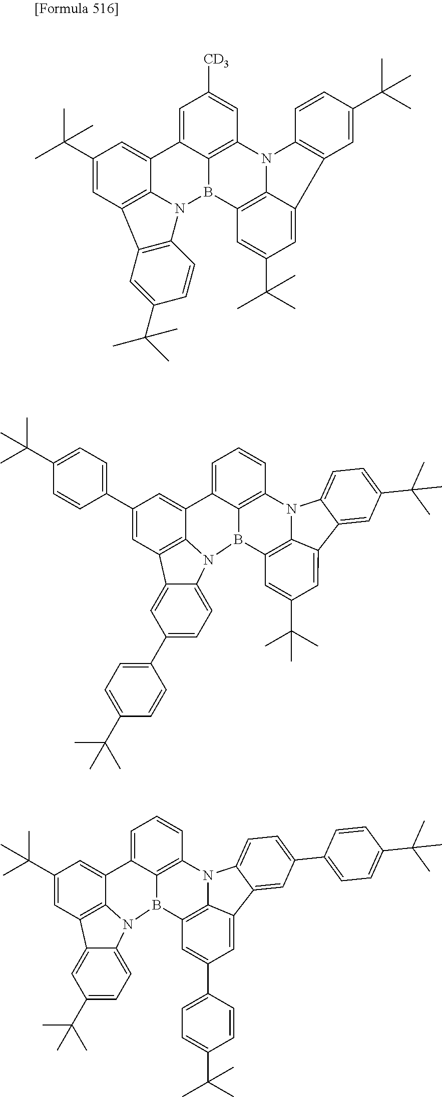

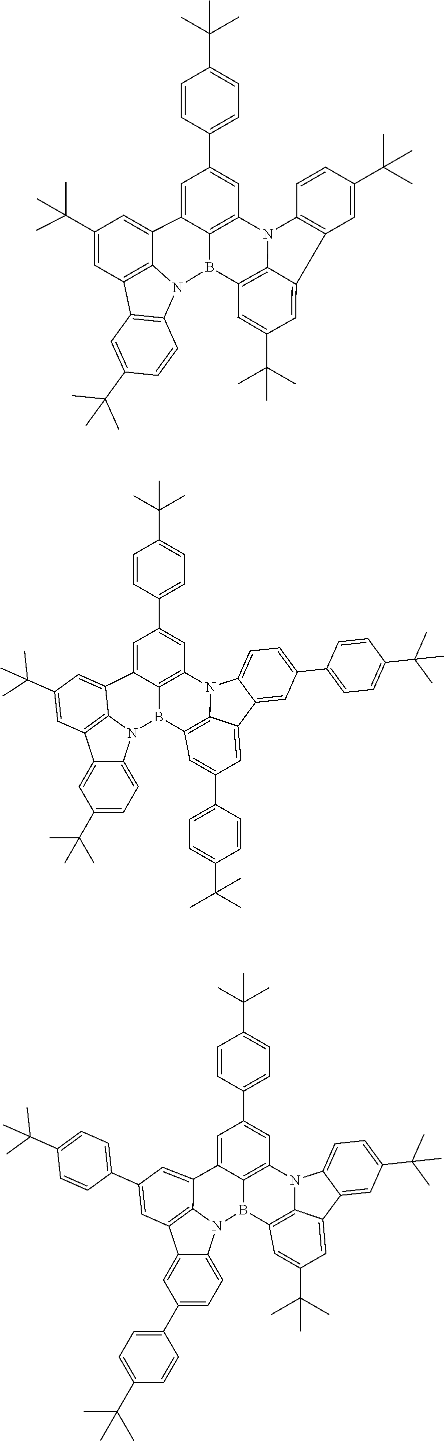

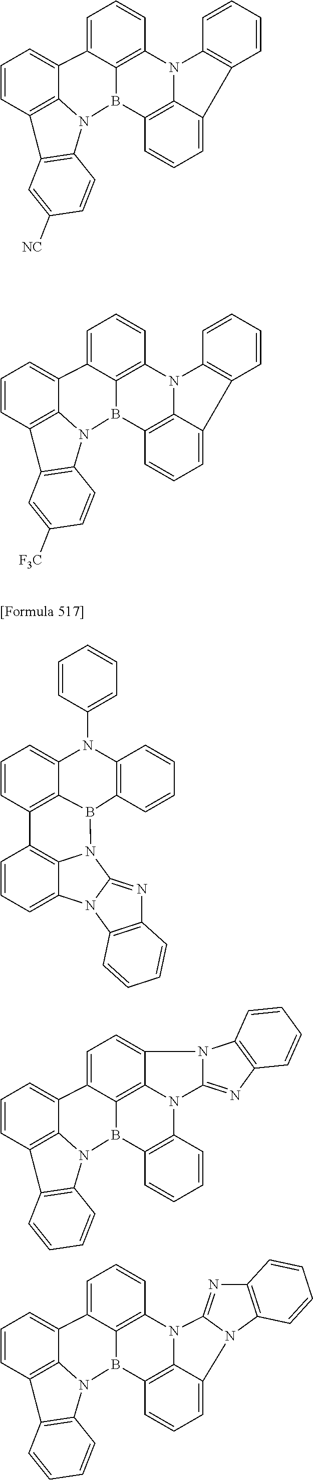

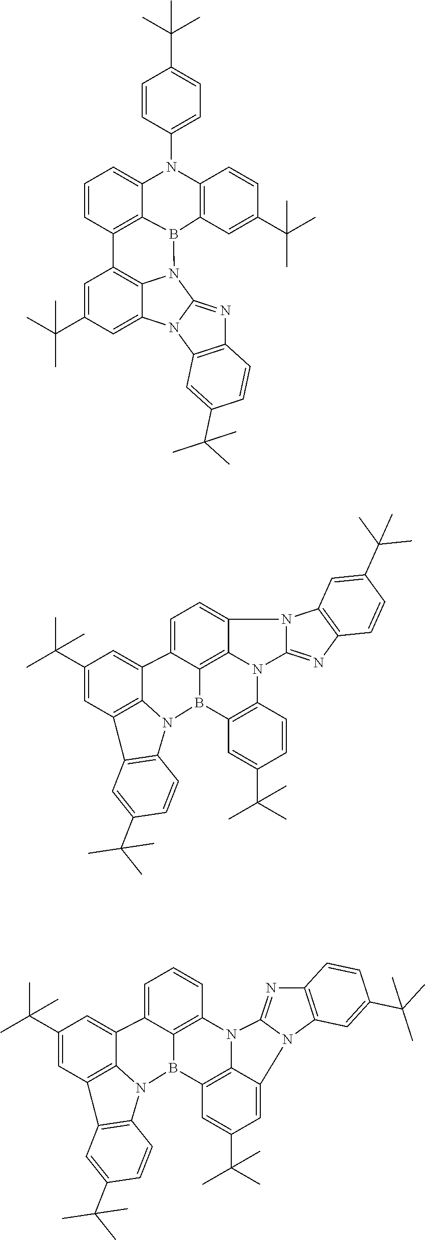

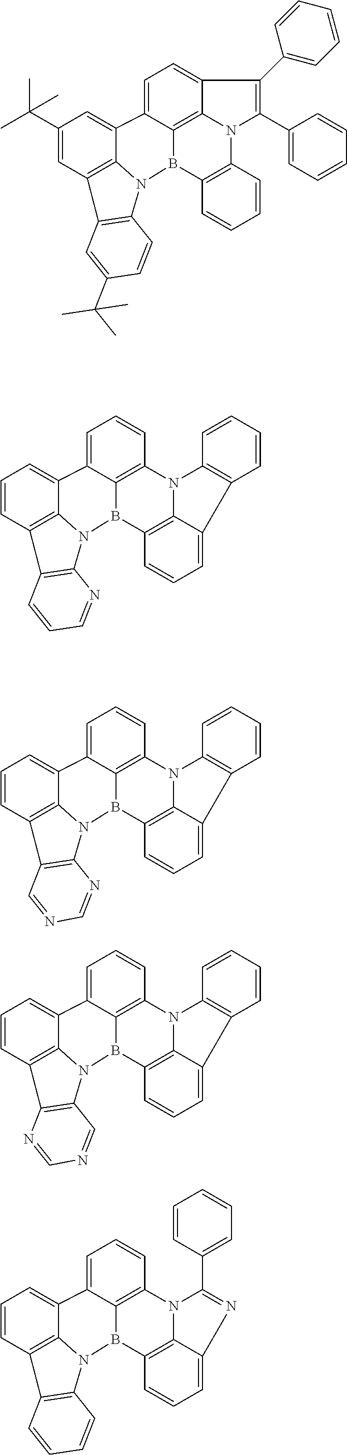 [SMILES: CC(C)(C)c1ccc2c(c1)c1cc(C(C)(C)C)cc3c1n2B1c2ccccc2-n2c(-c4ccccc4)c(-c4ccccc4)c4ccc-3c1c42 ; c1cc2c3c(c1)-n1c4ccccc4c4cccc(c41)B3n1c3ncccc3c3cccc-2c31 ; c1cc2c3c(c1)-n1c4ccccc4c4cccc(c41)B3n1c3ncncc3c3cccc-2c31 ; c1cc2c3c(c1)-n1c4ccccc4c4cccc(c41)B3n1c3cncnc3c3cccc-2c31 ; c1ccc(-c2nc3cccc4c3n2-c2cccc3c2B4n2c4ccccc4c4cccc-3c42)cc1]

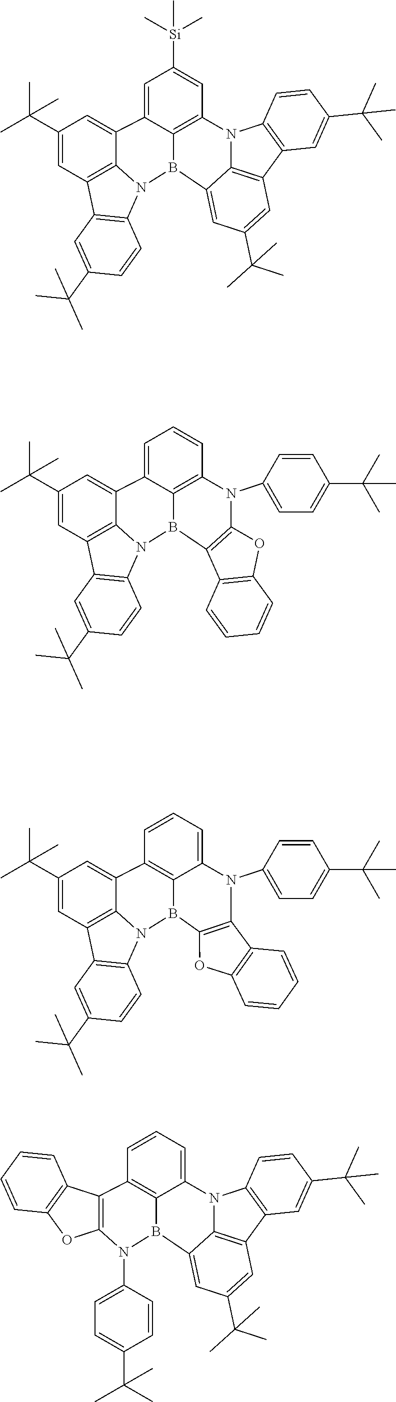

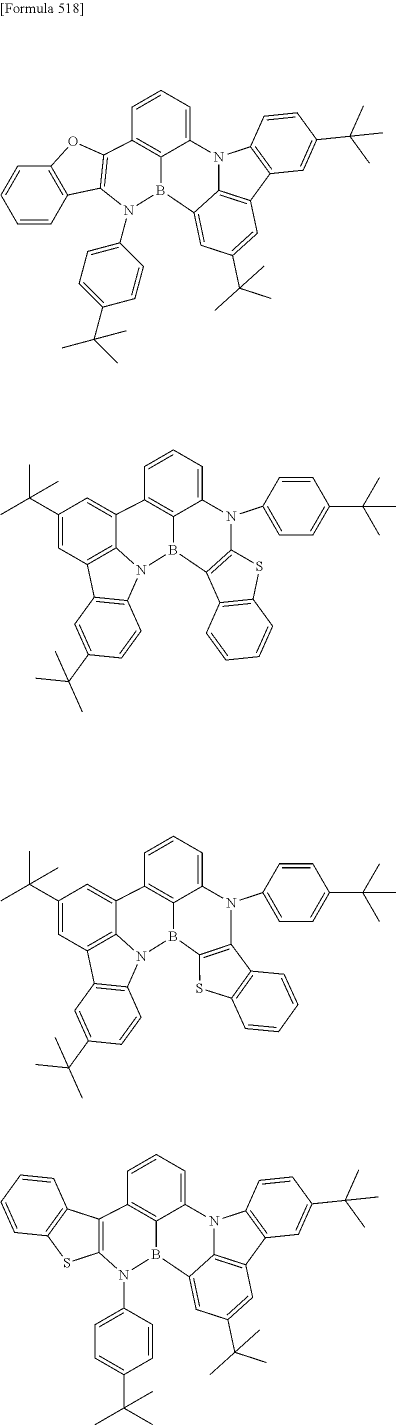

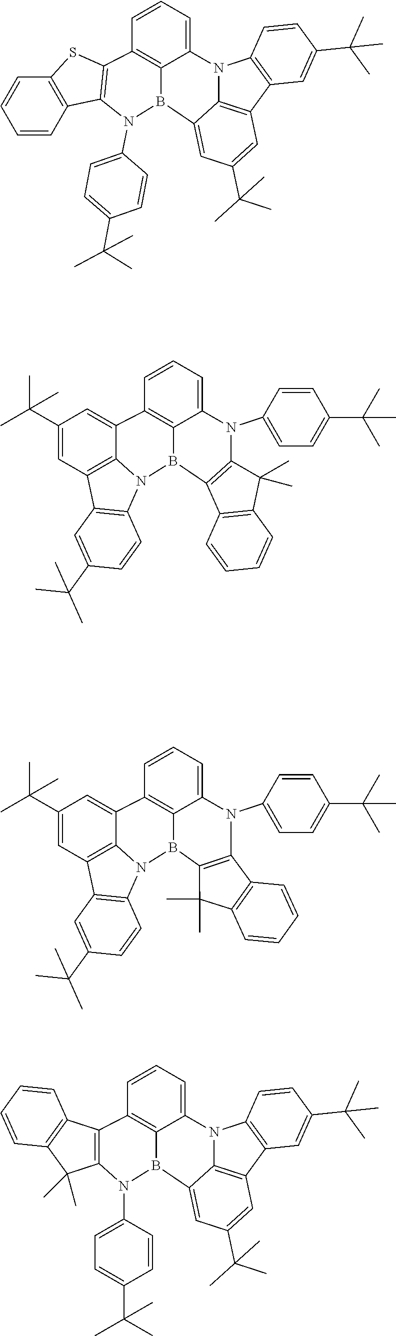

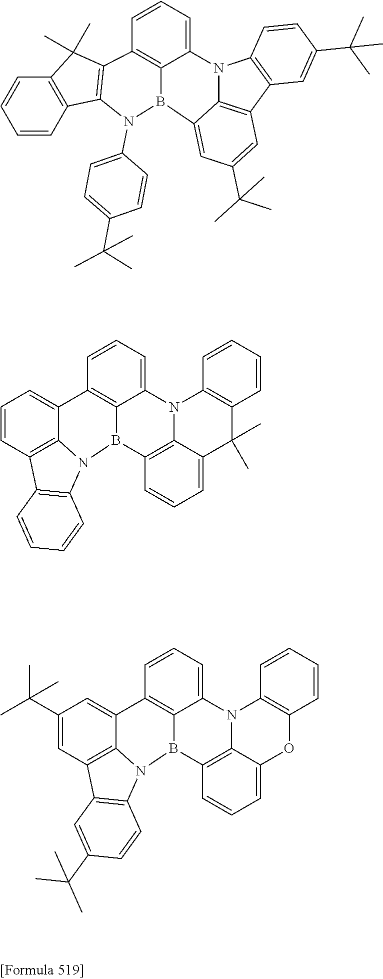

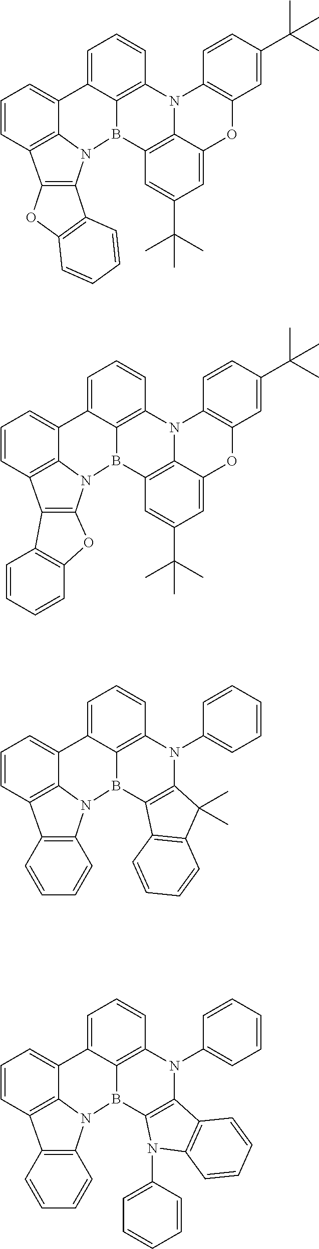 [SMILES: CC(C)(C)c1ccc2c(c1)Oc1cc(C(C)(C)C)cc3c1N2c1cccc2c1B3n1c3c-2cccc3c2oc3ccccc3c21 ; CC(C)(C)c1ccc2c(c1)Oc1cc(C(C)(C)C)cc3c1N2c1cccc2c1B3n1c3oc4ccccc4c3c3cccc-2c31 ; CC1(C)C2=C(B3c4c(cccc4N2c2ccccc2)-c2cccc4c5ccccc5n3c24)c2ccccc21 ; c1ccc(N2c3cccc4c3B(c3c2c2ccccc2n3-c2ccccc2)n2c3ccccc3c3cccc-4c32)cc1]

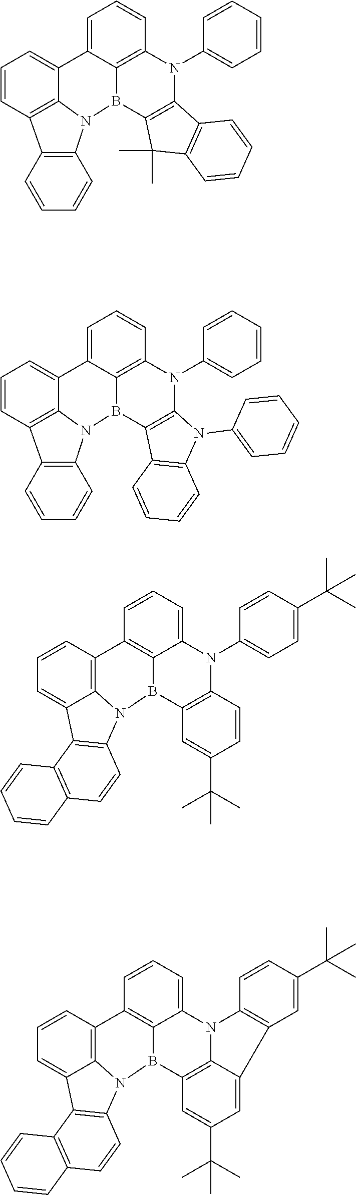 [SMILES: CC1(C)C2=C(c3ccccc31)N(c1ccccc1)c1cccc3c1B2n1c2ccccc2c2cccc-3c21 ; c1ccc(N2c3cccc4c3B(c3c2n(-c2ccccc2)c2ccccc32)n2c3ccccc3c3cccc-4c32)cc1 ; CC(C)(C)c1ccc(N2c3ccc(C(C)(C)C)cc3B3c4c(cccc42)-c2cccc4c5c6ccccc6ccc5n3c24)cc1 ; CC(C)(C)c1ccc2c(c1)c1cc(C(C)(C)C)cc3c1n2-c1cccc2c1B3n1c3ccc4ccccc4c3c3cccc-2c31]

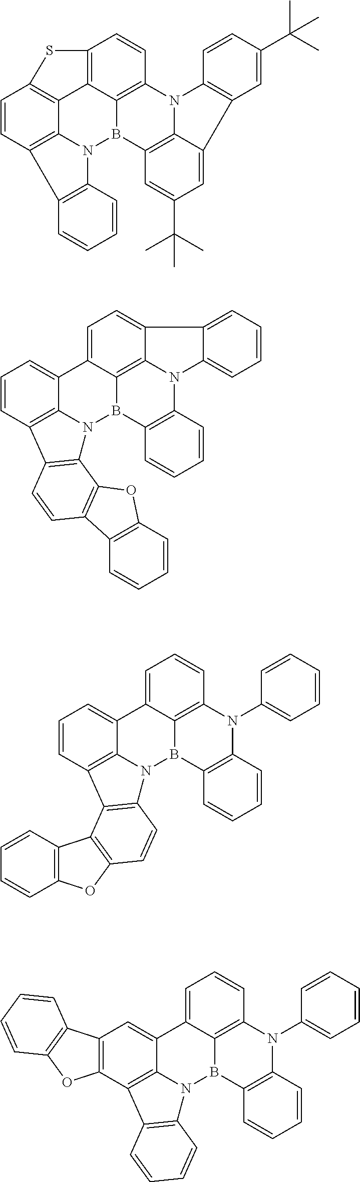 [SMILES: CC(C)(C)c1ccc2c(c1)c1cc(C(C)(C)C)cc3c1n2-c1ccc2sc4ccc5c6ccccc6n6c5c4c2c1B36 ; c1ccc2c(c1)B1c3c(ccc4c5ccccc5n-2c34)-c2cccc3c4ccc5c6ccccc6oc5c4n1c23 ; c1ccc(N2c3ccccc3B3c4c(cccc42)-c2cccc4c5c6c(ccc5n3c24)oc2ccccc26)cc1 ; c1ccc(N2c3ccccc3B3c4c(cccc42)-c2cc4c5ccccc5oc4c4c5ccccc5n3c24)cc1]

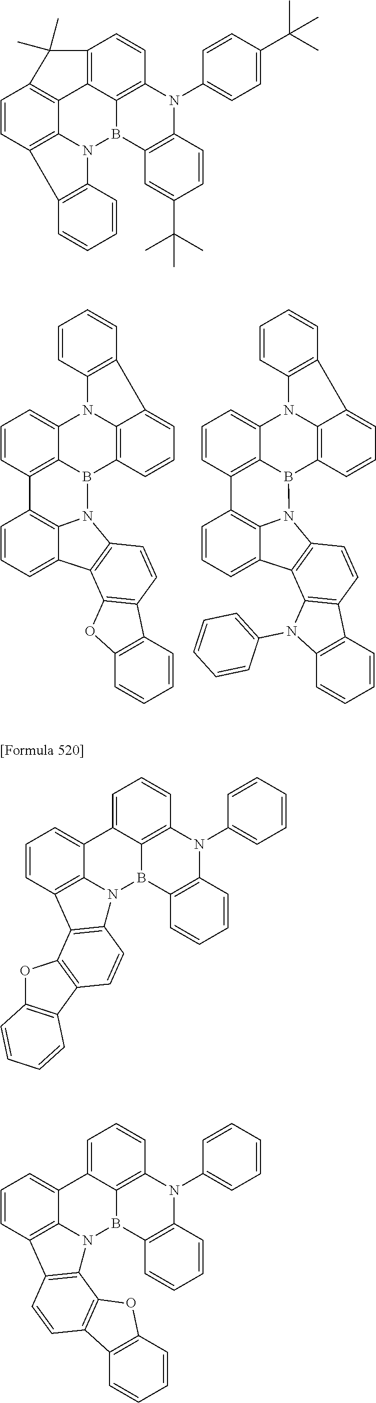

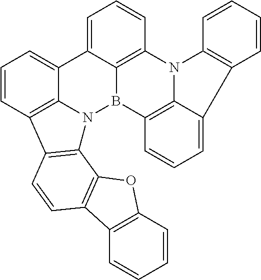 [SMILES: c1cc2c3c(c1)-n1c4ccccc4c4cccc(c41)B3n1c3c-2cccc3c2ccc3c4ccccc4oc3c21]

### Second Exemplary Embodiment

An organic electroluminescence display device (hereinafter also referred to as an organic EL display device) according to a second exemplary embodiment will be described below. In the description of the second exemplary embodiment, the same components as those in the first exemplary embodiment are denoted by the same reference signs and names to simplify or omit an explanation of the components. In the second exemplary embodiment, the same materials and compounds as described in the first exemplary embodiment are usable, unless otherwise specified.

### Organic Electroluminescence Display Device

An organic EL display device according to the exemplary embodiment includes: an anode and a cathode arranged opposite each other; a blue-emitting organic EL device as a blue pixel; a green-emitting organic EL device as a green pixel; and a red-emitting organic EL device as a red pixel, in which the blue-emitting organic EL device includes a blue emitting region having a first emitting layer and a second emitting layer provided between the anode and the cathode, the first emitting layer is disposed close to the anode in the blue emitting region, the green-emitting organic EL device includes a green emitting layer provided between the anode and the cathode, the red-emitting organic EL device includes a red emitting layer provided between the anode and the cathode, a hole transporting zone is provided between the anode and the blue emitting region of the blue-emitting organic EL device, the green emitting layer of the green-emitting organic EL device, and the red emitting layer of the red-emitting organic EL device in a shared manner across the blue-emitting organic EL device, the green-emitting organic EL device, and the red-emitting organic EL device, the hole transporting zone is in direct contact with the first emitting layer in the blue emitting region of the blue-emitting organic EL device, the hole transporting zone includes one or more organic layers, the first emitting layer contains a first host material and a first emitting compound that emits light having a maximum peak wavelength of 500 nm or less, the second emitting layer contains a second host material and a second emitting compound that emits light having a maximum peak wavelength of 500 nm or less, the first host material is different from the second host material, the first emitting compound and the second emitting compound are mutually the same or different, and a triplet energy of the first host material T₁(H1) and a triplet energy of the second host material T₁(H2) satisfy a relationship of a numerical formula (Numerical Formula 1) below.

Further, in the blue emitting region of the blue-emitting organic EL device of the organic electroluminescence display device according to the exemplary embodiment, the dipole of the first host material contained in the first emitting layer is 0.4 D or more.

T₁(H1)>T₁(H2) (Numerical Formula 1)

Herein, a layer provided in a shared manner across a plurality of devices is occasionally referred to as a common layer. Herein, a layer not provided in a shared manner across a plurality of devices is occasionally referred to as a non-common layer.

Herein, a zone provided in a shared manner across a plurality of devices is occasionally referred to as a common zone. The hole transporting zone, which is provided between the anode and the blue emitting region of the blue-emitting organic EL device, the green emitting layer of the green-emitting organic EL device, and the red emitting layer of the red-emitting organic EL device in a shared manner across the blue-emitting organic EL device, the green-emitting organic EL device, and the red-emitting organic EL device, is a common zone.

Herein, “blue”, “green”, or “red” used for each element, such as “pixel”, “emitting layer”, “organic layer”, or “material”, is used to distinguish one from another. Although “blue”, “green”, or “red” may represent a color of light emitted from “pixel”, “emitting layer”, “organic layer”, or “material”, “blue”, “green”, or “red” does not mean the color of appearance of each element.

In the organic EL display device according to the exemplary embodiment, the blue-emitting organic EL device includes the first emitting layer and the second emitting layer satisfying the relationship of the numerical formula (Numerical Formula 1). The luminous efficiency of the blue-emitting organic EL device can thus be improved for the same reason as in the first exemplary embodiment.

The organic EL display device according to the exemplary embodiment has a layer arrangement (layer-saving arrangement) in which the number of organic layers forming the hole transporting zone between the blue emitting region and the anode is reduced.

In a conventional organic EL display device, a non-common layer (e.g., electron blocking layer) is provided between the anode and the blue emitting region of the blue-emitting organic EL device, the non-common layer not being provided for the green-emitting organic EL device and the red-emitting organic EL device.

In the organic EL display device according to the exemplary embodiment, the hole transporting zone (common zone) provided in a shared manner across the blue-emitting organic EL device, the green-emitting organic EL device, and the red-emitting organic EL device is in direct contact with the first emitting layer in the blue emitting region. Specifically, in the organic EL display device according to the exemplary embodiment, the non-common layer is not provided at a side close to the anode with respect to the first emitting layer of the blue-emitting organic EL device, that is, the number of layers in the hole transporting zone of the blue-emitting organic EL device is reduced.

In the organic EL display device with the layer-saving arrangement, however, the injection amount of holes to the blue emitting region is likely to be insufficient, which may decrease luminous efficiency.

In the organic EL display device according to the exemplary embodiment, using a material with a large dipole (0.4 D or more) as the first host material contained in the first emitting layer of the blue emitting region facilitates the transfer of holes from the hole transporting zone (common zone) to the blue emitting region. This makes it easy to achieve high efficiency even in a layer-saving arrangement of the hole transporting zone in which the supply amount of holes to the blue emitting region is likely to be insufficient.

In the organic EL display device according to the exemplary embodiment, at least one organic layer in the hole transporting zone (common zone) is the first organic layer that is in direct contact with the first emitting layer, and the first organic layer preferably contains a hole transporting zone material.

In the blue-emitting organic EL device according to the exemplary embodiment, each organic layer in the hole transporting zone (common zone) may or may not contain a common hole transporting zone material described in the first exemplary embodiment.

The same arrangement of the organic EL device according to the first exemplary embodiment is thus applicable to the blue-emitting organic EL device according to the exemplary embodiment.

The first emitting layer and the second emitting layer explained in the first exemplary embodiment are usable as the first emitting layer and the second emitting layer contained in the blue emitting region according to the exemplary embodiment. Further, one or a plurality of organic layers (e.g., the first organic layer, the second organic layer, and the third organic layer) contained in the hole transporting zone according to the first exemplary embodiment is/are usable as one or a plurality of organic layers contained in the hole transporting zone according to the exemplary embodiment.

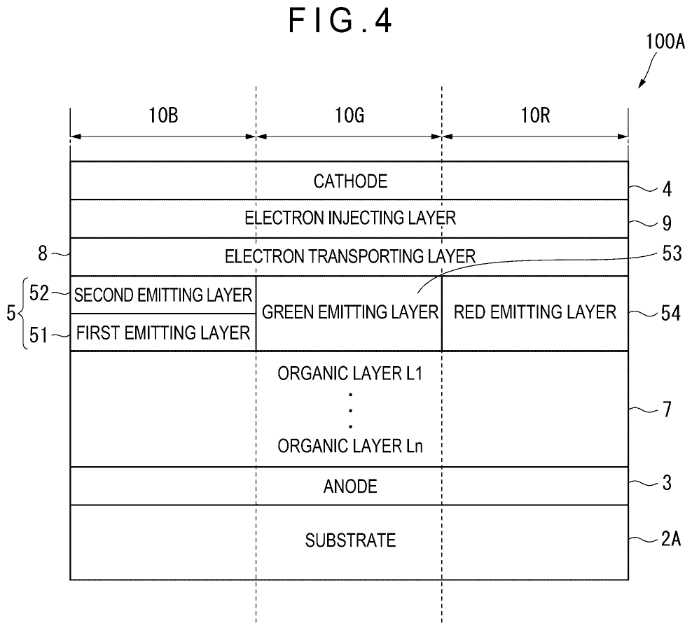

Referring to FIG. 4, explanation is made about an exemplary arrangement of the organic EL display device according to the second exemplary embodiment.

FIG. 4 depicts an organic EL display device 100A according to an exemplary embodiment.

The organic EL display device 100A includes electrodes and an organic layer(s) supported by a substrate 2A.

The organic EL display device 100A includes the anode 3 and the cathode 4 arranged opposite each other.

The organic EL display device 100A includes a blue-emitting organic EL device 10B as a blue pixel, a green-emitting organic EL device 10G as a green pixel, and a red-emitting organic EL device 10R as a red pixel.

It should be noted that FIG. 4 schematically depicts the organic EL display device 100A, and thus does not limit, for instance, a thickness of each layer of the device 100A and a size of the device 100A. For instance, FIG. 4 depicts that the first emitting layer 51, the second emitting layer 52, a green emitting layer 53, and a red emitting layer 54 have the same thickness, but does not necessarily mean that these layers in an actual organic EL display device have the same thickness.

The blue-emitting organic EL device 10B includes, between the anode 3 and the cathode 4, a hole transporting zone 7, a blue emitting region 5, the electron transporting layer 8, and the electron injecting layer 9 in this order from a side close to the anode 3. The blue emitting region 5 includes the first emitting layer 51 and the second emitting layer 52. The first emitting layer 51 is in direct contact with the hole transporting zone 7.

The green-emitting organic EL device 10G includes, between the anode 3 and the cathode 4, the hole transporting zone 7, the green emitting layer 53, the electron transporting layer 8, and the electron injecting layer 9 in this order from the side close to the anode 3.

The red-emitting organic EL device 10R includes, between the anode 3 and the cathode 4, the hole transporting zone 7, the red emitting layer 54, the electron transporting layer 8, and the electron injecting layer 9 in this order from the side close to the anode 3.

In the organic EL display device 100A according to the exemplary embodiment, the hole transporting zone 7 is a common zone including a total of n layers of organic layers from an organic layer L1 to an organic layer Ln. n may be 1, 2, or 3 or more. In the exemplary embodiment, the organic layer L1 is a layer that is in direct contact with the blue emitting region 5. The first organic layer corresponds to the organic layer L1.

For instance, when the hole transporting zone consists of a single organic layer (first organic layer), n is 1, the organic layer L1 is the first organic layer, and the organic layer L1 is in direct contact with the anode and the first emitting layer of the blue-emitting organic EL device.

For instance, when the hole transporting zone consists of two organic layers (first organic layer and second organic layer), n is 2, the organic layer L1 is the first organic layer, the organic layer L2 is the second organic layer, the organic layer L1 is in direct contact with the first emitting layer of the blue-emitting organic EL device, and the organic layer L2 is in direct contact with the anode.

The anode 3 is independently provided for each of the blue-emitting organic EL device 10B, the green-emitting organic EL device 10G, and the red-emitting organic EL device 10R. Thus, the blue-emitting organic EL device 10B, the green-emitting organic EL device 10G, and the red-emitting organic EL device 10R can be individually driven in the organic EL display device 100A. The respective anodes of the organic EL devices 10B, 10G, and 10R are insulated from each other by an insulation material (not depicted). The cathode 4 is provided in a shared manner across the blue-emitting organic EL device 10B, the green-emitting organic EL device 10G, and the red-emitting organic EL device 10R.

In an exemplary embodiment, the blue-emitting organic EL device 10B, the green-emitting organic EL device 10G, and the red-emitting organic EL device 10R as pixels are arranged in parallel with each other on the substrate 2A.

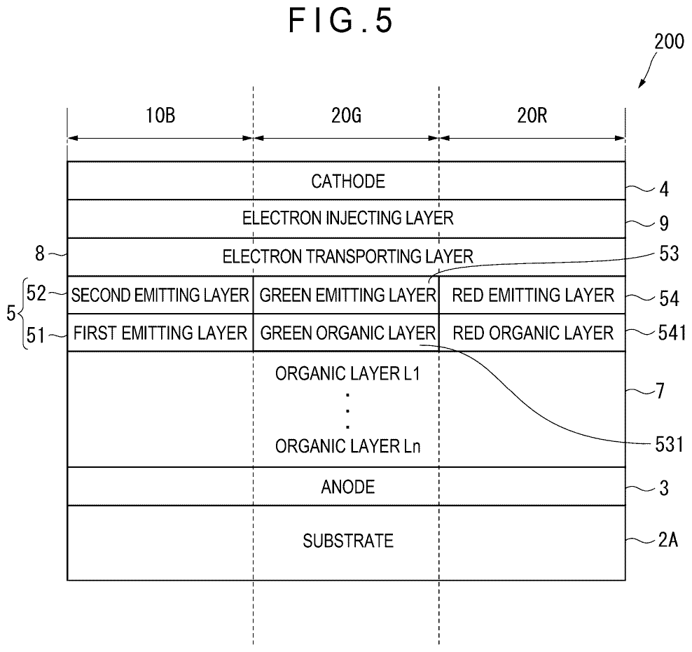

FIG. 5 schematically depicts another exemplary arrangement of the organic EL display device according to the second exemplary embodiment.

An organic EL display device 200 has a similar arrangement as that of the organic EL display device 100A depicted in FIG. 4 except for a green-emitting organic EL device 20G as the green pixel and a red-emitting organic EL device 20R as the red pixel. Differences between the organic EL display device 100A and the organic EL display device 200 are explained below.

The green-emitting organic EL device 20G includes, between the anode 3 and the cathode 4, the hole transporting zone 7, a green organic layer 531, the green emitting region 53, the electron transporting layer 8, and the electron injecting layer 9 in this order from the side close to the anode 3. In a case depicted in FIG. 5, the green organic layer 531 is in direct contact with the hole transporting zone 7. The green organic layer 531 is preferably an electron blocking layer.

The red-emitting organic EL device 20R includes, between the anode 3 and the cathode 4, the hole transporting zone 7, a red organic layer 541, the red emitting layer 54, the electron transporting layer 8, and the electron injecting layer 9 in this order from the side close to the anode 3. In a case depicted in FIG. 5, the red organic layer 541 is in direct contact with the hole transporting zone 7. The red organic layer 541 is preferably an electron blocking layer.

Also in the organic EL display device depicted in FIG. 5, using a material with a large dipole (0.4 D or more) as the first host material contained in the first emitting layer facilitates the transfer of holes from the hole transporting zone (common zone) to the blue emitting region. This makes it easy to achieve high efficiency even in a layer-saving arrangement of the hole transporting zone in which the supply amount of holes to the blue emitting region is likely to be insufficient.

The invention is not limited to the arrangements of the organic EL display devices depicted in FIGS. 4 to 5.

Further, in the organic EL display devices depicted in FIGS. 4 and 5, the green-emitting organic EL device and the red-emitting organic EL device may each be a device that fluoresces or a device that phosphoresces.

In the organic EL display devices depicted in FIGS. 4 and 5, the green emitting layer 53 and the red emitting layer 54 may each be an emitting layer that contains a delayed fluorescent compound, which will be described later.

Referring to FIG. 4, the organic EL display device according to the exemplary embodiment is further explained.

### Hole Transporting Zone

The hole transporting zone 7, which is provided between the anode 3 and the blue emitting region 5 of the blue-emitting organic EL device 10B, the green emitting layer 53 of the green-emitting organic EL device 10G, and the red emitting layer 54 of the red-emitting organic EL device 10R, is a common zone provided in a shared manner across the blue-emitting organic EL device 10B, the green-emitting organic EL device 10G, and the red-emitting organic EL device 10R.

When the hole transporting zone 7 includes a plurality of layers, the layers are each a common layer provided between the anode 3 and the blue emitting region 5 of the blue-emitting organic EL device 10B, the green emitting layer 53 of the green-emitting organic EL device 10G, and the red emitting layer 54 of the red-emitting organic EL device 10R in a shared manner across the blue-emitting organic EL device 10B, the green-emitting organic EL device 10G, and the red-emitting organic EL device 10R.

In an exemplary embodiment, at least one of the organic layers in the hole transporting zone 7 (organic layer L1 to organic layer Ln) contains a hole transporting zone material, and the hole mobility of the hole transporting zone material is preferably 1.0×10⁻⁵ cm²/Vs or more, more preferably 5.0×10⁻⁵ cm²/Vs or more, and still more preferably 1.0×10⁻⁴ cm²/Vs or more.

When the hole mobility of the hole transporting zone material contained in the hole transporting zone is 1.0×10⁻⁵ cm²/Vs or more, the transfer of holes from the hole transporting zone (common zone) to the blue emitting region is facilitated. This easily achieves high efficiency even in a layer-saving arrangement of the hole transporting zone in which the supply amount of holes to the blue emitting region is likely to be insufficient.

Also preferably, at least two of the organic layers in the hole transporting zone 7 each contain a hole transporting zone material.

As the hole transporting zone material, it is possible to use, for instance, a doped compound explained in the first exemplary embodiment, a compound represented by the formula (21), a compound represented by the formula (22), and a compound usable as the hole transporting layer.

As the n layers of organic layers included in the hole transporting zone 7, for instance, one or more layers selected from the group consisting of the first organic layer, the second organic layer, the third organic layer, the hole injecting layer, and the hole transporting layer explained in the first exemplary embodiment are usable in combination.

The hole mobility can be measured according to impedance measurement using a mobility evaluation device produced by the following steps. The mobility evaluation device is, for instance, produced by the following steps.

A compound HA-2 below is vapor-deposited on a glass substrate having an ITO transparent electrode (anode) so as to cover the transparent electrode, thereby forming a hole injecting layer. A compound HT-A below is vapor-deposited on this formed hole injecting layer to form a hole transporting layer. Subsequently, a compound Target, which is to be measured for a hole mobility, is vapor-deposited to form a measurement target layer. Metal aluminum (Al) is vapor-deposited on this measurement target layer to form a metal cathode.

An arrangement of the mobility evaluation device above is roughly shown as follows.

ITO(130)/HA-2(5)/HT-A(10)/Target(200)/Al(80)

Numerals in parentheses represent a film thickness (nm).

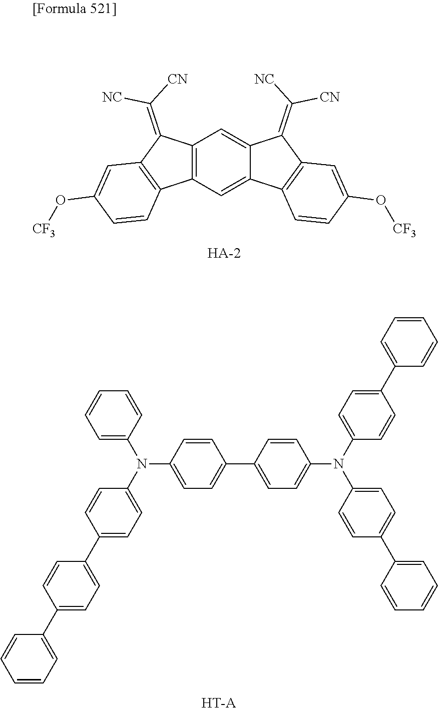 [SMILES: N#CC(C#N)=C1c2cc(OC(F)(F)F)ccc2-c2cc3c(cc21)C(=C(C#N)C#N)c1cc(OC(F)(F)F)ccc1-3 ; "HA-2" ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; "HT-A"]

The mobility evaluation device for the hole mobility is set in an impedance measurement apparatus to perform impedance measurement. In the impedance measurement, a measurement frequency is swept from 1 Hz to 1 MHz. At this time, an alternating current amplitude of 0.1 V and a direct current voltage V are applied to the device. A modulus M is calculated from a measured impedance Z using a relationship of a calculation formula (C1) below.

M=jωZ Calculation Formula (C1):

In the calculation formula (C1), j is an imaginary unit whose square is −1 and w is an angular frequency [rad/s].

In a bode plot in which an imaginary part of the modulus M is represented by an ordinate axis and the frequency [Hz] is represented by an abscissa axis, an electrical time constant τ of the mobility evaluation device is obtained from a frequency fmax showing a peak using the calculation formula (C2).

τ=1/(2πf max) Calculation Formula (C2):

π in the calculation formula (C2) is a symbol representing a circumference ratio.

The hole mobility is calculated from a relationship of a calculation formula (C3) below using τ obtained from the calculation formula (C2).

μh=d²/(Vτ) Calculation Formula (C3):

d in the calculation formula (C3) is a total film thickness of organic thin film(s) forming the device. In a case of the arrangement of the mobility evaluation device for the hole mobility, d=215 [nm] is satisfied.

The hole mobility herein is a value obtained in a case where a square root of an electric field intensity meets E^{1/2}=500 [V^{1/2}/cm^{1/2}]. The square root of the electric field intensity, E_{1/2}, can be calculated from a relationship of a calculation formula (C4) below.

E^{1/2}=V^{1/2}/d^{1/2} Calculation formula (C4):

For the impedance measurement, a 1260 type by Solartron Analytical is used as the impedance measurement apparatus, and for a higher accuracy, a 1296 type dielectric constant measurement interface by Solartron Analytical can be used together therewith.

### Blue-Emitting Organic EL Device

In an exemplary embodiment, the blue-emitting organic EL device 10B includes the anode 3, the hole transporting zone 7, the blue emitting region 5, the electron transporting layer 8, the electron injecting layer 9, and the cathode 4 in this order. The blue-emitting organic EL device 10B may include any other layer different from the layers depicted in FIG. 4.

### First Emitting Layer and Second Emitting Layer

The blue emitting region 5 includes the first emitting layer 51 and the second emitting layer 52. The blue emitting region 5 has a similar arrangement as the emitting region according to the first exemplary embodiment. A preferable range of the blue emitting region 5 is similar to that of the emitting region according to the first exemplary embodiment.

### Green-Emitting Organic EL Device

In an exemplary embodiment, the green-emitting organic EL device 10G includes the anode 3, the hole transporting zone 7, the green emitting region 53, the electron transporting layer 8, the electron injecting layer 9, and the cathode 4 in this order. The green-emitting organic EL device 10G may include any other layer different from the layers depicted in FIG. 4.

### Green Emitting Layer

In an exemplary embodiment, the green emitting layer 53, which is disposed between the hole transporting zone 7 and the electron transporting layer 8, is in direct contact with the electron transporting layer 8.

In the organic EL display device according to the exemplary embodiment, the green emitting layer preferably contains a host material. Accordingly, for instance, the green emitting layer contains 50 mass % or more of a host material with respect to the total mass of the green emitting layer.

In the organic EL display device according to the exemplary embodiment, it is preferable that the green emitting layer of the green-emitting organic EL device at least contains a green emitting compound that emits light having a maximum peak wavelength in a range from 500 nm to 550 nm. The green emitting compound is also preferably a fluorescent compound that exhibits fluorescence having a maximum peak wavelength in a range from 500 nm to 550 nm. Further, the green emitting compound is also preferably a phosphorescent compound that exhibits phosphorescence having a maximum peak wavelength in a range from 500 nm to 550 nm. Herein, the green light emission refers to light emission in which the maximum peak wavelength of emission spectrum is in a range from 500 nm to 550 nm.

The fluorescent compound is a compound capable of emitting in a singlet state. The phosphorescent compound is a compound capable of emitting in a triplet state.

Examples of a green fluorescent compound usable for the green emitting layer include an aromatic amine derivative. Examples of a green phosphorescent compound usable for the green emitting layer include an iridium complex.

In the organic EL display device according to the exemplary embodiment, the green emitting layer may contain a delayed fluorescent compound, which will be described later.

### Maximum Phosphorescence Peak Wavelength (PH-Peak)

A maximum peak wavelength (maximum phosphorescence peak wavelength) of a phosphorescent compound is measurable by the following method.

A measurement target compound is dissolved in EPA (diethylether:isopentane:ethanol=5:5:2 in volume ratio) so as to fall within a range from 10⁻⁵ mol/L to 10⁻⁴ mol/L, and the obtained EPA solution is encapsulated in a quartz cell to provide a measurement sample. A phosphorescence spectrum (ordinate axis: phosphorescent luminous intensity, abscissa axis: wavelength) of the measurement sample is measured at a low temperature (77K). The local maximum value closest to the short-wavelength region among the local maximum values of the phosphorescence spectrum is defined as the maximum phosphorescence peak wavelength. A spectrophotofluorometer F-7000 produced by Hitachi High-Tech Science Corporation can be used to measure phosphorescence. The measurement apparatus is not limited thereto. A combination of a cooling unit, a low temperature container, an excitation light source and a light-receiving unit may be used for measurement. Herein, the maximum peak wavelength of phosphorescence is occasionally referred to as the maximum phosphorescence peak wavelength (PH-peak).

### Green Organic Layer

In the organic EL display device according to the exemplary embodiment, the green-emitting organic EL device preferably includes the green organic layer between the green emitting layer and the hole transporting zone. The green organic layer may be in direct contact with the hole transporting zone. The green organic layer may be in direct contact with the green emitting layer.

The green organic layer contains a green organic material. As the green organic material, it is possible to use a hole transporting material according to the exemplary embodiment or a hole transporting zone material according to the first exemplary embodiment. Although the green organic material and the hole transporting zone material contained in the hole transporting zone may be the same compound or different compounds, the green organic material is preferably different from the hole transporting zone material. A hole mobility of the green organic material is preferably larger than a hole mobility of the hole transporting zone material contained in the hole transporting zone. The green organic material is a compound different from the host material and the green emitting compound contained in the green emitting layer.

In the organic EL display device according to the exemplary embodiment, an emission position in the green-emitting organic EL device is easily adjustable by providing the green organic layer in the green-emitting organic EL device.

### Red-Emitting Organic EL Device

In an exemplary embodiment, the red-emitting organic EL device 10R includes the anode 3, the hole transporting zone 7, the red emitting layer 54, the electron transporting layer 8, the electron injecting layer 9, and the cathode 4 in this order. The red-emitting organic EL device 10R may include any other layer different from the layers depicted in FIG. 4.

### Red Emitting Layer

In an exemplary embodiment, the red emitting layer 54, which is disposed between the hole transporting zone 7 and the electron transporting layer 8, is in direct contact with the electron transporting layer 8.

In the organic EL display device according to the exemplary embodiment, the red emitting layer preferably contains a host material. Accordingly, for instance, the red emitting layer 54 contains 50 mass % or more of a host material with respect to the total mass of the red emitting layer 54.

In the organic EL display device according to the exemplary embodiment, the red emitting layer of the red-emitting organic EL device preferably contains a red emitting compound that emits light having a maximum peak wavelength in a range from 600 nm to 640 nm. The red emitting compound is also preferably a fluorescent compound that exhibits fluorescence having a maximum peak wavelength in a range from 600 nm to 640 nm. Further, the red emitting compound is also preferably a phosphorescent compound that exhibits phosphorescence having a maximum peak wavelength in a range from 600 nm to 640 nm. Herein, the red light emission refers to light emission in which the maximum peak wavelength of emission spectrum is in a range from 600 nm to 640 nm.

Examples of a red fluorescent compound usable for the red emitting layer include a tetracene derivative and a diamine derivative. Examples of a red phosphorescent compound usable for the red emitting layer include metal complexes such as an iridium complex, platinum complex, terbium complex, and europium complex.

In the organic EL display device according to the exemplary embodiment, the red emitting layer may contain a delayed fluorescent compound, which will be described later.

### Red Organic Layer

In the organic EL display device according to the exemplary embodiment, the red-emitting organic EL device preferably includes the red organic layer between the red emitting layer and the hole transporting zone. The red organic layer may be in direct contact with the hole transporting zone. The red organic layer may be in direct contact with the red emitting layer.

The red organic layer contains a red organic material. As the red organic material, it is possible to use a hole transporting material according to the exemplary embodiment or a hole transporting zone material according to the first exemplary embodiment. Although the red organic material and the hole transporting zone material contained in the hole transporting zone may be the same compound or different compounds, the red organic material is preferably different from the hole transporting zone material. A hole mobility of the red organic material is preferably larger than a hole mobility of the hole transporting zone material contained in the hole transporting zone. The red organic material is a compound different from the host material and the red emitting compound contained in the red emitting layer.

Although the red organic material contained in the red organic layer of the red-emitting organic EL device and the green organic material contained in the green emitting layer of the green-emitting organic EL device may be the same compound or different compounds, the red organic material is preferably different from the green organic material. A hole mobility of the red organic material is preferably larger than a hole mobility of the green organic material.

The film thickness of the red organic layer is preferably larger than the film thickness of the green organic layer.

In the organic EL display device according to the exemplary embodiment, an emission position in the red-emitting organic EL device is easily adjustable by providing the red organic layer in the red-emitting organic EL device.

It is preferable that the host material contained in the green emitting layer and the host material contained in the red emitting layer are each, for instance, a compound for dispersing a highly emittable substance (dopant material) in the emitting layers. As the host material contained in the green emitting layer and the host material contained in the red emitting layer, it is preferable to use a substance having a higher lowest unoccupied molecular orbital (LUMO) level and a lower highest occupied molecular orbital (HOMO) level than the highly emittable substance.

For instance, the following compounds (1) to (4) can be each independently used as the host material contained in the green emitting layer and the host material contained in the red emitting layer,
(1) a metal complex such as an aluminum complex, beryllium complex, or zinc complex
(2) a heterocyclic compound such as an oxadiazole derivative, benzimidazole derivative, or phenanthroline derivative
(3) a fused aromatic compound such as a carbazole derivative, anthracene derivative, phenanthrene derivative, pyrene derivative or chrysene derivative
(4) an aromatic amine compound such as a triarylamine derivative or a fused polycyclic aromatic amine derivative.

In the organic EL display device according to the exemplary embodiment, at least one of the green-emitting organic EL device or the red-emitting organic EL device may contain a delayed fluorescent compound. The delayed fluorescent compound is preferably not a metal complex. The delayed fluorescent compound is preferably an organic compound containing no metal atom.

In the organic EL display device according to the exemplary embodiment, when at least one of the green-emitting organic EL device or the red-emitting organic EL device contains a delayed fluorescent compound, at least one of the green emitting layer of the green-emitting organic EL device or the red emitting layer of the red-emitting organic EL device preferably contains a delayed fluorescent compound. The emitting layer that contains the delayed fluorescent compound is occasionally referred to as a delayed fluorescent layer.

The delayed fluorescent layer preferably contains a delayed fluorescent compound as a host material. The delayed fluorescent layer preferably contains a delayed fluorescent compound as a host material and a fluorescent compound. A singlet energy of the delayed fluorescent compound as the host material is preferably larger than that of the fluorescent compound.

The delayed fluorescent layer preferably does not contain any heavy-metal complex and any phosphorescent rare earth metal complex. Here, examples of the heavy-metal complex include an iridium complex, osmium complex, and platinum complex. The delayed fluorescent layer also preferably contains no metal complex.

In the organic EL display device according to the exemplary embodiment, the emitting layer containing the delayed fluorescent compound may contain a first organic material of which affinity is smaller than that of the delayed fluorescent compound. That is, preferably, the delayed fluorescent layer contains a delayed fluorescent compound and the first organic material and an affinity of the delayed fluorescent compound Af(M2) and an affinity of the first organic material Af(M1) satisfy a relationship of a numerical formula (Numerical Formula 6A) below.

Af(M2)−Af(M1)>0 eV (Numerical Formula 6A)

A value of the affinity Af of a measurement target (compound or material) is a value calculated by a numerical formula (Numerical Formula 6) below. The unit of the affinity Af is eV.

Af=−1.19×(Ere−Efc)−4.78 eV (Numerical Formula 6)

In the numerical formula (Numerical Formula 6), Ere and Efc are as follows:
Ere: first reduction potential of measurement target (DPV, Negative scan)
Efc: first oxidation potential of ferrocene (DPV, Positive scan), (ca. +0.55V vs Ag/AgCl)
Oxidation-reduction potential is measured by the differential pulse voltammetry (DPV) method using an electrochemical analyzer (CHI630B produced by ALS).

A sample solution used for the measurement is prepared by using N,N-dimethylformamide (DMF) as a solvent; dissolving the measurement target so that its concentration is 1.0 mmol/L; and dissolving tetrabutylammmonium hexafluorophosphate (TBHP) as a supporting electrolyte so that its concentration is 100 mmol/L. A glassy carbon electrode is used as a working electrode. A platinum (Pt) electrode is used as a counter electrode.

A singlet energy of the first organic material is preferably larger than that of the delayed fluorescent compound.

In the organic EL display device according to the exemplary embodiment, the delayed fluorescent layer also preferably contains the first organic material, a delayed fluorescent compound as a host material, and a fluorescent compound. In this case, preferably, the singlet energy of the first organic material is larger than that of the delayed fluorescent compound and the singlet energy of the delayed fluorescent compound is larger than that of the fluorescent compound.

In the organic EL display device according to the exemplary embodiment, at least one of the green emitting layer or the red emitting layer containing no delayed fluorescent compound also preferably contains a phosphorescent compound. For instance, when the green emitting layer contains a delayed fluorescent compound and the red emitting layer contains no delayed fluorescent compound, the red emitting layer contains a phosphorescent compound. In the organic EL display device according to the exemplary embodiment, also preferably, the green emitting layer and the red emitting layer do not simultaneously contain a delayed fluorescent compound and a phosphorescent compound.

### Delayed Fluorescence

Delayed fluorescence is explained in “Yuki Hando-tai no Debaisu Bussei (Device Physics of Organic Semiconductors)” (edited by ADACHI, Chihaya, published by Kodansha, on pages 261-268). This document describes that, if an energy difference ΔE₁₃ of a fluorescent material between an excited singlet state and an excited triplet state is reducible, a reverse energy transfer from the excited triplet state to the excited singlet state, which usually occurs at a low transition probability, would occur at a high efficiency to express thermally activated delayed fluorescence (TADF). Further, a generation mechanism of delayed fluorescence is explained in FIG. 10.38 in the document. The delayed fluorescent compound (delayed fluorescent material) in the exemplary embodiment) is preferably a compound exhibiting thermally activated delayed fluorescence generated by such a mechanism.

In general, emission of delayed fluorescence can be confirmed by measuring the transient PL (photo luminescence).

The behavior of delayed fluorescence can also be analyzed based on the decay curve obtained from the transient PL measurement. The transient PL measurement is a method of irradiating a sample with a pulse laser to excite the sample, and measuring the decay behavior (transient characteristics) of PL emission after the irradiation is stopped. PL emission in TADF materials is classified into a light emission component from a singlet exciton generated by the first PL excitation and a light emission component from a singlet exciton generated via a triplet exciton. The lifetime of the singlet exciton generated by the first PL excitation is on the order of nanoseconds and is very short. Therefore, light emission from the singlet exciton rapidly attenuates after irradiation with the pulse laser.

On the other hand, the delayed fluorescence is gradually attenuated due to light emission from a singlet exciton generated via a triplet exciton having a long lifetime. As described above, there is a large temporal difference between the light emission from the singlet exciton generated by the first PL excitation and the light emission from the singlet exciton generated via the triplet exciton. Therefore, the luminous intensity derived from delayed fluorescence can be determined.

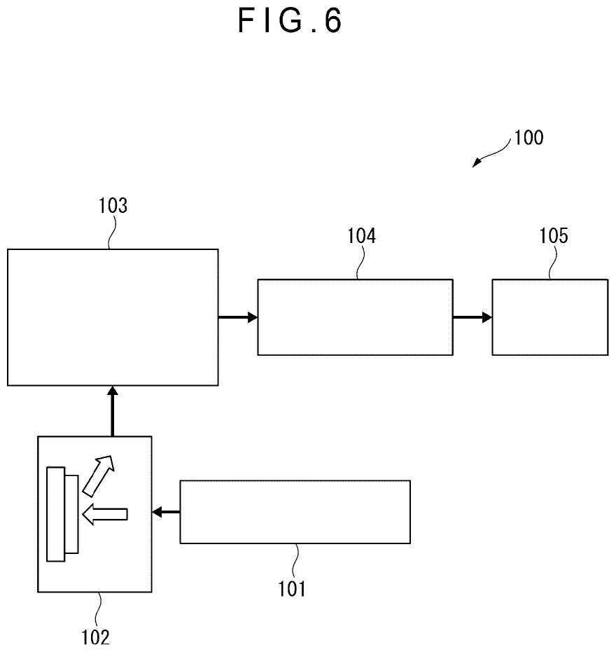

FIG. 6 is a schematic diagram of an exemplary apparatus for measuring the transient PL. An exemplary method of measuring a transient PL using FIG. 6 and an example of behavior analysis of delayed fluorescence will be described.

A transient PL measuring apparatus 100 in FIG. 6 includes: a pulse laser 101 capable of radiating light having a predetermined wavelength; a sample chamber 102 configured to house a measurement sample; a spectrometer 103 configured to divide light radiated from the measurement sample; a streak camera 104 configured to provide a two-dimensional image; and a personal computer 105 configured to import and analyze the two-dimensional image. An apparatus for measuring the transient PL is not limited to the apparatus depicted in FIG. 6.

The sample housed in the sample chamber 102 is obtained by forming a thin film, in which a matrix material is doped with a doping material at a concentration of 12 mass %, on the quartz substrate.

The thin film sample housed in the sample chamber 102 is irradiated with the pulse laser from the pulse laser 101 to excite the doping material. Emission is extracted in a direction of 90 degrees with respect to a radiation direction of the excited light. The extracted emission is divided by the spectrometer 103 to form a two-dimensional image in the streak camera 104. As a result, the two-dimensional image is obtainable in which the ordinate axis represents a time, the abscissa axis represents a wavelength, and a bright spot represents a luminous intensity. When this two-dimensional image is taken out at a predetermined time axis, an emission spectrum in which the ordinate axis represents the luminous intensity and the abscissa axis represents the wavelength is obtainable. Moreover, when this two-dimensional image is taken out at the wavelength axis, a decay curve (transient PL) in which the ordinate axis represents a logarithm of the luminous intensity and the abscissa axis represents the time is obtainable.

For instance, a thin film sample A was prepared as described above from a reference compound H1 as a matrix material and a reference compound D1 as a doping material, and was measured in terms of the transient PL.

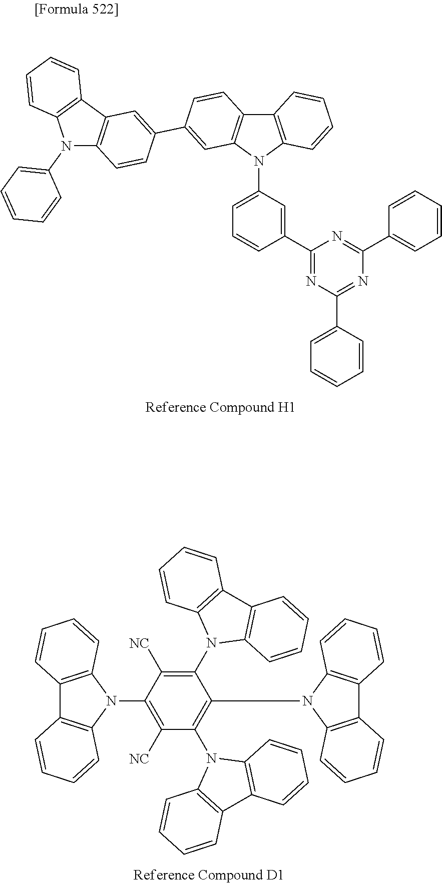 [SMILES: c1ccc(-c2nc(-c3ccccc3)nc(-c3cccc(-n4c5ccccc5c5ccc(-c6ccc7c(c6)c6ccccc6n7-c6ccccc6)cc54)c3)n2)cc1 ; N#Cc1c(-n2c3ccccc3c3ccccc32)c(C#N)c(-n2c3ccccc3c3ccccc32)c(-n2c3ccccc3c3ccccc32)c1-n1c2ccccc2c2ccccc21]

The decay curve was analyzed with respect to the above thin film sample A and a thin film sample B. The thin film sample B was produced in the same manner as described above from a reference compound H2 as a matrix material and the reference compound D1 as a doping material.

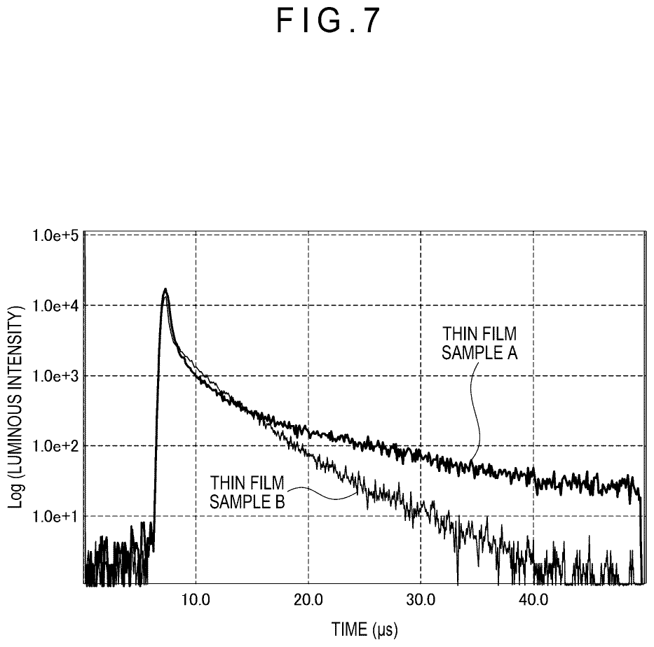

FIG. 7 illustrates decay curves obtained from the transient PL obtained by measuring the thin film samples A and B.

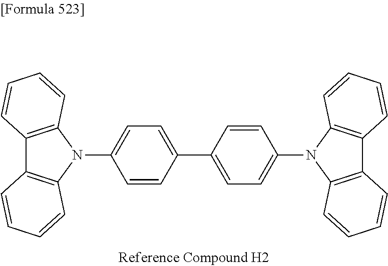 [SMILES: c1ccc2c(c1)c1ccccc1n2-c1ccc(-c2ccc(-n3c4ccccc4c4ccccc43)cc2)cc1]

As described above, an emission decay curve in which the ordinate axis represents the luminous intensity and the abscissa axis represents the time can be obtained by the transient PL measurement. Based on the emission decay curve, a fluorescence intensity ratio between fluorescence emitted from a singlet state generated by photo-excitation and delayed fluorescence emitted from a singlet state generated by reverse energy transfer via a triplet state can be estimated. In a delayed fluorescent material, a ratio of the intensity of the slowly decaying delayed fluorescence to the intensity of the promptly decaying fluorescence is relatively large.

Specifically, Prompt emission and Delay emission are present as emission from the delayed fluorescent material. Prompt emission is observed promptly when the excited state is achieved by exciting the compound of the exemplary embodiment with a pulse beam (i.e., a beam emitted from a pulse laser) having a wavelength absorbable by the delayed fluorescent material. Delay emission is observed not promptly when the excited state is achieved but after the excited state is achieved.

Herein, a sample produced by the following method is used for measuring delayed fluorescence of the delayed fluorescent material. For instance, the delayed fluorescent material is dissolved in toluene to prepare a dilute solution with an absorbance of 0.05 or less at the excitation wavelength to eliminate the contribution of self-absorption. In order to prevent quenching due to oxygen, the sample solution is frozen and degassed and then sealed in a cell with a lid under an argon atmosphere to obtain an oxygen-free sample solution saturated with argon.

The fluorescence spectrum of the sample solution is measured with a spectrofluorometer FP-8600 (produced by JASCO Corporation), and the fluorescence spectrum of a 9,10-diphenylanthracene ethanol solution is measured under the same conditions. Using the fluorescence area intensities of both spectra, the total fluorescence quantum yield is calculated by an equation (1) in Morris et al. J. Phys. Chem. 80 (1976) 969.

An amount of Prompt emission, an amount of Delay emission and a ratio between their amounts can be obtained according to the method as described in “Nature 492, 234-238, 2012” (Reference Document 1). The amount of Prompt emission and the amount of Delay emission may be calculated using an apparatus different from one described in Reference Document 1 or one depicted in FIG. 6.

In the exemplary embodiment, provided that an amount of Prompt emission of a measurement target compound (delayed fluorescent material) is denoted by X_{P} and an amount of Delay emission is denoted by X_{D}, a value of X_{D}/X_{P} is preferably 0.05 or more.

The amounts of Prompt emission and Delay emission and the ratio between their amounts in compounds other than the delayed fluorescent material herein are measured in the same manner as those of the delayed fluorescent material.

Referring to FIG. 4, the organic EL display device according to the exemplary embodiment is further explained. Descriptions on the same arrangements as those of the organic EL device according to the first exemplary embodiment are simplified or omitted.

### Anode

In an exemplary embodiment, the anode 3 is arranged opposite the cathode 4.

In an exemplary embodiment, the anode 3 is typically a non-common layer. In an exemplary embodiment, for instance, when the anode 3 is a non-common layer, the respective anodes in the blue-emitting organic EL device 10B, the green-emitting organic EL device 10G and the red-emitting organic EL device 10R are physically separated from each other, and specifically, may be insulated from each other by an insulation material (not illustrated) or the like.

### Cathode

In an exemplary embodiment, the cathode 4 is arranged opposite the anode 3.

In an exemplary embodiment, the cathode 4 may be a common layer or a non-common layer.

In an exemplary embodiment, the cathode 4 is preferably a common layer provided in a shared manner across the blue-emitting organic EL device 10B, the green-emitting organic EL device 10G, and the red-emitting organic EL device 10R.

In an exemplary embodiment, the cathode 4 is in direct contact with the electron injecting layer 9.

In an exemplary embodiment, the cathode 4 is a common layer. In this case, the film thickness of the cathode 4 is constant over the blue-emitting organic EL device 10B, the green-emitting organic EL device 10G, and the red-emitting organic EL device 10R. When the cathode 4 is a common layer, the cathode 4 provided for the blue-emitting organic EL device 10B, the green-emitting organic EL device 10G, and the red-emitting organic EL device 10R can be produced without changing a mask or the like. The organic EL display device 100A thus has enhanced productivity.

### Electron Transporting Layer

In an exemplary embodiment, the electron transporting layer 8 is a common layer provided in a shared manner across the blue-emitting organic EL device 10B, the green-emitting organic EL device 10G, and the red-emitting organic EL device 10R.

In an exemplary embodiment, the electron transporting layer 8 is provided between the electron injecting layer 9 and the emitting layers of the blue-emitting organic EL device 10B, the green-emitting organic EL device 10G, and the red-emitting organic EL device 10R.

In an exemplary embodiment, the side of the electron transporting layer 8 close to the anode 3 is in direct contact with the second emitting layer 52, the green emitting layer 53, and the red emitting layer 54.

The side of the electron transporting layer 8 close to the cathode 4 is in direct contact with the electron injecting layer 9.

In an exemplary embodiment, the electron transporting layer 8 is a common layer. In this case, the film thickness of the electron transporting layer 8 is constant over the blue-emitting organic EL device 10B, the green-emitting organic EL device 10G, and the red-emitting organic EL device 10R. When the electron transporting layer 8 is a common layer, the electron transporting layer 8 provided for the blue-emitting organic EL device 10B, the green-emitting organic EL device 10G, and the red-emitting organic EL device 10R can be produced without changing a mask or the like. The organic EL display device 100A thus has enhanced productivity.

### Electron Injecting Layer

In an exemplary embodiment, the electron injecting layer 9 is a common layer provided in a shared manner across the blue-emitting organic EL device 10B, the green-emitting organic EL device 10G, and the red-emitting organic EL device 10R.

In an exemplary embodiment, the electron injecting layer 9 is disposed between the electron transporting layer 8 and the cathode 4.

In an exemplary embodiment, the electron injecting layer 9 is in direct contact with the electron transporting layer 8.

In an exemplary embodiment, the electron injecting layer 9 is a common layer. In this case, the film thickness of the electron injecting layer 9 is constant over the blue-emitting organic EL device 10B, the green-emitting organic EL device 10G, and the red-emitting organic EL device 10R. When the electron injecting layer 9 is a common layer, the electron injecting layer 9 provided for the blue-emitting organic EL device 10B, the green-emitting organic EL device 10G, and the red-emitting organic EL device 10R can be produced without changing a mask or the like. The organic EL display device 100A thus has enhanced productivity.

In an exemplary embodiment, any other layer than the first emitting layer 51, the second emitting layer 52, the green emitting layer 53, the red emitting layer 54, the green organic layer 531, and the red organic layer 541 is preferably provided in a shared manner across the blue-emitting organic EL device 10B, the green-emitting organic EL device 10G, and the red-emitting organic EL device 10R. Reducing the number of the non-common layers in the organic EL display device 100A improves productivity of the display device.

### Method of Producing Organic EL Display Device

Explanation is made about a method of producing the organic EL display device 100A (FIG. 4) according to an exemplary embodiment.

First, the anode 3 is formed on the substrate 2A.

Subsequently, the organic layers as common layers (from the organic layer L1 to the organic layer Ln) are sequentially formed on the anode 3 to extend thereover, forming the hole transporting zone 7 as a common zone. Respective organic layers in the hole transporting zone 7 of the blue-emitting organic EL device 10B, the green-emitting organic EL device 10G, and the red-emitting organic EL device 10R are formed to have a constant film thickness using the same material.

Subsequently, the first emitting layer 51 is formed on the hole transporting zone 7 in a region corresponding to the anode 3 of the blue-emitting organic EL device 10B using a predetermined film-forming mask (mask for the blue-emitting organic EL device). After that, the second emitting layer 52 is formed on the first emitting layer 51.

Subsequently, the green emitting layer 53 with a predetermined film thickness is formed on the hole transporting zone 7 in a region corresponding to the anode 3 of the green-emitting organic EL device 10G using a predetermined film-forming mask (mask for the green-emitting organic EL device).

Subsequently, the red emitting layer 54 with a predetermined film thickness is formed on the hole transporting zone 7 in a region corresponding to the anode 3 of the red-emitting organic EL device 10R using a predetermined film-forming mask (mask for the red-emitting organic EL device).

The first emitting layer 51, the second emitting layer 52, the green emitting layer 53, and the red emitting layer 54 are formed from mutually different materials.

After the formation of the hole transporting zone 7, the order of forming the non-common layers of the blue-emitting organic EL device 10B, the green-emitting organic EL device 10G, and the red-emitting organic EL device 10R is not particularly limited.

For instance, after forming the hole transporting zone 7, the green emitting layer 53 of the green-emitting organic EL device 10G may be formed, then the red emitting layer 54 of the red-emitting organic EL device 10R may be formed, and then the first emitting layer 51 and the second emitting layer 52 of the blue-emitting organic EL device 10B may be formed.

Alternatively, for instance, after forming the hole transporting zone 7, the red emitting layer 54 of the red-emitting organic EL device 10R may be formed, then the green emitting layer 53 of the green-emitting organic EL device 10G may be formed, and then the first emitting layer 51 and the second emitting layer 52 of the blue-emitting organic EL device 10B may be formed.

Subsequently, the electron transporting layer 8 as a common layer is formed on the second emitting layer 52, the green emitting layer 53, and the red emitting layer 54 to extend thereover. The electron transporting layer 8 of the blue-emitting organic EL device 10B, the green-emitting organic EL device 10G, and the red-emitting organic EL device 10R is formed to have a constant film thickness using the same material.

Subsequently, the electron injecting layer 9 as a common layer is formed on the electron transporting layer 8. The electron injecting layer 9 of the blue-emitting organic EL device 10B, the green-emitting organic EL device 10G, and the red-emitting organic EL device 10R is formed to have a constant film thickness using the same material.

Subsequently, the cathode 4 as a common layer is formed on the electron injecting layer 9. The cathode 4 of the blue-emitting organic EL device 10B, the green-emitting organic EL device 10G, and the red-emitting organic EL device 10R is formed to have a constant film thickness using the same material.

The organic EL display device 100A depicted in FIG. 4 is produced as described above.

Next, explanation is made about a method of producing the organic EL display device 200 (FIG. 5) according to an exemplary embodiment.

First, the anode 3 is formed on the substrate 2A.

Subsequently, the organic layers as common layers (from the organic layer L1 to the organic layer Ln) are sequentially formed on the anode 3 to extend thereover, forming the hole transporting zone 7 as a common zone. Respective organic layers in the hole transporting zone 7 of the blue-emitting organic EL device 10B, the green-emitting organic EL device 20G, and the red-emitting organic EL device 20R are formed to have a constant film thickness using the same material.

Subsequently, the first emitting layer 51 is formed on the hole transporting zone 7 in a region corresponding to the anode 3 of the blue-emitting organic EL device 10B using a predetermined film-forming mask (mask for the blue-emitting organic EL device). After that, the second emitting layer 52 is formed on the first emitting layer 51.

Subsequently, the green organic layer 531 with a predetermined film thickness is formed on the hole transporting zone 7 in a region corresponding to the anode 3 of the green-emitting organic EL device 20G using a predetermined film-forming mask (mask for the green-emitting organic EL device). After forming the green organic layer 531, the green emitting layer 53 is formed on the green organic layer 531.

Subsequently, the red organic layer 541 with a predetermined film thickness is formed on the hole transporting zone 7 in a region corresponding to the anode 3 of the red-emitting organic EL device 20R using a predetermined film-forming mask (mask for the red-emitting organic EL device). After forming the red organic layer 541, the red emitting layer 54 is formed on the red organic layer 541.

The first emitting layer 51, the second emitting layer 52, the green emitting layer 53, and the red emitting layer 54 are formed from mutually different materials.

After the formation of the hole transporting zone 7, the order of forming the non-common layers of the blue-emitting organic EL device 10B, the green-emitting organic EL device 20G, and the red-emitting organic EL device 20R is not particularly limited.

For instance, after forming the hole transporting zone 7, the green organic layer 531 and the green emitting layer 53 of the green-emitting organic EL device 20G may be formed, then the red organic layer 541 and the red emitting layer 54 of the red-emitting organic EL device 20R may be formed, and then the first emitting layer 51 and the second emitting layer 52 of the blue-emitting organic EL device 10B may be formed.

Alternatively, for instance, after forming the hole transporting zone 7, the red organic layer 541 and the red emitting layer 54 of the red-emitting organic EL device 20R may be formed, then the green organic layer 531 and the green emitting layer 53 of the green-emitting organic EL device 20G may be formed, and then the first emitting layer 51 and the second emitting layer 52 of the blue-emitting organic EL device 10B may be formed.

Subsequently, the electron transporting layer 8, the electron injecting layer 9, and the cathode 4 as common layers are formed by the same method as the method of producing the organic EL display device 100A depicted in FIG. 4 described above.

The organic EL display device 200 depicted in FIG. 5 is produced as described above.

According to the second exemplary embodiment, an existing production line is usable to produce the organic EL display device including the organic EL devices with layered emitting layers as the pixels.

### Third Exemplary Embodiment

### Electronic Device

An electronic device according to a third exemplary embodiment is installed with one of the organic EL devices according to the above exemplary embodiment or one of the organic EL display devices according to the above exemplary embodiment. Examples of the electronic device include a display device and a light-emitting unit. Examples of the display device include a display component (e.g., an organic EL panel module), TV, mobile phone, tablet and personal computer. Examples of the light-emitting unit include an illuminator and a vehicle light.

### Modification of Embodiment(s)

The scope of the invention is not limited to the above-described exemplary embodiments but includes any modification and improvement as long as such modification and improvement are compatible with the invention.

For instance, the number of emitting layers is not limited to two, and more than two emitting layers may be layered. When the organic EL device includes more than two emitting layers, it is only necessary that at least two of the emitting layers should satisfy the requirements mentioned in the above exemplary embodiment(s). For instance, the rest of the emitting layers may be a fluorescent emitting layer or a phosphorescent emitting layer with use of emission caused by electron transfer from the triplet excited state directly to the ground state.

When the organic EL device includes a plurality of emitting layers, these emitting layers may be mutually adjacently provided, or may form a so-called tandem organic EL device in which a plurality of emitting units are layered via an intermediate layer.

Further, for instance, a blocking layer is optionally provided adjacent to a side of the emitting layer close to the cathode. The blocking layer provided in direct contact with the side of the emitting layer close to the cathode preferably blocks at least one of holes or excitons.

For instance, when the blocking layer is provided in contact with the side of the emitting layer close to the cathode, the blocking layer permits transport of electrons, and blocks holes from reaching a layer provided closer to the cathode (e.g., the electron transporting layer) beyond the blocking layer. When the organic EL device includes the electron transporting layer, the blocking layer is preferably interposed between the emitting layer and the electron transporting layer.

Alternatively, the blocking layer may be provided adjacent to the emitting layer so that the excitation energy does not leak out from the emitting layer toward neighboring layer(s). The blocking layer blocks excitons generated in the emitting layer from being transferred to a layer(s) (e.g., the electron transporting layer and the hole transporting layer) closer to the electrode(s) beyond the blocking layer.

The emitting layer is preferably bonded with the blocking layer.

The specific structure, shape, and the like of the components in the invention may be designed in any manner as long as an object of the invention can be achieved.

### EXAMPLES

The invention will be described in further detail with reference to Examples. The scope of the invention is by no means limited to Examples.

### Compounds

The first host material and the second host material used for producing the organic EL devices in Examples are shown below.

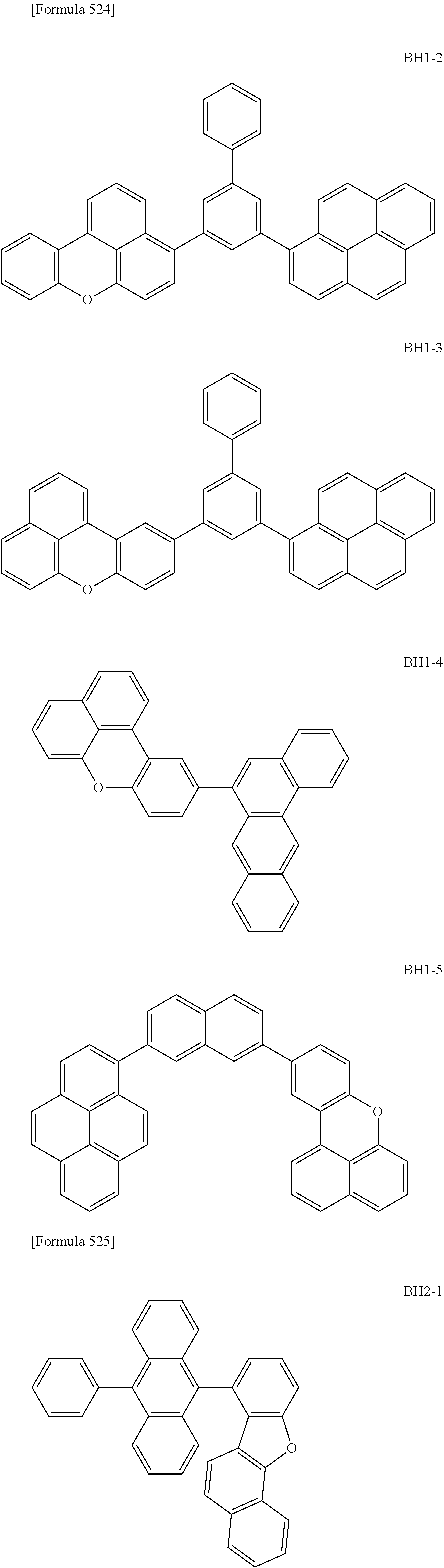 [SMILES: c1ccc(-c2cc(-c3ccc4c5c(cccc35)-c3ccccc3O4)cc(-c3ccc4ccc5cccc6ccc3c4c56)c2)cc1 ; c1ccc(-c2cc(-c3ccc4c(c3)-c3cccc5cccc(c35)O4)cc(-c3ccc4ccc5cccc6ccc3c4c56)c2)cc1 ; c1ccc2cc3c(cc2c1)c(-c1ccc2c(c1)-c1cccc4cccc(c14)O2)cc1ccccc13 ; c1cc2c3c(cccc3c1)-c1cc(-c3ccc4ccc(-c5ccc6ccc7cccc8ccc5c6c78)cc4c3)ccc1O2 ; c1ccc(-c2c3ccccc3c(-c3cccc4oc5c6ccccc6ccc5c34)c3ccccc23)cc1]

The first host material used for producing the organic EL devices in Comparatives is shown below.

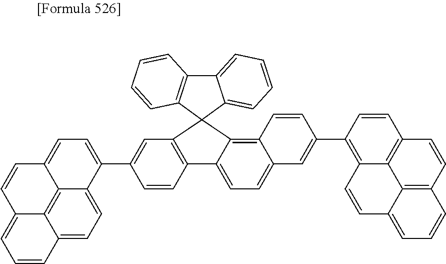 [SMILES: c1ccc2c(c1)-c1ccccc1C21c2cc(-c3ccc4ccc5cccc6ccc3c4c56)ccc2-c2ccc3cc(-c4ccc5ccc6cccc7ccc4c5c67)ccc3c21]

Other compounds used for producing the organic EL devices in Examples and Comparatives are shown below.

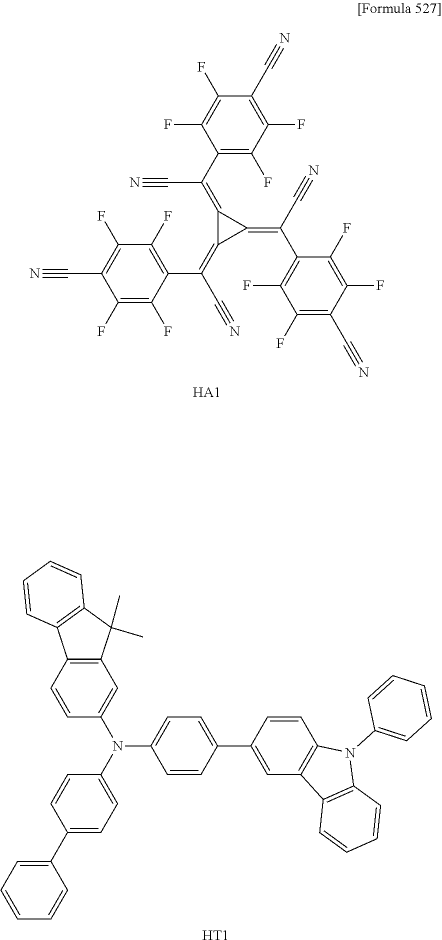

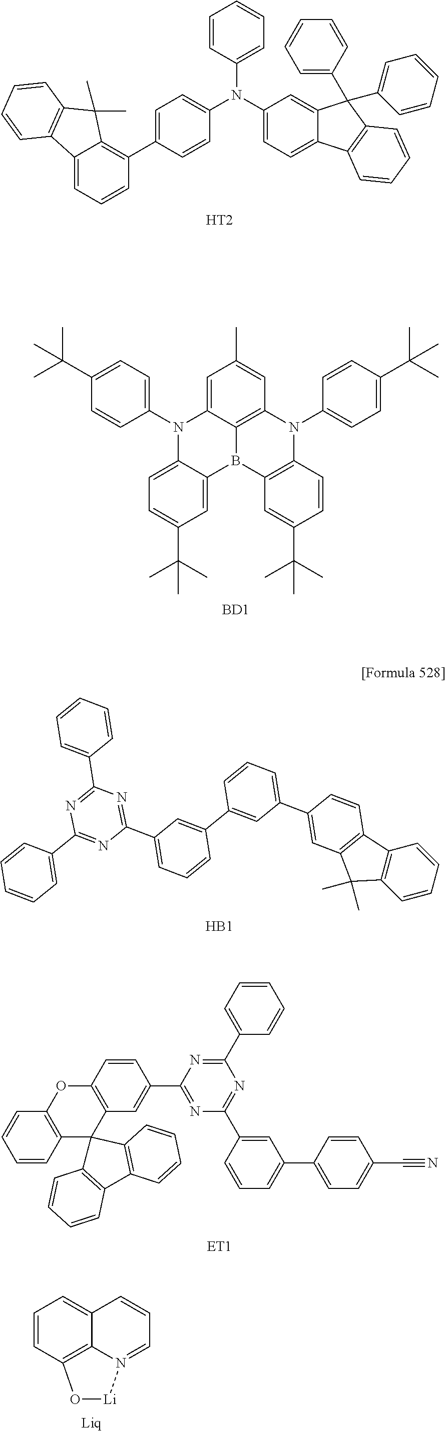

### Production 1 of Organic EL Device

### Example 1-1

A glass substrate (size: 25 mm×75 mm×1.1 mm thick, produced by Geomatec Co., Ltd.) having an ITO transparent electrode (anode) was ultrasonic-cleaned in isopropyl alcohol for five minutes, and then UV-ozone-cleaned for 30 minutes. The film thickness of the ITO transparent electrode was 130 nm.

After the glass substrate having the transparent electrode line was cleaned, the glass substrate was mounted on a substrate holder of a vacuum deposition apparatus. Firstly, a compound HT1 and a compound HA1 were co-deposited on a surface of the glass substrate where the transparent electrode line was provided in a manner to cover the transparent electrode, thereby forming a 10-nm-thick second organic layer (also referred to as a hole injecting layer (HI)). The ratios of the compound HT1 and the compound HA1 in the second organic layer were 97 mass % and 3 mass %, respectively.

The compound HT1 was vapor-deposited on the second organic layer to form a 90-nm-thick first organic layer (also referred to as a hole transporting layer (HT) or an electron blocking layer (EBL)).

As described above, a hole transporting zone, which was formed by the first organic layer and the second organic layer containing the compound HT1 (common hole transporting zone material), was formed.

A compound BH1-2 (first host material (BH)) and a compound BD1 (first emitting compound (BD)) were co-deposited on the first organic layer such that the ratio of the compound BD1 accounted for 1 mass %, thereby forming a 5-nm-thick first emitting layer.

A compound BH2-1 (second host material (BH)) and the compound BD1 (second emitting compound (BD)) were co-deposited on the first emitting layer such that the ratio of the compound BD1 accounted for 1 mass %, thereby forming a 15-nm-thick second emitting layer.

A compound HB1 was vapor-deposited on the second emitting layer to form a 5-nm-thick first electron transporting layer (also referred to as a hole blocking layer (HBL)).

A compound ET1 and a compound Liq were co-deposited on the first electron transporting layer to form a 25-nm-thick second electron transporting layer (ET). The ratios of the compound ET1 and the compound Liq in the second electron transporting layer were 50 mass % and 50 mass %, respectively.

The compound Liq was vapor-deposited on the second electron transporting layer to form a 1-nm-thick electron injecting layer.

Metal Al was vapor-deposited on the electron injecting layer to form an 80-nm-thick cathode.

A device arrangement of the organic EL device in Example 1-1 is roughly shown as follows.

ITO(130)/HT1:HA1(10,97%:3%)/HT1(90)/BH1-2:BD1(5,99%:1%)/BH2-1:BD1(15,99%:1%)/HB1(5)/ET1:Liq(25,50%:50%)/Liq(1)/Al(80)

Numerals in parentheses represent a film thickness (unit: nm).

The numerals (97%:3%) represented by percentage in the same parentheses indicate a ratio (mass %) between the compound HT1 and the compound HA1 in the second organic layer. The numerals (99%: 1%) represented by percentage in the same parentheses indicate a ratio (mass %) between the host material (compound BH1-2 or BH2-1) and the emitting compound (compound BD1) in the first emitting layer or the second emitting layer. The numerals (50%:50%) represented by percentage in the same parentheses indicate a ratio (mass %) between the compound ET1 and the compound Liq in the second electron transporting layer. Similar notations apply to the description below.

### Examples 1-2 to 1-4 and Comparative 1-1

Organic EL devices in Examples 1-2 to 1-4 and Comparative 1-1 were each produced in the same manner as in Example 1-1 except that the first host material in the first emitting layer was replaced with the first host material shown in Table 1.

### Evaluation of Organic EL Devices

The produced organic EL devices were evaluated as follows. Table 1 shows the results.

### External Quantum Efficiency EQE

Voltage was applied to the organic EL device such that a current density was 10 mA/cm², where spectral radiance spectrum was measured by a spectroradiometer CS-2000 (produced by Konica Minolta, Inc.). The external quantum efficiency EQE (unit: %) was calculated based on the obtained spectral radiance spectra, assuming that the spectra was provided under a Lambertian radiation.

TABLE 1

| | Hole transporting zone | | | | | | | |
|---|---|---|---|---|---|---|---|---|
| | | First | Common hole | Emitting layer | | | | |
| | Second organic | organic | transporting zone | First emitting layer | | | | |
| | layer | layer | material | First host material | | | | |
| | Compound | Compound | Compound | | S₁ | T₁ | Dipole | Ip |
| | Name | Name | Name | Name | [eV] | [eV] | [D] | [eV] |
| Comp. 1-1 | HT1 and | HT1 | HT1 | BH1-ref | 2.96 | 2.02 | 0.29 | 5.88 |
| | HA1 | | | | | | | |
| Ex. 1-1 | HT1 and | HT1 | HT1 | BH1-2 | 3.03 | 2.09 | 0.79 | 5.70 |
| | HA1 | | | | | | | |
| Ex. 1-2 | HT1 and | HT1 | HT1 | BH1-3 | 3.08 | 2.06 | 0.75 | 5.75 |
| | HA1 | | | | | | | |
| Ex. 1-3 | HT1 and | HT1 | HT1 | BH1-4 | 3.08 | 2.02 | 0.63 | 5.79 |
| | HA1 | | | | | | | |
| Ex. 1-4 | HT1 and | HT1 | HT1 | BH1-5 | 3.07 | 2.04 | 0.70 | 5.78 |
| | HA1 | | | | | | | |

| | Emitting layer | | | | | | | |
|---|---|---|---|---|---|---|---|---|
| | | | | Second emitting layer | | | | |
| | First emitting layer | | | | | | Second | Device |
| | First emitting compound | | | Second host material | | | emitting | Evaluation |
| | | S₁ | T₁ | | S₁ | T₁ | compound | EQE |
| | Name | [eV] | [eV] | Name | [eV] | [eV] | Name | [%] |
| Comp. 1-1 | BD1 | 2.71 | 2.64 | BH2-1 | 3.01 | 1.82 | BD1 | 8.6 |
| Ex. 1-1 | BD1 | 2.71 | 2.64 | BH2-1 | 3.01 | 1.82 | BD1 | 9.8 |
| Ex. 1-2 | BD1 | 2.71 | 2.64 | BH2-1 | 3.01 | 1.82 | BD1 | 9.7 |
| Ex. 1-3 | BD1 | 2.71 | 2.64 | BH2-1 | 3.01 | 1.82 | BD1 | 9.8 |
| Ex. 1-4 | BD1 | 2.71 | 2.64 | BH2-1 | 3.01 | 1.82 | BD1 | 9.7 |

The organic EL devices in Examples 1-1 to 1-4 using the first host material of which dipole was 0.4 D or more emitted light at a higher luminous efficiency than the organic EL device in Comparative 1-1 using the first host material of which dipole was less than 0.4 D.

### Production 2 of Organic EL Device

### Example 2-1

The organic EL device in Example 2-1 was produced in the same manner as in Example 1-1 except that the hole transporting zone was formed as follows.

Similar to Example 1-1, after the glass substrate having the transparent electrode line was cleaned, the glass substrate was mounted on a substrate holder of a vacuum deposition apparatus. Firstly, the compound HT1 and the compound HA1 were co-deposited on a surface of the glass substrate where the transparent electrode line was provided in a manner to cover the transparent electrode, thereby forming a 10-nm-thick second organic layer (also referred to as a hole injecting layer (HI)). The ratios of the compound HT1 and the compound HA1 in the second organic layer were 97 mass % and 3 mass %, respectively.

The compound HT1 and a compound HT2 were co-deposited on the second organic layer to form a 90-nm-thick first organic layer (also referred to as a hole transporting layer (HT) or an electron blocking layer (EBL)). The ratios of the compound HT1 and the compound HT2 in the first organic layer were 50 mass % and 50 mass %, respectively.

As described above, a hole transporting zone, which was formed by the first organic layer and the second organic layer containing the compound HT1 (common hole transporting zone material), was formed.

### Examples 2-2 to 2-4 and Comparative 2-1

Organic EL devices in Examples 2-2 to 2-4 and Comparative 2-1 were each produced in the same manner as in Example 2-1 except that the first host material in the first emitting layer was replaced with the first host material shown in Table 2.

The external quantum efficiency EQE of each of the produced organic EL devices was measured in the same manner as in Example 1-1. Table 2 shows the results.

TABLE 2

| | Hole transporting zone | | | | | | | |
|---|---|---|---|---|---|---|---|---|
| | | | Common hole | Emitting layer | | | | |
| | Second | First organic | transporting zone | First emitting layer | | | | |
| | organic layer | layer | material | First host material | | | | |
| | Compound | Compound | Compound | | S₁ | T₁ | Dipole | Ip |
| | Name | Name | Name | Name | [eV] | [eV] | [D] | [eV] |
| Comp. 2-1 | HT1 and | HT1 and | HT1 | BH1-ref | 2.96 | 2.02 | 0.29 | 5.88 |
| | HA1 | HT2 | | | | | | |
| Ex. 2-1 | HT1 and | HT1 and | HT1 | BH1-2 | 3.03 | 2.09 | 0.79 | 5.70 |
| | HA1 | HT2 | | | | | | |
| Ex. 2-2 | HT1 and | HT1 and | HT1 | BH1-3 | 3.08 | 2.06 | 0.75 | 5.75 |
| | HA1 | HT2 | | | | | | |
| Ex. 2-3 | HT1 and | HT1 and | HT1 | BH1-4 | 3.08 | 2.02 | 0.63 | 5.79 |
| | HA1 | HT2 | | | | | | |
| Ex. 2-4 | HT1 and | HT1 and | HT1 | BH1-5 | 3.07 | 2.04 | 0.70 | 5.78 |
| | HA1 | HT2 | | | | | | |

| | Emitting layer | | | | | | | |
|---|---|---|---|---|---|---|---|---|
| | | | | Second emitting layer | | | | |
| | First emitting layer | | | | | | Second | Device |
| | First emitting compound | | | Second host material | | | emitting | Evaluation |
| | | S₁ | T₁ | | S₁ | T₁ | compound | EQE |
| | Name | [eV] | [eV] | Name | [eV] | [eV] | Name | [%] |
| Comp. 2-1 | BD1 | 2.71 | 2.64 | BH2-1 | 3.01 | 1.82 | BD1 | 9.3 |
| Ex. 2-1 | BD1 | 2.71 | 2.64 | BH2-1 | 3.01 | 1.82 | BD1 | 10.3 |
| Ex. 2-2 | BD1 | 2.71 | 2.64 | BH2-1 | 3.01 | 1.82 | BD1 | 10.3 |
| Ex. 2-3 | BD1 | 2.71 | 2.64 | BH2-1 | 3.01 | 1.82 | BD1 | 10.2 |
| Ex. 2-4 | BD1 | 2.71 | 2.64 | BH2-1 | 3.01 | 1.82 | BD1 | 10.2 |

The organic EL devices in Examples 2-1 to 2-4 using the first host material of which dipole was 0.4 D or more emitted light at a higher luminous efficiency than the organic EL device in Comparative 2-1 using the first host material of which dipole was less than 0.4 D.

### Production 3 of Organic EL Device

### Example 3-1

The organic EL device in Example 3-1 was produced in the same manner as in Example 1-1 except that the hole transporting zone was formed as follows.

Similar to Example 1-1, after the glass substrate having the transparent electrode line was cleaned, the glass substrate was mounted on a substrate holder of a vacuum deposition apparatus. Firstly, the compound HT1, compound HT2, and compound HA1 were co-deposited on a surface of the glass substrate where the transparent electrode line was provided in a manner to cover the transparent electrode, thereby forming a 10-nm-thick second organic layer (also referred to as a hole injecting layer (HI)).

In the second organic layer, the ratio of the compound HT1 was 48.5 mass %, the ratio of the compound HT2 was 48.5 mass %, and the ratio of the compound HA1 was 3 mass %.

The compound HT1 and compound HT2 were co-deposited on the second organic layer to form a 90-nm-thick first organic layer (also referred to as a hole transporting layer (HT) or an electron blocking layer) (EBL). The ratios of the compound HT1 and the compound HT2 in the first organic layer were 50 mass % and 50 mass %, respectively.

As described above, a hole transporting zone, which was formed by the first organic layer and the second organic layer containing the compound HT1 and the compound HT2 (common hole transporting zone materials), was formed.

### Examples 3-2 to 3-4 and Comparative 3-1

Organic EL devices in Examples 3-2 to 3-4 and Comparative 3-1 were each produced in the same manner as in Example 3-1 except that the first host material in the first emitting layer was replaced with the first host material shown in Table 3.

The external quantum efficiency EQE of each of the produced organic EL devices was measured in the same manner as in Example 1-1. Table 3 shows the results.

TABLE 3

| | Hole transporting zone | | | | | | | |
|---|---|---|---|---|---|---|---|---|
| | | | Common hole | Emitting layer | | | | |
| | Second | First organic | transporting zone | First emitting layer | | | | |
| | organic layer | layer | material | First host material | | | | |
| | Compound | Compound | Compound | | S₁ | T₁ | Dipole | Ip |
| | Name | Name | Name | Name | [eV] | [eV] | [D] | [eV] |
| Comp. 3-1 | HT1, HT2 | HT1 and | HT1 and | BH1-ref | 2.96 | 2.02 | 0.29 | 5.88 |
| | and HA1 | HT2 | HT2 | | | | | |
| Ex. 3-1 | HT1, HT2 | HT1 and | HT1 and | BH1-2 | 3.03 | 2.09 | 0.79 | 5.70 |
| | and HA1 | HT2 | HT2 | | | | | |
| Ex. 3-2 | HT1, HT2 | HT1 and | HT1 and | BH1-3 | 3.08 | 2.06 | 0.75 | 5.75 |
| | and HA1 | HT2 | HT2 | | | | | |
| Ex. 3-3 | HT1, HT2 | HT1 and | HT1 and | BH1-4 | 3.08 | 2.02 | 0.63 | 5.79 |
| | and HA1 | HT2 | HT2 | | | | | |
| Ex. 3-4 | HT1, HT2 | HT1 and | HT1 and | BH1-5 | 3.07 | 2.04 | 0.70 | 5.78 |
| | and HA1 | HT2 | HT2 | | | | | |

| | Emitting layer | | | | | | | |
|---|---|---|---|---|---|---|---|---|
| | | | | Second emitting layer | | | | |
| | First emitting layer | | | | | | Second | Device |
| | First emitting compound | | | Second host material | | | emitting | Evaluation |
| | | S₁ | T₁ | | S₁ | T₁ | compound | EQE |
| | Name | [eV] | [eV] | Name | [eV] | [eV] | Name | [%] |
| Comp. 3-1 | BD1 | 2.71 | 2.64 | BH2-1 | 3.01 | 1.82 | BD1 | 9.4 |
| Ex. 3-1 | BD1 | 2.71 | 2.64 | BH2-1 | 3.01 | 1.82 | BD1 | 10.4 |
| Ex. 3-2 | BD1 | 2.71 | 2.64 | BH2-1 | 3.01 | 1.82 | BD1 | 10.3 |
| Ex. 3-3 | BD1 | 2.71 | 2.64 | BH2-1 | 3.01 | 1.82 | BD1 | 10.4 |
| Ex. 3-4 | BD1 | 2.71 | 2.64 | BH2-1 | 3.01 | 1.82 | BD1 | 10.2 |

The organic EL devices in Examples 3-1 to 3-4 using the first host material of which dipole was 0.4 D or more emitted light at a higher luminous efficiency than the organic EL device in Comparative 3-1 using the first host material of which dipole was less than 0.4 D.

### Production 4 of Organic EL Device

### Example 4-1

The organic EL device in Example 4-1 was produced in the same manner as in Example 1-1 except that the hole transporting zone was formed as follows.

Similar to Example 1-1, after the glass substrate having the transparent electrode line was cleaned, the glass substrate was mounted on a substrate holder of a vacuum deposition apparatus. Firstly, the compound HT1 and the compound HA1 were co-deposited on a surface of the glass substrate where the transparent electrode line was provided in a manner to cover the transparent electrode, thereby forming a 10-nm-thick third organic layer (also referred to as a hole injecting layer (HI)). The ratios of the compound HT1 and the compound HA1 in the third organic layer were 97 mass % and 3 mass %, respectively.

The compound HT1 was vapor-deposited on the third organic layer to form a 35-nm-thick second organic layer (also referred to as a hole transporting layer (HT)).

The compound HT1 and the compound HT2 were co-deposited on the second organic layer to form a 55-nm-thick first organic layer (also referred to as a hole transporting layer (HT) or an electron blocking layer (EBL)). The ratios of the compound HT1 and the compound HT2 in the first organic layer were 50 mass % and 50 mass %, respectively.

As described above, a hole transporting zone, which was formed by the first organic layer, the second organic layer, and the third organic layer that contain the compound HT1 (common hole transporting zone material), was formed.

### Examples 4-2 to 4-4 and Comparative 4-1

Organic EL devices in Examples 4-2 to 4-4 and Comparative 4-1 were each produced in the same manner as in Example 4-1 except that the first host material in the first emitting layer was replaced with the first host material shown in Table 4.

The external quantum efficiency EQE of each of the produced organic EL devices was measured in the same manner as in Example 1-1. Table 4 shows the results.

TABLE 4

| | Hole transporting zone | | | | | | | |
|---|---|---|---|---|---|---|---|---|
| | | | | Common hole | Emitting layer | | | |
| | Third organic | Second organic | First organic | transporting | First emitting layer | | | |
| | layer | layer | layer | zone material | First host material | | | |
| | Compound | Compound | Compound | Compound | | S₁ | T₁ | Dipole |
| | Name | Name | Name | Name | Name | [eV] | [eV] | [D] |
| Comp. 4-1 | HT1 and | HT1 | HT1 and | HT1 | BH1-ref | 2.96 | 2.02 | 0.29 |
| | HA1 | | HT2 | | | | | |
| Ex. 4-1 | HT1 and | HT1 | HT1 and | HT1 | BH1-2 | 3.03 | 2.09 | 0.79 |
| | HA1 | | HT2 | | | | | |
| Ex. 4-2 | HT1 and | HT1 | HT1 and | HT1 | BH1-3 | 3.08 | 2.06 | 0.75 |
| | HA1 | | HT2 | | | | | |
| Ex. 4-3 | HT1 and | HT1 | HT1 and | HT1 | BH1-4 | 3.08 | 2.02 | 0.63 |
| | HA1 | | HT2 | | | | | |
| Ex. 4-4 | HT1 and | HT1 | HT1 and | HT1 | BH1-5 | 3.07 | 2.04 | 0.70 |
| | HA1 | | HT2 | | | | | |

| | Emitting layer | | | | | | | | |
|---|---|---|---|---|---|---|---|---|---|
| | | | | | Second emitting layer | | | | |
| | First emitting layer | | | | | | | Second | Device |
| | First host material | First emitting compound | | | Second host material | | | emitting | Evaluation |
| | Ip | | S₁ | T₁ | | S₁ | T₁ | compound | EQE |
| | [eV] | Name | [eV] | [eV] | Name | [eV] | [eV] | Name | [%] |
| Comp. 4-1 | 5.88 | BD1 | 2.71 | 2.64 | BH2-1 | 3.01 | 1.82 | BD1 | 9.7 |
| Ex. 4-1 | 5.70 | BD1 | 2.71 | 2.64 | BH2-1 | 3.01 | 1.82 | BD1 | 10.9 |
| Ex. 4-2 | 5.75 | BD1 | 2.71 | 2.64 | BH2-1 | 3.01 | 1.82 | BD1 | 10.8 |
| Ex. 4-3 | 5.79 | BD1 | 2.71 | 2.64 | BH2-1 | 3.01 | 1.82 | BD1 | 10.9 |
| Ex. 4-4 | 5.78 | BD1 | 2.71 | 2.64 | BH2-1 | 3.01 | 1.82 | BD1 | 10.8 |

The organic EL devices in Examples 4-1 to 4-4 using the first host material of which dipole was 0.4 D or more emitted light at a higher luminous efficiency than the organic EL device in Comparative 4-1 using the first host material of which dipole was less than 0.4 D.

### Evaluation Method of Compounds

### Triplet Energy T₁

A measurement target compound was dissolved in EPA (diethylether:isopentane:ethanol=5:5:2 in volume ratio) at a concentration of 10 μmol/L, and the obtained solution was put in a quartz cell to provide a measurement sample. A phosphorescence spectrum (ordinate axis: phosphorescent luminous intensity, abscissa axis: wavelength) of the measurement sample was measured at a low temperature (77K). A tangent was drawn to the rise of the phosphorescence spectrum close to the short-wavelength region. An energy amount was calculated by a conversion equation (F1) below on a basis of a wavelength value λ_{edge} [nm] at an intersection of the tangent and the abscissa axis. The calculated energy amount was defined as triplet energy T₁. It should be noted that the triplet energy T₁ may have an error of about plus or minus 0.02 eV depending on measurement conditions.

T₁ [eV]=1239.85/λ_{edge} Conversion Equation (F1):

The tangent to the rise of the phosphorescence spectrum close to the short-wavelength region is drawn as follows. While moving on a curve of the phosphorescence spectrum from the short-wavelength region to the local maximum value closest to the short-wavelength region among the local maximum values of the phosphorescence spectrum, a tangent is checked at each point on the curve toward the long-wavelength of the phosphorescence spectrum. An inclination of the tangent is increased along the rise of the curve (i.e., a value of the ordinate axis is increased). A tangent drawn at a point of the local maximum inclination (i.e., a tangent at an inflection point) is defined as the tangent to the rise of the phosphorescence spectrum close to the short-wavelength region.

A local maximum point where a peak intensity is 15% or less of the maximum peak intensity of the spectrum is not counted as the above-mentioned local maximum peak intensity closest to the short-wavelength region. The tangent drawn at a point that is closest to the local maximum peak intensity closest to the short-wavelength region and where the inclination of the curve is the local maximum is defined as a tangent to the rise of the phosphorescence spectrum close to the short-wavelength region.

For phosphorescence measurement, a spectrophotofluorometer body F-4500 produced by Hitachi High-Technologies Corporation was used.

### Singlet Energy S₁

A toluene solution of a measurement target compound at a concentration of 10 μmol/L was prepared and put in a quartz cell. An absorption spectrum (ordinate axis: absorption intensity, abscissa axis: wavelength) of the thus-obtained sample was measured at a normal temperature (300K). A tangent was drawn to the fall of the absorption spectrum close to the long-wavelength region, and a wavelength value λ_{edge} (nm) at an intersection of the tangent and the abscissa axis was assigned to a conversion equation (F2) below to calculate singlet energy.

S₁ [eV]=1239.85/λ_{edge} Conversion Equation (F2):

A spectrophotometer (U3310 produced by Hitachi, Ltd.) was used for measuring absorption spectrum.

The tangent to the fall of the absorption spectrum close to the long-wavelength region is drawn as follows. While moving on a curve of the absorption spectrum from the local maximum value closest to the long-wavelength region, among the local maximum values of the absorption spectrum, in a long-wavelength direction, a tangent at each point on the curve is checked. An inclination of the tangent is decreased and increased in a repeated manner as the curve falls (i.e., a value of the ordinate axis is decreased). A tangent drawn at a point where the inclination of the curve is the local minimum closest to the long-wavelength region (except when absorbance is 0.1 or less) is defined as the tangent to the fall of the absorption spectrum close to the long-wavelength region.

The local maximum absorbance of 0.2 or less is not counted as the above-mentioned local maximum absorbance closest to the long-wavelength region.

### Dipole D

The dipole D of the compound was calculated using a quantum chemical calculation program [Gaussian 16, Revision B.01 (Gaussian Inc.); computational method: B3LYP/6-31G*] (which means that B3LYP was used for the theory and 6-31G* was used for the basis function).

### Ionization Potential Ip

The ionization potential Ip of the compound was measured in atmosphere using a photoelectron spectroscope (“AC-3” produced by RIKEN KEIKI Co., Ltd.). Specifically, the material was irradiated with light and the amount of electrons generated by charge separation was measured to measure the ionization potential of the compound. The ionization potential is also denoted by Ip.

### Measurement of Maximum Fluorescence Peak Wavelength (FL-Peak)

The compound BD1 was dissolved in toluene at a concentration of 4.9×10⁻⁶ mol/L to prepare a toluene solution of the compound BD1. Using a fluorescence spectrometer (spectrophotofluorometer F-7000 produced by Hitachi High-Tech Science Corporation), the toluene solution of the compound BD1 was excited at 390 nm, where a maximum fluorescence peak wavelength was measured.

The maximum fluorescence peak wavelength of the compound BD1 was 455 nm.

### EXPLANATION OF CODES

1, 1B, 1C . . . organic electroluminescence device, 10, 12, 13 . . . organic layer, 2, 2A . . . substrate, 3 . . . anode, 4 . . . cathode, 5 . . . emitting region, 6, 6A, 6B, 7 . . . hole transporting zone, 8 . . . electron transporting layer, 9 . . . electron injecting layer, 10B . . . blue-emitting organic EL device, 10G, 20G . . . green-emitting organic EL device, 10R, 20R . . . red-emitting organic EL device, 51 . . . first emitting layer, 52 . . . second emitting layer, 53 . . . green emitting layer, 54 . . . red emitting layer, 61 . . . first organic layer, 62 . . . second organic layer, 63 . . . third organic layer, 100A, 200 . . . organic EL display device, 531 . . . green organic layer, 541 . . . red organic layer.

1. An organic electroluminescence device, comprising:
an anode;
a cathode;
an emitting region disposed between the anode and the cathode; and
a hole transporting zone disposed between the anode and the emitting region, wherein
the emitting region comprises a first emitting layer and a second emitting layer,
the first emitting layer is disposed close to the anode in the emitting region,
the hole transporting zone is in direct contact with the anode and the first emitting layer,
the hole transporting zone comprises one or more organic layers,
at least one of the one or more organic layers in the hole transporting zone is a first organic layer that is in direct contact with the first emitting layer,
the first organic layer comprises a hole transporting zone material,
the first emitting layer comprises a first host material and a first emitting compound that emits light having a maximum peak wavelength of 500 nm or less,
the second emitting layer comprises a second host material and a second emitting compound that emits light having a maximum peak wavelength of 500 nm or less,
the first host material is different from the second host material,
the first emitting compound and the second emitting compound are mutually the same or different,
a triplet energy of the first host material T₁(H1) and a triplet energy of the second host material T₁(H2) satisfy a relationship of a numerical formula (Numerical Formula 1) below, and
in the emitting region, a dipole of the first host material comprised in the first emitting layer is 0.4 D or more,
T₁(H1)>T₁(H2) (Numerical Formula 1).

2. The organic electroluminescence device according to claim 1, wherein
each of the one or more organic layers in the hole transporting zone comprises the hole transporting zone material as a common hole transporting zone material.

3. The organic electroluminescence device according to claim 1, wherein
the hole transporting zone comprises the first organic layer and a second organic layer disposed between the first organic layer and the anode, and
the second organic layer comprises the hole transporting zone material and further comprises a second hole transporting zone material different from the hole transporting zone material.

4. The organic electroluminescence device according to claim 3, wherein
the second organic layer is in direct contact with the anode.

5. The organic electroluminescence device according to claim 3, wherein
the hole transporting zone comprises the first organic layer, the second organic layer, and a third organic layer disposed between the second organic layer and the anode, and
the third organic layer comprises the hole transporting zone material and further comprises a third hole transporting zone material different from the hole transporting zone material.

6. The organic electroluminescence device according to claim 1, wherein
the first organic layer comprises the hole transporting zone material and a first hole transporting zone material different from the hole transporting zone material.

7. The organic electroluminescence device according to claim 1, wherein
the hole transporting zone comprises no material different from the hole transporting zone material.

8. The organic electroluminescence device according to claim 1, wherein
an ionization potential of the first host material comprised in the first emitting layer is smaller than 5.85 eV.

9. The organic electroluminescence device according to claim 1, wherein
the first host material comprised in the first emitting layer comprises a heterocyclic structure in which an oxygen atom or a sulfur atom is comprised in a molecule.

10. The organic electroluminescence device according to claim 1, wherein
a singlet energy of the first host material S₁(H1) and a singlet energy of the first emitting compound S₁(D1) satisfy a relationship of a numerical formula (Numerical Formula 20) below,
S₁(H1)>S₁(D1) (Numerical Formula 20).

11. The organic electroluminescence device according to claim 1, wherein
the triplet energy of the first host material T₁(H1) and a triplet energy of the first emitting compound T₁(D1) satisfy a relationship of a numerical formula (Numerical Formula 20A) below,
T₁(D1)>T₁(H1) (Numerical Formula 20A).

12. The organic electroluminescence device according to claim 1, wherein
the first emitting layer and the second emitting layer are in direct contact with each other.

13. An organic electroluminescence display device, comprising:
an anode and a cathode arranged opposite each other;
a blue-emitting organic EL device as a blue pixel;
a green-emitting organic EL device as a green pixel; and
a red-emitting organic EL device as a red pixel, wherein
the blue-emitting organic EL device comprises a blue emitting region comprising a first emitting layer and a second emitting layer provided between the anode and the cathode,
the first emitting layer is disposed close to the anode in the blue emitting region,
the green-emitting organic EL device comprises a green emitting layer provided between the anode and the cathode,
the red-emitting organic EL device comprises a red emitting layer provided between the anode and the cathode,
a hole transporting zone is provided between the anode and the blue emitting region of the blue-emitting organic EL device, the green emitting layer of the green-emitting organic EL device, and the red emitting layer of the red-emitting organic EL device in a shared manner across the blue-emitting organic EL device, the green-emitting organic EL device, and the red-emitting organic EL device,
the hole transporting zone is in direct contact with the first emitting layer in the blue emitting region of the blue-emitting organic EL device,
the hole transporting zone comprises one or more organic layers,
the first emitting layer comprises a first host material and a first emitting compound that emits light having a maximum peak wavelength of 500 nm or less,
the second emitting layer comprises a second host material and a second emitting compound that emits light having a maximum peak wavelength of 500 nm or less,
the first host material is different from the second host material,
the first emitting compound and the second emitting compound are mutually the same or different,
a triplet energy of the first host material T₁(H1) and a triplet energy of the second host material T₁(H2) satisfy a relationship of a numerical formula (Numerical Formula 1) below, and
in the blue emitting region of the blue-emitting organic EL device, a dipole of the first host material comprised in the first emitting layer is 0.4 D or more,
T₁(H1)>T₁(H2) (Numerical Formula 1).

14. The organic electroluminescence display device according to claim 13, wherein
at least one of the one or more organic layers in the hole transporting zone comprises a hole transporting zone material, and
a hole mobility of the hole transporting zone material is 1.0×10⁻⁵ cm²/Vs or more.

15. The organic electroluminescence display device according to claim 13, further comprising a green organic layer between the green emitting layer and the hole transporting zone.

16. The organic electroluminescence display device according to claim 13, further comprising a red organic layer between the red emitting layer and the hole transporting zone.

17. The organic electroluminescence display device according to claim 13, wherein at least one of the green-emitting organic EL device or the red-emitting organic EL device comprises a delayed fluorescent compound.

18. The organic electroluminescence display device according to claim 13, wherein at least one of the green emitting layer of the green-emitting organic EL device or the red emitting layer of the red-emitting organic EL device comprises a delayed fluorescent compound.

19. The organic electroluminescence display device according to claim 18, wherein
the emitting layer comprising the delayed fluorescent compound comprises a first organic material of which affinity is smaller than an affinity of the delayed fluorescent compound.

20. The organic electroluminescence display device according to claim 18, wherein at least one of the green emitting layer or the red emitting layer comprising no delayed fluorescent compound comprises a phosphorescent compound.

21. An electronic device comprising the organic electroluminescence device according to claim 1.

22. An electronic device comprising the organic electroluminescence display device according to claim 13.
